(19) United States
(12) Patent Application Publication
(10) Pub. No.: US 2023/0371374 A1
(43) Pub. Date: Nov. 16, 2023

(54) PLURALITY OF HOST MATERIALS AND ORGANIC ELECTROLUMINESCENT DEVICE COMPRISING THE SAME

(71) Applicant: ROHM AND HAAS ELECTRONIC MATERIALS KOREA LTD., Chungcheongnam-do (KR)

(72) Inventors: Sang-Hee CHO, Gyeonggi-do (KR); Young-Jae KIM, Gyeonggi-do (KR); Hae-Yeon KIM, Gyeonggi-do (KR); So-Young JUNG, Gyeonggi-do (KR); Su-Hyun LEE, Gyeonggi-do (KR); Mi-Ja LEE, Gyeonggi-do (KR); So-Mi PARK, Gyeonggi-do (KR); Young-Gil KIM, Gyeonggi-do (KR); Hong-Se OH, Gyeonggi-do (KR); Hyo-Soon PARK, Gyeonggi-do (KR)

(21) Appl. No.: 18/310,062

(22) Filed: May 1, 2023

(30) Foreign Application Priority Data
May 10, 2022 (KR) 10-2022-0057242
Aug. 18, 2022 (KR) 10-2022-0103141
Apr. 3, 2023 (KR) 10-2023-0043477

(51) Int. Cl. H10K 85/60; H10K 85/40; H10K 85/30; C09K 11/02; C09K 11/06

(52) U.S. Cl. CPC H10K 85/6574; H10K 85/633; H10K 85/6576; H10K 85/615; H10K 85/6572; H10K 85/622; H10K 85/654; H10K 85/40; H10K 85/30; C09K 11/02; C09K 11/06; C07B 2200/05; C09K 2211/1022; C09K 2211/188

(57) ABSTRACT

The present disclosure relates to a plurality of host materials comprising a first host compound represented by formula 1 and a second host compound represented by formula 2 and an organic electroluminescent device comprising the same. By comprising the specific combination of the compound according to the present disclosure as host materials, an organic electroluminescent device having low driving voltage and/or high luminous efficiency and/or significantly improved lifespan characteristics can be provided.

### TECHNICAL FIELD

The present disclosure relates to a plurality of host materials and organic electroluminescent device comprising the same.

### BACKGROUND ART

The TPD/Alq₃ bilayer small molecule organic electroluminescent device (OLED) with green-emission, which is constituted with a light-emitting layer and a charge transport layer, was first developed by Tang, et al., of Eastman Kodak in 1987. Thereafter, the studies on an OLED have been rapidly effected, and OLEDs have been commercialized. At present, an organic electroluminescent device mainly includes phosphorescent materials having excellent luminous efficiency in panel realization. In many applications such as TVs and lightings, OLED lifespan is insufficient, and high efficiency of OLEDs is still required.

Typically, the higher the luminance of an OLED corresponds to a shorter lifespan of the OLED. Accordingly, for prolonged use and high resolution of the display, an OLED having high luminous efficiency and/or long lifespan is necessary.

Korean Patent No. 10-2244170 discloses a plurality of host materials. However, said reference does not specifically disclose a specific combination of host materials as described in the present disclosure.

### DISCLOSURE OF THE INVENTION

### Problems to be Solved

The object of the present disclosure is firstly, to provide a plurality of host materials which is able to produce an organic electroluminescent device having low driving voltage and/or high luminous efficiency and/or long lifespan characteristics, and secondly, to provide an organic electroluminescent device with low driving voltage and/or high luminous efficiency and/or long lifespan characteristics by comprising a specific combination of compounds according to the present disclosure as host materials.

### Solution to Problems

As a result of intensive studies to solve the technical problem above, the present inventors found that the aforementioned objective can be achieved by a plurality of host materials comprising at least one first host compound represented by the following formula 1 and at least one second host compound represented by the following formula 2, so that the present invention was completed.

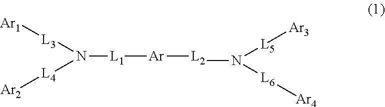

in formula 1,

Ar represents a substituted or unsubstituted (C6-C30)arylene or a substituted or unsubstituted (3- to 30-membered)heteroarylene;

L₁ to L₆ each independently represent, a single bond, a substituted or unsubstituted (C6-C30)arylene, a substituted or unsubstituted (C3-C30)cycloalkylene, or a substituted or unsubstituted (3- to 30-membered)heteroarylene; and

Ar₁ to Ar₄ each independently represent, deuterium, a substituted or unsubstituted (C1-C30)alkyl, a substituted or unsubstituted (C6-C30)aryl, a substituted or unsubstituted fused ring of (C3-C30) aliphatic ring and (C6-C30) aromatic ring, or a substituted or unsubstituted (3- to 30-membered)heteroaryl; or may be linked to the adjacent substituents to form a ring(s);

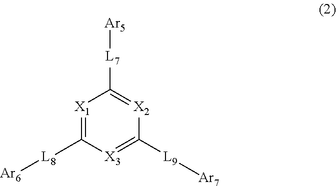

in formula 2,

X₁ to X₃ each independently represent, N or CH;

L₇ to L₉ each independently represent, a single bond, a substituted or unsubstituted (C6-C30)arylene, a substituted or unsubstituted (C3-C30)cycloalkylene, or a substituted or unsubstituted (3- to 30-membered)heteroarylene;

Ar₅ to Ar₇ each independently represent, hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or —N—(R′)(R″); or may be linked to the adjacent substituents to form a ring(s); provided that at least one of Ar₅ to Ar₇ is(are) a substituted or unsubstituted (3- to 30-membered)heteroaryl; and

R′ and R″ each independently represent, a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl.

### Advantageous Effects of Invention

By using the specific combination of the compounds according to the present disclosure as host materials, an organic electroluminescent device having low driving voltage and/or high luminous efficiency and/or significantly improved lifespan characteristics can be provided.

### EMBODIMENTS OF THE INVENTION

Hereinafter, the present disclosure will be described in detail. However, the following description is intended to explain the invention, and is not meant in any way to restrict the scope of the invention.

The present disclosure relates to a plurality of host materials comprising a first host compound containing at least one compound represented by formula 1 and a second host compound containing at least one compound represented by formula 2, and an organic electroluminescent device comprising the host materials.

The present disclosure relates to an organic electroluminescent compound represented by formula 1′ and an organic electroluminescent material comprising the same, and an organic electroluminescent device.

The term “organic electroluminescent compound” in the present disclosure means a compound that may be used in an organic electroluminescent device, and may be comprised in any material layer constituting an organic electroluminescent device, as necessary.

Herein, the term “organic electroluminescent material” means a material that may be used in an organic electroluminescent device, and may comprise at least one compound. The organic electroluminescent material may be comprised in any layer constituting an organic electroluminescent device, as necessary. For example, the organic electroluminescent material may be a hole injection material, a hole transport material, a hole auxiliary material, a light-emitting auxiliary material, an electron blocking material, a light-emitting material (containing host and dopant materials), an electron buffer material, a hole blocking material, an electron transport material, or an electron injection material, etc.

The term “a plurality of organic electroluminescent materials” in the present disclosure means an organic electroluminescent material comprising a combination of at least two compounds, which may be comprised in any layer constituting an organic electroluminescent device. It may mean both a material before being comprised in an organic electroluminescent device (for example, before vapor deposition) and a material after being comprised in an organic electroluminescent device (for example, after vapor deposition). For example, a plurality of organic electroluminescent materials may be a combination of at least two compounds, which may be comprised in at least one layer of a hole injection layer, a hole transport layer, a hole auxiliary layer, a light-emitting auxiliary layer, an electron blocking layer, a light-emitting layer, an electron buffer layer, a hole blocking layer, an electron transport layer, and an electron injection layer. Such at least two compounds may be comprised in the same layer or in different layers, and may be mixture-evaporated or co-evaporated, or may be individually evaporated.

Herein, the term “a plurality of host materials” means an organic electroluminescent material comprising a combination of at least two host materials. It may mean both a material before being comprised in an organic electroluminescent device (e.g., before vapor deposition) and a material after being comprised in an organic electroluminescent device (e.g., after vapor deposition). A plurality of host materials of the present disclosure may be comprised in any light-emitting layer constituting an organic electroluminescent device. The at least two compounds comprised in a plurality of host materials may be comprised together in one light-emitting layer, or may each be comprised in separate light-emitting layers. When at least two host materials are comprised in one light-emitting layer, the at least two host materials may be mixture-evaporated to form a layer or may be individually and simultaneously co-evaporated to form a layer.

Herein, “(C1-C30)alkyl” is meant to be a linear or branched alkyl having 1 to 30 carbon atoms constituting the chain, in which the number of carbon atoms is preferably 1 to 20, and more preferably 1 to 10. The above alkyl may include methyl, ethyl, n-propyl, isopropyl, n-butyl, isobutyl, tert-butyl, sec-butyl, etc. Herein, the term “(C3-C30)cycloalkyl(ene)” is meant to be a mono- or polycyclic hydrocarbon having 3 to 30 ring backbone carbon atoms, in which the number of carbon atoms is preferably 3 to 20, and more preferably 3 to 7. The above cycloalkyl may include cyclopropyl, cyclobutyl, cyclopentyl, cyclohexyl, cyclopentylmethyl, cyclohexylmethyl, etc. Herein, “(3- to 7-membered)heterocycloalkyl” is meant to be a cycloalkyl having 3 to 7 ring backbone atoms and including at least one heteroatoms selected from the group consisting of B, N, O, S, Si, and P, preferably the group consisting of O, S and N, in which the number of the ring backbone carbon atoms is preferably 5 to 7, for example, tetrahydrofuran, pyrrolidine, thiolane, tetrahydropyran, etc. Herein, “(C6-C30)aryl(ene)” is a monocyclic or fused ring radical derived from an aromatic hydrocarbon having 6 to 30 ring backbone carbon atoms, in which the number of the ring backbone carbon atoms is preferably 6 to 20, more preferably 6 to 15, may be partially saturated, and may include a spiro structure. Examples of the aryl specifically may be phenyl, biphenyl, terphenyl, quaterphenyl, naphthyl, binaphthyl, phenylnaphthyl, naphthylphenyl, fluorenyl, phenylfluorenyl, dimethylfluorenyl, diphenylfluorenyl, benzofluorenyl, diphenylbenzofluorenyl, dibenzofluorenyl, phenanthrenyl, benzophenanthrenyl, phenylphenanthrenyl, anthracenyl, benzanthracenyl, indenyl, triphenylenyl, pyrenyl, tetracenyl, perylenyl, chrysenyl, benzochrysenyl, naphthacenyl, fluoranthenyl, benzofluoranthenyl, tolyl, xylyl, mesityl, cumenyl, spiro[fluoren-fluoren]yl, spiro[fluoren-benzofluoren]yl, azulenyl, tetramethyl-dihydrophenanthrenyl, etc. More specifically, the aryl may be o-tolyl, m-tolyl, p-tolyl, 2,3-xylyl, 3,4-xylyl, 2,5-xylyl, mesityl, o-cumenyl, m-cumenyl, p-cumenyl, p-t-butylphenyl, p-(2-phenylpropyl)phenyl, 4′-methylbiphenyl, 4″-t-butyl-p-terphenyl-4-yl, o-biphenyl, m-biphenyl, p-biphenyl, o-terphenyl, m-terphenyl-4-yl, m-terphenyl-3-yl, m-terphenyl-2-yl, p-terphenyl-4-yl, p-terphenyl-3-yl, p-terphenyl-2-yl, m-quaterphenyl, 1-naphthyl, 2-naphthyl, 1-fluorenyl, 2-fluorenyl, 3-fluorenyl, 4-fluorenyl, 9-fluorenyl, 9,9-dimethyl-1-fluorenyl, 9,9-dimethyl-2-fluorenyl, 9,9-dimethyl-3-fluorenyl, 9,9-dimethyl-4-fluorenyl, 9,9-diphenyl-1-fluorenyl, 9,9-diphenyl-2-fluorenyl, 9,9-diphenyl-3-fluorenyl, 9,9-diphenyl-4-fluorenyl, 1-anthryl, 2-anthryl, 9-anthryl, 1-phenanthryl, 2-phenanthryl, 3-phenanthryl, 4-phenanthryl, 9-phenanthryl, 1-chrysenyl, 2-chrysenyl, 3-chrysenyl, 4-chrysenyl, 5-chrysenyl, 6-chrysenyl, benzo[c]phenanthryl, benzo[g]chrysenyl, 1-triphenylenyl, 2-triphenylenyl, 3-triphenylenyl, 4-triphenylenyl, 3-fluoranthenyl, 4-fluoranthenyl, 8-fluoranthenyl, 9-fluoranthenyl, benzofluoranthenyl, 11,11-dimethyl-1-benzo[a]fluorenyl, 11,11-dimethyl-2-benzo[a]fluorenyl, 11,11-dimethyl-3-benzo[a]fluorenyl, 11,11-dimethyl-4-benzo[a]fluorenyl, 11,11-dimethyl-5-benzo[a]fluorenyl, 11,11-dimethyl-6-benzo[a]fluorenyl, 11,11-dimethyl-7-benzo[a]fluorenyl, 11,11-dimethyl-8-benzo[a]fluorenyl, 11,11-dimethyl-9-benzo[a]fluorenyl, 11,11-dimethyl-10-benzo[a]fluorenyl, 11,11-dimethyl-1-benzo[b]fluorenyl, 11,11-dimethyl-2-benzo[b]fluorenyl, 11,11-dimethyl-3-benzo[b]fluorenyl, 11,11-dimethyl-4-benzo[b]fluorenyl, 11,11-dimethyl-5-benzo[b]fluorenyl, 11,11-dimethyl-6-benzo[b]fluorenyl, 11,11-dimethyl-7-benzo[b]fluorenyl, 11,11-dimethyl-8-benzo[b]fluorenyl, 11,11-dimethyl-9-benzo[b]fluorenyl, 11,11-dimethyl-10-benzo[b]fluorenyl, 11,11-dimethyl-1-benzo[c]fluorenyl, 11,11-dimethyl-2-benzo[c]fluorenyl, 11,11-dimethyl-3-benzo[c]fluorenyl, 11,11-dimethyl-4-benzo[c]fluorenyl, 11,11-dimethyl-5-benzo[c]fluorenyl, 11,11-dimethyl-6-benzo[c]fluorenyl, 11,11-dimethyl-7-benzo[c]fluorenyl, 11,11-dimethyl-8-benzo[c]fluorenyl, 11,11-dimethyl-9-benzo[c]fluorenyl, 11,11-dimethyl-10-benzo[c]fluorenyl, 11,11-diphenyl-1-benzo[a]fluorenyl, 11,11-diphenyl-2-benzo[a]fluorenyl, 11,11-diphenyl-3-benzo[a]fluorenyl, 11,11-diphenyl-4-benzo[a]fluorenyl, 11,11-diphenyl-5-benzo[a]fluorenyl, 11,11-diphenyl-6-benzo[a]fluorenyl, 11,11-diphenyl-7-benzo[a]fluorenyl, 11,11-diphenyl-8-benzo[a]fluorenyl, 11,11-diphenyl-9-benzo[a]fluorenyl, 11,11-diphenyl-10-benzo[a]fluorenyl, 11,11-diphenyl-1-benzo[b]fluorenyl, 11,11-diphenyl-2-benzo[b]fluorenyl, 11,11-diphenyl-3-benzo[b]fluorenyl, 11,11-diphenyl-4-benzo[b]fluorenyl, 11,11-diphenyl-5-benzo[b]fluorenyl, 11,11-diphenyl-6-benzo[b]fluorenyl, 11,11-diphenyl-7-benzo[b]fluorenyl, 11,11-diphenyl-8-benzo[b]fluorenyl, 11,11-diphenyl-9-benzo[b]fluorenyl, 11,11-diphenyl-10-benzo[b]fluorenyl, 11,11-diphenyl-1-benzo[c]fluorenyl, 11,11-diphenyl-2-benzo[c]fluorenyl, 11,11-diphenyl-3-benzo[c]fluorenyl, 11,11-diphenyl-4-benzo[c]fluorenyl, 11,11-diphenyl-5-benzo[c]fluorenyl, 11,11-diphenyl-6-benzo[c]fluorenyl, 11,11-diphenyl-7-benzo[c]fluorenyl, 11,11-diphenyl-8-benzo[c]fluorenyl, 11,11-diphenyl-9-benzo[c]fluorenyl, 11,11-diphenyl-10-benzo[c]fluorenyl, 9,9,10,10-tetramethyl-9,10-dihydro-1-phenanthrenyl, 9,9,10,10-tetramethyl-9,10-dihydro-2-phenanthrenyl, 9,9,10,10-tetramethyl-9,10-dihydro-3-phenanthrenyl, 9,9,10,10-tetramethyl-9,10-dihydro-4-phenanthrenyl, etc. Herein, “(3- to 30-membered)heteroaryl(ene)” is an aryl having 3 to 30 ring backbone atoms and including at least one, preferably 1 to 4 heteroatoms selected from the group consisting of B, N, O, S, Si, P, Se, and Ge, in which the number of the ring backbone carbon atoms is preferably 3 to 30, and more preferably 5 to 20. The above heteroaryl(ene) may be a monocyclic ring, or a fused ring condensed with at least one benzene ring; and may be partially saturated. Also, the above heteroaryl or heteroarylene herein may be one formed by linking at least one heteroaryl or aryl group to a heteroaryl group via a single bond(s), and may comprise a spiro structure. Examples of the heteroaryl specifically may be a monocyclic ring-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl including benzofuranyl, benzothiophenyl, isobenzofuranyl, dibenzofuranyl, dibenzothiophenyl, dibenzoselenophenyl, benzofuroquinolinyl, benzofuroquinazolinyl, benzofuronaphthiridinyl, benzofuropyrimidinyl, naphthofuropyrimidinyl, benzothienoquinolinyl, benzothienoquinazolinyl, benzothienonaphthiridinyl, benzothienopyrimidinyl, naphthothienopyrimidinyl, pyrimidoindolyl, benzopyrimidoindolyl, benzofuropyrazinyl, naphthofuropyrazinyl, benzothienopyrazinyl, naphthothienopyrazinyl, pyrazinoindolyl, benzopyrazinoindolyl, benzoimidazolyl, benzothiazolyl, benzoisothiazolyl, benzoisoxazolyl, benzoxazolyl, imidazopyridinyl, isoindolyl, indolyl, benzoindolyl, indazolyl, benzothiadiazolyl, quinolyl, isoquinolyl, cinnolinyl, quinazolinyl, quinoxalinyl, carbazolyl, azacarbazolyl, benzocarbazolyl, dibenzocarbazolyl, phenoxazinyl, phenanthridinyl, benzodioxolyl, indolizidinyl, acridinyl, silafluorenyl, germafluorenyl, benzotriazolyl, phenazinyl, imidazopyridinyl, chromenoquinazolinyl, thiochromenoquinazolinyl, dimethylbenzopyrimidinyl, indolocarbazolyl, indenocarbazolyl, etc. More specifically, the heteroaryl may be 1-pyrrolyl, 2-pyrrolyl, 3-pyrrolyl, 2-pyridinyl, 3-pyridinyl, 4-pyridinyl, 2-pyrimidinyl, 4-pyrimidinyl, 5-pyrimidinyl, 6-pyrimidinyl, 1,2,3-triazin-4-yl, 1,2,4-triazin-3-yl, 1,3,5-triazin-2-yl, 1-imidazolyl, 2-imidazolyl, 1-pyrazolyl, 1-indolizidinyl, 2-indolizidinyl, 3-indolizidinyl, 5-indolizidinyl, 6-indolizidinyl, 7-indolizidinyl, 8-indolizidinyl, 2-imidazopyridinyl, 3-imidazopyridinyl, 5-imidazopyridinyl, 6-imidazopyridinyl, 7-imidazopyridinyl, 8-imidazopyridinyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 2-quinolyl, 3-quinolyl, 4-quinolyl, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyl, 2-carbazolyl, 3-carbazolyl, 4-carbazolyl, 9-carbazolyl, azacarbazol-1-yl, azacarbazol-2-yl, azacarbazol-3-yl, azacarbazol-4-yl, azacarbazol-5-yl, azacarbazol-6-yl, azacarbazol-7-yl, azacarbazol-8-yl, azacarbazol-9-yl, 1-phenanthridinyl, 2-phenanthridinyl, 3-phenanthridinyl, 4-phenanthridinyl, 6-phenanthridinyl, 7-phenanthridinyl, 8-phenanthridinyl, 9-phenanthridinyl, 10-phenanthridinyl, 1-acridinyl, 2-acridinyl, 3-acridinyl, 4-acridinyl, 9-acridinyl, 2-oxazolyl, 4-oxazolyl, 5-oxazolyl, 2-oxadiazolyl, 5-oxadiazolyl, 3-furazanyl, 2-thienyl, 3-thienyl, 2-methylpyrrol-1-yl, 2-methylpyrrol-3-yl, 2-methylpyrrol-4-yl, 2-methylpyrrol-5-yl, 3-methylpyrrol-1-yl, 3-methylpyrrol-2-yl, 3-methylpyrrol-4-yl, 3-methylpyrrol-5-yl, 2-t-butylpyrrol-4-yl, 3-(2-phenylpropyl)pyrrol-1-yl, 2-methyl-1-indolyl, 4-methyl-1-indolyl, 2-methyl-3-indolyl, 4-methyl-3-indolyl, 2-t-butyl-1-indolyl, 4-t-butyl-1-indolyl, 2-t-butyl-3-indolyl, 4-t-butyl-3-indolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-naphtho-[1,2-b]-benzofuranyl, 2-naphtho-[1,2-b]-benzofuranyl, 3-naphtho-[1,2-b]-benzofuranyl, 4-naphtho-[1,2-b]-benzofuranyl, 5-naphtho-[1,2-b]-benzofuranyl, 6-naphtho-[1,2-b]-benzofuranyl, 7-naphtho-[1,2-b]-benzofuranyl, 8-naphtho-[1,2-b]-benzofuranyl, 9-naphtho-[1,2-b]-benzofuranyl, 10-naphtho-[1,2-b]-benzofuranyl, 1-naphtho-[2,3-b]-benzofuranyl, 2-naphtho-[2,3-b]-benzofuranyl, 3-naphtho-[2,3-b]-benzofuranyl, 4-naphtho-[2,3-b]-benzofuranyl, 5-naphtho-[2,3-b]-benzofuranyl, 6-naphtho-[2,3-b]-benzofuranyl, 7-naphtho-[2,3-b]-benzofuranyl, 8-naphtho-[2,3-b]-benzofuranyl, 9-naphtho-[2,3-b]-benzofuranyl, 10-naphtho-[2,3-b]-benzofuranyl, 1-naphtho-[2,1-b]-benzofuranyl, 2-naphtho-[2,1-b]-benzofuranyl, 3-naphtho-[2,1-b]-benzofuranyl, 4-naphtho-[2,1-b]-benzofuranyl, 5-naphtho-[2,1-b]-benzofuranyl, 6-naphtho-[2,1-b]-benzofuranyl, 7-naphtho-[2,1-b]-benzofuranyl, 8-naphtho-[2,1-b]-benzofuranyl, 9-naphtho-[2,1-b]-benzofuranyl, 10-naphtho-[2,1-b]-benzofuranyl, 1-naphtho-[1,2-b]-benzothiophenyl, 2-naphtho-[1,2-b]-benzothiophenyl, 3-naphtho-[1,2-b]-benzothiophenyl, 4-naphtho-[1,2-b]-benzothiophenyl, 5-naphtho-[1,2-b]-benzothiophenyl, 6-naphtho-[1,2-b]-benzothiophenyl, 7-naphtho-[1,2-b]-benzothiophenyl, 8-naphtho-[1,2-b]-benzothiophenyl, 9-naphtho-[1,2-b]-benzothiophenyl, 10-naphtho-[1,2-b]-benzothiophenyl, 1-naphtho-[2,3-b]-benzothiophenyl, 2-naphtho-[2,3-b]-benzothiophenyl, 3-naphtho-[2,3-b]-benzothiophenyl, 4-naphtho-[2,3-b]-benzothiophenyl, 5-naphtho-[2,3-b]-benzothiophenyl, 1-naphtho-[2,1-b]-benzothiophenyl, 2-naphtho-[2,1-b]-benzothiophenyl, 3-naphtho-[2,1-b]-benzothiophenyl, 4-naphtho-[2,1-b]-benzothiophenyl, 5-naphtho-[2,1-b]-benzothiophenyl, 6-naphtho-[2,1-b]-benzothiophenyl, 7-naphtho-[2,1-b]-benzothiophenyl, 8-naphtho-[2,1-b]-benzothiophenyl, 9-naphtho-[2,1-b]-benzothiophenyl, 10-naphtho-[2,1-b]-benzothiophenyl, 2-benzofuro[3,2-d]pyrimidinyl, 6-benzofuro[3,2-d]pyrimidinyl, 7-benzofuro[3,2-d]pyrimidinyl, 8-benzofuro[3,2-d]pyrimidinyl, 9-benzofuro[3,2-d]pyrimidinyl, 2-benzothio[3,2-d]pyrimidinyl, 6-benzothio[3,2-d]pyrimidinyl, 7-benzothio[3,2-d]pyrimidinyl, 8-benzothio[3,2-d]pyrimidinyl, 9-benzothio[3,2-d]pyrimidinyl, 2-benzofuro[3,2-d]pyrazinyl, 6-benzofuro[3,2-d]pyrazinyl, 7-benzofuro[3,2-d]pyrazinyl, 8-benzofuro[3,2-d]pyrazinyl, 9-benzofuro[3,2-d]pyrazinyl, 2-benzothio[3,2-d]pyrazinyl, 6-benzothio[3,2-d]pyrazinyl, 7-benzothio[3,2-d]pyrazinyl, 8-benzothio[3,2-d]pyrazinyl, 9-benzothio[3,2-d]pyrazinyl, 1-silafluorenyl, 2-silafluorenyl, 3-silafluorenyl, 4-silafluorenyl, 1-germafluorenyl, 2-germafluorenyl, 3-germafluorenyl, 4-germafluorenyl, 1-dibenzoselenophenyl, 2-dibenzoselenophenyl, 3-dibenzoselenophenyl, 4-dibenzoselenophenyl, etc. Herein, the term “a fused ring of (C3-C30) aliphatic ring and (C6-C30) aromatic ring” means a ring formed by fusing at least one aliphatic ring having 3 to 30 ring backbone carbon atoms in which the carbon atoms number is preferably 3 to 25, more preferably 3 to 18, and at least one aromatic ring having 6 to 30 ring backbone carbon atoms in which the carbon atoms number is preferably 6 to 25, more preferably 6 to 18. For example, the fused ring may be a fused ring of at least one benzene and at least one cyclohexane, or a fused ring of at least one naphthalene and at least one cyclopentane, etc. Herein, the carbon atoms in the fused ring of (C3-C30) aliphatic ring and (C6-C30) aromatic ring may be replaced with at least one heteroatom selected from B, N, O, S, Si and P, preferably at least one heteroatom selected from N, O and S. The term “Halogen” in the present disclosure includes F, Cl, Br, and I.

In addition, “ortho (o),” “meta (m),” and “para (p)” are meant to signify the substitution position of all substituents. Ortho position is a compound with substituents, which are adjacent to each other, e.g., at the 1 and 2 positions on benzene. Meta position is the next substitution position of the immediately adjacent substitution position, e.g., a compound with substituents at the 1 and 3 positions on benzene. Para position is the next substitution position of the meta position, e.g., a compound with substituents at the 1 and 4 positions on benzene.

Herein, the term “a ring formed in linking to an adjacent substituent” means a substituted or unsubstituted (3- to 30-membered) mono- or polycyclic, alicyclic, aromatic ring, or a combination thereof, formed by linking or fusing two or more adjacent substituents, preferably a substituted or unsubstituted (5- to 25-membered) mono- or polycyclic, alicyclic, aromatic ring, or a combination thereof. Further, the formed ring may include at least one heteroatom selected from the group consisting of B, N, O, S, Si and P, preferably, N, O and S. According to one embodiment of the present disclosure, the number of atoms in the ring skeleton is 5 to 20; according to another embodiment of the present disclosure, the number of atoms in the ring skeleton is 5 to 15. In one embodiment, the fused ring may be, for example, a substituted or unsubstituted dibenzothiophene ring, a substituted or unsubstituted dibenzofuran ring, a substituted or unsubstituted naphthalene ring, a substituted or unsubstituted phenanthrene ring, a substituted or unsubstituted fluorene ring, a substituted or unsubstituted benzofluorene ring, a substituted or unsubstituted benzothiophene ring, a substituted or unsubstituted benzofuran ring, a substituted or unsubstituted indole ring, a substituted or unsubstituted indene ring, a substituted or unsubstituted benzene ring, or a substituted or unsubstituted carbazole ring, etc.

In addition, “substituted” in the expression “substituted or unsubstituted” means that a hydrogen atom in a certain functional group is replaced with another atom or functional group, i.e., a substituent, and substituted with a group to which two or more substituents are connected among the substituents. For example, “a substituent to which two or more substituents are connected” may be pyridine-triazine. That is, pyridine-triazine may be heteroaryl or may be interpreted as one substituent in which two heteroaryls are connected.

Preferably, the substituents of the substituted alkyl, the substituted alkenyl, the substituted aryl(ene), the substituted heteroaryl(ene), the substituted cycloalkyl(ene), the substituted alkoxy, the substituted trialkylsilyl, the substituted dialkylarylsilyl, the substituted alkyldiarylsilyl, the substituted triarylsilyl, and the substituted fused ring of aliphatic ring and aromatic ring in the formulas of the present disclosure, each independently represent at least one selected from the group consisting of deuterium, halogen, cyano, carboxyl, nitro, hydroxyl, phosphine oxide, (C1-C30)alkyl, halo(C1-C30)alkyl, (C2-C30)alkenyl, (C2-C30)alkynyl, (C1-C30)alkoxy, (C1-C30)alkylthio, (C3-C30)cycloalkyl, (C3-C30)cycloalkenyl, (3- to 7-membered)heterocycloalkyl, (C6-C30)aryloxy, (C6-C30)arylthio, (3- to 30-membered)heteroaryl unsubstituted or substituted with at least one of deuterium and (C6-C30)aryl, (C6-C30)aryl unsubstituted or substituted with at least one of deuterium and (3- to 30-membered)heteroaryl, tri(C1-C30)alkylsilyl, tri(C6-C30)arylsilyl, di(C1-C30)alkyl(C6-C30)arylsilyl, (C1-C30)alkyldi(C6-C30)arylsilyl, amino, mono- or di-(C1-C30)alkylamino, mono- or di-(C2-C30)alkenylamino, mono- or di-(C6-C30)arylamino unsubstituted or substituted with (C1-C30)alkyl, mono- or di-(3- to 30-membered)heteroarylamino, (C1-C30)alkyl(C2-C30)alkenylamino, (C1-C30)alkyl(C6-C30)arylamino, (C1-C30)alkyl(3- to 30-membered)heteroarylamino, (C2-C30)alkenyl(C6-C30)arylamino, (C2-C30)alkenyl(3- to 30-membered)heteroarylamino, (C6-C30)aryl(3- to 30-membered)heteroarylamino, (C1-C30)alkylcarbonyl, (C1-C30)alkoxycarbonyl, (C6-C30)arylcarbonyl, (C6-C30)arylphosphine, di(C6-C30)arylboronyl, di(C1-C30)alkylboronyl, (C1-C30)alkyl(C6-C30)arylboronyl, (C6-C30)ar(C1-C30)alkyl, and (C1-C30)alkyl(C6-C30)aryl.

Hereinafter, the plurality of host materials according to one embodiment will be described.

The plurality of host materials according to one embodiment comprise at least one first host compound and at least one second host compound, wherein the first host compound is a compound represented by formula 1 and the second host compound is a compound represented by formula 2; and the plurality of host materials may be comprised in the light-emitting layer of an organic electroluminescent device according to one embodiment.

The first host compound as the host materials according to one embodiment is represented by the following formula 1.

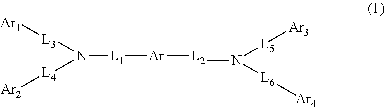

in formula 1,

Ar represents a substituted or unsubstituted (C6-C30)arylene or a substituted or unsubstituted (3- to 30-membered)heteroarylene;

L₁ to L₆ each independently represent, a single bond, a substituted or unsubstituted (C6-C30)arylene, a substituted or unsubstituted (C3-C30)cycloalkylene, or a substituted or unsubstituted (3- to 30-membered)heteroarylene; and

Ar₁ to Ar₄ each independently represent, deuterium, a substituted or unsubstituted (C1-C30)alkyl, a substituted or unsubstituted (C6-C30)aryl, a substituted or unsubstituted fused ring of (C3-C30) aliphatic ring and (C6-C30) aromatic ring, or a substituted or unsubstituted (3- to 30-membered)heteroaryl; or may be linked to the adjacent substituents to form a ring(s).

In one embodiment, L₁ and L₂ each independently may be a single bond or a substituted or unsubstituted (C6-C30)arylene, preferably a single bond or a substituted or unsubstituted (C6-C25)arylene, more preferably a single bond or a substituted or unsubstituted (C6-C18)arylene. For example, L₁ and L₂ each independently may be a single bond, a substituted or unsubstituted phenylene, or a substituted or unsubstituted fluorenylene.

In one embodiment, L₃ to L₆ each independently may be a single bond, a substituted or unsubstituted (C6-C30)arylene, or a substituted or unsubstituted (5- to 30-membered)heteroarylene, preferably a single bond, a substituted or unsubstituted (C6-C25)arylene, or a substituted or unsubstituted (5- to 25-membered)heteroarylene, more preferably a single bond, a substituted or unsubstituted (C6-C18)arylene, or a substituted or unsubstituted (5- to 18-membered)heteroarylene. For example, L₃ to L₆ each independently may be a single bond, a substituted or unsubstituted phenylene, a substituted or unsubstituted carbazolylene, or a substituted or unsubstituted dibenzothiophenylene. Wherein, the substituents of the substituted groups may be diphenylamino.

In one embodiment, Ar may be a substituted or unsubstituted (C6-C30)arylene or a substituted or unsubstituted (5- to 30-membered)heteroarylene, preferably a substituted or unsubstituted (C6-C25)arylene or a substituted or unsubstituted (5- to 25-membered)heteroarylene, more preferably a substituted or unsubstituted (C6-C20)arylene or a substituted or unsubstituted (5- to 20-membered)heteroarylene. For example, Ar may be a substituted or unsubstituted phenylene, a substituted or unsubstituted biphenylene, a substituted or unsubstituted naphthalenylene, a substituted or unsubstituted fluorenylene, a substituted or unsubstituted phenanthrenylene, a substituted or unsubstituted chrysenylene, a substituted or unsubstituted dihydrophenanthrenylene, a substituted or unsubstituted spirobifluorenylene, a substituted or unsubstituted pyridylene, a substituted or unsubstituted dibenzofuranylene, a substituted or unsubstituted dibenzothiophenylene, a substituted or unsubstituted carbazolylene, a substituted or unsubstituted benzocarbazolylene, a substituted or unsubstituted benzonaphthofuranylene, a substituted or unsubstituted benzonaphthothiophenylene, a substituted or unsubstituted benzofluorenylene, a substituted or unsubstituted benzothiazolylene, a substituted or unsubstituted benzoxazolylene, a substituted or unsubstituted benzimidazolylene, a substituted or unsubstituted naphthooxazolylene, or a substituted or unsubstituted naphthothiazolylene. Wherein, the substituents of the substituted groups may be at least one selected from deuterium, methyl, phenyl, biphenyl, carbazolyl unsubstituted or substituted with phenyl, diphenylamino, dibenzothiophenyl, and naphthooxazolyl.

Ar according to one embodiment may be any one selected from the following formulas 1-1-1 to 1-1-21.

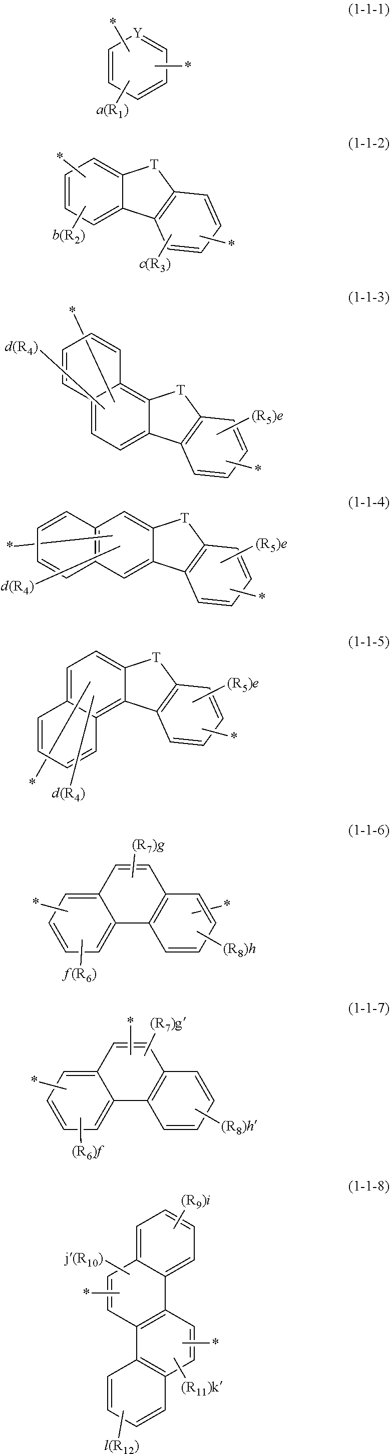

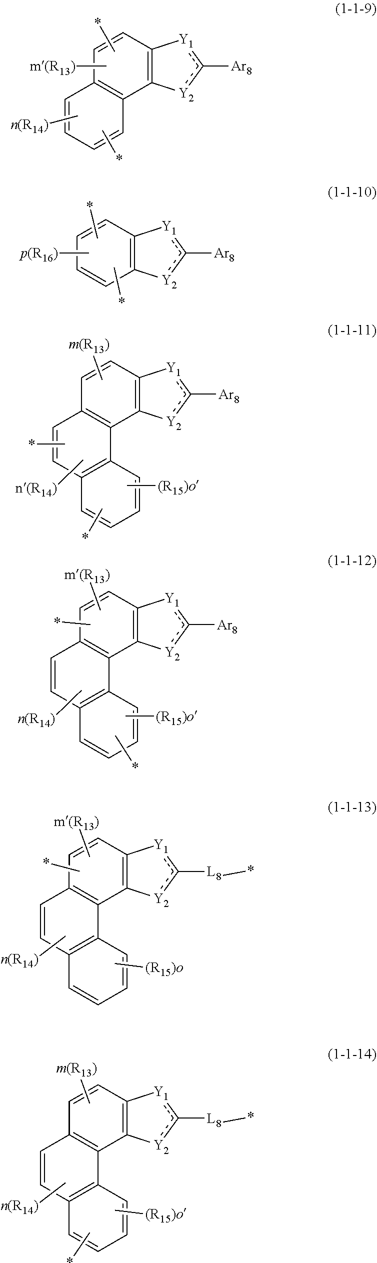

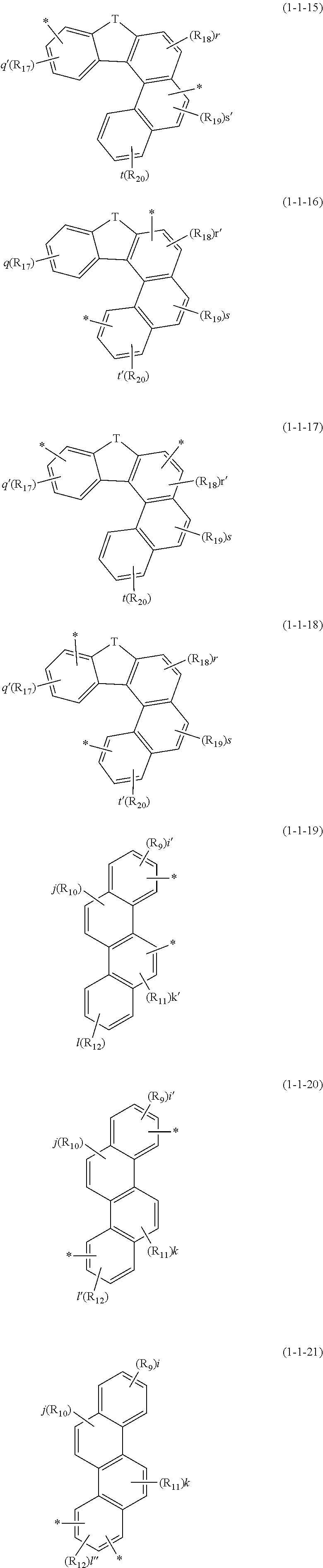

in formulas 1-1-1 to 1-1-21,

T represents —O—, —S—, —CR₂₁R₂₂—, or —NR₂₃—;

Y represents CH or N;

Y₁ and Y₂ each independently represent, —N═, —NR₂₄—, —O—, —S—, or —Se—; provided that any one of Y₁ and Y₂ is —N═, and the other of Y₁ and Y₂ is —NR₂₄—, —O—, —S—, or —Se;

R₁ to R₂₀ each independently represent, hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or —N—(R′)(R″); or may be linked to the adjacent substituents to form a ring(s);

R′ and R″ each independently represent, a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl;

R₂₁ to R₂₄ each independently represent, a substituted or unsubstituted (C1-C30)alkyl, a substituted or unsubstituted (C6-C30)aryl, or a substituted or unsubstituted (3- to 30-membered)heteroaryl; or may be linked to the adjacent substituents to form a ring(s);

Ar₈ represents a substituted or unsubstituted (C6-C30)aryl or a substituted or unsubstituted (3- to 30-membered)heteroaryl;

L₈ represents a single bond, a substituted or unsubstituted (C6-C30)arylene, or a substituted or unsubstituted (3- to 30-membered)heteroarylene;

h′, i, l, o, q, and t are an integer of 1 to 4; a, b, c, e, f, h, i′, l′, o′, q′, and t′ are an integer of 1 to 3; d is an integer of 1 to 5; g, j, k, l″, m, n, p, r and s are an integer of 1 or 2; g′, j′, k′, m′, n′, r′ and s′ are 1;

when a to t, h′, i′, l′, l″, o′, q′, and t′ are an integer of 2 or more, each of R₁ to R₂₀ may be the same or different; and

represents a linking site with L₁ and L₂ in formula 1.

For example, in formula 1-1-1, * represents a linking site with L₁ and L₂, and can be linked at the 1- and 2-positions, the 1- and 3-positions, and the 1- and 4-positions, respectively.

In one embodiment, in formula 1-1-1, R₁ may be hydrogen, deuterium, a substituted or unsubstituted (C6-C30)aryl, or a substituted or unsubstituted (5- to 30-membered)heteroaryl, preferably hydrogen, deuterium, a substituted or unsubstituted (C6-C25)aryl, or a substituted or unsubstituted (5- to 25-membered)heteroaryl, more preferably hydrogen, deuterium, a substituted or unsubstituted (C6-C18)aryl, or a substituted or unsubstituted (5- to 18-membered)heteroaryl. For example, R₁ may be hydrogen, deuterium, phenyl, or carbazolyl.

In one embodiment, Ar₁ to Ar₄ each independently may be a substituted or unsubstituted (C6-C30)aryl or a substituted or unsubstituted (5- to 30-membered)heteroaryl; or may be linked to the adjacent substituents to form a ring(s), preferably a substituted or unsubstituted (C6-C25)aryl or a substituted or unsubstituted (5- to 25-membered)heteroaryl; or may be linked to the adjacent substituents to form a substituted or unsubstituted (5- to 30-membered) polycyclic aromatic ring(s), more preferably a substituted or unsubstituted (C6-C18)aryl or a substituted or unsubstituted (5- to 25-membered)heteroaryl; or may be linked to the adjacent substituents to form a substituted or unsubstituted (5- to 25-membered) polycyclic aromatic ring(s). For example, Ar₁ to Ar₄ each independently may be a substituted or unsubstituted phenyl, a substituted or unsubstituted naphthyl, a substituted or unsubstituted p-biphenyl, a substituted or unsubstituted m-biphenyl, a substituted or unsubstituted o-terphenyl, a substituted or unsubstituted m-terphenyl, a substituted or unsubstituted dibenzofuranyl, a substituted or unsubstituted dibenzothiophenyl, a substituted or unsubstituted dibenzoselenophenyl, a substituted or unsubstituted fluorenyl, a substituted or unsubstituted carbazolyl, a substituted or unsubstituted phenanthrenyl, a substituted or unsubstituted chrysenyl, a substituted or unsubstituted benzocarbazolyl, a substituted or unsubstituted benzonaphthofuranyl, a substituted or unsubstituted benzonaphthothiophenyl, a substituted or unsubstituted benzofluorenyl, a substituted or unsubstituted benzothiazolyl, a substituted or unsubstituted benzoxazolyl, a substituted or unsubstituted benzimidazolyl, a substituted or unsubstituted naphthooxazolyl, a substituted or unsubstituted naphthothiazolyl, or a substituted or unsubstituted naphthoimidazolyl. Preferably, Ar₁ to Ar₄ each independently may be, a substituted or unsubstituted phenyl, a substituted or unsubstituted naphthyl, a substituted or unsubstituted o-biphenyl, a substituted or unsubstituted p-biphenyl, a substituted or unsubstituted m-biphenyl, a substituted or unsubstituted o-terphenyl, a substituted or unsubstituted m-terphenyl, a substituted or unsubstituted dibenzofuranyl, a substituted or unsubstituted dibenzothiophenyl, a substituted or unsubstituted dibenzoselenophenyl, a substituted or unsubstituted fluorenyl, a substituted or unsubstituted carbazolyl, a substituted or unsubstituted phenanthrenyl, a substituted or unsubstituted chrysenyl, a substituted or unsubstituted benzonaphthofuranyl, a substituted or unsubstituted benzonaphthothiophenyl, a substituted or unsubstituted benzofluorenyl, a substituted or unsubstituted naphthooxazolyl, a substituted or unsubstituted phenanthrooxazolyl, a substituted or unsubstituted naphthothiazolyl, or a substituted or unsubstituted phenanthrothiazolyl. Wherein, the substituents of the substituted groups may be deuterium, cyano, methyl, phenyl, pyridyl, diphenylamino, or phenylpyridylamino.

At least one of Ar₁ to Ar₄ according to one embodiment may be any one selected from the following formulas 1-1 to 1-20.

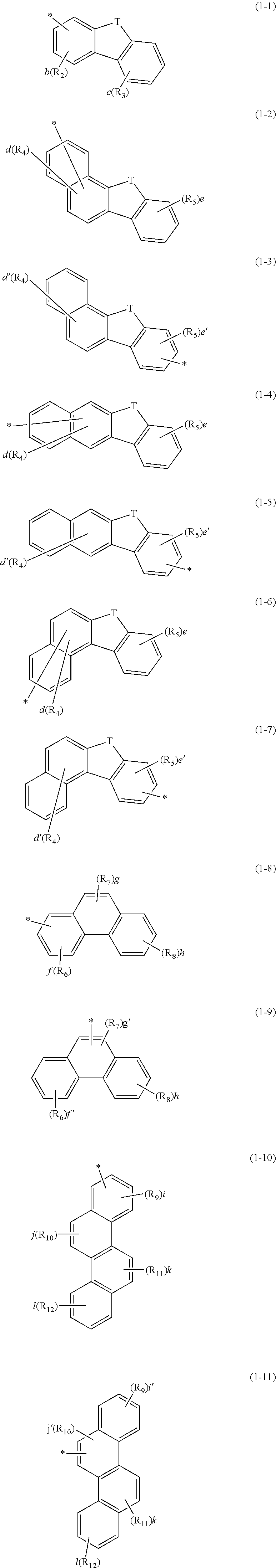

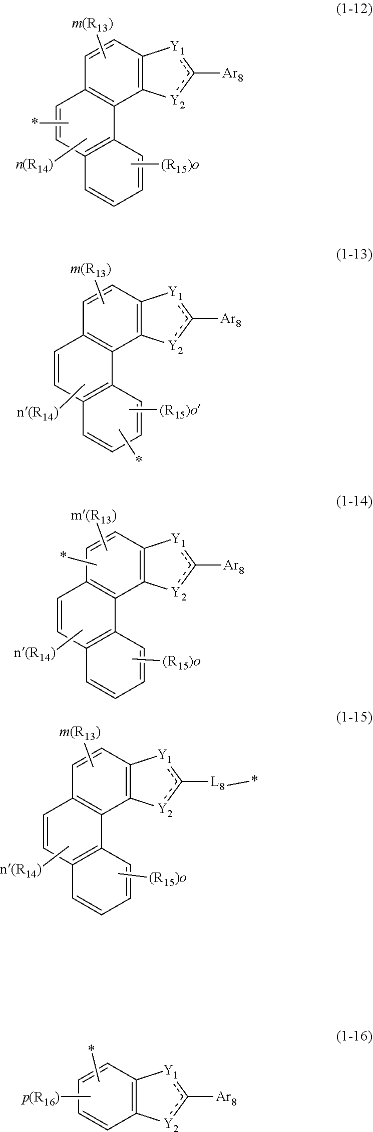

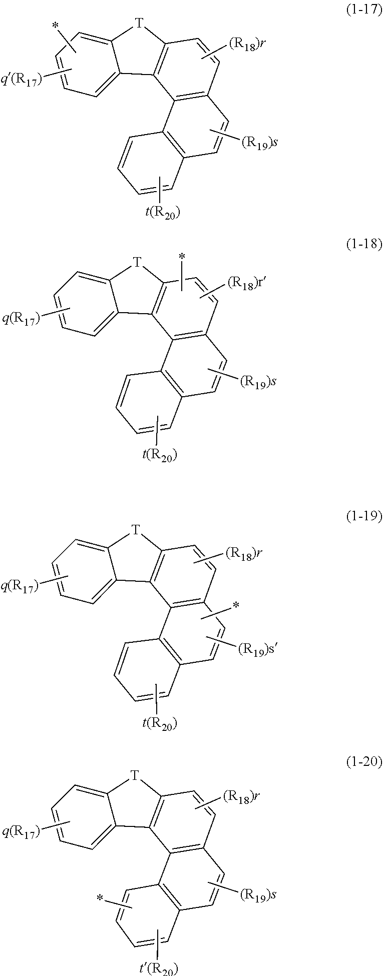

in formulas 1-1 to 1-20,

T represents —O—, —S—, —Se—, —CR₂₁R₂₂—, or —NR₂₃—;

Y₁ and Y₂ each independently represent, —N═, —NR₂₄—, —O—, —S— or —Se—; provided that any one of Y₁ and Y₂ is —N═, and the other of Y₁ and Y₂ is —NR₂₄—, —O—, —S— or —Se—;

R₂ to R₂₀ each independently represent, hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or —N—(R′)(R″); or may be linked to the adjacent substituents to form a ring(s);

R′ and R″ each independently represent, a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl;

R₂₁ to R₂₄ each independently represent, a substituted or unsubstituted (C1-C30)alkyl, a substituted or unsubstituted (C6-C30)aryl, or a substituted or unsubstituted (3- to 30-membered)heteroaryl; or may be linked to the adjacent substituents to form a ring(s);

Ar₈ represents a substituted or unsubstituted (C6-C30)aryl or a substituted or unsubstituted (3- to 30-membered)heteroaryl;

L₈ represents a single bond, a substituted or unsubstituted (C6-C30)arylene, or a substituted or unsubstituted (3- to 30-membered)heteroarylene;

b, e′, f, i, o′, p, q′, and t′ are an integer of 1 to 3; c, e, h, f′, l, i′, o, q, and t are an integer of 1 to 4; d is an integer of 1 to 5; d′ is an integer of 1 to 6; g, j, k, m, n′, r, and s are an integer of 1 or 2; g′, j′, m′, n, r′, and s′ are 1;

when b to m, o to t, d′ to f′, i′, n′, o′, q′, and t′ are an integer of 2 or more, each of R₂ to R₂₀ may be the same or different; and

* represents a linking site with L₃ to L₆ in formula 1.

In one embodiment, R₂₁ to R₂₃ each independently may be a substituted or unsubstituted (C1-C30)alkyl, a substituted or unsubstituted (C6-C30)aryl, or a substituted or unsubstituted (5- to 30-membered)heteroaryl, preferably a substituted or unsubstituted (C1-C10)alkyl, a substituted or unsubstituted (C6-C25)aryl, or a substituted or unsubstituted (5- to 25-membered)heteroaryl, more preferably a substituted or unsubstituted (C1-C4)alkyl, a substituted or unsubstituted (C6-C18)aryl, or a substituted or unsubstituted (5- to 18-membered)heteroaryl. For example, R₂₁ to R₂₃ each independently may be methyl, phenyl, or pyridyl.

In one embodiment, R₁ to R₈ each independently may be hydrogen, deuterium, halogen, cyano, a substituted or unsubstituted (C1-C30)alkyl, or a substituted or unsubstituted (C6-C30)aryl, preferably hydrogen, deuterium, or a substituted or unsubstituted (C6-C25)aryl, more preferably hydrogen, deuterium, or a substituted or unsubstituted (C6-C18)aryl.

In one embodiment, R₉ to R₂₀ each independently may be, hydrogen, deuterium, or a substituted or unsubstituted (C6-C30)aryl, for example, may be phenyl.

In one embodiment, Ar₈ may be a substituted or unsubstituted (C6-C30)aryl, for example, may be phenyl.

According to one embodiment, the first host compound represented by formula 1 may be more specifically illustrated by the following compounds, but is not limited thereto.

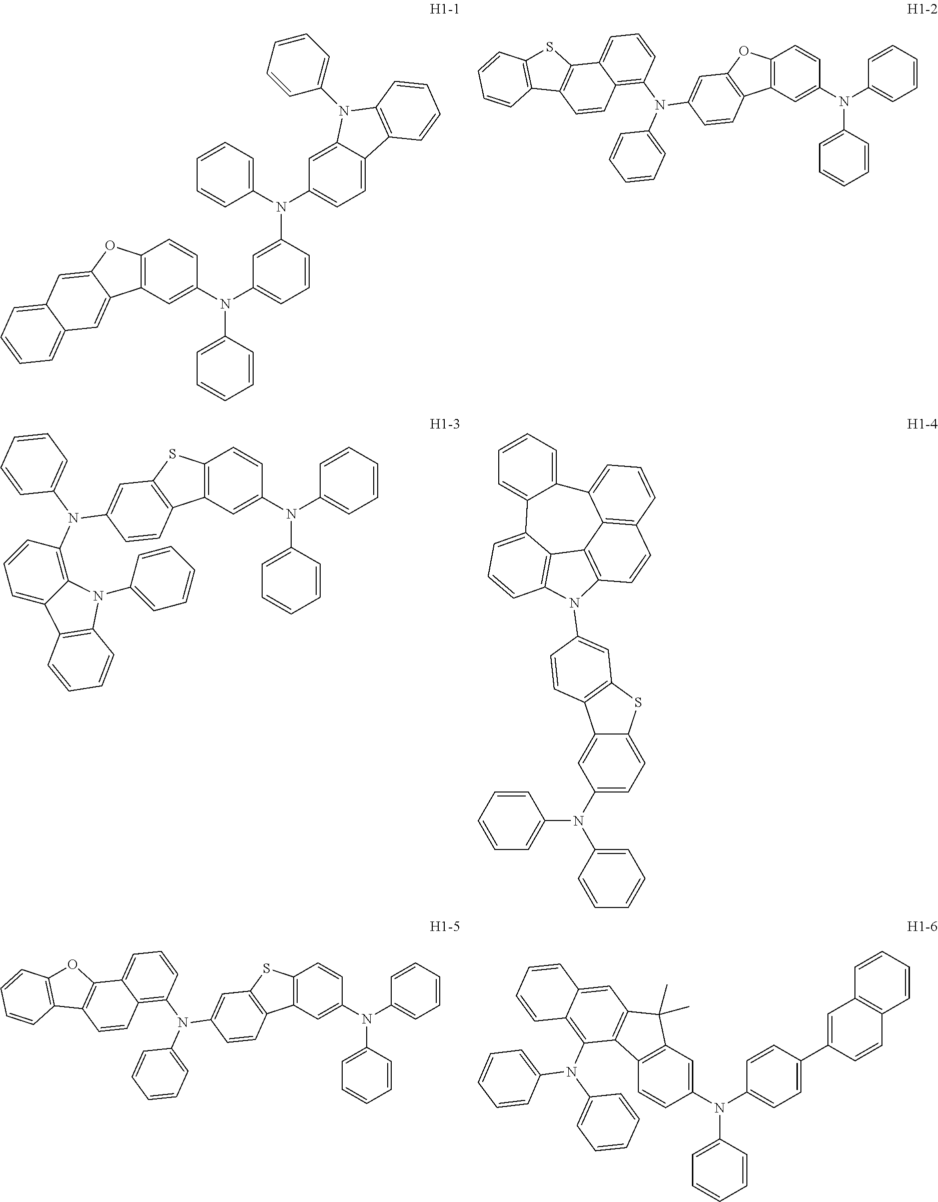

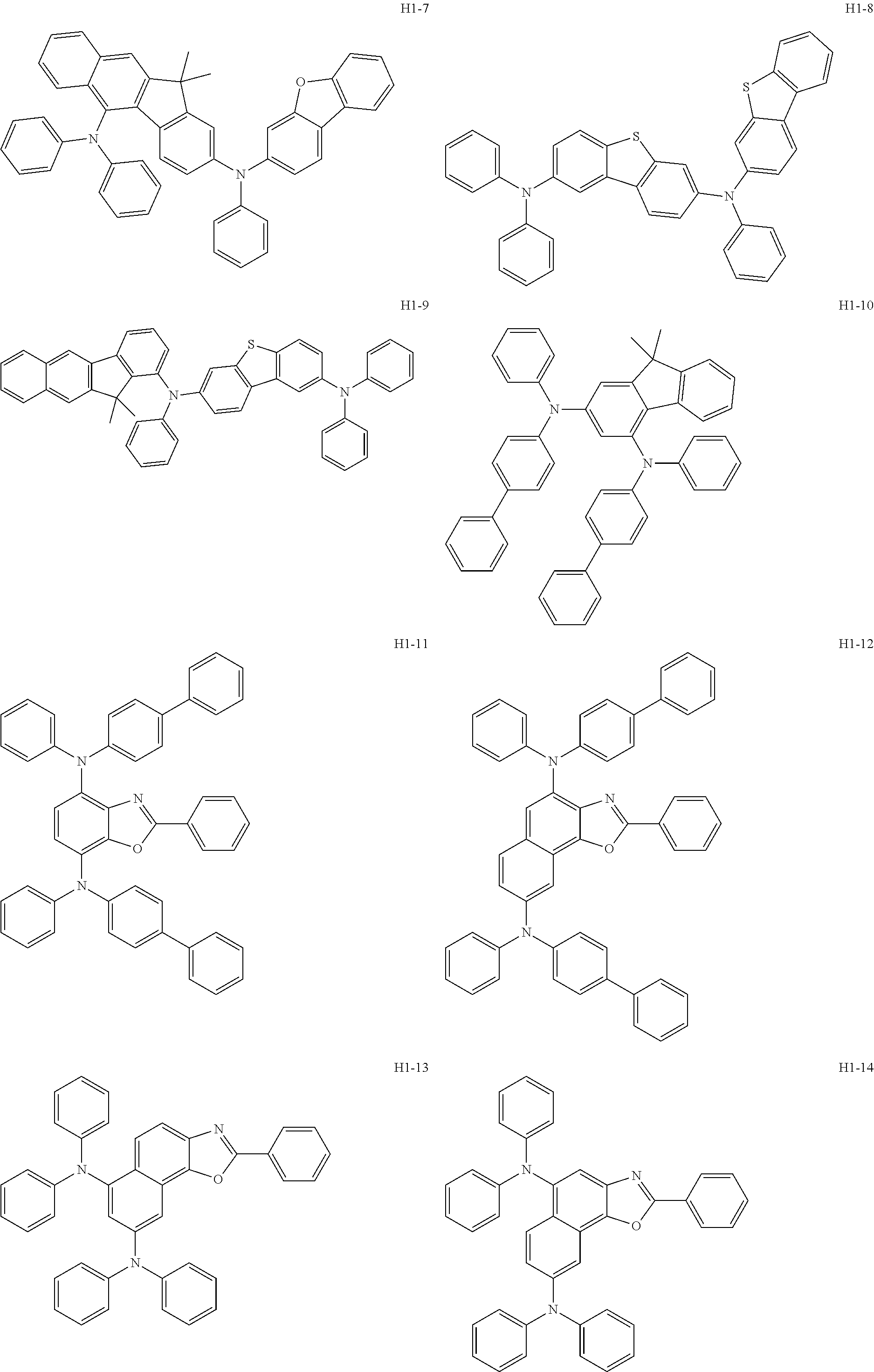

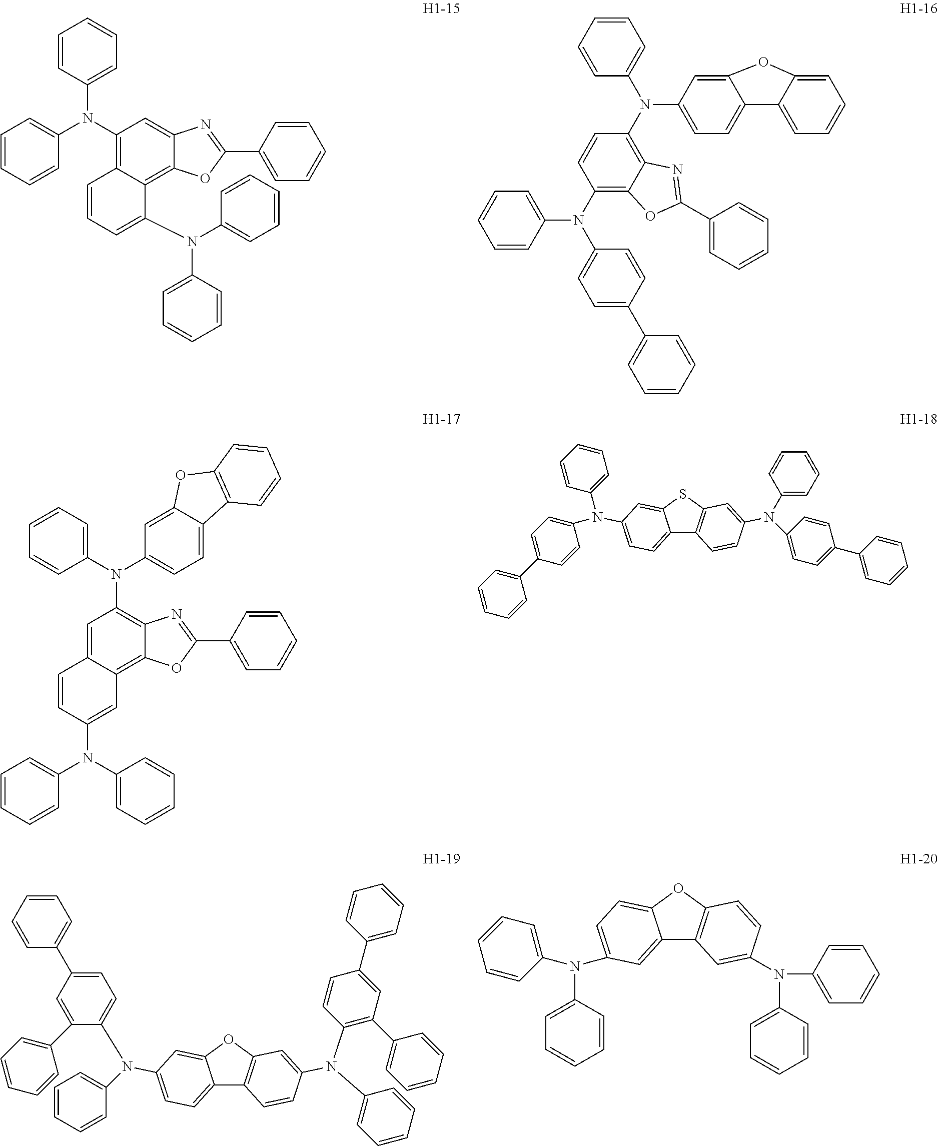

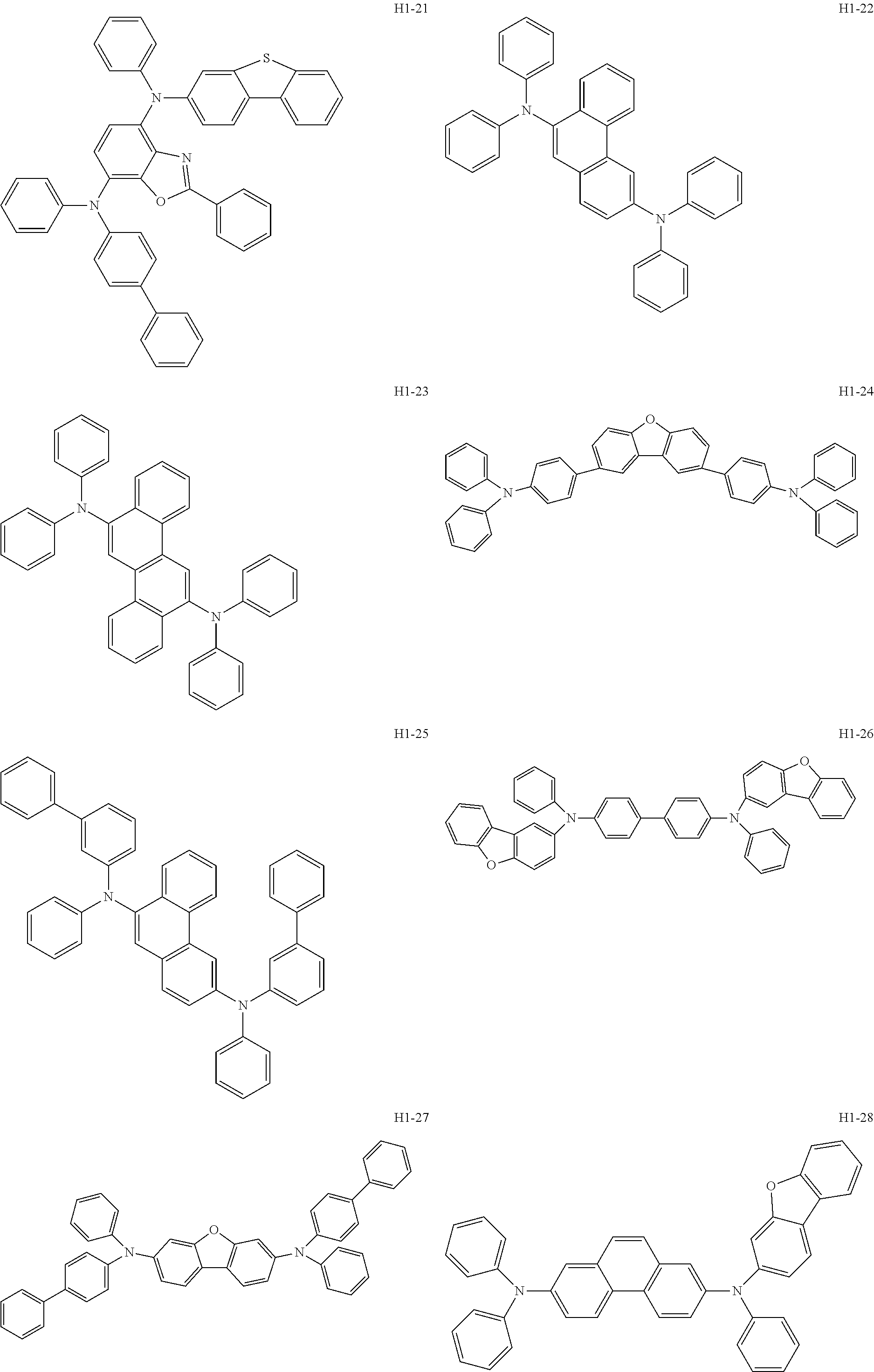

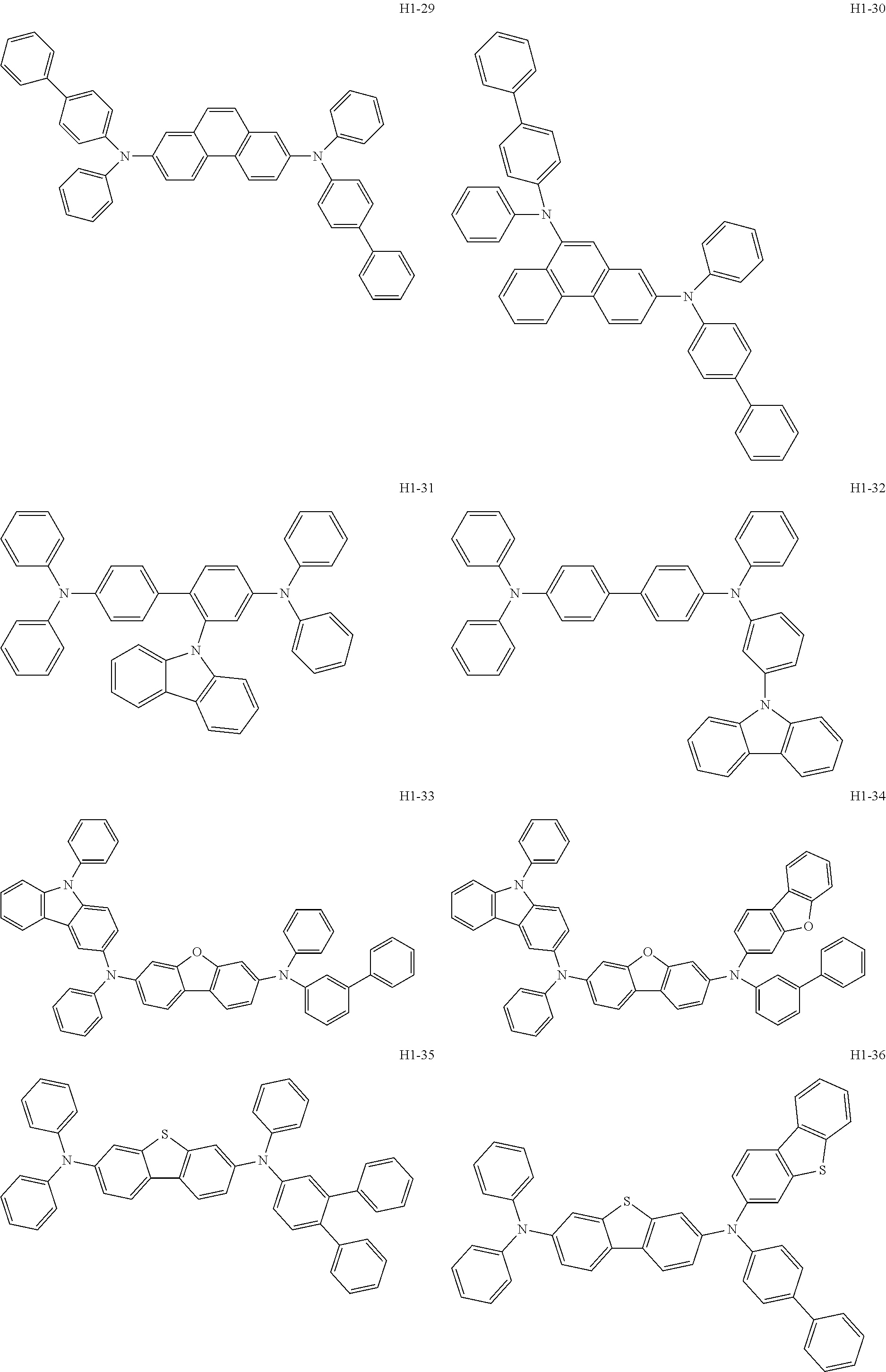

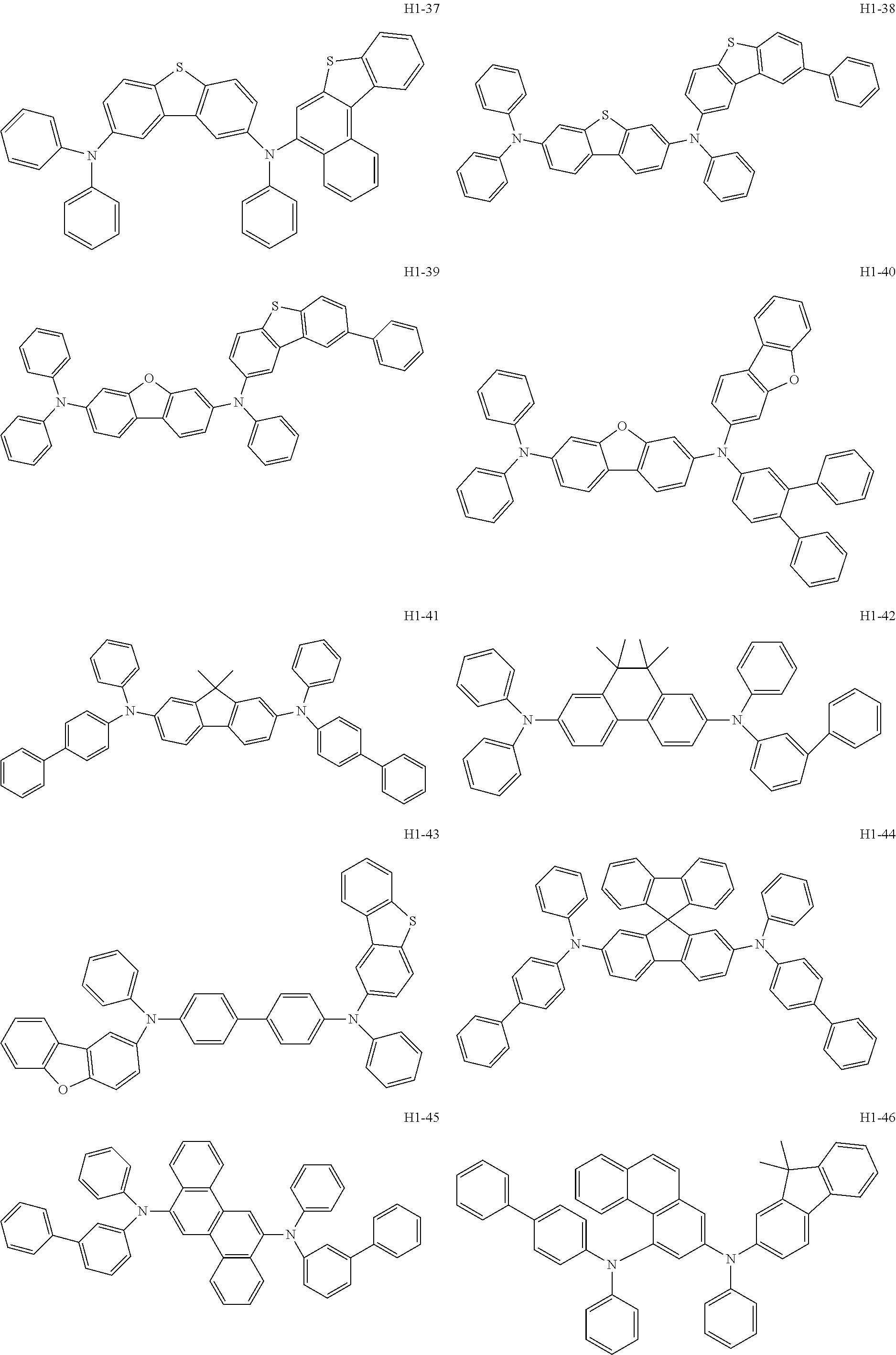

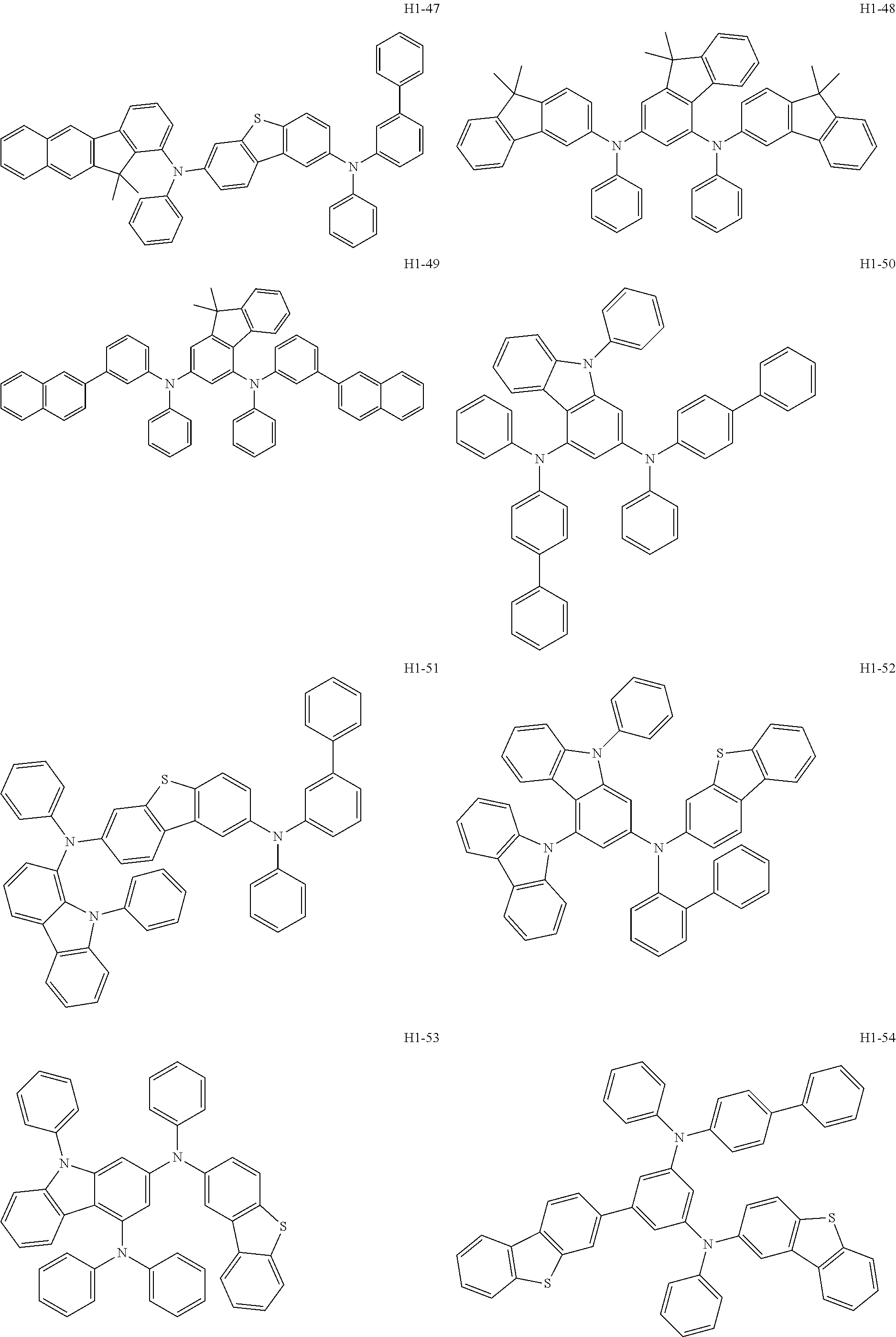

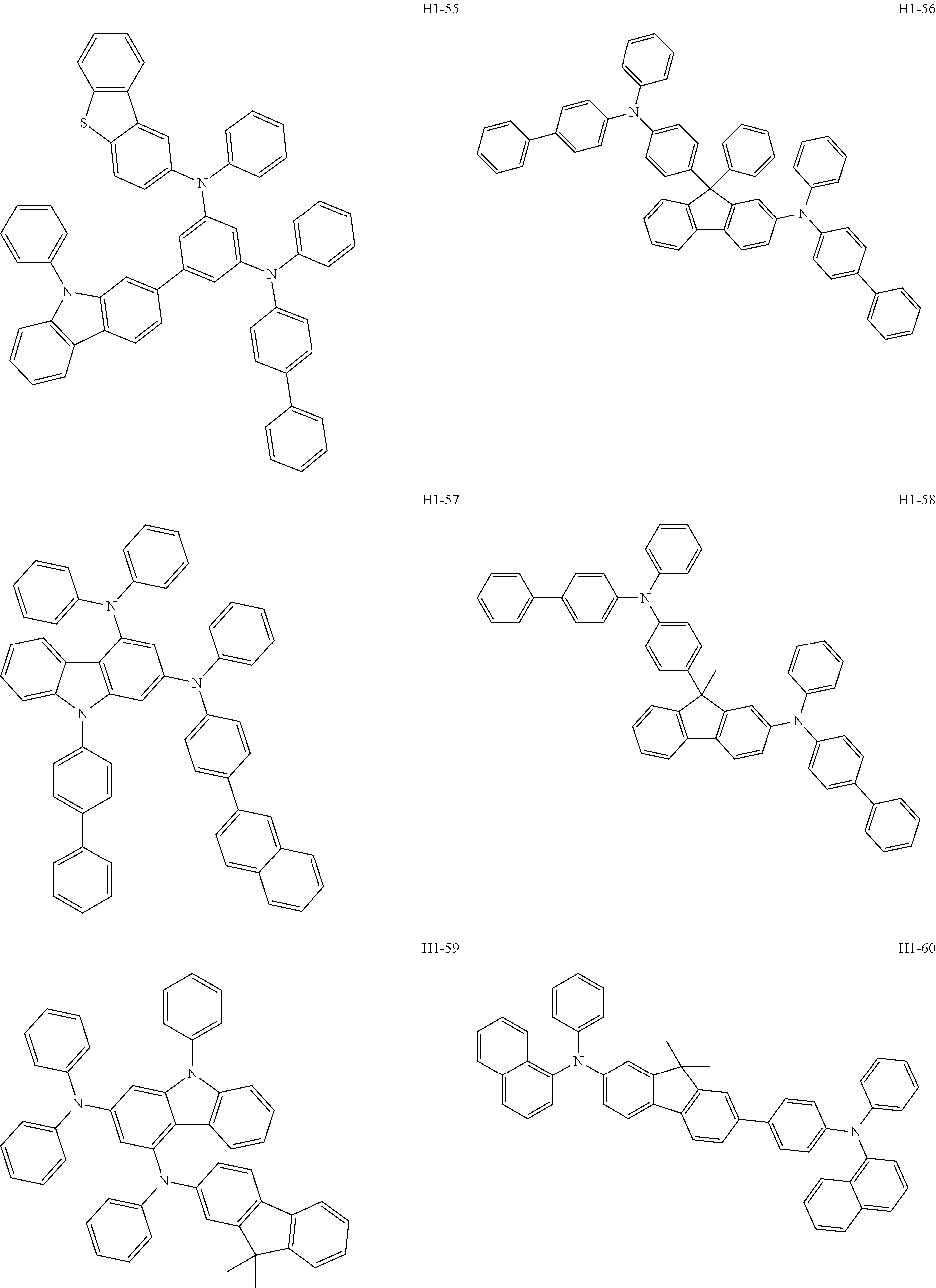

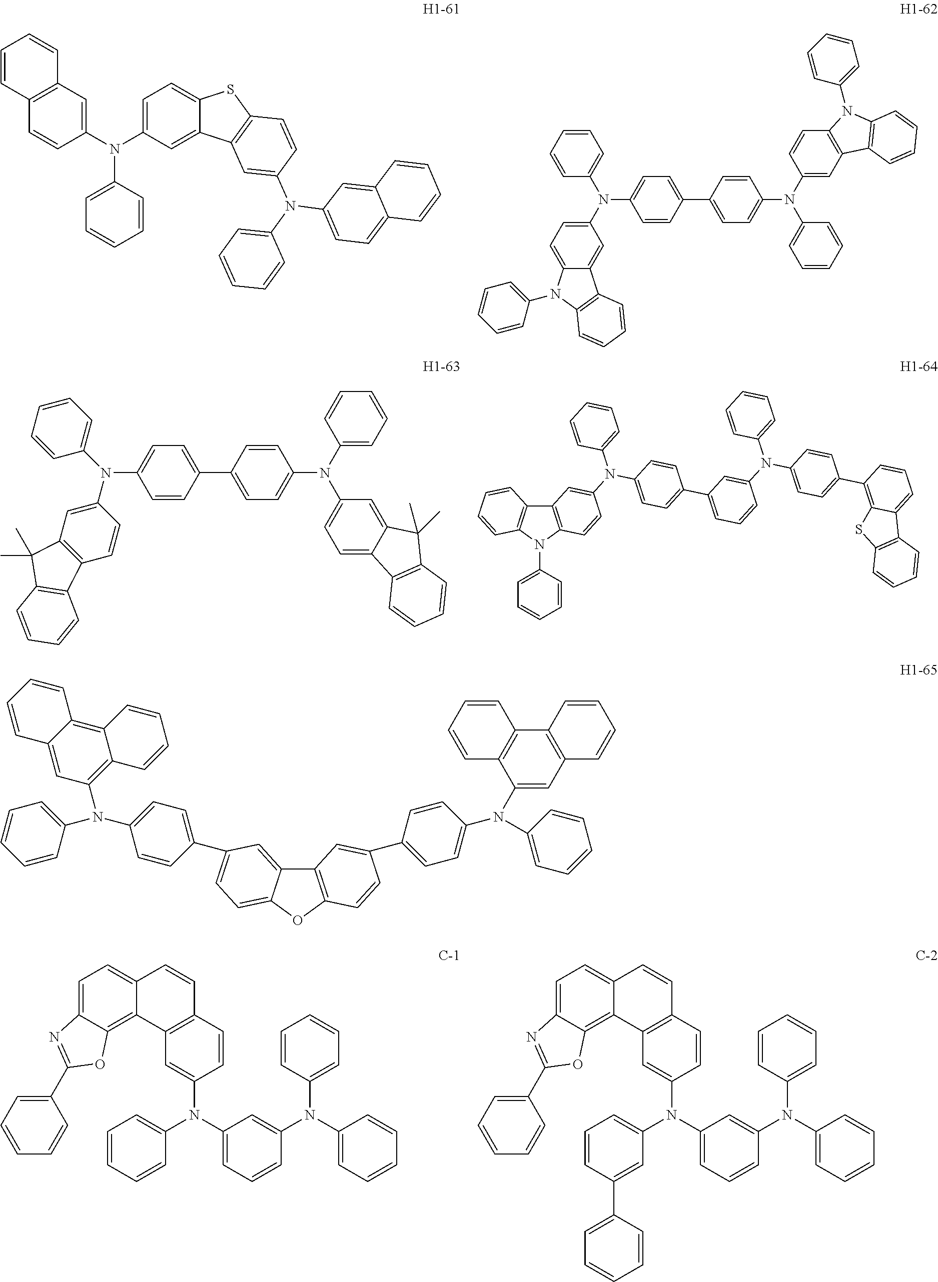

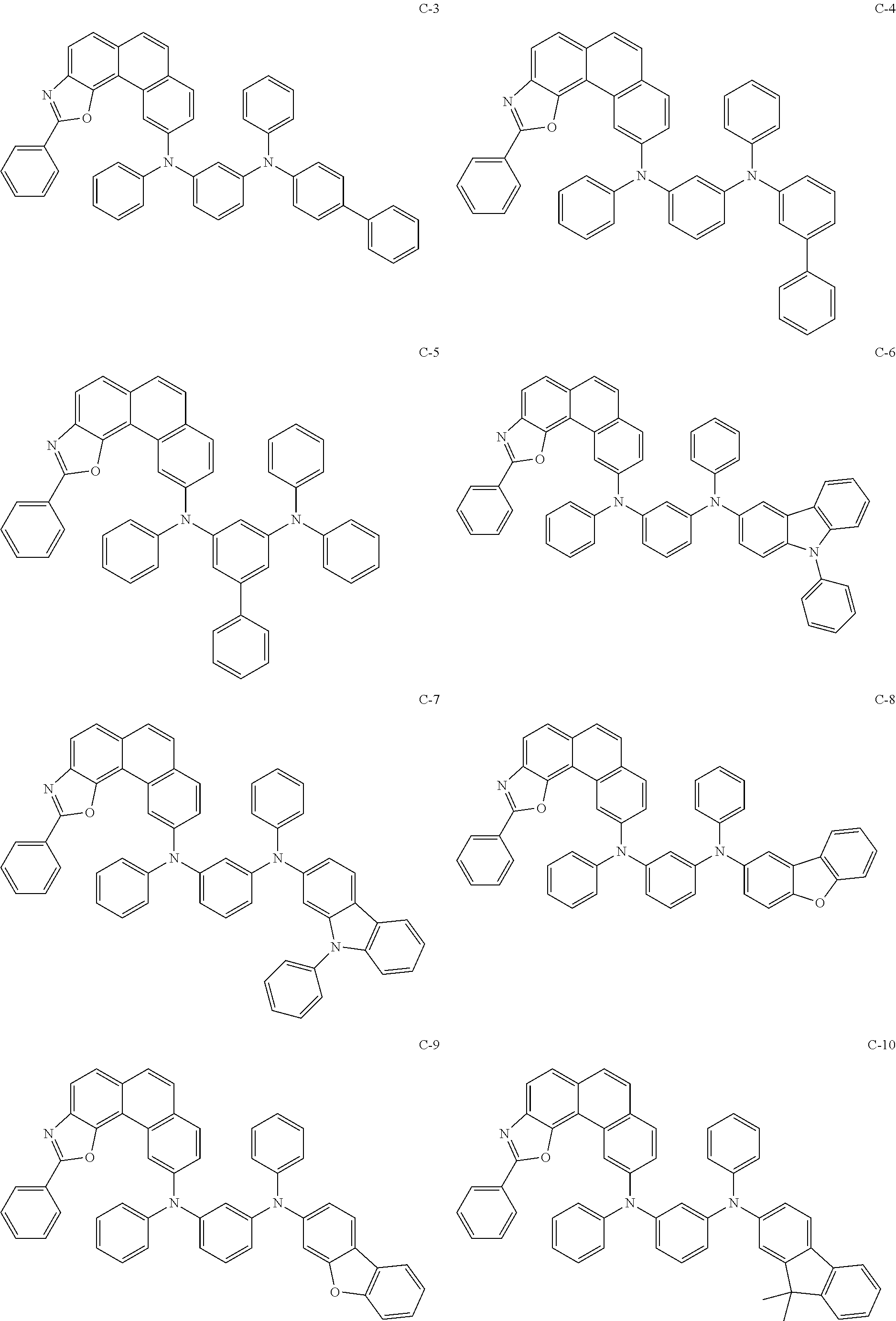

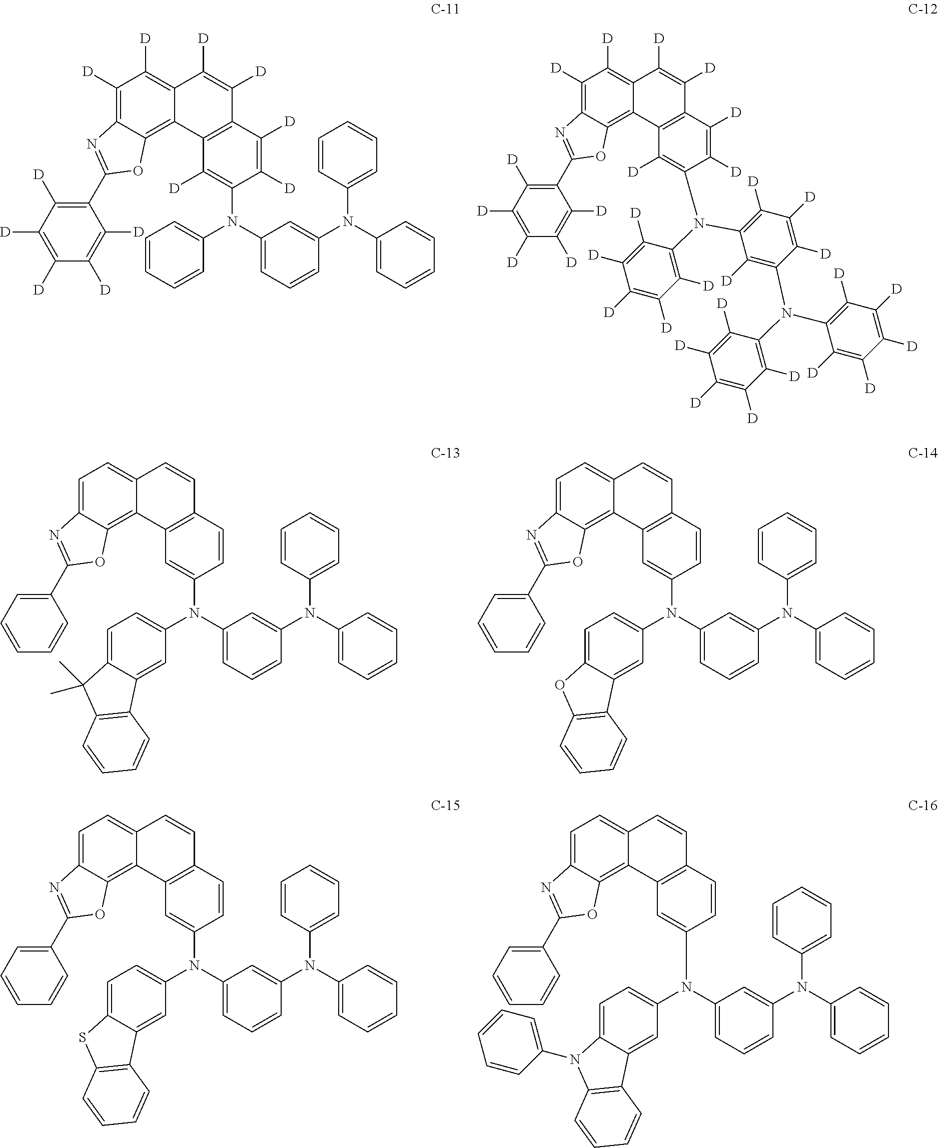

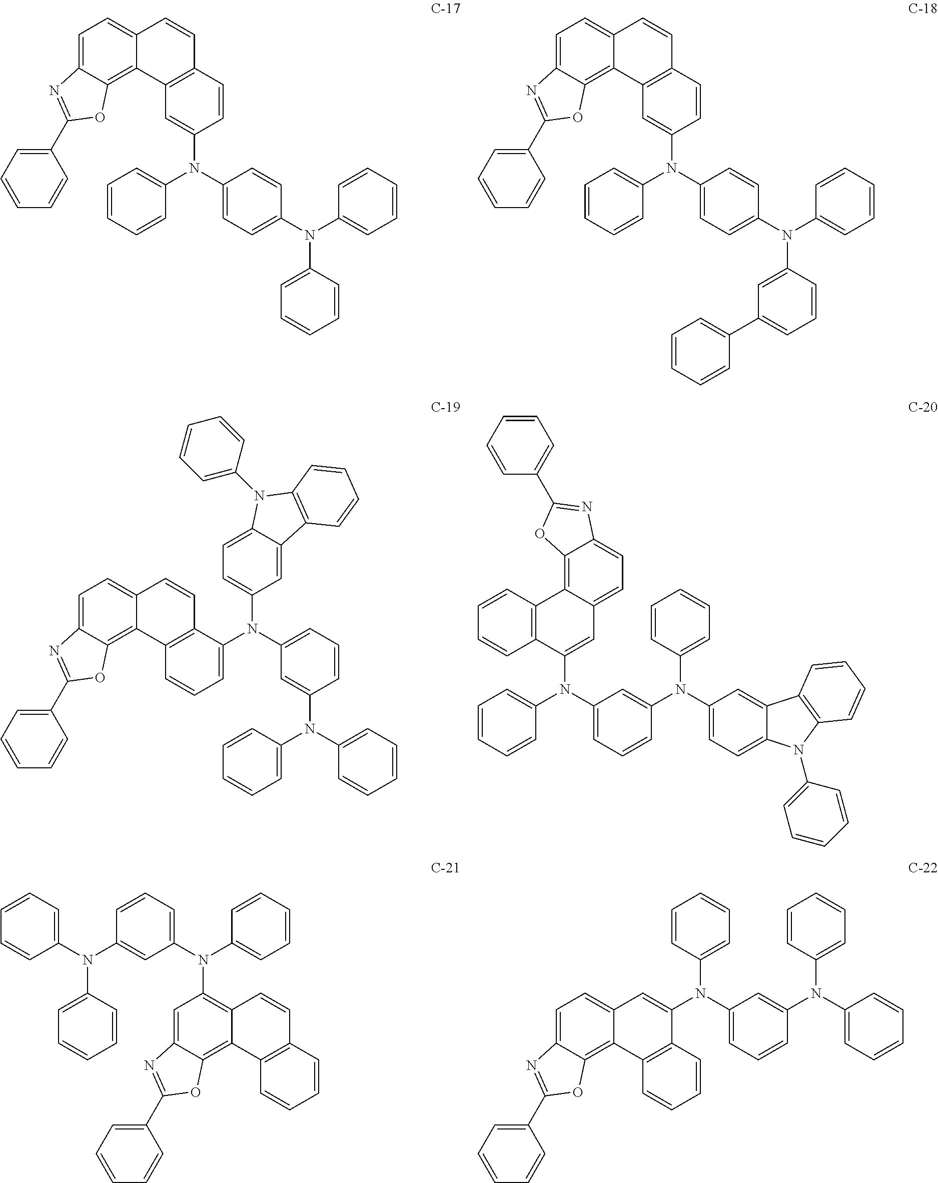

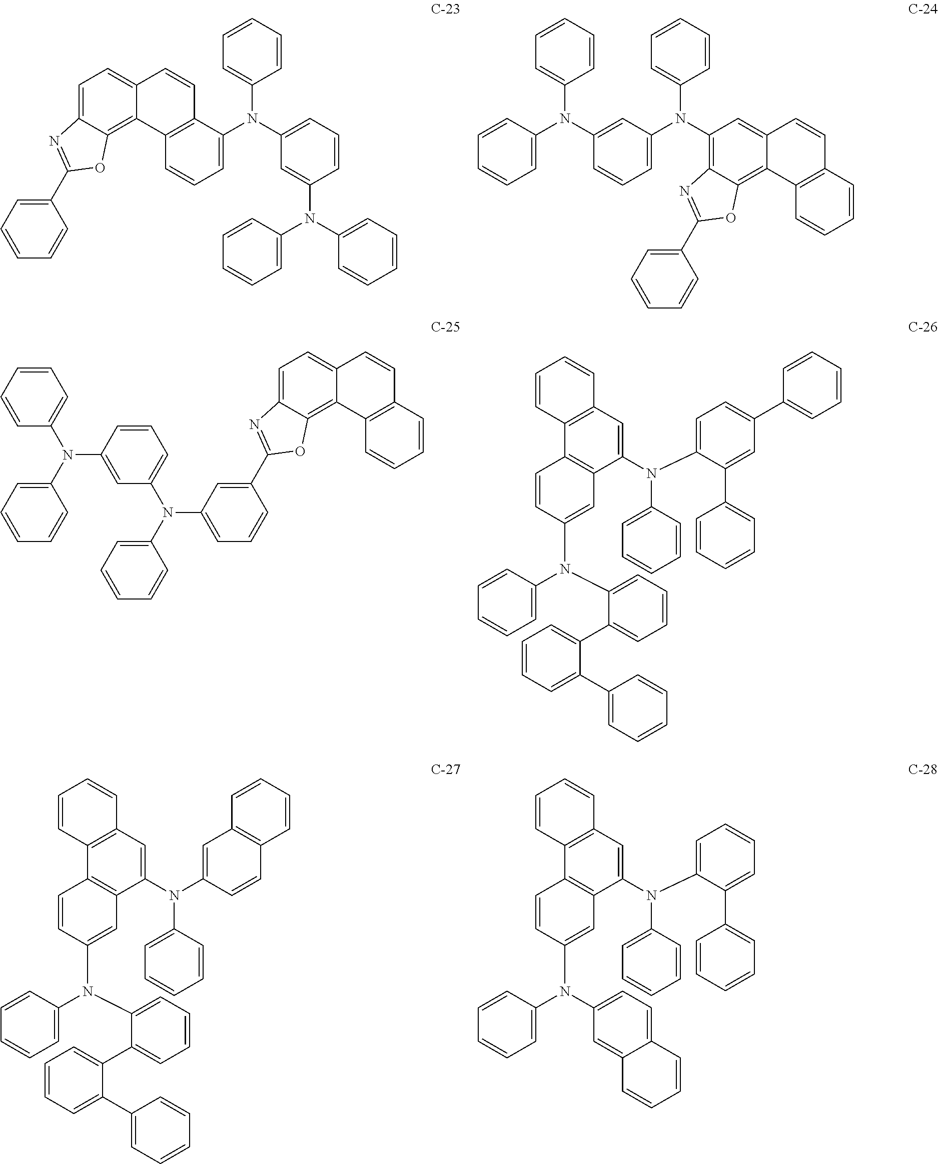

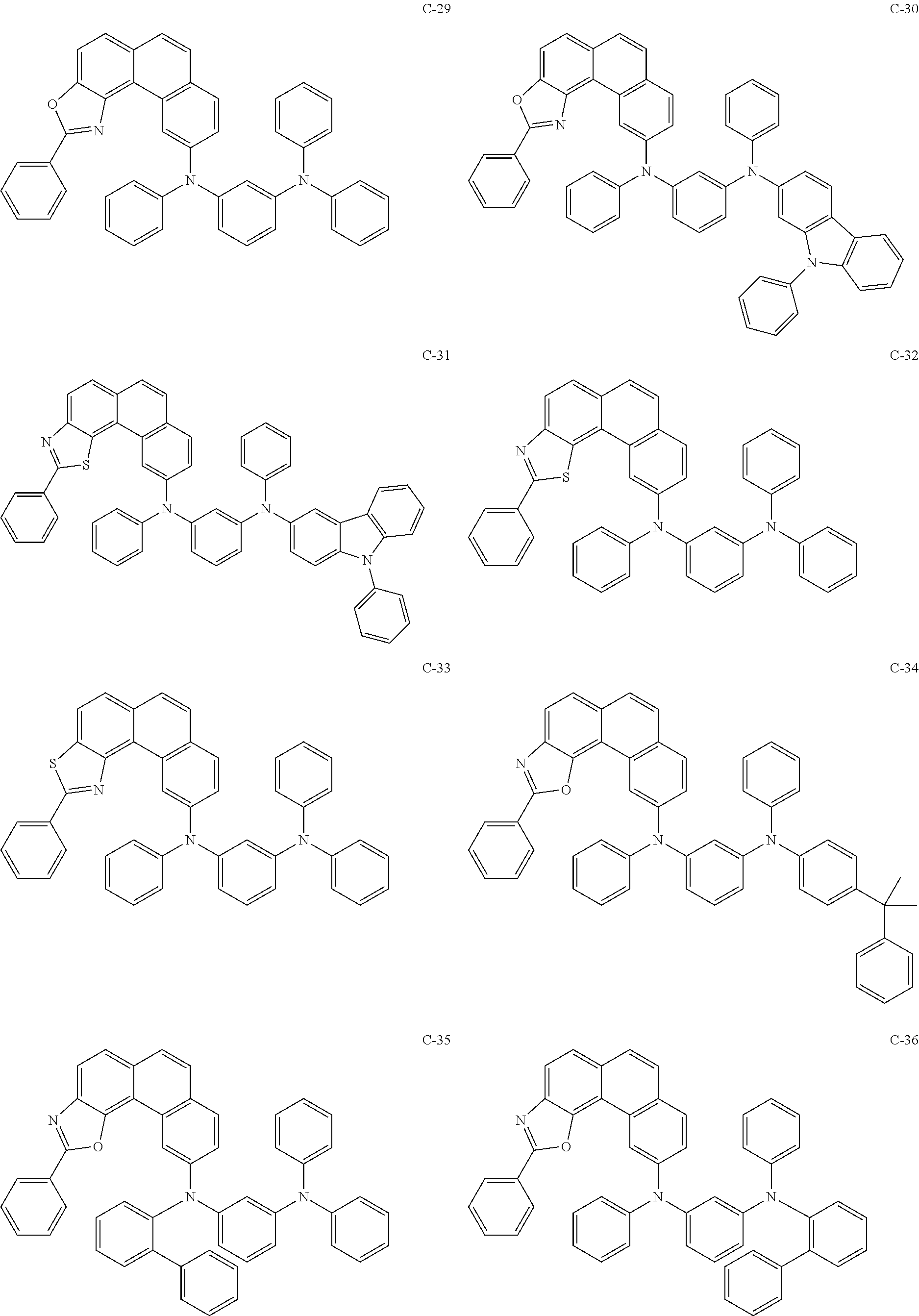

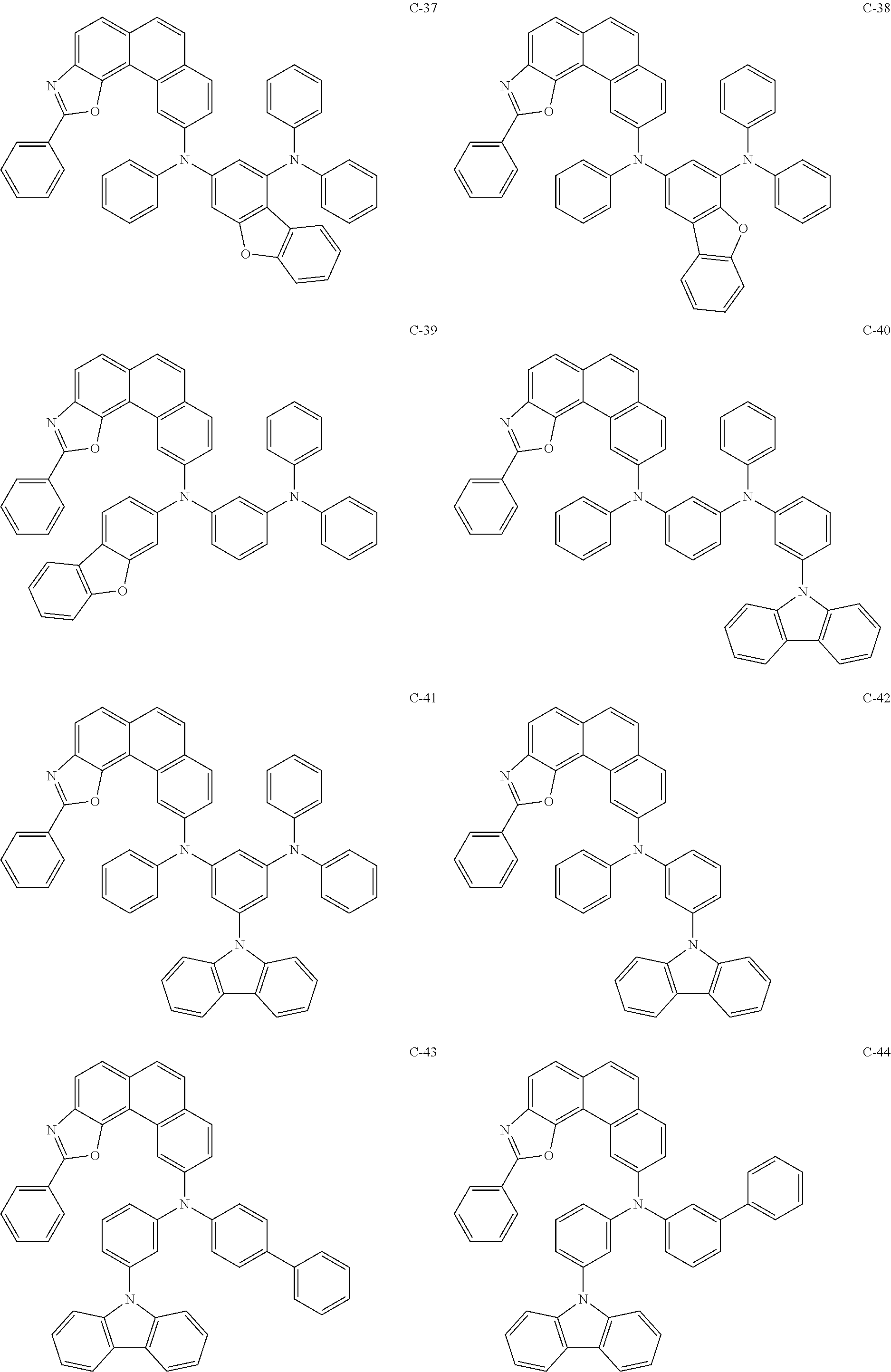

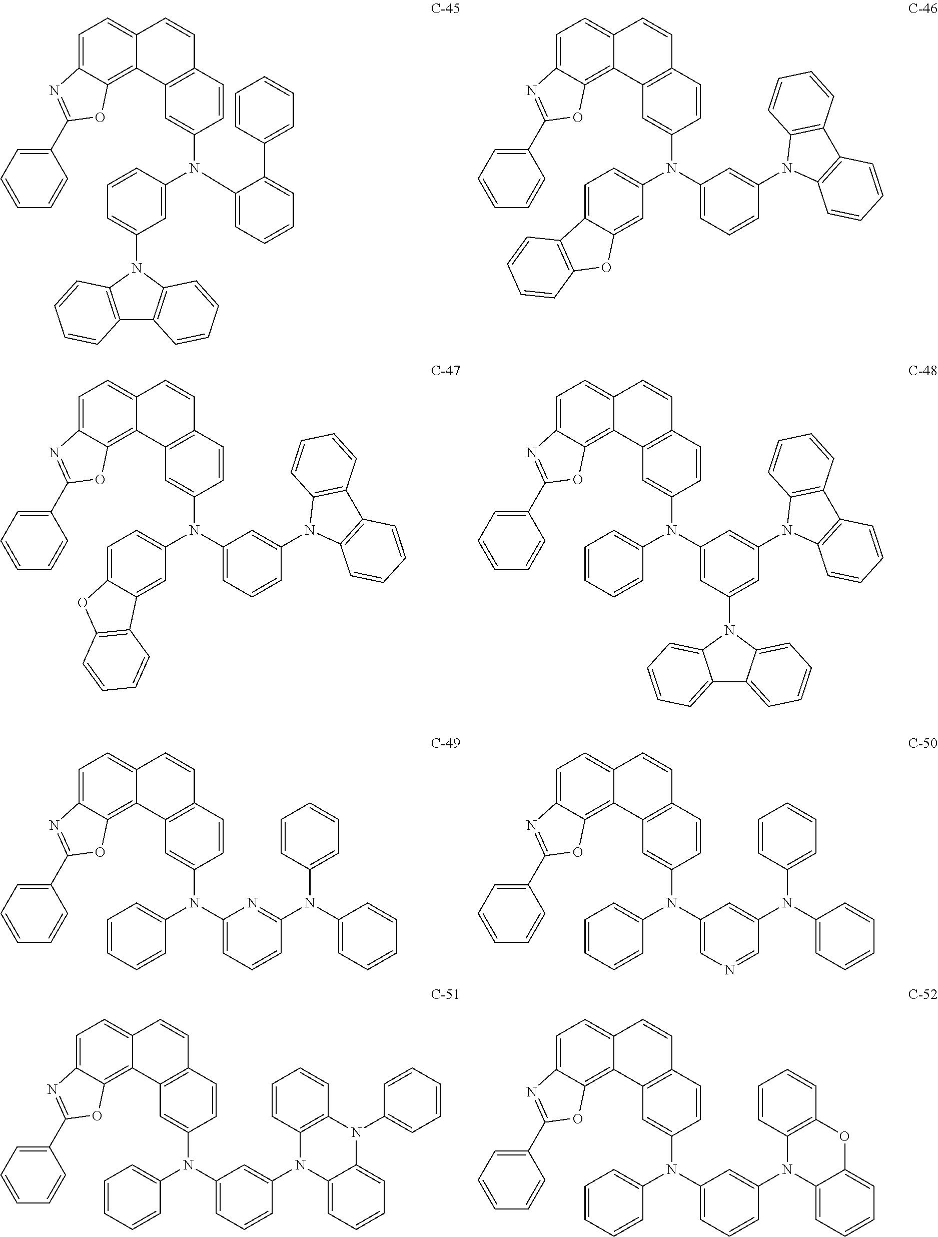

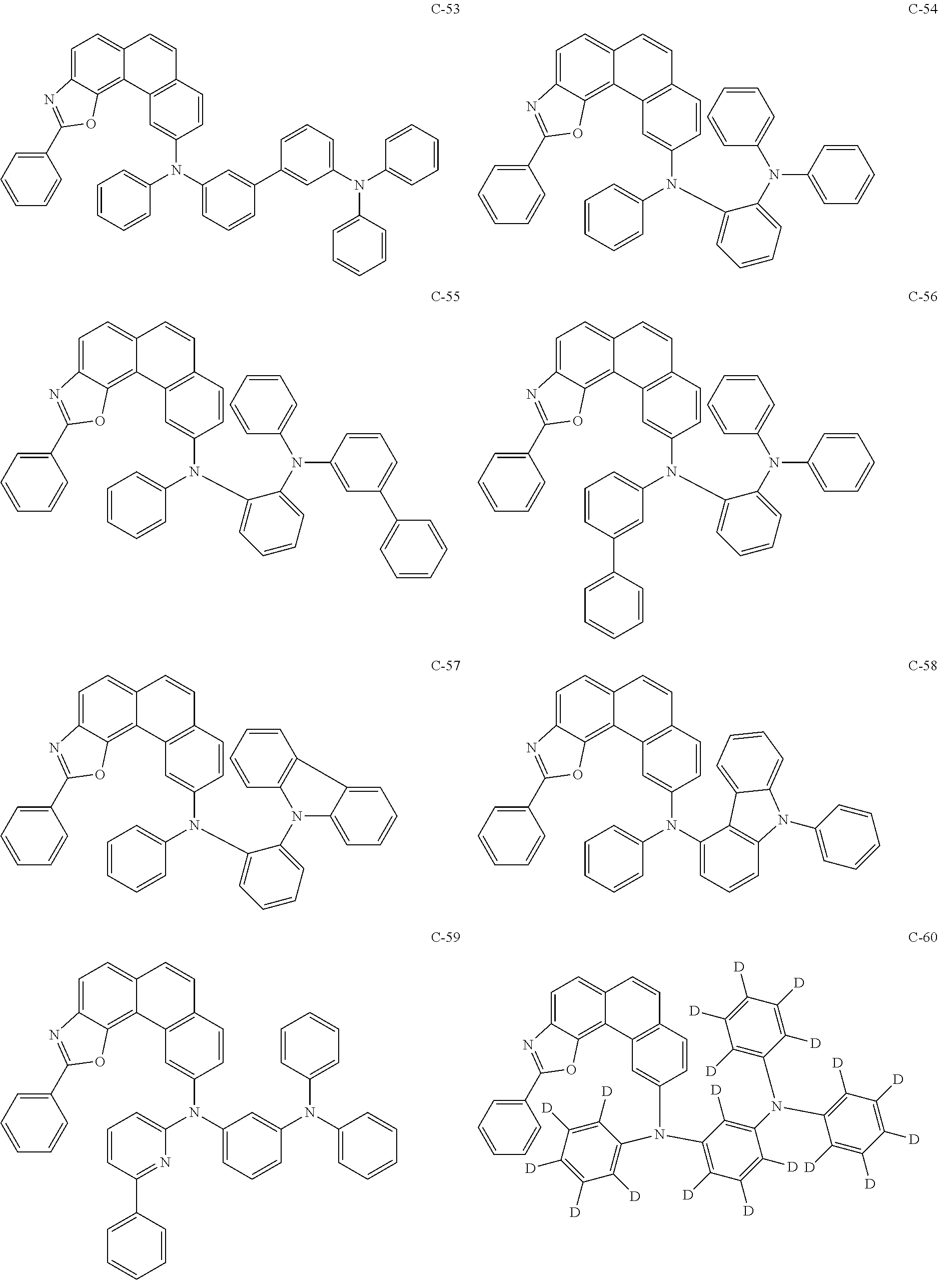

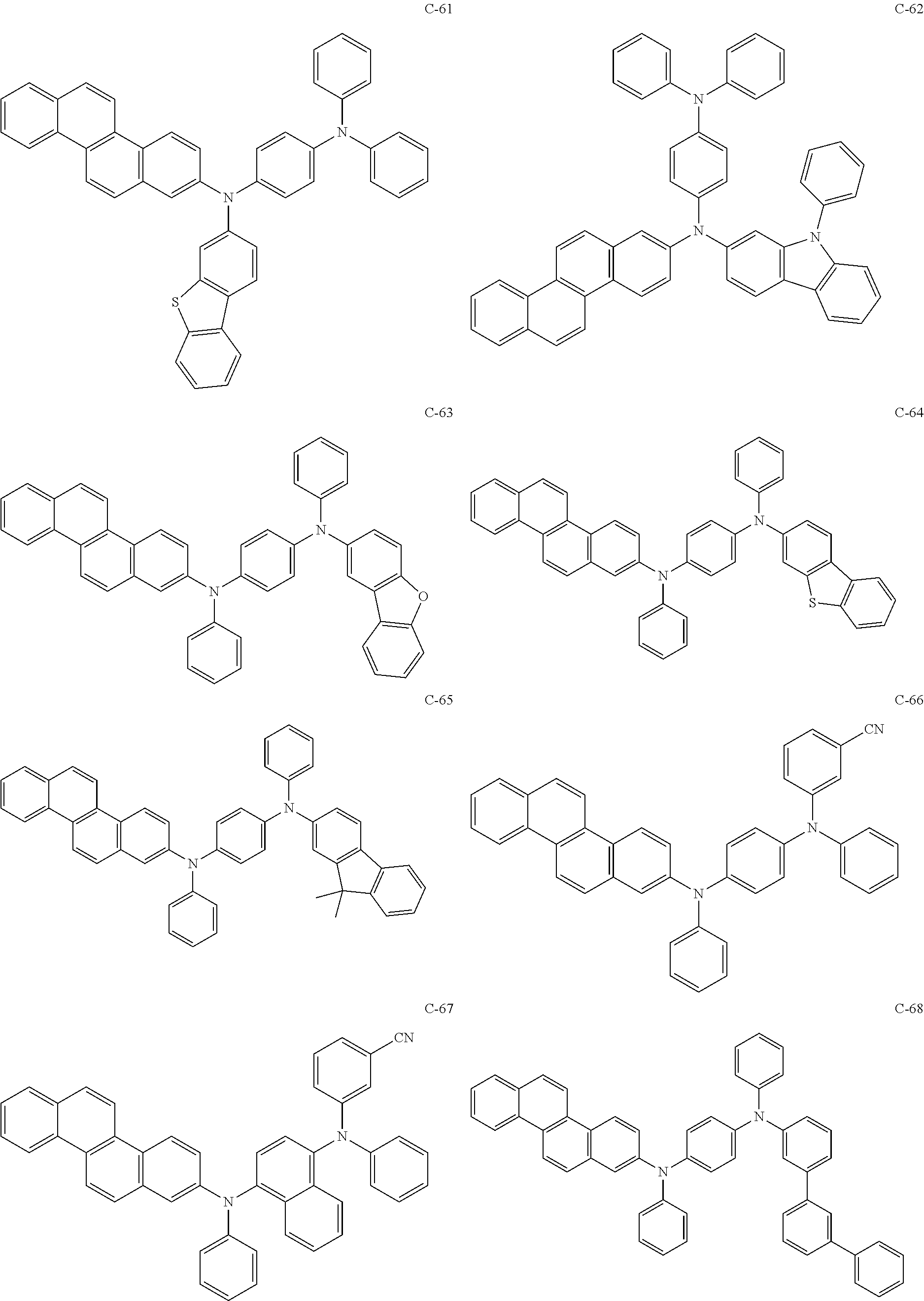

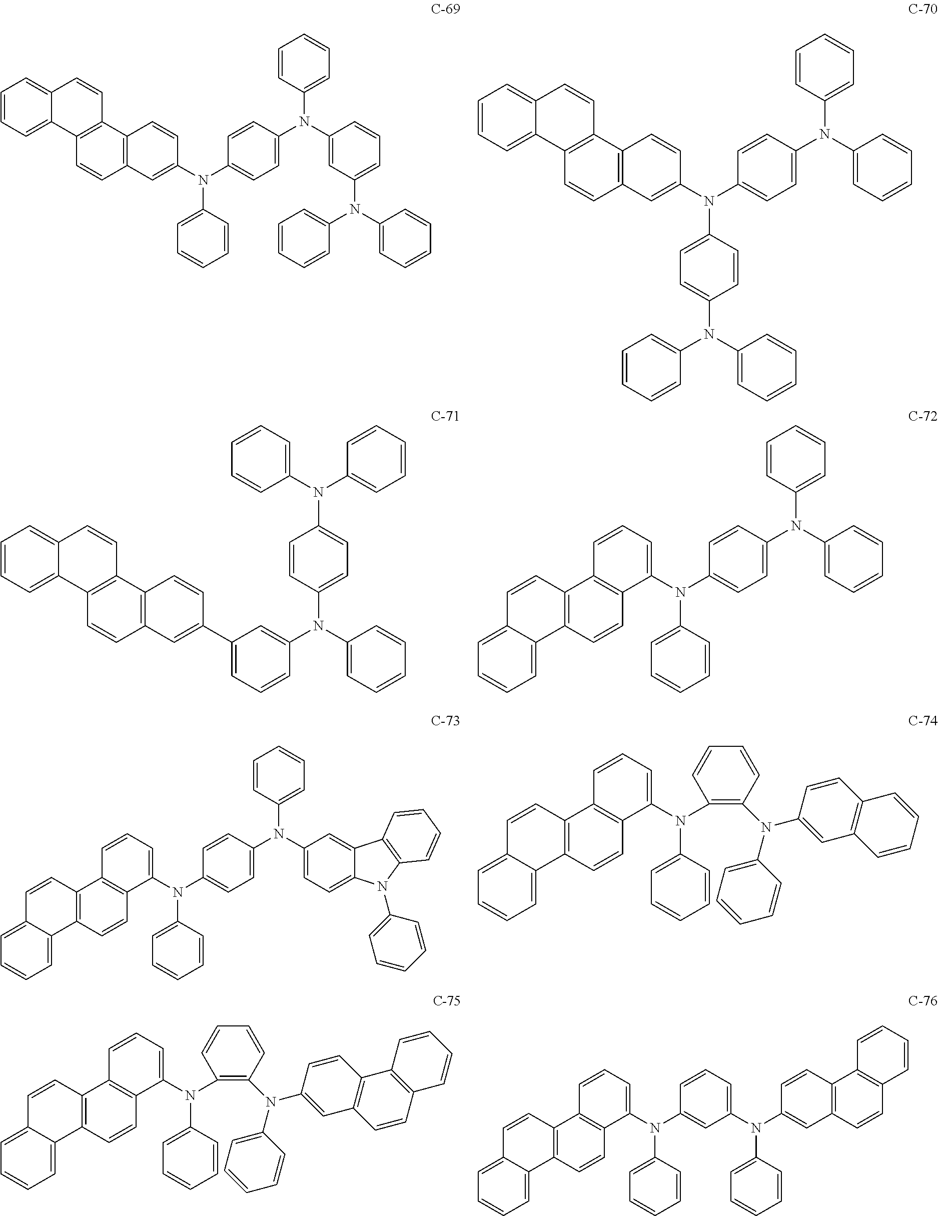

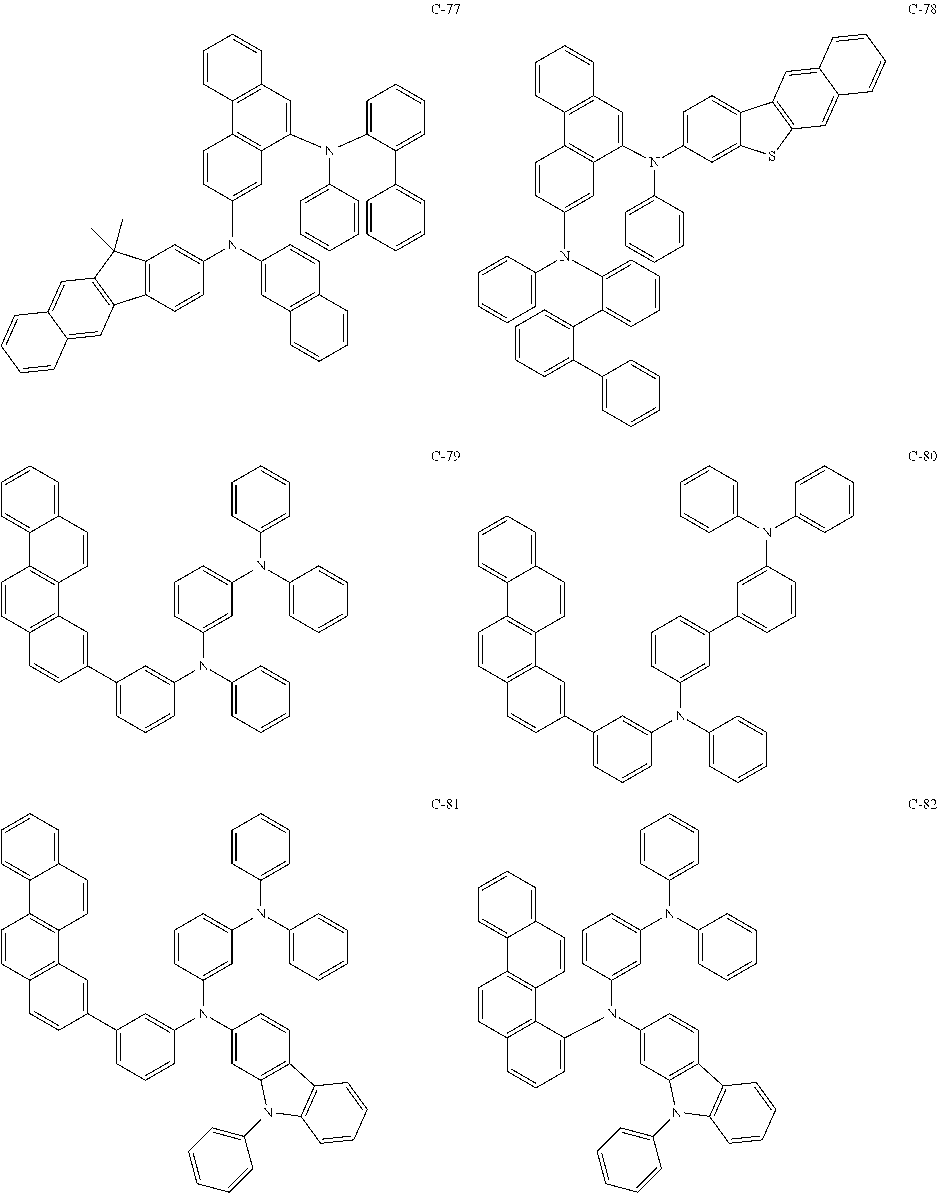

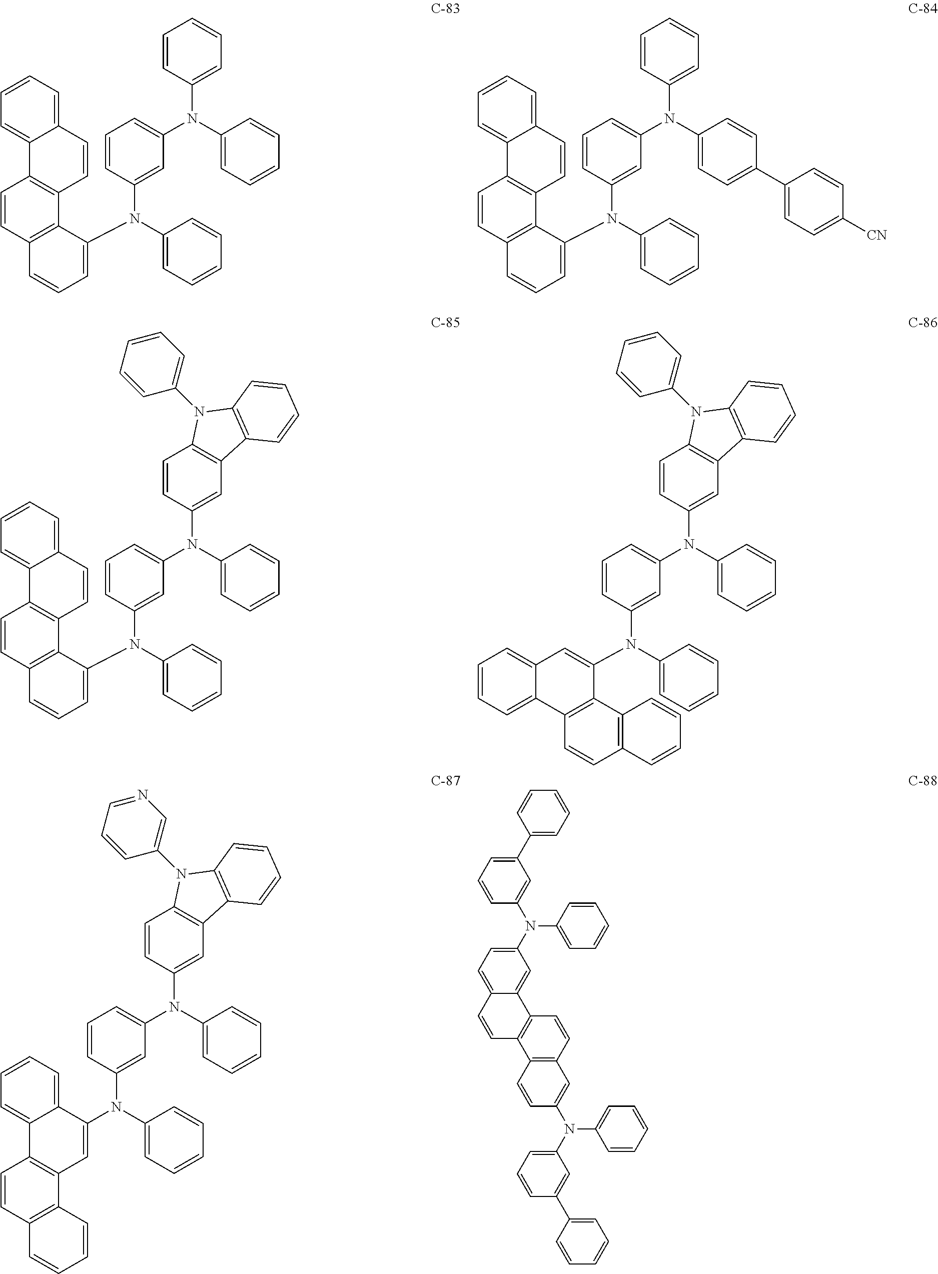

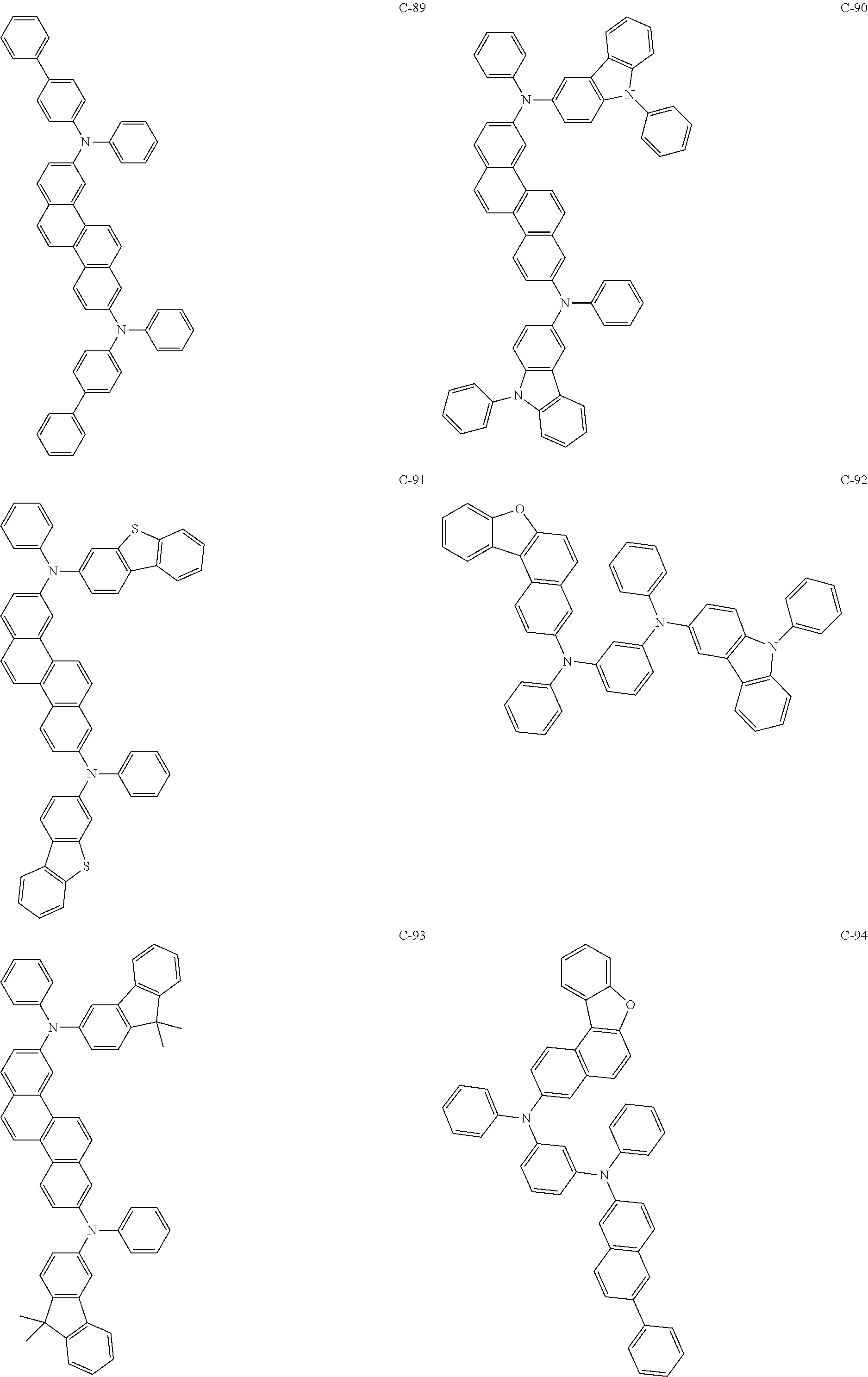

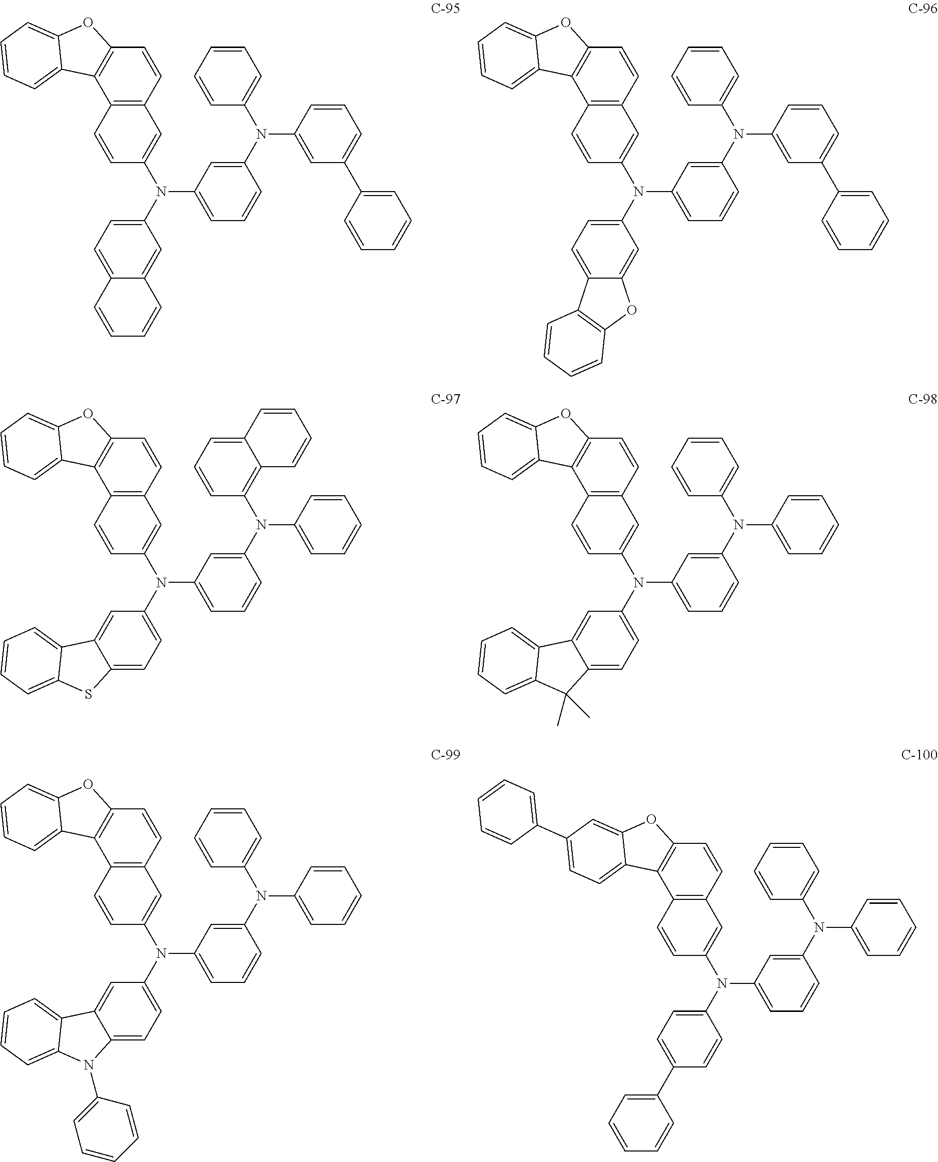

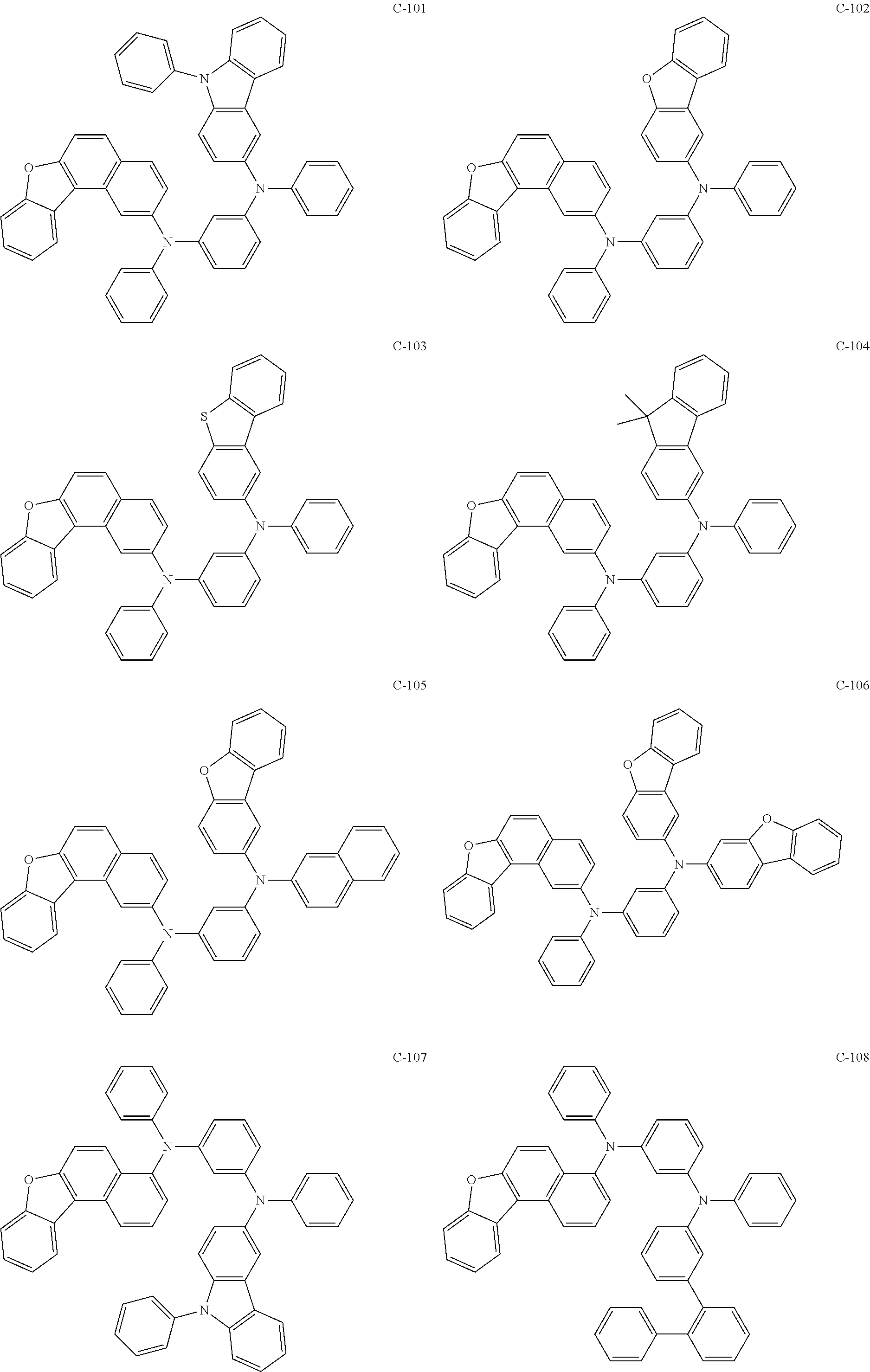

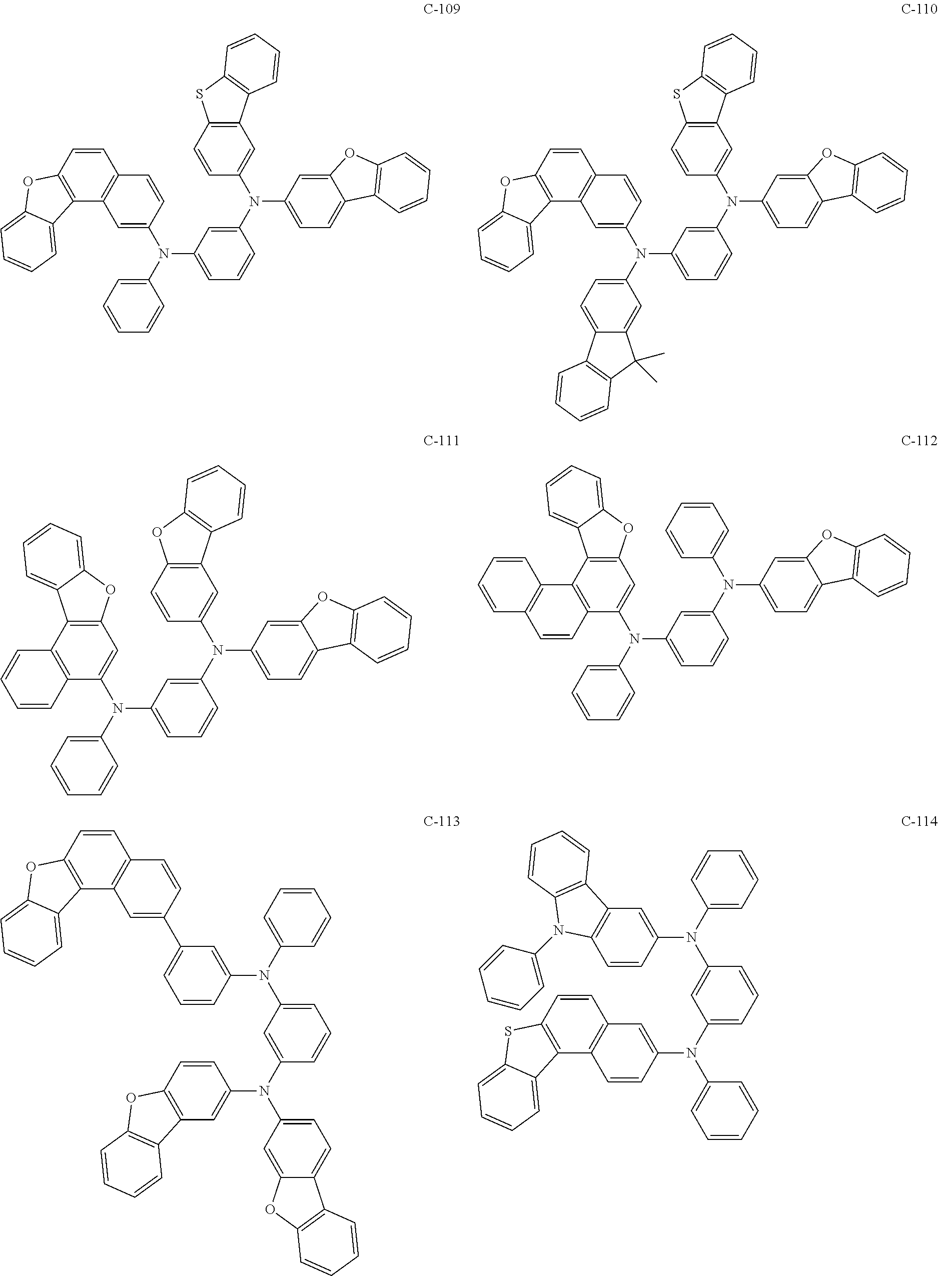

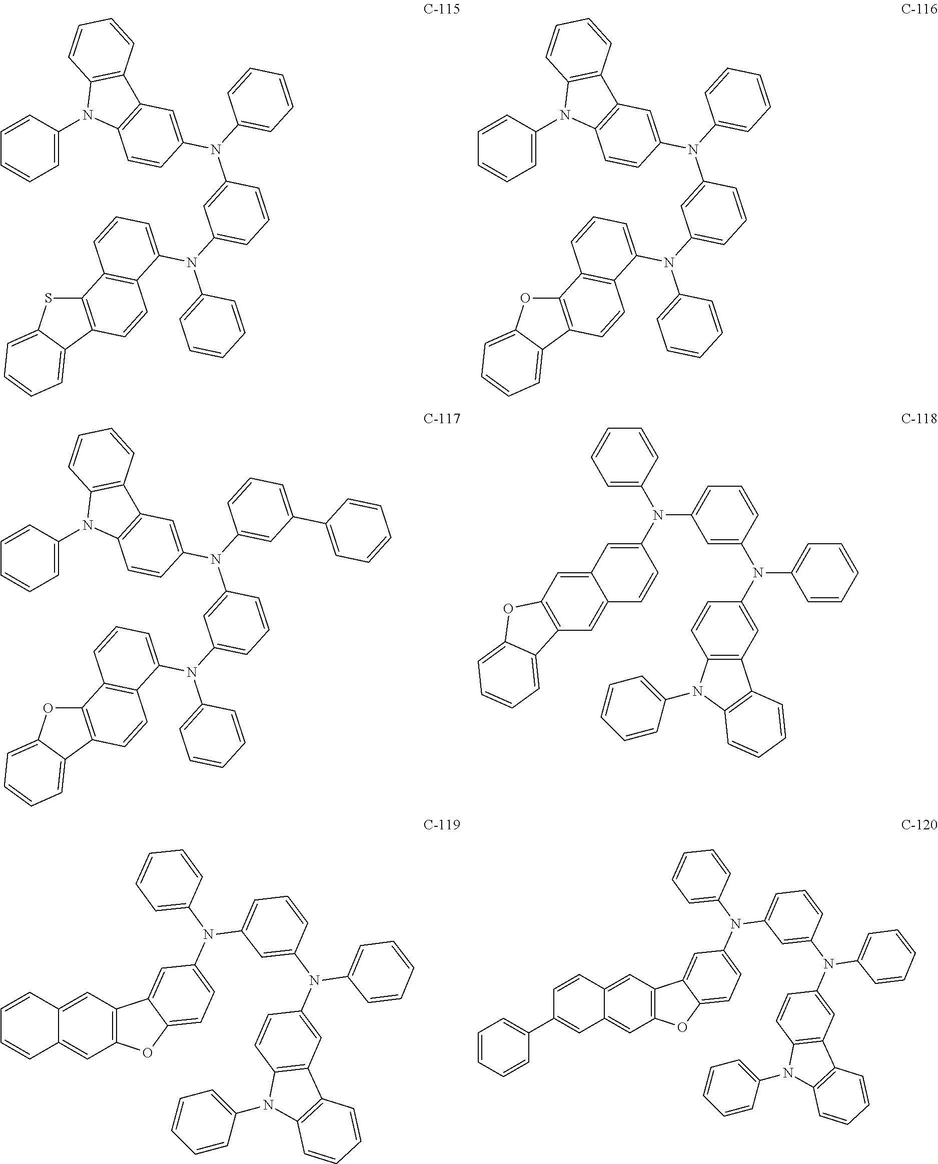

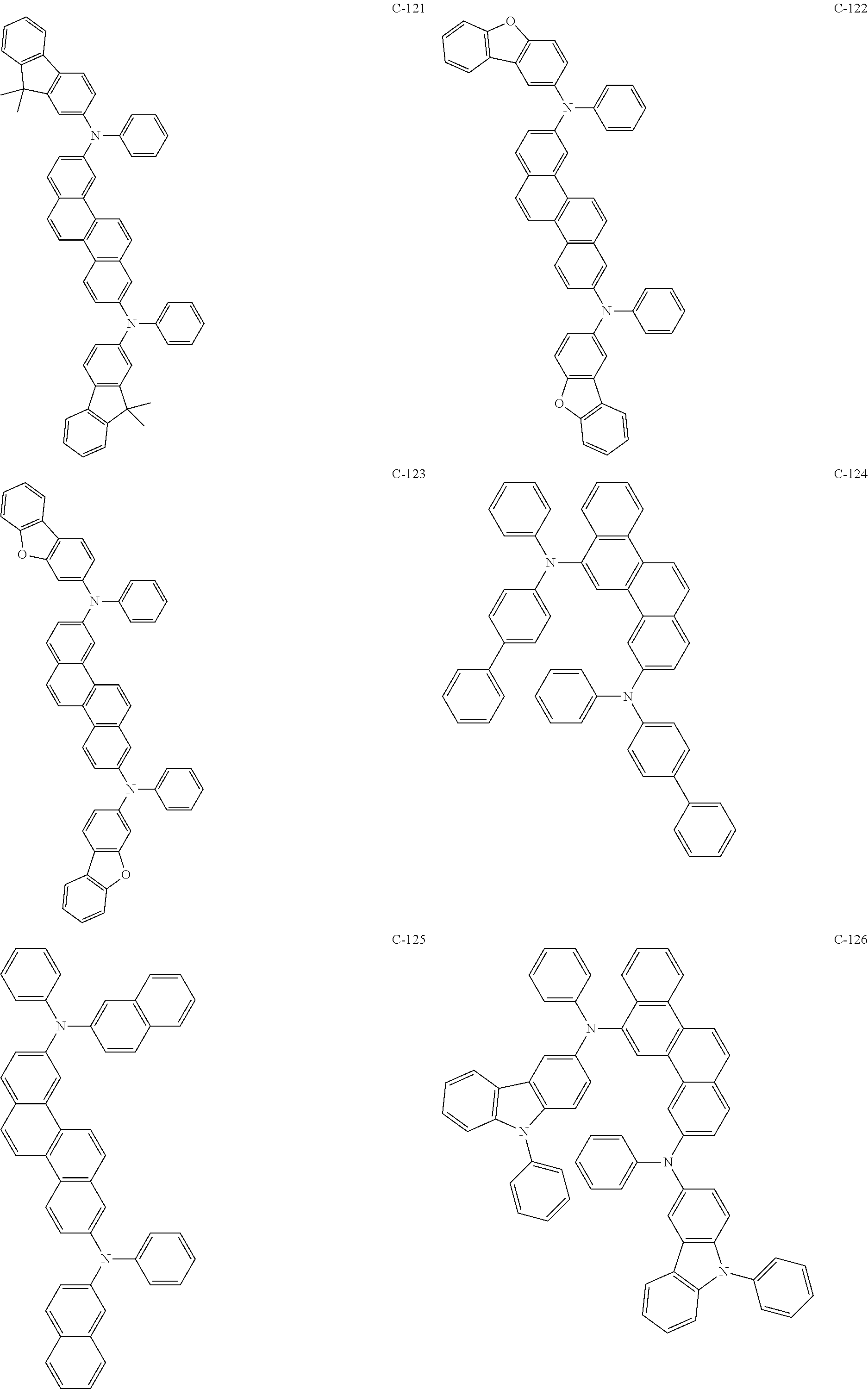

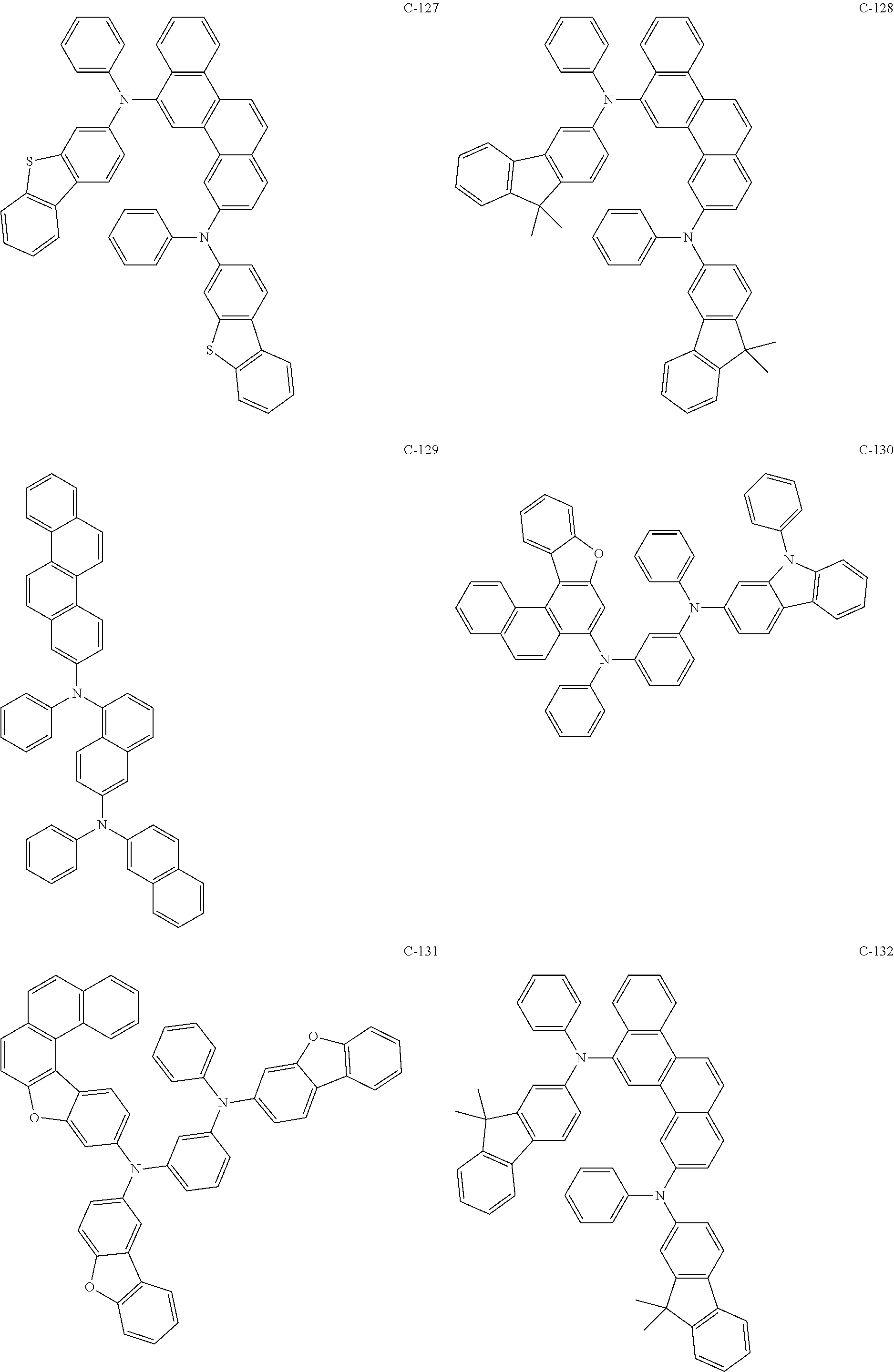

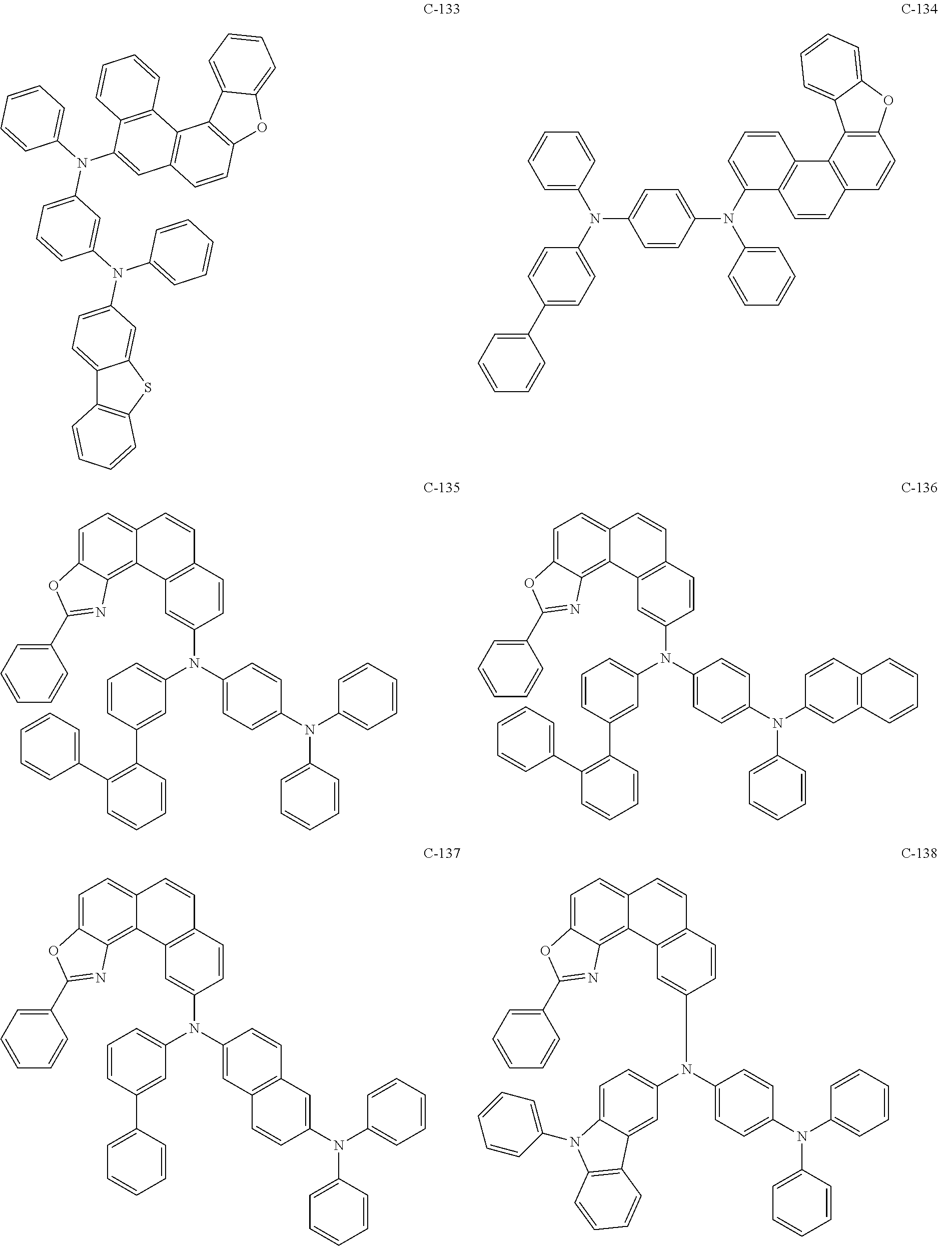

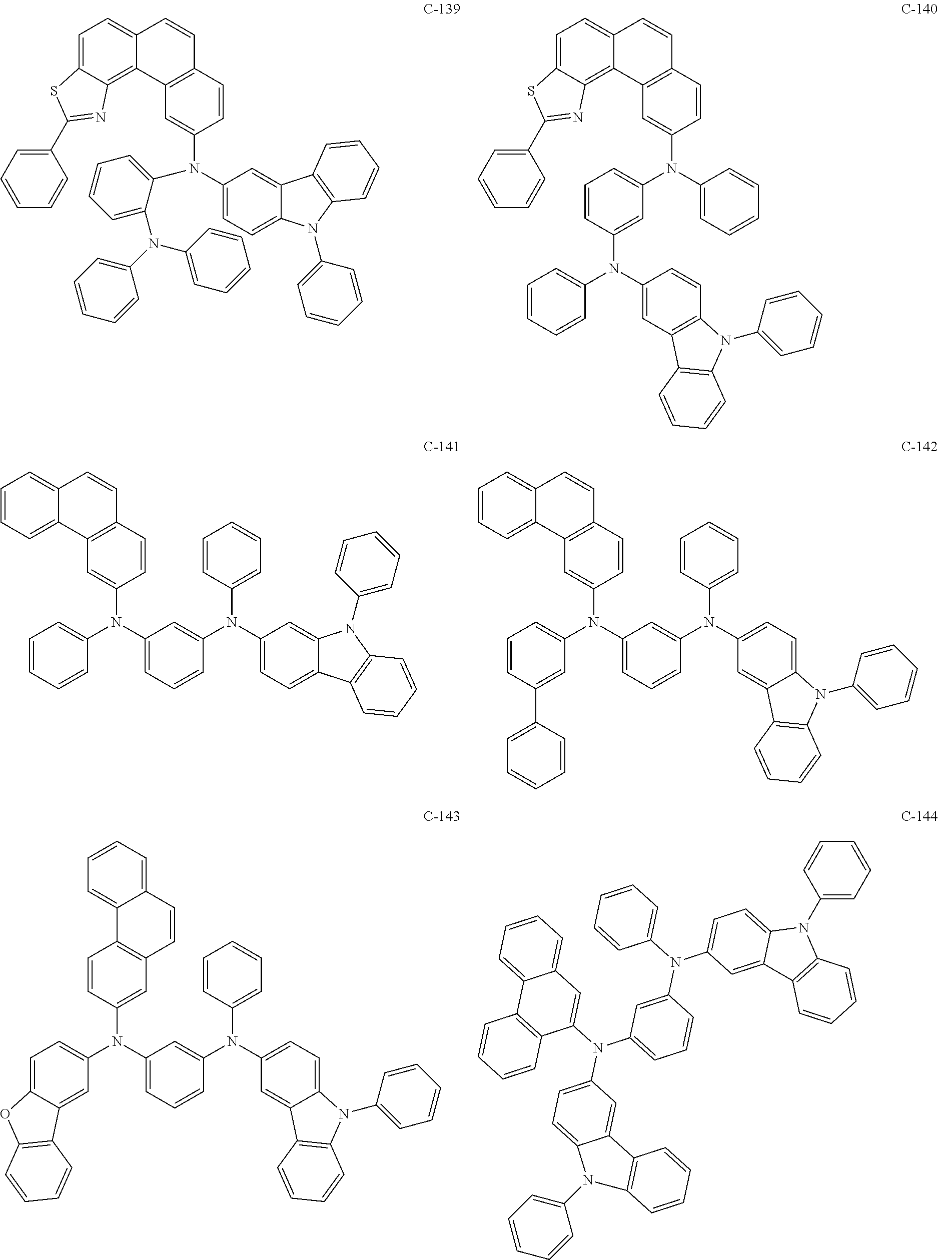

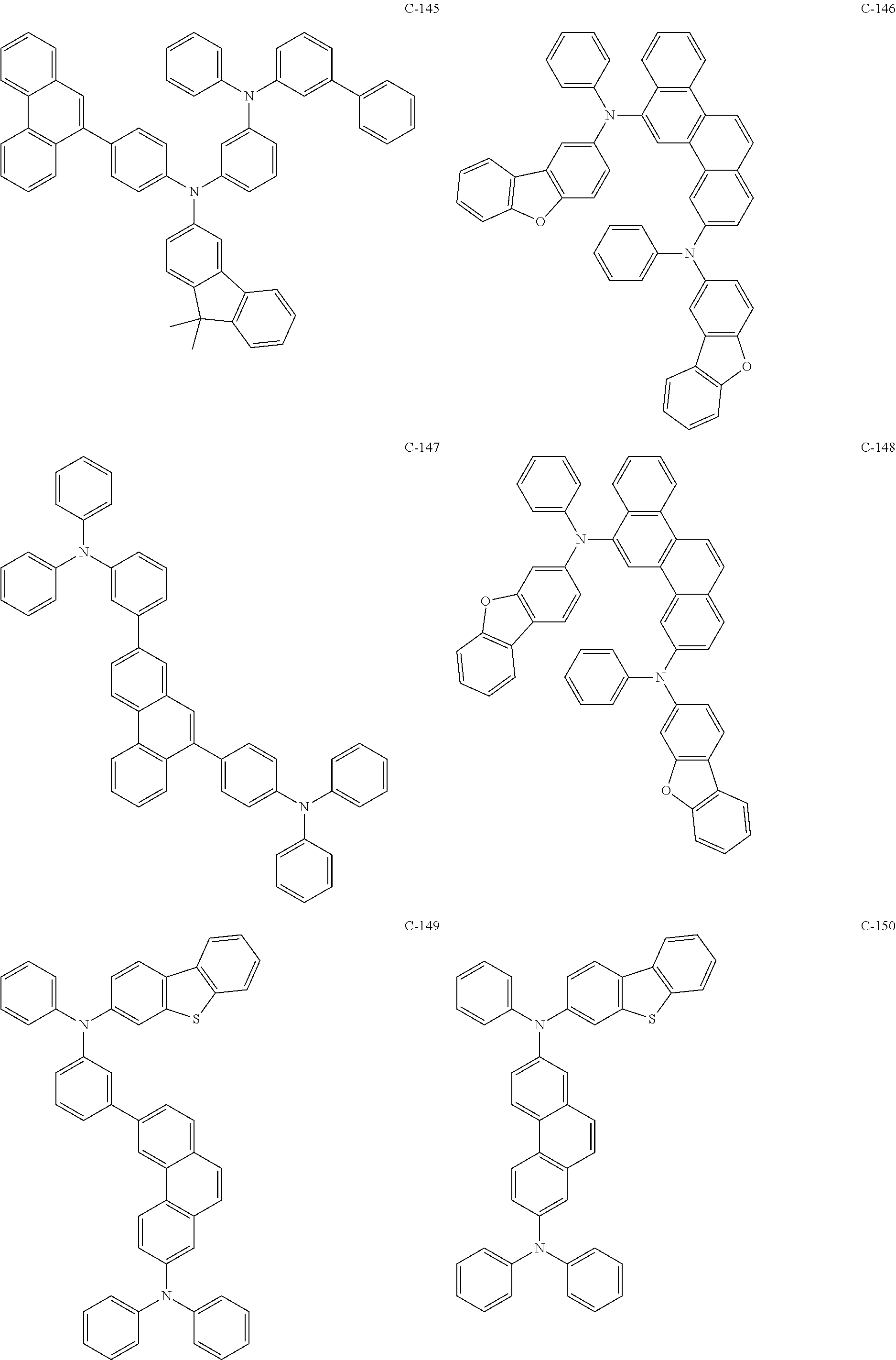

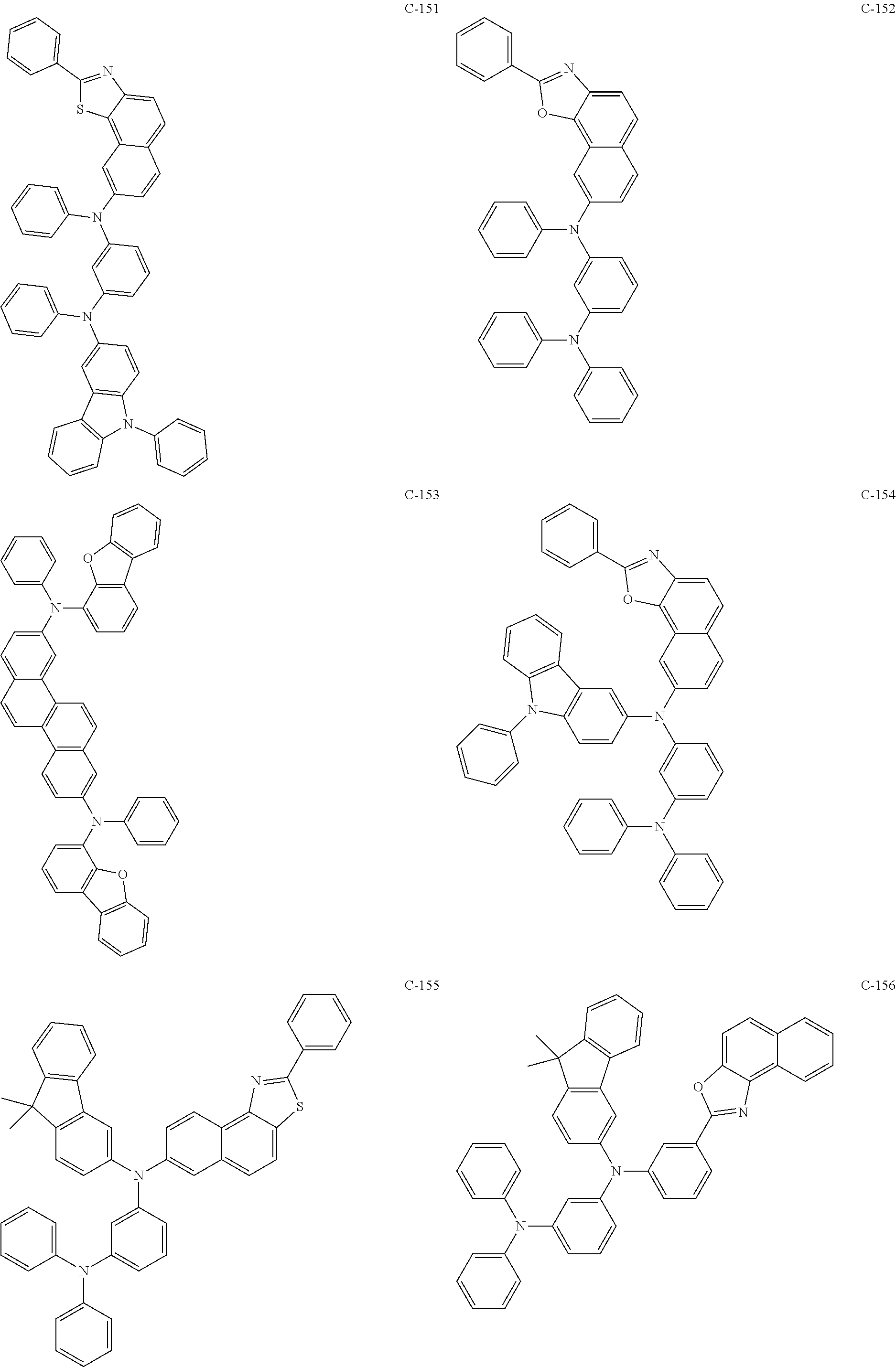

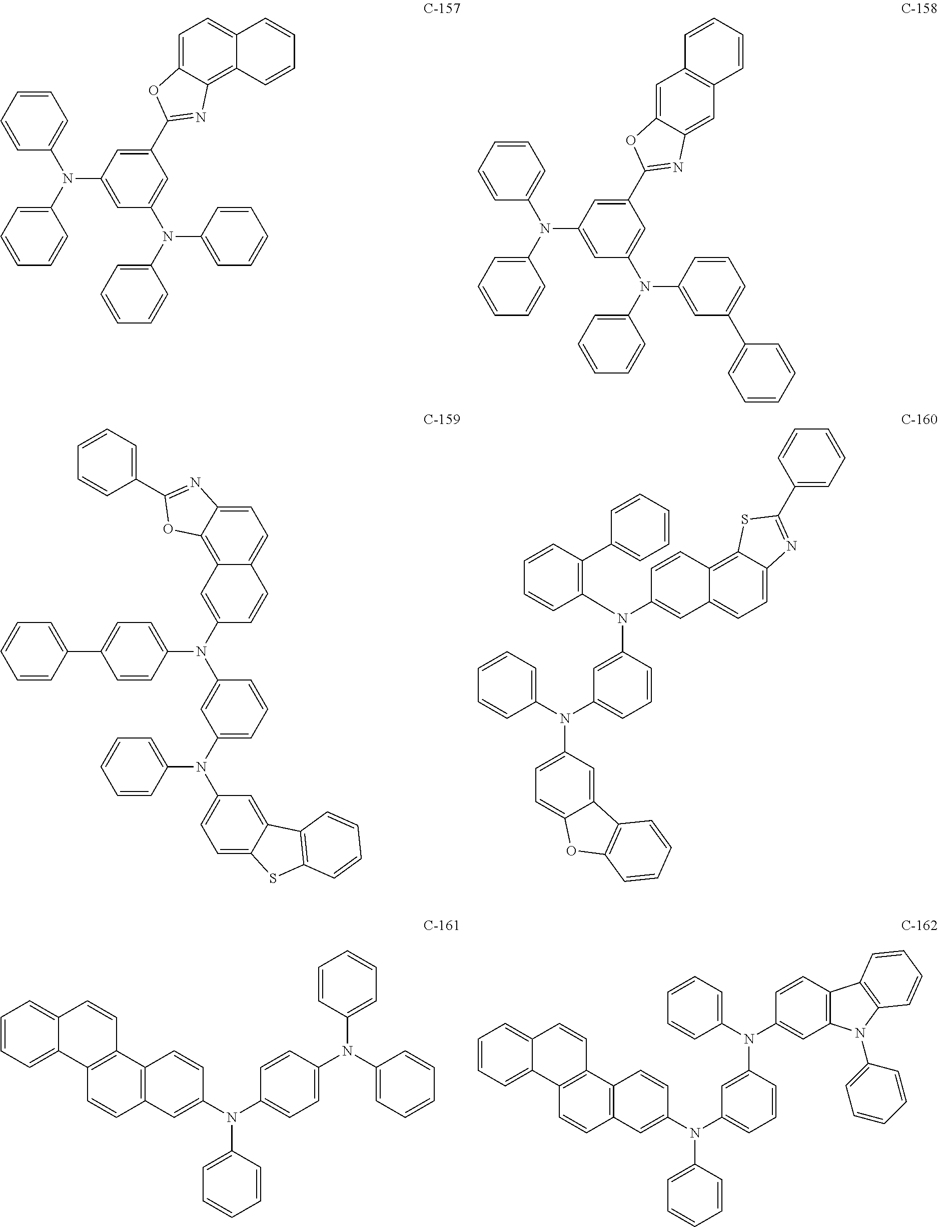

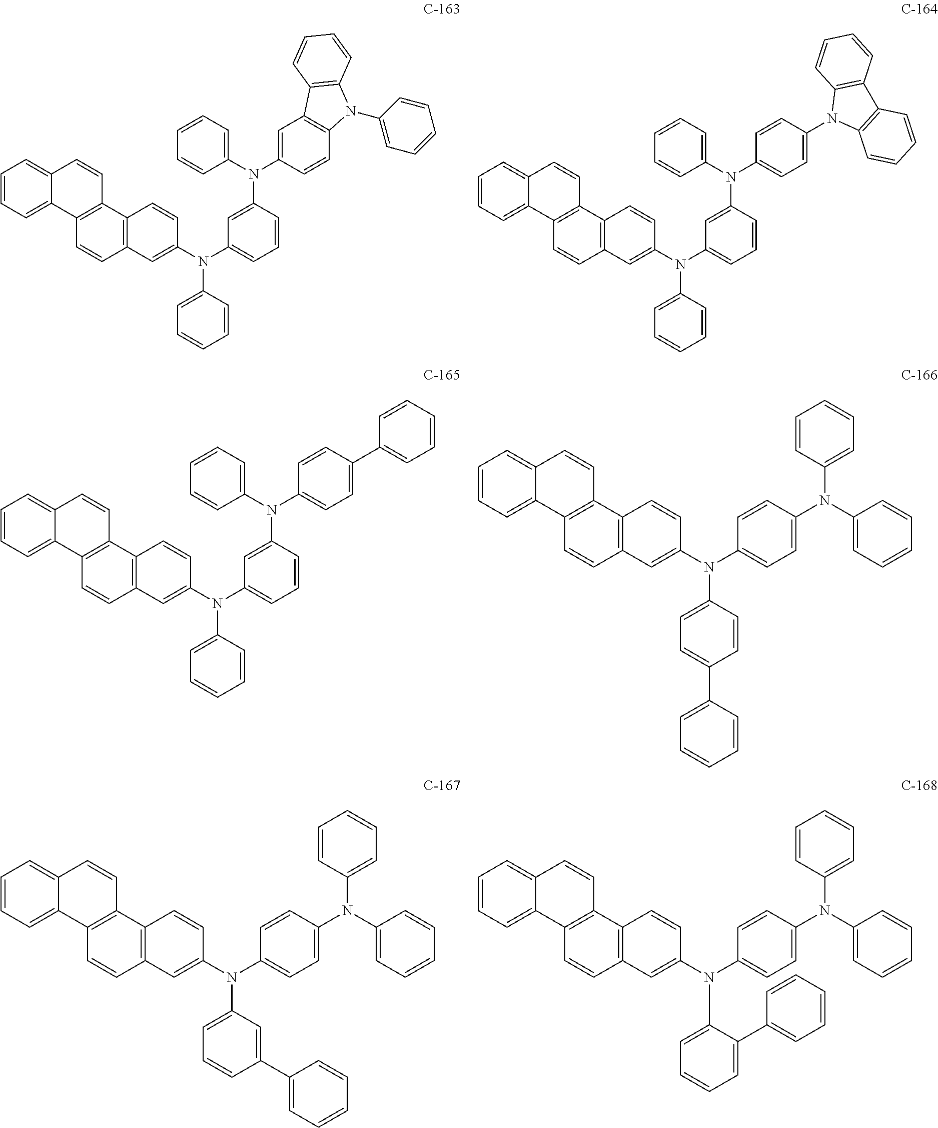

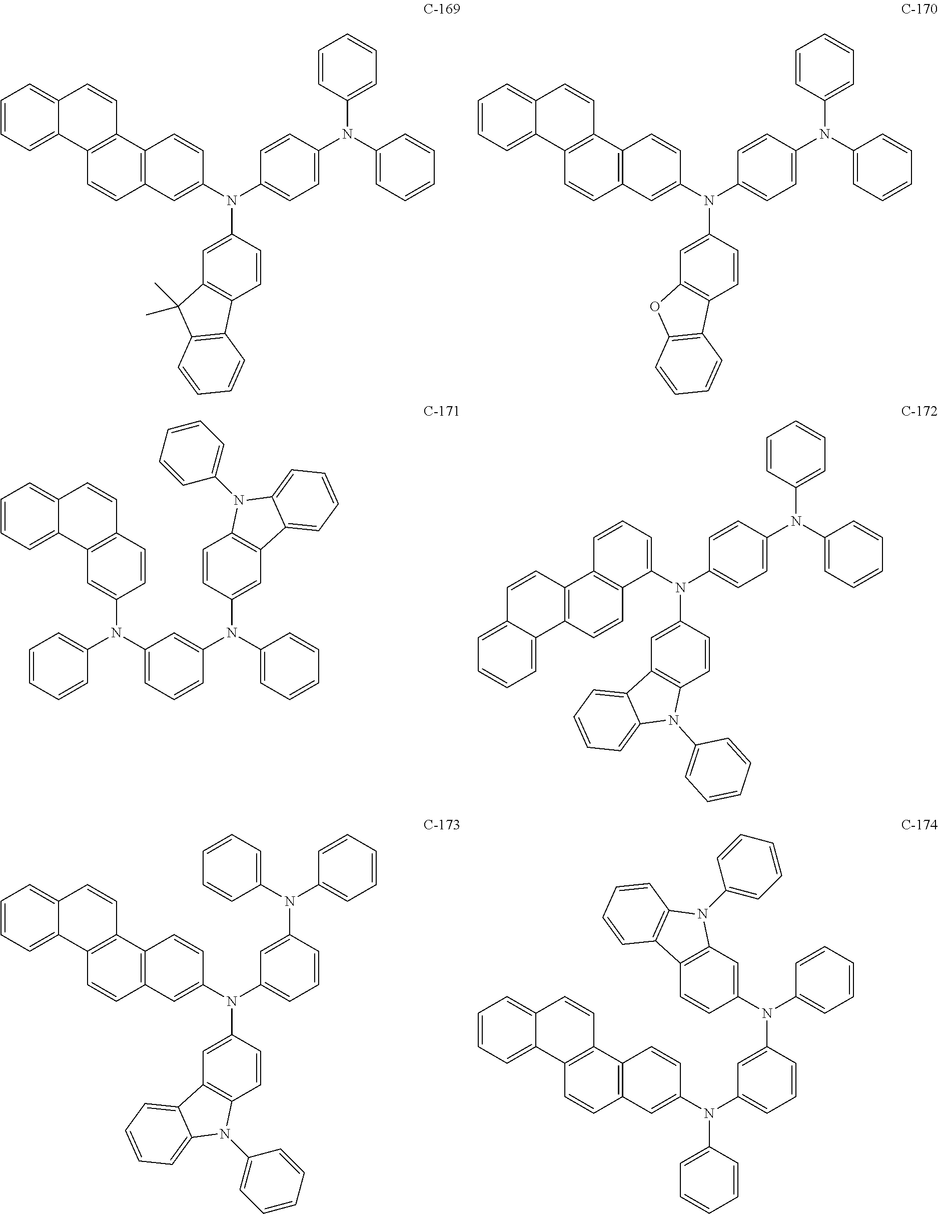

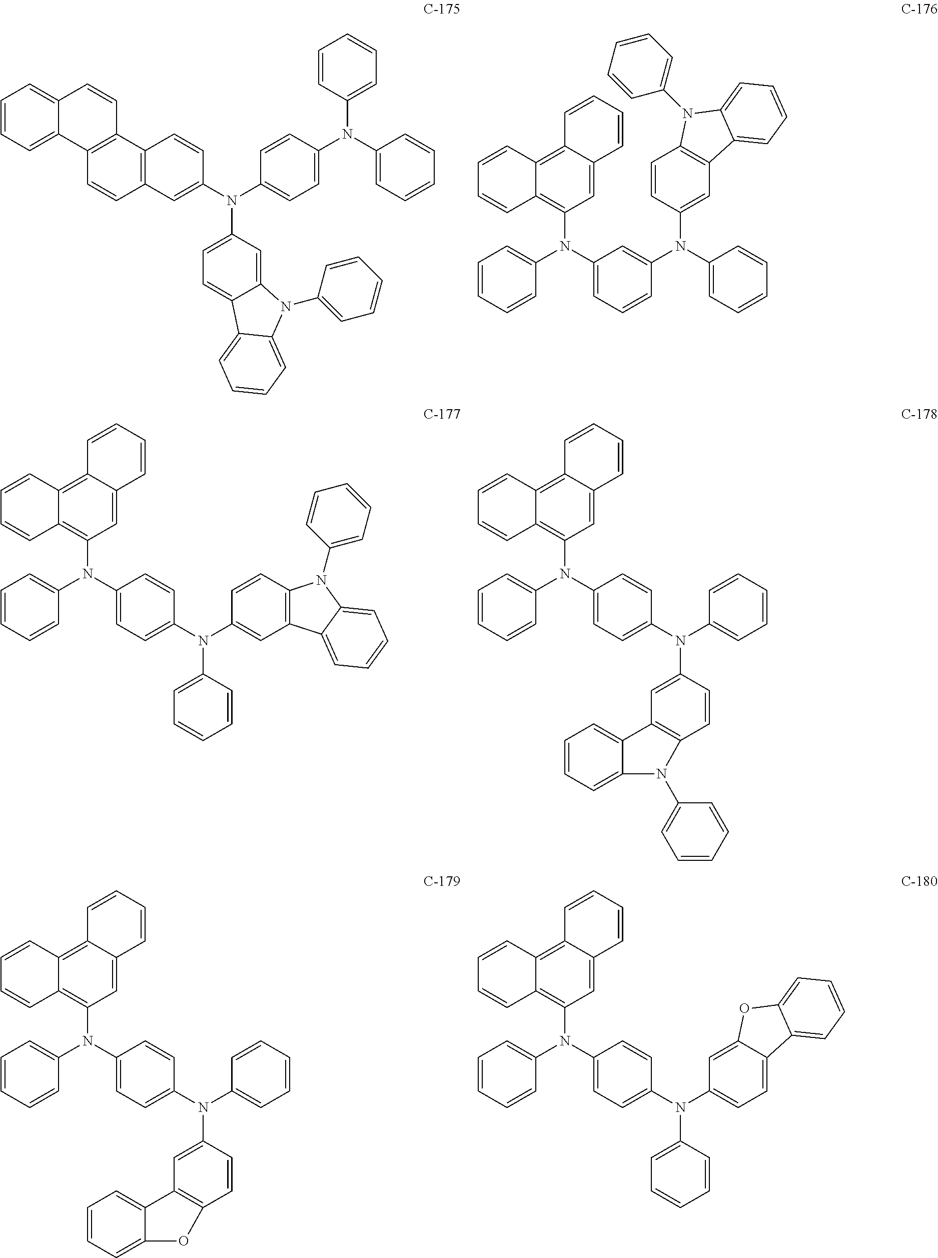

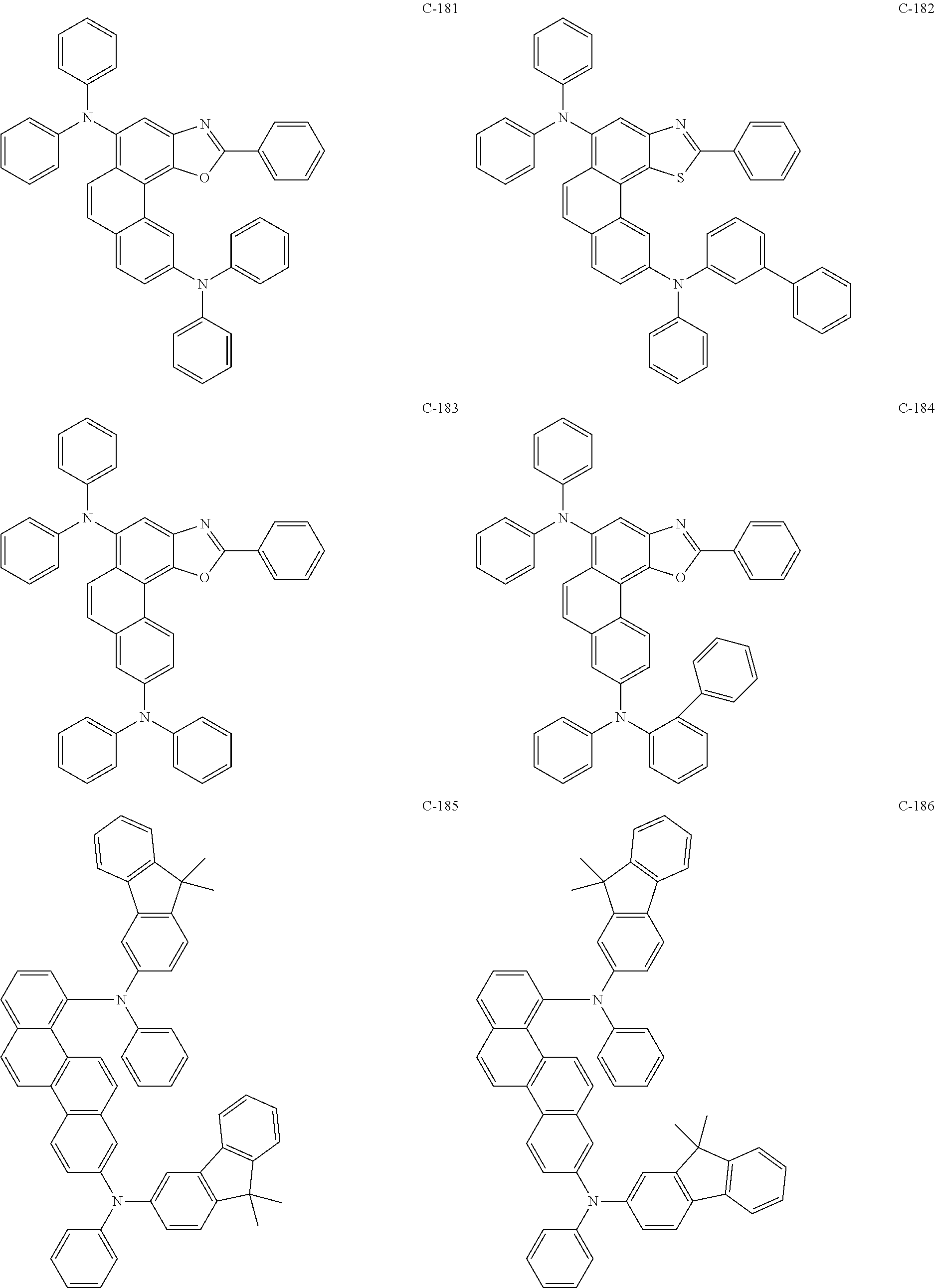

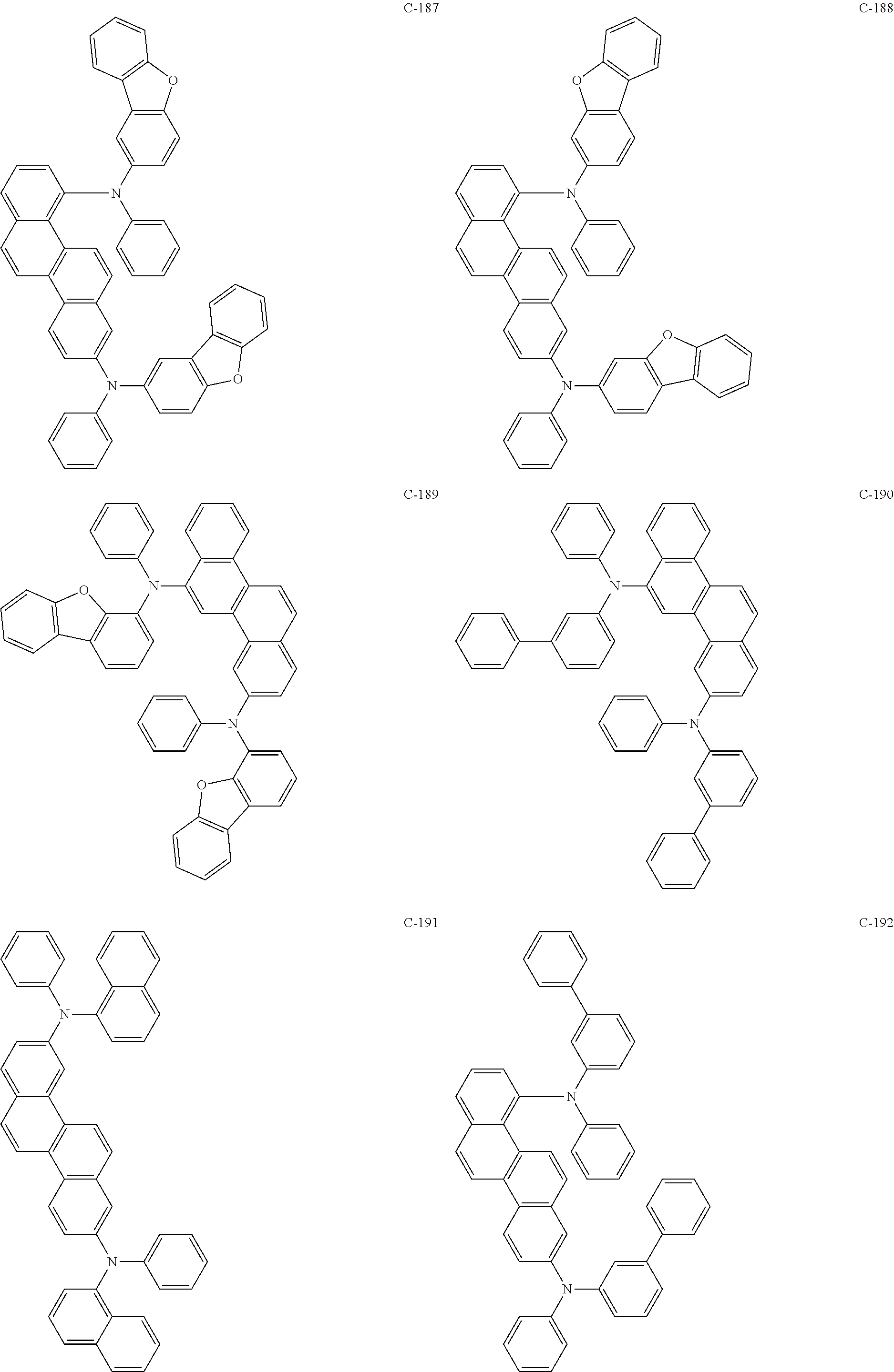

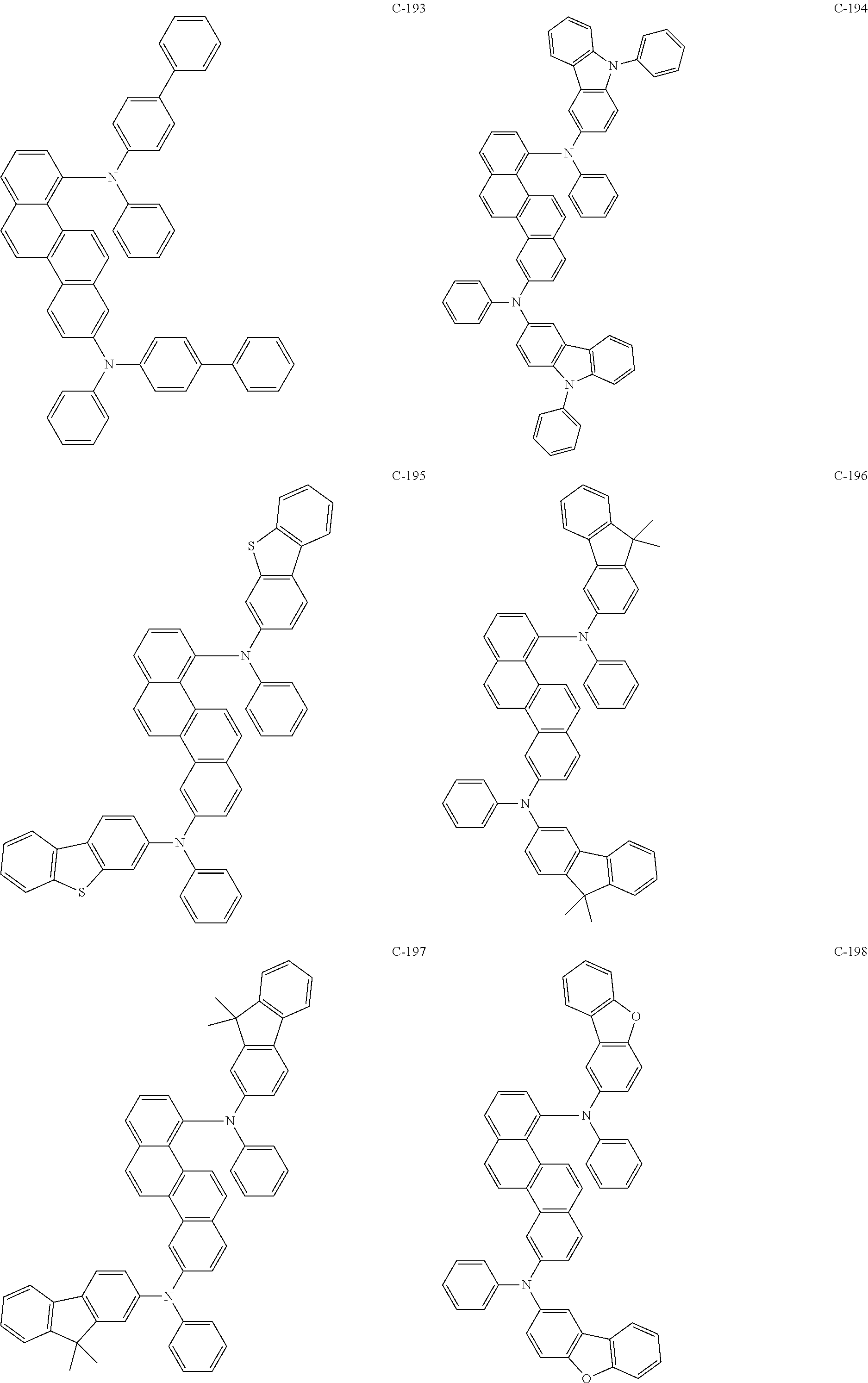

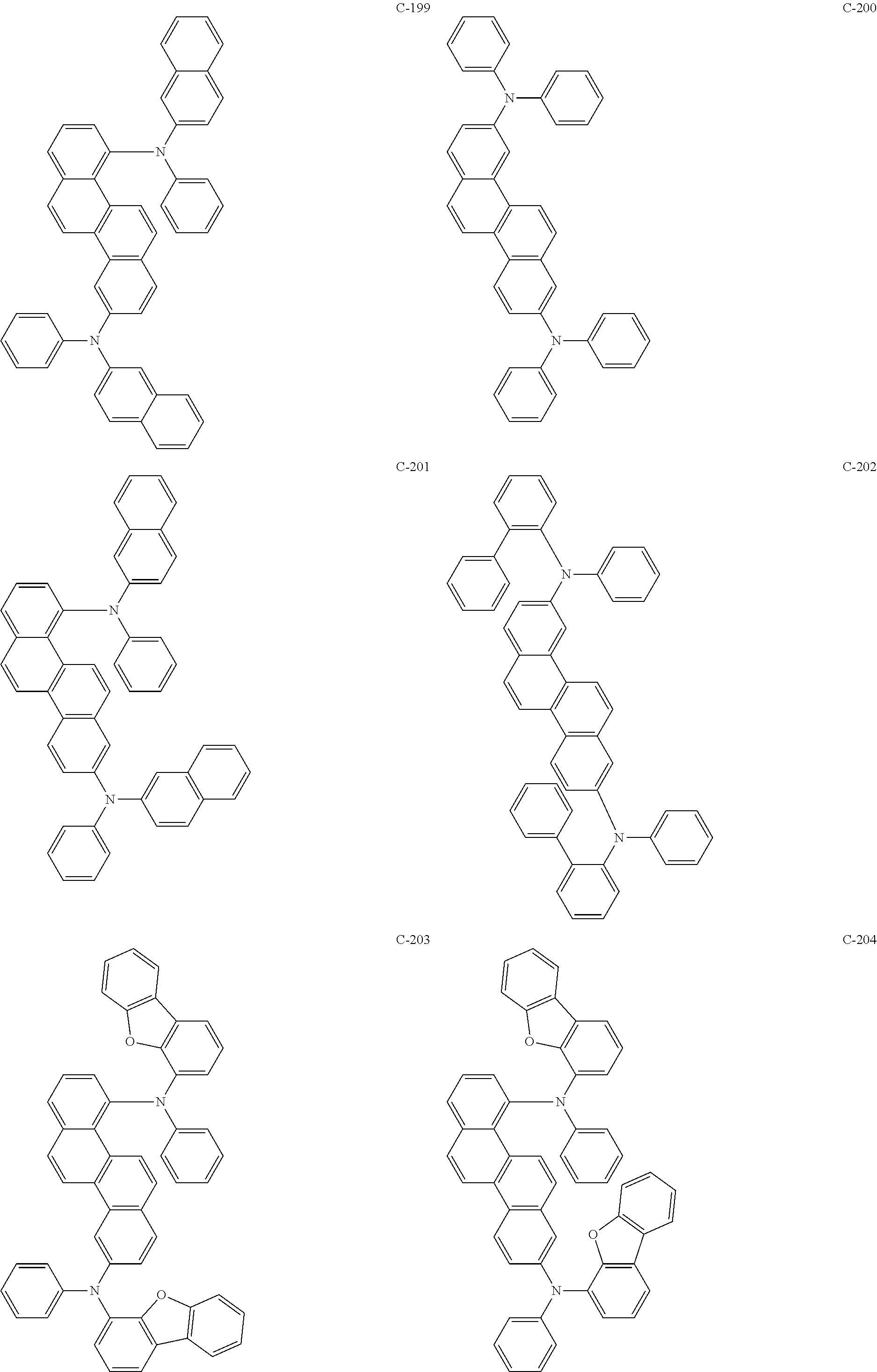

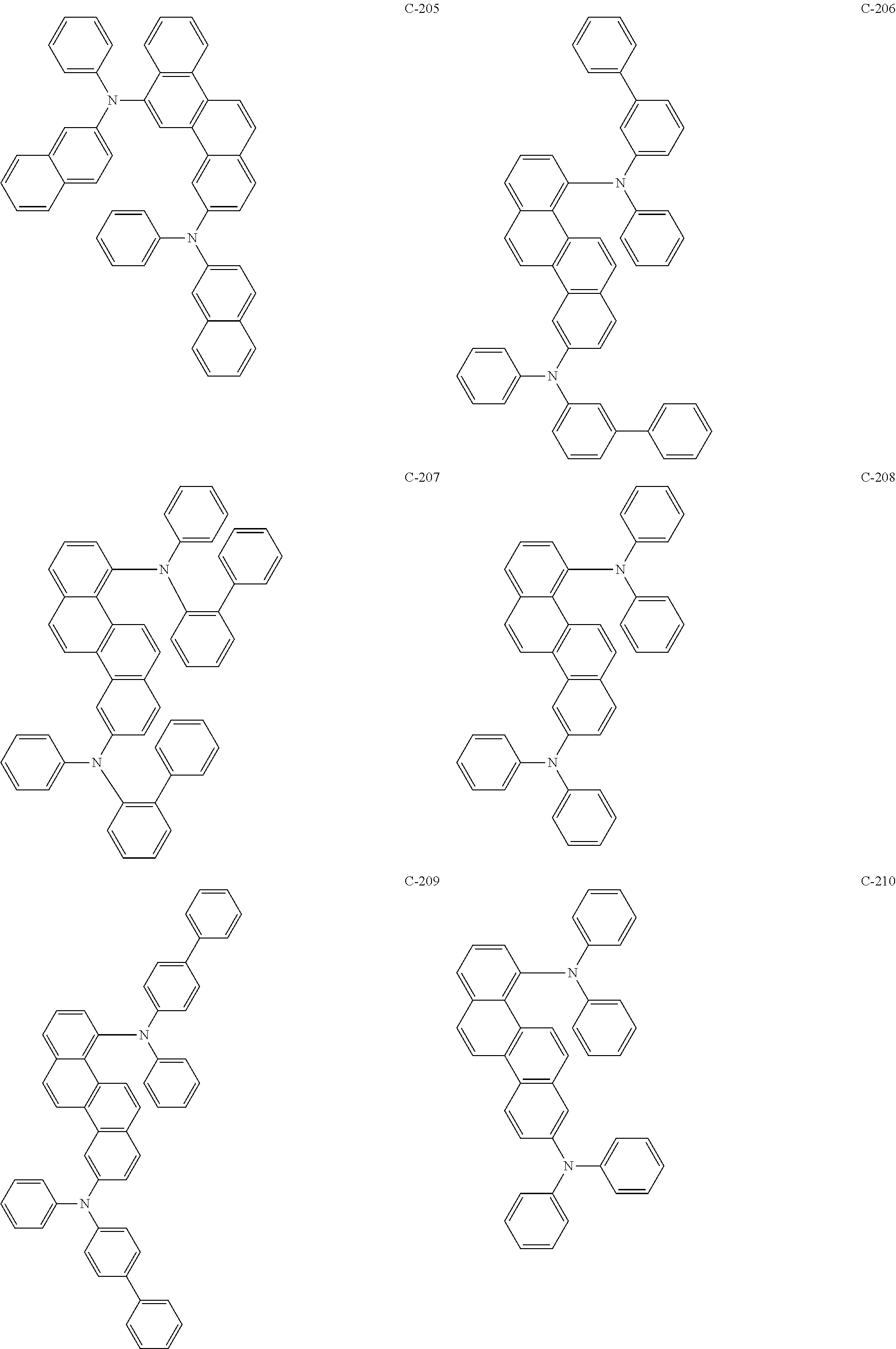

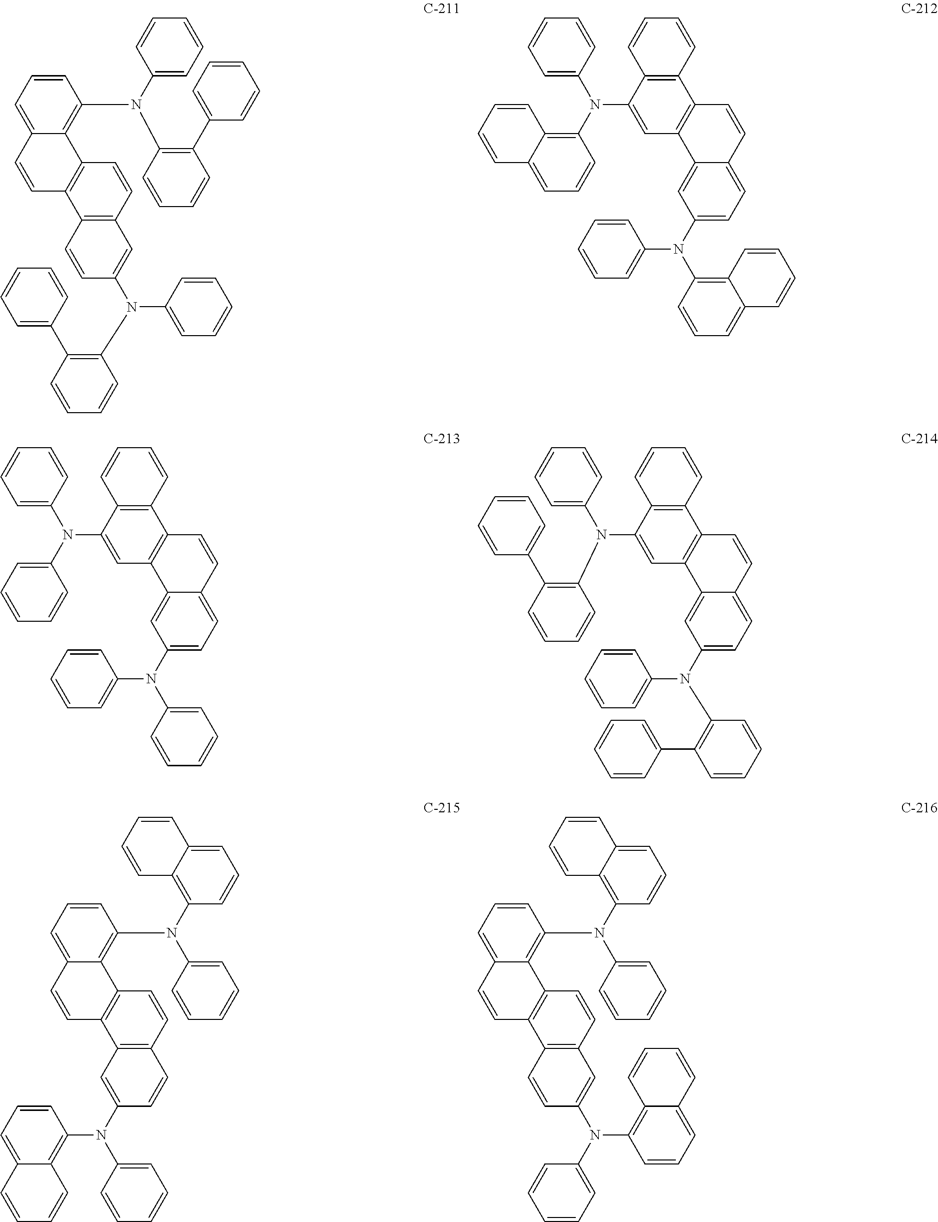

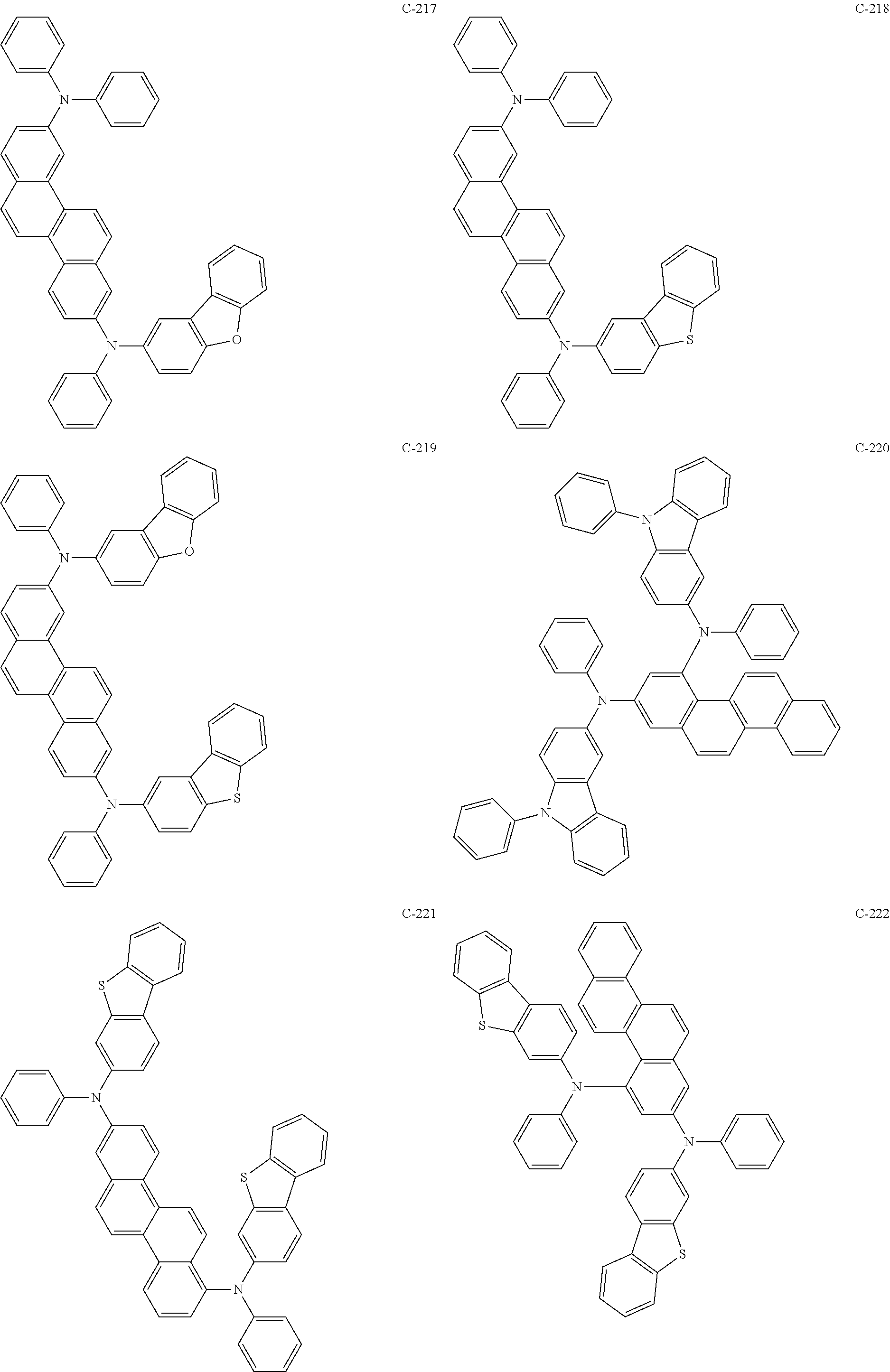

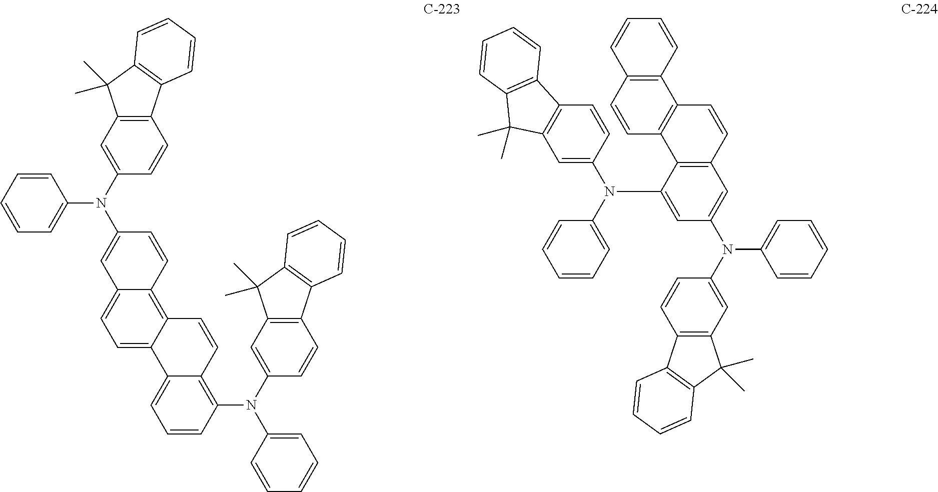 [SMILES: CC1(C)c2ccccc2-c2ccc(N(c3ccccc3)c3ccc4c(ccc5c6cccc(N(c7ccccc7)c7ccc8c(c7)C(C)(C)c7ccccc7-8)c6ccc45)c3)cc21 ; CC1(C)c2ccccc2-c2ccc(N(c3ccccc3)c3cc(N(c4ccccc4)c4ccc5c(c4)C(C)(C)c4ccccc4-5)c4c(ccc5c6ccccc6ccc54)c3)cc21]

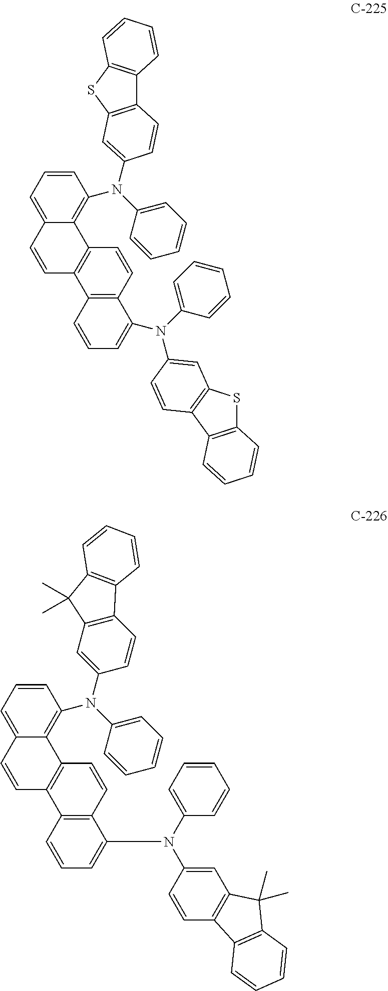 [SMILES: c1ccc(N(c2ccc3c(c2)sc2ccccc23)c2cccc3c2ccc2c3ccc3cccc(N(c4ccccc4)c4ccc5c(c4)sc4ccccc45)c32)cc1 ; CC1(C)c2ccccc2-c2ccc(N(c3ccccc3)c3cccc4c3ccc3c4ccc4cccc(N(c5ccccc5)c5ccc6c(c5)C(C)(C)c5ccccc5-6)c43)cc21]

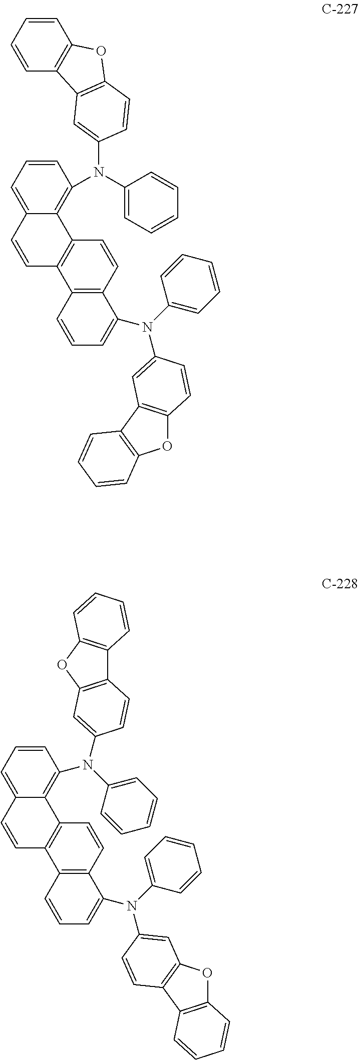 [SMILES: c1ccc(N(c2ccc3oc4ccccc4c3c2)c2cccc3c2ccc2c3ccc3cccc(N(c4ccccc4)c4ccc5oc6ccccc6c5c4)c32)cc1 ; c1ccc(N(c2ccc3c(c2)oc2ccccc23)c2cccc3c2ccc2c3ccc3cccc(N(c4ccccc4)c4ccc5c(c4)oc4ccccc45)c32)cc1]

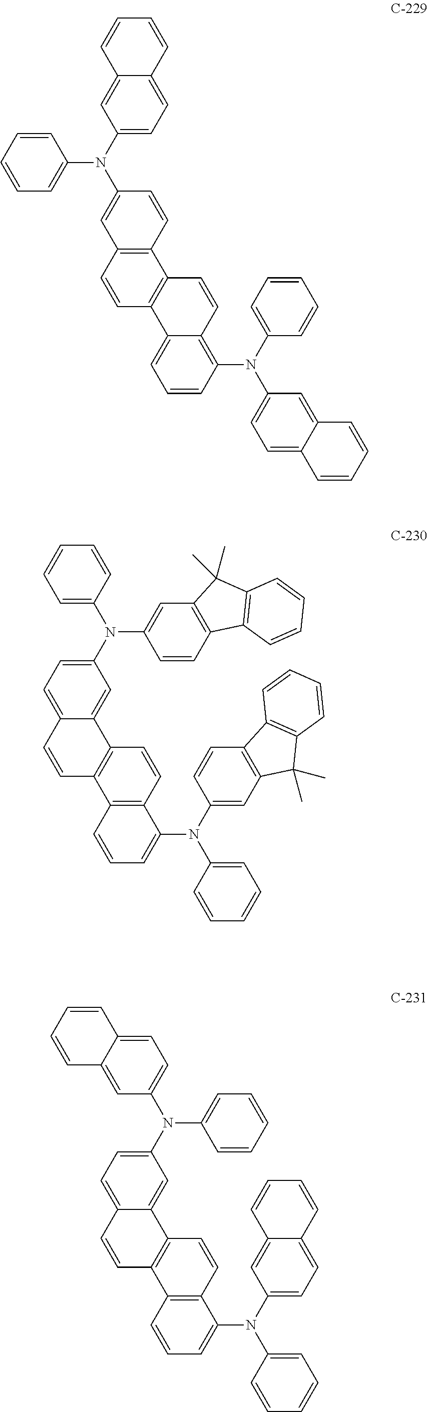 [SMILES: c1ccc(N(c2ccc3ccccc3c2)c2ccc3c(ccc4c5cccc(N(c6ccccc6)c6ccc7ccccc7c6)c5ccc34)c2)cc1 ; CC1(C)c2ccccc2-c2ccc(N(c3ccccc3)c3ccc4ccc5c6cccc(N(c7ccccc7)c7ccc8c(c7)C(C)(C)c7ccccc7-8)c6ccc5c4c3)cc21 ; c1ccc(N(c2ccc3ccccc3c2)c2ccc3ccc4c5cccc(N(c6ccccc6)c6ccc7ccccc7c6)c5ccc4c3c2)cc1]

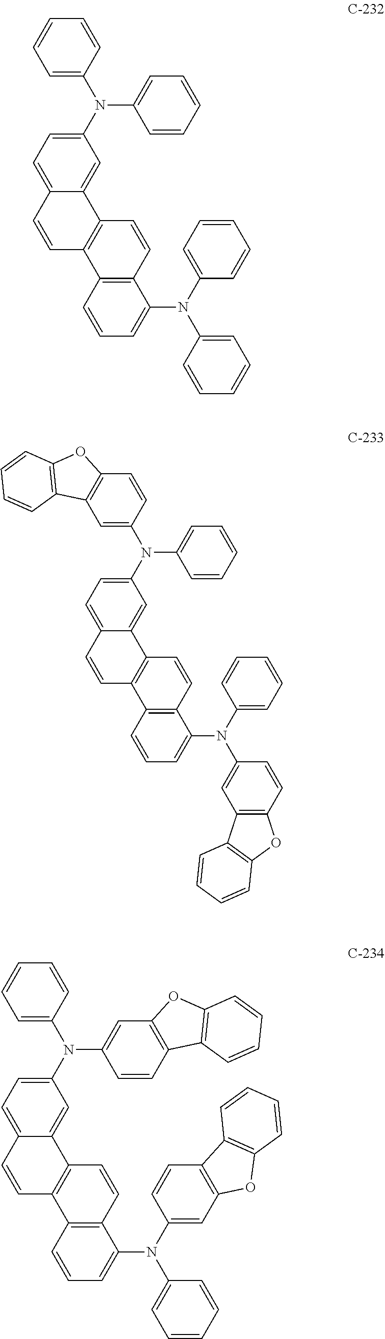 [SMILES: c1ccc(N(c2ccccc2)c2ccc3ccc4c5cccc(N(c6ccccc6)c6ccccc6)c5ccc4c3c2)cc1 ; c1ccc(N(c2ccc3ccc4c5cccc(N(c6ccccc6)c6ccc7oc8ccccc8c7c6)c5ccc4c3c2)c2ccc3oc4ccccc4c3c2)cc1 ; c1ccc(N(c2ccc3c(c2)oc2ccccc23)c2ccc3ccc4c5cccc(N(c6ccccc6)c6ccc7c(c6)oc6ccccc67)c5ccc4c3c2)cc1]

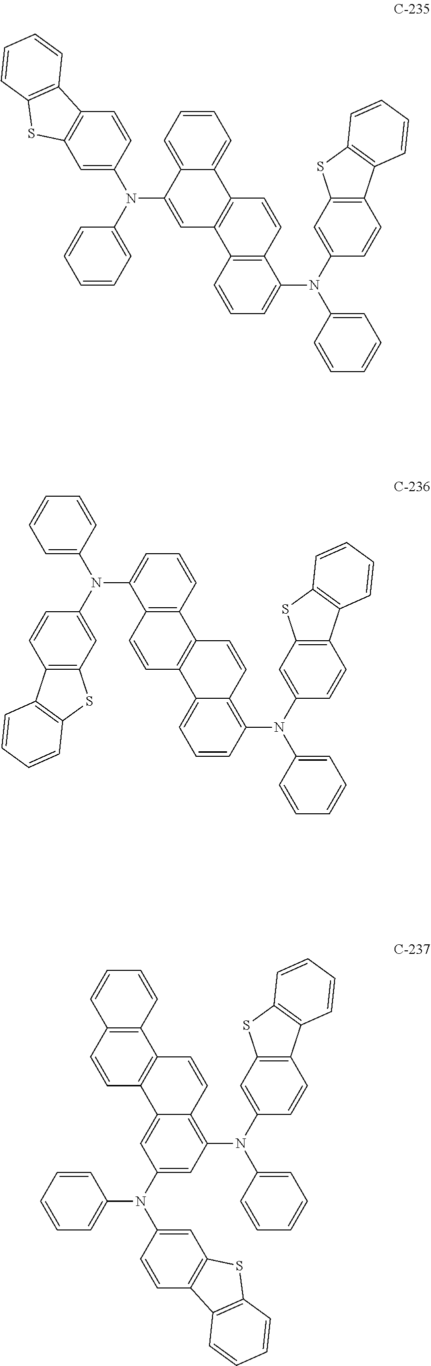 [SMILES: c1ccc(N(c2ccc3c(c2)sc2ccccc23)c2cc3c4cccc(N(c5ccccc5)c5ccc6c(c5)sc5ccccc56)c4ccc3c3ccccc23)cc1 ; c1ccc(N(c2ccc3c(c2)sc2ccccc23)c2cccc3c2ccc2c4cccc(N(c5ccccc5)c5ccc6c(c5)sc5ccccc56)c4ccc32)cc1 ; c1ccc(N(c2ccc3c(c2)sc2ccccc23)c2cc(N(c3ccccc3)c3ccc4c(c3)sc3ccccc34)c3ccc4c5ccccc5ccc4c3c2)cc1]

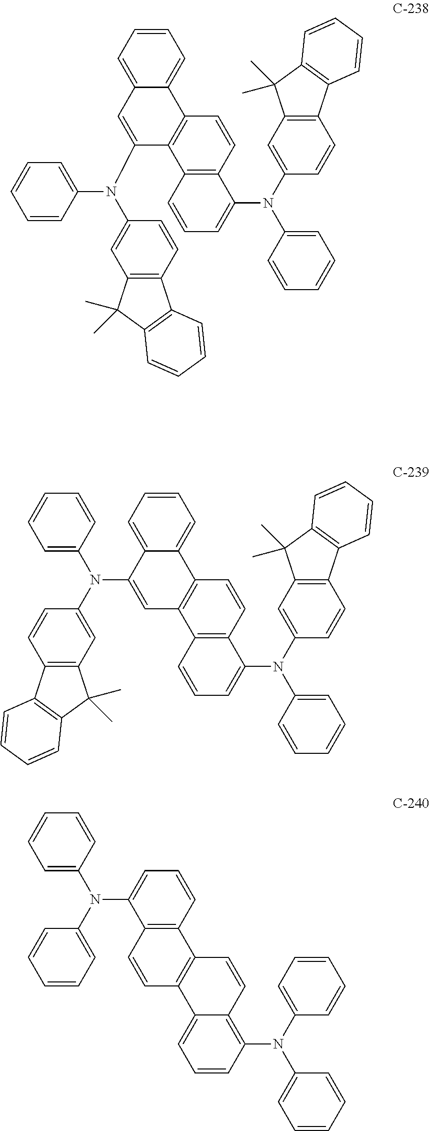 [SMILES: CC1(C)c2ccccc2-c2ccc(N(c3ccccc3)c3cccc4c3ccc3c5ccccc5cc(N(c5ccccc5)c5ccc6c(c5)C(C)(C)c5ccccc5-6)c43)cc21 ; CC1(C)c2ccccc2-c2ccc(N(c3ccccc3)c3cc4c5cccc(N(c6ccccc6)c6ccc7c(c6)C(C)(C)c6ccccc6-7)c5ccc4c4ccccc34)cc21 ; c1ccc(N(c2ccccc2)c2cccc3c2ccc2c4cccc(N(c5ccccc5)c5ccccc5)c4ccc32)cc1]

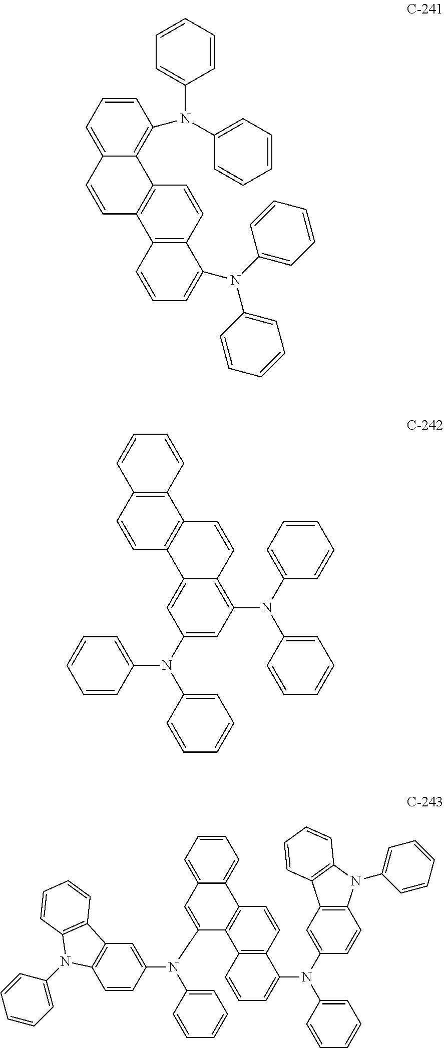

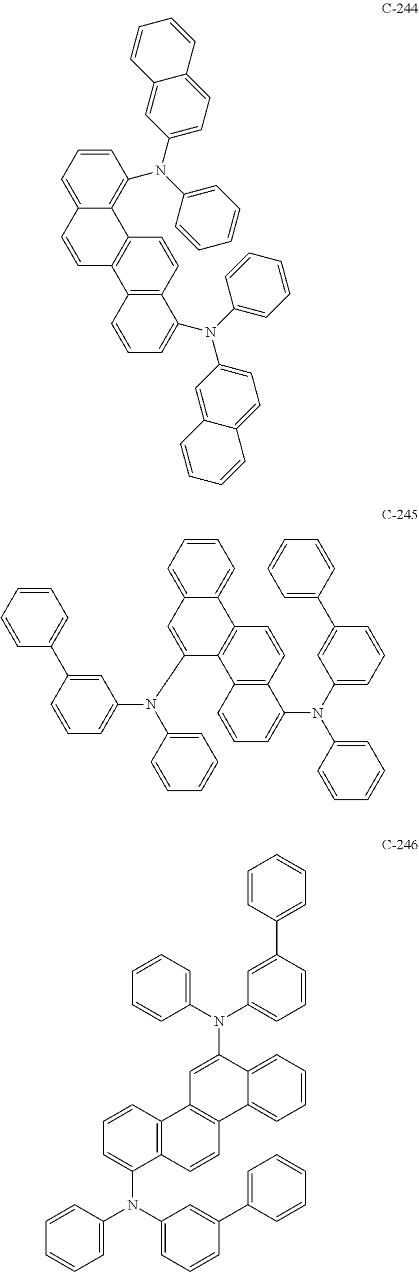

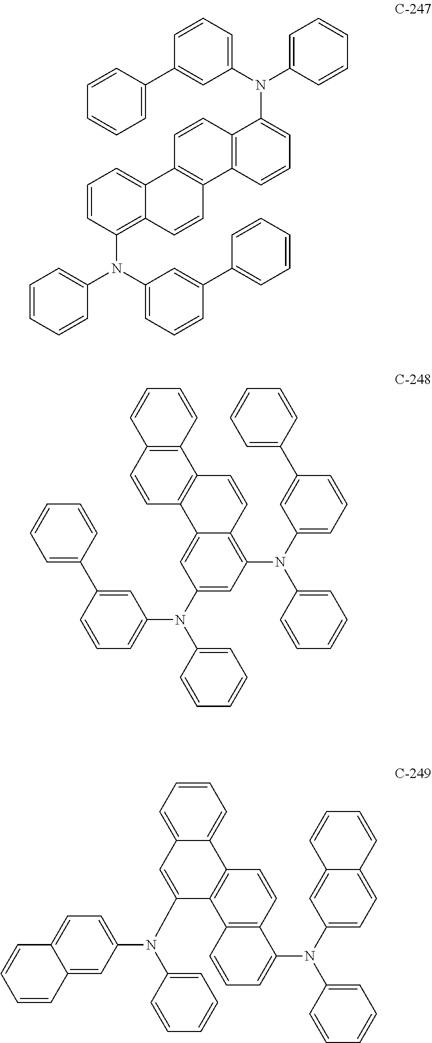

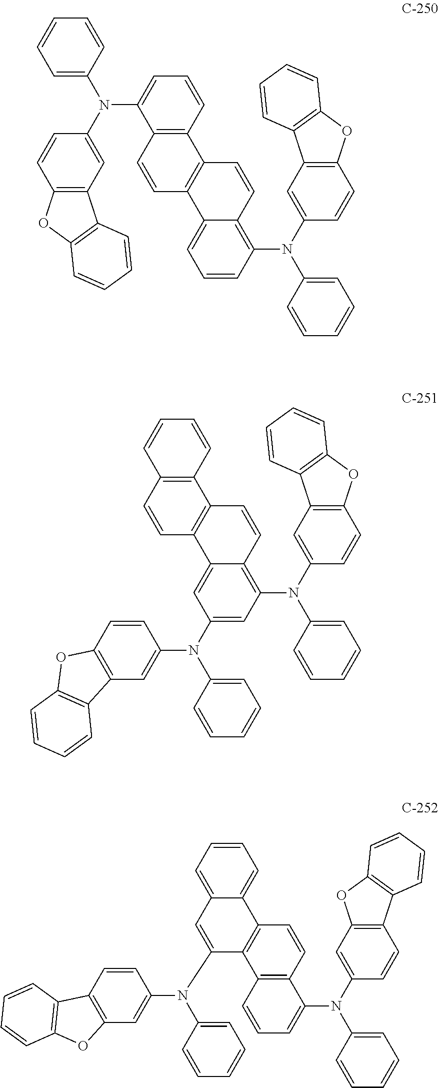 [SMILES: c1ccc(N(c2ccc3oc4ccccc4c3c2)c2cccc3c2ccc2c4cccc(N(c5ccccc5)c5ccc6oc7ccccc7c6c5)c4ccc32)cc1 ; c1ccc(N(c2ccc3oc4ccccc4c3c2)c2cc(N(c3ccccc3)c3ccc4oc5ccccc5c4c3)c3ccc4c5ccccc5ccc4c3c2)cc1 ; c1ccc(N(c2ccc3c(c2)oc2ccccc23)c2cccc3c2ccc2c4ccccc4cc(N(c4ccccc4)c4ccc5c(c4)oc4ccccc45)c32)cc1]

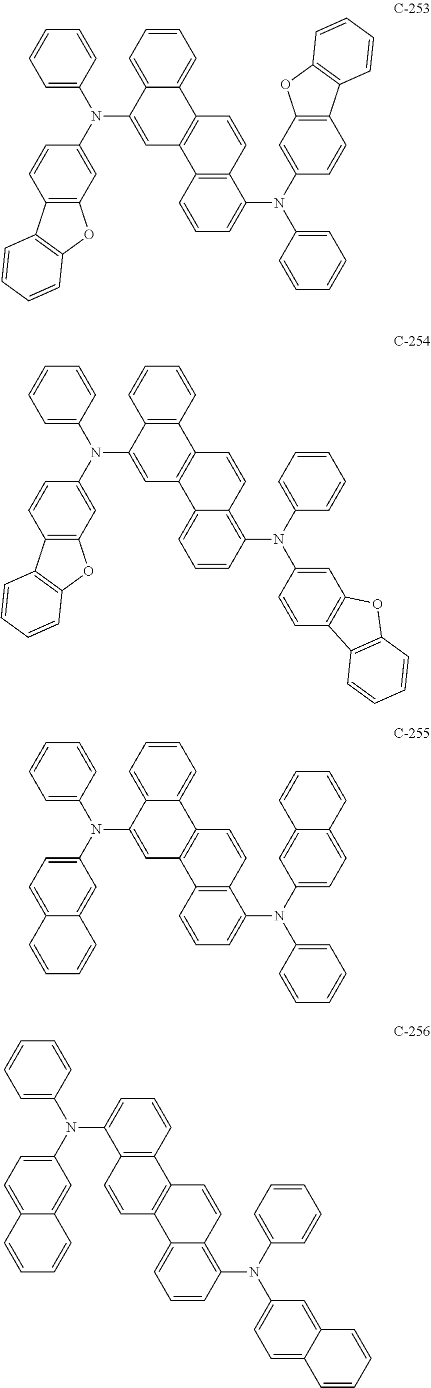 [SMILES: c1ccc(N(c2ccc3c(c2)oc2ccccc23)c2cc3c4cccc(N(c5ccccc5)c5ccc6c(c5)oc5ccccc56)c4ccc3c3ccccc23)cc1 ; c1ccc(N(c2ccc3c(c2)oc2ccccc23)c2cc3c4cccc(N(c5ccccc5)c5ccc6c(c5)oc5ccccc56)c4ccc3c3ccccc23)cc1 ; c1ccc(N(c2ccc3ccccc3c2)c2cc3c4cccc(N(c5ccccc5)c5ccc6ccccc6c5)c4ccc3c3ccccc23)cc1 ; c1ccc(N(c2ccc3ccccc3c2)c2cccc3c2ccc2c4cccc(N(c5ccccc5)c5ccc6ccccc6c5)c4ccc32)cc1]

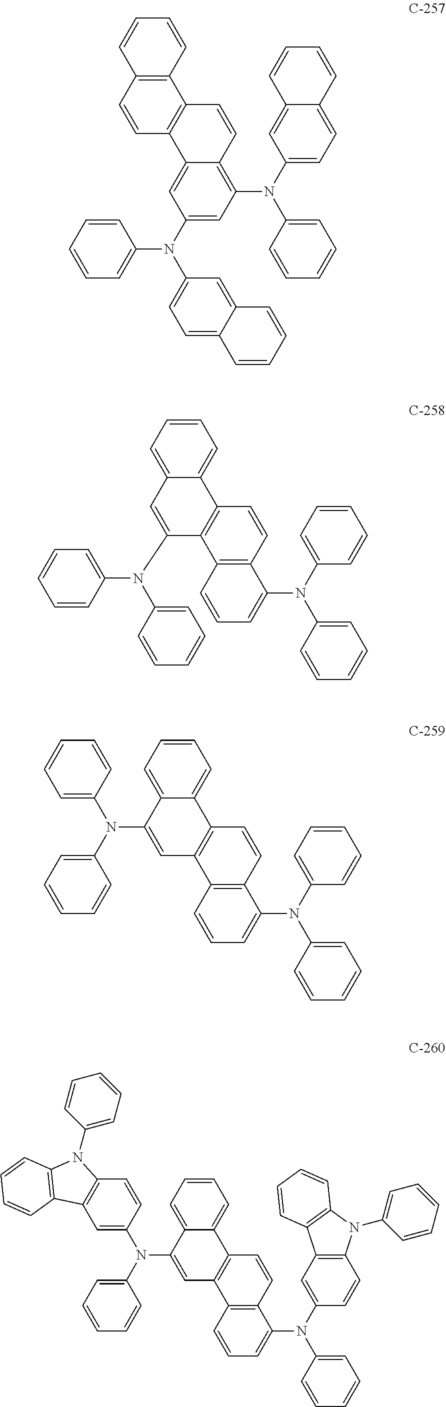 [SMILES: c1ccc(N(c2ccc3ccccc3c2)c2cc(N(c3ccccc3)c3ccc4ccccc4c3)c3ccc4c5ccccc5ccc4c3c2)cc1 ; c1ccc(N(c2ccccc2)c2cccc3c2ccc2c4ccccc4cc(N(c4ccccc4)c4ccccc4)c32)cc1 ; c1ccc(N(c2ccccc2)c2cc3c4cccc(N(c5ccccc5)c5ccccc5)c4ccc3c3ccccc23)cc1 ; c1ccc(N(c2ccc3c(c2)c2ccccc2n3-c2ccccc2)c2cc3c4cccc(N(c5ccccc5)c5ccc6c(c5)c5ccccc5n6-c5ccccc5)c4ccc3c3ccccc23)cc1]

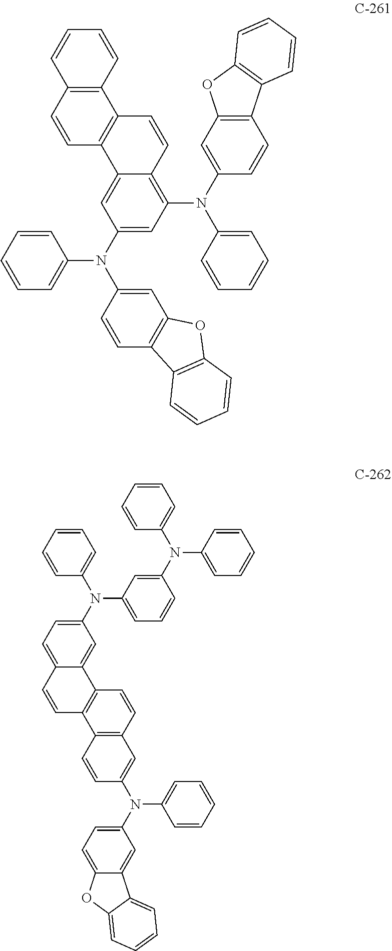 [SMILES: c1ccc(N(c2ccc3c(c2)oc2ccccc23)c2cc(N(c3ccccc3)c3ccc4c(c3)oc3ccccc34)c3ccc4c5ccccc5ccc4c3c2)cc1 ; c1ccc(N(c2ccccc2)c2cccc(N(c3ccccc3)c3ccc4ccc5c6ccc(N(c7ccccc7)c7ccc8oc9ccccc9c8c7)cc6ccc5c4c3)c2)cc1]

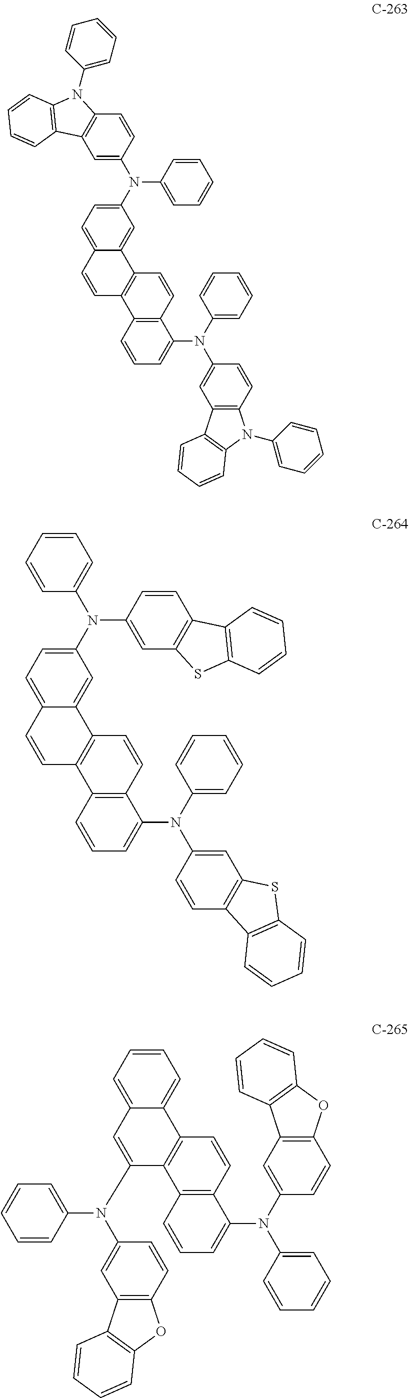 [SMILES: c1ccc(N(c2ccc3ccc4c5cccc(N(c6ccccc6)c6ccc7c(c6)c6ccccc6n7-c6ccccc6)c5ccc4c3c2)c2ccc3c(c2)c2ccccc2n3-c2ccccc2)cc1 ; c1ccc(N(c2ccc3c(c2)sc2ccccc23)c2ccc3ccc4c5cccc(N(c6ccccc6)c6ccc7c(c6)sc6ccccc67)c5ccc4c3c2)cc1 ; c1ccc(N(c2ccc3oc4ccccc4c3c2)c2cccc3c2ccc2c4ccccc4cc(N(c4ccccc4)c4ccc5oc6ccccc6c5c4)c32)cc1]

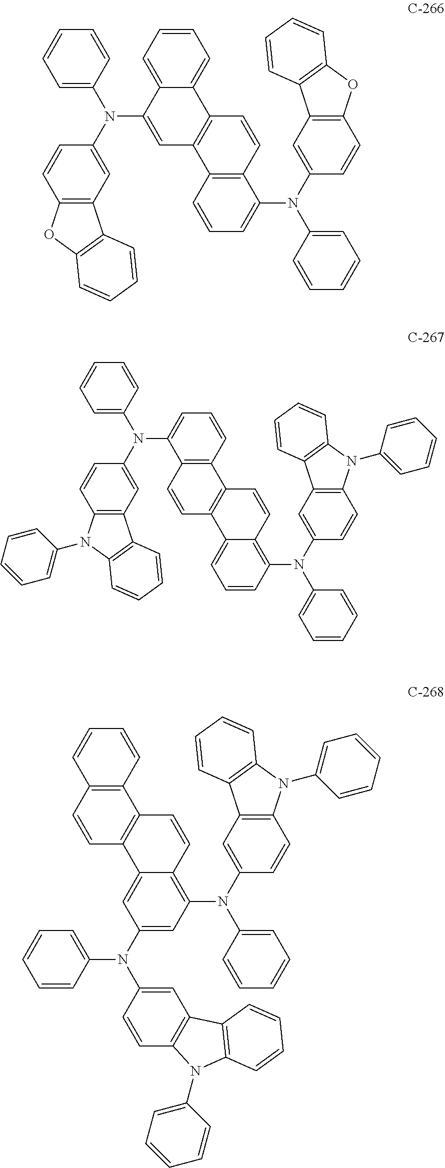 [SMILES: c1ccc(N(c2ccc3oc4ccccc4c3c2)c2cc3c4cccc(N(c5ccccc5)c5ccc6oc7ccccc7c6c5)c4ccc3c3ccccc23)cc1 ; c1ccc(N(c2ccc3c(c2)c2ccccc2n3-c2ccccc2)c2cccc3c2ccc2c4cccc(N(c5ccccc5)c5ccc6c(c5)c5ccccc5n6-c5ccccc5)c4ccc32)cc1 ; c1ccc(N(c2cc(N(c3ccccc3)c3ccc4c(c3)c3ccccc3n4-c3ccccc3)c3ccc4c5ccccc5ccc4c3c2)c2ccc3c(c2)c2ccccc2n3-c2ccccc2)cc1]

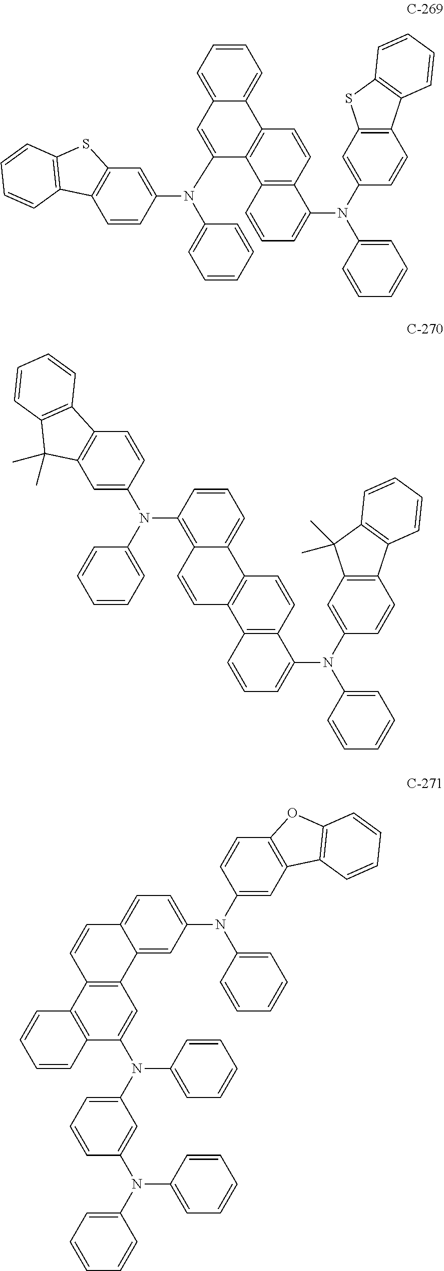 [SMILES: c1ccc(N(c2ccc3c(c2)sc2ccccc23)c2cccc3c2ccc2c4ccccc4cc(N(c4ccccc4)c4ccc5c(c4)sc4ccccc45)c32)cc1 ; CC1(C)c2ccccc2-c2ccc(N(c3ccccc3)c3cccc4c3ccc3c5cccc(N(c6ccccc6)c6ccc7c(c6)C(C)(C)c6ccccc6-7)c5ccc43)cc21 ; c1ccc(N(c2ccccc2)c2cccc(N(c3ccccc3)c3cc4c5cc(N(c6ccccc6)c6ccc7oc8ccccc8c7c6)ccc5ccc4c4ccccc34)c2)cc1]

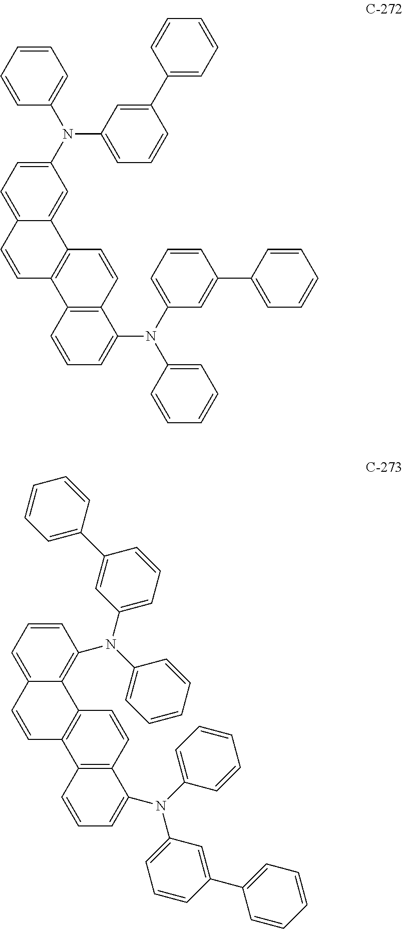 [SMILES: c1ccc(-c2cccc(N(c3ccccc3)c3ccc4ccc5c6cccc(N(c7ccccc7)c7cccc(-c8ccccc8)c7)c6ccc5c4c3)c2)cc1 ; c1ccc(-c2cccc(N(c3ccccc3)c3cccc4c3ccc3c4ccc4cccc(N(c5ccccc5)c5cccc(-c6ccccc6)c5)c43)c2)cc1]

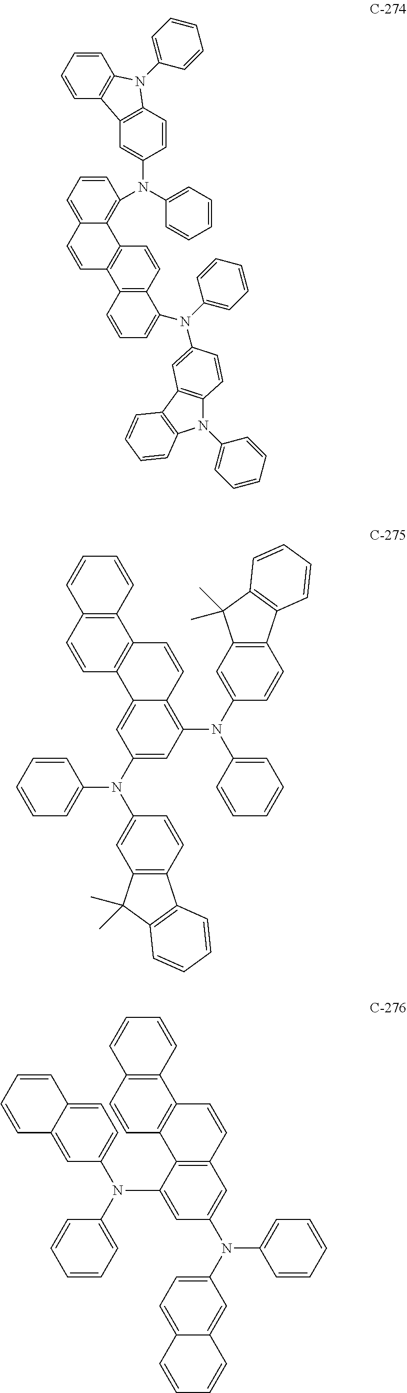 [SMILES: c1ccc(N(c2ccc3c(c2)c2ccccc2n3-c2ccccc2)c2cccc3c2ccc2c3ccc3cccc(N(c4ccccc4)c4ccc5c(c4)c4ccccc4n5-c4ccccc4)c32)cc1 ; CC1(C)c2ccccc2-c2ccc(N(c3ccccc3)c3cc(N(c4ccccc4)c4ccc5c(c4)C(C)(C)c4ccccc4-5)c4ccc5c6ccccc6ccc5c4c3)cc21 ; c1ccc(N(c2ccc3ccccc3c2)c2cc(N(c3ccccc3)c3ccc4ccccc4c3)c3c(ccc4c5ccccc5ccc43)c2)cc1]

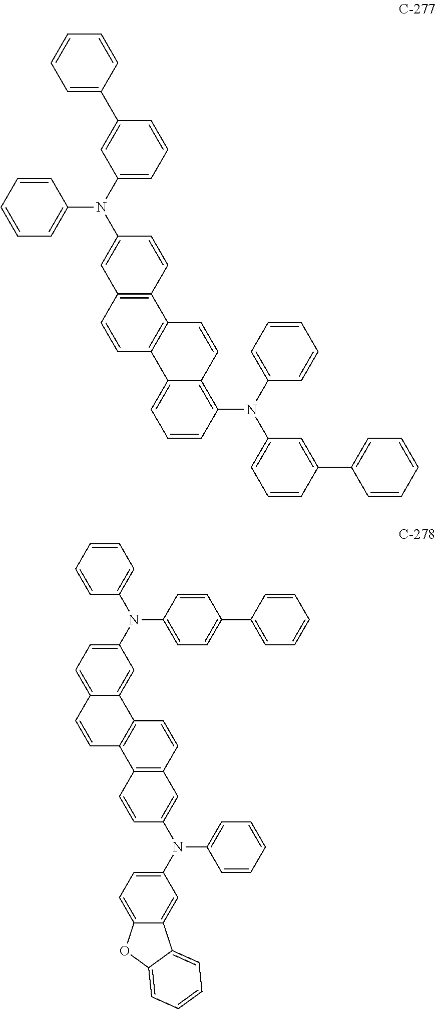 [SMILES: c1ccc(-c2cccc(N(c3ccccc3)c3ccc4c(ccc5c6cccc(N(c7ccccc7)c7cccc(-c8ccccc8)c7)c6ccc45)c3)c2)cc1 ; c1ccc(-c2ccc(N(c3ccccc3)c3ccc4ccc5c6ccc(N(c7ccccc7)c7ccc8oc9ccccc9c8c7)cc6ccc5c4c3)cc2)cc1]

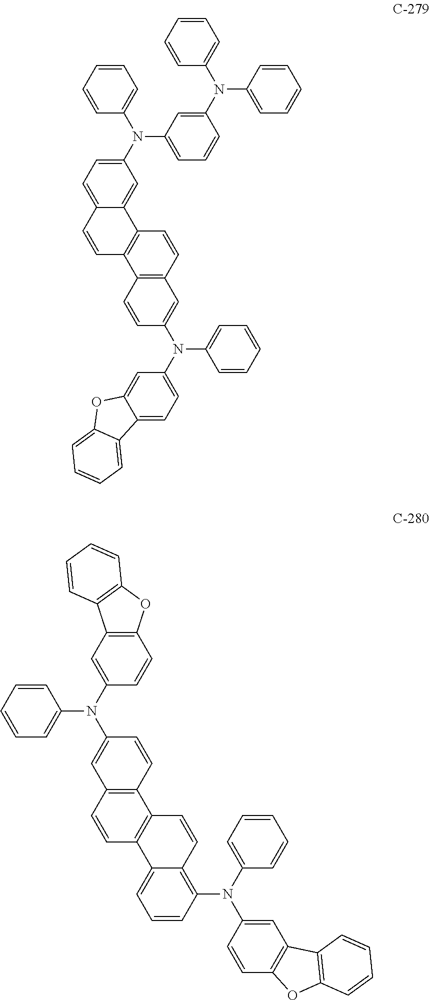 [SMILES: c1ccc(N(c2ccccc2)c2cccc(N(c3ccccc3)c3ccc4ccc5c6ccc(N(c7ccccc7)c7ccc8c(c7)oc7ccccc78)cc6ccc5c4c3)c2)cc1 ; c1ccc(N(c2ccc3c(ccc4c5cccc(N(c6ccccc6)c6ccc7oc8ccccc8c7c6)c5ccc34)c2)c2ccc3oc4ccccc4c3c2)cc1]

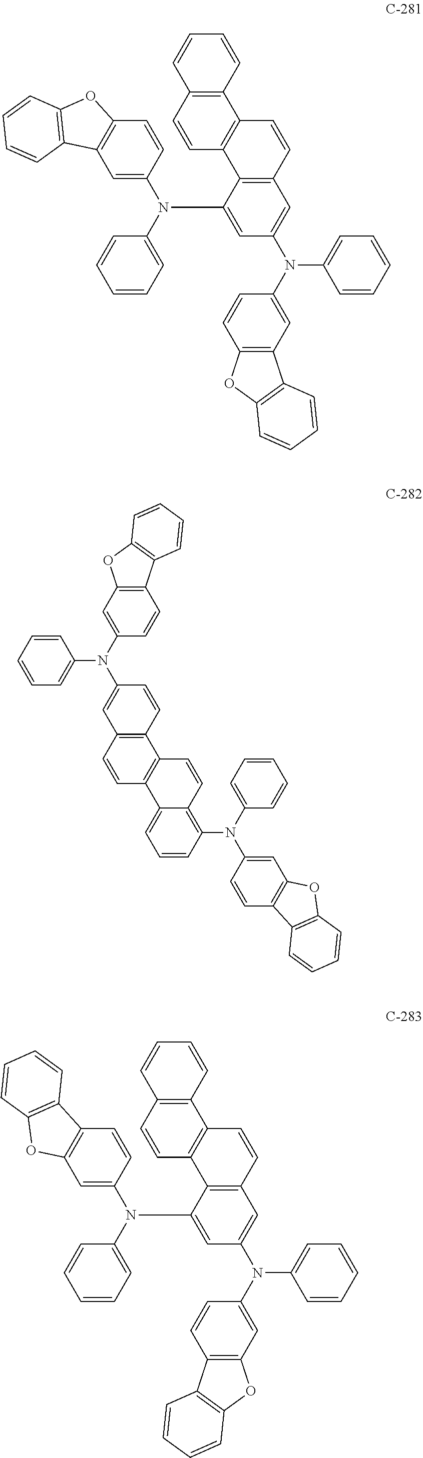 [SMILES: c1ccc(N(c2cc(N(c3ccccc3)c3ccc4oc5ccccc5c4c3)c3c(ccc4c5ccccc5ccc43)c2)c2ccc3oc4ccccc4c3c2)cc1 ; c1ccc(N(c2ccc3c(ccc4c5cccc(N(c6ccccc6)c6ccc7c(c6)oc6ccccc67)c5ccc34)c2)c2ccc3c(c2)oc2ccccc23)cc1 ; c1ccc(N(c2cc(N(c3ccccc3)c3ccc4c(c3)oc3ccccc34)c3c(ccc4c5ccccc5ccc43)c2)c2ccc3c(c2)oc2ccccc23)cc1]

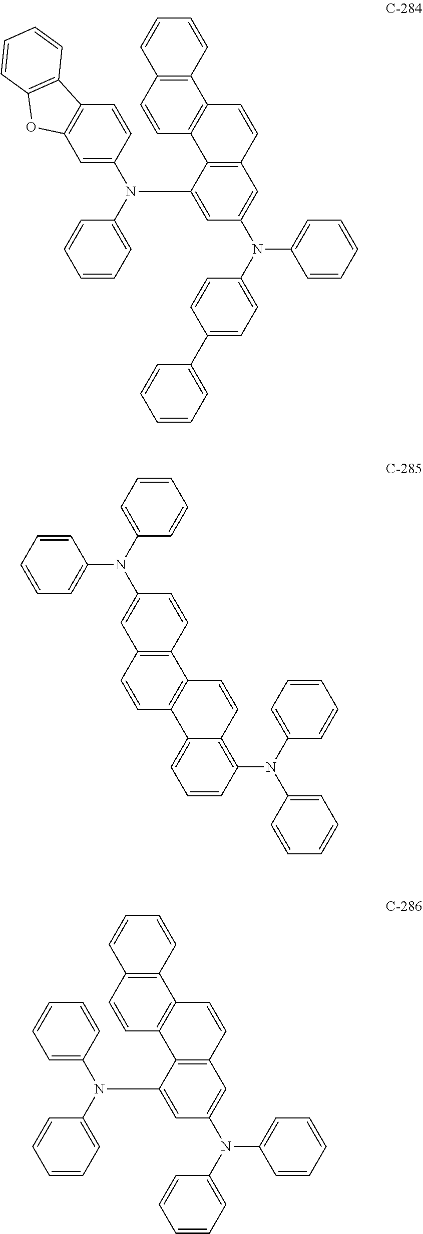 [SMILES: c1ccc(-c2ccc(N(c3ccccc3)c3cc(N(c4ccccc4)c4ccc5c(c4)oc4ccccc45)c4c(ccc5c6ccccc6ccc54)c3)cc2)cc1 ; c1ccc(N(c2ccccc2)c2ccc3c(ccc4c5cccc(N(c6ccccc6)c6ccccc6)c5ccc34)c2)cc1 ; c1ccc(N(c2ccccc2)c2cc(N(c3ccccc3)c3ccccc3)c3c(ccc4c5ccccc5ccc43)c2)cc1]

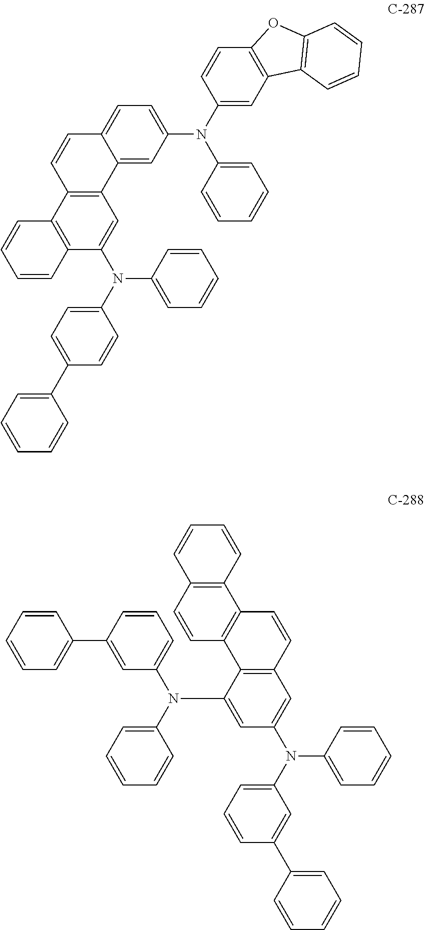 [SMILES: c1ccc(-c2ccc(N(c3ccccc3)c3cc4c5cc(N(c6ccccc6)c6ccc7oc8ccccc8c7c6)ccc5ccc4c4ccccc34)cc2)cc1 ; c1ccc(-c2cccc(N(c3ccccc3)c3cc(N(c4ccccc4)c4cccc(-c5ccccc5)c4)c4c(ccc5c6ccccc6ccc54)c3)c2)cc1]

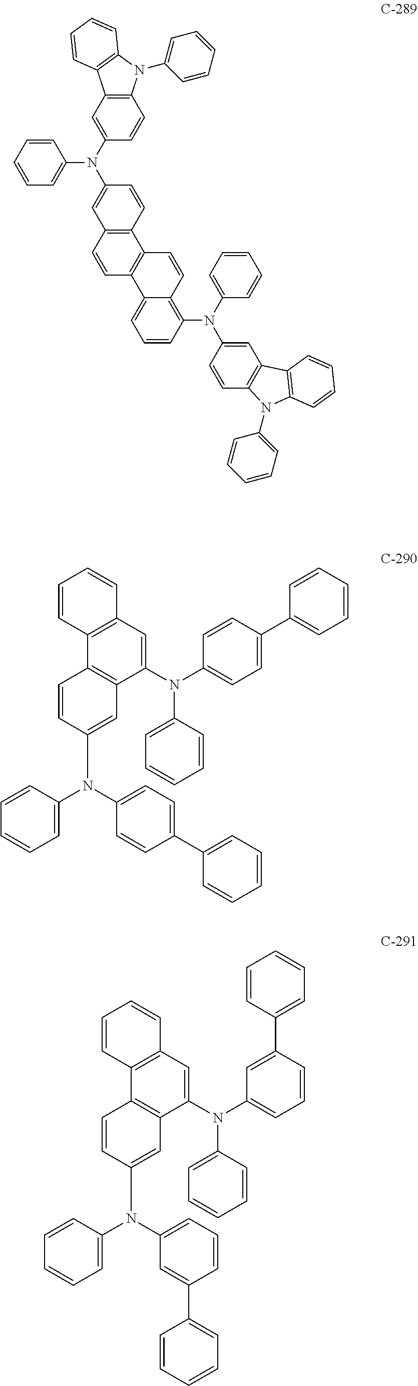 [SMILES: c1ccc(N(c2ccc3c(ccc4c5cccc(N(c6ccccc6)c6ccc7c(c6)c6ccccc6n7-c6ccccc6)c5ccc34)c2)c2ccc3c(c2)c2ccccc2n3-c2ccccc2)cc1 ; c1ccc(-c2ccc(N(c3ccccc3)c3ccc4c(c3)c(N(c3ccccc3)c3ccc(-c5ccccc5)cc3)cc3ccccc34)cc2)cc1 ; c1ccc(-c2cccc(N(c3ccccc3)c3ccc4c(c3)c(N(c3ccccc3)c3cccc(-c5ccccc5)c3)cc3ccccc34)c2)cc1]

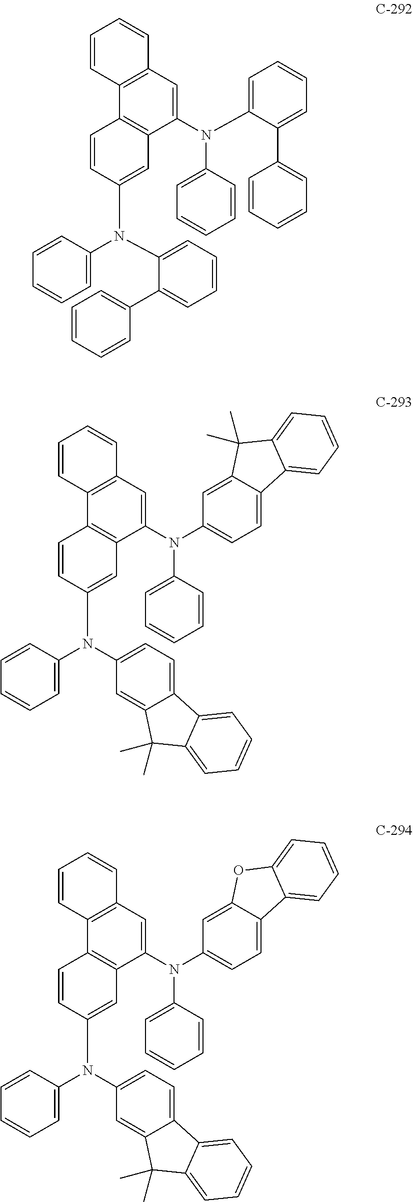 [SMILES: c1ccc(-c2ccccc2N(c2ccccc2)c2ccc3c(c2)c(N(c2ccccc2)c2ccccc2-c2ccccc2)cc2ccccc23)cc1 ; CC1(C)c2ccccc2-c2ccc(N(c3ccccc3)c3ccc4c(c3)c(N(c3ccccc3)c3ccc5c(c3)C(C)(C)c3ccccc3-5)cc3ccccc34)cc21 ; CC1(C)c2ccccc2-c2ccc(N(c3ccccc3)c3ccc4c(c3)c(N(c3ccccc3)c3ccc5c(c3)oc3ccccc35)cc3ccccc34)cc21]

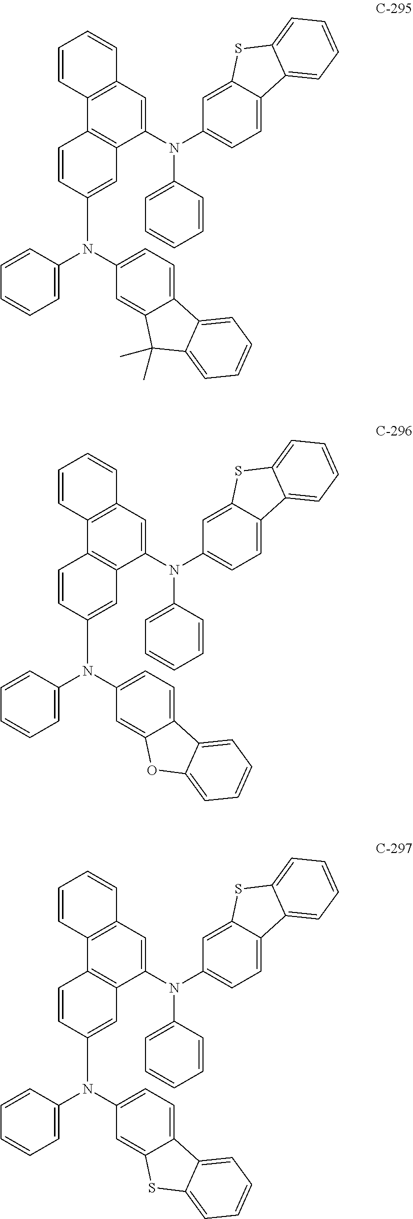 [SMILES: CC1(C)c2ccccc2-c2ccc(N(c3ccccc3)c3ccc4c(c3)c(N(c3ccccc3)c3ccc5c(c3)sc3ccccc35)cc3ccccc34)cc21 ; c1ccc(N(c2ccc3c(c2)oc2ccccc23)c2ccc3c(c2)c(N(c2ccccc2)c2ccc4c(c2)sc2ccccc24)cc2ccccc23)cc1 ; c1ccc(N(c2ccc3c(c2)sc2ccccc23)c2ccc3c(c2)c(N(c2ccccc2)c2ccc4c(c2)sc2ccccc24)cc2ccccc23)cc1]

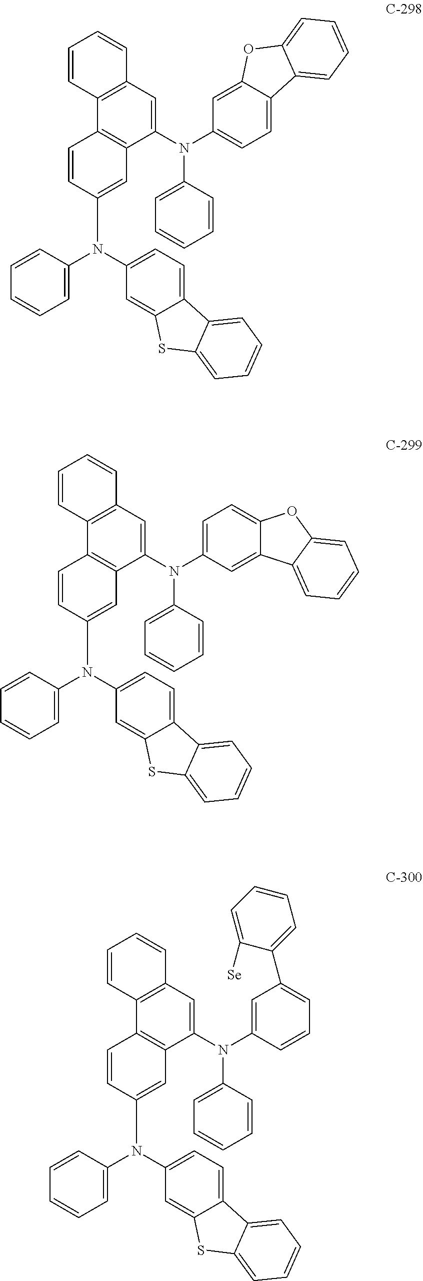

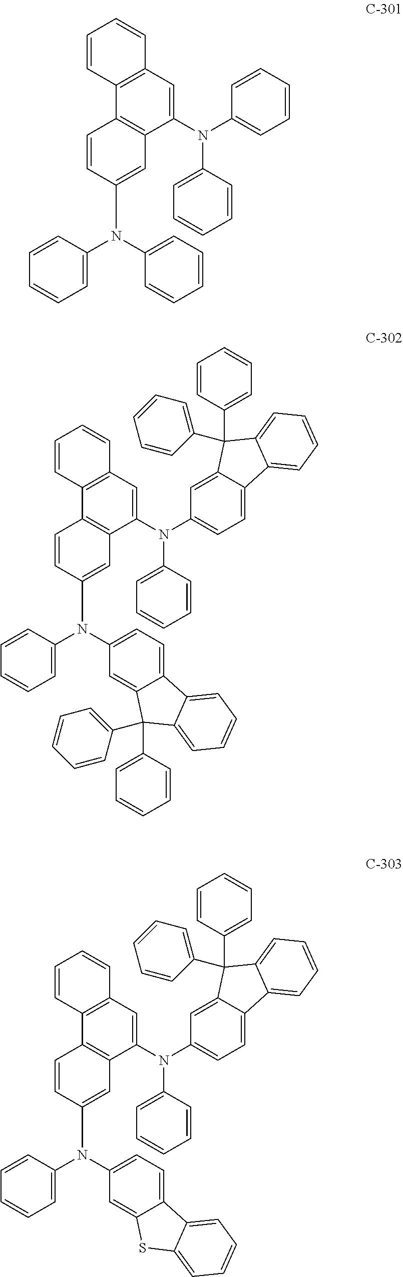 [SMILES: c1ccc(N(c2ccccc2)c2ccc3c(c2)c(N(c2ccccc2)c2ccccc2)cc2ccccc23)cc1 ; c1ccc(N(c2ccc3c(c2)C(c2ccccc2)(c2ccccc2)c2ccccc2-3)c2ccc3c(c2)c(N(c2ccccc2)c2ccc4c(c2)C(c2ccccc2)(c2ccccc2)c2ccccc2-4)cc2ccccc23)cc1 ; c1ccc(N(c2ccc3c(c2)sc2ccccc23)c2ccc3c(c2)c(N(c2ccccc2)c2ccc4c(c2)C(c2ccccc2)(c2ccccc2)c2ccccc2-4)cc2ccccc23)cc1]

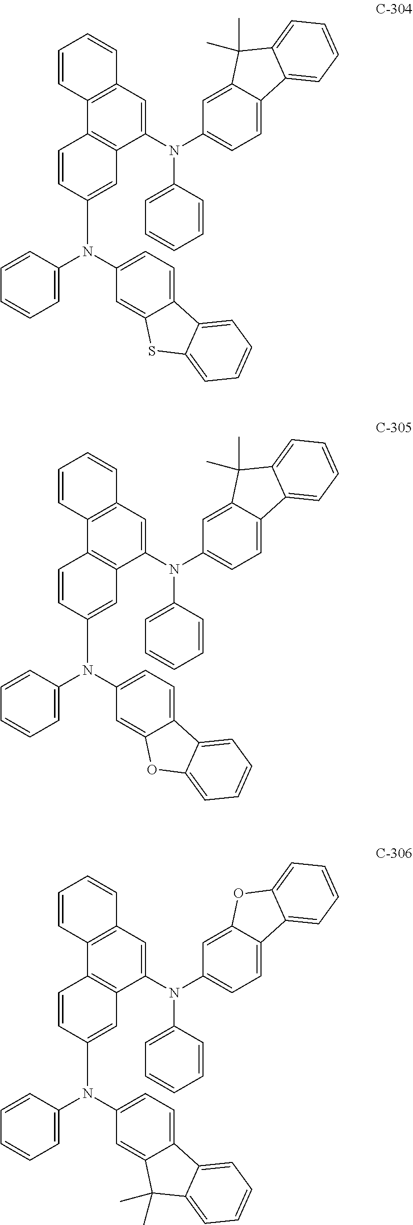 [SMILES: CC1(C)c2ccccc2-c2ccc(N(c3ccccc3)c3cc4ccccc4c4ccc(N(c5ccccc5)c5ccc6c(c5)sc5ccccc56)cc34)cc21 ; CC1(C)c2ccccc2-c2ccc(N(c3ccccc3)c3cc4ccccc4c4ccc(N(c5ccccc5)c5ccc6c(c5)oc5ccccc56)cc34)cc21 ; CC1(C)c2ccccc2-c2ccc(N(c3ccccc3)c3ccc4c(c3)c(N(c3ccccc3)c3ccc5c(c3)oc3ccccc35)cc3ccccc34)cc21]

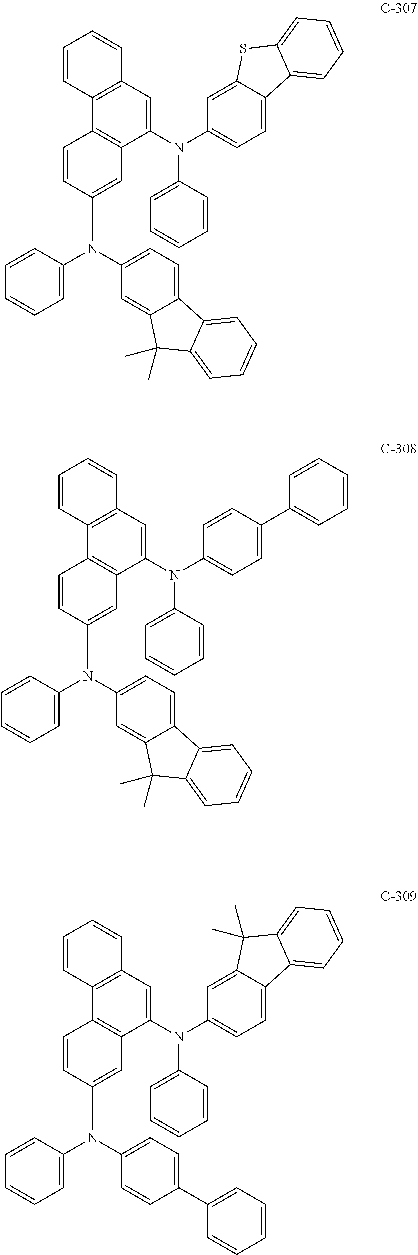 [SMILES: CC1(C)c2ccccc2-c2ccc(N(c3ccccc3)c3ccc4c(c3)c(N(c3ccccc3)c3ccc5c(c3)sc3ccccc35)cc3ccccc34)cc21 ; CC1(C)c2ccccc2-c2ccc(N(c3ccccc3)c3ccc4c(c3)c(N(c3ccccc3)c3ccc(-c5ccccc5)cc3)cc3ccccc34)cc21 ; CC1(C)c2ccccc2-c2ccc(N(c3ccccc3)c3cc4ccccc4c4ccc(N(c5ccccc5)c5ccc(-c6ccccc6)cc5)cc34)cc21]

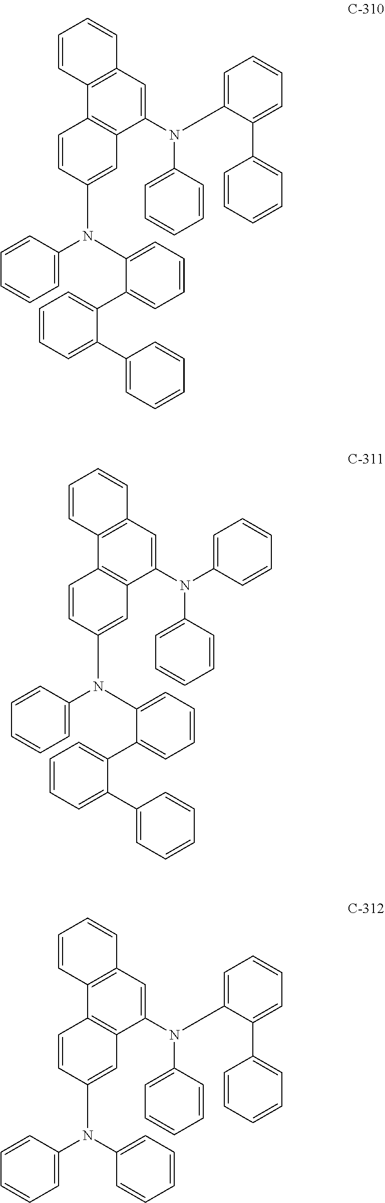 [SMILES: c1ccc(-c2ccccc2-c2ccccc2N(c2ccccc2)c2ccc3c(c2)c(N(c2ccccc2)c2ccccc2-c2ccccc2)cc2ccccc23)cc1 ; c1ccc(-c2ccccc2-c2ccccc2N(c2ccccc2)c2ccc3c(c2)c(N(c2ccccc2)c2ccccc2)cc2ccccc23)cc1 ; c1ccc(-c2ccccc2N(c2ccccc2)c2cc3ccccc3c3ccc(N(c4ccccc4)c4ccccc4)cc23)cc1]

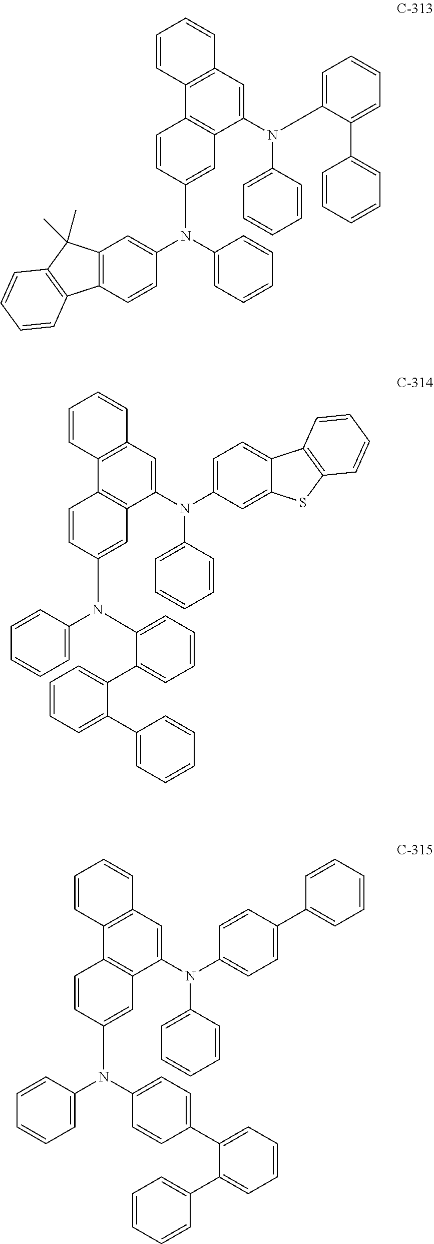 [SMILES: CC1(C)c2ccccc2-c2ccc(N(c3ccccc3)c3ccc4c(c3)c(N(c3ccccc3)c3ccccc3-c3ccccc3)cc3ccccc34)cc21 ; c1ccc(-c2ccccc2-c2ccccc2N(c2ccccc2)c2ccc3c(c2)c(N(c2ccccc2)c2ccc4c(c2)sc2ccccc24)cc2ccccc23)cc1 ; c1ccc(-c2ccc(N(c3ccccc3)c3cc4ccccc4c4ccc(N(c5ccccc5)c5ccc(-c6ccccc6-c6ccccc6)cc5)cc34)cc2)cc1]

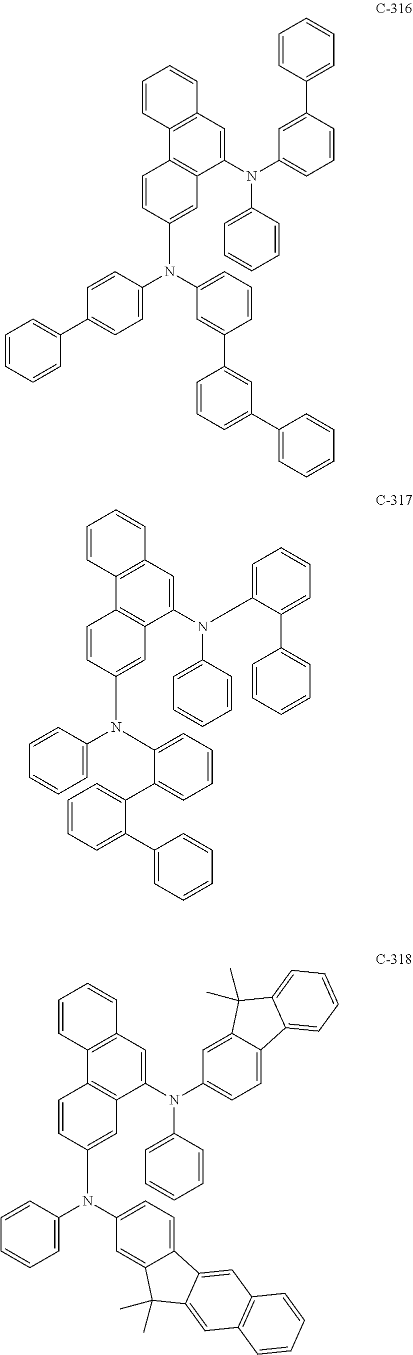 [SMILES: c1ccc(-c2ccc(N(c3cccc(-c4cccc(-c5ccccc5)c4)c3)c3ccc4c(c3)c(N(c3ccccc3)c3cccc(-c5ccccc5)c3)cc3ccccc34)cc2)cc1 ; c1ccc(-c2ccccc2-c2ccccc2N(c2ccccc2)c2ccc3c(c2)c(N(c2ccccc2)c2ccccc2-c2ccccc2)cc2ccccc23)cc1 ; CC1(C)c2ccccc2-c2ccc(N(c3ccccc3)c3cc4ccccc4c4ccc(N(c5ccccc5)c5ccc6c(c5)C(C)(C)c5cc7ccccc7cc5-6)cc34)cc21]

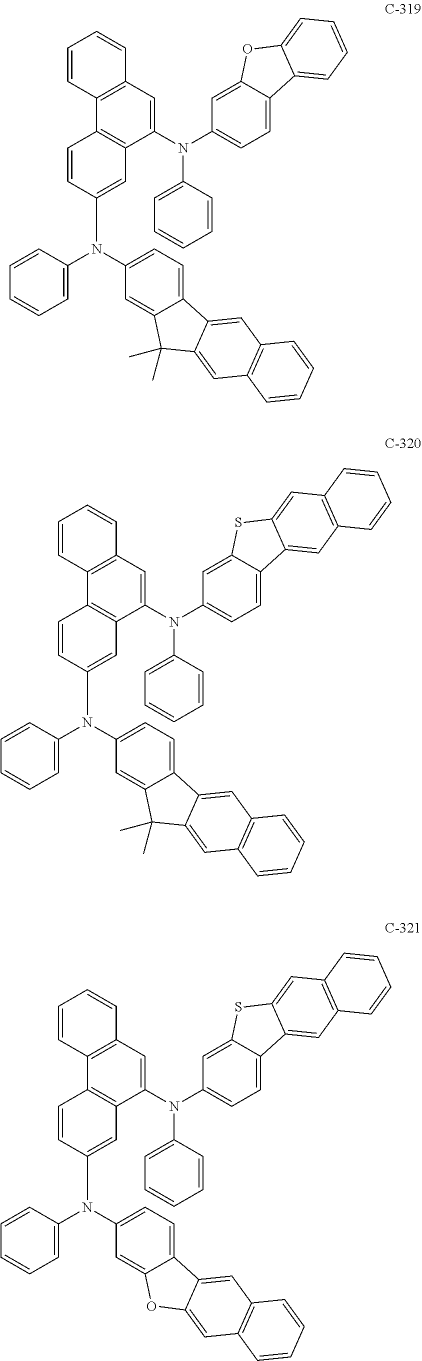 [SMILES: CC1(C)c2cc(N(c3ccccc3)c3ccc4c(c3)c(N(c3ccccc3)c3ccc5c(c3)oc3ccccc35)cc3ccccc34)ccc2-c2cc3ccccc3cc21 ; CC1(C)c2cc(N(c3ccccc3)c3ccc4c(c3)c(N(c3ccccc3)c3ccc5c(c3)sc3cc6ccccc6cc35)cc3ccccc34)ccc2-c2cc3ccccc3cc21 ; c1ccc(N(c2ccc3c(c2)oc2cc4ccccc4cc23)c2ccc3c(c2)c(N(c2ccccc2)c2ccc4c(c2)sc2cc5ccccc5cc24)cc2ccccc23)cc1]

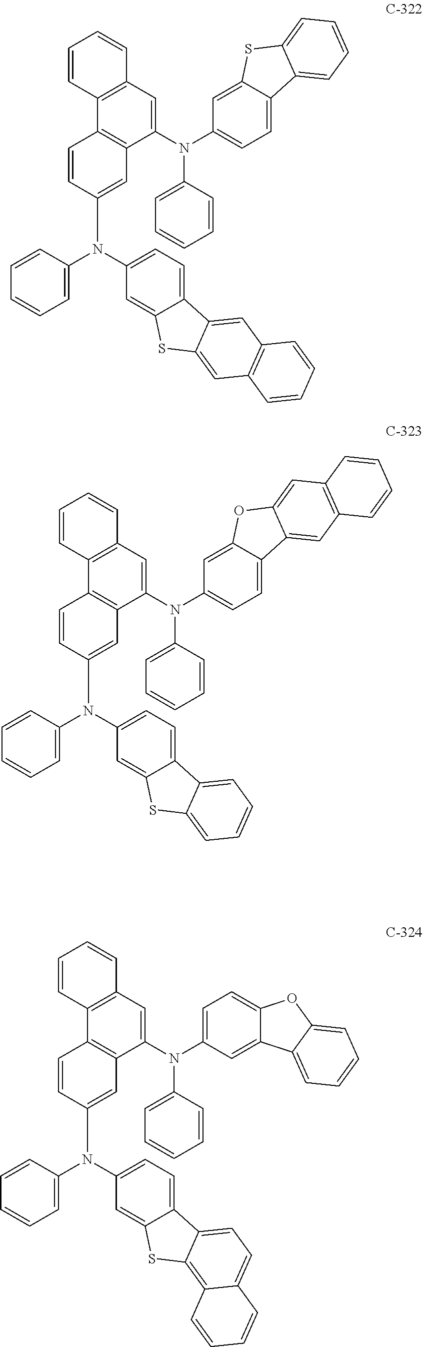 [SMILES: c1ccc(N(c2ccc3c(c2)sc2cc4ccccc4cc23)c2ccc3c(c2)c(N(c2ccccc2)c2ccc4c(c2)sc2ccccc24)cc2ccccc23)cc1 ; c1ccc(N(c2ccc3c(c2)sc2ccccc23)c2ccc3c(c2)c(N(c2ccccc2)c2ccc4c(c2)oc2cc5ccccc5cc24)cc2ccccc23)cc1 ; c1ccc(N(c2ccc3c(c2)sc2c4ccccc4ccc32)c2ccc3c(c2)c(N(c2ccccc2)c2ccc4oc5ccccc5c4c2)cc2ccccc23)cc1]

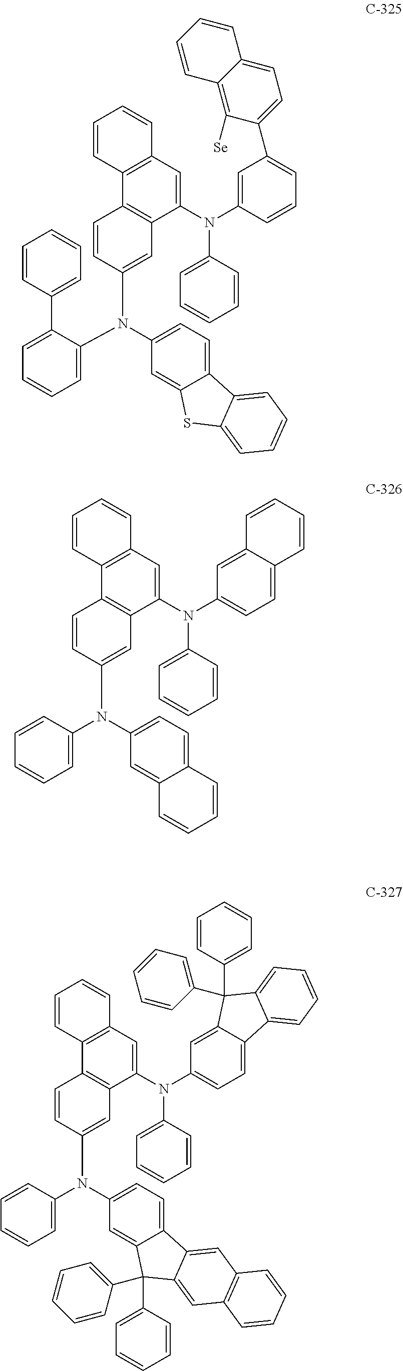

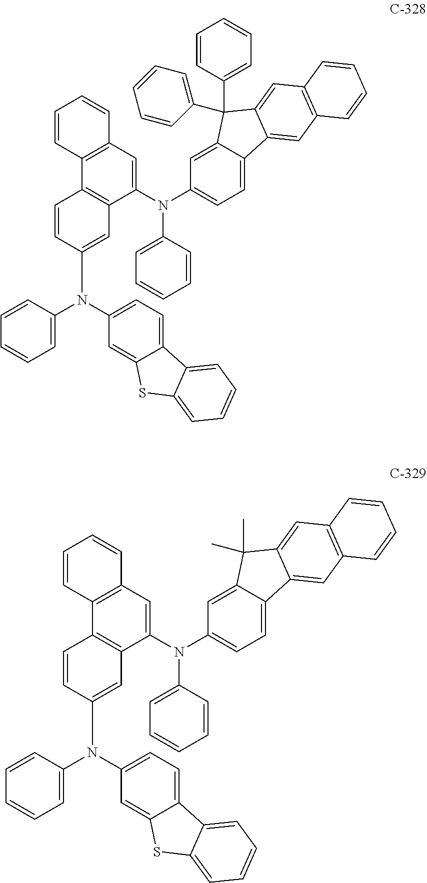 [SMILES: c1ccc(N(c2ccc3c(c2)sc2ccccc23)c2ccc3c(c2)c(N(c2ccccc2)c2ccc4c(c2)C(c2ccccc2)(c2ccccc2)c2cc5ccccc5cc2-4)cc2ccccc23)cc1 ; CC1(C)c2cc(N(c3ccccc3)c3cc4ccccc4c4ccc(N(c5ccccc5)c5ccc6c(c5)sc5ccccc56)cc34)ccc2-c2cc3ccccc3cc21]

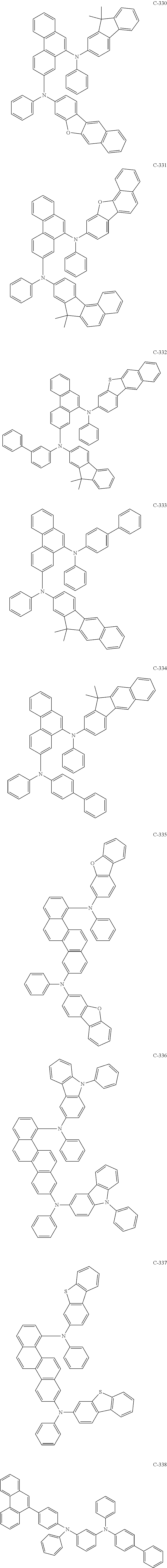

The host compound of formula 1 according to the present disclosure may be prepared by a synthetic method known to a person skilled in the art, for example, by referring to the synthesis method disclosed in US 2017/0294628 A1 and the like.

The second host compound as another host material according to one embodiment is represented by the following formula 2.

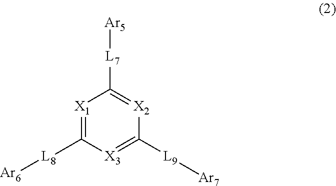

in formula 2,

X₁ to X₃ each independently represent, N or CH;

L₇ to L₉ each independently represent, a single bond, a substituted or unsubstituted (C6-C30)arylene, a substituted or unsubstituted (C3-C30)cycloalkylene, or a substituted or unsubstituted (3- to 30-membered)heteroarylene;

Ar₅ to Ar₇ each independently represent, hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or —N—(R′)(R″); or may be linked to the adjacent substituents to form a ring(s); provided that at least one of Ar₅ to Ar₇ is(are) a substituted or unsubstituted (3- to 30-membered)heteroaryl; and

R′ and R″ each independently represent, a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl.

In one embodiment, at least one of X₁ to X₃ may be N, preferably at least two of X₁ to X₃ may be N, more preferably all of X₁ to X₃ may be N.

In one embodiment, L₇ to L₉ each independently may be a single bond, a substituted or unsubstituted (C6-C30)arylene, or a substituted or unsubstituted (5- to 30-membered)heteroarylene, preferably a single bond, a substituted or unsubstituted (C6-C25)arylene or a substituted or unsubstituted (5- to 25-membered)heteroarylene, more preferably a single bond, a substituted or unsubstituted (C6-C18)arylene or a substituted or unsubstituted (5- to 18-membered)heteroarylene. For example, L₇ to L₉ each independently may be a single bond, a substituted or unsubstituted phenylene, a substituted or unsubstituted naphthylene, a substituted or unsubstituted biphenylene, a substituted or unsubstituted naphthylphenylene, a substituted or unsubstituted phenylnaphthylene, a substituted or unsubstituted fluorenylene, a substituted or unsubstituted phenanthrenylene, a substituted or unsubstituted dibenzofuranylene, a substituted or unsubstituted benzonaphthothiophenylene, or a substituted or unsubstituted benzonaphthofuranylene.

In one embodiment, Ar₅ to Ar₇ each independently may be a substituted or unsubstituted (C6-C30)aryl, a substituted or unsubstituted (5- to 30-membered)heteroaryl, or a substituted or unsubstituted tri(C6-C30)arylsilyl, preferably a substituted or unsubstituted (C6-C25)aryl, a substituted or unsubstituted (5- to 25-membered)heteroaryl, or a substituted or unsubstituted tri(C6-C25)arylsilyl, more preferably a substituted or unsubstituted (C6-C25)aryl, a substituted or unsubstituted (5- to 18-membered)heteroaryl, or a substituted or unsubstituted tri(C6-C18)arylsilyl. Wherein, at least one of Ar⁵ to Ar₇ may be a substituted or unsubstituted (5- to 30-membered)heteroaryl, preferably at least two of Ar₅ to Ar₇ may be a substituted or unsubstituted (5- to 30-membered)heteroaryl.

For example, Ar₅ to Ar₇ each independently may be a substituted or unsubstituted phenyl, a substituted or unsubstituted naphthyl, a substituted or unsubstituted p-biphenyl, a substituted or unsubstituted m-biphenyl, a substituted or unsubstituted o-terphenyl, a substituted or unsubstituted m-terphenyl, a substituted or unsubstituted triphenylsilyl, a substituted or unsubstituted dibenzofuranyl, a substituted or unsubstituted dibenzothiophenyl, a substituted or unsubstituted fluorenyl, a substituted or unsubstituted spirobifluorenyl, a substituted or unsubstituted carbazolyl, a substituted or unsubstituted phenanthrenyl, a substituted or unsubstituted benzophenanthrenyl, a substituted or unsubstituted chrysenyl, a substituted or unsubstituted triphenylenyl, a substituted or unsubstituted benzocarbazolyl, a substituted or unsubstituted benzonaphthofuranyl, a substituted or unsubstituted benzonaphthothiophenyl, a substituted or unsubstituted benzofluorenyl, a substituted or unsubstituted benzothiazolyl, a substituted or unsubstituted benzoxazolyl, a substituted or unsubstituted benzimidazolyl, a substituted or unsubstituted naphthooxazolyl, a substituted or unsubstituted benzonaphthooxazolyl, a substituted or unsubstituted naphthothiazolyl, a substituted or unsubstituted benzonaphthothiazolyl, or a substituted or unsubstituted naphthoimidazolyl. Preferably, Ar₅ to Ar₇ each independently may be a substituted or unsubstituted phenyl, a substituted or unsubstituted naphthyl, a substituted or unsubstituted p-biphenyl, a substituted or unsubstituted m-biphenyl, a substituted or unsubstituted o-terphenyl, a substituted or unsubstituted m-terphenyl, a substituted or unsubstituted triphenylsilyl, a substituted or unsubstituted dibenzofuranyl, a substituted or unsubstituted dibenzothiophenyl, a substituted or unsubstituted fluorenyl, a substituted or unsubstituted benzofluorenyl, a substituted or unsubstituted spirobifluorenyl, a substituted or unsubstituted phenanthrenyl, a substituted or unsubstituted chrysenyl, a substituted or unsubstituted triphenylenyl, a substituted or unsubstituted benzonaphthofuranyl, a substituted or unsubstituted benzonaphthothiophenyl, a substituted or unsubstituted benzonaphthooxazolyl, or a substituted or unsubstituted benzonaphthothiazolyl. Wherein, the substituents of the substituted groups may be at least one selected from deuterium, cyano, methyl, phenyl, biphenyl, naphthyl, phenanthrenyl, triphenylsilyl, fluorenyl, dibenzothiophenyl, and dibenzofuranyl.

At least one of Ar₅ to Ar₇ according to one embodiment may be any one selected from the following formulas 1-1 to 1-26.

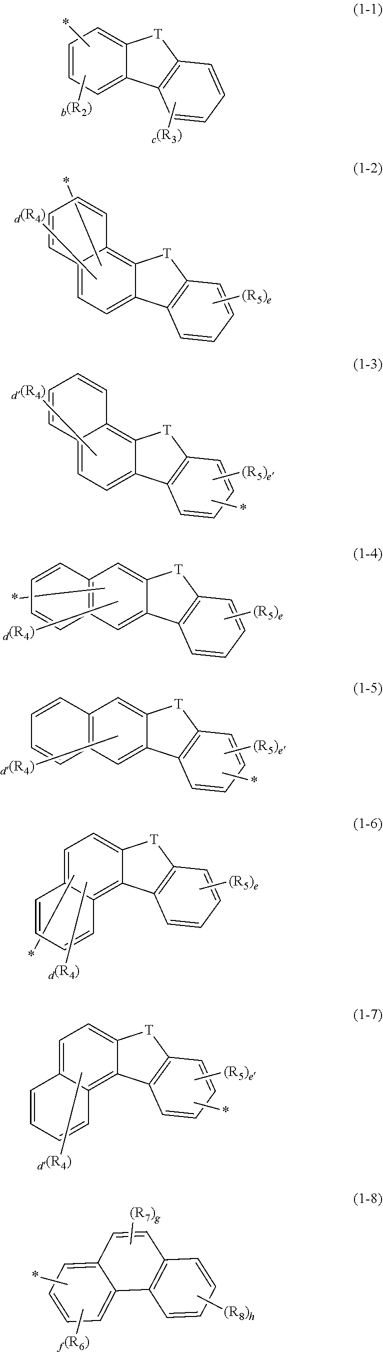

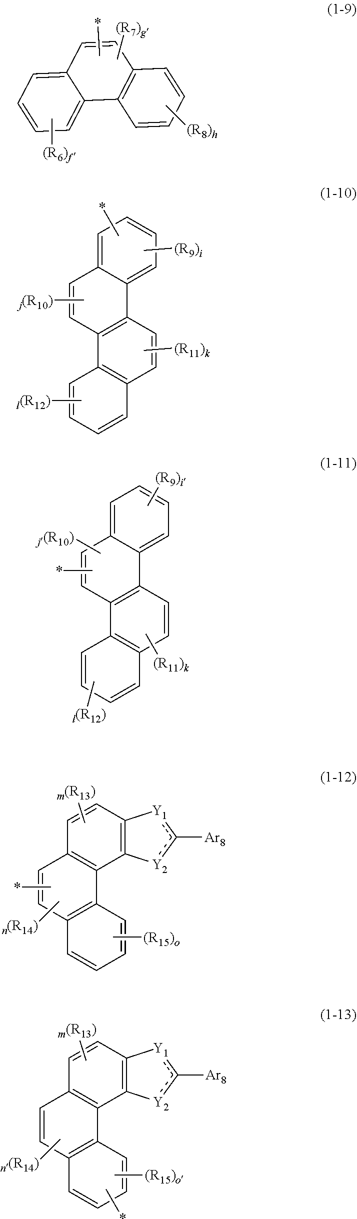

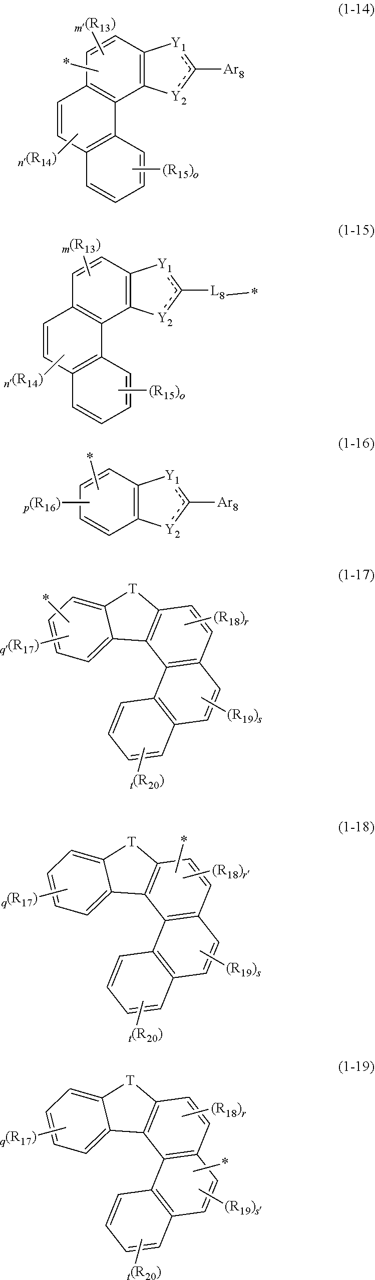

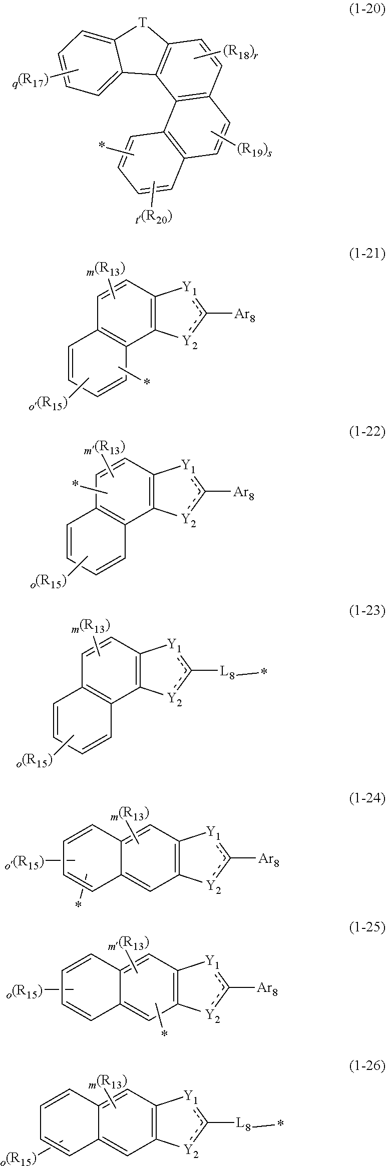

in formulas 1-1 to 1-26,

T represents —O—, —S—, —Se—, —CR₂₁R₂₂—, or —NR₂₃—;

Y₁ and Y₂ each independently represent, —N═, —NR₂₄—, —O—, —S— or —Se—; provided that any one of Y₁ and Y₂ is —N═, and the other of Y₁ and Y₂ is —NR₂₄—, —O—, —S—, or —Se—;

R₂ to R₂₀ each independently represent, hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or —N—(R′)(R″); or may be linked to the adjacent substituents to form a ring(s);

R′ and R″ each independently represent, a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl;

R₂₁ to R₂₄ each independently represent, a substituted or unsubstituted (C1-C30)alkyl, a substituted or unsubstituted (C6-C30)aryl, or a substituted or unsubstituted (3- to 30-membered)heteroaryl; or may be linked to the adjacent substituents to form a ring(s);

Ar₈ represents a substituted or unsubstituted (C6-C30)aryl or a substituted or unsubstituted (3- to 30-membered)heteroaryl;

L₈ represents a single bond, a substituted or unsubstituted (C6-C30)arylene, or a substituted or unsubstituted (3- to 30-membered)heteroarylene;

b, e′, f, i, o′, p, q′, and t′ are an integer of 1 to 3; c, e, h, f′, l, i′, o, q, and t are an integer of 1 to 4; d is an integer of 1 to 5; d′ is an integer of 1 to 6; g, j, k, m, n′, r, and s are an integer of 1 or 2; g′, j′, m′, n, r′, and s′ are 1;

when b to m, o to t, d′ to f′, i′, n′, o′, q′, and t′ are an integer of 2 or more, each of R₂ to R₂₀ may be the same or different; and

* represents a linking site with L₇ to L₉ in formula 2.

In one embodiment, at least one of Ar₅ to Ar₇ may be a substituted or unsubstituted (5- to 30-membered)heteroaryl. For example, at least one of Ar₅ to Ar₇ may be heteroaryl represented by one of the formulas 1-1 to 1-26, for example, may be heteroaryl represented by one of the formulas 1-1 to 1-20.

In one embodiment, Ar₈ may be a substituted or unsubstituted (C6-C30)aryl, preferably a substituted or unsubstituted (C6-C25)aryl, more preferably a substituted or unsubstituted (C6-C18)aryl. For example, Ar₈ may be a substituted or unsubstituted phenyl.

According to one embodiment, the second host compound represented by formula 2 may be more specifically illustrated by the following compounds, but is not limited thereto.

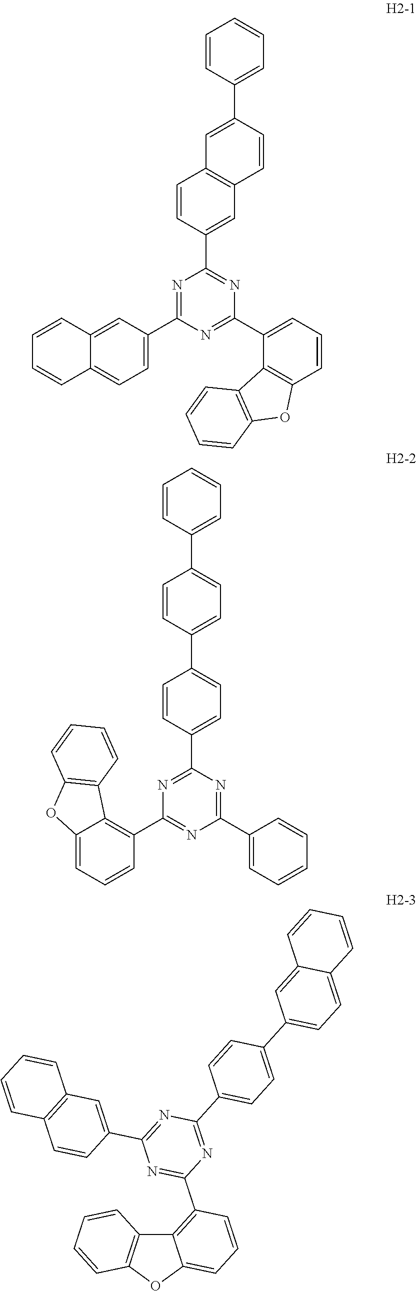

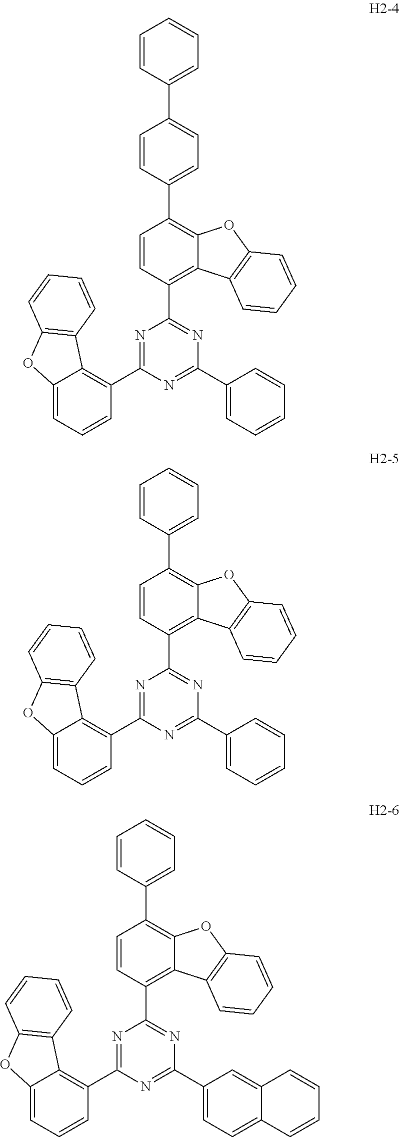 [SMILES: c1ccc(-c2ccc(-c3ccc(-c4nc(-c5ccccc5)nc(-c5cccc6oc7ccccc7c56)n4)c4c3oc3ccccc34)cc2)cc1 ; c1ccc(-c2nc(-c3cccc4oc5ccccc5c34)nc(-c3ccc(-c4ccccc4)c4oc5ccccc5c34)n2)cc1 ; c1ccc(-c2ccc(-c3nc(-c4ccc5ccccc5c4)nc(-c4cccc5oc6ccccc6c45)n3)c3c2oc2ccccc23)cc1]

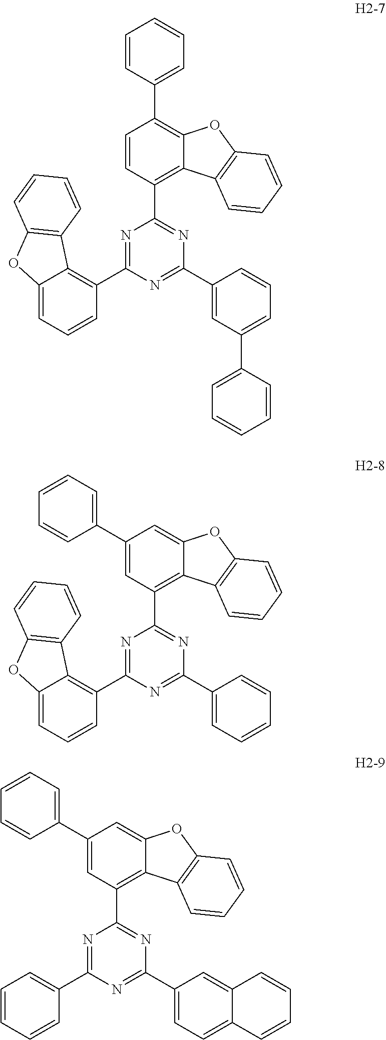 [SMILES: c1ccc(-c2cccc(-c3nc(-c4cccc5oc6ccccc6c45)nc(-c4ccc(-c5ccccc5)c5oc6ccccc6c45)n3)c2)cc1 ; c1ccc(-c2cc(-c3nc(-c4ccccc4)nc(-c4cccc5oc6ccccc6c45)n3)c3c(c2)oc2ccccc23)cc1 ; c1ccc(-c2cc(-c3nc(-c4ccccc4)nc(-c4ccc5ccccc5c4)n3)c3c(c2)oc2ccccc23)cc1]

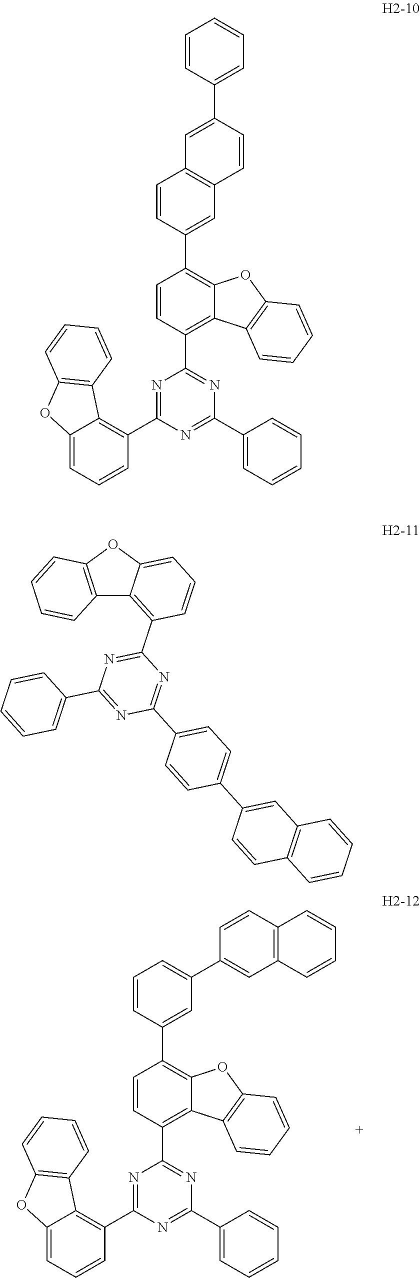

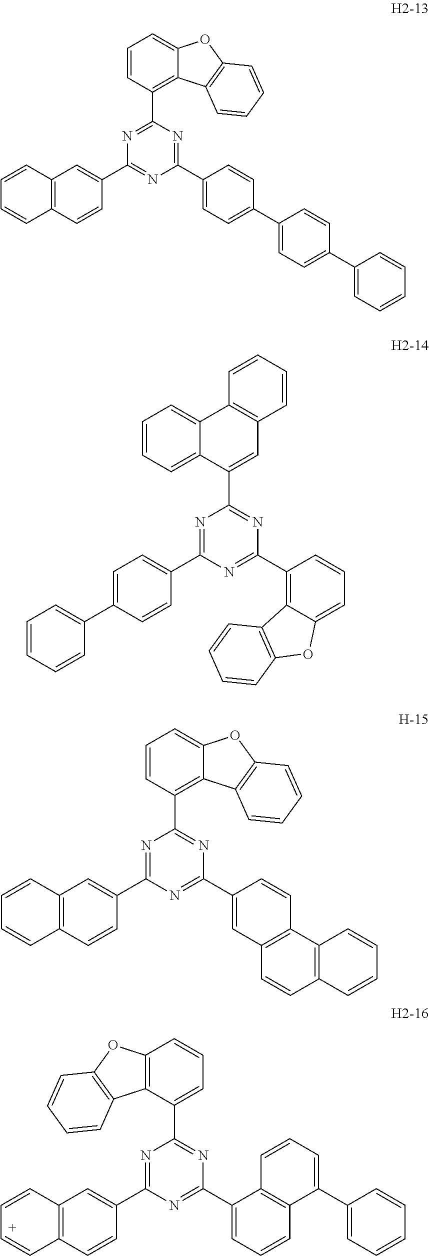 [SMILES: c1ccc(-c2ccc(-c3ccc(-c4nc(-c5ccc6ccccc6c5)nc(-c5cccc6oc7ccccc7c56)n4)cc3)cc2)cc1 ; c1ccc(-c2ccc(-c3nc(-c4cc5ccccc5c5ccccc45)nc(-c4cccc5oc6ccccc6c45)n3)cc2)cc1 ; c1ccc2cc(-c3nc(-c4ccc5c(ccc6ccccc65)c4)nc(-c4cccc5oc6ccccc6c45)n3)ccc2c1 ; [C+]1=Cc2ccc(-c3nc(-c4cccc5c(-c6ccccc6)cccc45)nc(-c4cccc5oc6ccccc6c45)n3)cc2C=C1]

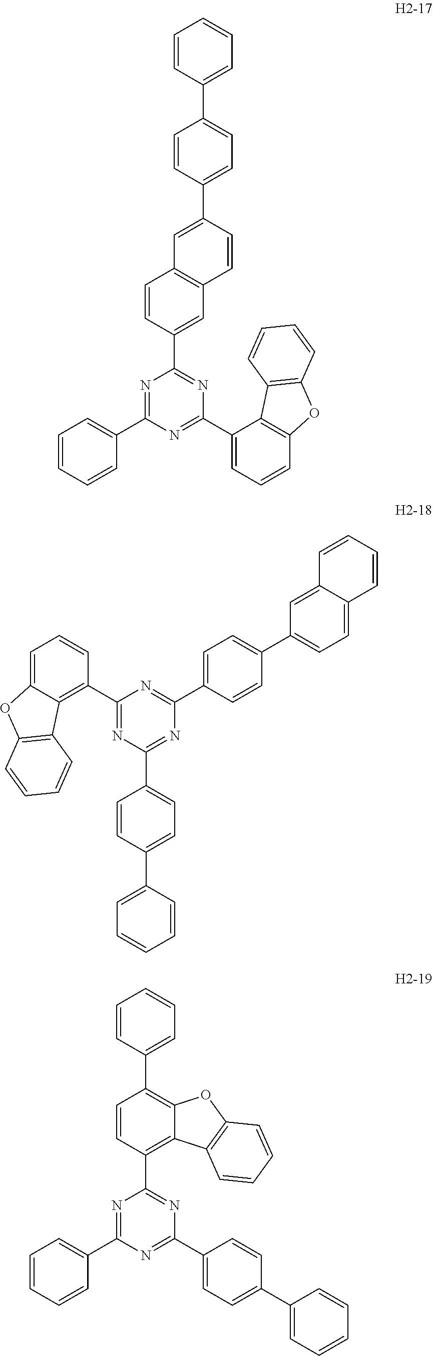

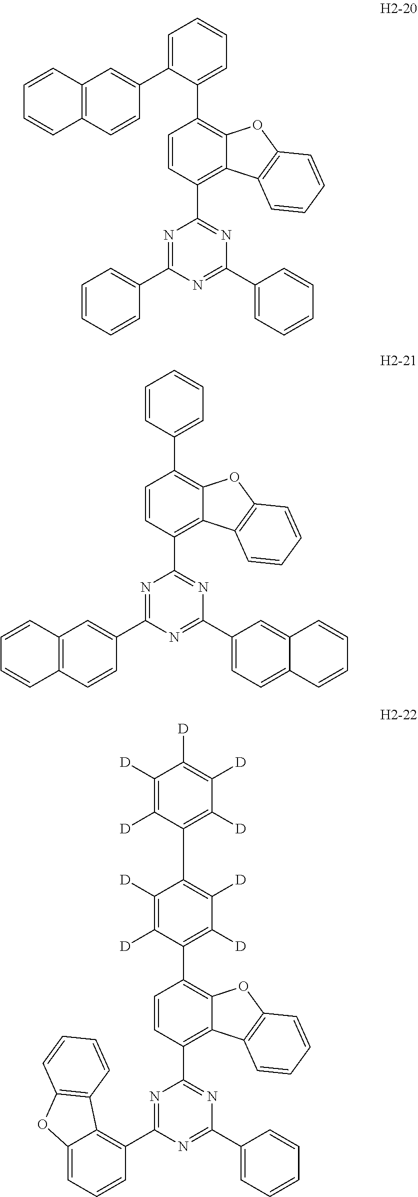 [SMILES: c1ccc(-c2nc(-c3ccccc3)nc(-c3ccc(-c4ccccc4-c4ccc5ccccc5c4)c4oc5ccccc5c34)n2)cc1 ; c1ccc(-c2ccc(-c3nc(-c4ccc5ccccc5c4)nc(-c4ccc5ccccc5c4)n3)c3c2oc2ccccc23)cc1 ; [2H]c1c([2H])c([2H])c(-c2c([2H])c([2H])c(-c3ccc(-c4nc(-c5ccccc5)nc(-c5cccc6oc7ccccc7c56)n4)c4c3oc3ccccc34)c([2H])c2[2H])c([2H])c1[2H]]

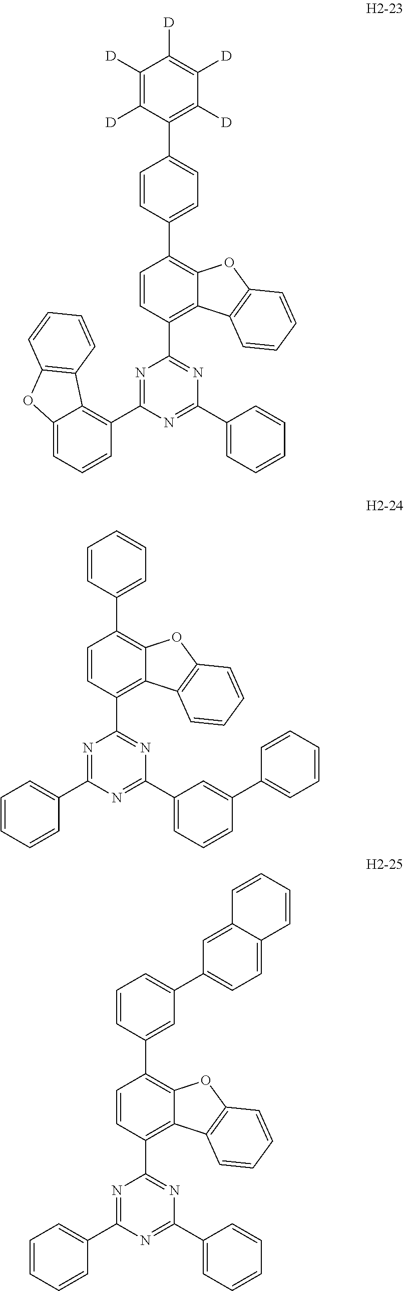 [SMILES: [2H]c1c([2H])c([2H])c(-c2ccc(-c3ccc(-c4nc(-c5ccccc5)nc(-c5cccc6oc7ccccc7c56)n4)c4c3oc3ccccc34)cc2)c([2H])c1[2H] ; c1ccc(-c2cccc(-c3nc(-c4ccccc4)nc(-c4ccc(-c5ccccc5)c5oc6ccccc6c45)n3)c2)cc1 ; c1ccc(-c2nc(-c3ccccc3)nc(-c3ccc(-c4cccc(-c5ccc6ccccc6c5)c4)c4oc5ccccc5c34)n2)cc1]

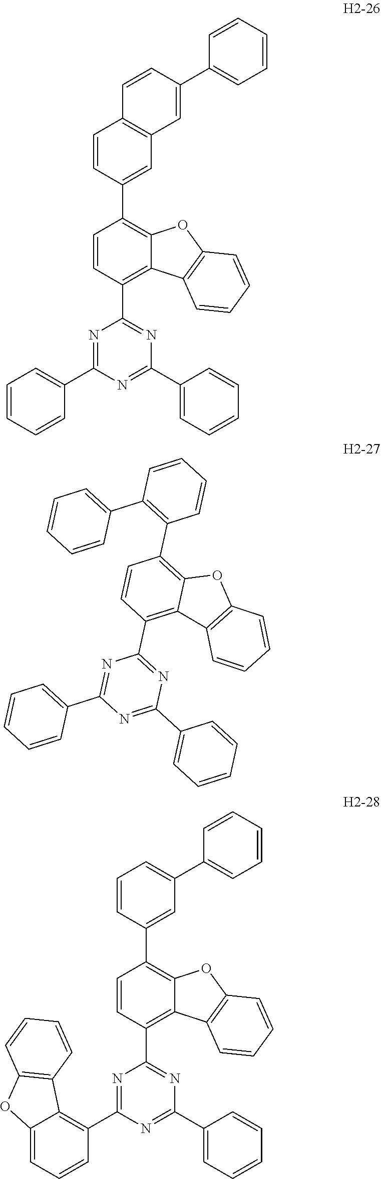

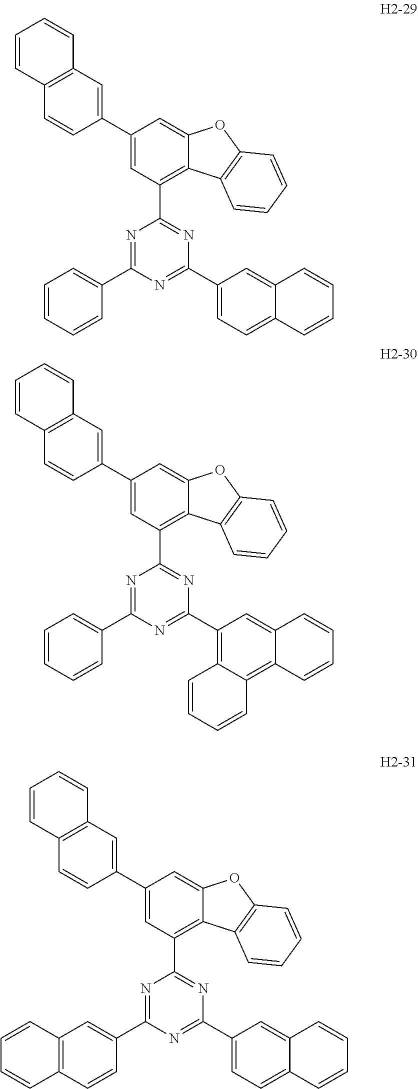

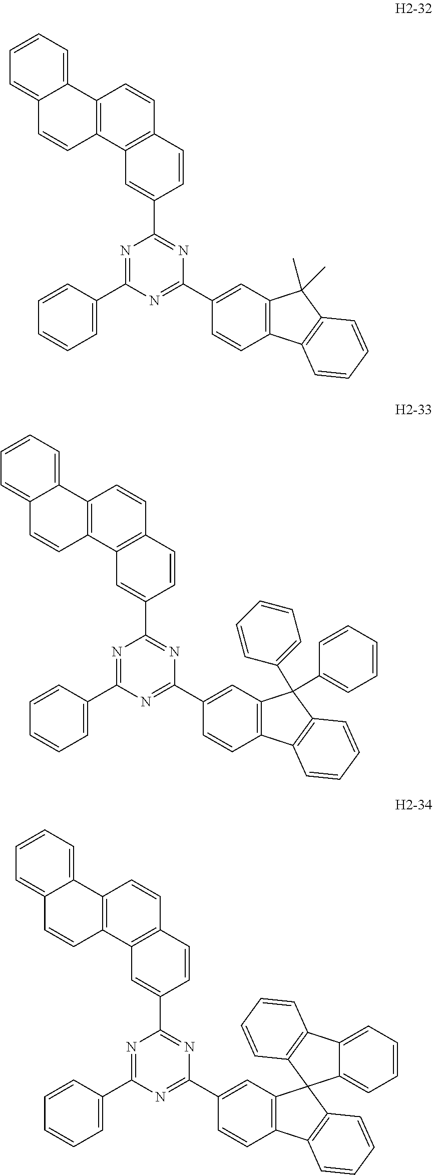 [SMILES: CC1(C)c2ccccc2-c2ccc(-c3nc(-c4ccccc4)nc(-c4ccc5ccc6c7ccccc7ccc6c5c4)n3)cc21 ; c1ccc(-c2nc(-c3ccc4c(c3)C(c3ccccc3)(c3ccccc3)c3ccccc3-4)nc(-c3ccc4ccc5c6ccccc6ccc5c4c3)n2)cc1 ; c1ccc(-c2nc(-c3ccc4c(c3)C3(c5ccccc5-c5ccccc53)c3ccccc3-4)nc(-c3ccc4ccc5c6ccccc6ccc5c4c3)n2)cc1]

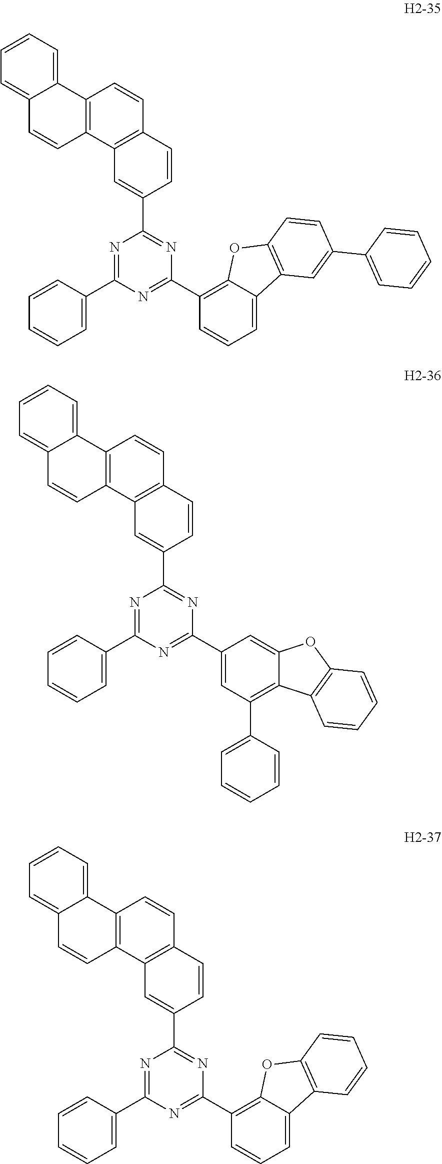

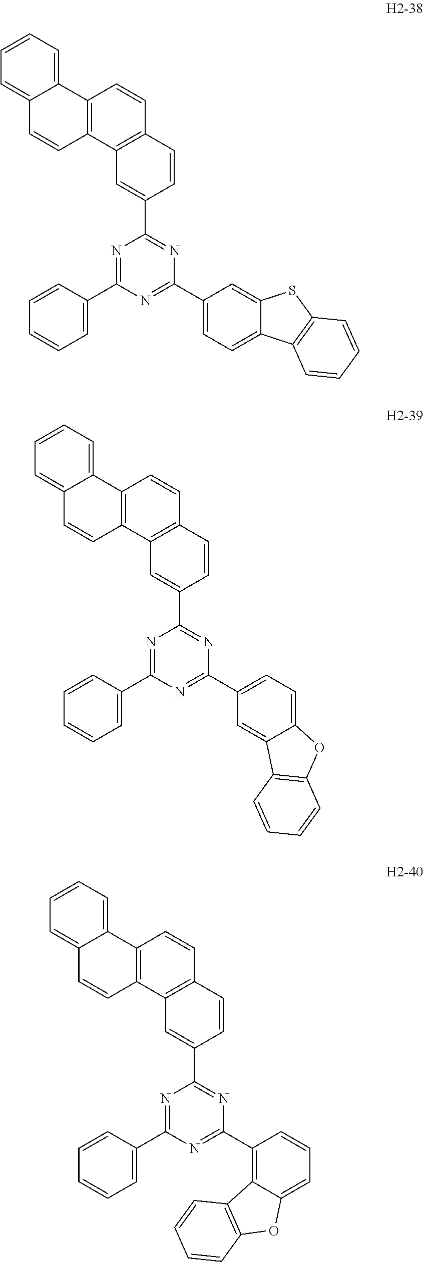 [SMILES: c1ccc(-c2nc(-c3ccc4c(c3)sc3ccccc34)nc(-c3ccc4ccc5c6ccccc6ccc5c4c3)n2)cc1 ; c1ccc(-c2nc(-c3ccc4ccc5c6ccccc6ccc5c4c3)nc(-c3ccc4oc5ccccc5c4c3)n2)cc1 ; c1ccc(-c2nc(-c3ccc4ccc5c6ccccc6ccc5c4c3)nc(-c3cccc4oc5ccccc5c34)n2)cc1]

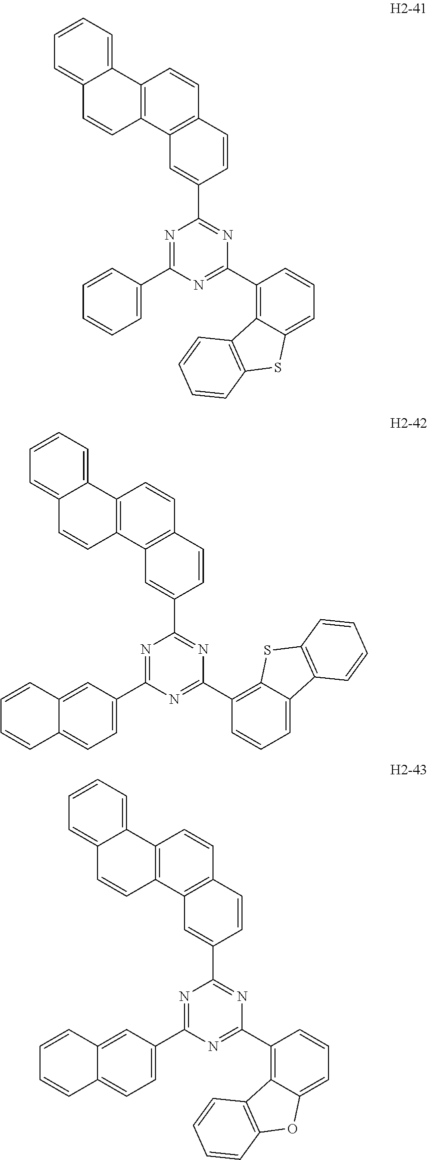

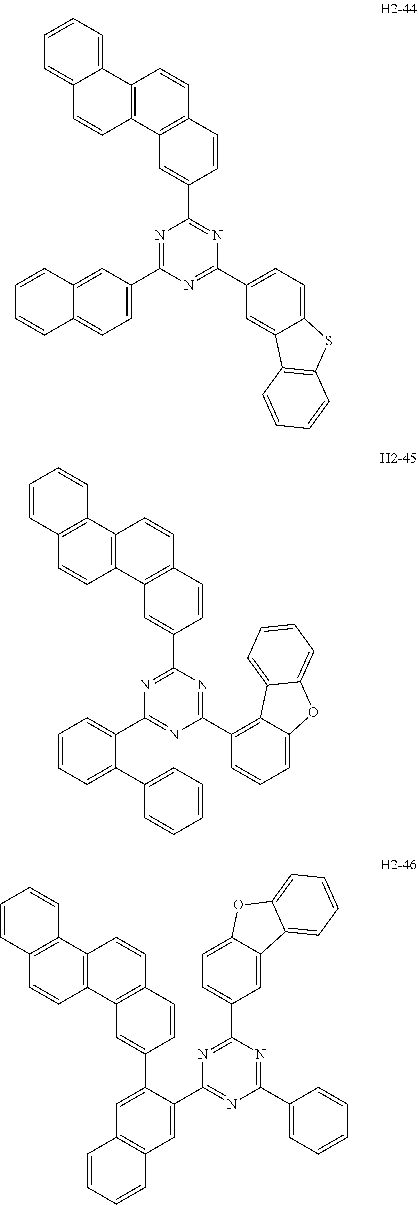 [SMILES: c1ccc2cc(-c3nc(-c4ccc5ccc6c7ccccc7ccc6c5c4)nc(-c4ccc5sc6ccccc6c5c4)n3)ccc2c1 ; c1ccc(-c2ccccc2-c2nc(-c3ccc4ccc5c6ccccc6ccc5c4c3)nc(-c3cccc4oc5ccccc5c34)n2)cc1 ; c1ccc(-c2nc(-c3ccc4oc5ccccc5c4c3)nc(-c3cc4ccccc4cc3-c3ccc4ccc5c6ccccc6ccc5c4c3)n2)cc1]

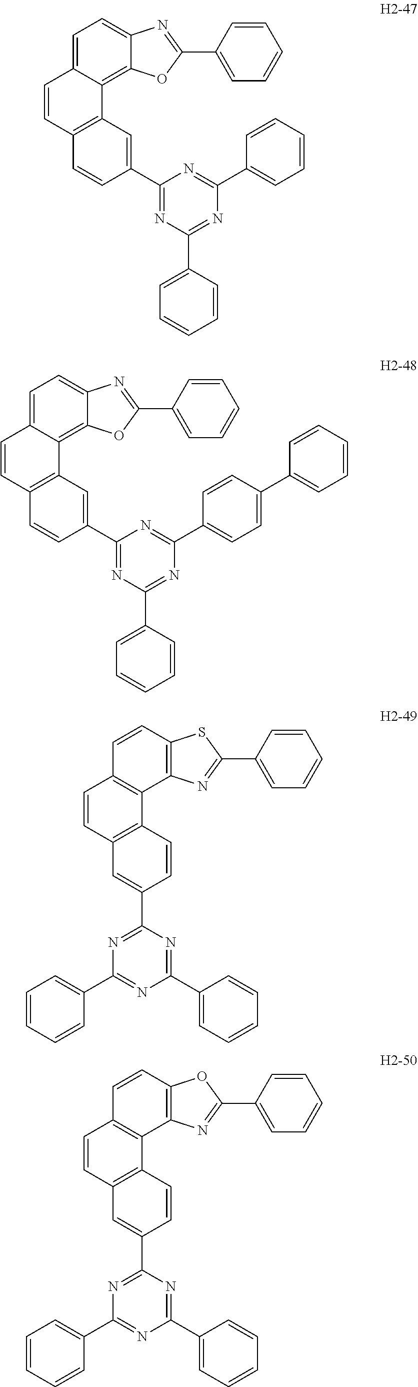

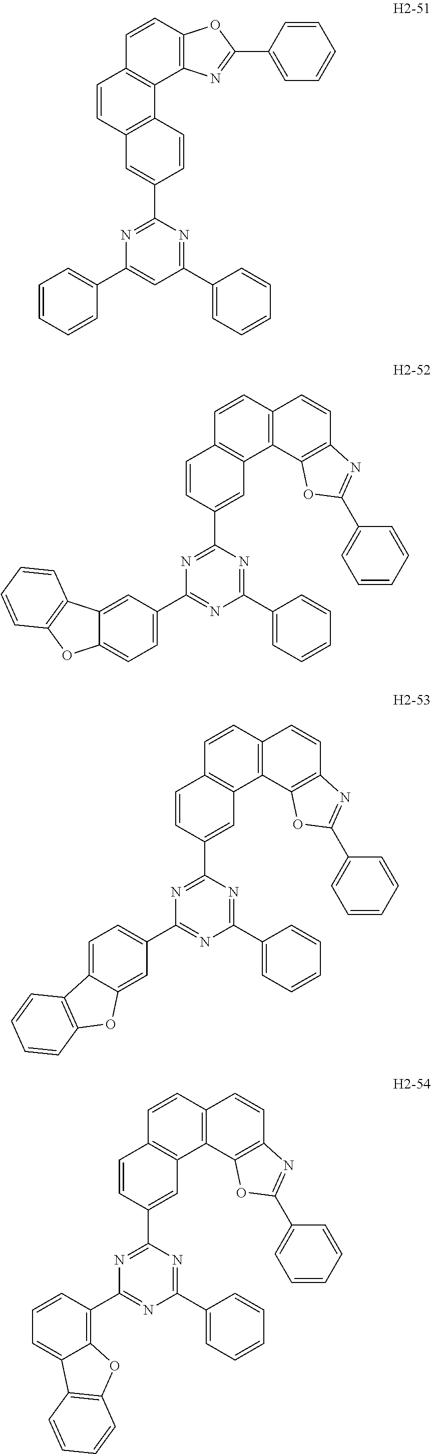 [SMILES: c1ccc(-c2cc(-c3ccccc3)nc(-c3ccc4c(ccc5ccc6oc(-c7ccccc7)nc6c54)c3)n2)cc1 ; c1ccc(-c2nc(-c3ccc4oc5ccccc5c4c3)nc(-c3ccc4ccc5ccc6nc(-c7ccccc7)oc6c5c4c3)n2)cc1 ; c1ccc(-c2nc(-c3ccc4c(c3)oc3ccccc34)nc(-c3ccc4ccc5ccc6nc(-c7ccccc7)oc6c5c4c3)n2)cc1 ; c1ccc(-c2nc(-c3ccc4ccc5ccc6nc(-c7ccccc7)oc6c5c4c3)nc(-c3cccc4c3oc3ccccc34)n2)cc1]

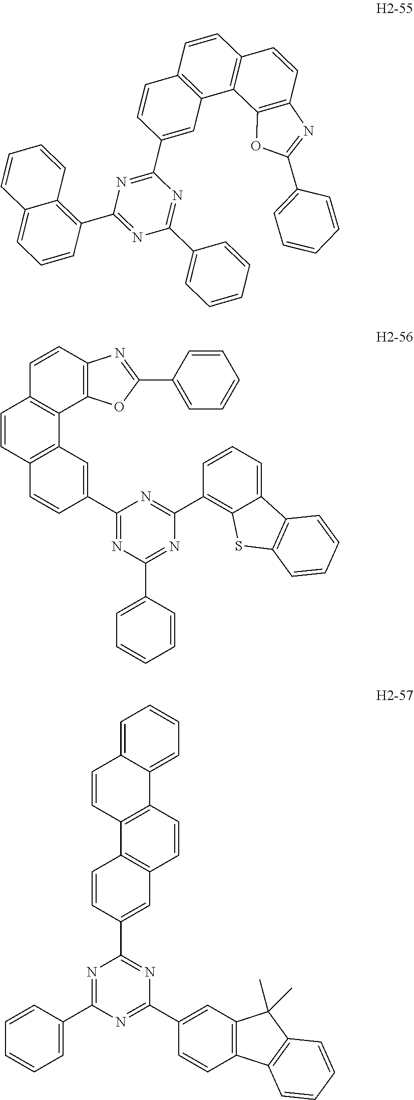

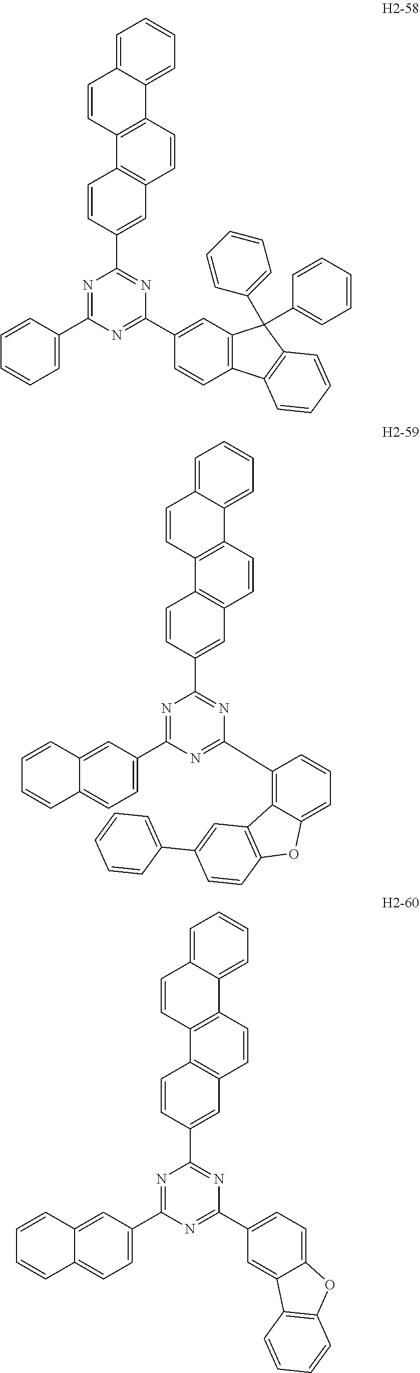

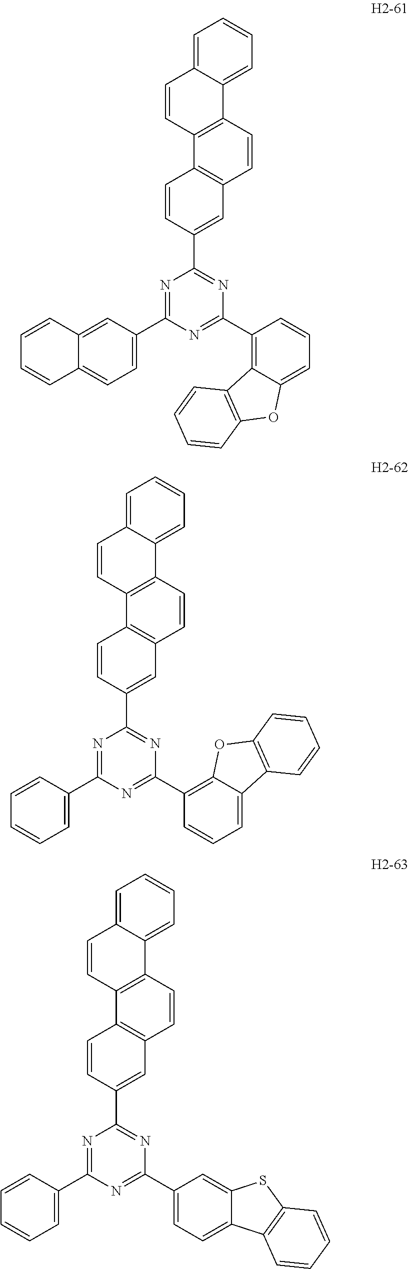

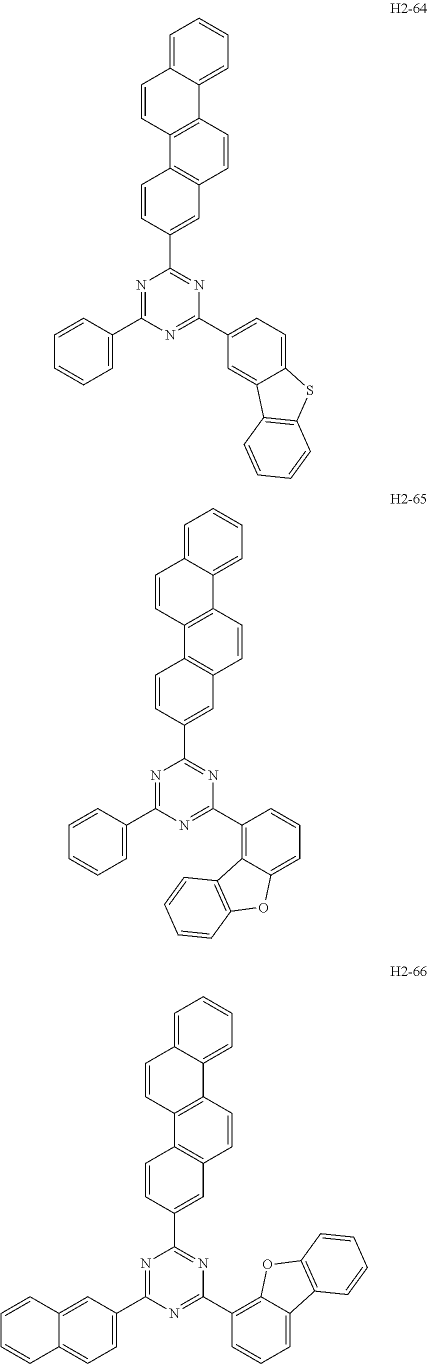 [SMILES: c1ccc(-c2nc(-c3ccc4c(ccc5c6ccccc6ccc45)c3)nc(-c3ccc4sc5ccccc5c4c3)n2)cc1 ; c1ccc(-c2nc(-c3ccc4c(ccc5c6ccccc6ccc45)c3)nc(-c3cccc4oc5ccccc5c34)n2)cc1 ; c1ccc2cc(-c3nc(-c4ccc5c(ccc6c7ccccc7ccc56)c4)nc(-c4cccc5c4oc4ccccc45)n3)ccc2c1]

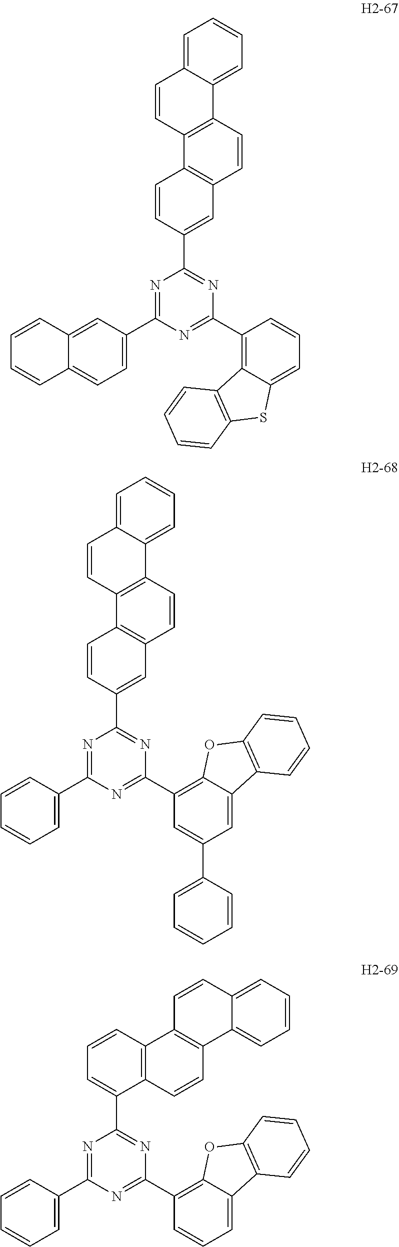

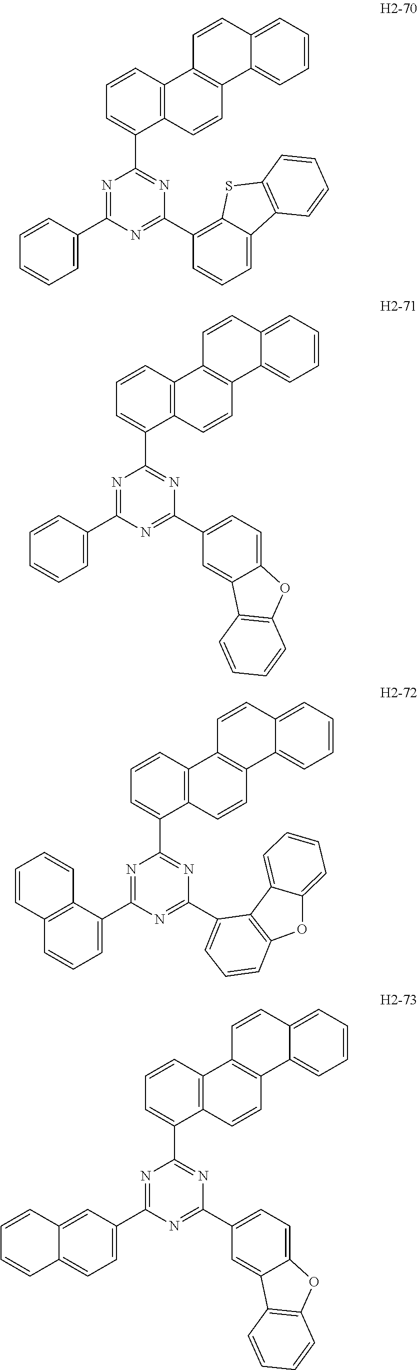

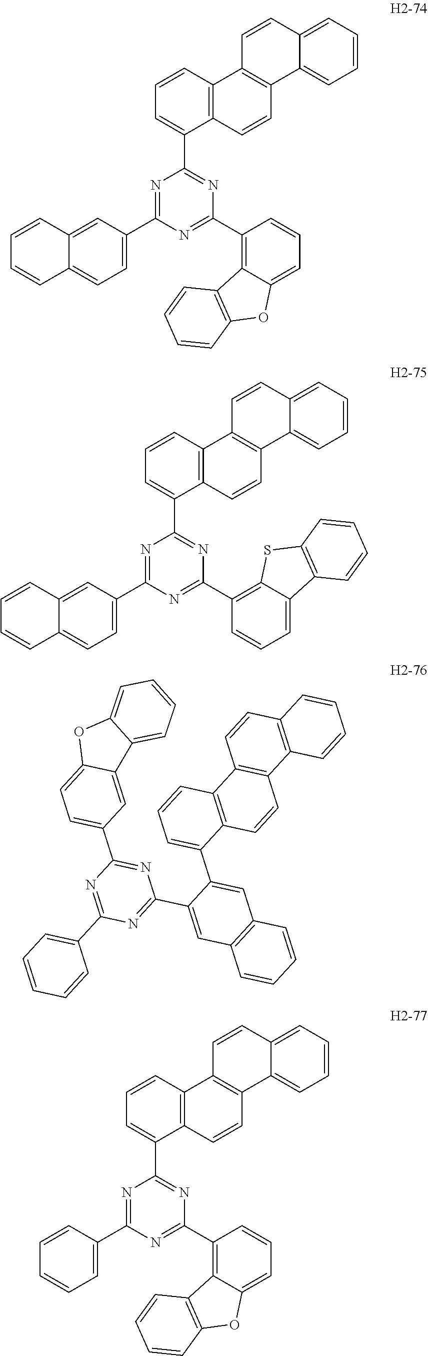 [SMILES: c1ccc2cc(-c3nc(-c4cccc5c4ccc4c6ccccc6ccc54)nc(-c4cccc5oc6ccccc6c45)n3)ccc2c1 ; c1ccc2cc(-c3nc(-c4cccc5c4ccc4c6ccccc6ccc54)nc(-c4cccc5c4sc4ccccc45)n3)ccc2c1 ; c1ccc(-c2nc(-c3ccc4oc5ccccc5c4c3)nc(-c3cc4ccccc4cc3-c3cccc4c3ccc3c5ccccc5ccc43)n2)cc1 ; c1ccc(-c2nc(-c3cccc4c3ccc3c5ccccc5ccc43)nc(-c3cccc4oc5ccccc5c34)n2)cc1]

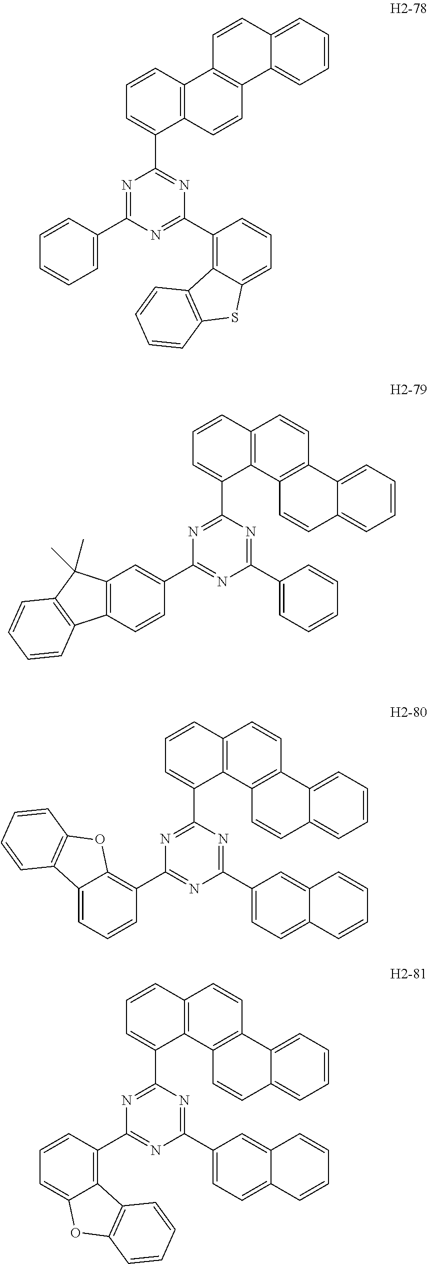 [SMILES: c1ccc(-c2nc(-c3cccc4c3ccc3c5ccccc5ccc43)nc(-c3cccc4sc5ccccc5c34)n2)cc1 ; CC1(C)c2ccccc2-c2ccc(-c3nc(-c4ccccc4)nc(-c4cccc5ccc6c7ccccc7ccc6c45)n3)cc21 ; c1ccc2cc(-c3nc(-c4cccc5c4oc4ccccc45)nc(-c4cccc5ccc6c7ccccc7ccc6c45)n3)ccc2c1 ; c1ccc2cc(-c3nc(-c4cccc5ccc6c7ccccc7ccc6c45)nc(-c4cccc5oc6ccccc6c45)n3)ccc2c1]

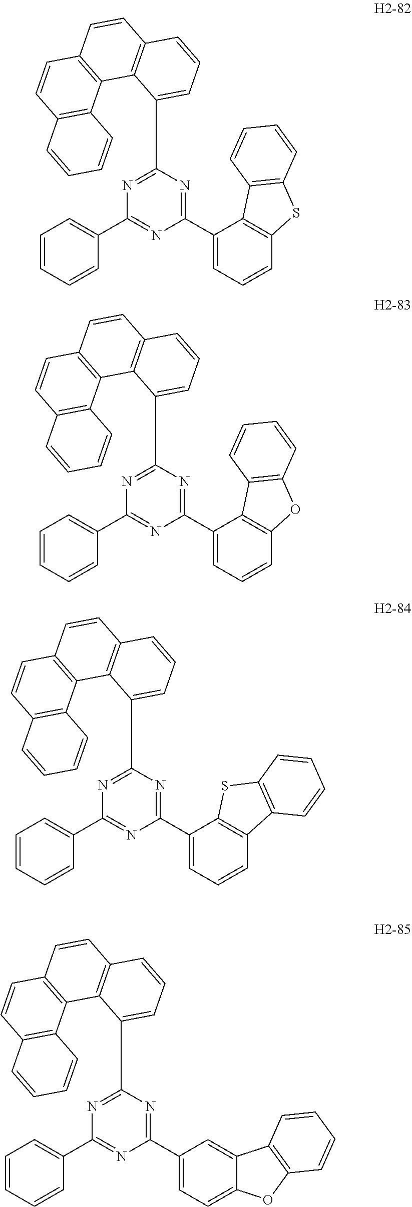

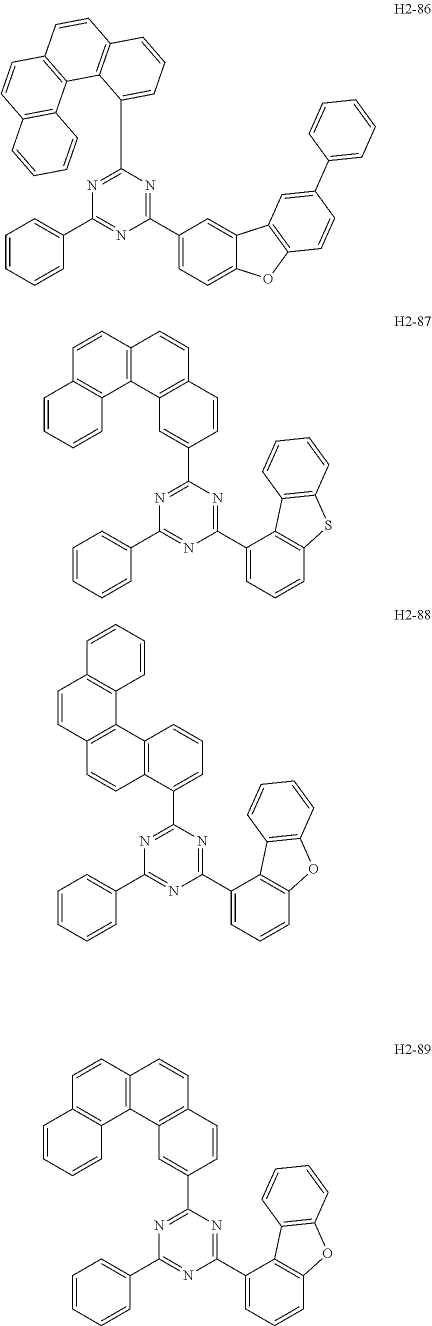

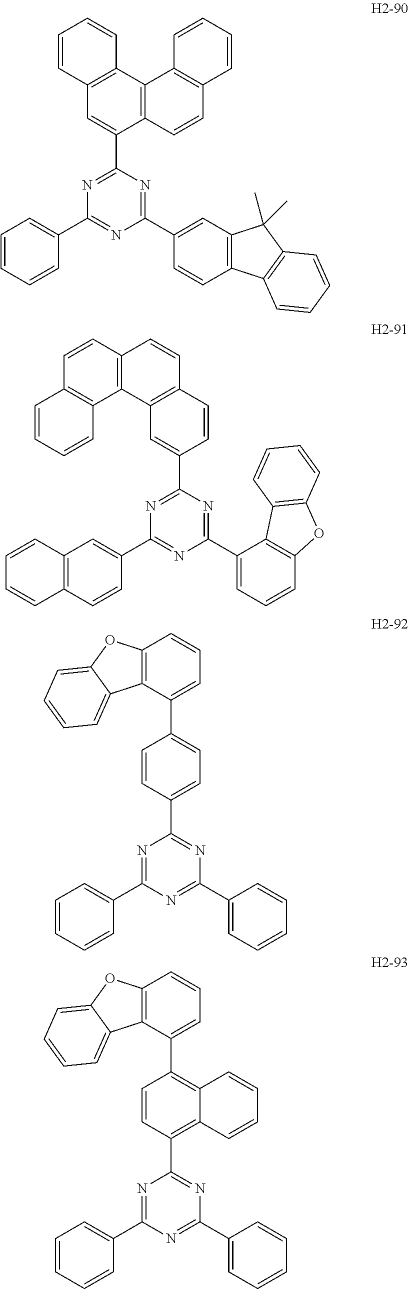

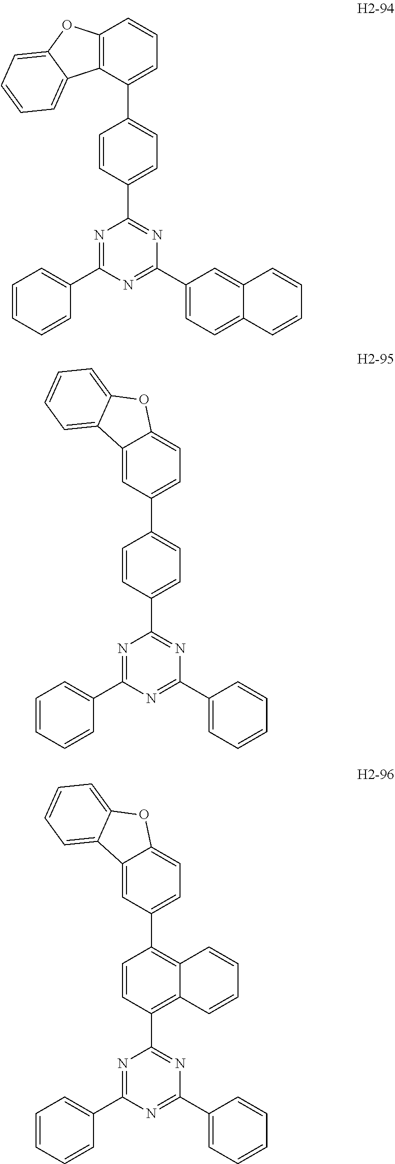

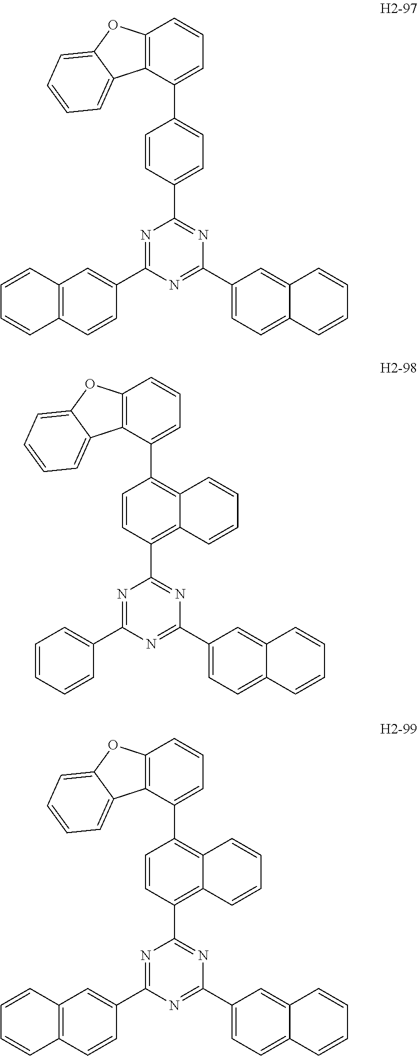 [SMILES: c1ccc2cc(-c3nc(-c4ccc(-c5cccc6oc7ccccc7c56)cc4)nc(-c4ccc5ccccc5c4)n3)ccc2c1 ; c1ccc(-c2nc(-c3ccc4ccccc4c3)nc(-c3ccc(-c4cccc5oc6ccccc6c45)c4ccccc34)n2)cc1 ; c1ccc2cc(-c3nc(-c4ccc5ccccc5c4)nc(-c4ccc(-c5cccc6oc7ccccc7c56)c5ccccc45)n3)ccc2c1]

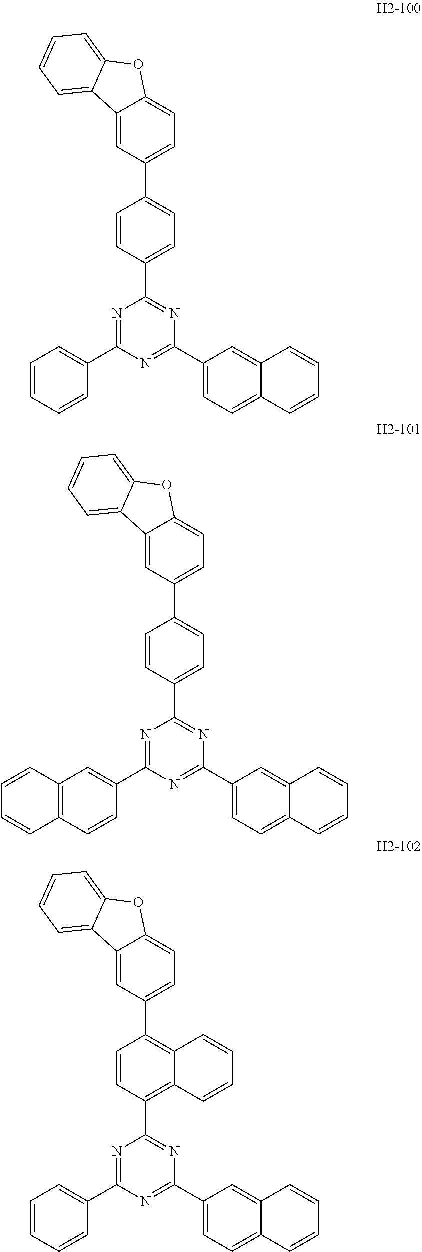

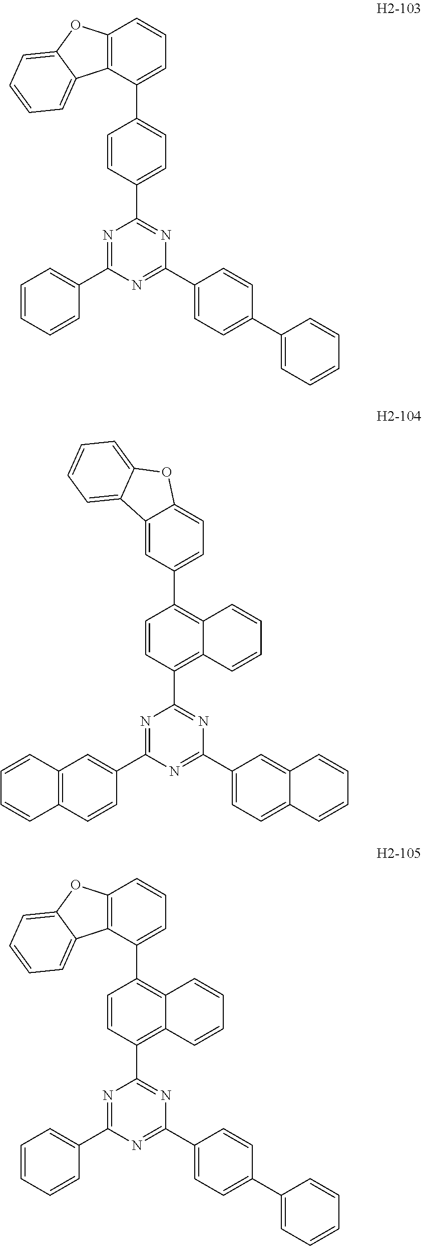 [SMILES: c1ccc(-c2ccc(-c3nc(-c4ccccc4)nc(-c4ccc(-c5cccc6oc7ccccc7c56)cc4)n3)cc2)cc1 ; c1ccc2cc(-c3nc(-c4ccc5ccccc5c4)nc(-c4ccc(-c5ccc6oc7ccccc7c6c5)c5ccccc45)n3)ccc2c1 ; c1ccc(-c2ccc(-c3nc(-c4ccccc4)nc(-c4ccc(-c5cccc6oc7ccccc7c56)c5ccccc45)n3)cc2)cc1]

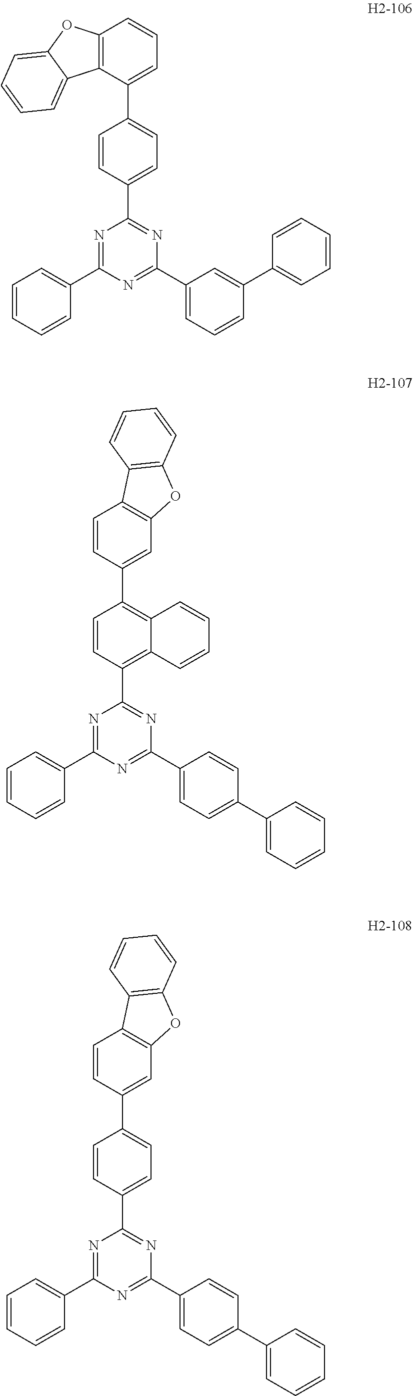 [SMILES: c1ccc(-c2cccc(-c3nc(-c4ccccc4)nc(-c4ccc(-c5cccc6oc7ccccc7c56)cc4)n3)c2)cc1 ; c1ccc(-c2ccc(-c3nc(-c4ccccc4)nc(-c4ccc(-c5ccc6c(c5)oc5ccccc56)c5ccccc45)n3)cc2)cc1 ; c1ccc(-c2ccc(-c3nc(-c4ccccc4)nc(-c4ccc(-c5ccc6c(c5)oc5ccccc56)cc4)n3)cc2)cc1]

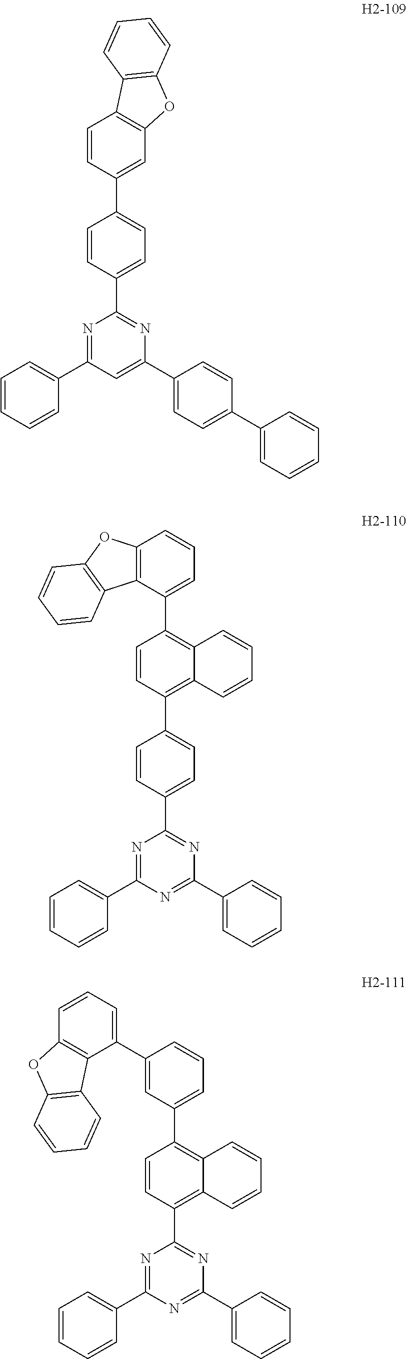

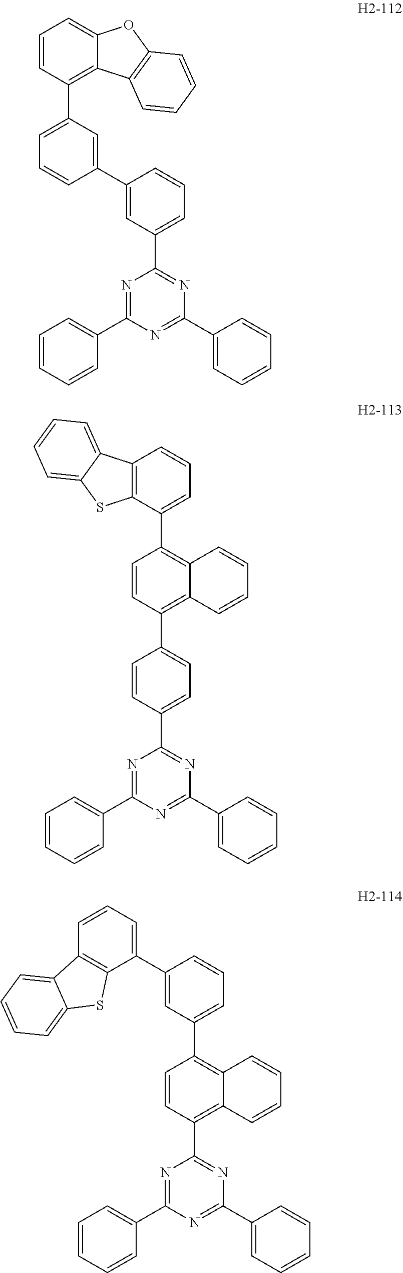

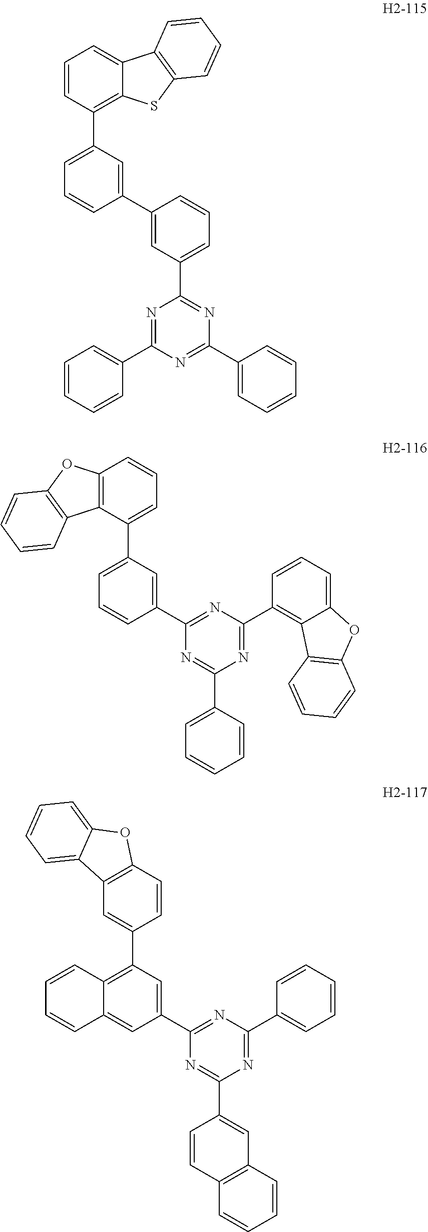 [SMILES: c1ccc(-c2nc(-c3ccccc3)nc(-c3cccc(-c4cccc(-c5cccc6c5sc5ccccc56)c4)c3)n2)cc1 ; c1ccc(-c2nc(-c3cccc(-c4cccc5oc6ccccc6c45)c3)nc(-c3cccc4oc5ccccc5c34)n2)cc1 ; c1ccc(-c2nc(-c3ccc4ccccc4c3)nc(-c3cc(-c4ccc5oc6ccccc6c5c4)c4ccccc4c3)n2)cc1]

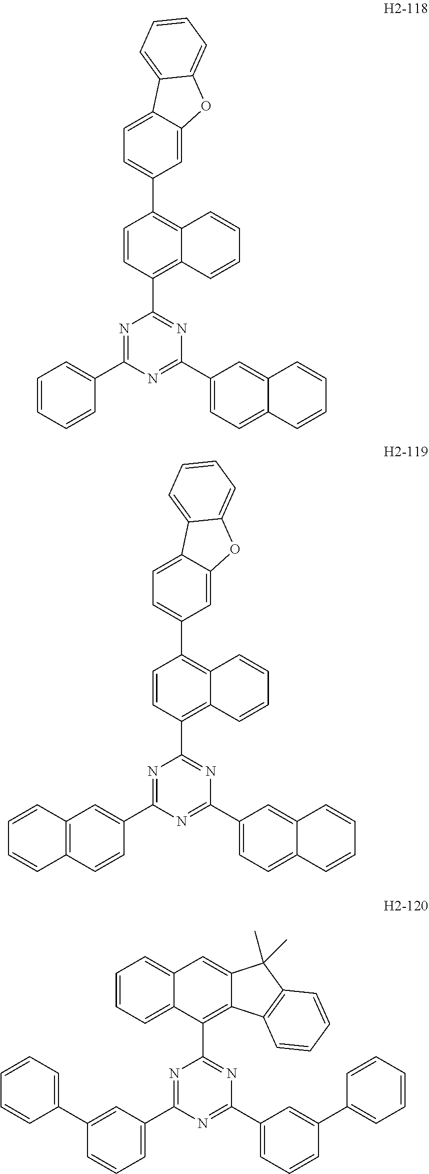

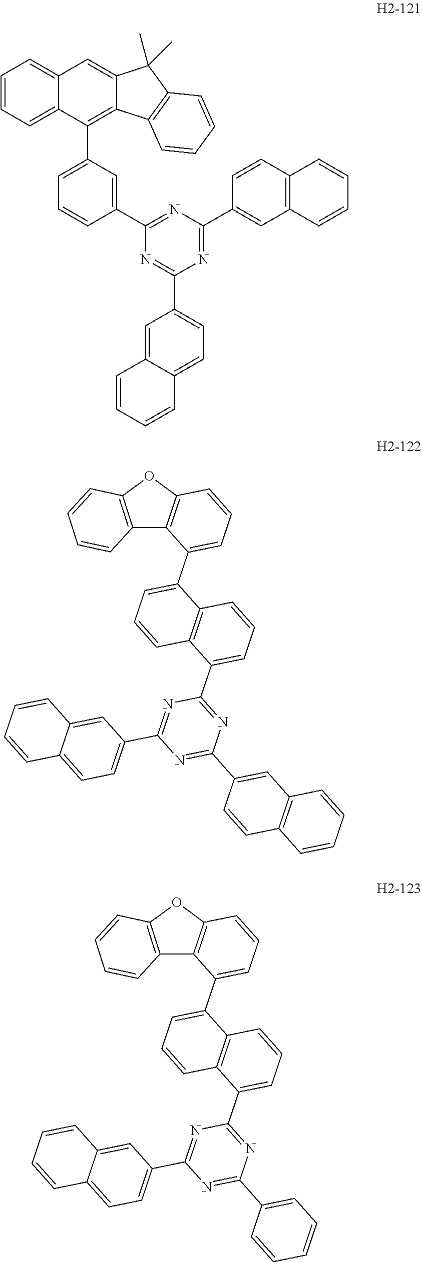 [SMILES: CC1(C)c2ccccc2-c2c1cc1ccccc1c2-c1cccc(-c2nc(-c3ccc4ccccc4c3)nc(-c3ccc4ccccc4c3)n2)c1 ; c1ccc2cc(-c3nc(-c4ccc5ccccc5c4)nc(-c4cccc5c(-c6cccc7oc8ccccc8c67)cccc45)n3)ccc2c1 ; c1ccc(-c2nc(-c3ccc4ccccc4c3)nc(-c3cccc4c(-c5cccc6oc7ccccc7c56)cccc34)n2)cc1]

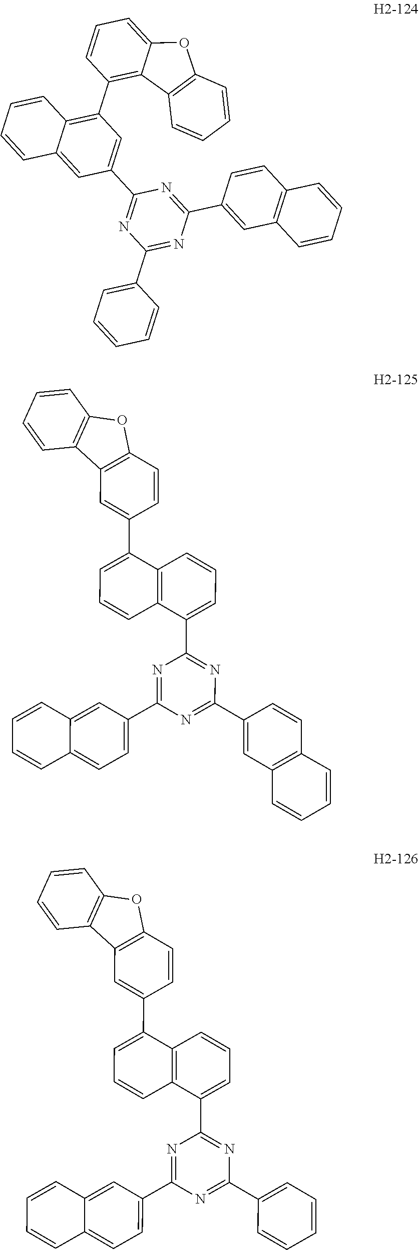 [SMILES: c1ccc(-c2nc(-c3ccc4ccccc4c3)nc(-c3cc(-c4cccc5oc6ccccc6c45)c4ccccc4c3)n2)cc1 ; c1ccc2cc(-c3nc(-c4ccc5ccccc5c4)nc(-c4cccc5c(-c6ccc7oc8ccccc8c7c6)cccc45)n3)ccc2c1 ; c1ccc(-c2nc(-c3ccc4ccccc4c3)nc(-c3cccc4c(-c5ccc6oc7ccccc7c6c5)cccc34)n2)cc1]

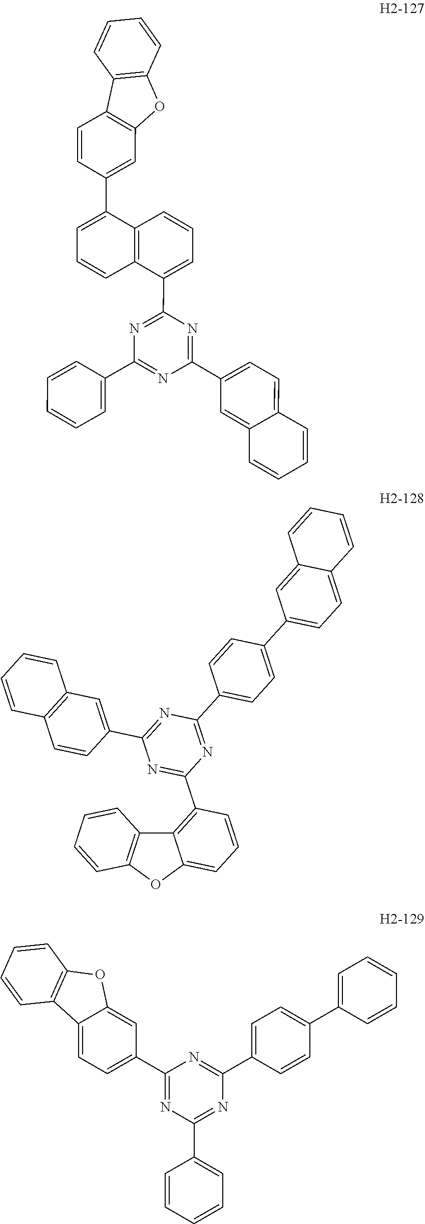

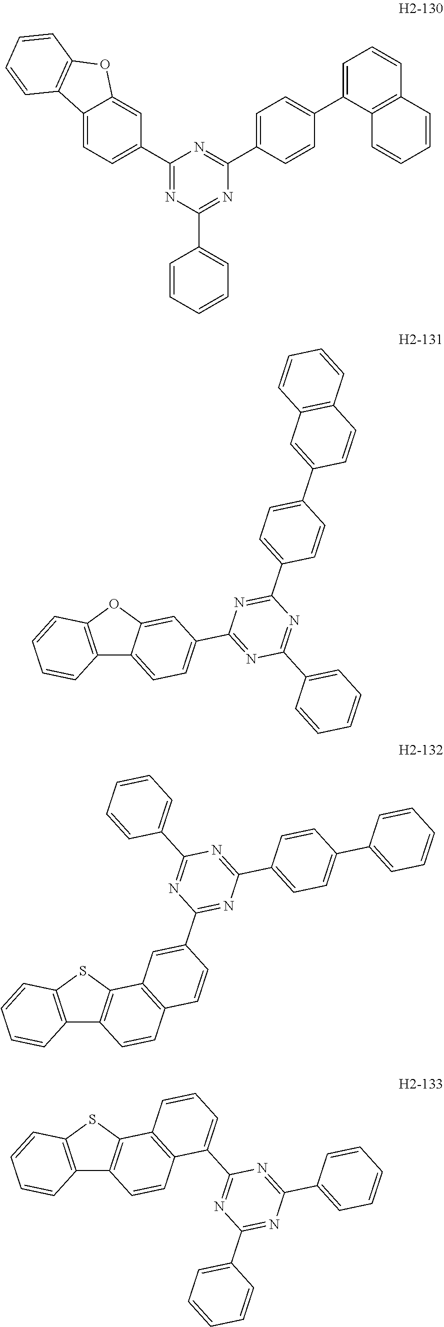 [SMILES: c1ccc(-c2nc(-c3ccc(-c4cccc5ccccc45)cc3)nc(-c3ccc4c(c3)oc3ccccc34)n2)cc1 ; c1ccc(-c2nc(-c3ccc(-c4ccc5ccccc5c4)cc3)nc(-c3ccc4c(c3)oc3ccccc34)n2)cc1 ; c1ccc(-c2ccc(-c3nc(-c4ccccc4)nc(-c4ccc5ccc6c7ccccc7sc6c5c4)n3)cc2)cc1 ; c1ccc(-c2nc(-c3ccccc3)nc(-c3cccc4c3ccc3c5ccccc5sc43)n2)cc1]

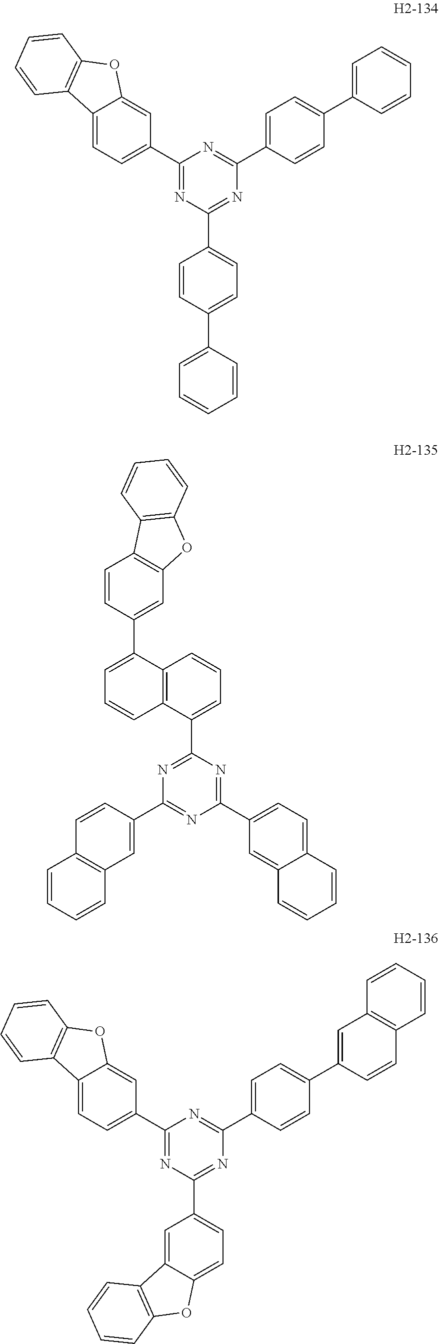 [SMILES: c1ccc(-c2ccc(-c3nc(-c4ccc(-c5ccccc5)cc4)nc(-c4ccc5c(c4)oc4ccccc45)n3)cc2)cc1 ; c1ccc2cc(-c3nc(-c4ccc5ccccc5c4)nc(-c4cccc5c(-c6ccc7c(c6)oc6ccccc67)cccc45)n3)ccc2c1 ; c1ccc2cc(-c3ccc(-c4nc(-c5ccc6c(c5)oc5ccccc56)nc(-c5ccc6oc7ccccc7c6c5)n4)cc3)ccc2c1]

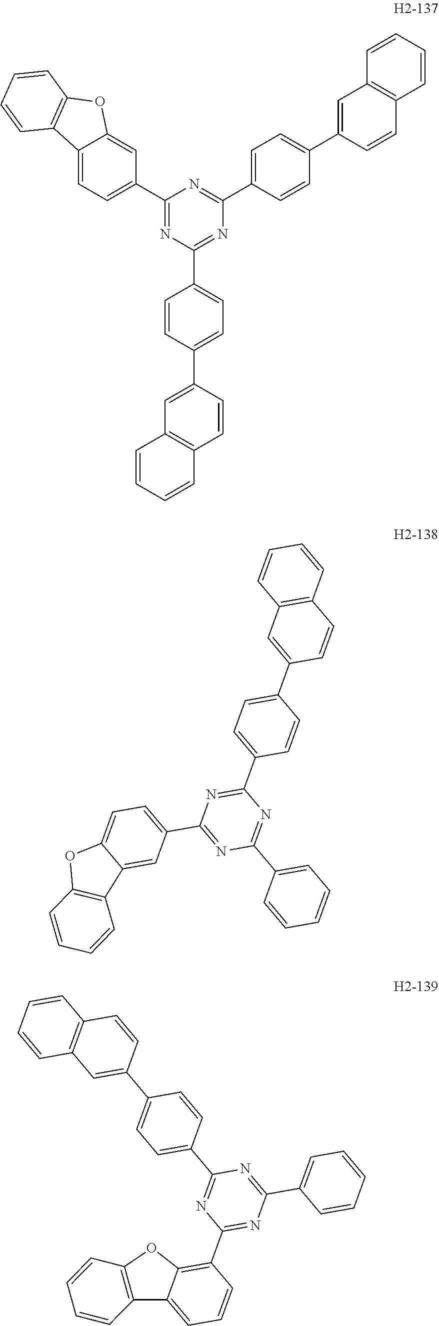 [SMILES: c1ccc2cc(-c3ccc(-c4nc(-c5ccc(-c6ccc7ccccc7c6)cc5)nc(-c5ccc6c(c5)oc5ccccc56)n4)cc3)ccc2c1 ; c1ccc(-c2nc(-c3ccc(-c4ccc5ccccc5c4)cc3)nc(-c3ccc4oc5ccccc5c4c3)n2)cc1 ; c1ccc(-c2nc(-c3ccc(-c4ccc5ccccc5c4)cc3)nc(-c3cccc4c3oc3ccccc34)n2)cc1]

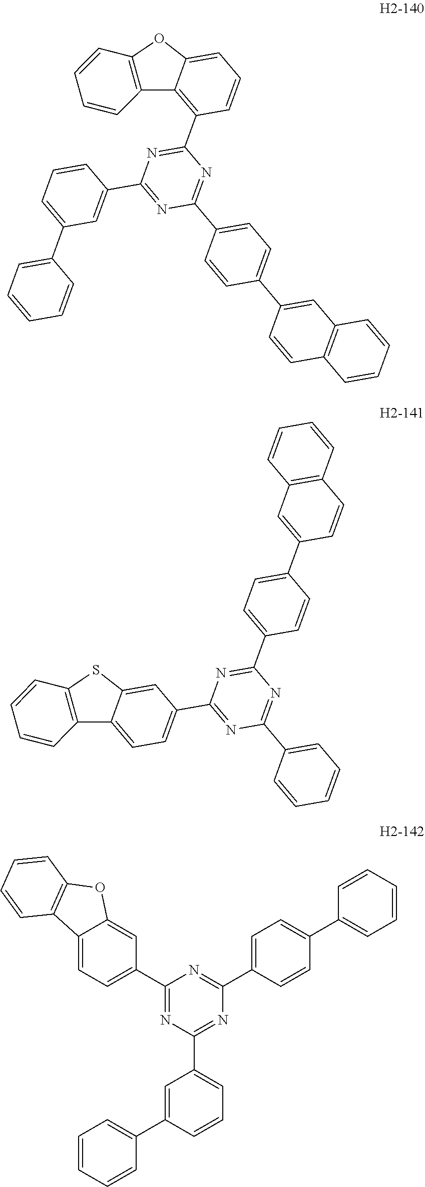 [SMILES: c1ccc(-c2cccc(-c3nc(-c4ccc(-c5ccc6ccccc6c5)cc4)nc(-c4cccc5oc6ccccc6c45)n3)c2)cc1 ; c1ccc(-c2nc(-c3ccc(-c4ccc5ccccc5c4)cc3)nc(-c3ccc4c(c3)sc3ccccc34)n2)cc1 ; c1ccc(-c2ccc(-c3nc(-c4cccc(-c5ccccc5)c4)nc(-c4ccc5c(c4)oc4ccccc45)n3)cc2)cc1]

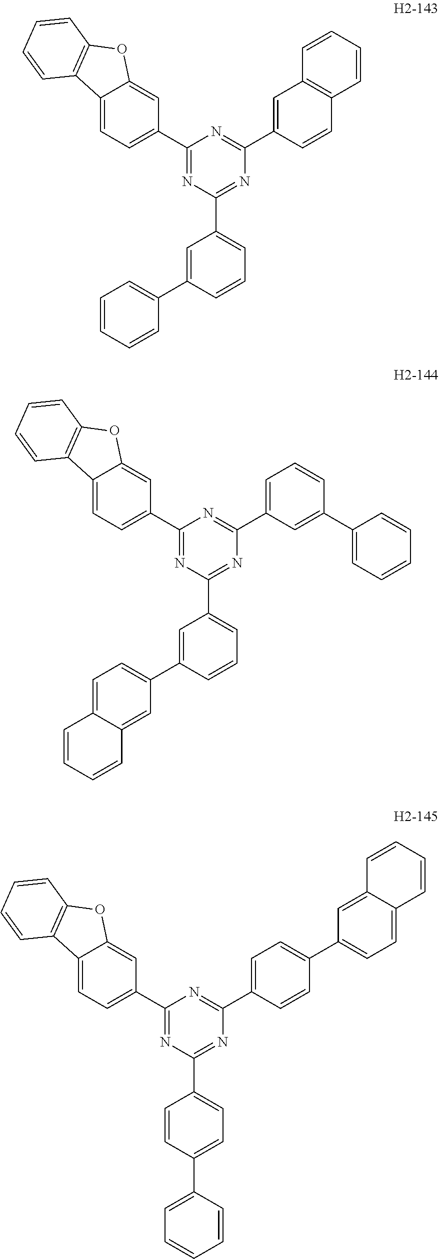 [SMILES: c1ccc(-c2cccc(-c3nc(-c4ccc5ccccc5c4)nc(-c4ccc5c(c4)oc4ccccc45)n3)c2)cc1 ; c1ccc(-c2cccc(-c3nc(-c4cccc(-c5ccc6ccccc6c5)c4)nc(-c4ccc5c(c4)oc4ccccc45)n3)c2)cc1 ; c1ccc(-c2ccc(-c3nc(-c4ccc(-c5ccc6ccccc6c5)cc4)nc(-c4ccc5c(c4)oc4ccccc45)n3)cc2)cc1]

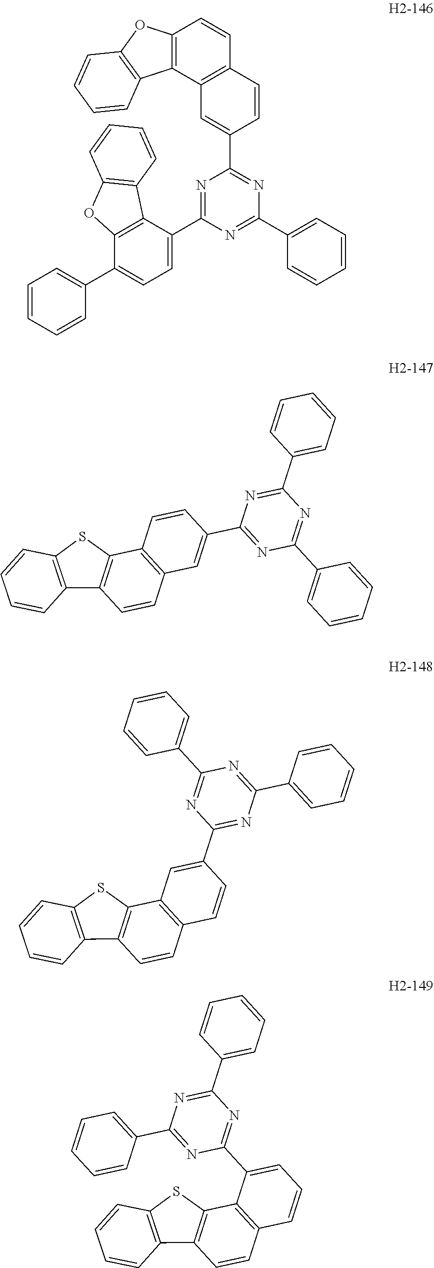 [SMILES: c1ccc(-c2nc(-c3ccc4ccc5oc6ccccc6c5c4c3)nc(-c3ccc(-c4ccccc4)c4oc5ccccc5c34)n2)cc1 ; c1ccc(-c2nc(-c3ccccc3)nc(-c3ccc4c(ccc5c6ccccc6sc45)c3)n2)cc1 ; c1ccc(-c2nc(-c3ccccc3)nc(-c3ccc4ccc5c6ccccc6sc5c4c3)n2)cc1 ; c1ccc(-c2nc(-c3ccccc3)nc(-c3cccc4ccc5c6ccccc6sc5c34)n2)cc1]

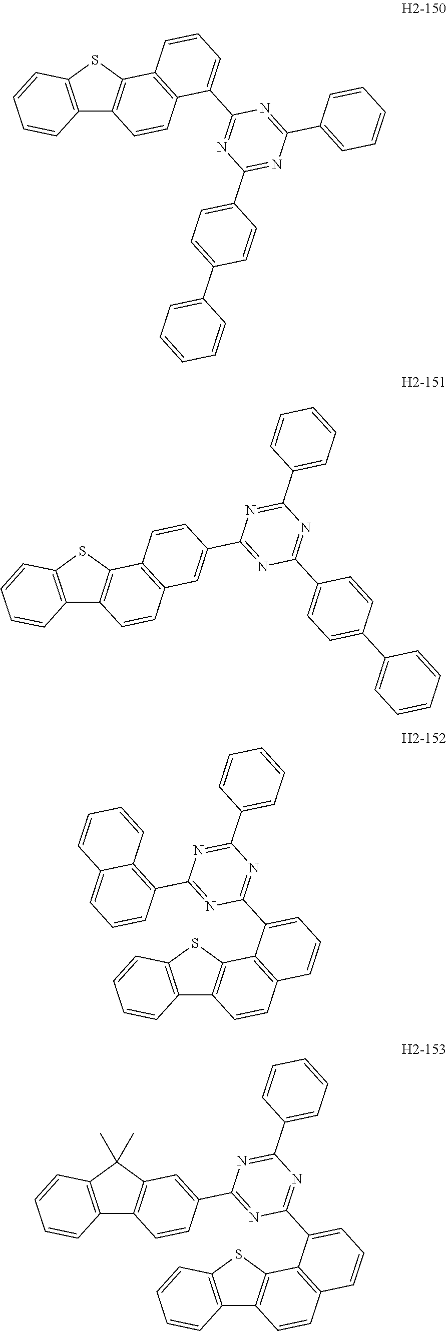 [SMILES: c1ccc(-c2ccc(-c3nc(-c4ccccc4)nc(-c4cccc5c4ccc4c6ccccc6sc54)n3)cc2)cc1 ; c1ccc(-c2ccc(-c3nc(-c4ccccc4)nc(-c4ccc5c(ccc6c7ccccc7sc56)c4)n3)cc2)cc1 ; c1ccc(-c2nc(-c3cccc4ccccc34)nc(-c3cccc4ccc5c6ccccc6sc5c34)n2)cc1 ; CC1(C)c2ccccc2-c2ccc(-c3nc(-c4ccccc4)nc(-c4cccc5ccc6c7ccccc7sc6c45)n3)cc21]

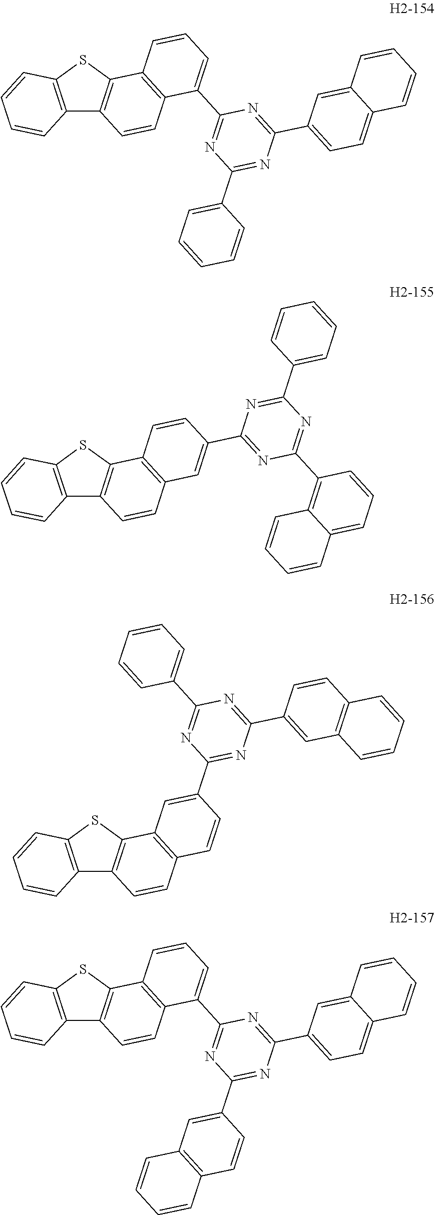 [SMILES: c1ccc(-c2nc(-c3ccc4ccccc4c3)nc(-c3cccc4c3ccc3c5ccccc5sc43)n2)cc1 ; c1ccc(-c2nc(-c3ccc4c(ccc5c6ccccc6sc45)c3)nc(-c3cccc4ccccc34)n2)cc1 ; c1ccc(-c2nc(-c3ccc4ccccc4c3)nc(-c3ccc4ccc5c6ccccc6sc5c4c3)n2)cc1 ; c1ccc2cc(-c3nc(-c4ccc5ccccc5c4)nc(-c4cccc5c4ccc4c6ccccc6sc54)n3)ccc2c1]

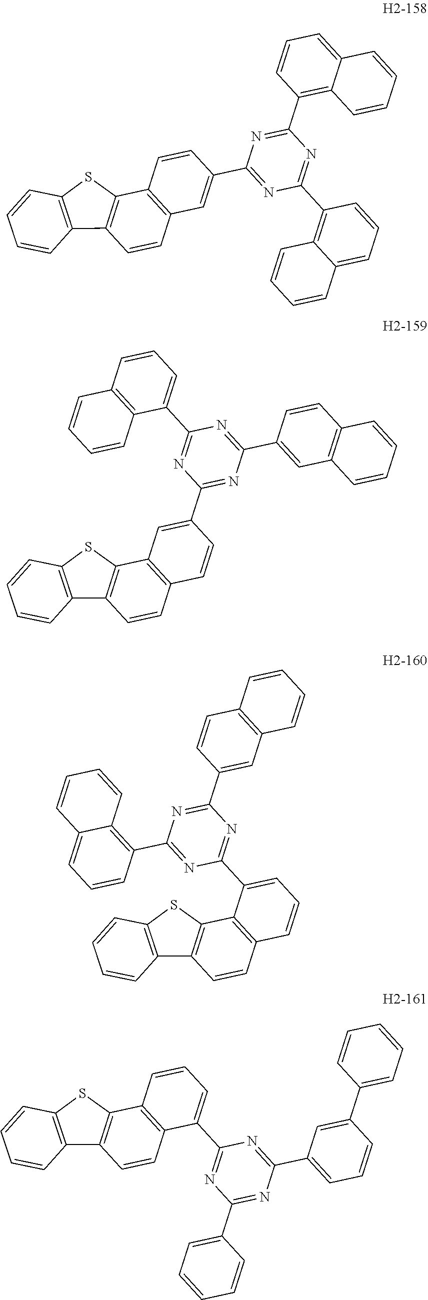 [SMILES: c1ccc2c(-c3nc(-c4ccc5c(ccc6c7ccccc7sc56)c4)nc(-c4cccc5ccccc45)n3)cccc2c1 ; c1ccc2cc(-c3nc(-c4ccc5ccc6c7ccccc7sc6c5c4)nc(-c4cccc5ccccc45)n3)ccc2c1 ; c1ccc2cc(-c3nc(-c4cccc5ccccc45)nc(-c4cccc5ccc6c7ccccc7sc6c45)n3)ccc2c1 ; c1ccc(-c2cccc(-c3nc(-c4ccccc4)nc(-c4cccc5c4ccc4c6ccccc6sc54)n3)c2)cc1]

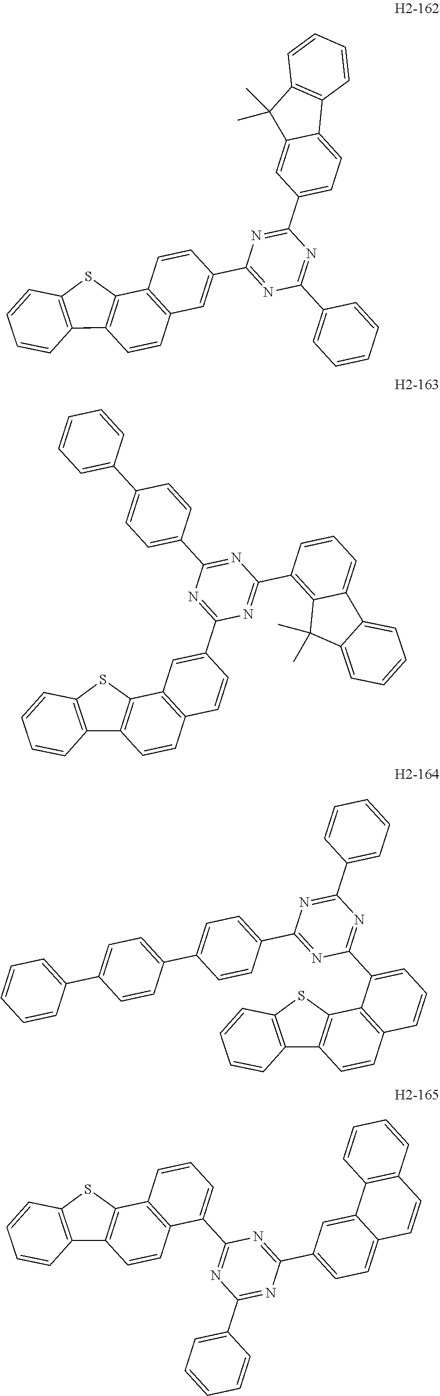 [SMILES: CC1(C)c2ccccc2-c2ccc(-c3nc(-c4ccccc4)nc(-c4ccc5c(ccc6c7ccccc7sc56)c4)n3)cc21 ; CC1(C)c2ccccc2-c2cccc(-c3nc(-c4ccc(-c5ccccc5)cc4)nc(-c4ccc5ccc6c7ccccc7sc6c5c4)n3)c21 ; c1ccc(-c2ccc(-c3ccc(-c4nc(-c5ccccc5)nc(-c5cccc6ccc7c8ccccc8sc7c56)n4)cc3)cc2)cc1 ; c1ccc(-c2nc(-c3ccc4ccc5ccccc5c4c3)nc(-c3cccc4c3ccc3c5ccccc5sc43)n2)cc1]

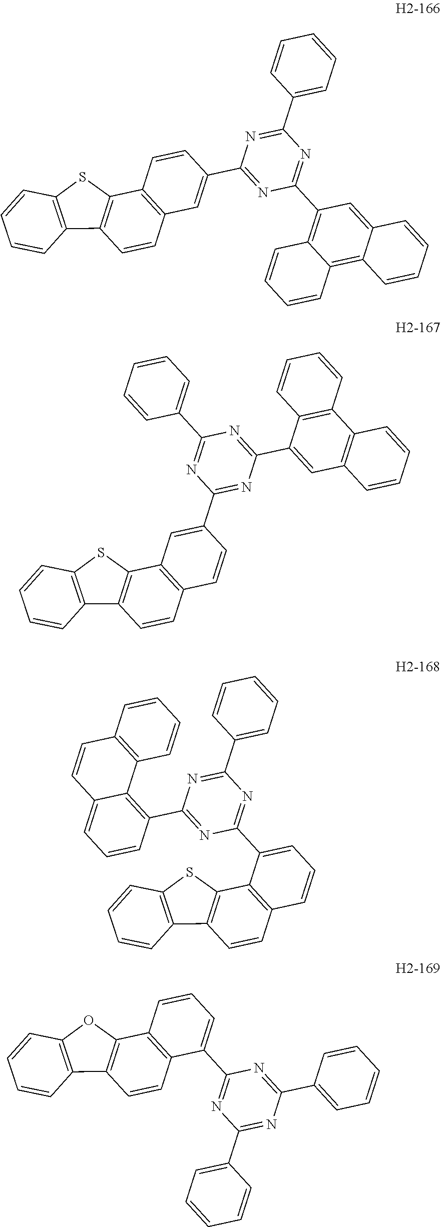 [SMILES: c1ccc(-c2nc(-c3ccc4c(ccc5c6ccccc6sc45)c3)nc(-c3cc4ccccc4c4ccccc34)n2)cc1 ; c1ccc(-c2nc(-c3ccc4ccc5c6ccccc6sc5c4c3)nc(-c3cc4ccccc4c4ccccc34)n2)cc1 ; c1ccc(-c2nc(-c3cccc4ccc5ccccc5c34)nc(-c3cccc4ccc5c6ccccc6sc5c34)n2)cc1 ; c1ccc(-c2nc(-c3ccccc3)nc(-c3cccc4c3ccc3c5ccccc5oc43)n2)cc1]

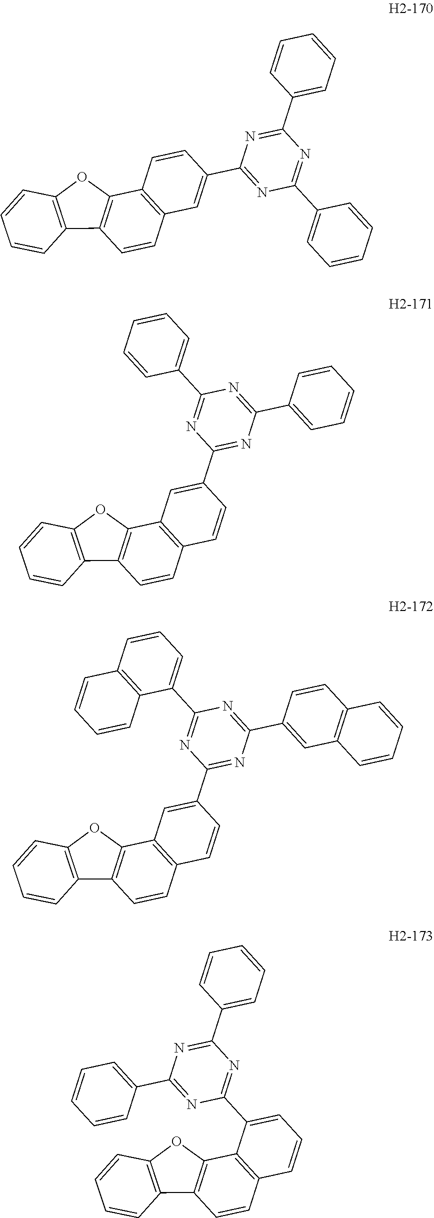 [SMILES: c1ccc(-c2nc(-c3ccccc3)nc(-c3ccc4c(ccc5c6ccccc6oc45)c3)n2)cc1 ; c1ccc(-c2nc(-c3ccccc3)nc(-c3ccc4ccc5c6ccccc6oc5c4c3)n2)cc1 ; c1ccc2cc(-c3nc(-c4ccc5ccc6c7ccccc7oc6c5c4)nc(-c4cccc5ccccc45)n3)ccc2c1 ; c1ccc(-c2nc(-c3ccccc3)nc(-c3cccc4ccc5c6ccccc6oc5c34)n2)cc1]

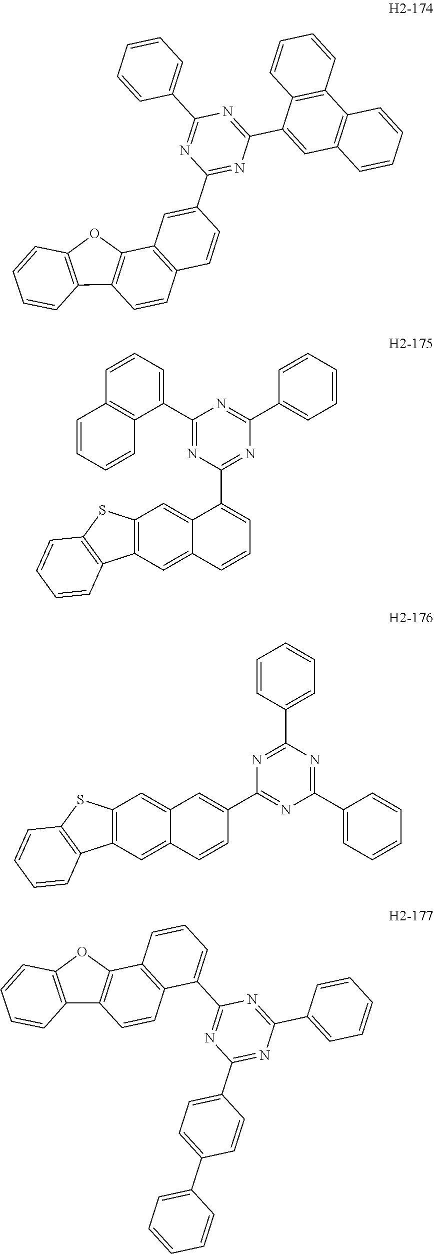

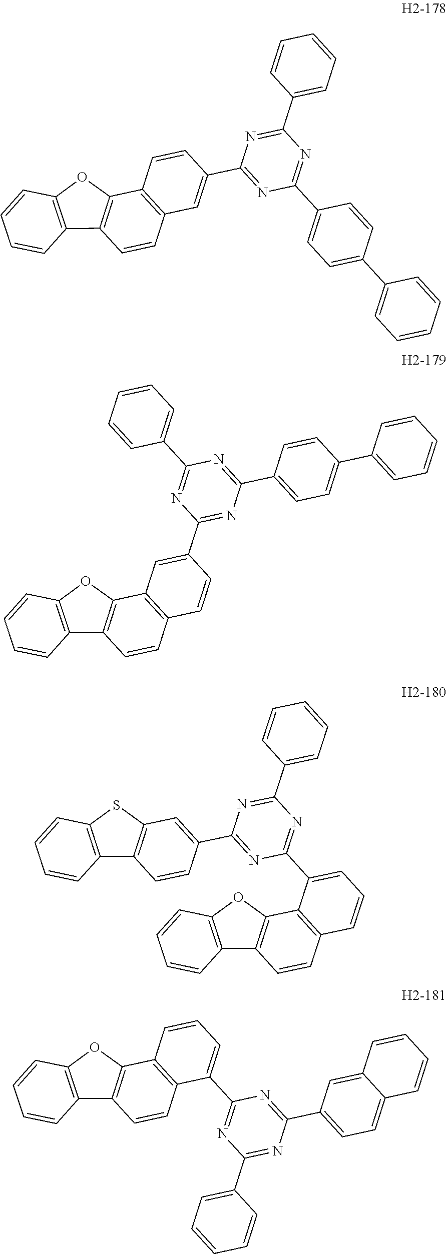 [SMILES: c1ccc(-c2ccc(-c3nc(-c4ccccc4)nc(-c4ccc5c(ccc6c7ccccc7oc56)c4)n3)cc2)cc1 ; c1ccc(-c2ccc(-c3nc(-c4ccccc4)nc(-c4ccc5ccc6c7ccccc7oc6c5c4)n3)cc2)cc1 ; c1ccc(-c2nc(-c3ccc4c(c3)sc3ccccc34)nc(-c3cccc4ccc5c6ccccc6oc5c34)n2)cc1 ; c1ccc(-c2nc(-c3ccc4ccccc4c3)nc(-c3cccc4c3ccc3c5ccccc5oc43)n2)cc1]

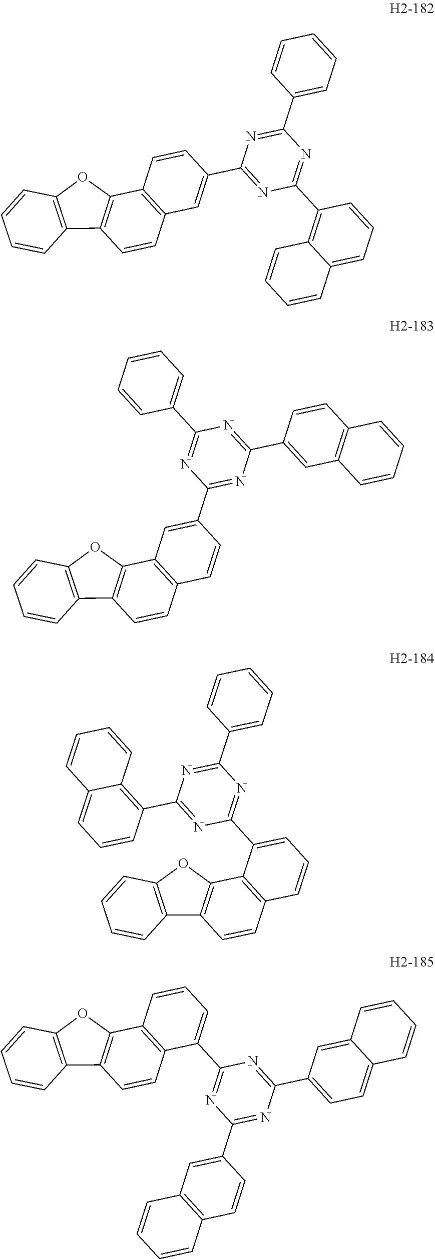 [SMILES: c1ccc(-c2nc(-c3ccc4c(ccc5c6ccccc6oc45)c3)nc(-c3cccc4ccccc34)n2)cc1 ; c1ccc(-c2nc(-c3ccc4ccccc4c3)nc(-c3ccc4ccc5c6ccccc6oc5c4c3)n2)cc1 ; c1ccc(-c2nc(-c3cccc4ccccc34)nc(-c3cccc4ccc5c6ccccc6oc5c34)n2)cc1 ; c1ccc2cc(-c3nc(-c4ccc5ccccc5c4)nc(-c4cccc5c4ccc4c6ccccc6oc54)n3)ccc2c1]

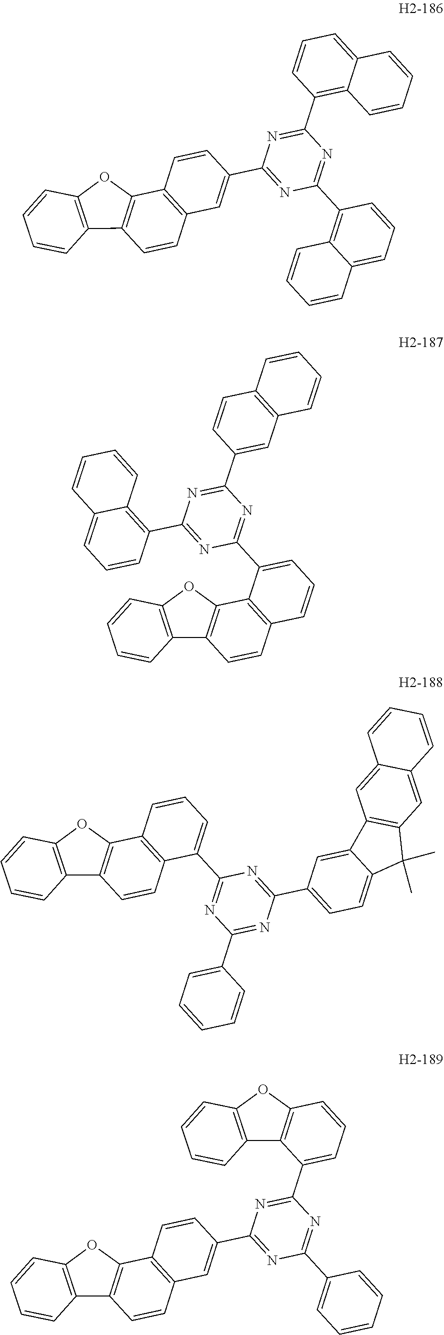 [SMILES: c1ccc2c(-c3nc(-c4ccc5c(ccc6c7ccccc7oc56)c4)nc(-c4cccc5ccccc45)n3)cccc2c1 ; c1ccc2cc(-c3nc(-c4cccc5ccccc45)nc(-c4cccc5ccc6c7ccccc7oc6c45)n3)ccc2c1 ; CC1(C)c2ccc(-c3nc(-c4ccccc4)nc(-c4cccc5c4ccc4c6ccccc6oc54)n3)cc2-c2cc3ccccc3cc21 ; c1ccc(-c2nc(-c3ccc4c(ccc5c6ccccc6oc45)c3)nc(-c3cccc4oc5ccccc5c34)n2)cc1]

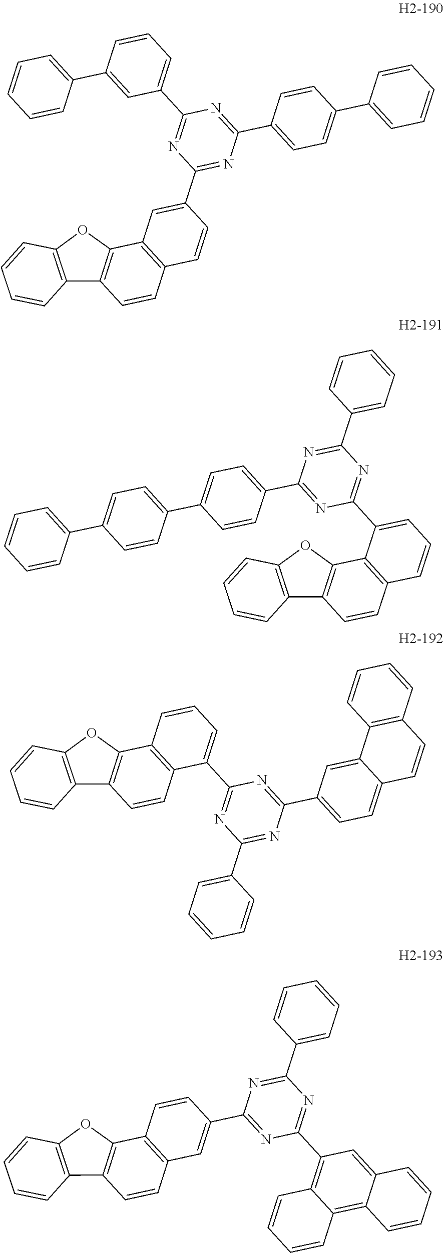 [SMILES: c1ccc(-c2ccc(-c3nc(-c4cccc(-c5ccccc5)c4)nc(-c4ccc5ccc6c7ccccc7oc6c5c4)n3)cc2)cc1 ; c1ccc(-c2ccc(-c3ccc(-c4nc(-c5ccccc5)nc(-c5cccc6ccc7c8ccccc8oc7c56)n4)cc3)cc2)cc1 ; c1ccc(-c2nc(-c3ccc4ccc5ccccc5c4c3)nc(-c3cccc4c3ccc3c5ccccc5oc43)n2)cc1 ; c1ccc(-c2nc(-c3ccc4c(ccc5c6ccccc6oc45)c3)nc(-c3cc4ccccc4c4ccccc34)n2)cc1]

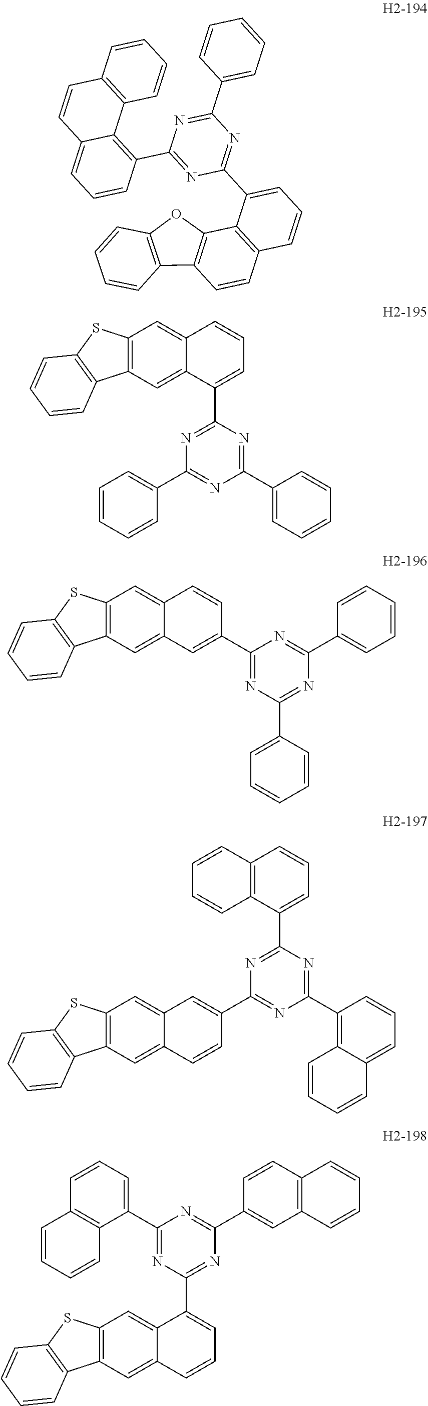

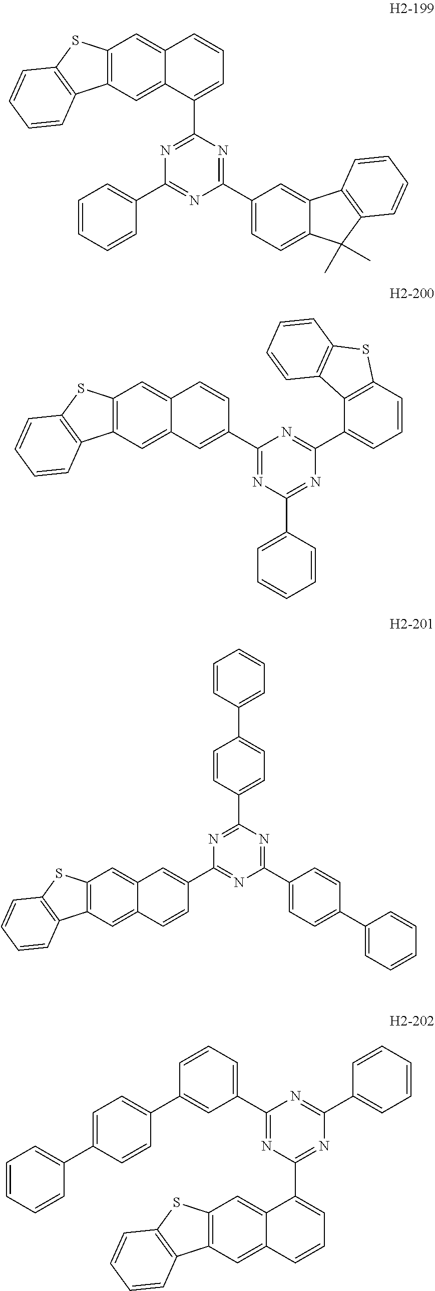 [SMILES: CC1(C)c2ccccc2-c2cc(-c3nc(-c4ccccc4)nc(-c4cccc5cc6sc7ccccc7c6cc45)n3)ccc21 ; c1ccc(-c2nc(-c3ccc4cc5sc6ccccc6c5cc4c3)nc(-c3cccc4sc5ccccc5c34)n2)cc1 ; c1ccc(-c2ccc(-c3nc(-c4ccc(-c5ccccc5)cc4)nc(-c4ccc5cc6c(cc5c4)sc4ccccc46)n3)cc2)cc1 ; c1ccc(-c2ccc(-c3cccc(-c4nc(-c5ccccc5)nc(-c5cccc6cc7c(cc56)sc5ccccc57)n4)c3)cc2)cc1]

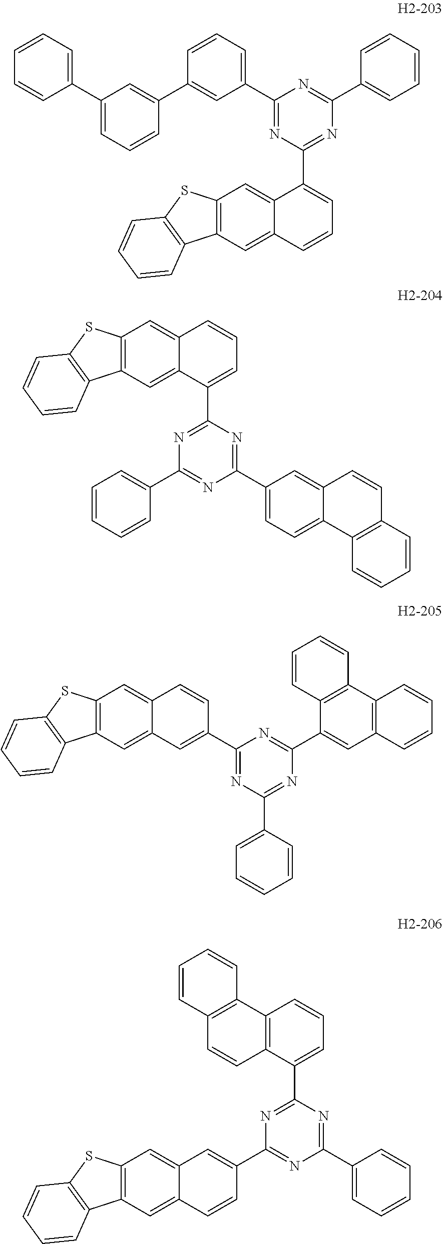

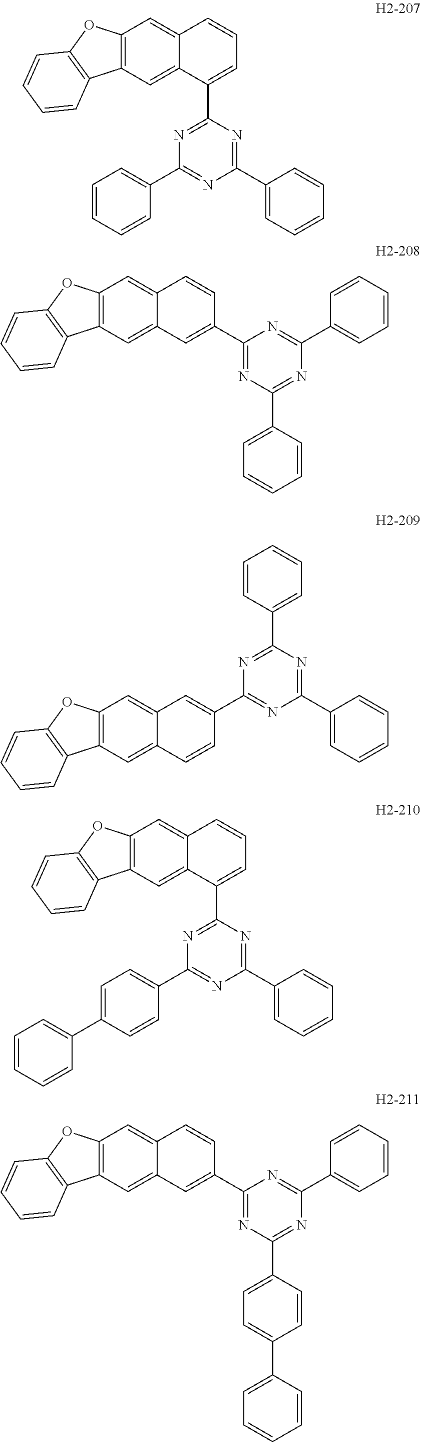

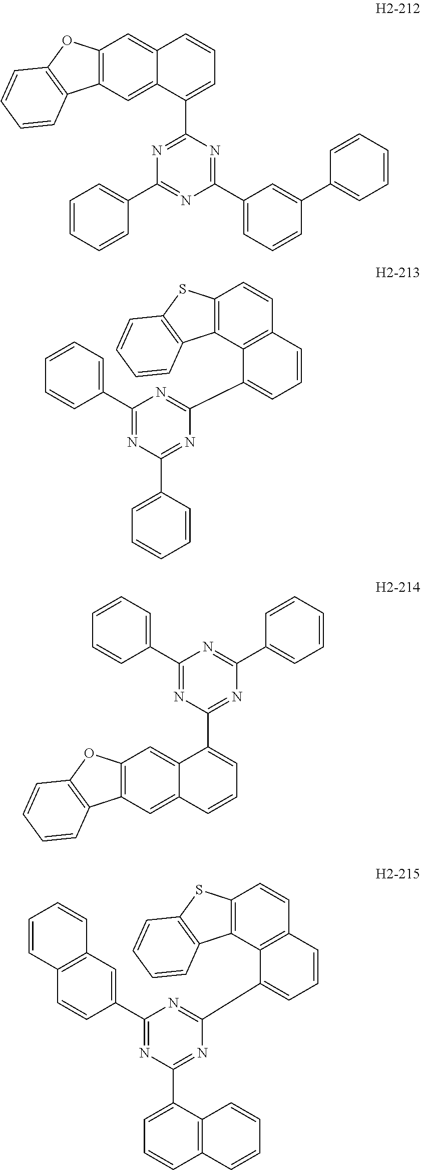

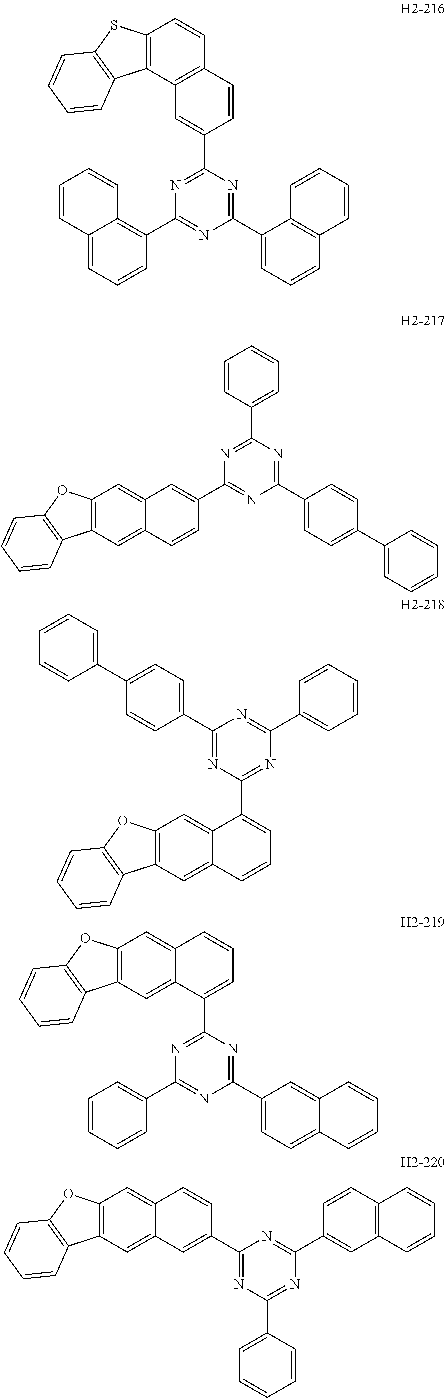

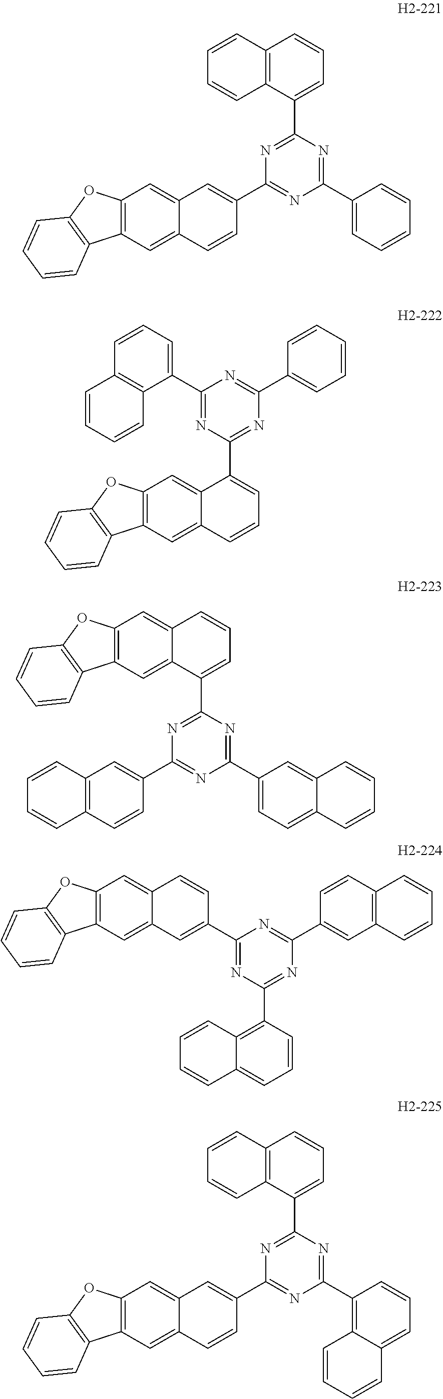 [SMILES: c1ccc(-c2nc(-c3ccc4cc5c(cc4c3)oc3ccccc35)nc(-c3cccc4ccccc34)n2)cc1 ; c1ccc(-c2nc(-c3cccc4ccccc34)nc(-c3cccc4cc5c(cc34)oc3ccccc35)n2)cc1 ; c1ccc2cc(-c3nc(-c4ccc5ccccc5c4)nc(-c4cccc5cc6oc7ccccc7c6cc45)n3)ccc2c1 ; c1ccc2cc(-c3nc(-c4ccc5cc6oc7ccccc7c6cc5c4)nc(-c4cccc5ccccc45)n3)ccc2c1 ; c1ccc2c(-c3nc(-c4ccc5cc6c(cc5c4)oc4ccccc46)nc(-c4cccc5ccccc45)n3)cccc2c1]

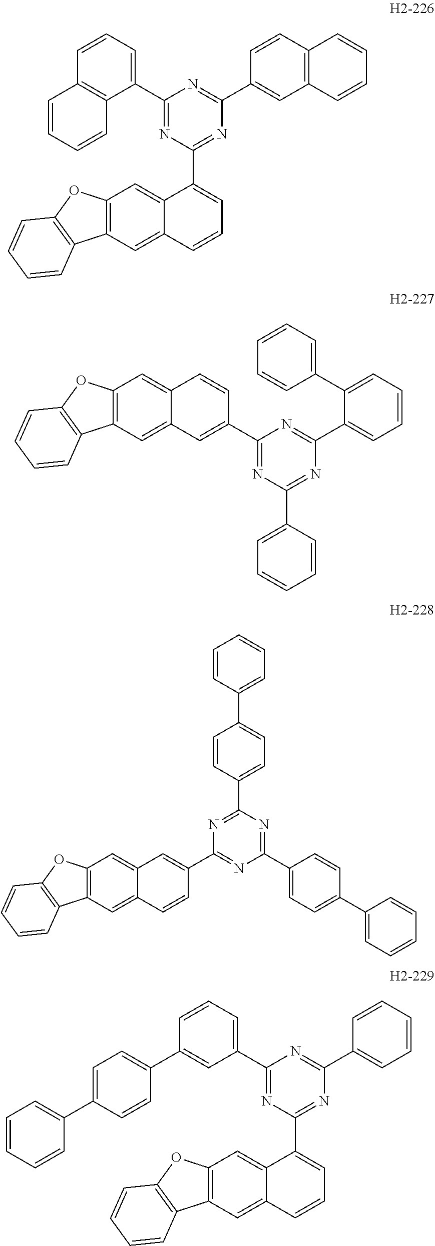

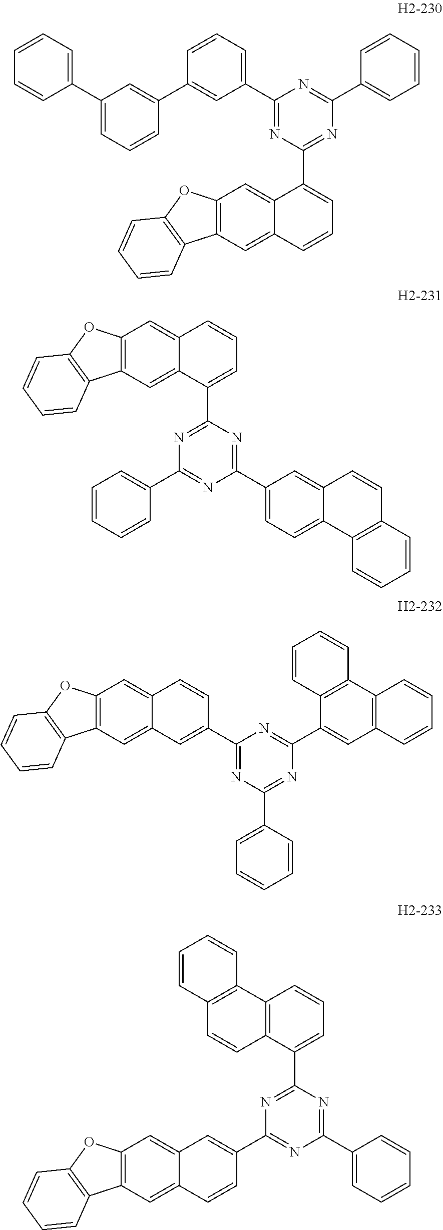

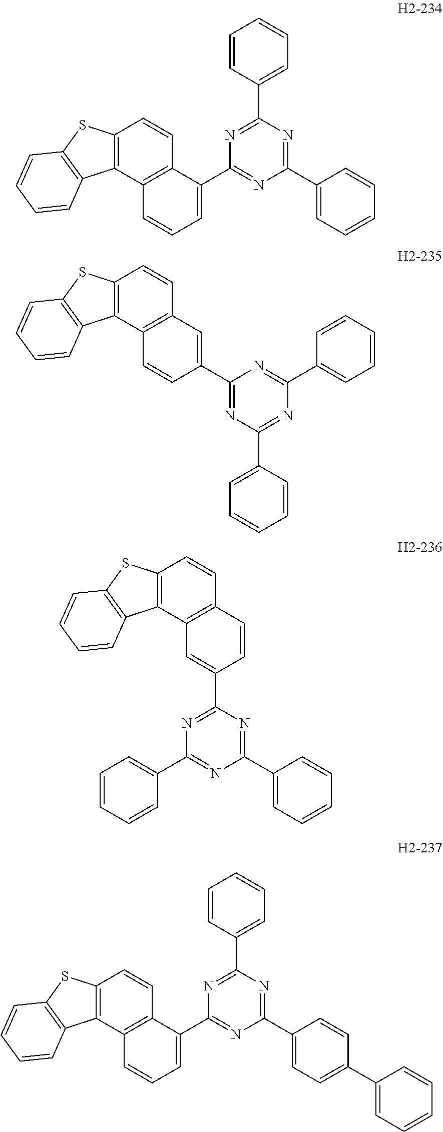

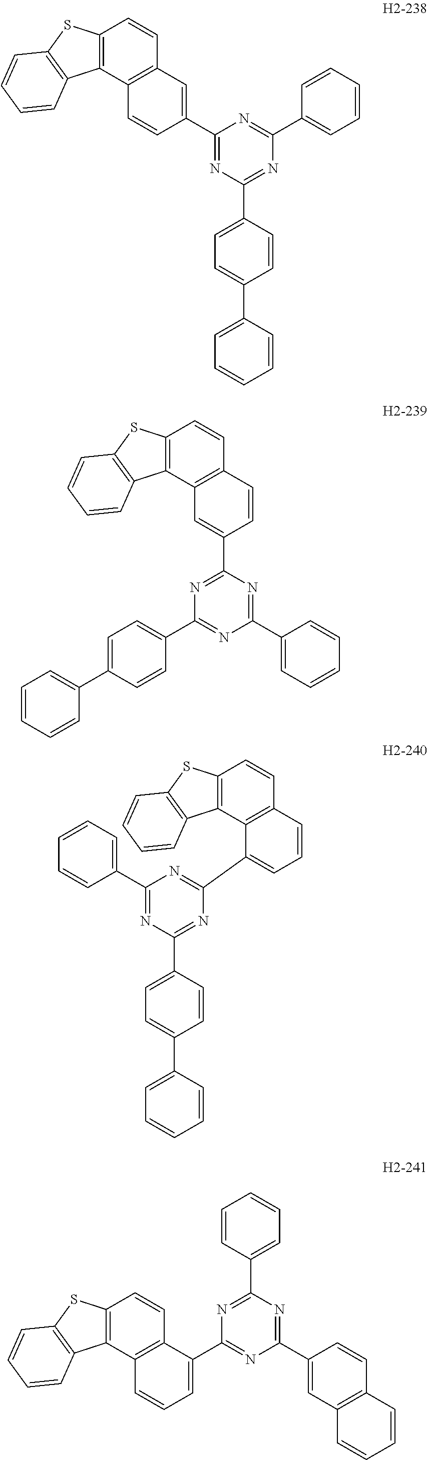 [SMILES: c1ccc(-c2ccc(-c3nc(-c4ccccc4)nc(-c4ccc5c(ccc6sc7ccccc7c65)c4)n3)cc2)cc1 ; c1ccc(-c2ccc(-c3nc(-c4ccccc4)nc(-c4ccc5ccc6sc7ccccc7c6c5c4)n3)cc2)cc1 ; c1ccc(-c2ccc(-c3nc(-c4ccccc4)nc(-c4cccc5ccc6sc7ccccc7c6c45)n3)cc2)cc1 ; c1ccc(-c2nc(-c3ccc4ccccc4c3)nc(-c3cccc4c3ccc3sc5ccccc5c34)n2)cc1]

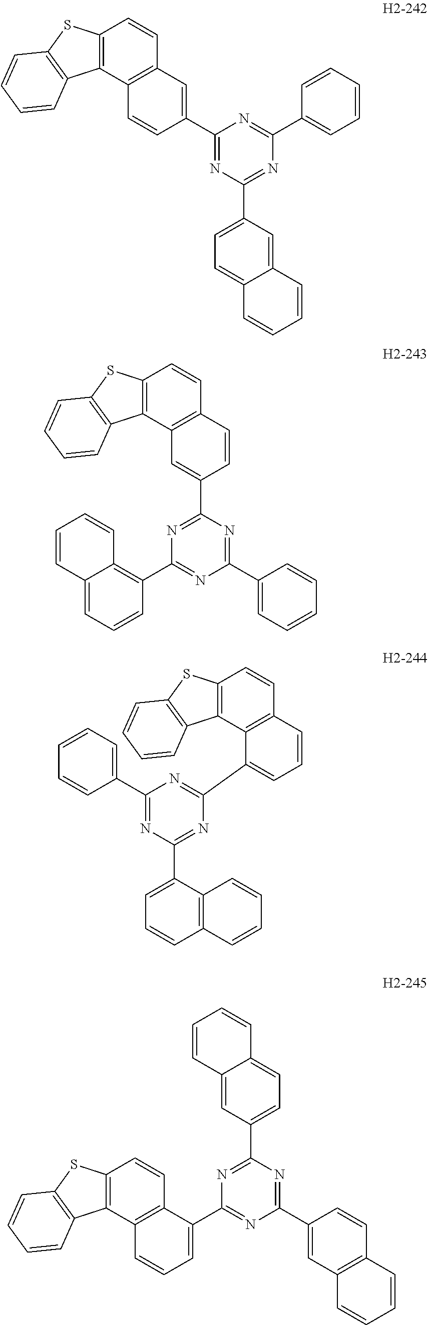 [SMILES: c1ccc(-c2nc(-c3ccc4ccccc4c3)nc(-c3ccc4c(ccc5sc6ccccc6c54)c3)n2)cc1 ; c1ccc(-c2nc(-c3ccc4ccc5sc6ccccc6c5c4c3)nc(-c3cccc4ccccc34)n2)cc1 ; c1ccc(-c2nc(-c3cccc4ccccc34)nc(-c3cccc4ccc5sc6ccccc6c5c34)n2)cc1 ; c1ccc2cc(-c3nc(-c4ccc5ccccc5c4)nc(-c4cccc5c4ccc4sc6ccccc6c45)n3)ccc2c1]

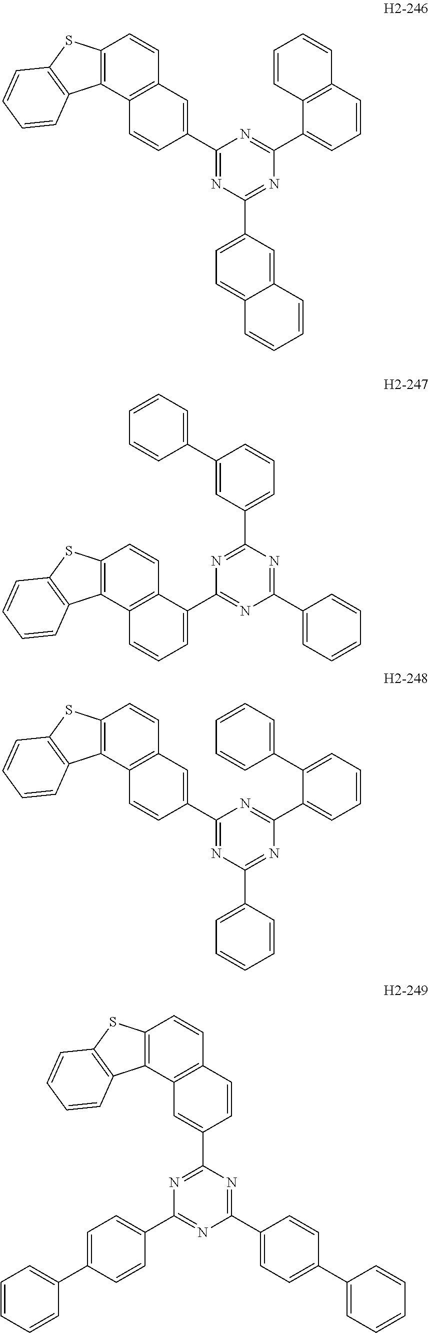 [SMILES: c1ccc2cc(-c3nc(-c4ccc5c(ccc6sc7ccccc7c65)c4)nc(-c4cccc5ccccc45)n3)ccc2c1 ; c1ccc(-c2cccc(-c3nc(-c4ccccc4)nc(-c4cccc5c4ccc4sc6ccccc6c45)n3)c2)cc1 ; c1ccc(-c2nc(-c3ccc4c(ccc5sc6ccccc6c54)c3)nc(-c3ccccc3-c3ccccc3)n2)cc1 ; c1ccc(-c2ccc(-c3nc(-c4ccc(-c5ccccc5)cc4)nc(-c4ccc5ccc6sc7ccccc7c6c5c4)n3)cc2)cc1]

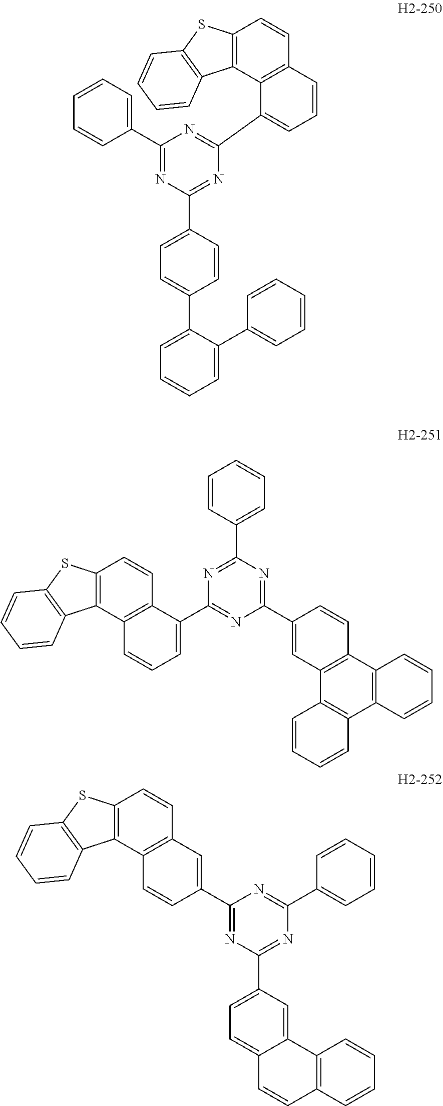 [SMILES: c1ccc(-c2nc(-c3ccc(-c4ccccc4-c4ccccc4)cc3)nc(-c3cccc4ccc5sc6ccccc6c5c34)n2)cc1 ; c1ccc(-c2nc(-c3ccc4c5ccccc5c5ccccc5c4c3)nc(-c3cccc4c3ccc3sc5ccccc5c34)n2)cc1 ; c1ccc(-c2nc(-c3ccc4c(ccc5sc6ccccc6c54)c3)nc(-c3ccc4ccc5ccccc5c4c3)n2)cc1]

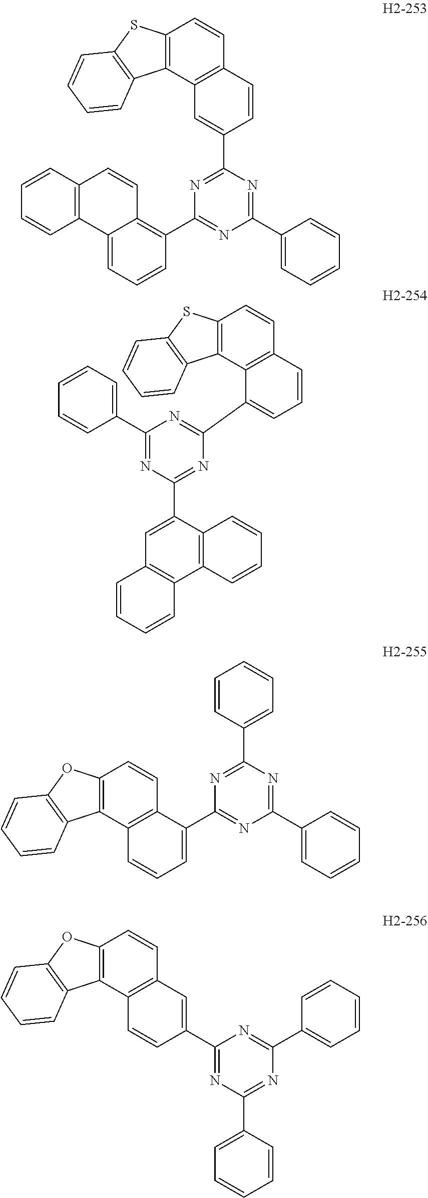 [SMILES: c1ccc(-c2nc(-c3ccc4ccc5sc6ccccc6c5c4c3)nc(-c3cccc4c3ccc3ccccc34)n2)cc1 ; c1ccc(-c2nc(-c3cc4ccccc4c4ccccc34)nc(-c3cccc4ccc5sc6ccccc6c5c34)n2)cc1 ; c1ccc(-c2nc(-c3ccccc3)nc(-c3cccc4c3ccc3oc5ccccc5c34)n2)cc1 ; c1ccc(-c2nc(-c3ccccc3)nc(-c3ccc4c(ccc5oc6ccccc6c54)c3)n2)cc1]

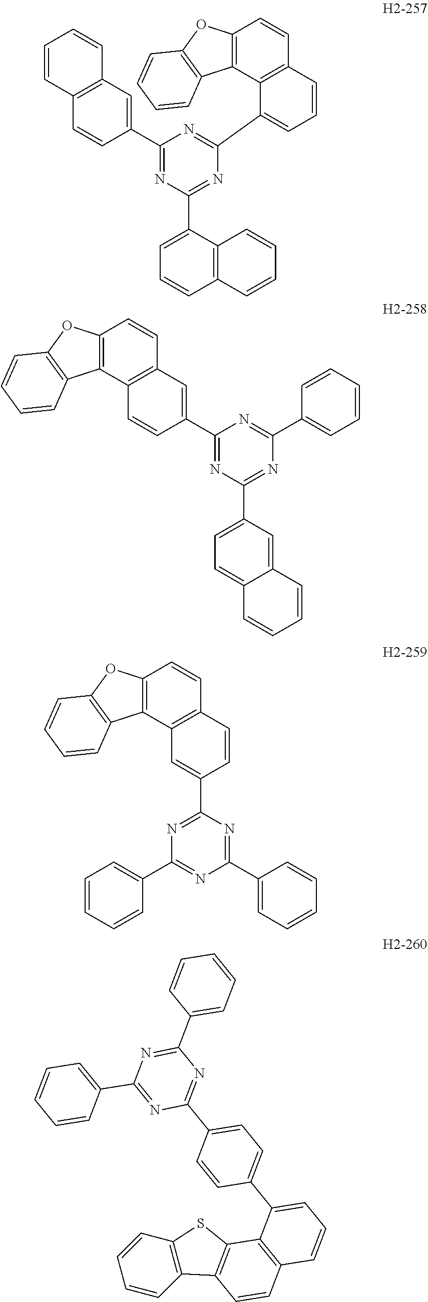 [SMILES: c1ccc2cc(-c3nc(-c4cccc5ccccc45)nc(-c4cccc5ccc6oc7ccccc7c6c45)n3)ccc2c1 ; c1ccc(-c2nc(-c3ccc4ccccc4c3)nc(-c3ccc4c(ccc5oc6ccccc6c54)c3)n2)cc1 ; c1ccc(-c2nc(-c3ccccc3)nc(-c3ccc4ccc5oc6ccccc6c5c4c3)n2)cc1 ; c1ccc(-c2nc(-c3ccccc3)nc(-c3ccc(-c4cccc5ccc6c7ccccc7sc6c45)cc3)n2)cc1]

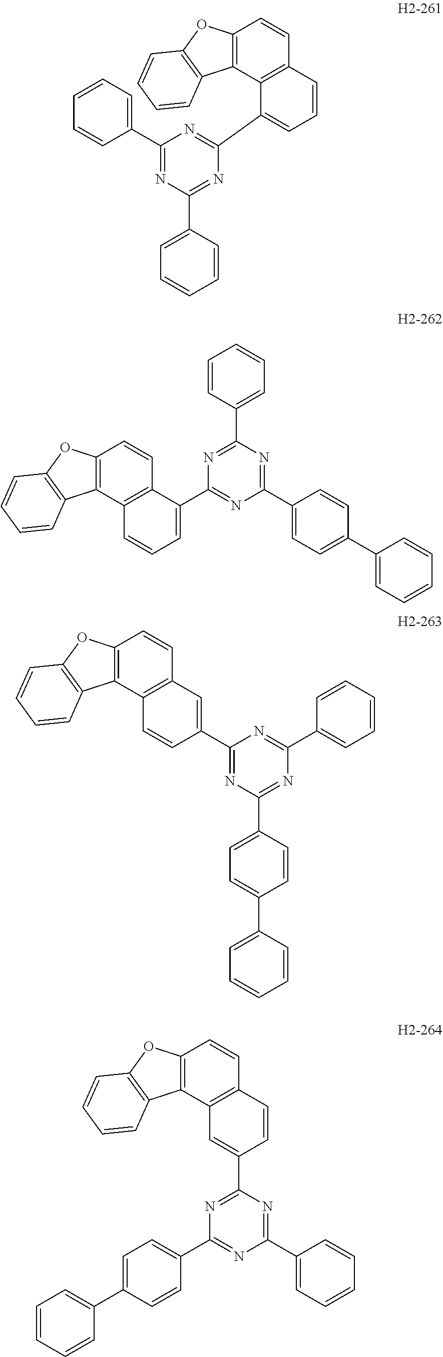 [SMILES: c1ccc(-c2nc(-c3ccccc3)nc(-c3cccc4ccc5oc6ccccc6c5c34)n2)cc1 ; c1ccc(-c2ccc(-c3nc(-c4ccccc4)nc(-c4cccc5c4ccc4oc6ccccc6c45)n3)cc2)cc1 ; c1ccc(-c2ccc(-c3nc(-c4ccccc4)nc(-c4ccc5c(ccc6oc7ccccc7c65)c4)n3)cc2)cc1 ; c1ccc(-c2ccc(-c3nc(-c4ccccc4)nc(-c4ccc5ccc6oc7ccccc7c6c5c4)n3)cc2)cc1]

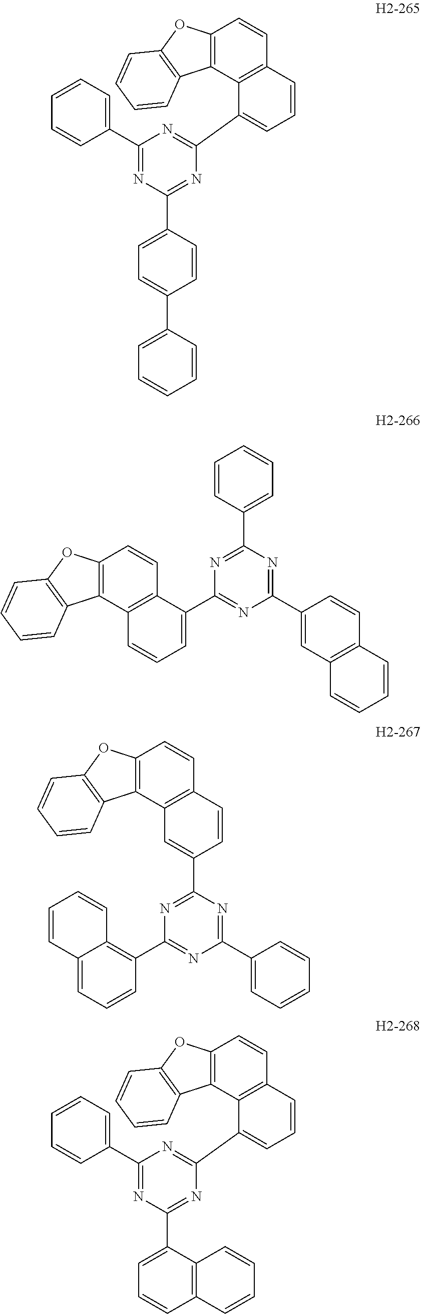

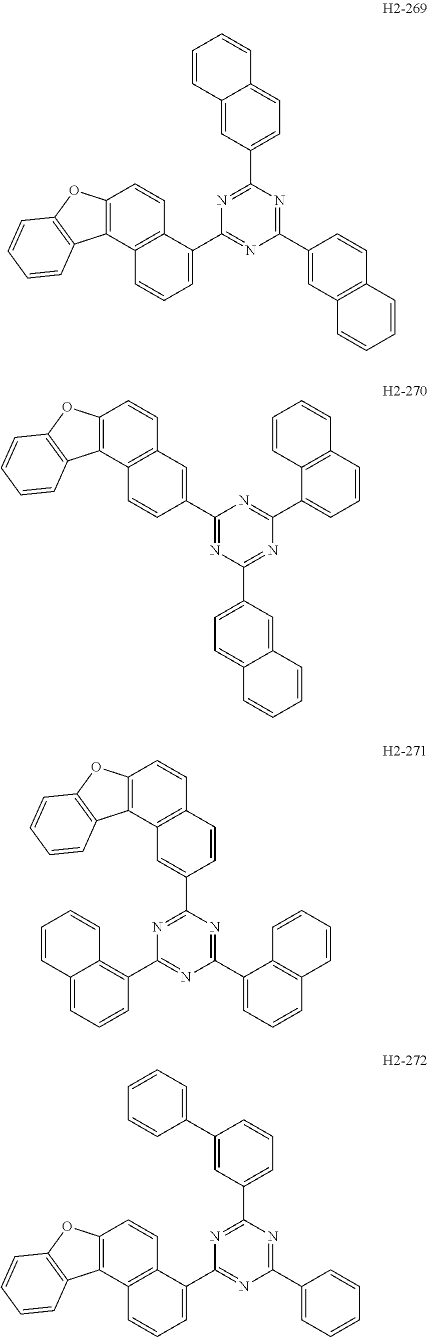 [SMILES: c1ccc2cc(-c3nc(-c4ccc5ccccc5c4)nc(-c4cccc5c4ccc4oc6ccccc6c45)n3)ccc2c1 ; c1ccc2cc(-c3nc(-c4ccc5c(ccc6oc7ccccc7c65)c4)nc(-c4cccc5ccccc45)n3)ccc2c1 ; c1ccc2c(-c3nc(-c4ccc5ccc6oc7ccccc7c6c5c4)nc(-c4cccc5ccccc45)n3)cccc2c1 ; c1ccc(-c2cccc(-c3nc(-c4ccccc4)nc(-c4cccc5c4ccc4oc6ccccc6c45)n3)c2)cc1]

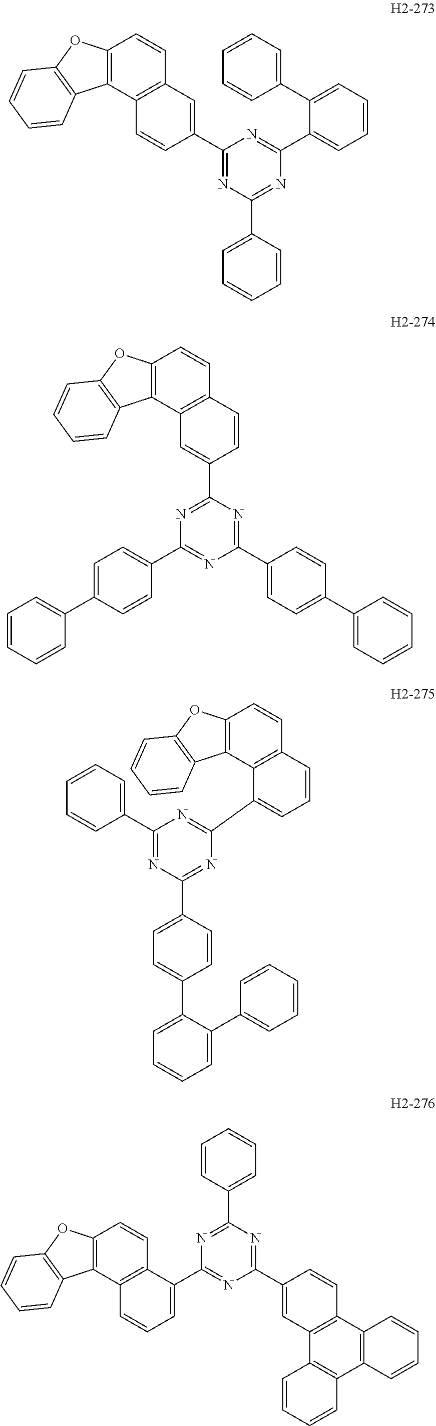 [SMILES: c1ccc(-c2nc(-c3ccc4c(ccc5oc6ccccc6c54)c3)nc(-c3ccccc3-c3ccccc3)n2)cc1 ; c1ccc(-c2ccc(-c3nc(-c4ccc(-c5ccccc5)cc4)nc(-c4ccc5ccc6oc7ccccc7c6c5c4)n3)cc2)cc1 ; c1ccc(-c2nc(-c3ccc(-c4ccccc4-c4ccccc4)cc3)nc(-c3cccc4ccc5oc6ccccc6c5c34)n2)cc1 ; c1ccc(-c2nc(-c3ccc4c5ccccc5c5ccccc5c4c3)nc(-c3cccc4c3ccc3oc5ccccc5c34)n2)cc1]

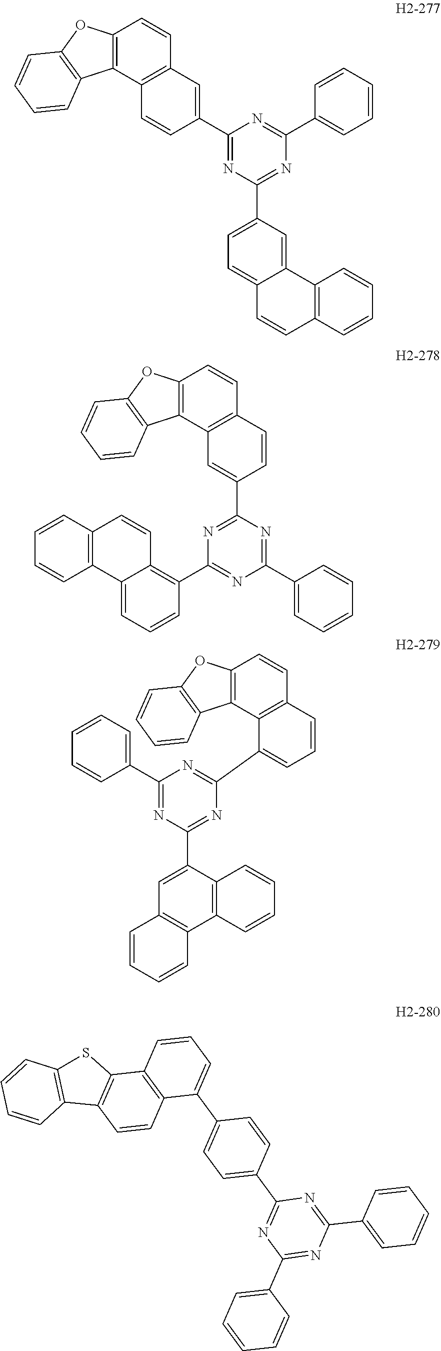 [SMILES: c1ccc(-c2nc(-c3ccc4c(ccc5oc6ccccc6c54)c3)nc(-c3ccc4ccc5ccccc5c4c3)n2)cc1 ; c1ccc(-c2nc(-c3ccc4ccc5oc6ccccc6c5c4c3)nc(-c3cccc4c3ccc3ccccc34)n2)cc1 ; c1ccc(-c2nc(-c3cc4ccccc4c4ccccc34)nc(-c3cccc4ccc5oc6ccccc6c5c34)n2)cc1 ; c1ccc(-c2nc(-c3ccccc3)nc(-c3ccc(-c4cccc5c4ccc4c6ccccc6sc54)cc3)n2)cc1]

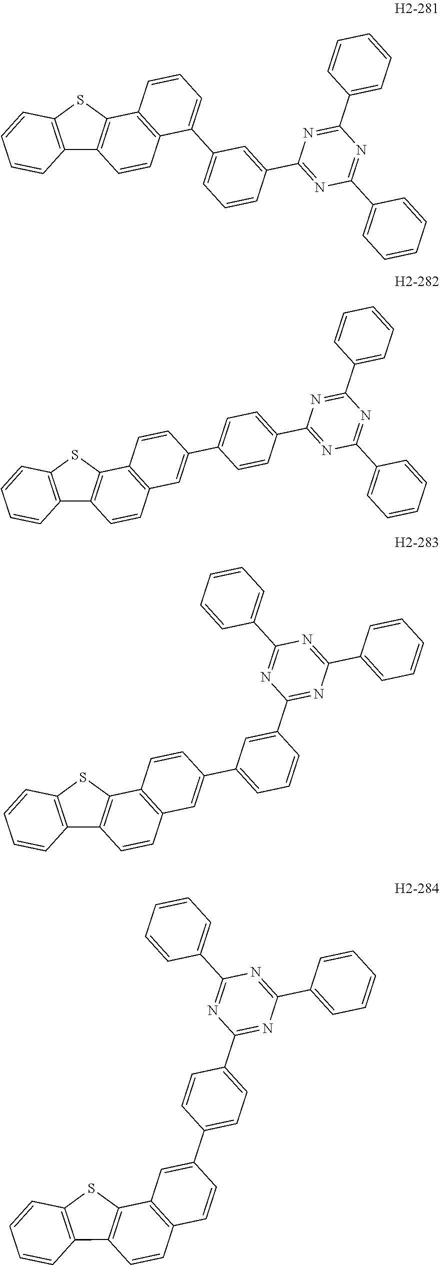 [SMILES: c1ccc(-c2nc(-c3ccccc3)nc(-c3cccc(-c4cccc5c4ccc4c6ccccc6sc54)c3)n2)cc1 ; c1ccc(-c2nc(-c3ccccc3)nc(-c3ccc(-c4ccc5c(ccc6c7ccccc7sc56)c4)cc3)n2)cc1 ; c1ccc(-c2nc(-c3ccccc3)nc(-c3cccc(-c4ccc5c(ccc6c7ccccc7sc56)c4)c3)n2)cc1 ; c1ccc(-c2nc(-c3ccccc3)nc(-c3ccc(-c4ccc5ccc6c7ccccc7sc6c5c4)cc3)n2)cc1]

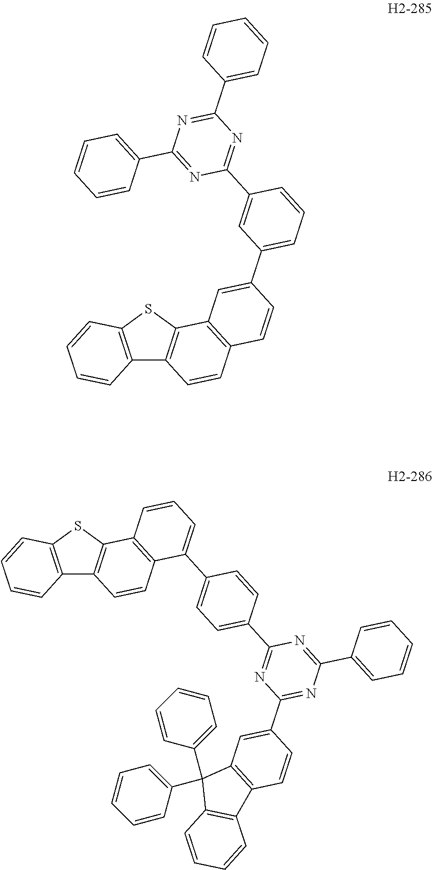 [SMILES: c1ccc(-c2nc(-c3ccccc3)nc(-c3cccc(-c4ccc5ccc6c7ccccc7sc6c5c4)c3)n2)cc1 ; c1ccc(-c2nc(-c3ccc(-c4cccc5c4ccc4c6ccccc6sc54)cc3)nc(-c3ccc4c(c3)C(c3ccccc3)(c3ccccc3)c3ccccc3-4)n2)cc1]

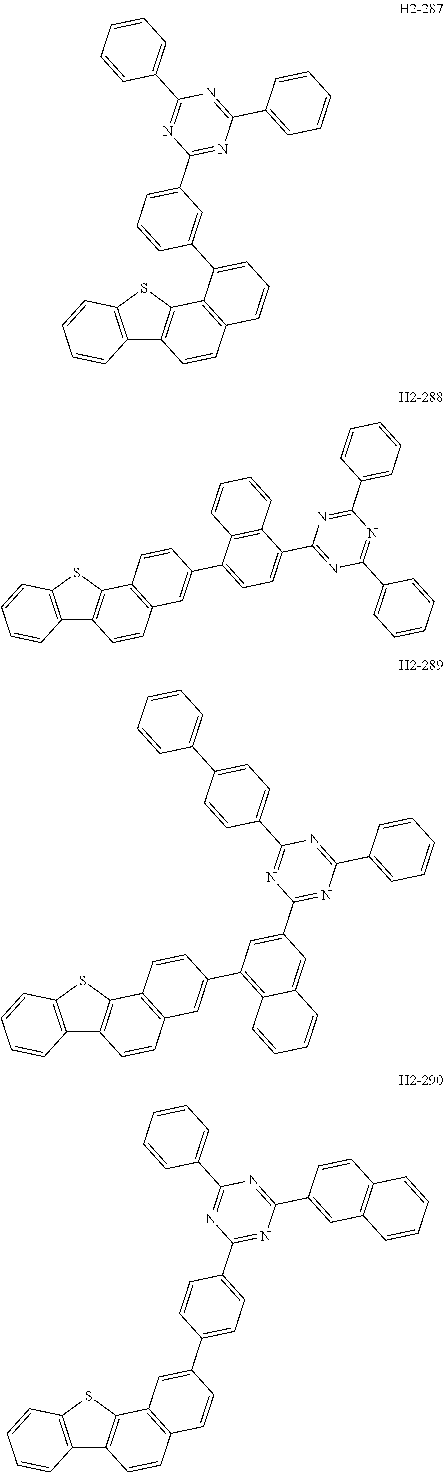 [SMILES: c1ccc(-c2nc(-c3ccccc3)nc(-c3cccc(-c4cccc5ccc6c7ccccc7sc6c45)c3)n2)cc1 ; c1ccc(-c2nc(-c3ccccc3)nc(-c3ccc(-c4ccc5c(ccc6c7ccccc7sc56)c4)c4ccccc34)n2)cc1 ; c1ccc(-c2ccc(-c3nc(-c4ccccc4)nc(-c4cc(-c5ccc6c(ccc7c8ccccc8sc67)c5)c5ccccc5c4)n3)cc2)cc1 ; c1ccc(-c2nc(-c3ccc(-c4ccc5ccc6c7ccccc7sc6c5c4)cc3)nc(-c3ccc4ccccc4c3)n2)cc1]

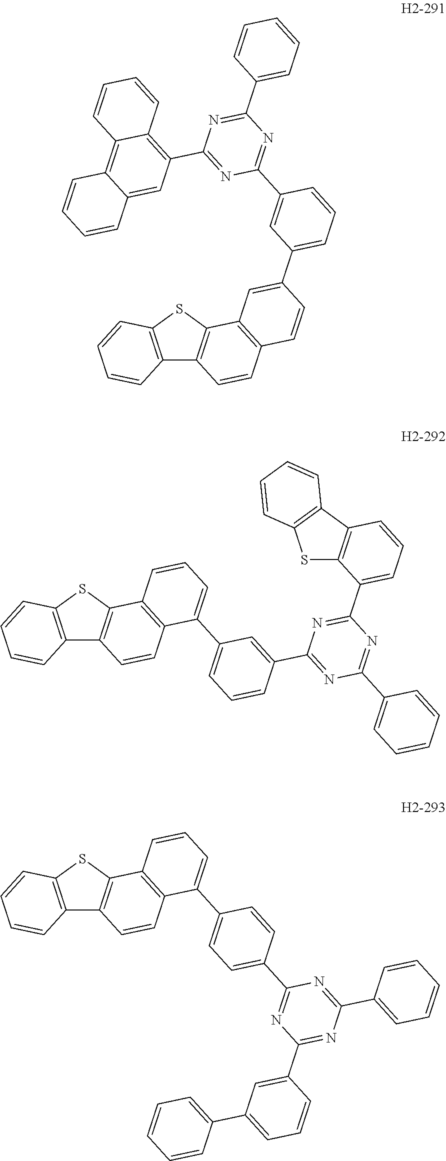 [SMILES: c1ccc(-c2nc(-c3cccc(-c4ccc5ccc6c7ccccc7sc6c5c4)c3)nc(-c3cc4ccccc4c4ccccc34)n2)cc1 ; c1ccc(-c2nc(-c3cccc(-c4cccc5c4ccc4c6ccccc6sc54)c3)nc(-c3cccc4c3sc3ccccc34)n2)cc1 ; c1ccc(-c2cccc(-c3nc(-c4ccccc4)nc(-c4ccc(-c5cccc6c5ccc5c7ccccc7sc65)cc4)n3)c2)cc1]

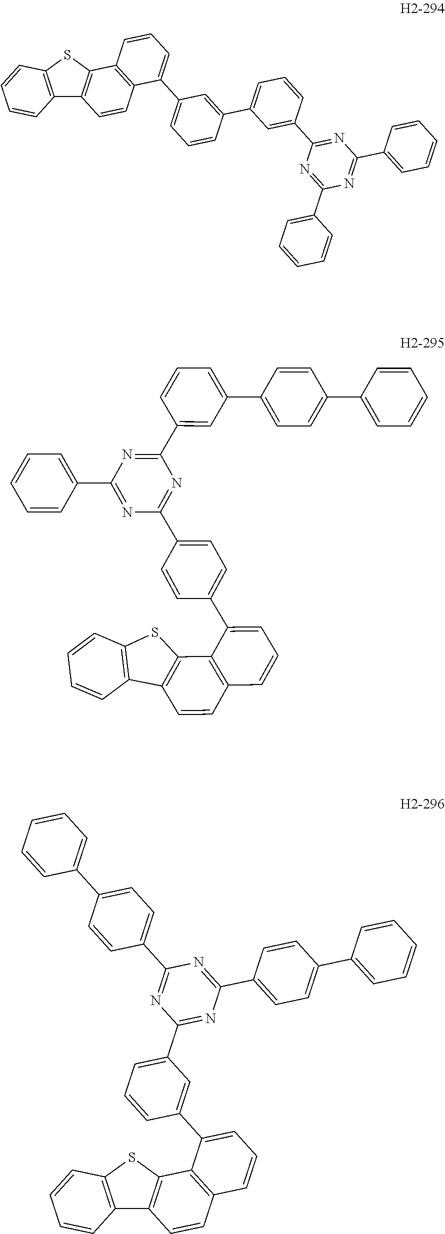 [SMILES: c1ccc(-c2nc(-c3ccccc3)nc(-c3cccc(-c4cccc(-c5cccc6c5ccc5c7ccccc7sc65)c4)c3)n2)cc1 ; c1ccc(-c2ccc(-c3cccc(-c4nc(-c5ccccc5)nc(-c5ccc(-c6cccc7ccc8c9ccccc9sc8c67)cc5)n4)c3)cc2)cc1 ; c1ccc(-c2ccc(-c3nc(-c4ccc(-c5ccccc5)cc4)nc(-c4cccc(-c5cccc6ccc7c8ccccc8sc7c56)c4)n3)cc2)cc1]

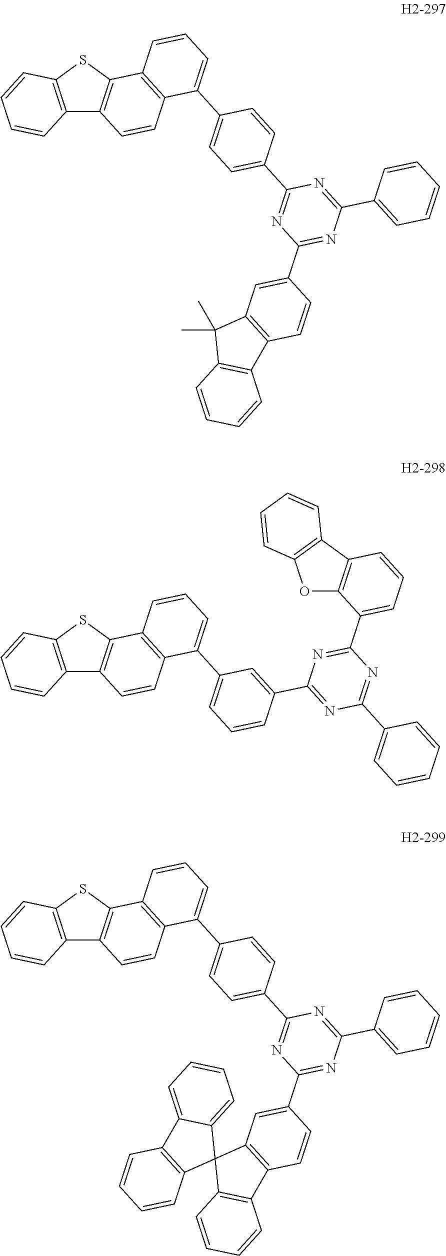 [SMILES: CC1(C)c2ccccc2-c2ccc(-c3nc(-c4ccccc4)nc(-c4ccc(-c5cccc6c5ccc5c7ccccc7sc65)cc4)n3)cc21 ; c1ccc(-c2nc(-c3cccc(-c4cccc5c4ccc4c6ccccc6sc54)c3)nc(-c3cccc4c3oc3ccccc34)n2)cc1 ; c1ccc(-c2nc(-c3ccc(-c4cccc5c4ccc4c6ccccc6sc54)cc3)nc(-c3ccc4c(c3)C3(c5ccccc5-c5ccccc53)c3ccccc3-4)n2)cc1]

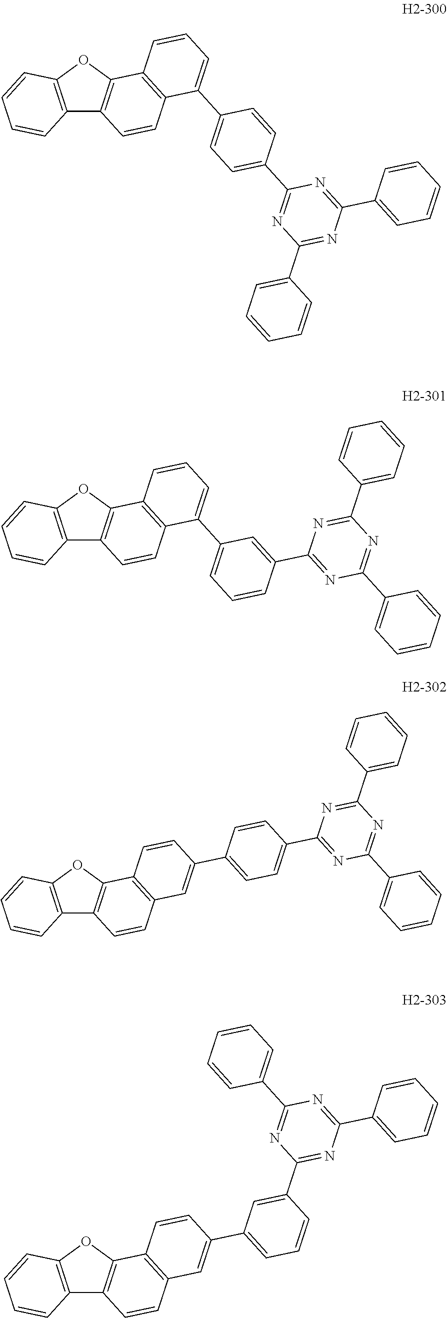 [SMILES: c1ccc(-c2nc(-c3ccccc3)nc(-c3ccc(-c4cccc5c4ccc4c6ccccc6oc54)cc3)n2)cc1 ; c1ccc(-c2nc(-c3ccccc3)nc(-c3cccc(-c4cccc5c4ccc4c6ccccc6oc54)c3)n2)cc1 ; c1ccc(-c2nc(-c3ccccc3)nc(-c3ccc(-c4ccc5c(ccc6c7ccccc7oc56)c4)cc3)n2)cc1 ; c1ccc(-c2nc(-c3ccccc3)nc(-c3cccc(-c4ccc5c(ccc6c7ccccc7oc56)c4)c3)n2)cc1]

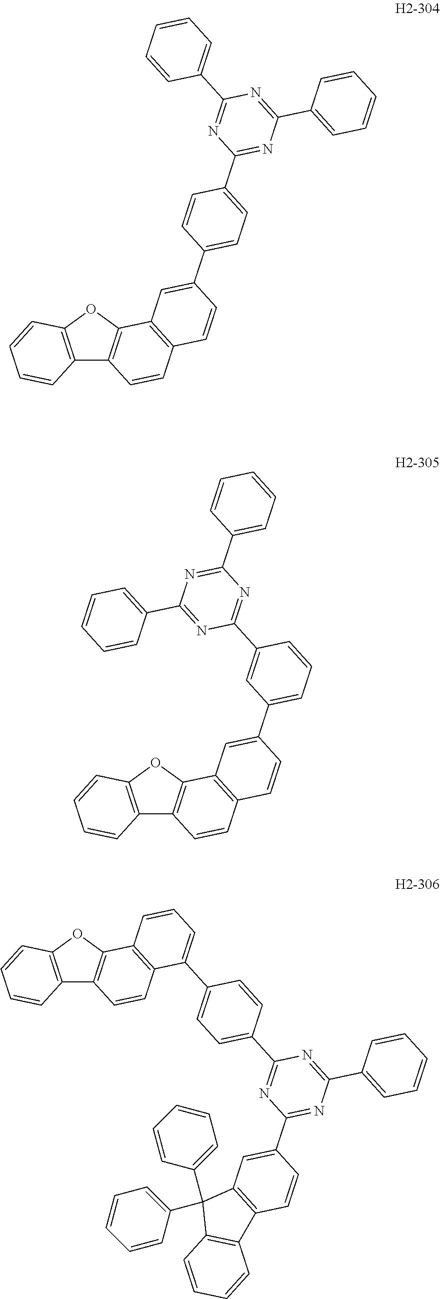 [SMILES: c1ccc(-c2nc(-c3ccccc3)nc(-c3ccc(-c4ccc5ccc6c7ccccc7oc6c5c4)cc3)n2)cc1 ; c1ccc(-c2nc(-c3ccccc3)nc(-c3cccc(-c4ccc5ccc6c7ccccc7oc6c5c4)c3)n2)cc1 ; c1ccc(-c2nc(-c3ccc(-c4cccc5c4ccc4c6ccccc6oc54)cc3)nc(-c3ccc4c(c3)C(c3ccccc3)(c3ccccc3)c3ccccc3-4)n2)cc1]

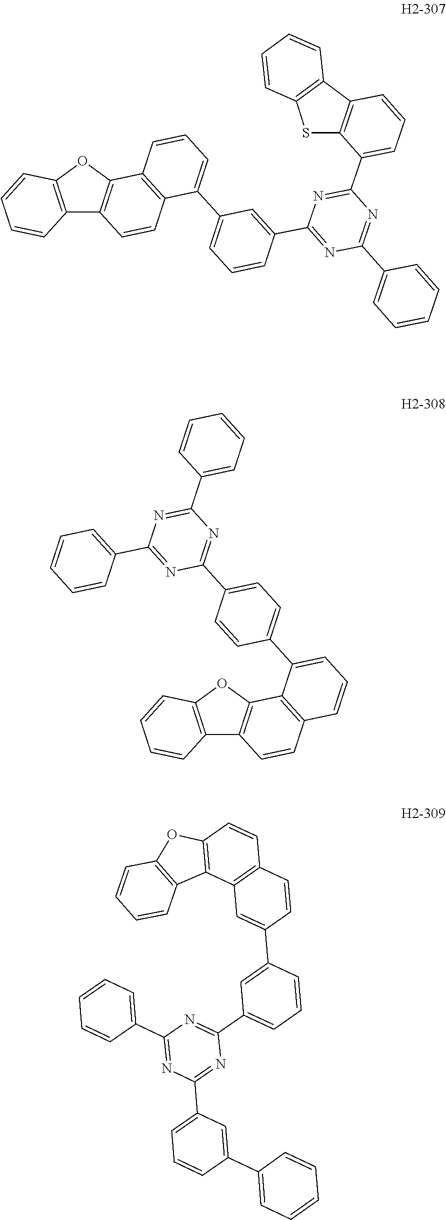 [SMILES: c1ccc(-c2nc(-c3cccc(-c4cccc5c4ccc4c6ccccc6oc54)c3)nc(-c3cccc4c3sc3ccccc34)n2)cc1 ; c1ccc(-c2nc(-c3ccccc3)nc(-c3ccc(-c4cccc5ccc6c7ccccc7oc6c45)cc3)n2)cc1 ; c1ccc(-c2cccc(-c3nc(-c4ccccc4)nc(-c4cccc(-c5ccc6ccc7oc8ccccc8c7c6c5)c4)n3)c2)cc1]

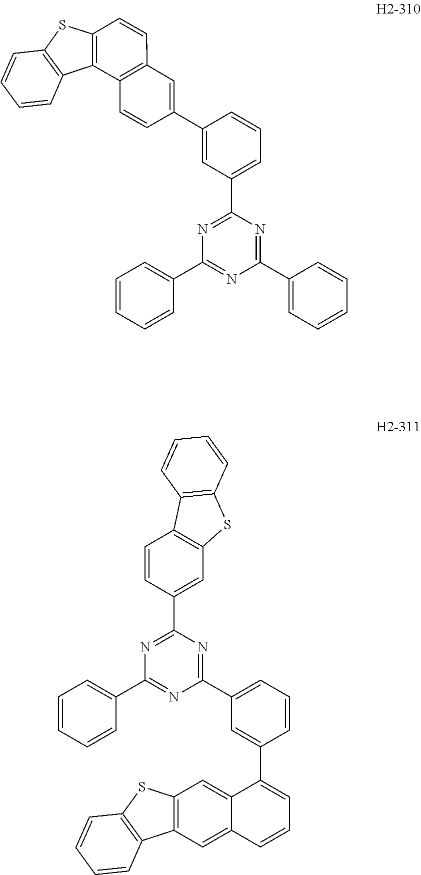 [SMILES: c1ccc(-c2nc(-c3ccccc3)nc(-c3cccc(-c4ccc5c(ccc6sc7ccccc7c65)c4)c3)n2)cc1 ; c1ccc(-c2nc(-c3cccc(-c4cccc5cc6c(cc45)sc4ccccc46)c3)nc(-c3ccc4c(c3)sc3ccccc34)n2)cc1]

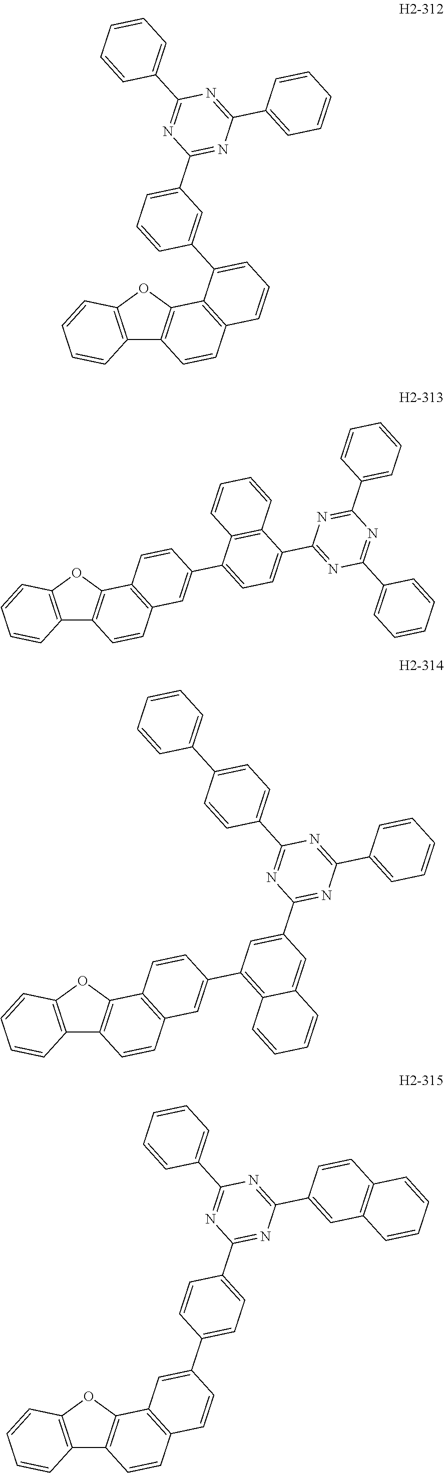 [SMILES: c1ccc(-c2nc(-c3ccccc3)nc(-c3cccc(-c4cccc5ccc6c7ccccc7oc6c45)c3)n2)cc1 ; c1ccc(-c2nc(-c3ccccc3)nc(-c3ccc(-c4ccc5c(ccc6c7ccccc7oc56)c4)c4ccccc34)n2)cc1 ; c1ccc(-c2ccc(-c3nc(-c4ccccc4)nc(-c4cc(-c5ccc6c(ccc7c8ccccc8oc67)c5)c5ccccc5c4)n3)cc2)cc1 ; c1ccc(-c2nc(-c3ccc(-c4ccc5ccc6c7ccccc7oc6c5c4)cc3)nc(-c3ccc4ccccc4c3)n2)cc1]

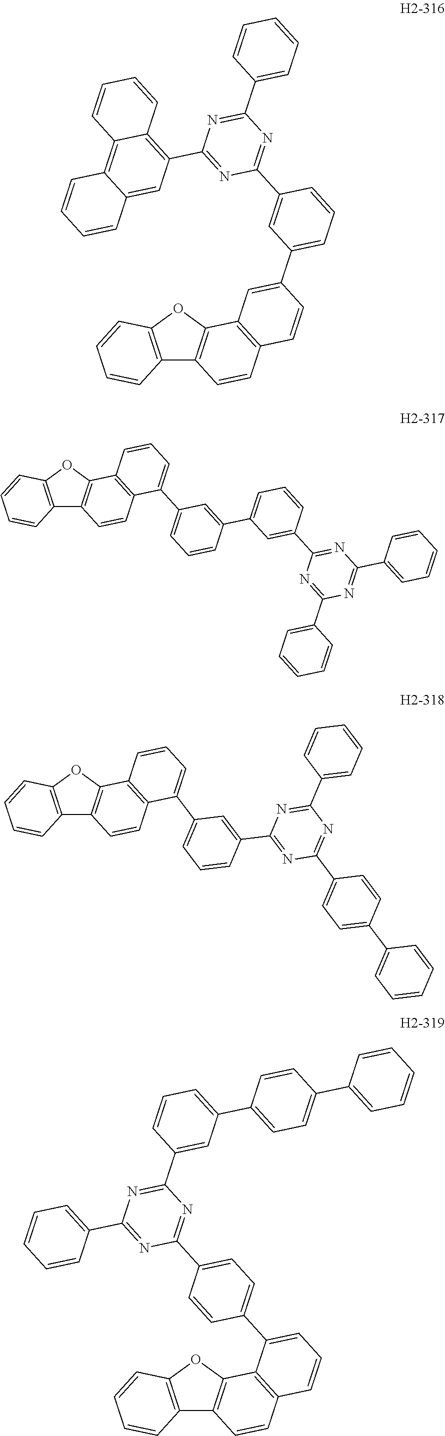 [SMILES: c1ccc(-c2nc(-c3cccc(-c4ccc5ccc6c7ccccc7oc6c5c4)c3)nc(-c3cc4ccccc4c4ccccc34)n2)cc1 ; c1ccc(-c2nc(-c3ccccc3)nc(-c3cccc(-c4cccc(-c5cccc6c5ccc5c7ccccc7oc65)c4)c3)n2)cc1 ; c1ccc(-c2ccc(-c3nc(-c4ccccc4)nc(-c4cccc(-c5cccc6c5ccc5c7ccccc7oc65)c4)n3)cc2)cc1 ; c1ccc(-c2ccc(-c3cccc(-c4nc(-c5ccccc5)nc(-c5ccc(-c6cccc7ccc8c9ccccc9oc8c67)cc5)n4)c3)cc2)cc1]

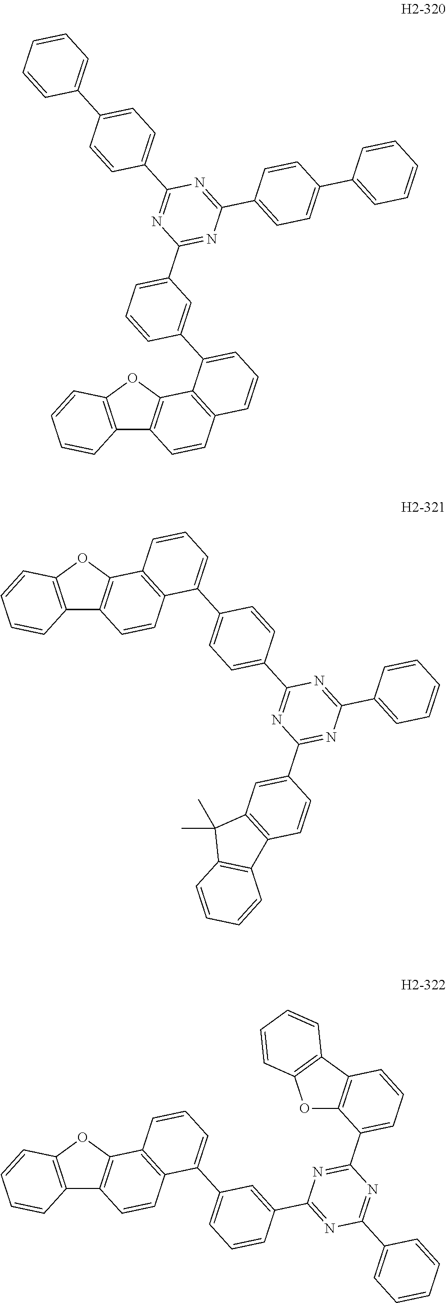 [SMILES: c1ccc(-c2ccc(-c3nc(-c4ccc(-c5ccccc5)cc4)nc(-c4cccc(-c5cccc6ccc7c8ccccc8oc7c56)c4)n3)cc2)cc1 ; CC1(C)c2ccccc2-c2ccc(-c3nc(-c4ccccc4)nc(-c4ccc(-c5cccc6c5ccc5c7ccccc7oc65)cc4)n3)cc21 ; c1ccc(-c2nc(-c3cccc(-c4cccc5c4ccc4c6ccccc6oc54)c3)nc(-c3cccc4c3oc3ccccc34)n2)cc1]

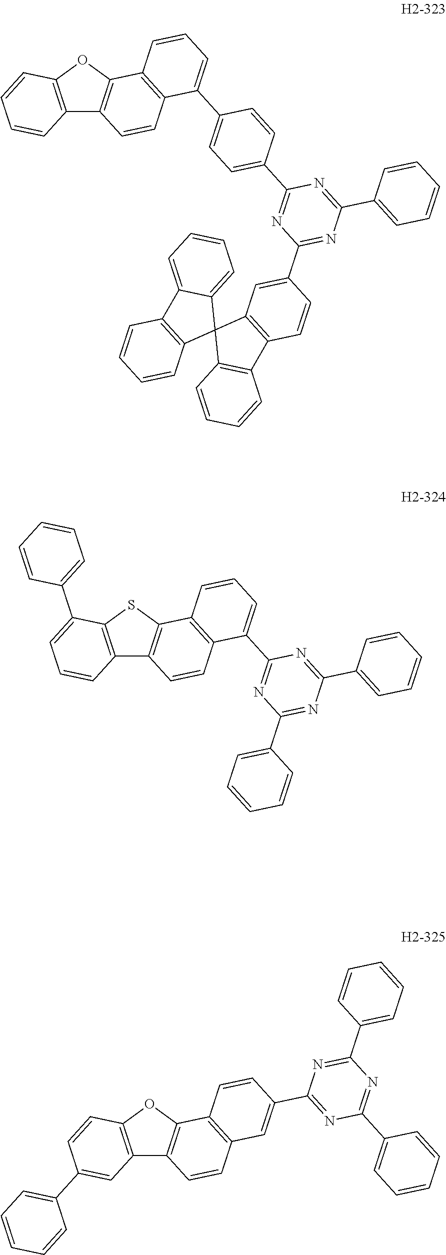 [SMILES: c1ccc(-c2nc(-c3ccc(-c4cccc5c4ccc4c6ccccc6oc54)cc3)nc(-c3ccc4c(c3)C3(c5ccccc5-c5ccccc53)c3ccccc3-4)n2)cc1 ; c1ccc(-c2nc(-c3ccccc3)nc(-c3cccc4c3ccc3c5cccc(-c6ccccc6)c5sc43)n2)cc1 ; c1ccc(-c2ccc3oc4c5ccc(-c6nc(-c7ccccc7)nc(-c7ccccc7)n6)cc5ccc4c3c2)cc1]

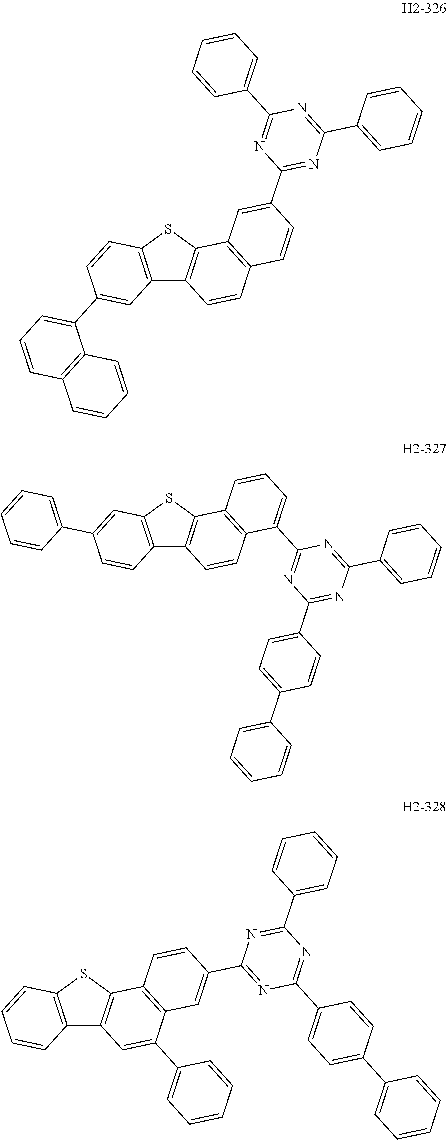 [SMILES: c1ccc(-c2nc(-c3ccccc3)nc(-c3ccc4ccc5c6cc(-c7cccc8ccccc78)ccc6sc5c4c3)n2)cc1 ; c1ccc(-c2ccc(-c3nc(-c4ccccc4)nc(-c4cccc5c4ccc4c6ccc(-c7ccccc7)cc6sc54)n3)cc2)cc1 ; c1ccc(-c2ccc(-c3nc(-c4ccccc4)nc(-c4ccc5c(c4)c(-c4ccccc4)cc4c6ccccc6sc54)n3)cc2)cc1]

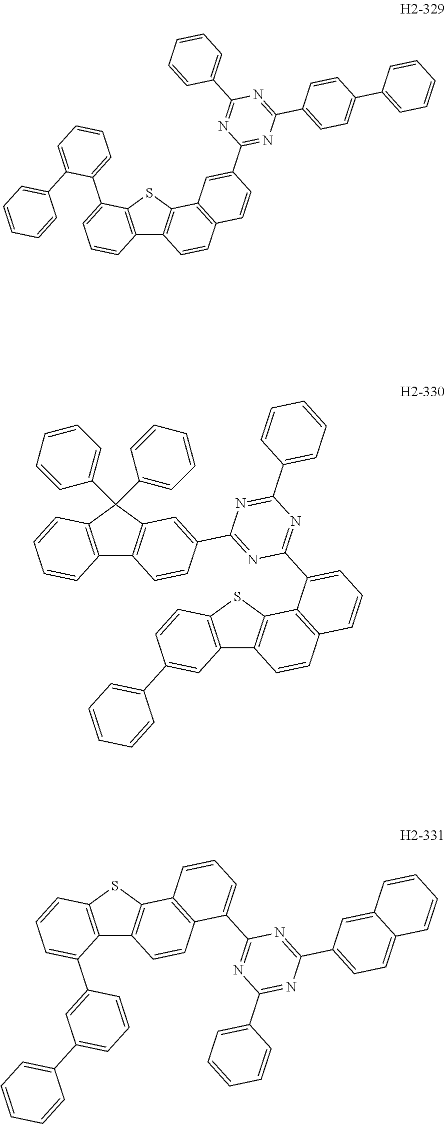 [SMILES: c1ccc(-c2ccc(-c3nc(-c4ccccc4)nc(-c4ccc5ccc6c7cccc(-c8ccccc8-c8ccccc8)c7sc6c5c4)n3)cc2)cc1 ; c1ccc(-c2ccc3sc4c(ccc5cccc(-c6nc(-c7ccccc7)nc(-c7ccc8c(c7)C(c7ccccc7)(c7ccccc7)c7ccccc7-8)n6)c54)c3c2)cc1 ; c1ccc(-c2cccc(-c3cccc4sc5c6cccc(-c7nc(-c8ccccc8)nc(-c8ccc9ccccc9c8)n7)c6ccc5c34)c2)cc1]

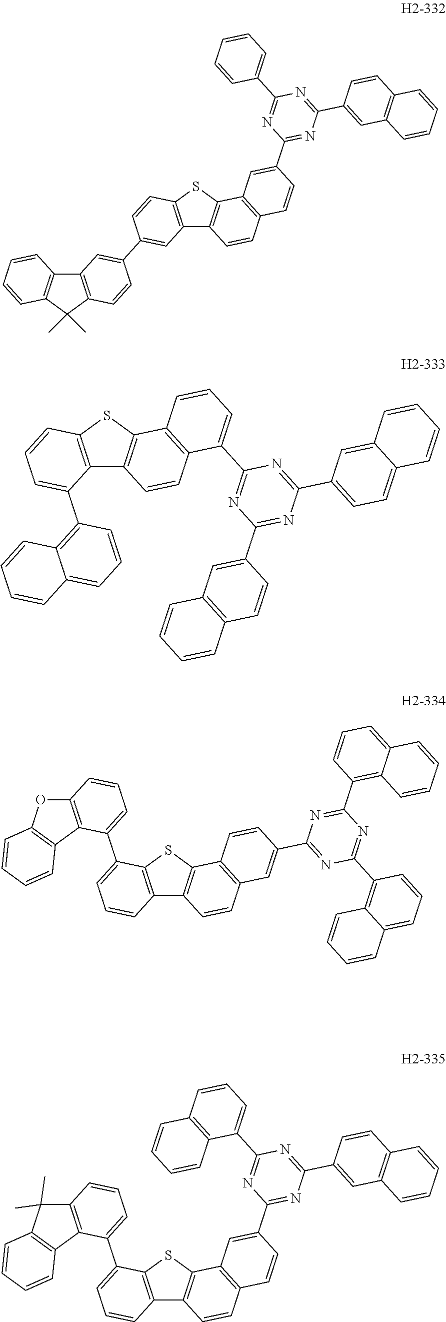 [SMILES: CC1(C)c2ccccc2-c2cc(-c3ccc4sc5c6cc(-c7nc(-c8ccccc8)nc(-c8ccc9ccccc9c8)n7)ccc6ccc5c4c3)ccc21 ; c1ccc2cc(-c3nc(-c4ccc5ccccc5c4)nc(-c4cccc5c4ccc4c5sc5cccc(-c6cccc7ccccc67)c54)n3)ccc2c1 ; c1ccc2c(-c3nc(-c4ccc5c(ccc6c7cccc(-c8cccc9oc%10ccccc%10c89)c7sc56)c4)nc(-c4cccc5ccccc45)n3)cccc2c1 ; CC1(C)c2ccccc2-c2c(-c3cccc4c3sc3c5cc(-c6nc(-c7ccc8ccccc8c7)nc(-c7cccc8ccccc78)n6)ccc5ccc43)cccc21]

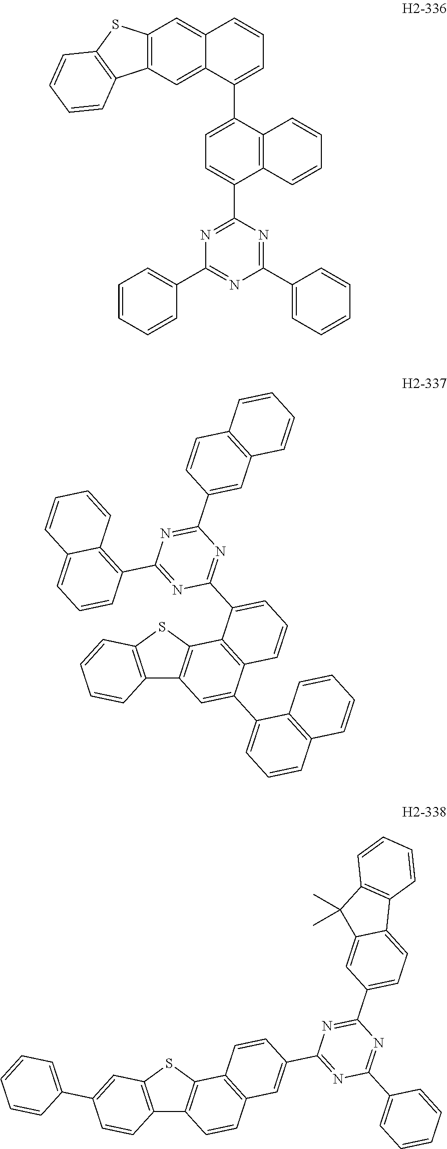 [SMILES: c1ccc(-c2nc(-c3ccccc3)nc(-c3ccc(-c4cccc5cc6sc7ccccc7c6cc45)c4ccccc34)n2)cc1 ; c1ccc2cc(-c3nc(-c4cccc5ccccc45)nc(-c4cccc5c(-c6cccc7ccccc67)cc6c7ccccc7sc6c45)n3)ccc2c1 ; CC1(C)c2ccccc2-c2ccc(-c3nc(-c4ccccc4)nc(-c4ccc5c(ccc6c7ccc(-c8ccccc8)cc7sc56)c4)n3)cc21]

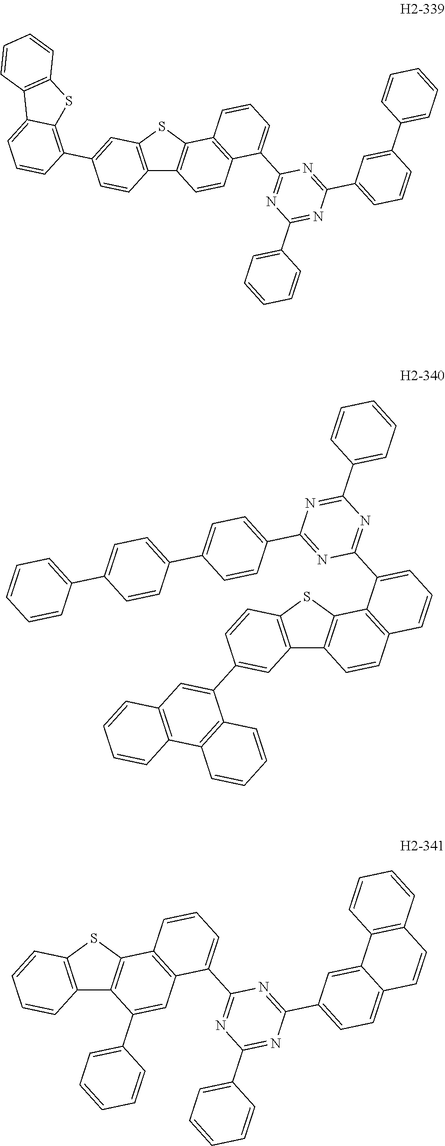 [SMILES: c1ccc(-c2cccc(-c3nc(-c4ccccc4)nc(-c4cccc5c4ccc4c6ccc(-c7cccc8c7sc7ccccc78)cc6sc54)n3)c2)cc1 ; c1ccc(-c2ccc(-c3ccc(-c4nc(-c5ccccc5)nc(-c5cccc6ccc7c8cc(-c9cc%10ccccc%10c%10ccccc9%10)ccc8sc7c56)n4)cc3)cc2)cc1 ; c1ccc(-c2nc(-c3ccc4ccc5ccccc5c4c3)nc(-c3cccc4c3cc(-c3ccccc3)c3c5ccccc5sc43)n2)cc1]

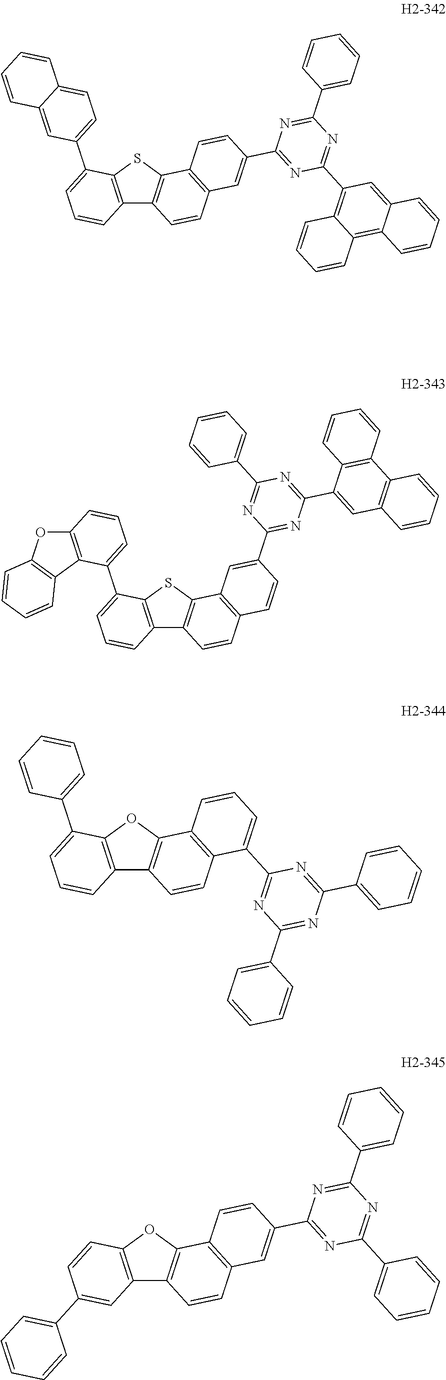 [SMILES: c1ccc(-c2nc(-c3ccc4c(ccc5c6cccc(-c7ccc8ccccc8c7)c6sc45)c3)nc(-c3cc4ccccc4c4ccccc34)n2)cc1 ; c1ccc(-c2nc(-c3ccc4ccc5c6cccc(-c7cccc8oc9ccccc9c78)c6sc5c4c3)nc(-c3cc4ccccc4c4ccccc34)n2)cc1 ; c1ccc(-c2nc(-c3ccccc3)nc(-c3cccc4c3ccc3c5cccc(-c6ccccc6)c5oc43)n2)cc1 ; c1ccc(-c2ccc3oc4c5ccc(-c6nc(-c7ccccc7)nc(-c7ccccc7)n6)cc5ccc4c3c2)cc1]

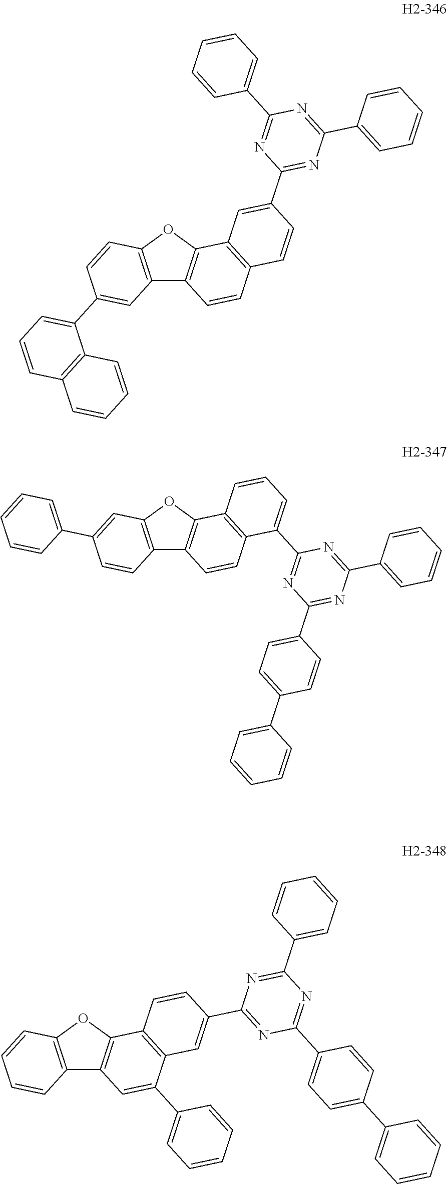 [SMILES: c1ccc(-c2nc(-c3ccccc3)nc(-c3ccc4ccc5c6cc(-c7cccc8ccccc78)ccc6oc5c4c3)n2)cc1 ; c1ccc(-c2ccc(-c3nc(-c4ccccc4)nc(-c4cccc5c4ccc4c6ccc(-c7ccccc7)cc6oc54)n3)cc2)cc1 ; c1ccc(-c2ccc(-c3nc(-c4ccccc4)nc(-c4ccc5c(c4)c(-c4ccccc4)cc4c6ccccc6oc54)n3)cc2)cc1]

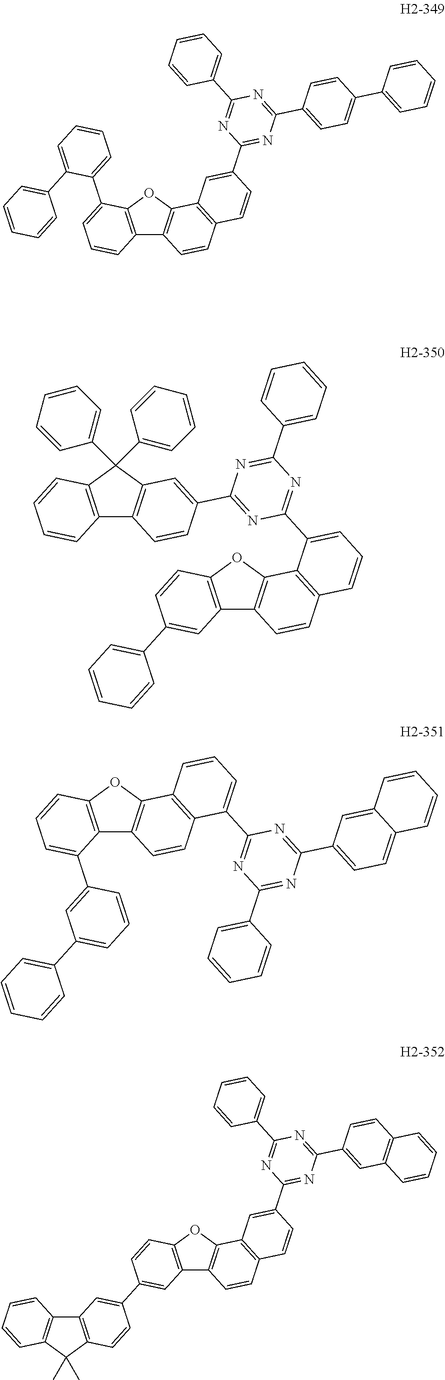 [SMILES: c1ccc(-c2ccc(-c3nc(-c4ccccc4)nc(-c4ccc5ccc6c7cccc(-c8ccccc8-c8ccccc8)c7oc6c5c4)n3)cc2)cc1 ; c1ccc(-c2ccc3oc4c(ccc5cccc(-c6nc(-c7ccccc7)nc(-c7ccc8c(c7)C(c7ccccc7)(c7ccccc7)c7ccccc7-8)n6)c54)c3c2)cc1 ; c1ccc(-c2cccc(-c3cccc4oc5c6cccc(-c7nc(-c8ccccc8)nc(-c8ccc9ccccc9c8)n7)c6ccc5c34)c2)cc1 ; CC1(C)c2ccccc2-c2cc(-c3ccc4oc5c6cc(-c7nc(-c8ccccc8)nc(-c8ccc9ccccc9c8)n7)ccc6ccc5c4c3)ccc21]

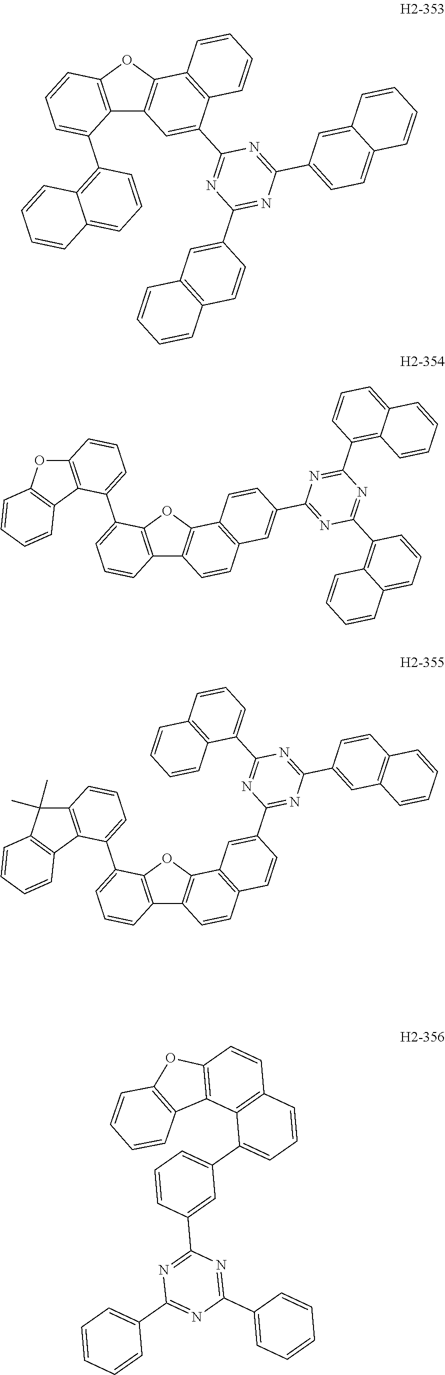 [SMILES: c1ccc2cc(-c3nc(-c4ccc5ccccc5c4)nc(-c4cc5c(oc6cccc(-c7cccc8ccccc78)c65)c5ccccc45)n3)ccc2c1 ; c1ccc2c(-c3nc(-c4ccc5c(ccc6c7cccc(-c8cccc9oc%10ccccc%10c89)c7oc56)c4)nc(-c4cccc5ccccc45)n3)cccc2c1 ; CC1(C)c2ccccc2-c2c(-c3cccc4c3oc3c5cc(-c6nc(-c7ccc8ccccc8c7)nc(-c7cccc8ccccc78)n6)ccc5ccc43)cccc21 ; c1ccc(-c2nc(-c3ccccc3)nc(-c3cccc(-c4cccc5ccc6oc7ccccc7c6c45)c3)n2)cc1]

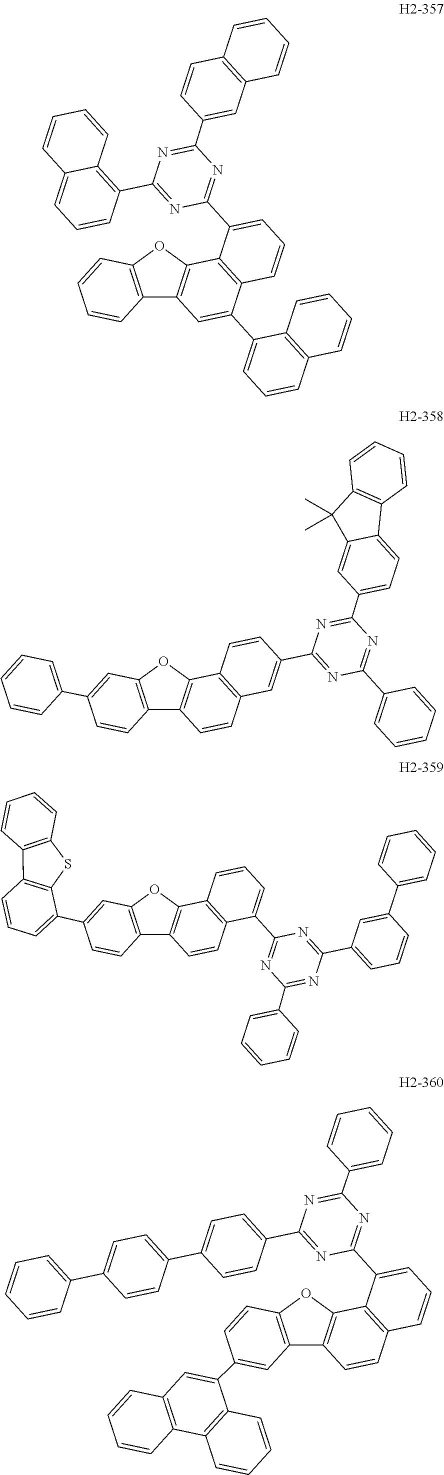 [SMILES: c1ccc2cc(-c3nc(-c4cccc5ccccc45)nc(-c4cccc5c(-c6cccc7ccccc67)cc6c7ccccc7oc6c45)n3)ccc2c1 ; CC1(C)c2ccccc2-c2ccc(-c3nc(-c4ccccc4)nc(-c4ccc5c(ccc6c7ccc(-c8ccccc8)cc7oc56)c4)n3)cc21 ; c1ccc(-c2cccc(-c3nc(-c4ccccc4)nc(-c4cccc5c4ccc4c6ccc(-c7cccc8c7sc7ccccc78)cc6oc54)n3)c2)cc1 ; c1ccc(-c2ccc(-c3ccc(-c4nc(-c5ccccc5)nc(-c5cccc6ccc7c8cc(-c9cc%10ccccc%10c%10ccccc9%10)ccc8oc7c56)n4)cc3)cc2)cc1]

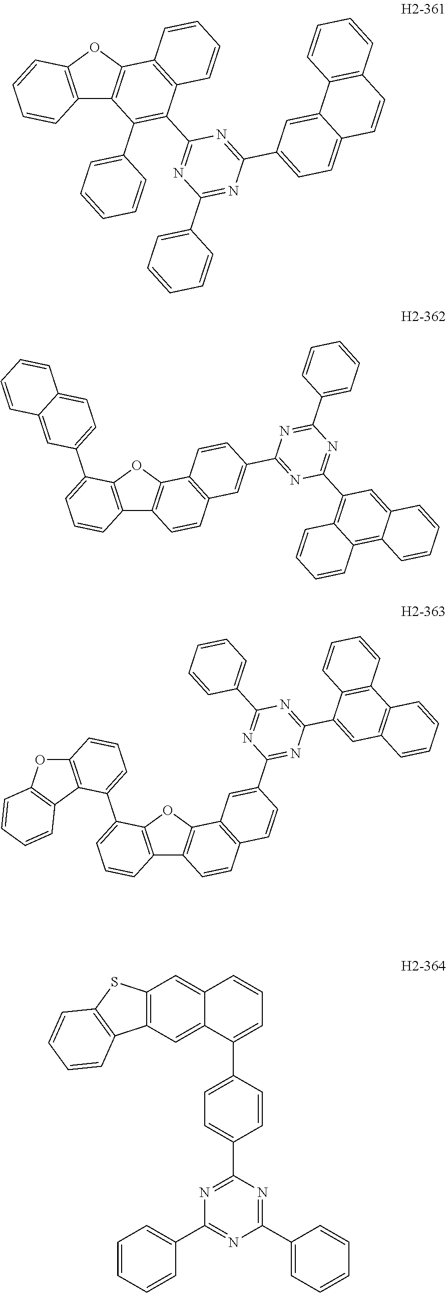 [SMILES: c1ccc(-c2nc(-c3ccc4ccc5ccccc5c4c3)nc(-c3c(-c4ccccc4)c4c5ccccc5oc4c4ccccc34)n2)cc1 ; c1ccc(-c2nc(-c3ccc4c(ccc5c6cccc(-c7ccc8ccccc8c7)c6oc45)c3)nc(-c3cc4ccccc4c4ccccc34)n2)cc1 ; c1ccc(-c2nc(-c3ccc4ccc5c6cccc(-c7cccc8oc9ccccc9c78)c6oc5c4c3)nc(-c3cc4ccccc4c4ccccc34)n2)cc1 ; c1ccc(-c2nc(-c3ccccc3)nc(-c3ccc(-c4cccc5cc6sc7ccccc7c6cc45)cc3)n2)cc1]

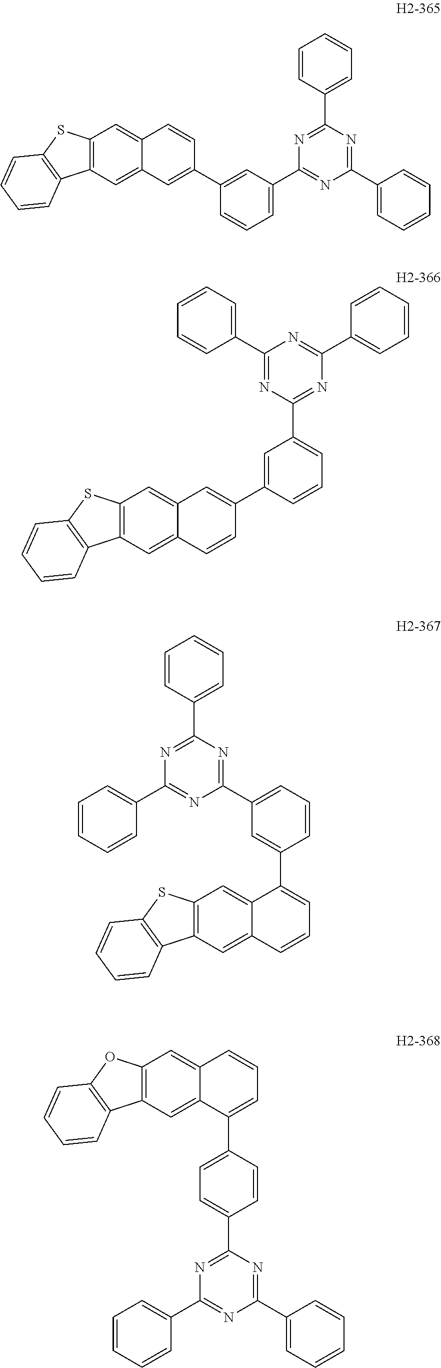 [SMILES: c1ccc(-c2nc(-c3ccccc3)nc(-c3cccc(-c4ccc5cc6sc7ccccc7c6cc5c4)c3)n2)cc1 ; c1ccc(-c2nc(-c3ccccc3)nc(-c3cccc(-c4ccc5cc6c(cc5c4)sc4ccccc46)c3)n2)cc1 ; c1ccc(-c2nc(-c3ccccc3)nc(-c3cccc(-c4cccc5cc6c(cc45)sc4ccccc46)c3)n2)cc1 ; c1ccc(-c2nc(-c3ccccc3)nc(-c3ccc(-c4cccc5cc6oc7ccccc7c6cc45)cc3)n2)cc1]

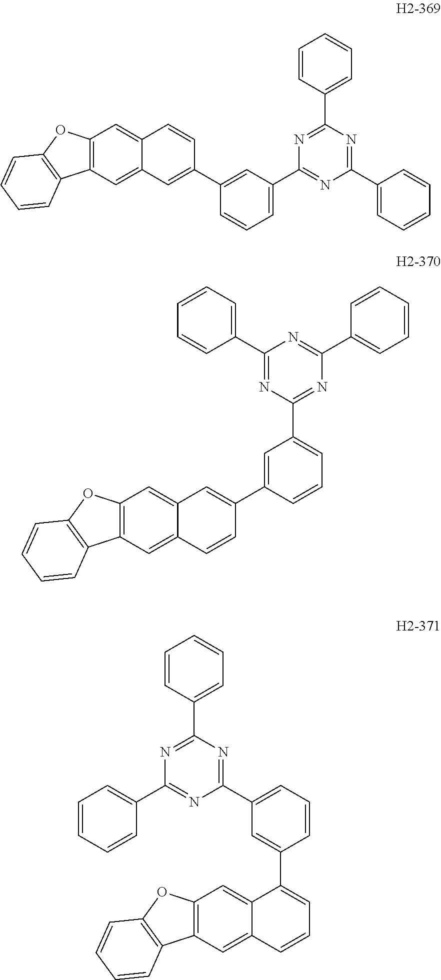 [SMILES: c1ccc(-c2nc(-c3ccccc3)nc(-c3cccc(-c4ccc5cc6oc7ccccc7c6cc5c4)c3)n2)cc1 ; c1ccc(-c2nc(-c3ccccc3)nc(-c3cccc(-c4ccc5cc6c(cc5c4)oc4ccccc46)c3)n2)cc1 ; c1ccc(-c2nc(-c3ccccc3)nc(-c3cccc(-c4cccc5cc6c(cc45)oc4ccccc46)c3)n2)cc1]

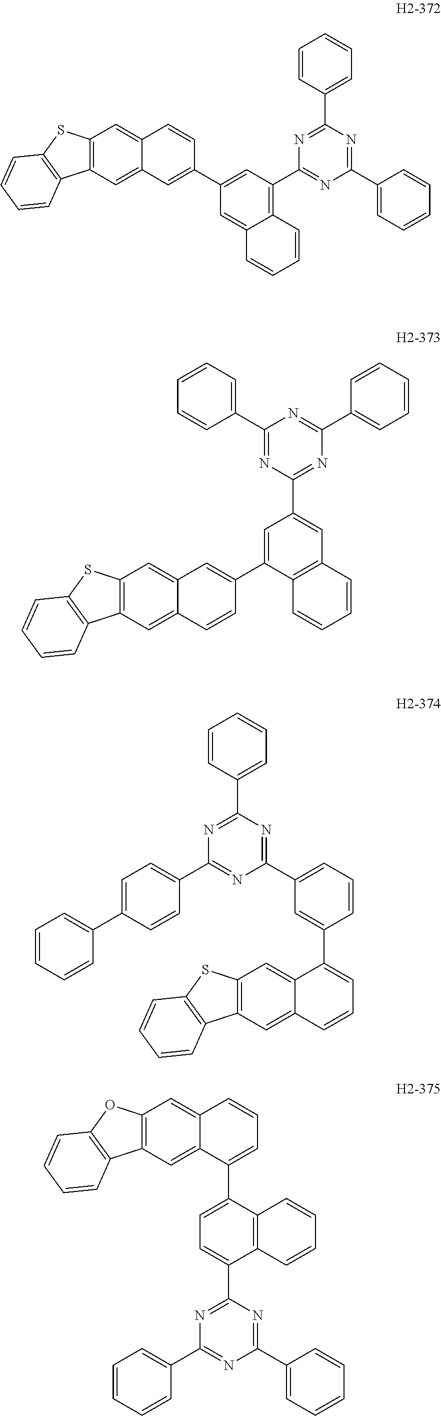

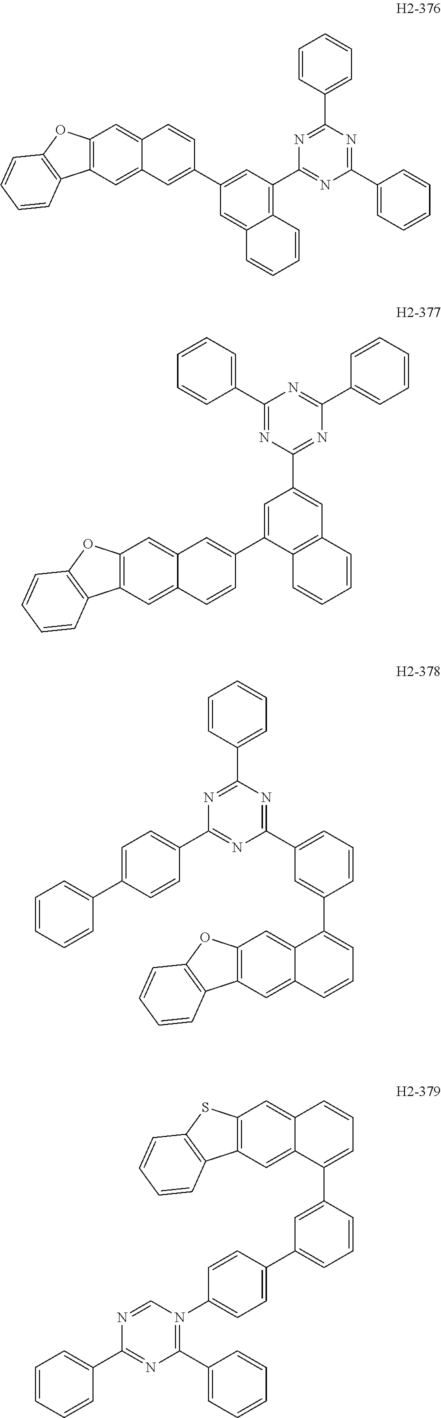

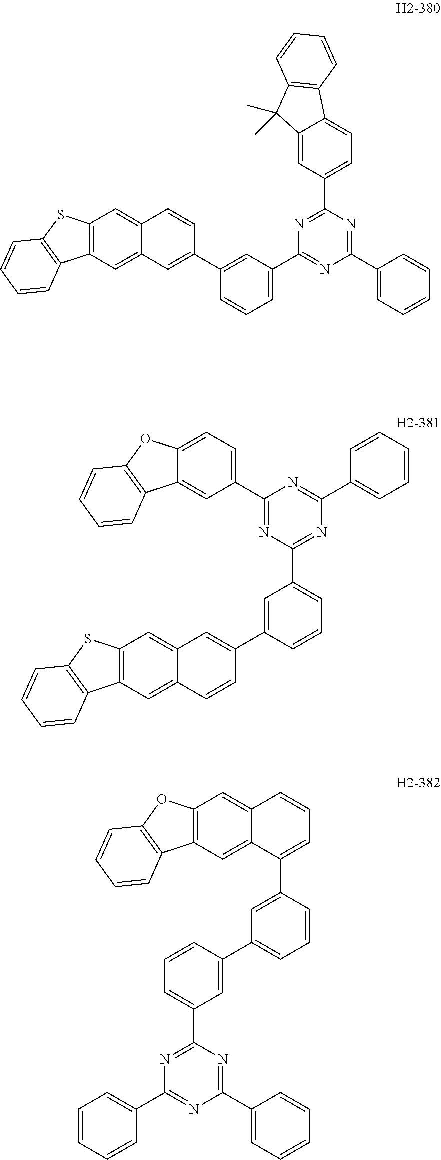 [SMILES: CC1(C)c2ccccc2-c2ccc(-c3nc(-c4ccccc4)nc(-c4cccc(-c5ccc6cc7sc8ccccc8c7cc6c5)c4)n3)cc21 ; c1ccc(-c2nc(-c3cccc(-c4ccc5cc6c(cc5c4)sc4ccccc46)c3)nc(-c3ccc4oc5ccccc5c4c3)n2)cc1 ; c1ccc(-c2nc(-c3ccccc3)nc(-c3cccc(-c4cccc(-c5cccc6cc7oc8ccccc8c7cc56)c4)c3)n2)cc1]

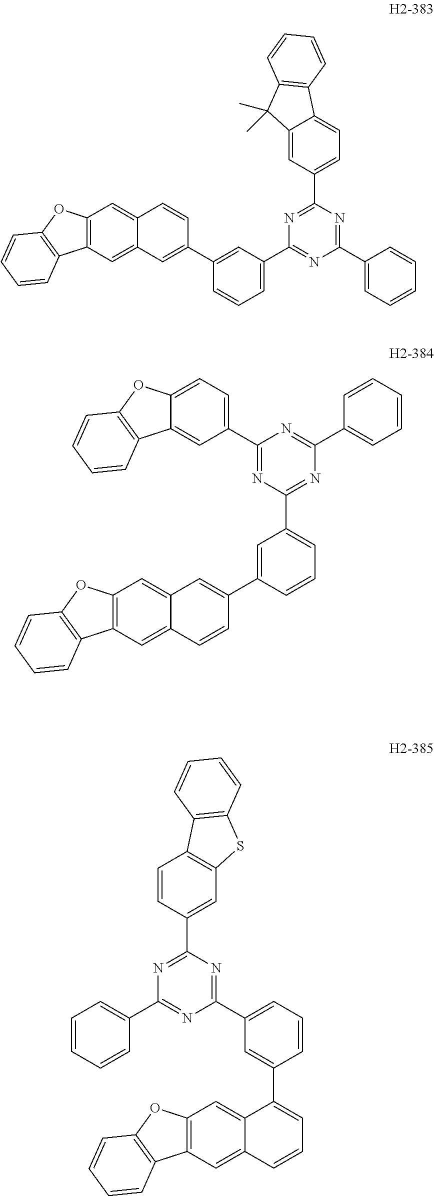 [SMILES: CC1(C)c2ccccc2-c2ccc(-c3nc(-c4ccccc4)nc(-c4cccc(-c5ccc6cc7oc8ccccc8c7cc6c5)c4)n3)cc21 ; c1ccc(-c2nc(-c3cccc(-c4ccc5cc6c(cc5c4)oc4ccccc46)c3)nc(-c3ccc4oc5ccccc5c4c3)n2)cc1 ; c1ccc(-c2nc(-c3cccc(-c4cccc5cc6c(cc45)oc4ccccc46)c3)nc(-c3ccc4c(c3)sc3ccccc34)n2)cc1]

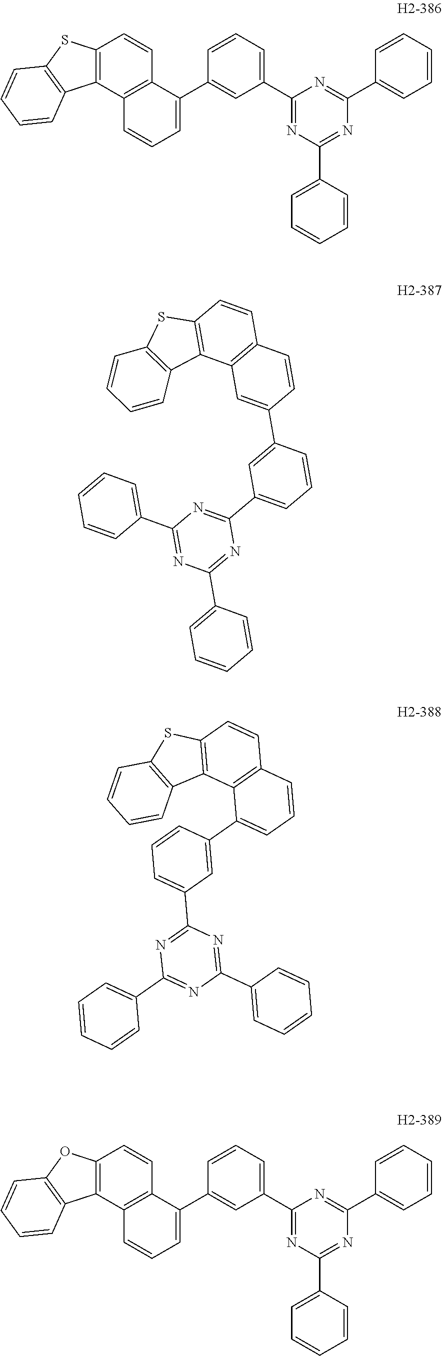 [SMILES: c1ccc(-c2nc(-c3ccccc3)nc(-c3cccc(-c4cccc5c4ccc4sc6ccccc6c45)c3)n2)cc1 ; c1ccc(-c2nc(-c3ccccc3)nc(-c3cccc(-c4ccc5ccc6sc7ccccc7c6c5c4)c3)n2)cc1 ; c1ccc(-c2nc(-c3ccccc3)nc(-c3cccc(-c4cccc5ccc6sc7ccccc7c6c45)c3)n2)cc1 ; c1ccc(-c2nc(-c3ccccc3)nc(-c3cccc(-c4cccc5c4ccc4oc6ccccc6c45)c3)n2)cc1]

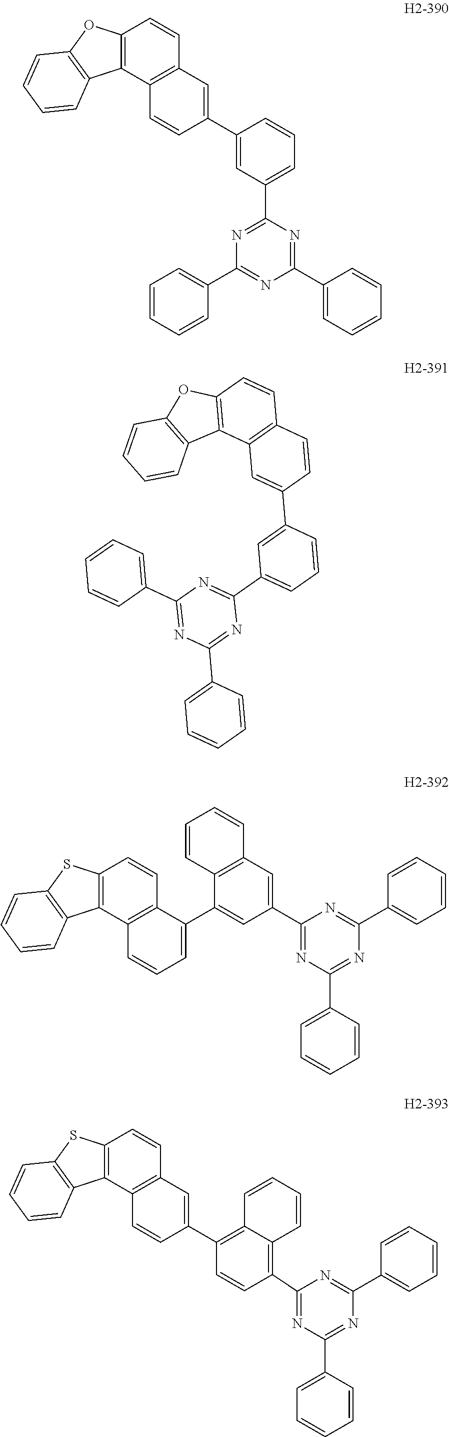 [SMILES: c1ccc(-c2nc(-c3ccccc3)nc(-c3cccc(-c4ccc5c(ccc6oc7ccccc7c65)c4)c3)n2)cc1 ; c1ccc(-c2nc(-c3ccccc3)nc(-c3cccc(-c4ccc5ccc6oc7ccccc7c6c5c4)c3)n2)cc1 ; c1ccc(-c2nc(-c3ccccc3)nc(-c3cc(-c4cccc5c4ccc4sc6ccccc6c45)c4ccccc4c3)n2)cc1 ; c1ccc(-c2nc(-c3ccccc3)nc(-c3ccc(-c4ccc5c(ccc6sc7ccccc7c65)c4)c4ccccc34)n2)cc1]

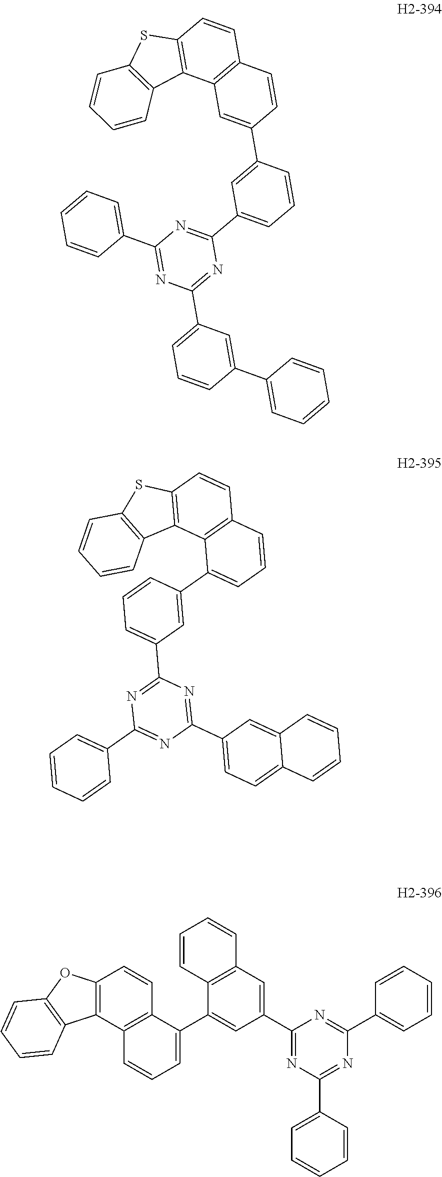 [SMILES: c1ccc(-c2cccc(-c3nc(-c4ccccc4)nc(-c4cccc(-c5ccc6ccc7sc8ccccc8c7c6c5)c4)n3)c2)cc1 ; c1ccc(-c2nc(-c3cccc(-c4cccc5ccc6sc7ccccc7c6c45)c3)nc(-c3ccc4ccccc4c3)n2)cc1 ; c1ccc(-c2nc(-c3ccccc3)nc(-c3cc(-c4cccc5c4ccc4oc6ccccc6c45)c4ccccc4c3)n2)cc1]

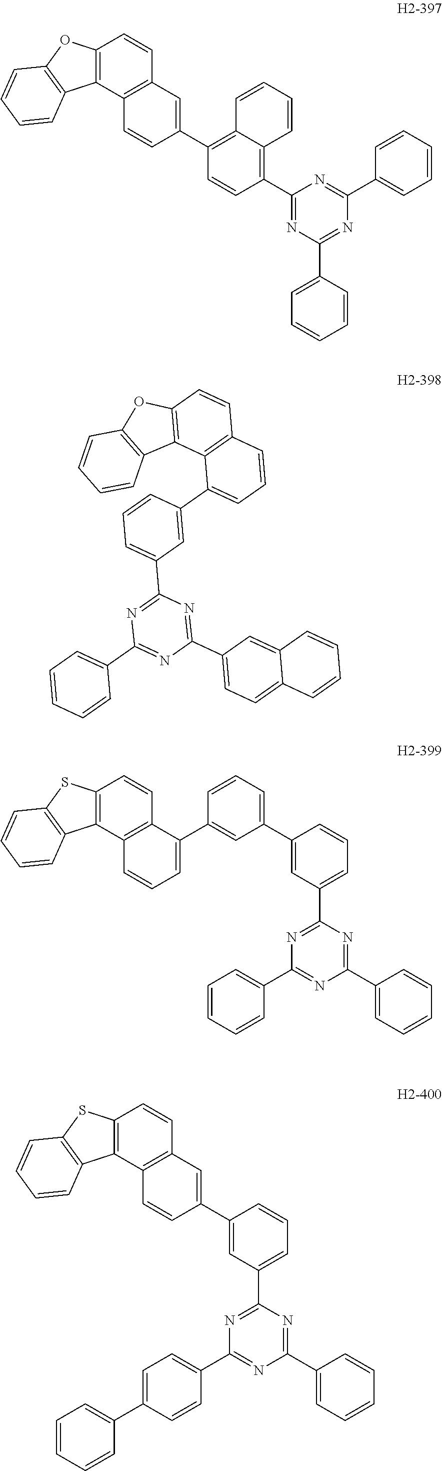 [SMILES: c1ccc(-c2nc(-c3ccccc3)nc(-c3ccc(-c4ccc5c(ccc6oc7ccccc7c65)c4)c4ccccc34)n2)cc1 ; c1ccc(-c2nc(-c3cccc(-c4cccc5ccc6oc7ccccc7c6c45)c3)nc(-c3ccc4ccccc4c3)n2)cc1 ; c1ccc(-c2nc(-c3ccccc3)nc(-c3cccc(-c4cccc(-c5cccc6c5ccc5sc7ccccc7c56)c4)c3)n2)cc1 ; c1ccc(-c2ccc(-c3nc(-c4ccccc4)nc(-c4cccc(-c5ccc6c(ccc7sc8ccccc8c76)c5)c4)n3)cc2)cc1]

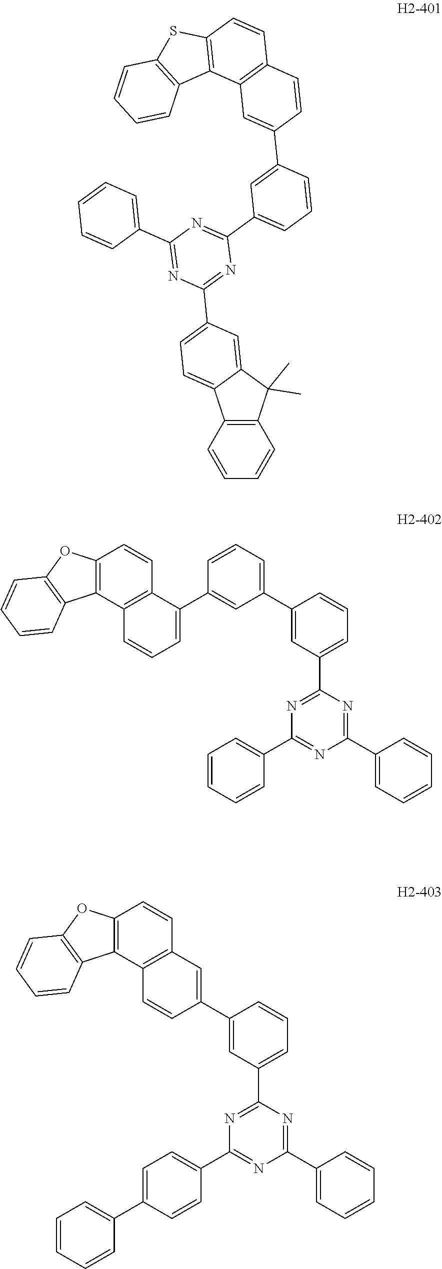 [SMILES: CC1(C)c2ccccc2-c2ccc(-c3nc(-c4ccccc4)nc(-c4cccc(-c5ccc6ccc7sc8ccccc8c7c6c5)c4)n3)cc21 ; c1ccc(-c2nc(-c3ccccc3)nc(-c3cccc(-c4cccc(-c5cccc6c5ccc5oc7ccccc7c56)c4)c3)n2)cc1 ; c1ccc(-c2ccc(-c3nc(-c4ccccc4)nc(-c4cccc(-c5ccc6c(ccc7oc8ccccc8c76)c5)c4)n3)cc2)cc1]

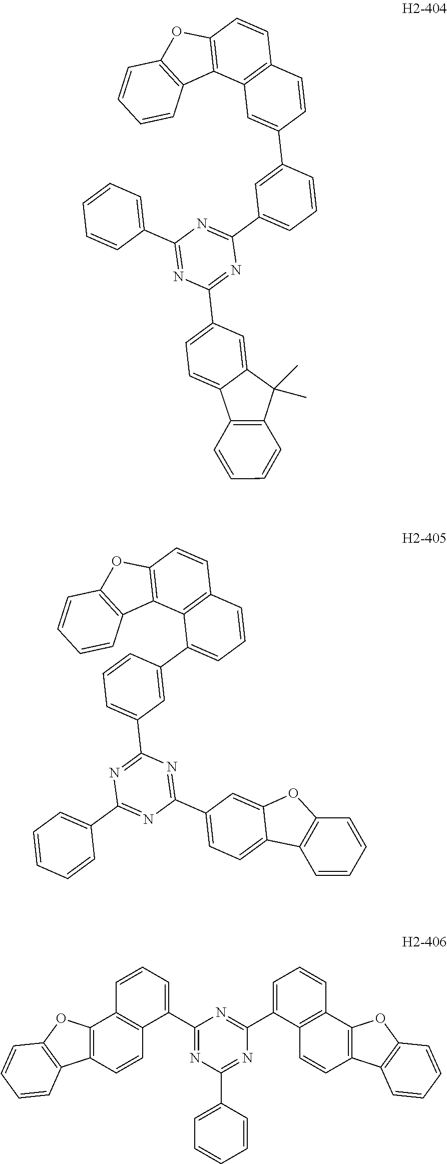 [SMILES: CC1(C)c2ccccc2-c2ccc(-c3nc(-c4ccccc4)nc(-c4cccc(-c5ccc6ccc7oc8ccccc8c7c6c5)c4)n3)cc21 ; c1ccc(-c2nc(-c3cccc(-c4cccc5ccc6oc7ccccc7c6c45)c3)nc(-c3ccc4c(c3)oc3ccccc34)n2)cc1 ; c1ccc(-c2nc(-c3cccc4c3ccc3c5ccccc5oc43)nc(-c3cccc4c3ccc3c5ccccc5oc43)n2)cc1]

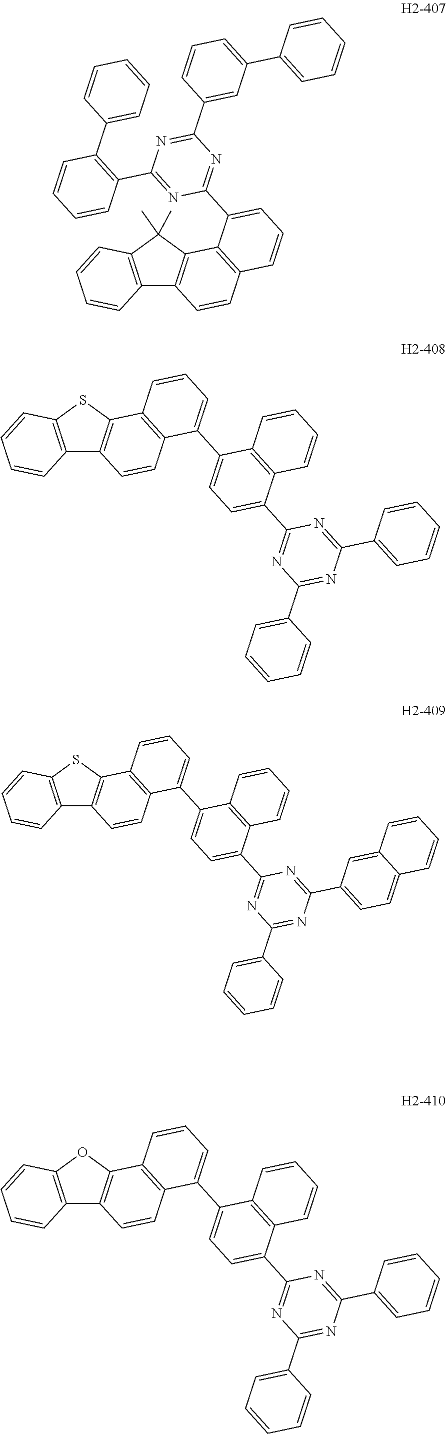 [SMILES: CC1(C)c2ccccc2-c2ccc3cccc(-c4nc(-c5cccc(-c6ccccc6)c5)nc(-c5ccccc5-c5ccccc5)n4)c3c21 ; c1ccc(-c2nc(-c3ccccc3)nc(-c3ccc(-c4cccc5c4ccc4c6ccccc6sc54)c4ccccc34)n2)cc1 ; c1ccc(-c2nc(-c3ccc4ccccc4c3)nc(-c3ccc(-c4cccc5c4ccc4c6ccccc6sc54)c4ccccc34)n2)cc1 ; c1ccc(-c2nc(-c3ccccc3)nc(-c3ccc(-c4cccc5c4ccc4c6ccccc6oc54)c4ccccc34)n2)cc1]

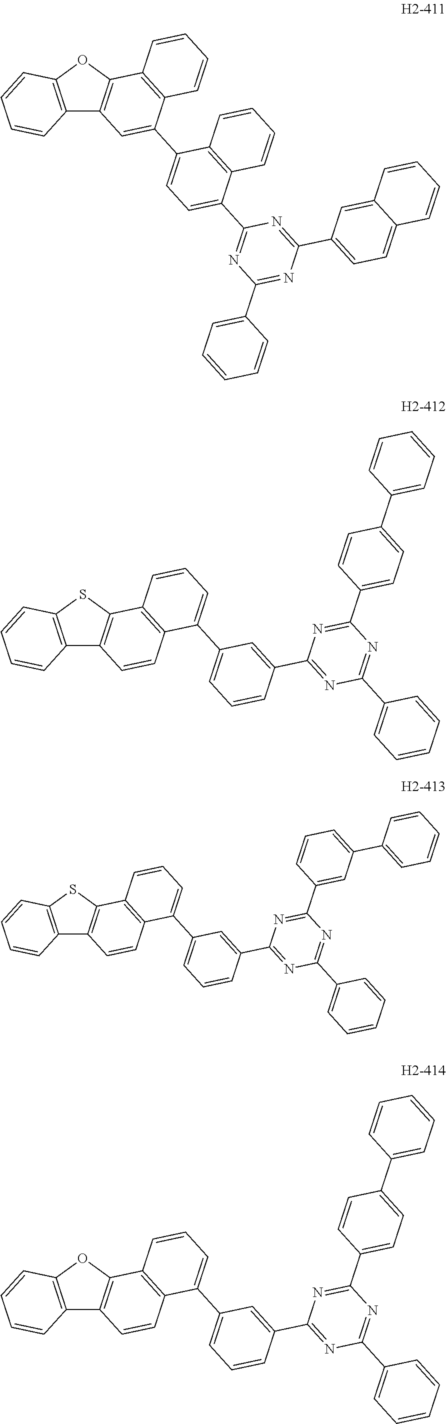 [SMILES: c1ccc(-c2nc(-c3ccc4ccccc4c3)nc(-c3ccc(-c4cc5c6ccccc6oc5c5ccccc45)c4ccccc34)n2)cc1 ; c1ccc(-c2ccc(-c3nc(-c4ccccc4)nc(-c4cccc(-c5cccc6c5ccc5c7ccccc7sc65)c4)n3)cc2)cc1 ; c1ccc(-c2cccc(-c3nc(-c4ccccc4)nc(-c4cccc(-c5cccc6c5ccc5c7ccccc7sc65)c4)n3)c2)cc1 ; c1ccc(-c2ccc(-c3nc(-c4ccccc4)nc(-c4cccc(-c5cccc6c5ccc5c7ccccc7oc65)c4)n3)cc2)cc1]

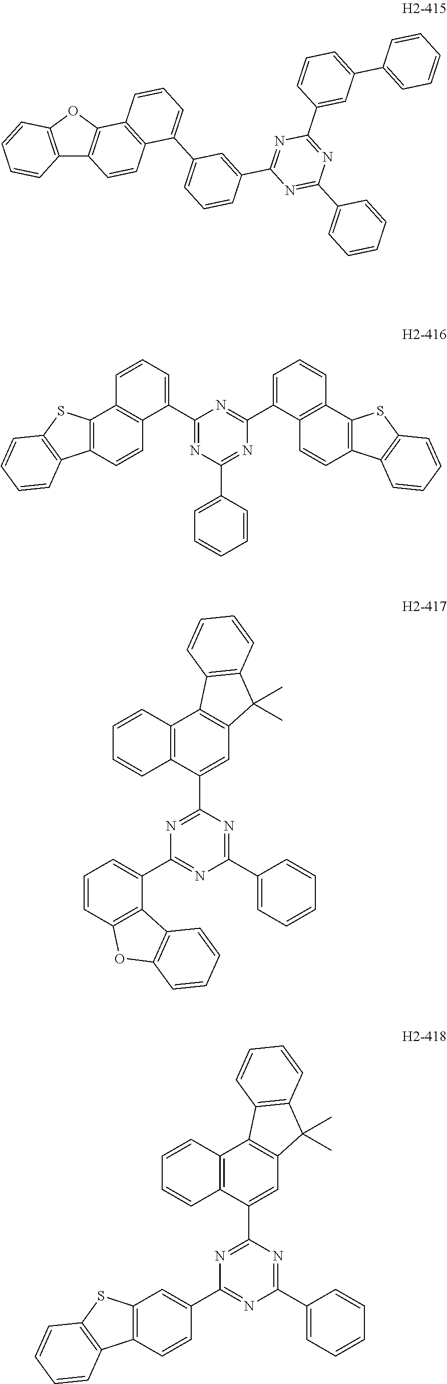 [SMILES: c1ccc(-c2cccc(-c3nc(-c4ccccc4)nc(-c4cccc(-c5cccc6c5ccc5c7ccccc7oc65)c4)n3)c2)cc1 ; c1ccc(-c2nc(-c3cccc4c3ccc3c5ccccc5sc43)nc(-c3cccc4c3ccc3c5ccccc5sc43)n2)cc1 ; CC1(C)c2ccccc2-c2c1cc(-c1nc(-c3ccccc3)nc(-c3cccc4oc5ccccc5c34)n1)c1ccccc21 ; CC1(C)c2ccccc2-c2c1cc(-c1nc(-c3ccccc3)nc(-c3ccc4c(c3)sc3ccccc34)n1)c1ccccc21]

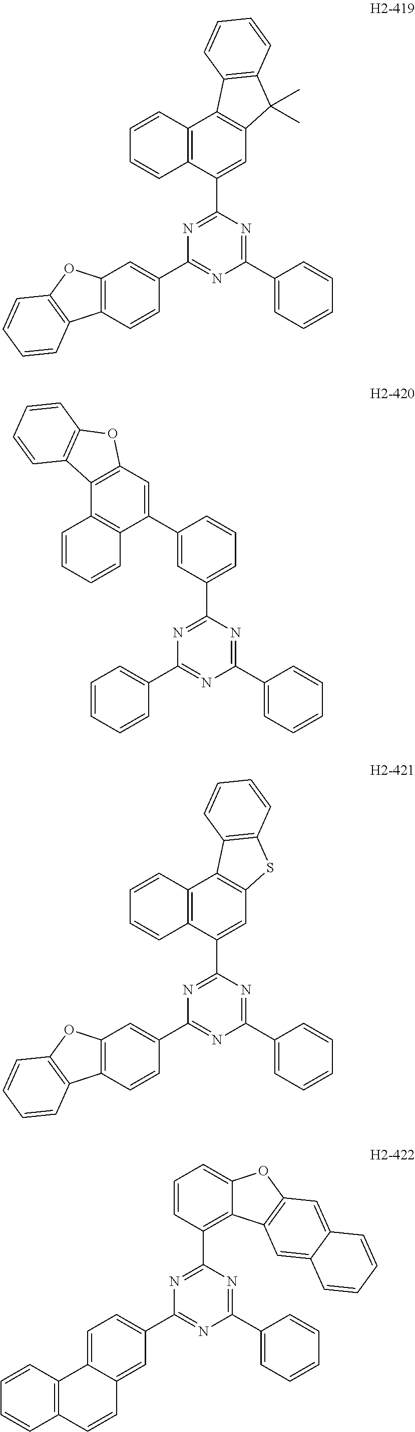 [SMILES: CC1(C)c2ccccc2-c2c1cc(-c1nc(-c3ccccc3)nc(-c3ccc4c(c3)oc3ccccc34)n1)c1ccccc21 ; c1ccc(-c2nc(-c3ccccc3)nc(-c3cccc(-c4cc5oc6ccccc6c5c5ccccc45)c3)n2)cc1 ; c1ccc(-c2nc(-c3ccc4c(c3)oc3ccccc34)nc(-c3cc4sc5ccccc5c4c4ccccc34)n2)cc1 ; c1ccc(-c2nc(-c3ccc4c(ccc5ccccc54)c3)nc(-c3cccc4oc5cc6ccccc6cc5c34)n2)cc1]

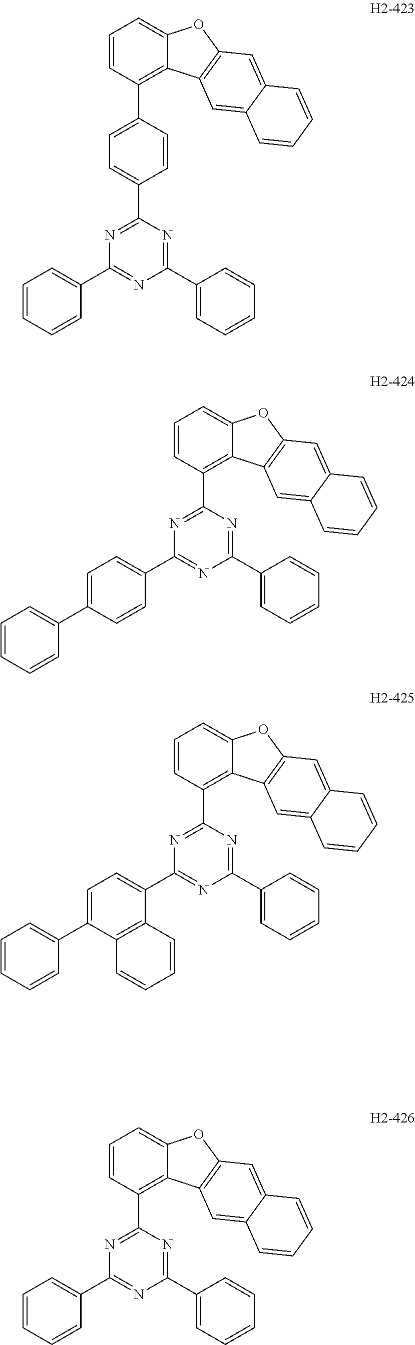 [SMILES: c1ccc(-c2nc(-c3ccccc3)nc(-c3ccc(-c4cccc5oc6cc7ccccc7cc6c45)cc3)n2)cc1 ; c1ccc(-c2ccc(-c3nc(-c4ccccc4)nc(-c4cccc5oc6cc7ccccc7cc6c45)n3)cc2)cc1 ; c1ccc(-c2nc(-c3ccc(-c4ccccc4)c4ccccc34)nc(-c3cccc4oc5cc6ccccc6cc5c34)n2)cc1 ; c1ccc(-c2nc(-c3ccccc3)nc(-c3cccc4oc5cc6ccccc6cc5c34)n2)cc1]

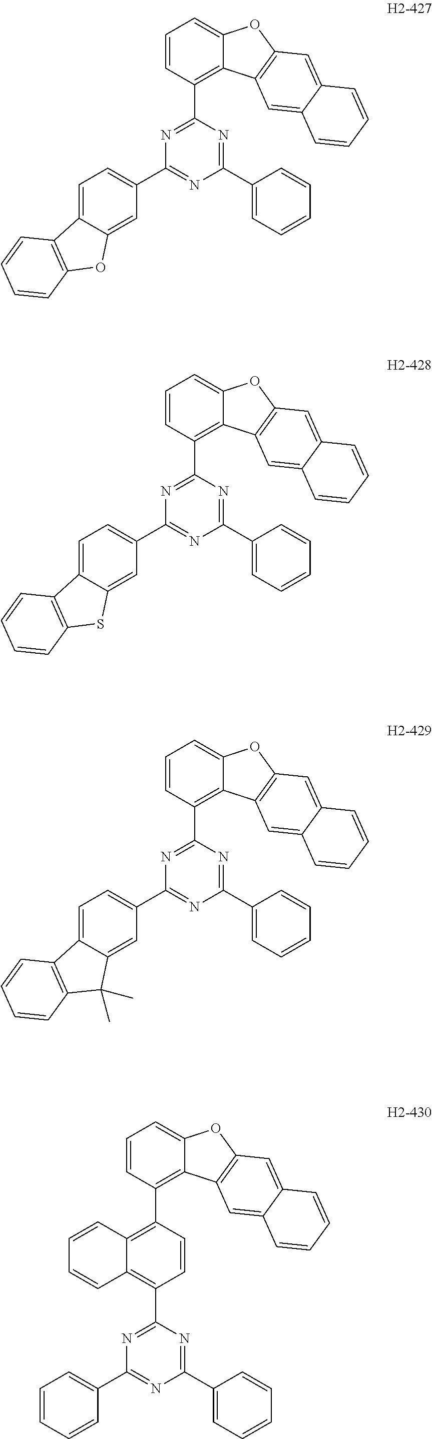 [SMILES: c1ccc(-c2nc(-c3ccc4c(c3)oc3ccccc34)nc(-c3cccc4oc5cc6ccccc6cc5c34)n2)cc1 ; c1ccc(-c2nc(-c3ccc4c(c3)sc3ccccc34)nc(-c3cccc4oc5cc6ccccc6cc5c34)n2)cc1 ; CC1(C)c2ccccc2-c2ccc(-c3nc(-c4ccccc4)nc(-c4cccc5oc6cc7ccccc7cc6c45)n3)cc21 ; c1ccc(-c2nc(-c3ccccc3)nc(-c3ccc(-c4cccc5oc6cc7ccccc7cc6c45)c4ccccc34)n2)cc1]

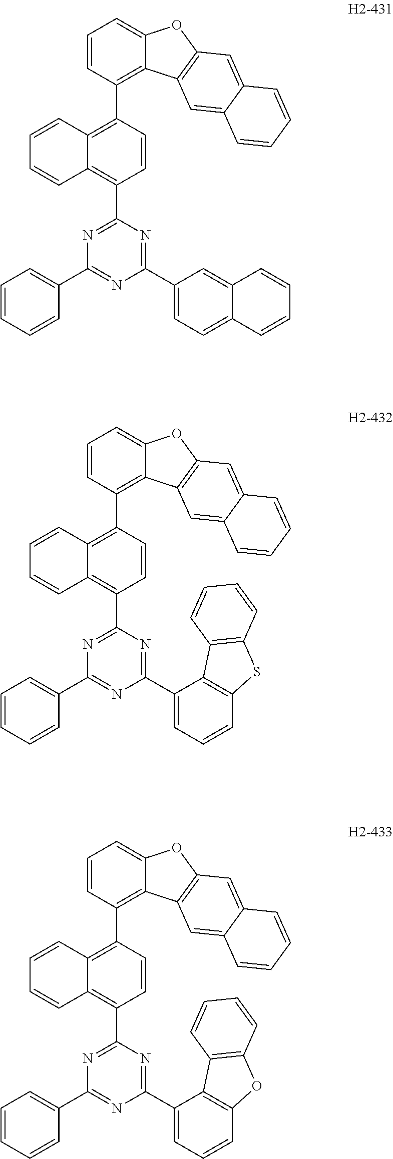 [SMILES: c1ccc(-c2nc(-c3ccc4ccccc4c3)nc(-c3ccc(-c4cccc5oc6cc7ccccc7cc6c45)c4ccccc34)n2)cc1 ; c1ccc(-c2nc(-c3ccc(-c4cccc5oc6cc7ccccc7cc6c45)c4ccccc34)nc(-c3cccc4sc5ccccc5c34)n2)cc1 ; c1ccc(-c2nc(-c3ccc(-c4cccc5oc6cc7ccccc7cc6c45)c4ccccc34)nc(-c3cccc4oc5ccccc5c34)n2)cc1]

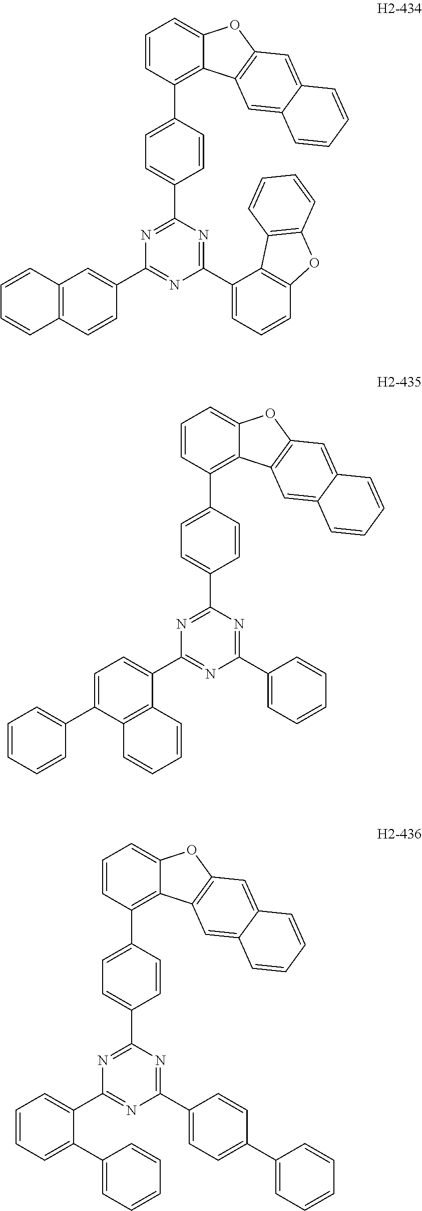 [SMILES: c1ccc2cc(-c3nc(-c4ccc(-c5cccc6oc7cc8ccccc8cc7c56)cc4)nc(-c4cccc5oc6ccccc6c45)n3)ccc2c1 ; c1ccc(-c2nc(-c3ccc(-c4cccc5oc6cc7ccccc7cc6c45)cc3)nc(-c3ccc(-c4ccccc4)c4ccccc34)n2)cc1 ; c1ccc(-c2ccc(-c3nc(-c4ccc(-c5cccc6oc7cc8ccccc8cc7c56)cc4)nc(-c4ccccc4-c4ccccc4)n3)cc2)cc1]

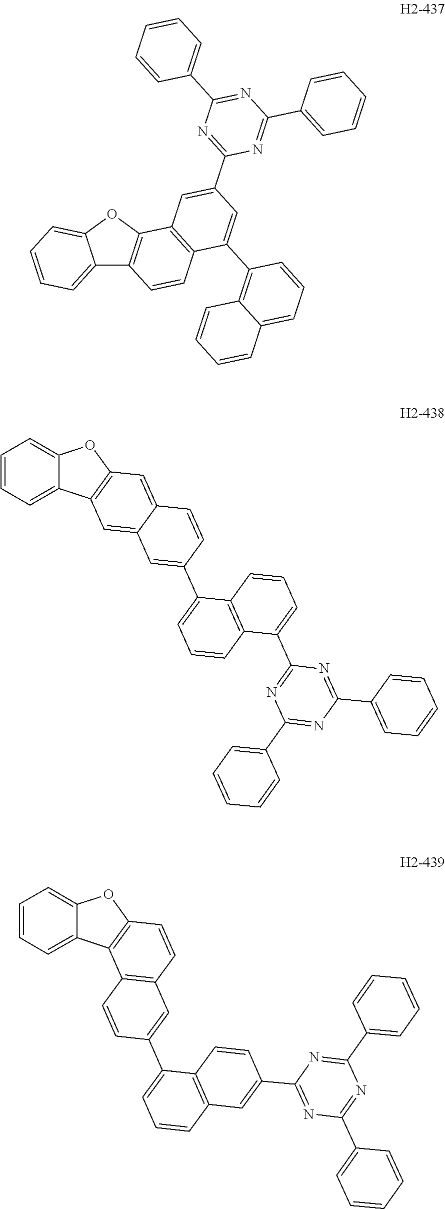 [SMILES: c1ccc(-c2nc(-c3ccccc3)nc(-c3cc(-c4cccc5ccccc45)c4ccc5c6ccccc6oc5c4c3)n2)cc1 ; c1ccc(-c2nc(-c3ccccc3)nc(-c3cccc4c(-c5ccc6cc7oc8ccccc8c7cc6c5)cccc34)n2)cc1 ; c1ccc(-c2nc(-c3ccccc3)nc(-c3ccc4c(-c5ccc6c(ccc7oc8ccccc8c76)c5)cccc4c3)n2)cc1]

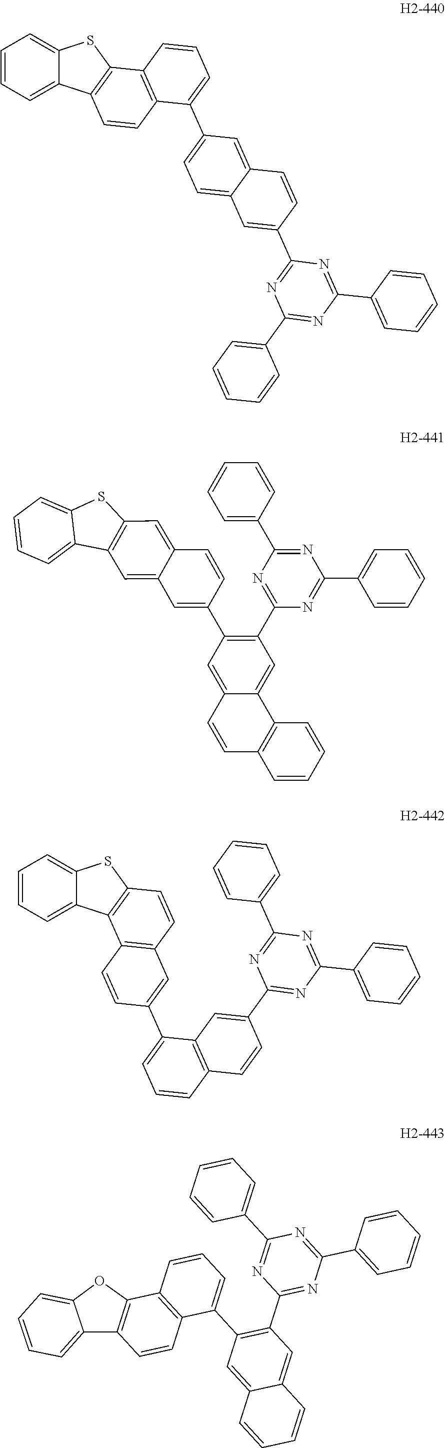 [SMILES: c1ccc(-c2nc(-c3ccccc3)nc(-c3ccc4cc(-c5cccc6c5ccc5c7ccccc7sc65)ccc4c3)n2)cc1 ; c1ccc(-c2nc(-c3ccccc3)nc(-c3cc4c(ccc5ccccc54)cc3-c3ccc4cc5sc6ccccc6c5cc4c3)n2)cc1 ; c1ccc(-c2nc(-c3ccccc3)nc(-c3ccc4cccc(-c5ccc6c(ccc7sc8ccccc8c76)c5)c4c3)n2)cc1 ; c1ccc(-c2nc(-c3ccccc3)nc(-c3cc4ccccc4cc3-c3cccc4c3ccc3c5ccccc5oc43)n2)cc1]

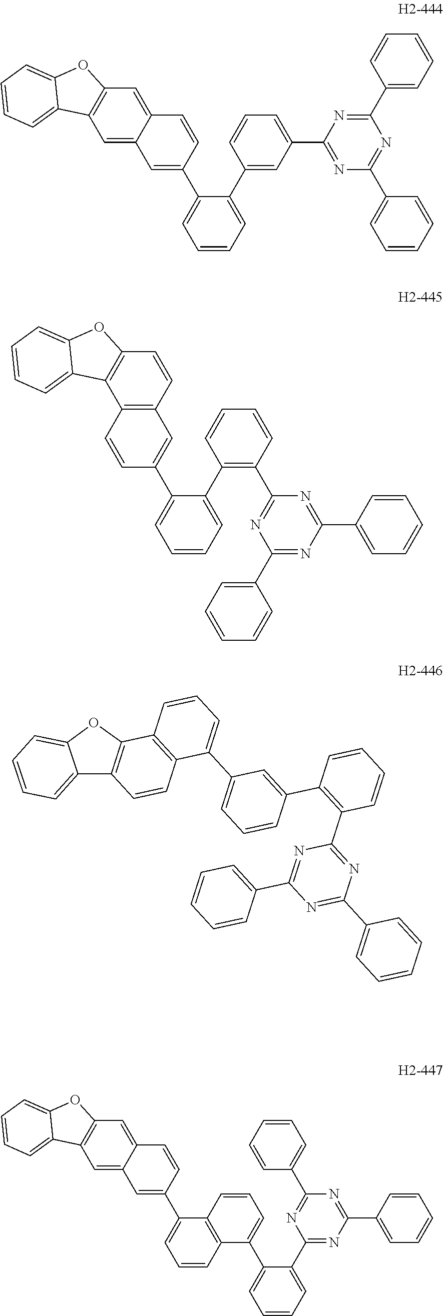 [SMILES: c1ccc(-c2nc(-c3ccccc3)nc(-c3cccc(-c4ccccc4-c4ccc5cc6oc7ccccc7c6cc5c4)c3)n2)cc1 ; c1ccc(-c2nc(-c3ccccc3)nc(-c3ccccc3-c3ccccc3-c3ccc4c(ccc5oc6ccccc6c54)c3)n2)cc1 ; c1ccc(-c2nc(-c3ccccc3)nc(-c3ccccc3-c3cccc(-c4cccc5c4ccc4c6ccccc6oc54)c3)n2)cc1 ; c1ccc(-c2nc(-c3ccccc3)nc(-c3ccccc3-c3cccc4c(-c5ccc6cc7oc8ccccc8c7cc6c5)cccc34)n2)cc1]

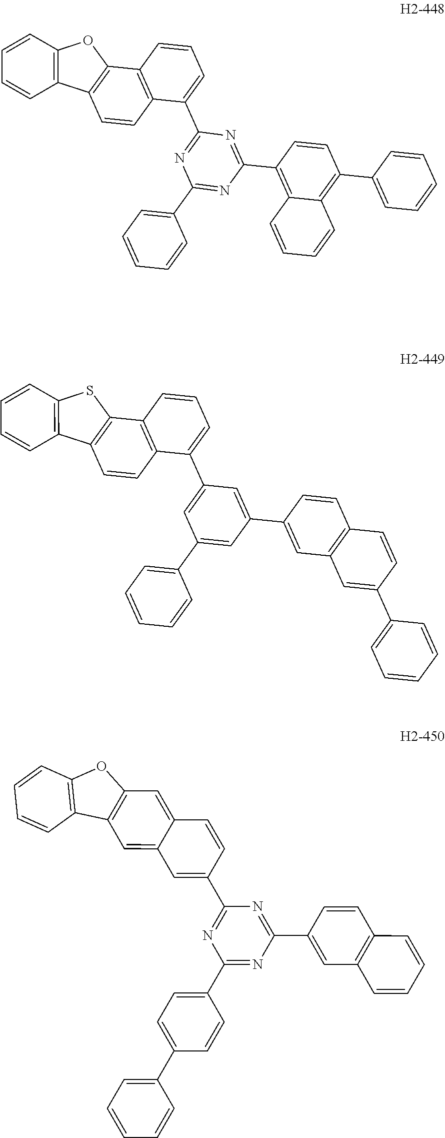 [SMILES: c1ccc(-c2nc(-c3ccc(-c4ccccc4)c4ccccc34)nc(-c3cccc4c3ccc3c5ccccc5oc43)n2)cc1 ; c1ccc(-c2cc(-c3ccc4ccc(-c5ccccc5)cc4c3)cc(-c3cccc4c3ccc3c5ccccc5sc43)c2)cc1 ; c1ccc(-c2ccc(-c3nc(-c4ccc5ccccc5c4)nc(-c4ccc5cc6oc7ccccc7c6cc5c4)n3)cc2)cc1]

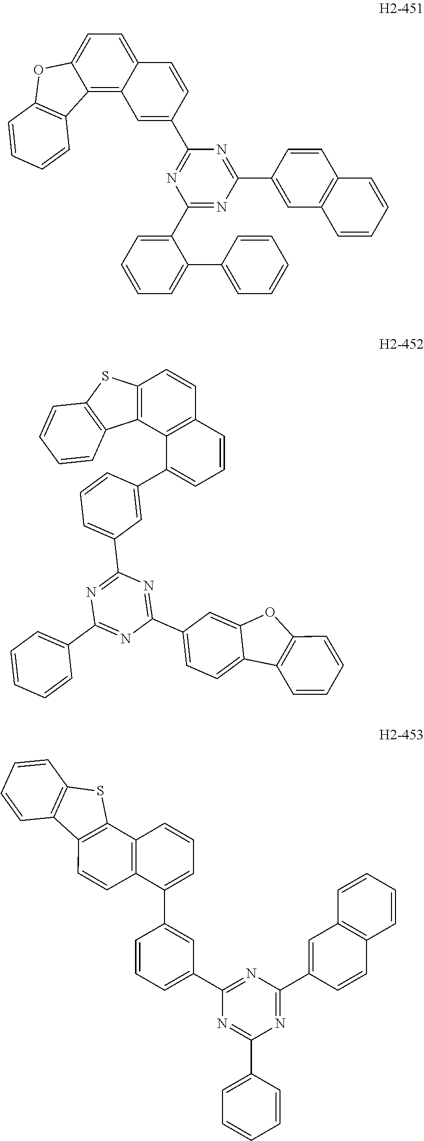 [SMILES: c1ccc(-c2ccccc2-c2nc(-c3ccc4ccccc4c3)nc(-c3ccc4ccc5oc6ccccc6c5c4c3)n2)cc1 ; c1ccc(-c2nc(-c3cccc(-c4cccc5ccc6sc7ccccc7c6c45)c3)nc(-c3ccc4c(c3)oc3ccccc34)n2)cc1 ; c1ccc(-c2nc(-c3cccc(-c4cccc5c4ccc4c6ccccc6sc54)c3)nc(-c3ccc4ccccc4c3)n2)cc1]

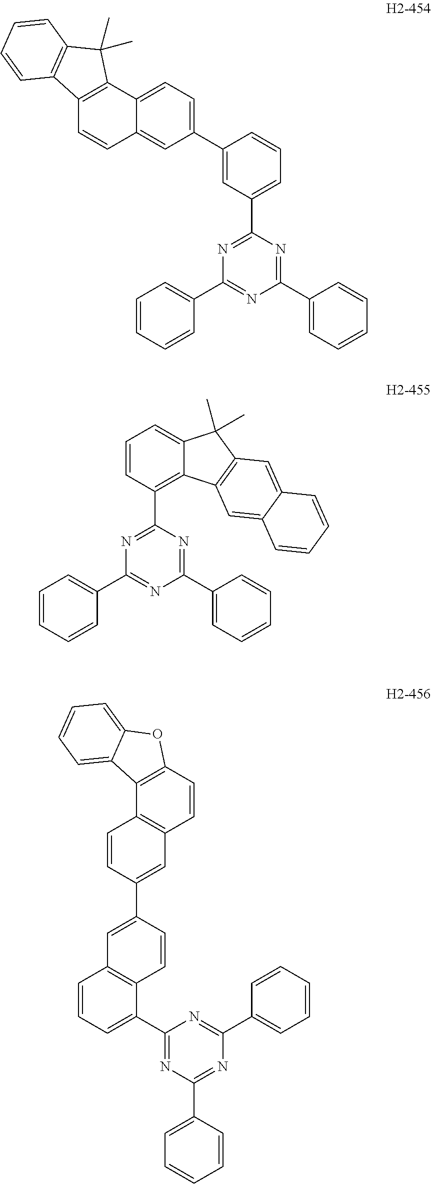 [SMILES: CC1(C)c2ccccc2-c2ccc3cc(-c4cccc(-c5nc(-c6ccccc6)nc(-c6ccccc6)n5)c4)ccc3c21 ; CC1(C)c2cc3ccccc3cc2-c2c(-c3nc(-c4ccccc4)nc(-c4ccccc4)n3)cccc21 ; c1ccc(-c2nc(-c3ccccc3)nc(-c3cccc4cc(-c5ccc6c(ccc7oc8ccccc8c76)c5)ccc34)n2)cc1]

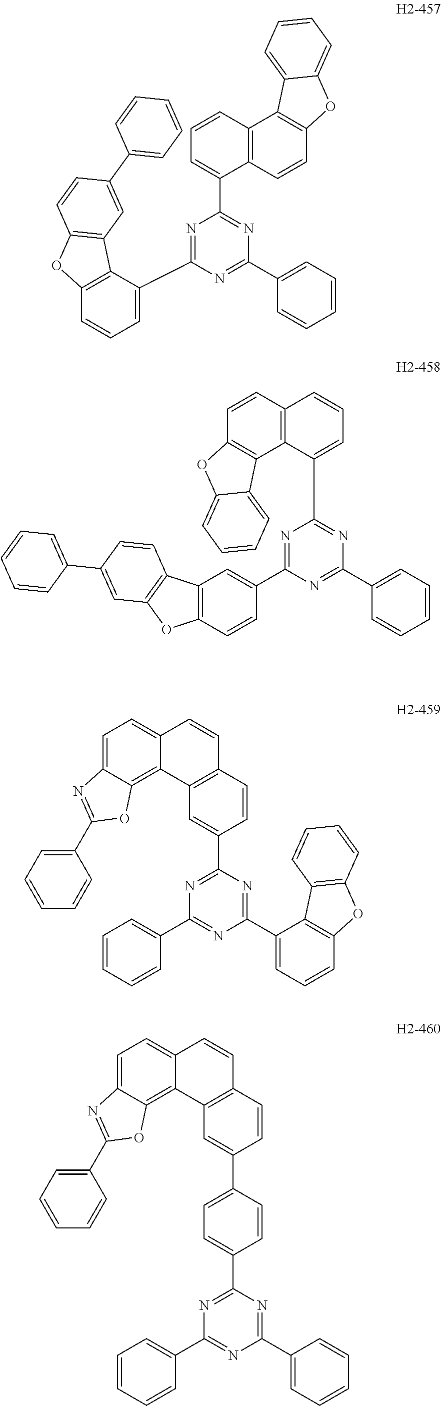 [SMILES: c1ccc(-c2ccc3oc4cccc(-c5nc(-c6ccccc6)nc(-c6cccc7c6ccc6oc8ccccc8c67)n5)c4c3c2)cc1 ; c1ccc(-c2ccc3c(c2)oc2ccc(-c4nc(-c5ccccc5)nc(-c5cccc6ccc7oc8ccccc8c7c56)n4)cc23)cc1 ; c1ccc(-c2nc(-c3ccc4ccc5ccc6nc(-c7ccccc7)oc6c5c4c3)nc(-c3cccc4oc5ccccc5c34)n2)cc1 ; c1ccc(-c2nc(-c3ccccc3)nc(-c3ccc(-c4ccc5ccc6ccc7nc(-c8ccccc8)oc7c6c5c4)cc3)n2)cc1]

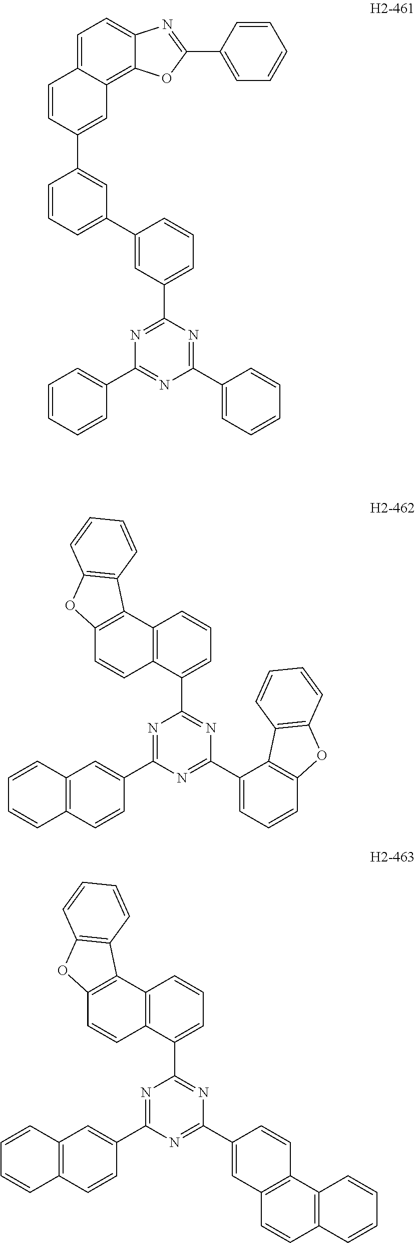 [SMILES: c1ccc(-c2nc(-c3ccccc3)nc(-c3cccc(-c4cccc(-c5ccc6ccc7nc(-c8ccccc8)oc7c6c5)c4)c3)n2)cc1 ; c1ccc2cc(-c3nc(-c4cccc5c4ccc4oc6ccccc6c45)nc(-c4cccc5oc6ccccc6c45)n3)ccc2c1 ; c1ccc2cc(-c3nc(-c4ccc5c(ccc6ccccc65)c4)nc(-c4cccc5c4ccc4oc6ccccc6c45)n3)ccc2c1]

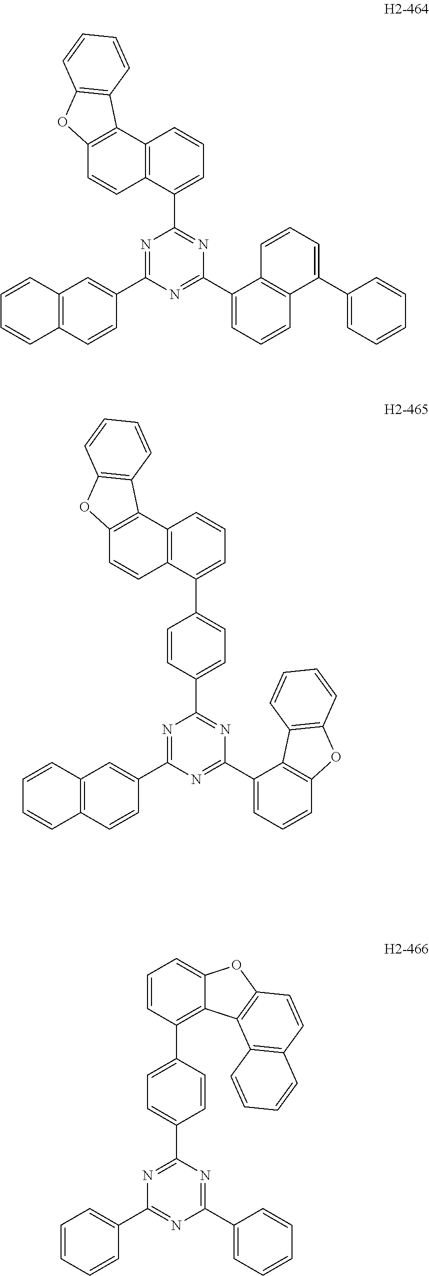 [SMILES: c1ccc(-c2cccc3c(-c4nc(-c5ccc6ccccc6c5)nc(-c5cccc6c5ccc5oc7ccccc7c56)n4)cccc23)cc1 ; c1ccc2cc(-c3nc(-c4ccc(-c5cccc6c5ccc5oc7ccccc7c56)cc4)nc(-c4cccc5oc6ccccc6c45)n3)ccc2c1 ; c1ccc(-c2nc(-c3ccccc3)nc(-c3ccc(-c4cccc5oc6ccc7ccccc7c6c45)cc3)n2)cc1]

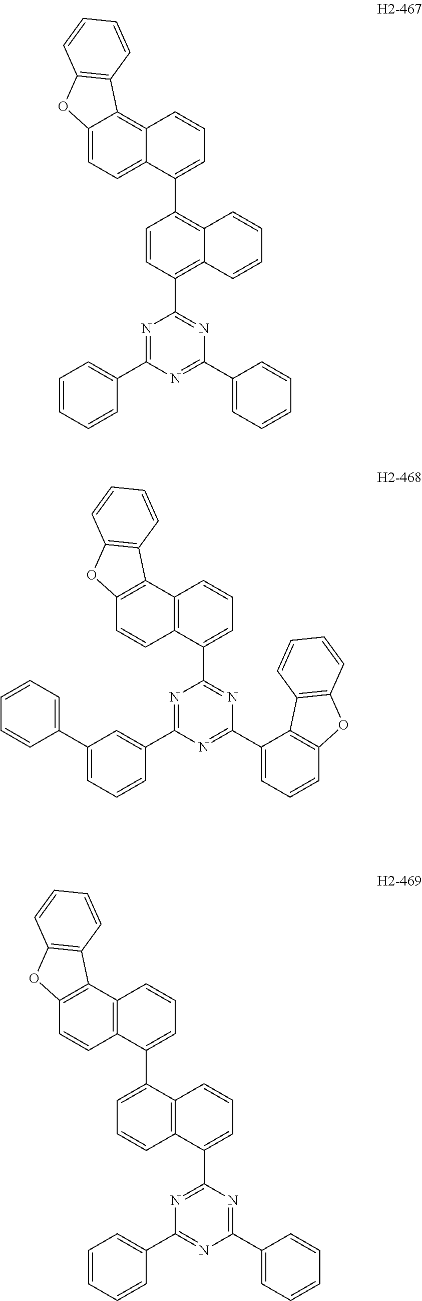 [SMILES: c1ccc(-c2nc(-c3ccccc3)nc(-c3ccc(-c4cccc5c4ccc4oc6ccccc6c45)c4ccccc34)n2)cc1 ; c1ccc(-c2cccc(-c3nc(-c4cccc5c4ccc4oc6ccccc6c45)nc(-c4cccc5oc6ccccc6c45)n3)c2)cc1 ; c1ccc(-c2nc(-c3ccccc3)nc(-c3cccc4c(-c5cccc6c5ccc5oc7ccccc7c56)cccc34)n2)cc1]

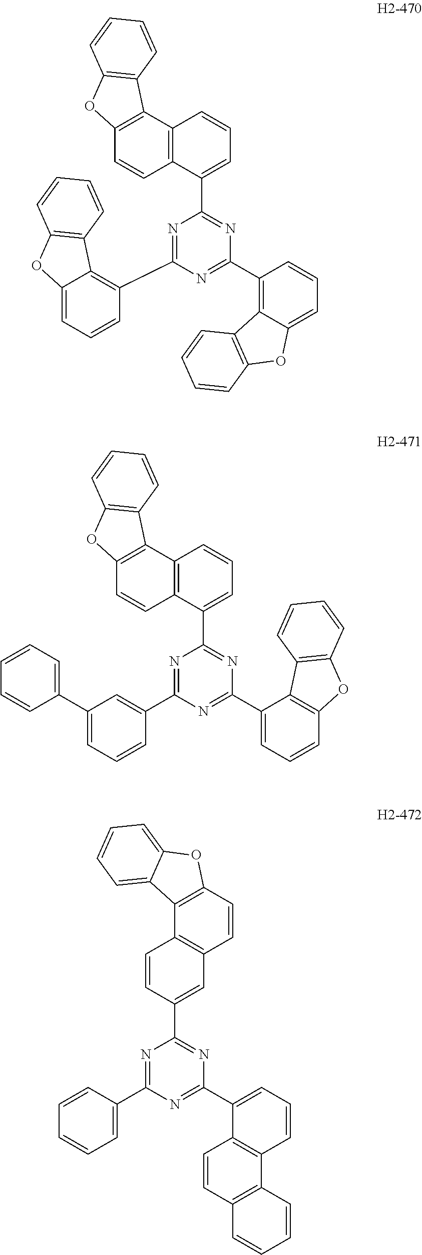 [SMILES: c1ccc2c(c1)oc1cccc(-c3nc(-c4cccc5c4ccc4oc6ccccc6c45)nc(-c4cccc5oc6ccccc6c45)n3)c12 ; c1ccc(-c2cccc(-c3nc(-c4cccc5c4ccc4oc6ccccc6c45)nc(-c4cccc5oc6ccccc6c45)n3)c2)cc1 ; c1ccc(-c2nc(-c3ccc4c(ccc5oc6ccccc6c54)c3)nc(-c3cccc4c3ccc3ccccc34)n2)cc1]

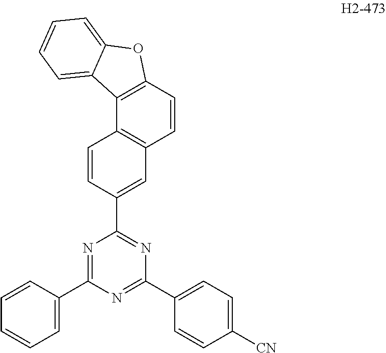 [SMILES: N#Cc1ccc(-c2nc(-c3ccccc3)nc(-c3ccc4c(ccc5oc6ccccc6c54)c3)n2)cc1]

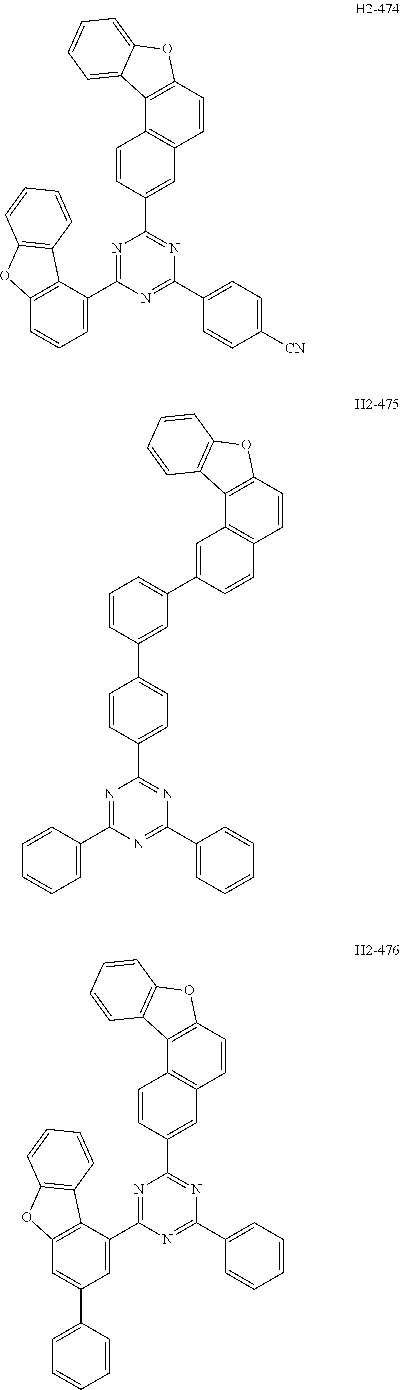 [SMILES: N#Cc1ccc(-c2nc(-c3ccc4c(ccc5oc6ccccc6c54)c3)nc(-c3cccc4oc5ccccc5c34)n2)cc1 ; c1ccc(-c2nc(-c3ccccc3)nc(-c3ccc(-c4cccc(-c5ccc6ccc7oc8ccccc8c7c6c5)c4)cc3)n2)cc1 ; c1ccc(-c2cc(-c3nc(-c4ccccc4)nc(-c4ccc5c(ccc6oc7ccccc7c65)c4)n3)c3c(c2)oc2ccccc23)cc1]

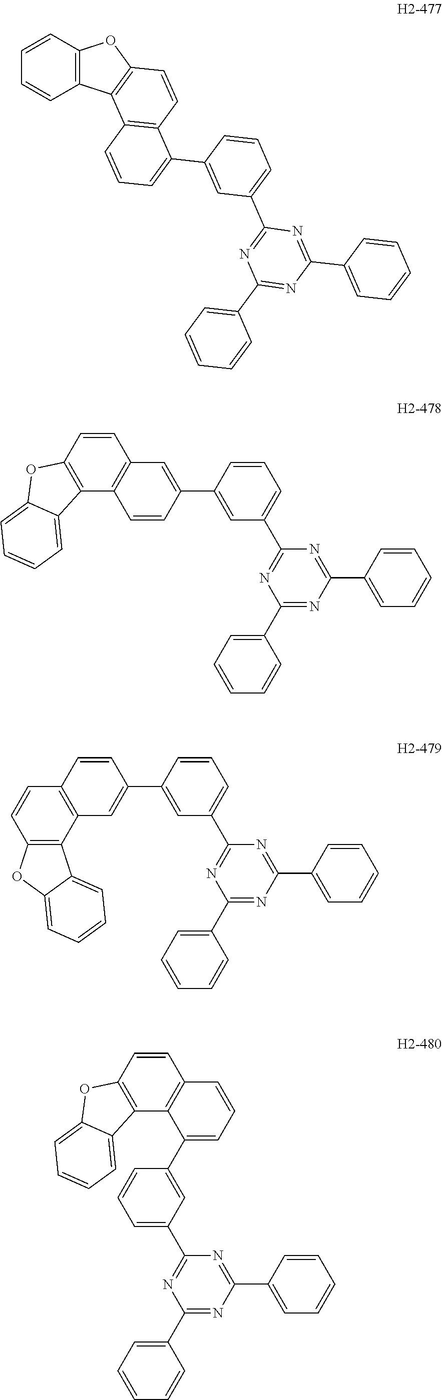 [SMILES: c1ccc(-c2nc(-c3ccccc3)nc(-c3cccc(-c4cccc5c4ccc4oc6ccccc6c45)c3)n2)cc1 ; c1ccc(-c2nc(-c3ccccc3)nc(-c3cccc(-c4ccc5c(ccc6oc7ccccc7c65)c4)c3)n2)cc1 ; c1ccc(-c2nc(-c3ccccc3)nc(-c3cccc(-c4ccc5ccc6oc7ccccc7c6c5c4)c3)n2)cc1 ; c1ccc(-c2nc(-c3ccccc3)nc(-c3cccc(-c4cccc5ccc6oc7ccccc7c6c45)c3)n2)cc1]

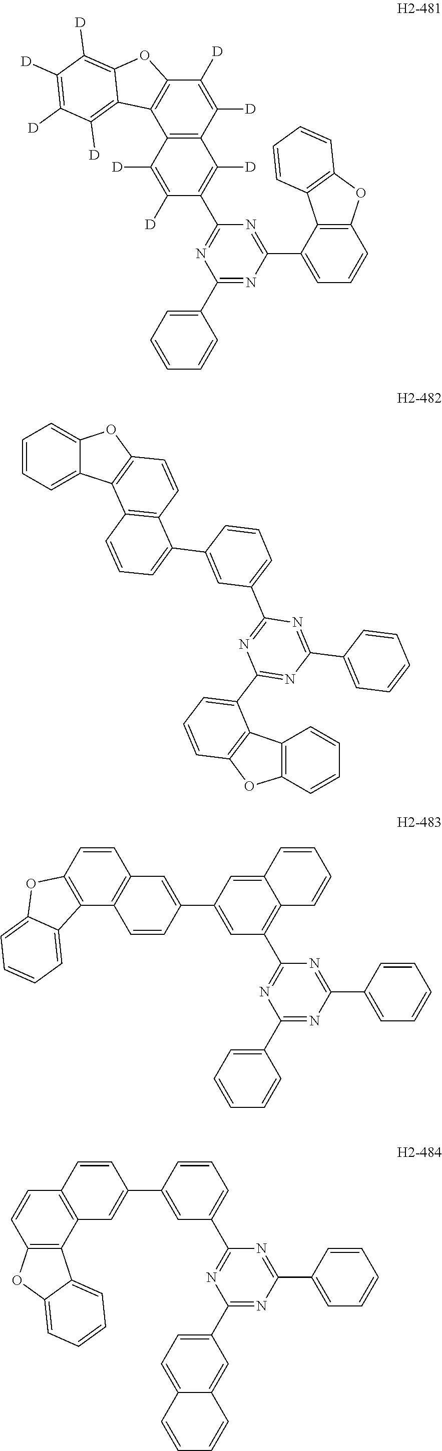 [SMILES: [2H]c1c([2H])c([2H])c2c(oc3c([2H])c([2H])c4c([2H])c(-c5nc(-c6ccccc6)nc(-c6cccc7oc8ccccc8c67)n5)c([2H])c([2H])c4c32)c1[2H] ; c1ccc(-c2nc(-c3cccc(-c4cccc5c4ccc4oc6ccccc6c45)c3)nc(-c3cccc4oc5ccccc5c34)n2)cc1 ; c1ccc(-c2nc(-c3ccccc3)nc(-c3cc(-c4ccc5c(ccc6oc7ccccc7c65)c4)cc4ccccc34)n2)cc1 ; c1ccc(-c2nc(-c3cccc(-c4ccc5ccc6oc7ccccc7c6c5c4)c3)nc(-c3ccc4ccccc4c3)n2)cc1]

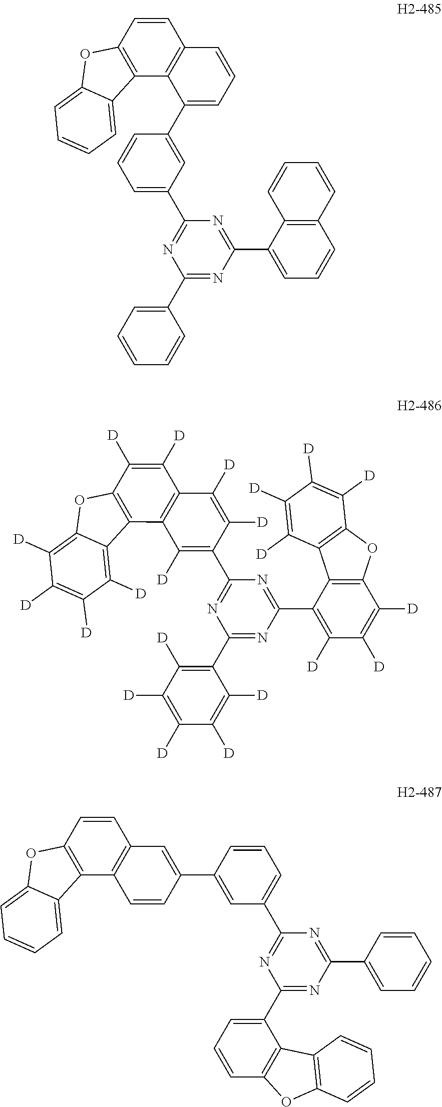 [SMILES: c1ccc(-c2nc(-c3cccc(-c4cccc5ccc6oc7ccccc7c6c45)c3)nc(-c3cccc4ccccc34)n2)cc1 ; [2H]c1c([2H])c([2H])c(-c2nc(-c3c([2H])c([2H])c4c([2H])c([2H])c5oc6c([2H])c([2H])c([2H])c([2H])c6c5c4c3[2H])nc(-c3c([2H])c([2H])c([2H])c4oc5c([2H])c([2H])c([2H])c([2H])c5c34)n2)c([2H])c1[2H] ; c1ccc(-c2nc(-c3cccc(-c4ccc5c(ccc6oc7ccccc7c65)c4)c3)nc(-c3cccc4oc5ccccc5c34)n2)cc1]

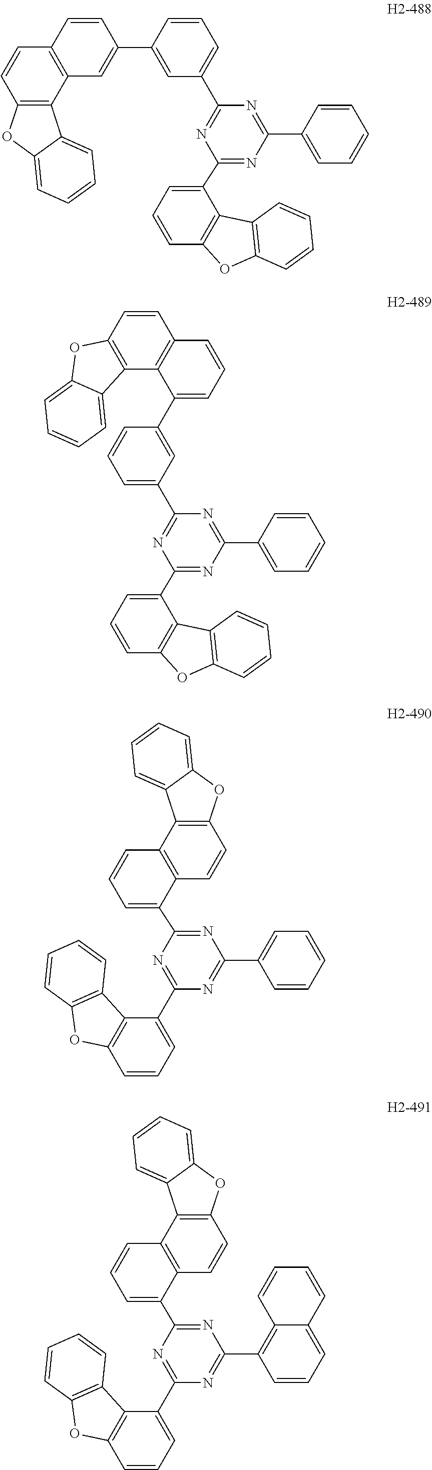

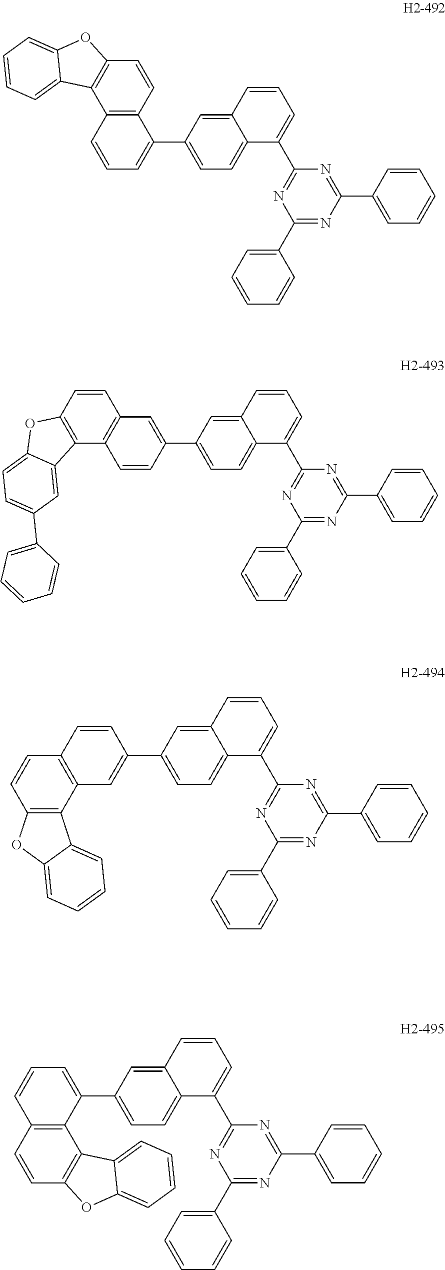 [SMILES: c1ccc(-c2nc(-c3ccccc3)nc(-c3cccc4cc(-c5cccc6c5ccc5oc7ccccc7c56)ccc34)n2)cc1 ; c1ccc(-c2ccc3oc4ccc5cc(-c6ccc7c(-c8nc(-c9ccccc9)nc(-c9ccccc9)n8)cccc7c6)ccc5c4c3c2)cc1 ; c1ccc(-c2nc(-c3ccccc3)nc(-c3cccc4cc(-c5ccc6ccc7oc8ccccc8c7c6c5)ccc34)n2)cc1 ; c1ccc(-c2nc(-c3ccccc3)nc(-c3cccc4cc(-c5cccc6ccc7oc8ccccc8c7c56)ccc34)n2)cc1]

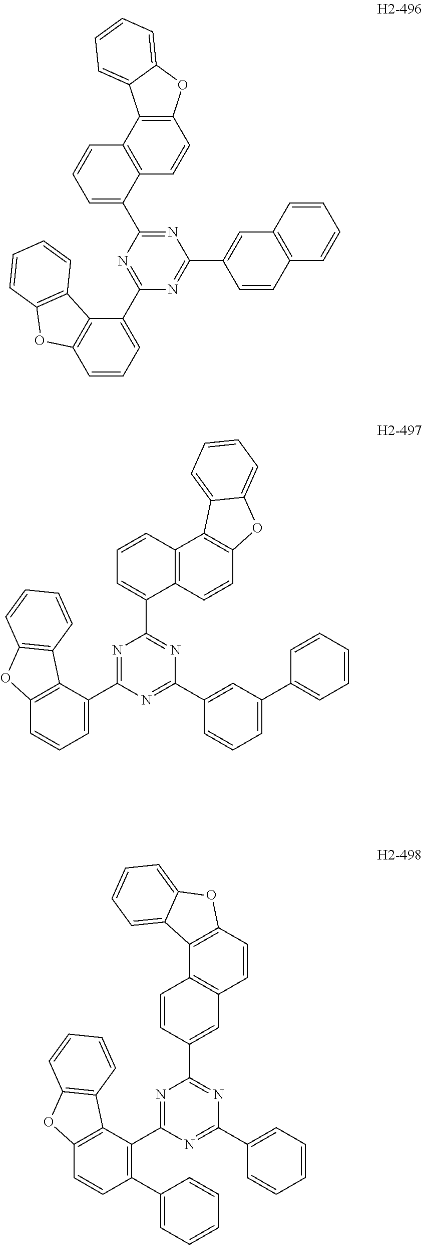 [SMILES: c1ccc2cc(-c3nc(-c4cccc5c4ccc4oc6ccccc6c45)nc(-c4cccc5oc6ccccc6c45)n3)ccc2c1 ; c1ccc(-c2cccc(-c3nc(-c4cccc5c4ccc4oc6ccccc6c45)nc(-c4cccc5oc6ccccc6c45)n3)c2)cc1 ; c1ccc(-c2nc(-c3ccc4c(ccc5oc6ccccc6c54)c3)nc(-c3c(-c4ccccc4)ccc4oc5ccccc5c34)n2)cc1]

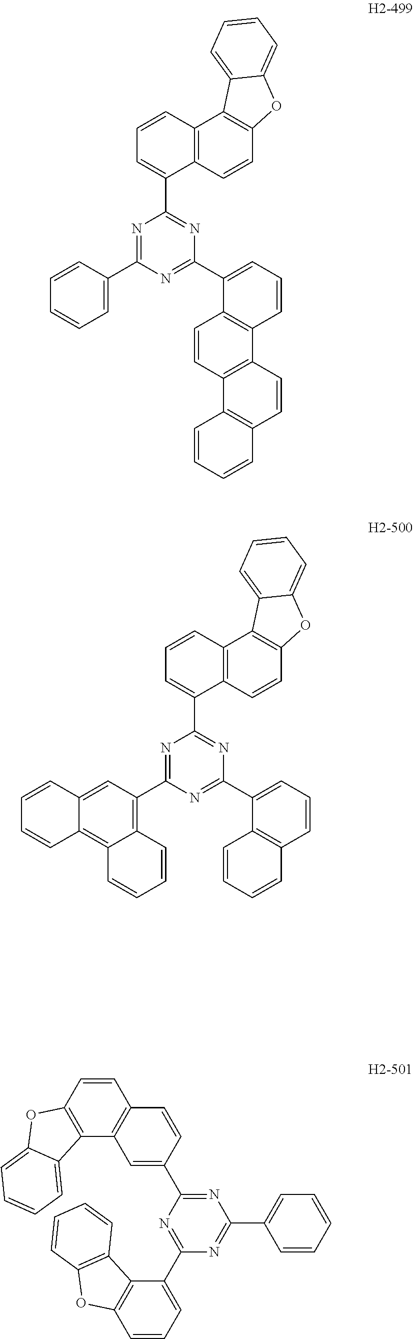 [SMILES: c1ccc(-c2nc(-c3cccc4c3ccc3c5ccccc5ccc43)nc(-c3cccc4c3ccc3oc5ccccc5c34)n2)cc1 ; c1ccc2c(-c3nc(-c4cc5ccccc5c5ccccc45)nc(-c4cccc5c4ccc4oc6ccccc6c45)n3)cccc2c1 ; c1ccc(-c2nc(-c3ccc4ccc5oc6ccccc6c5c4c3)nc(-c3cccc4oc5ccccc5c34)n2)cc1]

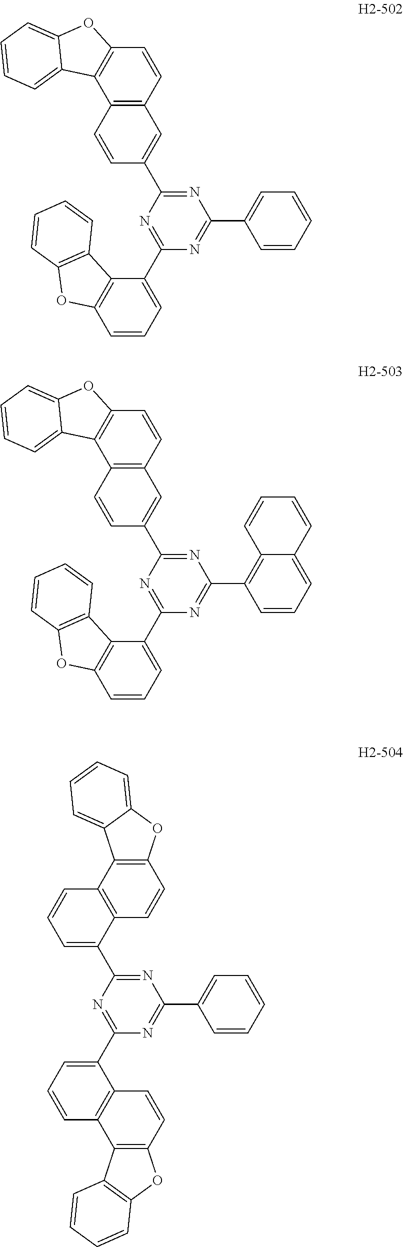 [SMILES: c1ccc(-c2nc(-c3ccc4c(ccc5oc6ccccc6c54)c3)nc(-c3cccc4oc5ccccc5c34)n2)cc1 ; c1ccc2c(-c3nc(-c4ccc5c(ccc6oc7ccccc7c65)c4)nc(-c4cccc5oc6ccccc6c45)n3)cccc2c1 ; c1ccc(-c2nc(-c3cccc4c3ccc3oc5ccccc5c34)nc(-c3cccc4c3ccc3oc5ccccc5c34)n2)cc1]

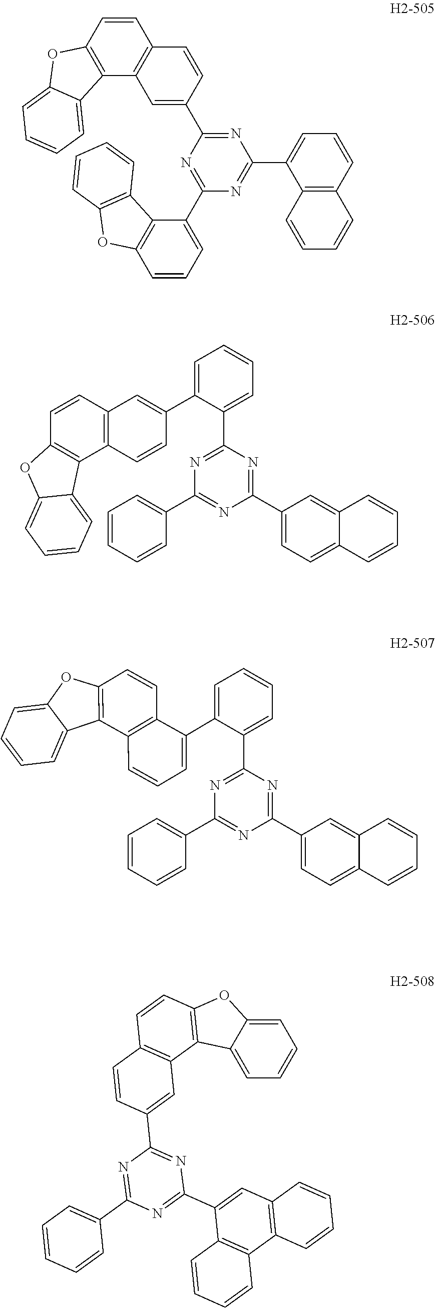 [SMILES: c1ccc2c(-c3nc(-c4ccc5ccc6oc7ccccc7c6c5c4)nc(-c4cccc5oc6ccccc6c45)n3)cccc2c1 ; c1ccc(-c2nc(-c3ccc4ccccc4c3)nc(-c3ccccc3-c3ccc4c(ccc5oc6ccccc6c54)c3)n2)cc1 ; c1ccc(-c2nc(-c3ccc4ccccc4c3)nc(-c3ccccc3-c3cccc4c3ccc3oc5ccccc5c34)n2)cc1 ; c1ccc(-c2nc(-c3ccc4ccc5oc6ccccc6c5c4c3)nc(-c3cc4ccccc4c4ccccc34)n2)cc1]

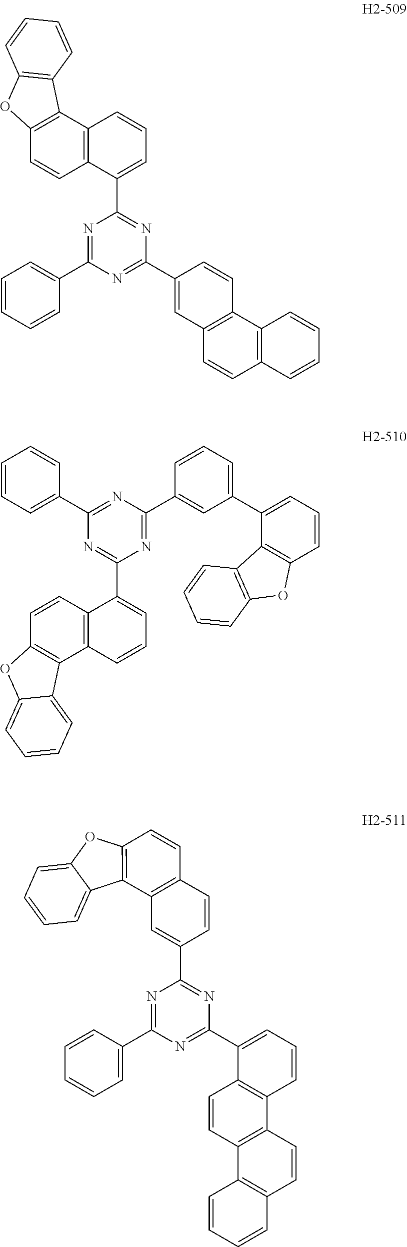 [SMILES: c1ccc(-c2nc(-c3ccc4c(ccc5ccccc54)c3)nc(-c3cccc4c3ccc3oc5ccccc5c34)n2)cc1 ; c1ccc(-c2nc(-c3cccc(-c4cccc5oc6ccccc6c45)c3)nc(-c3cccc4c3ccc3oc5ccccc5c34)n2)cc1 ; c1ccc(-c2nc(-c3ccc4ccc5oc6ccccc6c5c4c3)nc(-c3cccc4c3ccc3c5ccccc5ccc43)n2)cc1]

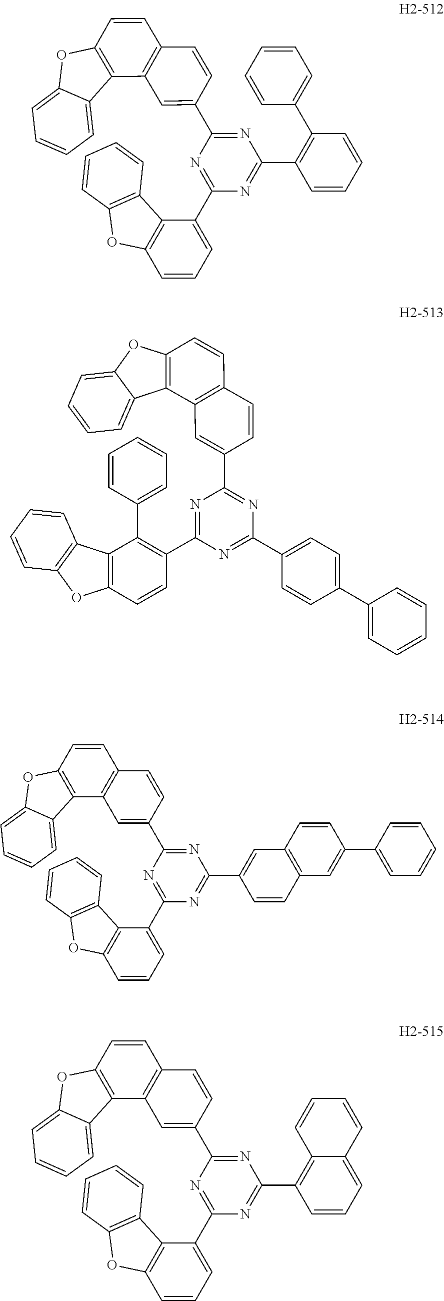 [SMILES: c1ccc(-c2ccccc2-c2nc(-c3ccc4ccc5oc6ccccc6c5c4c3)nc(-c3cccc4oc5ccccc5c34)n2)cc1 ; c1ccc(-c2ccc(-c3nc(-c4ccc5ccc6oc7ccccc7c6c5c4)nc(-c4ccc5oc6ccccc6c5c4-c4ccccc4)n3)cc2)cc1 ; c1ccc(-c2ccc3cc(-c4nc(-c5ccc6ccc7oc8ccccc8c7c6c5)nc(-c5cccc6oc7ccccc7c56)n4)ccc3c2)cc1 ; c1ccc2c(-c3nc(-c4ccc5ccc6oc7ccccc7c6c5c4)nc(-c4cccc5oc6ccccc6c45)n3)cccc2c1]

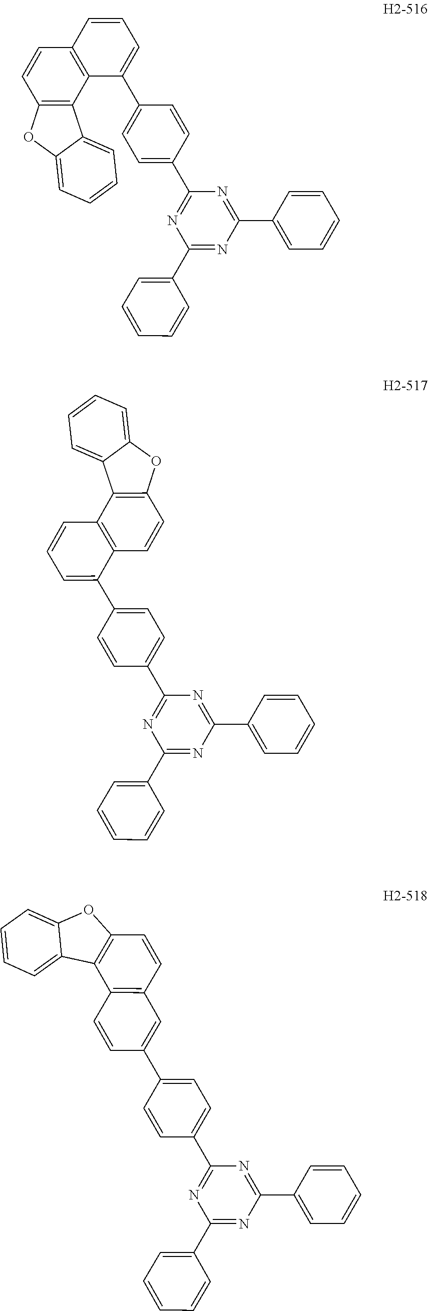 [SMILES: c1ccc(-c2nc(-c3ccccc3)nc(-c3ccc(-c4cccc5ccc6oc7ccccc7c6c45)cc3)n2)cc1 ; c1ccc(-c2nc(-c3ccccc3)nc(-c3ccc(-c4cccc5c4ccc4oc6ccccc6c45)cc3)n2)cc1 ; c1ccc(-c2nc(-c3ccccc3)nc(-c3ccc(-c4ccc5c(ccc6oc7ccccc7c65)c4)cc3)n2)cc1]

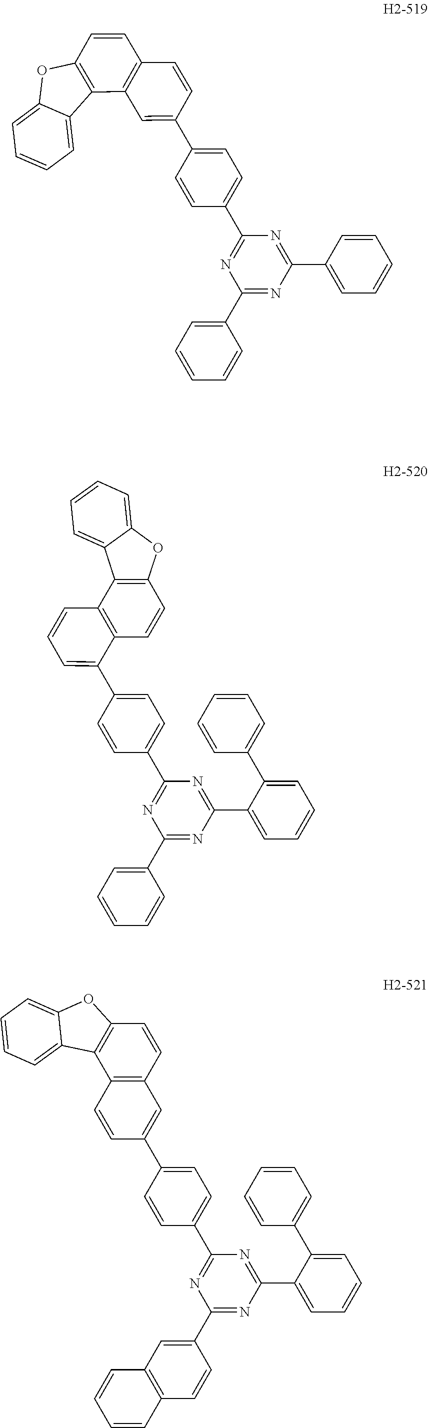 [SMILES: c1ccc(-c2nc(-c3ccccc3)nc(-c3ccc(-c4ccc5ccc6oc7ccccc7c6c5c4)cc3)n2)cc1 ; c1ccc(-c2nc(-c3ccc(-c4cccc5c4ccc4oc6ccccc6c45)cc3)nc(-c3ccccc3-c3ccccc3)n2)cc1 ; c1ccc(-c2ccccc2-c2nc(-c3ccc(-c4ccc5c(ccc6oc7ccccc7c65)c4)cc3)nc(-c3ccc4ccccc4c3)n2)cc1]

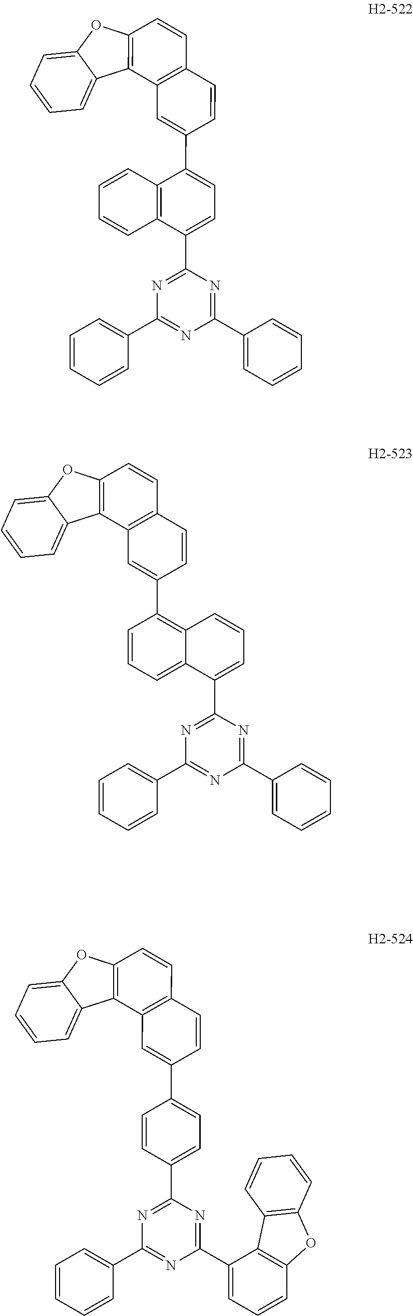 [SMILES: c1ccc(-c2nc(-c3ccccc3)nc(-c3ccc(-c4ccc5ccc6oc7ccccc7c6c5c4)c4ccccc34)n2)cc1 ; c1ccc(-c2nc(-c3ccccc3)nc(-c3cccc4c(-c5ccc6ccc7oc8ccccc8c7c6c5)cccc34)n2)cc1 ; c1ccc(-c2nc(-c3ccc(-c4ccc5ccc6oc7ccccc7c6c5c4)cc3)nc(-c3cccc4oc5ccccc5c34)n2)cc1]

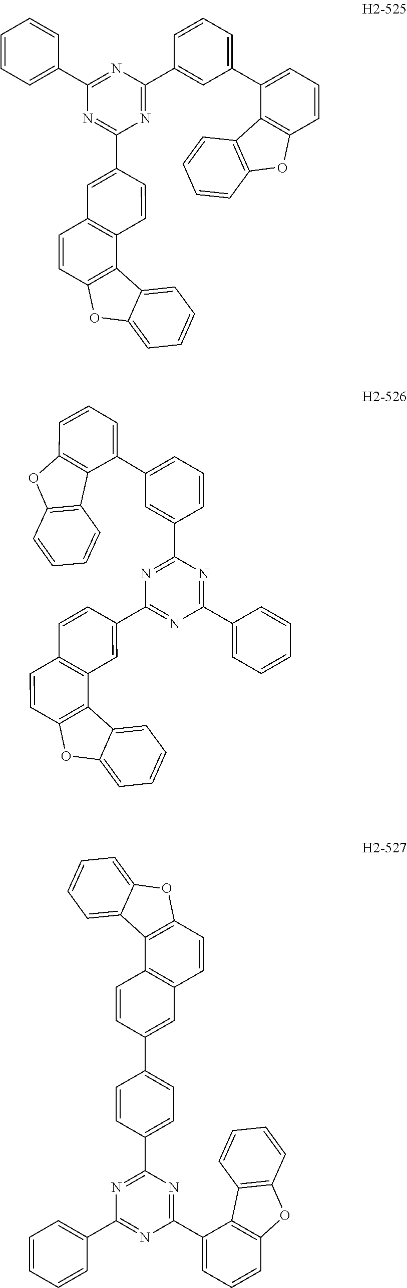 [SMILES: c1ccc(-c2nc(-c3cccc(-c4cccc5oc6ccccc6c45)c3)nc(-c3ccc4c(ccc5oc6ccccc6c54)c3)n2)cc1 ; c1ccc(-c2nc(-c3cccc(-c4cccc5oc6ccccc6c45)c3)nc(-c3ccc4ccc5oc6ccccc6c5c4c3)n2)cc1 ; c1ccc(-c2nc(-c3ccc(-c4ccc5c(ccc6oc7ccccc7c65)c4)cc3)nc(-c3cccc4oc5ccccc5c34)n2)cc1]

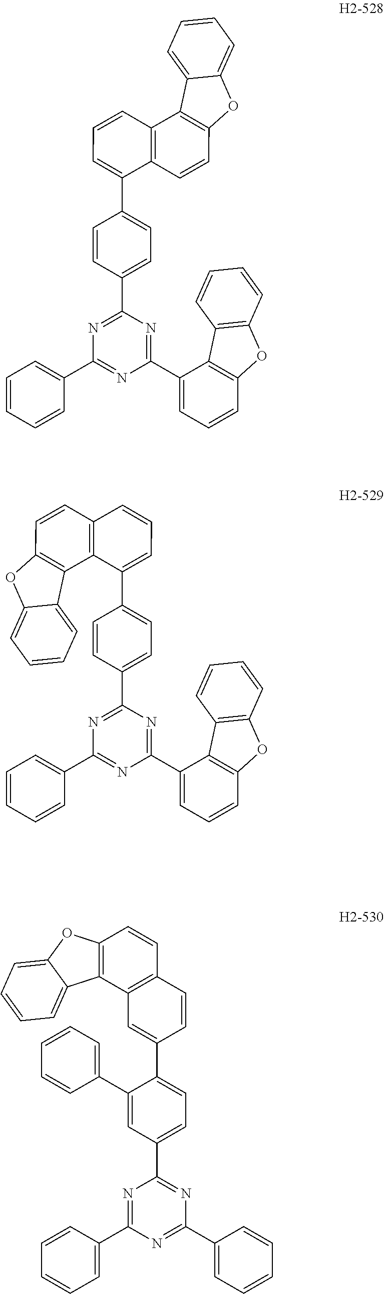 [SMILES: c1ccc(-c2nc(-c3ccc(-c4cccc5c4ccc4oc6ccccc6c45)cc3)nc(-c3cccc4oc5ccccc5c34)n2)cc1 ; c1ccc(-c2nc(-c3ccc(-c4cccc5ccc6oc7ccccc7c6c45)cc3)nc(-c3cccc4oc5ccccc5c34)n2)cc1 ; c1ccc(-c2nc(-c3ccccc3)nc(-c3ccc(-c4ccc5ccc6oc7ccccc7c6c5c4)c(-c4ccccc4)c3)n2)cc1]

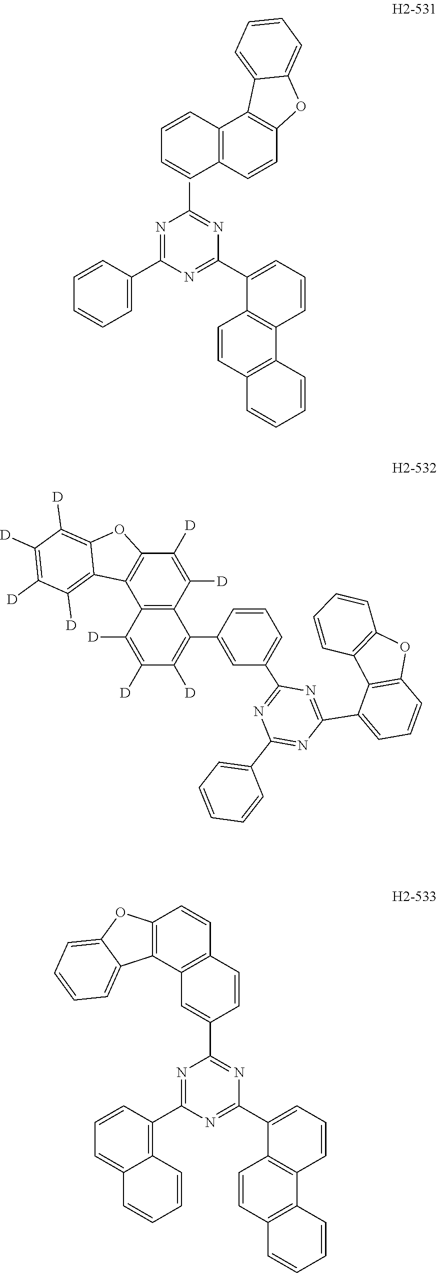

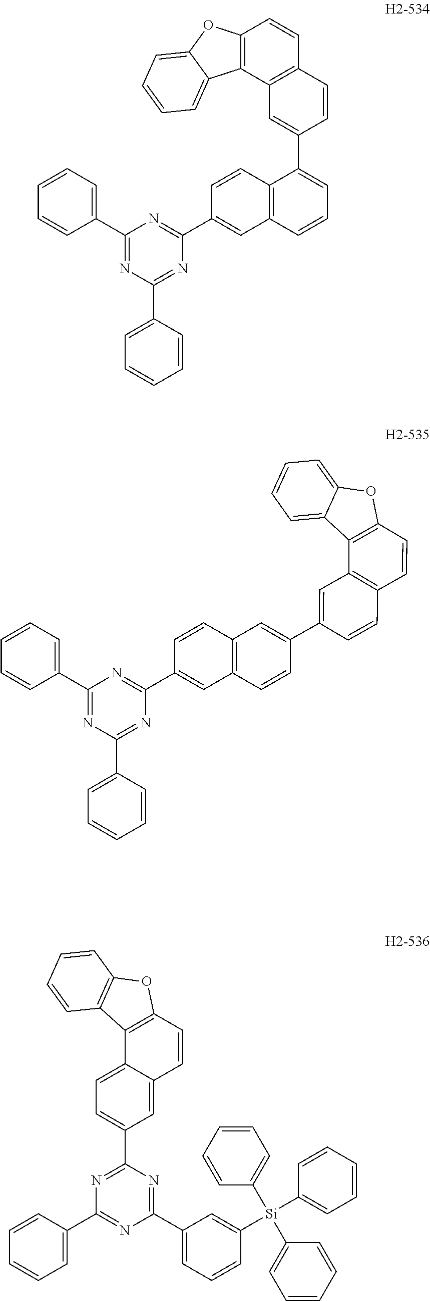 [SMILES: c1ccc(-c2nc(-c3ccccc3)nc(-c3ccc4c(-c5ccc6ccc7oc8ccccc8c7c6c5)cccc4c3)n2)cc1 ; c1ccc(-c2nc(-c3ccccc3)nc(-c3ccc4cc(-c5ccc6ccc7oc8ccccc8c7c6c5)ccc4c3)n2)cc1 ; c1ccc(-c2nc(-c3cccc([Si](c4ccccc4)(c4ccccc4)c4ccccc4)c3)nc(-c3ccc4c(ccc5oc6ccccc6c54)c3)n2)cc1]

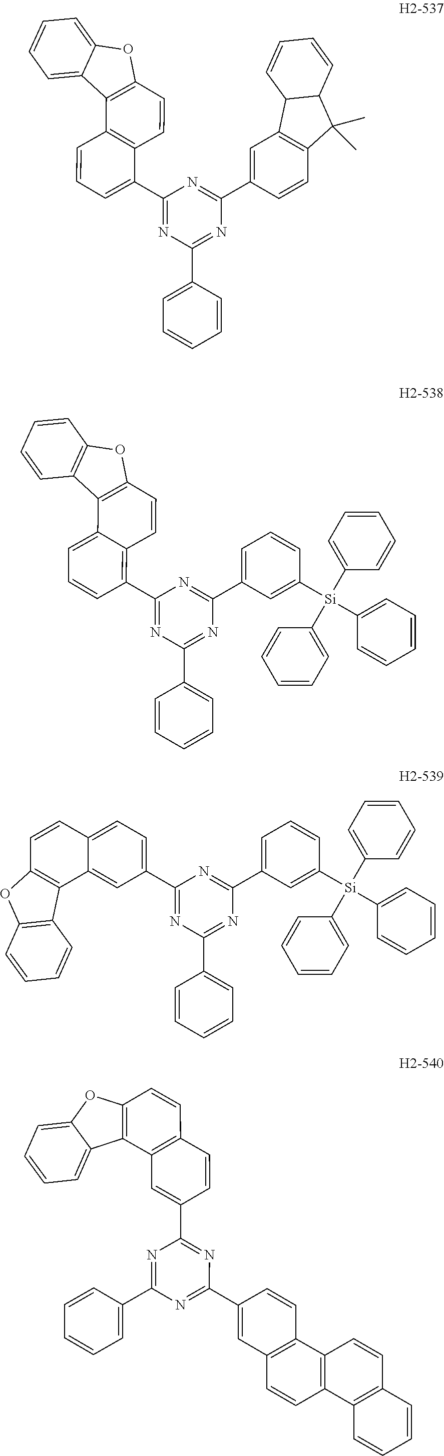 [SMILES: CC1(C)c2ccc(-c3nc(-c4ccccc4)nc(-c4cccc5c4ccc4oc6ccccc6c45)n3)cc2C2C=CC=CC21 ; c1ccc(-c2nc(-c3cccc([Si](c4ccccc4)(c4ccccc4)c4ccccc4)c3)nc(-c3cccc4c3ccc3oc5ccccc5c34)n2)cc1 ; c1ccc(-c2nc(-c3cccc([Si](c4ccccc4)(c4ccccc4)c4ccccc4)c3)nc(-c3ccc4ccc5oc6ccccc6c5c4c3)n2)cc1 ; c1ccc(-c2nc(-c3ccc4c(ccc5c6ccccc6ccc45)c3)nc(-c3ccc4ccc5oc6ccccc6c5c4c3)n2)cc1]

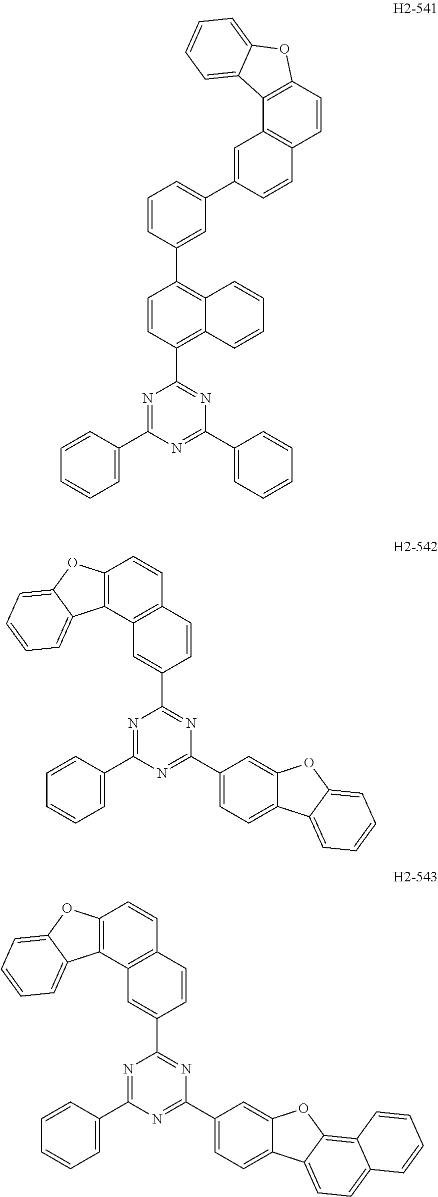 [SMILES: c1ccc(-c2nc(-c3ccccc3)nc(-c3ccc(-c4cccc(-c5ccc6ccc7oc8ccccc8c7c6c5)c4)c4ccccc34)n2)cc1 ; c1ccc(-c2nc(-c3ccc4c(c3)oc3ccccc34)nc(-c3ccc4ccc5oc6ccccc6c5c4c3)n2)cc1 ; c1ccc(-c2nc(-c3ccc4c(c3)oc3c5ccccc5ccc43)nc(-c3ccc4ccc5oc6ccccc6c5c4c3)n2)cc1]

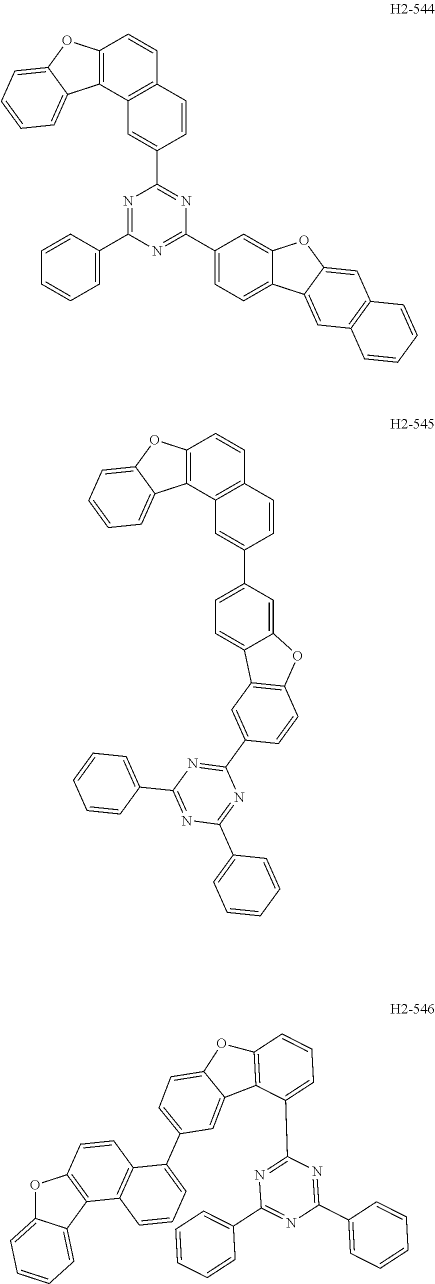 [SMILES: c1ccc(-c2nc(-c3ccc4c(c3)oc3cc5ccccc5cc34)nc(-c3ccc4ccc5oc6ccccc6c5c4c3)n2)cc1 ; c1ccc(-c2nc(-c3ccccc3)nc(-c3ccc4oc5cc(-c6ccc7ccc8oc9ccccc9c8c7c6)ccc5c4c3)n2)cc1 ; c1ccc(-c2nc(-c3ccccc3)nc(-c3cccc4oc5ccc(-c6cccc7c6ccc6oc8ccccc8c67)cc5c34)n2)cc1]

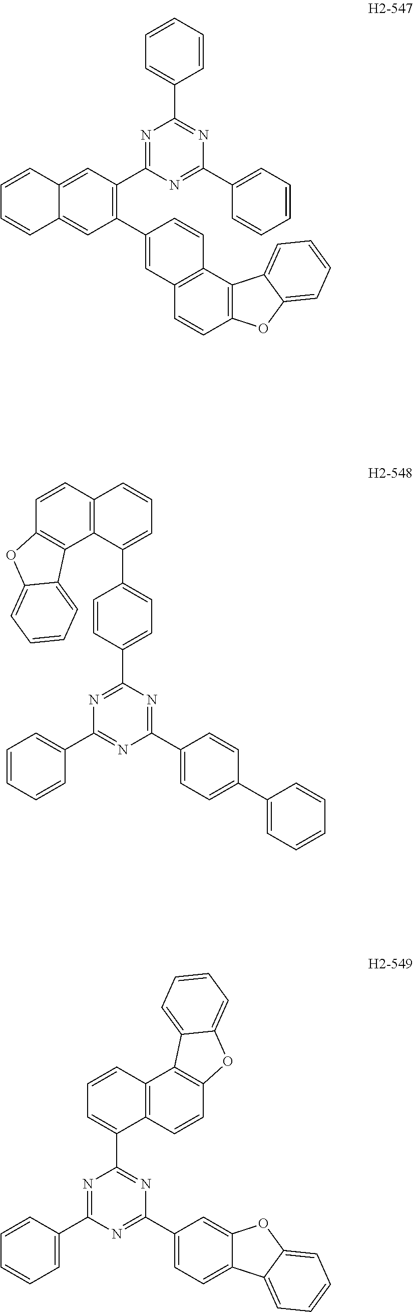 [SMILES: c1ccc(-c2nc(-c3ccccc3)nc(-c3cc4ccccc4cc3-c3ccc4c(ccc5oc6ccccc6c54)c3)n2)cc1 ; c1ccc(-c2ccc(-c3nc(-c4ccccc4)nc(-c4ccc(-c5cccc6ccc7oc8ccccc8c7c56)cc4)n3)cc2)cc1 ; c1ccc(-c2nc(-c3ccc4c(c3)oc3ccccc34)nc(-c3cccc4c3ccc3oc5ccccc5c34)n2)cc1]

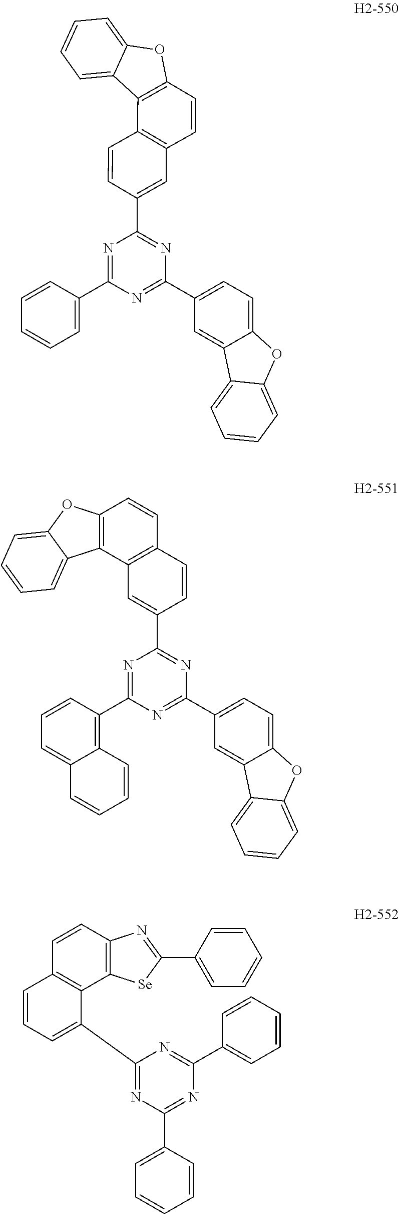 [SMILES: c1ccc(-c2nc(-c3ccc4c(ccc5oc6ccccc6c54)c3)nc(-c3ccc4oc5ccccc5c4c3)n2)cc1 ; c1ccc2c(-c3nc(-c4ccc5oc6ccccc6c5c4)nc(-c4ccc5ccc6oc7ccccc7c6c5c4)n3)cccc2c1 ; c1ccc(-c2nc(-c3ccccc3)nc(-c3cccc4ccc5nc(-c6ccccc6)[se]c5c34)n2)cc1]

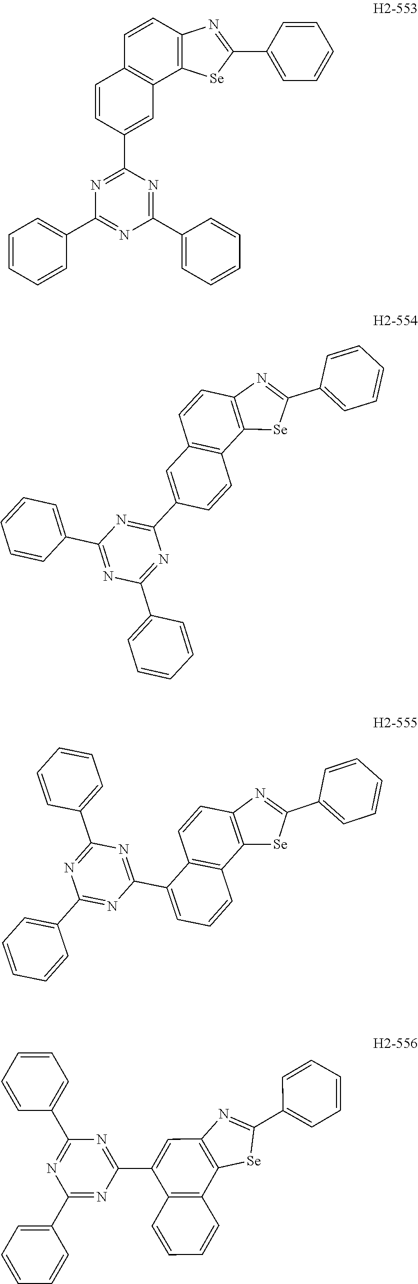 [SMILES: c1ccc(-c2nc(-c3ccccc3)nc(-c3ccc4ccc5nc(-c6ccccc6)[se]c5c4c3)n2)cc1 ; c1ccc(-c2nc(-c3ccccc3)nc(-c3ccc4c(ccc5nc(-c6ccccc6)[se]c54)c3)n2)cc1 ; c1ccc(-c2nc(-c3ccccc3)nc(-c3cccc4c3ccc3nc(-c5ccccc5)[se]c34)n2)cc1 ; c1ccc(-c2nc(-c3ccccc3)nc(-c3cc4nc(-c5ccccc5)[se]c4c4ccccc34)n2)cc1]

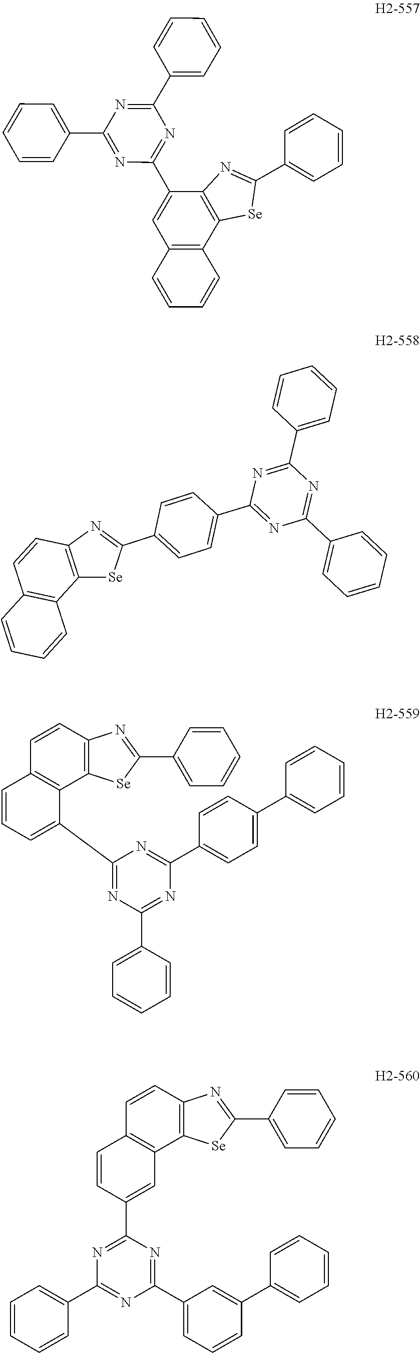 [SMILES: c1ccc(-c2nc(-c3ccccc3)nc(-c3cc4ccccc4c4[se]c(-c5ccccc5)nc34)n2)cc1 ; c1ccc(-c2nc(-c3ccccc3)nc(-c3ccc(-c4nc5ccc6ccccc6c5[se]4)cc3)n2)cc1 ; c1ccc(-c2ccc(-c3nc(-c4ccccc4)nc(-c4cccc5ccc6nc(-c7ccccc7)[se]c6c45)n3)cc2)cc1 ; c1ccc(-c2cccc(-c3nc(-c4ccccc4)nc(-c4ccc5ccc6nc(-c7ccccc7)[se]c6c5c4)n3)c2)cc1]

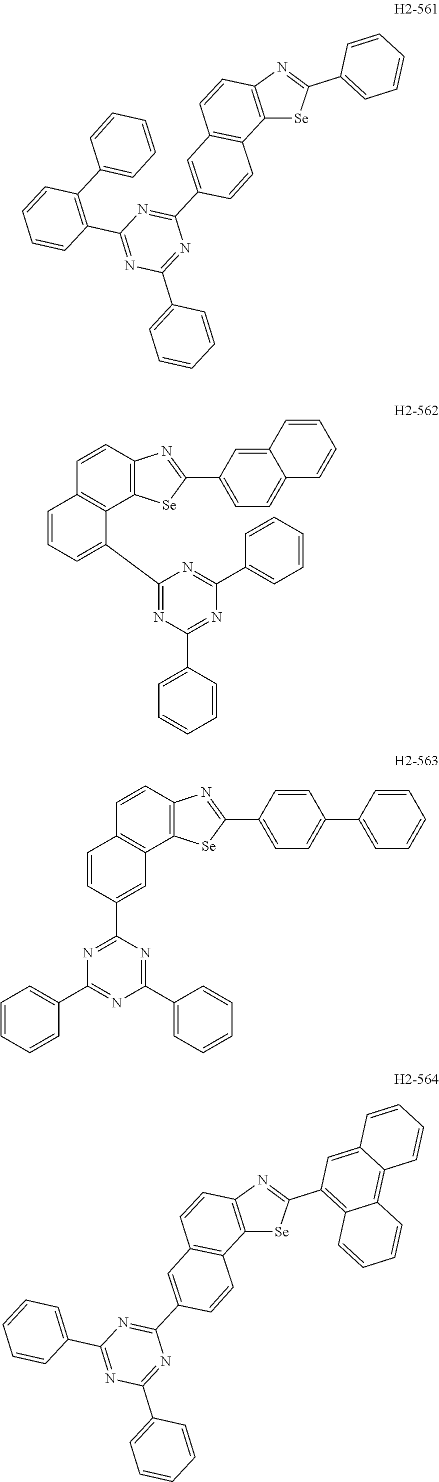 [SMILES: c1ccc(-c2nc(-c3ccc4c(ccc5nc(-c6ccccc6)[se]c54)c3)nc(-c3ccccc3-c3ccccc3)n2)cc1 ; c1ccc(-c2nc(-c3ccccc3)nc(-c3cccc4ccc5nc(-c6ccc7ccccc7c6)[se]c5c34)n2)cc1 ; c1ccc(-c2ccc(-c3nc4ccc5ccc(-c6nc(-c7ccccc7)nc(-c7ccccc7)n6)cc5c4[se]3)cc2)cc1 ; c1ccc(-c2nc(-c3ccccc3)nc(-c3ccc4c(ccc5nc(-c6cc7ccccc7c7ccccc67)[se]c54)c3)n2)cc1]

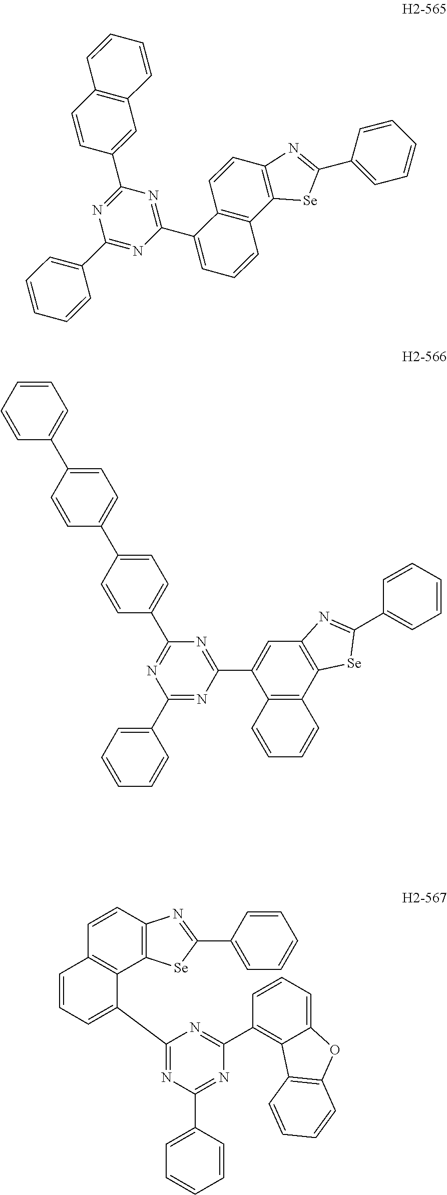 [SMILES: c1ccc(-c2nc(-c3ccc4ccccc4c3)nc(-c3cccc4c3ccc3nc(-c5ccccc5)[se]c34)n2)cc1 ; c1ccc(-c2ccc(-c3ccc(-c4nc(-c5ccccc5)nc(-c5cc6nc(-c7ccccc7)[se]c6c6ccccc56)n4)cc3)cc2)cc1 ; c1ccc(-c2nc(-c3cccc4oc5ccccc5c34)nc(-c3cccc4ccc5nc(-c6ccccc6)[se]c5c34)n2)cc1]

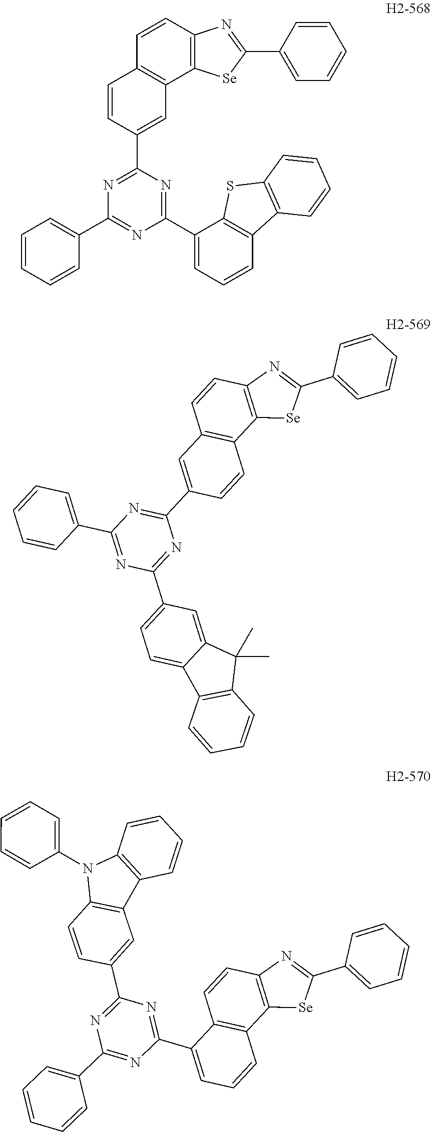 [SMILES: c1ccc(-c2nc(-c3ccc4ccc5nc(-c6ccccc6)[se]c5c4c3)nc(-c3cccc4c3sc3ccccc34)n2)cc1 ; CC1(C)c2ccccc2-c2ccc(-c3nc(-c4ccccc4)nc(-c4ccc5c(ccc6nc(-c7ccccc7)[se]c65)c4)n3)cc21 ; c1ccc(-c2nc(-c3ccc4c(c3)c3ccccc3n4-c3ccccc3)nc(-c3cccc4c3ccc3nc(-c5ccccc5)[se]c34)n2)cc1]

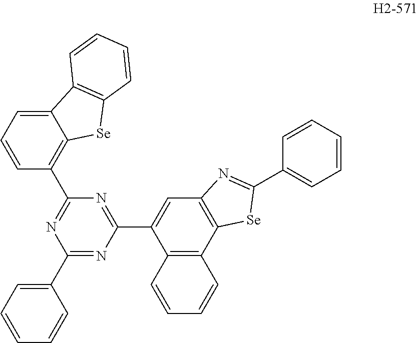 [SMILES: c1ccc(-c2nc(-c3cc4nc(-c5ccccc5)[se]c4c4ccccc34)nc(-c3cccc4c3[se]c3ccccc34)n2)cc1]

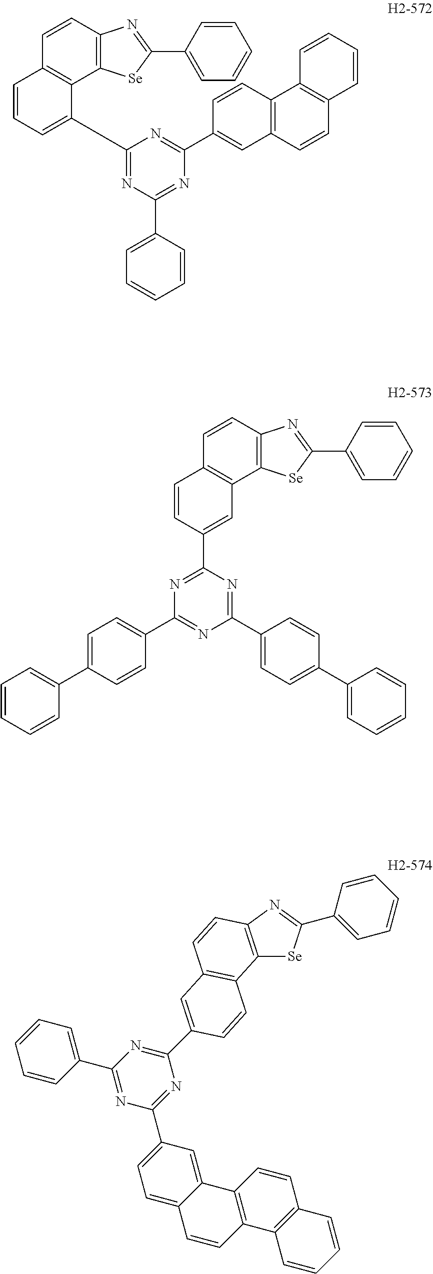 [SMILES: c1ccc(-c2nc(-c3ccc4c(ccc5ccccc54)c3)nc(-c3cccc4ccc5nc(-c6ccccc6)[se]c5c34)n2)cc1 ; c1ccc(-c2ccc(-c3nc(-c4ccc(-c5ccccc5)cc4)nc(-c4ccc5ccc6nc(-c7ccccc7)[se]c6c5c4)n3)cc2)cc1 ; c1ccc(-c2nc(-c3ccc4c(ccc5nc(-c6ccccc6)[se]c54)c3)nc(-c3ccc4ccc5c6ccccc6ccc5c4c3)n2)cc1]

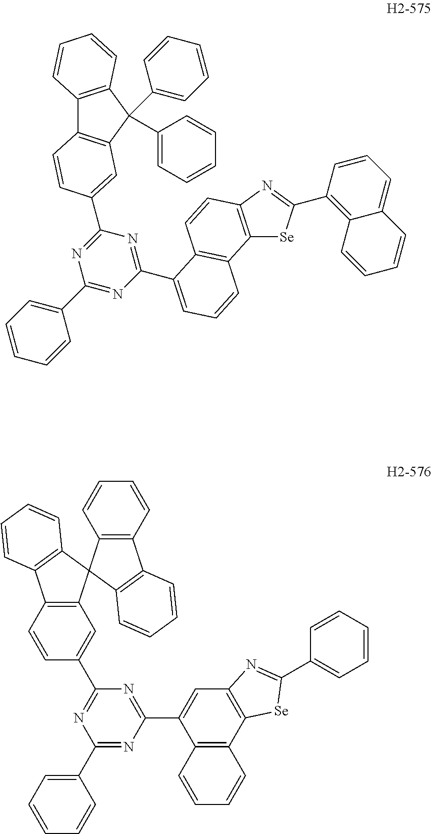 [SMILES: c1ccc(-c2nc(-c3ccc4c(c3)C(c3ccccc3)(c3ccccc3)c3ccccc3-4)nc(-c3cccc4c3ccc3nc(-c5cccc6ccccc56)[se]c34)n2)cc1 ; c1ccc(-c2nc(-c3ccc4c(c3)C3(c5ccccc5-c5ccccc53)c3ccccc3-4)nc(-c3cc4nc(-c5ccccc5)[se]c4c4ccccc34)n2)cc1]

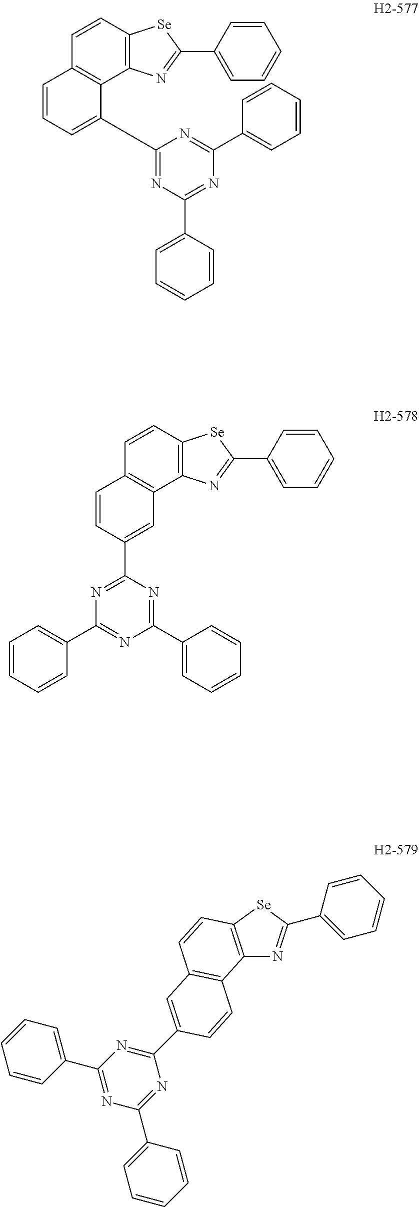 [SMILES: c1ccc(-c2nc(-c3ccccc3)nc(-c3cccc4ccc5[se]c(-c6ccccc6)nc5c34)n2)cc1 ; c1ccc(-c2nc(-c3ccccc3)nc(-c3ccc4ccc5[se]c(-c6ccccc6)nc5c4c3)n2)cc1 ; c1ccc(-c2nc(-c3ccccc3)nc(-c3ccc4c(ccc5[se]c(-c6ccccc6)nc54)c3)n2)cc1]

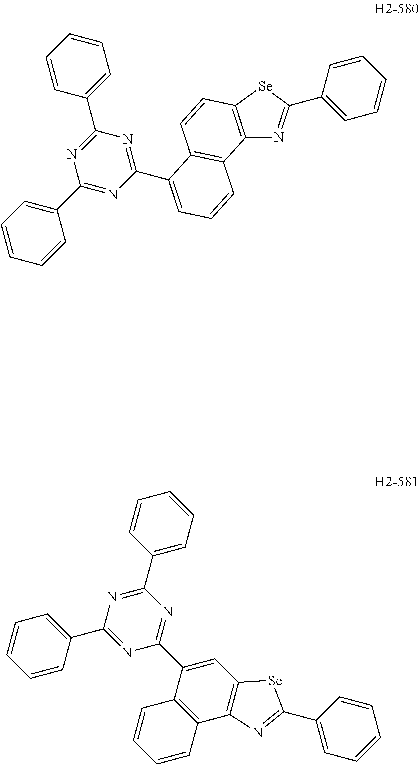 [SMILES: c1ccc(-c2nc(-c3ccccc3)nc(-c3cccc4c3ccc3[se]c(-c5ccccc5)nc34)n2)cc1 ; c1ccc(-c2nc(-c3ccccc3)nc(-c3cc4[se]c(-c5ccccc5)nc4c4ccccc34)n2)cc1]

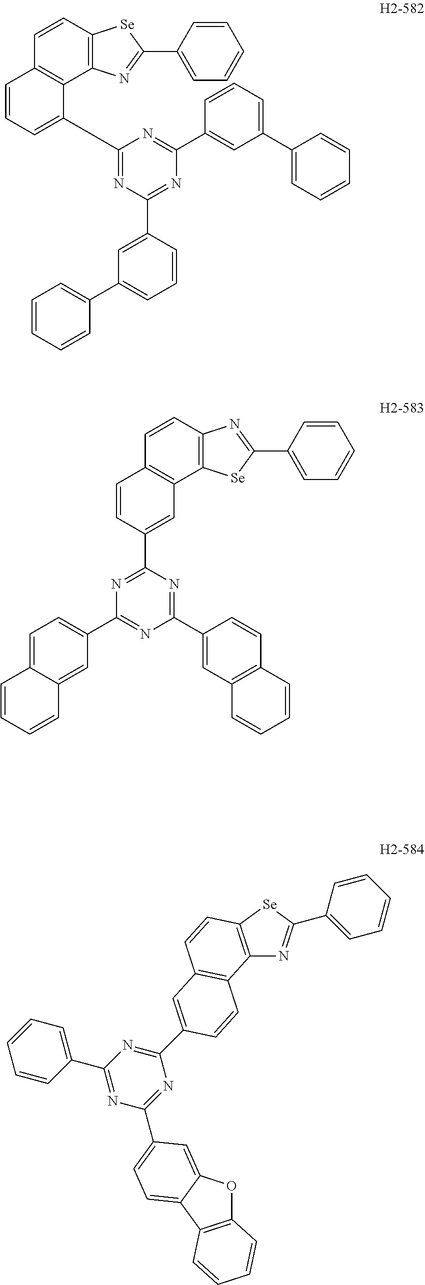 [SMILES: c1ccc(-c2cccc(-c3nc(-c4cccc(-c5ccccc5)c4)nc(-c4cccc5ccc6[se]c(-c7ccccc7)nc6c45)n3)c2)cc1 ; c1ccc(-c2nc3ccc4ccc(-c5nc(-c6ccc7ccccc7c6)nc(-c6ccc7ccccc7c6)n5)cc4c3[se]2)cc1 ; c1ccc(-c2nc(-c3ccc4c(ccc5[se]c(-c6ccccc6)nc54)c3)nc(-c3ccc4c(c3)oc3ccccc34)n2)cc1]

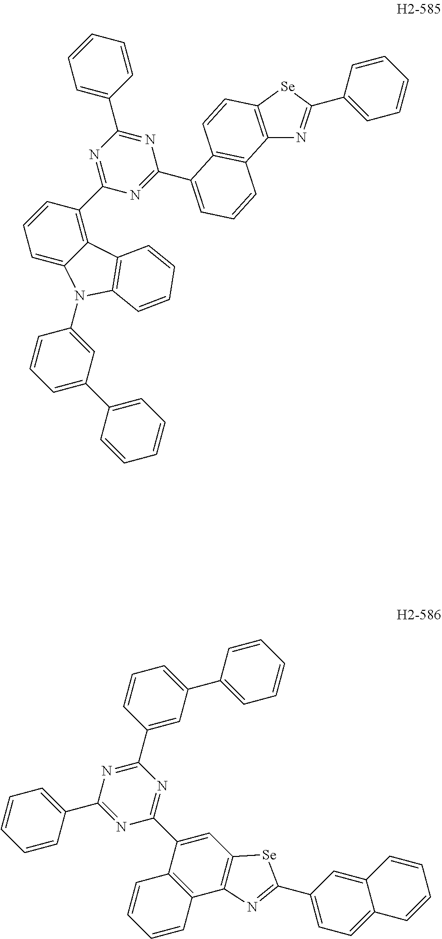 [SMILES: c1ccc(-c2cccc(-n3c4ccccc4c4c(-c5nc(-c6ccccc6)nc(-c6cccc7c6ccc6[se]c(-c8ccccc8)nc67)n5)cccc43)c2)cc1 ; c1ccc(-c2cccc(-c3nc(-c4ccccc4)nc(-c4cc5[se]c(-c6ccc7ccccc7c6)nc5c5ccccc45)n3)c2)cc1]

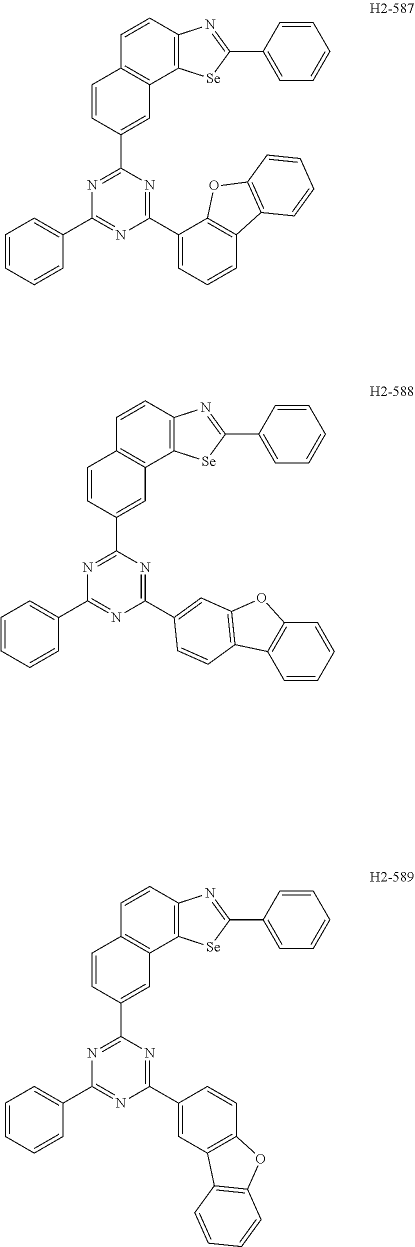 [SMILES: c1ccc(-c2nc(-c3ccc4ccc5nc(-c6ccccc6)[se]c5c4c3)nc(-c3cccc4c3oc3ccccc34)n2)cc1 ; c1ccc(-c2nc(-c3ccc4c(c3)oc3ccccc34)nc(-c3ccc4ccc5nc(-c6ccccc6)[se]c5c4c3)n2)cc1 ; c1ccc(-c2nc(-c3ccc4oc5ccccc5c4c3)nc(-c3ccc4ccc5nc(-c6ccccc6)[se]c5c4c3)n2)cc1]

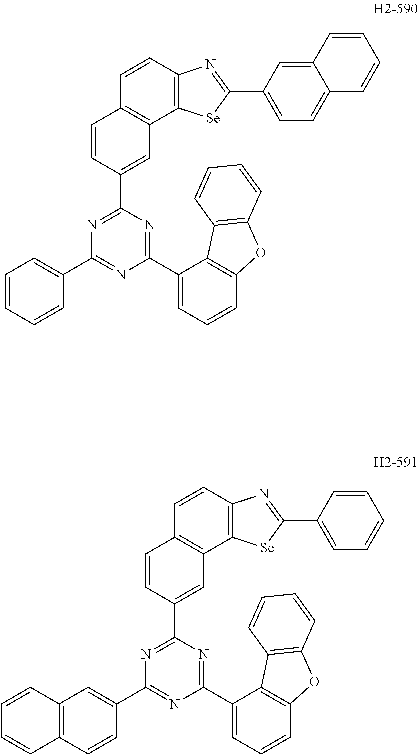 [SMILES: c1ccc(-c2nc(-c3ccc4ccc5nc(-c6ccc7ccccc7c6)[se]c5c4c3)nc(-c3cccc4oc5ccccc5c34)n2)cc1 ; c1ccc(-c2nc3ccc4ccc(-c5nc(-c6ccc7ccccc7c6)nc(-c6cccc7oc8ccccc8c67)n5)cc4c3[se]2)cc1]

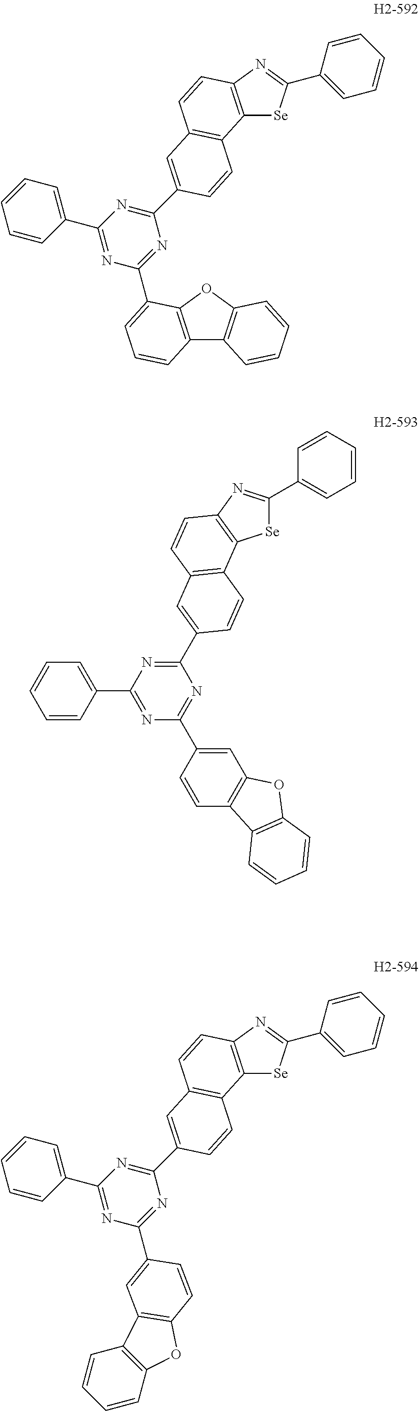 [SMILES: c1ccc(-c2nc(-c3ccc4c(ccc5nc(-c6ccccc6)[se]c54)c3)nc(-c3cccc4c3oc3ccccc34)n2)cc1 ; c1ccc(-c2nc(-c3ccc4c(ccc5nc(-c6ccccc6)[se]c54)c3)nc(-c3ccc4c(c3)oc3ccccc34)n2)cc1 ; c1ccc(-c2nc(-c3ccc4c(ccc5nc(-c6ccccc6)[se]c54)c3)nc(-c3ccc4oc5ccccc5c4c3)n2)cc1]

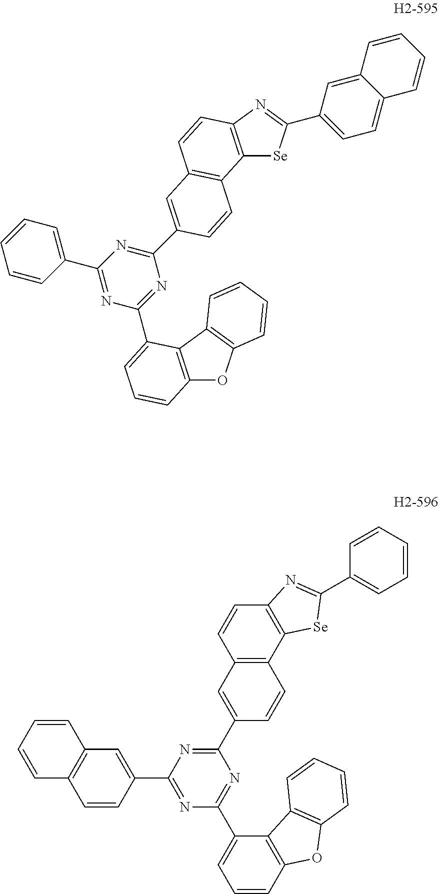 [SMILES: c1ccc(-c2nc(-c3ccc4c(ccc5nc(-c6ccc7ccccc7c6)[se]c54)c3)nc(-c3cccc4oc5ccccc5c34)n2)cc1 ; c1ccc(-c2nc3ccc4cc(-c5nc(-c6ccc7ccccc7c6)nc(-c6cccc7oc8ccccc8c67)n5)ccc4c3[se]2)cc1]

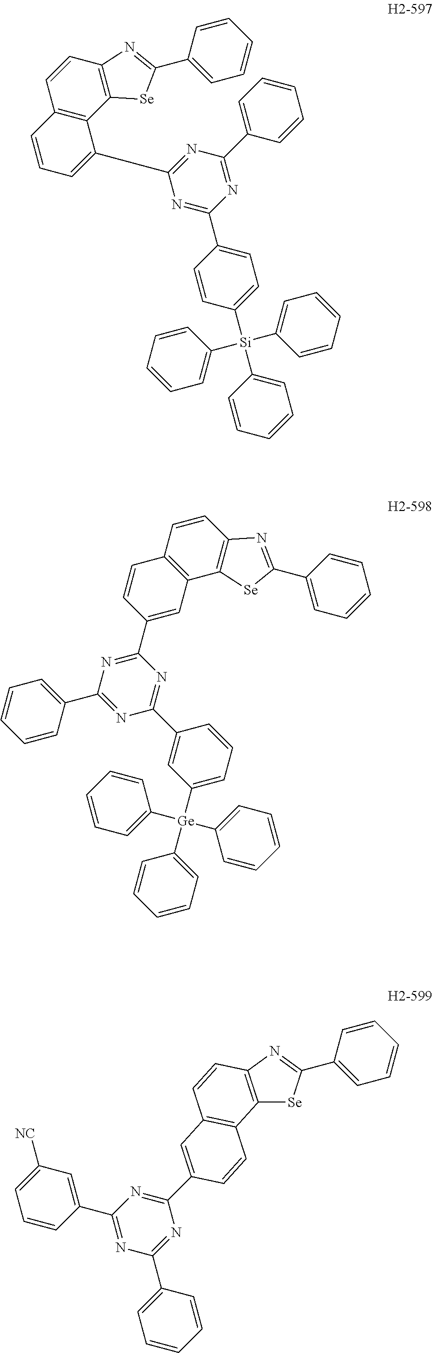

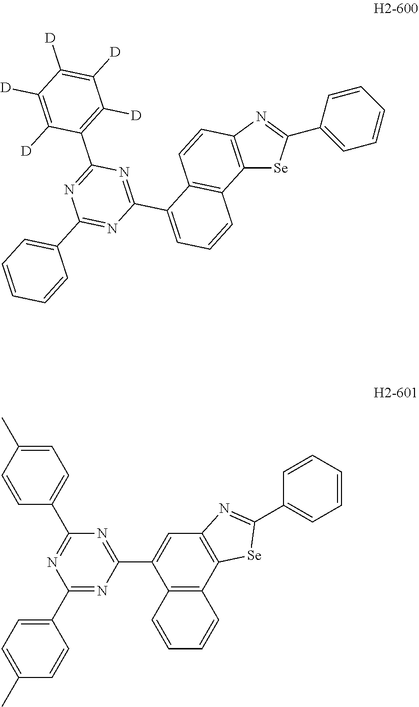 [SMILES: [2H]c1c([2H])c([2H])c(-c2nc(-c3ccccc3)nc(-c3cccc4c3ccc3nc(-c5ccccc5)[se]c34)n2)c([2H])c1[2H] ; Cc1ccc(-c2nc(-c3ccc(C)cc3)nc(-c3cc4nc(-c5ccccc5)[se]c4c4ccccc34)n2)cc1]

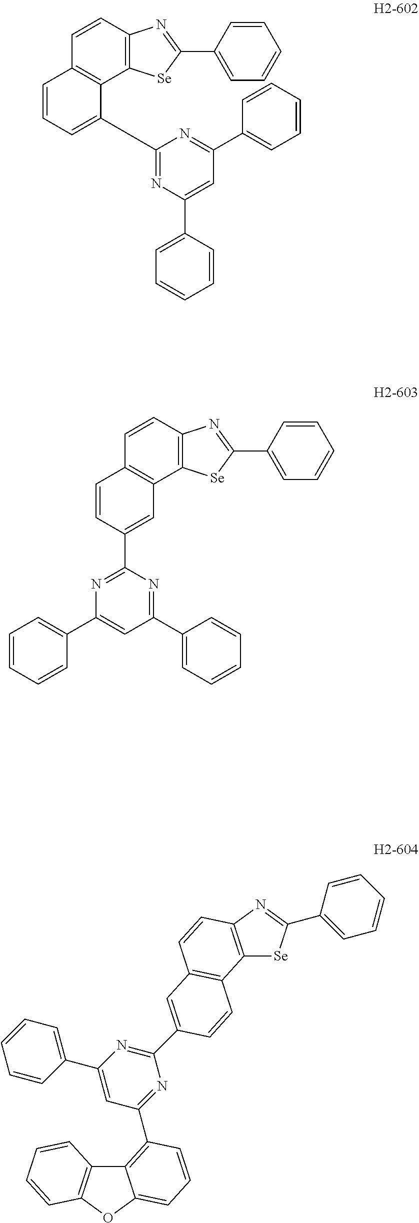 [SMILES: c1ccc(-c2cc(-c3ccccc3)nc(-c3cccc4ccc5nc(-c6ccccc6)[se]c5c34)n2)cc1 ; c1ccc(-c2cc(-c3ccccc3)nc(-c3ccc4ccc5nc(-c6ccccc6)[se]c5c4c3)n2)cc1 ; c1ccc(-c2cc(-c3cccc4oc5ccccc5c34)nc(-c3ccc4c(ccc5nc(-c6ccccc6)[se]c54)c3)n2)cc1]

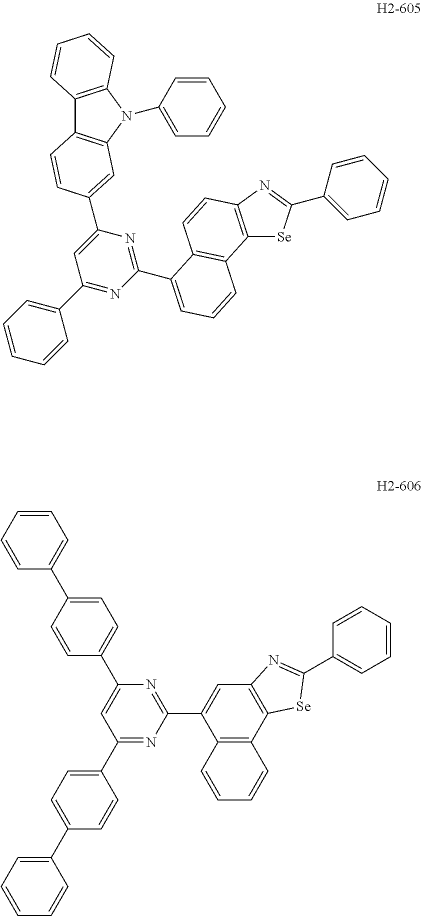 [SMILES: c1ccc(-c2cc(-c3ccc4c5ccccc5n(-c5ccccc5)c4c3)nc(-c3cccc4c3ccc3nc(-c5ccccc5)[se]c34)n2)cc1 ; c1ccc(-c2ccc(-c3cc(-c4ccc(-c5ccccc5)cc4)nc(-c4cc5nc(-c6ccccc6)[se]c5c5ccccc45)n3)cc2)cc1]

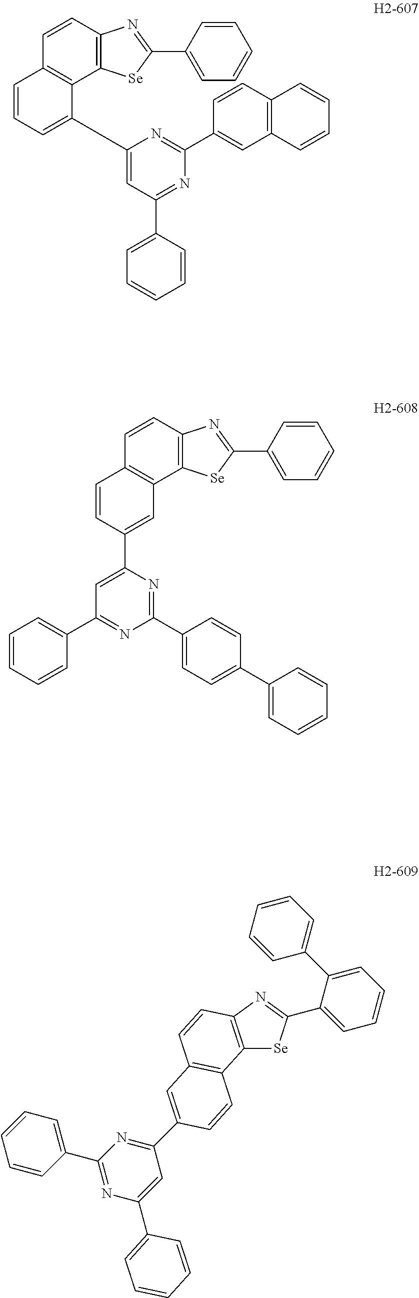 [SMILES: c1ccc(-c2cc(-c3cccc4ccc5nc(-c6ccccc6)[se]c5c34)nc(-c3ccc4ccccc4c3)n2)cc1 ; c1ccc(-c2ccc(-c3nc(-c4ccccc4)cc(-c4ccc5ccc6nc(-c7ccccc7)[se]c6c5c4)n3)cc2)cc1 ; c1ccc(-c2cc(-c3ccc4c(ccc5nc(-c6ccccc6-c6ccccc6)[se]c54)c3)nc(-c3ccccc3)n2)cc1]

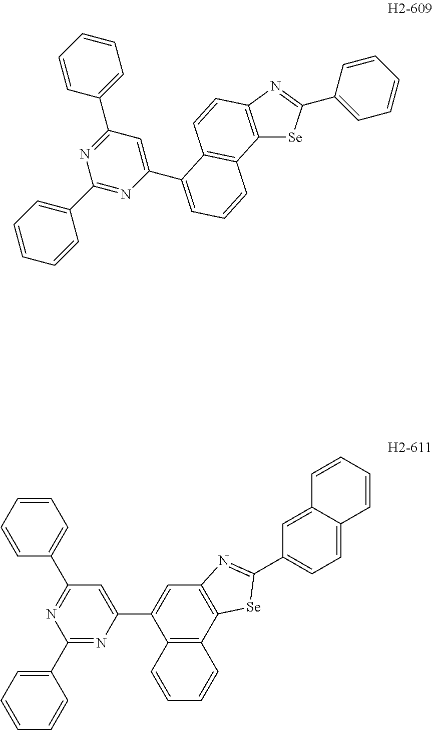 [SMILES: c1ccc(-c2cc(-c3cccc4c3ccc3nc(-c5ccccc5)[se]c34)nc(-c3ccccc3)n2)cc1 ; c1ccc(-c2cc(-c3cc4nc(-c5ccc6ccccc6c5)[se]c4c4ccccc34)nc(-c3ccccc3)n2)cc1]

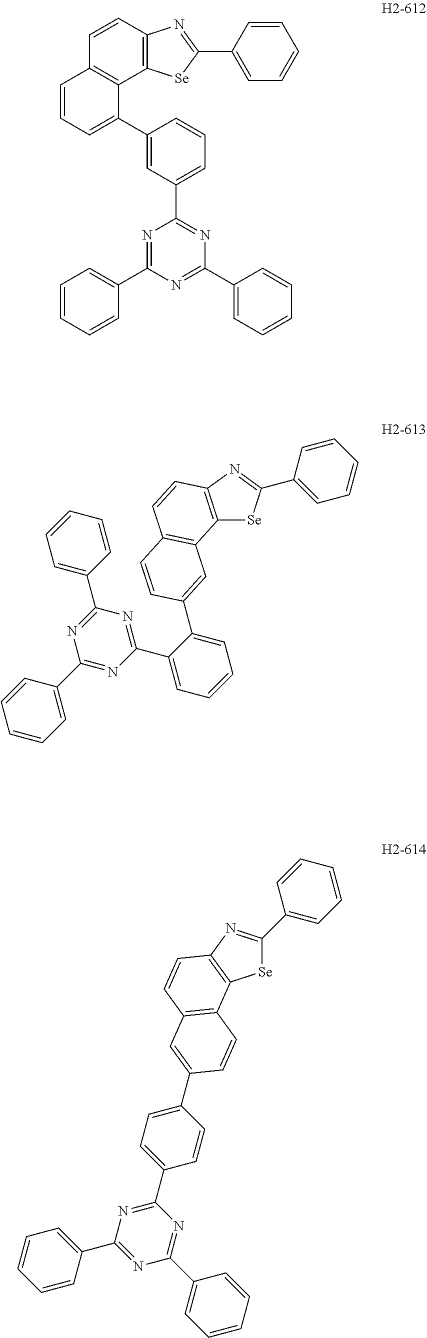 [SMILES: c1ccc(-c2nc(-c3ccccc3)nc(-c3cccc(-c4cccc5ccc6nc(-c7ccccc7)[se]c6c45)c3)n2)cc1 ; c1ccc(-c2nc(-c3ccccc3)nc(-c3ccccc3-c3ccc4ccc5nc(-c6ccccc6)[se]c5c4c3)n2)cc1 ; c1ccc(-c2nc(-c3ccccc3)nc(-c3ccc(-c4ccc5c(ccc6nc(-c7ccccc7)[se]c65)c4)cc3)n2)cc1]

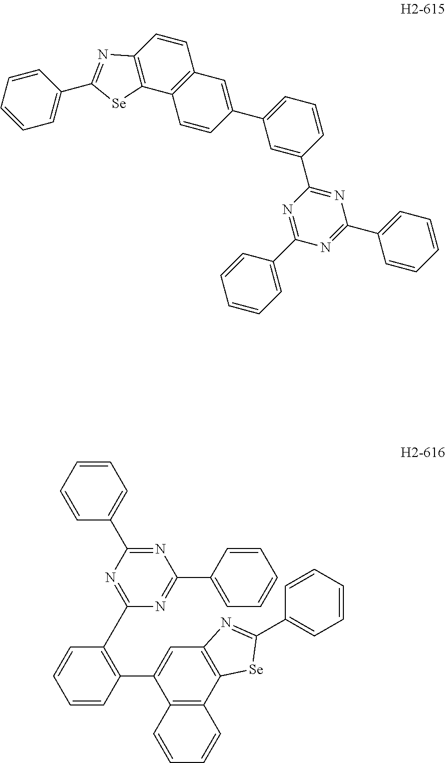 [SMILES: c1ccc(-c2nc(-c3ccccc3)nc(-c3cccc(-c4ccc5c(ccc6nc(-c7ccccc7)[se]c65)c4)c3)n2)cc1 ; c1ccc(-c2nc(-c3ccccc3)nc(-c3ccccc3-c3cc4nc(-c5ccccc5)[se]c4c4ccccc34)n2)cc1]

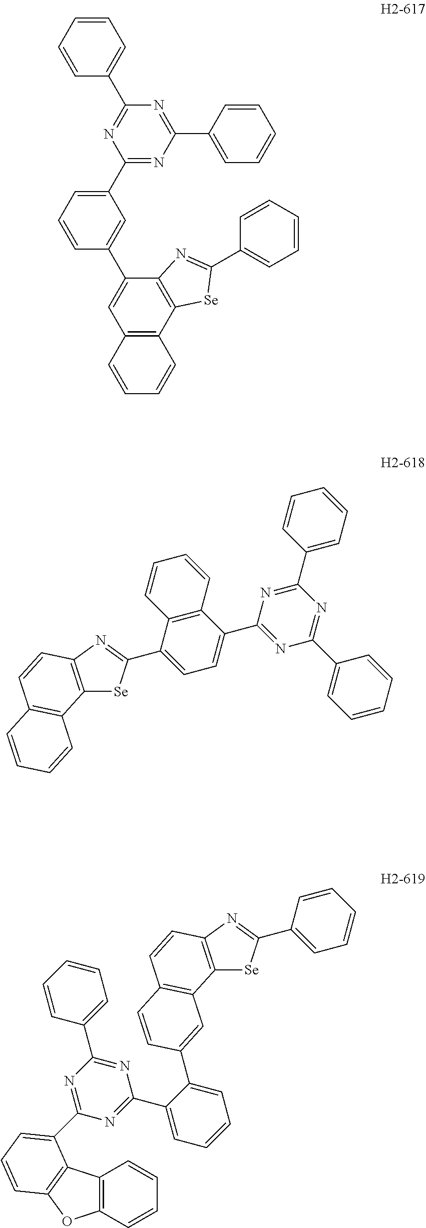 [SMILES: c1ccc(-c2nc(-c3ccccc3)nc(-c3cccc(-c4cc5ccccc5c5[se]c(-c6ccccc6)nc45)c3)n2)cc1 ; c1ccc(-c2nc(-c3ccccc3)nc(-c3ccc(-c4nc5ccc6ccccc6c5[se]4)c4ccccc34)n2)cc1 ; c1ccc(-c2nc(-c3ccccc3-c3ccc4ccc5nc(-c6ccccc6)[se]c5c4c3)nc(-c3cccc4oc5ccccc5c34)n2)cc1]

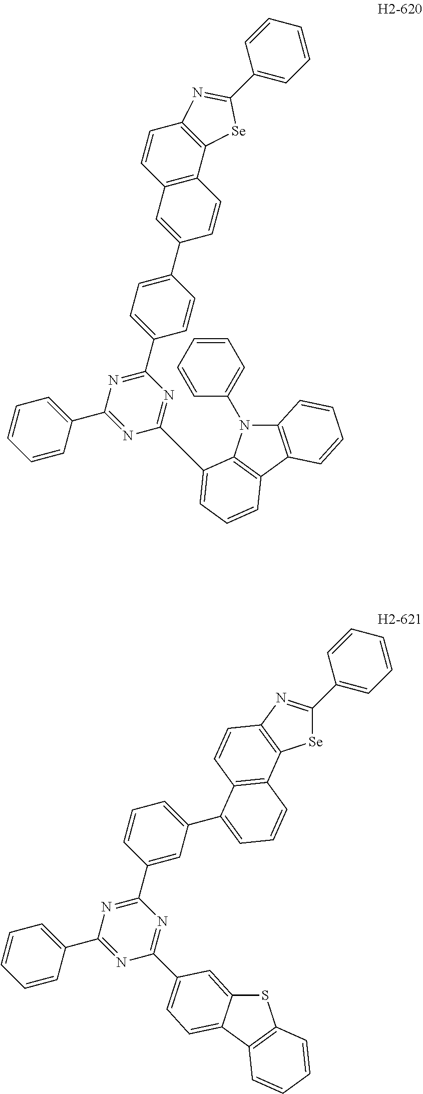 [SMILES: c1ccc(-c2nc(-c3ccc(-c4ccc5c(ccc6nc(-c7ccccc7)[se]c65)c4)cc3)nc(-c3cccc4c5ccccc5n(-c5ccccc5)c34)n2)cc1 ; c1ccc(-c2nc(-c3cccc(-c4cccc5c4ccc4nc(-c6ccccc6)[se]c45)c3)nc(-c3ccc4c(c3)sc3ccccc34)n2)cc1]

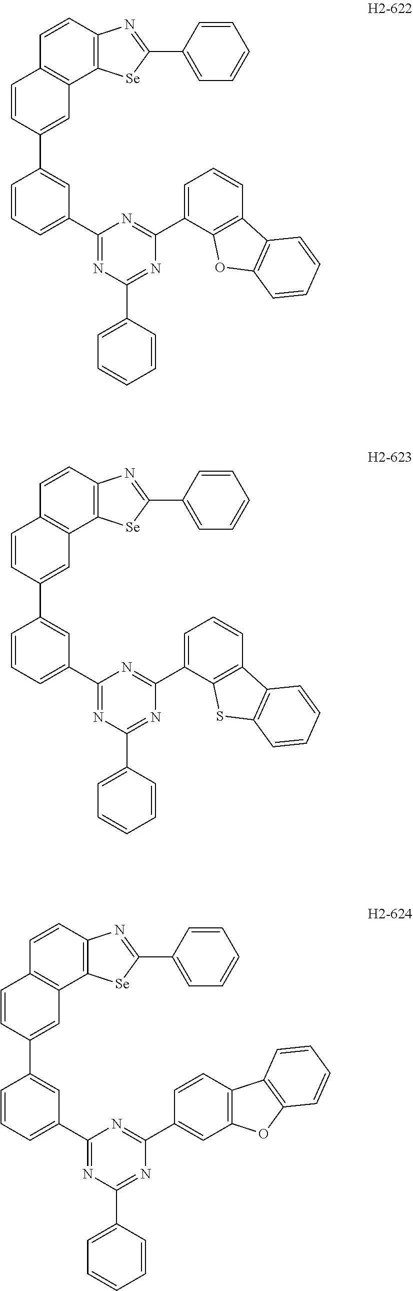 [SMILES: c1ccc(-c2nc(-c3cccc(-c4ccc5ccc6nc(-c7ccccc7)[se]c6c5c4)c3)nc(-c3cccc4c3oc3ccccc34)n2)cc1 ; c1ccc(-c2nc(-c3cccc(-c4ccc5ccc6nc(-c7ccccc7)[se]c6c5c4)c3)nc(-c3cccc4c3sc3ccccc34)n2)cc1 ; c1ccc(-c2nc(-c3cccc(-c4ccc5ccc6nc(-c7ccccc7)[se]c6c5c4)c3)nc(-c3ccc4c(c3)oc3ccccc34)n2)cc1]

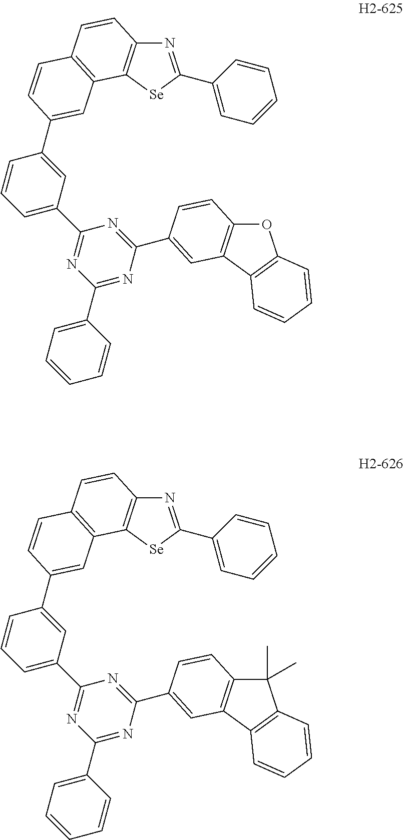 [SMILES: c1ccc(-c2nc(-c3cccc(-c4ccc5ccc6nc(-c7ccccc7)[se]c6c5c4)c3)nc(-c3ccc4oc5ccccc5c4c3)n2)cc1 ; CC1(C)c2ccccc2-c2cc(-c3nc(-c4ccccc4)nc(-c4cccc(-c5ccc6ccc7nc(-c8ccccc8)[se]c7c6c5)c4)n3)ccc21]

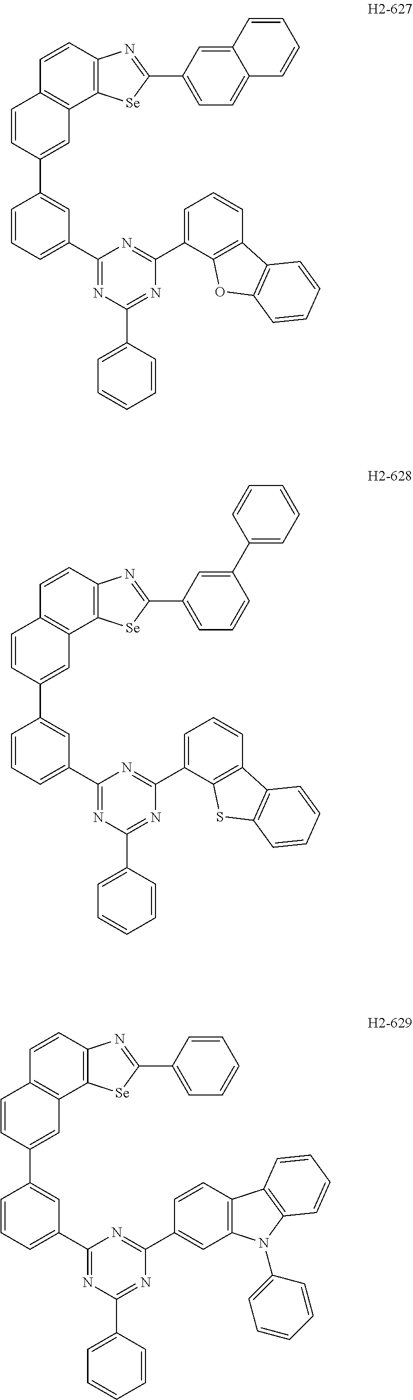 [SMILES: c1ccc(-c2nc(-c3cccc(-c4ccc5ccc6nc(-c7ccc8ccccc8c7)[se]c6c5c4)c3)nc(-c3cccc4c3oc3ccccc34)n2)cc1 ; c1ccc(-c2cccc(-c3nc4ccc5ccc(-c6cccc(-c7nc(-c8ccccc8)nc(-c8cccc9c8sc8ccccc89)n7)c6)cc5c4[se]3)c2)cc1 ; c1ccc(-c2nc(-c3cccc(-c4ccc5ccc6nc(-c7ccccc7)[se]c6c5c4)c3)nc(-c3ccc4c5ccccc5n(-c5ccccc5)c4c3)n2)cc1]

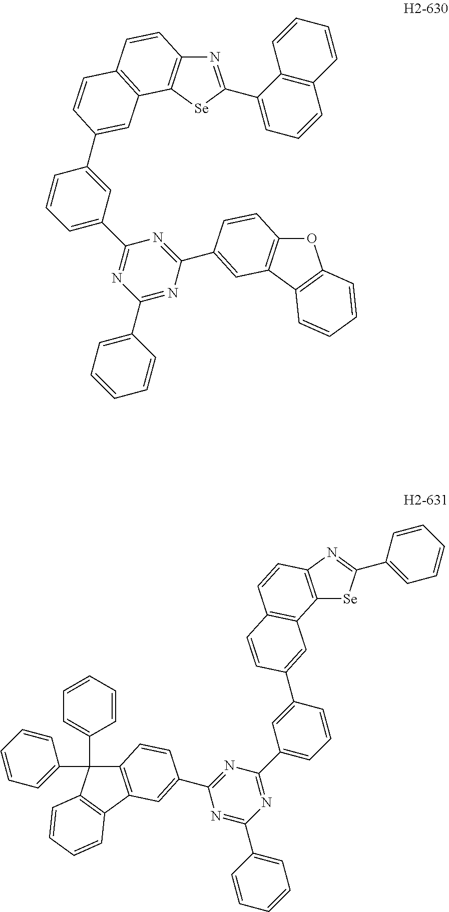 [SMILES: c1ccc(-c2nc(-c3cccc(-c4ccc5ccc6nc(-c7cccc8ccccc78)[se]c6c5c4)c3)nc(-c3ccc4oc5ccccc5c4c3)n2)cc1 ; c1ccc(-c2nc(-c3cccc(-c4ccc5ccc6nc(-c7ccccc7)[se]c6c5c4)c3)nc(-c3ccc4c(c3)-c3ccccc3C4(c3ccccc3)c3ccccc3)n2)cc1]

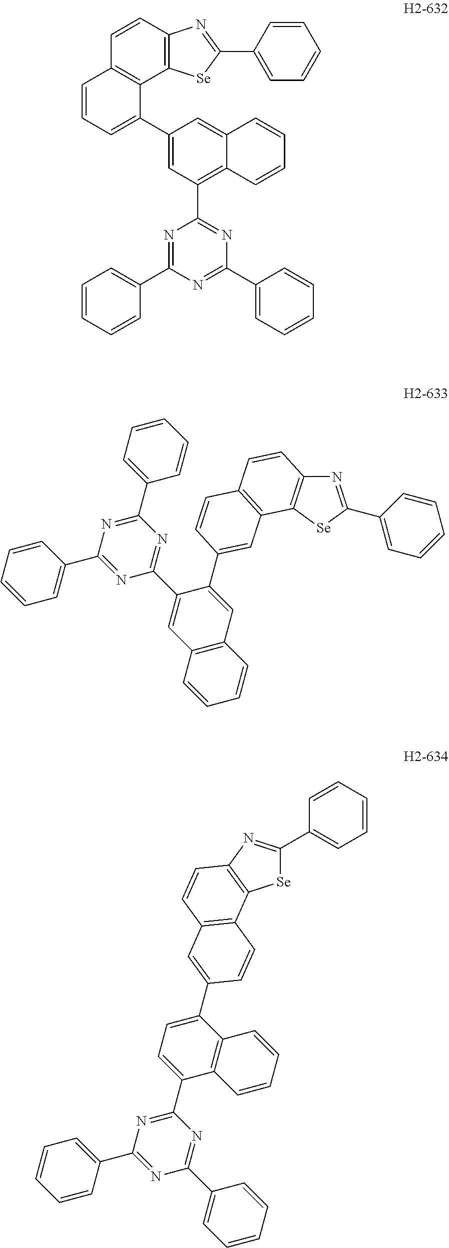 [SMILES: c1ccc(-c2nc(-c3ccccc3)nc(-c3cc(-c4cccc5ccc6nc(-c7ccccc7)[se]c6c45)cc4ccccc34)n2)cc1 ; c1ccc(-c2nc(-c3ccccc3)nc(-c3cc4ccccc4cc3-c3ccc4ccc5nc(-c6ccccc6)[se]c5c4c3)n2)cc1 ; c1ccc(-c2nc(-c3ccccc3)nc(-c3ccc(-c4ccc5c(ccc6nc(-c7ccccc7)[se]c65)c4)c4ccccc34)n2)cc1]

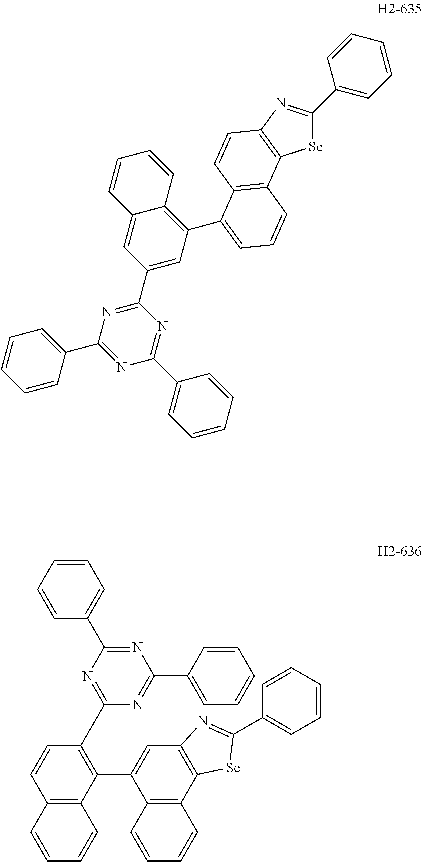 [SMILES: c1ccc(-c2nc(-c3ccccc3)nc(-c3cc(-c4cccc5c4ccc4nc(-c6ccccc6)[se]c45)c4ccccc4c3)n2)cc1 ; c1ccc(-c2nc(-c3ccccc3)nc(-c3ccc4ccccc4c3-c3cc4nc(-c5ccccc5)[se]c4c4ccccc34)n2)cc1]

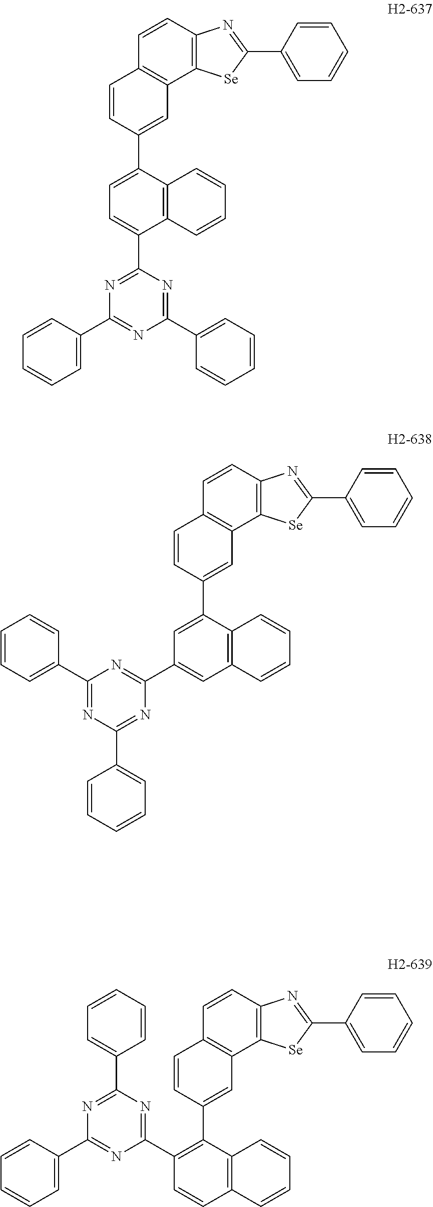 [SMILES: c1ccc(-c2nc(-c3ccccc3)nc(-c3ccc(-c4ccc5ccc6nc(-c7ccccc7)[se]c6c5c4)c4ccccc34)n2)cc1 ; c1ccc(-c2nc(-c3ccccc3)nc(-c3cc(-c4ccc5ccc6nc(-c7ccccc7)[se]c6c5c4)c4ccccc4c3)n2)cc1 ; c1ccc(-c2nc(-c3ccccc3)nc(-c3ccc4ccccc4c3-c3ccc4ccc5nc(-c6ccccc6)[se]c5c4c3)n2)cc1]

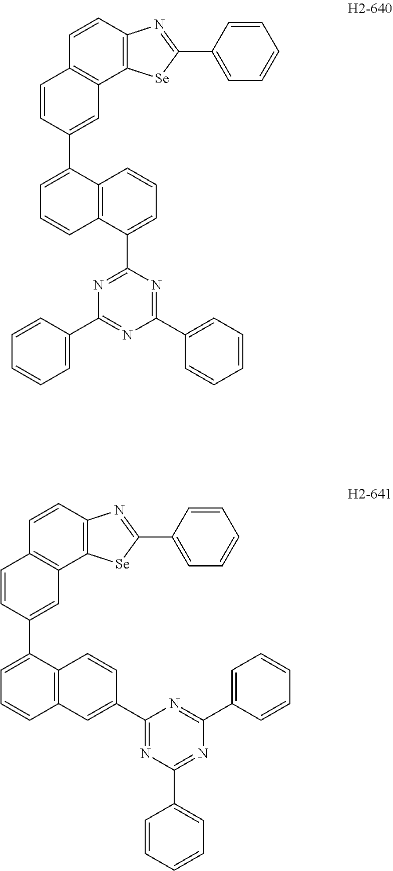 [SMILES: c1ccc(-c2nc(-c3ccccc3)nc(-c3cccc4c(-c5ccc6ccc7nc(-c8ccccc8)[se]c7c6c5)cccc34)n2)cc1 ; c1ccc(-c2nc(-c3ccccc3)nc(-c3ccc4c(-c5ccc6ccc7nc(-c8ccccc8)[se]c7c6c5)cccc4c3)n2)cc1]

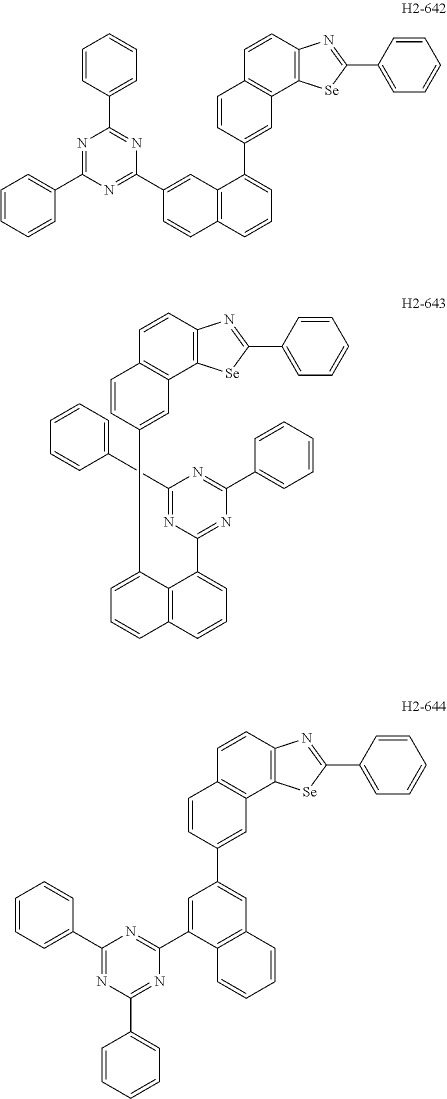 [SMILES: c1ccc(-c2nc(-c3ccccc3)nc(-c3ccc4cccc(-c5ccc6ccc7nc(-c8ccccc8)[se]c7c6c5)c4c3)n2)cc1 ; c1ccc(-c2nc(-c3ccccc3)nc(-c3cccc4cccc(-c5ccc6ccc7nc(-c8ccccc8)[se]c7c6c5)c34)n2)cc1 ; c1ccc(-c2nc(-c3ccccc3)nc(-c3cc(-c4ccc5ccc6nc(-c7ccccc7)[se]c6c5c4)cc4ccccc34)n2)cc1]

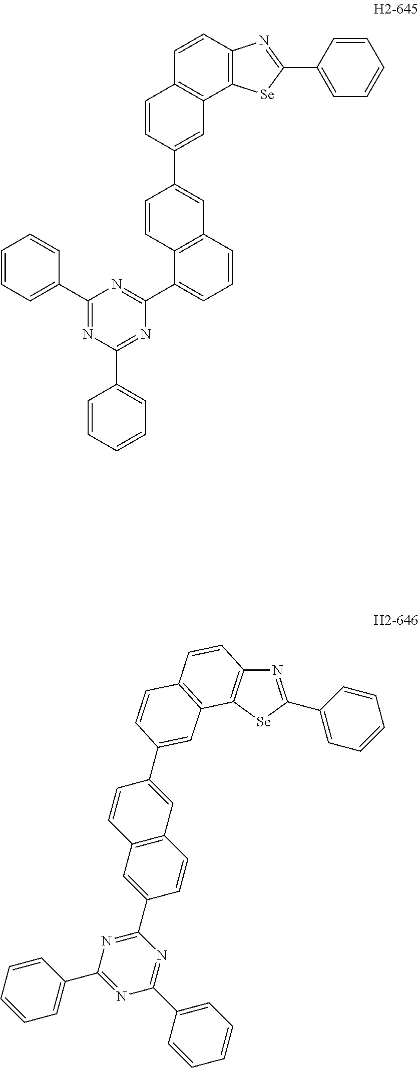 [SMILES: c1ccc(-c2nc(-c3ccccc3)nc(-c3cccc4cc(-c5ccc6ccc7nc(-c8ccccc8)[se]c7c6c5)ccc34)n2)cc1 ; c1ccc(-c2nc(-c3ccccc3)nc(-c3ccc4cc(-c5ccc6ccc7nc(-c8ccccc8)[se]c7c6c5)ccc4c3)n2)cc1]

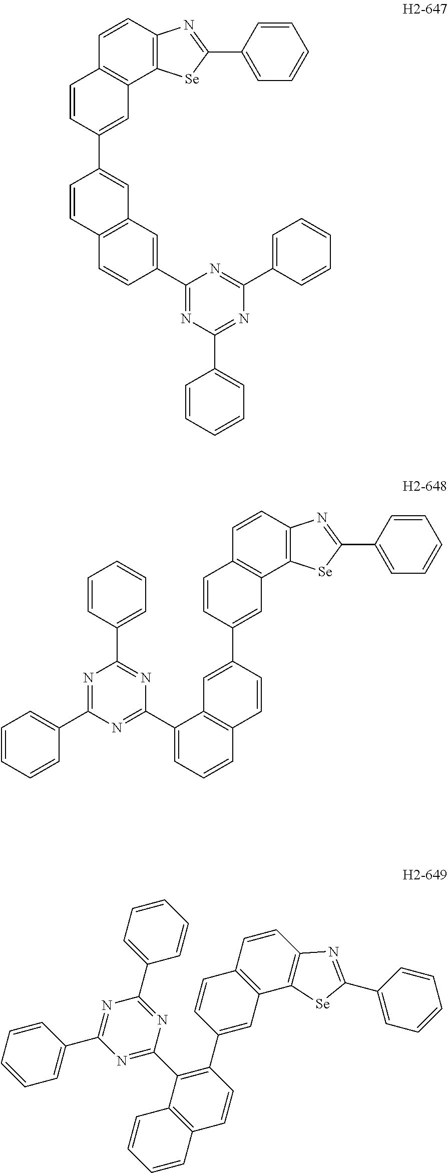

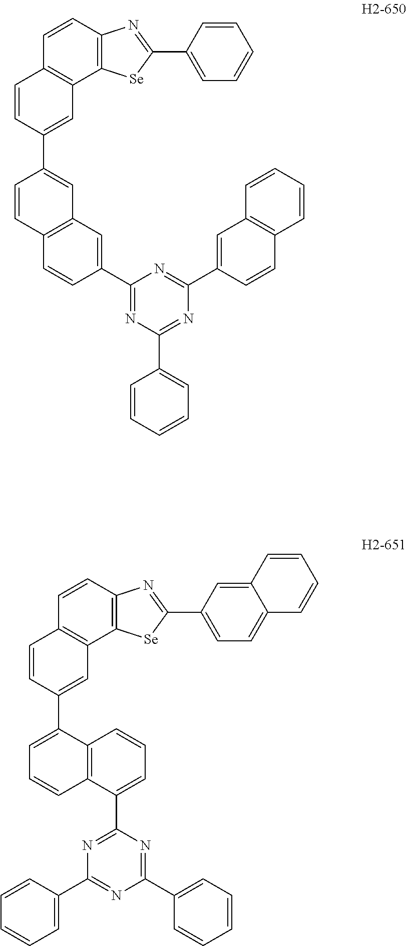 [SMILES: c1ccc(-c2nc(-c3ccc4ccccc4c3)nc(-c3ccc4ccc(-c5ccc6ccc7nc(-c8ccccc8)[se]c7c6c5)cc4c3)n2)cc1 ; c1ccc(-c2nc(-c3ccccc3)nc(-c3cccc4c(-c5ccc6ccc7nc(-c8ccc9ccccc9c8)[se]c7c6c5)cccc34)n2)cc1]

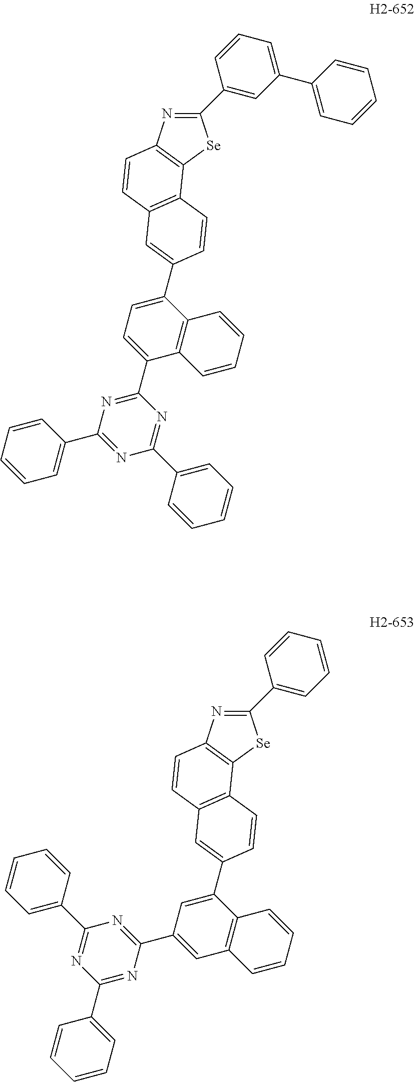 [SMILES: c1ccc(-c2cccc(-c3nc4ccc5cc(-c6ccc(-c7nc(-c8ccccc8)nc(-c8ccccc8)n7)c7ccccc67)ccc5c4[se]3)c2)cc1 ; c1ccc(-c2nc(-c3ccccc3)nc(-c3cc(-c4ccc5c(ccc6nc(-c7ccccc7)[se]c65)c4)c4ccccc4c3)n2)cc1]

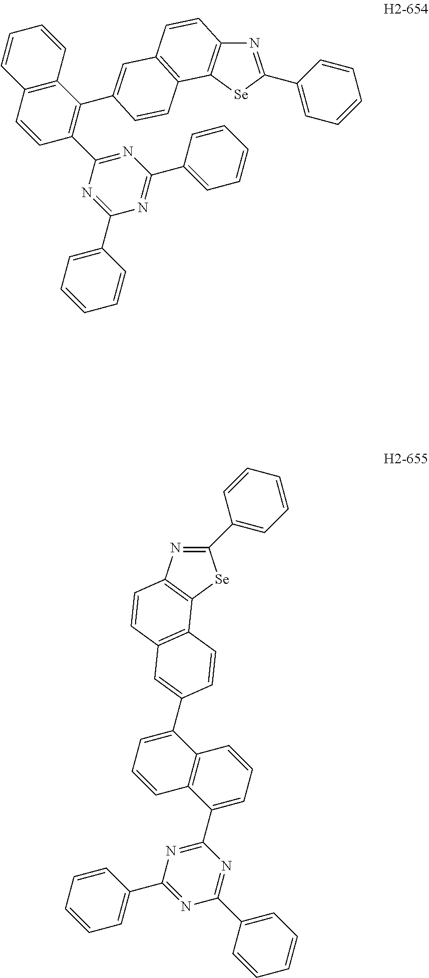 [SMILES: c1ccc(-c2nc(-c3ccccc3)nc(-c3ccc4ccccc4c3-c3ccc4c(ccc5nc(-c6ccccc6)[se]c54)c3)n2)cc1 ; c1ccc(-c2nc(-c3ccccc3)nc(-c3cccc4c(-c5ccc6c(ccc7nc(-c8ccccc8)[se]c76)c5)cccc34)n2)cc1]

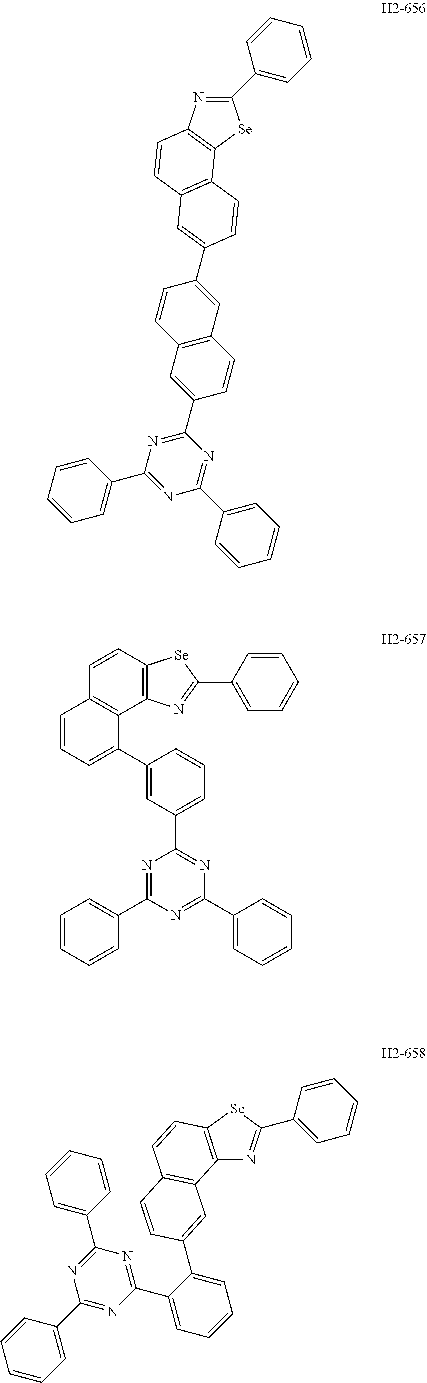 [SMILES: c1ccc(-c2nc(-c3ccccc3)nc(-c3ccc4cc(-c5ccc6c(ccc7nc(-c8ccccc8)[se]c76)c5)ccc4c3)n2)cc1 ; c1ccc(-c2nc(-c3ccccc3)nc(-c3cccc(-c4cccc5ccc6[se]c(-c7ccccc7)nc6c45)c3)n2)cc1 ; c1ccc(-c2nc(-c3ccccc3)nc(-c3ccccc3-c3ccc4ccc5[se]c(-c6ccccc6)nc5c4c3)n2)cc1]

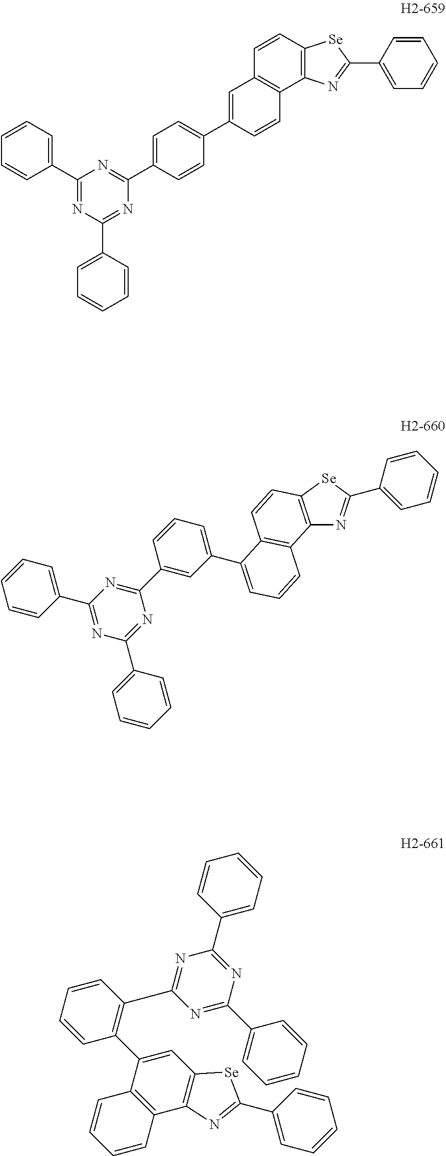 [SMILES: c1ccc(-c2nc(-c3ccccc3)nc(-c3ccc(-c4ccc5c(ccc6[se]c(-c7ccccc7)nc65)c4)cc3)n2)cc1 ; c1ccc(-c2nc(-c3ccccc3)nc(-c3cccc(-c4cccc5c4ccc4[se]c(-c6ccccc6)nc45)c3)n2)cc1 ; c1ccc(-c2nc(-c3ccccc3)nc(-c3ccccc3-c3cc4[se]c(-c5ccccc5)nc4c4ccccc34)n2)cc1]

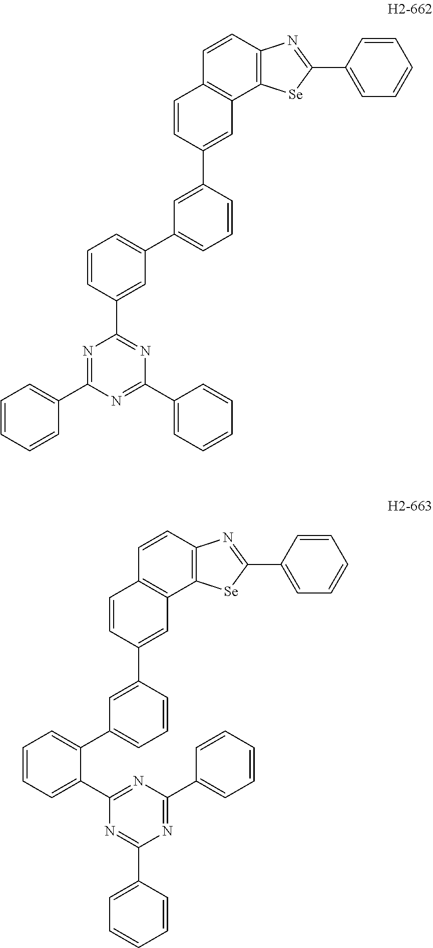 [SMILES: c1ccc(-c2nc(-c3ccccc3)nc(-c3cccc(-c4cccc(-c5ccc6ccc7nc(-c8ccccc8)[se]c7c6c5)c4)c3)n2)cc1 ; c1ccc(-c2nc(-c3ccccc3)nc(-c3ccccc3-c3cccc(-c4ccc5ccc6nc(-c7ccccc7)[se]c6c5c4)c3)n2)cc1]

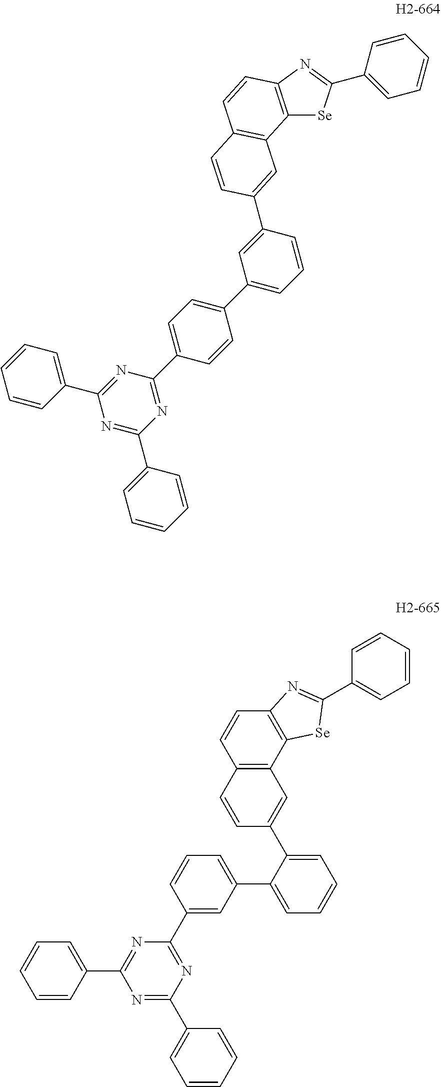 [SMILES: c1ccc(-c2nc(-c3ccccc3)nc(-c3ccc(-c4cccc(-c5ccc6ccc7nc(-c8ccccc8)[se]c7c6c5)c4)cc3)n2)cc1 ; c1ccc(-c2nc(-c3ccccc3)nc(-c3cccc(-c4ccccc4-c4ccc5ccc6nc(-c7ccccc7)[se]c6c5c4)c3)n2)cc1]

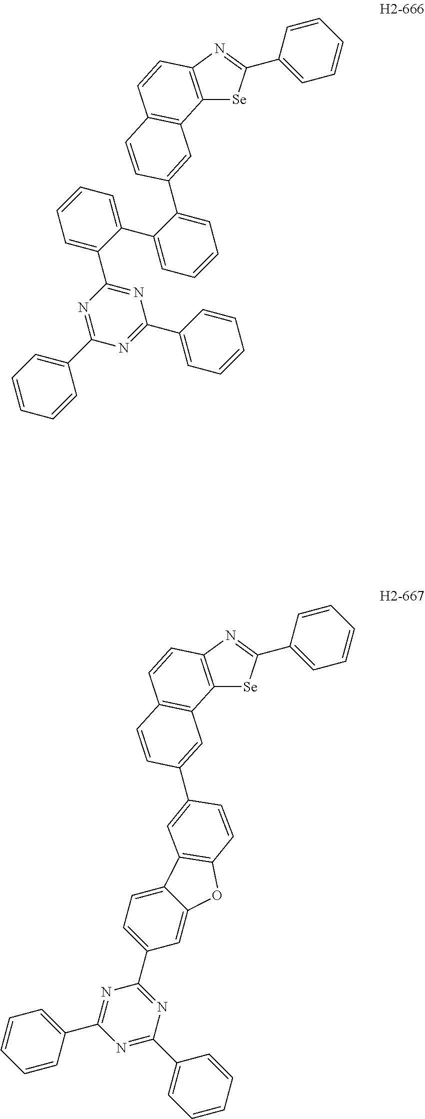 [SMILES: c1ccc(-c2nc(-c3ccccc3)nc(-c3ccccc3-c3ccccc3-c3ccc4ccc5nc(-c6ccccc6)[se]c5c4c3)n2)cc1 ; c1ccc(-c2nc(-c3ccccc3)nc(-c3ccc4c(c3)oc3ccc(-c5ccc6ccc7nc(-c8ccccc8)[se]c7c6c5)cc34)n2)cc1]

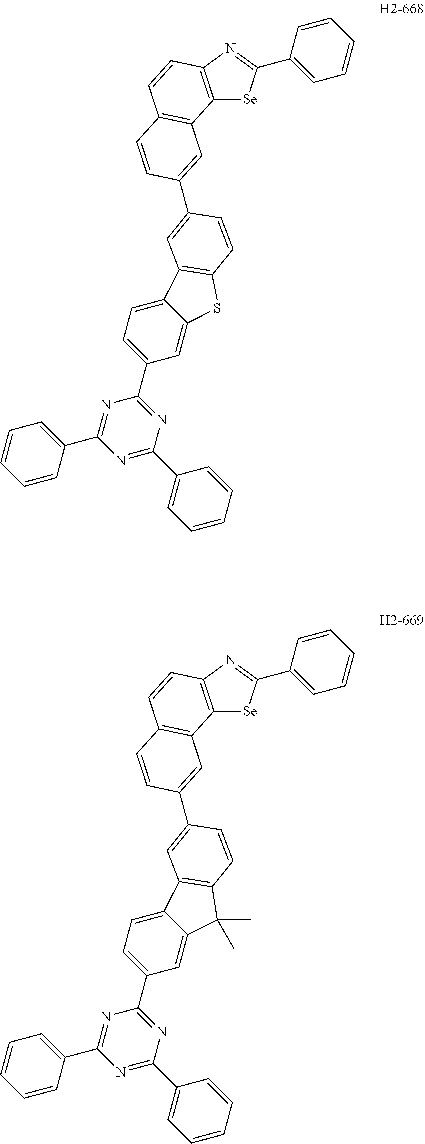 [SMILES: c1ccc(-c2nc(-c3ccccc3)nc(-c3ccc4c(c3)sc3ccc(-c5ccc6ccc7nc(-c8ccccc8)[se]c7c6c5)cc34)n2)cc1 ; CC1(C)c2ccc(-c3ccc4ccc5nc(-c6ccccc6)[se]c5c4c3)cc2-c2ccc(-c3nc(-c4ccccc4)nc(-c4ccccc4)n3)cc21]

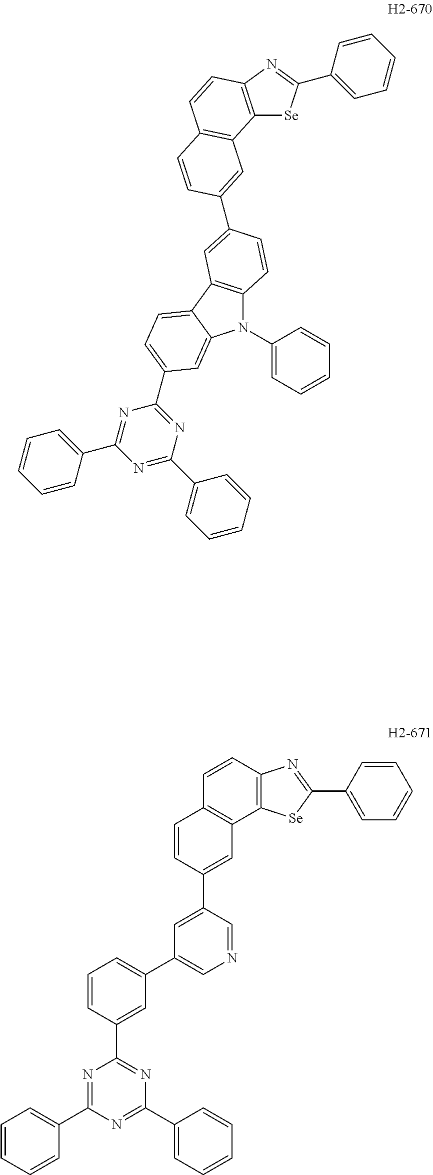 [SMILES: c1ccc(-c2nc(-c3ccccc3)nc(-c3ccc4c5cc(-c6ccc7ccc8nc(-c9ccccc9)[se]c8c7c6)ccc5n(-c5ccccc5)c4c3)n2)cc1 ; c1ccc(-c2nc(-c3ccccc3)nc(-c3cccc(-c4cncc(-c5ccc6ccc7nc(-c8ccccc8)[se]c7c6c5)c4)c3)n2)cc1]

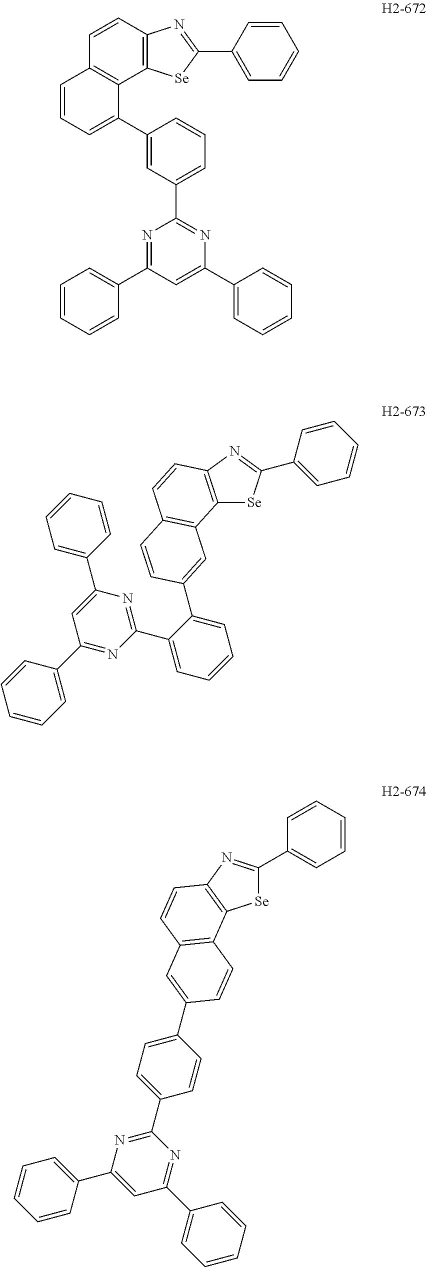 [SMILES: c1ccc(-c2cc(-c3ccccc3)nc(-c3cccc(-c4cccc5ccc6nc(-c7ccccc7)[se]c6c45)c3)n2)cc1 ; c1ccc(-c2cc(-c3ccccc3)nc(-c3ccccc3-c3ccc4ccc5nc(-c6ccccc6)[se]c5c4c3)n2)cc1 ; c1ccc(-c2cc(-c3ccccc3)nc(-c3ccc(-c4ccc5c(ccc6nc(-c7ccccc7)[se]c65)c4)cc3)n2)cc1]

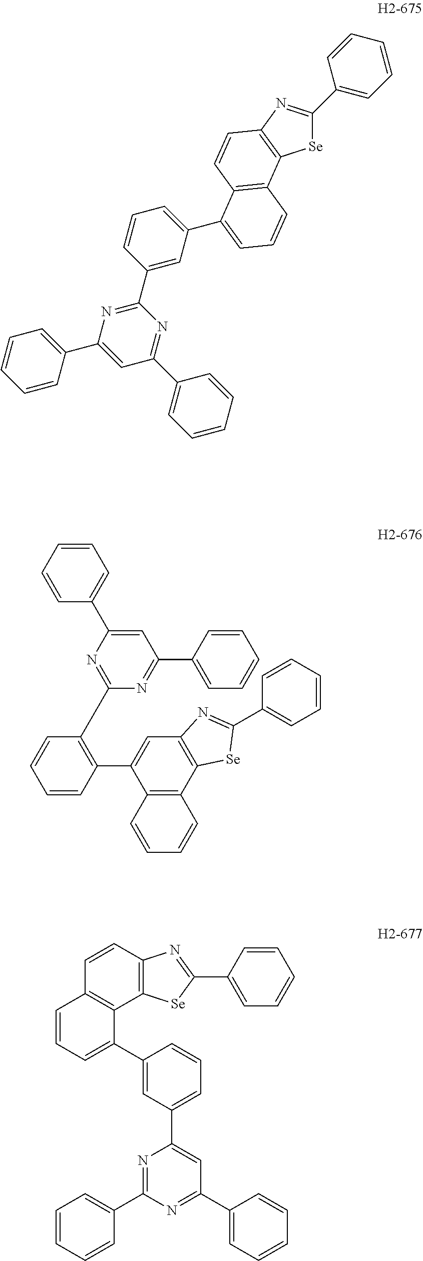 [SMILES: c1ccc(-c2cc(-c3ccccc3)nc(-c3cccc(-c4cccc5c4ccc4nc(-c6ccccc6)[se]c45)c3)n2)cc1 ; c1ccc(-c2cc(-c3ccccc3)nc(-c3ccccc3-c3cc4nc(-c5ccccc5)[se]c4c4ccccc34)n2)cc1 ; c1ccc(-c2cc(-c3cccc(-c4cccc5ccc6nc(-c7ccccc7)[se]c6c45)c3)nc(-c3ccccc3)n2)cc1]

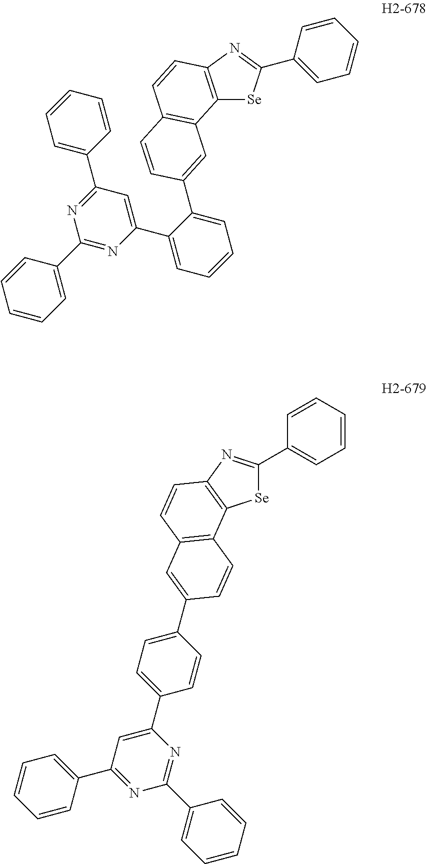 [SMILES: c1ccc(-c2cc(-c3ccccc3-c3ccc4ccc5nc(-c6ccccc6)[se]c5c4c3)nc(-c3ccccc3)n2)cc1 ; c1ccc(-c2cc(-c3ccc(-c4ccc5c(ccc6nc(-c7ccccc7)[se]c65)c4)cc3)nc(-c3ccccc3)n2)cc1]

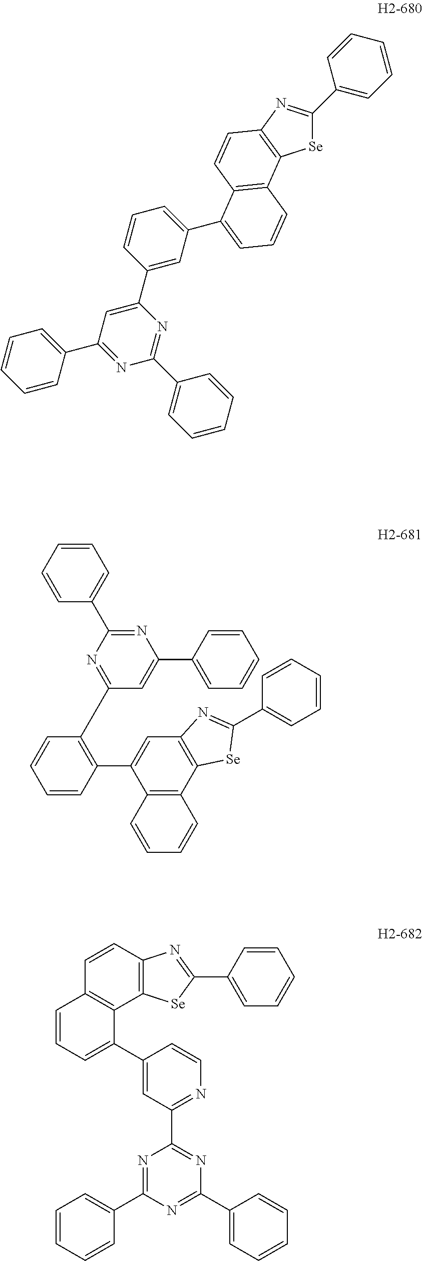 [SMILES: c1ccc(-c2cc(-c3cccc(-c4cccc5c4ccc4nc(-c6ccccc6)[se]c45)c3)nc(-c3ccccc3)n2)cc1 ; c1ccc(-c2cc(-c3ccccc3-c3cc4nc(-c5ccccc5)[se]c4c4ccccc34)nc(-c3ccccc3)n2)cc1 ; c1ccc(-c2nc(-c3ccccc3)nc(-c3cc(-c4cccc5ccc6nc(-c7ccccc7)[se]c6c45)ccn3)n2)cc1]

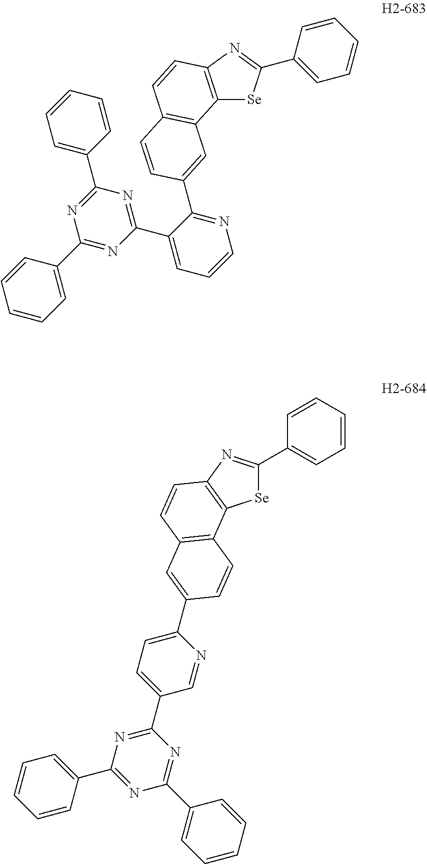 [SMILES: c1ccc(-c2nc(-c3ccccc3)nc(-c3cccnc3-c3ccc4ccc5nc(-c6ccccc6)[se]c5c4c3)n2)cc1 ; c1ccc(-c2nc(-c3ccccc3)nc(-c3ccc(-c4ccc5c(ccc6nc(-c7ccccc7)[se]c65)c4)nc3)n2)cc1]

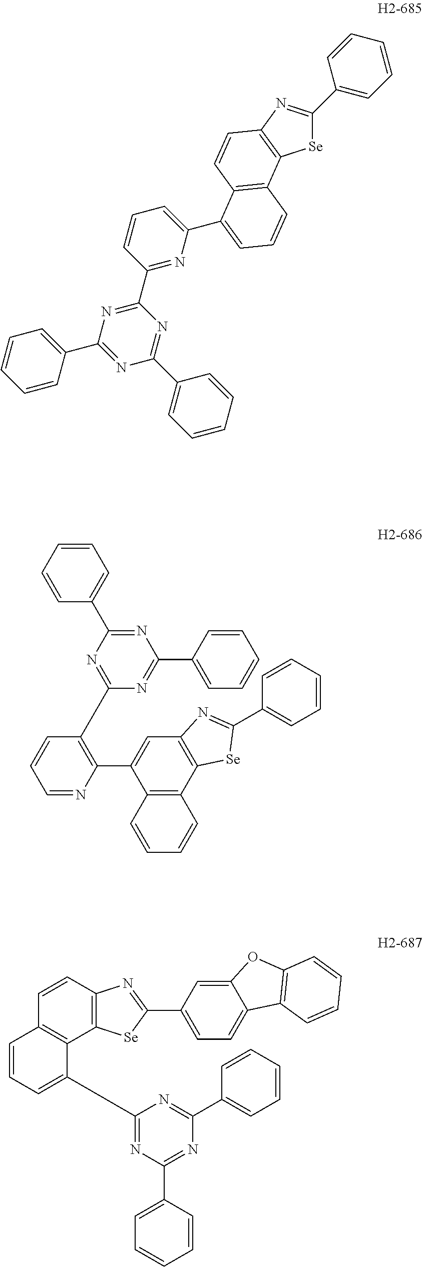 [SMILES: c1ccc(-c2nc(-c3ccccc3)nc(-c3cccc(-c4cccc5c4ccc4nc(-c6ccccc6)[se]c45)n3)n2)cc1 ; c1ccc(-c2nc(-c3ccccc3)nc(-c3cccnc3-c3cc4nc(-c5ccccc5)[se]c4c4ccccc34)n2)cc1 ; c1ccc(-c2nc(-c3ccccc3)nc(-c3cccc4ccc5nc(-c6ccc7c(c6)oc6ccccc67)[se]c5c34)n2)cc1]

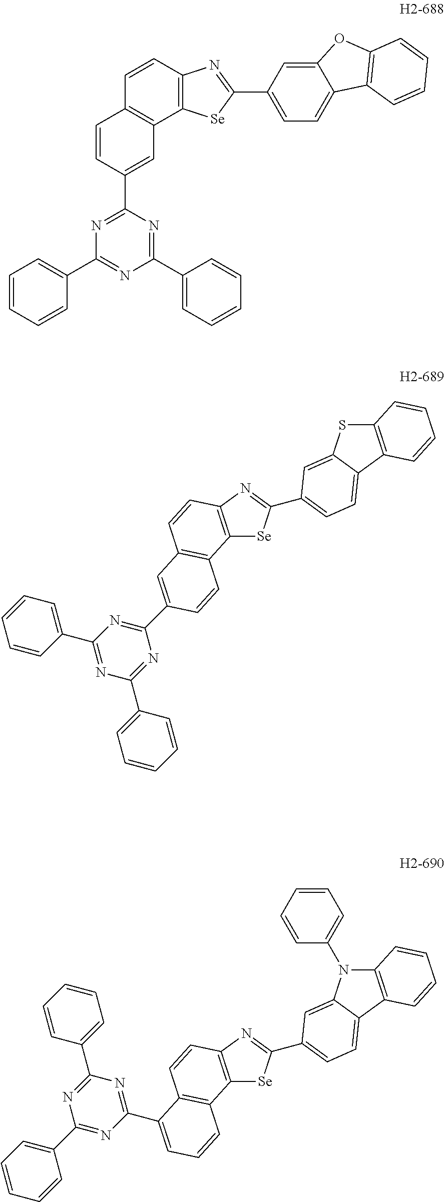 [SMILES: c1ccc(-c2nc(-c3ccccc3)nc(-c3ccc4ccc5nc(-c6ccc7c(c6)oc6ccccc67)[se]c5c4c3)n2)cc1 ; c1ccc(-c2nc(-c3ccccc3)nc(-c3ccc4c(ccc5nc(-c6ccc7c(c6)sc6ccccc67)[se]c54)c3)n2)cc1 ; c1ccc(-c2nc(-c3ccccc3)nc(-c3cccc4c3ccc3nc(-c5ccc6c7ccccc7n(-c7ccccc7)c6c5)[se]c34)n2)cc1]

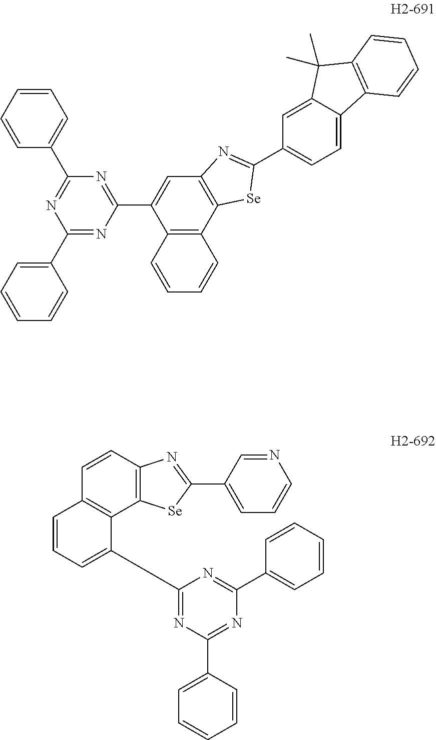 [SMILES: CC1(C)c2ccccc2-c2ccc(-c3nc4cc(-c5nc(-c6ccccc6)nc(-c6ccccc6)n5)c5ccccc5c4[se]3)cc21 ; c1ccc(-c2nc(-c3ccccc3)nc(-c3cccc4ccc5nc(-c6cccnc6)[se]c5c34)n2)cc1]

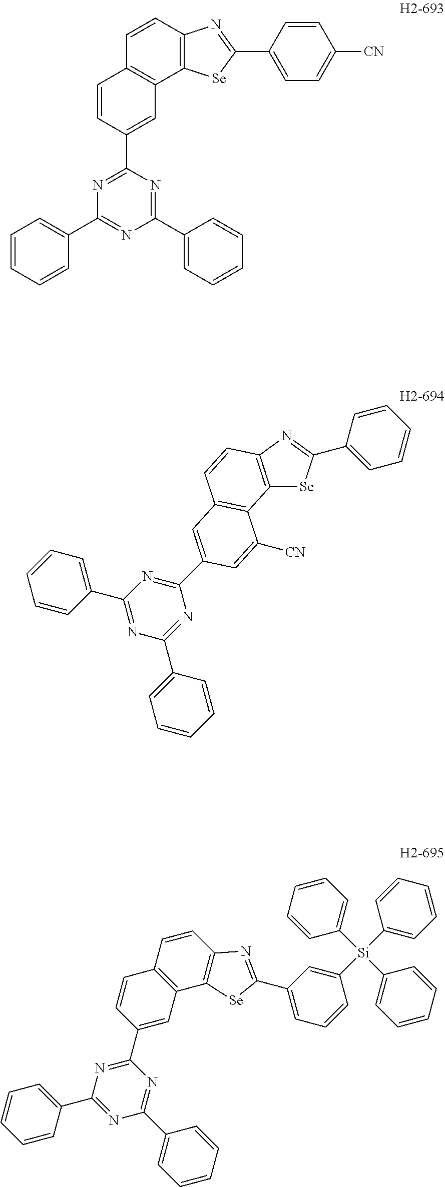 [SMILES: N#Cc1ccc(-c2nc3ccc4ccc(-c5nc(-c6ccccc6)nc(-c6ccccc6)n5)cc4c3[se]2)cc1 ; N#Cc1cc(-c2nc(-c3ccccc3)nc(-c3ccccc3)n2)cc2ccc3nc(-c4ccccc4)[se]c3c12 ; c1ccc(-c2nc(-c3ccccc3)nc(-c3ccc4ccc5nc(-c6cccc([Si](c7ccccc7)(c7ccccc7)c7ccccc7)c6)[se]c5c4c3)n2)cc1]

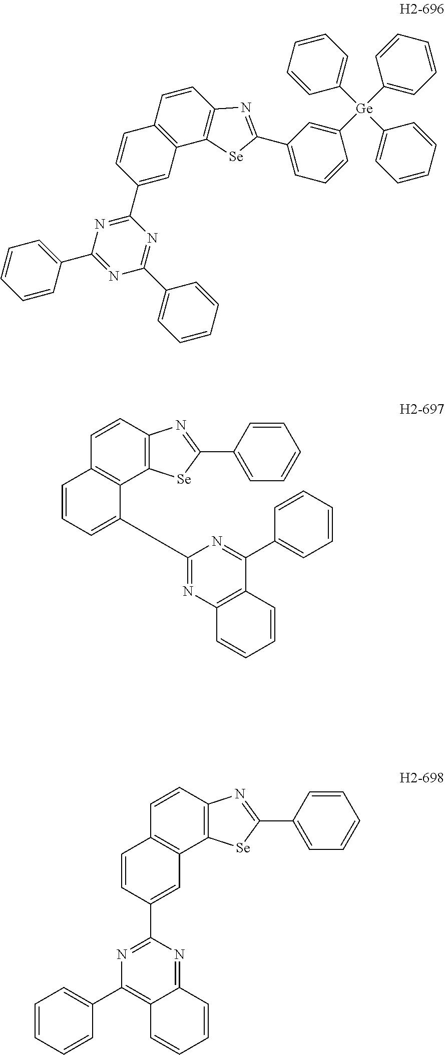

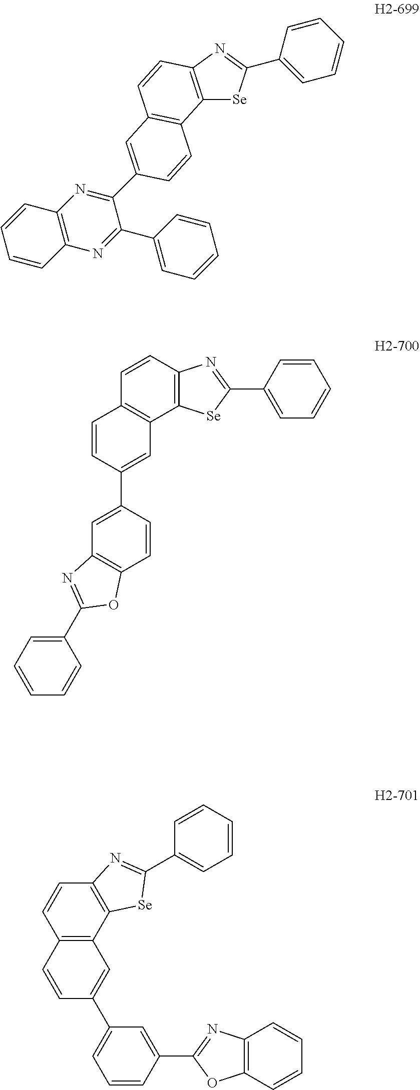 [SMILES: c1ccc(-c2nc3ccc4cc(-c5nc6ccccc6nc5-c5ccccc5)ccc4c3[se]2)cc1 ; c1ccc(-c2nc3cc(-c4ccc5ccc6nc(-c7ccccc7)[se]c6c5c4)ccc3o2)cc1 ; c1ccc(-c2nc3ccc4ccc(-c5cccc(-c6nc7ccccc7o6)c5)cc4c3[se]2)cc1]

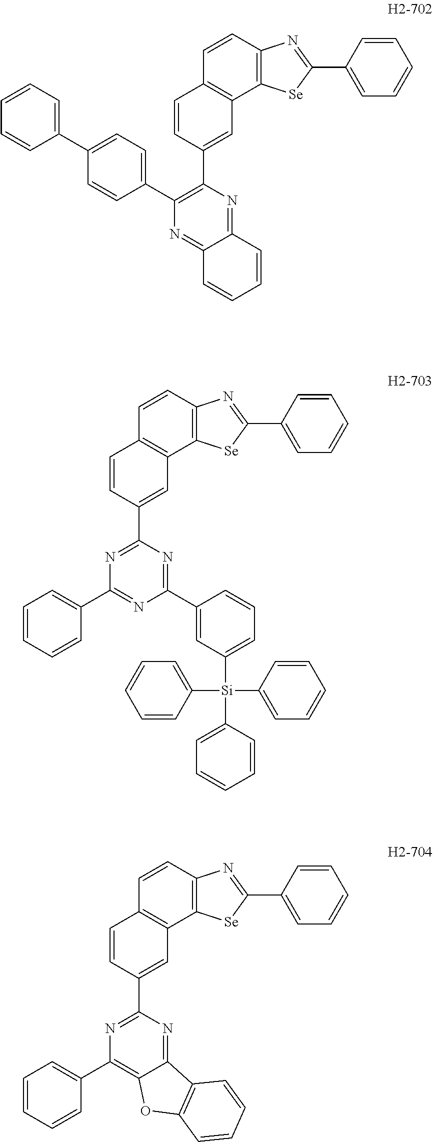 [SMILES: c1ccc(-c2ccc(-c3nc4ccccc4nc3-c3ccc4ccc5nc(-c6ccccc6)[se]c5c4c3)cc2)cc1 ; c1ccc(-c2nc(-c3cccc([Si](c4ccccc4)(c4ccccc4)c4ccccc4)c3)nc(-c3ccc4ccc5nc(-c6ccccc6)[se]c5c4c3)n2)cc1 ; c1ccc(-c2nc3ccc4ccc(-c5nc(-c6ccccc6)c6oc7ccccc7c6n5)cc4c3[se]2)cc1]

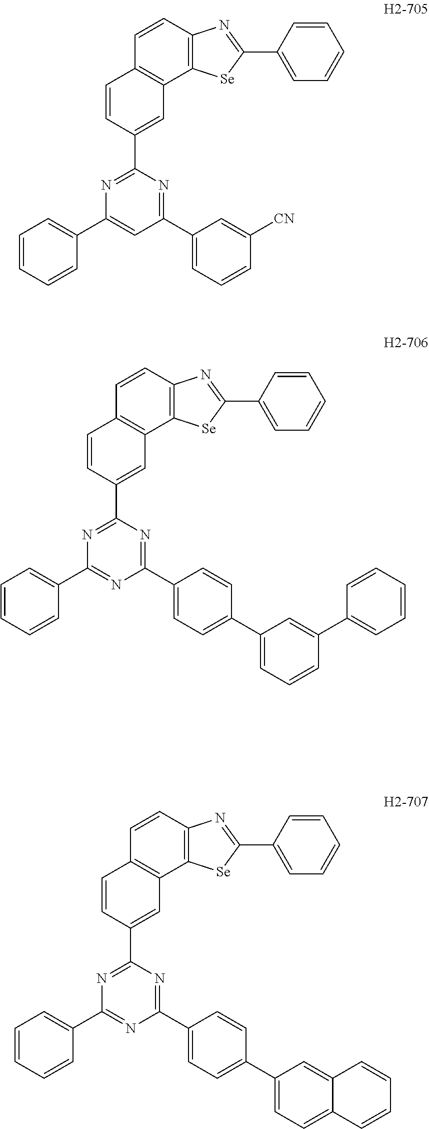 [SMILES: N#Cc1cccc(-c2cc(-c3ccccc3)nc(-c3ccc4ccc5nc(-c6ccccc6)[se]c5c4c3)n2)c1 ; c1ccc(-c2cccc(-c3ccc(-c4nc(-c5ccccc5)nc(-c5ccc6ccc7nc(-c8ccccc8)[se]c7c6c5)n4)cc3)c2)cc1 ; c1ccc(-c2nc(-c3ccc(-c4ccc5ccccc5c4)cc3)nc(-c3ccc4ccc5nc(-c6ccccc6)[se]c5c4c3)n2)cc1]

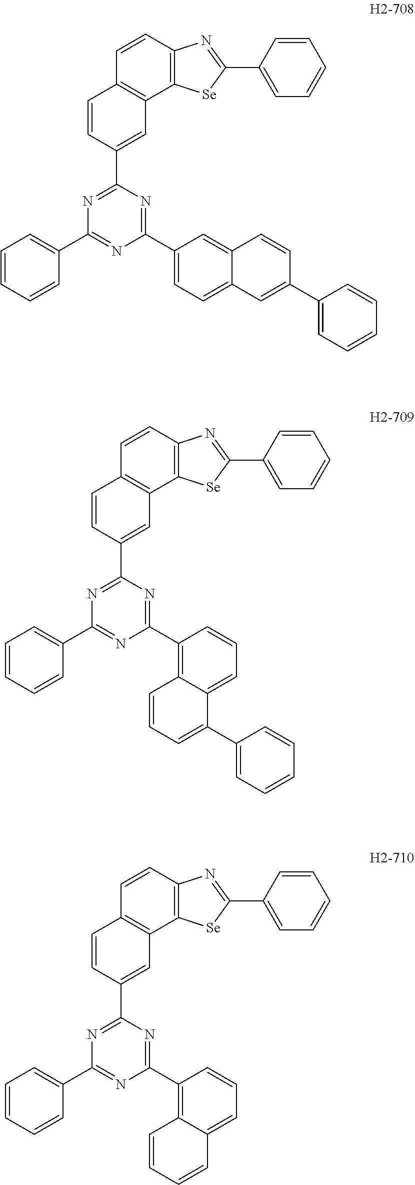 [SMILES: c1ccc(-c2ccc3cc(-c4nc(-c5ccccc5)nc(-c5ccc6ccc7nc(-c8ccccc8)[se]c7c6c5)n4)ccc3c2)cc1 ; c1ccc(-c2nc(-c3ccc4ccc5nc(-c6ccccc6)[se]c5c4c3)nc(-c3cccc4c(-c5ccccc5)cccc34)n2)cc1 ; c1ccc(-c2nc(-c3ccc4ccc5nc(-c6ccccc6)[se]c5c4c3)nc(-c3cccc4ccccc34)n2)cc1]

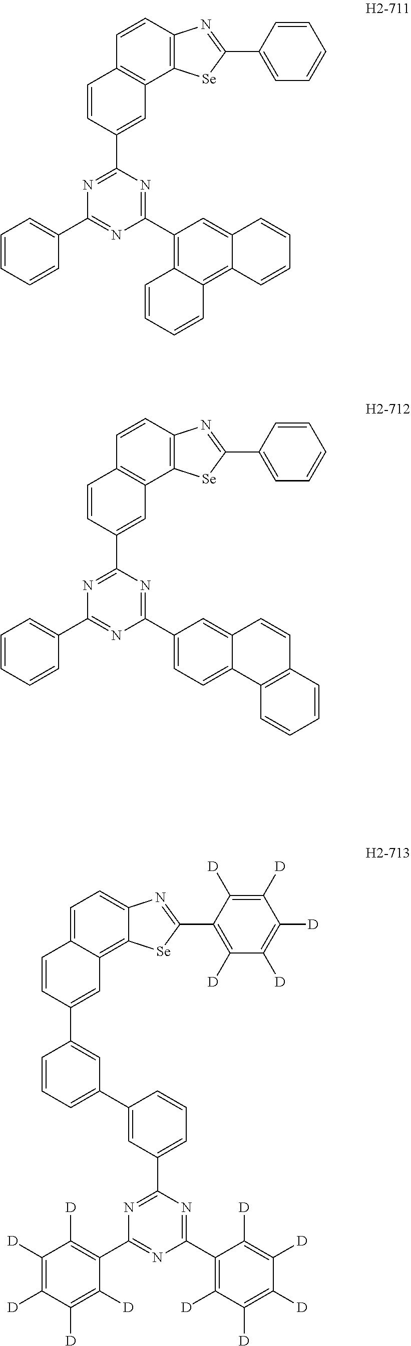 [SMILES: c1ccc(-c2nc(-c3ccc4ccc5nc(-c6ccccc6)[se]c5c4c3)nc(-c3cc4ccccc4c4ccccc34)n2)cc1 ; c1ccc(-c2nc(-c3ccc4c(ccc5ccccc54)c3)nc(-c3ccc4ccc5nc(-c6ccccc6)[se]c5c4c3)n2)cc1 ; [2H]c1c([2H])c([2H])c(-c2nc(-c3cccc(-c4cccc(-c5ccc6ccc7nc(-c8c([2H])c([2H])c([2H])c([2H])c8[2H])[se]c7c6c5)c4)c3)nc(-c3c([2H])c([2H])c([2H])c([2H])c3[2H])n2)c([2H])c1[2H]]

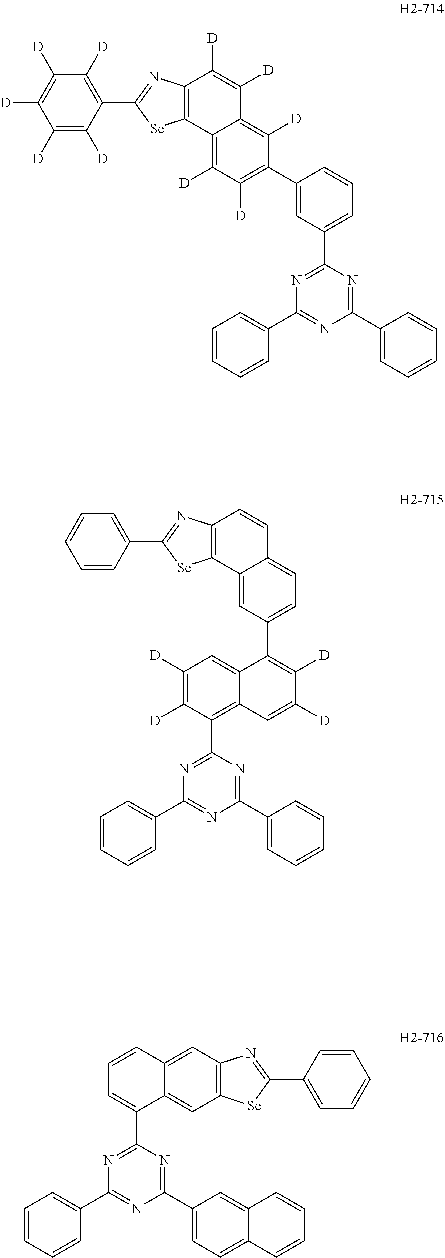 [SMILES: [2H]c1c([2H])c([2H])c(-c2nc3c([2H])c([2H])c4c([2H])c(-c5cccc(-c6nc(-c7ccccc7)nc(-c7ccccc7)n6)c5)c([2H])c([2H])c4c3[se]2)c([2H])c1[2H] ; [2H]c1cc2c(-c3nc(-c4ccccc4)nc(-c4ccccc4)n3)c([2H])c([2H])cc2c(-c2ccc3ccc4nc(-c5ccccc5)[se]c4c3c2)c1[2H] ; c1ccc(-c2nc(-c3ccc4ccccc4c3)nc(-c3cccc4cc5nc(-c6ccccc6)[se]c5cc34)n2)cc1]

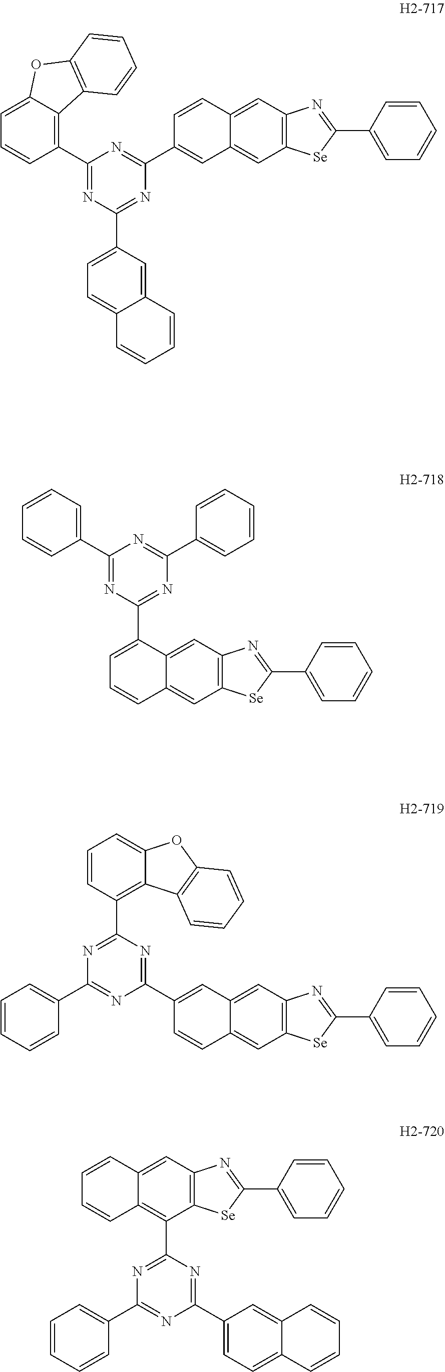 [SMILES: c1ccc(-c2nc3cc4ccc(-c5nc(-c6ccc7ccccc7c6)nc(-c6cccc7oc8ccccc8c67)n5)cc4cc3[se]2)cc1 ; c1ccc(-c2nc(-c3ccccc3)nc(-c3cccc4cc5[se]c(-c6ccccc6)nc5cc34)n2)cc1 ; c1ccc(-c2nc(-c3ccc4cc5[se]c(-c6ccccc6)nc5cc4c3)nc(-c3cccc4oc5ccccc5c34)n2)cc1 ; c1ccc(-c2nc(-c3ccc4ccccc4c3)nc(-c3c4ccccc4cc4nc(-c5ccccc5)[se]c34)n2)cc1]

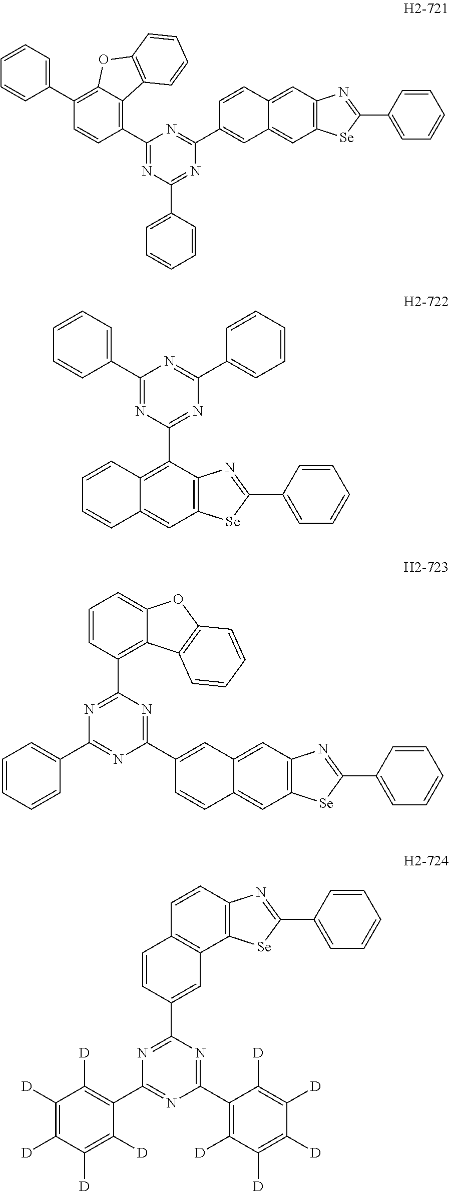 [SMILES: c1ccc(-c2nc(-c3ccc4cc5nc(-c6ccccc6)[se]c5cc4c3)nc(-c3ccc(-c4ccccc4)c4oc5ccccc5c34)n2)cc1 ; c1ccc(-c2nc(-c3ccccc3)nc(-c3c4ccccc4cc4[se]c(-c5ccccc5)nc34)n2)cc1 ; c1ccc(-c2nc(-c3ccc4cc5[se]c(-c6ccccc6)nc5cc4c3)nc(-c3cccc4oc5ccccc5c34)n2)cc1 ; [2H]c1c([2H])c([2H])c(-c2nc(-c3ccc4ccc5nc(-c6ccccc6)[se]c5c4c3)nc(-c3c([2H])c([2H])c([2H])c([2H])c3[2H])n2)c([2H])c1[2H]]

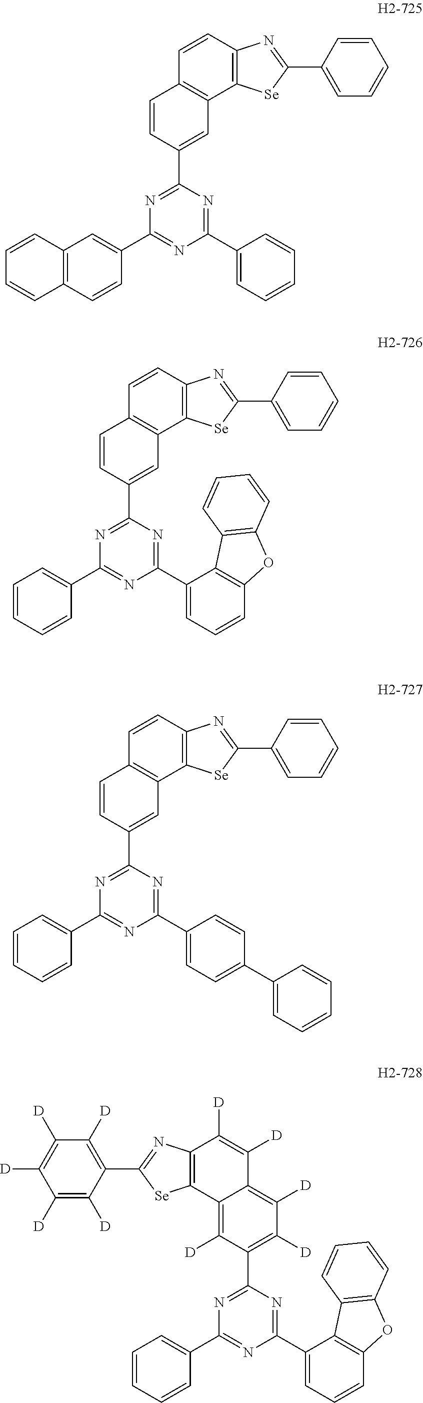 [SMILES: c1ccc(-c2nc(-c3ccc4ccccc4c3)nc(-c3ccc4ccc5nc(-c6ccccc6)[se]c5c4c3)n2)cc1 ; c1ccc(-c2nc(-c3ccc4ccc5nc(-c6ccccc6)[se]c5c4c3)nc(-c3cccc4oc5ccccc5c34)n2)cc1 ; c1ccc(-c2ccc(-c3nc(-c4ccccc4)nc(-c4ccc5ccc6nc(-c7ccccc7)[se]c6c5c4)n3)cc2)cc1 ; [2H]c1c([2H])c([2H])c(-c2nc3c([2H])c([2H])c4c([2H])c([2H])c(-c5nc(-c6ccccc6)nc(-c6cccc7oc8ccccc8c67)n5)c([2H])c4c3[se]2)c([2H])c1[2H]]

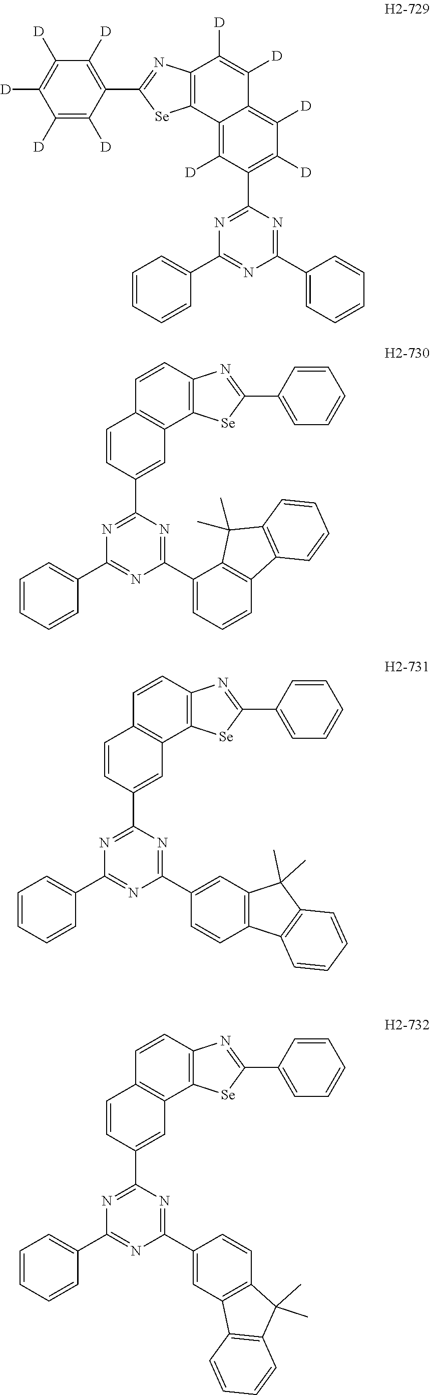

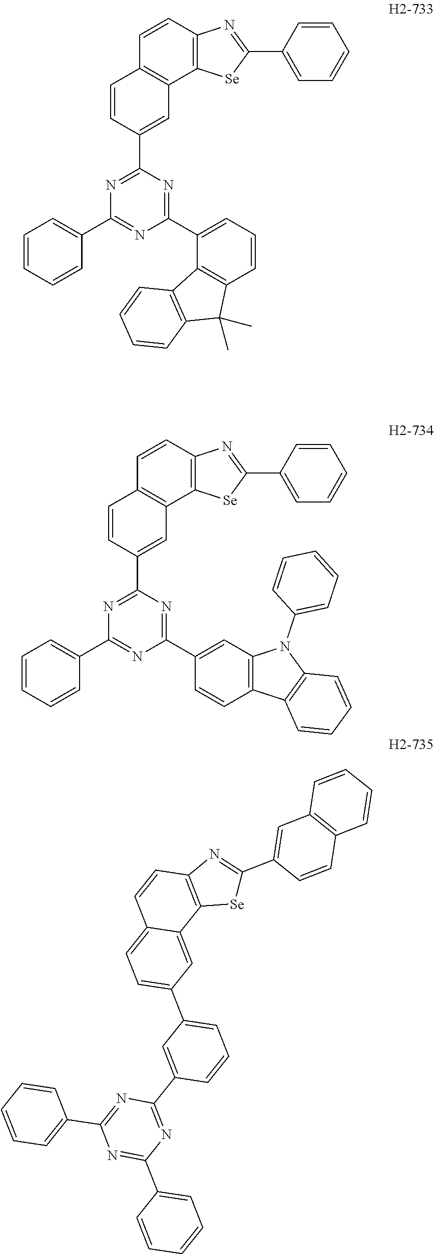

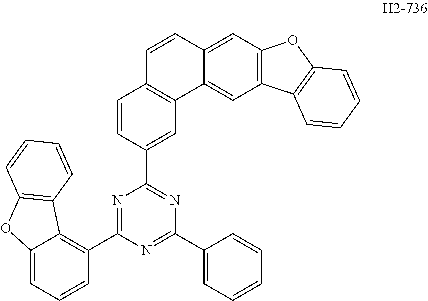 [SMILES: c1ccc(-c2nc(-c3ccc4ccc5cc6oc7ccccc7c6cc5c4c3)nc(-c3cccc4oc5ccccc5c34)n2)cc1]

The host compound represented by formula 2 according to the present disclosure may be prepared by a synthetic method known to those skilled in the art, for example, by referring to the synthesis method disclosed in KR 2020-0092879 A and the like.

According to another embodiment of the present disclosure, the present disclosure provides an organic electroluminescent compound represented by the following formula 1′.

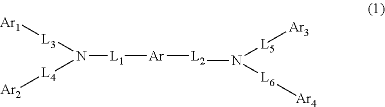

in formula 1′,

Ar represents a substituted or unsubstituted (C6-C30)arylene, a substituted or unsubstituted (3- to 30-membered)heteroarylene, or a substituent represented any one of the following formulas 1-1-1 to 1-1-21;

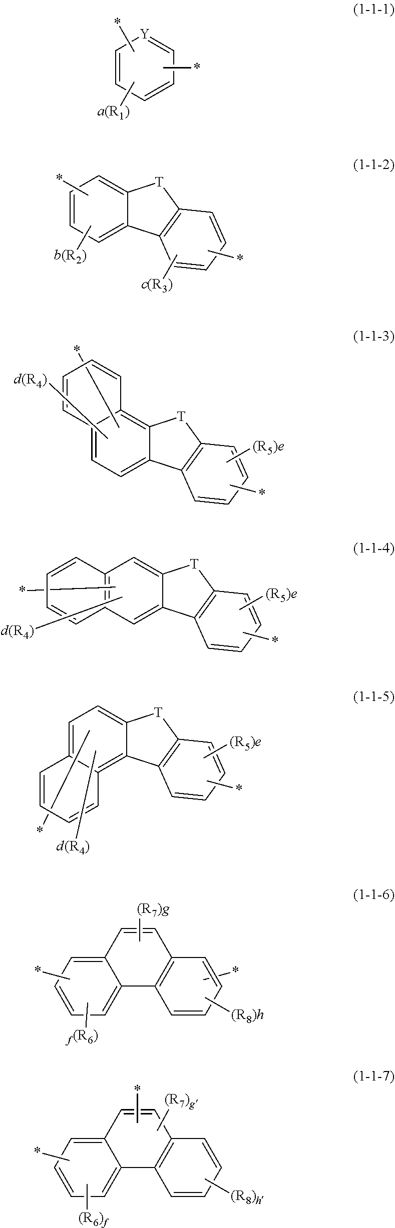

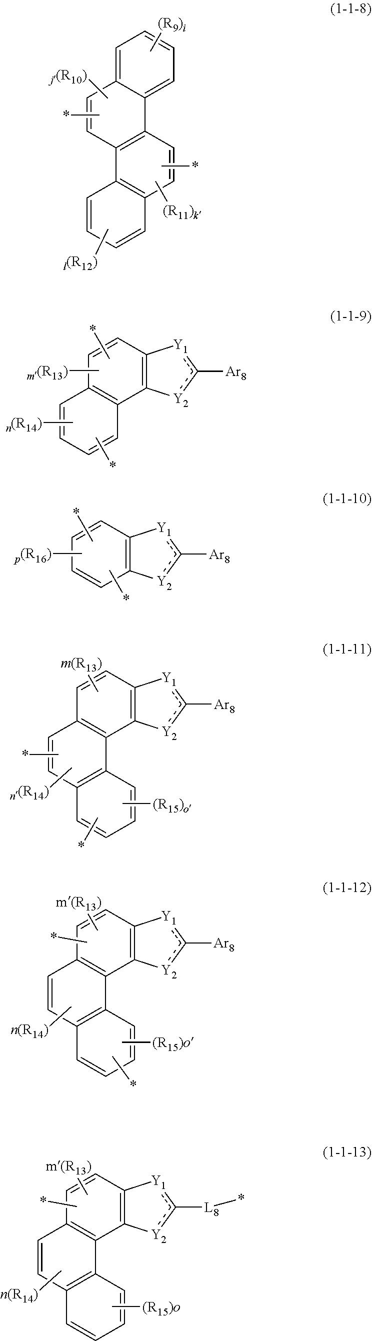

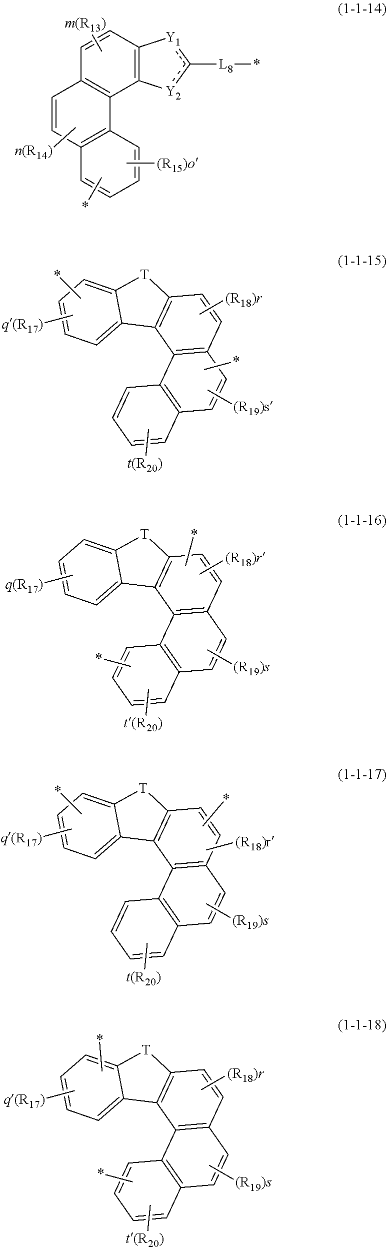

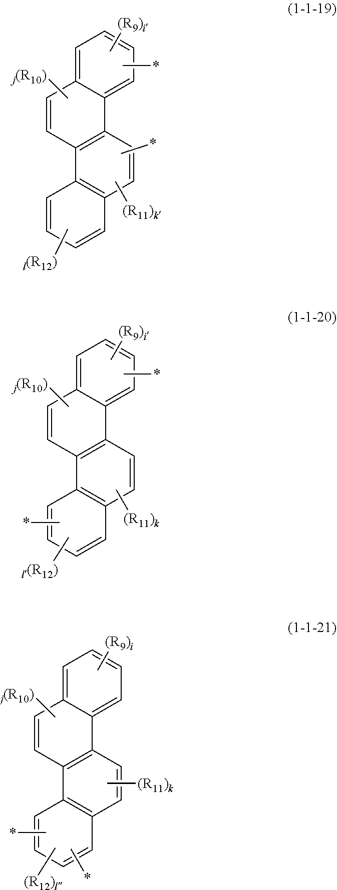

in formulas 1-1-1 to 1-1-21,

T represnts —O—, —S—, —CR₂₁R₂₂—, or —NR₂₃—;

Y represents CH or N;

Y₁ and Y₂ each independently represent, —N═, —NR₂₄—, —O—, —S— or —Se—; provided that any one of Y₁ and Y₂ is —N═, and the other of Y₁ and Y₂ is —NR₂₄—, —O—, —S— or —Se—;

R₁ to R₂₀ each independently represent, hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or —N—(R′)(R″); or may be linked to the adjacent substituents to form a ring(s);

R′ and R″ each independently represent, a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl;

R₂₁ to R₂₄ each independently represent, a substituted or unsubstituted (C1-C30)alkyl, a substituted or unsubstituted (C6-C30)aryl, or a substituted or unsubstituted (3- to 30-membered)heteroaryl; or may be linked to the adjacent substituents to form a ring(s);

Ar₈ represents a substituted or unsubstituted (C6-C30)aryl or a substituted or unsubstituted (3- to 30-membered)heteroaryl;

L₈ represents a single bond, a substituted or unsubstituted (C6-C30)arylene, or a substituted or unsubstituted (3- to 30-membered)heteroarylene;

h′, i, l, o, q, and t are an integer of 1 to 4; a, b, c, e, f, h, i′, l′, o′, q′, and t′ are an integer of 1 to 3; d is an integer of 1 to 5; g, j, k, l″, m, n, p, r, and s are an integer of 1 or 2; g′, j′, k′, m′, n′, r′ and s′ are 1;

when a to t, h′, i′, l′, l″, o′, q′, and t′ are an integer of 2 or more, each of R₁ to R₂₀ may be the same or different;

* represents a linking site with L₁ and L₂ in formula 1′;

L₁ to L₆ each independently represent, a single bond, a substituted or unsubstituted (C6-C30)arylene, a substituted or unsubstituted (C3-C30)cycloalkylene, or a substituted or unsubstituted (3- to 30-membered)heteroarylene;

Ar₁ to Ar₄ each independently represent, deuterium, a substituted or unsubstituted (C1-C30)alkyl, a substituted or unsubstituted (C6-C30)aryl, a substituted or unsubstituted fused ring of (C3-C30) aliphatic ring and (C6-C30) aromatic ring, or a substituted or unsubstituted (3- to 30-membered)heteroaryl; or may be linked to the adjacent substituents to form a ring(s); provided that at least one of Ar₁ to Ar₄ is a substituent selected from the following formulas 1-1, 1-8 to 1-15, 1-17 to 1-21, and 1-27;

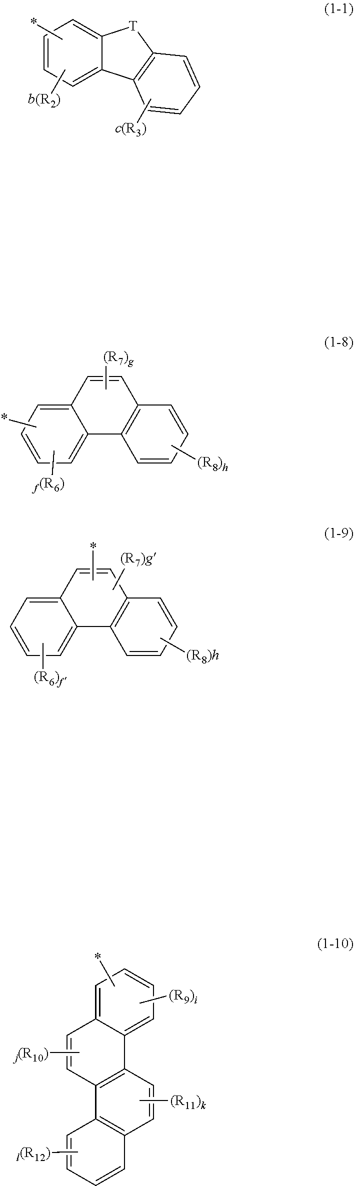

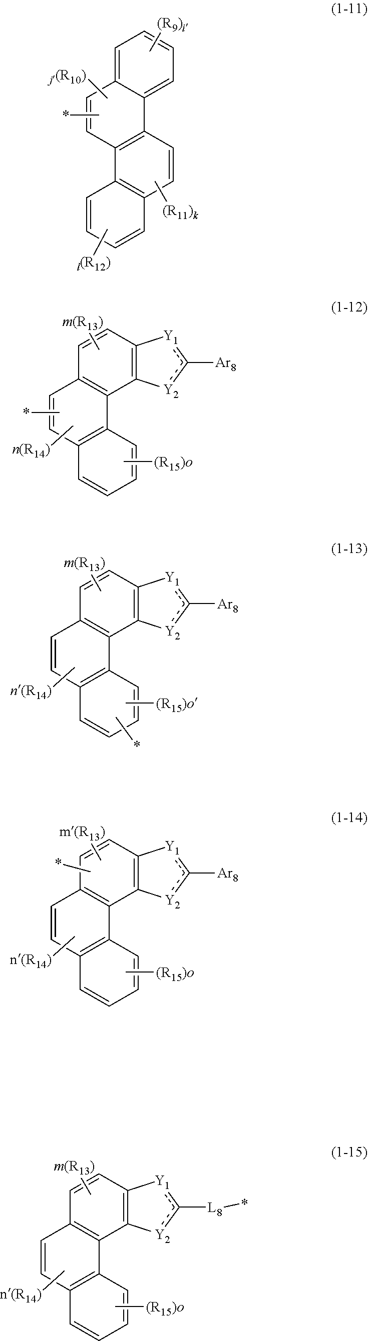

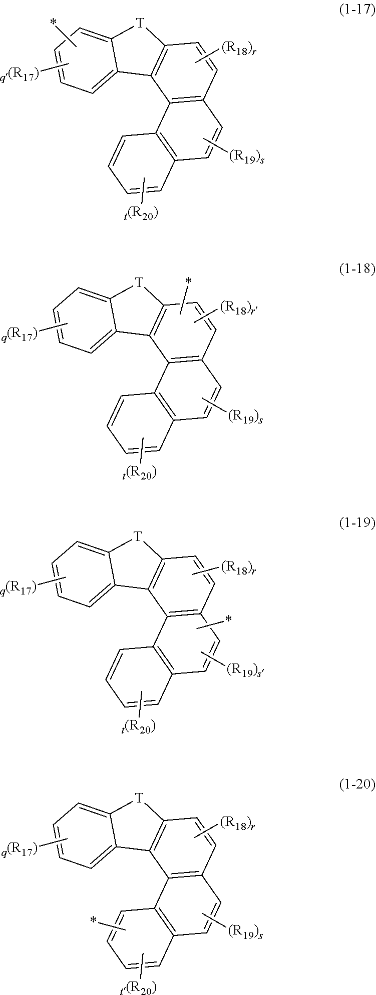

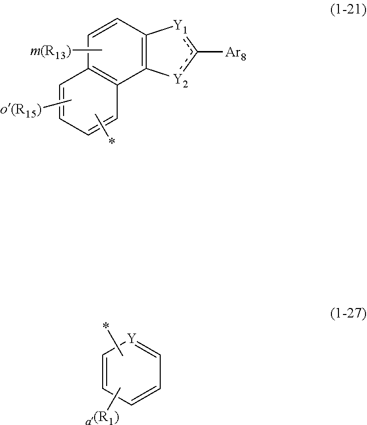

in formulas 1-1, 1-8 to 1-15, 1-17 to 1-21, and 1-27,

T represents —O—, —S—, —Se—, —CR₂₁R₂₂—, or —NR₂₃—;

Y represents CH or N;

Y₁ and Y₂ each independently represent, —N═, —NR₂₄—, —O—, —S—, or —Se—; provided that any one of Y₁ and Y₂ is —N═, and the other of Y₁ and Y₂ is —NR₂₄—, —O—, —S—, or —Se—;

R₁ to R₃, R₆ to R₁₅, and R₁₇ to R₂₀ each independently represent, hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or —N—(R′)(R″); or may be linked to the adjacent substituents to form a ring(s);

R′ and R″ each independently represent, a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl;

R₂₁ to R₂₄ each independently represent, a substituted or unsubstituted (C1-C30)alkyl, a substituted or unsubstituted (C6-C30)aryl, or a substituted or unsubstituted (3- to 30-membered)heteroaryl; or may be linked to the adjacent substituents to form a ring(s);

Ar₈ represents a substituted or unsubstituted (C6-C30)aryl or a substituted or unsubstituted (3- to 30-membered)heteroaryl;

L₈ represents a single bond, a substituted or unsubstituted (C6-C30)arylene, or a substituted or unsubstituted (3- to 30-membered)heteroarylene;

b, f, i, o′, q′, and t′ are an integer of 1 to 3; a′, c, h, f′, l, i′, o, q, and t are an integer of 1 to 4; g, j, k, m, n′, r, and s are an integer of 1 or 2; g′, j′, m′, n, r′, and s′ are 1;

when a′, b, c, f to m, o, q to t, f′ i′, n′, o′, q′, and t′ are an integer of 2 or more, each of R₁ to R₃, R₆ to R₁₅, and R₁₇ to R₂₀ may be the same or different; and

* represents a linking site with L₃ to L₆ in formula 1′.

In one embodiment, Ar may be a substituted or unsubstituted (C6-C30)arylene or a substituted or unsubstituted (5- to 30-membered)heteroarylene, preferably (C6-C25)arylene unsubstituted or substituted with at least one of deuterium; a substituted or unsubstituted (C6-C30)aryl; (5- to 30-membered)heteroaryl; and di(C6-C30)arylamino, or a substituted or unsubstituted (5- to 25-membered)heteroarylene, more preferably (C6-C18)arylene unsubstituted or substituted with at least one of deuterium; a substituted or unsubstituted (C6-C30)aryl; (5- to 30-membered)heteroaryl; and di(C6-C30)arylamino, or a substituted or unsubstituted (5- to 18-membered)heteroarylene. For example, Ar may be phenylene unsubstituted or substituted with at least one of deuterium; phenyl; carbazolyl; and diphenylamino, a substituted or unsubstituted naphthalenylene, a substituted or unsubstituted biphenylene, a substituted or unsubstituted phenanthrenylene, a substituted or unsubstituted chrysenylene, a substituted or unsubstituted pyridylene, or a substituted or unsubstituted dibenzofuranylene.

In one embodiment, in formula 1-1-1, Y may be CH; R₁ may be hydrogen, deuterium, a substituted or unsubstituted (C6-C30)aryl, a substituted or unsubstituted (5- to 30-membered)heteroaryl, or —N—(R′)(R″), for example, may be hydrogen, deuterium, phenyl, carbazolyl, naphthooxazolyl, and diphenylamino. For example, in formula 1-1-1, * may be a linking site with L₁ and L₂, and may be linked at the 1- and 2-positions, the 1- and 3-positions, and the 1- and 4-positions, respectively.

In one embodiment, in formula 1-1-1, Y may be N.

In one embodiment, L₁ to L₆ each independently may be a single bond, a substituted or unsubstituted (C6-C30)arylene, or a substituted or unsubstituted (5- to 30-membered)heteroarylene, preferably a single bond, a substituted or unsubstituted (C6-C25)arylene, or a substituted or unsubstituted (5- to 25-membered)heteroarylene, more preferably a single bond, a substituted or unsubstituted (C6-C18)arylene, or a substituted or unsubstituted (5- to 18-membered)heteroarylene. For example, L₁ to L₆ each independently may be a single bond, a substituted or unsubstituted phenylene, a substituted or unsubstituted pyridylene, or a substituted or unsubstituted carbazolylene. Wherein, the substituent of the substituted groups may be diphenylamino.

In one embodiment, Ar₁ to Ar₄ each independently may be a substituted or unsubstituted (C1-C30)alkyl, a substituted or unsubstituted (C6-C30)aryl, or a substituted or unsubstituted (5- to 30-membered)heteroaryl; or may be linked to the adjacent substituents to form a ring(s), preferably a substituted or unsubstituted (C1-C10)alkyl, a substituted or unsubstituted (C6-C25)aryl, or a substituted or unsubstituted (5- to 25-membered)heteroaryl; or may be linked to the adjacent substituents to form a substituted or unsubstituted (5- to 30-membered) monocyclic or polycyclic aromatic ring, more preferably a substituted or unsubstituted (C1-C4)alkyl, a substituted or unsubstituted (C6-C18)aryl, or a substituted or unsubstituted (5- to 18-membered)heteroaryl; or may be linked to the adjacent substituents to form a substituted or unsubstituted (5- to 30-membered) polycyclic aromatic ring. For example, Ar₁ to Ar₄ each independently may be a substituted or unsubstituted tert-butyl, phenyl unsubstituted or substituted with deuterium, naphthyl unsubstituted or substituted with phenyl, a substituted or unsubstituted p-biphenyl, a substituted or unsubstituted m-biphenyl, a substituted or unsubstituted o-biphenyl, a substituted or unsubstituted o-terphenyl, a substituted or unsubstituted fluorenyl, a substituted or unsubstituted phenanthrenyl, a substituted or unsubstituted chrysenyl, a substituted or unsubstituted pyridyl, a substituted or unsubstituted carbazolyl, a substituted or unsubstituted dibenzofuranyl, a substituted or unsubstituted dibenzothiophenyl, a substituted or unsubstituted dibenzoselenophenyl, a substituted or unsubstituted benzonaphthofuranyl, a substituted or unsubstituted benzonaphthothiophenyl, a substituted or unsubstituted benzophenanthrofuranyl, a substituted or unsubstituted naphthooxazolyl, a substituted or unsubstituted phenanthrooxazolyl, a substituted or unsubstituted naphthothiazolyl, or a substituted or unsubstituted phenanthrothiazolyl; or may be linked to the adjacent substituents to form a substituted or unsubstituted, carbazole ring, phenoxazine ring, or phenazine ring. Wherein, the substituent of the substituted groups may be deuterium, cyano, phenyl, pyridyl, diphenylamino, or phenylpyridylamino.

Provided that at least one of Ar₁ to Ar₄ is a substituent selected from the formulas 1-1, 1-8 to 1-15, 1-17 to 1-21, and 1-27.

In one embodiment, in formula 1-1, T may be —O—, —S—, —Se—, —CR₂₁R₂₂—, or —NR₂₃—, wherein R₂₁ to R₂₃ each independently may be a substituted or unsubstituted (C1-C10)alkyl, or a substituted or unsubstituted (C6-C25)aryl, preferably a substituted or unsubstituted (C1-C4)alkyl, or a substituted or unsubstituted (C6-C18)aryl, for example, may be methyl or phenyl.

In one embodiment, in formulas 1-17 to 1-20, T may be —O—, —S—, or —Se—.

In one embodiment, in formulas 1-12 to 1-15 and 1-21, any one of Y₁ and Y₂ may be —N═, and the other of Y₁ and Y₂ may be —O— or —S—.

In one embodiment, in formula 1-27, R₁ may be hydrogen, deuterium, a substituted or unsubstituted (C6-C30)aryl or a substituted or unsubstituted (5- to 30-membered)heteroaryl, preferably hydrogen, deuterium, a substituted or unsubstituted (C6-C25)aryl or a substituted or unsubstituted (5- to 25-membered)heteroaryl, more preferably, hydrogen, deuterium, a substituted or unsubstituted (C6-C18)aryl or a substituted or unsubstituted (5- to 18-membered)heteroaryl. For example, R₁ may be hydrogen, deuterium, phenyl, biphenyl, or phenanthrooxazolyl.

In one embodiment, R₂, R₃, R₆ to R₁₅, and R₁₇ to R₂₀ each independently may be hydrogen or deuterium.

In one embodiment, Ar₈ may be a substituted or unsubstituted (C6-C30)aryl, preferably a substituted or unsubstituted (C6-C25)aryl, more preferably a substituted or unsubstituted (C6-C18)aryl. For example, Ar₈ may be phenyl unsubstituted or substituted with deuterium.

According to one embodiment, the organic electroluminescent compound represented by formula 1′ may be more specifically illustrated by the following compounds, but is not limited thereto.

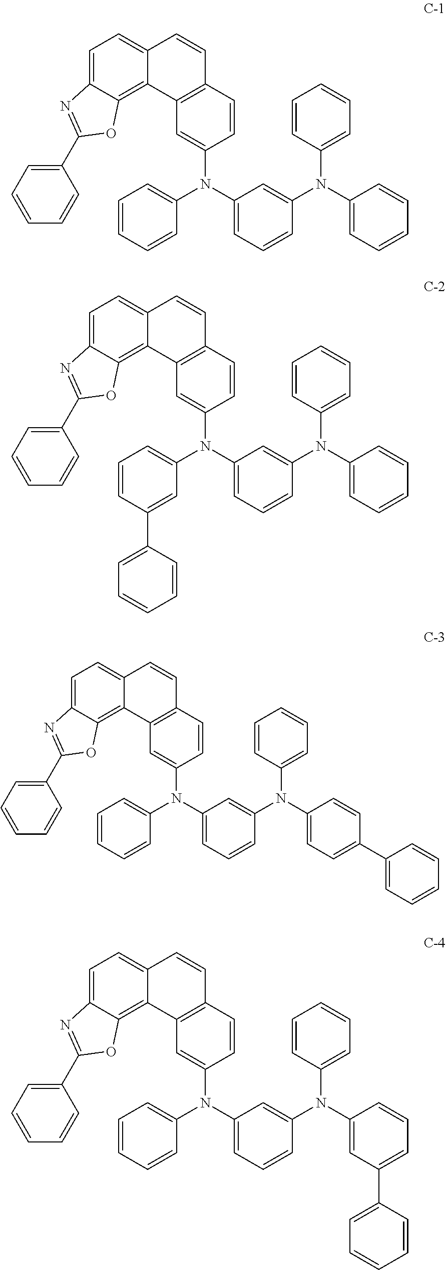 [SMILES: c1ccc(-c2nc3ccc4ccc5ccc(N(c6ccccc6)c6cccc(N(c7ccccc7)c7ccccc7)c6)cc5c4c3o2)cc1 ; c1ccc(-c2cccc(N(c3cccc(N(c4ccccc4)c4ccccc4)c3)c3ccc4ccc5ccc6nc(-c7ccccc7)oc6c5c4c3)c2)cc1 ; c1ccc(-c2ccc(N(c3ccccc3)c3cccc(N(c4ccccc4)c4ccc5ccc6ccc7nc(-c8ccccc8)oc7c6c5c4)c3)cc2)cc1 ; c1ccc(-c2cccc(N(c3ccccc3)c3cccc(N(c4ccccc4)c4ccc5ccc6ccc7nc(-c8ccccc8)oc7c6c5c4)c3)c2)cc1]

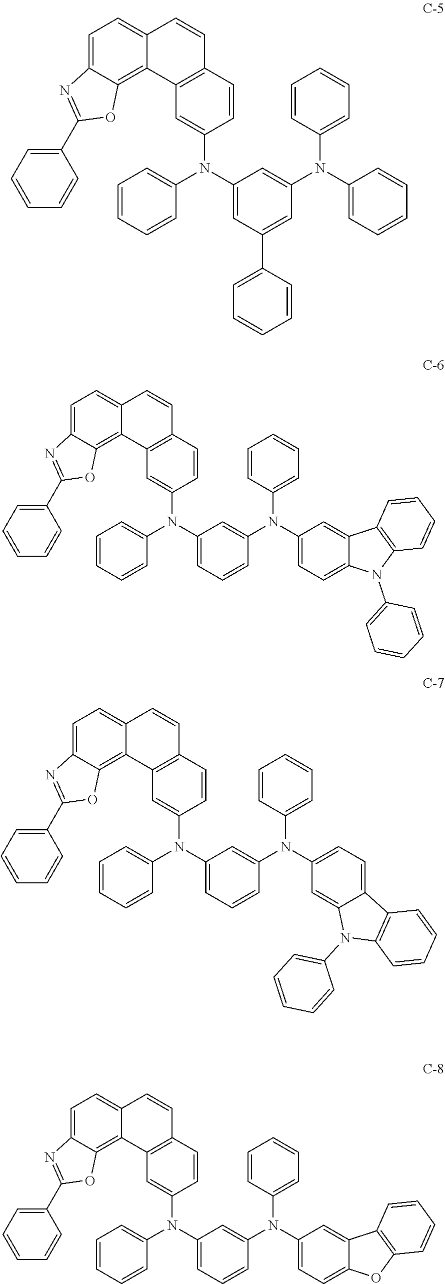 [SMILES: c1ccc(-c2cc(N(c3ccccc3)c3ccccc3)cc(N(c3ccccc3)c3ccc4ccc5ccc6nc(-c7ccccc7)oc6c5c4c3)c2)cc1 ; c1ccc(-c2nc3ccc4ccc5ccc(N(c6ccccc6)c6cccc(N(c7ccccc7)c7ccc8c(c7)c7ccccc7n8-c7ccccc7)c6)cc5c4c3o2)cc1 ; c1ccc(-c2nc3ccc4ccc5ccc(N(c6ccccc6)c6cccc(N(c7ccccc7)c7ccc8c9ccccc9n(-c9ccccc9)c8c7)c6)cc5c4c3o2)cc1 ; c1ccc(-c2nc3ccc4ccc5ccc(N(c6ccccc6)c6cccc(N(c7ccccc7)c7ccc8oc9ccccc9c8c7)c6)cc5c4c3o2)cc1]

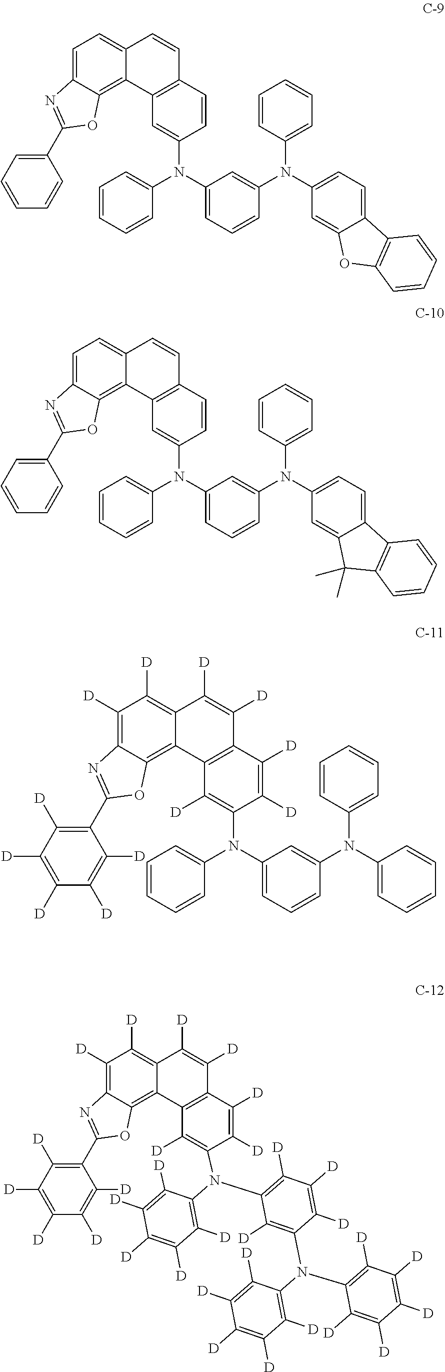

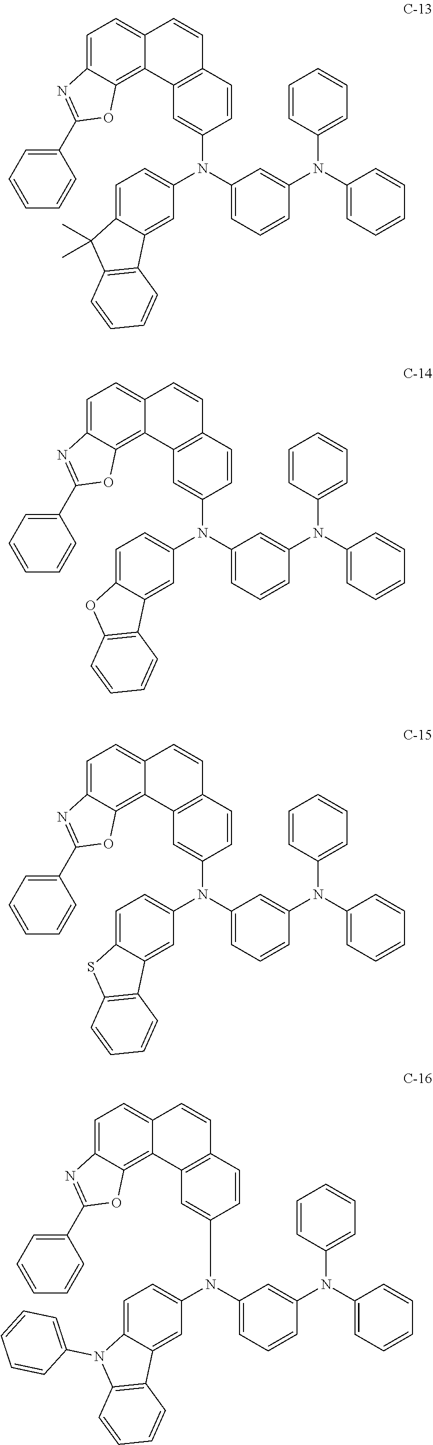 [SMILES: CC1(C)c2ccccc2-c2cc(N(c3cccc(N(c4ccccc4)c4ccccc4)c3)c3ccc4ccc5ccc6nc(-c7ccccc7)oc6c5c4c3)ccc21 ; c1ccc(-c2nc3ccc4ccc5ccc(N(c6cccc(N(c7ccccc7)c7ccccc7)c6)c6ccc7oc8ccccc8c7c6)cc5c4c3o2)cc1 ; c1ccc(-c2nc3ccc4ccc5ccc(N(c6cccc(N(c7ccccc7)c7ccccc7)c6)c6ccc7sc8ccccc8c7c6)cc5c4c3o2)cc1 ; c1ccc(-c2nc3ccc4ccc5ccc(N(c6cccc(N(c7ccccc7)c7ccccc7)c6)c6ccc7c(c6)c6ccccc6n7-c6ccccc6)cc5c4c3o2)cc1]

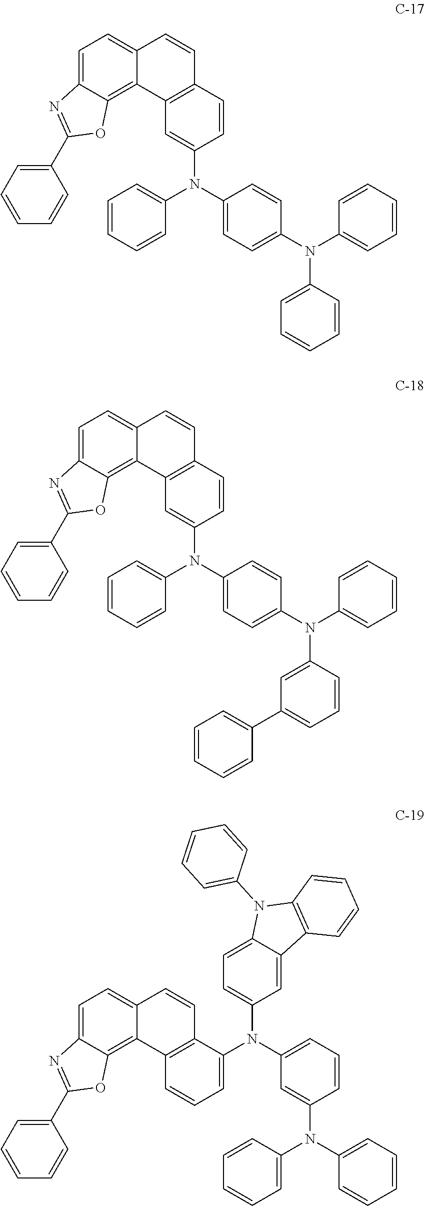 [SMILES: c1ccc(-c2nc3ccc4ccc5ccc(N(c6ccccc6)c6ccc(N(c7ccccc7)c7ccccc7)cc6)cc5c4c3o2)cc1 ; c1ccc(-c2cccc(N(c3ccccc3)c3ccc(N(c4ccccc4)c4ccc5ccc6ccc7nc(-c8ccccc8)oc7c6c5c4)cc3)c2)cc1 ; c1ccc(-c2nc3ccc4ccc5c(N(c6cccc(N(c7ccccc7)c7ccccc7)c6)c6ccc7c(c6)c6ccccc6n7-c6ccccc6)cccc5c4c3o2)cc1]

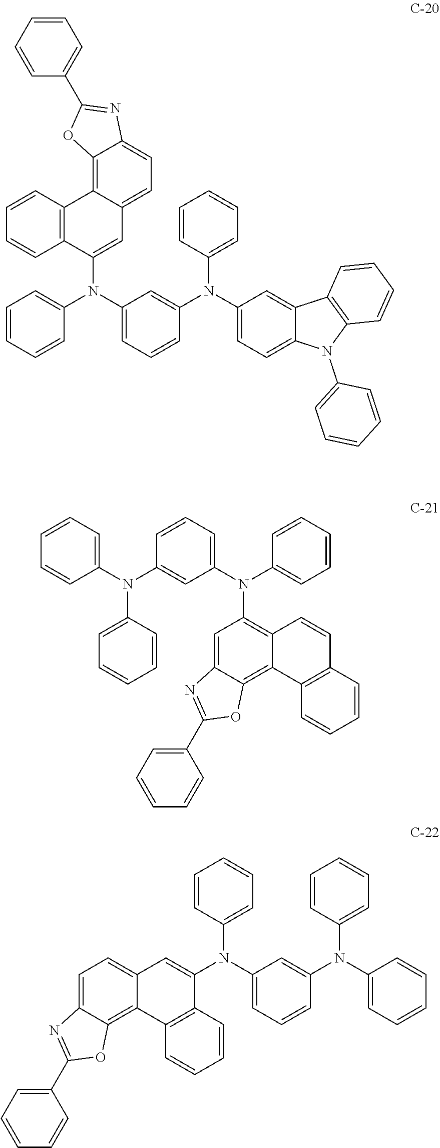 [SMILES: c1ccc(-c2nc3ccc4cc(N(c5ccccc5)c5cccc(N(c6ccccc6)c6ccc7c(c6)c6ccccc6n7-c6ccccc6)c5)c5ccccc5c4c3o2)cc1 ; c1ccc(-c2nc3cc(N(c4ccccc4)c4cccc(N(c5ccccc5)c5ccccc5)c4)c4ccc5ccccc5c4c3o2)cc1 ; c1ccc(-c2nc3ccc4cc(N(c5ccccc5)c5cccc(N(c6ccccc6)c6ccccc6)c5)c5ccccc5c4c3o2)cc1]

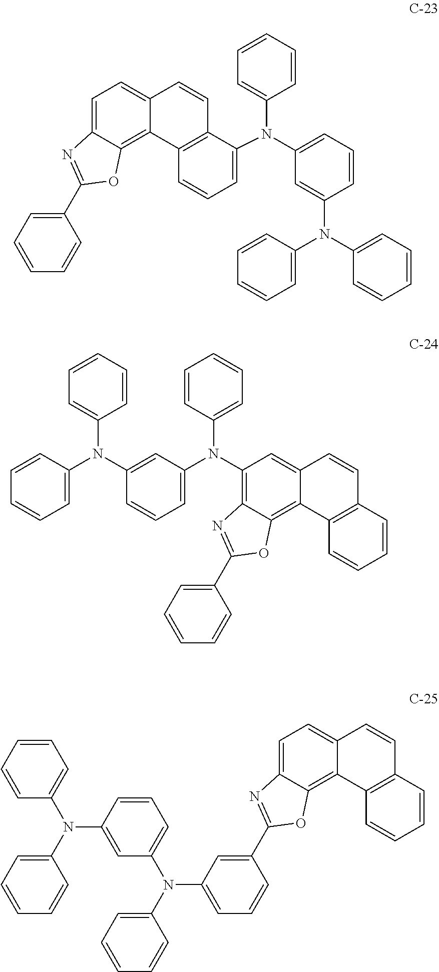 [SMILES: c1ccc(-c2nc3ccc4ccc5c(N(c6ccccc6)c6cccc(N(c7ccccc7)c7ccccc7)c6)cccc5c4c3o2)cc1 ; c1ccc(-c2nc3c(N(c4ccccc4)c4cccc(N(c5ccccc5)c5ccccc5)c4)cc4ccc5ccccc5c4c3o2)cc1 ; c1ccc(N(c2ccccc2)c2cccc(N(c3ccccc3)c3cccc(-c4nc5ccc6ccc7ccccc7c6c5o4)c3)c2)cc1]

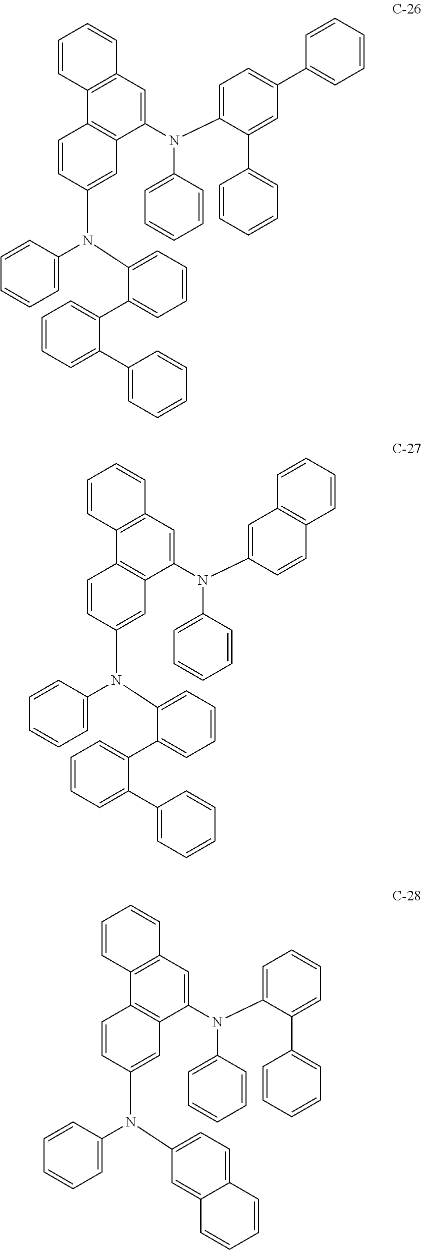 [SMILES: c1ccc(-c2ccc(N(c3ccccc3)c3cc4ccccc4c4ccc(N(c5ccccc5)c5ccccc5-c5ccccc5-c5ccccc5)cc34)c(-c3ccccc3)c2)cc1 ; c1ccc(-c2ccccc2-c2ccccc2N(c2ccccc2)c2ccc3c(c2)c(N(c2ccccc2)c2ccc4ccccc4c2)cc2ccccc23)cc1 ; c1ccc(-c2ccccc2N(c2ccccc2)c2cc3ccccc3c3ccc(N(c4ccccc4)c4ccc5ccccc5c4)cc23)cc1]

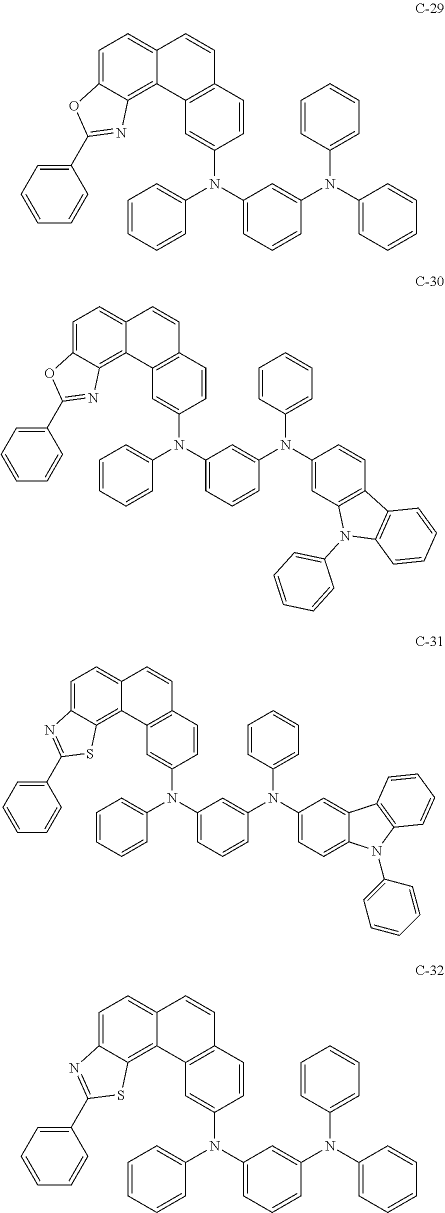 [SMILES: c1ccc(-c2nc3c(ccc4ccc5ccc(N(c6ccccc6)c6cccc(N(c7ccccc7)c7ccccc7)c6)cc5c43)o2)cc1 ; c1ccc(-c2nc3c(ccc4ccc5ccc(N(c6ccccc6)c6cccc(N(c7ccccc7)c7ccc8c9ccccc9n(-c9ccccc9)c8c7)c6)cc5c43)o2)cc1 ; c1ccc(-c2nc3ccc4ccc5ccc(N(c6ccccc6)c6cccc(N(c7ccccc7)c7ccc8c(c7)c7ccccc7n8-c7ccccc7)c6)cc5c4c3s2)cc1 ; c1ccc(-c2nc3ccc4ccc5ccc(N(c6ccccc6)c6cccc(N(c7ccccc7)c7ccccc7)c6)cc5c4c3s2)cc1]

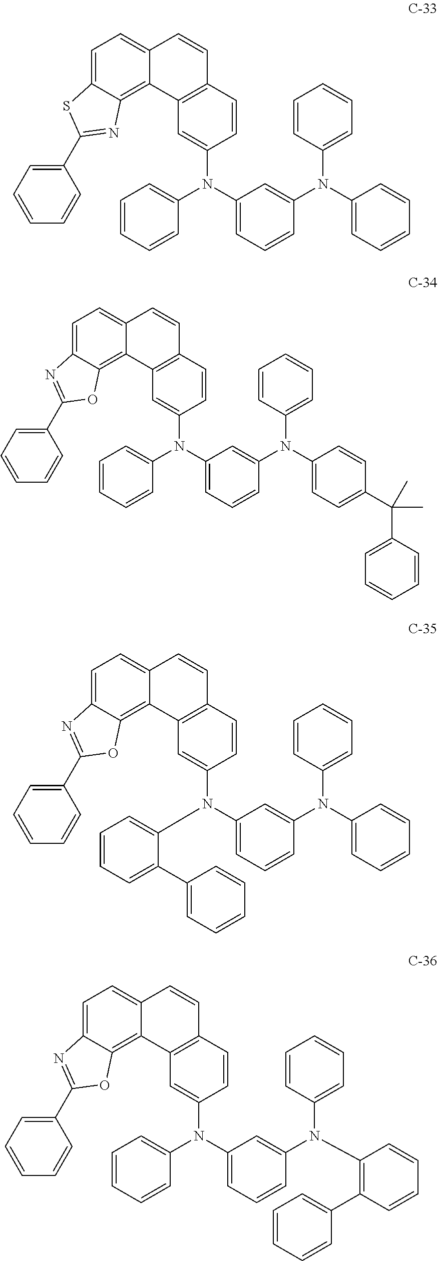 [SMILES: c1ccc(-c2nc3c(ccc4ccc5ccc(N(c6ccccc6)c6cccc(N(c7ccccc7)c7ccccc7)c6)cc5c43)s2)cc1 ; CC(C)(c1ccccc1)c1ccc(N(c2ccccc2)c2cccc(N(c3ccccc3)c3ccc4ccc5ccc6nc(-c7ccccc7)oc6c5c4c3)c2)cc1 ; c1ccc(-c2nc3ccc4ccc5ccc(N(c6cccc(N(c7ccccc7)c7ccccc7)c6)c6ccccc6-c6ccccc6)cc5c4c3o2)cc1 ; c1ccc(-c2nc3ccc4ccc5ccc(N(c6ccccc6)c6cccc(N(c7ccccc7)c7ccccc7-c7ccccc7)c6)cc5c4c3o2)cc1]

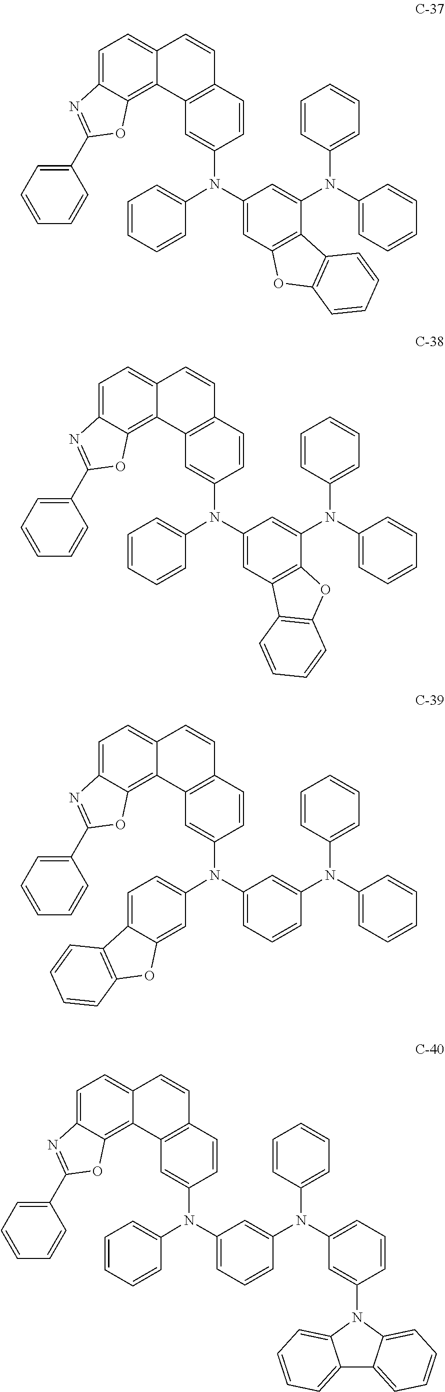 [SMILES: c1ccc(-c2nc3ccc4ccc5ccc(N(c6ccccc6)c6cc(N(c7ccccc7)c7ccccc7)c7c(c6)oc6ccccc67)cc5c4c3o2)cc1 ; c1ccc(-c2nc3ccc4ccc5ccc(N(c6ccccc6)c6cc(N(c7ccccc7)c7ccccc7)c7oc8ccccc8c7c6)cc5c4c3o2)cc1 ; c1ccc(-c2nc3ccc4ccc5ccc(N(c6cccc(N(c7ccccc7)c7ccccc7)c6)c6ccc7c(c6)oc6ccccc67)cc5c4c3o2)cc1 ; c1ccc(-c2nc3ccc4ccc5ccc(N(c6ccccc6)c6cccc(N(c7ccccc7)c7cccc(-n8c9ccccc9c9ccccc98)c7)c6)cc5c4c3o2)cc1]

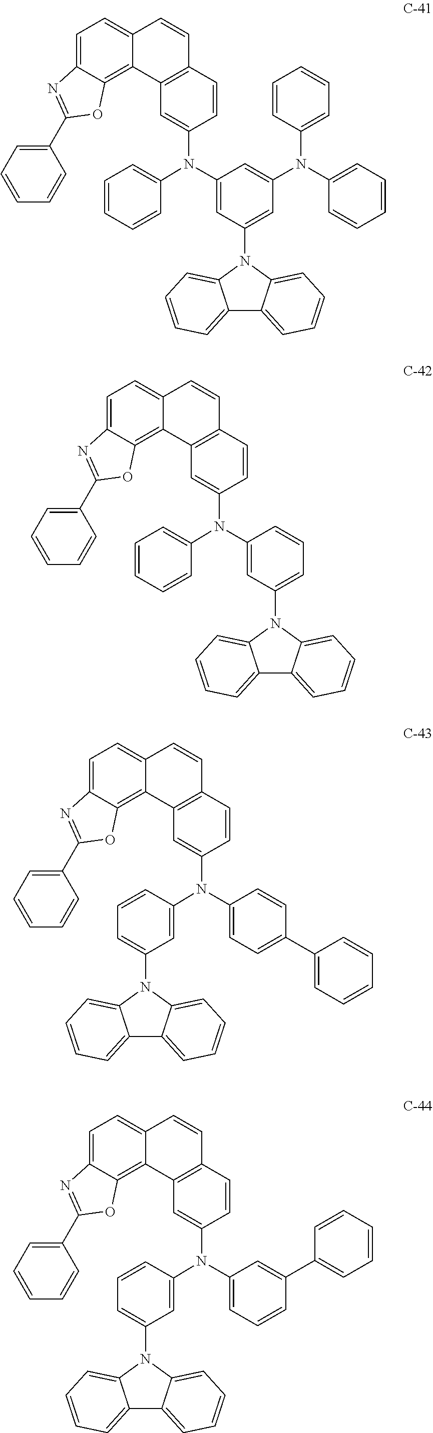 [SMILES: c1ccc(-c2nc3ccc4ccc5ccc(N(c6ccccc6)c6cc(N(c7ccccc7)c7ccccc7)cc(-n7c8ccccc8c8ccccc87)c6)cc5c4c3o2)cc1 ; c1ccc(-c2nc3ccc4ccc5ccc(N(c6ccccc6)c6cccc(-n7c8ccccc8c8ccccc87)c6)cc5c4c3o2)cc1 ; c1ccc(-c2ccc(N(c3cccc(-n4c5ccccc5c5ccccc54)c3)c3ccc4ccc5ccc6nc(-c7ccccc7)oc6c5c4c3)cc2)cc1 ; c1ccc(-c2cccc(N(c3cccc(-n4c5ccccc5c5ccccc54)c3)c3ccc4ccc5ccc6nc(-c7ccccc7)oc6c5c4c3)c2)cc1]

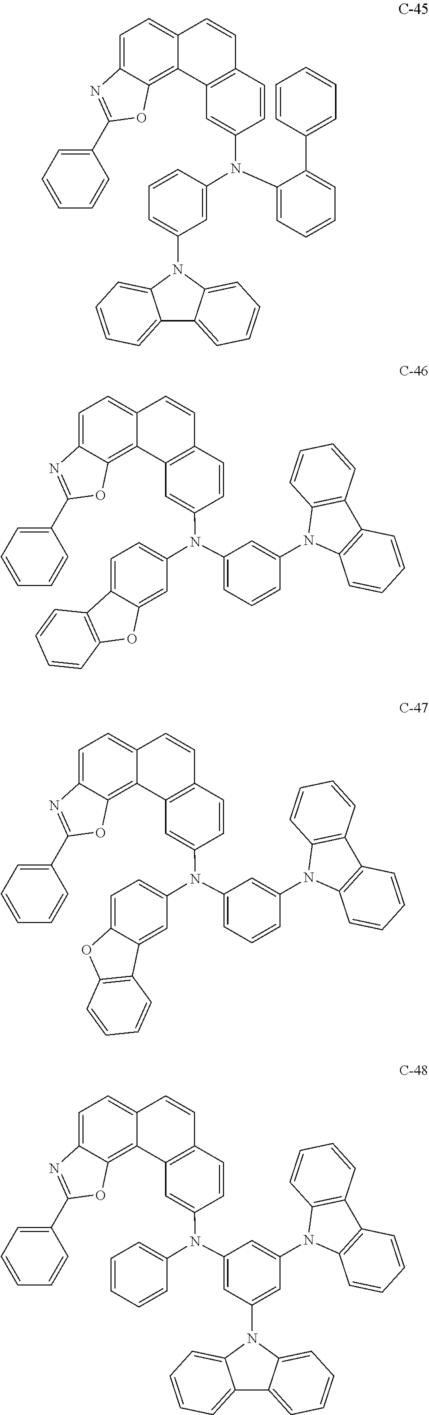 [SMILES: c1ccc(-c2nc3ccc4ccc5ccc(N(c6cccc(-n7c8ccccc8c8ccccc87)c6)c6ccccc6-c6ccccc6)cc5c4c3o2)cc1 ; c1ccc(-c2nc3ccc4ccc5ccc(N(c6cccc(-n7c8ccccc8c8ccccc87)c6)c6ccc7c(c6)oc6ccccc67)cc5c4c3o2)cc1 ; c1ccc(-c2nc3ccc4ccc5ccc(N(c6cccc(-n7c8ccccc8c8ccccc87)c6)c6ccc7oc8ccccc8c7c6)cc5c4c3o2)cc1 ; c1ccc(-c2nc3ccc4ccc5ccc(N(c6ccccc6)c6cc(-n7c8ccccc8c8ccccc87)cc(-n7c8ccccc8c8ccccc87)c6)cc5c4c3o2)cc1]

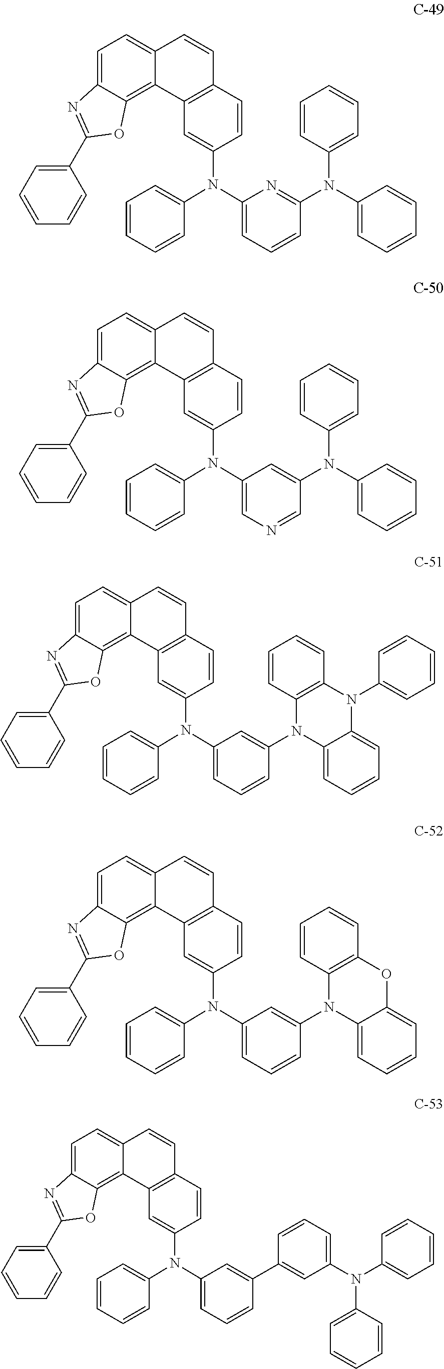 [SMILES: c1ccc(-c2nc3ccc4ccc5ccc(N(c6ccccc6)c6cccc(N(c7ccccc7)c7ccccc7)n6)cc5c4c3o2)cc1 ; c1ccc(-c2nc3ccc4ccc5ccc(N(c6ccccc6)c6cncc(N(c7ccccc7)c7ccccc7)c6)cc5c4c3o2)cc1 ; c1ccc(-c2nc3ccc4ccc5ccc(N(c6ccccc6)c6cccc(N7c8ccccc8N(c8ccccc8)c8ccccc87)c6)cc5c4c3o2)cc1 ; c1ccc(-c2nc3ccc4ccc5ccc(N(c6ccccc6)c6cccc(N7c8ccccc8Oc8ccccc87)c6)cc5c4c3o2)cc1 ; c1ccc(-c2nc3ccc4ccc5ccc(N(c6ccccc6)c6cccc(-c7cccc(N(c8ccccc8)c8ccccc8)c7)c6)cc5c4c3o2)cc1]

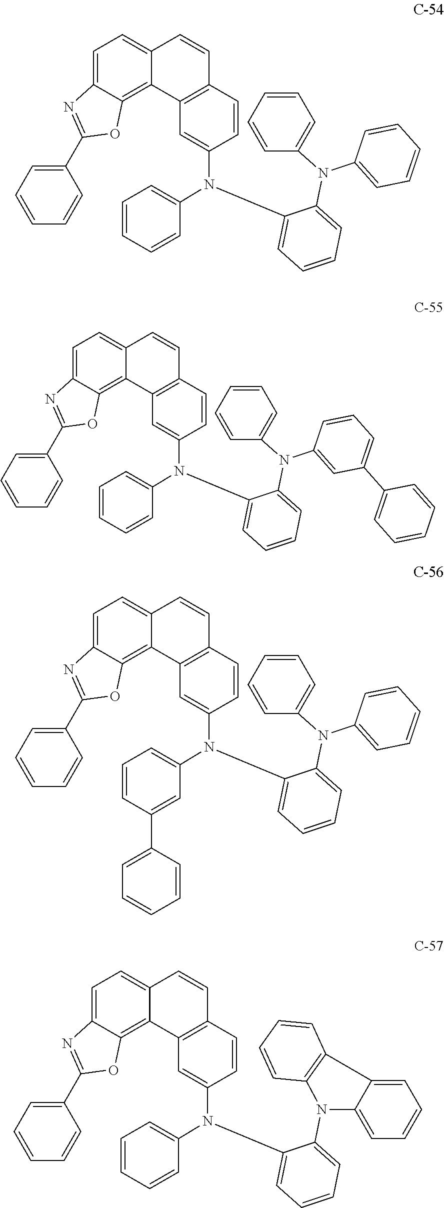 [SMILES: c1ccc(-c2nc3ccc4ccc5ccc(N(c6ccccc6)c6ccccc6N(c6ccccc6)c6ccccc6)cc5c4c3o2)cc1 ; c1ccc(-c2cccc(N(c3ccccc3)c3ccccc3N(c3ccccc3)c3ccc4ccc5ccc6nc(-c7ccccc7)oc6c5c4c3)c2)cc1 ; c1ccc(-c2cccc(N(c3ccc4ccc5ccc6nc(-c7ccccc7)oc6c5c4c3)c3ccccc3N(c3ccccc3)c3ccccc3)c2)cc1 ; c1ccc(-c2nc3ccc4ccc5ccc(N(c6ccccc6)c6ccccc6-n6c7ccccc7c7ccccc76)cc5c4c3o2)cc1]

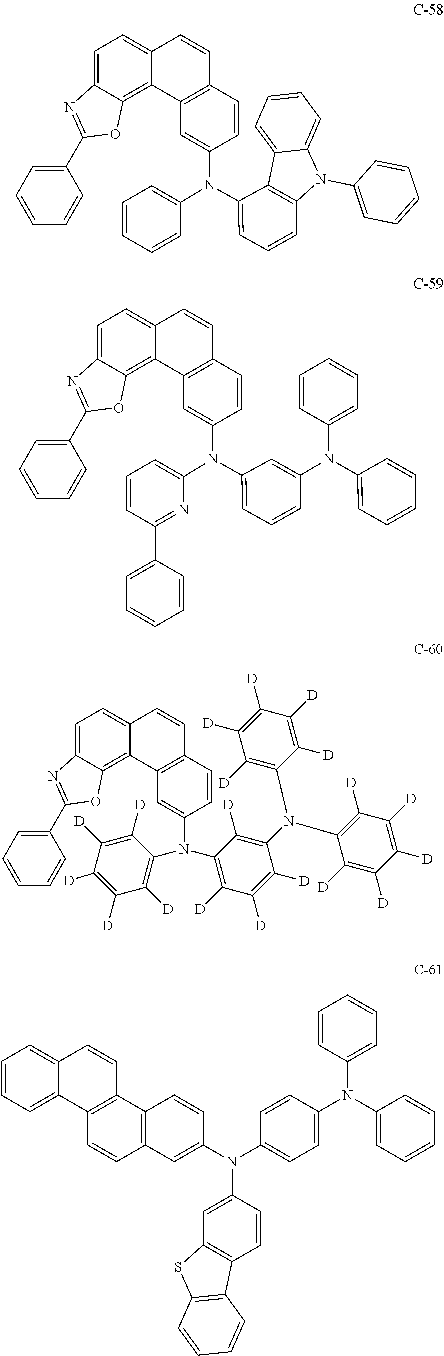 [SMILES: c1ccc(-c2nc3ccc4ccc5ccc(N(c6ccccc6)c6cccc7c6c6ccccc6n7-c6ccccc6)cc5c4c3o2)cc1 ; c1ccc(-c2cccc(N(c3cccc(N(c4ccccc4)c4ccccc4)c3)c3ccc4ccc5ccc6nc(-c7ccccc7)oc6c5c4c3)n2)cc1 ; [2H]c1c([2H])c([2H])c(N(c2ccc3ccc4ccc5nc(-c6ccccc6)oc5c4c3c2)c2c([2H])c([2H])c([2H])c(N(c3c([2H])c([2H])c([2H])c([2H])c3[2H])c3c([2H])c([2H])c([2H])c([2H])c3[2H])c2[2H])c([2H])c1[2H] ; c1ccc(N(c2ccccc2)c2ccc(N(c3ccc4c(ccc5c6ccccc6ccc45)c3)c3ccc4c(c3)sc3ccccc34)cc2)cc1]

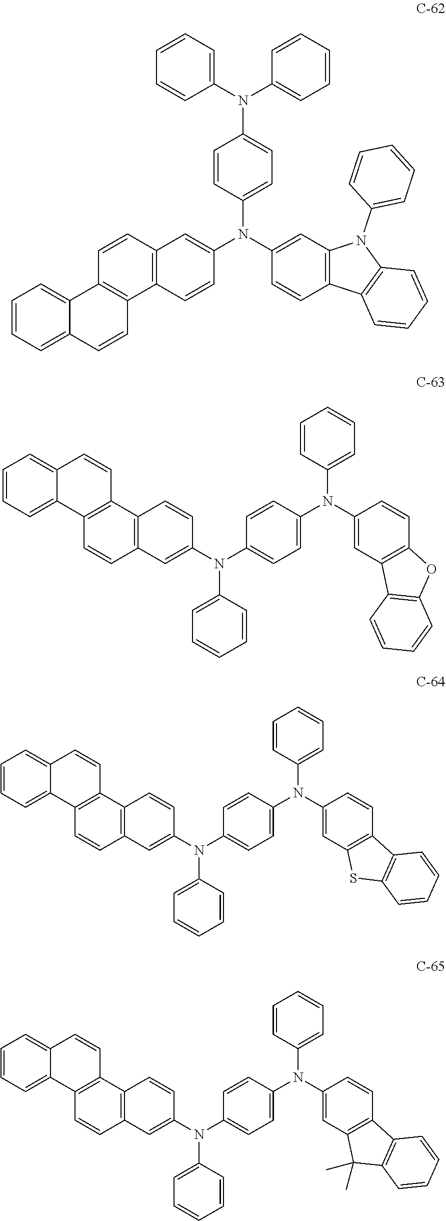 [SMILES: c1ccc(N(c2ccccc2)c2ccc(N(c3ccc4c(ccc5c6ccccc6ccc45)c3)c3ccc4c5ccccc5n(-c5ccccc5)c4c3)cc2)cc1 ; c1ccc(N(c2ccc(N(c3ccccc3)c3ccc4oc5ccccc5c4c3)cc2)c2ccc3c(ccc4c5ccccc5ccc34)c2)cc1 ; c1ccc(N(c2ccc(N(c3ccccc3)c3ccc4c(c3)sc3ccccc34)cc2)c2ccc3c(ccc4c5ccccc5ccc34)c2)cc1 ; CC1(C)c2ccccc2-c2ccc(N(c3ccccc3)c3ccc(N(c4ccccc4)c4ccc5c(ccc6c7ccccc7ccc56)c4)cc3)cc21]

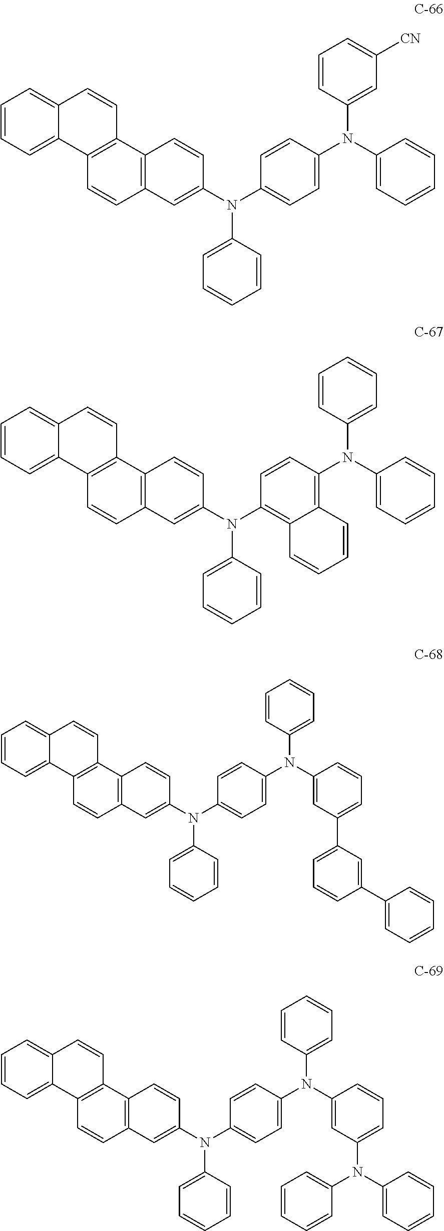 [SMILES: N#Cc1cccc(N(c2ccccc2)c2ccc(N(c3ccccc3)c3ccc4c(ccc5c6ccccc6ccc45)c3)cc2)c1 ; c1ccc(N(c2ccccc2)c2ccc(N(c3ccccc3)c3ccc4c(ccc5c6ccccc6ccc45)c3)c3ccccc23)cc1 ; c1ccc(-c2cccc(-c3cccc(N(c4ccccc4)c4ccc(N(c5ccccc5)c5ccc6c(ccc7c8ccccc8ccc67)c5)cc4)c3)c2)cc1 ; c1ccc(N(c2ccccc2)c2cccc(N(c3ccccc3)c3ccc(N(c4ccccc4)c4ccc5c(ccc6c7ccccc7ccc56)c4)cc3)c2)cc1]

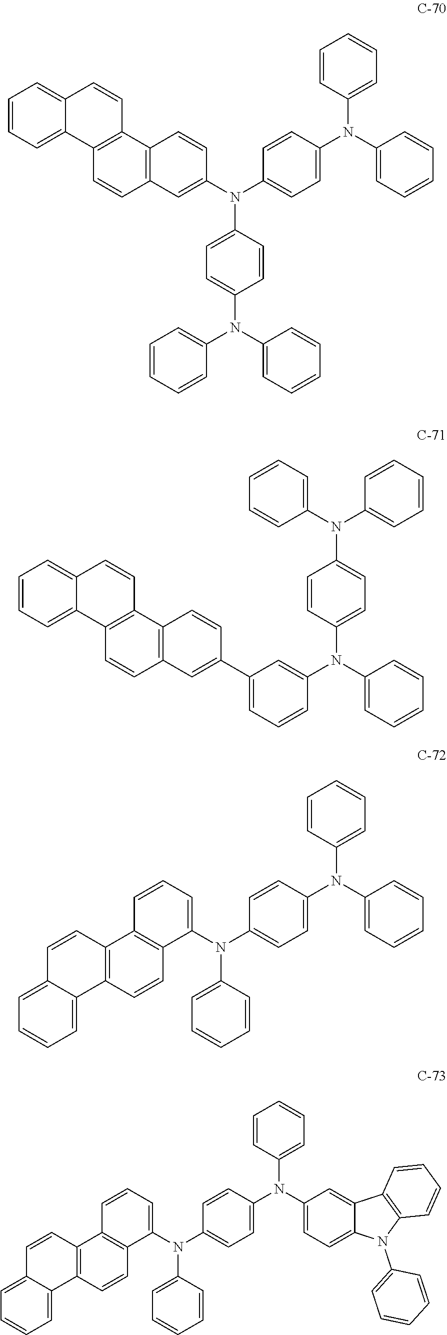 [SMILES: c1ccc(N(c2ccccc2)c2ccc(N(c3ccc(N(c4ccccc4)c4ccccc4)cc3)c3ccc4c(ccc5c6ccccc6ccc45)c3)cc2)cc1 ; c1ccc(N(c2ccccc2)c2ccc(N(c3ccccc3)c3cccc(-c4ccc5c(ccc6c7ccccc7ccc56)c4)c3)cc2)cc1 ; c1ccc(N(c2ccccc2)c2ccc(N(c3ccccc3)c3cccc4c3ccc3c5ccccc5ccc43)cc2)cc1 ; c1ccc(N(c2ccc(N(c3ccccc3)c3cccc4c3ccc3c5ccccc5ccc43)cc2)c2ccc3c(c2)c2ccccc2n3-c2ccccc2)cc1]

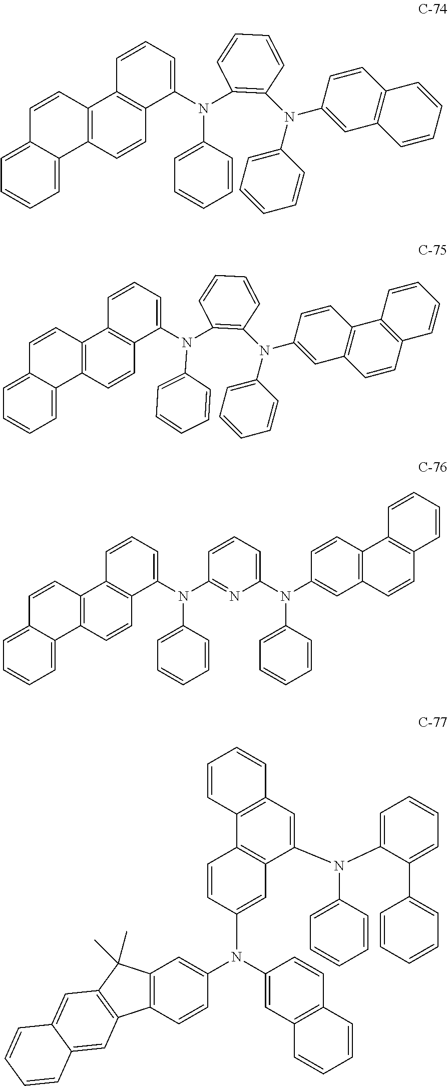 [SMILES: c1ccc(N(c2ccc3ccccc3c2)c2ccccc2N(c2ccccc2)c2cccc3c2ccc2c4ccccc4ccc32)cc1 ; c1ccc(N(c2ccc3c(ccc4ccccc43)c2)c2ccccc2N(c2ccccc2)c2cccc3c2ccc2c4ccccc4ccc32)cc1 ; c1ccc(N(c2ccc3c(ccc4ccccc43)c2)c2cccc(N(c3ccccc3)c3cccc4c3ccc3c5ccccc5ccc43)n2)cc1 ; CC1(C)c2cc(N(c3ccc4ccccc4c3)c3ccc4c(c3)c(N(c3ccccc3)c3ccccc3-c3ccccc3)cc3ccccc34)ccc2-c2cc3ccccc3cc21]

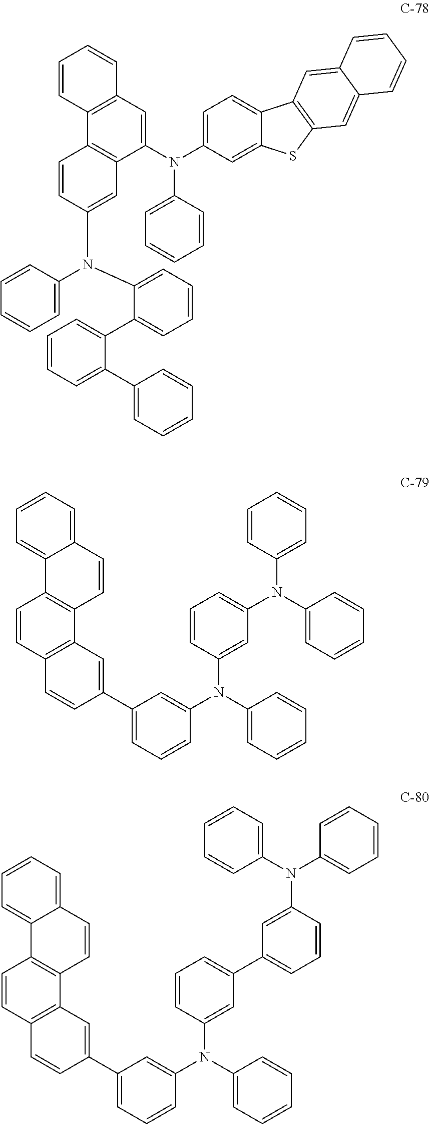 [SMILES: c1ccc(-c2ccccc2-c2ccccc2N(c2ccccc2)c2ccc3c(c2)c(N(c2ccccc2)c2ccc4c(c2)sc2cc5ccccc5cc24)cc2ccccc23)cc1 ; c1ccc(N(c2ccccc2)c2cccc(N(c3ccccc3)c3cccc(-c4ccc5ccc6c7ccccc7ccc6c5c4)c3)c2)cc1 ; c1ccc(N(c2ccccc2)c2cccc(-c3cccc(N(c4ccccc4)c4cccc(-c5ccc6ccc7c8ccccc8ccc7c6c5)c4)c3)c2)cc1]

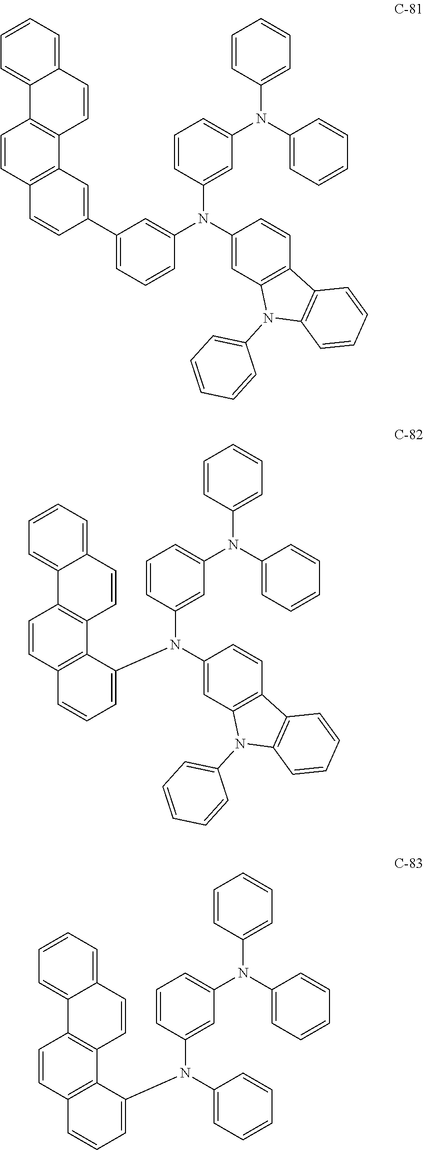

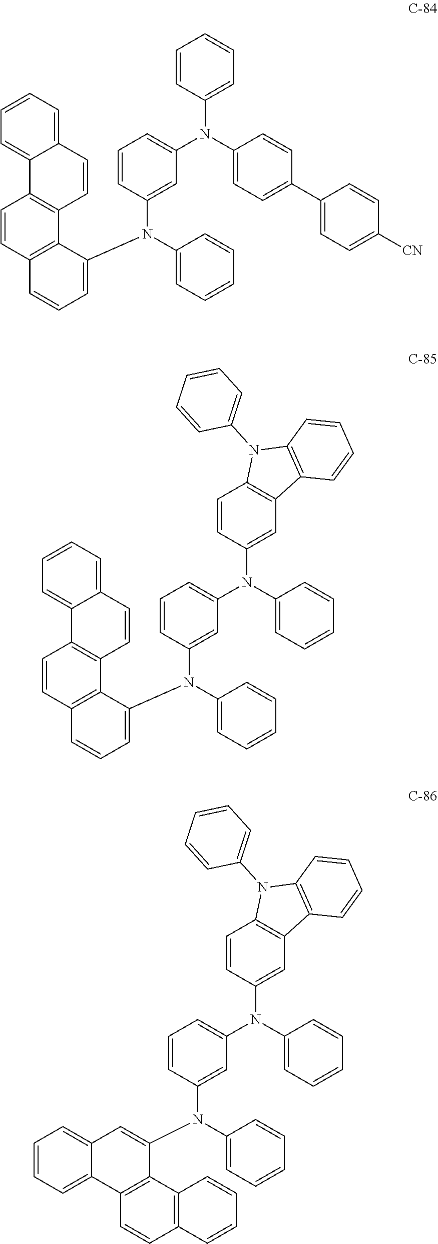 [SMILES: N#Cc1ccc(-c2ccc(N(c3ccccc3)c3cccc(N(c4ccccc4)c4cccc5ccc6c7ccccc7ccc6c45)c3)cc2)cc1 ; c1ccc(N(c2cccc(N(c3ccccc3)c3cccc4ccc5c6ccccc6ccc5c34)c2)c2ccc3c(c2)c2ccccc2n3-c2ccccc2)cc1 ; c1ccc(N(c2cccc(N(c3ccccc3)c3cc4ccccc4c4ccc5ccccc5c34)c2)c2ccc3c(c2)c2ccccc2n3-c2ccccc2)cc1]

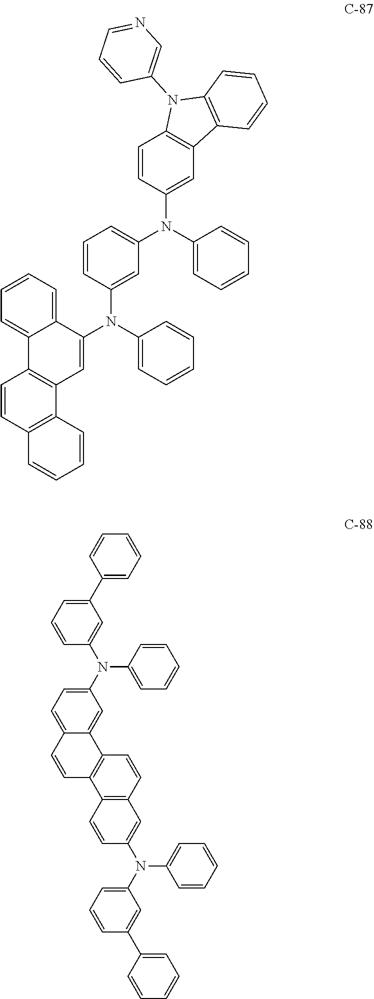 [SMILES: c1ccc(N(c2cccc(N(c3ccccc3)c3cc4c5ccccc5ccc4c4ccccc34)c2)c2ccc3c(c2)c2ccccc2n3-c2cccnc2)cc1 ; c1ccc(-c2cccc(N(c3ccccc3)c3ccc4c(ccc5c6cc(N(c7ccccc7)c7cccc(-c8ccccc8)c7)ccc6ccc45)c3)c2)cc1]

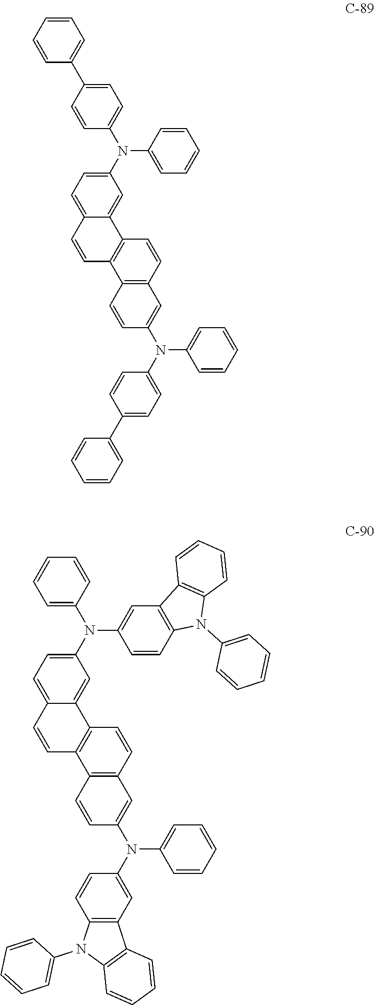 [SMILES: c1ccc(-c2ccc(N(c3ccccc3)c3ccc4c(ccc5c6cc(N(c7ccccc7)c7ccc(-c8ccccc8)cc7)ccc6ccc45)c3)cc2)cc1 ; c1ccc(N(c2ccc3c(ccc4c5cc(N(c6ccccc6)c6ccc7c(c6)c6ccccc6n7-c6ccccc6)ccc5ccc34)c2)c2ccc3c(c2)c2ccccc2n3-c2ccccc2)cc1]

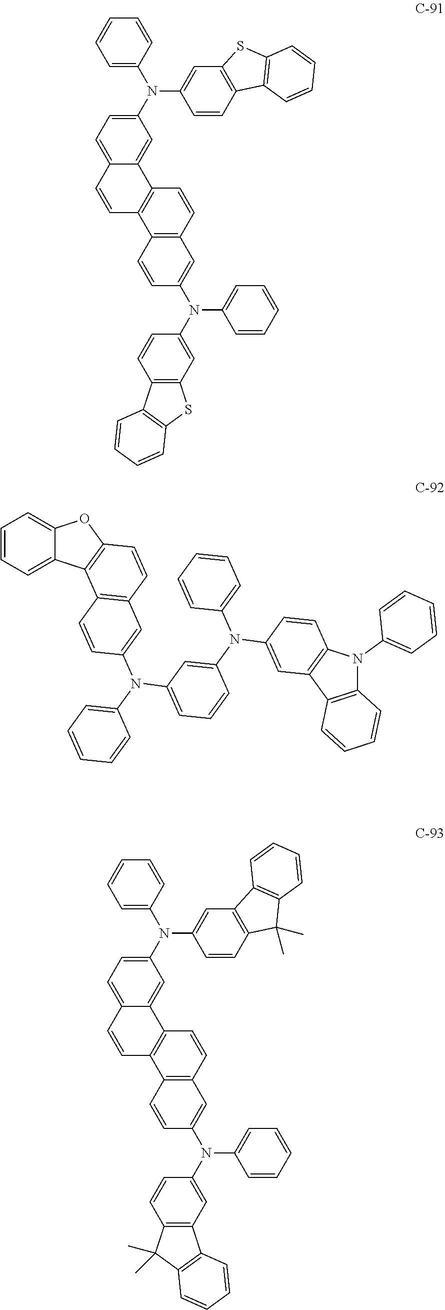 [SMILES: c1ccc(N(c2ccc3c(ccc4c5cc(N(c6ccccc6)c6ccc7c(c6)sc6ccccc67)ccc5ccc34)c2)c2ccc3c(c2)sc2ccccc23)cc1 ; c1ccc(N(c2cccc(N(c3ccccc3)c3ccc4c(c3)c3ccccc3n4-c3ccccc3)c2)c2ccc3c(ccc4oc5ccccc5c43)c2)cc1 ; CC1(C)c2ccccc2-c2cc(N(c3ccccc3)c3ccc4c(ccc5c6cc(N(c7ccccc7)c7ccc8c(c7)-c7ccccc7C8(C)C)ccc6ccc45)c3)ccc21]

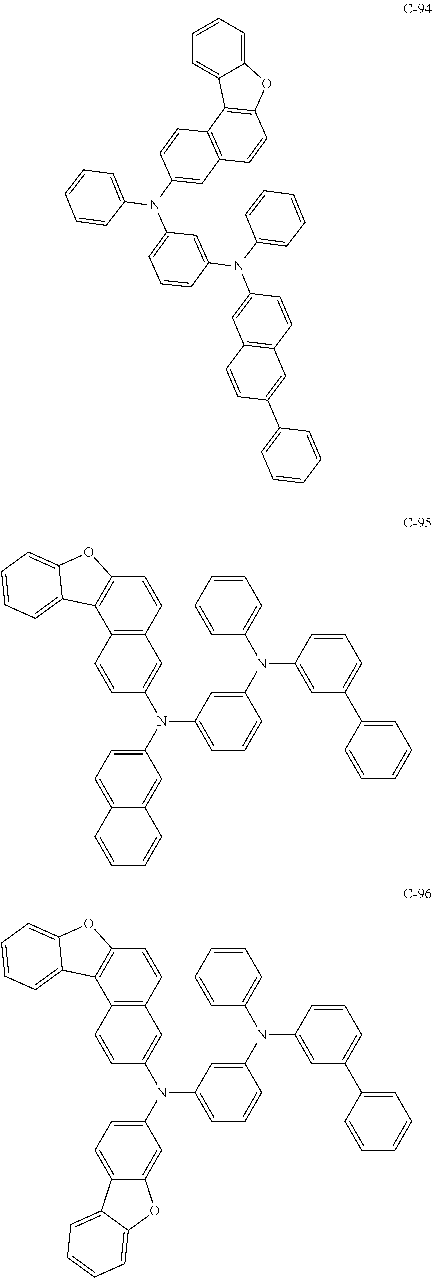 [SMILES: c1ccc(-c2ccc3cc(N(c4ccccc4)c4cccc(N(c5ccccc5)c5ccc6c(ccc7oc8ccccc8c76)c5)c4)ccc3c2)cc1 ; c1ccc(-c2cccc(N(c3ccccc3)c3cccc(N(c4ccc5ccccc5c4)c4ccc5c(ccc6oc7ccccc7c65)c4)c3)c2)cc1 ; c1ccc(-c2cccc(N(c3ccccc3)c3cccc(N(c4ccc5c(ccc6oc7ccccc7c65)c4)c4ccc5c(c4)oc4ccccc45)c3)c2)cc1]

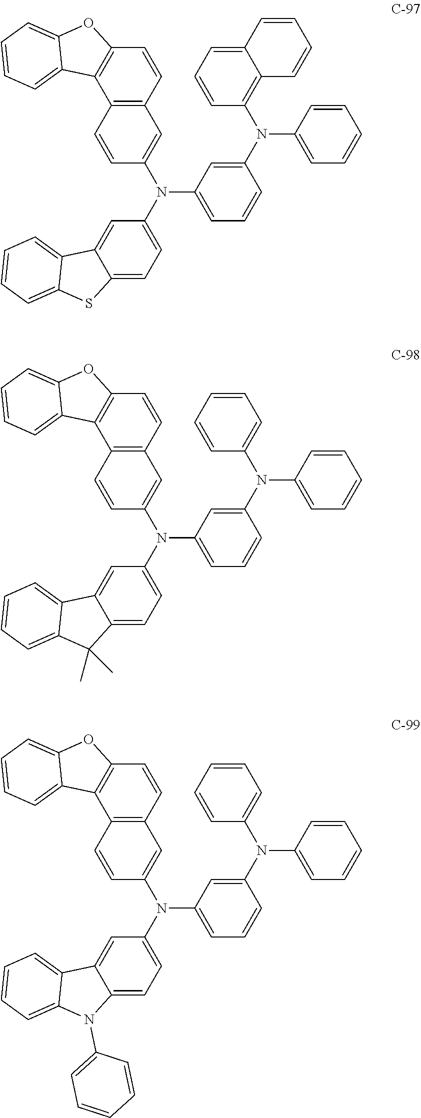 [SMILES: c1ccc(N(c2cccc(N(c3ccc4c(ccc5oc6ccccc6c54)c3)c3ccc4sc5ccccc5c4c3)c2)c2cccc3ccccc23)cc1 ; CC1(C)c2ccccc2-c2cc(N(c3cccc(N(c4ccccc4)c4ccccc4)c3)c3ccc4c(ccc5oc6ccccc6c54)c3)ccc21 ; c1ccc(N(c2ccccc2)c2cccc(N(c3ccc4c(ccc5oc6ccccc6c54)c3)c3ccc4c(c3)c3ccccc3n4-c3ccccc3)c2)cc1]

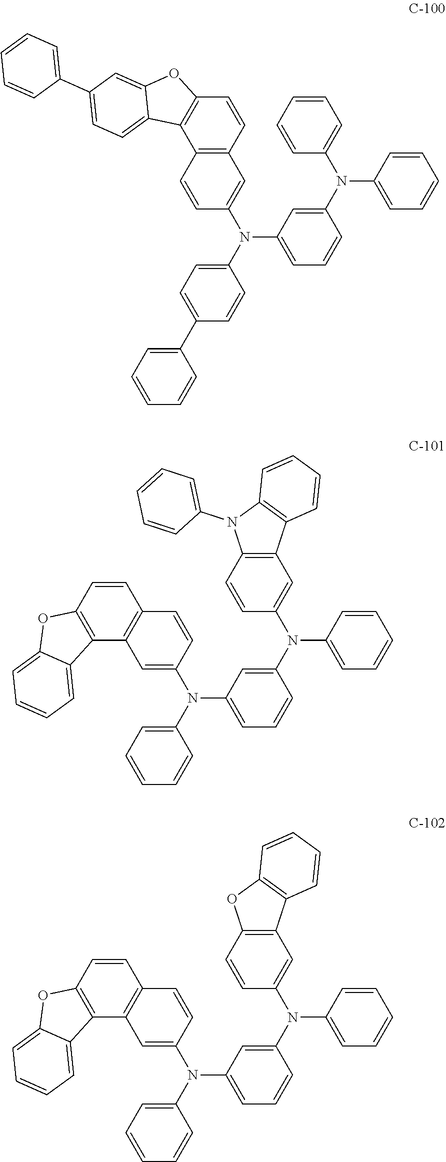 [SMILES: c1ccc(-c2ccc(N(c3cccc(N(c4ccccc4)c4ccccc4)c3)c3ccc4c(ccc5oc6cc(-c7ccccc7)ccc6c54)c3)cc2)cc1 ; c1ccc(N(c2cccc(N(c3ccccc3)c3ccc4c(c3)c3ccccc3n4-c3ccccc3)c2)c2ccc3ccc4oc5ccccc5c4c3c2)cc1 ; c1ccc(N(c2cccc(N(c3ccccc3)c3ccc4ccc5oc6ccccc6c5c4c3)c2)c2ccc3oc4ccccc4c3c2)cc1]

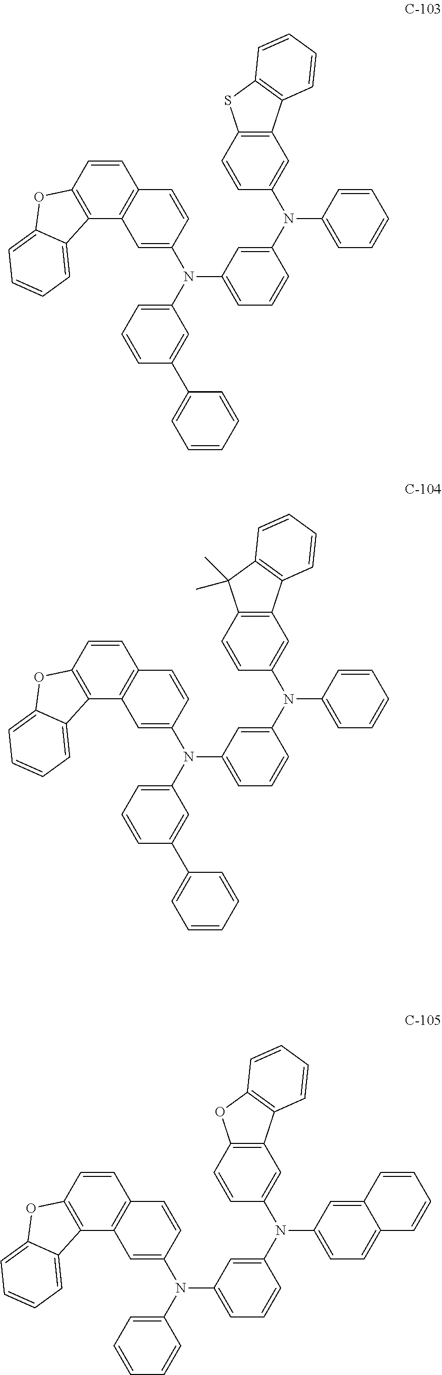 [SMILES: c1ccc(-c2cccc(N(c3cccc(N(c4ccccc4)c4ccc5sc6ccccc6c5c4)c3)c3ccc4ccc5oc6ccccc6c5c4c3)c2)cc1 ; CC1(C)c2ccccc2-c2cc(N(c3ccccc3)c3cccc(N(c4cccc(-c5ccccc5)c4)c4ccc5ccc6oc7ccccc7c6c5c4)c3)ccc21 ; c1ccc(N(c2cccc(N(c3ccc4ccccc4c3)c3ccc4oc5ccccc5c4c3)c2)c2ccc3ccc4oc5ccccc5c4c3c2)cc1]

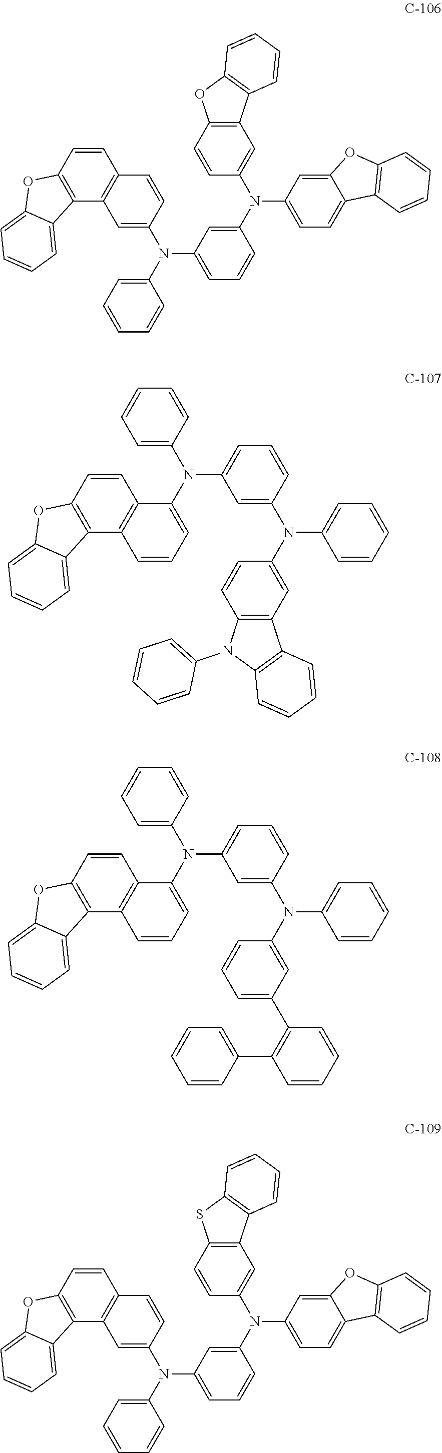 [SMILES: c1ccc(N(c2cccc(N(c3ccc4c(c3)oc3ccccc34)c3ccc4oc5ccccc5c4c3)c2)c2ccc3ccc4oc5ccccc5c4c3c2)cc1 ; c1ccc(N(c2cccc(N(c3ccccc3)c3cccc4c3ccc3oc5ccccc5c34)c2)c2ccc3c(c2)c2ccccc2n3-c2ccccc2)cc1 ; c1ccc(-c2ccccc2-c2cccc(N(c3ccccc3)c3cccc(N(c4ccccc4)c4cccc5c4ccc4oc6ccccc6c45)c3)c2)cc1 ; c1ccc(N(c2cccc(N(c3ccc4c(c3)oc3ccccc34)c3ccc4sc5ccccc5c4c3)c2)c2ccc3ccc4oc5ccccc5c4c3c2)cc1]

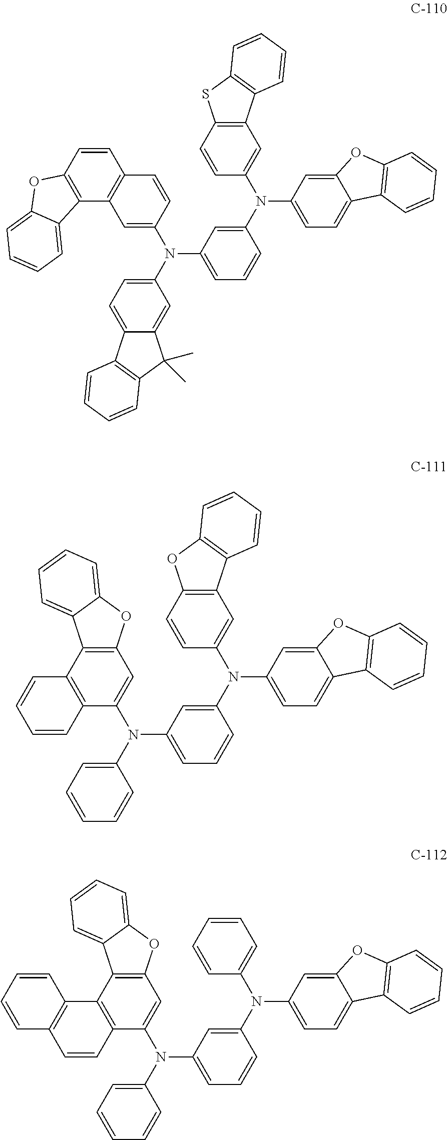 [SMILES: CC1(C)c2ccccc2-c2ccc(N(c3cccc(N(c4ccc5c(c4)oc4ccccc45)c4ccc5sc6ccccc6c5c4)c3)c3ccc4ccc5oc6ccccc6c5c4c3)cc21 ; c1ccc(N(c2cccc(N(c3ccc4c(c3)oc3ccccc34)c3ccc4oc5ccccc5c4c3)c2)c2cc3oc4ccccc4c3c3ccccc23)cc1 ; c1ccc(N(c2cccc(N(c3ccccc3)c3cc4oc5ccccc5c4c4c3ccc3ccccc34)c2)c2ccc3c(c2)oc2ccccc23)cc1]

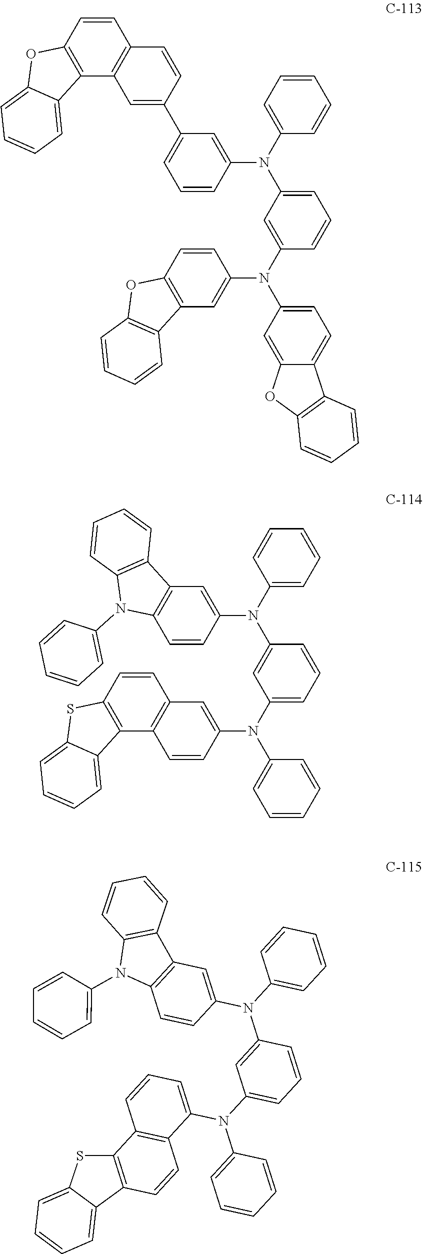 [SMILES: c1ccc(N(c2cccc(-c3ccc4ccc5oc6ccccc6c5c4c3)c2)c2cccc(N(c3ccc4c(c3)oc3ccccc34)c3ccc4oc5ccccc5c4c3)c2)cc1 ; c1ccc(N(c2cccc(N(c3ccccc3)c3ccc4c(c3)c3ccccc3n4-c3ccccc3)c2)c2ccc3c(ccc4sc5ccccc5c43)c2)cc1 ; c1ccc(N(c2cccc(N(c3ccccc3)c3cccc4c3ccc3c5ccccc5sc43)c2)c2ccc3c(c2)c2ccccc2n3-c2ccccc2)cc1]

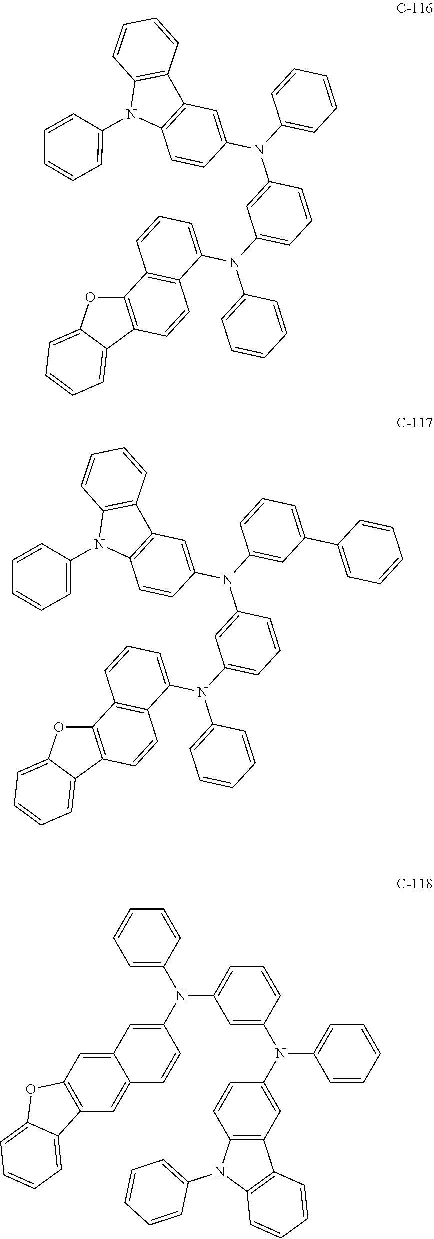 [SMILES: c1ccc(N(c2cccc(N(c3ccccc3)c3cccc4c3ccc3c5ccccc5oc43)c2)c2ccc3c(c2)c2ccccc2n3-c2ccccc2)cc1 ; c1ccc(-c2cccc(N(c3cccc(N(c4ccccc4)c4cccc5c4ccc4c6ccccc6oc54)c3)c3ccc4c(c3)c3ccccc3n4-c3ccccc3)c2)cc1 ; c1ccc(N(c2cccc(N(c3ccccc3)c3ccc4c(c3)c3ccccc3n4-c3ccccc3)c2)c2ccc3cc4c(cc3c2)oc2ccccc24)cc1]

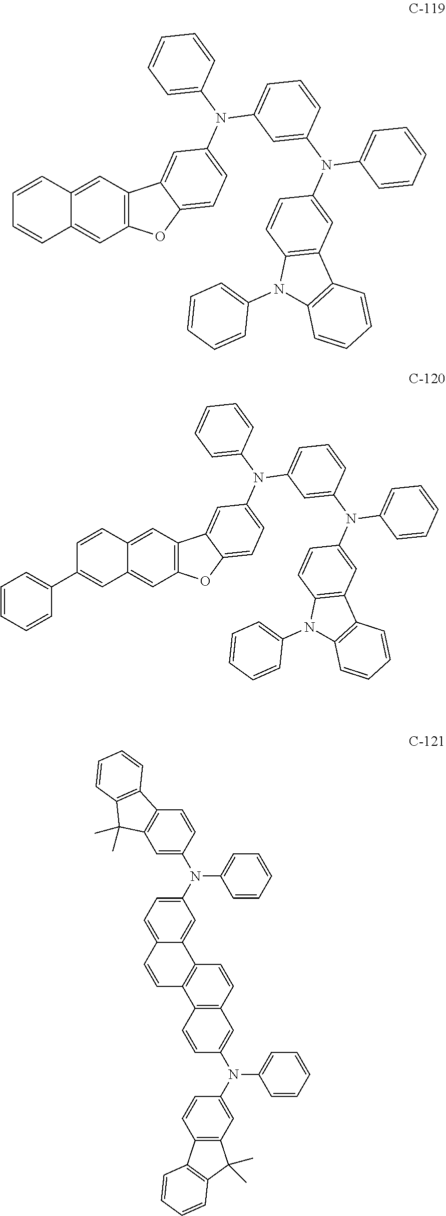 [SMILES: c1ccc(N(c2cccc(N(c3ccccc3)c3ccc4c(c3)c3ccccc3n4-c3ccccc3)c2)c2ccc3oc4cc5ccccc5cc4c3c2)cc1 ; c1ccc(-c2ccc3cc4c(cc3c2)oc2ccc(N(c3ccccc3)c3cccc(N(c5ccccc5)c5ccc6c(c5)c5ccccc5n6-c5ccccc5)c3)cc24)cc1 ; CC1(C)c2ccccc2-c2ccc(N(c3ccccc3)c3ccc4c(ccc5c6cc(N(c7ccccc7)c7ccc8c(c7)C(C)(C)c7ccccc7-8)ccc6ccc45)c3)cc21]

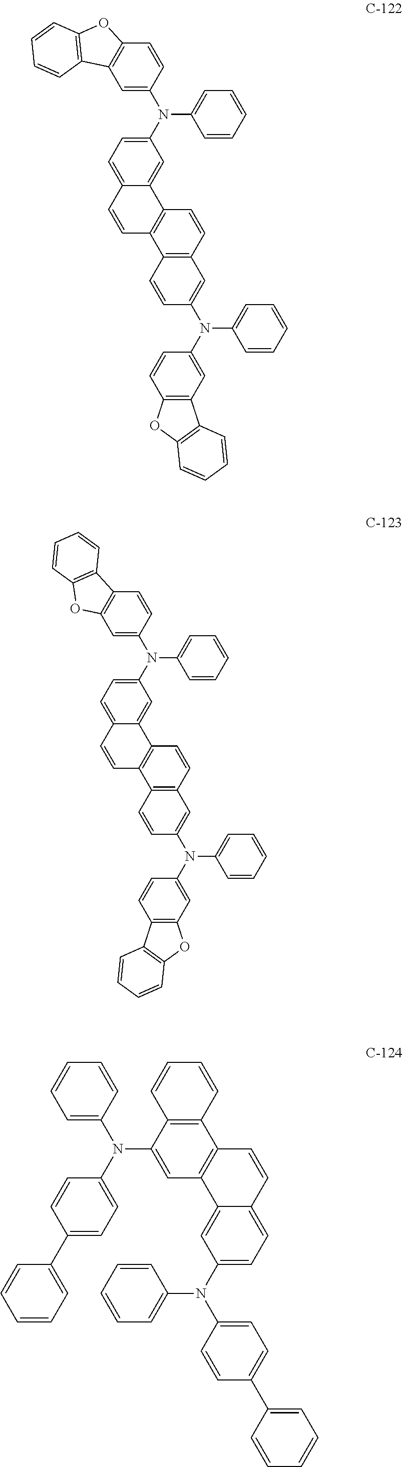 [SMILES: c1ccc(N(c2ccc3c(ccc4c5cc(N(c6ccccc6)c6ccc7oc8ccccc8c7c6)ccc5ccc34)c2)c2ccc3oc4ccccc4c3c2)cc1 ; c1ccc(N(c2ccc3c(ccc4c5cc(N(c6ccccc6)c6ccc7c(c6)oc6ccccc67)ccc5ccc34)c2)c2ccc3c(c2)oc2ccccc23)cc1 ; c1ccc(-c2ccc(N(c3ccccc3)c3ccc4ccc5c6ccccc6c(N(c6ccccc6)c6ccc(-c7ccccc7)cc6)cc5c4c3)cc2)cc1]

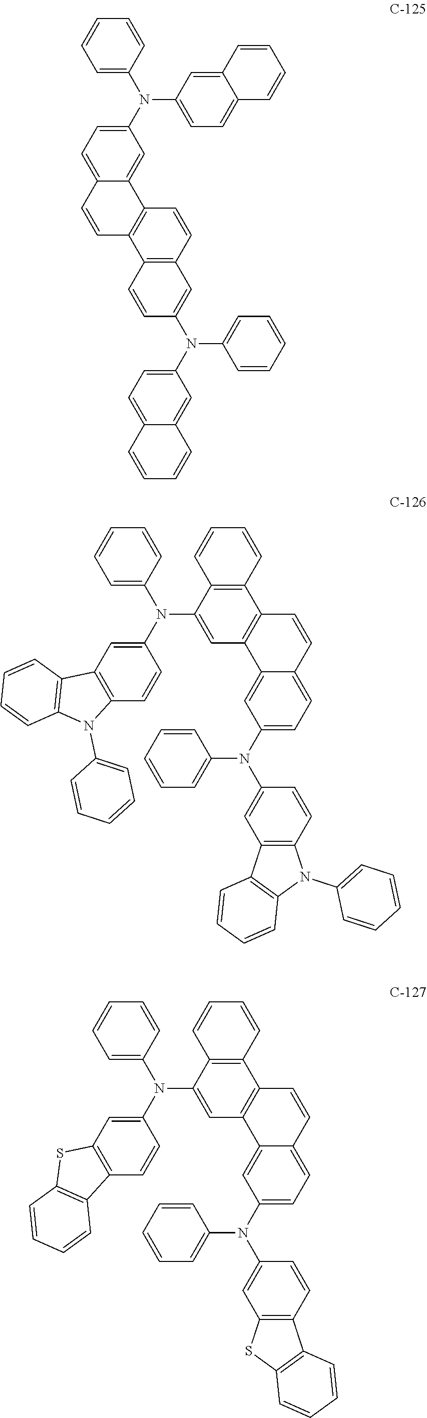 [SMILES: c1ccc(N(c2ccc3ccccc3c2)c2ccc3c(ccc4c5cc(N(c6ccccc6)c6ccc7ccccc7c6)ccc5ccc34)c2)cc1 ; c1ccc(N(c2ccc3ccc4c5ccccc5c(N(c5ccccc5)c5ccc6c(c5)c5ccccc5n6-c5ccccc5)cc4c3c2)c2ccc3c(c2)c2ccccc2n3-c2ccccc2)cc1 ; c1ccc(N(c2ccc3c(c2)sc2ccccc23)c2ccc3ccc4c5ccccc5c(N(c5ccccc5)c5ccc6c(c5)sc5ccccc56)cc4c3c2)cc1]

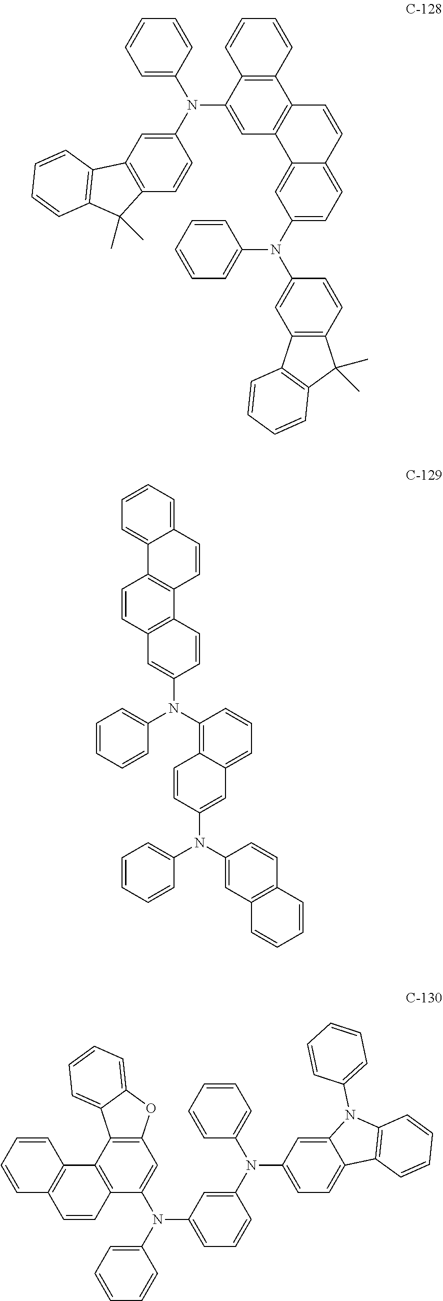 [SMILES: CC1(C)c2ccccc2-c2cc(N(c3ccccc3)c3ccc4ccc5c6ccccc6c(N(c6ccccc6)c6ccc7c(c6)-c6ccccc6C7(C)C)cc5c4c3)ccc21 ; c1ccc(N(c2ccc3ccccc3c2)c2ccc3c(N(c4ccccc4)c4ccc5c(ccc6c7ccccc7ccc56)c4)cccc3c2)cc1 ; c1ccc(N(c2cccc(N(c3ccccc3)c3cc4oc5ccccc5c4c4c3ccc3ccccc34)c2)c2ccc3c4ccccc4n(-c4ccccc4)c3c2)cc1]

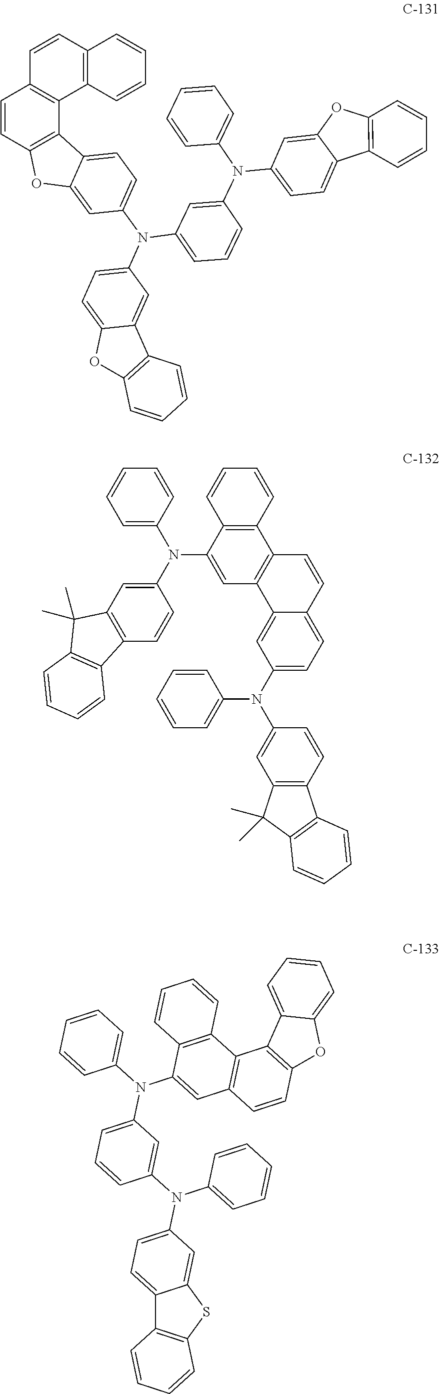 [SMILES: c1ccc(N(c2cccc(N(c3ccc4c(c3)oc3ccc5ccc6ccccc6c5c34)c3ccc4oc5ccccc5c4c3)c2)c2ccc3c(c2)oc2ccccc23)cc1 ; CC1(C)c2ccccc2-c2ccc(N(c3ccccc3)c3ccc4ccc5c6ccccc6c(N(c6ccccc6)c6ccc7c(c6)C(C)(C)c6ccccc6-7)cc5c4c3)cc21 ; c1ccc(N(c2cccc(N(c3ccccc3)c3cc4ccc5oc6ccccc6c5c4c4ccccc34)c2)c2ccc3c(c2)sc2ccccc23)cc1]

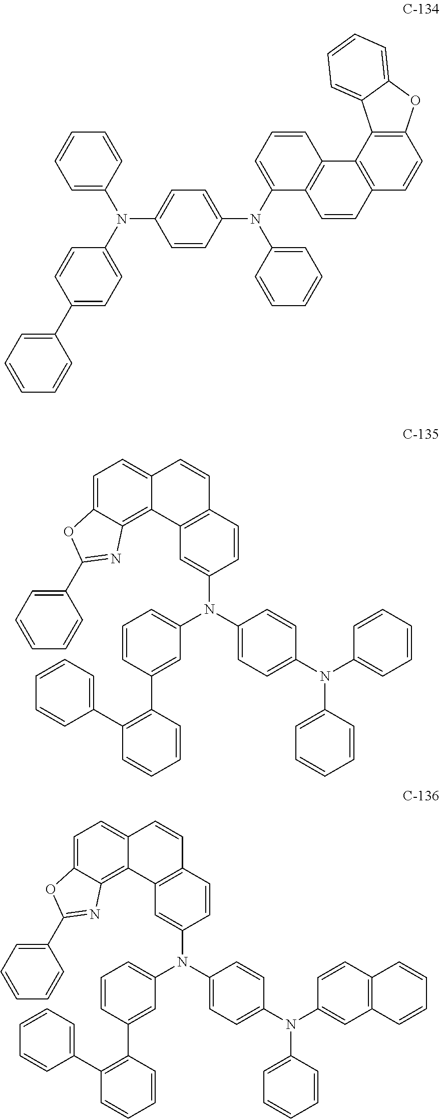

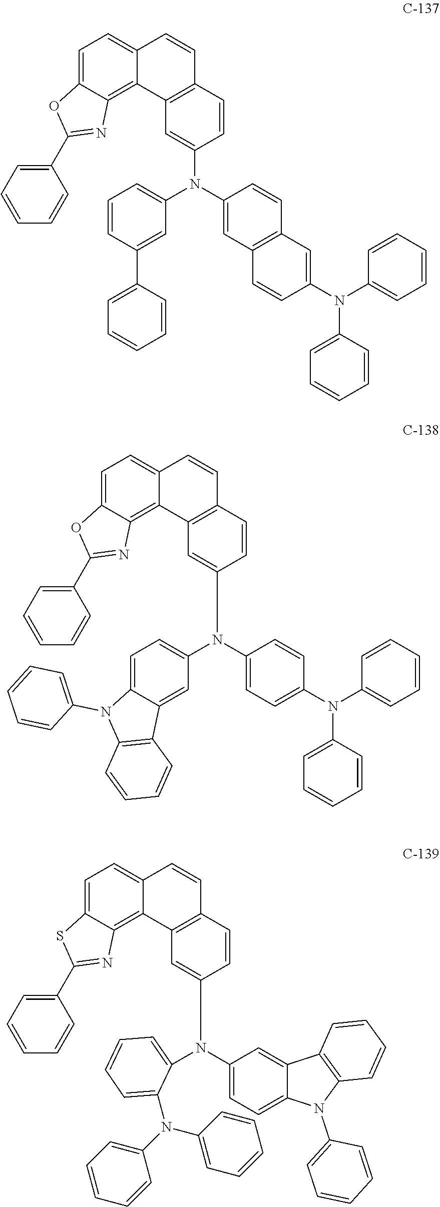 [SMILES: c1ccc(-c2cccc(N(c3ccc4cc(N(c5ccccc5)c5ccccc5)ccc4c3)c3ccc4ccc5ccc6oc(-c7ccccc7)nc6c5c4c3)c2)cc1 ; c1ccc(-c2nc3c(ccc4ccc5ccc(N(c6ccc(N(c7ccccc7)c7ccccc7)cc6)c6ccc7c(c6)c6ccccc6n7-c6ccccc6)cc5c43)o2)cc1 ; c1ccc(-c2nc3c(ccc4ccc5ccc(N(c6ccc7c(c6)c6ccccc6n7-c6ccccc6)c6ccccc6N(c6ccccc6)c6ccccc6)cc5c43)s2)cc1]

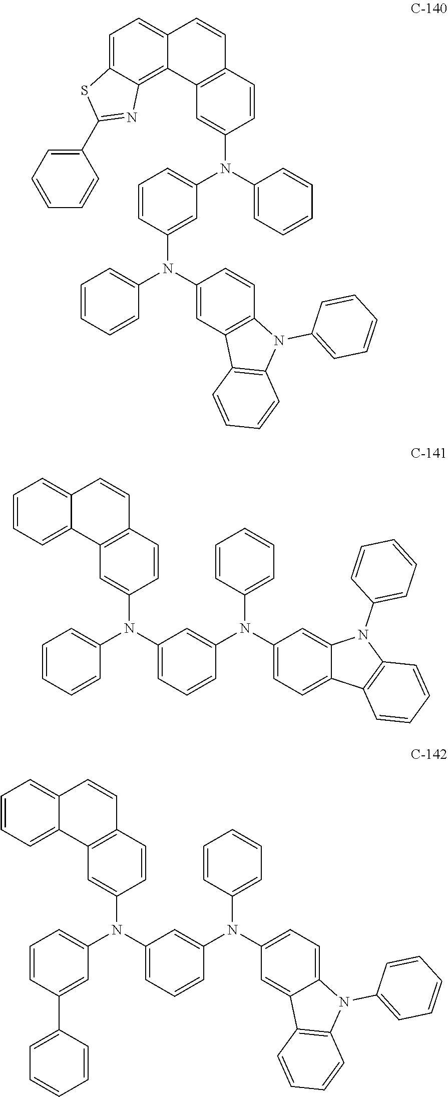 [SMILES: c1ccc(-c2nc3c(ccc4ccc5ccc(N(c6ccccc6)c6cccc(N(c7ccccc7)c7ccc8c(c7)c7ccccc7n8-c7ccccc7)c6)cc5c43)s2)cc1 ; c1ccc(N(c2cccc(N(c3ccccc3)c3ccc4c5ccccc5n(-c5ccccc5)c4c3)c2)c2ccc3ccc4ccccc4c3c2)cc1 ; c1ccc(-c2cccc(N(c3cccc(N(c4ccccc4)c4ccc5c(c4)c4ccccc4n5-c4ccccc4)c3)c3ccc4ccc5ccccc5c4c3)c2)cc1]

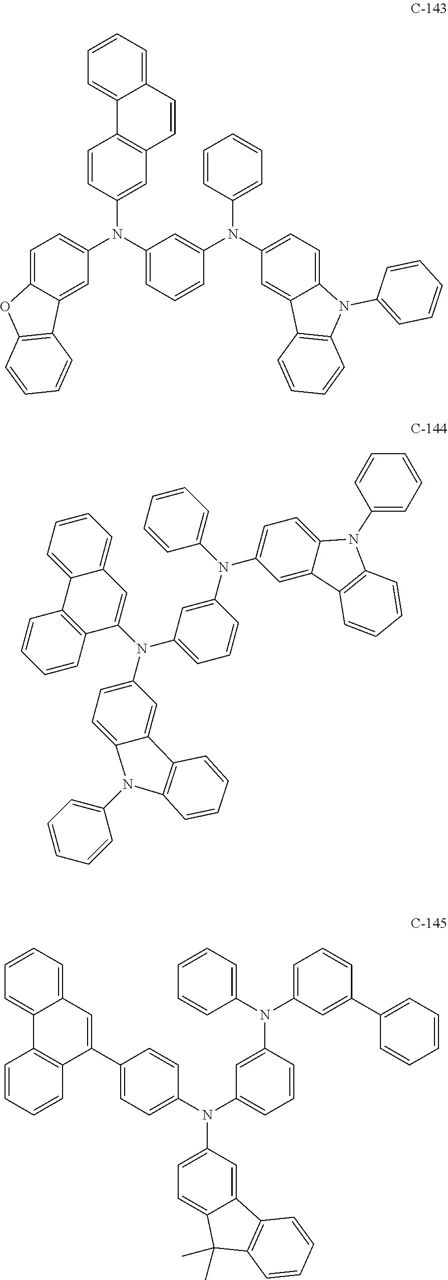 [SMILES: c1ccc(N(c2cccc(N(c3ccc4c(ccc5ccccc54)c3)c3ccc4oc5ccccc5c4c3)c2)c2ccc3c(c2)c2ccccc2n3-c2ccccc2)cc1 ; c1ccc(N(c2cccc(N(c3ccc4c(c3)c3ccccc3n4-c3ccccc3)c3cc4ccccc4c4ccccc34)c2)c2ccc3c(c2)c2ccccc2n3-c2ccccc2)cc1 ; CC1(C)c2ccccc2-c2cc(N(c3ccc(-c4cc5ccccc5c5ccccc45)cc3)c3cccc(N(c4ccccc4)c4cccc(-c5ccccc5)c4)c3)ccc21]

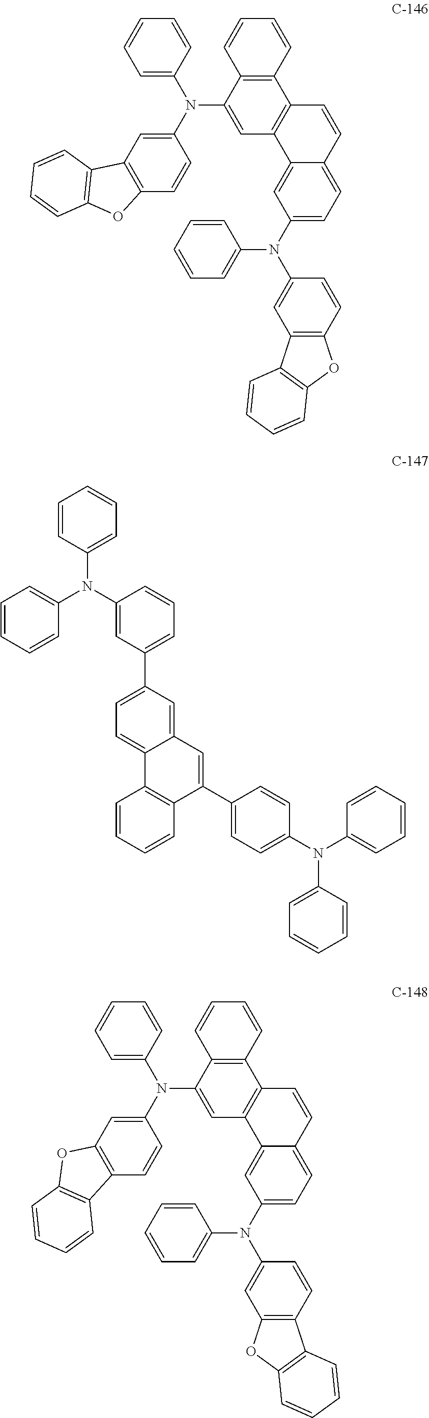 [SMILES: c1ccc(N(c2ccc3ccc4c5ccccc5c(N(c5ccccc5)c5ccc6oc7ccccc7c6c5)cc4c3c2)c2ccc3oc4ccccc4c3c2)cc1 ; c1ccc(N(c2ccccc2)c2ccc(-c3cc4cc(-c5cccc(N(c6ccccc6)c6ccccc6)c5)ccc4c4ccccc34)cc2)cc1 ; c1ccc(N(c2ccc3c(c2)oc2ccccc23)c2ccc3ccc4c5ccccc5c(N(c5ccccc5)c5ccc6c(c5)oc5ccccc56)cc4c3c2)cc1]

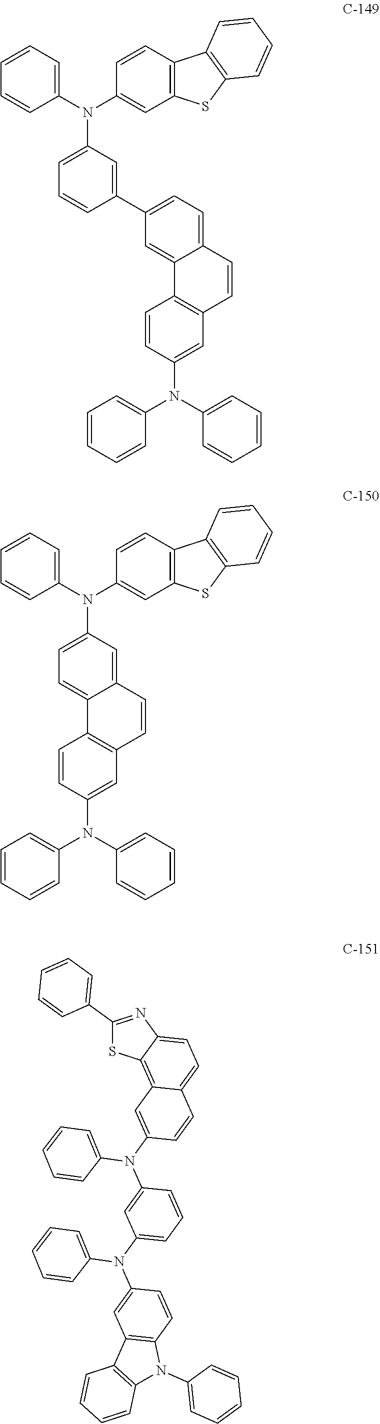 [SMILES: c1ccc(N(c2ccccc2)c2ccc3c(ccc4ccc(-c5cccc(N(c6ccccc6)c6ccc7c(c6)sc6ccccc67)c5)cc43)c2)cc1 ; c1ccc(N(c2ccccc2)c2ccc3c(ccc4cc(N(c5ccccc5)c5ccc6c(c5)sc5ccccc56)ccc43)c2)cc1 ; c1ccc(-c2nc3ccc4ccc(N(c5ccccc5)c5cccc(N(c6ccccc6)c6ccc7c(c6)c6ccccc6n7-c6ccccc6)c5)cc4c3s2)cc1]

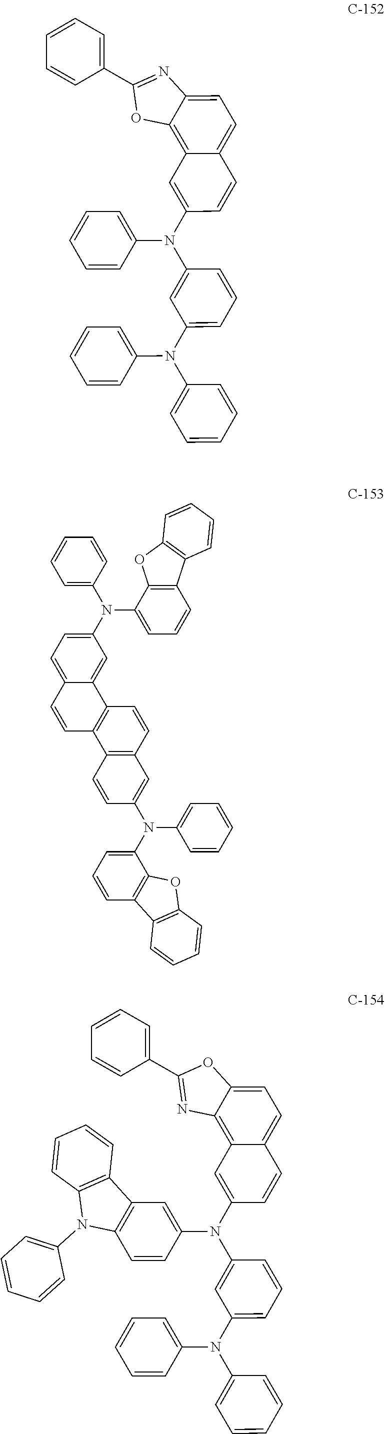 [SMILES: c1ccc(-c2nc3ccc4ccc(N(c5ccccc5)c5cccc(N(c6ccccc6)c6ccccc6)c5)cc4c3o2)cc1 ; c1ccc(N(c2ccc3c(ccc4c5cc(N(c6ccccc6)c6cccc7c6oc6ccccc67)ccc5ccc34)c2)c2cccc3c2oc2ccccc23)cc1 ; c1ccc(-c2nc3c(ccc4ccc(N(c5cccc(N(c6ccccc6)c6ccccc6)c5)c5ccc6c(c5)c5ccccc5n6-c5ccccc5)cc43)o2)cc1]

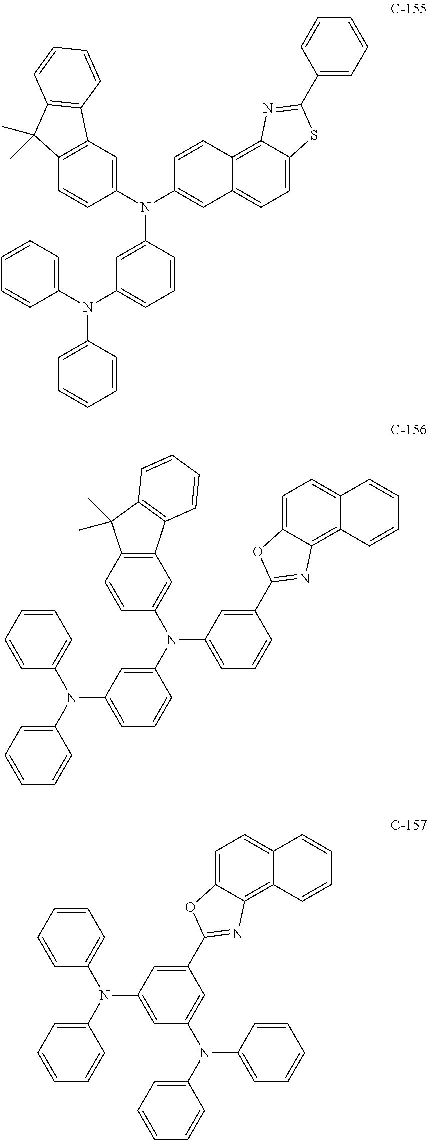 [SMILES: CC1(C)c2ccccc2-c2cc(N(c3cccc(N(c4ccccc4)c4ccccc4)c3)c3ccc4c(ccc5sc(-c6ccccc6)nc54)c3)ccc21 ; CC1(C)c2ccccc2-c2cc(N(c3cccc(-c4nc5c(ccc6ccccc65)o4)c3)c3cccc(N(c4ccccc4)c4ccccc4)c3)ccc21 ; c1ccc(N(c2ccccc2)c2cc(-c3nc4c(ccc5ccccc54)o3)cc(N(c3ccccc3)c3ccccc3)c2)cc1]

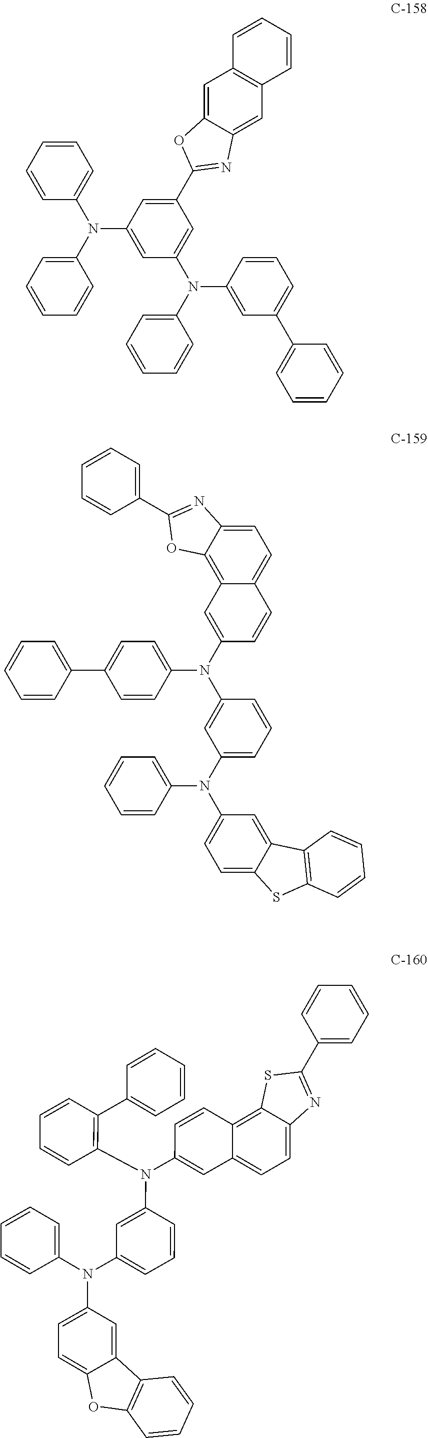 [SMILES: c1ccc(-c2cccc(N(c3ccccc3)c3cc(-c4nc5cc6ccccc6cc5o4)cc(N(c4ccccc4)c4ccccc4)c3)c2)cc1 ; c1ccc(-c2ccc(N(c3cccc(N(c4ccccc4)c4ccc5sc6ccccc6c5c4)c3)c3ccc4ccc5nc(-c6ccccc6)oc5c4c3)cc2)cc1 ; c1ccc(-c2nc3ccc4cc(N(c5cccc(N(c6ccccc6)c6ccc7oc8ccccc8c7c6)c5)c5ccccc5-c5ccccc5)ccc4c3s2)cc1]

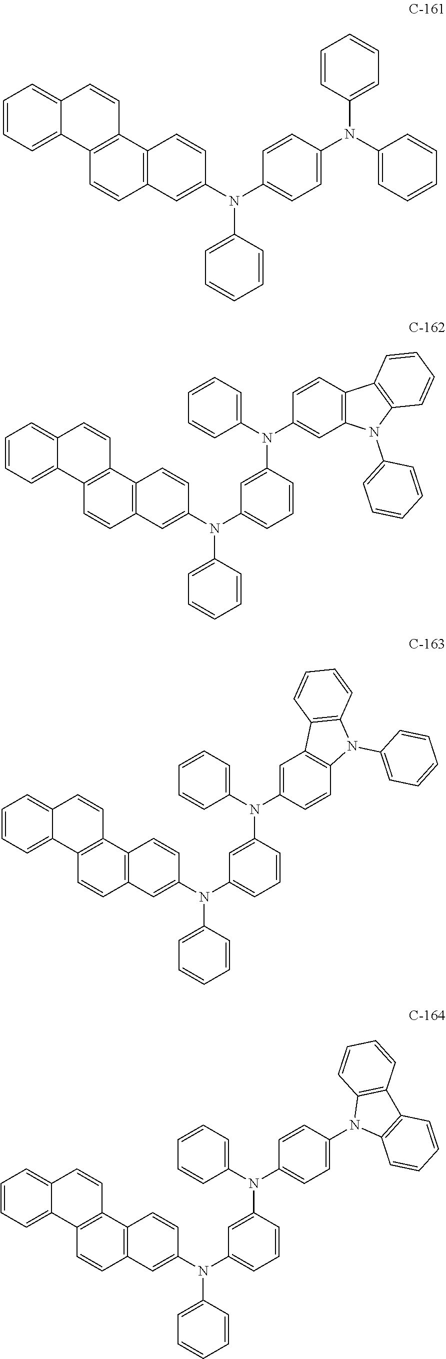 [SMILES: c1ccc(N(c2ccccc2)c2ccc(N(c3ccccc3)c3ccc4c(ccc5c6ccccc6ccc45)c3)cc2)cc1 ; c1ccc(N(c2cccc(N(c3ccccc3)c3ccc4c5ccccc5n(-c5ccccc5)c4c3)c2)c2ccc3c(ccc4c5ccccc5ccc34)c2)cc1 ; c1ccc(N(c2cccc(N(c3ccccc3)c3ccc4c(c3)c3ccccc3n4-c3ccccc3)c2)c2ccc3c(ccc4c5ccccc5ccc34)c2)cc1 ; c1ccc(N(c2ccc(-n3c4ccccc4c4ccccc43)cc2)c2cccc(N(c3ccccc3)c3ccc4c(ccc5c6ccccc6ccc45)c3)c2)cc1]

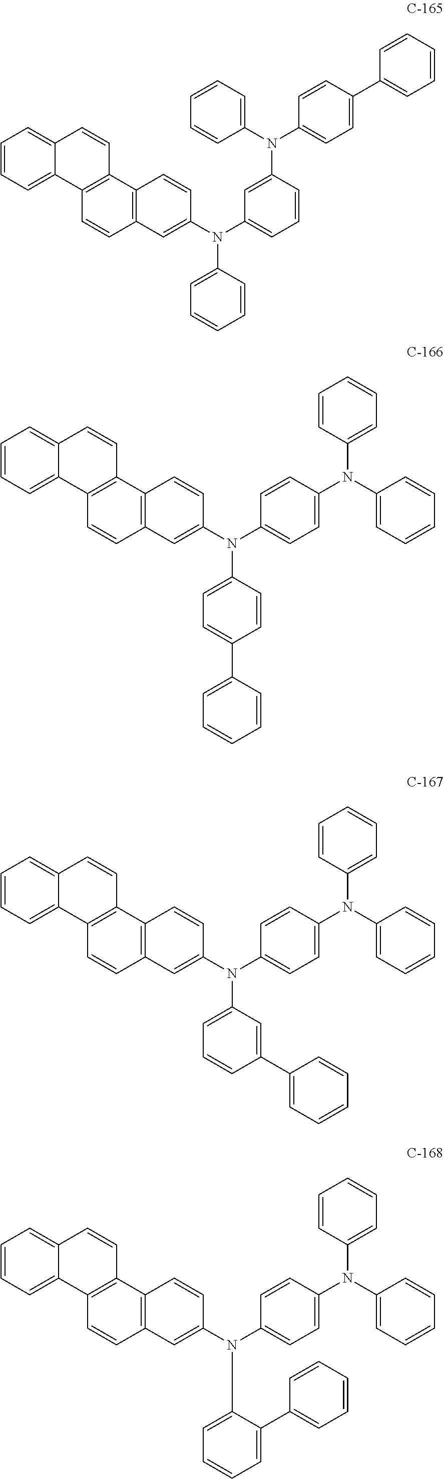 [SMILES: c1ccc(-c2ccc(N(c3ccccc3)c3cccc(N(c4ccccc4)c4ccc5c(ccc6c7ccccc7ccc56)c4)c3)cc2)cc1 ; c1ccc(-c2ccc(N(c3ccc(N(c4ccccc4)c4ccccc4)cc3)c3ccc4c(ccc5c6ccccc6ccc45)c3)cc2)cc1 ; c1ccc(-c2cccc(N(c3ccc(N(c4ccccc4)c4ccccc4)cc3)c3ccc4c(ccc5c6ccccc6ccc45)c3)c2)cc1 ; c1ccc(-c2ccccc2N(c2ccc(N(c3ccccc3)c3ccccc3)cc2)c2ccc3c(ccc4c5ccccc5ccc34)c2)cc1]

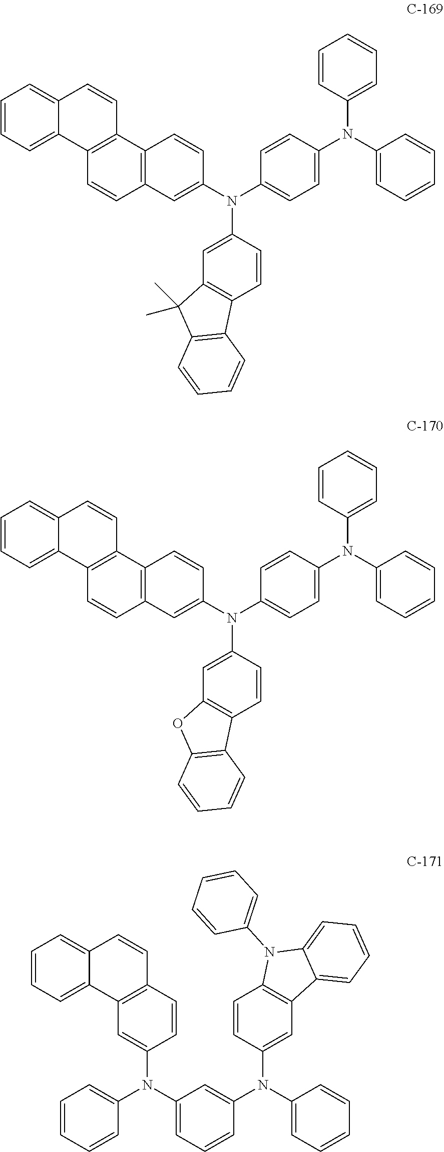 [SMILES: CC1(C)c2ccccc2-c2ccc(N(c3ccc(N(c4ccccc4)c4ccccc4)cc3)c3ccc4c(ccc5c6ccccc6ccc45)c3)cc21 ; c1ccc(N(c2ccccc2)c2ccc(N(c3ccc4c(ccc5c6ccccc6ccc45)c3)c3ccc4c(c3)oc3ccccc34)cc2)cc1 ; c1ccc(N(c2cccc(N(c3ccccc3)c3ccc4c(c3)c3ccccc3n4-c3ccccc3)c2)c2ccc3ccc4ccccc4c3c2)cc1]

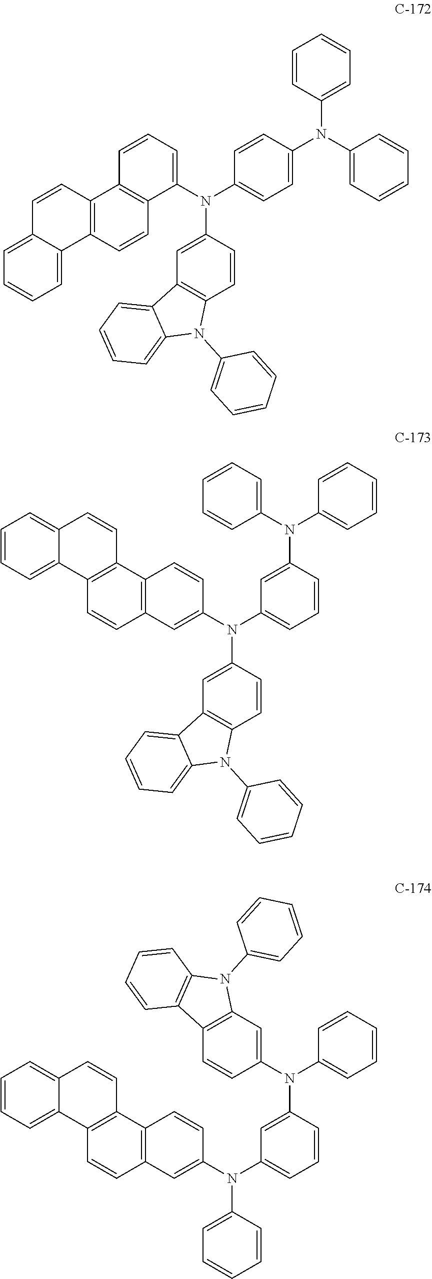 [SMILES: c1ccc(N(c2ccccc2)c2ccc(N(c3ccc4c(c3)c3ccccc3n4-c3ccccc3)c3cccc4c3ccc3c5ccccc5ccc43)cc2)cc1 ; c1ccc(N(c2ccccc2)c2cccc(N(c3ccc4c(ccc5c6ccccc6ccc45)c3)c3ccc4c(c3)c3ccccc3n4-c3ccccc3)c2)cc1 ; c1ccc(N(c2cccc(N(c3ccccc3)c3ccc4c5ccccc5n(-c5ccccc5)c4c3)c2)c2ccc3c(ccc4c5ccccc5ccc34)c2)cc1]

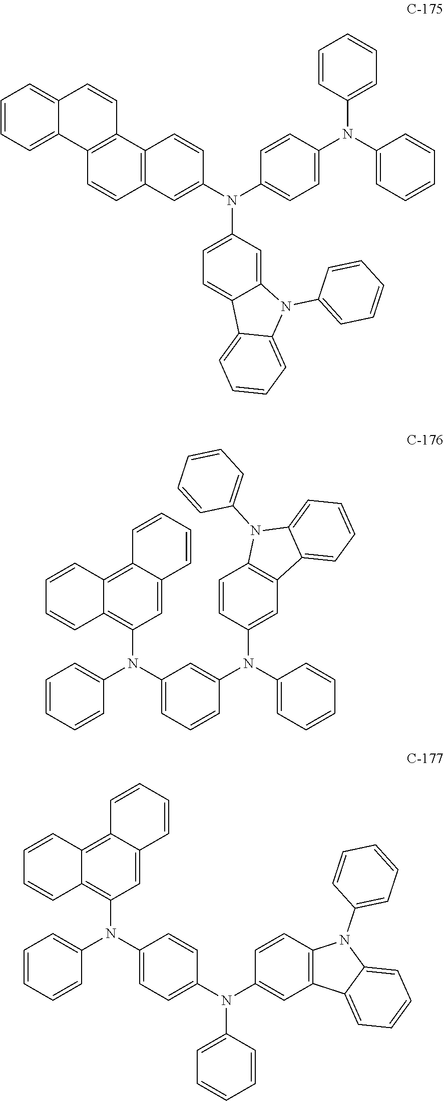 [SMILES: c1ccc(N(c2ccccc2)c2ccc(N(c3ccc4c(ccc5c6ccccc6ccc45)c3)c3ccc4c5ccccc5n(-c5ccccc5)c4c3)cc2)cc1 ; c1ccc(N(c2cccc(N(c3ccccc3)c3cc4ccccc4c4ccccc34)c2)c2ccc3c(c2)c2ccccc2n3-c2ccccc2)cc1 ; c1ccc(N(c2ccc(N(c3ccccc3)c3cc4ccccc4c4ccccc34)cc2)c2ccc3c(c2)c2ccccc2n3-c2ccccc2)cc1]

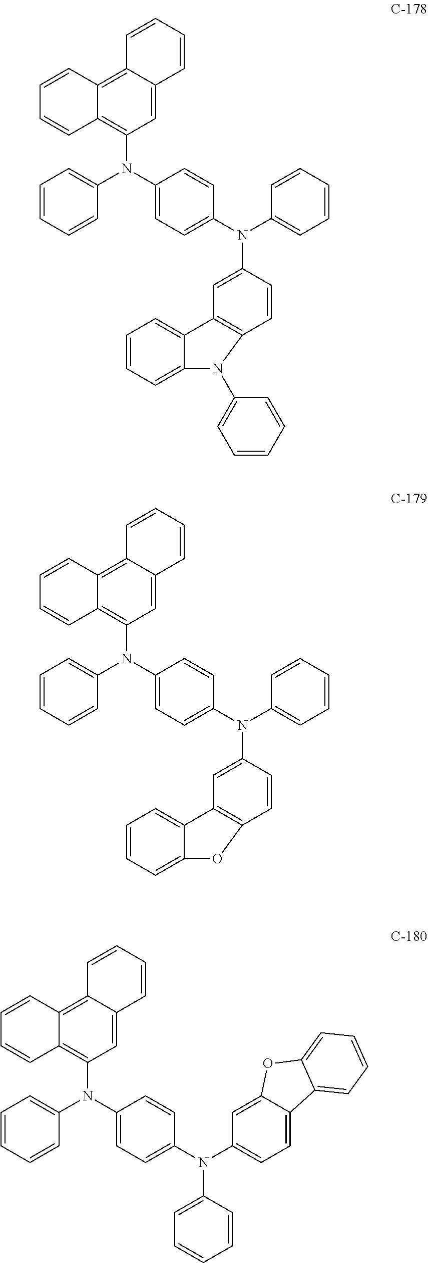 [SMILES: c1ccc(N(c2ccc(N(c3ccccc3)c3cc4ccccc4c4ccccc34)cc2)c2ccc3c(c2)c2ccccc2n3-c2ccccc2)cc1 ; c1ccc(N(c2ccc(N(c3ccccc3)c3cc4ccccc4c4ccccc34)cc2)c2ccc3oc4ccccc4c3c2)cc1 ; c1ccc(N(c2ccc(N(c3ccccc3)c3cc4ccccc4c4ccccc34)cc2)c2ccc3c(c2)oc2ccccc23)cc1]

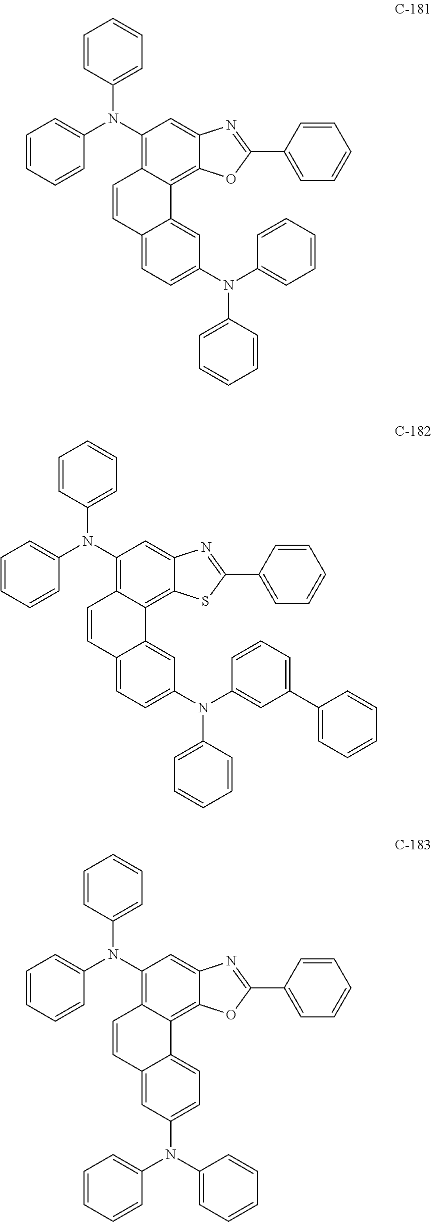 [SMILES: c1ccc(-c2nc3cc(N(c4ccccc4)c4ccccc4)c4ccc5ccc(N(c6ccccc6)c6ccccc6)cc5c4c3o2)cc1 ; c1ccc(-c2cccc(N(c3ccccc3)c3ccc4ccc5c(N(c6ccccc6)c6ccccc6)cc6nc(-c7ccccc7)sc6c5c4c3)c2)cc1 ; c1ccc(-c2nc3cc(N(c4ccccc4)c4ccccc4)c4ccc5cc(N(c6ccccc6)c6ccccc6)ccc5c4c3o2)cc1]

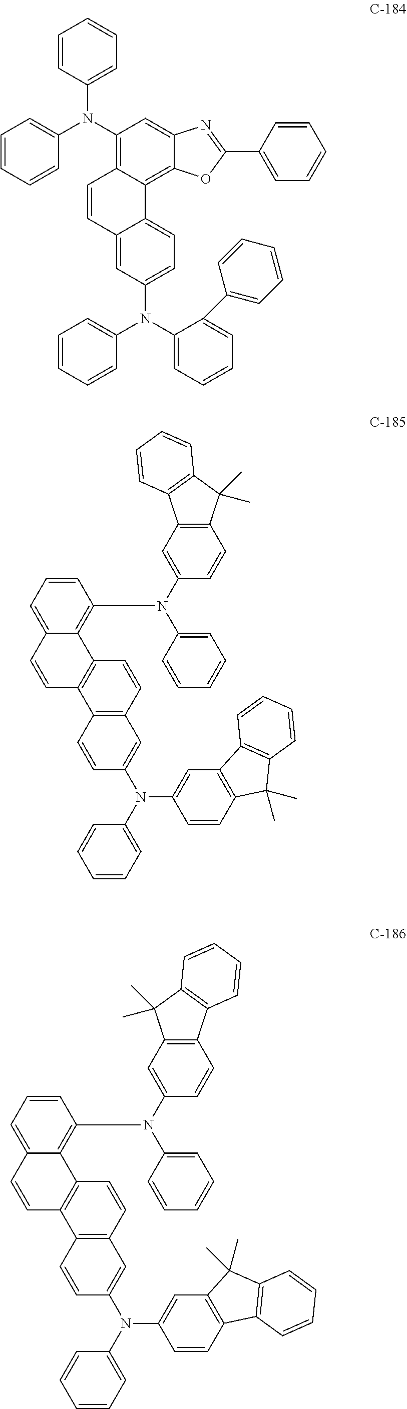 [SMILES: c1ccc(-c2nc3cc(N(c4ccccc4)c4ccccc4)c4ccc5cc(N(c6ccccc6)c6ccccc6-c6ccccc6)ccc5c4c3o2)cc1 ; CC1(C)c2ccccc2-c2cc(N(c3ccccc3)c3ccc4c(ccc5c4ccc4cccc(N(c6ccccc6)c6ccc7c(c6)-c6ccccc6C7(C)C)c45)c3)ccc21 ; CC1(C)c2ccccc2-c2ccc(N(c3ccccc3)c3ccc4c(ccc5c4ccc4cccc(N(c6ccccc6)c6ccc7c(c6)C(C)(C)c6ccccc6-7)c45)c3)cc21]

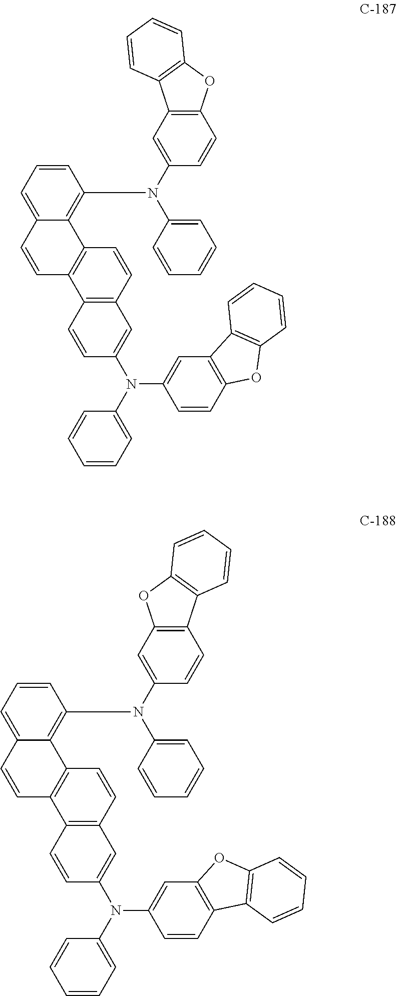 [SMILES: c1ccc(N(c2ccc3c(ccc4c3ccc3cccc(N(c5ccccc5)c5ccc6oc7ccccc7c6c5)c34)c2)c2ccc3oc4ccccc4c3c2)cc1 ; c1ccc(N(c2ccc3c(ccc4c3ccc3cccc(N(c5ccccc5)c5ccc6c(c5)oc5ccccc56)c34)c2)c2ccc3c(c2)oc2ccccc23)cc1]

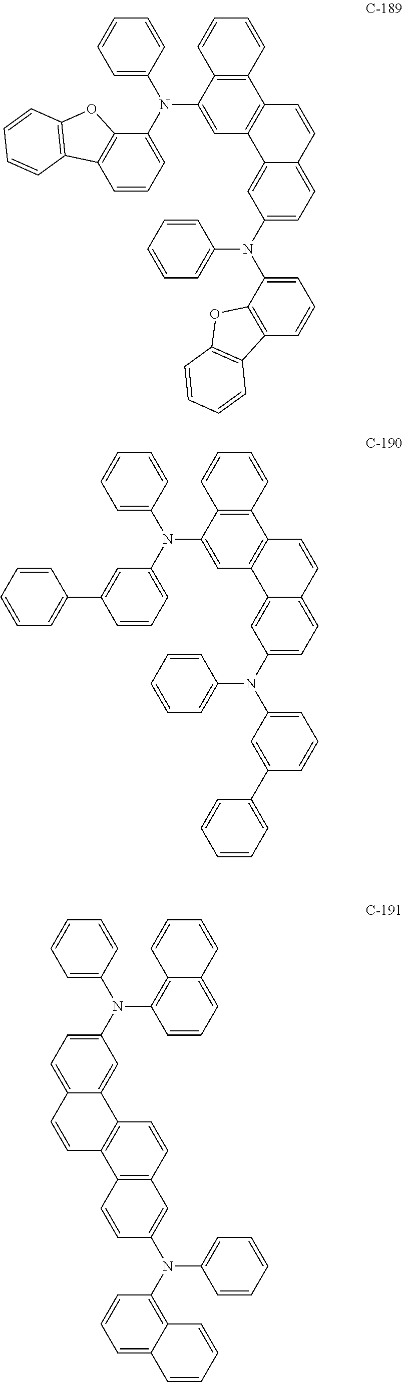

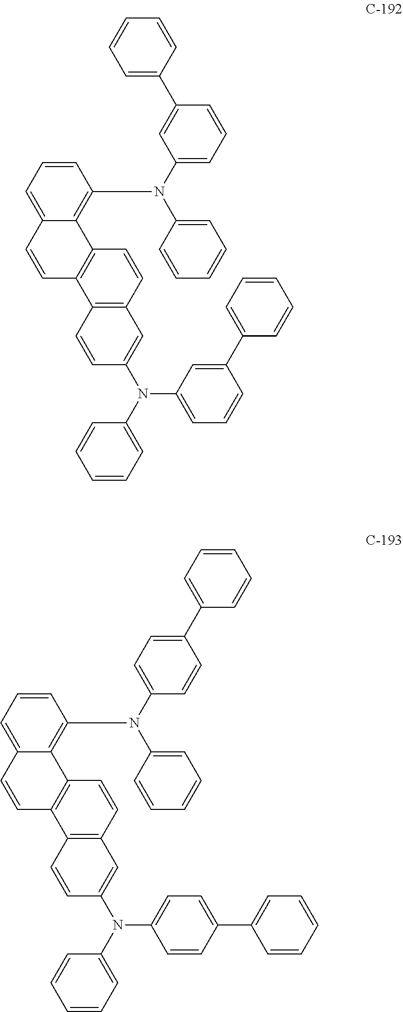 [SMILES: c1ccc(-c2cccc(N(c3ccccc3)c3ccc4c(ccc5c4ccc4cccc(N(c6ccccc6)c6cccc(-c7ccccc7)c6)c45)c3)c2)cc1 ; c1ccc(-c2ccc(N(c3ccccc3)c3ccc4c(ccc5c4ccc4cccc(N(c6ccccc6)c6ccc(-c7ccccc7)cc6)c45)c3)cc2)cc1]

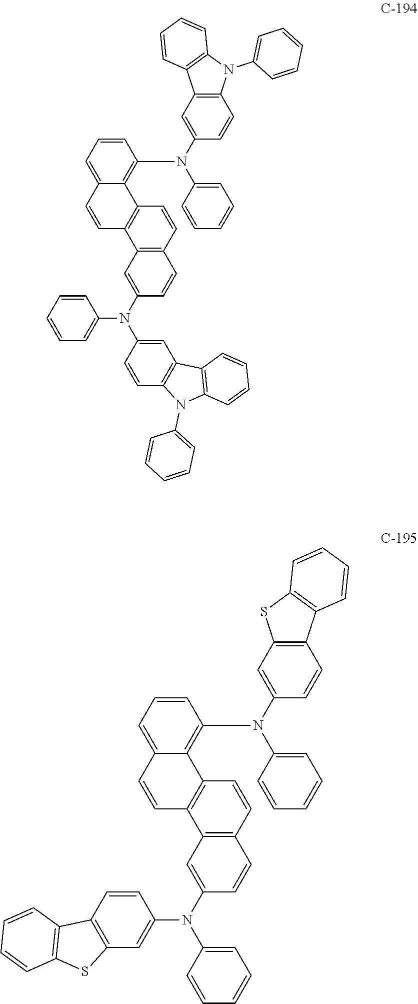 [SMILES: c1ccc(N(c2ccc3ccc4c(ccc5cccc(N(c6ccccc6)c6ccc7c(c6)c6ccccc6n7-c6ccccc6)c54)c3c2)c2ccc3c(c2)c2ccccc2n3-c2ccccc2)cc1 ; c1ccc(N(c2ccc3c(c2)sc2ccccc23)c2ccc3ccc4c(ccc5cccc(N(c6ccccc6)c6ccc7c(c6)sc6ccccc67)c54)c3c2)cc1]

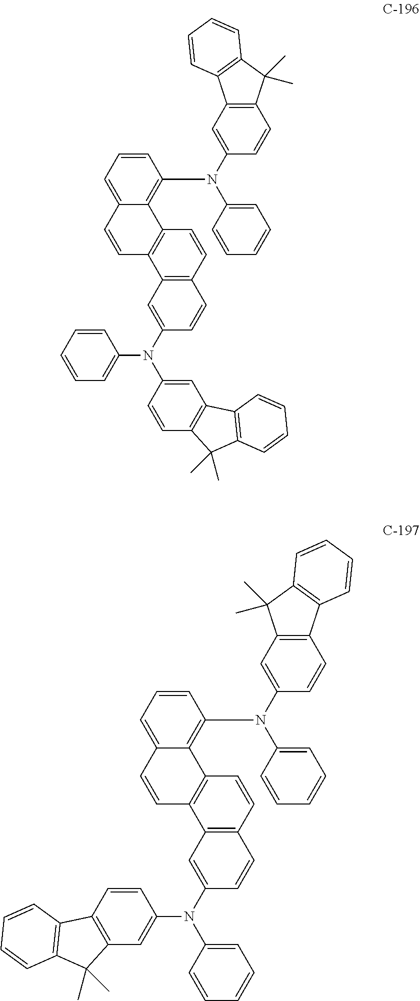 [SMILES: CC1(C)c2ccccc2-c2cc(N(c3ccccc3)c3ccc4ccc5c(ccc6cccc(N(c7ccccc7)c7ccc8c(c7)-c7ccccc7C8(C)C)c65)c4c3)ccc21 ; CC1(C)c2ccccc2-c2ccc(N(c3ccccc3)c3ccc4ccc5c(ccc6cccc(N(c7ccccc7)c7ccc8c(c7)C(C)(C)c7ccccc7-8)c65)c4c3)cc21]

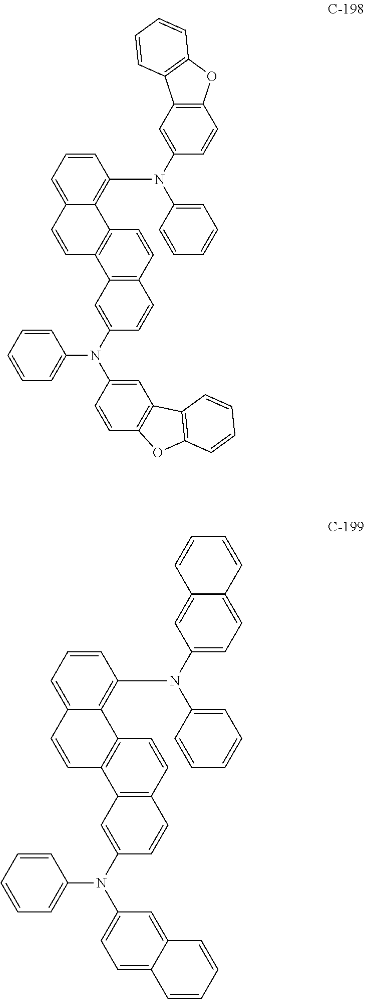 [SMILES: c1ccc(N(c2ccc3ccc4c(ccc5cccc(N(c6ccccc6)c6ccc7oc8ccccc8c7c6)c54)c3c2)c2ccc3oc4ccccc4c3c2)cc1 ; c1ccc(N(c2ccc3ccccc3c2)c2ccc3ccc4c(ccc5cccc(N(c6ccccc6)c6ccc7ccccc7c6)c54)c3c2)cc1]

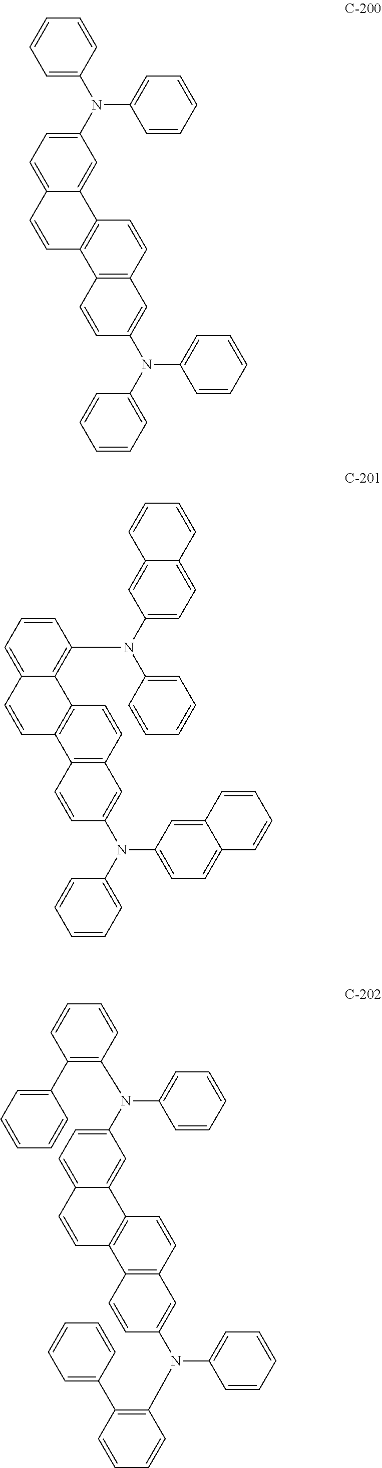 [SMILES: c1ccc(N(c2ccccc2)c2ccc3c(ccc4c5cc(N(c6ccccc6)c6ccccc6)ccc5ccc34)c2)cc1 ; c1ccc(N(c2ccc3ccccc3c2)c2ccc3c(ccc4c3ccc3cccc(N(c5ccccc5)c5ccc6ccccc6c5)c34)c2)cc1 ; c1ccc(-c2ccccc2N(c2ccccc2)c2ccc3c(ccc4c5cc(N(c6ccccc6)c6ccccc6-c6ccccc6)ccc5ccc34)c2)cc1]

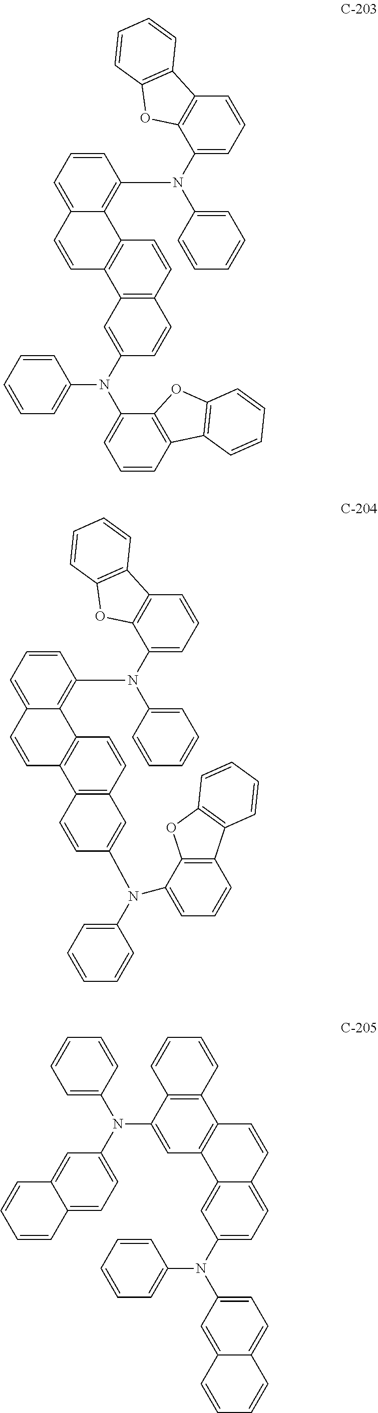 [SMILES: c1ccc(N(c2ccc3ccc4c(ccc5cccc(N(c6ccccc6)c6cccc7c6oc6ccccc67)c54)c3c2)c2cccc3c2oc2ccccc23)cc1 ; c1ccc(N(c2ccc3c(ccc4c3ccc3cccc(N(c5ccccc5)c5cccc6c5oc5ccccc56)c34)c2)c2cccc3c2oc2ccccc23)cc1 ; c1ccc(N(c2ccc3ccccc3c2)c2ccc3ccc4c5ccccc5c(N(c5ccccc5)c5ccc6ccccc6c5)cc4c3c2)cc1]

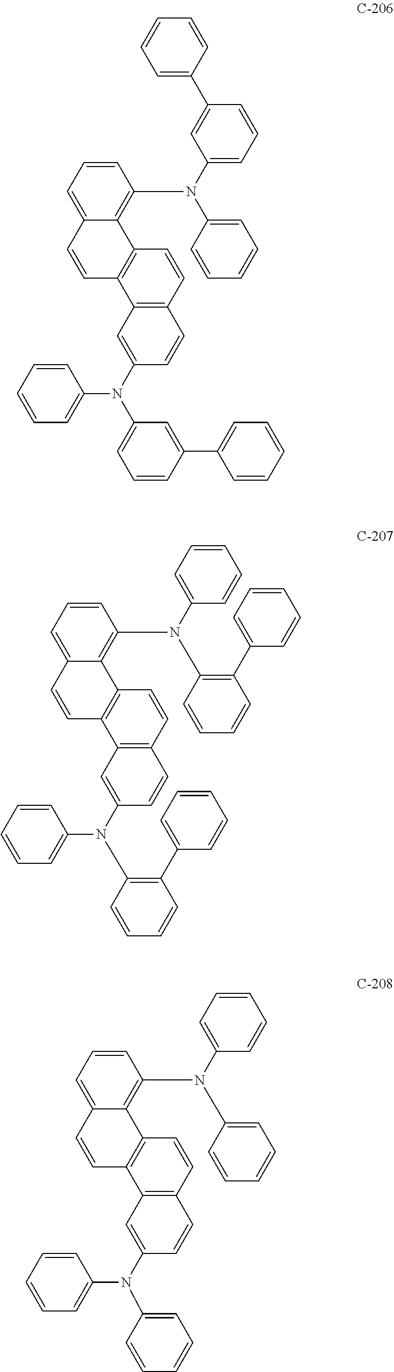 [SMILES: c1ccc(-c2cccc(N(c3ccccc3)c3ccc4ccc5c(ccc6cccc(N(c7ccccc7)c7cccc(-c8ccccc8)c7)c65)c4c3)c2)cc1 ; c1ccc(-c2ccccc2N(c2ccccc2)c2ccc3ccc4c(ccc5cccc(N(c6ccccc6)c6ccccc6-c6ccccc6)c54)c3c2)cc1 ; c1ccc(N(c2ccccc2)c2ccc3ccc4c(ccc5cccc(N(c6ccccc6)c6ccccc6)c54)c3c2)cc1]

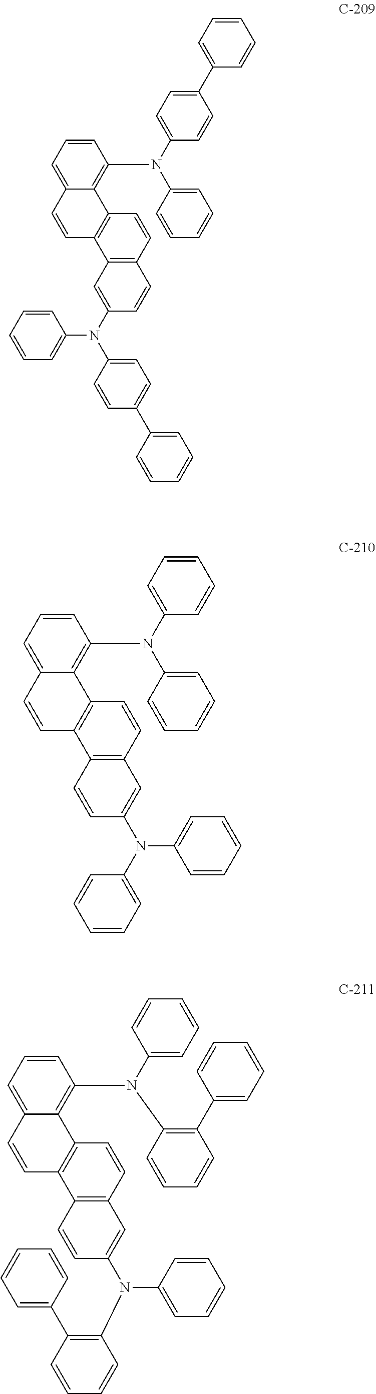 [SMILES: c1ccc(-c2ccc(N(c3ccccc3)c3ccc4ccc5c(ccc6cccc(N(c7ccccc7)c7ccc(-c8ccccc8)cc7)c65)c4c3)cc2)cc1 ; c1ccc(N(c2ccccc2)c2ccc3c(ccc4c3ccc3cccc(N(c5ccccc5)c5ccccc5)c34)c2)cc1 ; c1ccc(-c2ccccc2N(c2ccccc2)c2ccc3c(ccc4c3ccc3cccc(N(c5ccccc5)c5ccccc5-c5ccccc5)c34)c2)cc1]

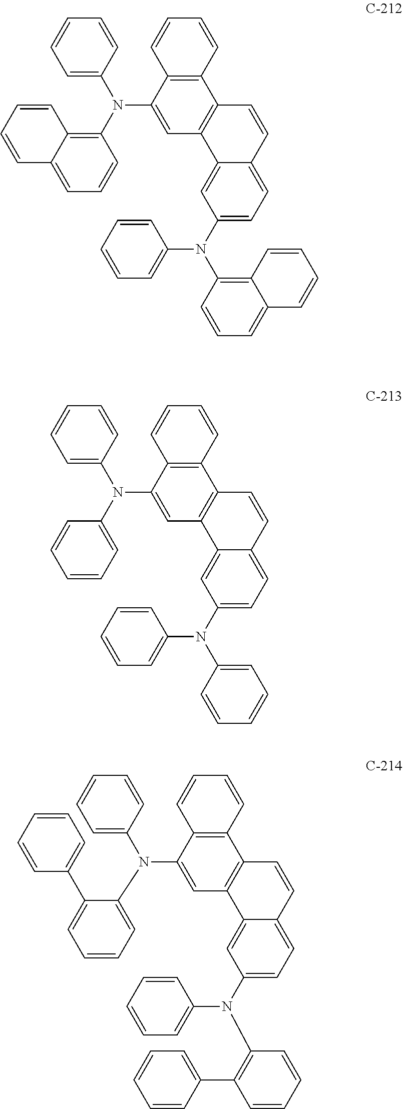 [SMILES: c1ccc(N(c2ccc3ccc4c5ccccc5c(N(c5ccccc5)c5cccc6ccccc56)cc4c3c2)c2cccc3ccccc23)cc1 ; c1ccc(N(c2ccccc2)c2ccc3ccc4c5ccccc5c(N(c5ccccc5)c5ccccc5)cc4c3c2)cc1 ; c1ccc(-c2ccccc2N(c2ccccc2)c2ccc3ccc4c5ccccc5c(N(c5ccccc5)c5ccccc5-c5ccccc5)cc4c3c2)cc1]

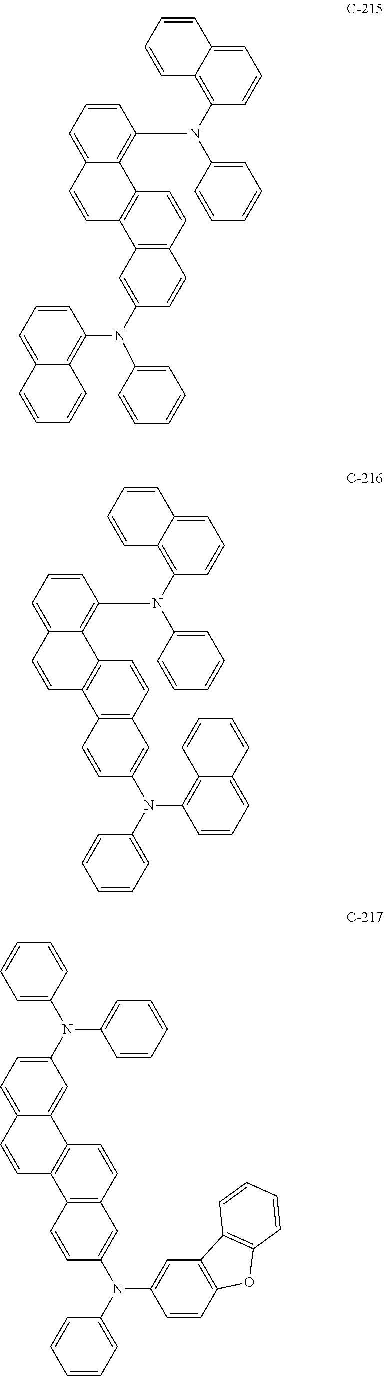 [SMILES: c1ccc(N(c2ccc3ccc4c(ccc5cccc(N(c6ccccc6)c6cccc7ccccc67)c54)c3c2)c2cccc3ccccc23)cc1 ; c1ccc(N(c2ccc3c(ccc4c3ccc3cccc(N(c5ccccc5)c5cccc6ccccc56)c34)c2)c2cccc3ccccc23)cc1 ; c1ccc(N(c2ccccc2)c2ccc3ccc4c5ccc(N(c6ccccc6)c6ccc7oc8ccccc8c7c6)cc5ccc4c3c2)cc1]

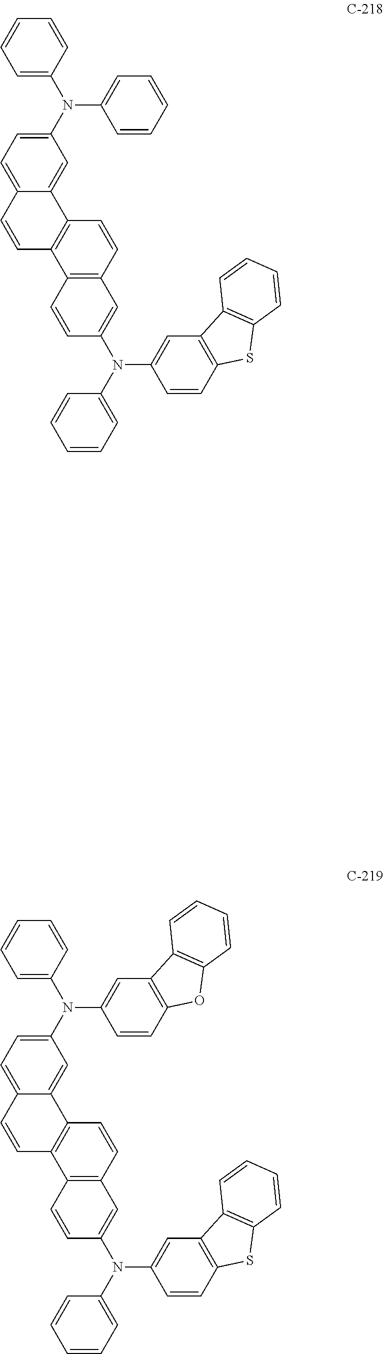 [SMILES: c1ccc(N(c2ccccc2)c2ccc3ccc4c5ccc(N(c6ccccc6)c6ccc7sc8ccccc8c7c6)cc5ccc4c3c2)cc1 ; c1ccc(N(c2ccc3ccc4c5ccc(N(c6ccccc6)c6ccc7sc8ccccc8c7c6)cc5ccc4c3c2)c2ccc3oc4ccccc4c3c2)cc1]

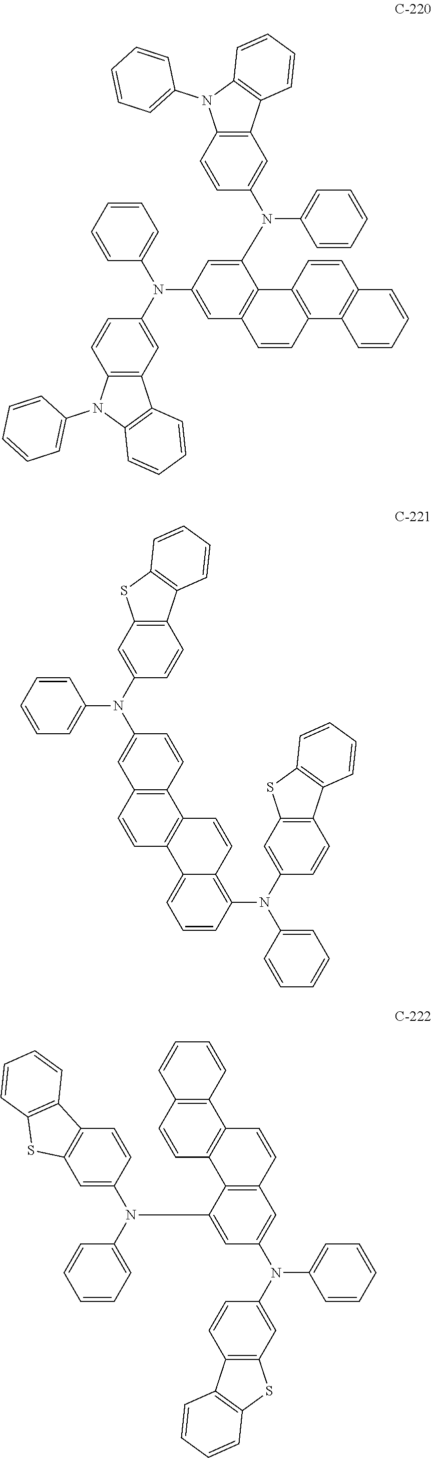 [SMILES: c1ccc(N(c2cc(N(c3ccccc3)c3ccc4c(c3)c3ccccc3n4-c3ccccc3)c3c(ccc4c5ccccc5ccc43)c2)c2ccc3c(c2)c2ccccc2n3-c2ccccc2)cc1 ; c1ccc(N(c2ccc3c(ccc4c5cccc(N(c6ccccc6)c6ccc7c(c6)sc6ccccc67)c5ccc34)c2)c2ccc3c(c2)sc2ccccc23)cc1 ; c1ccc(N(c2cc(N(c3ccccc3)c3ccc4c(c3)sc3ccccc34)c3c(ccc4c5ccccc5ccc43)c2)c2ccc3c(c2)sc2ccccc23)cc1]

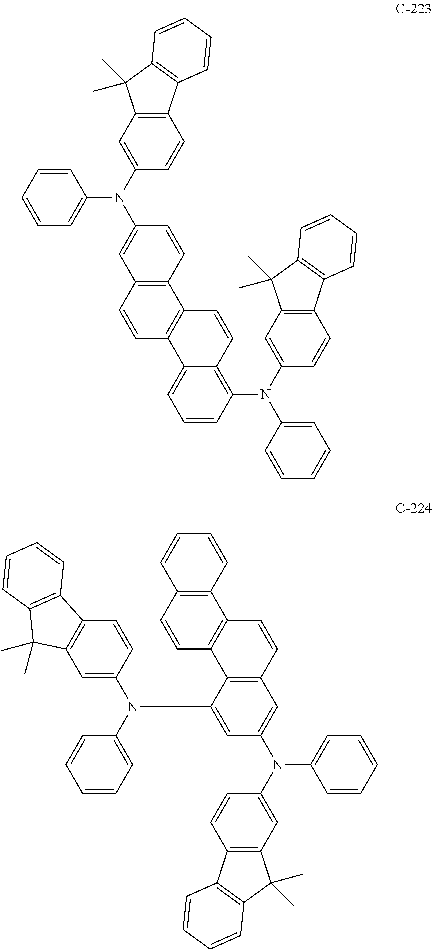 [SMILES: CC1(C)c2ccccc2-c2ccc(N(c3ccccc3)c3ccc4c(ccc5c6cccc(N(c7ccccc7)c7ccc8c(c7)C(C)(C)c7ccccc7-8)c6ccc45)c3)cc21 ; CC1(C)c2ccccc2-c2ccc(N(c3ccccc3)c3cc(N(c4ccccc4)c4ccc5c(c4)C(C)(C)c4ccccc4-5)c4c(ccc5c6ccccc6ccc54)c3)cc21]

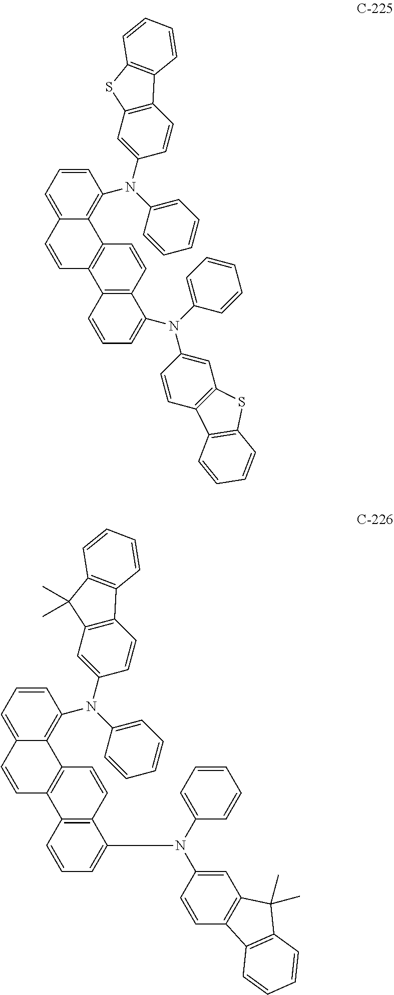 [SMILES: c1ccc(N(c2ccc3c(c2)sc2ccccc23)c2cccc3c2ccc2c3ccc3cccc(N(c4ccccc4)c4ccc5c(c4)sc4ccccc45)c32)cc1 ; CC1(C)c2ccccc2-c2ccc(N(c3ccccc3)c3cccc4c3ccc3c4ccc4cccc(N(c5ccccc5)c5ccc6c(c5)C(C)(C)c5ccccc5-6)c43)cc21]

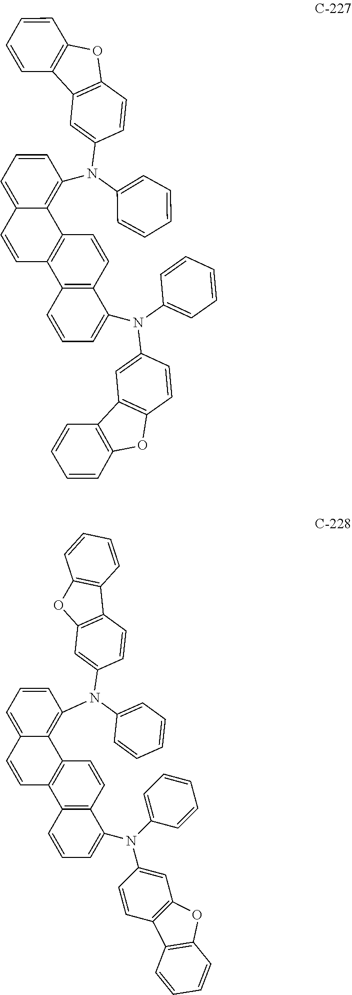 [SMILES: c1ccc(N(c2ccc3oc4ccccc4c3c2)c2cccc3c2ccc2c3ccc3cccc(N(c4ccccc4)c4ccc5oc6ccccc6c5c4)c32)cc1 ; c1ccc(N(c2ccc3c(c2)oc2ccccc23)c2cccc3c2ccc2c3ccc3cccc(N(c4ccccc4)c4ccc5c(c4)oc4ccccc45)c32)cc1]

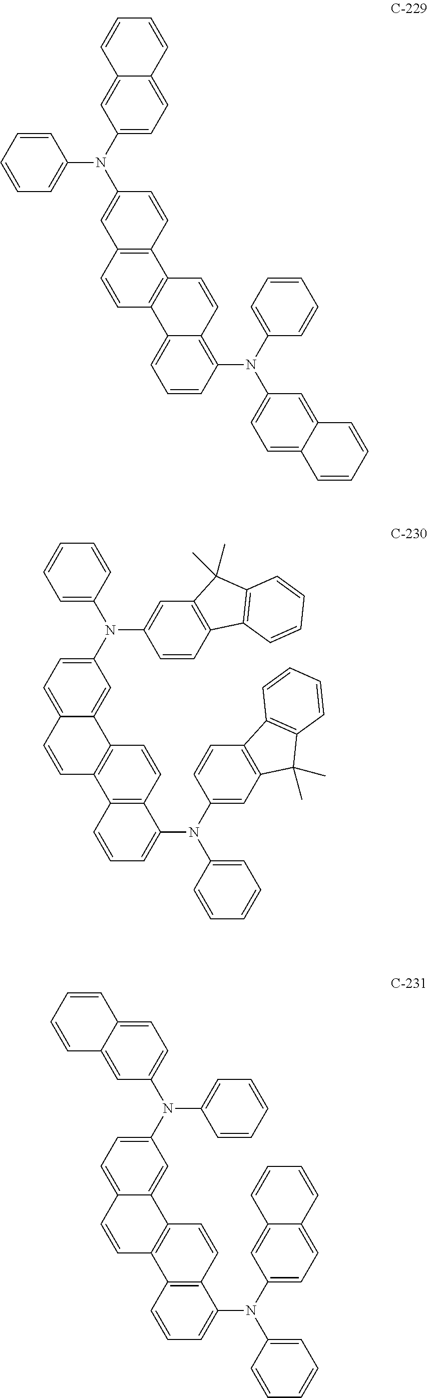 [SMILES: c1ccc(N(c2ccc3ccccc3c2)c2ccc3c(ccc4c5cccc(N(c6ccccc6)c6ccc7ccccc7c6)c5ccc34)c2)cc1 ; CC1(C)c2ccccc2-c2ccc(N(c3ccccc3)c3ccc4ccc5c6cccc(N(c7ccccc7)c7ccc8c(c7)C(C)(C)c7ccccc7-8)c6ccc5c4c3)cc21 ; c1ccc(N(c2ccc3ccccc3c2)c2ccc3ccc4c5cccc(N(c6ccccc6)c6ccc7ccccc7c6)c5ccc4c3c2)cc1]

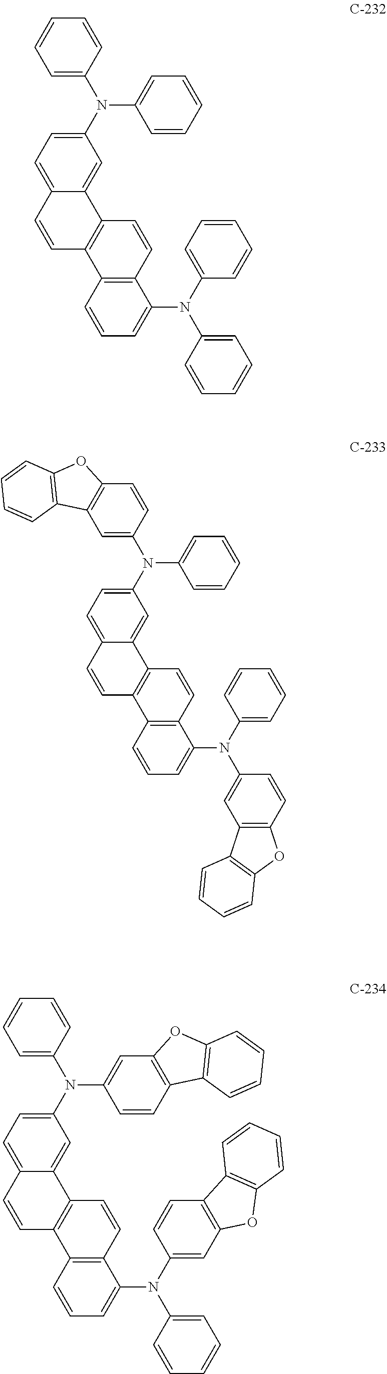 [SMILES: c1ccc(N(c2ccccc2)c2ccc3ccc4c5cccc(N(c6ccccc6)c6ccccc6)c5ccc4c3c2)cc1 ; c1ccc(N(c2ccc3ccc4c5cccc(N(c6ccccc6)c6ccc7oc8ccccc8c7c6)c5ccc4c3c2)c2ccc3oc4ccccc4c3c2)cc1 ; c1ccc(N(c2ccc3c(c2)oc2ccccc23)c2ccc3ccc4c5cccc(N(c6ccccc6)c6ccc7c(c6)oc6ccccc67)c5ccc4c3c2)cc1]

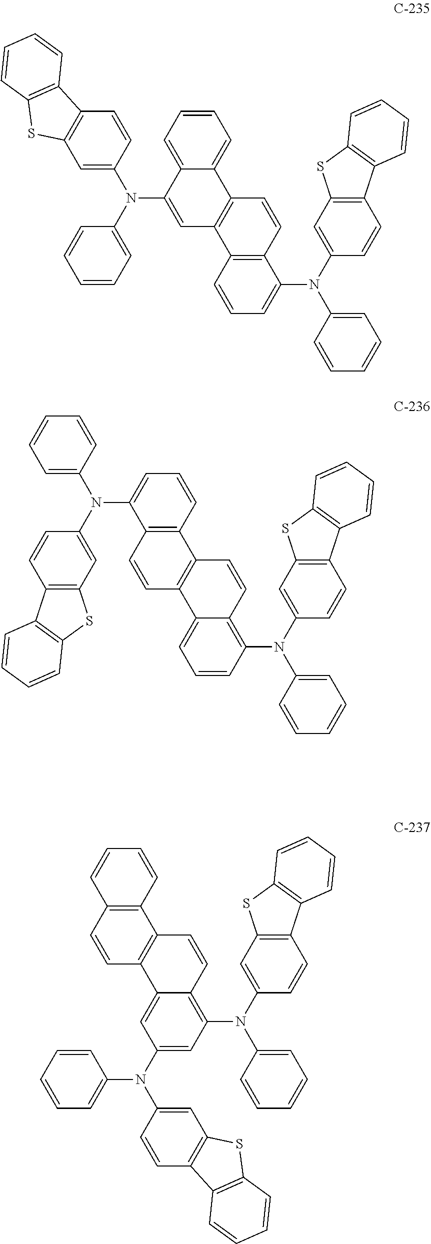 [SMILES: c1ccc(N(c2ccc3c(c2)sc2ccccc23)c2cc3c4cccc(N(c5ccccc5)c5ccc6c(c5)sc5ccccc56)c4ccc3c3ccccc23)cc1 ; c1ccc(N(c2ccc3c(c2)sc2ccccc23)c2cccc3c2ccc2c4cccc(N(c5ccccc5)c5ccc6c(c5)sc5ccccc56)c4ccc32)cc1 ; c1ccc(N(c2ccc3c(c2)sc2ccccc23)c2cc(N(c3ccccc3)c3ccc4c(c3)sc3ccccc34)c3ccc4c5ccccc5ccc4c3c2)cc1]

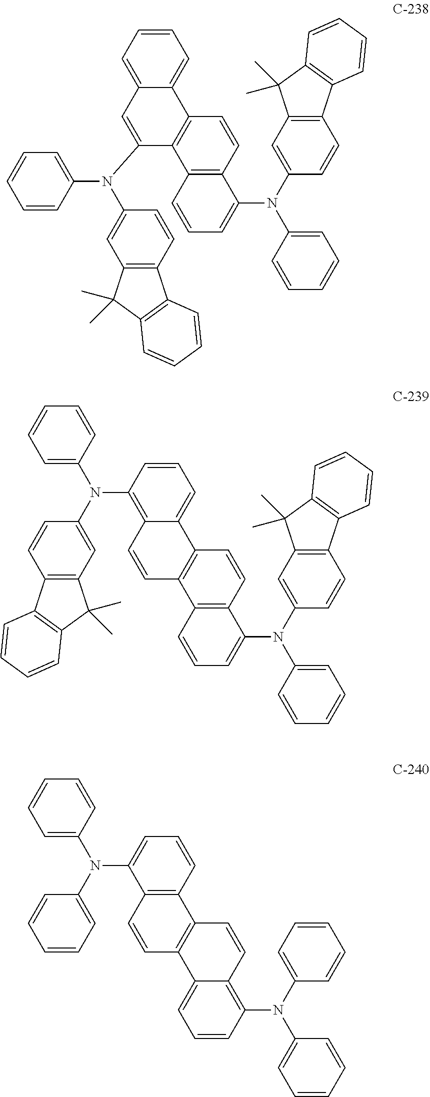 [SMILES: CC1(C)c2ccccc2-c2ccc(N(c3ccccc3)c3cccc4c3ccc3c5ccccc5cc(N(c5ccccc5)c5ccc6c(c5)C(C)(C)c5ccccc5-6)c43)cc21 ; CC1(C)c2ccccc2-c2ccc(N(c3ccccc3)c3cccc4c3ccc3c5cccc(N(c6ccccc6)c6ccc7c(c6)C(C)(C)c6ccccc6-7)c5ccc43)cc21 ; c1ccc(N(c2ccccc2)c2cccc3c2ccc2c4cccc(N(c5ccccc5)c5ccccc5)c4ccc32)cc1]

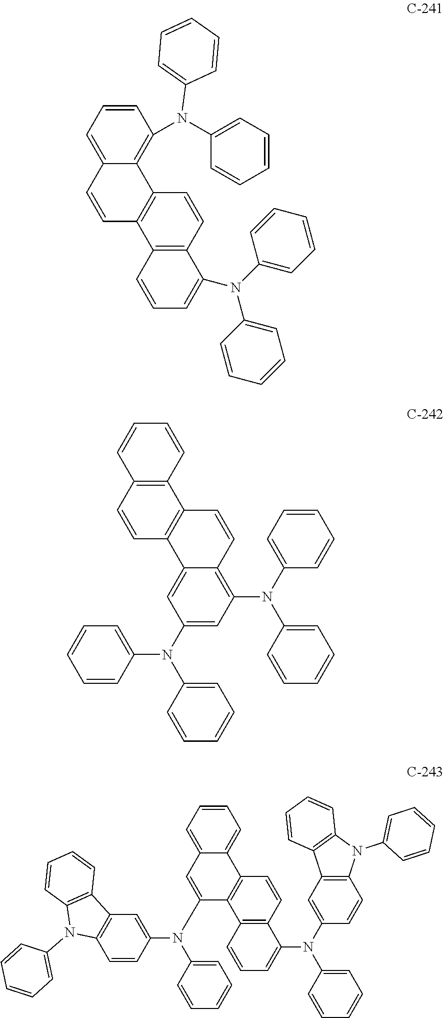 [SMILES: c1ccc(N(c2ccccc2)c2cccc3c2ccc2c3ccc3cccc(N(c4ccccc4)c4ccccc4)c32)cc1 ; c1ccc(N(c2ccccc2)c2cc(N(c3ccccc3)c3ccccc3)c3ccc4c5ccccc5ccc4c3c2)cc1 ; c1ccc(N(c2ccc3c(c2)c2ccccc2n3-c2ccccc2)c2cccc3c2ccc2c4ccccc4cc(N(c4ccccc4)c4ccc5c(c4)c4ccccc4n5-c4ccccc4)c32)cc1]

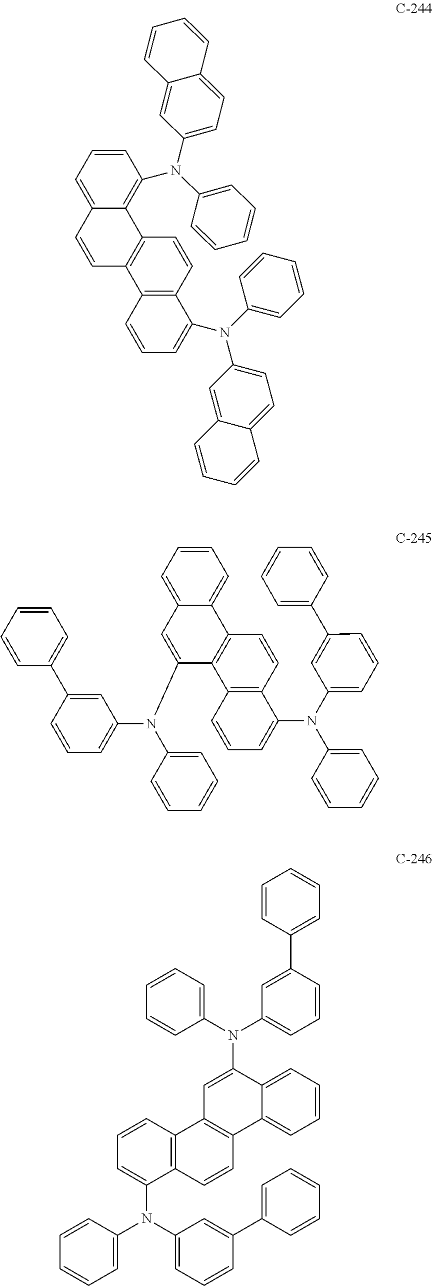 [SMILES: c1ccc(N(c2ccc3ccccc3c2)c2cccc3c2ccc2c3ccc3cccc(N(c4ccccc4)c4ccc5ccccc5c4)c32)cc1 ; c1ccc(-c2cccc(N(c3ccccc3)c3cccc4c3ccc3c5ccccc5cc(N(c5ccccc5)c5cccc(-c6ccccc6)c5)c43)c2)cc1 ; c1ccc(-c2cccc(N(c3ccccc3)c3cc4c5cccc(N(c6ccccc6)c6cccc(-c7ccccc7)c6)c5ccc4c4ccccc34)c2)cc1]

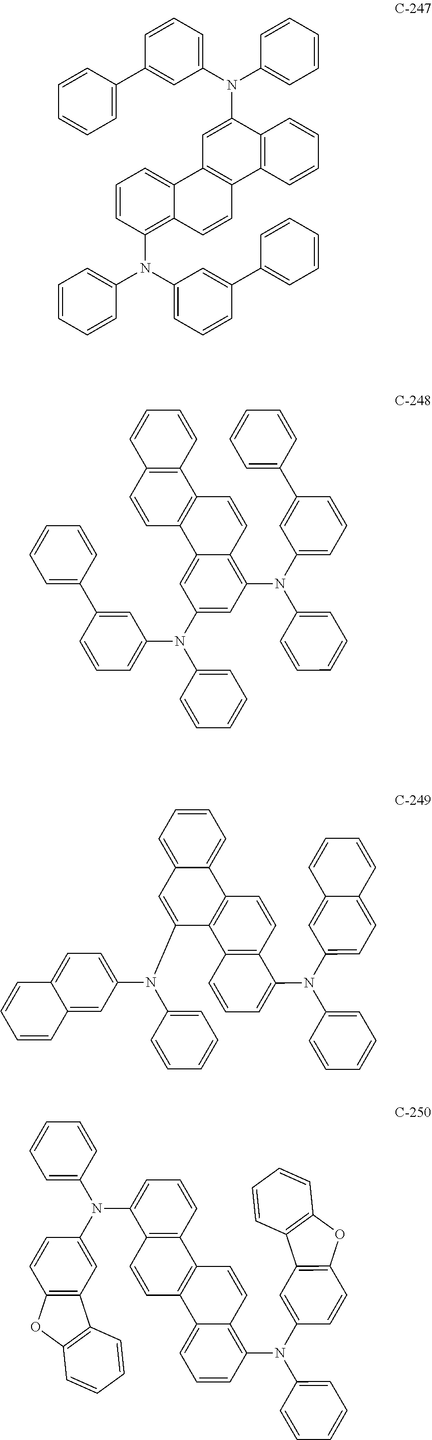 [SMILES: c1ccc(-c2cccc(N(c3ccccc3)c3cc4c5cccc(N(c6ccccc6)c6cccc(-c7ccccc7)c6)c5ccc4c4ccccc34)c2)cc1 ; c1ccc(-c2cccc(N(c3ccccc3)c3cc(N(c4ccccc4)c4cccc(-c5ccccc5)c4)c4ccc5c6ccccc6ccc5c4c3)c2)cc1 ; c1ccc(N(c2ccc3ccccc3c2)c2cccc3c2ccc2c4ccccc4cc(N(c4ccccc4)c4ccc5ccccc5c4)c32)cc1 ; c1ccc(N(c2ccc3oc4ccccc4c3c2)c2cccc3c2ccc2c4cccc(N(c5ccccc5)c5ccc6oc7ccccc7c6c5)c4ccc32)cc1]

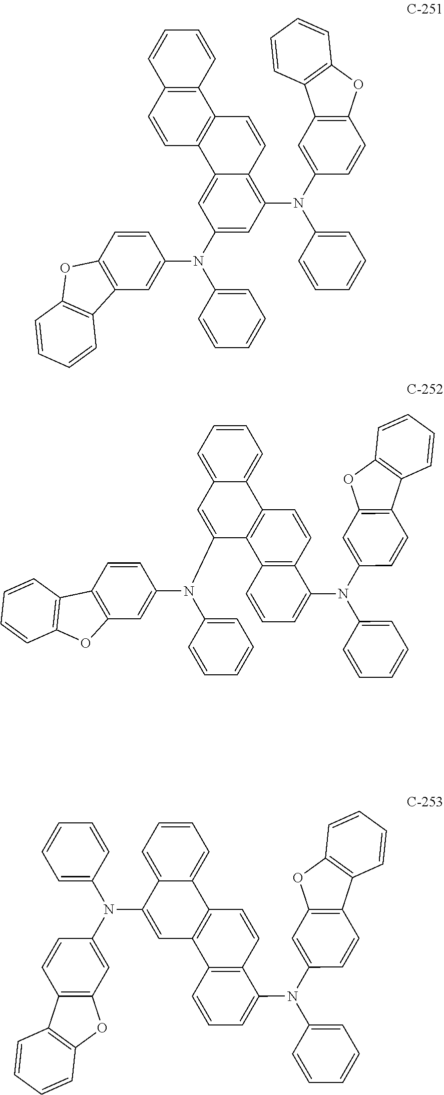 [SMILES: c1ccc(N(c2ccc3oc4ccccc4c3c2)c2cc(N(c3ccccc3)c3ccc4oc5ccccc5c4c3)c3ccc4c5ccccc5ccc4c3c2)cc1 ; c1ccc(N(c2ccc3c(c2)oc2ccccc23)c2cccc3c2ccc2c4ccccc4cc(N(c4ccccc4)c4ccc5c(c4)oc4ccccc45)c32)cc1 ; c1ccc(N(c2ccc3c(c2)oc2ccccc23)c2cc3c4cccc(N(c5ccccc5)c5ccc6c(c5)oc5ccccc56)c4ccc3c3ccccc23)cc1]

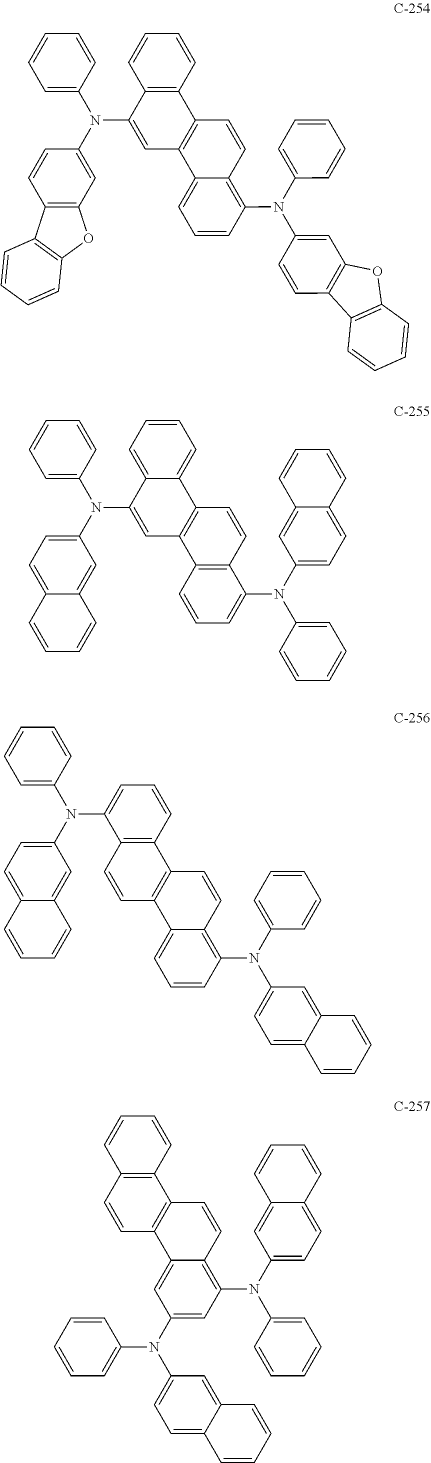 [SMILES: c1ccc(N(c2ccc3c(c2)oc2ccccc23)c2cc3c4cccc(N(c5ccccc5)c5ccc6c(c5)oc5ccccc56)c4ccc3c3ccccc23)cc1 ; c1ccc(N(c2ccc3ccccc3c2)c2cc3c4cccc(N(c5ccccc5)c5ccc6ccccc6c5)c4ccc3c3ccccc23)cc1 ; c1ccc(N(c2ccc3ccccc3c2)c2cccc3c2ccc2c4cccc(N(c5ccccc5)c5ccc6ccccc6c5)c4ccc32)cc1 ; c1ccc(N(c2ccc3ccccc3c2)c2cc(N(c3ccccc3)c3ccc4ccccc4c3)c3ccc4c5ccccc5ccc4c3c2)cc1]

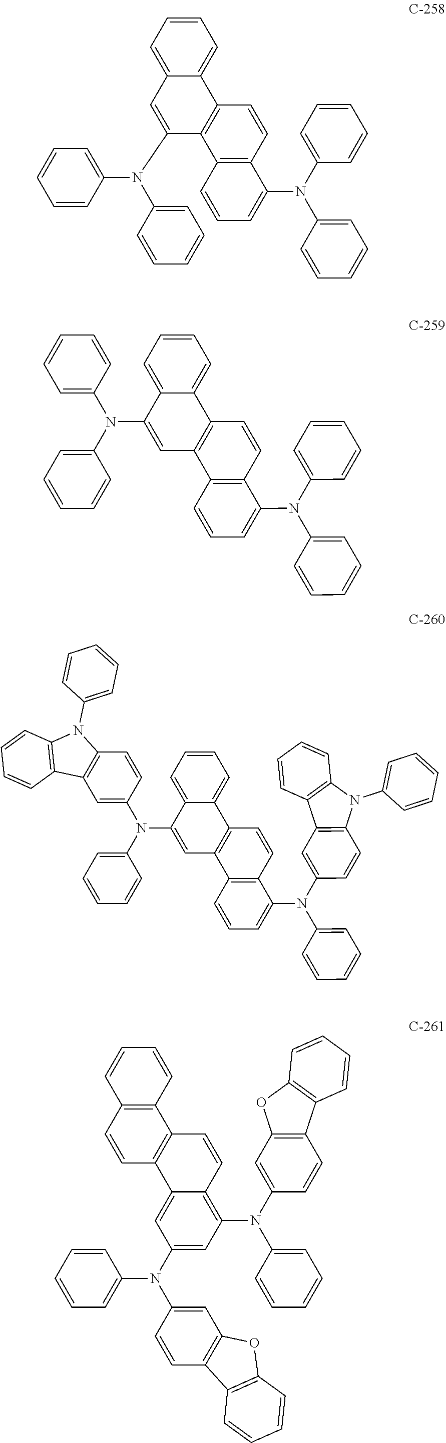 [SMILES: c1ccc(N(c2ccccc2)c2cccc3c2ccc2c4ccccc4cc(N(c4ccccc4)c4ccccc4)c32)cc1 ; c1ccc(N(c2ccccc2)c2cc3c4cccc(N(c5ccccc5)c5ccccc5)c4ccc3c3ccccc23)cc1 ; c1ccc(N(c2ccc3c(c2)c2ccccc2n3-c2ccccc2)c2cc3c4cccc(N(c5ccccc5)c5ccc6c(c5)c5ccccc5n6-c5ccccc5)c4ccc3c3ccccc23)cc1 ; c1ccc(N(c2ccc3c(c2)oc2ccccc23)c2cc(N(c3ccccc3)c3ccc4c(c3)oc3ccccc34)c3ccc4c5ccccc5ccc4c3c2)cc1]

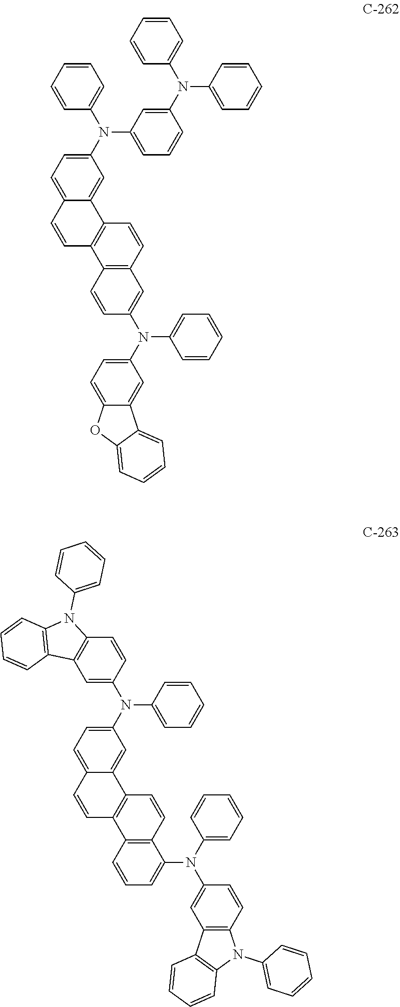 [SMILES: c1ccc(N(c2ccccc2)c2cccc(N(c3ccccc3)c3ccc4ccc5c6ccc(N(c7ccccc7)c7ccc8oc9ccccc9c8c7)cc6ccc5c4c3)c2)cc1 ; c1ccc(N(c2ccc3ccc4c5cccc(N(c6ccccc6)c6ccc7c(c6)c6ccccc6n7-c6ccccc6)c5ccc4c3c2)c2ccc3c(c2)c2ccccc2n3-c2ccccc2)cc1]

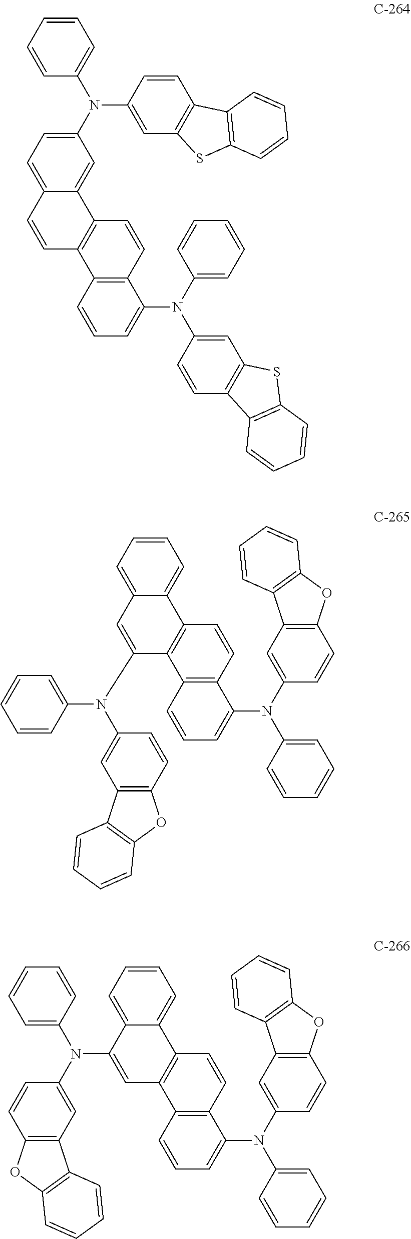 [SMILES: c1ccc(N(c2ccc3c(c2)sc2ccccc23)c2ccc3ccc4c5cccc(N(c6ccccc6)c6ccc7c(c6)sc6ccccc67)c5ccc4c3c2)cc1 ; c1ccc(N(c2ccc3oc4ccccc4c3c2)c2cccc3c2ccc2c4ccccc4cc(N(c4ccccc4)c4ccc5oc6ccccc6c5c4)c32)cc1 ; c1ccc(N(c2ccc3oc4ccccc4c3c2)c2cc3c4cccc(N(c5ccccc5)c5ccc6oc7ccccc7c6c5)c4ccc3c3ccccc23)cc1]

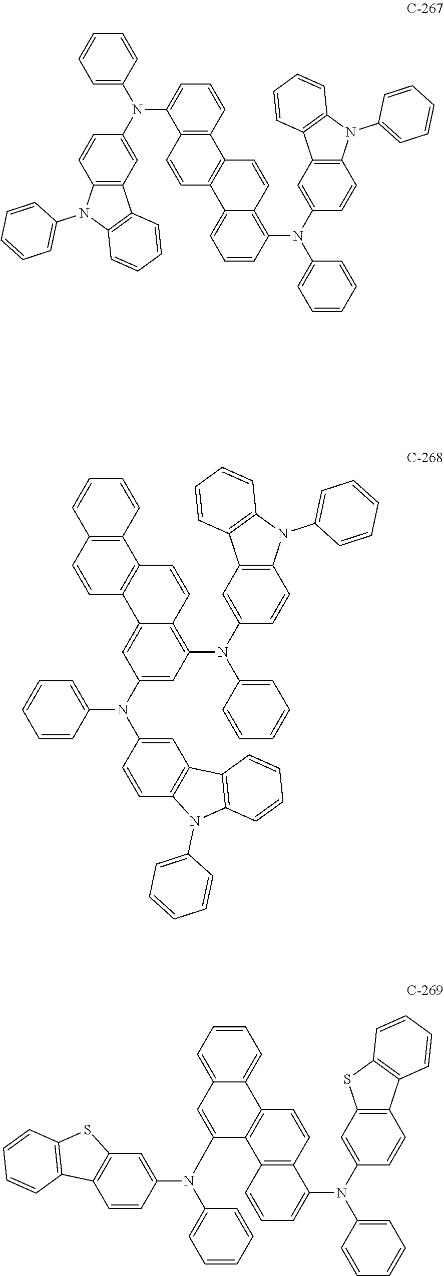 [SMILES: c1ccc(N(c2ccc3c(c2)c2ccccc2n3-c2ccccc2)c2cccc3c2ccc2c4cccc(N(c5ccccc5)c5ccc6c(c5)c5ccccc5n6-c5ccccc5)c4ccc32)cc1 ; c1ccc(N(c2cc(N(c3ccccc3)c3ccc4c(c3)c3ccccc3n4-c3ccccc3)c3ccc4c5ccccc5ccc4c3c2)c2ccc3c(c2)c2ccccc2n3-c2ccccc2)cc1 ; c1ccc(N(c2ccc3c(c2)sc2ccccc23)c2cccc3c2ccc2c4ccccc4cc(N(c4ccccc4)c4ccc5c(c4)sc4ccccc45)c32)cc1]

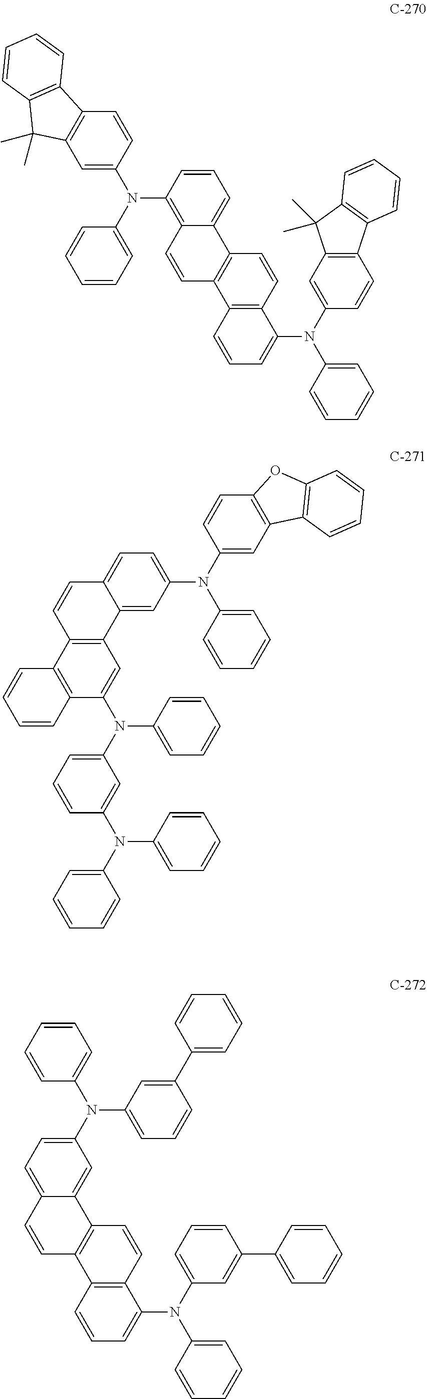 [SMILES: CC1(C)c2ccccc2-c2ccc(N(c3ccccc3)c3cccc4c3ccc3c5cccc(N(c6ccccc6)c6ccc7c(c6)C(C)(C)c6ccccc6-7)c5ccc43)cc21 ; c1ccc(N(c2ccccc2)c2cccc(N(c3ccccc3)c3cc4c5cc(N(c6ccccc6)c6ccc7oc8ccccc8c7c6)ccc5ccc4c4ccccc34)c2)cc1 ; c1ccc(-c2cccc(N(c3ccccc3)c3ccc4ccc5c6cccc(N(c7ccccc7)c7cccc(-c8ccccc8)c7)c6ccc5c4c3)c2)cc1]

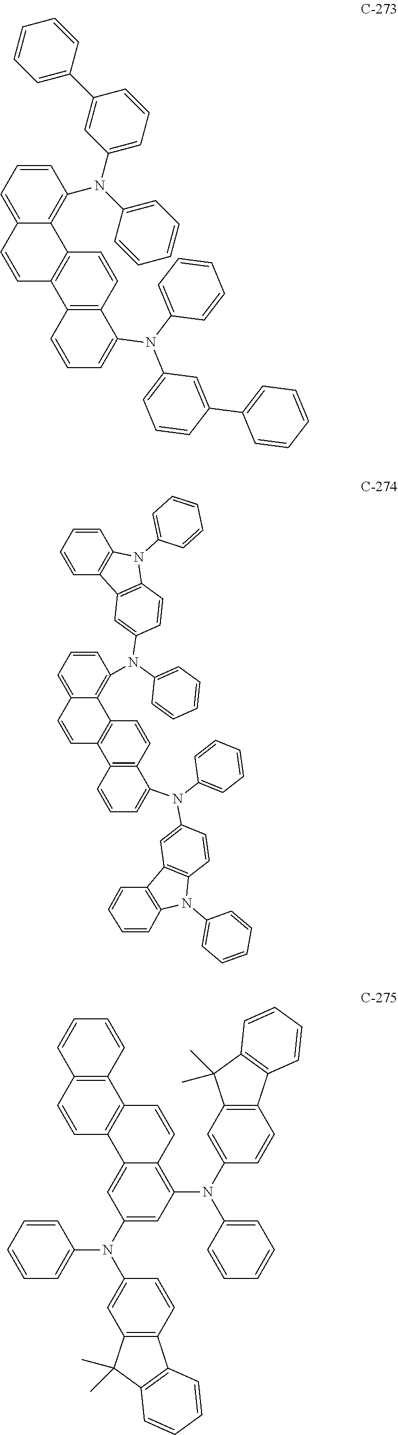 [SMILES: c1ccc(-c2cccc(N(c3ccccc3)c3cccc4c3ccc3c4ccc4cccc(N(c5ccccc5)c5cccc(-c6ccccc6)c5)c43)c2)cc1 ; c1ccc(N(c2ccc3c(c2)c2ccccc2n3-c2ccccc2)c2cccc3c2ccc2c3ccc3cccc(N(c4ccccc4)c4ccc5c(c4)c4ccccc4n5-c4ccccc4)c32)cc1 ; CC1(C)c2ccccc2-c2ccc(N(c3ccccc3)c3cc(N(c4ccccc4)c4ccc5c(c4)C(C)(C)c4ccccc4-5)c4ccc5c6ccccc6ccc5c4c3)cc21]

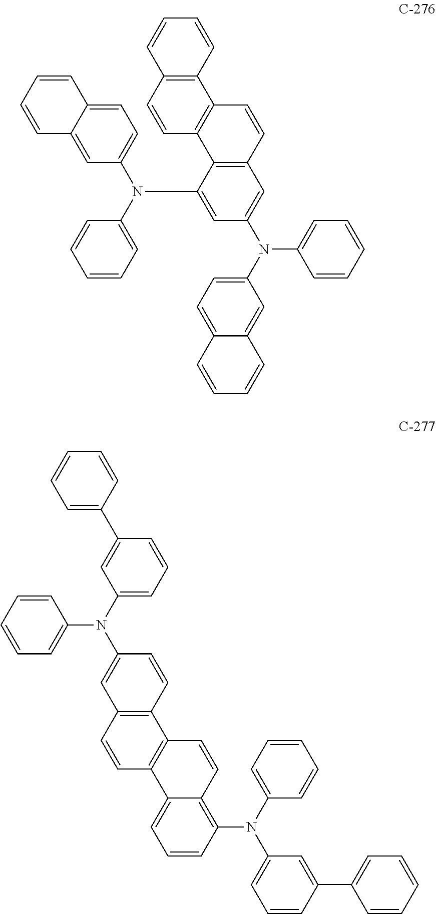 [SMILES: c1ccc(N(c2ccc3ccccc3c2)c2cc(N(c3ccccc3)c3ccc4ccccc4c3)c3c(ccc4c5ccccc5ccc43)c2)cc1 ; c1ccc(-c2cccc(N(c3ccccc3)c3ccc4c(ccc5c6cccc(N(c7ccccc7)c7cccc(-c8ccccc8)c7)c6ccc45)c3)c2)cc1]

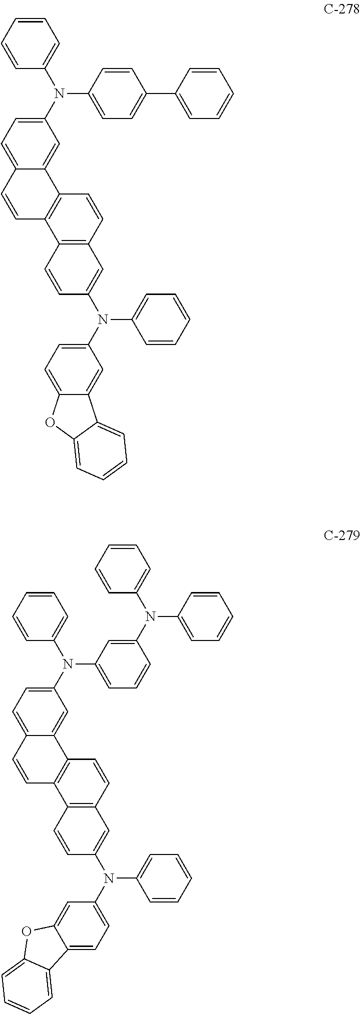 [SMILES: c1ccc(-c2ccc(N(c3ccccc3)c3ccc4ccc5c6ccc(N(c7ccccc7)c7ccc8oc9ccccc9c8c7)cc6ccc5c4c3)cc2)cc1 ; c1ccc(N(c2ccccc2)c2cccc(N(c3ccccc3)c3ccc4ccc5c6ccc(N(c7ccccc7)c7ccc8c(c7)oc7ccccc78)cc6ccc5c4c3)c2)cc1]

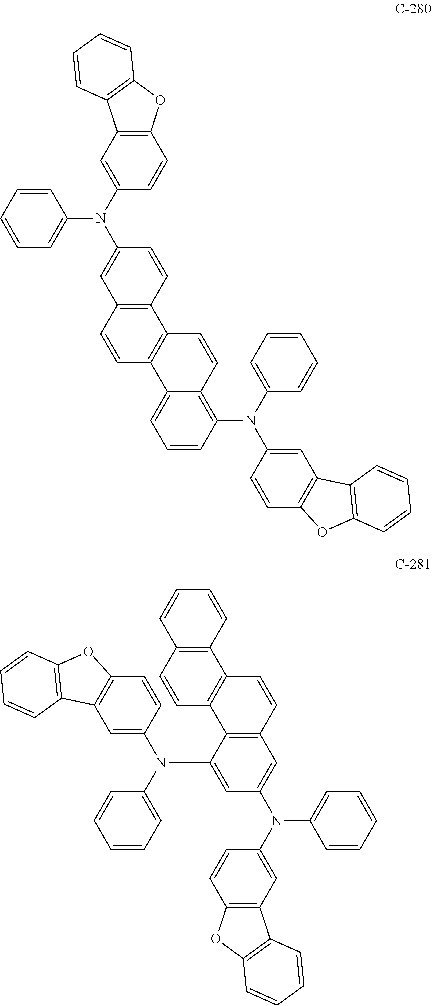 [SMILES: c1ccc(N(c2ccc3c(ccc4c5cccc(N(c6ccccc6)c6ccc7oc8ccccc8c7c6)c5ccc34)c2)c2ccc3oc4ccccc4c3c2)cc1 ; c1ccc(N(c2cc(N(c3ccccc3)c3ccc4oc5ccccc5c4c3)c3c(ccc4c5ccccc5ccc43)c2)c2ccc3oc4ccccc4c3c2)cc1]

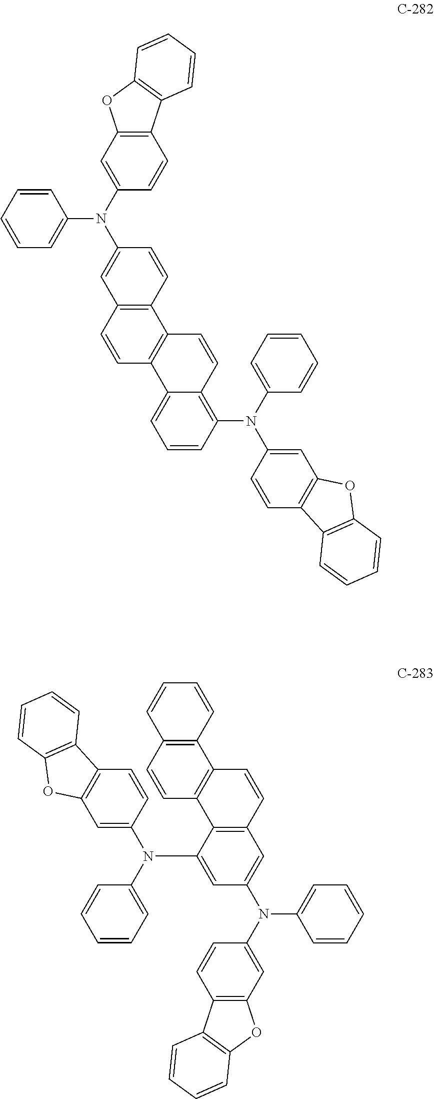 [SMILES: c1ccc(N(c2ccc3c(ccc4c5cccc(N(c6ccccc6)c6ccc7c(c6)oc6ccccc67)c5ccc34)c2)c2ccc3c(c2)oc2ccccc23)cc1 ; c1ccc(N(c2cc(N(c3ccccc3)c3ccc4c(c3)oc3ccccc34)c3c(ccc4c5ccccc5ccc43)c2)c2ccc3c(c2)oc2ccccc23)cc1]

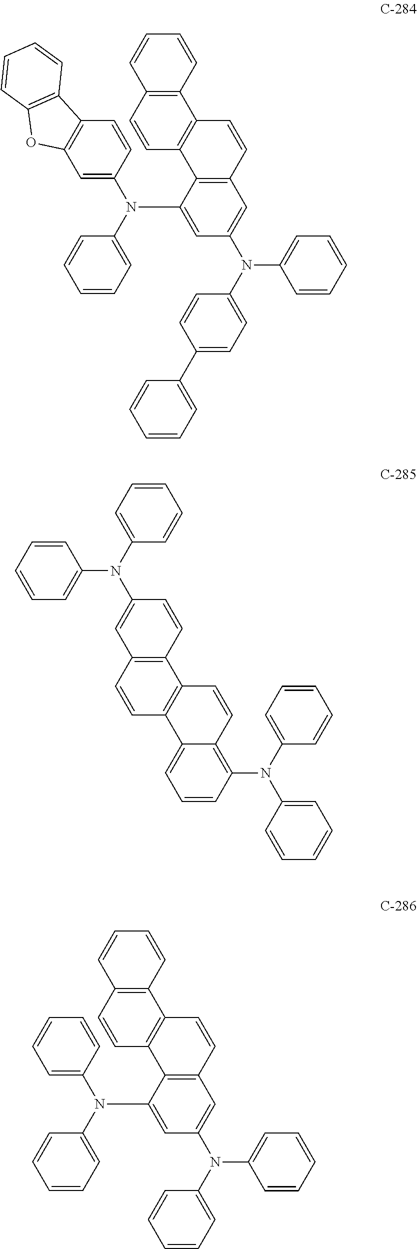 [SMILES: c1ccc(-c2ccc(N(c3ccccc3)c3cc(N(c4ccccc4)c4ccc5c(c4)oc4ccccc45)c4c(ccc5c6ccccc6ccc54)c3)cc2)cc1 ; c1ccc(N(c2ccccc2)c2ccc3c(ccc4c5cccc(N(c6ccccc6)c6ccccc6)c5ccc34)c2)cc1 ; c1ccc(N(c2ccccc2)c2cc(N(c3ccccc3)c3ccccc3)c3c(ccc4c5ccccc5ccc43)c2)cc1]

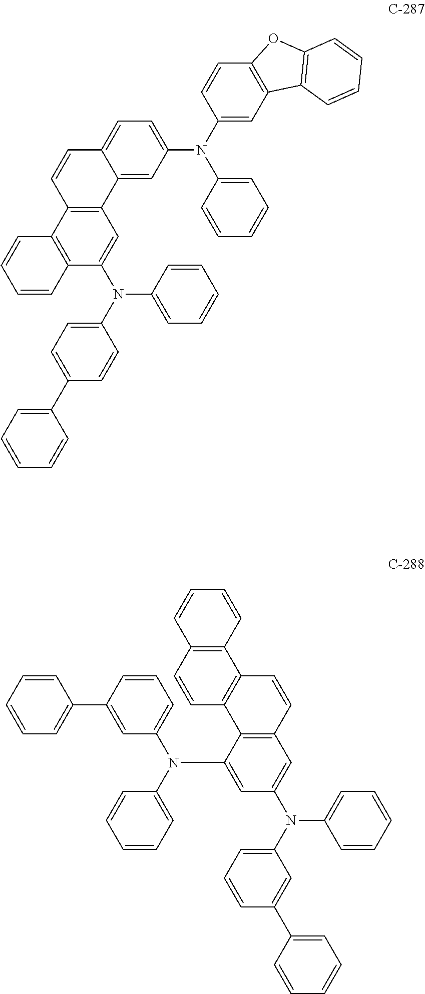 [SMILES: c1ccc(-c2ccc(N(c3ccccc3)c3cc4c5cc(N(c6ccccc6)c6ccc7oc8ccccc8c7c6)ccc5ccc4c4ccccc34)cc2)cc1 ; c1ccc(-c2cccc(N(c3ccccc3)c3cc(N(c4ccccc4)c4cccc(-c5ccccc5)c4)c4c(ccc5c6ccccc6ccc54)c3)c2)cc1]

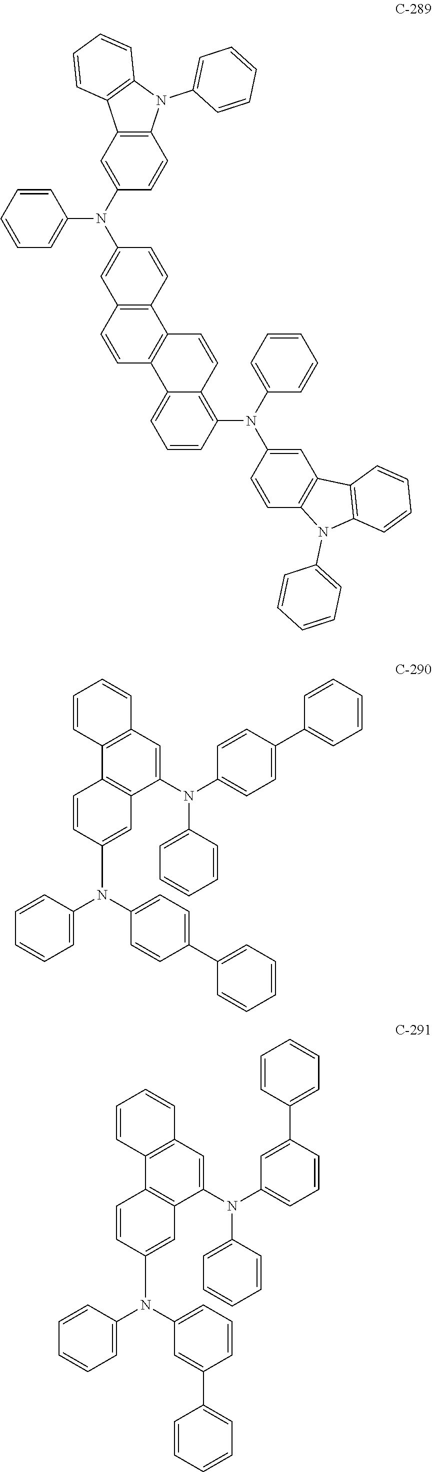 [SMILES: c1ccc(N(c2ccc3c(ccc4c5cccc(N(c6ccccc6)c6ccc7c(c6)c6ccccc6n7-c6ccccc6)c5ccc34)c2)c2ccc3c(c2)c2ccccc2n3-c2ccccc2)cc1 ; c1ccc(-c2ccc(N(c3ccccc3)c3ccc4c(c3)c(N(c3ccccc3)c3ccc(-c5ccccc5)cc3)cc3ccccc34)cc2)cc1 ; c1ccc(-c2cccc(N(c3ccccc3)c3ccc4c(c3)c(N(c3ccccc3)c3cccc(-c5ccccc5)c3)cc3ccccc34)c2)cc1]

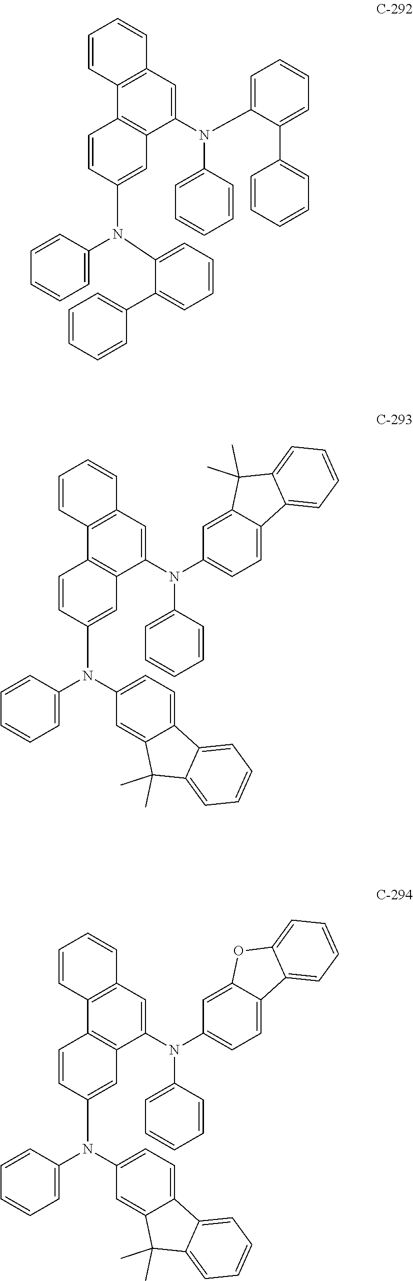 [SMILES: c1ccc(-c2ccccc2N(c2ccccc2)c2ccc3c(c2)c(N(c2ccccc2)c2ccccc2-c2ccccc2)cc2ccccc23)cc1 ; CC1(C)c2ccccc2-c2ccc(N(c3ccccc3)c3ccc4c(c3)c(N(c3ccccc3)c3ccc5c(c3)C(C)(C)c3ccccc3-5)cc3ccccc34)cc21 ; CC1(C)c2ccccc2-c2ccc(N(c3ccccc3)c3ccc4c(c3)c(N(c3ccccc3)c3ccc5c(c3)oc3ccccc35)cc3ccccc34)cc21]

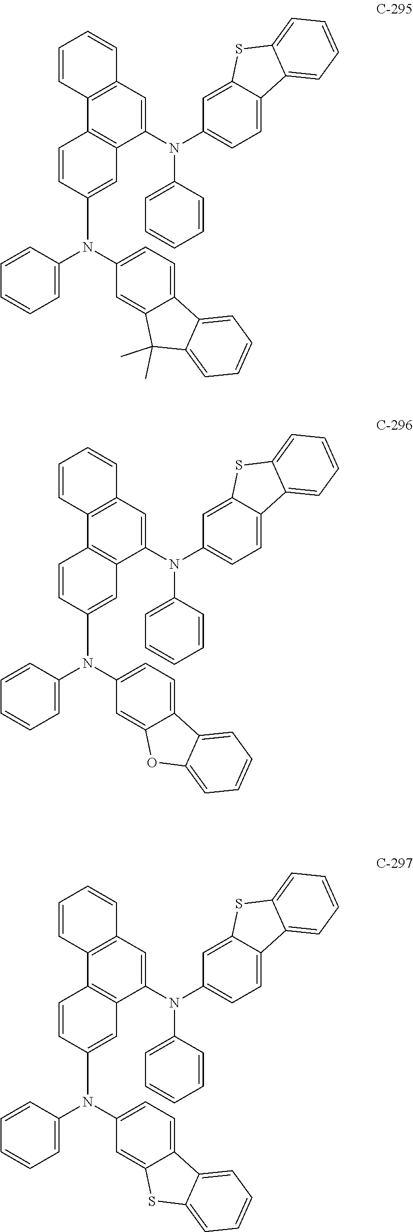 [SMILES: CC1(C)c2ccccc2-c2ccc(N(c3ccccc3)c3ccc4c(c3)c(N(c3ccccc3)c3ccc5c(c3)sc3ccccc35)cc3ccccc34)cc21 ; c1ccc(N(c2ccc3c(c2)oc2ccccc23)c2ccc3c(c2)c(N(c2ccccc2)c2ccc4c(c2)sc2ccccc24)cc2ccccc23)cc1 ; c1ccc(N(c2ccc3c(c2)sc2ccccc23)c2ccc3c(c2)c(N(c2ccccc2)c2ccc4c(c2)sc2ccccc24)cc2ccccc23)cc1]

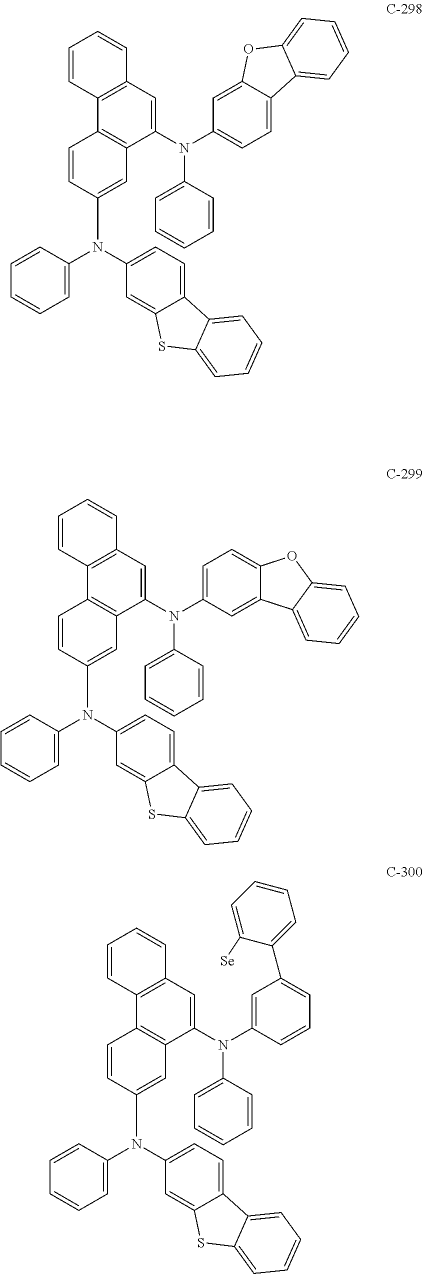

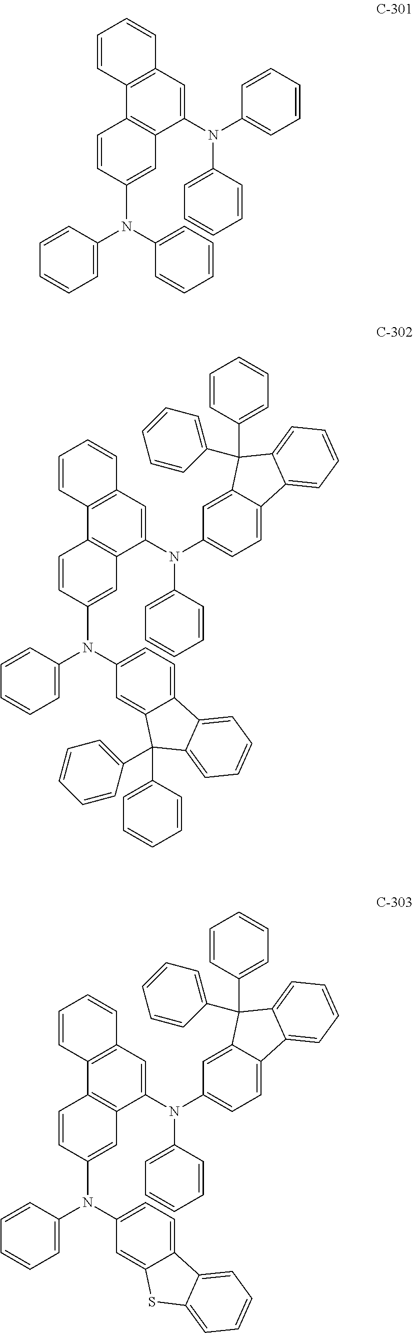 [SMILES: c1ccc(N(c2ccccc2)c2ccc3c(c2)c(N(c2ccccc2)c2ccccc2)cc2ccccc23)cc1 ; c1ccc(N(c2ccc3c(c2)C(c2ccccc2)(c2ccccc2)c2ccccc2-3)c2ccc3c(c2)c(N(c2ccccc2)c2ccc4c(c2)C(c2ccccc2)(c2ccccc2)c2ccccc2-4)cc2ccccc23)cc1 ; c1ccc(N(c2ccc3c(c2)sc2ccccc23)c2ccc3c(c2)c(N(c2ccccc2)c2ccc4c(c2)C(c2ccccc2)(c2ccccc2)c2ccccc2-4)cc2ccccc23)cc1]

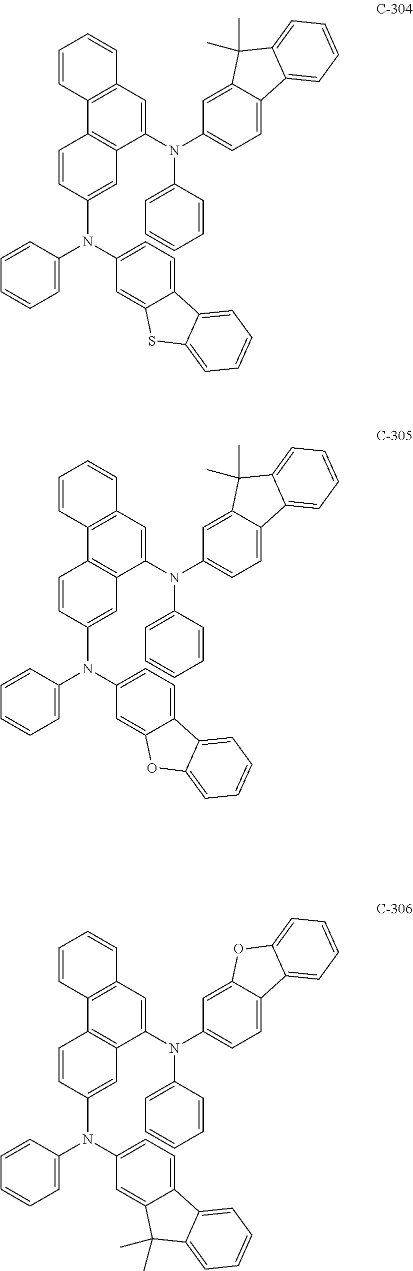 [SMILES: CC1(C)c2ccccc2-c2ccc(N(c3ccccc3)c3cc4ccccc4c4ccc(N(c5ccccc5)c5ccc6c(c5)sc5ccccc56)cc34)cc21 ; CC1(C)c2ccccc2-c2ccc(N(c3ccccc3)c3cc4ccccc4c4ccc(N(c5ccccc5)c5ccc6c(c5)oc5ccccc56)cc34)cc21 ; CC1(C)c2ccccc2-c2ccc(N(c3ccccc3)c3ccc4c(c3)c(N(c3ccccc3)c3ccc5c(c3)oc3ccccc35)cc3ccccc34)cc21]

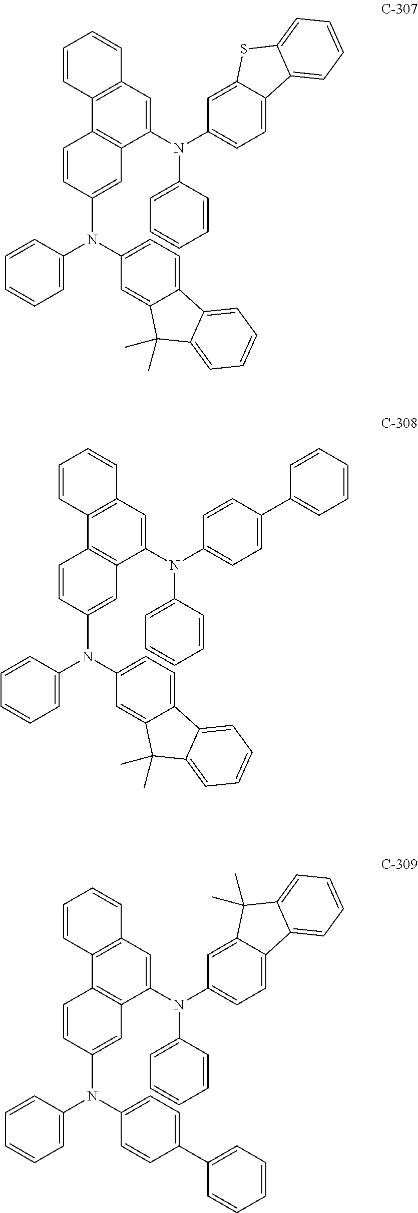 [SMILES: CC1(C)c2ccccc2-c2ccc(N(c3ccccc3)c3ccc4c(c3)c(N(c3ccccc3)c3ccc5c(c3)sc3ccccc35)cc3ccccc34)cc21 ; CC1(C)c2ccccc2-c2ccc(N(c3ccccc3)c3ccc4c(c3)c(N(c3ccccc3)c3ccc(-c5ccccc5)cc3)cc3ccccc34)cc21 ; CC1(C)c2ccccc2-c2ccc(N(c3ccccc3)c3cc4ccccc4c4ccc(N(c5ccccc5)c5ccc(-c6ccccc6)cc5)cc34)cc21]

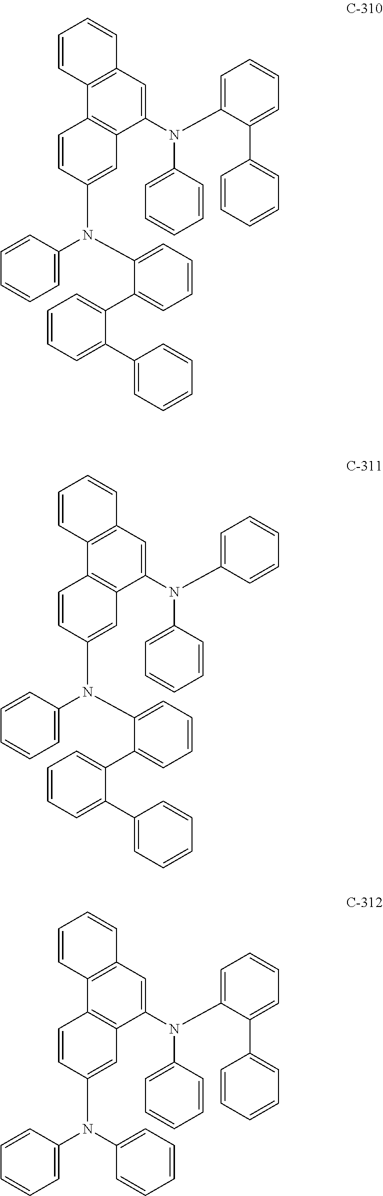 [SMILES: c1ccc(-c2ccccc2-c2ccccc2N(c2ccccc2)c2ccc3c(c2)c(N(c2ccccc2)c2ccccc2-c2ccccc2)cc2ccccc23)cc1 ; c1ccc(-c2ccccc2-c2ccccc2N(c2ccccc2)c2ccc3c(c2)c(N(c2ccccc2)c2ccccc2)cc2ccccc23)cc1 ; c1ccc(-c2ccccc2N(c2ccccc2)c2cc3ccccc3c3ccc(N(c4ccccc4)c4ccccc4)cc23)cc1]

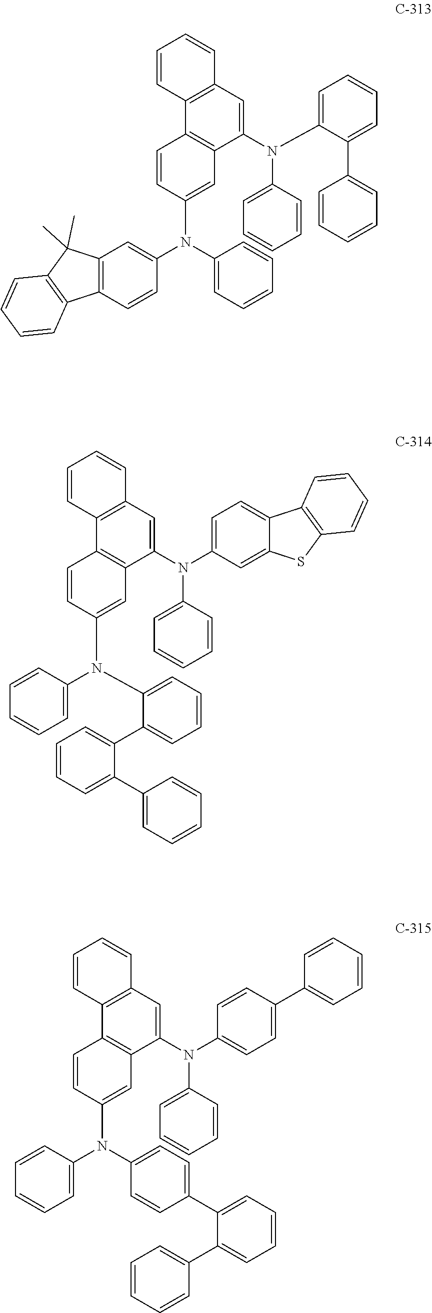 [SMILES: CC1(C)c2ccccc2-c2ccc(N(c3ccccc3)c3ccc4c(c3)c(N(c3ccccc3)c3ccccc3-c3ccccc3)cc3ccccc34)cc21 ; c1ccc(-c2ccccc2-c2ccccc2N(c2ccccc2)c2ccc3c(c2)c(N(c2ccccc2)c2ccc4c(c2)sc2ccccc24)cc2ccccc23)cc1 ; c1ccc(-c2ccc(N(c3ccccc3)c3cc4ccccc4c4ccc(N(c5ccccc5)c5ccc(-c6ccccc6-c6ccccc6)cc5)cc34)cc2)cc1]

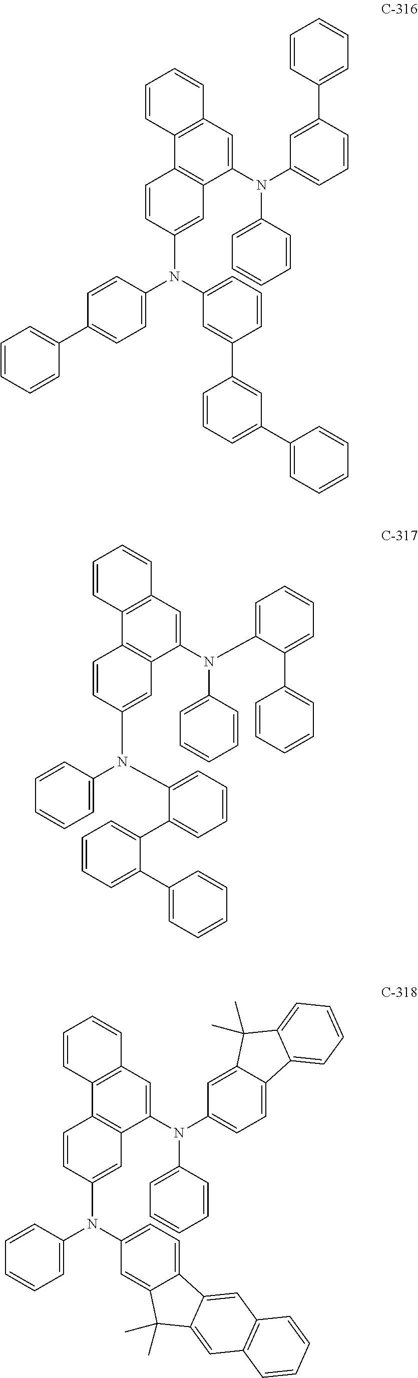 [SMILES: c1ccc(-c2ccc(N(c3cccc(-c4cccc(-c5ccccc5)c4)c3)c3ccc4c(c3)c(N(c3ccccc3)c3cccc(-c5ccccc5)c3)cc3ccccc34)cc2)cc1 ; c1ccc(-c2ccccc2-c2ccccc2N(c2ccccc2)c2ccc3c(c2)c(N(c2ccccc2)c2ccccc2-c2ccccc2)cc2ccccc23)cc1 ; CC1(C)c2ccccc2-c2ccc(N(c3ccccc3)c3cc4ccccc4c4ccc(N(c5ccccc5)c5ccc6c(c5)C(C)(C)c5cc7ccccc7cc5-6)cc34)cc21]

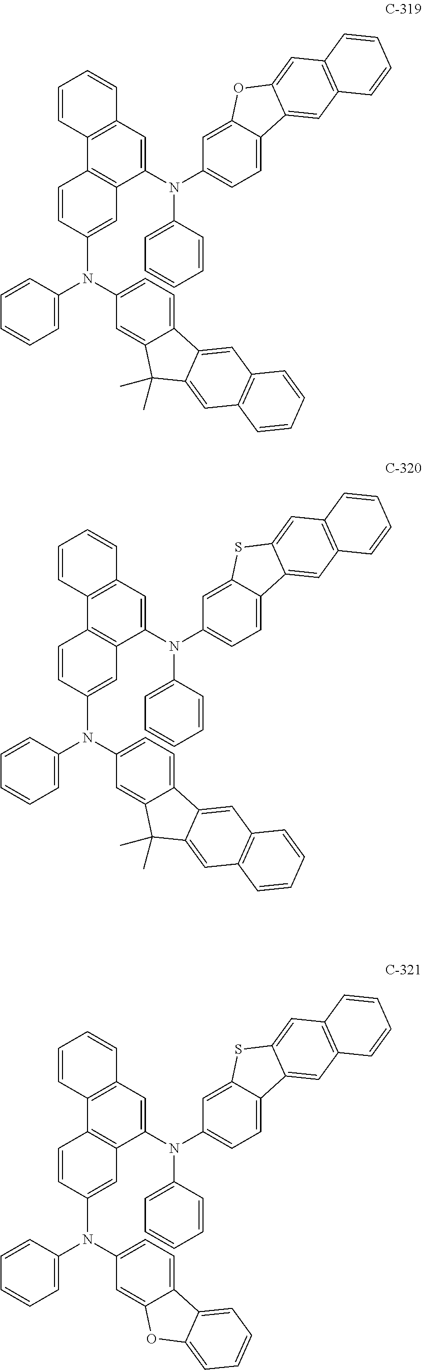 [SMILES: CC1(C)c2cc(N(c3ccccc3)c3ccc4c(c3)c(N(c3ccccc3)c3ccc5c(c3)oc3cc6ccccc6cc35)cc3ccccc34)ccc2-c2cc3ccccc3cc21 ; CC1(C)c2cc(N(c3ccccc3)c3ccc4c(c3)c(N(c3ccccc3)c3ccc5c(c3)sc3cc6ccccc6cc35)cc3ccccc34)ccc2-c2cc3ccccc3cc21 ; c1ccc(N(c2ccc3c(c2)oc2ccccc23)c2ccc3c(c2)c(N(c2ccccc2)c2ccc4c(c2)sc2cc5ccccc5cc24)cc2ccccc23)cc1]

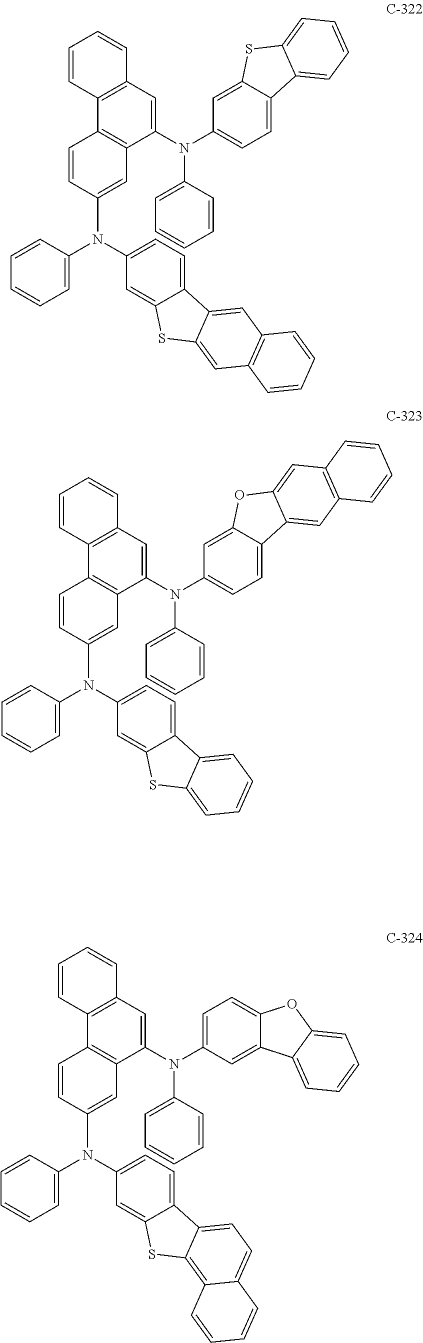 [SMILES: c1ccc(N(c2ccc3c(c2)sc2cc4ccccc4cc23)c2ccc3c(c2)c(N(c2ccccc2)c2ccc4c(c2)sc2ccccc24)cc2ccccc23)cc1 ; c1ccc(N(c2ccc3c(c2)sc2ccccc23)c2ccc3c(c2)c(N(c2ccccc2)c2ccc4c(c2)oc2cc5ccccc5cc24)cc2ccccc23)cc1 ; c1ccc(N(c2ccc3c(c2)sc2c4ccccc4ccc32)c2ccc3c(c2)c(N(c2ccccc2)c2ccc4oc5ccccc5c4c2)cc2ccccc23)cc1]

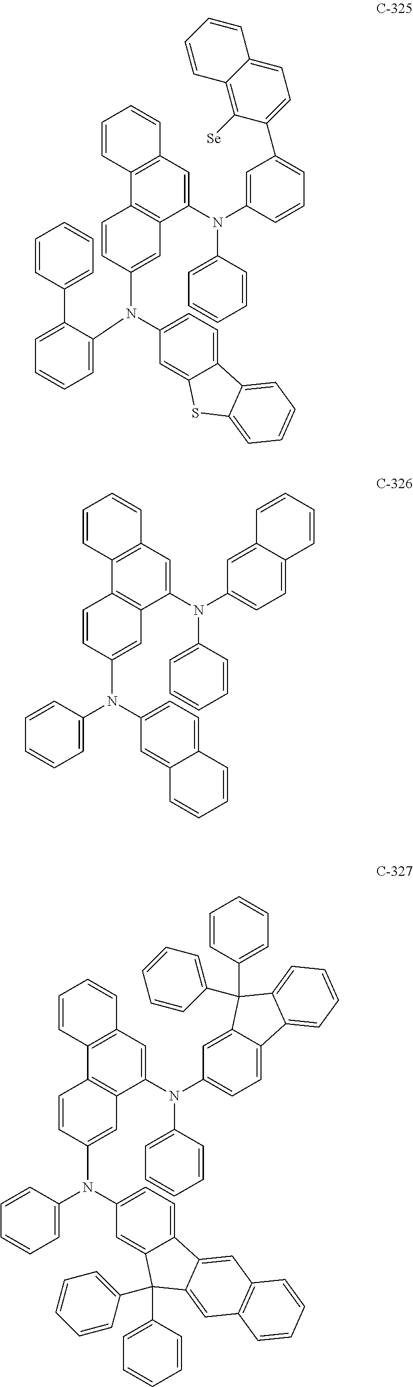

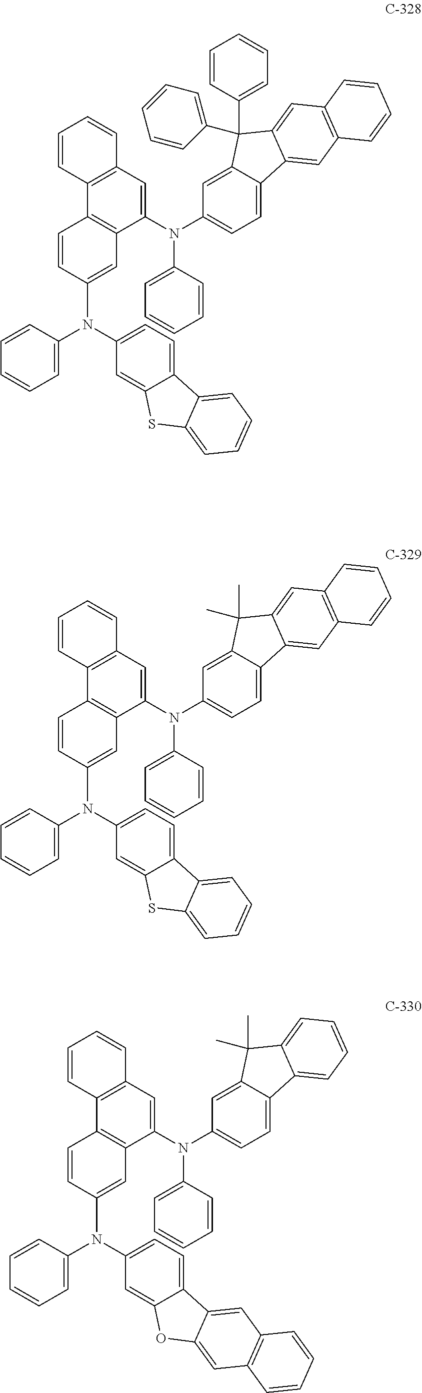 [SMILES: c1ccc(N(c2ccc3c(c2)sc2ccccc23)c2ccc3c(c2)c(N(c2ccccc2)c2ccc4c(c2)C(c2ccccc2)(c2ccccc2)c2cc5ccccc5cc2-4)cc2ccccc23)cc1 ; CC1(C)c2cc(N(c3ccccc3)c3cc4ccccc4c4ccc(N(c5ccccc5)c5ccc6c(c5)sc5ccccc56)cc34)ccc2-c2cc3ccccc3cc21 ; CC1(C)c2ccccc2-c2ccc(N(c3ccccc3)c3cc4ccccc4c4ccc(N(c5ccccc5)c5ccc6c(c5)oc5cc7ccccc7cc56)cc34)cc21]

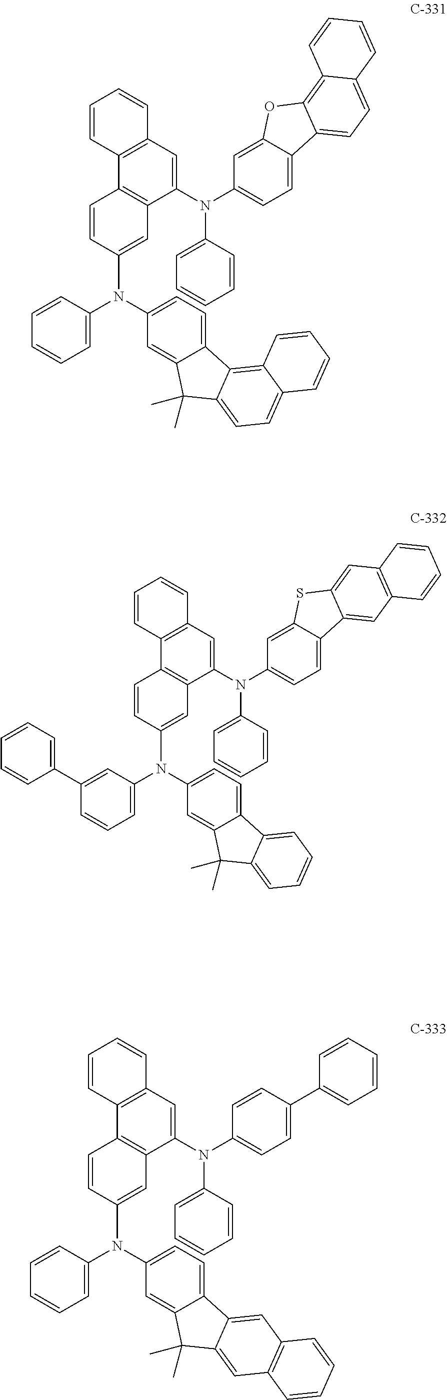 [SMILES: CC1(C)c2cc(N(c3ccccc3)c3ccc4c(c3)c(N(c3ccccc3)c3ccc5c(c3)oc3c6ccccc6ccc53)cc3ccccc34)ccc2-c2c1ccc1ccccc21 ; CC1(C)c2ccccc2-c2ccc(N(c3cccc(-c4ccccc4)c3)c3ccc4c(c3)c(N(c3ccccc3)c3ccc5c(c3)sc3cc6ccccc6cc35)cc3ccccc34)cc21 ; CC1(C)c2cc(N(c3ccccc3)c3ccc4c(c3)c(N(c3ccccc3)c3ccc(-c5ccccc5)cc3)cc3ccccc34)ccc2-c2cc3ccccc3cc21]

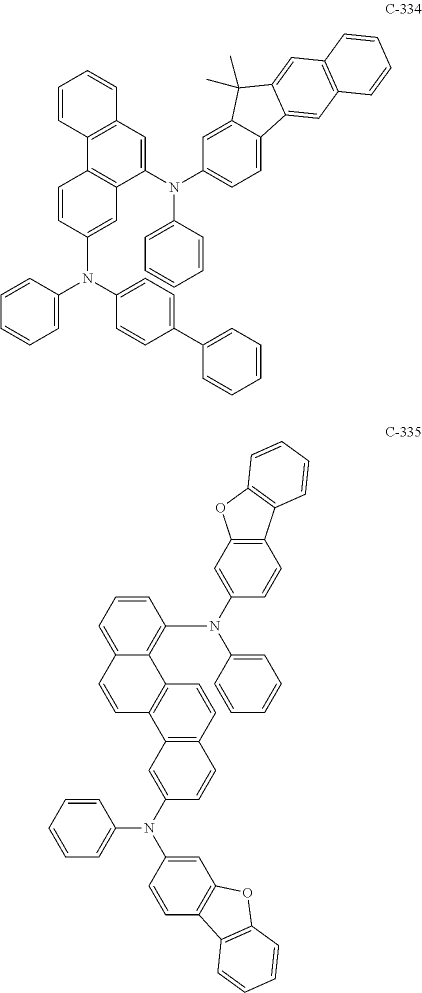 [SMILES: CC1(C)c2cc(N(c3ccccc3)c3cc4ccccc4c4ccc(N(c5ccccc5)c5ccc(-c6ccccc6)cc5)cc34)ccc2-c2cc3ccccc3cc21 ; c1ccc(N(c2ccc3c(c2)oc2ccccc23)c2ccc3ccc4c(ccc5cccc(N(c6ccccc6)c6ccc7c(c6)oc6ccccc67)c54)c3c2)cc1]

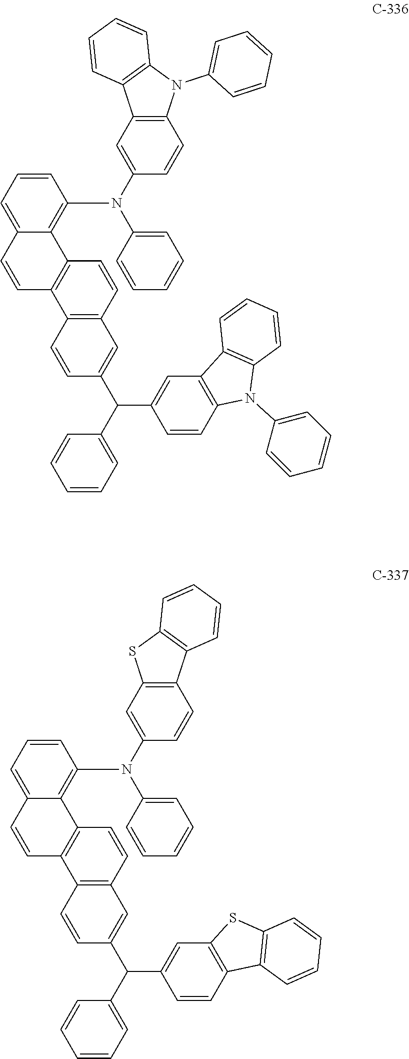 [SMILES: c1ccc(C(c2ccc3c(ccc4c3ccc3cccc(N(c5ccccc5)c5ccc6c(c5)c5ccccc5n6-c5ccccc5)c34)c2)c2ccc3c(c2)c2ccccc2n3-c2ccccc2)cc1 ; c1ccc(C(c2ccc3c(ccc4c3ccc3cccc(N(c5ccccc5)c5ccc6c(c5)sc5ccccc56)c34)c2)c2ccc3c(c2)sc2ccccc23)cc1]

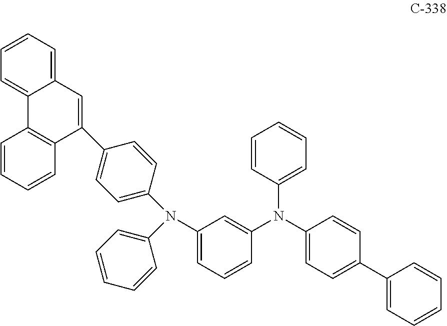 [SMILES: c1ccc(-c2ccc(N(c3ccccc3)c3cccc(N(c4ccccc4)c4ccc(-c5cc6ccccc6c6ccccc56)cc4)c3)cc2)cc1]

Hereinafter, an organic electroluminescent device to which the aforementioned plurality of host materials and/or organic electroluminescent compound is (are) applied, will be described.

The organic electroluminescent device according to one embodiment includes a first electrode; a second electrode; and at least one organic layer(s) interposed between the first electrode and the second electrode. The organic layer may include a light-emitting layer, and the light-emitting layer may comprise a plurality of host materials comprising at least one first host compound represented by formula 1 and at least one second host compound represented by formula 2. Wherein, the weight ratio of the first host compound to the second host compound may be in the range of about 1:99 to about 99:1, preferably about 10:90 to about 90:10, more preferably about 30:70 to about 70:30, more preferably about 40:60 to about 60:40, even more preferably about 50:50 in the light-emitting layer.

According to another embodiment, the light-emitting layer may further comprise at least one third host compound. Specifically, the light-emitting layer may comprise may further comprise at least one third host compound which is represented by the formula 1 or 2, but is different from the first host compound and the second host compound. Wherein, the mixing ratio of the first host compound, the second host compound, and the third host compound is not particularly limited, for example, the weight ratio of the first host compound, the second host compound, and the third host compound may be in the range of about 5˜45: about 10˜90: about 5˜45, preferably about 10˜40: about 20˜80: about 10˜40.

According to another embodiment, the light-emitting layer may comprise an organic electroluminescent compound represented by the formula 1′.

According to one embodiment, the organic electroluminescent material of the present disclosure may further comprise at least one compound(s) of compounds H1-1 to H1-65 and C-1 to C-338, which is a first host compound, at least one compound(s) of compounds H2-1 to H2-736, which is a second host compound, and at least one compound(s) of compounds H1-1 to H1-65, C-1 to C-338, and H2-1 to H2-736, which is a second host compound. The plurality of host materials may be included in the same organic layer, for example a light-emitting layer, or may be included in different light-emitting layers, respectively.

According to one embodiment, the light-emitting layer of the present disclosure may comprise at least one of compounds C-1 to C-337 which is represented by formula 1′ as a host material.

The organic layer may further comprise at least one layer selected from a hole injection layer, a hole transport layer, a hole auxiliary layer, a light-emitting auxiliary layer, an electron transport layer, an electron injection layer, an interlayer, a hole blocking layer, an electron blocking layer, and an electron buffer layer in addition to the light-emitting layer. The organic layer may further comprise an amine-based compound and/or an azine-based compound other than the light-emitting material according to the present disclosure. Specifically, the hole injection layer, the hole transport layer, the hole auxiliary layer, the light-emitting layer, the light-emitting auxiliary layer, or the electron blocking layer may contain the amine-based compound, e.g., an arylamine-based compound and a styrylarylamine-based compound, etc., as a hole injection material, a hole transport material, a hole auxiliary material, a light-emitting material, a light-emitting auxiliary material, or an electron blocking material. Also, the electron transport layer, the electron injection layer, the electron buffer layer, or the hole blocking layer may contain the azine-based compound as an electron transport material, an electron injection material, an electron buffer material, or a hole blocking material. Further, the organic layer may further comprise at least one metal selected from the group consisting of metals of Group 1, metals of Group 2, transition metals of the 4^{th} period, transition metals of the 5^{th} period, lanthanides, and organic metals of the d-transition elements of the Periodic Table, or at least one complex compound comprising such a metal.

The plurality of host materials according to one embodiment may be used as light-emitting materials for a white organic light-emitting device. The white organic light-emitting device has suggested various structures such as a parallel side-by-side arrangement method, a stacking arrangement method, or CCM (color conversion material) method, etc., according to the arrangement of R (Red), G (Green), YG (yellowish green), or B (blue) light-emitting units. In addition, the plurality of host materials according to one embodiment may also be applied to the organic electroluminescent device comprising a QD (quantum dot).

One of the first electrode and the second electrode may be an anode and the other may be a cathode. Wherein, the first electrode and the second electrode may each be formed as a transmissive conductive material, a transflective conductive material, or a reflective conductive material. The organic electroluminescent device may be a top emission type, a bottom emission type, or a both-sides emission type according to the kinds of the material forming the first electrode and the second electrode.

A hole injection layer, a hole transport layer, an electron blocking layer, or a combination thereof can be used between the anode and the light-emitting layer. The hole injection layer may be multi-layers in order to lower the hole injection barrier (or hole injection voltage) from the anode to the hole transport layer or the electron blocking layer, wherein each of the multi-layers may use two compounds simultaneously. Also, the hole injection layer may be doped as a p-dopant. Also, the electron blocking layer may be placed between the hole transport layer (or hole injection layer) and the light-emitting layer, and can confine the excitons within the light-emitting layer by blocking the overflow of electrons from the light-emitting layer to prevent a light-emitting leakage. The hole transport layer or the electron blocking layer may be multi-layers, and wherein each layer may use a plurality of compounds.

An electron buffer layer, a hole blocking layer, an electron transport layer, an electron injection layer, or a combination thereof can be used between the light-emitting layer and the cathode. The electron buffer layer may be multi-layers in order to control the injection of the electron and improve the interfacial properties between the light-emitting layer and the electron injection layer, wherein each of the multi-layers may use two compounds simultaneously. The hole blocking layer may be placed between the electron transport layer (or electron injection layer) and the light-emitting layer, and blocks the arrival of holes to the cathode, thereby improving the probability of recombination of electrons and holes in the light-emitting layer. The hole blocking layer or the electron transport layer may also be multi-layers, wherein each layer may use a plurality of compounds. Also, the electron injection layer may be doped as an n-dopant.

The light-emitting auxiliary layer may be placed between the anode and the light-emitting layer, or between the cathode and the light-emitting layer. When the light-emitting auxiliary layer is placed between the anode and the light-emitting layer, it can be used for promoting the hole injection and/or the hole transport, or for preventing the overflow of electrons. When the light-emitting auxiliary layer is placed between the cathode and the light-emitting layer, it can be used for promoting the electron injection and/or the electron transport, or for preventing the overflow of holes. In addition, the hole auxiliary layer may be placed between the hole transport layer (or hole injection layer) and the light-emitting layer, and may be effective to promote or block the hole transport rate (or the hole injection rate), thereby enabling the charge balance to be controlled. When an organic electroluminescent device includes two or more hole transport layers, the hole transport layer, which is further included, may be used as the hole auxiliary layer or the electron blocking layer. The light-emitting auxiliary layer, the hole auxiliary layer, or the electron blocking layer may have an effect of improving the efficiency and/or the lifespan of the organic electroluminescent device.

In the organic electroluminescent device of the present disclosure, preferably, at least one layer (hereinafter, “a surface layer”) selected from a chalcogenide layer, a halogenated metal layer, and a metal oxide layer may be placed on an inner surface(s) of one or both of a pair of electrodes. Specifically, a chalcogenide (including oxides) layer of silicon and aluminum is preferably placed on an anode surface of an electroluminescent medium layer, and a halogenated metal layer or a metal oxide layer is preferably placed on a cathode surface of an electroluminescent medium layer. The operation stability for the organic electroluminescent device may be obtained by the surface layer. Preferably, the chalcogenide includes SiOₓ(1≤X≤2), AlOₓ(1≤X≤1.5), SiON, SiAlON, etc.; the halogenated metal includes LiF, MgF₂, CaF₂, a rare earth metal fluoride, etc.; and the metal oxide includes Cs₂O, Li₂O, MgO, SrO, BaO, CaO, etc.

In addition, in the organic electroluminescent device of the present disclosure, a mixed region of an electron transport compound and a reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Furthermore, the hole transport compound is oxidized to a cation, and thus it becomes easier to inject and transport holes from the mixed region to the electroluminescent medium. Preferably, the oxidative dopant includes various Lewis acids and acceptor compounds, and the reductive dopant includes alkali metals, alkali metal compounds, alkaline earth metals, rare-earth metals, and mixtures thereof. In addition, a reductive dopant layer may be employed as a charge generating layer to prepare an organic electroluminescent device having two or more light-emitting layers and emitting white light.

An organic electroluminescent device according to one embodiment may further comprise at least one dopant in the light-emitting layer.

The dopant comprised in the organic electroluminescent device of the present disclosure may be at least one phosphorescent or fluorescent dopant, preferably a phosphorescent dopant. The phosphorescent dopant material applied to the organic electroluminescent device of the present disclosure is not particularly limited, but may be preferably a metallated complex compound(s) of a metal atom(s) selected from iridium (Ir), osmium (Os), copper (Cu), and platinum (Pt), more preferably an ortho-metallated complex compound(s) of a metal atom(s) selected from iridium (Ir), osmium (Os), copper (Cu), and platinum (Pt), and even more preferably ortho-metallated iridium complex compound(s).

The dopant comprised in the organic electroluminescent device of the present disclosure may use the compound represented by the following formula 101, but is not limited thereto.

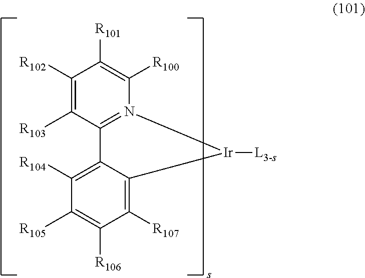

in formula 101,

L is selected from the following structures 1 to 3:

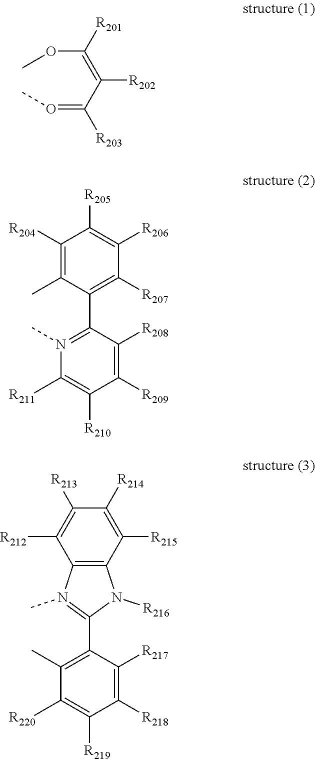

R₁₀₀ to R₁₀₃ each independently represent, hydrogen, deuterium, halogen, (C1-C30)alkyl unsubstituted or substituted with deuterium and/or halogen, a substituted or unsubstituted (C3-C30)cycloalkyl, a substituted or unsubstituted (C6-C30)aryl, cyano, a substituted or unsubstituted (3- to 30-membered)heteroaryl, or a substituted or unsubstituted (C1-C30)alkoxy; or may be linked to the adjacent substituents to form a ring(s), for example, to form a ring(s) with a pyridine, e.g., a substituted or unsubstituted quinoline, a substituted or unsubstituted benzofuropyridine, a substituted or unsubstituted benzothienopyridine, a substituted or unsubstituted indenopyridine, a substituted or unsubstituted benzofuroquinoline, a substituted or unsubstituted benzothienoquinoline, or a substituted or unsubstituted indenoquinoline;

R₁₀₄ to R₁₀₇ each independently represent, hydrogen, deuterium, halogen, (C1-C30)alkyl unsubstituted or substituted with deuterium and/or halogen, a substituted or unsubstituted (C3-C30)cycloalkyl, a substituted or unsubstituted (C6-C30)aryl, a substituted or unsubstituted (3- to 30-membered)heteroaryl, cyano, or a substituted or unsubstituted (C1-C30)alkoxy; or may be linked to an adjacent substituent(s) to form a substituted or unsubstituted ring(s), for example, to form a ring(s) with a benzene, e.g., a substituted or unsubstituted naphthalene, a substituted or unsubstituted fluorene, a substituted or unsubstituted dibenzothiophene, a substituted or unsubstituted dibenzofuran, a substituted or unsubstituted indenopyridine, a substituted or unsubstituted benzofuropyridine, or a substituted or unsubstituted benzothienopyridine;

R₂₀₁ to R₂₁₁ each independently represent, hydrogen, deuterium, halogen, (C1-C30)alkyl unsubstituted or substituted with deuterium and/or halogen, a substituted or unsubstituted (C3-C30)cycloalkyl, or a substituted or unsubstituted (C6-C30)aryl; or may be linked to an adjacent substituent(s) to form a substituted or unsubstituted ring(s); and

s represents an integer of 1 to 3.

Specifically, the specific examples of the dopant compound include the following, but are not limited thereto.

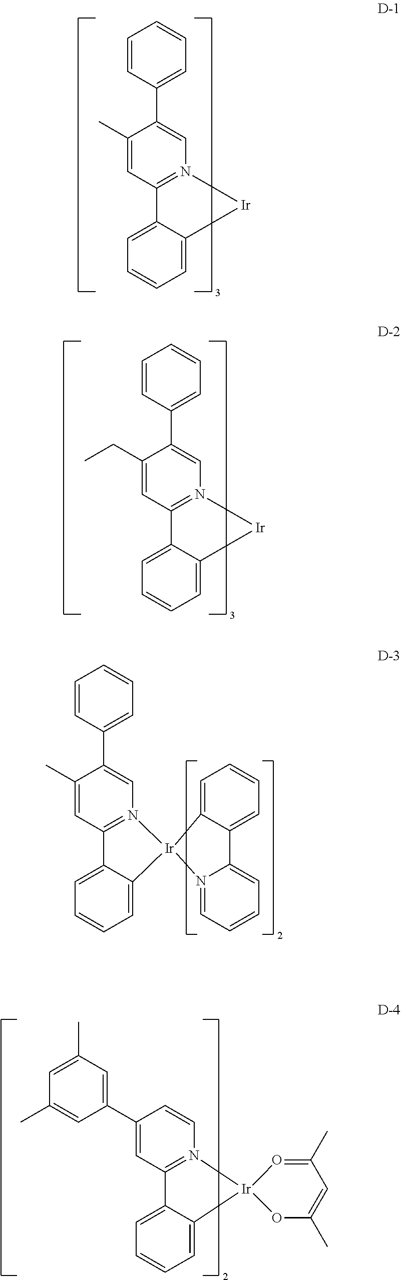

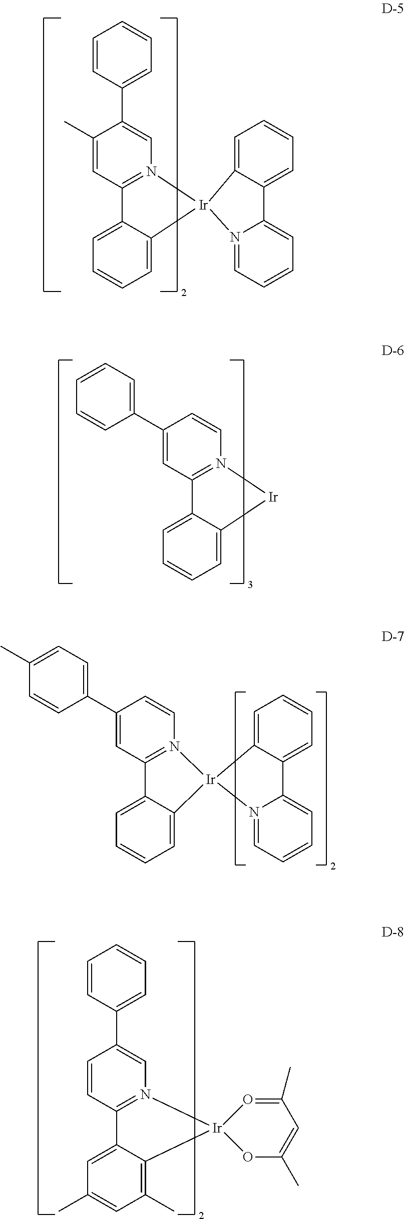

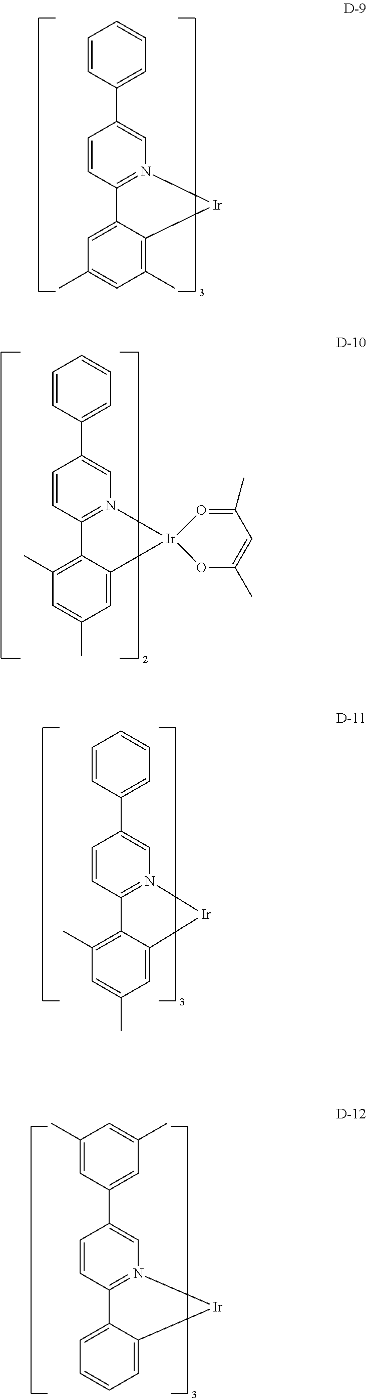

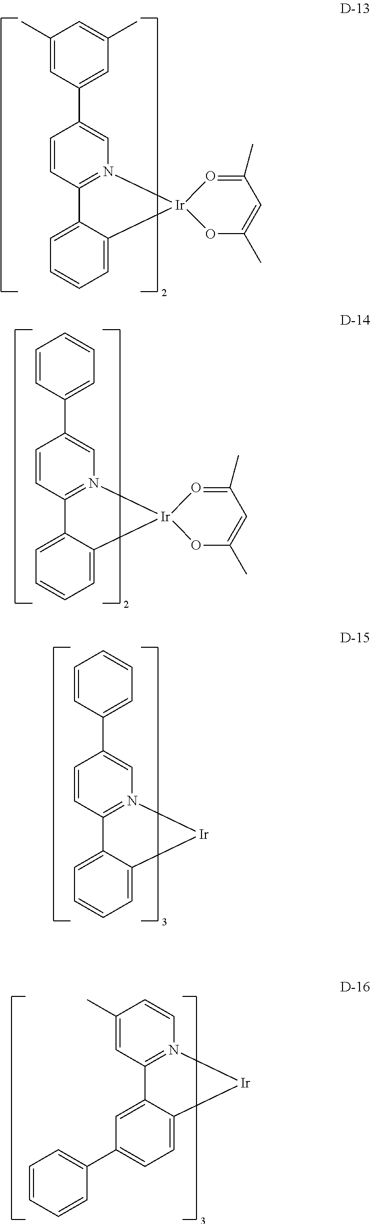

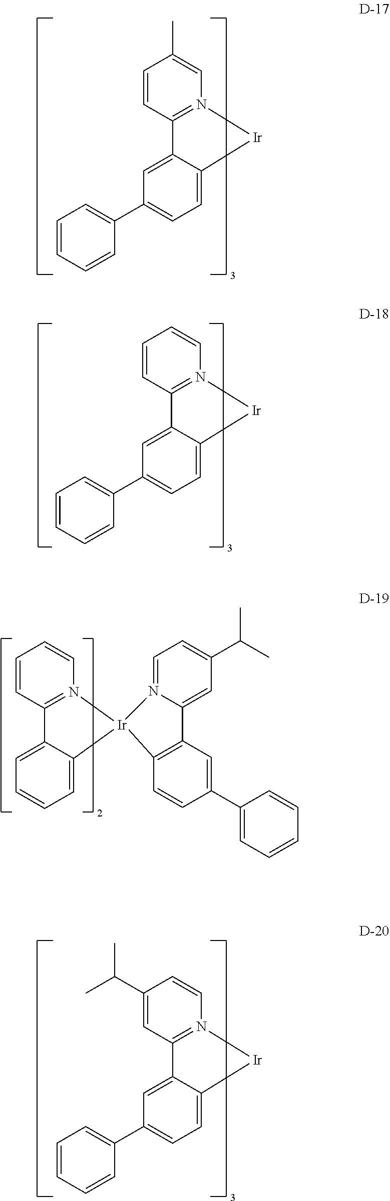

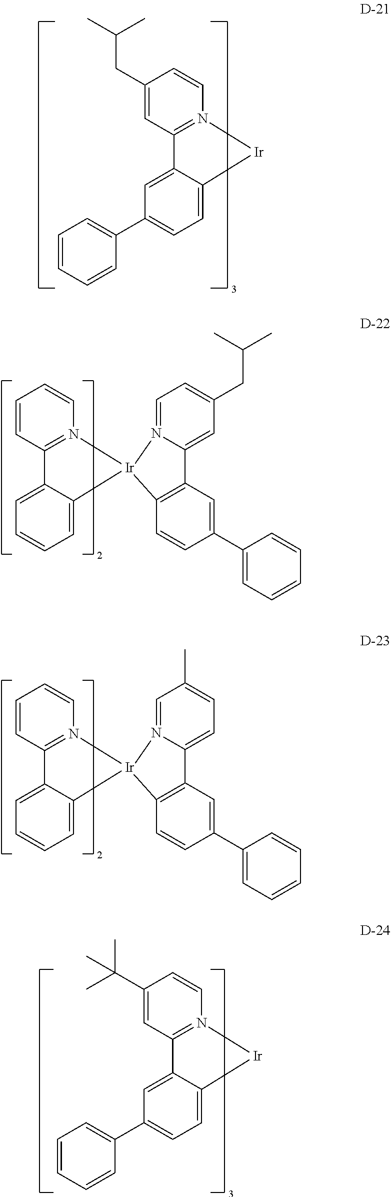

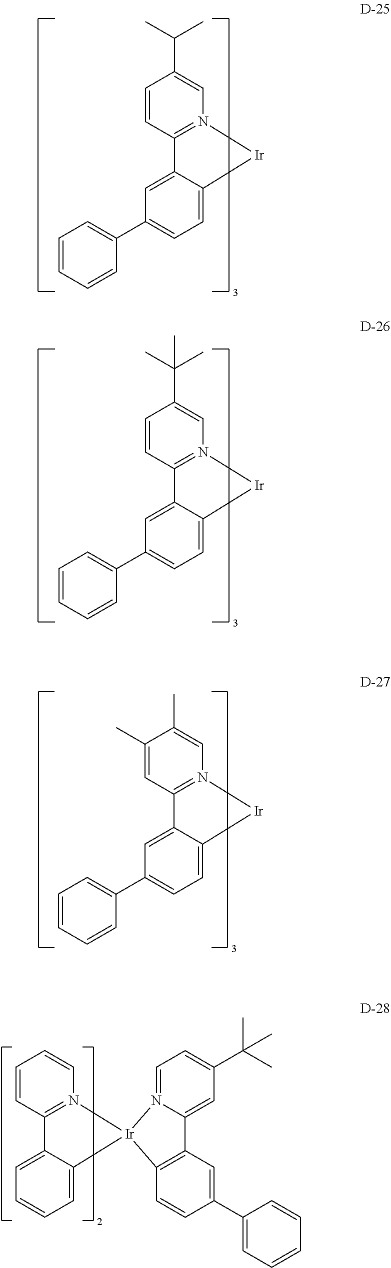

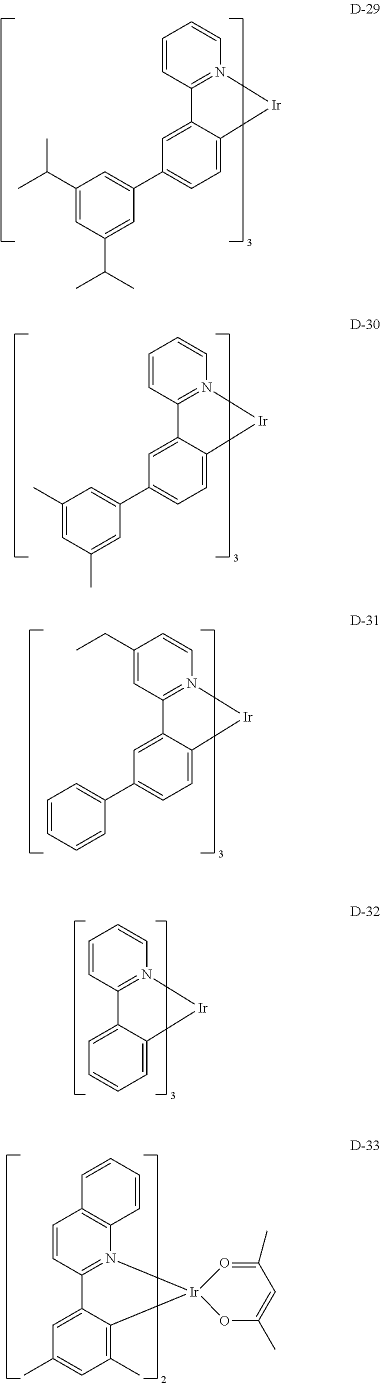

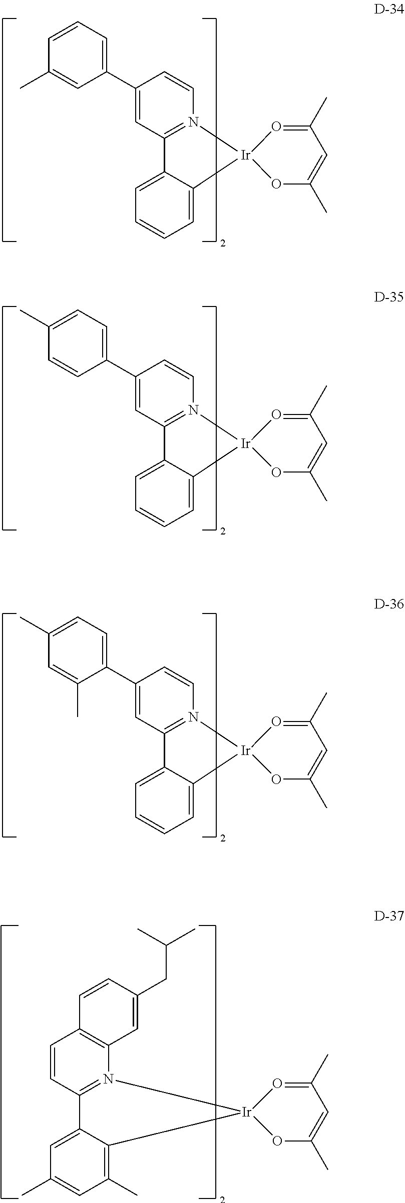

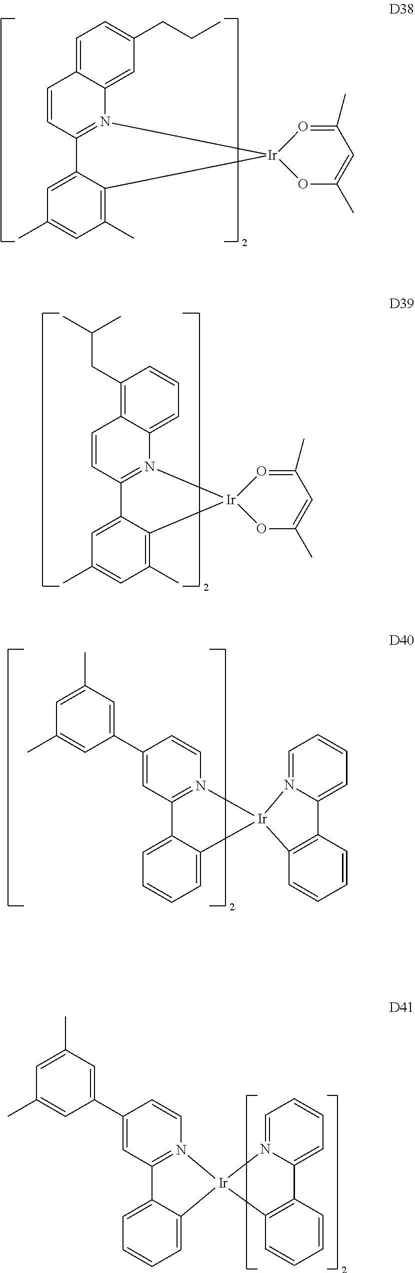

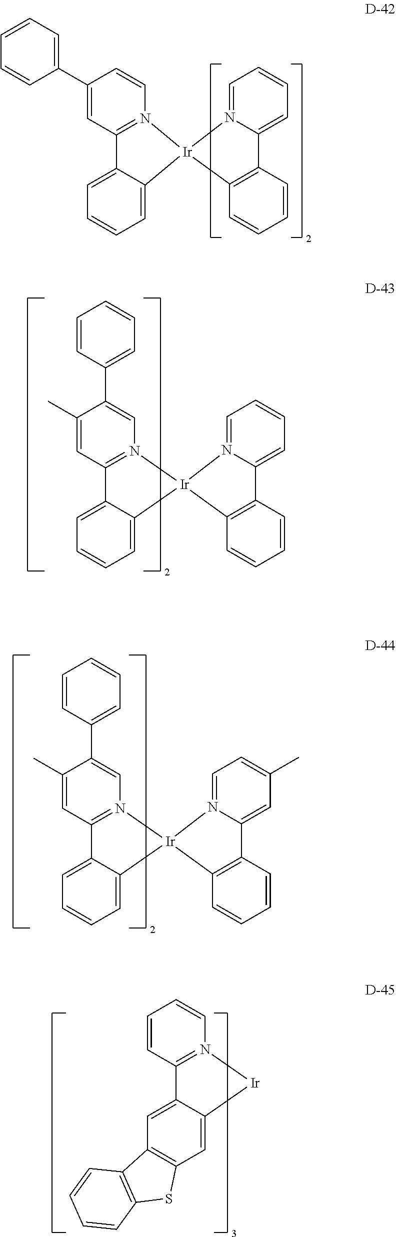

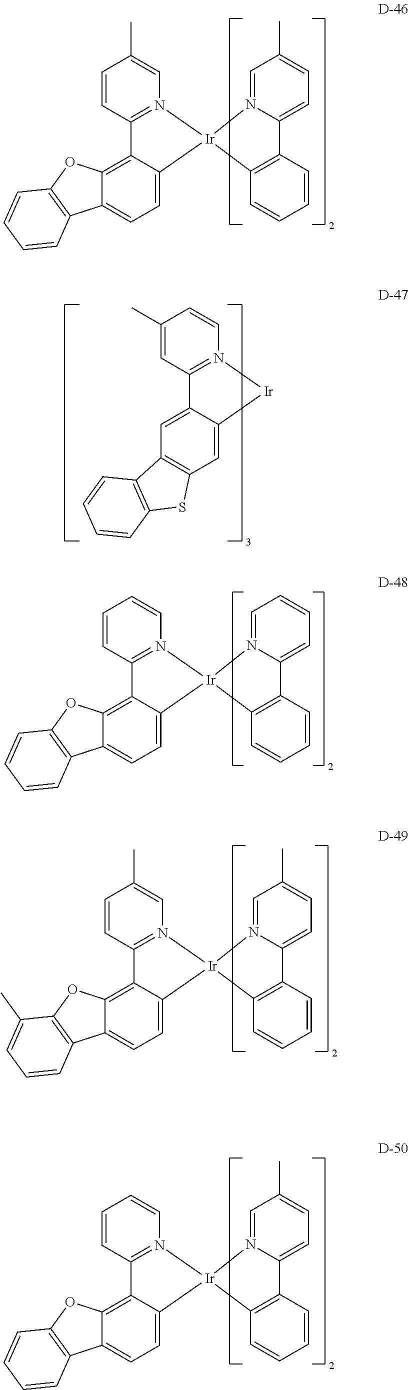

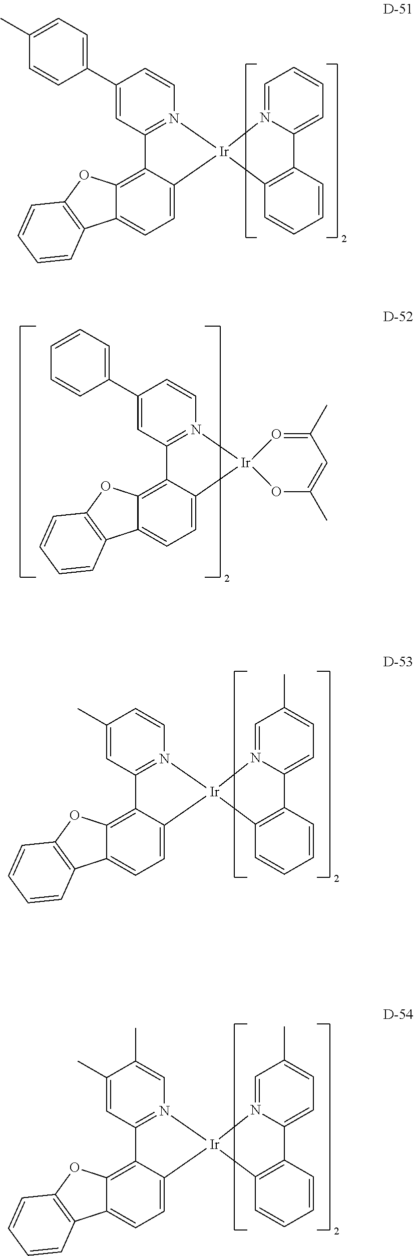

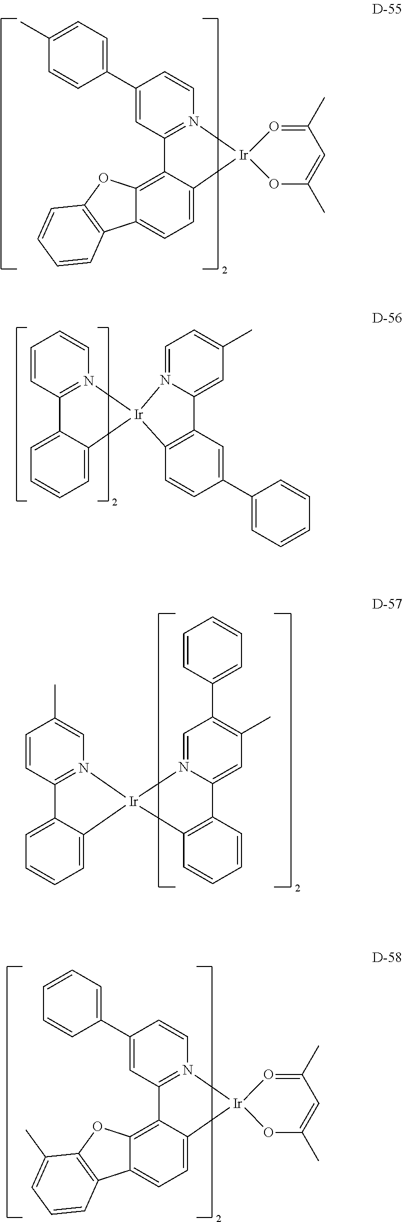

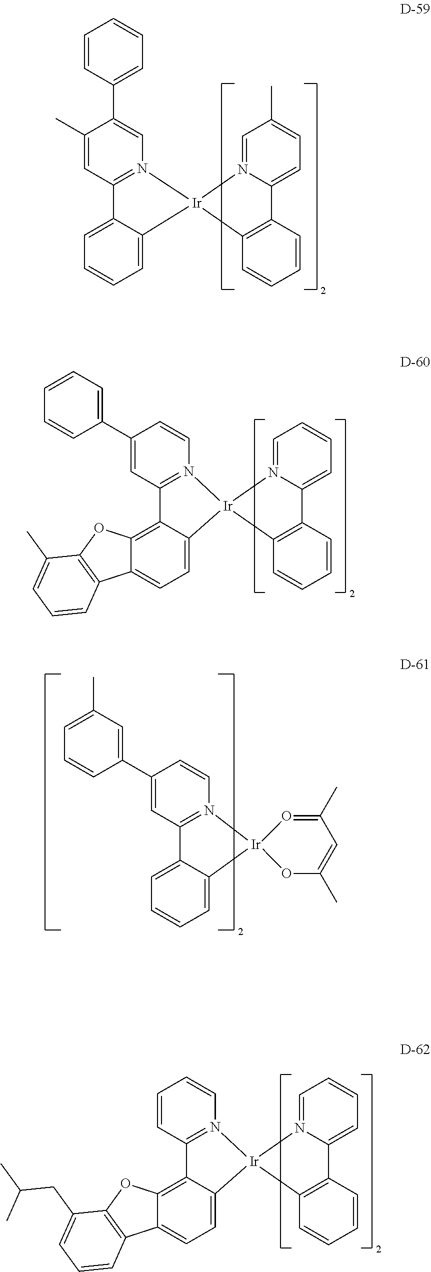

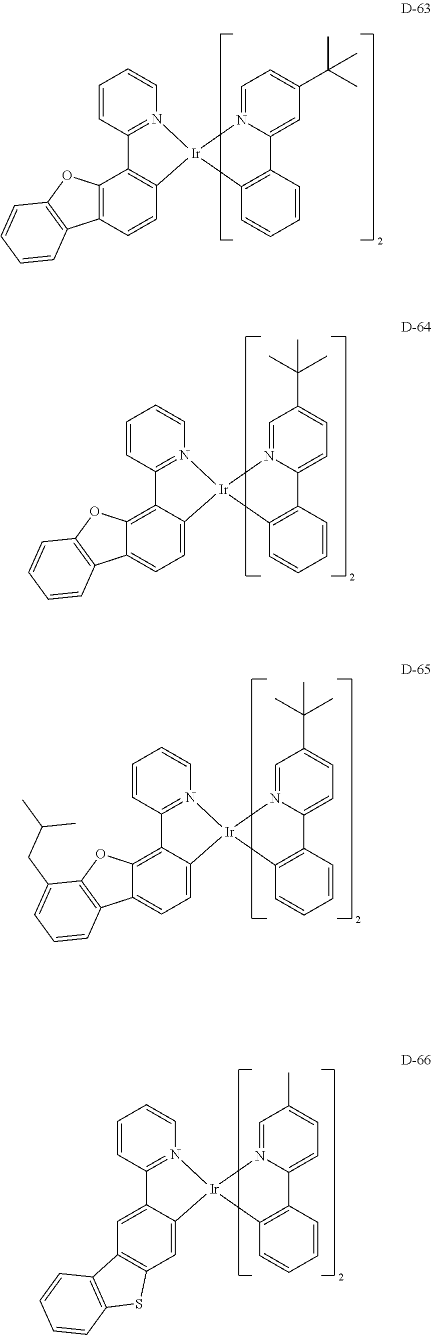

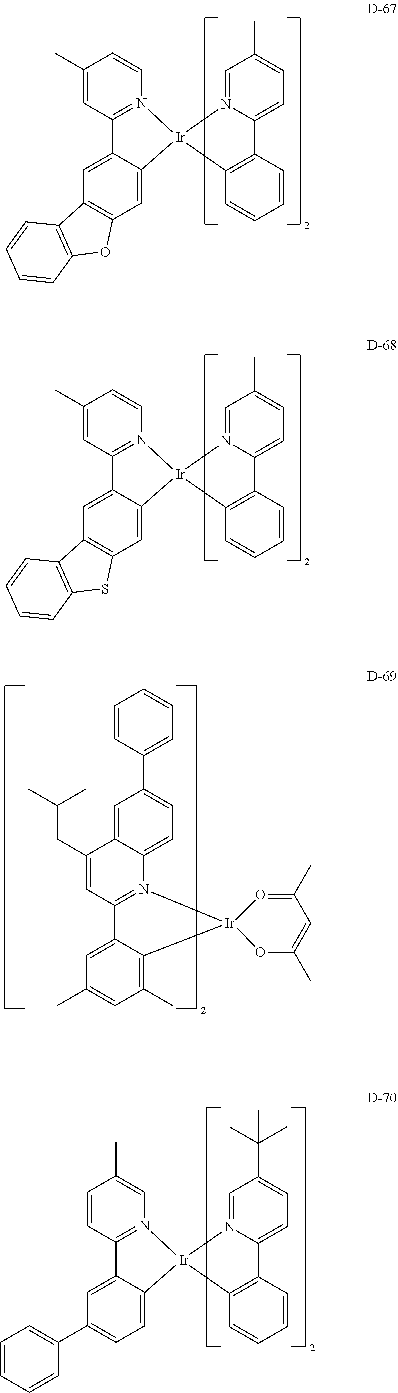

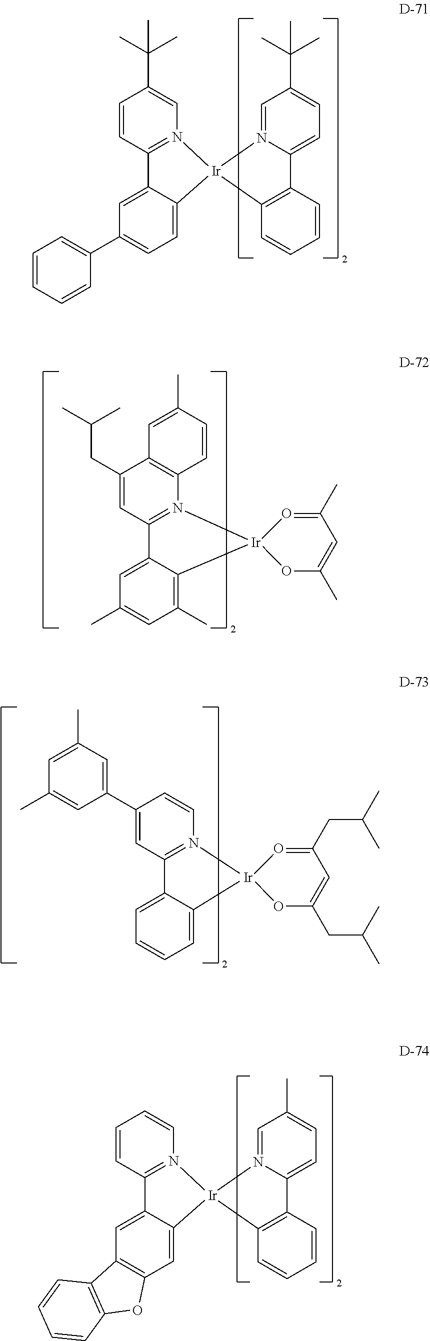

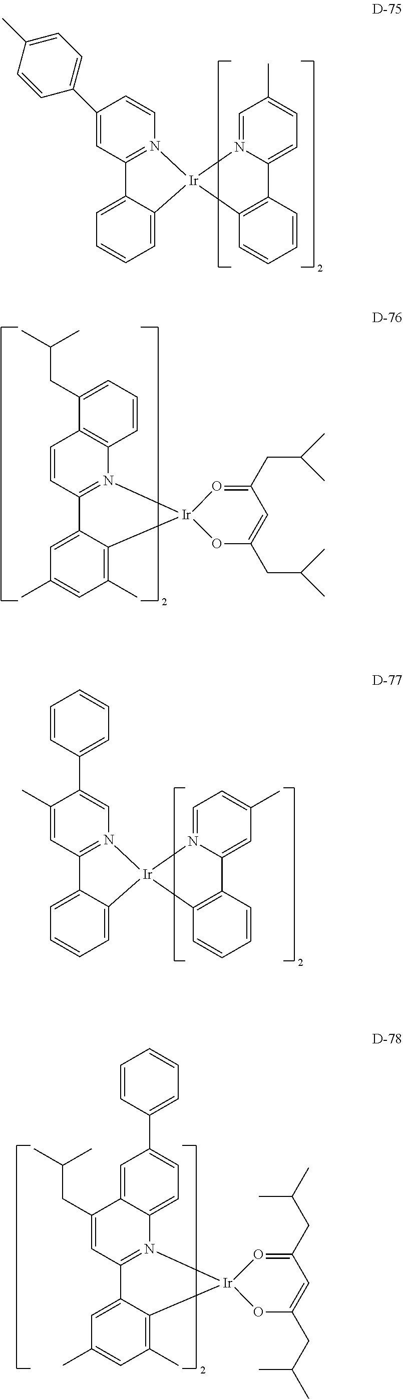

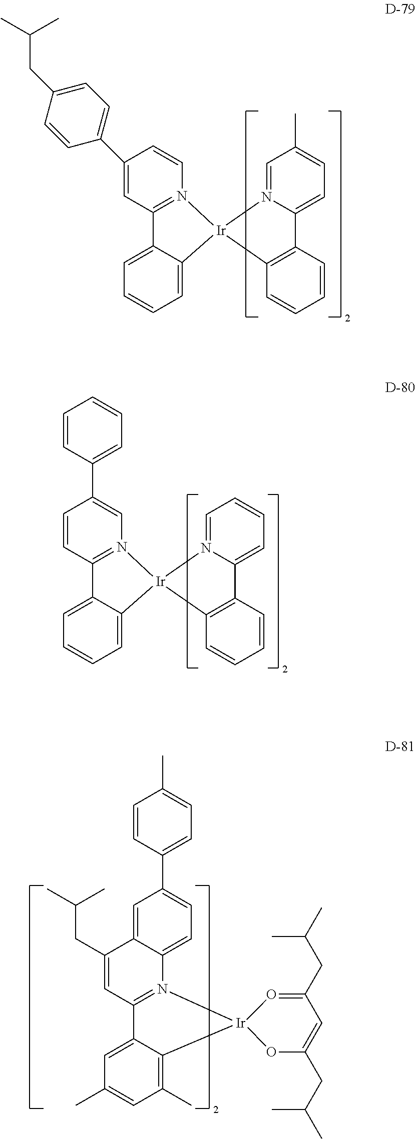

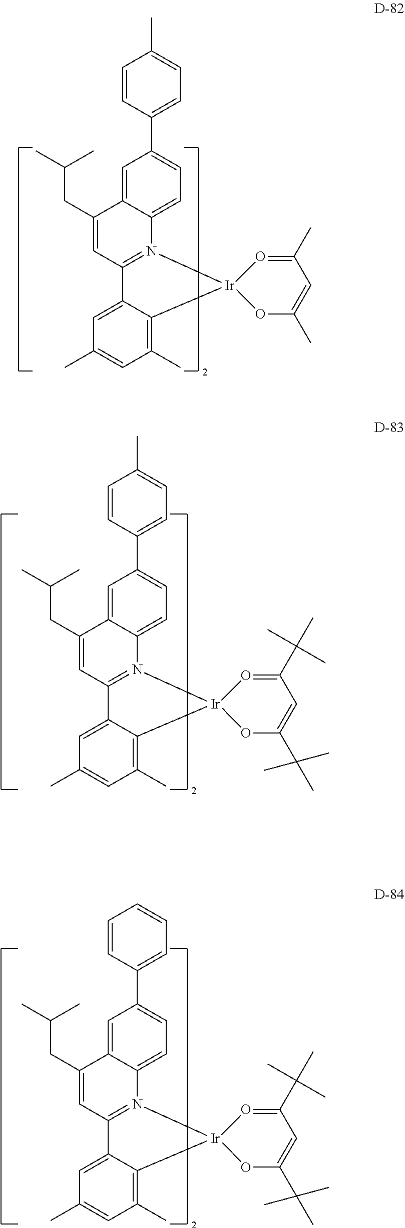

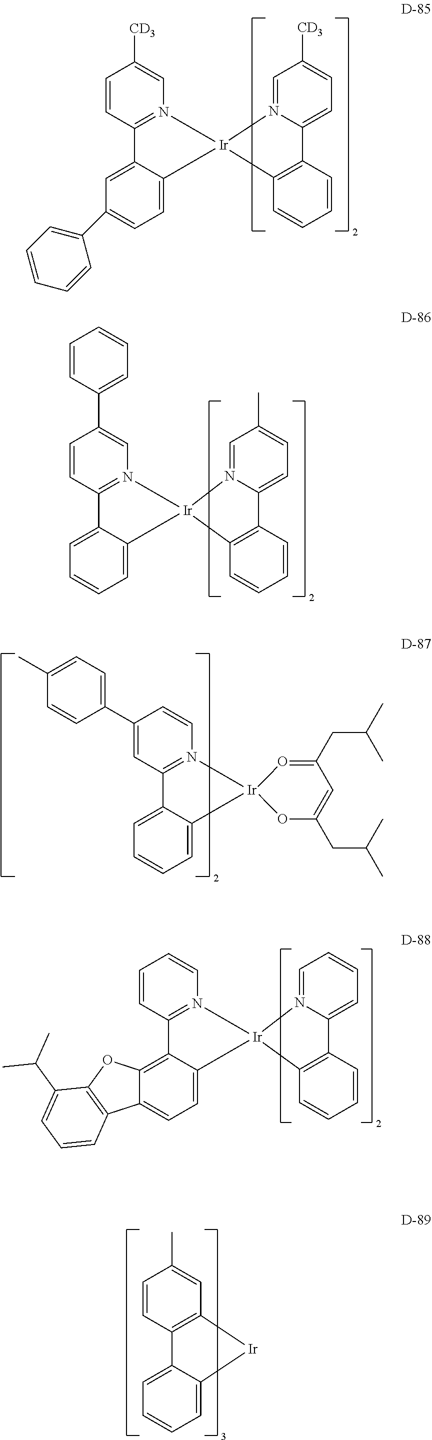

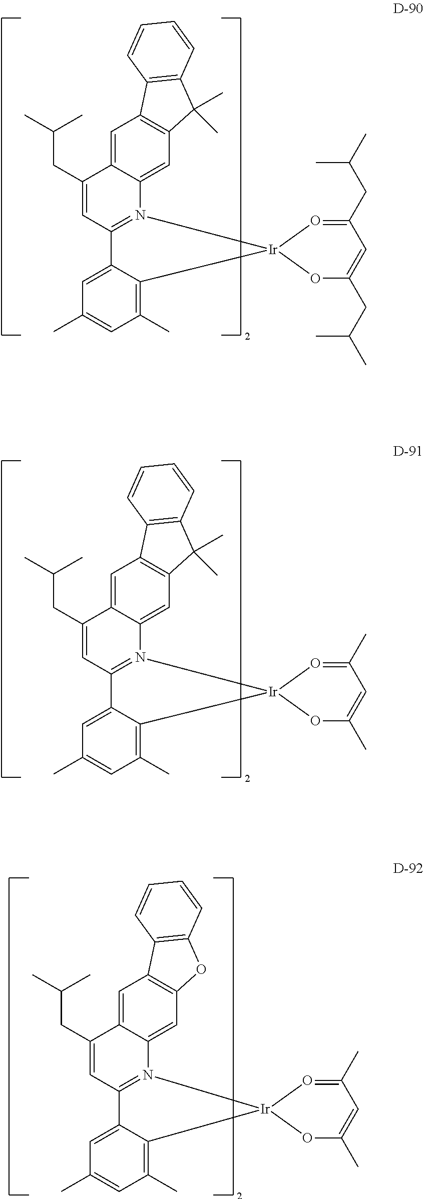

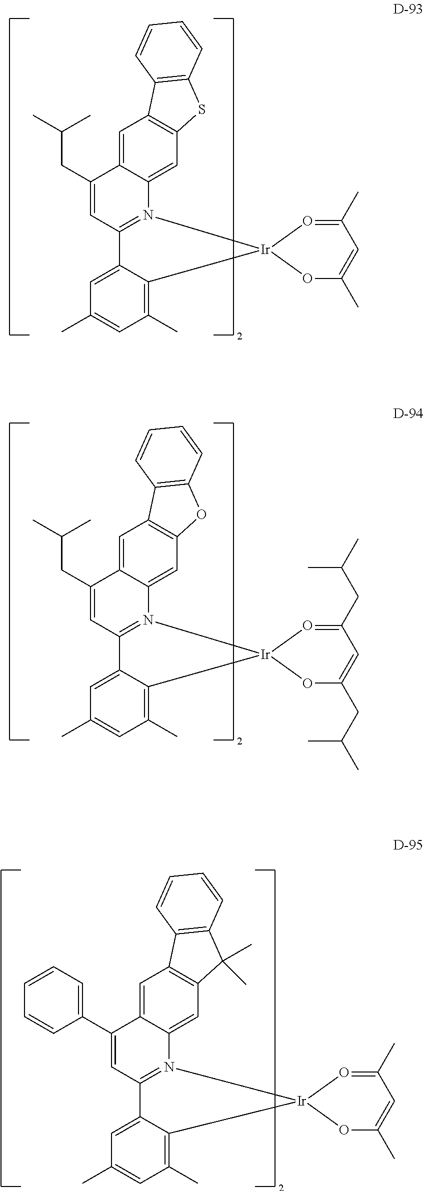

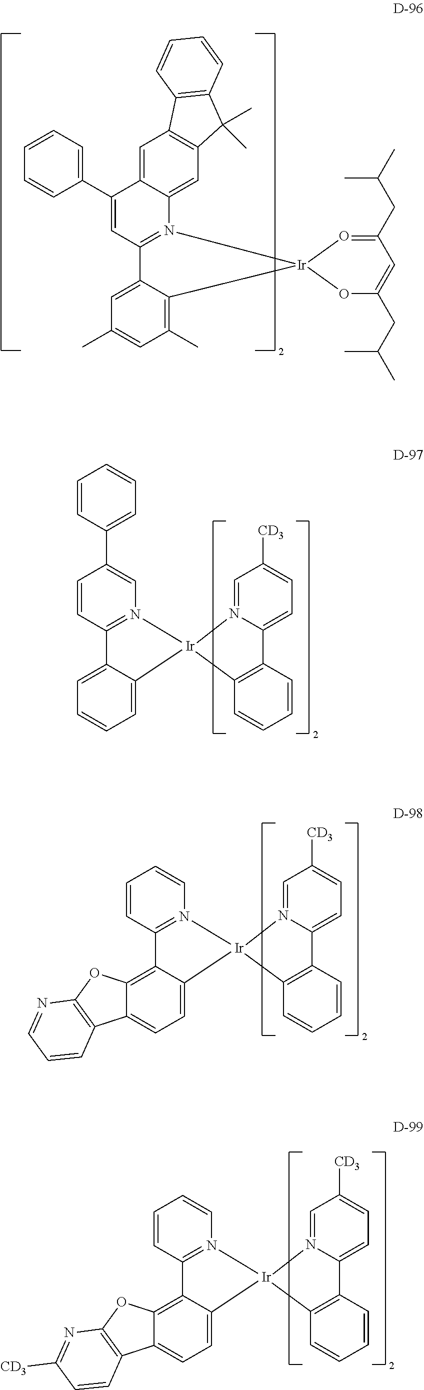

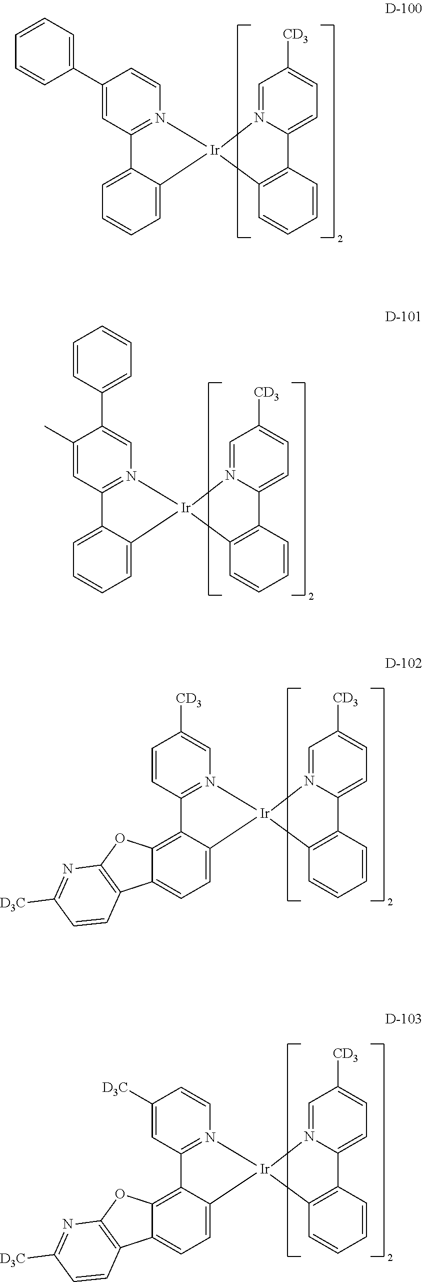

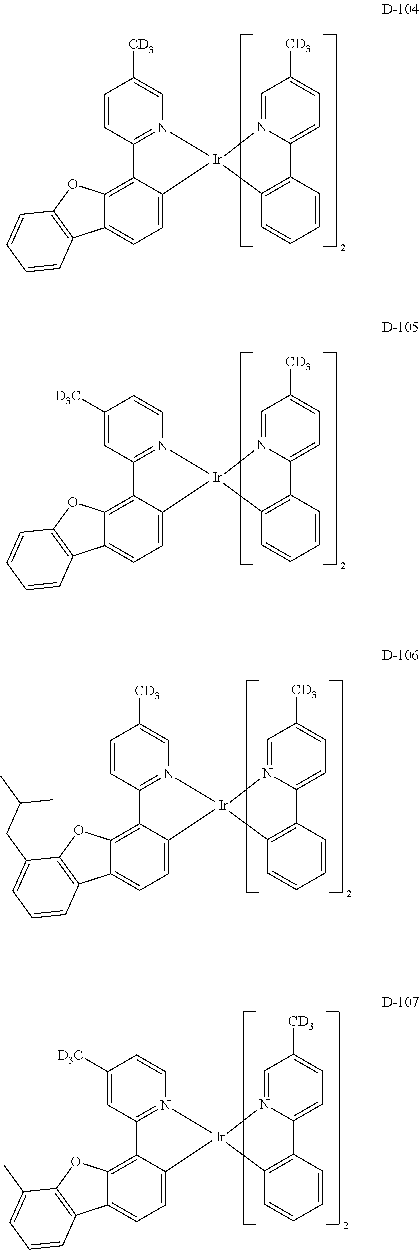

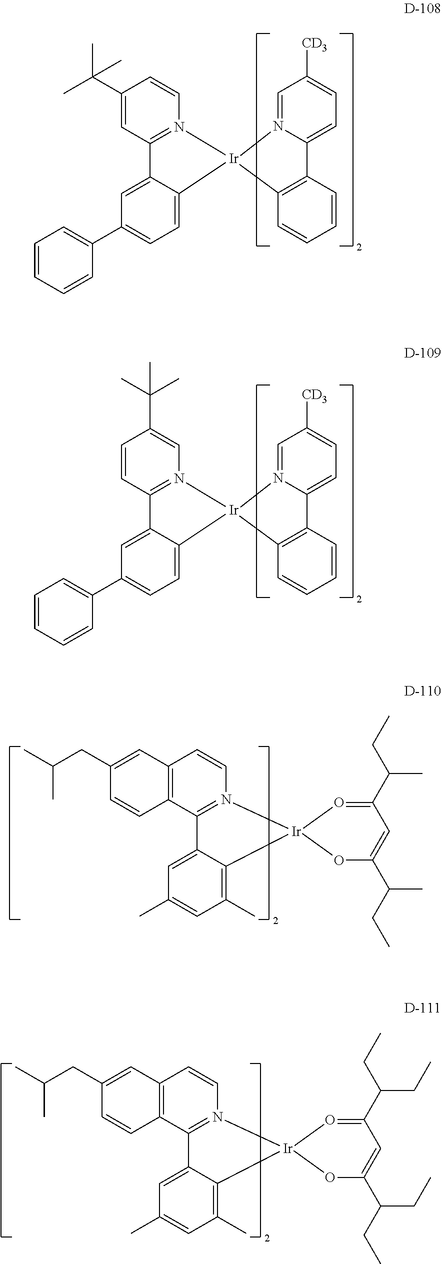

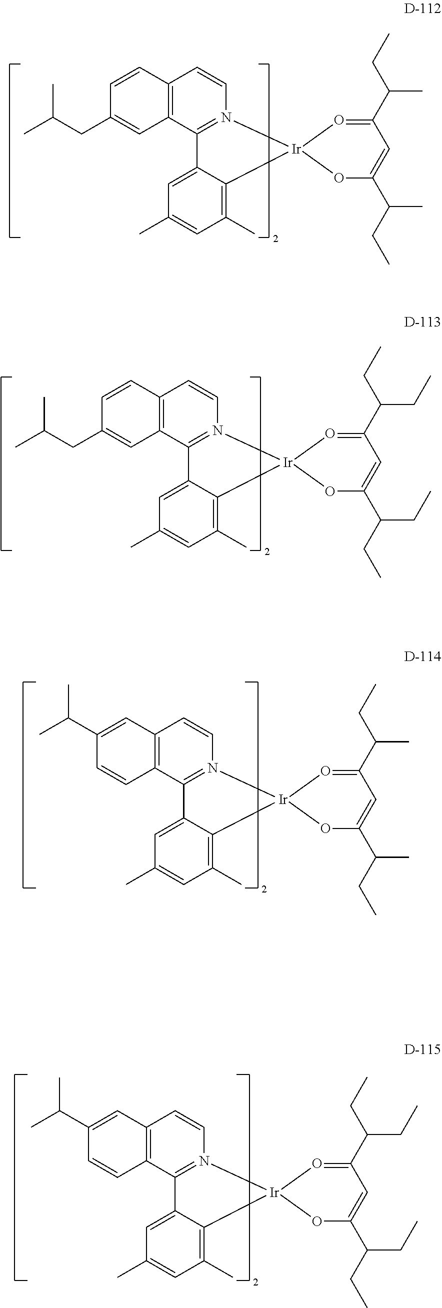

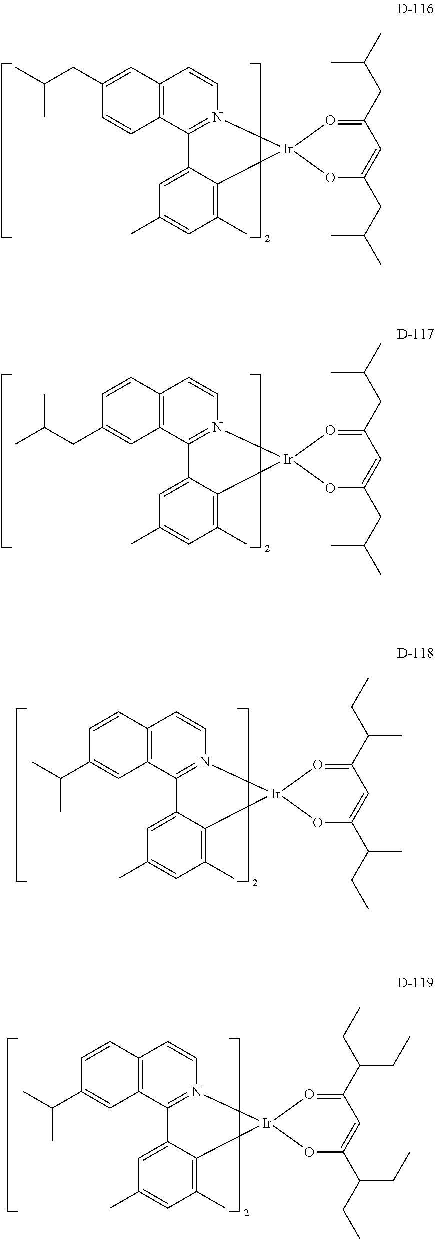

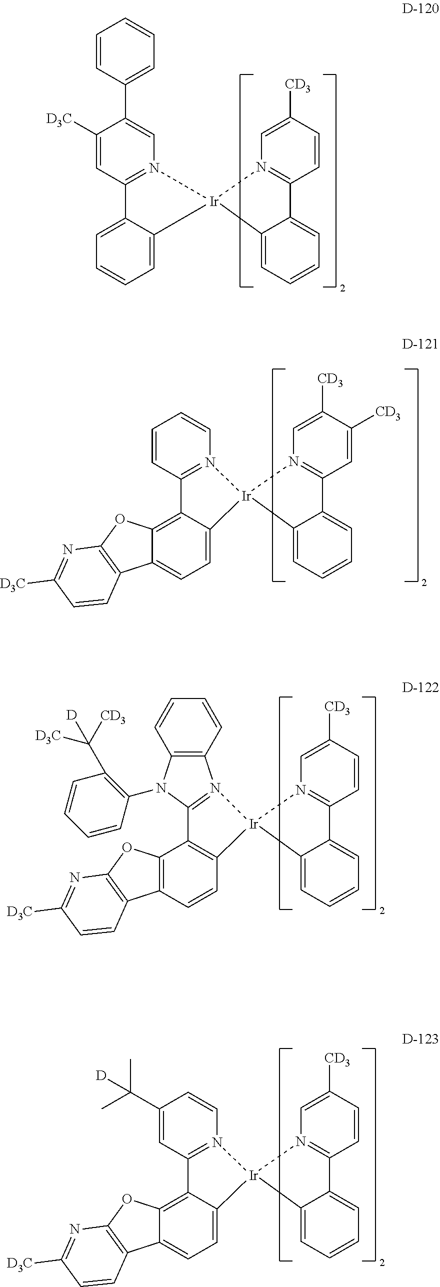

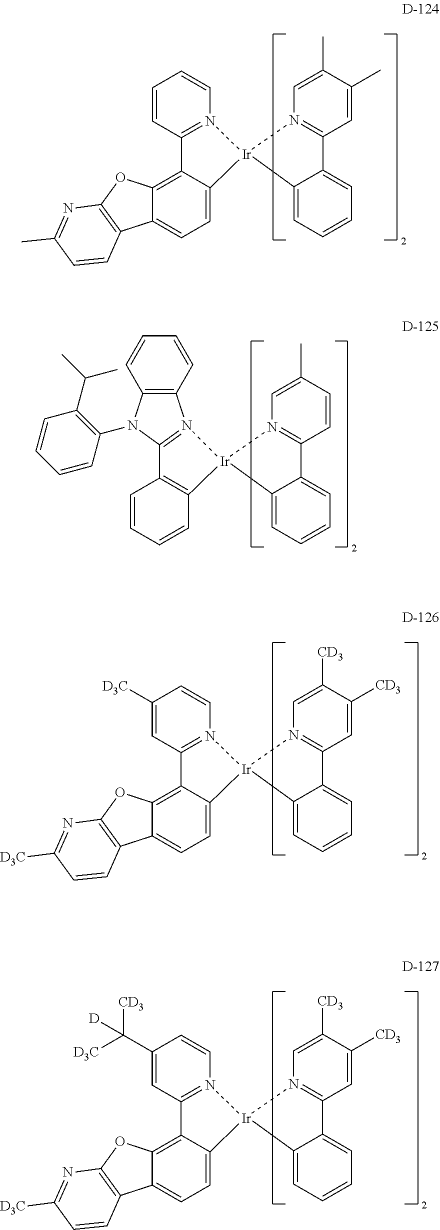

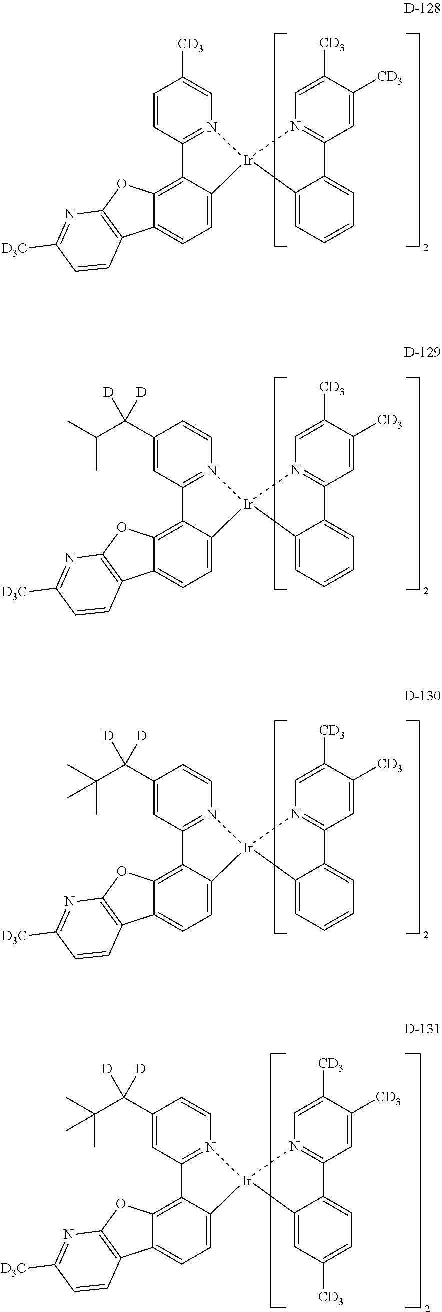

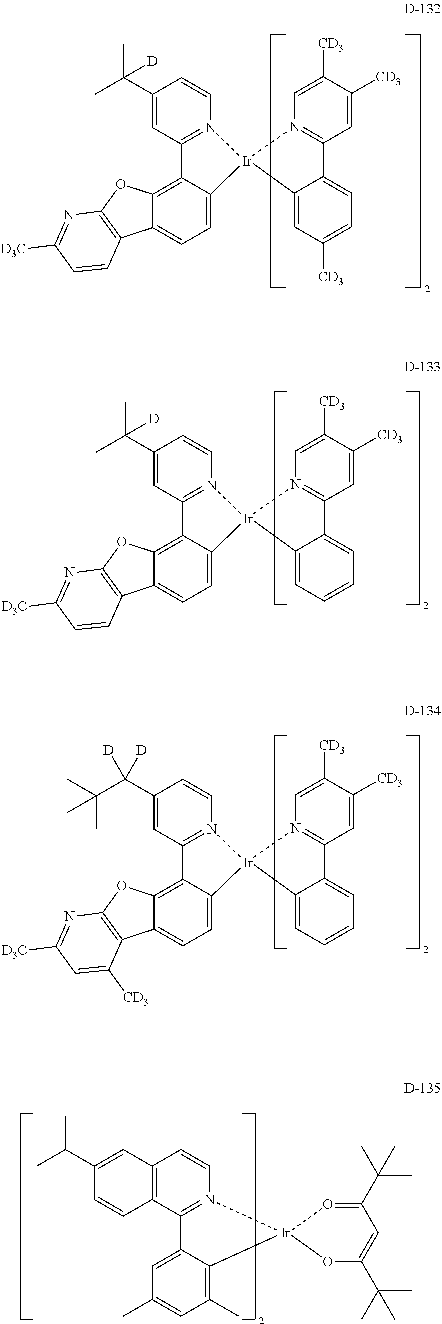

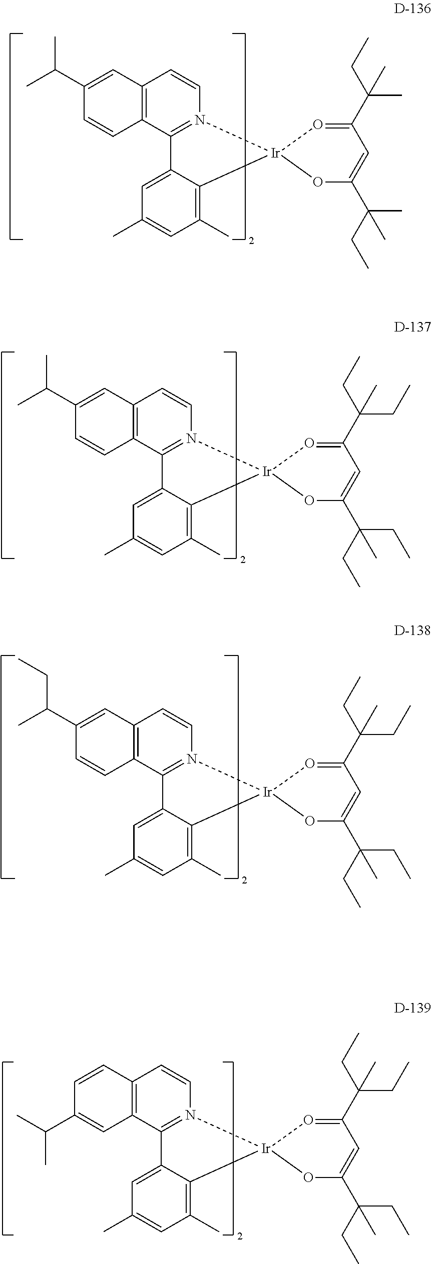

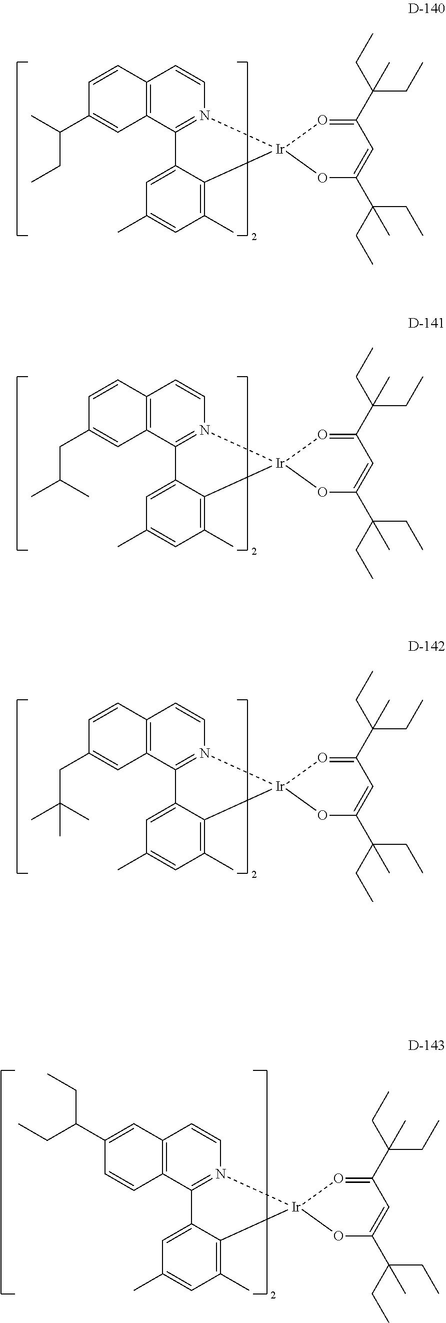

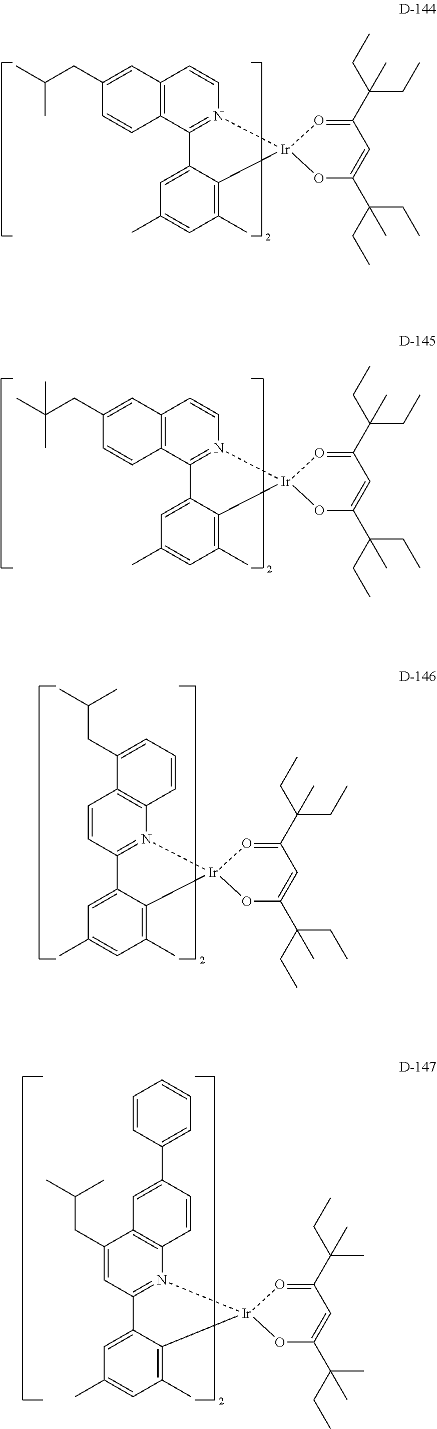

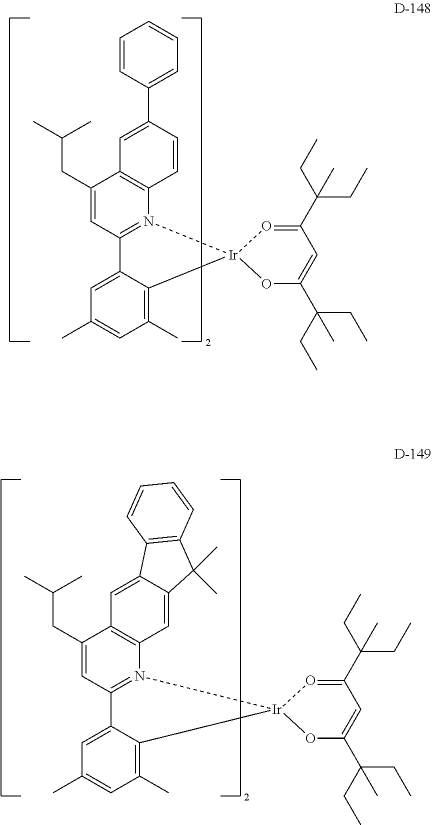

In order to form each layer of the organic electroluminescent device of the present disclosure, dry film-forming methods such as vacuum evaporation, sputtering, plasma, ion plating methods, etc., or wet film-forming methods such as spin coating, dip coating, flow coating methods, etc., can be used. When using a wet film-forming method, a thin film may be formed by dissolving or diffusing materials forming each layer into any suitable solvent such as ethanol, chloroform, tetrahydrofuran, dioxane, etc. The solvent may be any solvent where the materials forming each layer can be dissolved or diffused, and where there are no problems in film-formation capability.

When forming a layer by the first host compound and the second host compound according to one embodiment, the layer can be formed by the above-listed methods, and can often be formed by co-deposition or mixture-deposition. The co-deposition is a mixed deposition method in which two or more materials are put into respective individual crucible sources and a current is applied to both cells simultaneously to evaporate the materials; and the mixed deposition is a method in which two or more materials are mixed in one crucible source before deposition, and then a current is applied to one cell to evaporate the materials.

According to one embodiment, when the first host compound and the second host compound are present in the same layer or different layers in the organic electroluminescent device, the two host compounds may be individually formed. For example, after depositing the first host compound, a second host compound may be deposited.

According to one embodiment, the present disclosure can provide display devices comprising a plurality of host materials including a first host compound represented by formula 1 and a second host compound represented by formula 2. In addition, by using the organic electroluminescent device of the present disclosure, display devices such as smartphones, tablets, notebooks, PCs, TVs, or display devices for vehicles, or lighting devices such as outdoor or indoor lighting can be prepared.

Hereinafter, the preparation method of organic electroluminescent compounds according to the present disclosure will be explained with reference to the synthesis method of a representative compound or intermediate compound in order to understand the present disclosure in detail.

### [Example 1] Synthesis of Compound H1-1

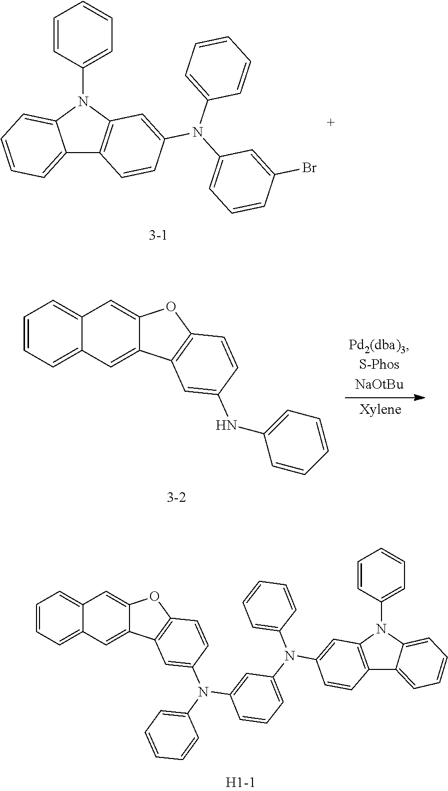 [SMILES: Brc1cccc(N(c2ccccc2)c2ccc3c4ccccc4n(-c4ccccc4)c3c2)c1 ; c1ccc(Nc2ccc3oc4cc5ccccc5cc4c3c2)cc1 ; c1ccc(N(c2cccc(N(c3ccccc3)c3ccc4c5ccccc5n(-c5ccccc5)c4c3)c2)c2ccc3oc4cc5ccccc5cc4c3c2)cc1]

Compound 3-1 (13 g, 26.56 mmol), compound 3-2 (7.8 g, 25.2 mmol), tris(dibenzylideneacetone)dipalladium (Pd₂(dba)₃) (1.15 g, 1.25 mmol), S-Phos (1.03 g, 2.50 mmol), sodium tert-butoxide (NaOtBu) (4.84 g, 50.36 mmol), and 126 mL of o-xylene were added to a flask, and stirred at 100° C. for 2 hours. After the reaction was completed, the mixture was cooled to room temperature, the organic layer was extracted with ethyl acetate, and residual moisture was removed using magnesium sulfate, followed by drying. Next, it was separated by column chromatography to obtain compound H1-1 (13 g, yield: 72.7%).

### [Example 2] Synthesis of Compound H1-2

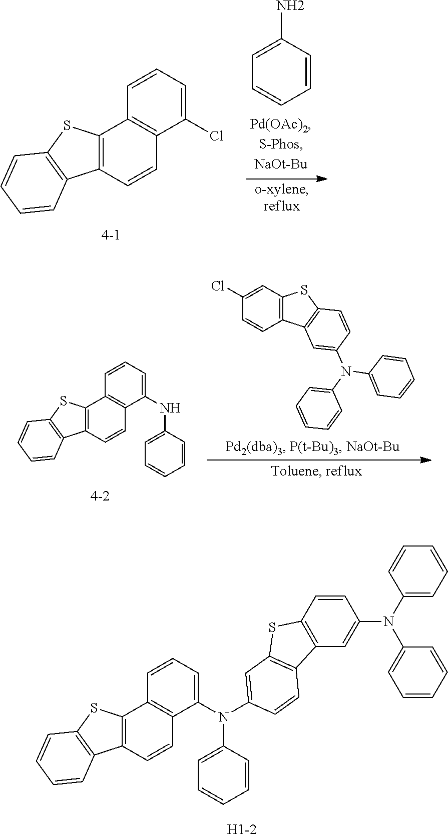 [SMILES: Clc1cccc2c1ccc1c3ccccc3sc21 ; Nc1ccccc1 ; c1ccc(Nc2cccc3c2ccc2c4ccccc4sc32)cc1 ; Clc1ccc2c(c1)sc1ccc(N(c3ccccc3)c3ccccc3)cc12 ; c1ccc(N(c2ccccc2)c2ccc3sc4cc(N(c5ccccc5)c5cccc6c5ccc5c7ccccc7sc65)ccc4c3c2)cc1]

### 1) Synthesis of Compound 4-2

Compound 4-1 (25.0 g, 93.3 mmol), aniline (13.0 mL, 139.9 mmol), palladium(II) acetate (Pd(OAc)₂) (1.05 g, 4.6 mmol), S-Phos (3.8 g, 9.3 mmol), NaOt-Bu (13.5 g, 139.9 mmol), and 325 mL of o-xylene were added to a flask, and refluxed for 3 hours. After the reaction was completed, the solvent from the reaction solution cooled to room temperature was removed using a rotary evaporator. Next, it was purified by column chromatography to obtain compound 4-2 (18.0 g, yield: 55%).

### 2) Synthesis of Compound H1-2

Compound 4-2 (5.6 g, 14.55 mmol), 7-chloro-N,N-diphenyldibenzo[b,d]thiophen-2-amine (5.1 g, 13.23 mmol), Pd₂(dba)₃ (0.6 g, 0.66 mmol), P(t-Bu)₃ (0.6 mL, 1.32 mmol), NaOt-Bu (1.9 g, 19.85 mmol), and 66 mL of toluene were added to the reaction vessel, and stirred at 130° C. for 1 hour. After the reaction was completed, the mixture was washed with distilled water, and the organic layer was extracted with ethyl acetate, followed by drying over magnesium sulfate, and the solvent was removed using a rotary evaporator. Next, it was purified by column chromatography to obtain compound H1-2 (6.0 g, yield: 69%).

### [Example 3] Synthesis of Compound H1-5

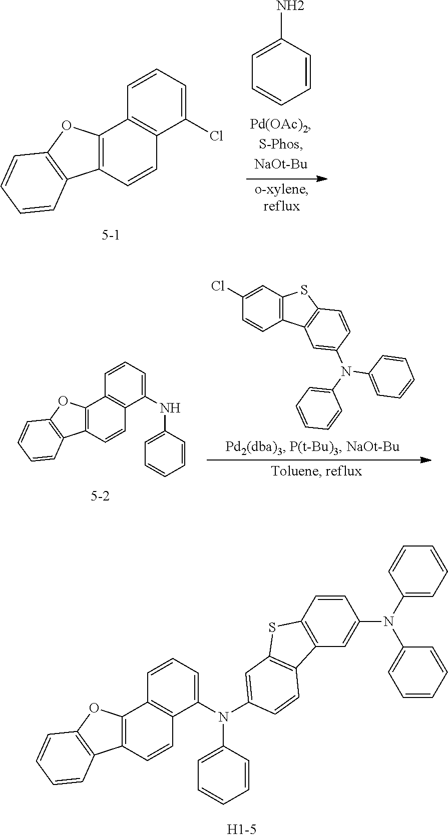 [SMILES: Clc1cccc2c1ccc1c3ccccc3oc21 ; Nc1ccccc1 ; c1ccc(Nc2cccc3c2ccc2c4ccccc4oc32)cc1 ; Clc1ccc2c(c1)sc1ccc(N(c3ccccc3)c3ccccc3)cc12 ; c1ccc(N(c2ccccc2)c2ccc3sc4cc(N(c5ccccc5)c5cccc6c5ccc5c7ccccc7oc65)ccc4c3c2)cc1]

### 1) Synthesis of Compound 5-2

Compound 5-1 (13.6 g, 53.9 mmol), aniline (7.5 mL, 80.8 mmol), Pd(OAc)₂ (0.6 g, 2.69 mmol), S-Phos (2.2 g, 5.4 mmol), NaOt-Bu (7.8 g, 80.8 mmol), and 270 mL of o-xylene were added to a flask and refluxed for 3 hours. After the reaction was completed, the solvent from the reaction solution cooled to room temperature was removed using a rotary evaporator. Next, it was purified by column chromatography to obtain compound 5-2 (14.5 g, yield: 87%).

### 2) Synthesis of Compound H1-5

Compound 5-2 (4.5 g, 14.55 mmol), 7-chloro-N,N-diphenyldibenzo[b,d]thiophen-2-amine (5.1 g, 13.23 mmol), Pd₂(dba)₃ (0.6 g, 0.66 mmol), P(t-Bu)₃ (0.6 mL, 1.32 mmol), NaOt-Bu (1.9 g, 19.85 mmol), and 66 mL of toluene were added to the reaction vessel, and then stirred at 130° C. for 1 hour. After the reaction was completed, the mixture was washed with distilled water, and the organic layer was extracted with ethyl acetate, followed by drying over magnesium sulfate, and the solvent was removed using a rotary evaporator. Next, it was purified by column chromatography to obtain compound H1-5 (3.9 g, yield: 45%).

### [Example 4] Synthesis of Compound C-7

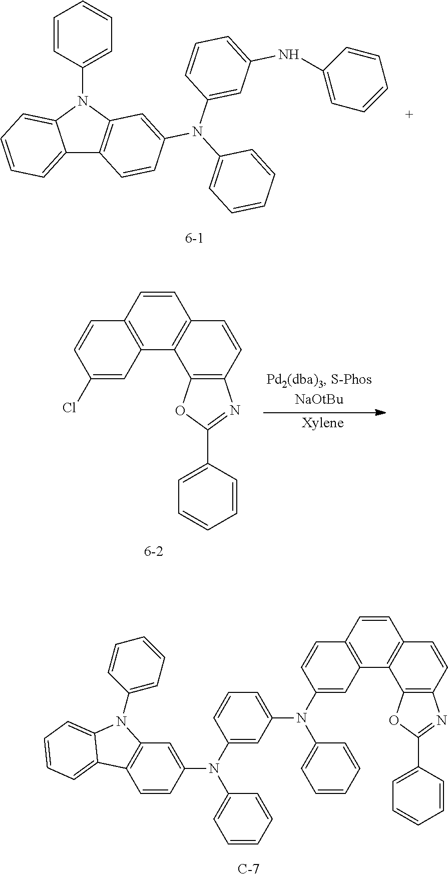

mL of o-xylene were added to a flask, and stirred at 135° C. for 10 hours. After the reaction was completed, the mixture was cooled to room temperature, the organic layer was extracted with ethyl acetate, the residual moisture was removed using magnesium sulfate, followed by drying. Next, it was separated by column chromatography to obtain compound C-7 (12.8 g, yield: 50%).

### [Example 5] Synthesis of Compound C-1

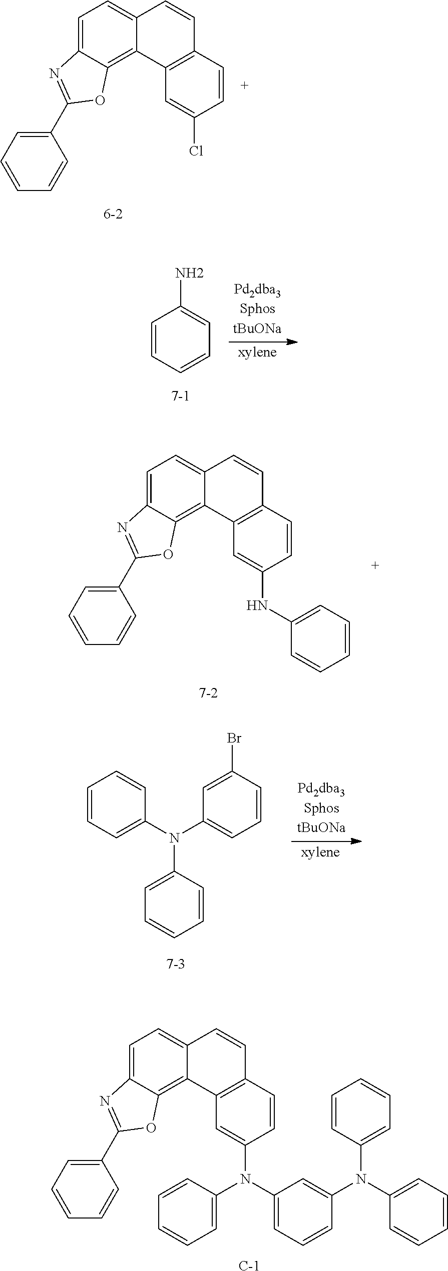

### 1) Synthesis of Compound 7-2

Compound 6-2 (30 g, 90 mmol), compound 7-1 (10.1 g, 109.2 mol), Pd₂(dba)₃ (4.2 g, 4.58 mmol), S-Phos (3.72 g, 9.06 mmol), and NaOtBu (13.2 g, 137.4 mmol) were added to a flask, dissolved in 450 mL of xylene, and then stirred at 150° C. for 40 minutes. After the reaction was completed, the mixture was cooled to room temperature, and filtered through a Celite filter to form a solid. Next, it was separated by column chromatography to obtain compound 7-2 (32 g, yield: 54.8%).

### 2) Synthesis of Compound C-1

Compound 7-2 (5 g, 12.93 mmol), compound 7-3 (5 g, 15.5 mmol), Pd₂(dba)₃ (590 mg, 0.65 mmol), S-Phos (531 mg, 1.29 mmol), NaOtBu (1.86 g, 19.4 mmol) were added to a flask, dissolved in 60 mL of xylene, and then stirred under reflux at 160° C. for 4 hours. After the reaction was completed, the mixture was cooled to room temperature, and filtered through a Celite filter to form a solid. Next, it was separated by column chromatography to obtain compound C-1 (4.2 g, yield: 51.5%).

### [Example 6] Synthesis of Compound C-3

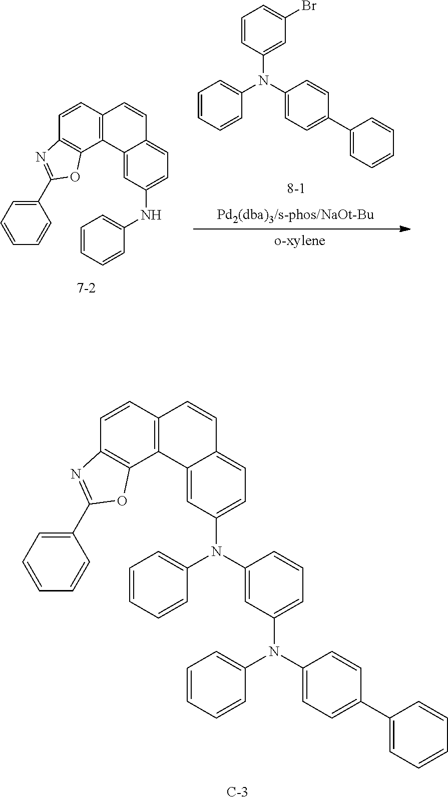

Compound 7-2 (5 g, 12.93 mmol), compound 8-1 (6.2 g, 15.52 mmol), Pd₂(dba)₃ (0.58 g, 0.646 mmol), s-phos (0.53 g, 1.293 mmol), and NaOt-Bu (1.86 g, 19.40 mmol) were added to a flask, dissolved in 65 mL of o-xylene, and then stirred under reflux at 60° C. for 1 hour. After the reaction was completed, the mixture was cooled to room temperature, and MeOH was added thereto, followed by separated with a solid filter. Next, it was dissolved in o-xylene and then separated with silica filter to obtain compound C-3 (7 g, yield: 76%).

### [Example 7] Synthesis of Compound C-17

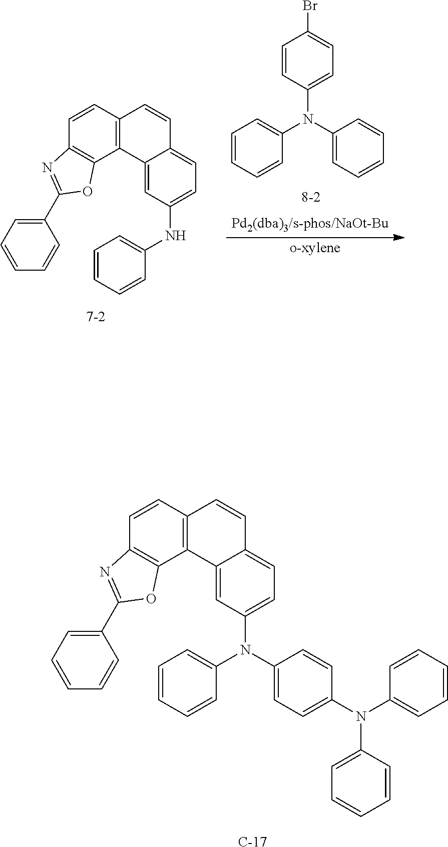

Compound 7-2 (5 g, 12.93 mmol), compound 8-2 (6.2 g, 15.52 mmol), Pd₂(dba)₃ (0.58 g, 0.646 mmol), s-phos (0.53 g, 1.293 mmol), NaOt-Bu (1.86 g, 19.40 mmol) and 65 mL of o-xylene were added to a flask and dissolved, and then stirred under reflux at 160° C. for 1 hour. After the reaction was completed, the mixture was cooled to room temperature, separated with Celite filter, and then distilled under reduced pressure. Next, it was separated by column chromatography with MC/Hex to obtain compound C-17 (6.7 g, yield: 82%).

### [Example 8] Synthesis of Compound C-2

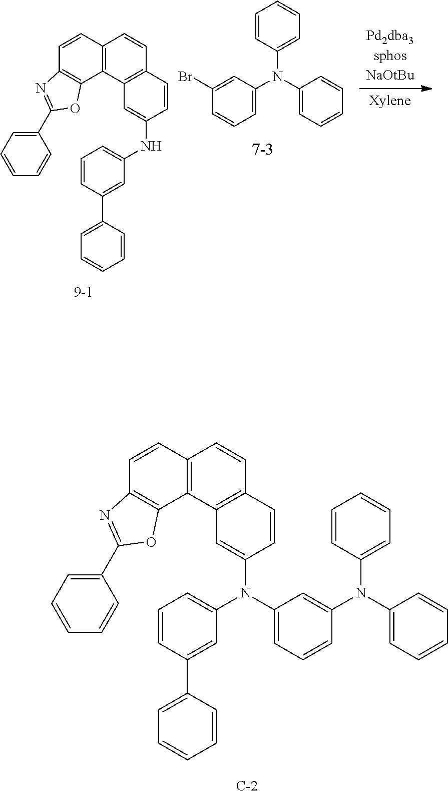

Compound 9-1 (5.0 g, 10.8 mmol), compound 7-3 (4.2 g, 13.0 mmol), Pd₂dba₃ (495 mg, 0.54 mmol), s-phos (443 mg, 1.08 mmol), NaOt-Bu (2.59 g, 27 mmol), and 55 mL of xylene were added to a flask and dissolved, and then stirred under reflux for 6 hours. After the reaction was completed, the mixture was concentrated under reduced pressure, and the organic layer was extracted with dichloromethane and filtered through a silica gel pad. After concentrating the organic layer, the product obtained was separated by silica gel column chromatography to obtain compound C-2 (6.3 g, yield: 83%).

### [Example 9] Synthesis of Compound C-290

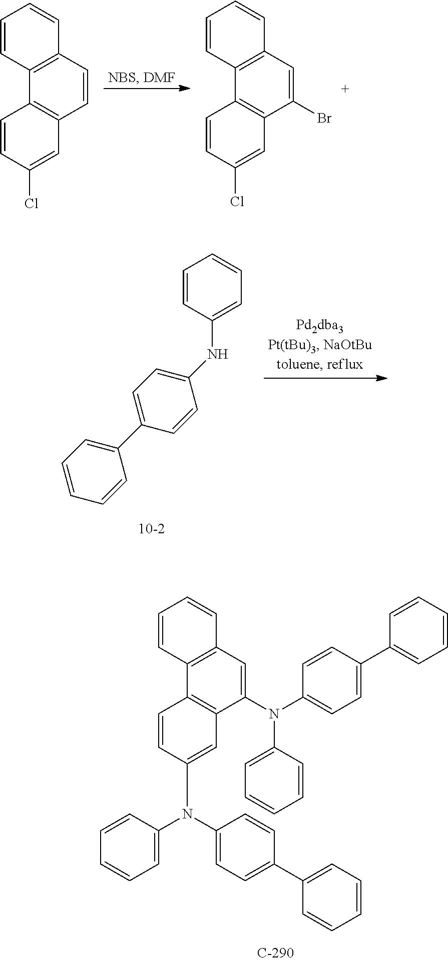 [SMILES: Clc1ccc2c(ccc3ccccc32)c1 ; Clc1ccc2c(c1)c(Br)cc1ccccc12 ; c1ccc(Nc2ccc(-c3ccccc3)cc2)cc1 ; c1ccc(-c2ccc(N(c3ccccc3)c3ccc4c(c3)c(N(c3ccccc3)c3ccc(-c5ccccc5)cc3)cc3ccccc34)cc2)cc1]

### 1) Synthesis of Compound 10-1

In a flask, 2-chlorophenanthrene (30 g, 141.1 mmol) was dissolved in 564 mL of dimethylformamide (DMF), N-bromosuccinimide (NBS) (200.0 g, 1128.5 mmol) was added thereto, and then stirred at 150° C. for 1 hour. After the reaction was completed, the mixture was cooled to room temperature, and dichloromethane and distilled water were added to the mixture. The organic layer was extracted with dichloromethane, filtered under reduced pressure. Next, it was separated by column chromatography to obtain compound 10-1 (36.7 g, yield: 68%).

### 2) Synthesis of Compound C-290

Compound 10-1 (5.0 g, 17.1 mmol), compound 10-2 (9.2 g, 37.6 mmol), Pd₂(dba)₃ (1.56 g, 1.71 mmol), P(tBu)₃ (1.7 mL, 3.42 mmol 50% toluene solution), NaOtBu (6.6 g, 68.4 mmol), and 170 mL of toluene were added to a flask, and refluxed for 18 hours. After the reaction was completed, the mixture was cooled to room temperature, and the solvent from the reaction mixture was removed with a rotary evaporator. Next, it was purified by column chromatography to obtain compound C-290 (3 g, yield: 26.3%) as a white solid.

### [Example 10] Synthesis of Compound C-200

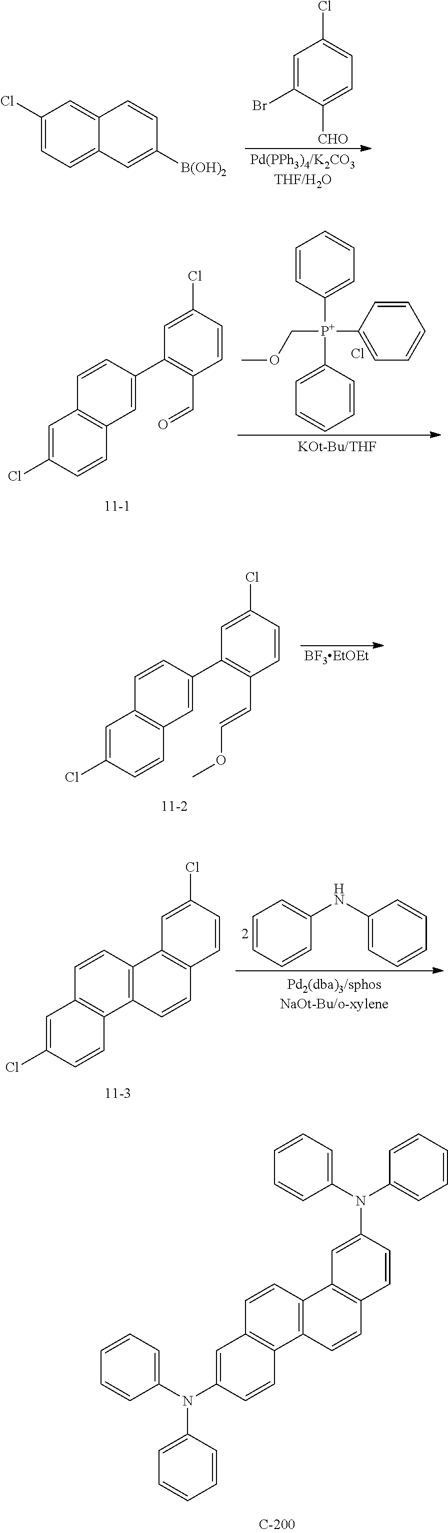

### 1) Synthesis of Compound 11-1

2-Bromo-4-chloro-benzaldehyde (20.0 g, 91.1 mmol), (6-chloro-2-naphthyl)boronic acid (19.8 g, 95.7 mmol), Pd(PPh₃)₄(3.16 g, 2.73 mmol), K₂CO₃ (37.8 g, 273 mmol), 360 mL of THF, and 90 mL of H₂O were added to a flask and dissolved, and then stirred under reflux at 140° C. for 2 hours. After the reaction was completed, the mixture was cooled to room temperature. Next, it was separated with a silica filter to obtain compound 11-1 (22.7 g, yield: 82.7%).

### 2) Synthesis of Compound 11-2

Compound 11-1 (21.7 g, 72.1 mmol), methoxymethyl(triphenyl)phosphonium chloride (37.0 g, 108 mmol), and 400 mL of THF were added to a flask and dissolved at 0° C., and KOt-Bu (12.1 g, 108 mmol) was added dropwise thereto and stirred for 2.5 hours. After the reaction was completed, the organic layer was separated by adding ethyl acetate and water to the reaction mixture, and was passed through a silica filter to obtain compound 11-2 (16.3 g, yield: 49%).

### 3) Synthesis of Compound 11-3

Compound 11-2 (3.5 g, 5.54 mmol) and 400 mL of MC were added to a flask, and dissolved at 0° C., BF₃·EtOEt (0.894 mL, 16.6 mmol) was added dropwise thereto, and stirred at room temperature for 50 minutes. After the reaction was completed, the organic layer was separated by adding MC and water to the reaction mixture, and was passed through a silica filter to obtain compound 11-3 (9.70 g, yield: 87.2%).

### 4) Synthesis of Compound C-200

Compound 11-3 (3.0 g, 22.2 mmol), N-phenylaniline (3.00 g, 10.1 mmol), Pd₂(dba)₃ (0.462 g, 0.505 mmol), sphos (0.414 g, 1.01 mmol), NaOt-Bu (2.43 g, 25.2 mmol) and 100 mL of o-xylene were added to a flask, and stirred under reflux at 180° C. for 1.5 hours. After the reaction was completed, it was passed through a silica filter to obtain compound C-200 (5.3 g, yield: 93.3%).

Hereinafter, the preparation method of an organic electroluminescent device comprising the plurality of host materials according to the present disclosure, and the device property thereof will be explained in order to understand the present disclosure in detail.

### [Device Examples 1 to 20] Preparation of Red Light Emitting OLEDs Deposited with a Plurality of Host Materials According to the Present Disclosure

OLEDs according to the present disclosure were produced. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and thereafter was stored in isopropyl alcohol and then used. Thereafter, the ITO substrate was mounted on a substrate holder of a vacuum vapor deposition apparatus. Then, compound HI-1 was introduced into a cell of the vacuum vapor deposition apparatus, and compound HT-1 was introduced into another cell. The two materials were evaporated at different rates and compound HI-1 was deposited in a doping amount of 3 wt % based on the total amount of compounds HI-1 and HT-1 to form a hole injection layer having a thickness of 10 nm. Next, compound HT-1 was deposited as a first hole transport layer having a thickness of 80 nm on the hole injection layer. Compound HT-2 was then introduced into another cell of the vacuum vapor deposition apparatus and was evaporated by applying an electric current to the cell, thereby forming a second hole transport layer having a thickness of 60 nm on the first hole transport layer. After forming the hole injection layer and the hole transport layers, a light-emitting layer was formed thereon as follows: each of the first host compound and the second host compound described in the following Table 1 were introduced into two cells of the vacuum vapor deposition apparatus as hosts, respectively, and compound D-39 was introduced into another cell as a dopant. The two host materials were evaporated at a rate of 1:1 and the dopant material was evaporated at a different rate, simultaneously, and was deposited in a doping amount of 3 wt % based on the total amount of the hosts and dopant to form a light-emitting layer having a thickness of 40 nm on the second hole transport layer. Next, compounds ETL-1 and EIL-1 as electron transport materials were deposited at a weight ratio of 50:50 to form an electron transport layer having a thickness of 35 nm on the light-emitting layer. After depositing compound EIL-1 as an electron injection layer having a thickness of 2 nm on the electron transport layer, an Al cathode having a thickness of 80 nm was deposited on the electron injection layer by another vacuum vapor deposition apparatus. Thus, OLEDs were produced. Each compound used for all the materials were purified by vacuum sublimation under 10⁻⁶ torr.

### [Comparative Examples 1 to 7 and 10] Preparation of OLEDs Comprising a Single Host Compound

OLEDs were manufactured in the same manner as in Device Example 1, except that the first host compound or the second host compound as the host of the light-emitting layer was used alone as in the following Table 1.

### [Comparative Examples 8 and 9] Preparation of OLEDs Comprising the Conventional Compound as the Host

OLEDs were manufactured in the same manner as in Device Example 1, except that the compound of the following Table 1 was used as the host of the light-emitting layer.

The driving voltage, luminous efficiency, and the luminous color at a luminance of 1,000 nits and the time taken for luminance to decrease from 100% to 95% at a luminance of 10,000 nits (lifespan: T95) of the OLED devices of Device Examples 1 to 20 and Comparative Examples 1 to 10 produced as described above, are measured, and the results thereof are shown in the following Tables 1 and 2.

TABLE 1

| | | | Driving | Luminous | | |
|---|---|---|---|---|---|---|
| | First | Second | Voltage | Efficiency | Luminous | Lifespan |
| | Host | Host | (V) | (cd/A) | Color | T95(hr) |
| Device | H1-1 | H2-77 | 3.0 | 37.1 | Red | 137 |
| Example 1 | | | | | | |
| Device | H1-1 | H2-1 | 2.8 | 34.8 | Red | 133 |
| Example 2 | | | | | | |
| Device | H1-1 | H2-456 | 3.0 | 36.7 | Red | 150 |
| Example 3 | | | | | | |
| Device | H1-1 | H2-494 | 3.1 | 37.4 | Red | 217 |
| Example 4 | | | | | | |
| Device | H1-1 | H2-40 | 3.0 | 37.2 | Red | 169 |
| Example 5 | | | | | | |
| Device | H1-2 | H2-77 | 2.9 | 35.1 | Red | 174 |
| Example 6 | | | | | | |
| Device | H1-5 | H2-77 | 3.0 | 35.5 | Red | 112 |
| Example 7 | | | | | | |
| Device | H1-1 | H2-98 | 3.0 | 36.5 | Red | 88 |
| Example 8 | | | | | | |
| Device | C-7 | H2-1 | 2.8 | 35 | Red | 210 |
| Example 9 | | | | | | |
| Device | C-7 | H2-77 | 2.9 | 37.2 | Red | 264 |
| Example 10 | | | | | | |
| Device | C-181 | H2-77 | 3.2 | 36.8 | Red | 112 |
| Example 11 | | | | | | |
| Device | C-1 | H2-98 | 3.0 | 36.9 | Red | 152 |
| Example 12 | | | | | | |
| Device | C-181 | H2-494 | 3.5 | 36.3 | Red | 85 |
| Example 13 | | | | | | |
| Device | C-1 | H2-494 | 3.1 | 37.1 | Red | 140 |
| Example 14 | | | | | | |
| Device | C-3 | H2-494 | 3.3 | 37.0 | Red | 314 |
| Example 15 | | | | | | |
| Device | C-17 | H2-494 | 3.1 | 33.3 | Red | 246 |
| Example 16 | | | | | | |
| Comparative | H1-1 | — | 3.8 | 6.4 | Red | 7 |
| Example 1 | | | | | | |
| Comparative | — | H2-77 | 3.4 | 32.6 | Red | 25 |
| Example 2 | | | | | | |
| Comparative | — | H2-1 | 3.0 | 25.3 | Red | 17 |
| Example 3 | | | | | | |
| Comparative | — | H2-456 | 3.6 | 28.6 | Red | 13 |
| Example 4 | | | | | | |
| Comparative | — | H2-494 | 4.0 | 31.2 | Red | 19 |
| Example 5 | | | | | | |
| Comparative | — | H2-40 | 3.7 | 31.5 | Red | 29 |
| Example 6 | | | | | | |
| Comparative | — | H2-98 | 3.7 | 29.8 | Red | 13 |
| Example 7 | | | | | | |
| Comparative | H1-1 | T-1 | 3.0 | 33.7 | Red | 69 |
| Example 8 | | | | | | |
| Comparative | H1-1 | T-2 | 3.1 | 36.2 | Red | 77 |
| Example 9 | | | | | | |

TABLE 2

| | | | Driving | Luminous | | |
|---|---|---|---|---|---|---|
| | First | Second | Voltage | Efficiency | Luminous | Lifespan |
| | Host | Host | (V) | (cd/A) | Color | T95(hr) |
| Device | C-7 | H2-726 | 2.8 | 33.5 | Red | 88 |
| Example 17 | | | | | | |
| Device | C-2 | H2-726 | 2.9 | 34.8 | Red | 72 |
| Example 18 | | | | | | |
| Device | C-1 | H2-726 | 2.9 | 34.7 | Red | 66 |
| Example 19 | | | | | | |
| Device | H1-1 | H2-726 | 2.8 | 35.1 | Red | 54 |
| Example 20 | | | | | | |
| Comparative | — | H2-726 | 2.9 | 24.3 | Red | 33 |
| Example 10 | | | | | | |

### [Device Examples 21 to 23] Preparation of Red Light Emitting OLEDs Deposited with a Plurality of Host Materials According to the Present Disclosure as a Host

OLEDs were manufactured in the same manner as in Device Example 1, except that the light emitting layer was deposited as follows: Each of the first host compound, the second host compound, and the third host compound listed in the following Table 3 were placed as hosts in three cells in the vacuum deposition equipment, and compound D-39 was placed as a dopant in another cell, then three host materials were evaporated at a rate of 0.25:0.5:0.25 (first host: second host: third host), and at the same time the dopant material is evaporated at a different rate and was deposited in a doping amount of 3 wt % based on the total amount of the hosts and dopant to from a light-emitting layer having a thickness of 40 nm on the second hole transport layer.

### [Comparative Examples 11 and 12] Preparation of OLEDs Comprising a Single Host Compound

OLEDs were manufactured in the same manner as in Device Example 21, except that the first host compound or the third host compound was used alone as the host of the light-emitting layer as in the following Table 3.

The driving voltage, luminous efficiency, and the luminous color at a luminance of 1,000 nits and the time taken for luminance to decrease from 100% to 95% at a luminance of 10,000 nits (lifespan: T95) of the OLED devices of Device Examples 21 to 23 and Comparative Examples 11 and 12 produced as described above, are measured, and the results thereof are shown in the following Table 3.

TABLE 3

| | | | | Driving | Luminous | | |
|---|---|---|---|---|---|---|---|
| | First | Second | Third | Voltage | Efficiency | Luminous | Lifespan |
| | Host | Host | Host | (V) | (cd/A) | Color | T95(hr) |
| Device | C-7 | H2-456 | H2-72 | 3.0 | 35.4 | Red | 200 |
| Example 21 | | | | | | | |
| Device | C-7 | H2-456 | H2-736 | 2.9 | 35.6 | Red | 188 |
| Example 22 | | | | | | | |
| Device | C-7 | H2-456 | H2-13 | 2.9 | 34.7 | Red | 144 |
| Example 23 | | | | | | | |
| Comparative | C-7 | — | — | 4.0 | 5.1 | Red | 2 |
| Example 11 | | | | | | | |
| Comparative | — | — | H2-736 | 3.6 | 29.9 | Red | 24 |
| Example 12 | | | | | | | |

### [Device Examples 24 and 25] Preparation of Red Light Emitting OLEDs Deposited with a Plurality of Host Materials According to the Present Disclosure as a Host

OLEDs were manufactured in the same manner as in Device Example 21, except that compound HT-3 was used as a material for the second hole transport layer and the compound shown in the following Table 4 was used as a host for the light-emitting layer.

### [Comparative Examples 13 to 16] Preparation of OLEDs Comprising a Single Host Compound

OLEDs were manufactured in the same manner as in Device Example 24, except that the first host compound, the second host compound, or the third host compound was used alone as the host of the light-emitting layer as in the following Table 4.

The driving voltage, luminous efficiency, and the luminous color at a luminance of 5,000 nits and the time taken for luminance to decrease from 100% to 95% at a luminance of 10,000 nits (lifespan: T95) of the OLED devices of Device Examples 24 and 25 and Comparative Examples 13 to 16 produced as described above, are measured, and the results thereof are shown in the following Table 4.

TABLE 4

| | | | | Driving | Luminous | | |
|---|---|---|---|---|---|---|---|
| | First | Second | Third | Voltage | Efficiency | Luminous | Lifespan |
| | Host | host | host | (V) | (cd/A) | Color | T95(hr) |
| Device | K-2 | H2-501 | C-200 | 4.0 | 32.3 | Red | 93 |
| Example 24 | | | | | | | |
| Device | K-1 | H2-501 | C-200 | 4.0 | 31.8 | Red | 90 |
| Example 25 | | | | | | | |
| Comparative | K-1 | — | — | 4.2 | 8.8 | Red | 9 |
| Example 13 | | | | | | | |
| Comparative | K-2 | — | — | 5.9 | 8.9 | Red | 5 |
| Example 14 | | | | | | | |
| Comparative | — | — | C-200 | 7.6 | 1.7 | Red | 2 |
| Example 15 | | | | | | | |
| Comparative | — | H2-501 | — | 3.9 | 29.6 | Red | 40 |
| Example 16 | | | | | | | |

### [Device Example 26] Preparation of a Red Light Emitting OLED Deposited with a Plurality of Host Materials According to the Present Disclosure as a Host

An OLED was manufactured in the same manner as in Device Example 1, except that the compound of the following Table 5 is used as a host of the light-emitting layer.

The driving voltage, luminous efficiency, and the luminous color at a luminance of 1,000 nits and the time taken for luminance to decrease from 100% to 95% at a luminance of 10,000 nits (lifespan: T95) of the OLED devices of Device Example 26 and Comparative Example 16 produced as described above, are measured, and the results thereof are shown in the following Table 5.

TABLE 5

| | | | Luminous | | |
|---|---|---|---|---|---|
| | First | Second | Efficiency | Luminous | Lifespan |
| | Host | Host | (cd/A) | Color | T95(hr) |
| Comparative | — | H2-501 | 33.1 | Red | 40 |
| Example 16 | | | | | |
| Device | C-338 | H2-501 | 35.8 | Red | 122 |
| Example 26 | | | | | |

From Tables 1 to 5 above, it can be seen that an organic electroluminescent device including a specific combination of compounds according to the present disclosure as host materials exhibits a low driving voltage and/or high luminous efficiency, and in particular, significantly improved lifespan characteristics, compared to the organic electroluminescent devices using only a single host material (Comparative Examples 1 to 7 and 10 to 16) or including a conventional host combination (Comparative Examples 8 and 9).

The compounds used in Device Examples and Comparative Examples above are shown in the following Table 6:

TABLE 6

| | |
|---|---|
| Hole Injection Layer/Hole Transport Layer | 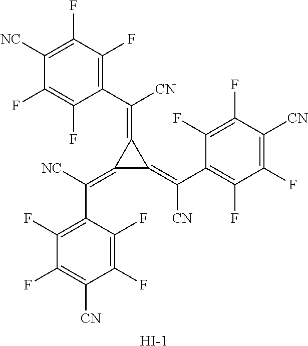 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; [I-]] |
| | 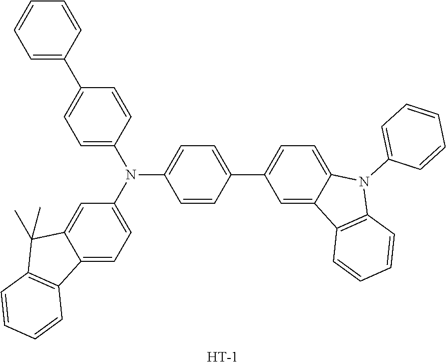 |
| | 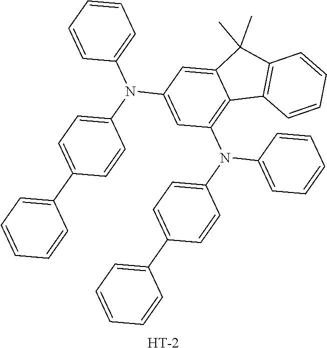 |
| | 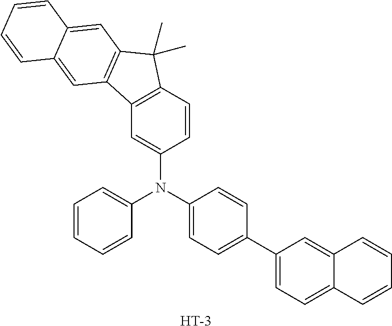 |
| Light-Emitting Layer | 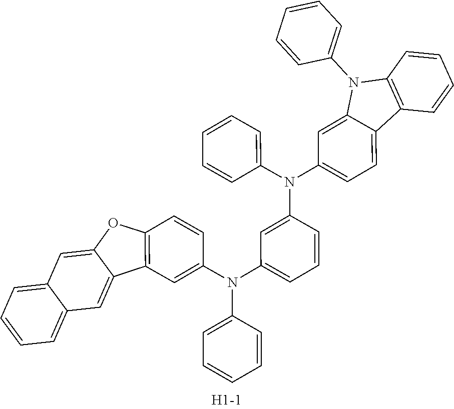 [SMILES: c1ccc(N(c2cccc(N(c3ccccc3)c3ccc4c5ccccc5n(-c5ccccc5)c4c3)c2)c2ccc3oc4cc5ccccc5cc4c3c2)cc1] |
| | 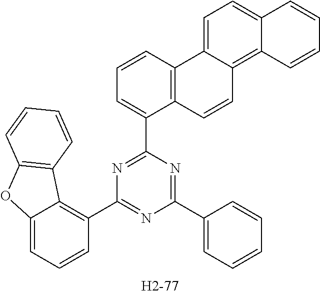 [SMILES: c1ccc(-c2nc(-c3cccc4c3ccc3c5ccccc5ccc43)nc(-c3cccc4oc5ccccc5c34)n2)cc1] |
| | 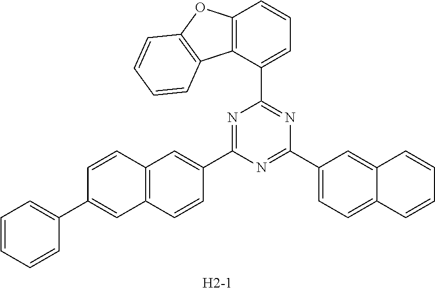 [SMILES: c1ccc(-c2ccc3cc(-c4nc(-c5ccc6ccccc6c5)nc(-c5cccc6oc7ccccc7c56)n4)ccc3c2)cc1 ; "H2-1"] |
| | 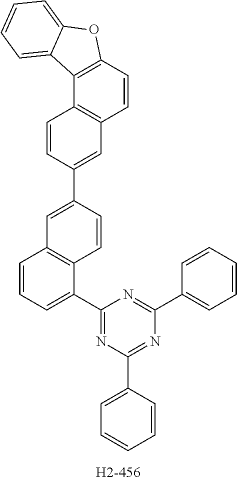 [SMILES: c1ccc(-c2nc(-c3ccccc3)nc(-c3cccc4cc(-c5ccc6c(ccc7oc8ccccc8c76)c5)ccc34)n2)cc1] |
| | 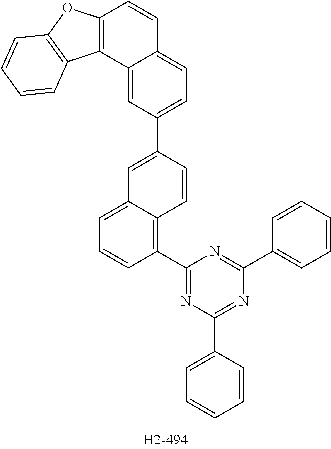 [SMILES: c1ccc(-c2nc(-c3ccccc3)nc(-c3cccc4cc(-c5ccc6ccc7oc8ccccc8c7c6c5)ccc34)n2)cc1] |
| | 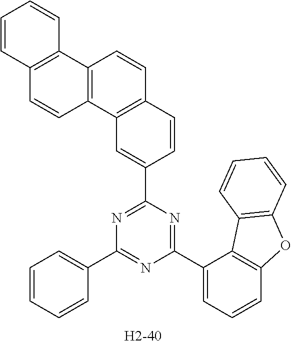 [SMILES: c1ccc(-c2nc(-c3ccc4ccc5c6ccccc6ccc5c4c3)nc(-c3cccc4oc5ccccc5c34)n2)cc1] |
| | 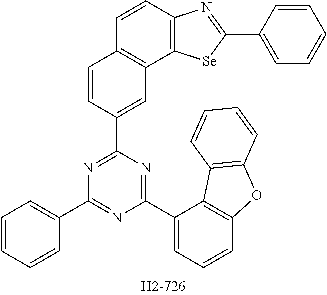 [SMILES: c1ccc(-c2nc(-c3ccc4ccc5nc(-c6ccccc6)[se]c5c4c3)nc(-c3cccc4oc5ccccc5c34)n2)cc1] |
| | 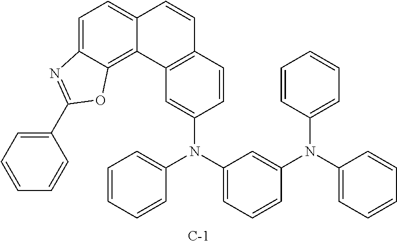 |
| | 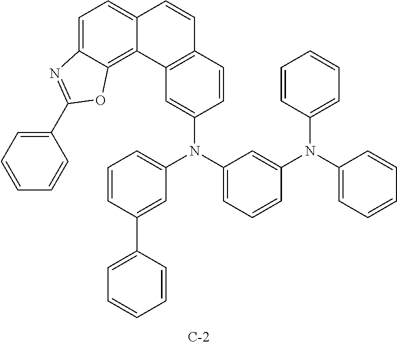 |
| | 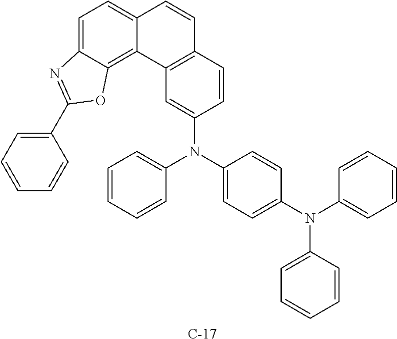 |
| | 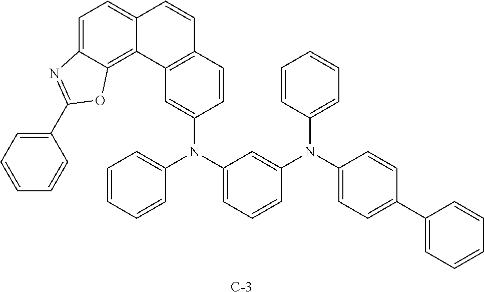 |
| | 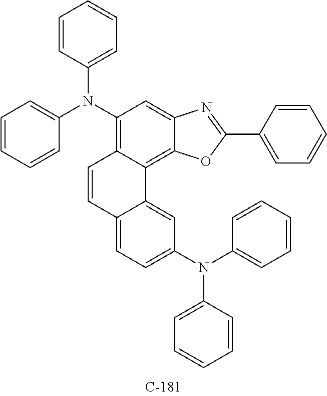 [SMILES: c1ccc(-c2nc3cc(N(c4ccccc4)c4ccccc4)c4ccc5ccc(N(c6ccccc6)c6ccccc6)cc5c4c3o2)cc1] |
| | 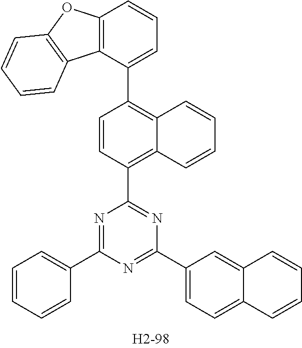 [SMILES: c1ccc(-c2nc(-c3ccc4ccccc4c3)nc(-c3ccc(-c4cccc5oc6ccccc6c45)c4ccccc34)n2)cc1] |
| | 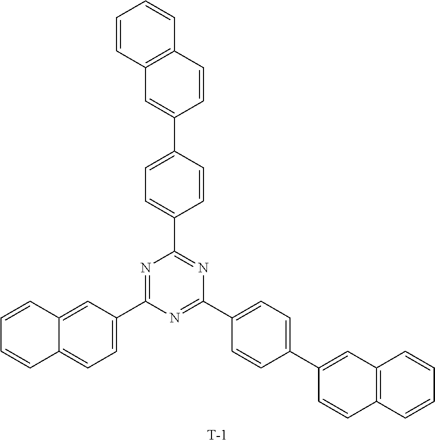 |
| | 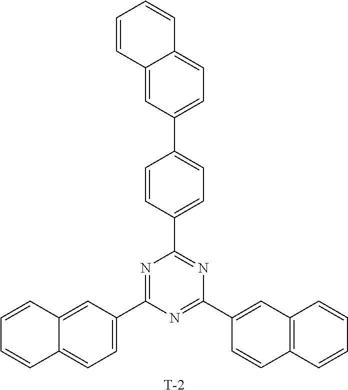 |
| | 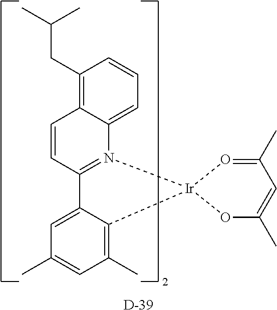 |
| | 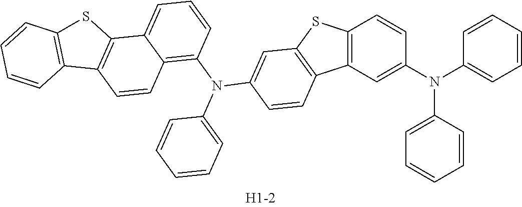 [SMILES: c1ccc(N(c2ccccc2)c2ccc3sc4cc(N(c5ccccc5)c5cccc6c5ccc5c7ccccc7sc65)ccc4c3c2)cc1] |
| | 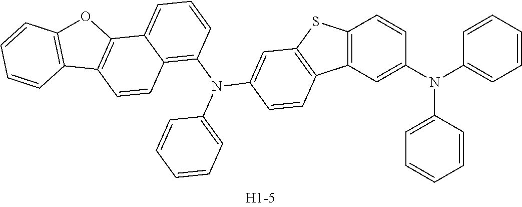 [SMILES: c1ccc(N(c2ccccc2)c2ccc3sc4cc(N(c5ccccc5)c5cccc6c5ccc5c7ccccc7oc65)ccc4c3c2)cc1] |
| | 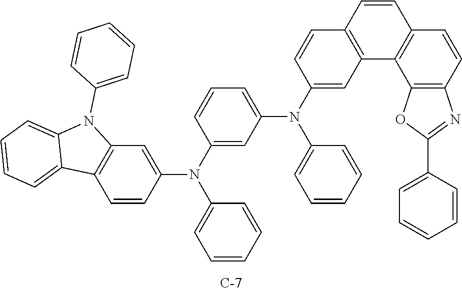 |
| | 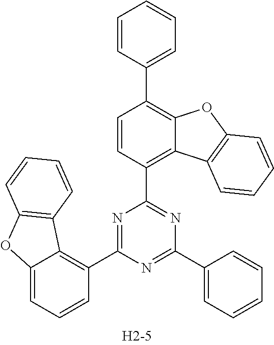 [SMILES: c1ccc(-c2nc(-c3cccc4oc5ccccc5c34)nc(-c3ccc(-c4ccccc4)c4oc5ccccc5c34)n2)cc1] |
| | 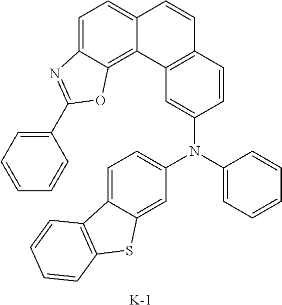 |
| | 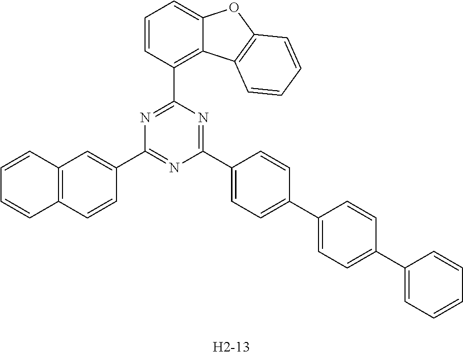 [SMILES: c1ccc(-c2ccc(-c3ccc(-c4nc(-c5ccc6ccccc6c5)nc(-c5cccc6oc7ccccc7c56)n4)cc3)cc2)cc1] |
| | 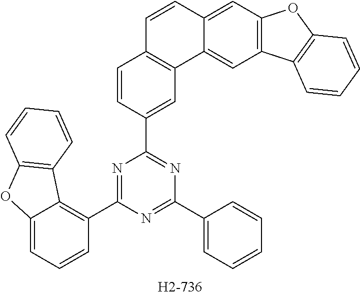 [SMILES: c1ccc(-c2nc(-c3ccc4ccc5cc6oc7ccccc7c6cc5c4c3)nc(-c3cccc4oc5ccccc5c34)n2)cc1] |
| | 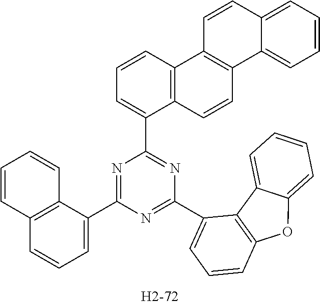 [SMILES: c1ccc2c(-c3nc(-c4cccc5c4ccc4c6ccccc6ccc54)nc(-c4cccc5oc6ccccc6c45)n3)cccc2c1] |
| | 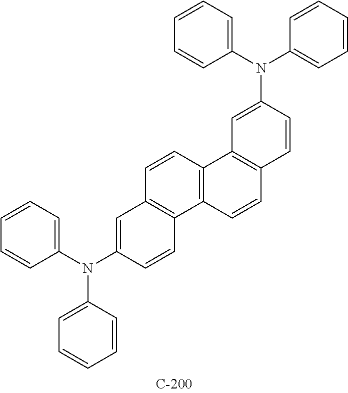 [SMILES: c1ccc(N(c2ccccc2)c2ccc3c(ccc4c5cc(N(c6ccccc6)c6ccccc6)ccc5ccc34)c2)cc1] |
| | 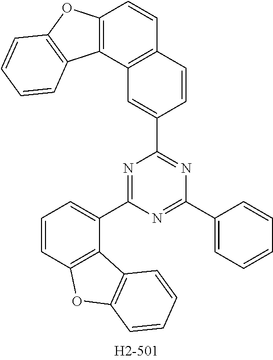 [SMILES: c1ccc(-c2nc(-c3ccc4ccc5oc6ccccc6c5c4c3)nc(-c3cccc4oc5ccccc5c34)n2)cc1] |
| | 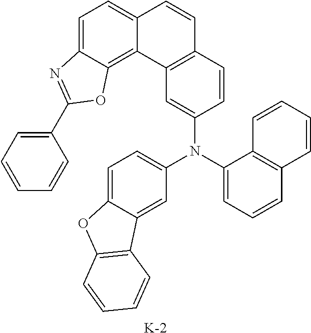 |
| | 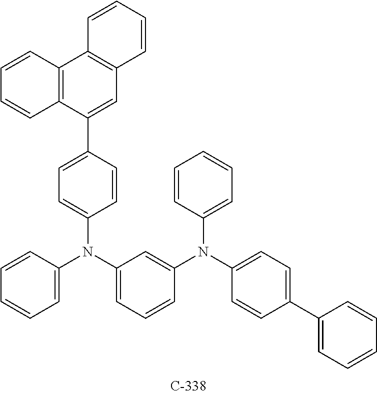 [SMILES: c1ccc(-c2ccc(N(c3ccccc3)c3cccc(N(c4ccccc4)c4ccc(-c5cc6ccccc6c6ccccc56)cc4)c3)cc2)cc1] |
| Electron Transport Layer/Electron Injection Layer | 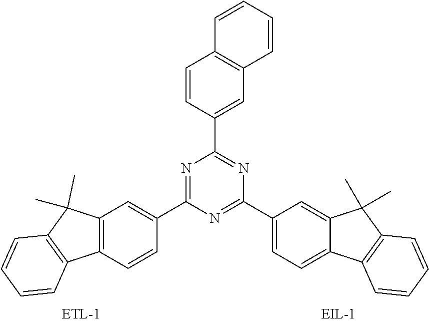 [SMILES: CC1(C)c2ccccc2-c2ccc(-c3nc(-c4ccc5c(c4)C(C)(C)c4ccccc4-5)nc(-c4ccc5ccccc5c4)n3)cc21] |
| | 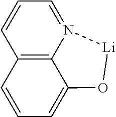 |

1. A plurality of host materials comprising at least one first host compound and at least one second host compound, wherein the first host compound is represented by the following formula 1 and the second host compound is represented by the following formula 2: 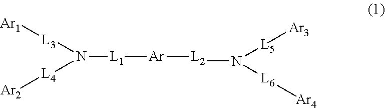
wherein
Ar represents a substituted or unsubstituted (C6-C30)arylene or a substituted or unsubstituted (3- to 30-membered)heteroarylene;
L₁ to L₆ each independently represent, a single bond, a substituted or unsubstituted (C6-C30)arylene, a substituted or unsubstituted (C3-C30)cycloalkylene, or a substituted or unsubstituted (3- to 30-membered)heteroarylene; and
Ar₁ to Ar₄ each independently represent, deuterium, a substituted or unsubstituted (C1-C30)alkyl, a substituted or unsubstituted (C6-C30)aryl, a substituted or unsubstituted fused ring of (C3-C30) aliphatic ring and (C6-C30) aromatic ring, or a substituted or unsubstituted (3- to 30-membered)heteroaryl; or may be linked to the adjacent substituents to form a ring(s); 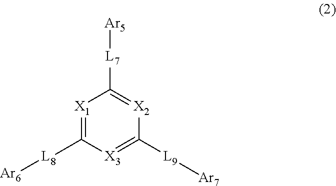
wherein
X₁ to X₃ each independently represent, N or CH,
L₇ to L₉ each independently represent, a single bond, a substituted or unsubstituted (C6-C30)arylene, a substituted or unsubstituted (C3-C30)cycloalkylene, or a substituted or unsubstituted (3- to 30-membered)heteroarylene;
Ar₅ to Ar₇ each independently represent, hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or —N—(R′)(R″); or may be linked to the adjacent substituents to form a ring(s); provided that at least one of Ar₅ to Ar₇ is(are) a substituted or unsubstituted (3- to 30-membered)heteroaryl; and
R′ and R″ each independently represent, a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl.

2. The plurality of host materials according to claim 1, wherein Ar₁ to Ar₄ in formula 1 and Ar₅ to Ar₇ in formula 2 each independently represent, a substituted or unsubstituted phenyl, a substituted or unsubstituted naphthyl, a substituted or unsubstituted biphenyl, a substituted or unsubstituted terphenyl, a substituted or unsubstituted dibenzofuranyl, a substituted or unsubstituted dibenzothiophenyl, a substituted or unsubstituted fluorenyl, a substituted or unsubstituted carbazolyl, a substituted or unsubstituted phenanthrenyl, a substituted or unsubstituted benzophenanthrenyl, a substituted or unsubstituted chrysenyl, a substituted or unsubstituted triphenylenyl, a substituted or unsubstituted benzocarbazolyl, a substituted or unsubstituted benzonaphthofuranyl, a substituted or unsubstituted benzonaphthothiophenyl, a substituted or unsubstituted benzofluorenyl, a substituted or unsubstituted benzothiazolyl, a substituted or unsubstituted benzoxazolyl, a substituted or unsubstituted benzimidazolyl, a substituted or unsubstituted naphthooxazolyl, a substituted or unsubstituted benzonaphthooxazolyl, a substituted or unsubstituted naphthothiazolyl, a substituted or unsubstituted benzonaphthothiazolyl, or a substituted or unsubstituted naphthoimidazolyl.

3. The plurality of host materials according to claim 1, wherein at least one of Ar₁ to Ar₄ in formula 1 is selected from the following formulas 1-1 to 1-20, and at least one of Ar₅ to Ar₇ in formula 2 is selected from the following formulas 1-1 to 1-26: 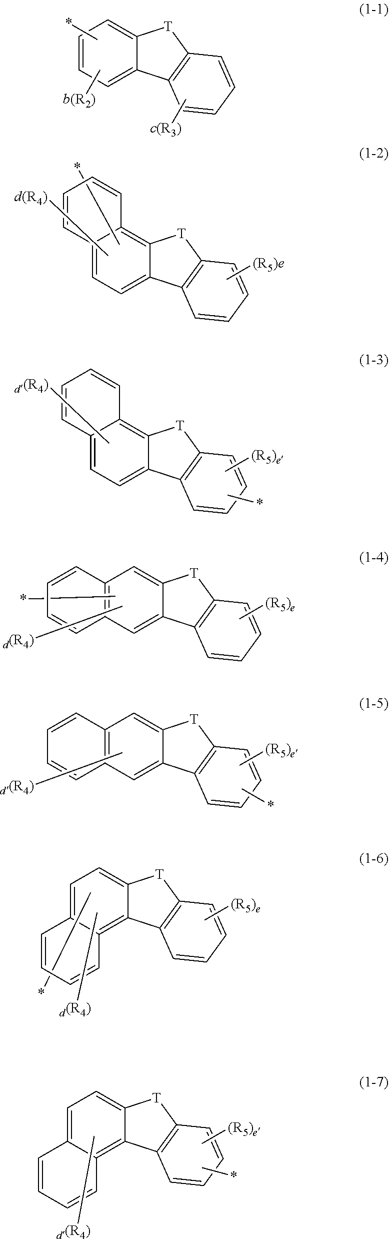 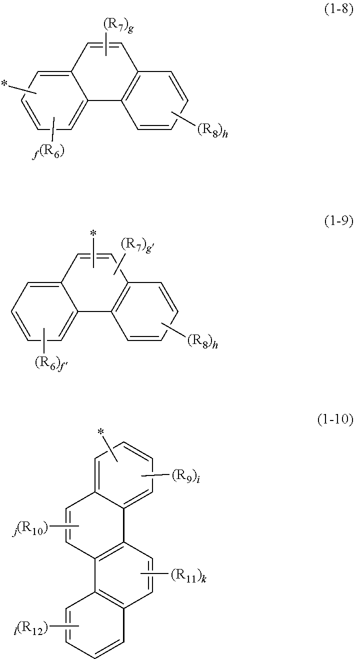 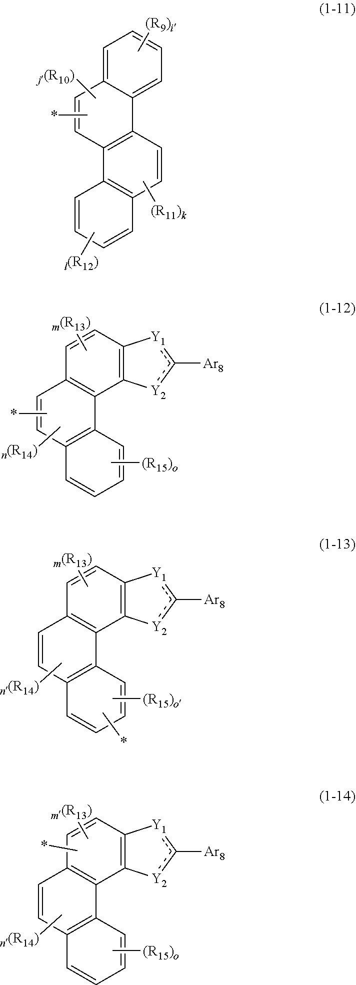 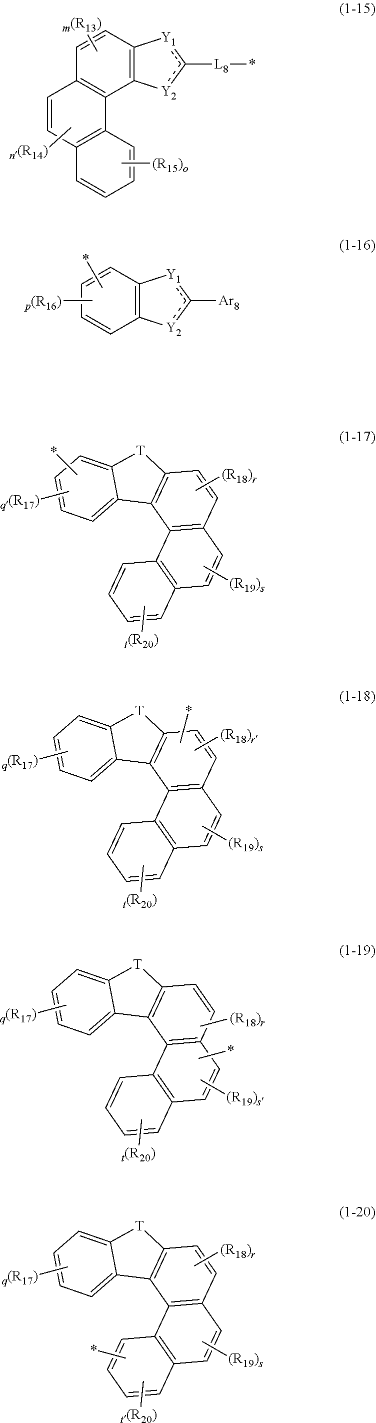 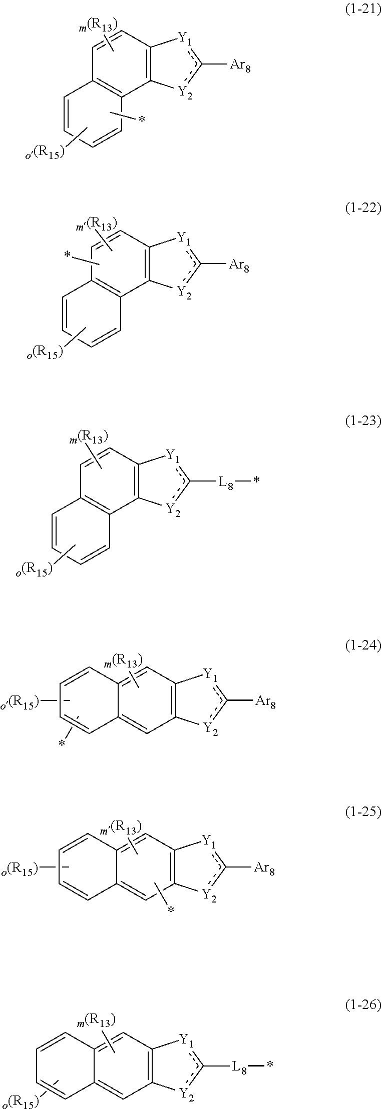
wherein
T represents —O—, —S—, —Se—, —CR₂₁R₂₂—, or —NR₂₃—;
Y₁ and Y₂ each independently represent, —N═, —NR₂₄—, —O—, —S— or —Se—; proived that any one of Y₁ and Y₂ is —N═, and the other of Y₁ and Y₂ is —NR₂₄—, —O—, —S—, or —Se—;
R₂ to R₂₀ each independently represent, hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or —N—(R′)(R″); or may be linked to the adjacent substituents to form a ring(s);
R′ and R″ each independently represent, a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl;
R₂₁ to R₂₄ each independently represent, a substituted or unsubstituted (C1-C30)alkyl, a substituted or unsubstituted (C6-C30)aryl, or a substituted or unsubstituted (3- to 30-membered)heteroaryl; or may be linked to the adjacent substituents to form a ring(s);
Ar₈ represents a substituted or unsubstituted (C6-C30)aryl or a substituted or unsubstituted (3- to 30-membered)heteroaryl;
L₈ represents a single bond, a substituted or unsubstituted (C6-C30)arylene, or a substituted or unsubstituted (3- to 30-membered)heteroarylene;
b, e′, f, i, o′, p, q′, and t′ are an integer of 1 to 3; c, e, h, f′, l, i′, o, q, and t are an integer of 1 to 4; d is an integer of 1 to 5; d′ is an integer of 1 to 6; g, j, k, m, n′, r, and s are an integer of 1 or 2; g′, j′, m′, n, r′, and s′ are an integer of 1;
when b to m, o to t, d′ to f′, i′, n′, o′, q′, and t′ are an integer of 2 or more, each of R₂ to R₂₀ may be the same or different; and
* represents a linking site with L₃ to L₆ in formula 1 or L₇ to L₉ in formula 2.

4. The plurality of host materials according to claim 1, wherein Ar in formula 1 represents a substituted or unsubstituted phenylene, a substituted or unsubstituted fluorenylene, a substituted or unsubstituted dihydrophenanthrenylene, a substituted or unsubstituted spirobifluorenylene, a substituted or unsubstituted dibenzofuranylene, a substituted or unsubstituted dibenzothiophenylene, a substituted or unsubstituted carbazolylene, a substituted or unsubstituted phenanthrenylene, a substituted or unsubstituted chrysenylene, a substituted or unsubstituted benzocarbazolylene, a substituted or unsubstituted benzonaphthofuranylene, a substituted or unsubstituted benzonaphthothiophenylene, a substituted or unsubstituted benzofluorenylene, a substituted or unsubstituted benzothiazolylene, a substituted or unsubstituted benzoxazolylene, a substituted or unsubstituted benzimidazolylene, a substituted or unsubstituted naphthooxazolylene, a substituted or unsubstituted benzonaphthooxazolylene, a substituted or unsubstituted naphthothiazolylene, a substituted or unsubstituted benzonaphthothiazolylene, or a substituted or unsubstituted naphthoimidazolylene.

5. The plurality of host materials according to claim 1, wherein Ar in formula 1 is selected from the following formulas 1-1-1 to 1-1-21: 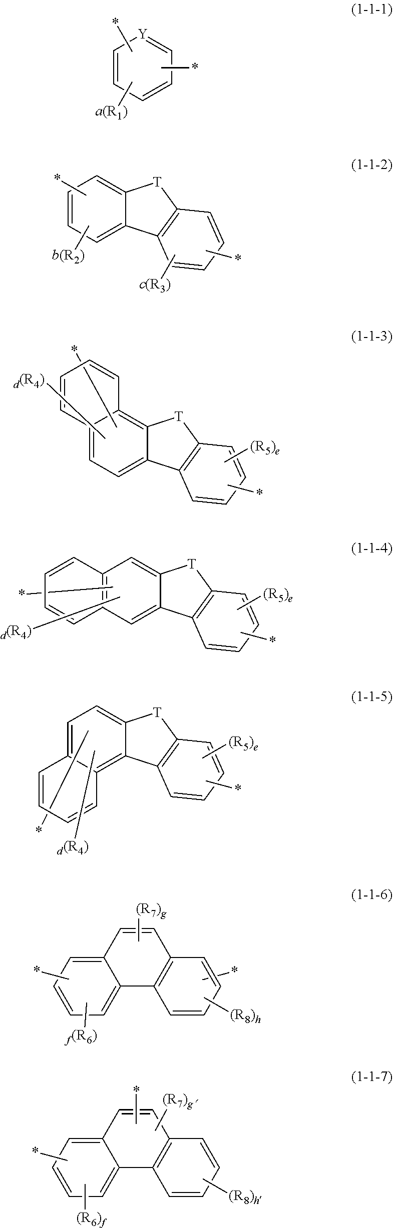 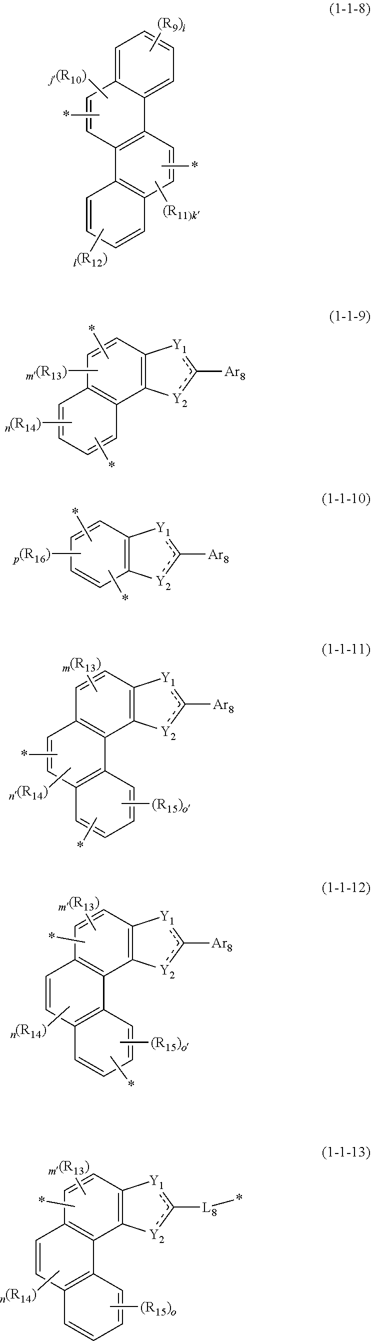 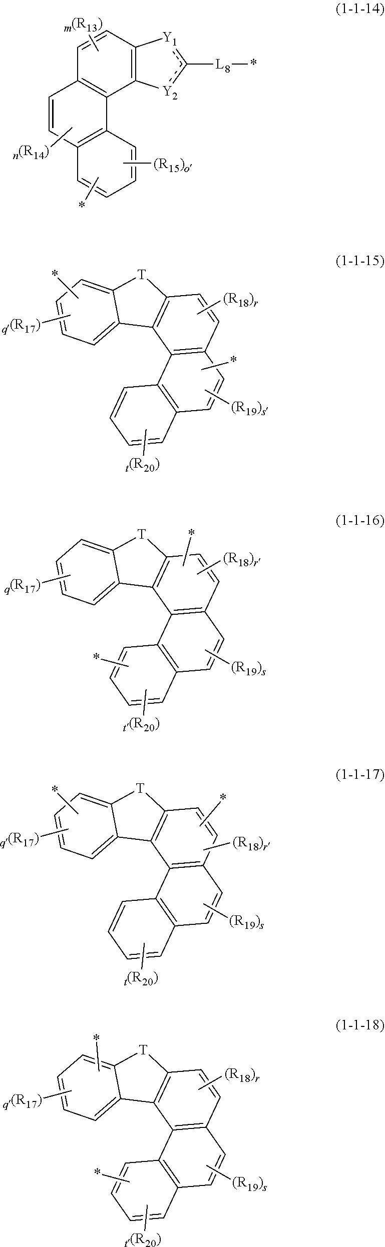 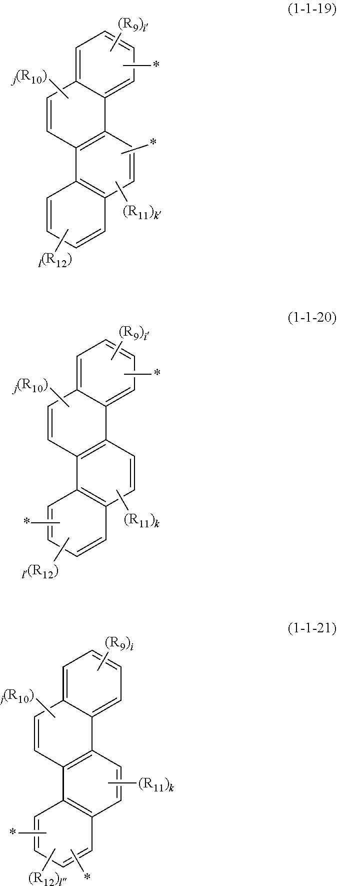
wherein
T represents —O—, —S—, —CR₂₁R₂₂—, or —NR₂₃—;
Y represents CH or N;
Y₁ and Y₂ each independently represent, —N═, —NR₂₄—, —O— —S—, or —Se—; provided that any one of Y₁ and Y₂ is —N═, and the other of Y₁ and Y₂ is —NR₂₄—, —O—, —S—, or —Se—;
R₁ to R₂₀ each independently represent, hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or —N—(R′)(R″); or may be linked to the adjacent substituents to form a ring(s);
R′ and R″ each independently represent, a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl;
R₂₁ to R₂₄ each independently represent, a substituted or unsubstituted (C1-C30)alkyl, a substituted or unsubstituted (C6-C30)aryl, or a substituted or unsubstituted (3- to 30-membered)heteroaryl; or may be linked to the adjacent substituents to form a ring(s);
Ar₈ represents a substituted or unsubstituted (C6-C30)aryl or a substituted or unsubstituted (3- to 30-membered)heteroaryl;
L₈ represents a single bond, a substituted or unsubstituted (C6-C30)arylene, or a substituted or unsubstituted (3- to 30-membered)heteroarylene;
h′, i, l, o, q, and t are an integer of 1 to 4; a, b, c, e, f, h, i′, l′, o′, q′, and t′ are an integer of 1 to 3; d is an integer of 1 to 5; g, j, k, l″, m, n, p, r and s are an integer of 1 or 2; g′, j′, k′, m′, n′, r′ and s′ are 1;
when a to t, h′, i′, l′, l″, o′, q′, and t′ are an integer of 2 or more, each of R₁ to R₂₀ may be the same or different; and
* represents a linking site with L₁ and L₂ in formula 1.

6. The plurality of host materials according to claim 1, wherein the compound represented by the formula 1 is selected from the following compounds:

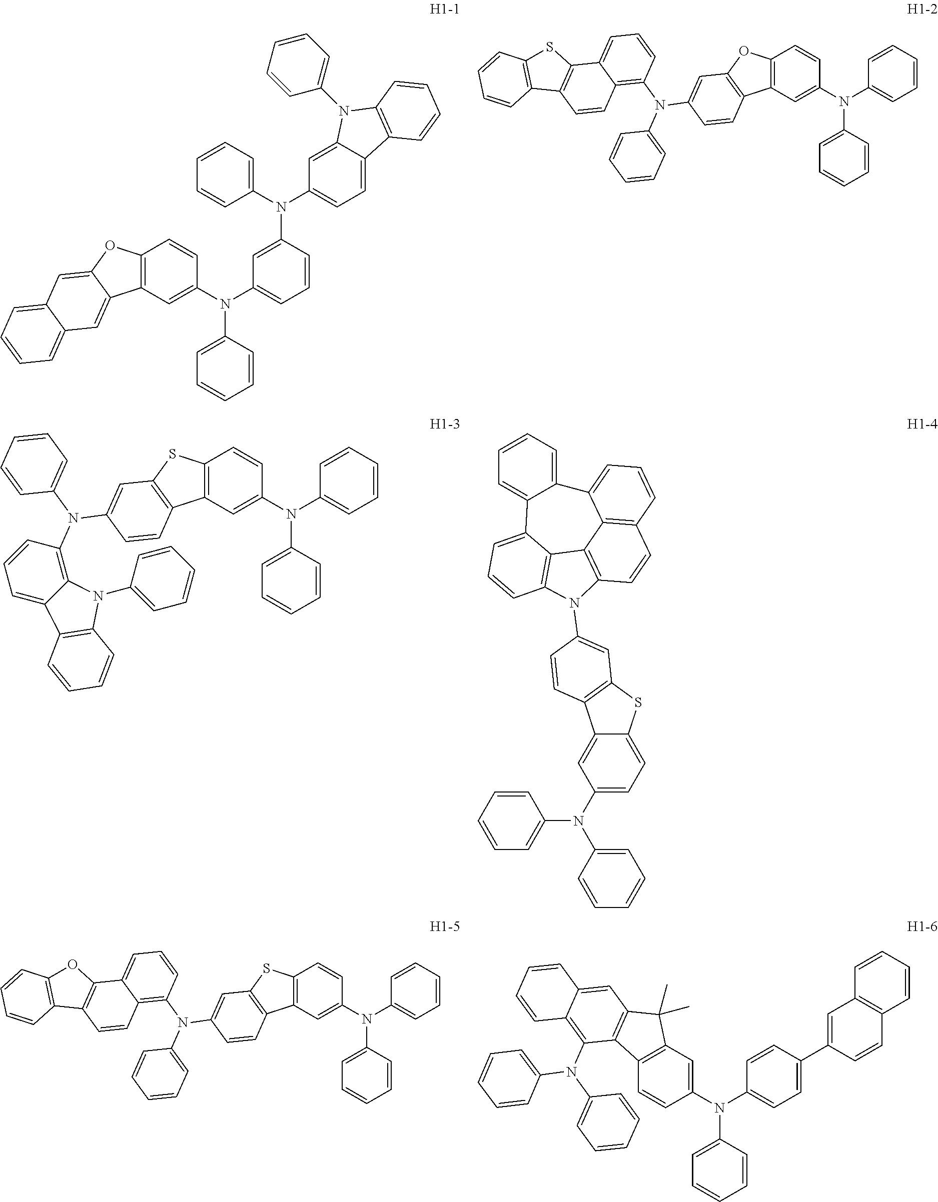

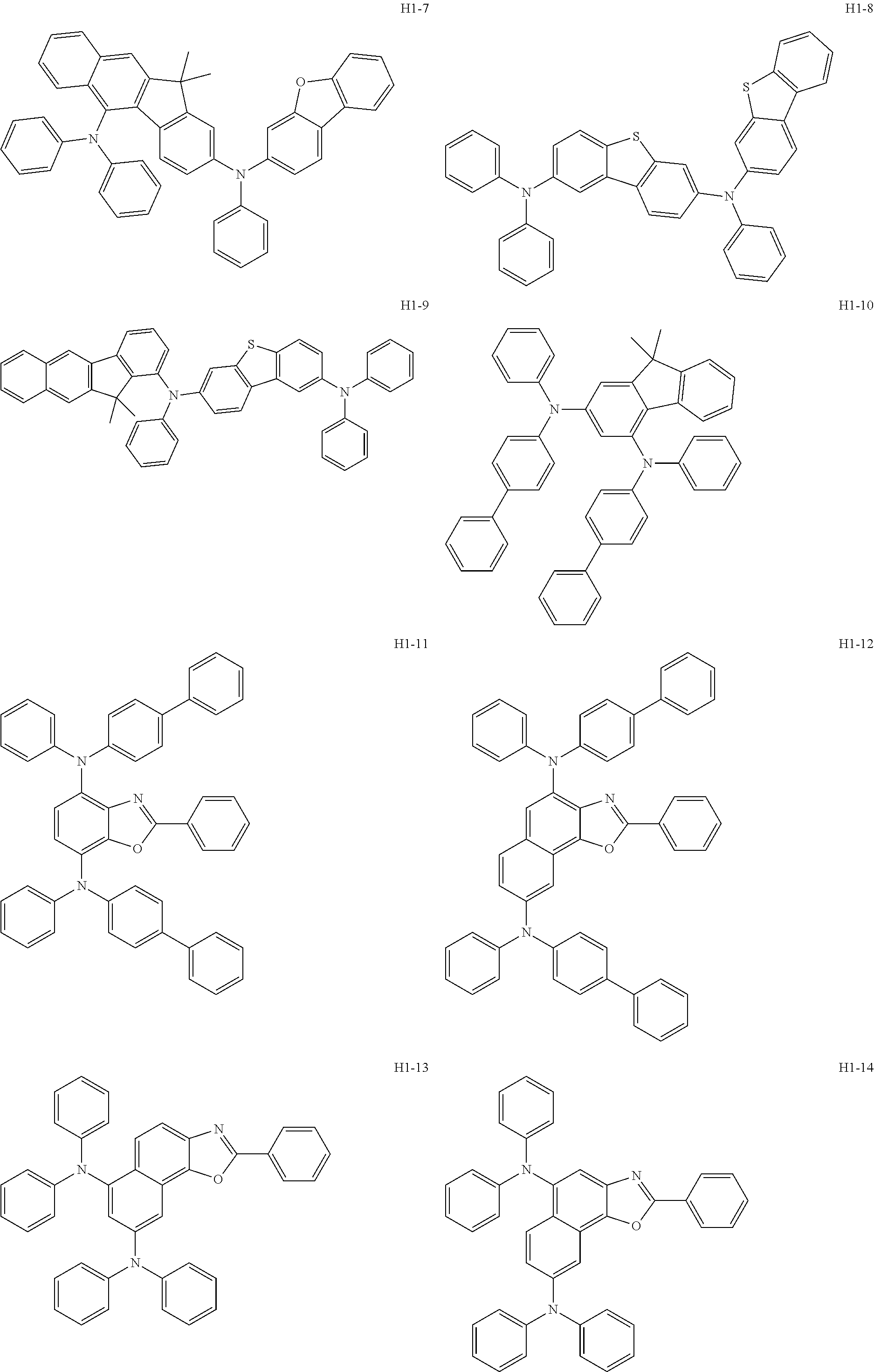

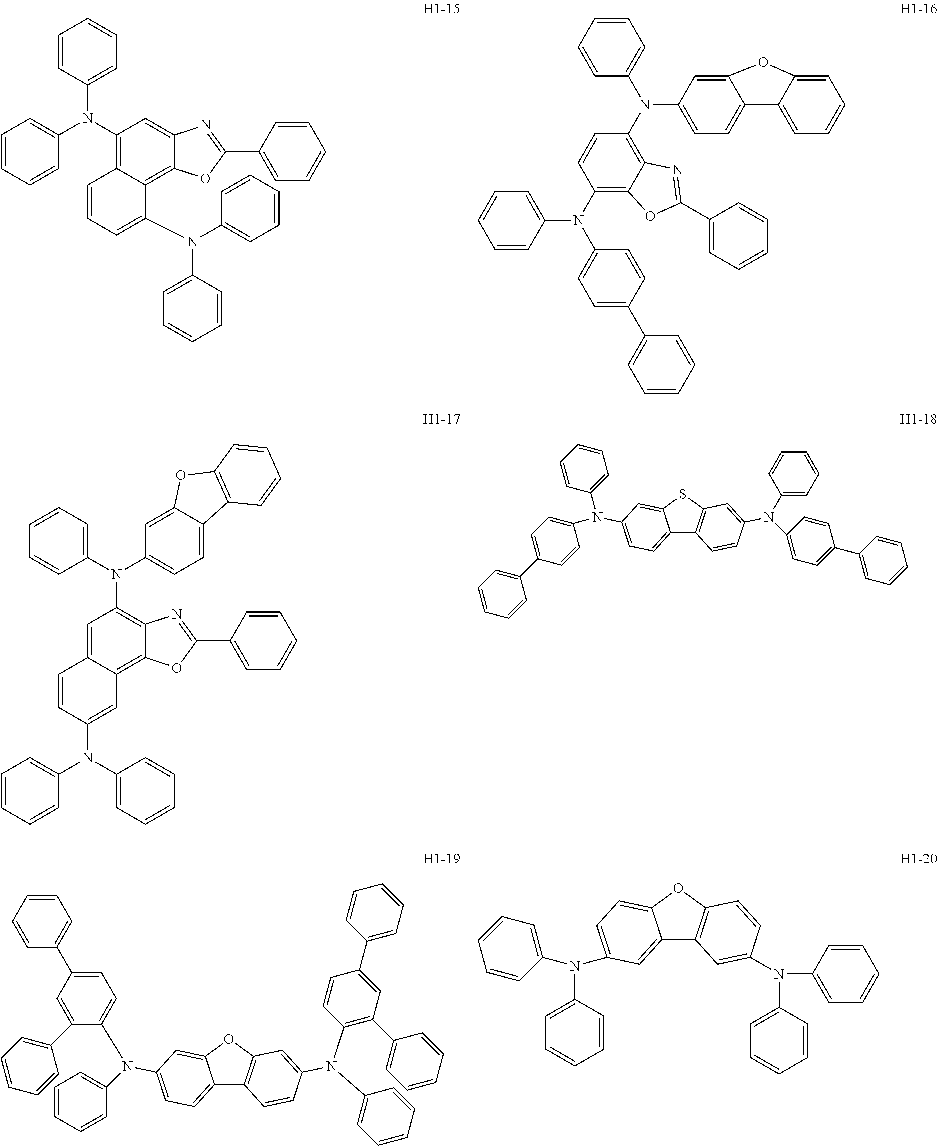

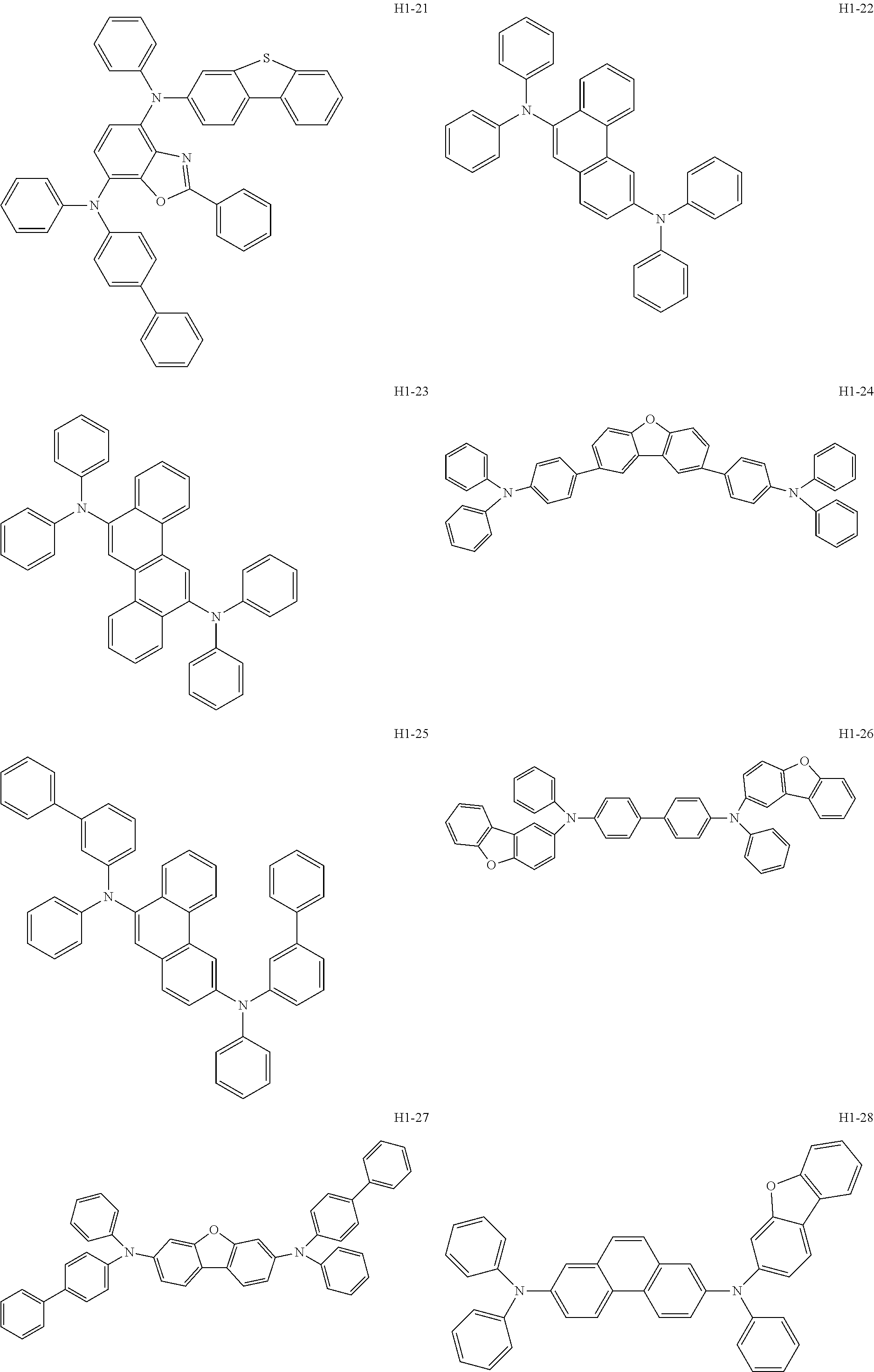

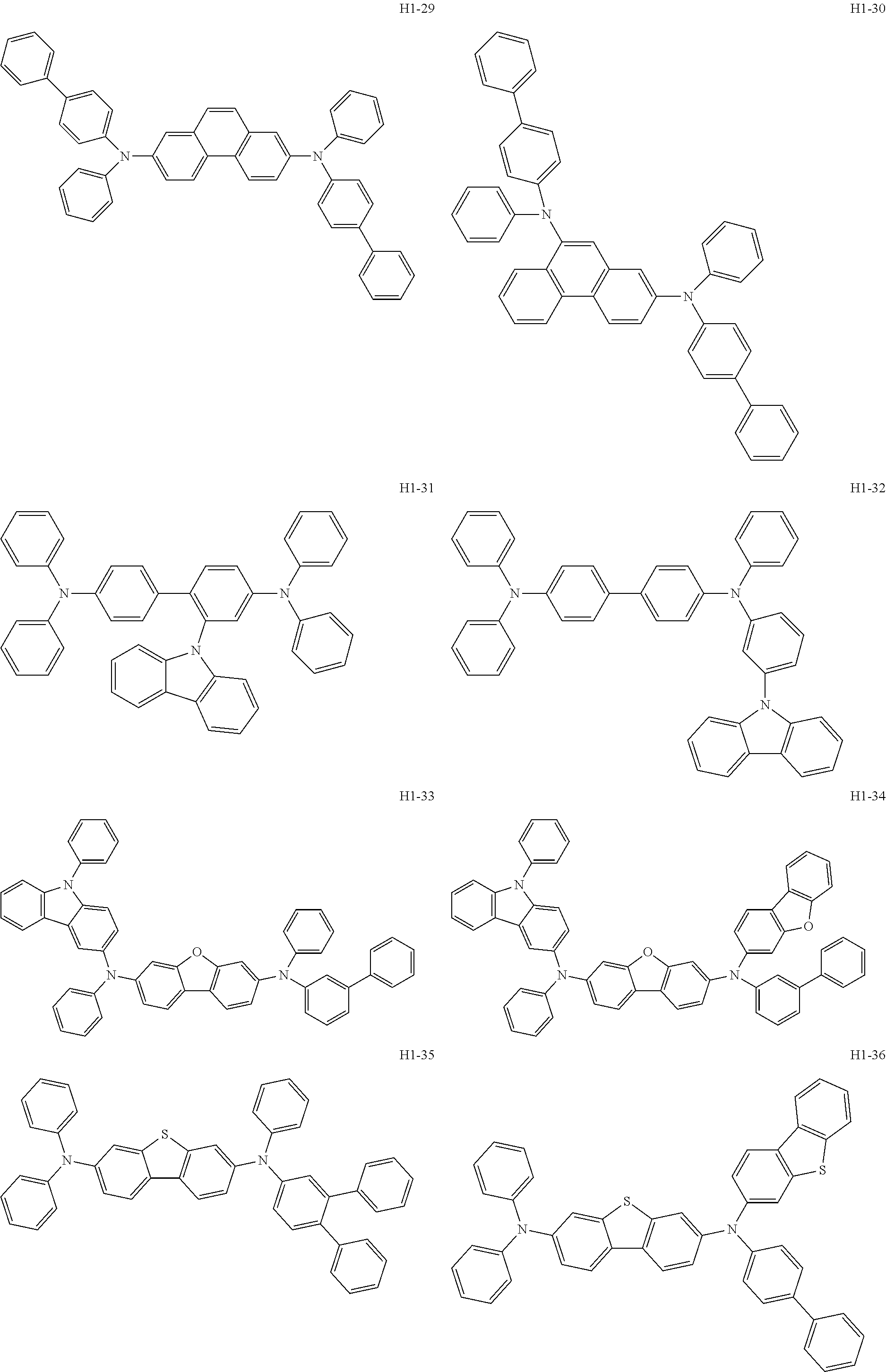

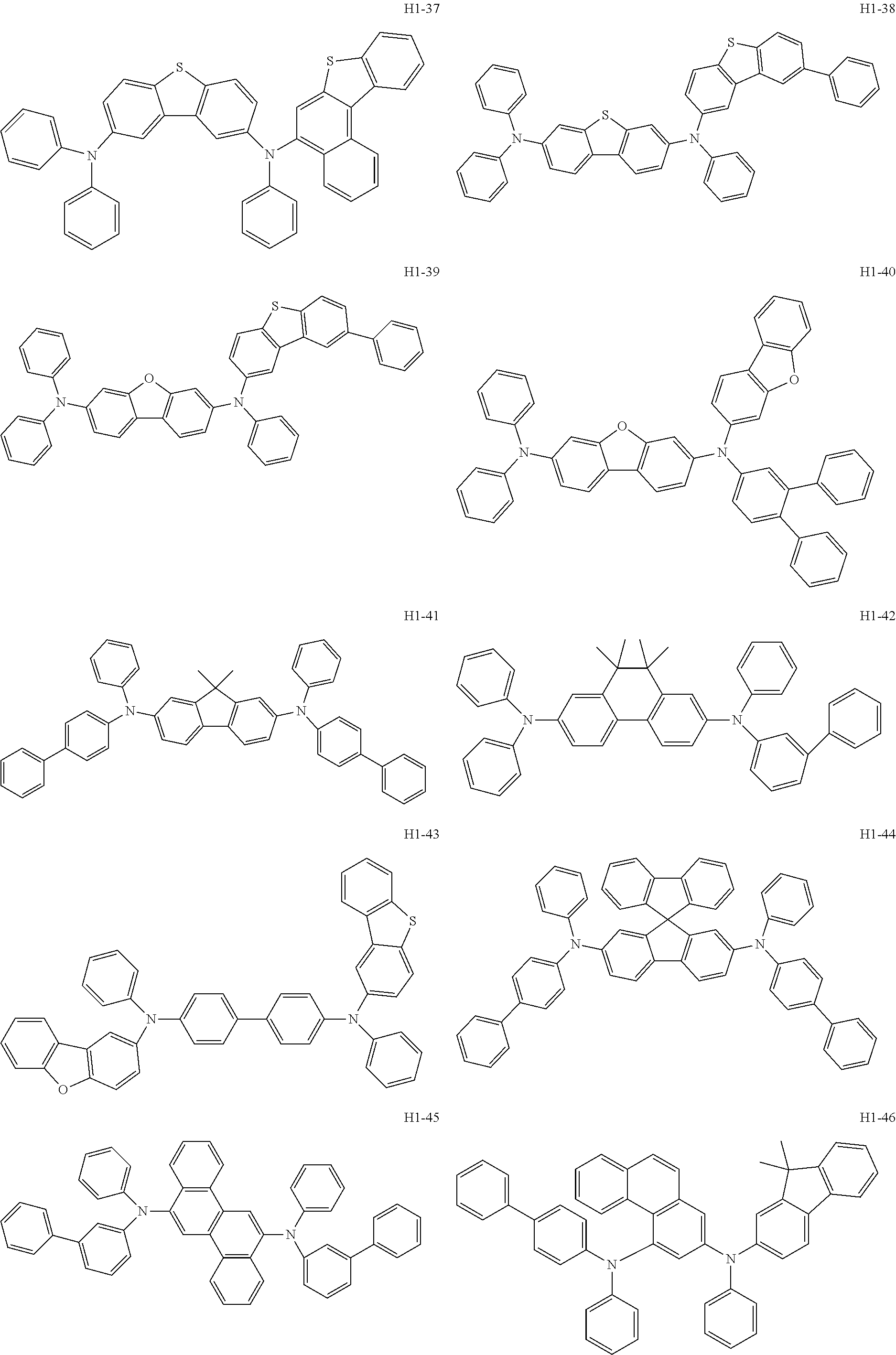

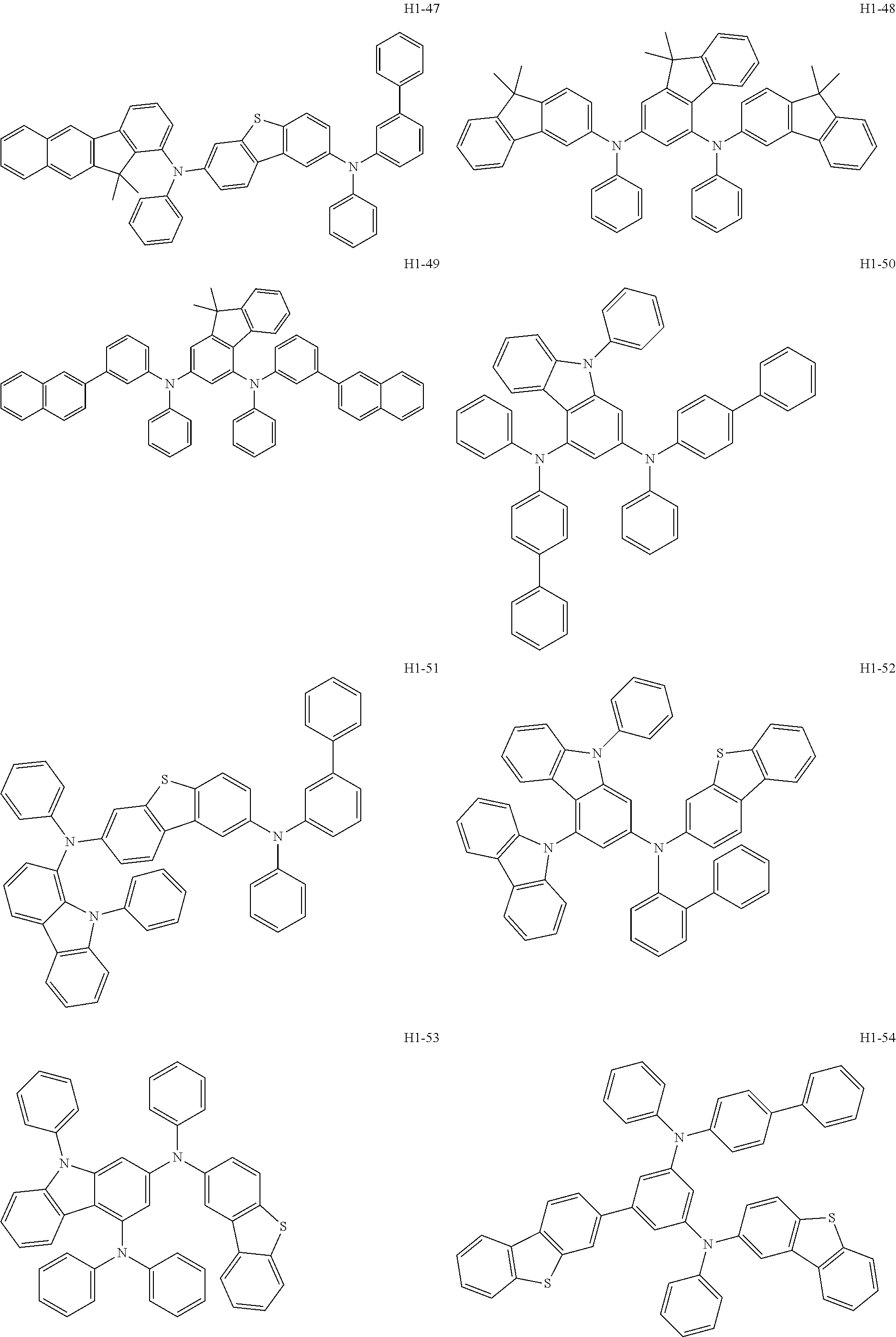

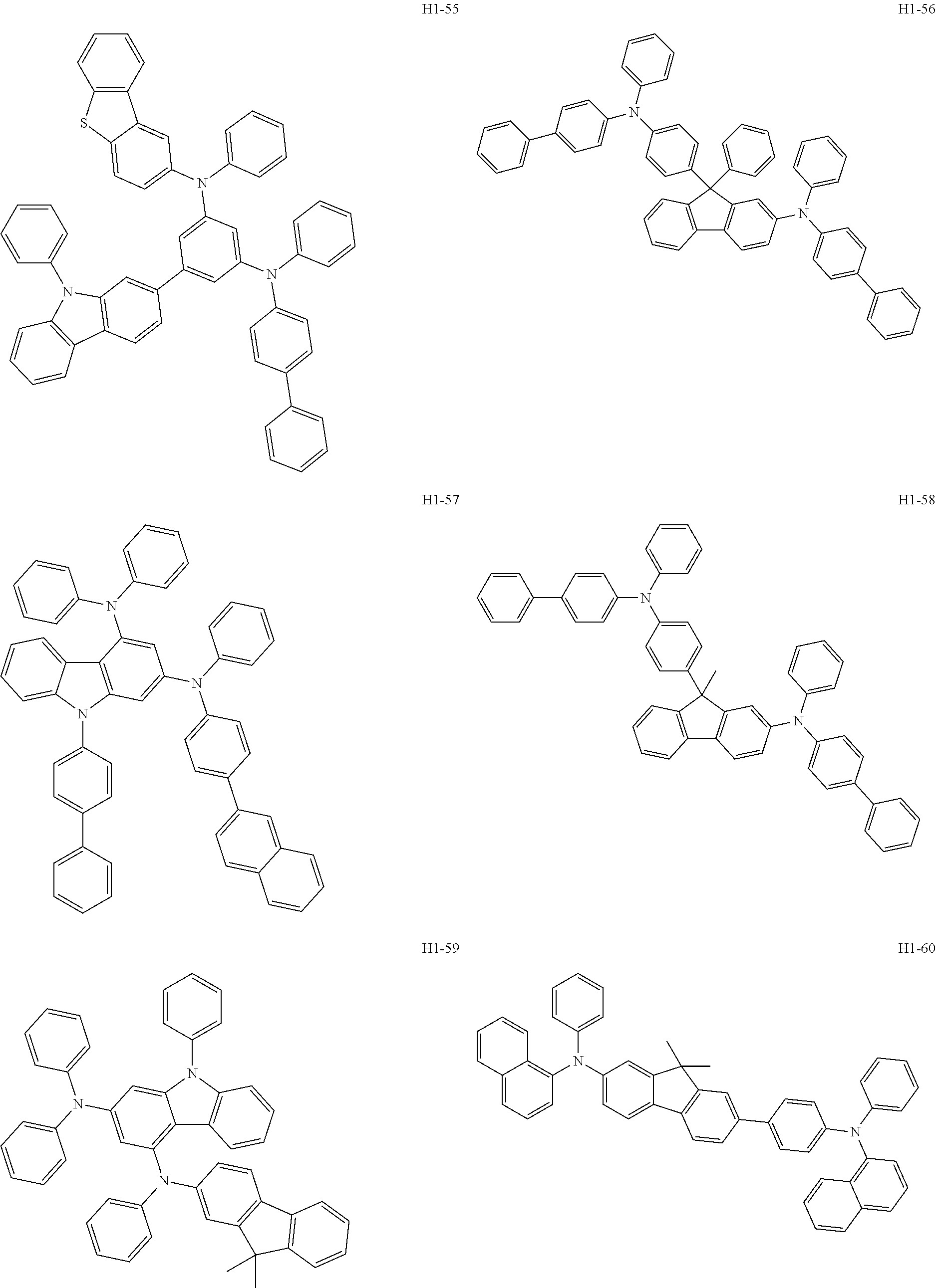

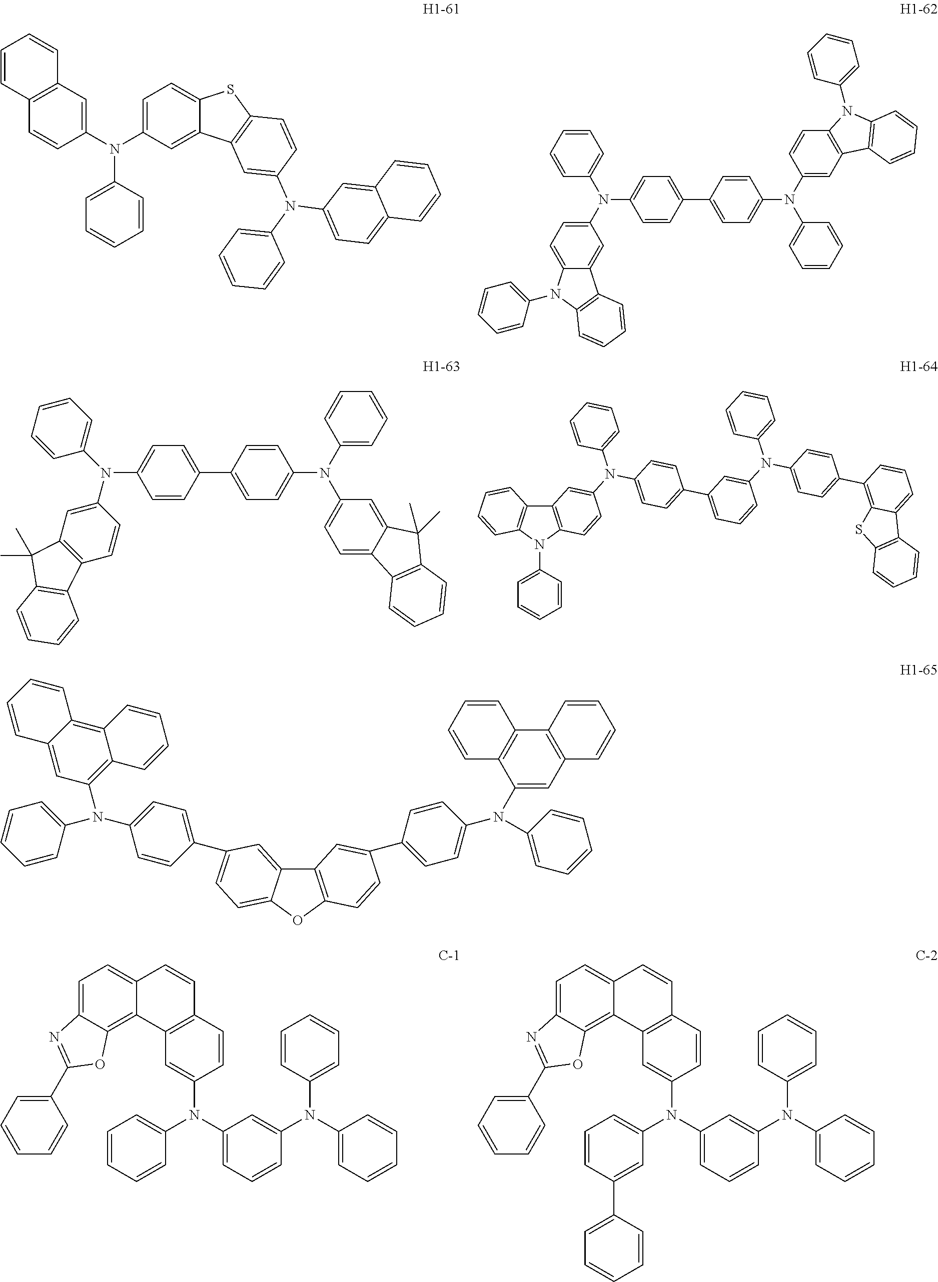

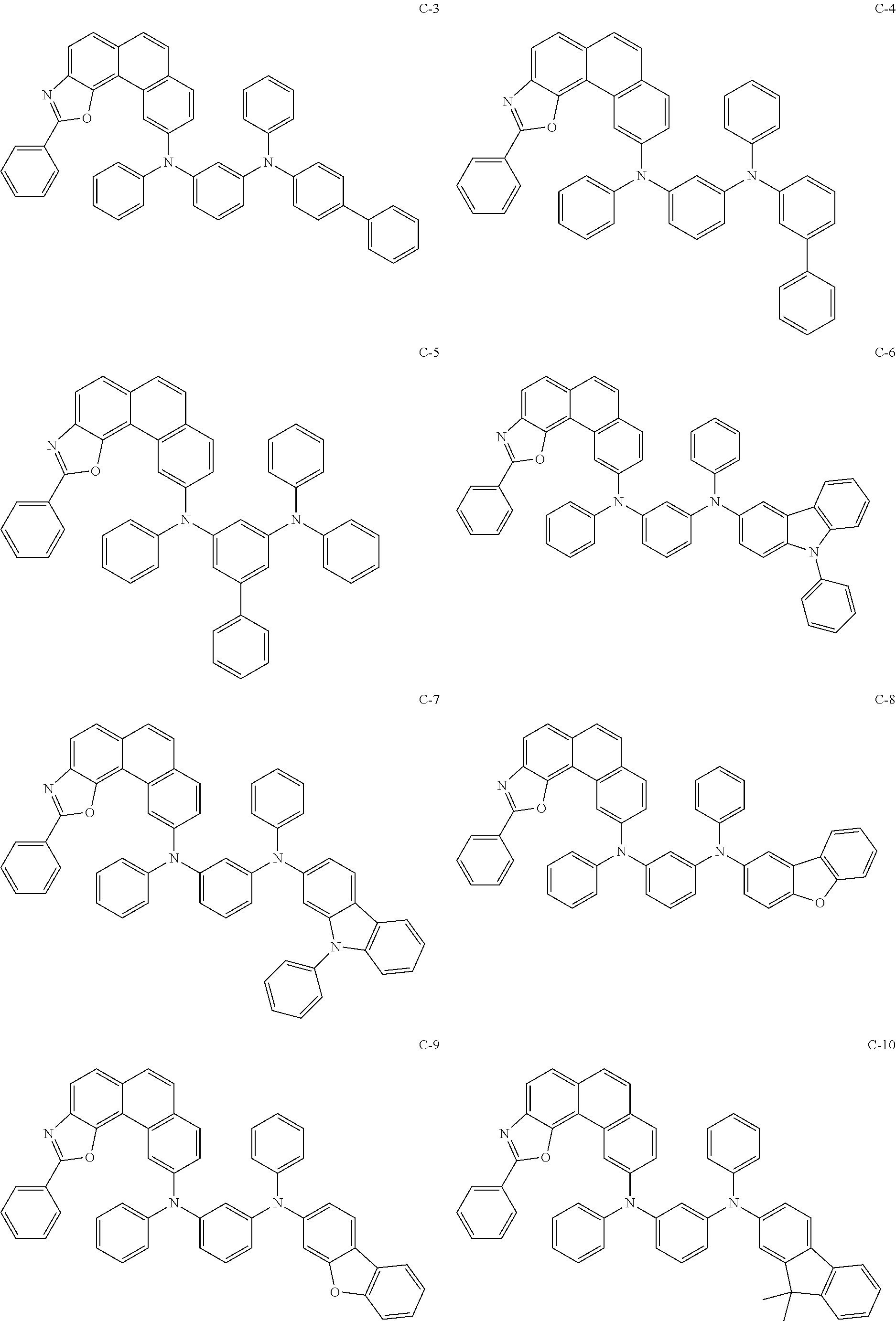

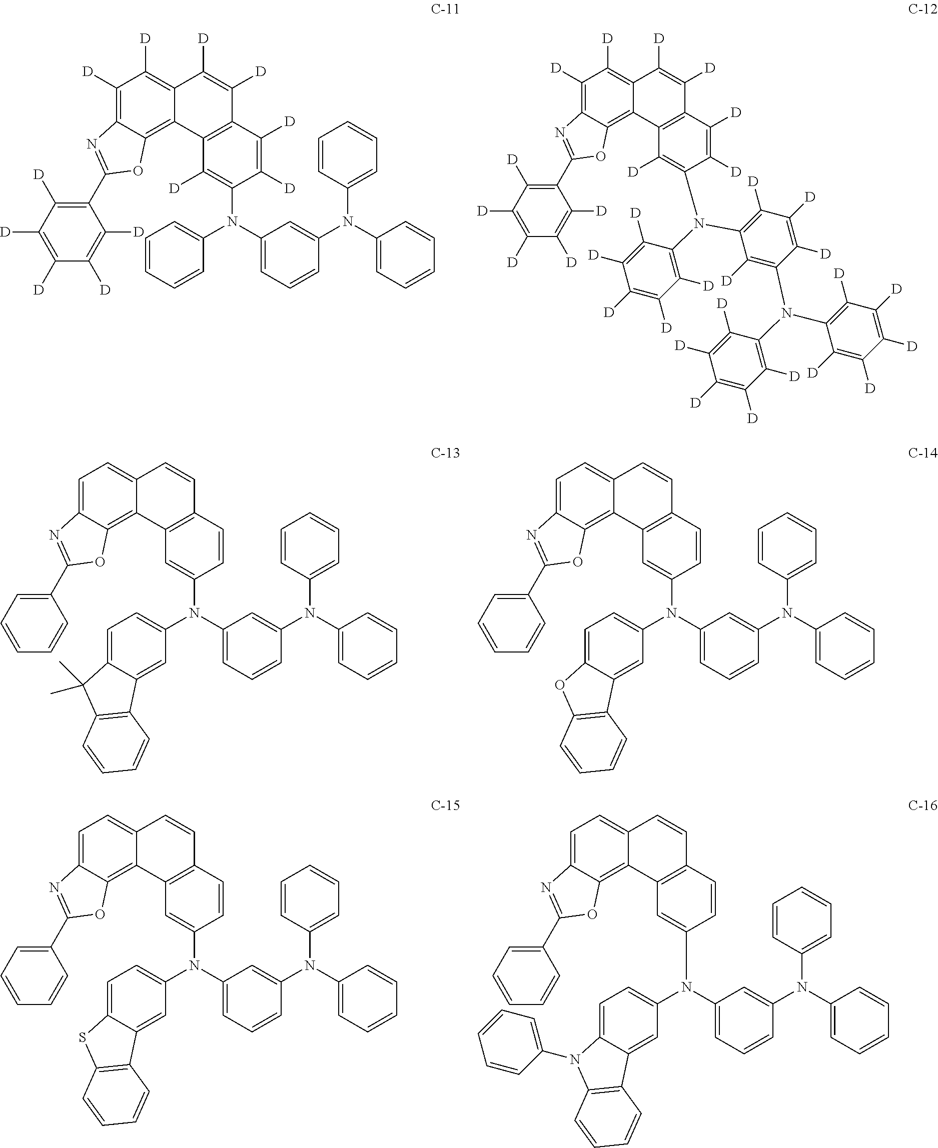

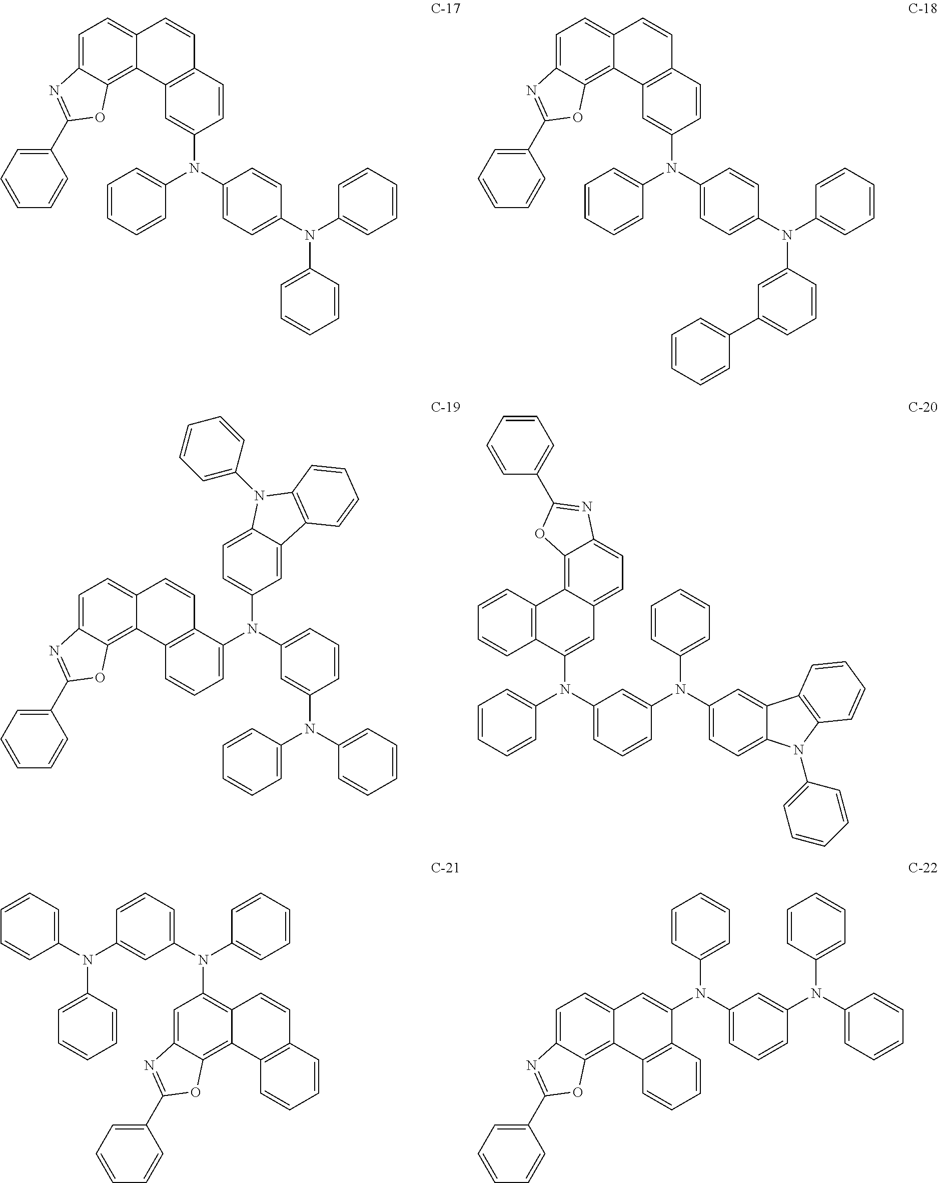

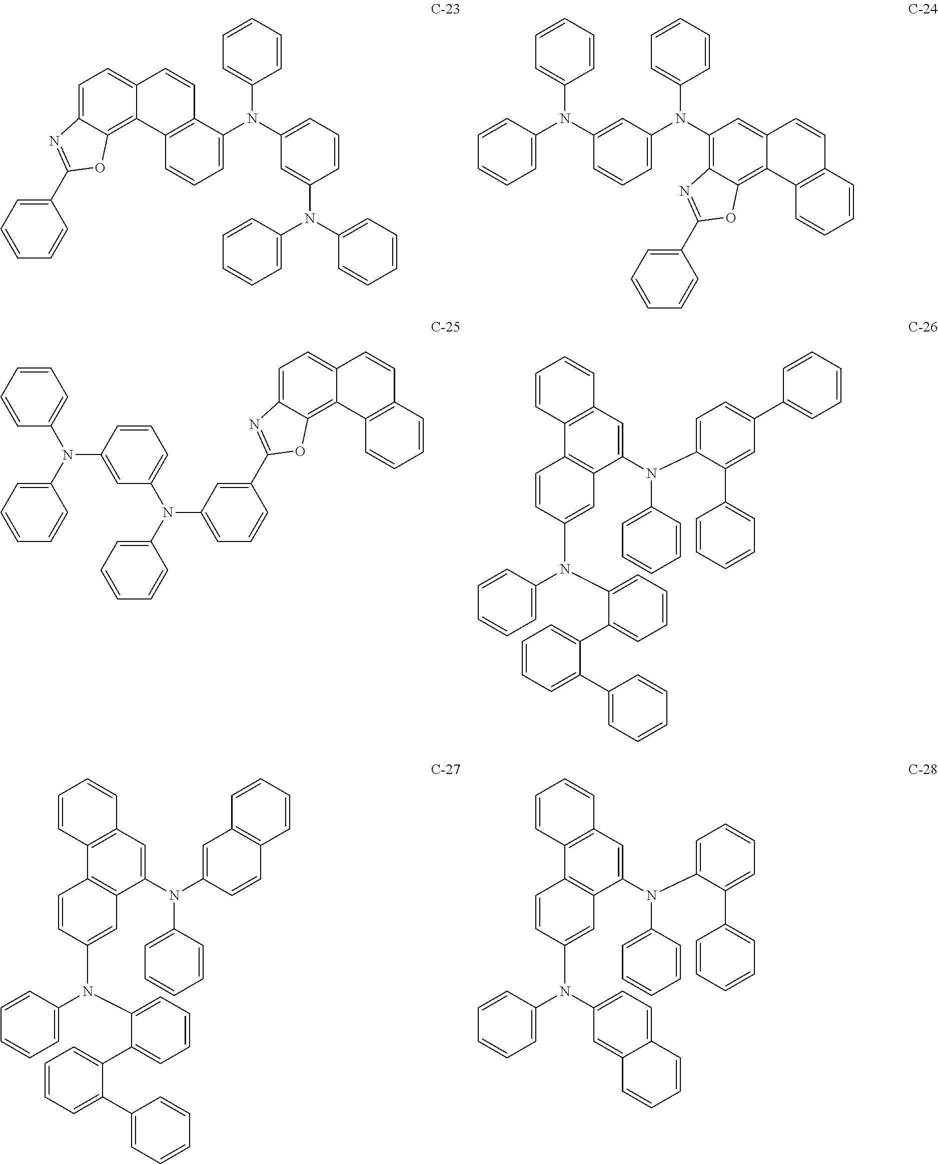

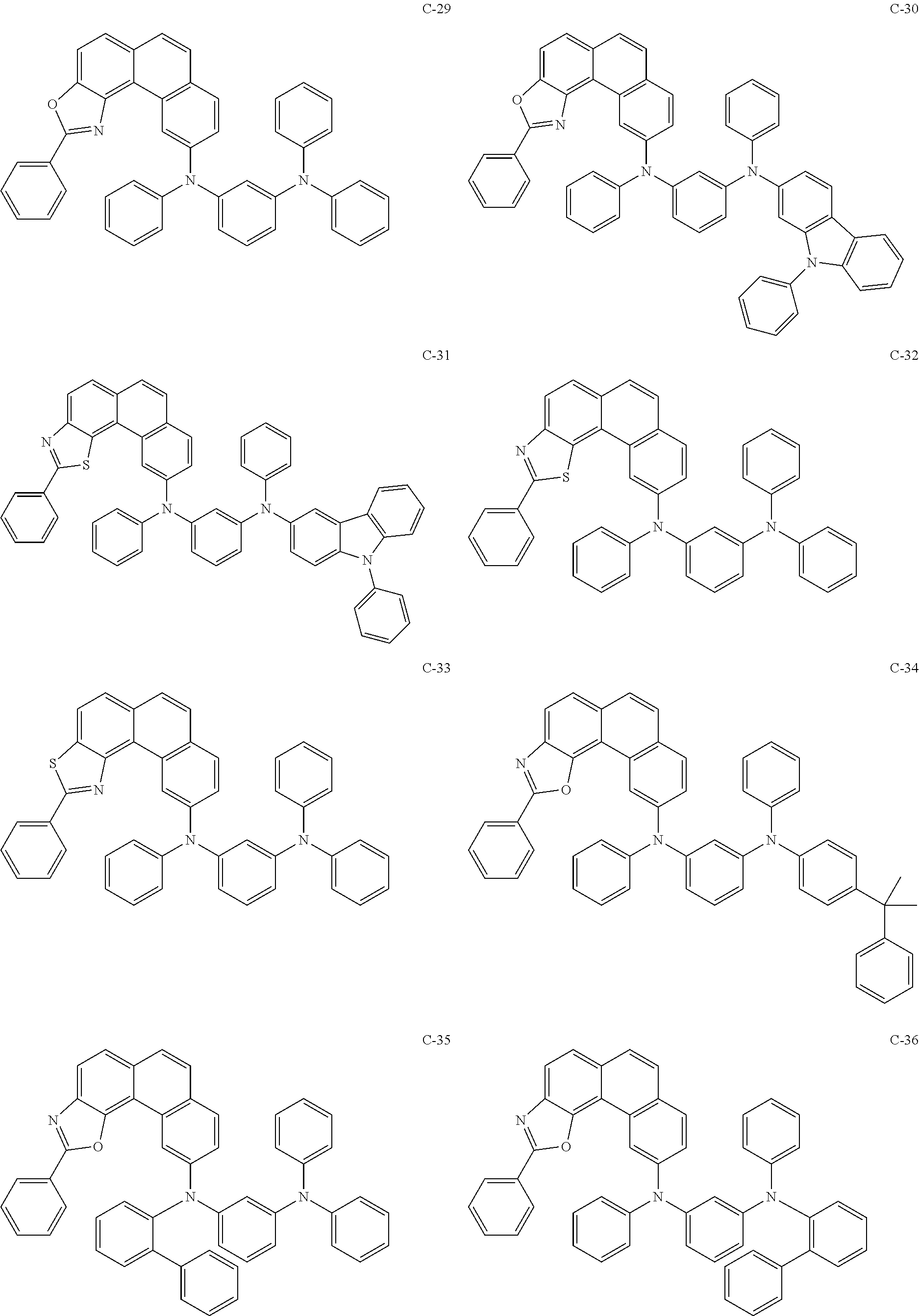

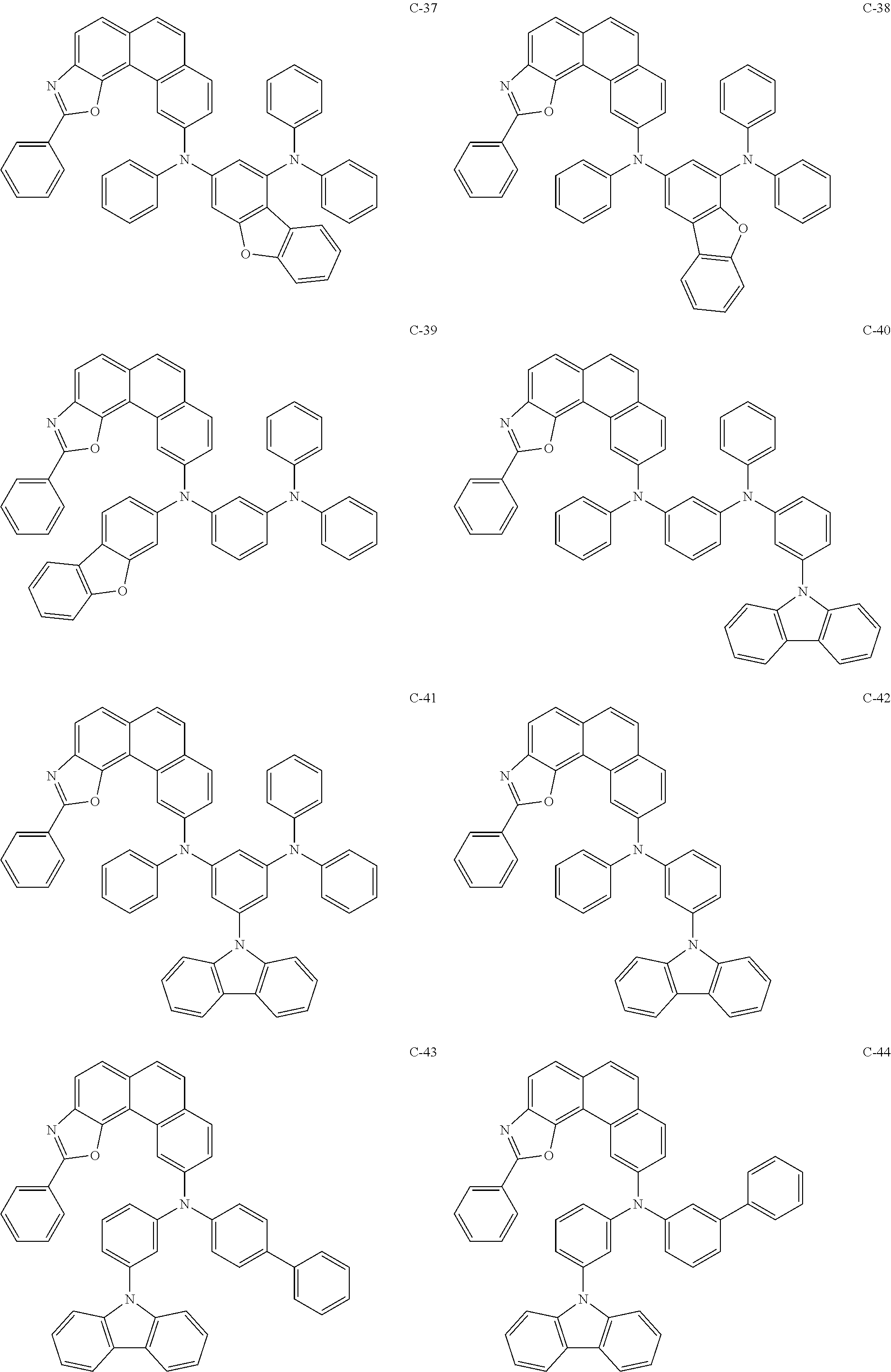

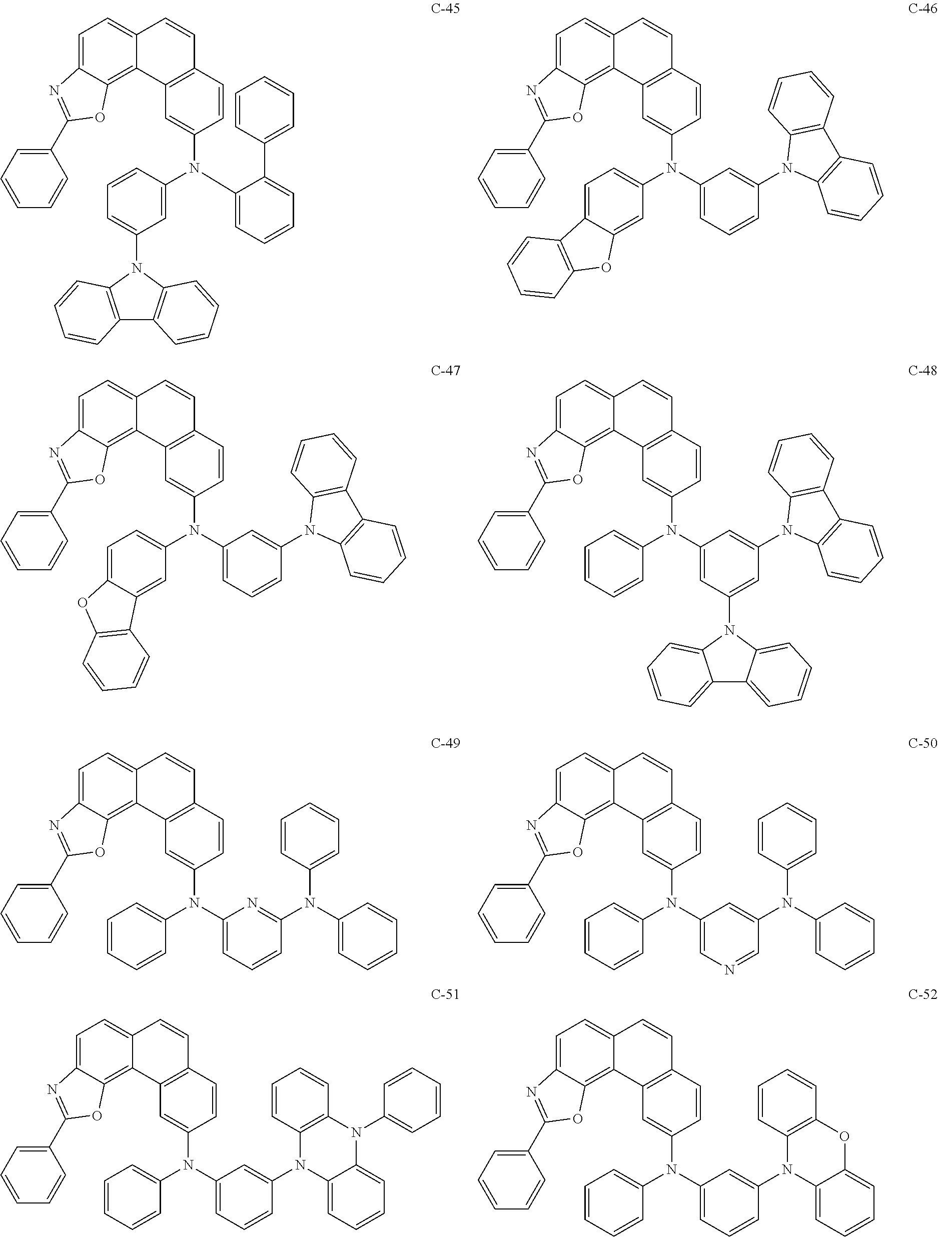

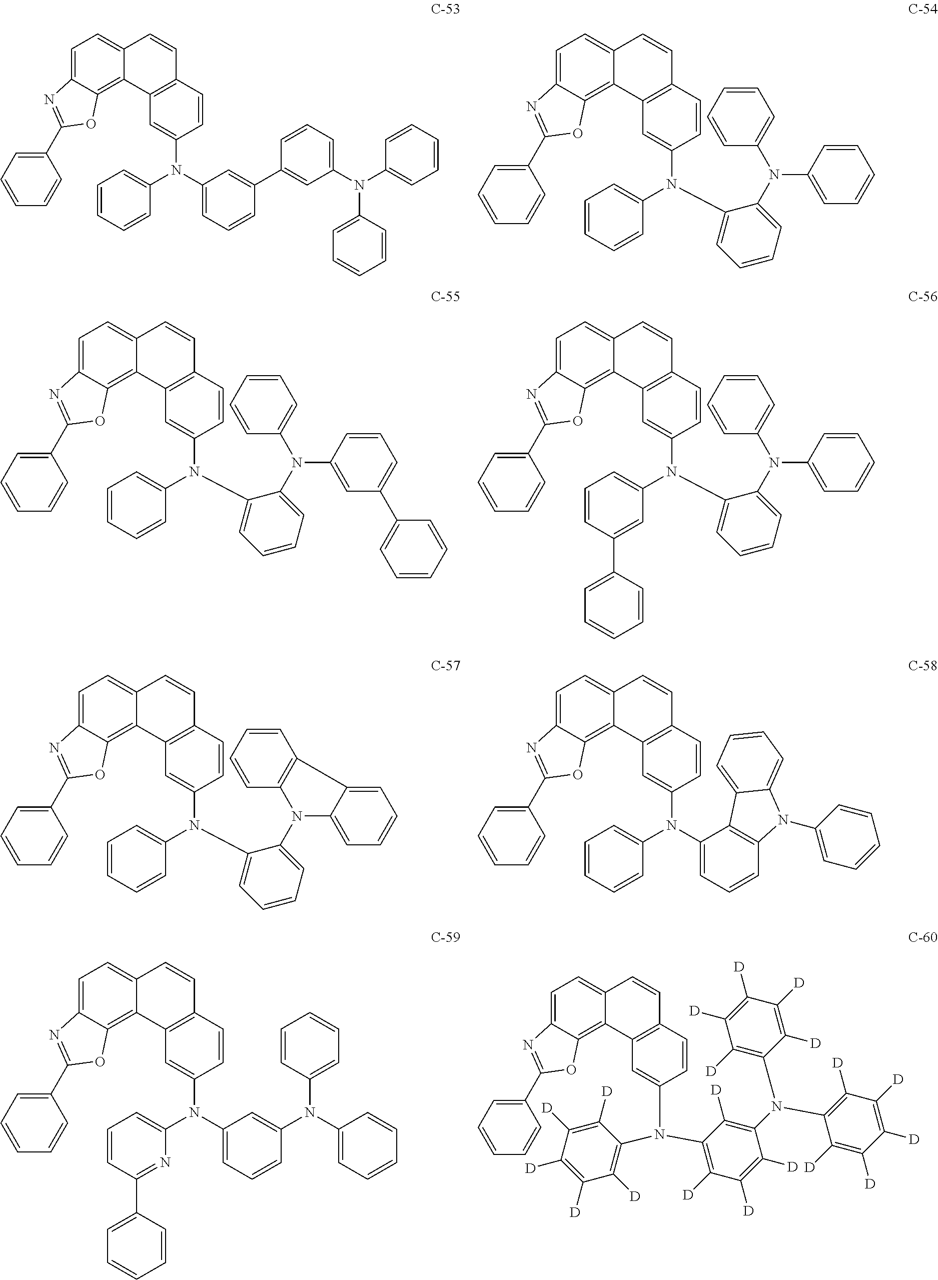

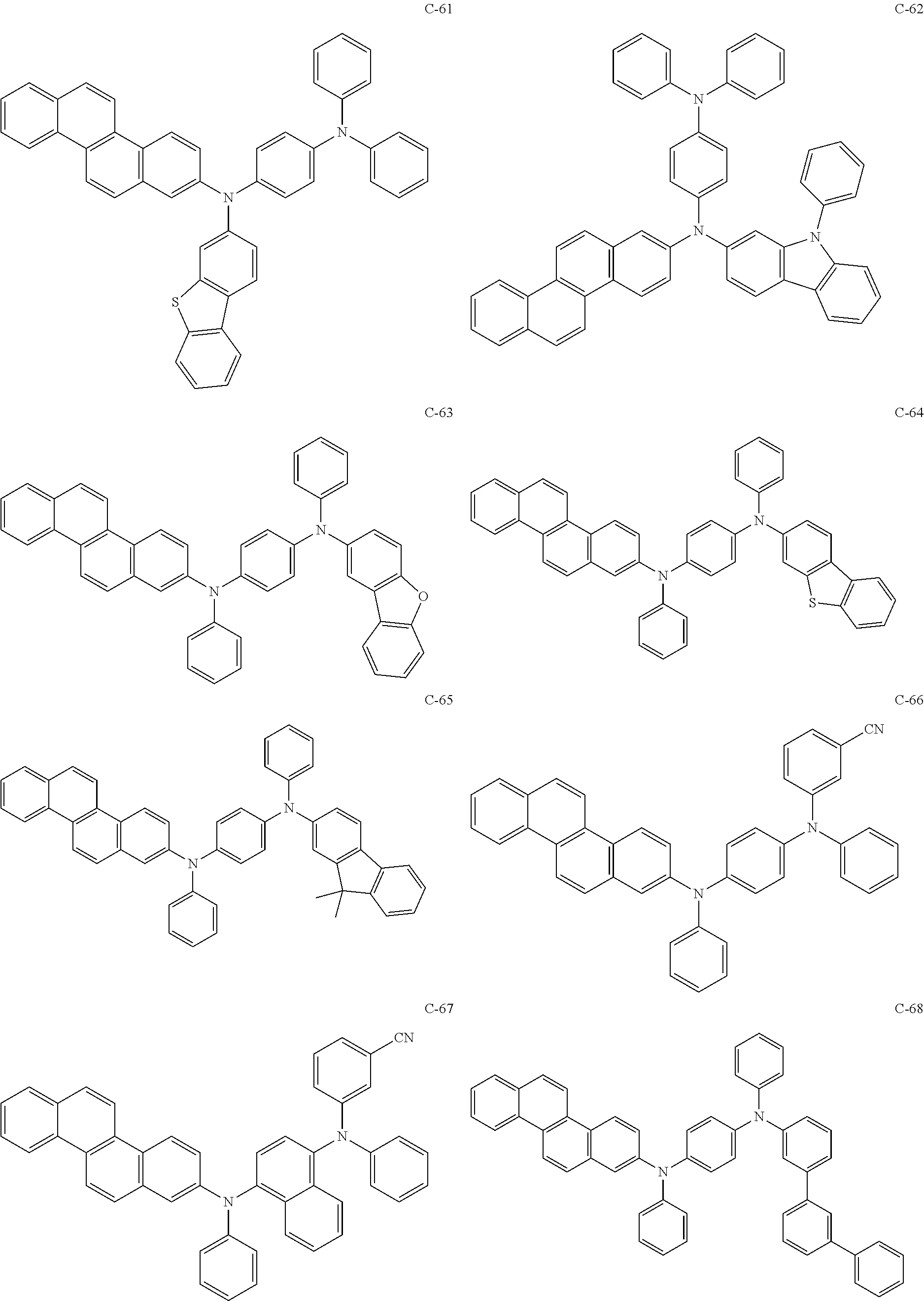

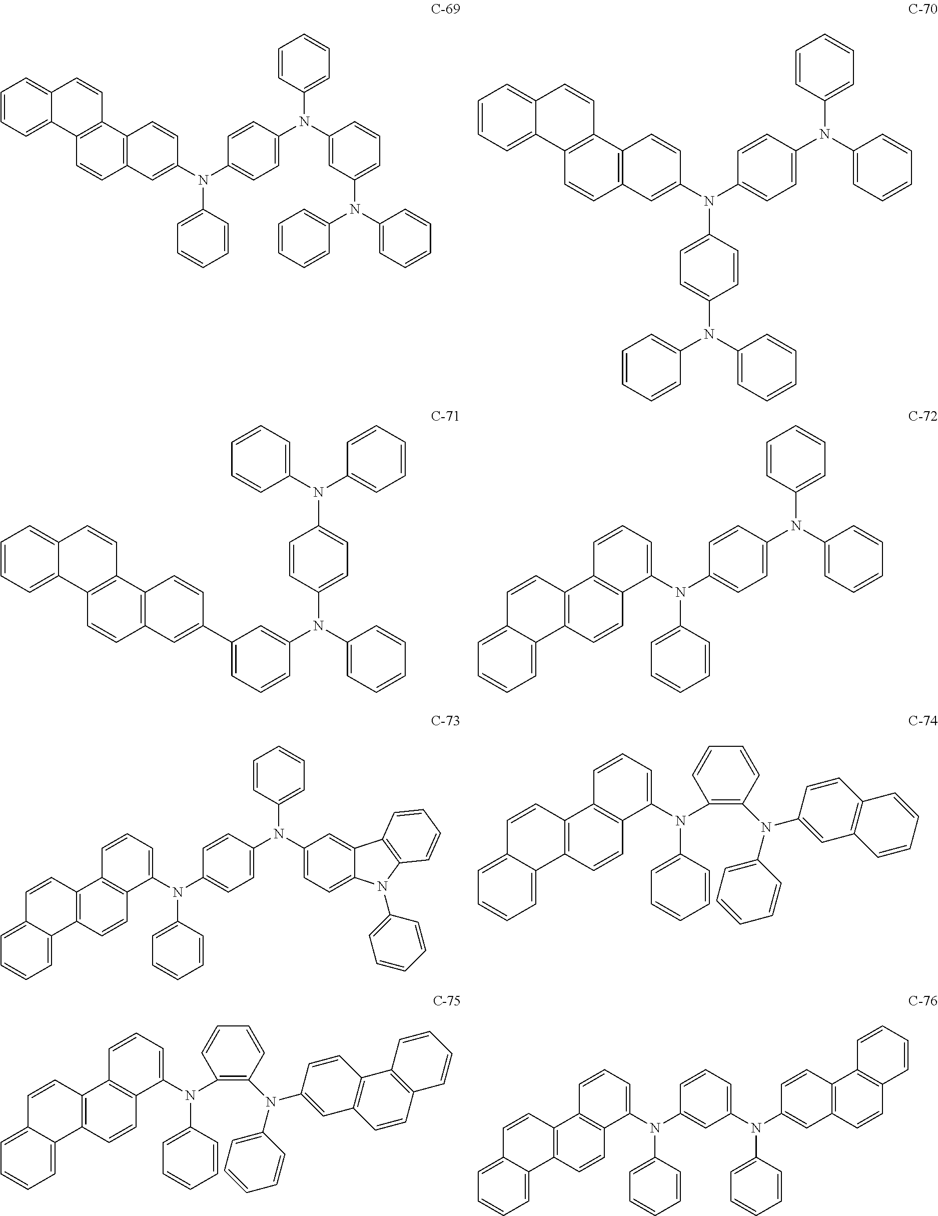

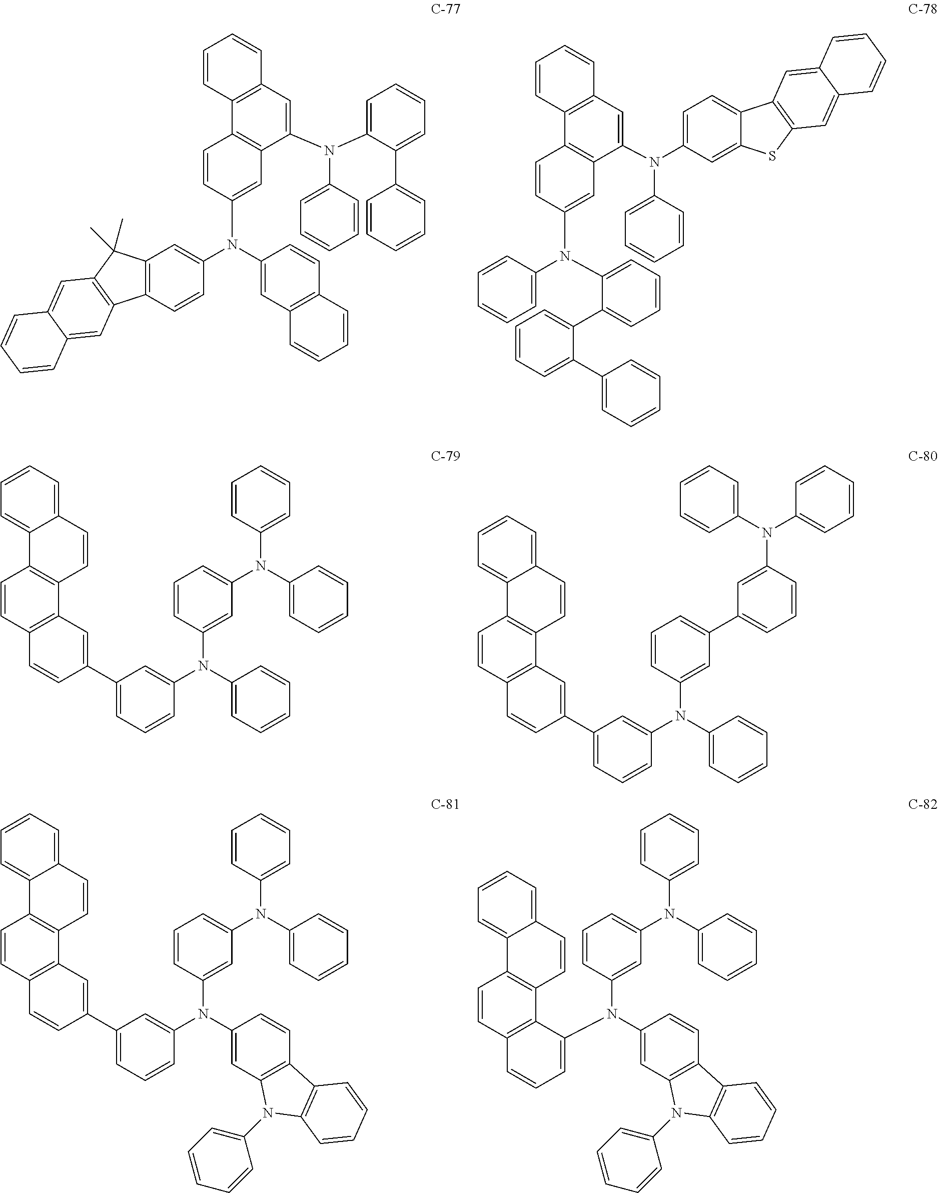

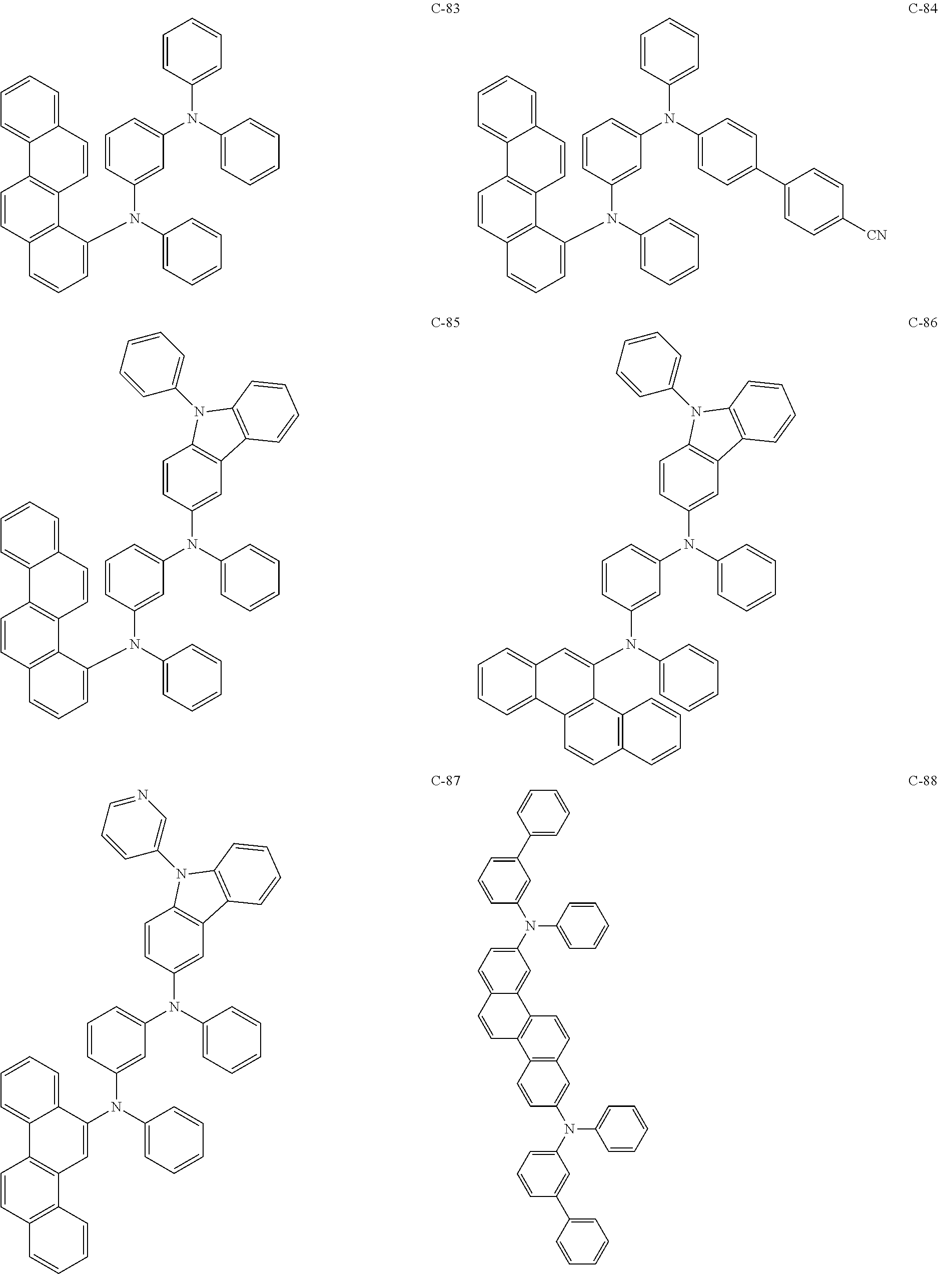

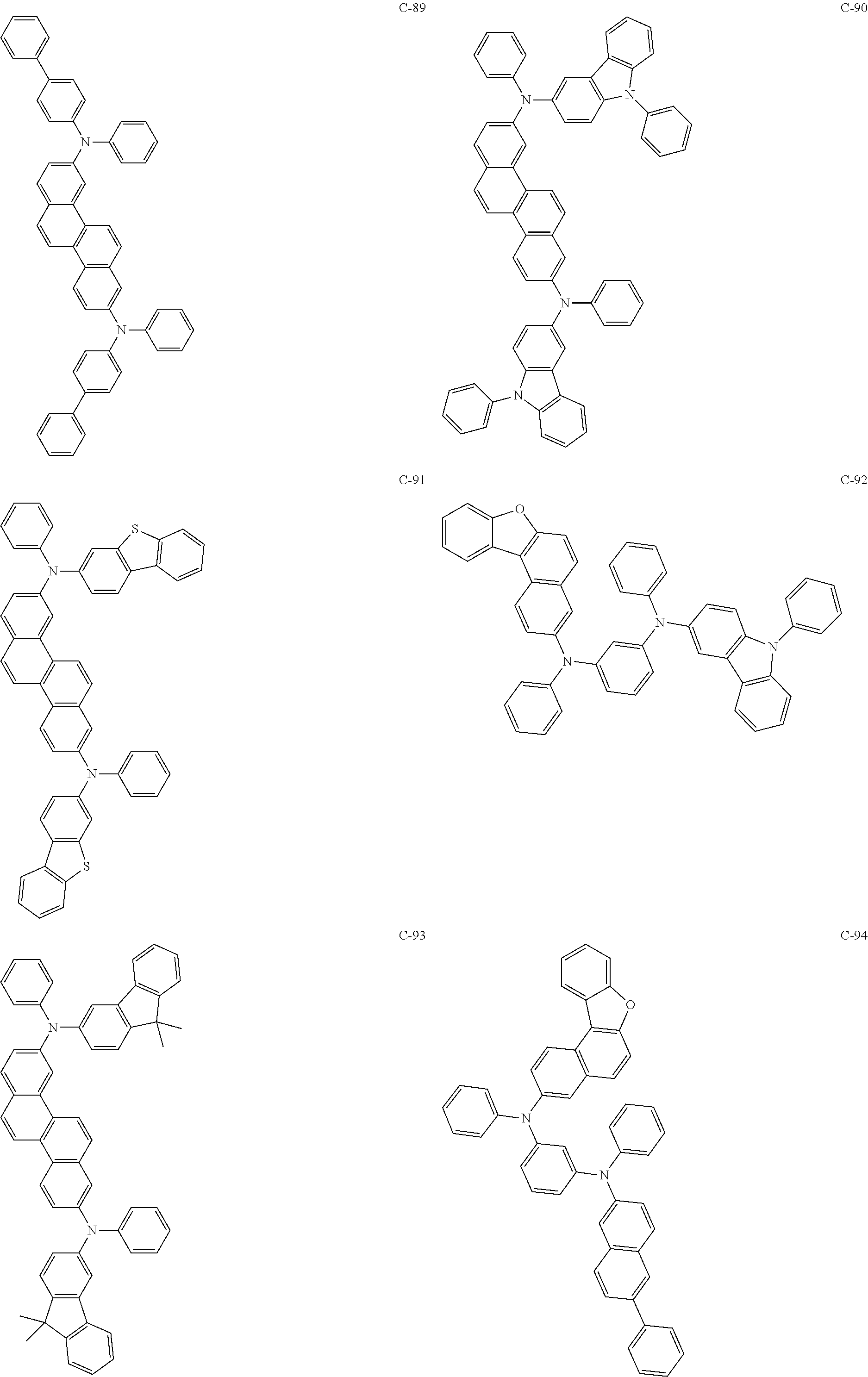

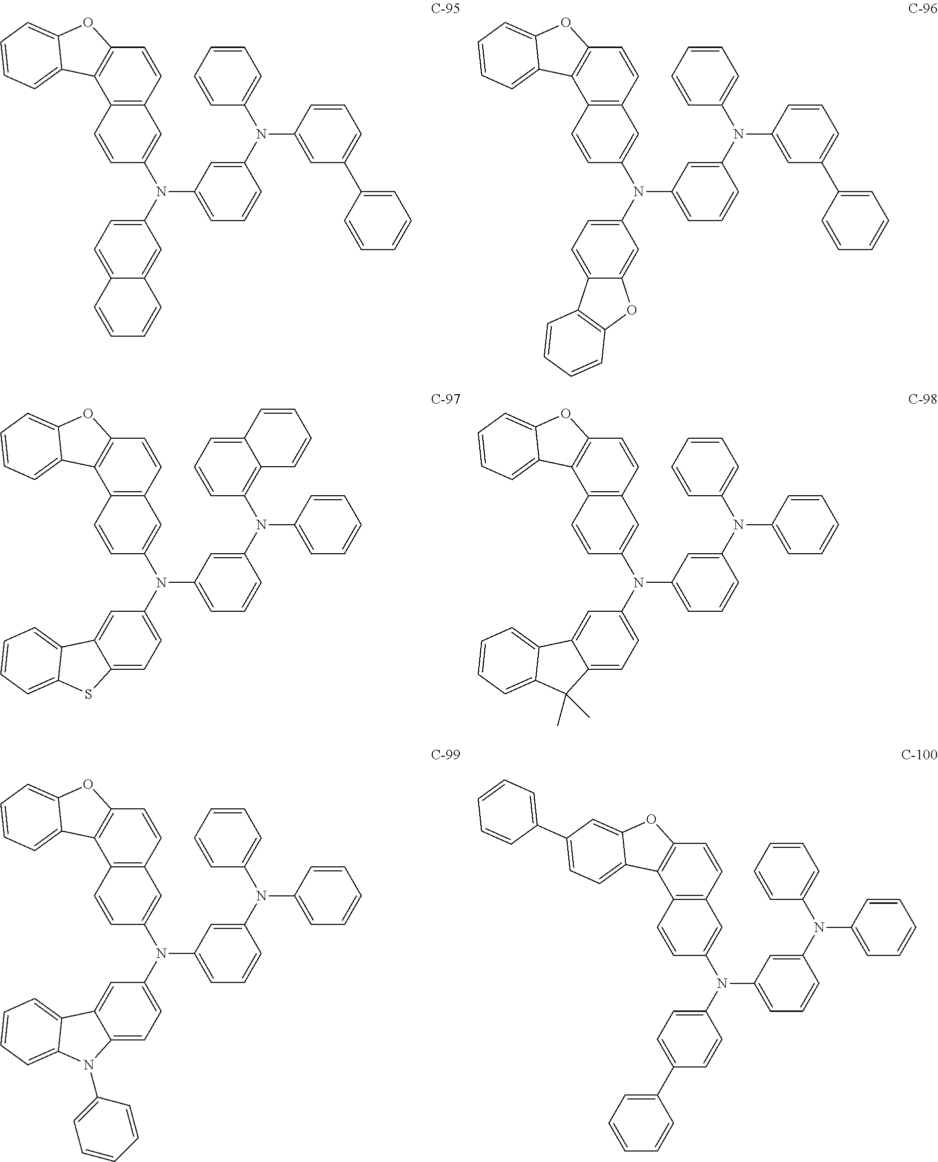

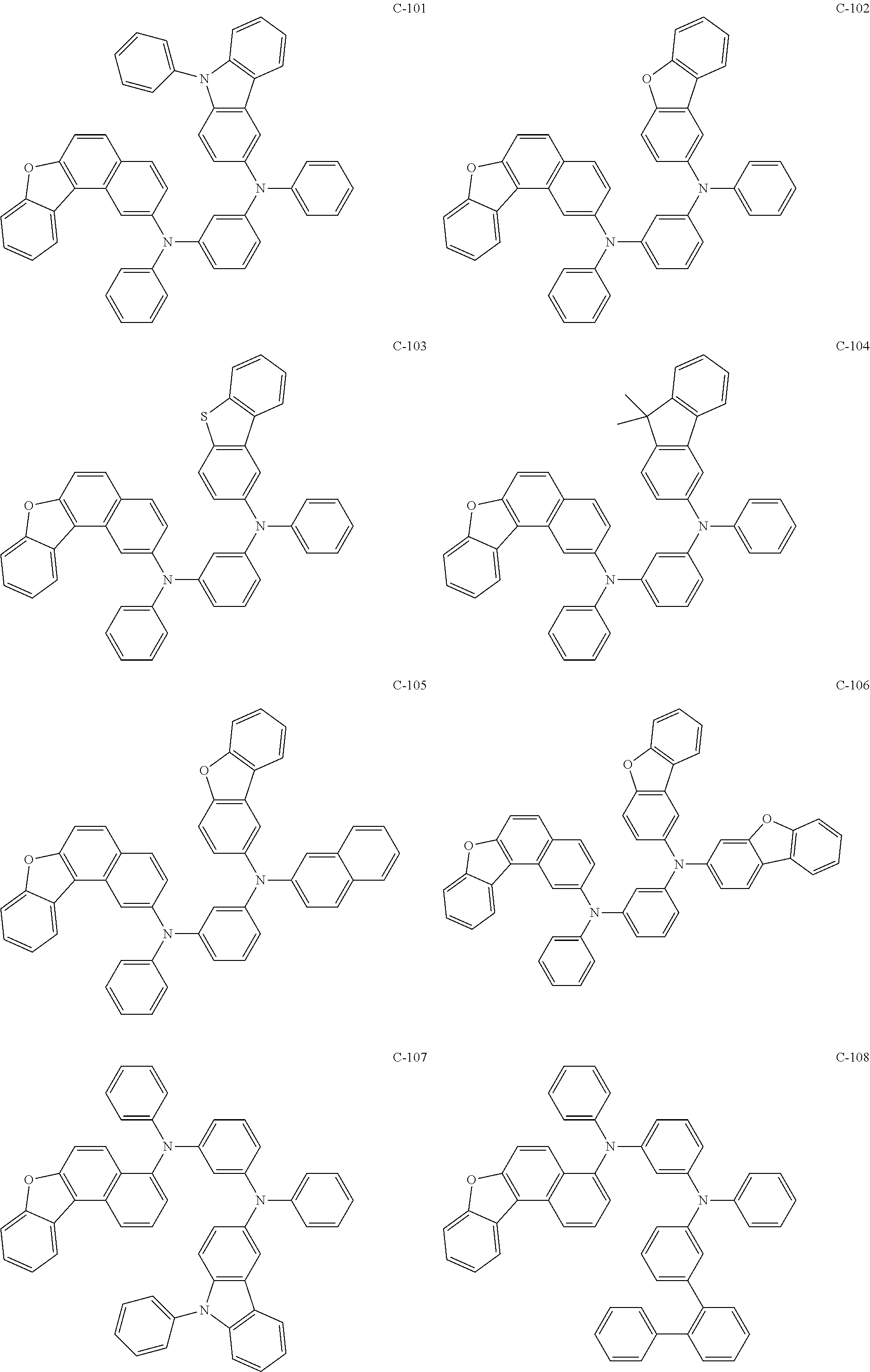

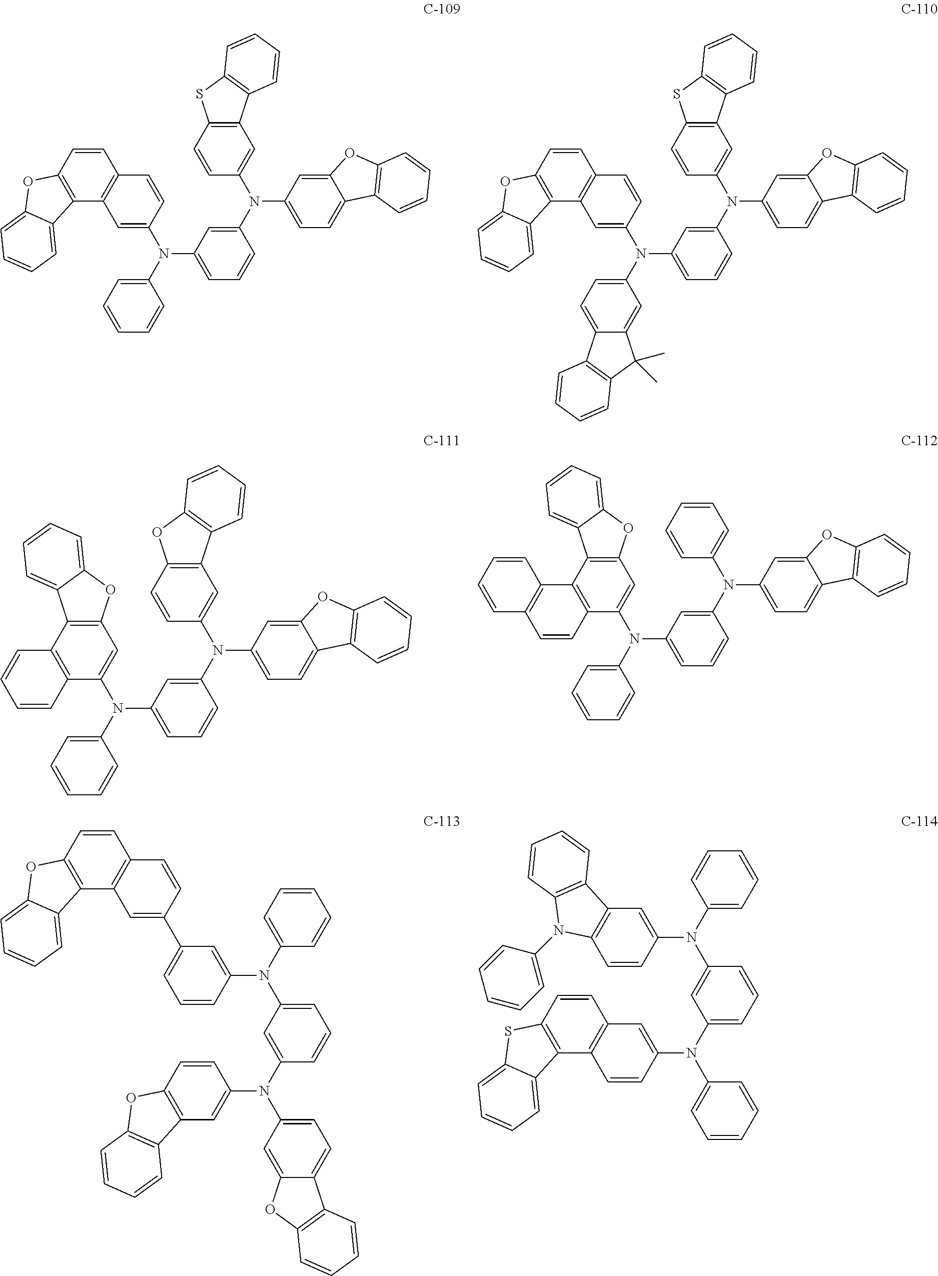

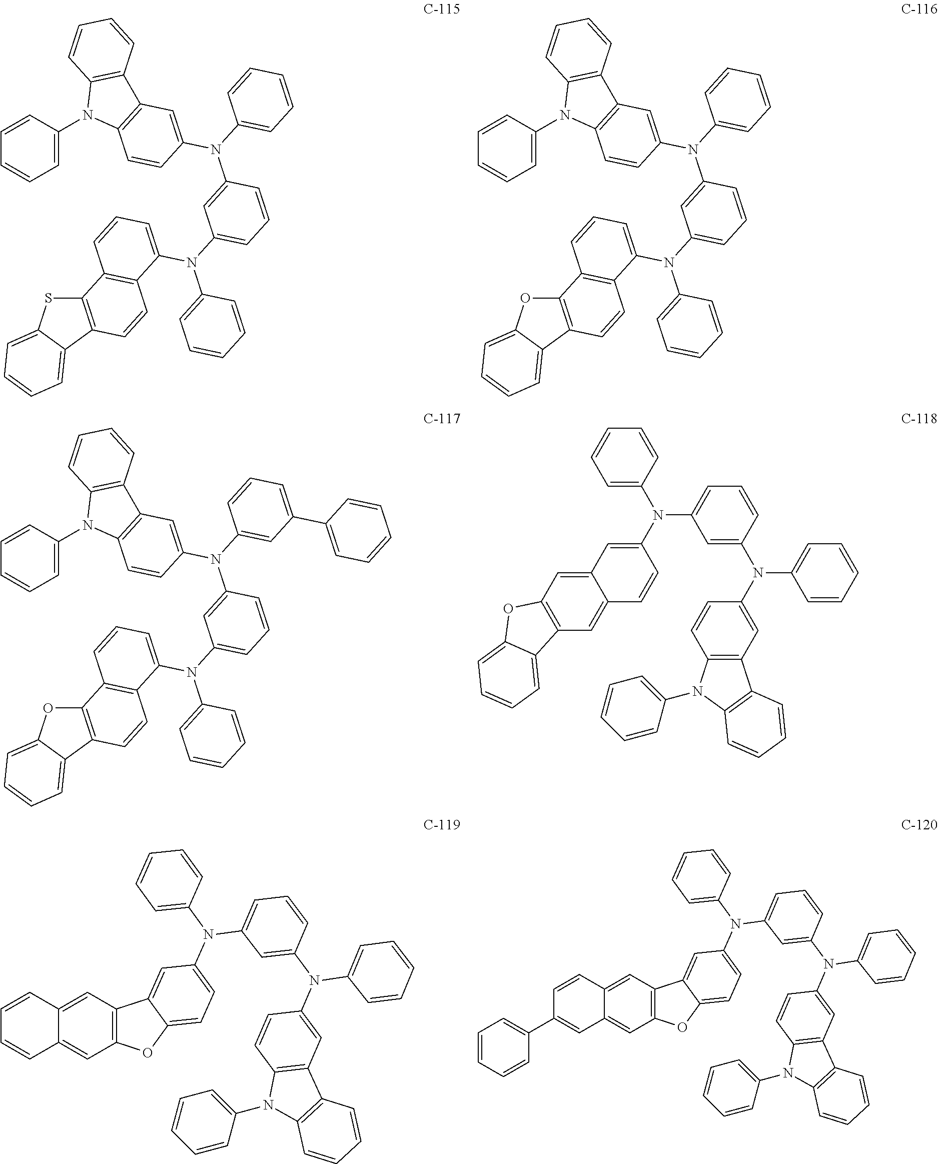

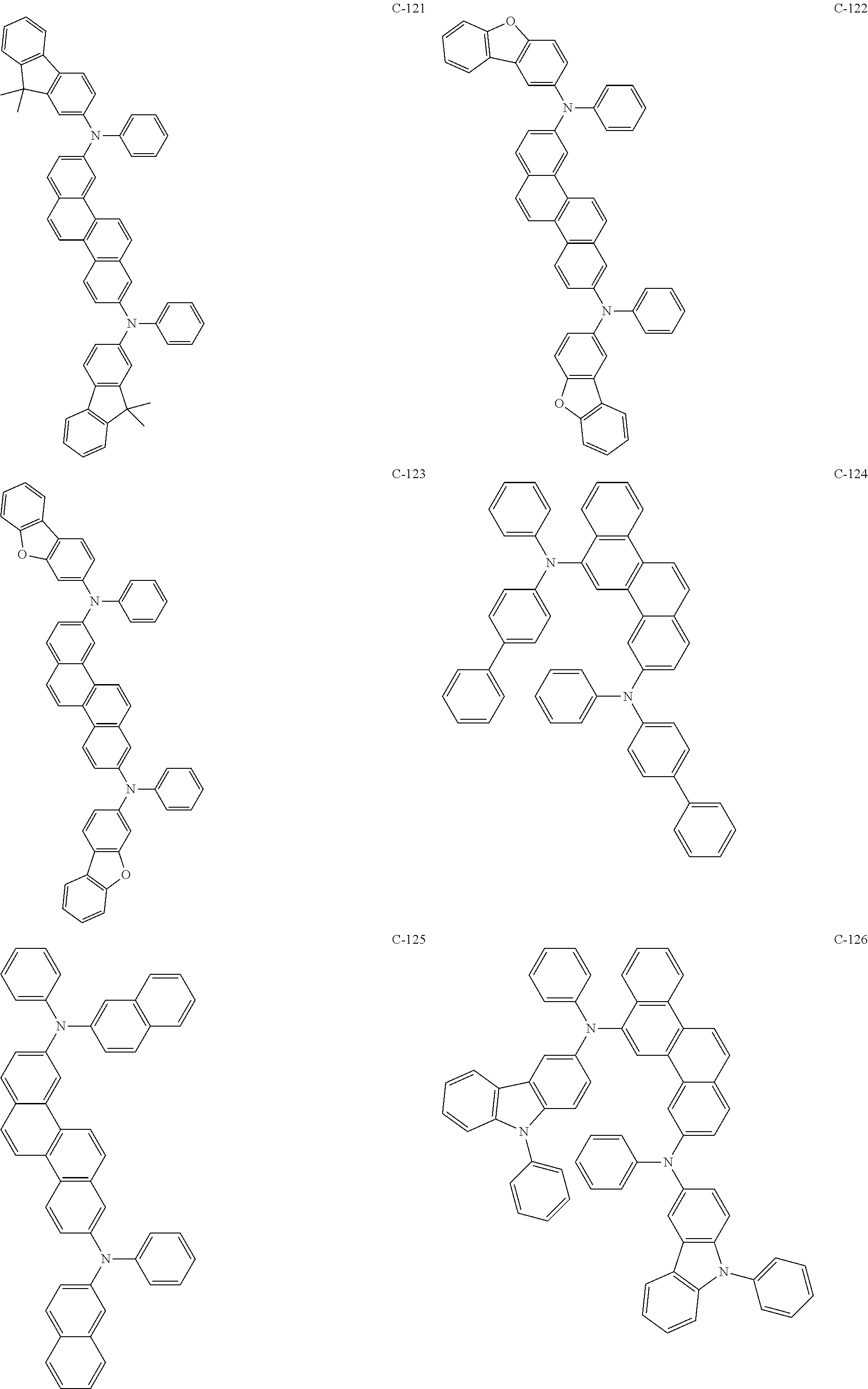

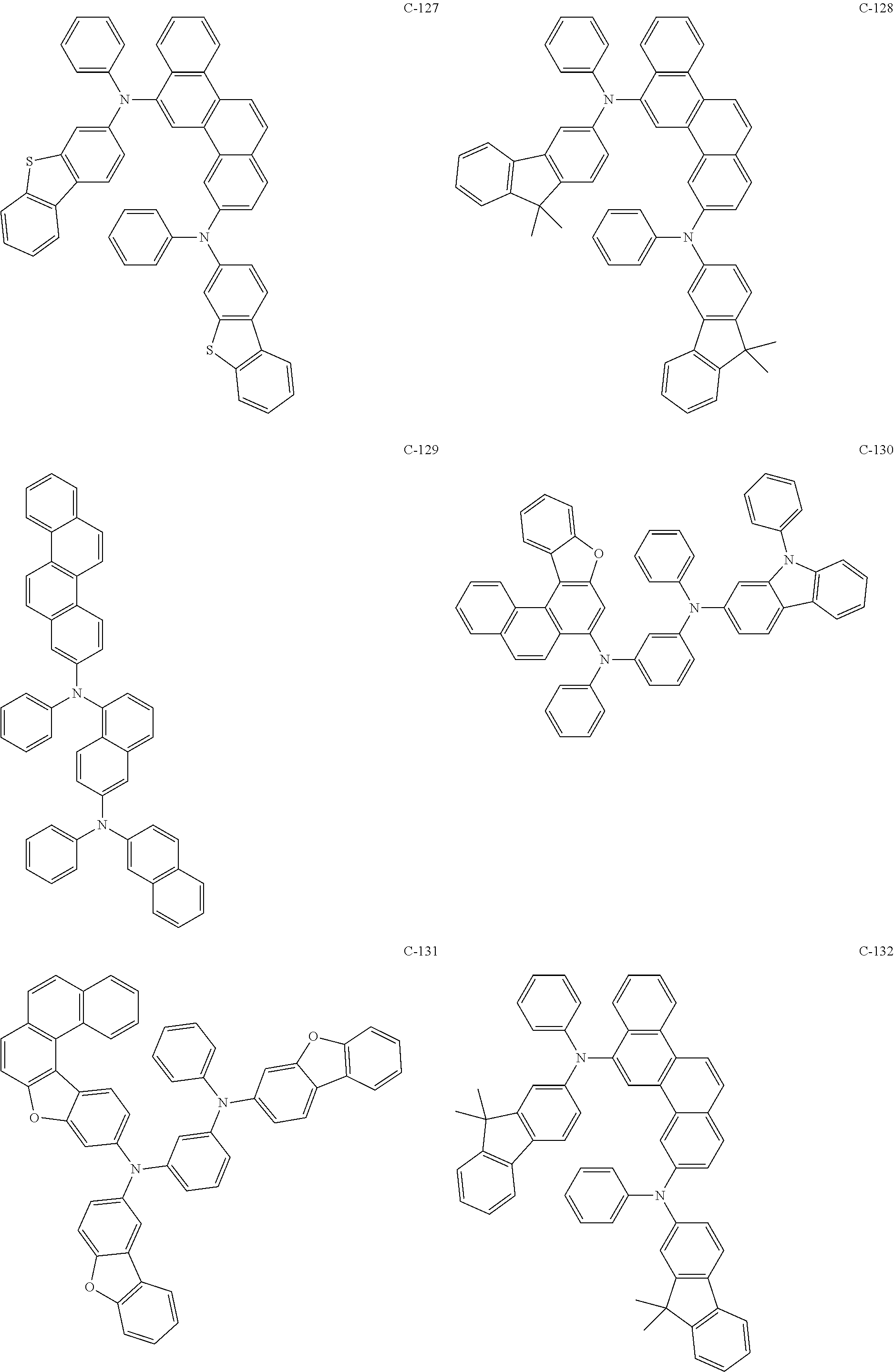

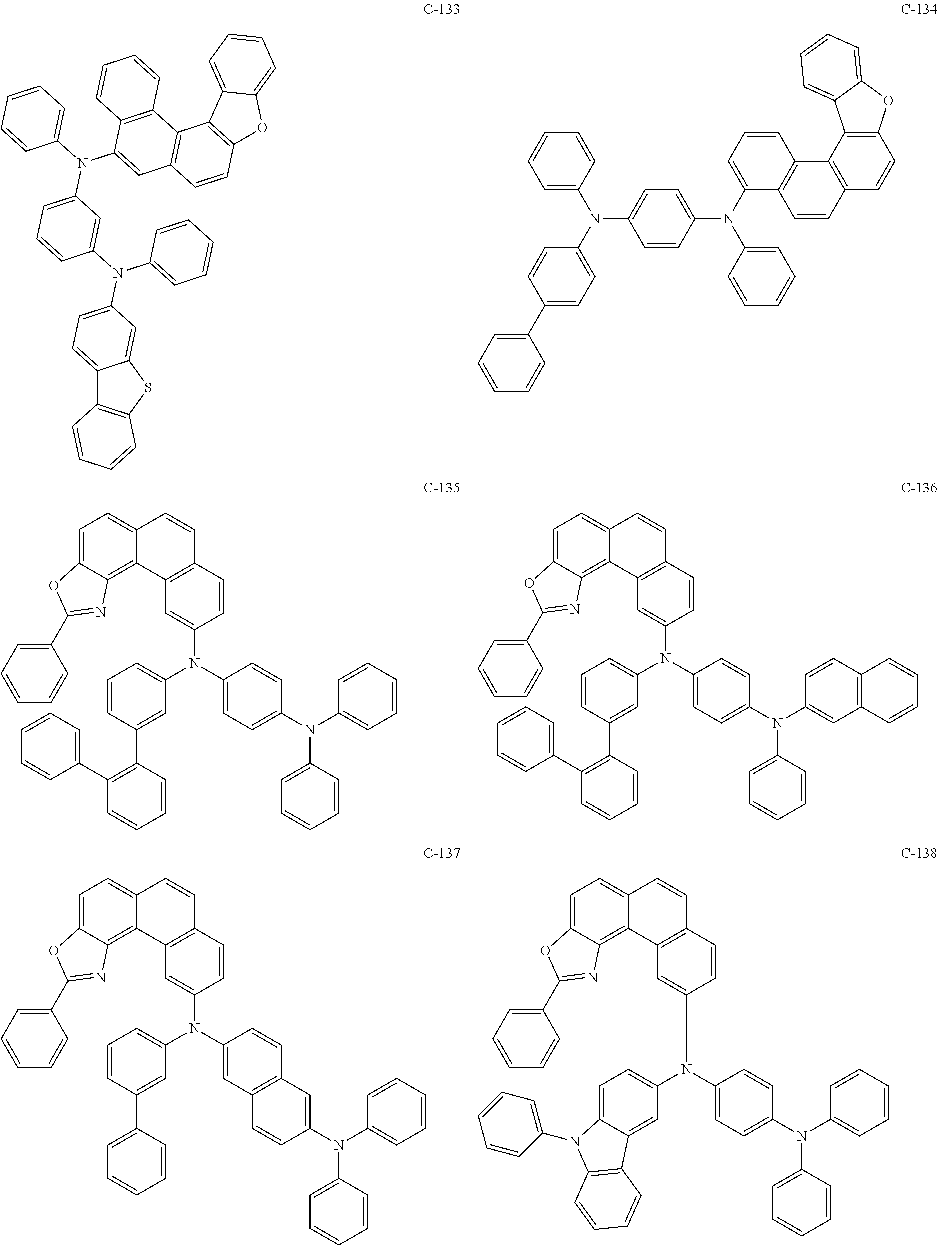

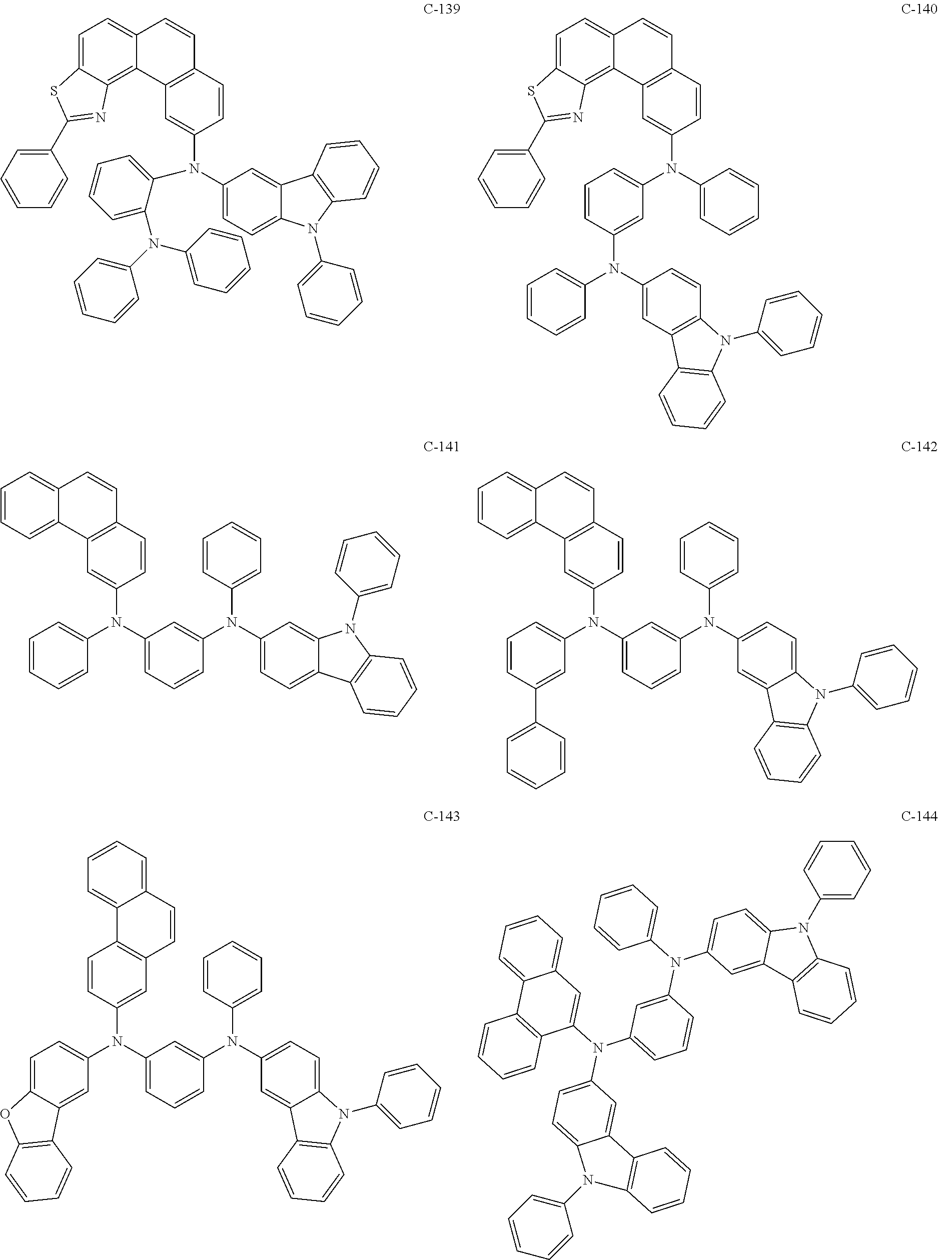

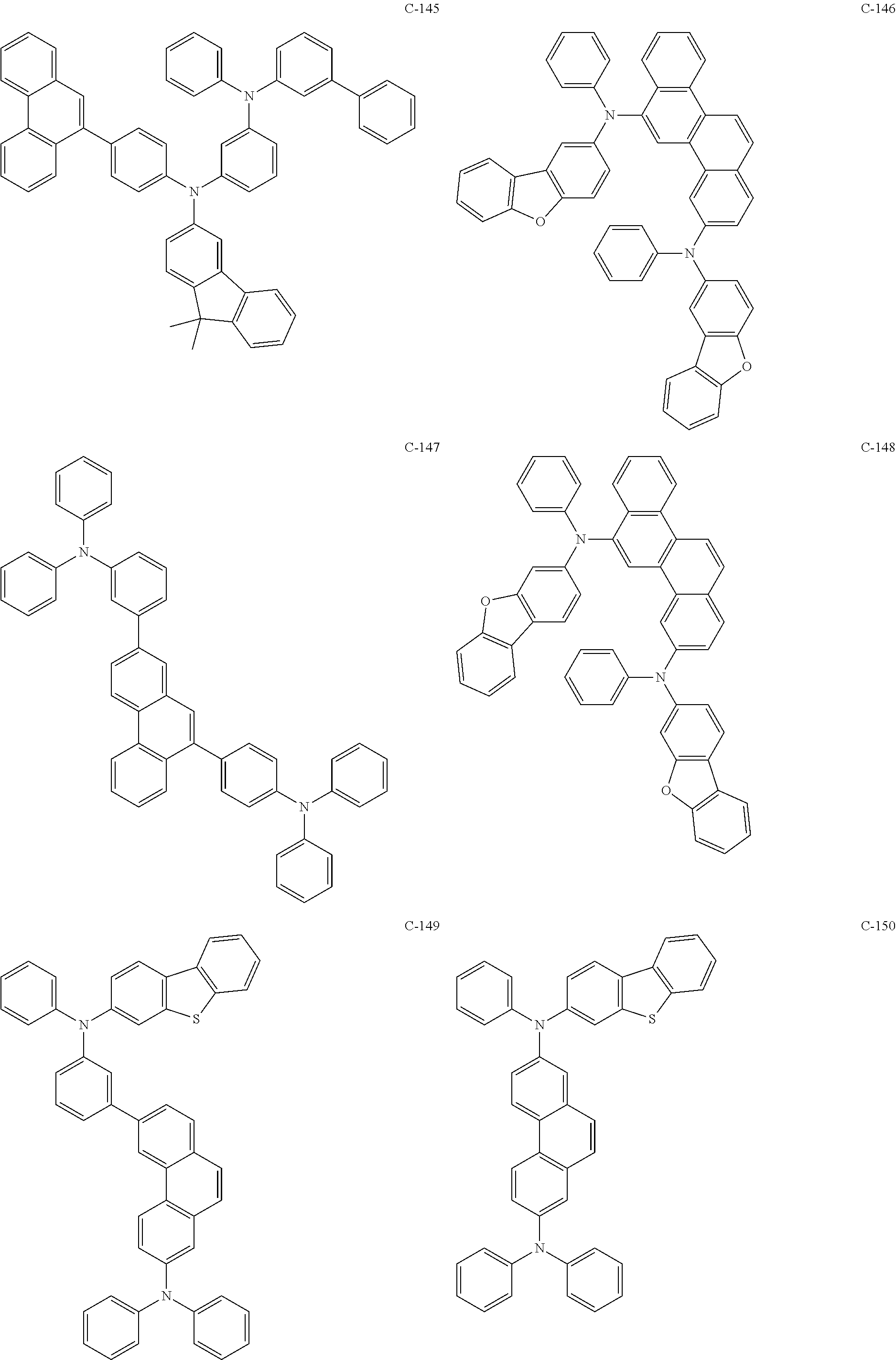

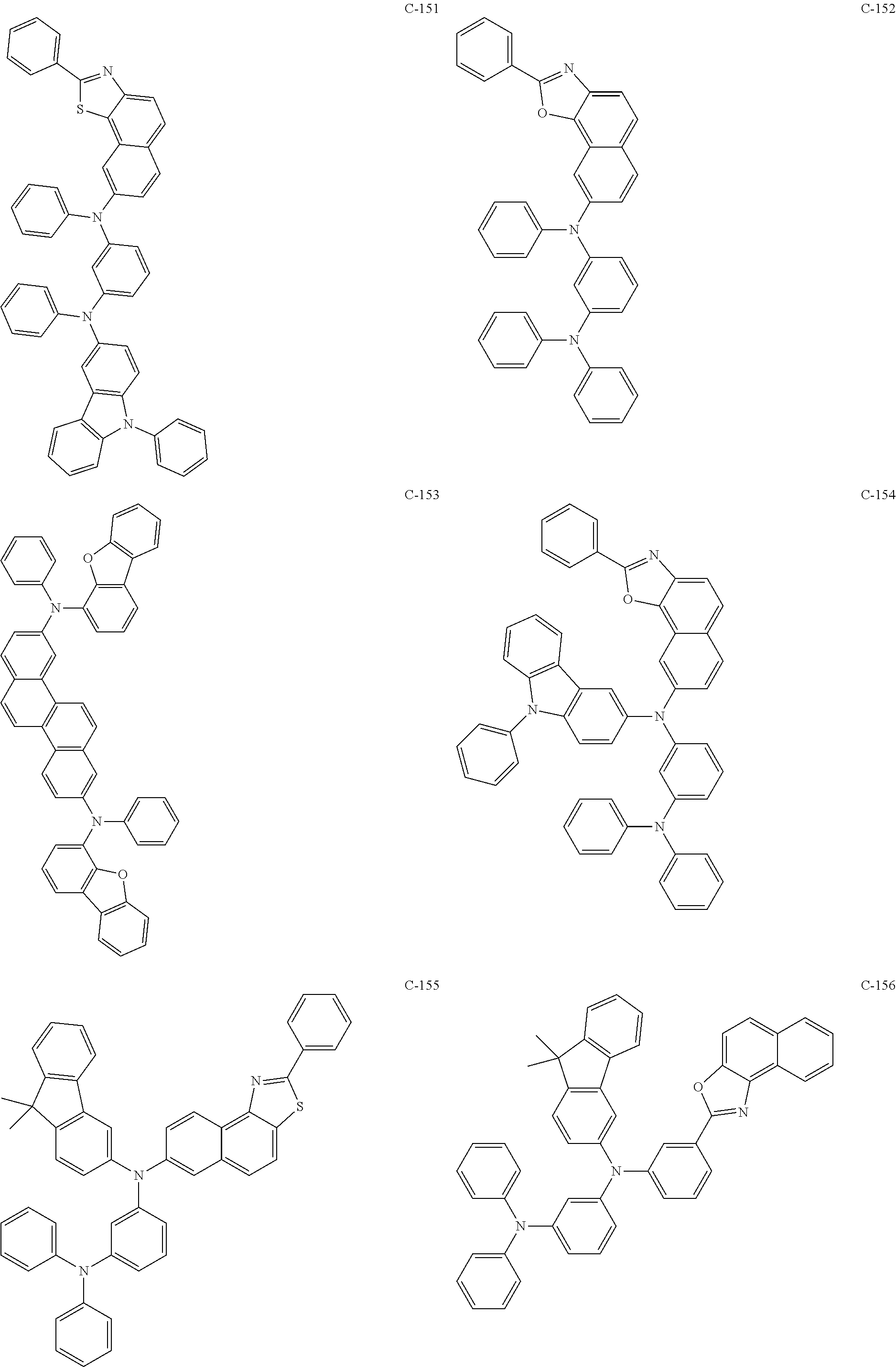

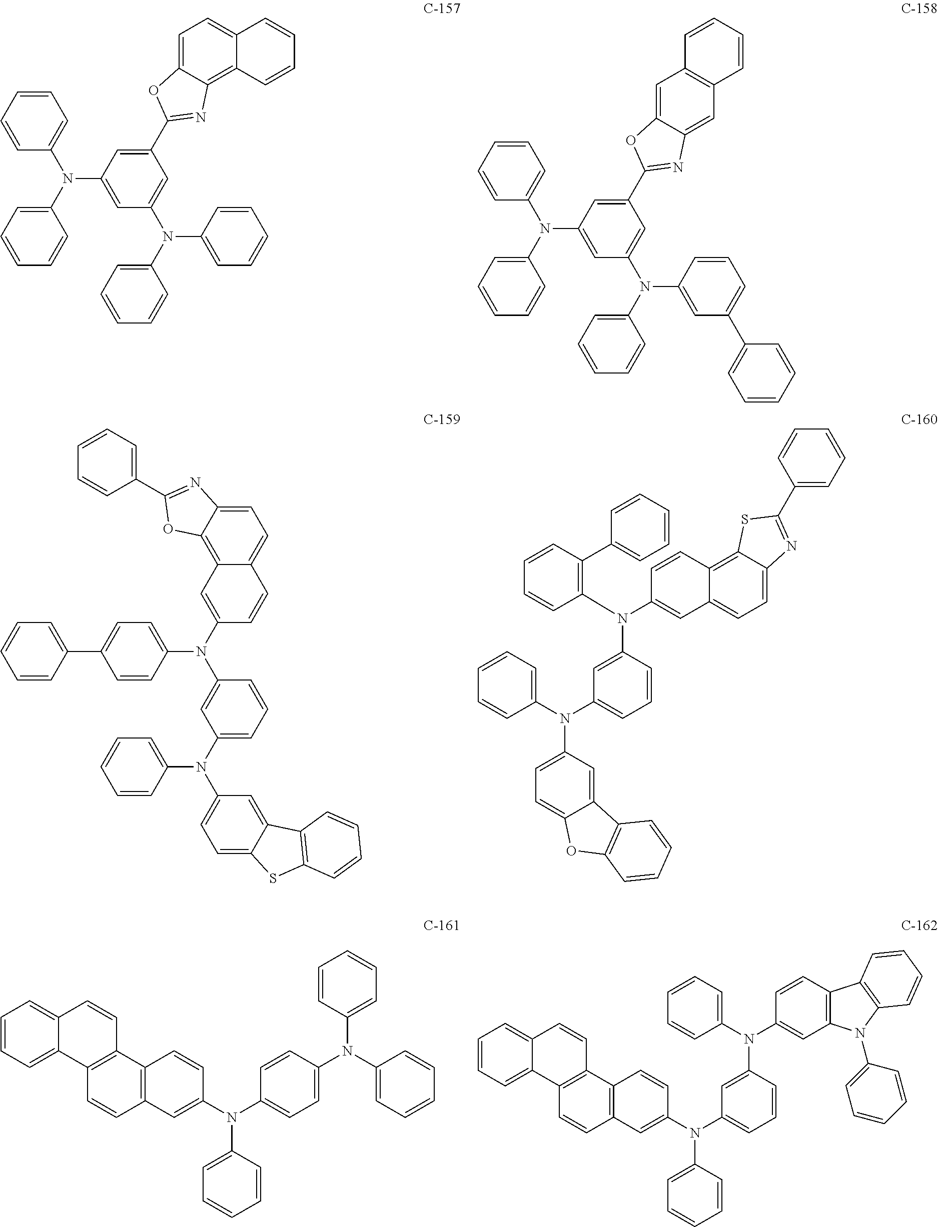

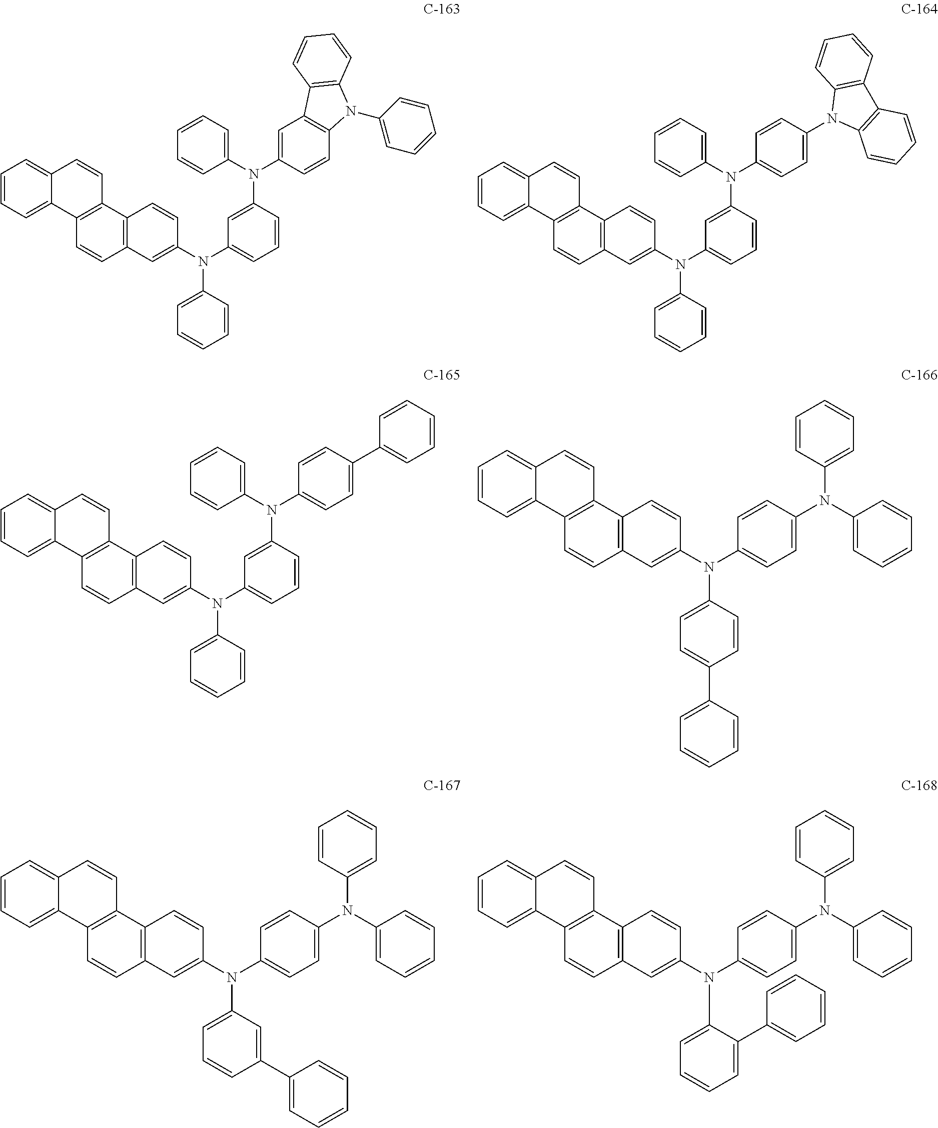

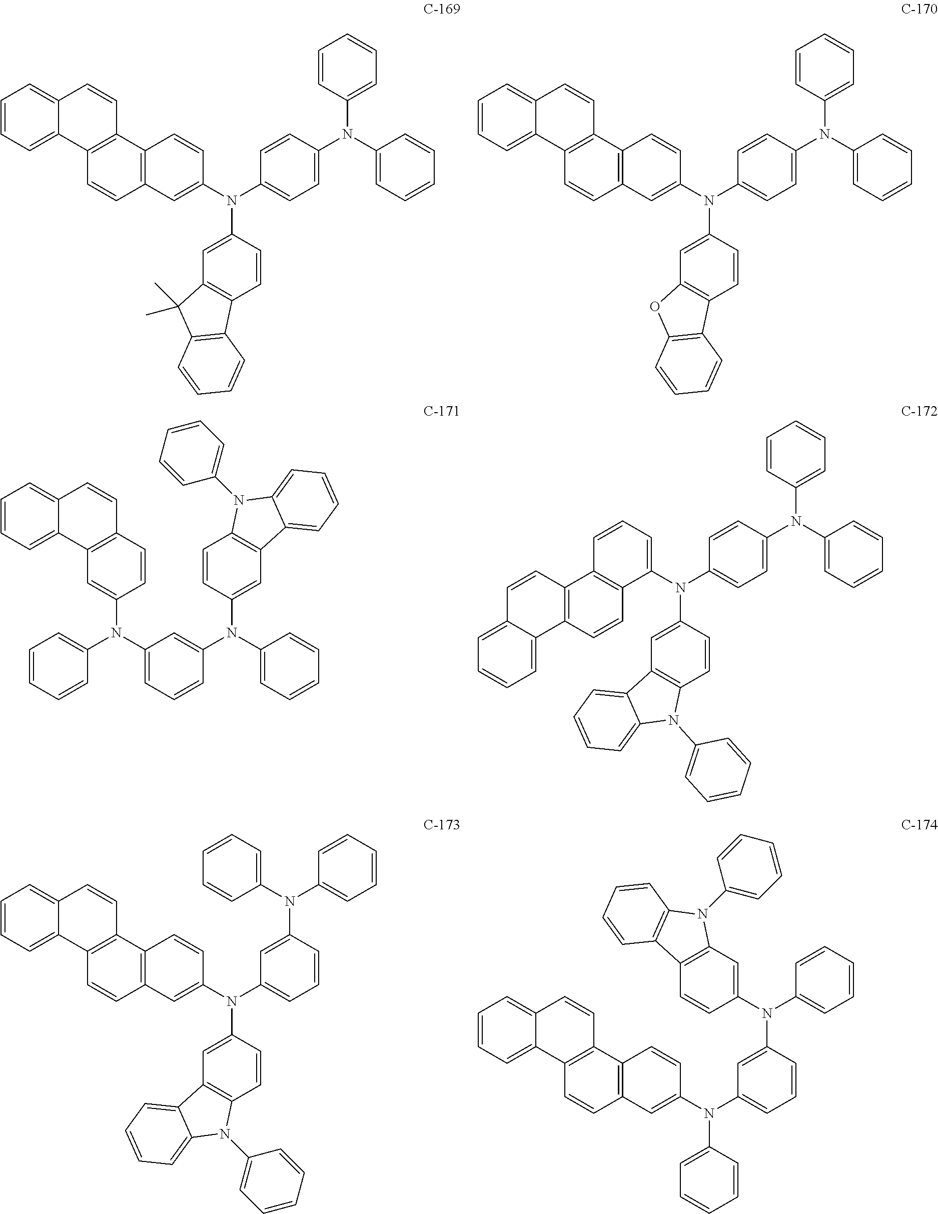

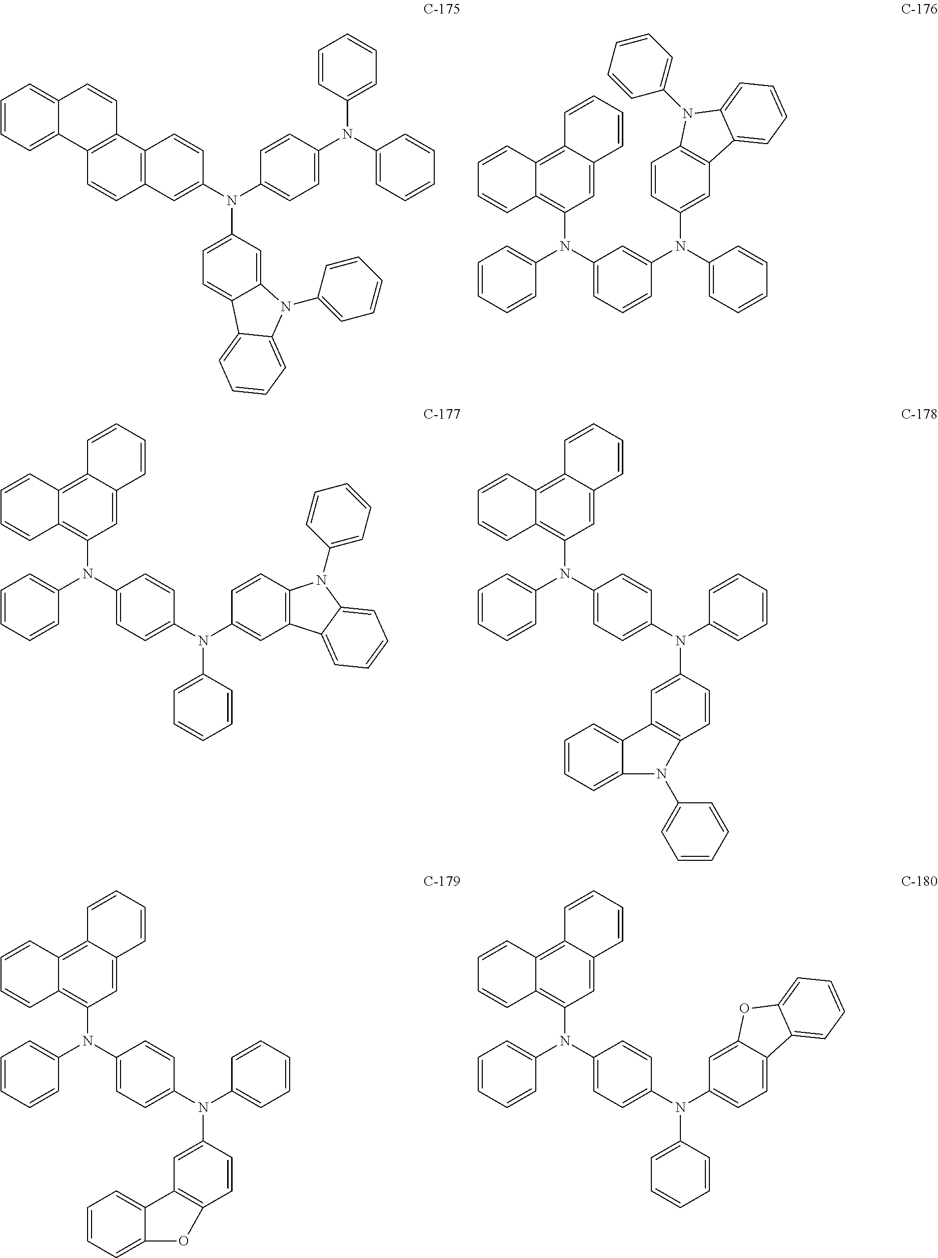

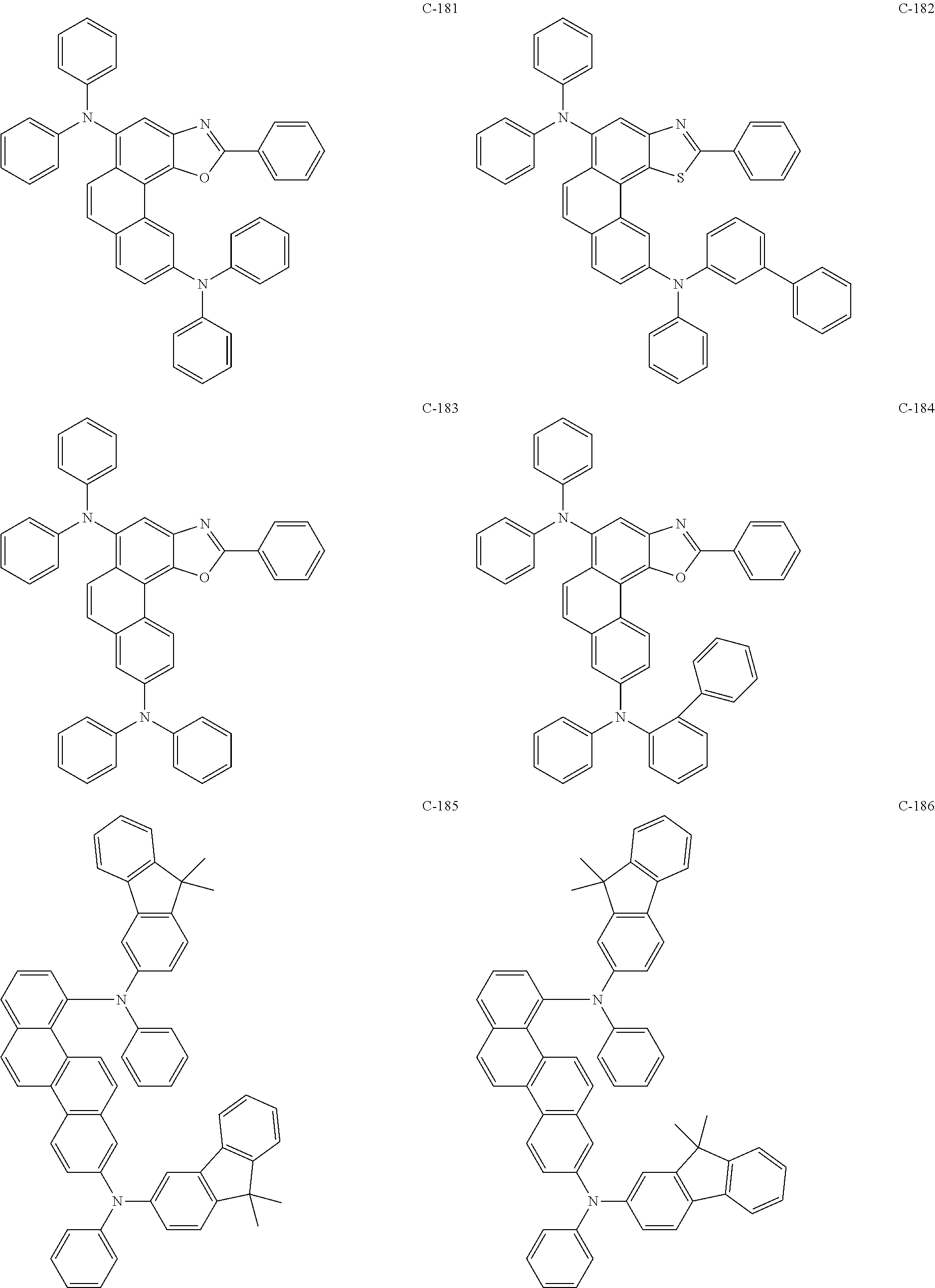

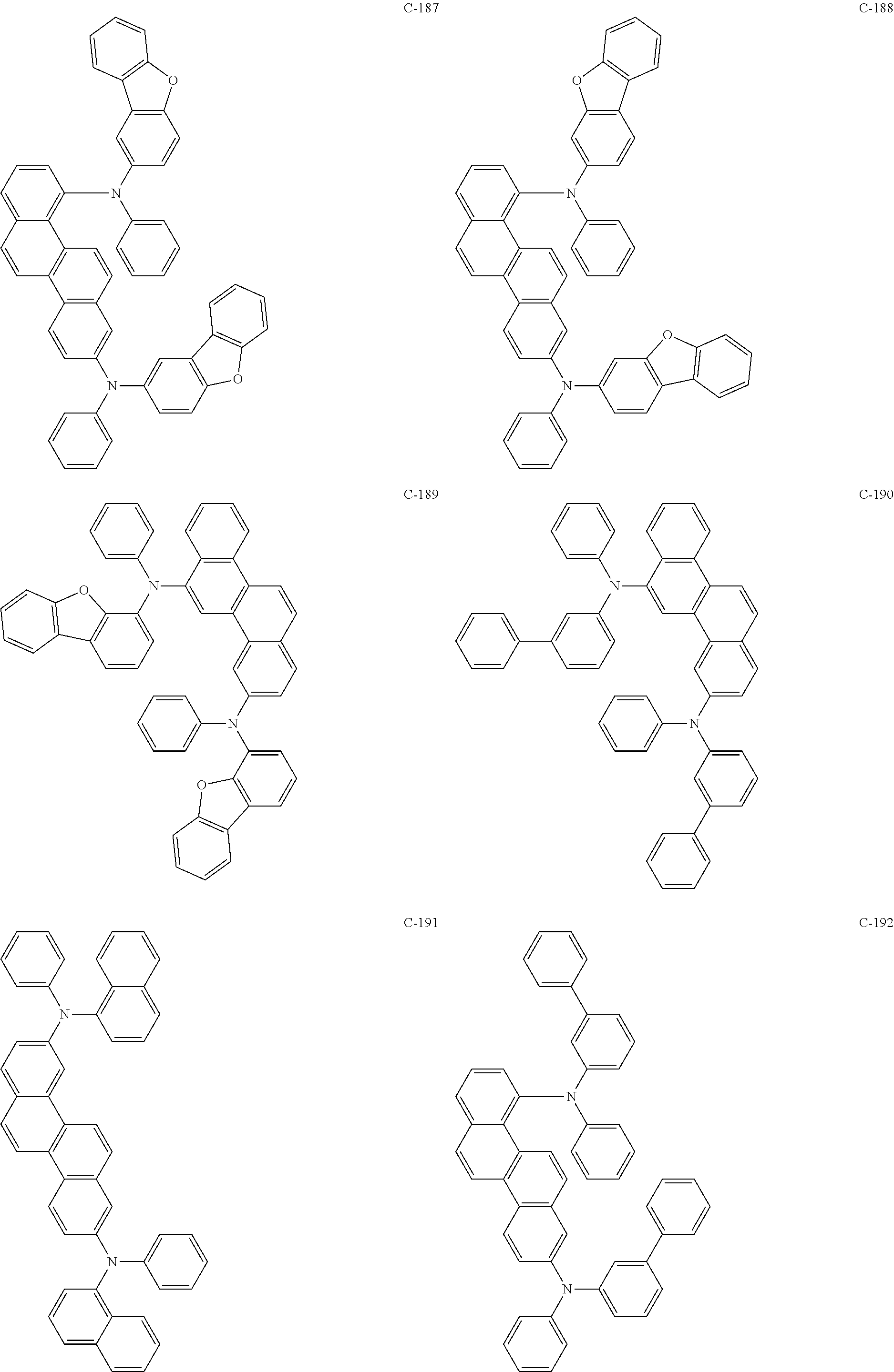

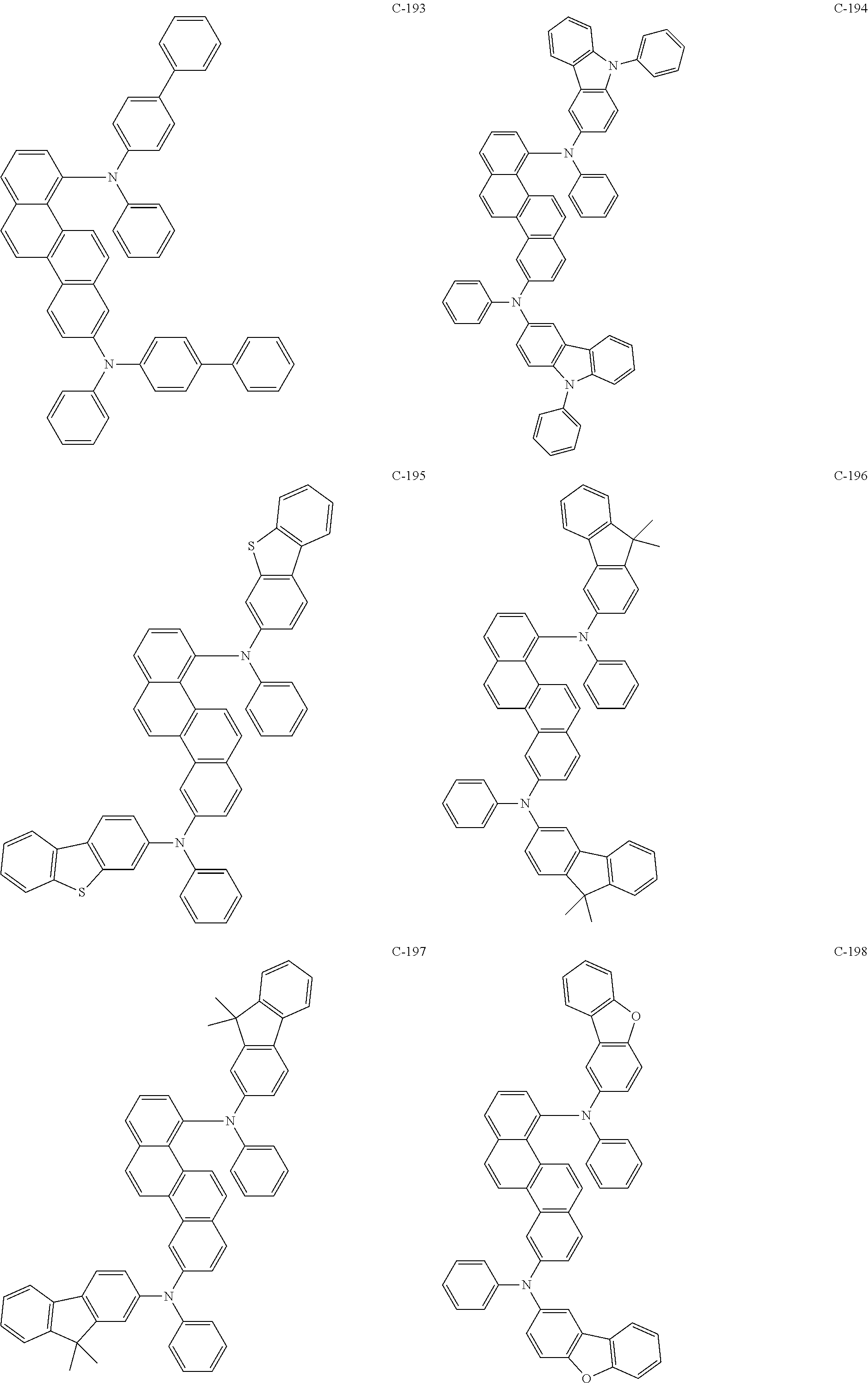

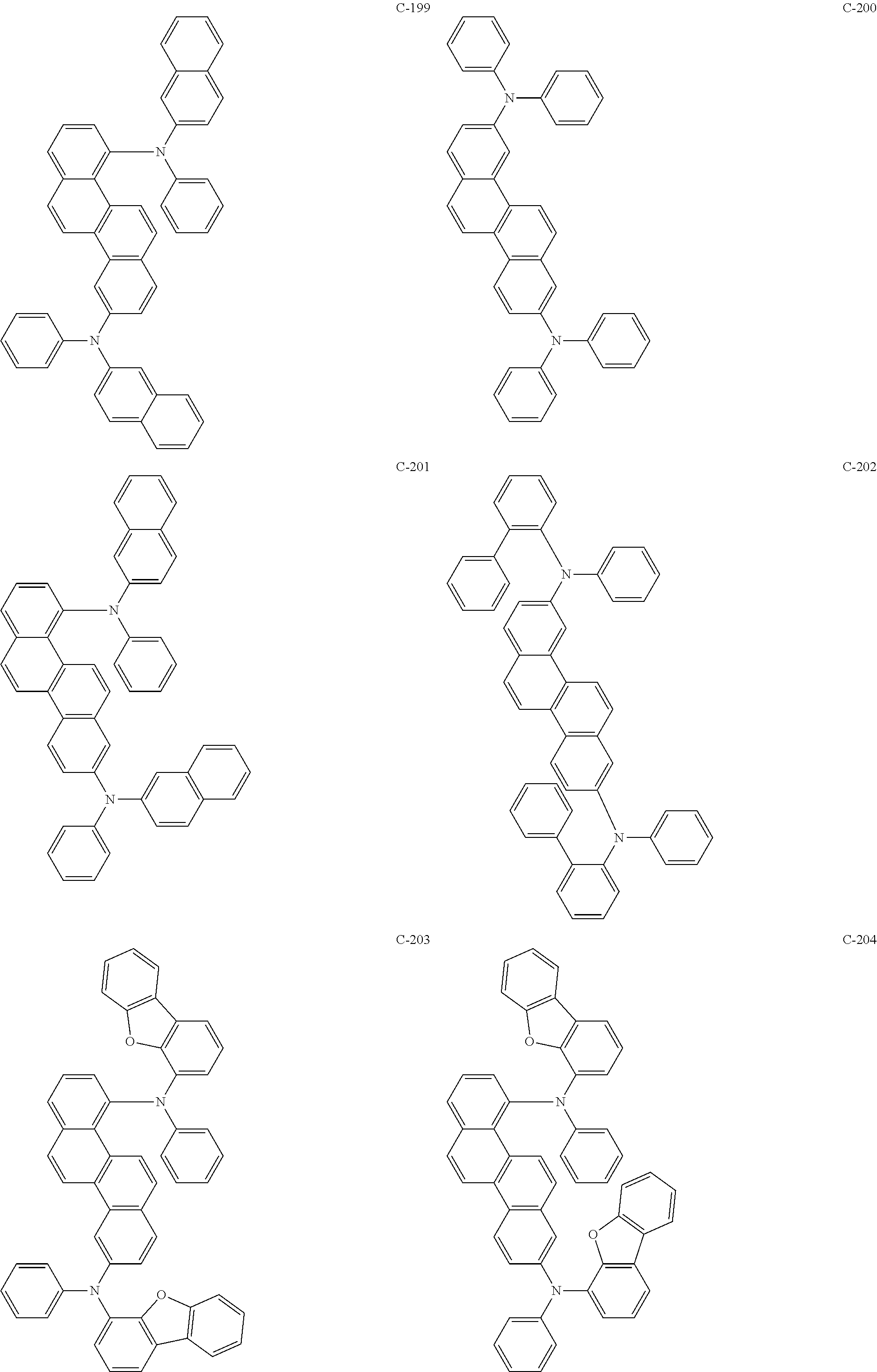

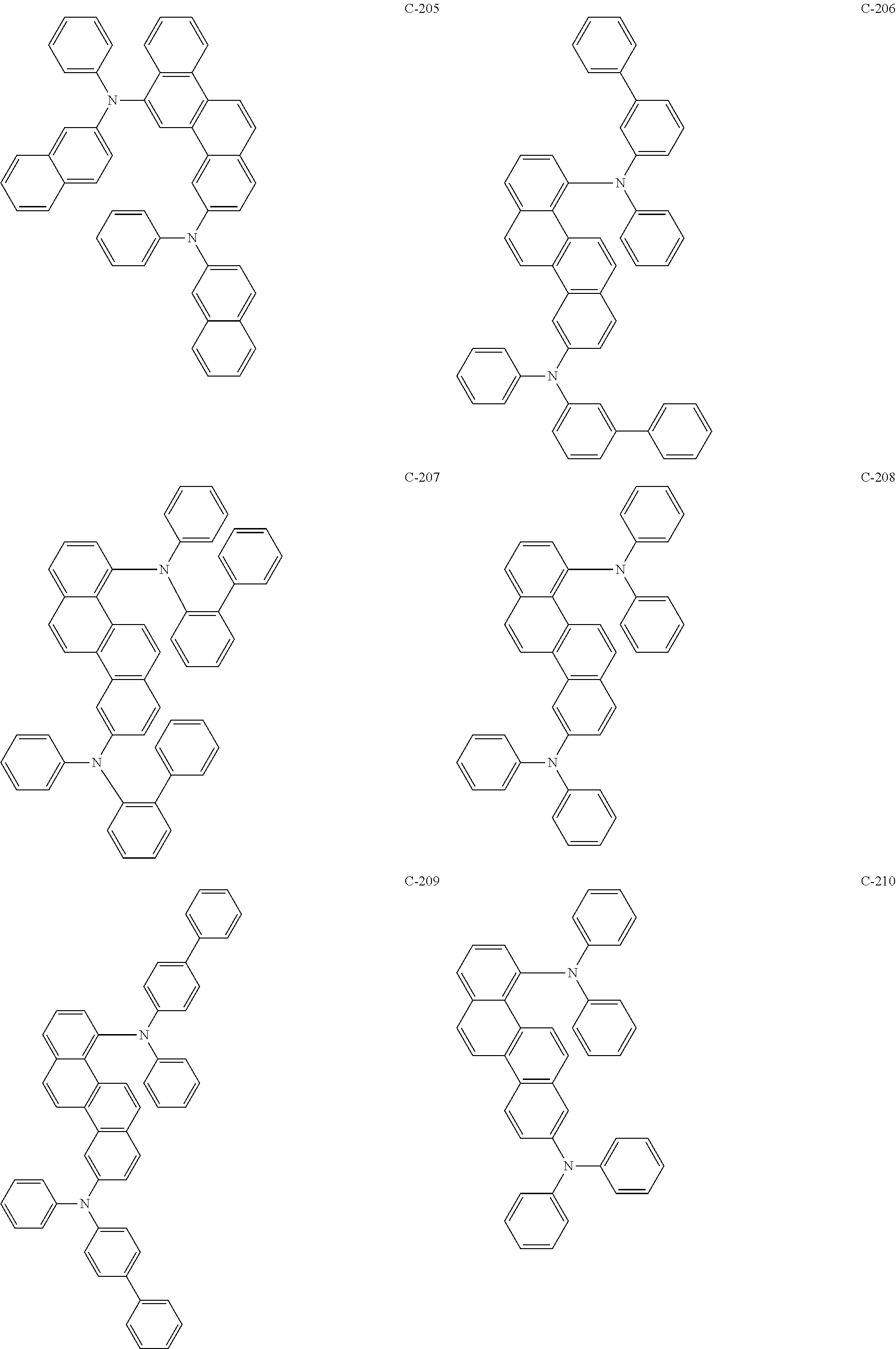

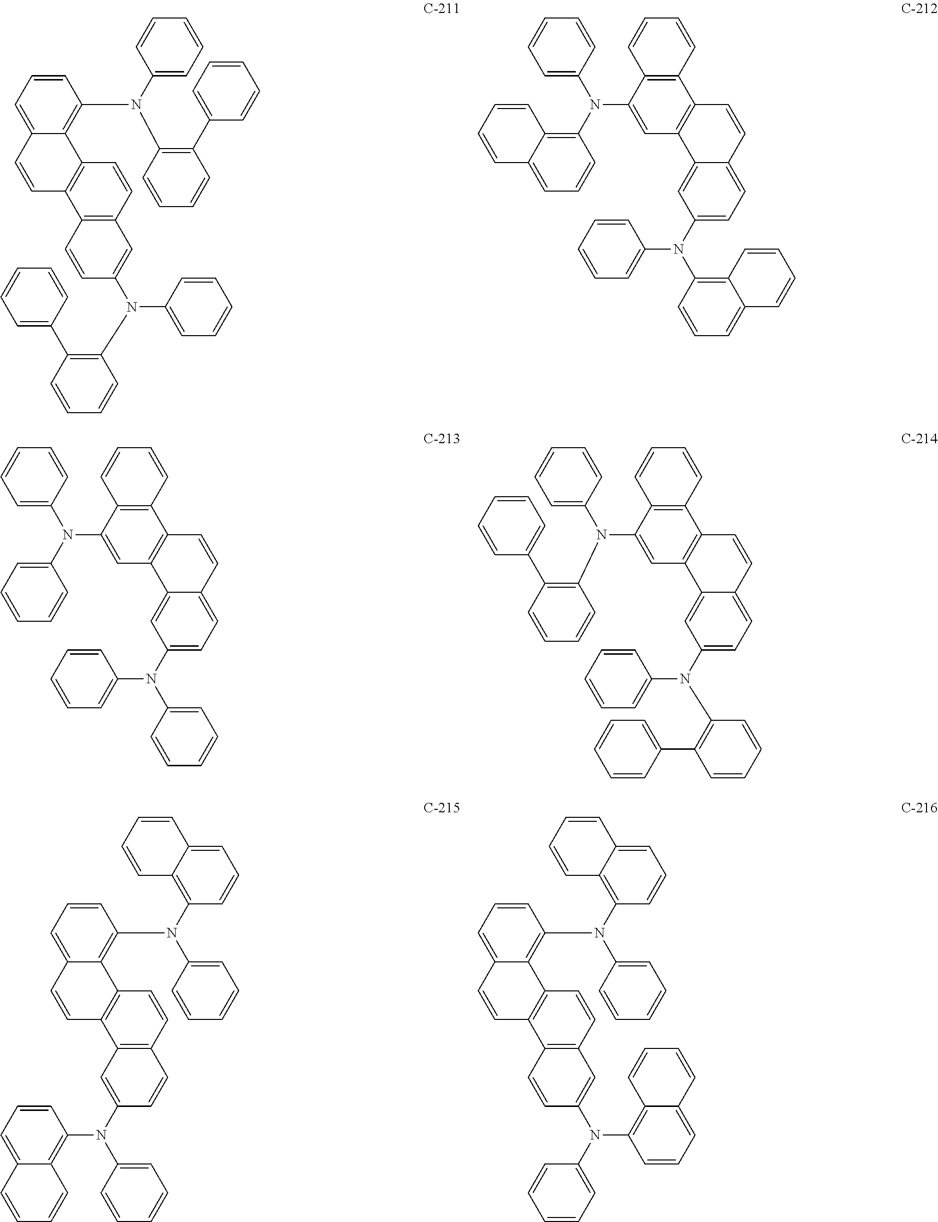

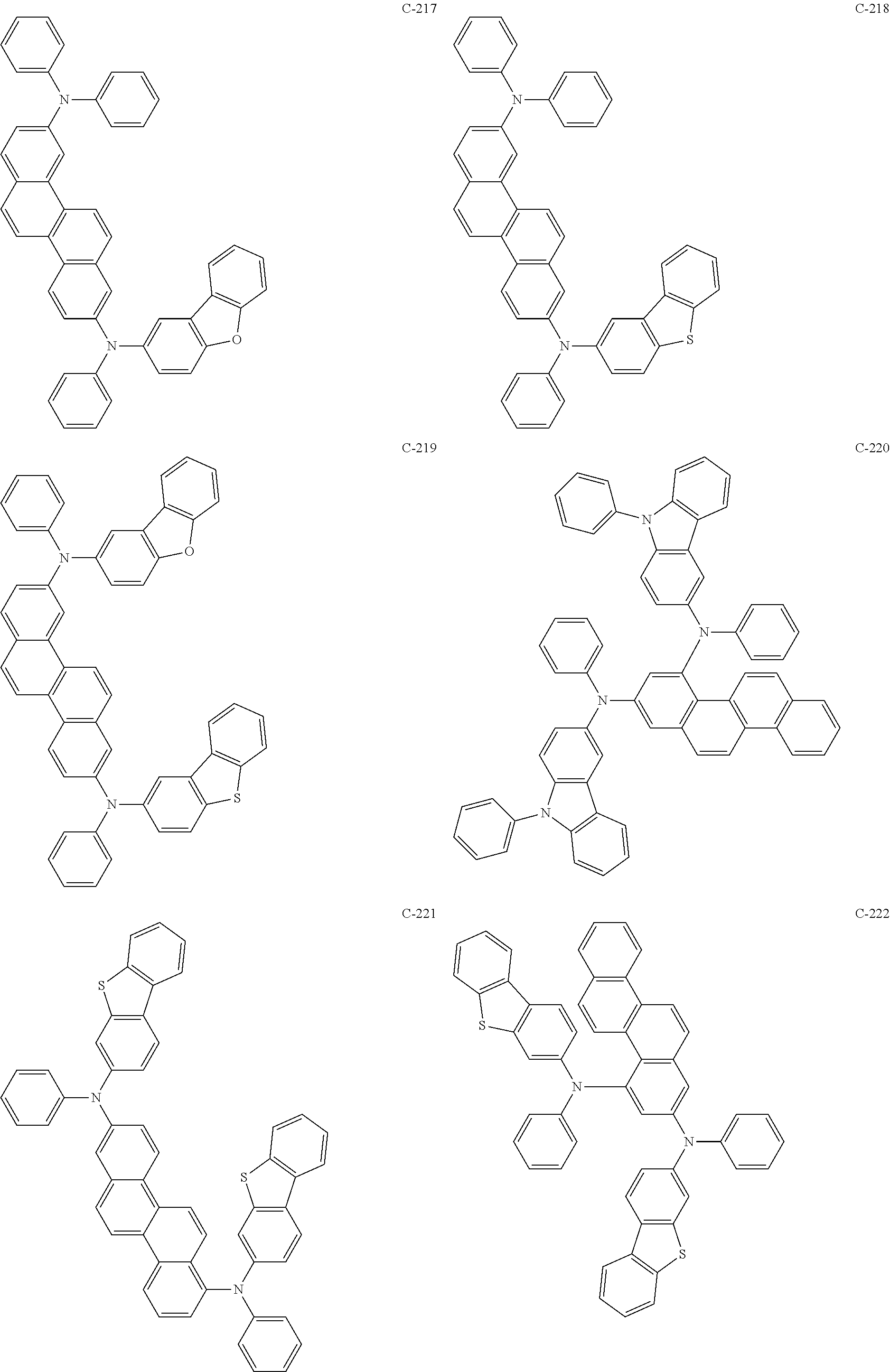

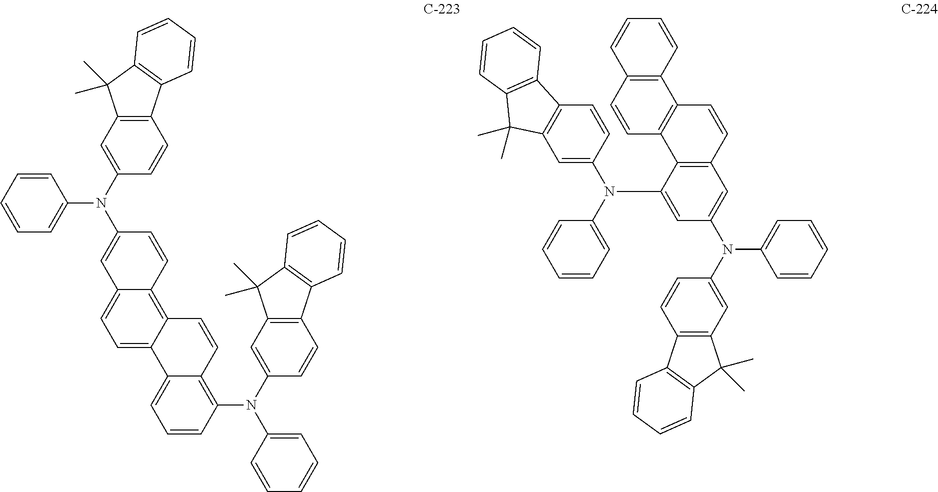 [SMILES: CC1(C)c2ccccc2-c2ccc(N(c3ccccc3)c3ccc4c(ccc5c6cccc(N(c7ccccc7)c7ccc8c(c7)C(C)(C)c7ccccc7-8)c6ccc45)c3)cc21 ; CC1(C)c2ccccc2-c2ccc(N(c3ccccc3)c3cc(N(c4ccccc4)c4ccc5c(c4)C(C)(C)c4ccccc4-5)c4c(ccc5c6ccccc6ccc54)c3)cc21]

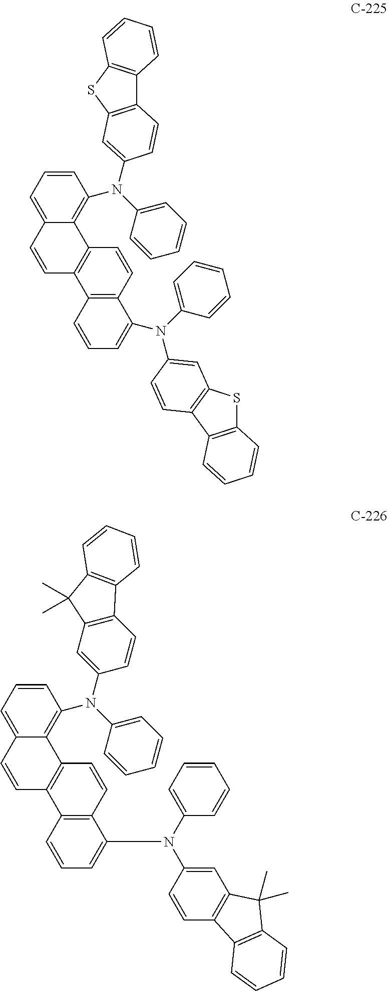 [SMILES: c1ccc(N(c2ccc3c(c2)sc2ccccc23)c2cccc3c2ccc2c3ccc3cccc(N(c4ccccc4)c4ccc5c(c4)sc4ccccc45)c32)cc1 ; CC1(C)c2ccccc2-c2ccc(N(c3ccccc3)c3cccc4c3ccc3c4ccc4cccc(N(c5ccccc5)c5ccc6c(c5)C(C)(C)c5ccccc5-6)c43)cc21]

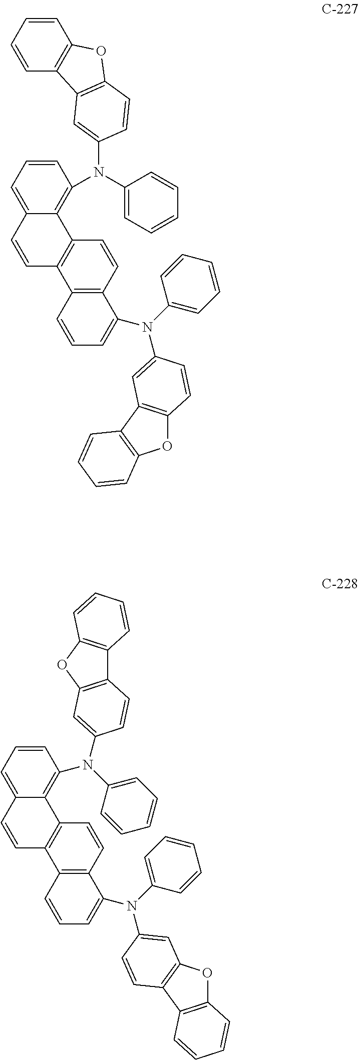 [SMILES: c1ccc(N(c2ccc3oc4ccccc4c3c2)c2cccc3c2ccc2c3ccc3cccc(N(c4ccccc4)c4ccc5oc6ccccc6c5c4)c32)cc1 ; c1ccc(N(c2ccc3c(c2)oc2ccccc23)c2cccc3c2ccc2c3ccc3cccc(N(c4ccccc4)c4ccc5c(c4)oc4ccccc45)c32)cc1]

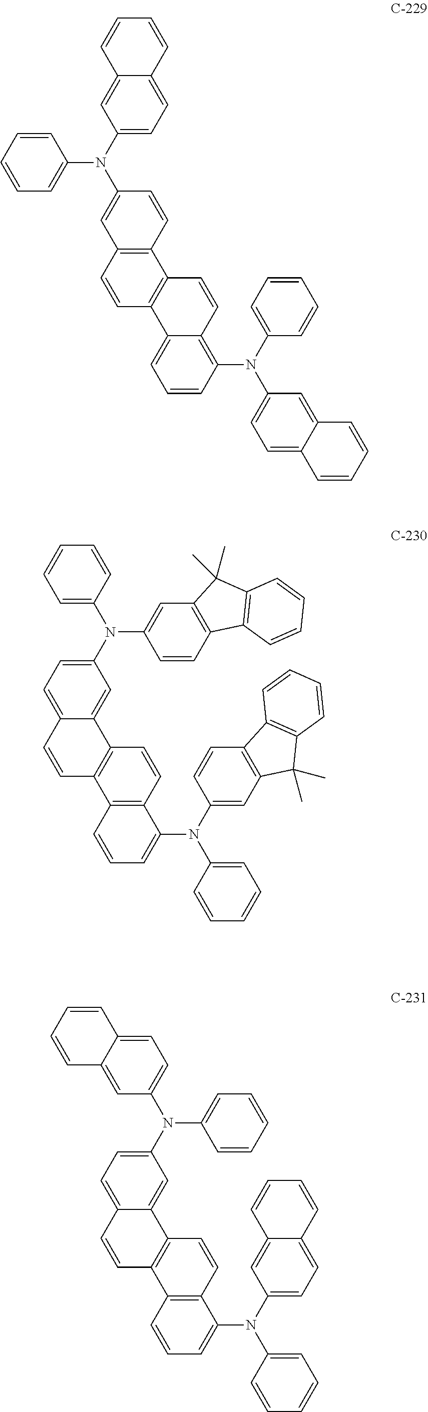 [SMILES: c1ccc(N(c2ccc3ccccc3c2)c2ccc3c(ccc4c5cccc(N(c6ccccc6)c6ccc7ccccc7c6)c5ccc34)c2)cc1 ; CC1(C)c2ccccc2-c2ccc(N(c3ccccc3)c3ccc4ccc5c6cccc(N(c7ccccc7)c7ccc8c(c7)C(C)(C)c7ccccc7-8)c6ccc5c4c3)cc21 ; c1ccc(N(c2ccc3ccccc3c2)c2ccc3ccc4c5cccc(N(c6ccccc6)c6ccc7ccccc7c6)c5ccc4c3c2)cc1]

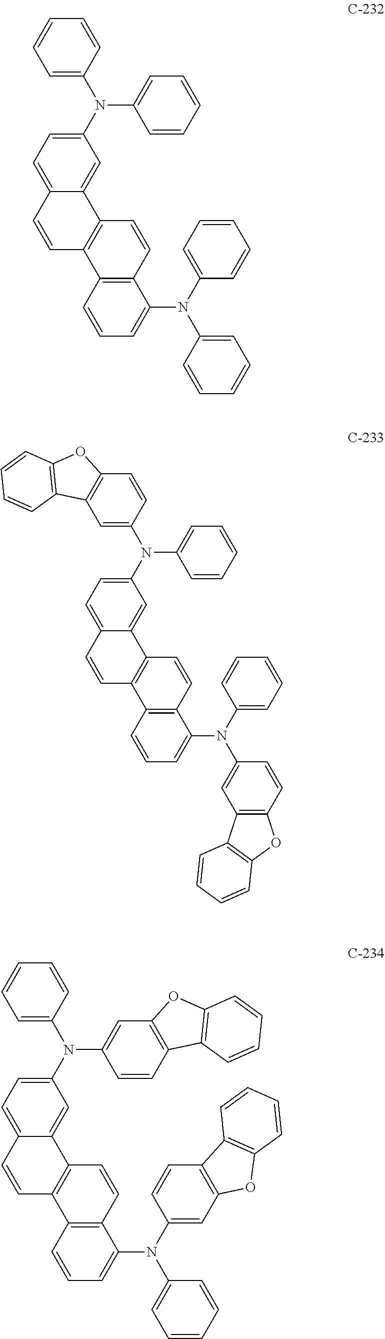 [SMILES: c1ccc(N(c2ccccc2)c2ccc3ccc4c5cccc(N(c6ccccc6)c6ccccc6)c5ccc4c3c2)cc1 ; c1ccc(N(c2ccc3ccc4c5cccc(N(c6ccccc6)c6ccc7oc8ccccc8c7c6)c5ccc4c3c2)c2ccc3oc4ccccc4c3c2)cc1 ; c1ccc(N(c2ccc3c(c2)oc2ccccc23)c2ccc3ccc4c5cccc(N(c6ccccc6)c6ccc7c(c6)oc6ccccc67)c5ccc4c3c2)cc1]

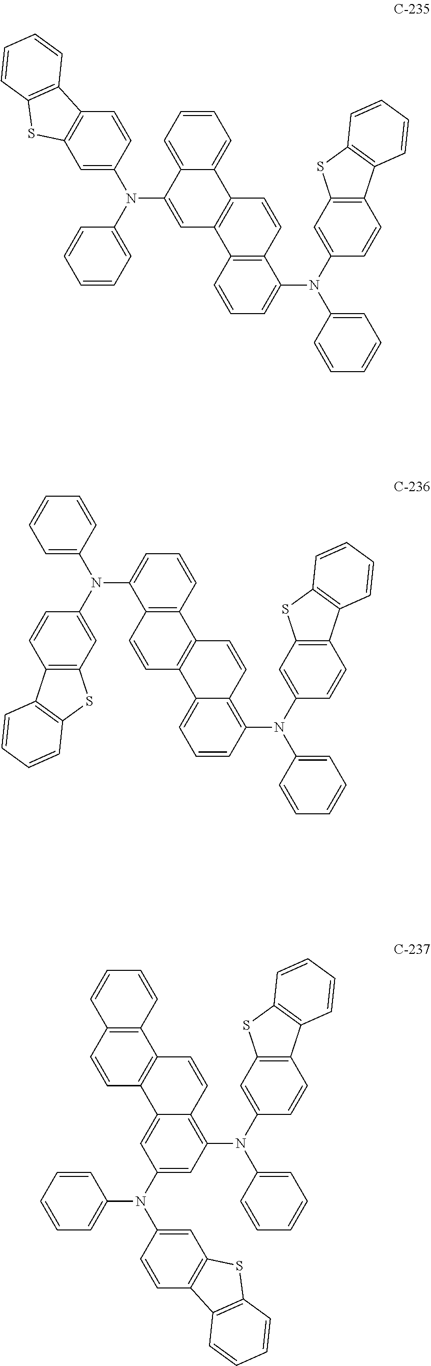 [SMILES: c1ccc(N(c2ccc3c(c2)sc2ccccc23)c2cc3c4cccc(N(c5ccccc5)c5ccc6c(c5)sc5ccccc56)c4ccc3c3ccccc23)cc1 ; c1ccc(N(c2ccc3c(c2)sc2ccccc23)c2cccc3c2ccc2c4cccc(N(c5ccccc5)c5ccc6c(c5)sc5ccccc56)c4ccc32)cc1 ; c1ccc(N(c2ccc3c(c2)sc2ccccc23)c2cc(N(c3ccccc3)c3ccc4c(c3)sc3ccccc34)c3ccc4c5ccccc5ccc4c3c2)cc1]

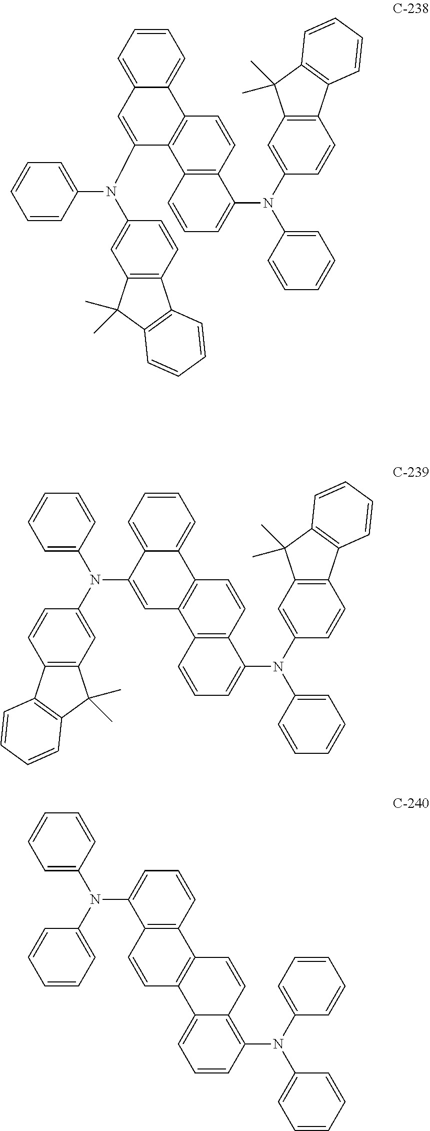 [SMILES: CC1(C)c2ccccc2-c2ccc(N(c3ccccc3)c3cccc4c3ccc3c5ccccc5cc(N(c5ccccc5)c5ccc6c(c5)C(C)(C)c5ccccc5-6)c43)cc21 ; CC1(C)c2ccccc2-c2ccc(N(c3ccccc3)c3cc4c5cccc(N(c6ccccc6)c6ccc7c(c6)C(C)(C)c6ccccc6-7)c5ccc4c4ccccc34)cc21 ; c1ccc(N(c2ccccc2)c2cccc3c2ccc2c4cccc(N(c5ccccc5)c5ccccc5)c4ccc32)cc1]

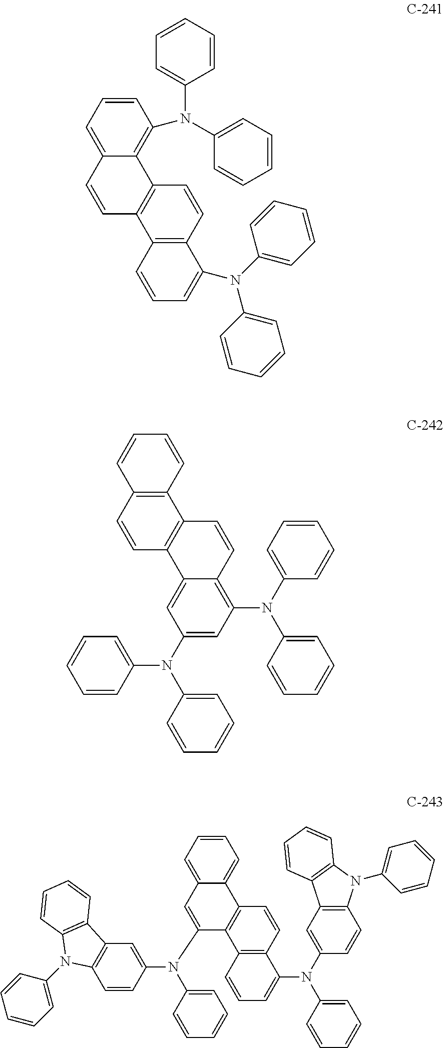

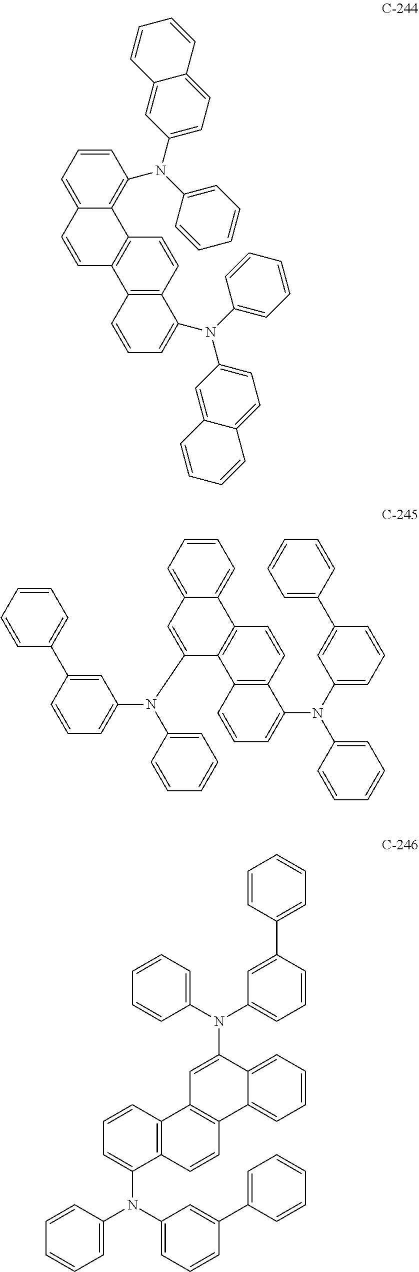

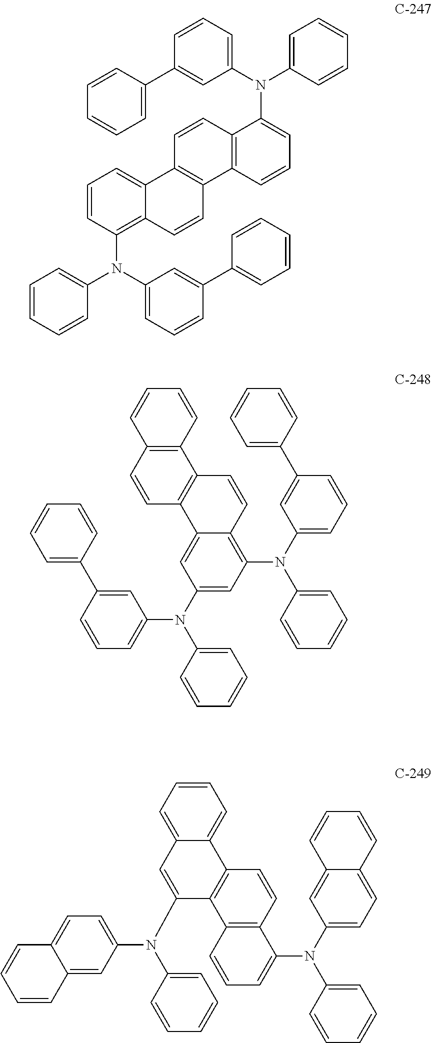

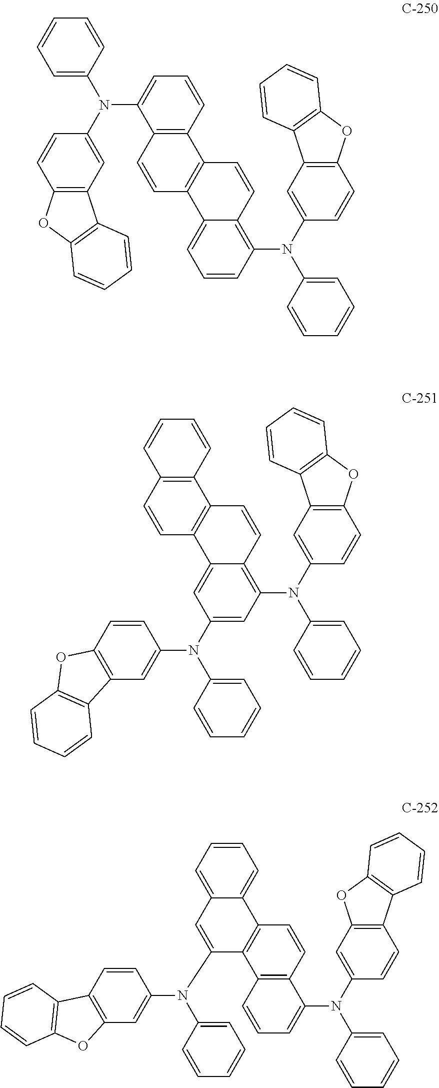 [SMILES: c1ccc(N(c2ccc3oc4ccccc4c3c2)c2cccc3c2ccc2c4cccc(N(c5ccccc5)c5ccc6oc7ccccc7c6c5)c4ccc32)cc1 ; c1ccc(N(c2ccc3oc4ccccc4c3c2)c2cc(N(c3ccccc3)c3ccc4oc5ccccc5c4c3)c3ccc4c5ccccc5ccc4c3c2)cc1 ; c1ccc(N(c2ccc3c(c2)oc2ccccc23)c2cccc3c2ccc2c4ccccc4cc(N(c4ccccc4)c4ccc5c(c4)oc4ccccc45)c32)cc1]

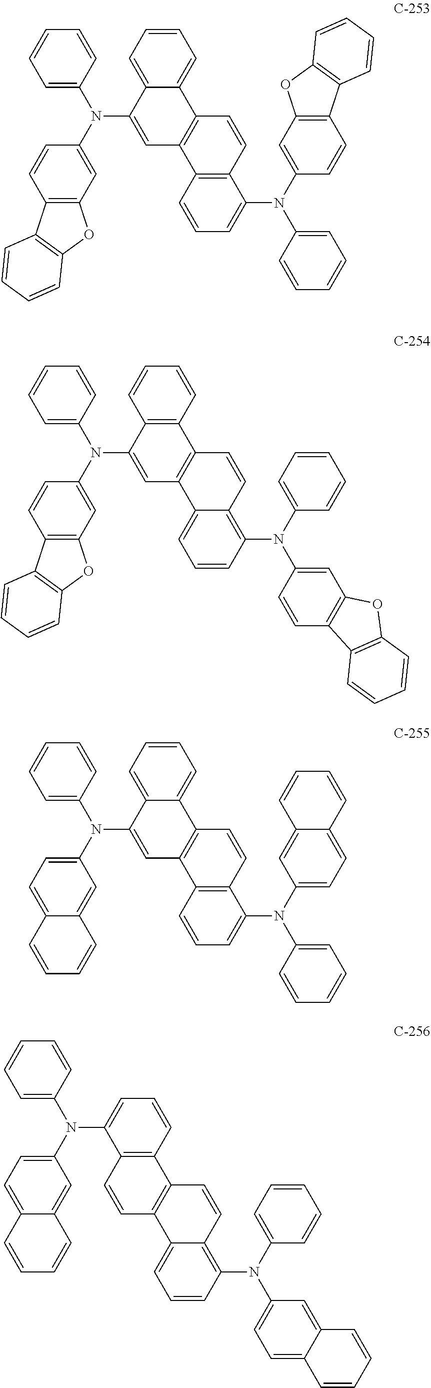 [SMILES: c1ccc(N(c2ccc3c(c2)oc2ccccc23)c2cc3c4cccc(N(c5ccccc5)c5ccc6c(c5)oc5ccccc56)c4ccc3c3ccccc23)cc1 ; c1ccc(N(c2ccc3c(c2)oc2ccccc23)c2cc3c4cccc(N(c5ccccc5)c5ccc6c(c5)oc5ccccc56)c4ccc3c3ccccc23)cc1 ; c1ccc(N(c2ccc3ccccc3c2)c2cc3c4cccc(N(c5ccccc5)c5ccc6ccccc6c5)c4ccc3c3ccccc23)cc1 ; c1ccc(N(c2ccc3ccccc3c2)c2cccc3c2ccc2c4cccc(N(c5ccccc5)c5ccc6ccccc6c5)c4ccc32)cc1]

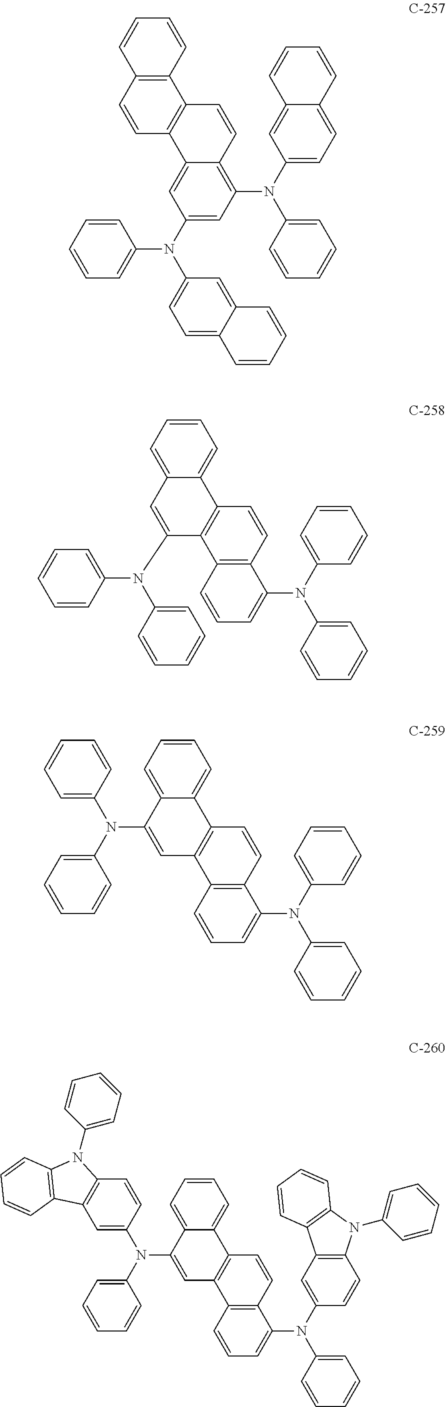 [SMILES: c1ccc(N(c2ccc3ccccc3c2)c2cc(N(c3ccccc3)c3ccc4ccccc4c3)c3ccc4c5ccccc5ccc4c3c2)cc1 ; c1ccc(N(c2ccccc2)c2cccc3c2ccc2c4ccccc4cc(N(c4ccccc4)c4ccccc4)c32)cc1 ; c1ccc(N(c2ccccc2)c2cc3c4cccc(N(c5ccccc5)c5ccccc5)c4ccc3c3ccccc23)cc1 ; c1ccc(N(c2ccc3c(c2)c2ccccc2n3-c2ccccc2)c2cc3c4cccc(N(c5ccccc5)c5ccc6c(c5)c5ccccc5n6-c5ccccc5)c4ccc3c3ccccc23)cc1]

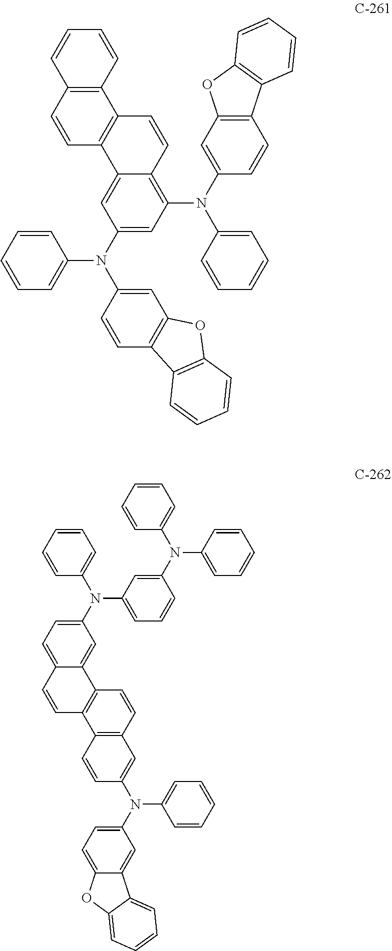 [SMILES: c1ccc(N(c2ccc3c(c2)oc2ccccc23)c2cc(N(c3ccccc3)c3ccc4c(c3)oc3ccccc34)c3ccc4c5ccccc5ccc4c3c2)cc1 ; c1ccc(N(c2ccccc2)c2cccc(N(c3ccccc3)c3ccc4ccc5c6ccc(N(c7ccccc7)c7ccc8oc9ccccc9c8c7)cc6ccc5c4c3)c2)cc1]

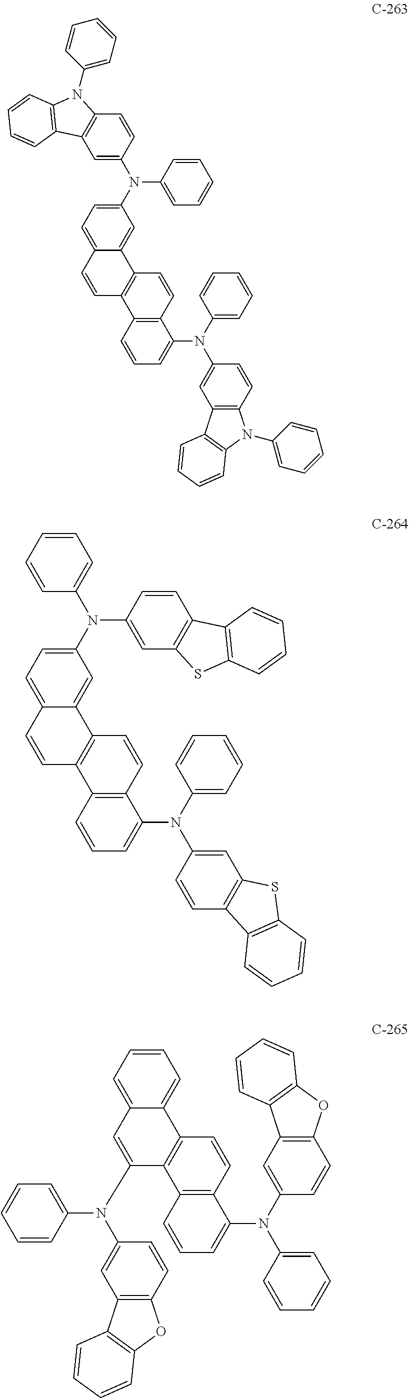 [SMILES: c1ccc(N(c2ccc3ccc4c5cccc(N(c6ccccc6)c6ccc7c(c6)c6ccccc6n7-c6ccccc6)c5ccc4c3c2)c2ccc3c(c2)c2ccccc2n3-c2ccccc2)cc1 ; c1ccc(N(c2ccc3c(c2)sc2ccccc23)c2ccc3ccc4c5cccc(N(c6ccccc6)c6ccc7c(c6)sc6ccccc67)c5ccc4c3c2)cc1 ; c1ccc(N(c2ccc3oc4ccccc4c3c2)c2cccc3c2ccc2c4ccccc4cc(N(c4ccccc4)c4ccc5oc6ccccc6c5c4)c32)cc1]

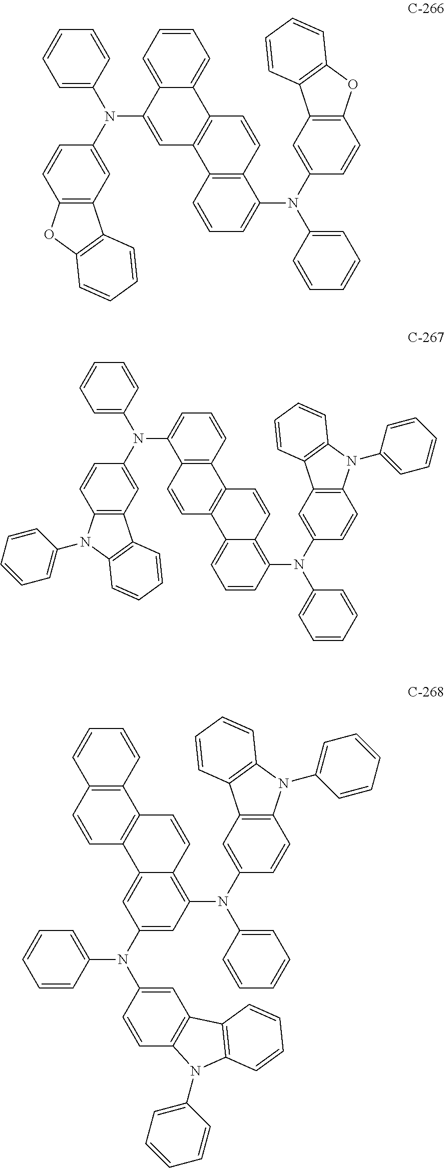 [SMILES: c1ccc(N(c2ccc3oc4ccccc4c3c2)c2cc3c4cccc(N(c5ccccc5)c5ccc6oc7ccccc7c6c5)c4ccc3c3ccccc23)cc1 ; c1ccc(N(c2ccc3c(c2)c2ccccc2n3-c2ccccc2)c2cccc3c2ccc2c4cccc(N(c5ccccc5)c5ccc6c(c5)c5ccccc5n6-c5ccccc5)c4ccc32)cc1 ; c1ccc(N(c2cc(N(c3ccccc3)c3ccc4c(c3)c3ccccc3n4-c3ccccc3)c3ccc4c5ccccc5ccc4c3c2)c2ccc3c(c2)c2ccccc2n3-c2ccccc2)cc1]

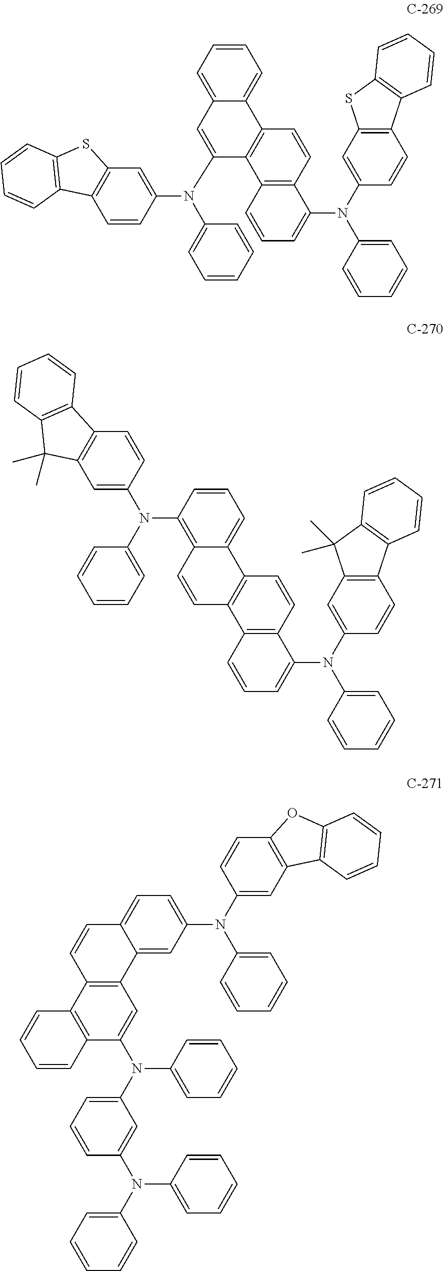 [SMILES: c1ccc(N(c2ccc3c(c2)sc2ccccc23)c2cccc3c2ccc2c4ccccc4cc(N(c4ccccc4)c4ccc5c(c4)sc4ccccc45)c32)cc1 ; CC1(C)c2ccccc2-c2ccc(N(c3ccccc3)c3cccc4c3ccc3c5cccc(N(c6ccccc6)c6ccc7c(c6)C(C)(C)c6ccccc6-7)c5ccc43)cc21 ; c1ccc(N(c2ccccc2)c2cccc(N(c3ccccc3)c3cc4c5cc(N(c6ccccc6)c6ccc7oc8ccccc8c7c6)ccc5ccc4c4ccccc34)c2)cc1]

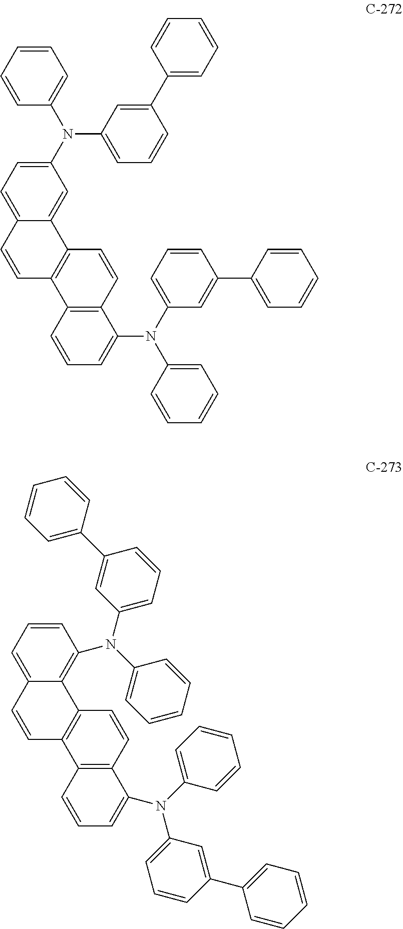 [SMILES: c1ccc(-c2cccc(N(c3ccccc3)c3ccc4ccc5c6cccc(N(c7ccccc7)c7cccc(-c8ccccc8)c7)c6ccc5c4c3)c2)cc1 ; c1ccc(-c2cccc(N(c3ccccc3)c3cccc4c3ccc3c4ccc4cccc(N(c5ccccc5)c5cccc(-c6ccccc6)c5)c43)c2)cc1]

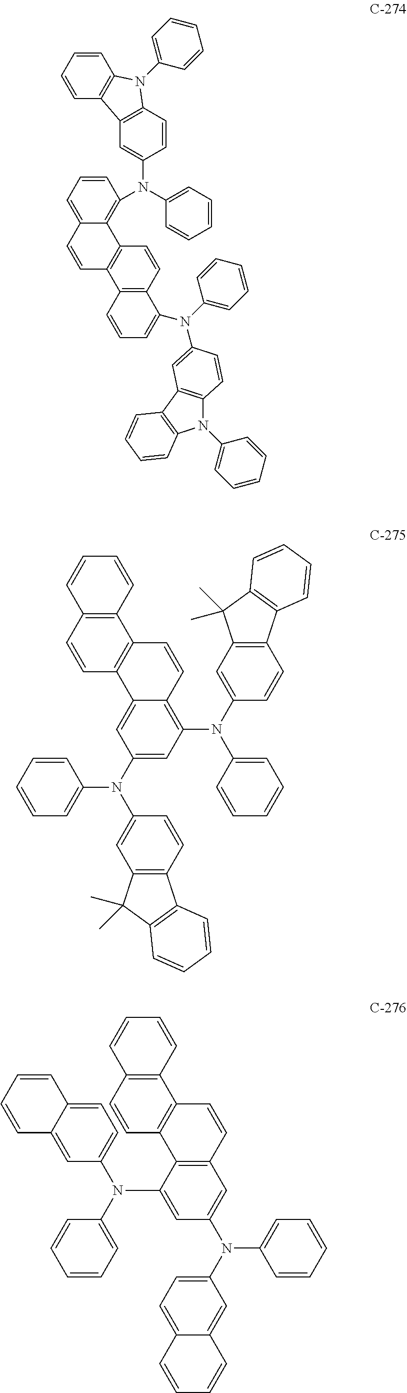 [SMILES: c1ccc(N(c2ccc3c(c2)c2ccccc2n3-c2ccccc2)c2cccc3c2ccc2c3ccc3cccc(N(c4ccccc4)c4ccc5c(c4)c4ccccc4n5-c4ccccc4)c32)cc1 ; CC1(C)c2ccccc2-c2ccc(N(c3ccccc3)c3cc(N(c4ccccc4)c4ccc5c(c4)C(C)(C)c4ccccc4-5)c4ccc5c6ccccc6ccc5c4c3)cc21 ; c1ccc(N(c2ccc3ccccc3c2)c2cc(N(c3ccccc3)c3ccc4ccccc4c3)c3c(ccc4c5ccccc5ccc43)c2)cc1]

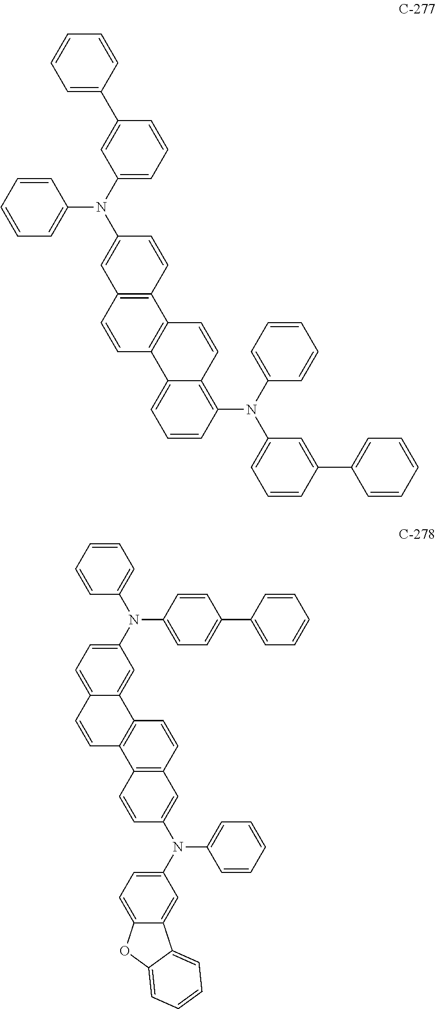 [SMILES: c1ccc(-c2cccc(N(c3ccccc3)c3ccc4c(ccc5c6cccc(N(c7ccccc7)c7cccc(-c8ccccc8)c7)c6ccc45)c3)c2)cc1 ; c1ccc(-c2ccc(N(c3ccccc3)c3ccc4ccc5c6ccc(N(c7ccccc7)c7ccc8oc9ccccc9c8c7)cc6ccc5c4c3)cc2)cc1]

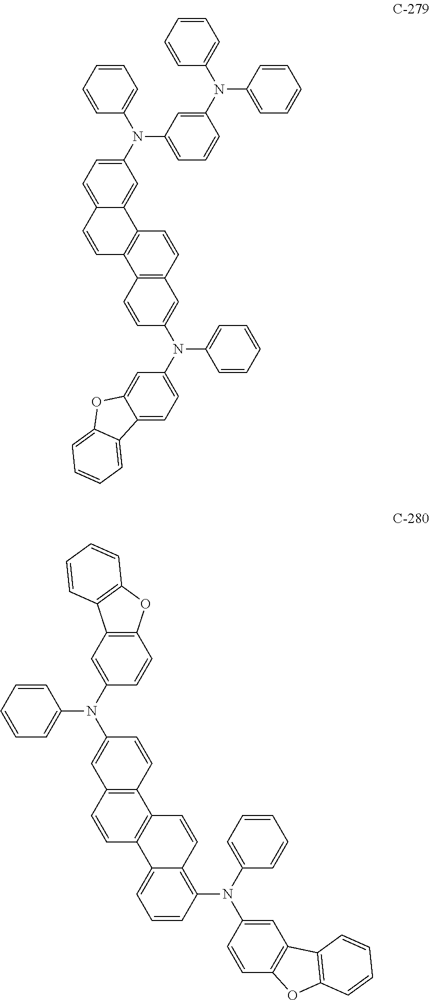 [SMILES: c1ccc(N(c2ccccc2)c2cccc(N(c3ccccc3)c3ccc4ccc5c6ccc(N(c7ccccc7)c7ccc8c(c7)oc7ccccc78)cc6ccc5c4c3)c2)cc1 ; c1ccc(N(c2ccc3c(ccc4c5cccc(N(c6ccccc6)c6ccc7oc8ccccc8c7c6)c5ccc34)c2)c2ccc3oc4ccccc4c3c2)cc1]

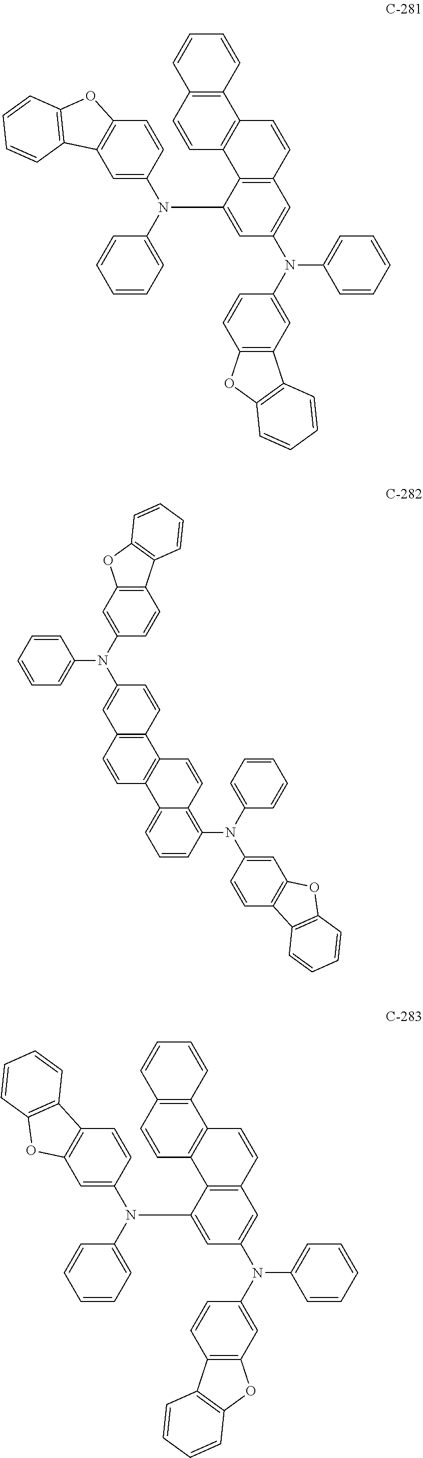 [SMILES: c1ccc(N(c2cc(N(c3ccccc3)c3ccc4oc5ccccc5c4c3)c3c(ccc4c5ccccc5ccc43)c2)c2ccc3oc4ccccc4c3c2)cc1 ; c1ccc(N(c2ccc3c(ccc4c5cccc(N(c6ccccc6)c6ccc7c(c6)oc6ccccc67)c5ccc34)c2)c2ccc3c(c2)oc2ccccc23)cc1 ; c1ccc(N(c2cc(N(c3ccccc3)c3ccc4c(c3)oc3ccccc34)c3c(ccc4c5ccccc5ccc43)c2)c2ccc3c(c2)oc2ccccc23)cc1]

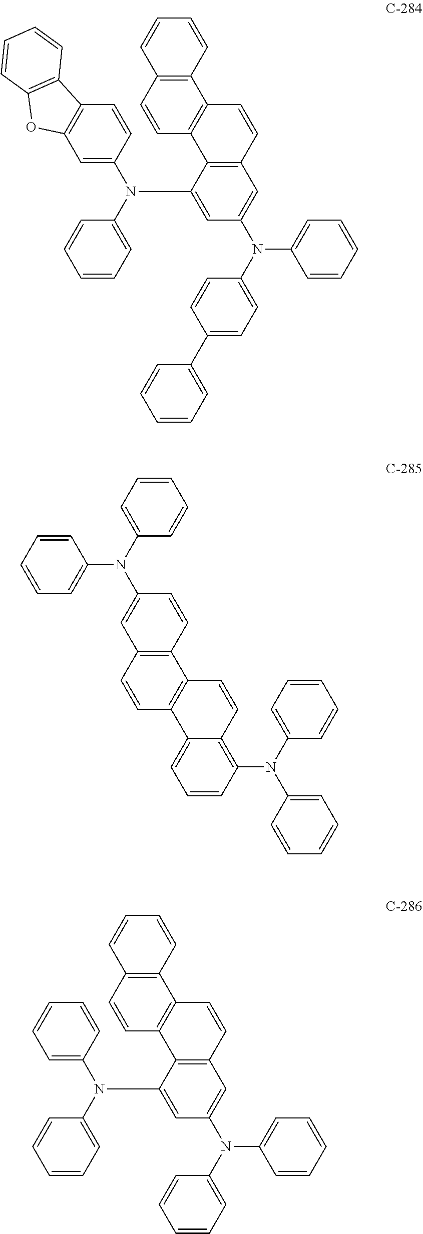 [SMILES: c1ccc(-c2ccc(N(c3ccccc3)c3cc(N(c4ccccc4)c4ccc5c(c4)oc4ccccc45)c4c(ccc5c6ccccc6ccc54)c3)cc2)cc1 ; c1ccc(N(c2ccccc2)c2ccc3c(ccc4c5cccc(N(c6ccccc6)c6ccccc6)c5ccc34)c2)cc1 ; c1ccc(N(c2ccccc2)c2cc(N(c3ccccc3)c3ccccc3)c3c(ccc4c5ccccc5ccc43)c2)cc1]

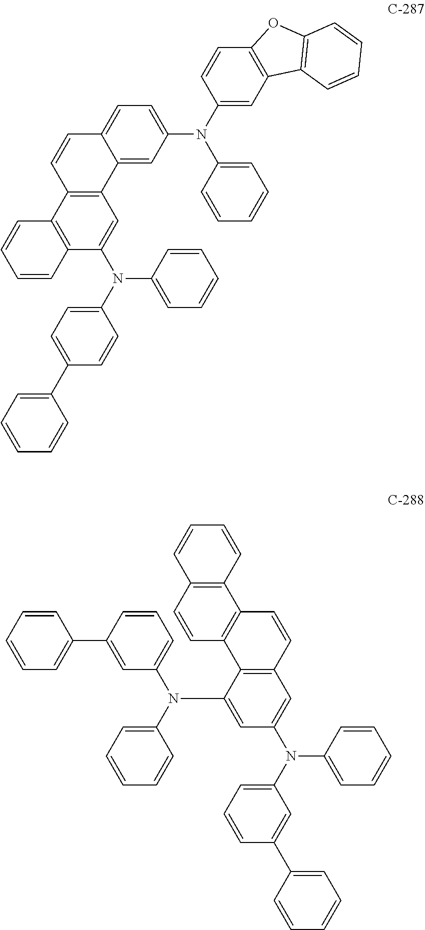 [SMILES: c1ccc(-c2ccc(N(c3ccccc3)c3cc4c5cc(N(c6ccccc6)c6ccc7oc8ccccc8c7c6)ccc5ccc4c4ccccc34)cc2)cc1 ; c1ccc(-c2cccc(N(c3ccccc3)c3cc(N(c4ccccc4)c4cccc(-c5ccccc5)c4)c4c(ccc5c6ccccc6ccc54)c3)c2)cc1]

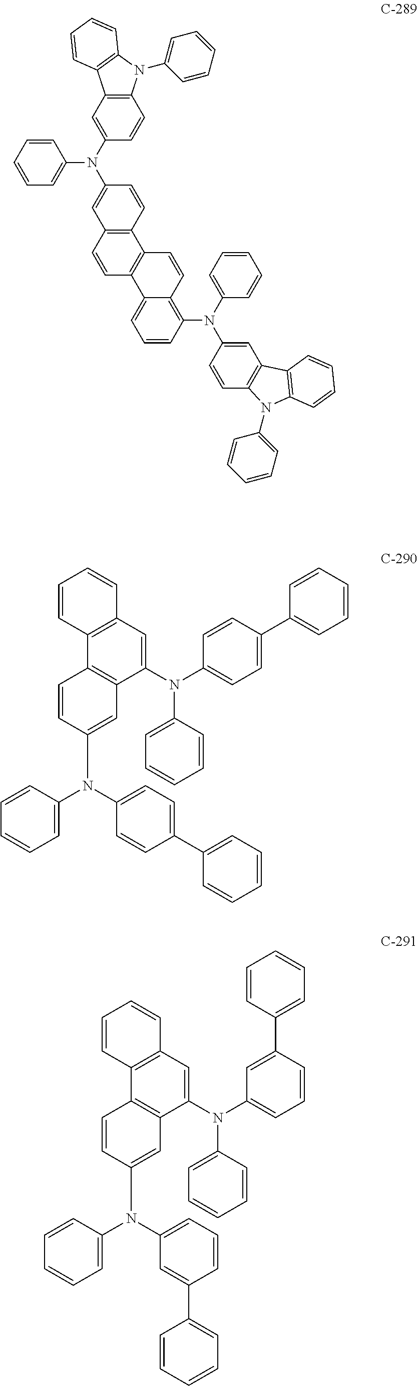 [SMILES: c1ccc(N(c2ccc3c(ccc4c5cccc(N(c6ccccc6)c6ccc7c(c6)c6ccccc6n7-c6ccccc6)c5ccc34)c2)c2ccc3c(c2)c2ccccc2n3-c2ccccc2)cc1 ; c1ccc(-c2ccc(N(c3ccccc3)c3ccc4c(c3)c(N(c3ccccc3)c3ccc(-c5ccccc5)cc3)cc3ccccc34)cc2)cc1 ; c1ccc(-c2cccc(N(c3ccccc3)c3ccc4c(c3)c(N(c3ccccc3)c3cccc(-c5ccccc5)c3)cc3ccccc34)c2)cc1]

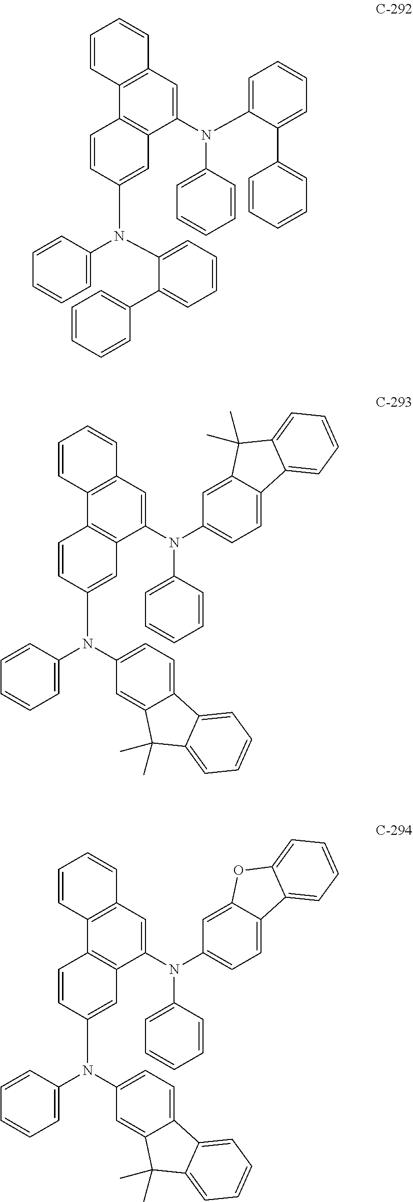 [SMILES: c1ccc(-c2ccccc2N(c2ccccc2)c2ccc3c(c2)c(N(c2ccccc2)c2ccccc2-c2ccccc2)cc2ccccc23)cc1 ; CC1(C)c2ccccc2-c2ccc(N(c3ccccc3)c3ccc4c(c3)c(N(c3ccccc3)c3ccc5c(c3)C(C)(C)c3ccccc3-5)cc3ccccc34)cc21 ; CC1(C)c2ccccc2-c2ccc(N(c3ccccc3)c3ccc4c(c3)c(N(c3ccccc3)c3ccc5c(c3)oc3ccccc35)cc3ccccc34)cc21]

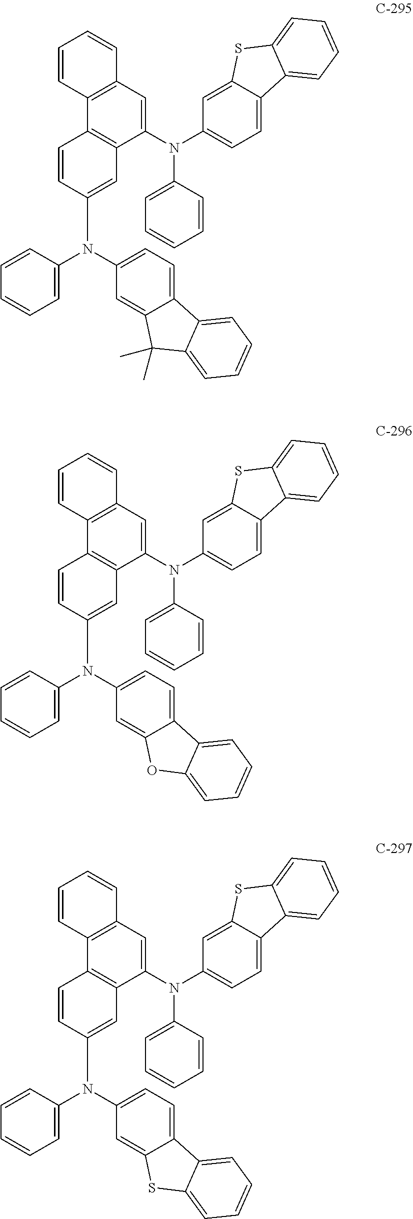 [SMILES: CC1(C)c2ccccc2-c2ccc(N(c3ccccc3)c3ccc4c(c3)c(N(c3ccccc3)c3ccc5c(c3)sc3ccccc35)cc3ccccc34)cc21 ; c1ccc(N(c2ccc3c(c2)oc2ccccc23)c2ccc3c(c2)c(N(c2ccccc2)c2ccc4c(c2)sc2ccccc24)cc2ccccc23)cc1 ; c1ccc(N(c2ccc3c(c2)sc2ccccc23)c2ccc3c(c2)c(N(c2ccccc2)c2ccc4c(c2)sc2ccccc24)cc2ccccc23)cc1]

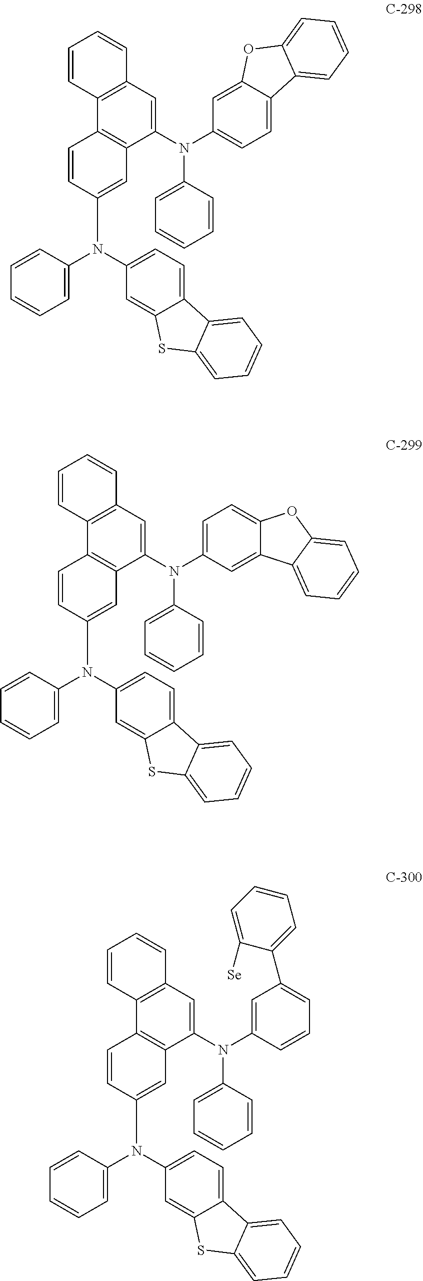

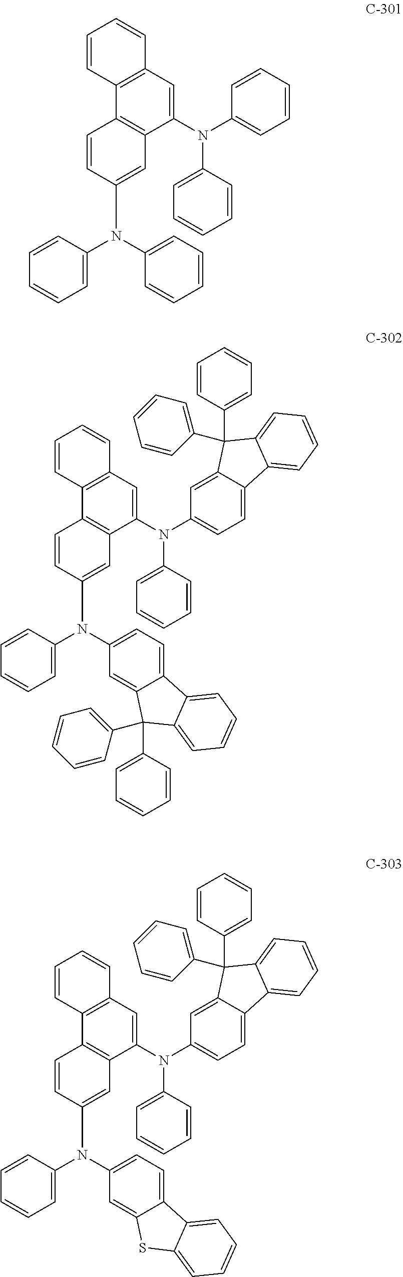 [SMILES: c1ccc(N(c2ccccc2)c2ccc3c(c2)c(N(c2ccccc2)c2ccccc2)cc2ccccc23)cc1 ; c1ccc(N(c2ccc3c(c2)C(c2ccccc2)(c2ccccc2)c2ccccc2-3)c2ccc3c(c2)c(N(c2ccccc2)c2ccc4c(c2)C(c2ccccc2)(c2ccccc2)c2ccccc2-4)cc2ccccc23)cc1 ; c1ccc(N(c2ccc3c(c2)sc2ccccc23)c2ccc3c(c2)c(N(c2ccccc2)c2ccc4c(c2)C(c2ccccc2)(c2ccccc2)c2ccccc2-4)cc2ccccc23)cc1]

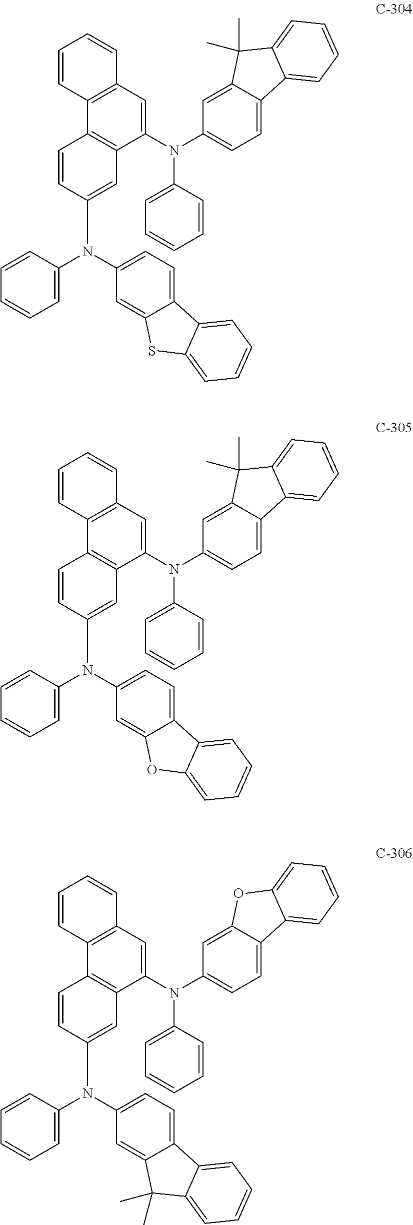 [SMILES: CC1(C)c2ccccc2-c2ccc(N(c3ccccc3)c3cc4ccccc4c4ccc(N(c5ccccc5)c5ccc6c(c5)sc5ccccc56)cc34)cc21 ; CC1(C)c2ccccc2-c2ccc(N(c3ccccc3)c3cc4ccccc4c4ccc(N(c5ccccc5)c5ccc6c(c5)oc5ccccc56)cc34)cc21 ; CC1(C)c2ccccc2-c2ccc(N(c3ccccc3)c3ccc4c(c3)c(N(c3ccccc3)c3ccc5c(c3)oc3ccccc35)cc3ccccc34)cc21]

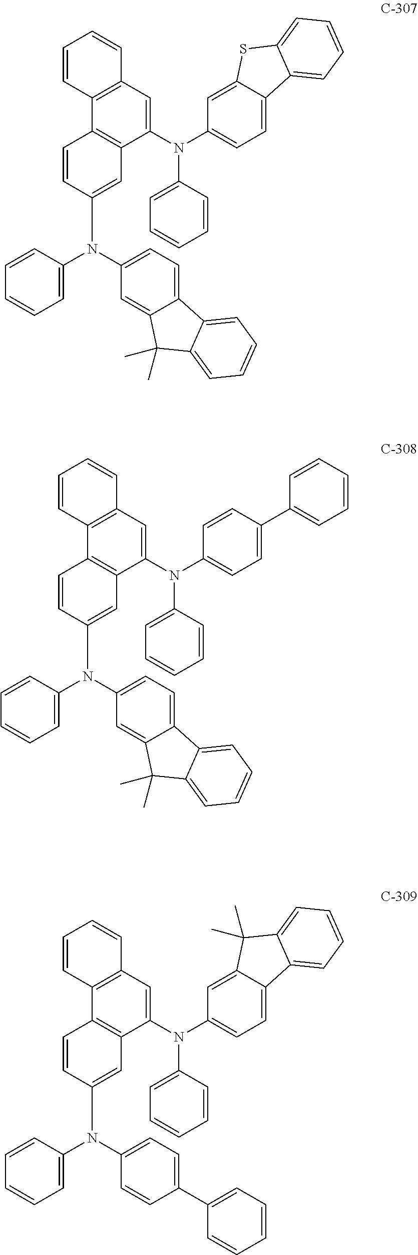 [SMILES: CC1(C)c2ccccc2-c2ccc(N(c3ccccc3)c3ccc4c(c3)c(N(c3ccccc3)c3ccc5c(c3)sc3ccccc35)cc3ccccc34)cc21 ; CC1(C)c2ccccc2-c2ccc(N(c3ccccc3)c3ccc4c(c3)c(N(c3ccccc3)c3ccc(-c5ccccc5)cc3)cc3ccccc34)cc21 ; CC1(C)c2ccccc2-c2ccc(N(c3ccccc3)c3cc4ccccc4c4ccc(N(c5ccccc5)c5ccc(-c6ccccc6)cc5)cc34)cc21]

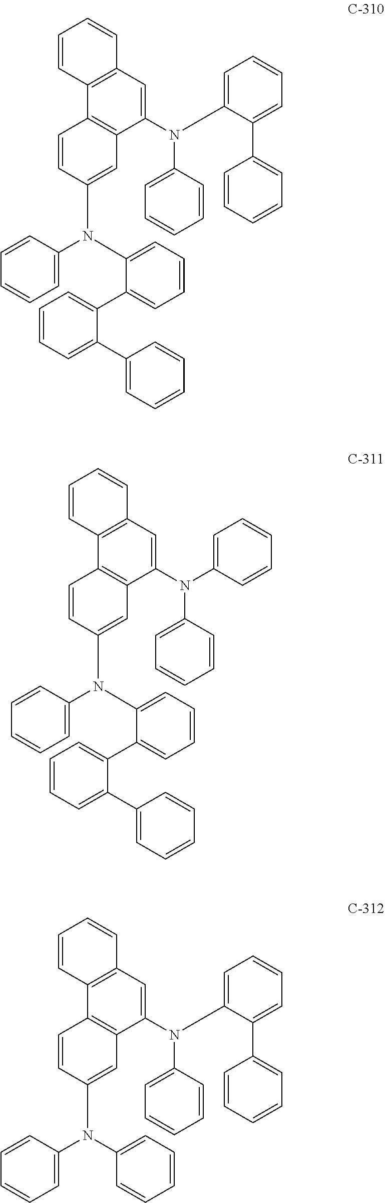 [SMILES: c1ccc(-c2ccccc2-c2ccccc2N(c2ccccc2)c2ccc3c(c2)c(N(c2ccccc2)c2ccccc2-c2ccccc2)cc2ccccc23)cc1 ; c1ccc(-c2ccccc2-c2ccccc2N(c2ccccc2)c2ccc3c(c2)c(N(c2ccccc2)c2ccccc2)cc2ccccc23)cc1 ; c1ccc(-c2ccccc2N(c2ccccc2)c2cc3ccccc3c3ccc(N(c4ccccc4)c4ccccc4)cc23)cc1]

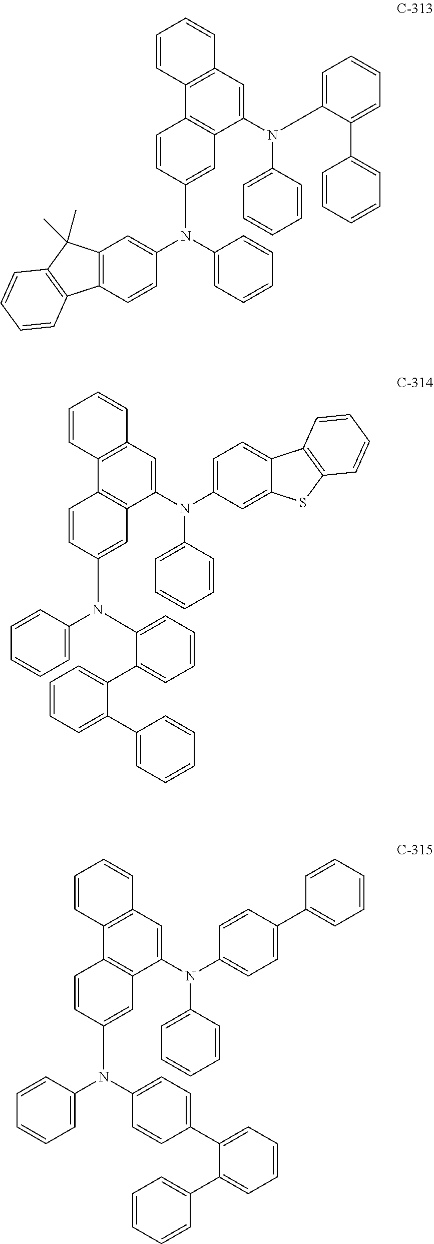 [SMILES: CC1(C)c2ccccc2-c2ccc(N(c3ccccc3)c3ccc4c(c3)c(N(c3ccccc3)c3ccccc3-c3ccccc3)cc3ccccc34)cc21 ; c1ccc(-c2ccccc2-c2ccccc2N(c2ccccc2)c2ccc3c(c2)c(N(c2ccccc2)c2ccc4c(c2)sc2ccccc24)cc2ccccc23)cc1 ; c1ccc(-c2ccc(N(c3ccccc3)c3cc4ccccc4c4ccc(N(c5ccccc5)c5ccc(-c6ccccc6-c6ccccc6)cc5)cc34)cc2)cc1]

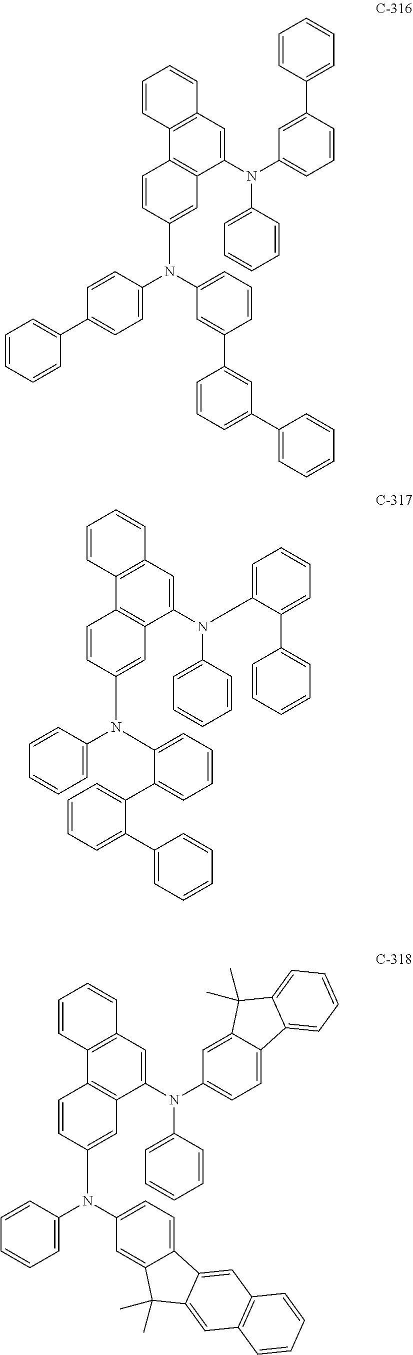 [SMILES: c1ccc(-c2ccc(N(c3cccc(-c4cccc(-c5ccccc5)c4)c3)c3ccc4c(c3)c(N(c3ccccc3)c3cccc(-c5ccccc5)c3)cc3ccccc34)cc2)cc1 ; c1ccc(-c2ccccc2-c2ccccc2N(c2ccccc2)c2ccc3c(c2)c(N(c2ccccc2)c2ccccc2-c2ccccc2)cc2ccccc23)cc1 ; CC1(C)c2ccccc2-c2ccc(N(c3ccccc3)c3cc4ccccc4c4ccc(N(c5ccccc5)c5ccc6c(c5)C(C)(C)c5cc7ccccc7cc5-6)cc34)cc21]

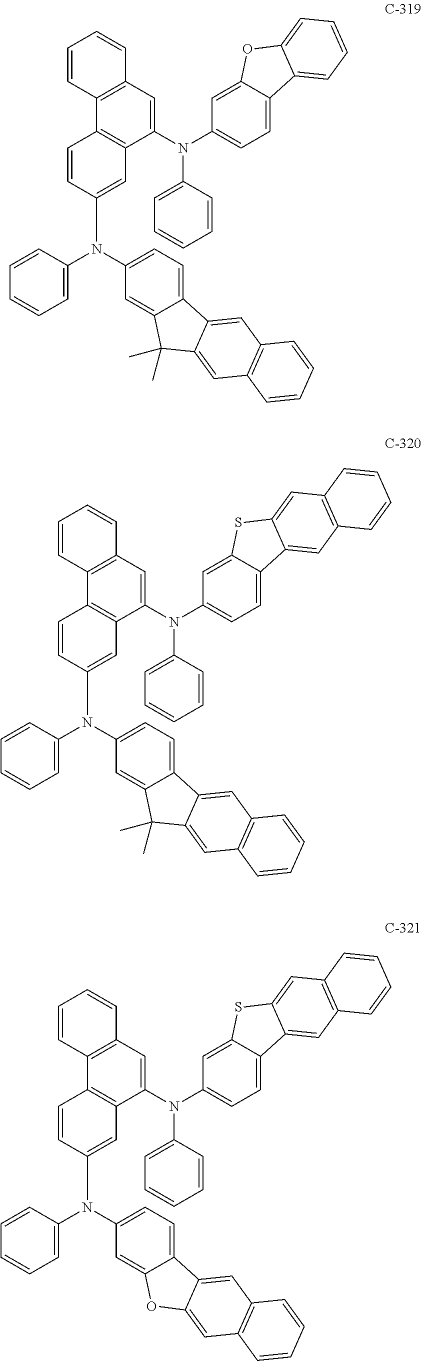 [SMILES: CC1(C)c2cc(N(c3ccccc3)c3ccc4c(c3)c(N(c3ccccc3)c3ccc5c(c3)oc3ccccc35)cc3ccccc34)ccc2-c2cc3ccccc3cc21 ; CC1(C)c2cc(N(c3ccccc3)c3ccc4c(c3)c(N(c3ccccc3)c3ccc5c(c3)sc3cc6ccccc6cc35)cc3ccccc34)ccc2-c2cc3ccccc3cc21 ; c1ccc(N(c2ccc3c(c2)oc2cc4ccccc4cc23)c2ccc3c(c2)c(N(c2ccccc2)c2ccc4c(c2)sc2cc5ccccc5cc24)cc2ccccc23)cc1]

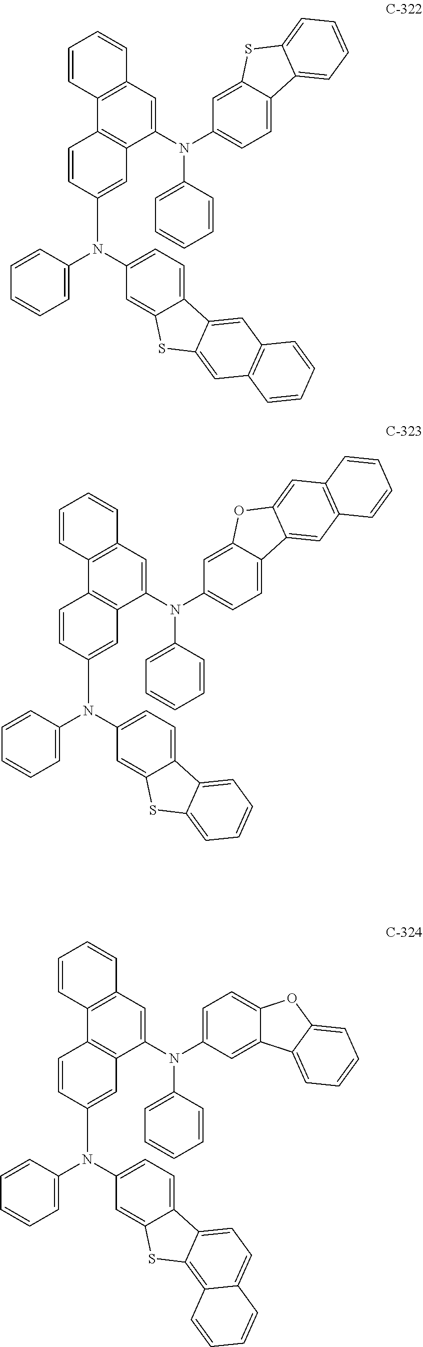 [SMILES: c1ccc(N(c2ccc3c(c2)sc2cc4ccccc4cc23)c2ccc3c(c2)c(N(c2ccccc2)c2ccc4c(c2)sc2ccccc24)cc2ccccc23)cc1 ; c1ccc(N(c2ccc3c(c2)sc2ccccc23)c2ccc3c(c2)c(N(c2ccccc2)c2ccc4c(c2)oc2cc5ccccc5cc24)cc2ccccc23)cc1 ; c1ccc(N(c2ccc3c(c2)sc2c4ccccc4ccc32)c2ccc3c(c2)c(N(c2ccccc2)c2ccc4oc5ccccc5c4c2)cc2ccccc23)cc1]

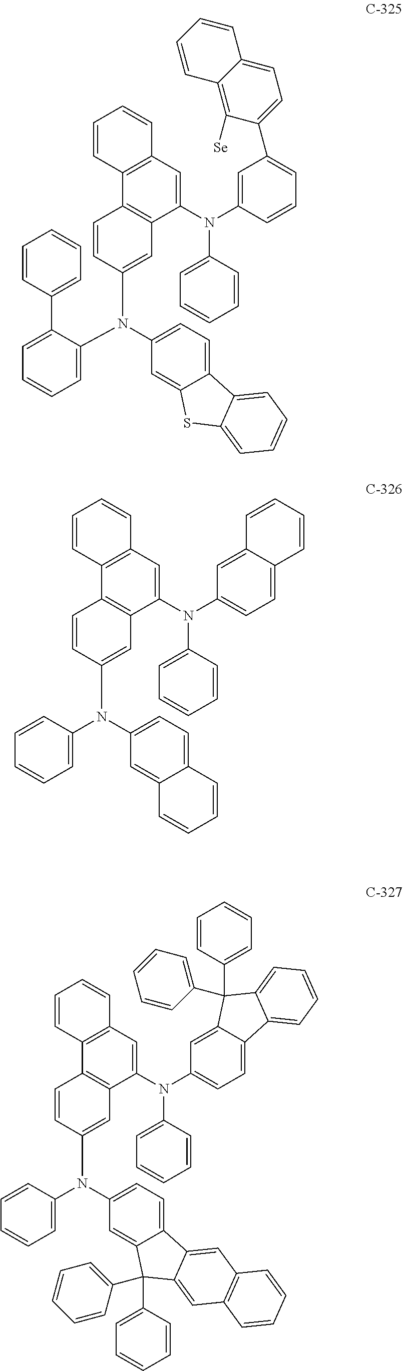

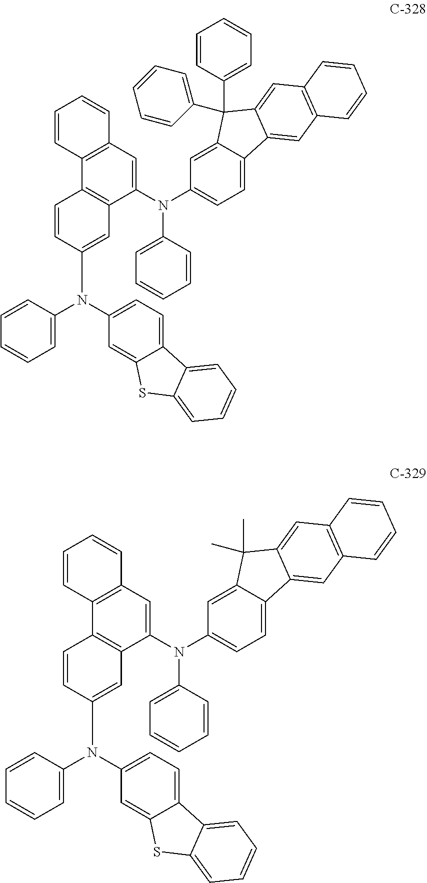 [SMILES: c1ccc(N(c2ccc3c(c2)sc2ccccc23)c2ccc3c(c2)c(N(c2ccccc2)c2ccc4c(c2)C(c2ccccc2)(c2ccccc2)c2cc5ccccc5cc2-4)cc2ccccc23)cc1 ; CC1(C)c2cc(N(c3ccccc3)c3cc4ccccc4c4ccc(N(c5ccccc5)c5ccc6c(c5)sc5ccccc56)cc34)ccc2-c2cc3ccccc3cc21]

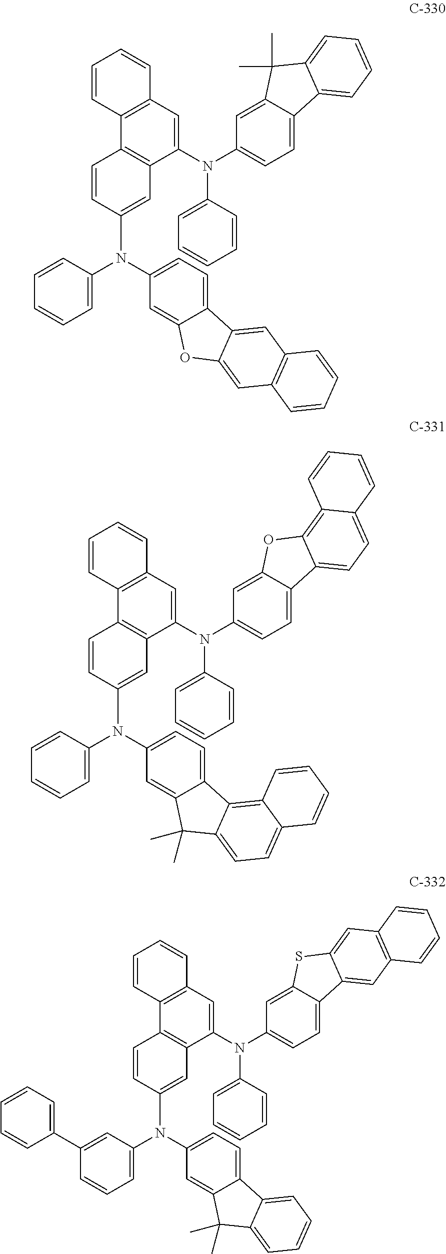

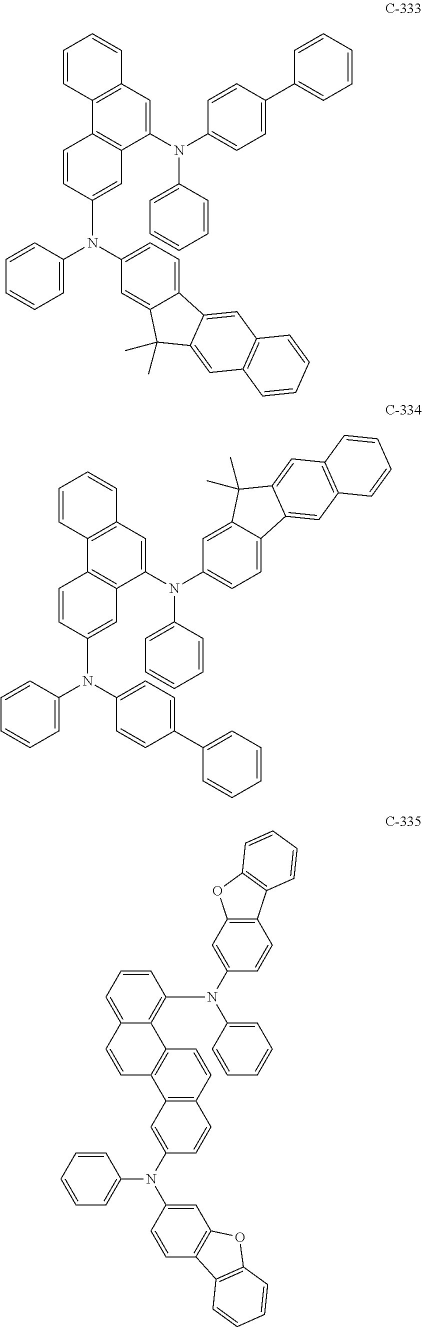 [SMILES: CC1(C)c2cc(N(c3ccccc3)c3ccc4c(c3)c(N(c3ccccc3)c3ccc(-c5ccccc5)cc3)cc3ccccc34)ccc2-c2cc3ccccc3cc21 ; CC1(C)c2cc(N(c3ccccc3)c3cc4ccccc4c4ccc(N(c5ccccc5)c5ccc(-c6ccccc6)cc5)cc34)ccc2-c2cc3ccccc3cc21 ; c1ccc(N(c2ccc3c(c2)oc2ccccc23)c2ccc3ccc4c(ccc5cccc(N(c6ccccc6)c6ccc7c(c6)oc6ccccc67)c54)c3c2)cc1]

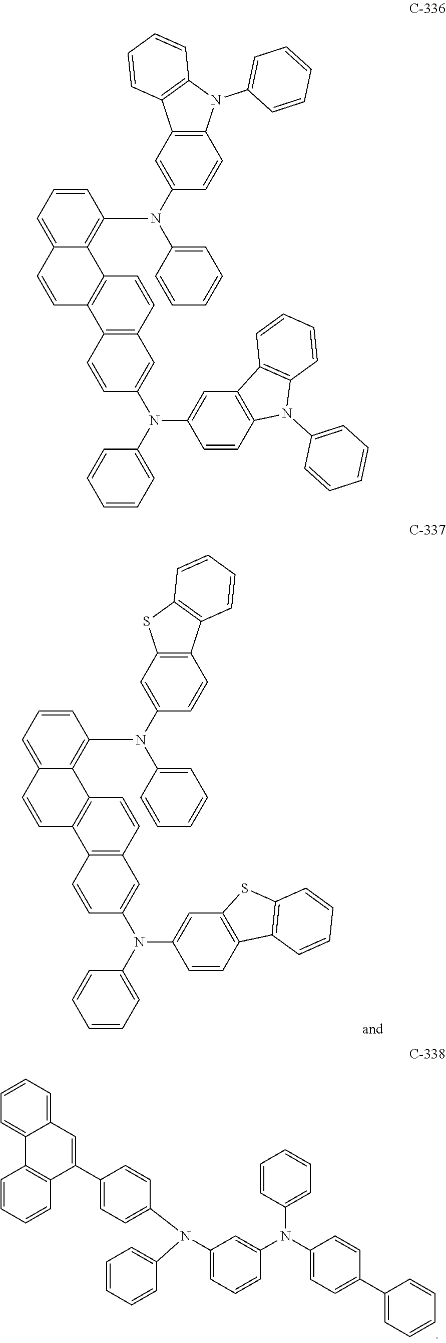 [SMILES: c1ccc(N(c2ccc3c(ccc4c3ccc3cccc(N(c5ccccc5)c5ccc6c(c5)c5ccccc5n6-c5ccccc5)c34)c2)c2ccc3c(c2)c2ccccc2n3-c2ccccc2)cc1 ; c1ccc(N(c2ccc3c(ccc4c3ccc3cccc(N(c5ccccc5)c5ccc6c(c5)sc5ccccc56)c34)c2)c2ccc3c(c2)sc2ccccc23)cc1 ; c1ccc(-c2ccc(N(c3ccccc3)c3cccc(N(c4ccccc4)c4ccc(-c5cc6ccccc6c6ccccc56)cc4)c3)cc2)cc1]

7. The plurality of host materials according to claim 1, wherein the compound represented by the formula 2 is selected from the following compounds:

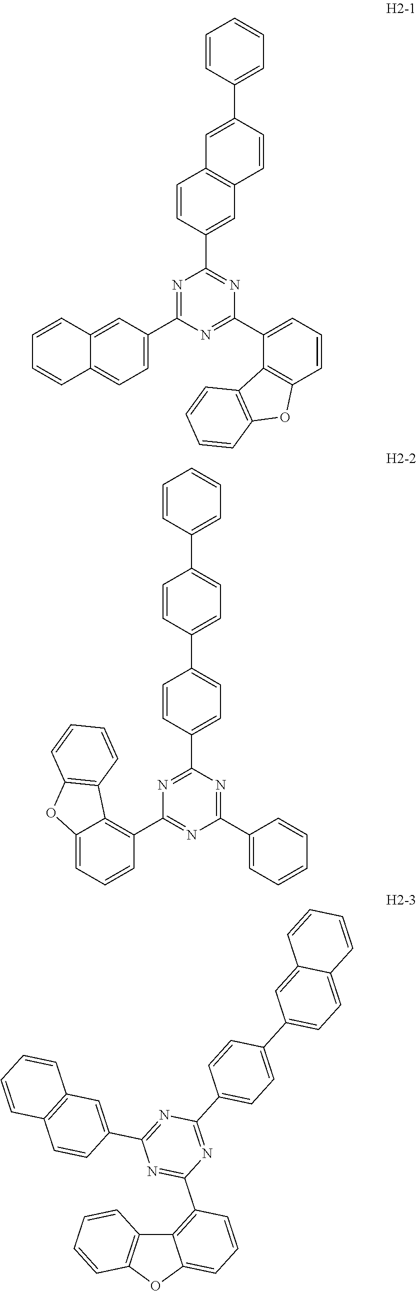

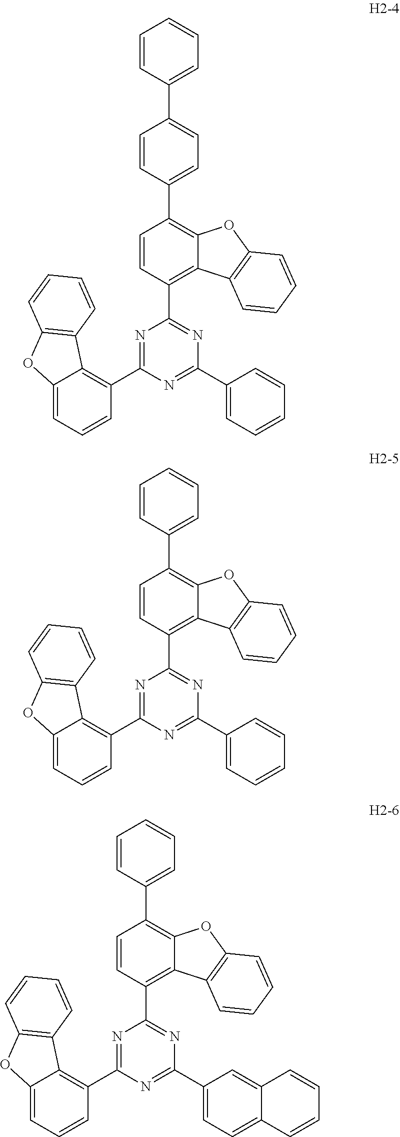 [SMILES: c1ccc(-c2ccc(-c3ccc(-c4nc(-c5ccccc5)nc(-c5cccc6oc7ccccc7c56)n4)c4c3oc3ccccc34)cc2)cc1 ; c1ccc(-c2nc(-c3cccc4oc5ccccc5c34)nc(-c3ccc(-c4ccccc4)c4oc5ccccc5c34)n2)cc1 ; c1ccc(-c2ccc(-c3nc(-c4ccc5ccccc5c4)nc(-c4cccc5oc6ccccc6c45)n3)c3c2oc2ccccc23)cc1]

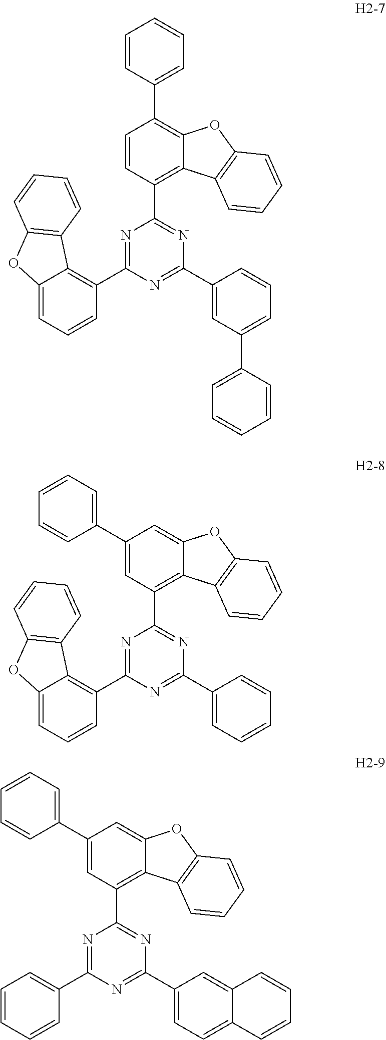 [SMILES: c1ccc(-c2cccc(-c3nc(-c4cccc5oc6ccccc6c45)nc(-c4ccc(-c5ccccc5)c5oc6ccccc6c45)n3)c2)cc1 ; c1ccc(-c2cc(-c3nc(-c4ccccc4)nc(-c4cccc5oc6ccccc6c45)n3)c3c(c2)oc2ccccc23)cc1 ; c1ccc(-c2cc(-c3nc(-c4ccccc4)nc(-c4ccc5ccccc5c4)n3)c3c(c2)oc2ccccc23)cc1]

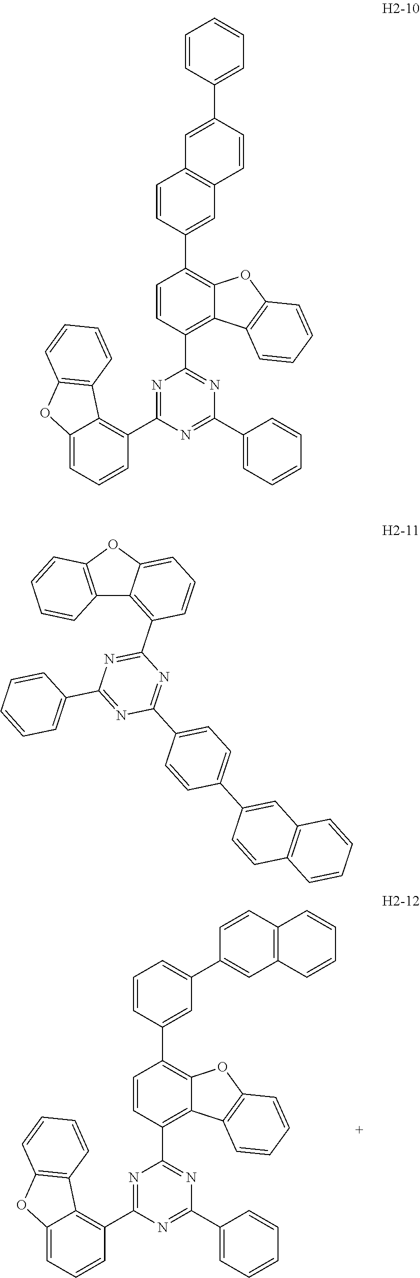

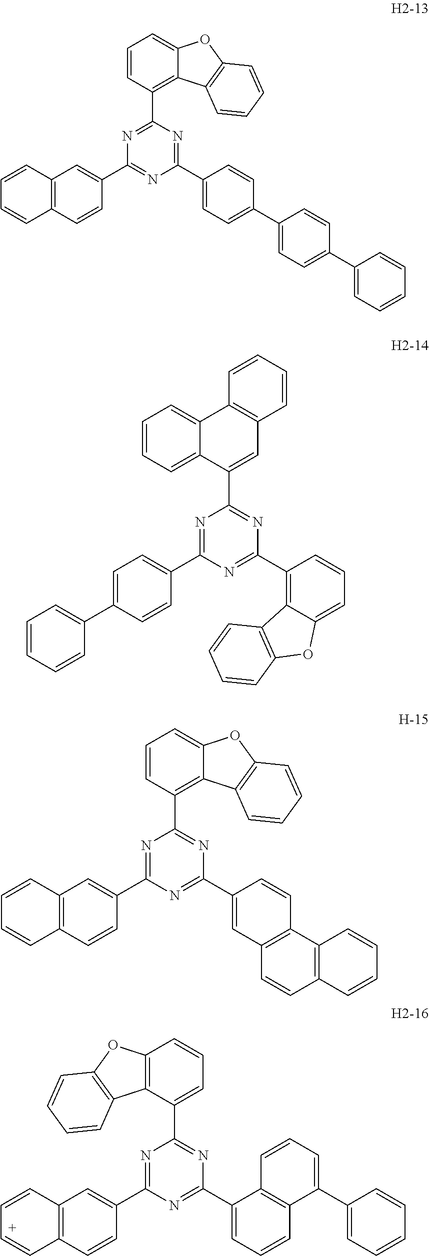 [SMILES: c1ccc(-c2ccc(-c3ccc(-c4nc(-c5ccc6ccccc6c5)nc(-c5cccc6oc7ccccc7c56)n4)cc3)cc2)cc1 ; c1ccc(-c2ccc(-c3nc(-c4cc5ccccc5c5ccccc45)nc(-c4cccc5oc6ccccc6c45)n3)cc2)cc1 ; c1ccc2cc(-c3nc(-c4ccc5c(ccc6ccccc65)c4)nc(-c4cccc5oc6ccccc6c45)n3)ccc2c1 ; [C+]1=Cc2ccc(-c3nc(-c4cccc5c(-c6ccccc6)cccc45)nc(-c4cccc5oc6ccccc6c45)n3)cc2C=C1]

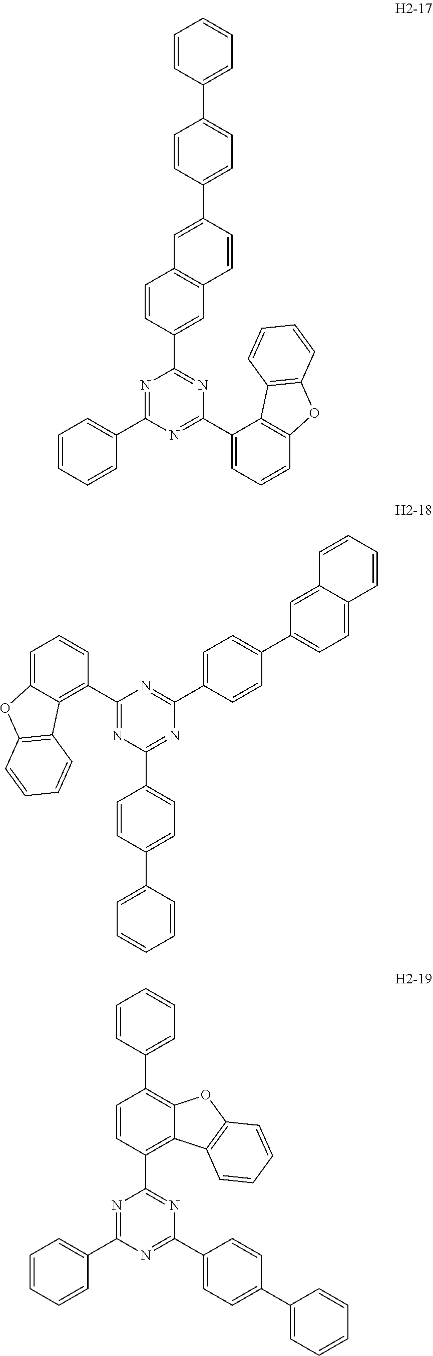

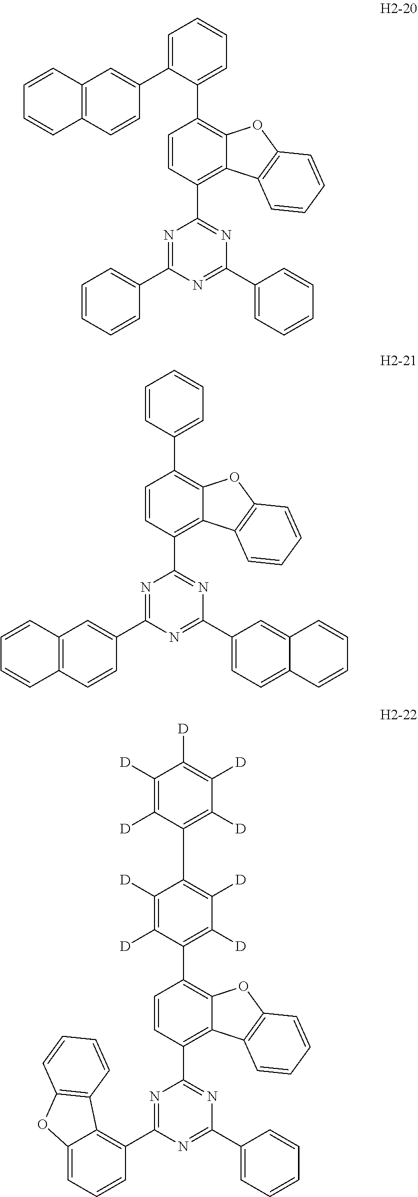 [SMILES: c1ccc(-c2nc(-c3ccccc3)nc(-c3ccc(-c4ccccc4-c4ccc5ccccc5c4)c4oc5ccccc5c34)n2)cc1 ; c1ccc(-c2ccc(-c3nc(-c4ccc5ccccc5c4)nc(-c4ccc5ccccc5c4)n3)c3c2oc2ccccc23)cc1 ; [2H]c1c([2H])c([2H])c(-c2c([2H])c([2H])c(-c3ccc(-c4nc(-c5ccccc5)nc(-c5cccc6oc7ccccc7c56)n4)c4c3oc3ccccc34)c([2H])c2[2H])c([2H])c1[2H]]

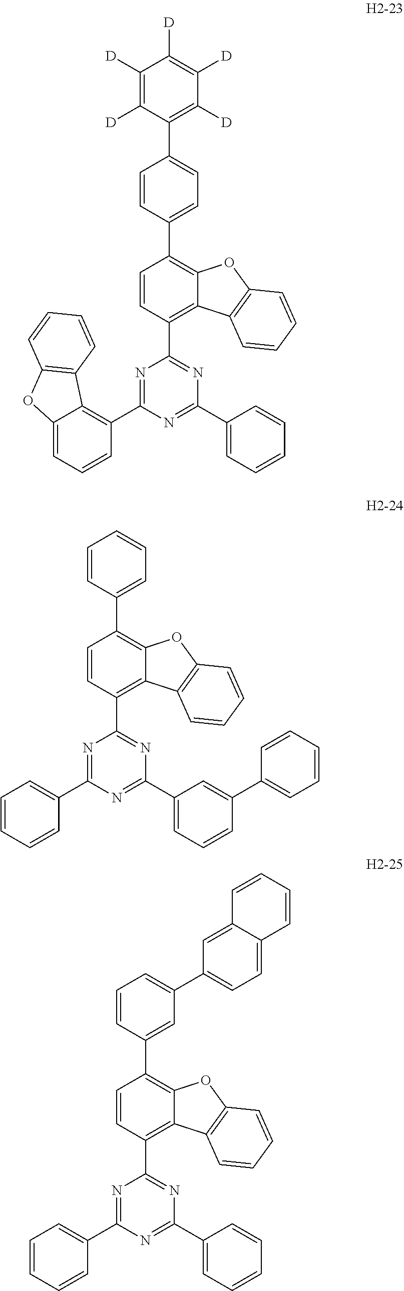 [SMILES: [2H]c1c([2H])c([2H])c(-c2ccc(-c3ccc(-c4nc(-c5ccccc5)nc(-c5cccc6oc7ccccc7c56)n4)c4c3oc3ccccc34)cc2)c([2H])c1[2H] ; c1ccc(-c2cccc(-c3nc(-c4ccccc4)nc(-c4ccc(-c5ccccc5)c5oc6ccccc6c45)n3)c2)cc1 ; c1ccc(-c2nc(-c3ccccc3)nc(-c3ccc(-c4cccc(-c5ccc6ccccc6c5)c4)c4oc5ccccc5c34)n2)cc1]

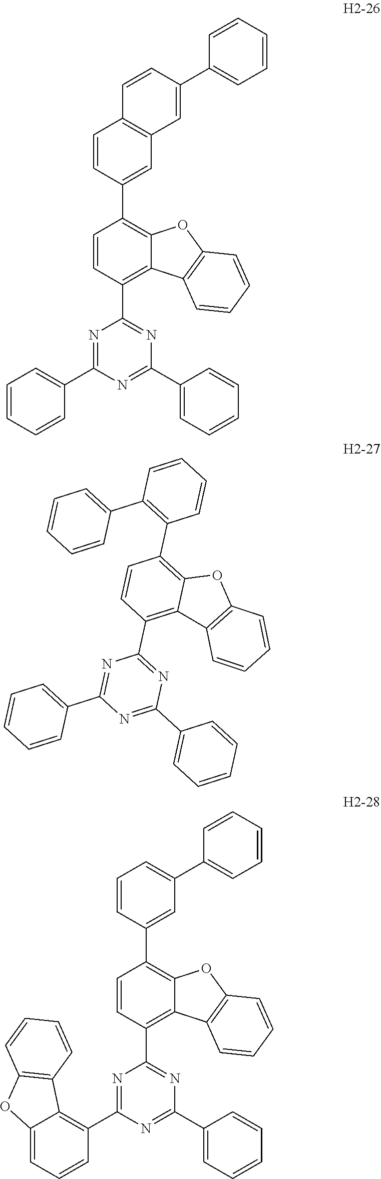

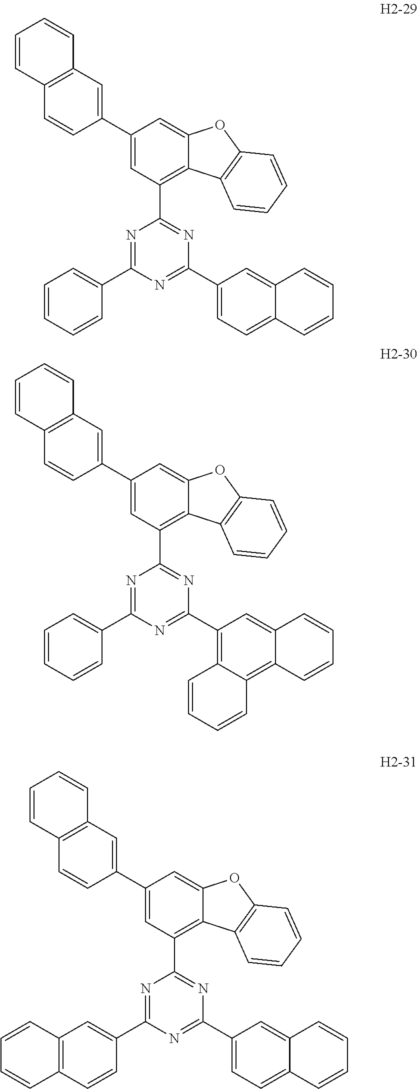

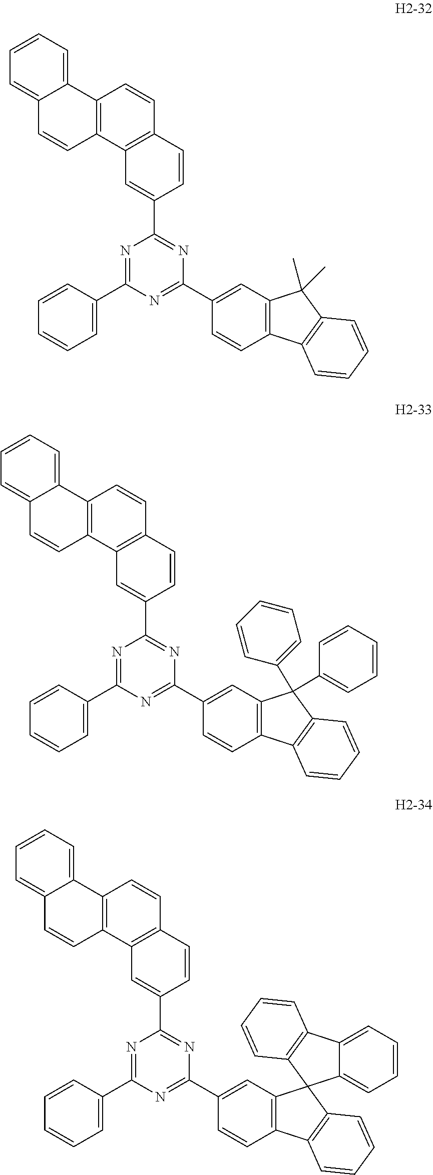 [SMILES: CC1(C)c2ccccc2-c2ccc(-c3nc(-c4ccccc4)nc(-c4ccc5ccc6c7ccccc7ccc6c5c4)n3)cc21 ; c1ccc(-c2nc(-c3ccc4c(c3)C(c3ccccc3)(c3ccccc3)c3ccccc3-4)nc(-c3ccc4ccc5c6ccccc6ccc5c4c3)n2)cc1 ; c1ccc(-c2nc(-c3ccc4c(c3)C3(c5ccccc5-c5ccccc53)c3ccccc3-4)nc(-c3ccc4ccc5c6ccccc6ccc5c4c3)n2)cc1]

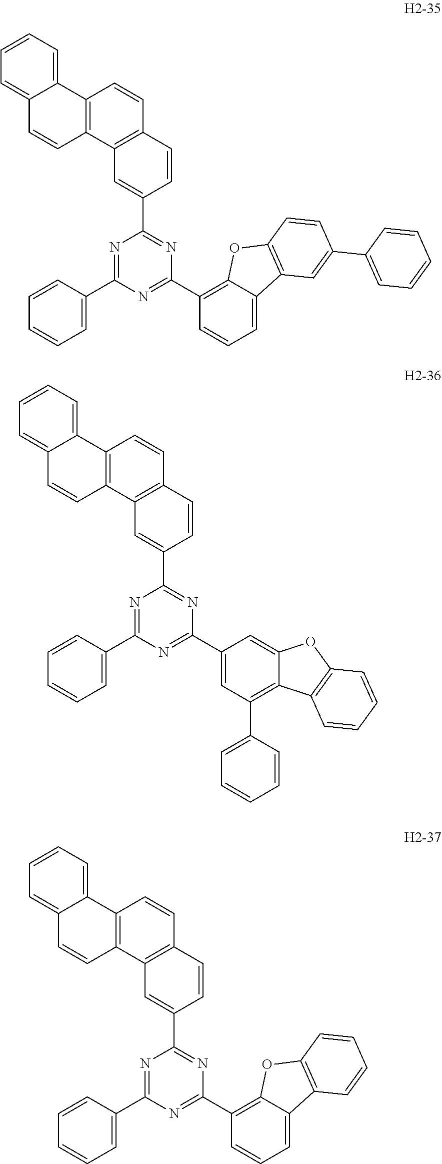

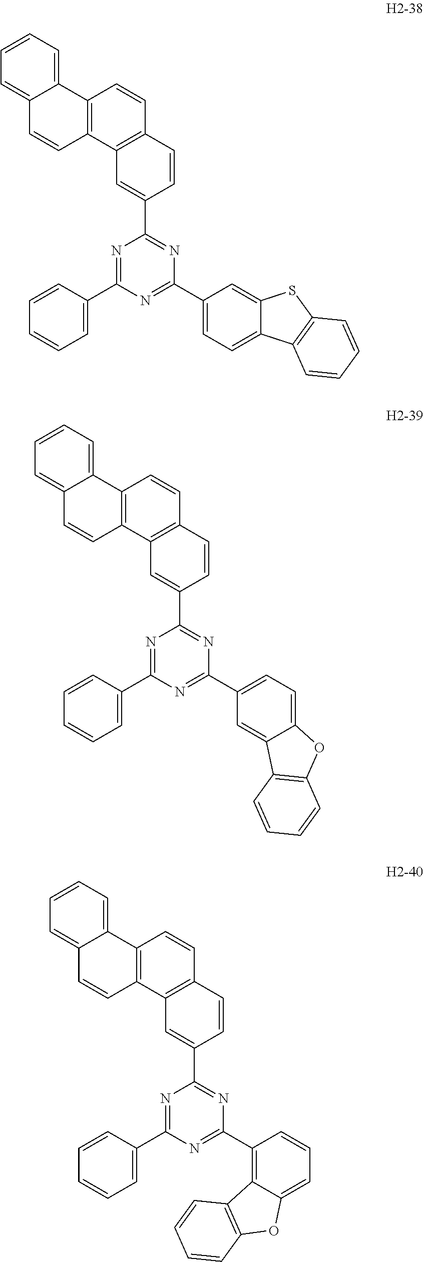 [SMILES: c1ccc(-c2nc(-c3ccc4c(c3)sc3ccccc34)nc(-c3ccc4ccc5c6ccccc6ccc5c4c3)n2)cc1 ; c1ccc(-c2nc(-c3ccc4ccc5c6ccccc6ccc5c4c3)nc(-c3ccc4oc5ccccc5c4c3)n2)cc1 ; c1ccc(-c2nc(-c3ccc4ccc5c6ccccc6ccc5c4c3)nc(-c3cccc4oc5ccccc5c34)n2)cc1]

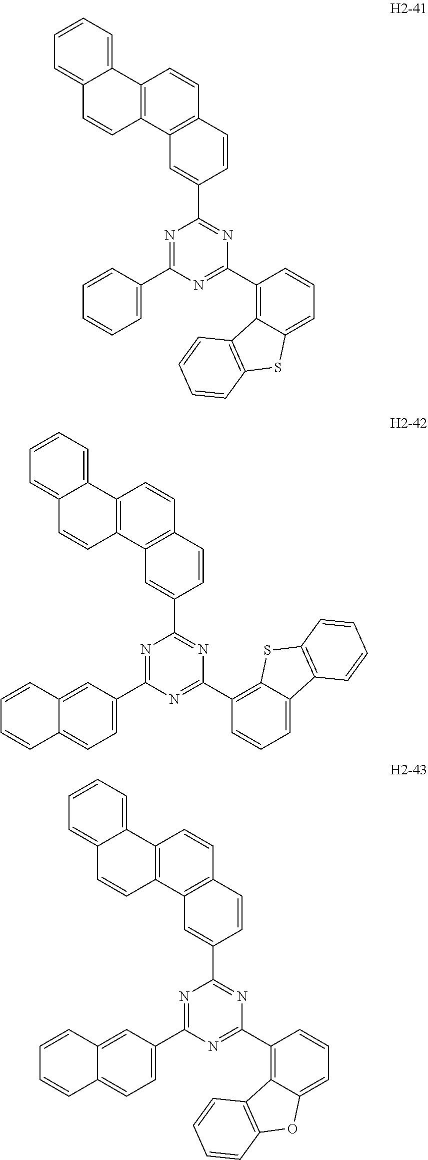

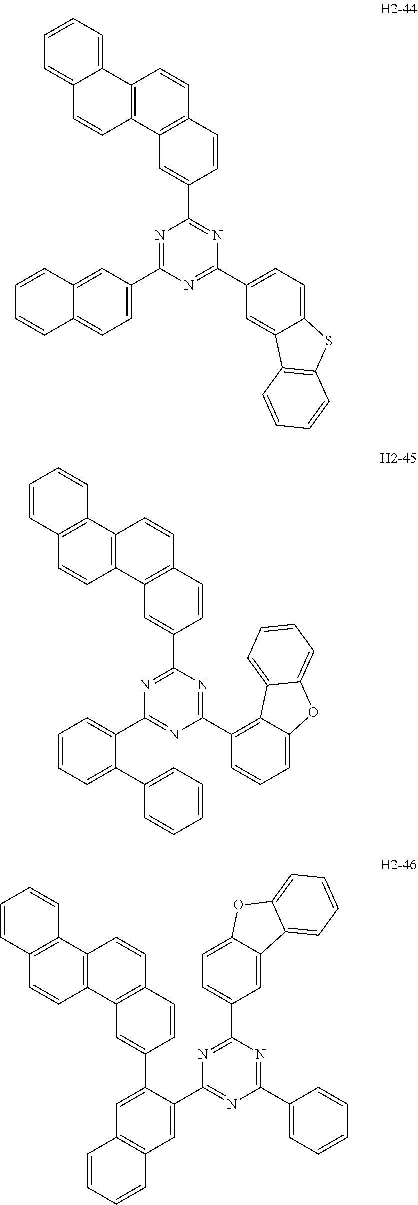 [SMILES: c1ccc2cc(-c3nc(-c4ccc5ccc6c7ccccc7ccc6c5c4)nc(-c4ccc5sc6ccccc6c5c4)n3)ccc2c1 ; c1ccc(-c2ccccc2-c2nc(-c3ccc4ccc5c6ccccc6ccc5c4c3)nc(-c3cccc4oc5ccccc5c34)n2)cc1 ; c1ccc(-c2nc(-c3ccc4oc5ccccc5c4c3)nc(-c3cc4ccccc4cc3-c3ccc4ccc5c6ccccc6ccc5c4c3)n2)cc1]

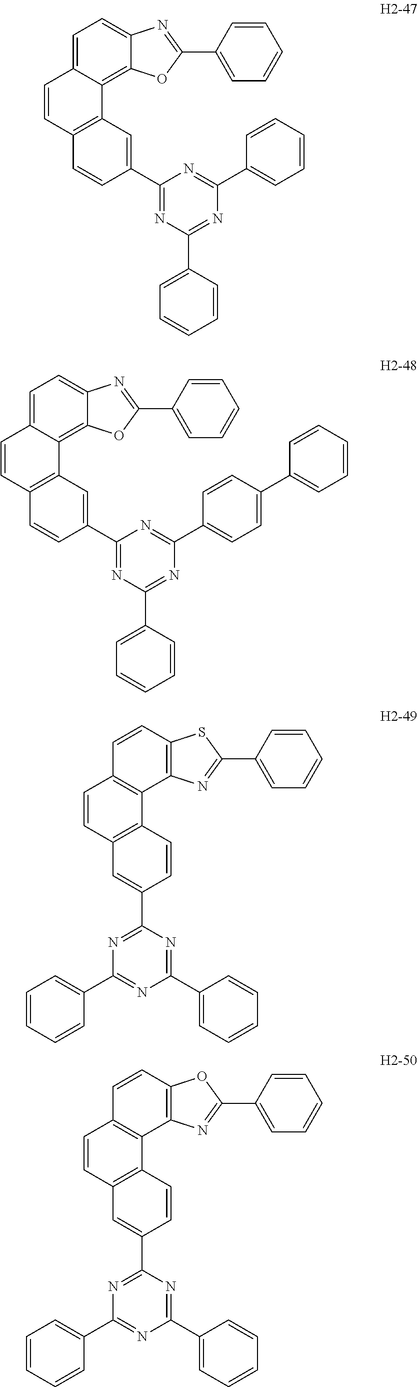

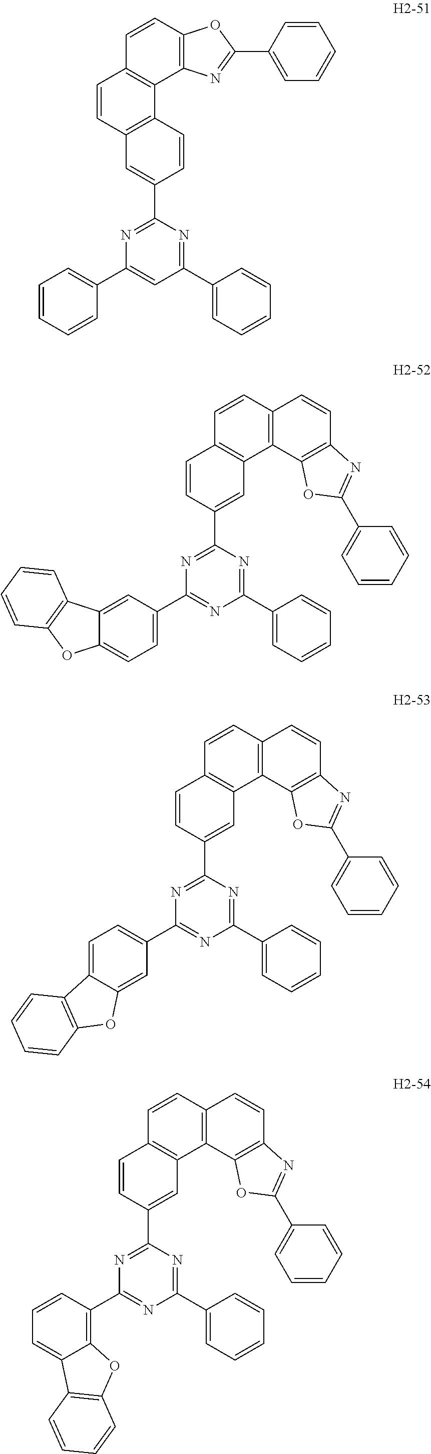 [SMILES: c1ccc(-c2cc(-c3ccccc3)nc(-c3ccc4c(ccc5ccc6oc(-c7ccccc7)nc6c54)c3)n2)cc1 ; c1ccc(-c2nc(-c3ccc4oc5ccccc5c4c3)nc(-c3ccc4ccc5ccc6nc(-c7ccccc7)oc6c5c4c3)n2)cc1 ; c1ccc(-c2nc(-c3ccc4c(c3)oc3ccccc34)nc(-c3ccc4ccc5ccc6nc(-c7ccccc7)oc6c5c4c3)n2)cc1 ; c1ccc(-c2nc(-c3ccc4ccc5ccc6nc(-c7ccccc7)oc6c5c4c3)nc(-c3cccc4c3oc3ccccc34)n2)cc1]

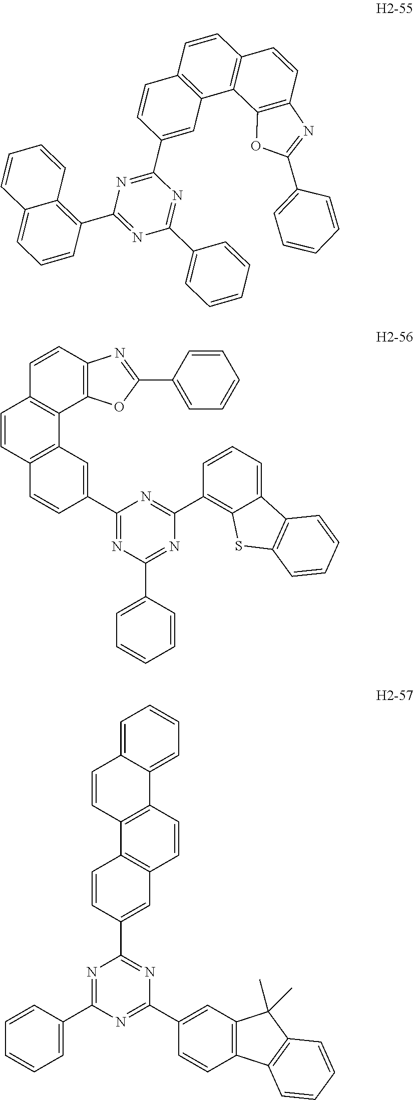

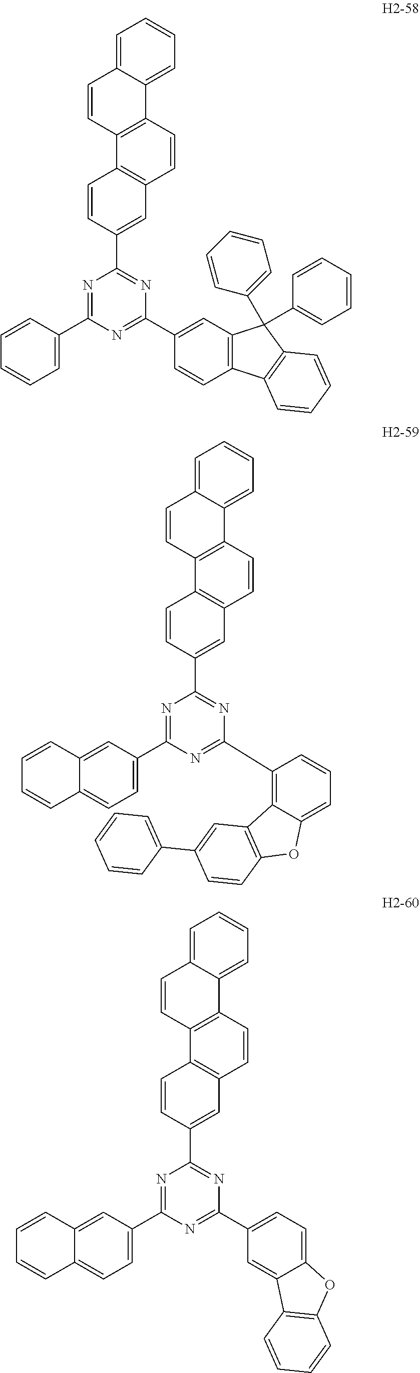

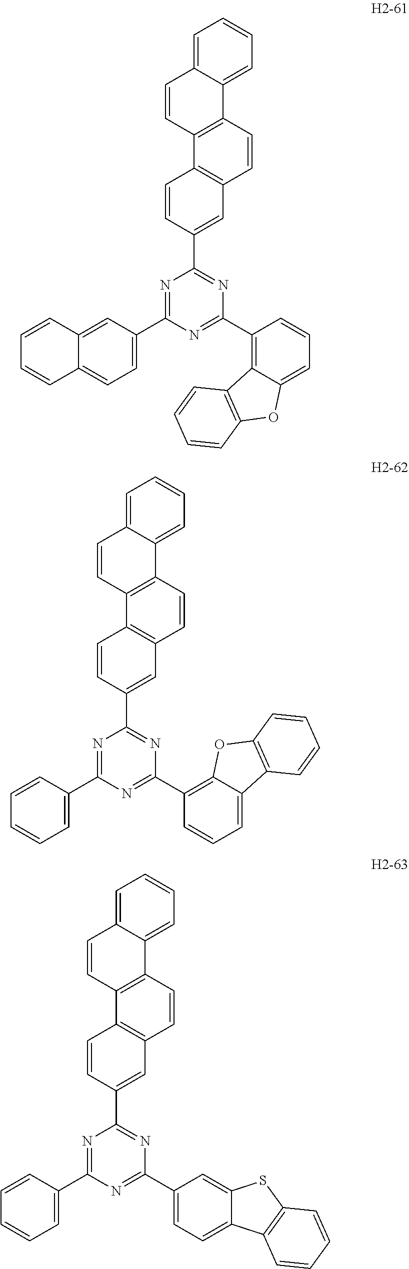

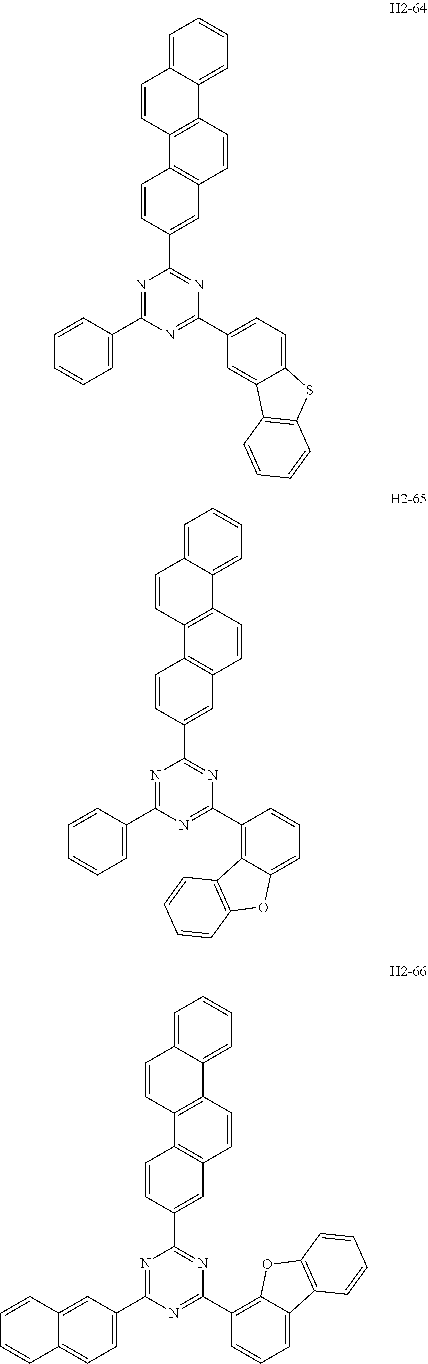 [SMILES: c1ccc(-c2nc(-c3ccc4c(ccc5c6ccccc6ccc45)c3)nc(-c3ccc4sc5ccccc5c4c3)n2)cc1 ; c1ccc(-c2nc(-c3ccc4c(ccc5c6ccccc6ccc45)c3)nc(-c3cccc4oc5ccccc5c34)n2)cc1 ; c1ccc2cc(-c3nc(-c4ccc5c(ccc6c7ccccc7ccc56)c4)nc(-c4cccc5c4oc4ccccc45)n3)ccc2c1]

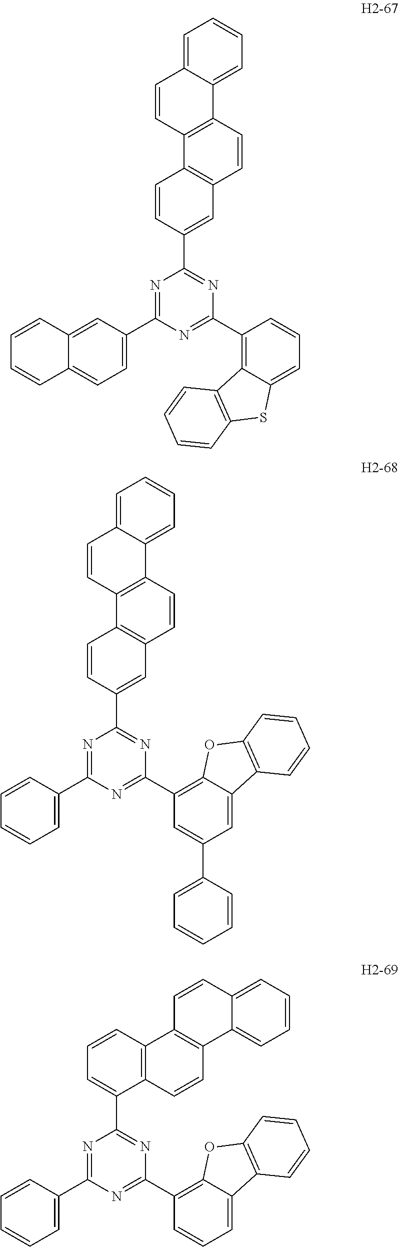

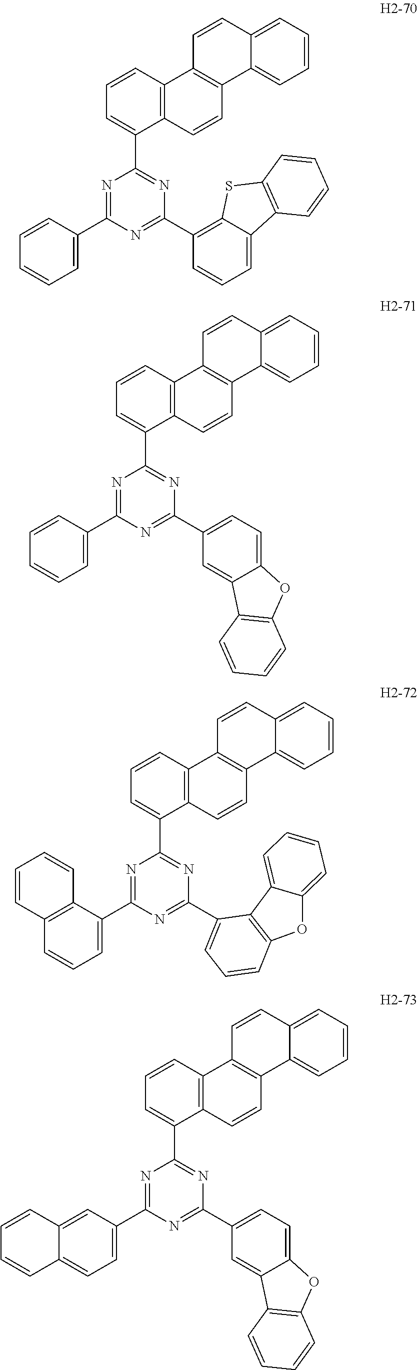

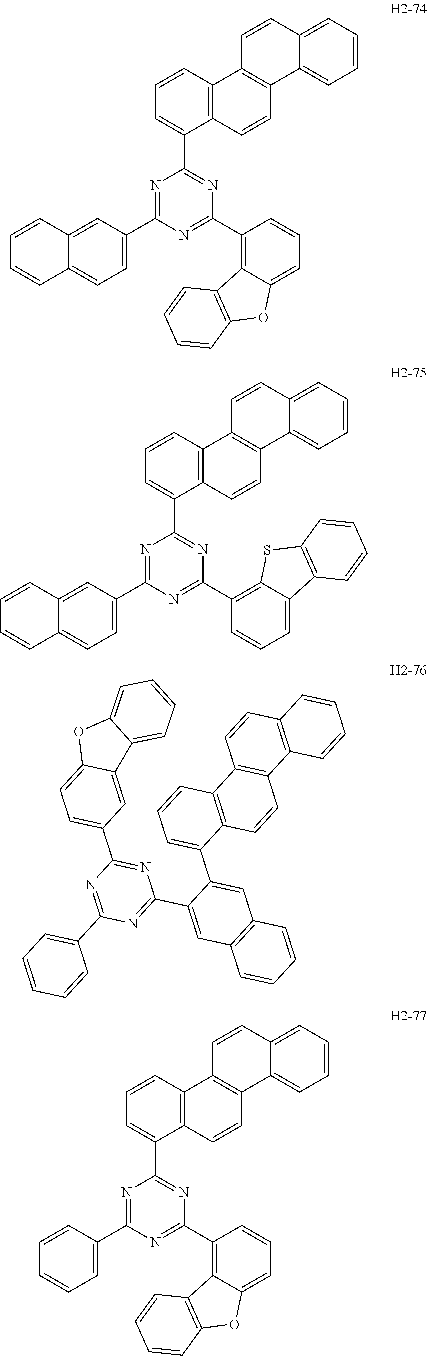 [SMILES: c1ccc2cc(-c3nc(-c4cccc5c4ccc4c6ccccc6ccc54)nc(-c4cccc5oc6ccccc6c45)n3)ccc2c1 ; c1ccc2cc(-c3nc(-c4cccc5c4ccc4c6ccccc6ccc54)nc(-c4cccc5c4sc4ccccc45)n3)ccc2c1 ; c1ccc(-c2nc(-c3ccc4oc5ccccc5c4c3)nc(-c3cc4ccccc4cc3-c3cccc4c3ccc3c5ccccc5ccc43)n2)cc1 ; c1ccc(-c2nc(-c3cccc4c3ccc3c5ccccc5ccc43)nc(-c3cccc4oc5ccccc5c34)n2)cc1]

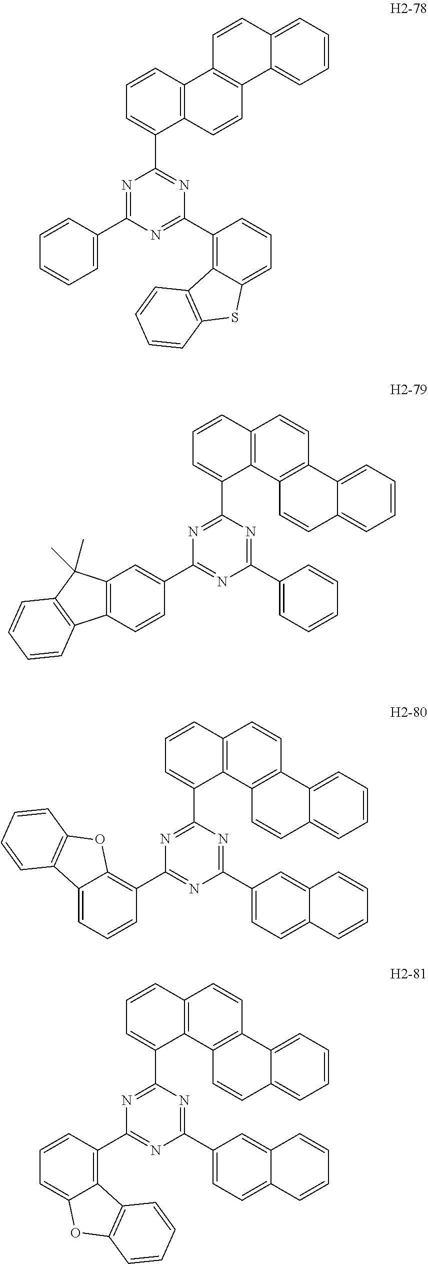 [SMILES: c1ccc(-c2nc(-c3cccc4c3ccc3c5ccccc5ccc43)nc(-c3cccc4sc5ccccc5c34)n2)cc1 ; CC1(C)c2ccccc2-c2ccc(-c3nc(-c4ccccc4)nc(-c4cccc5ccc6c7ccccc7ccc6c45)n3)cc21 ; c1ccc2cc(-c3nc(-c4cccc5c4oc4ccccc45)nc(-c4cccc5ccc6c7ccccc7ccc6c45)n3)ccc2c1 ; c1ccc2cc(-c3nc(-c4cccc5ccc6c7ccccc7ccc6c45)nc(-c4cccc5oc6ccccc6c45)n3)ccc2c1]

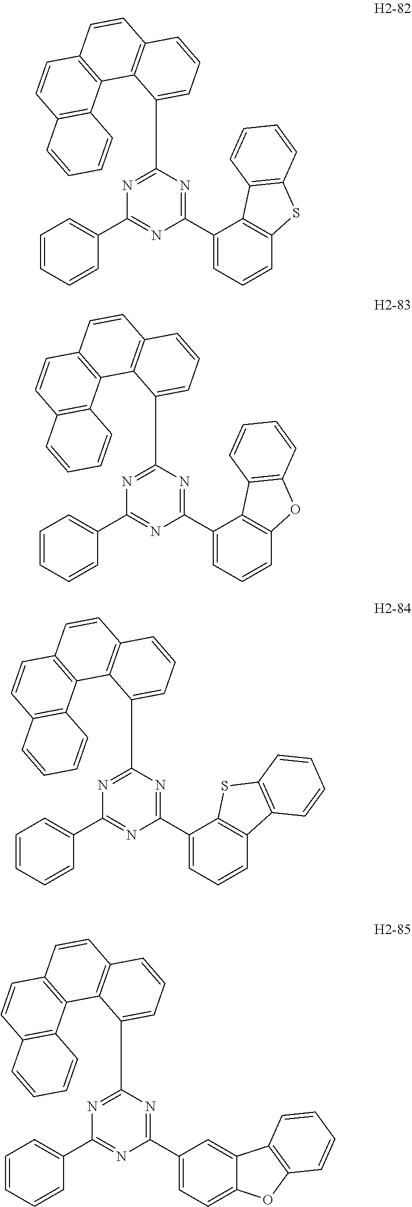

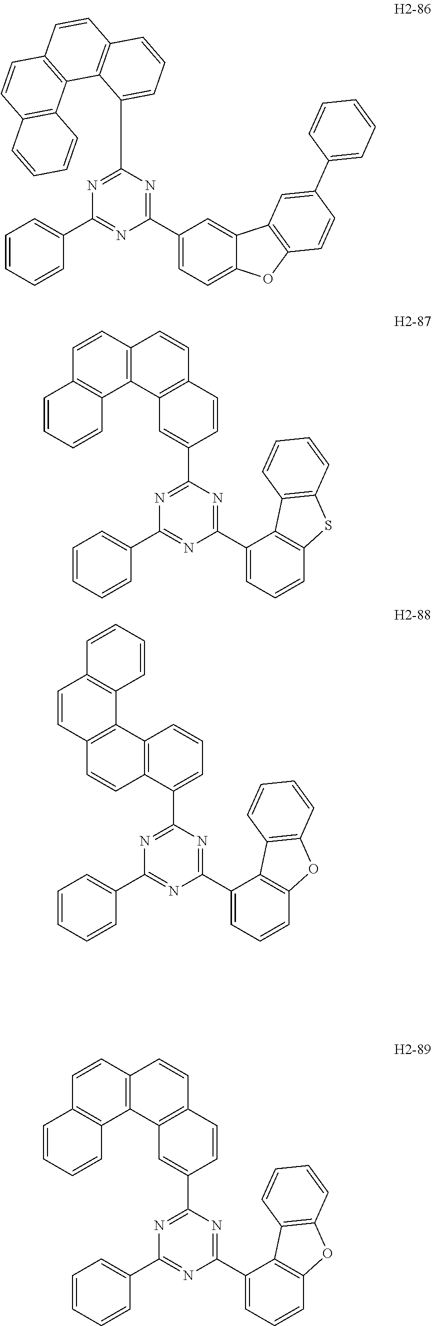

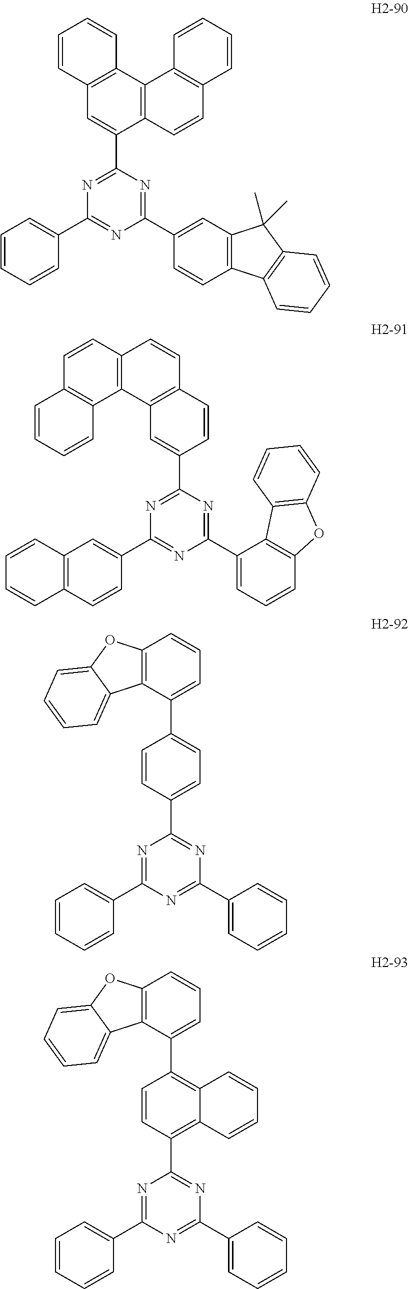

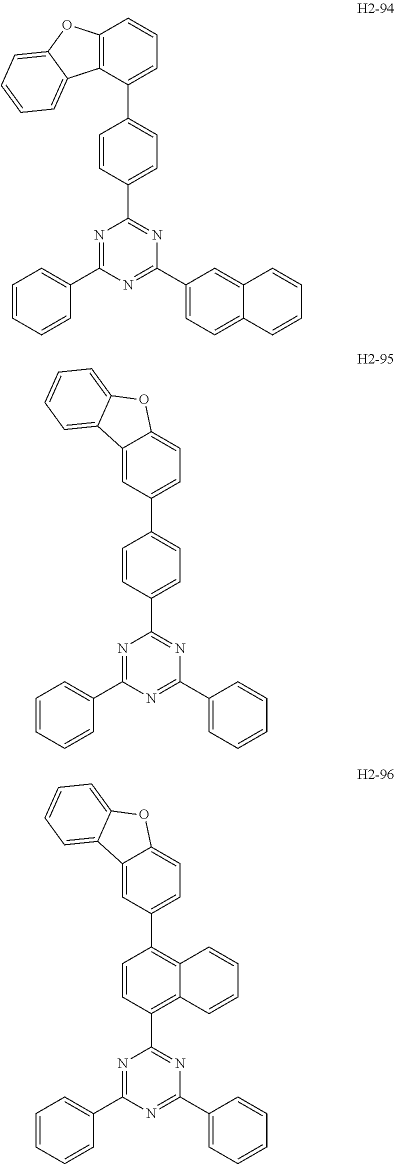

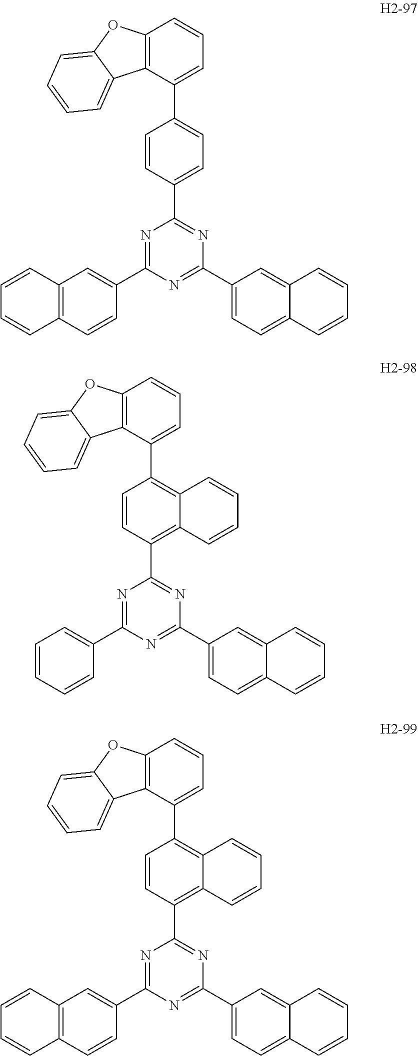 [SMILES: c1ccc2cc(-c3nc(-c4ccc(-c5cccc6oc7ccccc7c56)cc4)nc(-c4ccc5ccccc5c4)n3)ccc2c1 ; c1ccc(-c2nc(-c3ccc4ccccc4c3)nc(-c3ccc(-c4cccc5oc6ccccc6c45)c4ccccc34)n2)cc1 ; c1ccc2cc(-c3nc(-c4ccc5ccccc5c4)nc(-c4ccc(-c5cccc6oc7ccccc7c56)c5ccccc45)n3)ccc2c1]

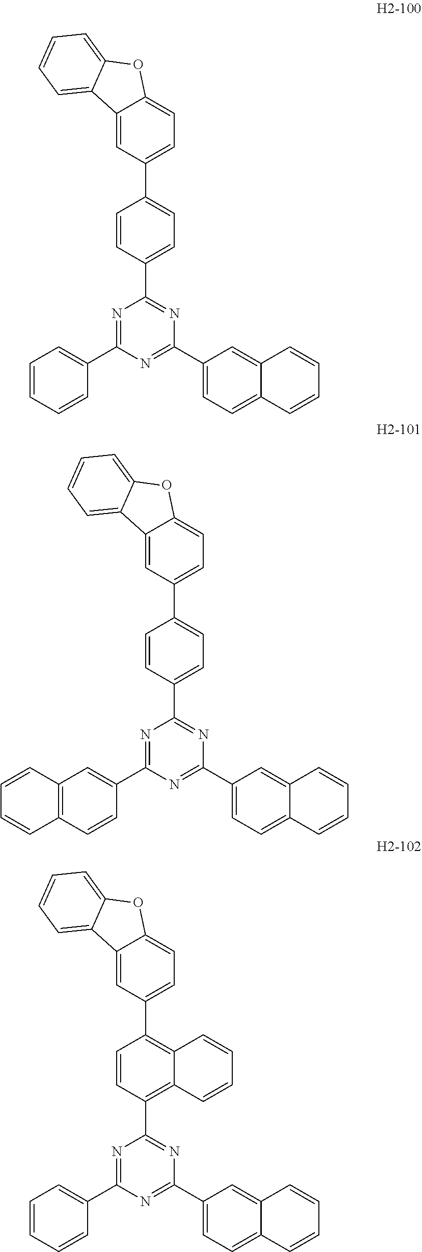

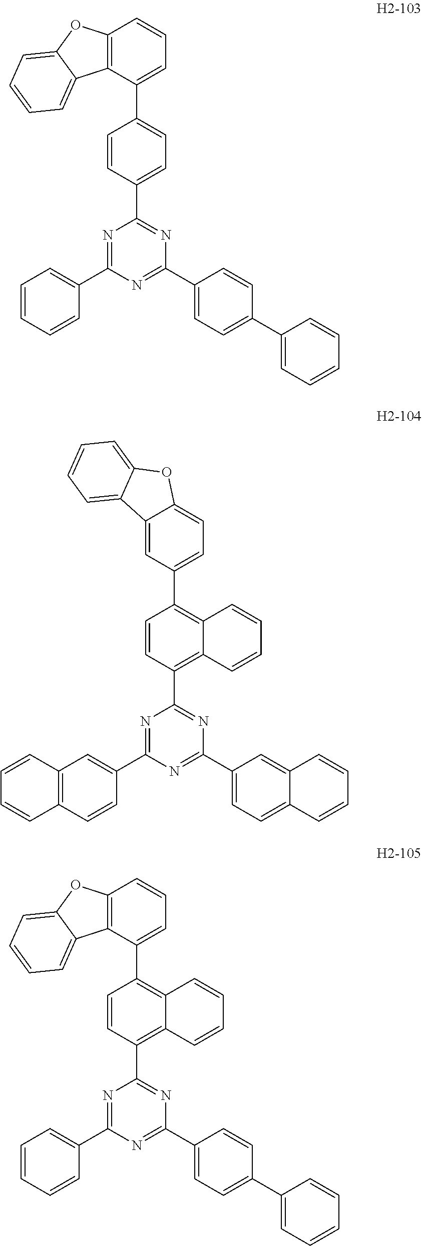 [SMILES: c1ccc(-c2ccc(-c3nc(-c4ccccc4)nc(-c4ccc(-c5cccc6oc7ccccc7c56)cc4)n3)cc2)cc1 ; c1ccc2cc(-c3nc(-c4ccc5ccccc5c4)nc(-c4ccc(-c5ccc6oc7ccccc7c6c5)c5ccccc45)n3)ccc2c1 ; c1ccc(-c2ccc(-c3nc(-c4ccccc4)nc(-c4ccc(-c5cccc6oc7ccccc7c56)c5ccccc45)n3)cc2)cc1]

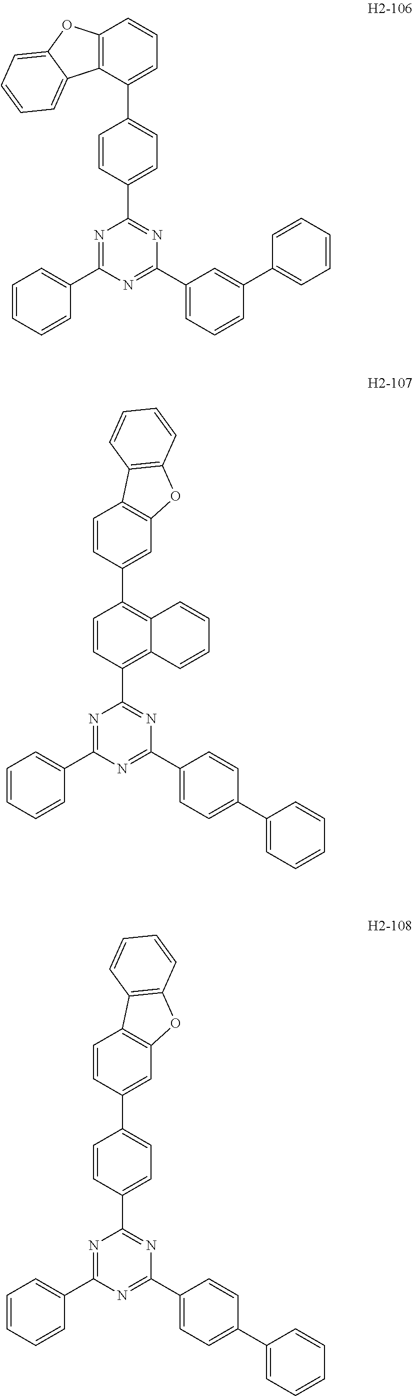 [SMILES: c1ccc(-c2cccc(-c3nc(-c4ccccc4)nc(-c4ccc(-c5cccc6oc7ccccc7c56)cc4)n3)c2)cc1 ; c1ccc(-c2ccc(-c3nc(-c4ccccc4)nc(-c4ccc(-c5ccc6c(c5)oc5ccccc56)c5ccccc45)n3)cc2)cc1 ; c1ccc(-c2ccc(-c3nc(-c4ccccc4)nc(-c4ccc(-c5ccc6c(c5)oc5ccccc56)cc4)n3)cc2)cc1]

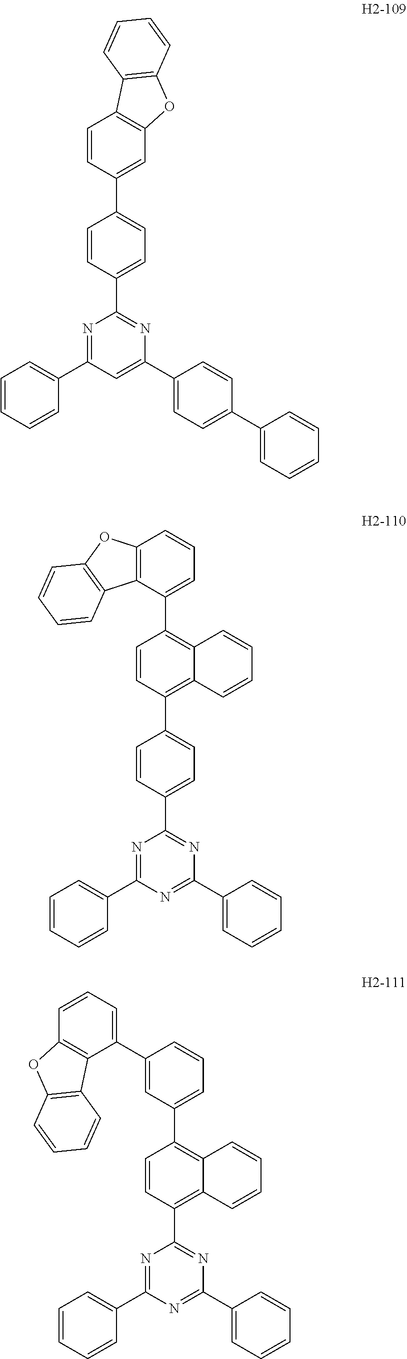

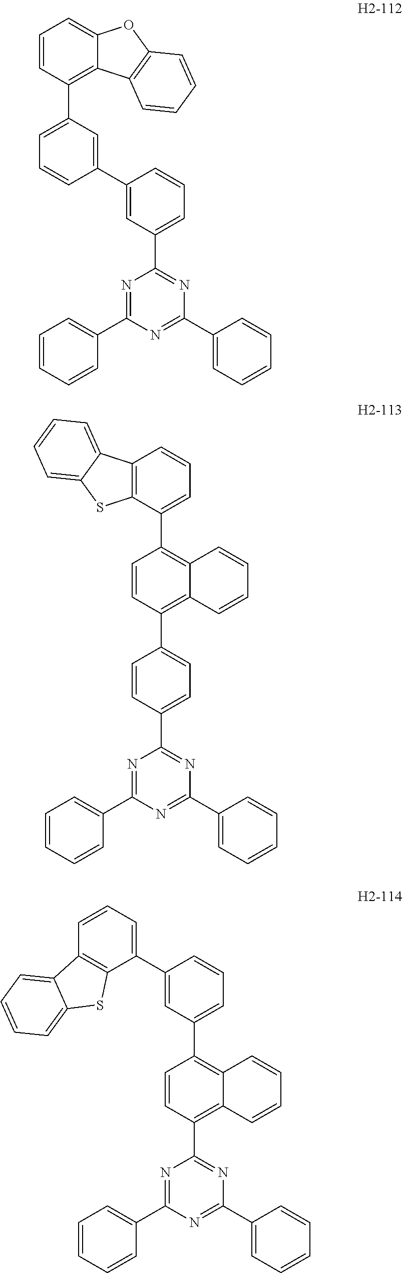

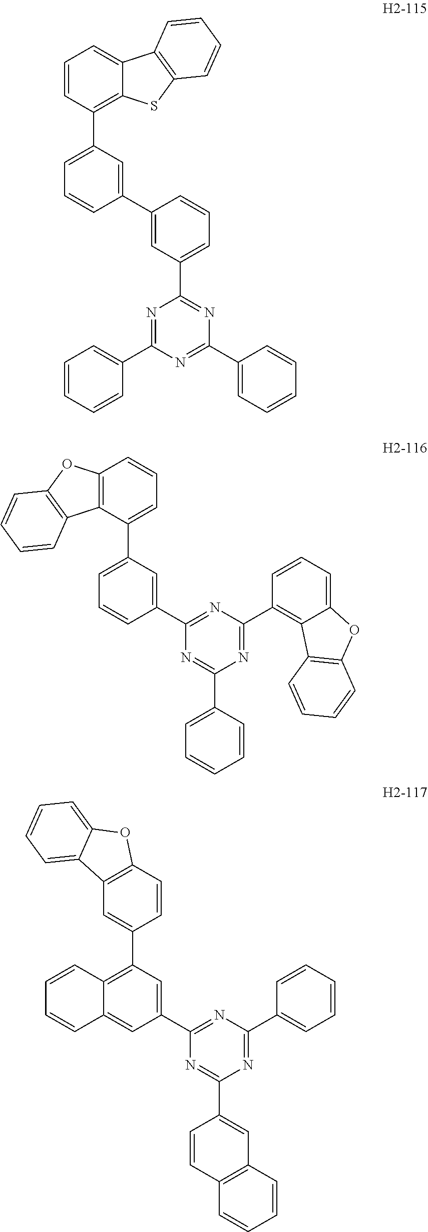 [SMILES: c1ccc(-c2nc(-c3ccccc3)nc(-c3cccc(-c4cccc(-c5cccc6c5sc5ccccc56)c4)c3)n2)cc1 ; c1ccc(-c2nc(-c3cccc(-c4cccc5oc6ccccc6c45)c3)nc(-c3cccc4oc5ccccc5c34)n2)cc1 ; c1ccc(-c2nc(-c3ccc4ccccc4c3)nc(-c3cc(-c4ccc5oc6ccccc6c5c4)c4ccccc4c3)n2)cc1]

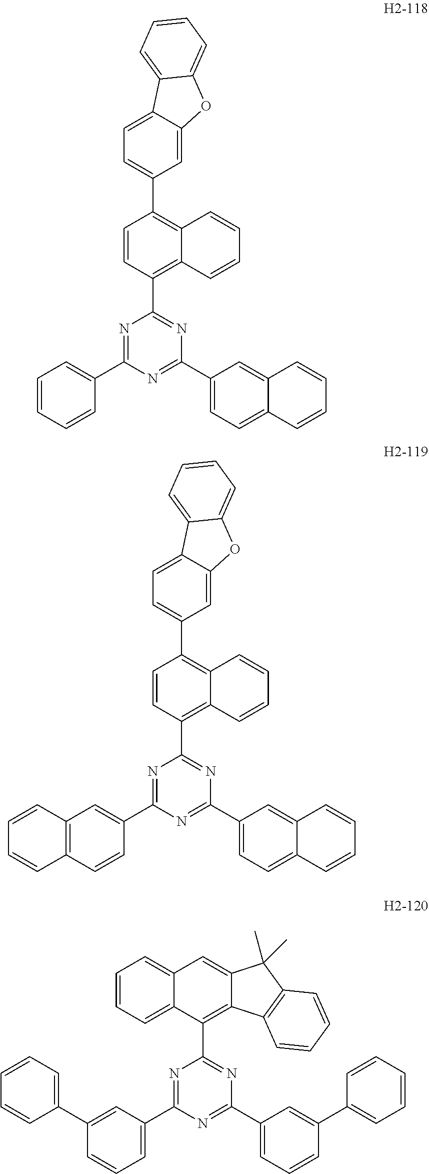

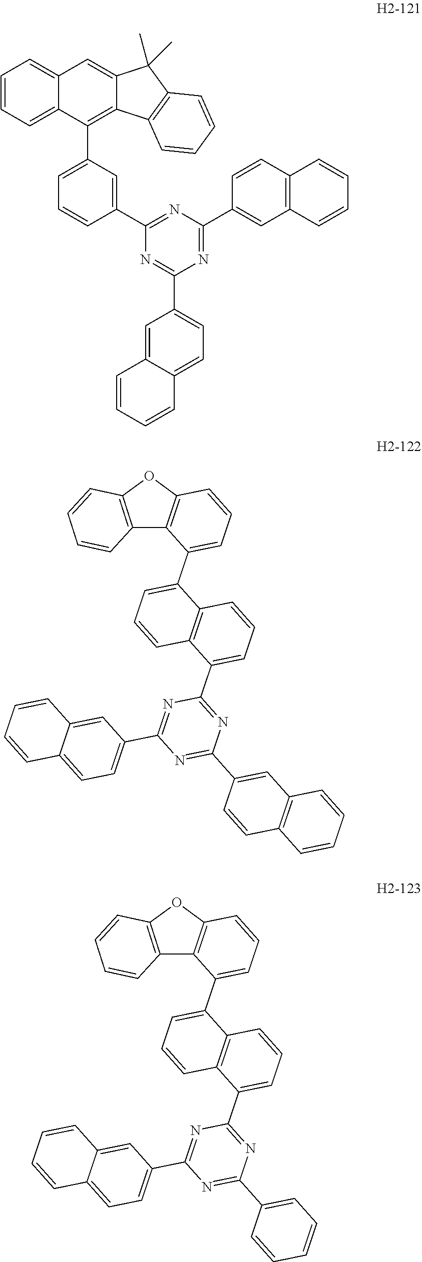 [SMILES: CC1(C)c2ccccc2-c2c1cc1ccccc1c2-c1cccc(-c2nc(-c3ccc4ccccc4c3)nc(-c3ccc4ccccc4c3)n2)c1 ; c1ccc2cc(-c3nc(-c4ccc5ccccc5c4)nc(-c4cccc5c(-c6cccc7oc8ccccc8c67)cccc45)n3)ccc2c1 ; c1ccc(-c2nc(-c3ccc4ccccc4c3)nc(-c3cccc4c(-c5cccc6oc7ccccc7c56)cccc34)n2)cc1]

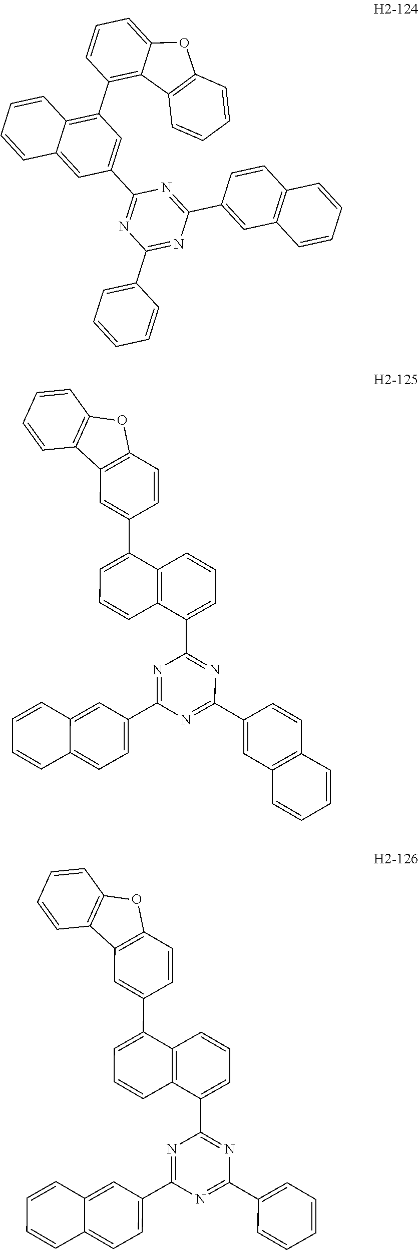 [SMILES: c1ccc(-c2nc(-c3ccc4ccccc4c3)nc(-c3cc(-c4cccc5oc6ccccc6c45)c4ccccc4c3)n2)cc1 ; c1ccc2cc(-c3nc(-c4ccc5ccccc5c4)nc(-c4cccc5c(-c6ccc7oc8ccccc8c7c6)cccc45)n3)ccc2c1 ; c1ccc(-c2nc(-c3ccc4ccccc4c3)nc(-c3cccc4c(-c5ccc6oc7ccccc7c6c5)cccc34)n2)cc1]

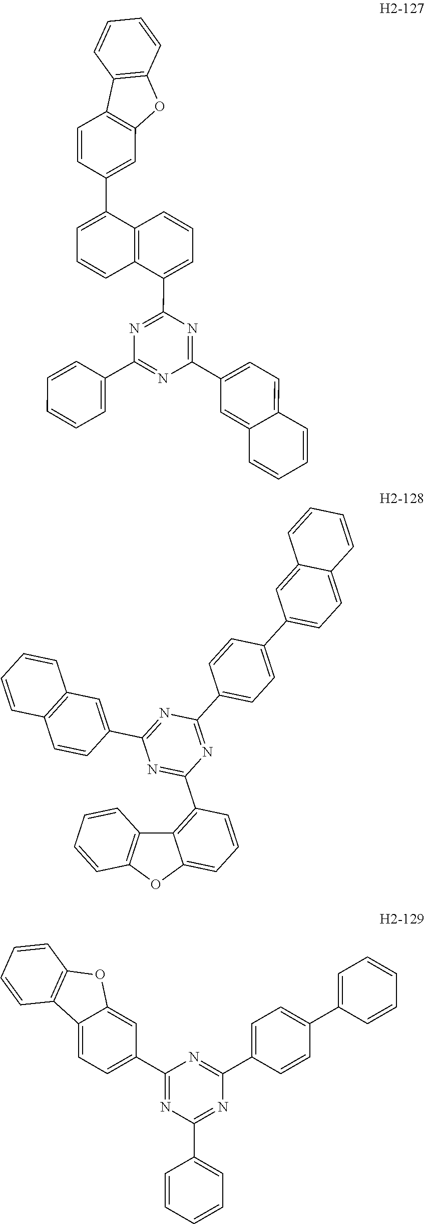

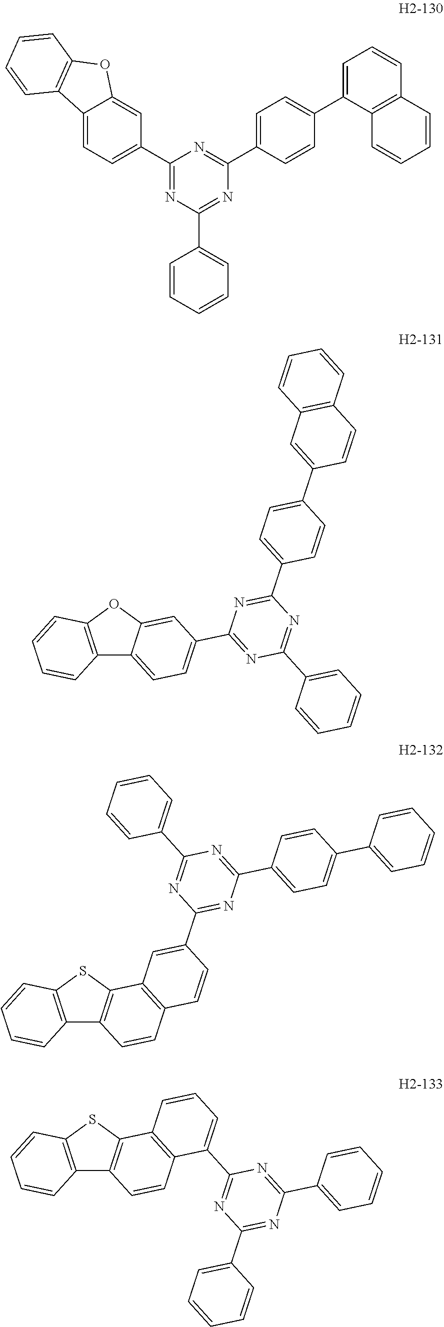 [SMILES: c1ccc(-c2nc(-c3ccc(-c4cccc5ccccc45)cc3)nc(-c3ccc4c(c3)oc3ccccc34)n2)cc1 ; c1ccc(-c2nc(-c3ccc(-c4ccc5ccccc5c4)cc3)nc(-c3ccc4c(c3)oc3ccccc34)n2)cc1 ; c1ccc(-c2ccc(-c3nc(-c4ccccc4)nc(-c4ccc5ccc6c7ccccc7sc6c5c4)n3)cc2)cc1 ; c1ccc(-c2nc(-c3ccccc3)nc(-c3cccc4c3ccc3c5ccccc5sc43)n2)cc1]

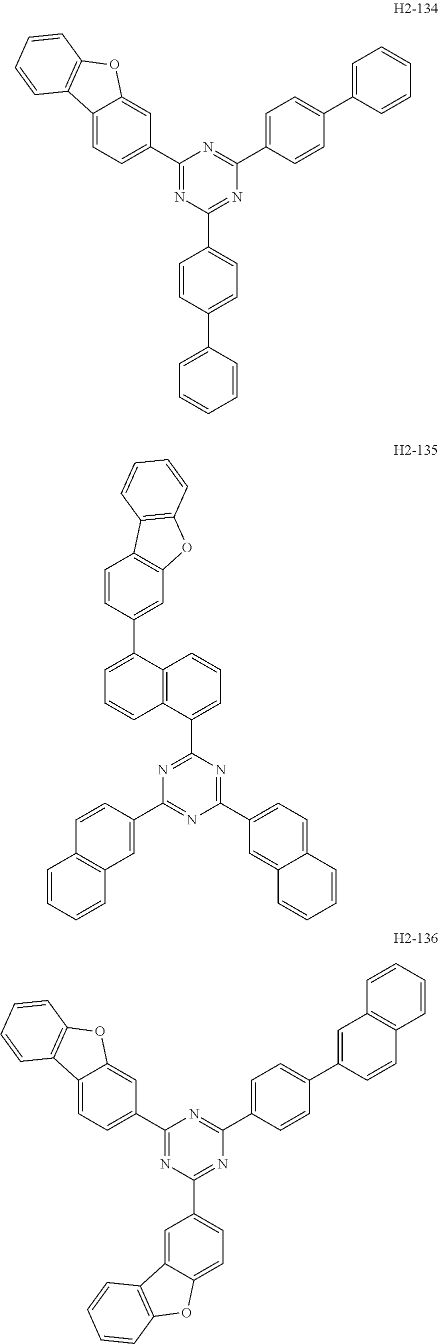 [SMILES: c1ccc(-c2ccc(-c3nc(-c4ccc(-c5ccccc5)cc4)nc(-c4ccc5c(c4)oc4ccccc45)n3)cc2)cc1 ; c1ccc2cc(-c3nc(-c4ccc5ccccc5c4)nc(-c4cccc5c(-c6ccc7c(c6)oc6ccccc67)cccc45)n3)ccc2c1 ; c1ccc2cc(-c3ccc(-c4nc(-c5ccc6c(c5)oc5ccccc56)nc(-c5ccc6oc7ccccc7c6c5)n4)cc3)ccc2c1]

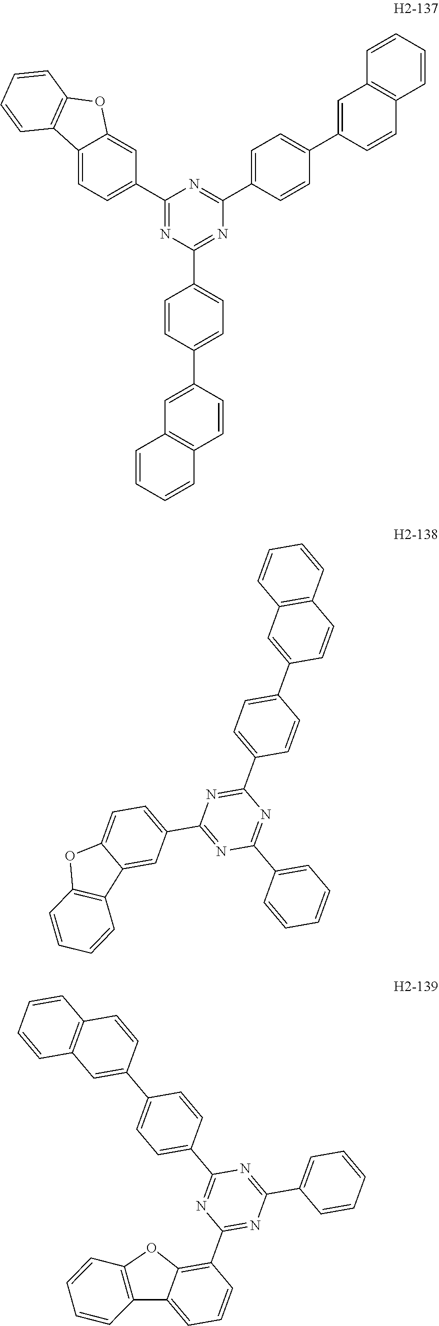 [SMILES: c1ccc2cc(-c3ccc(-c4nc(-c5ccc(-c6ccc7ccccc7c6)cc5)nc(-c5ccc6c(c5)oc5ccccc56)n4)cc3)ccc2c1 ; c1ccc(-c2nc(-c3ccc(-c4ccc5ccccc5c4)cc3)nc(-c3ccc4oc5ccccc5c4c3)n2)cc1 ; c1ccc(-c2nc(-c3ccc(-c4ccc5ccccc5c4)cc3)nc(-c3cccc4c3oc3ccccc34)n2)cc1]

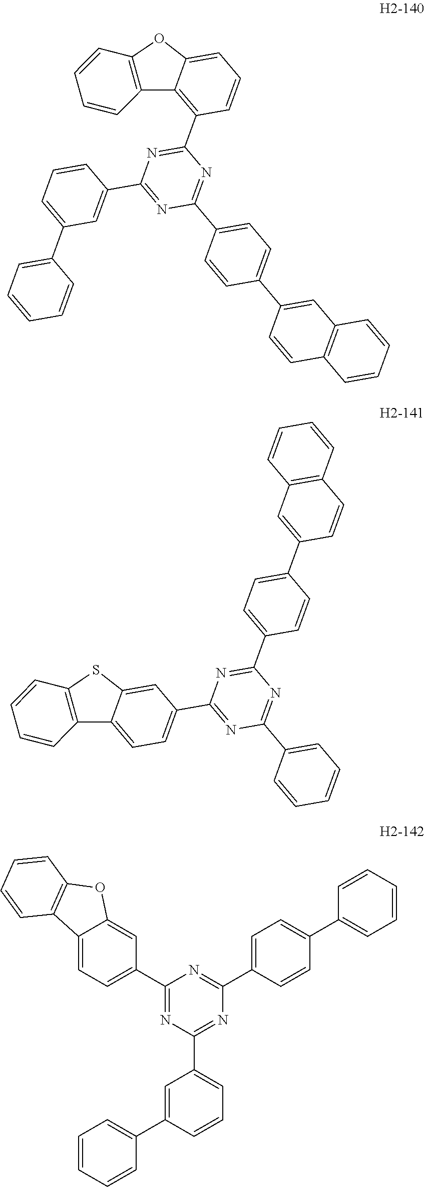 [SMILES: c1ccc(-c2cccc(-c3nc(-c4ccc(-c5ccc6ccccc6c5)cc4)nc(-c4cccc5oc6ccccc6c45)n3)c2)cc1 ; c1ccc(-c2nc(-c3ccc(-c4ccc5ccccc5c4)cc3)nc(-c3ccc4c(c3)sc3ccccc34)n2)cc1 ; c1ccc(-c2ccc(-c3nc(-c4cccc(-c5ccccc5)c4)nc(-c4ccc5c(c4)oc4ccccc45)n3)cc2)cc1]

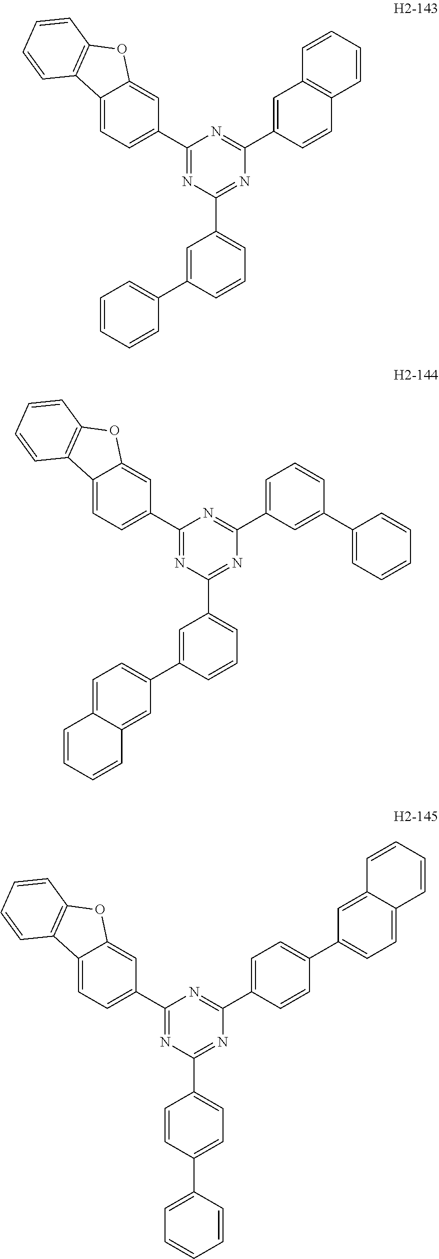 [SMILES: c1ccc(-c2cccc(-c3nc(-c4ccc5ccccc5c4)nc(-c4ccc5c(c4)oc4ccccc45)n3)c2)cc1 ; c1ccc(-c2cccc(-c3nc(-c4cccc(-c5ccc6ccccc6c5)c4)nc(-c4ccc5c(c4)oc4ccccc45)n3)c2)cc1 ; c1ccc(-c2ccc(-c3nc(-c4ccc(-c5ccc6ccccc6c5)cc4)nc(-c4ccc5c(c4)oc4ccccc45)n3)cc2)cc1]

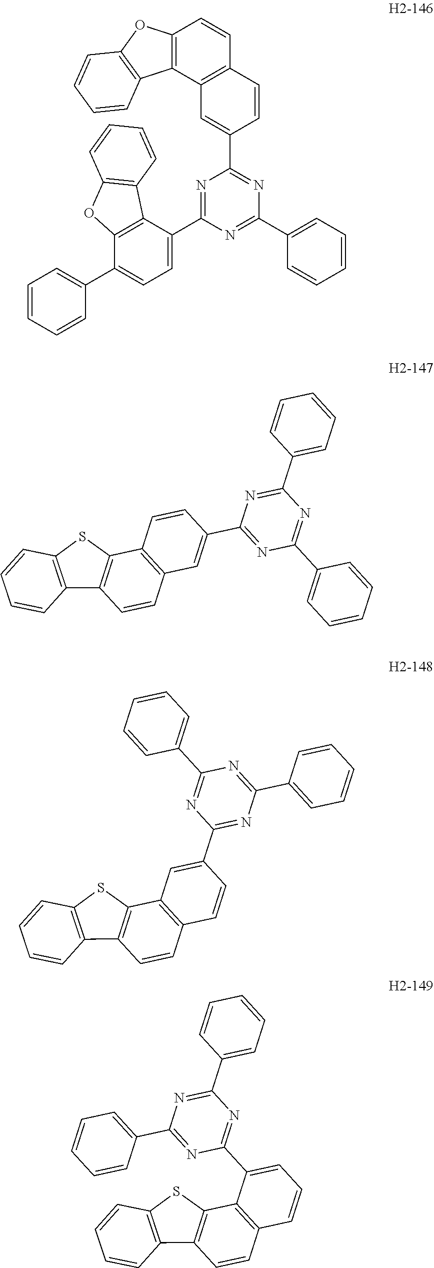 [SMILES: c1ccc(-c2nc(-c3ccc4ccc5oc6ccccc6c5c4c3)nc(-c3ccc(-c4ccccc4)c4oc5ccccc5c34)n2)cc1 ; c1ccc(-c2nc(-c3ccccc3)nc(-c3ccc4c(ccc5c6ccccc6sc45)c3)n2)cc1 ; c1ccc(-c2nc(-c3ccccc3)nc(-c3ccc4ccc5c6ccccc6sc5c4c3)n2)cc1 ; c1ccc(-c2nc(-c3ccccc3)nc(-c3cccc4ccc5c6ccccc6sc5c34)n2)cc1]

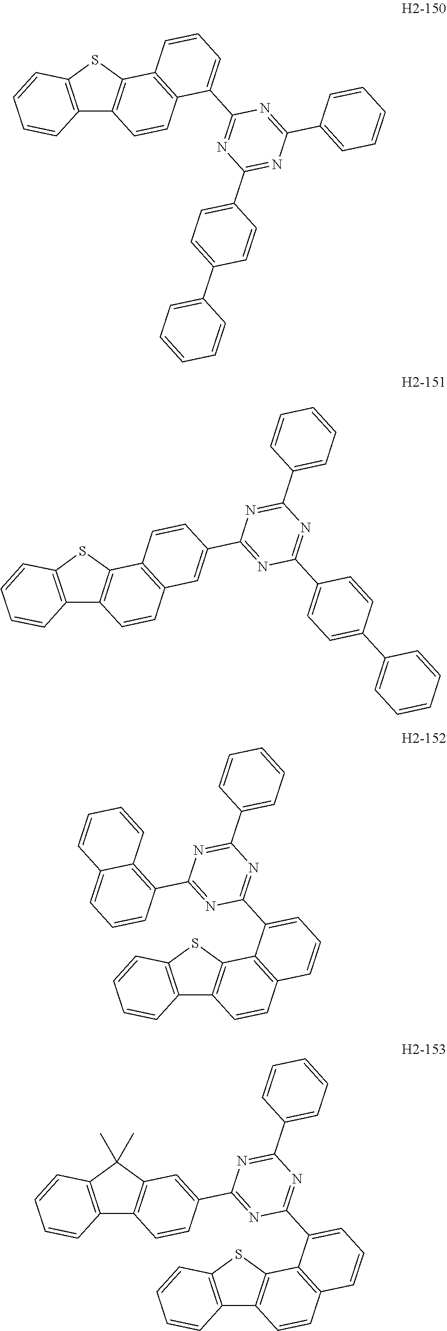 [SMILES: c1ccc(-c2ccc(-c3nc(-c4ccccc4)nc(-c4cccc5c4ccc4c6ccccc6sc54)n3)cc2)cc1 ; c1ccc(-c2ccc(-c3nc(-c4ccccc4)nc(-c4ccc5c(ccc6c7ccccc7sc56)c4)n3)cc2)cc1 ; c1ccc(-c2nc(-c3cccc4ccccc34)nc(-c3cccc4ccc5c6ccccc6sc5c34)n2)cc1 ; CC1(C)c2ccccc2-c2ccc(-c3nc(-c4ccccc4)nc(-c4cccc5ccc6c7ccccc7sc6c45)n3)cc21]

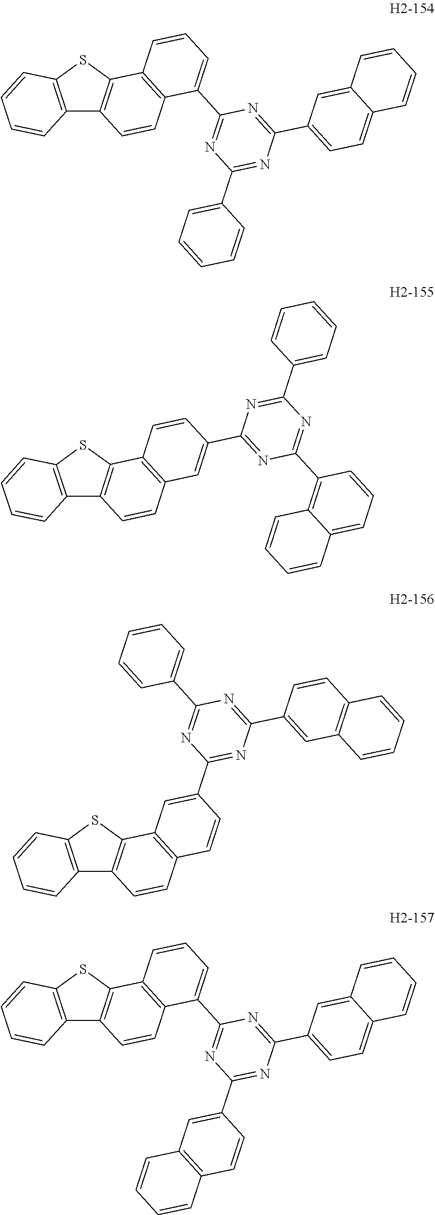 [SMILES: c1ccc(-c2nc(-c3ccc4ccccc4c3)nc(-c3cccc4c3ccc3c5ccccc5sc43)n2)cc1 ; c1ccc(-c2nc(-c3ccc4c(ccc5c6ccccc6sc45)c3)nc(-c3cccc4ccccc34)n2)cc1 ; c1ccc(-c2nc(-c3ccc4ccccc4c3)nc(-c3ccc4ccc5c6ccccc6sc5c4c3)n2)cc1 ; c1ccc2cc(-c3nc(-c4ccc5ccccc5c4)nc(-c4cccc5c4ccc4c6ccccc6sc54)n3)ccc2c1]

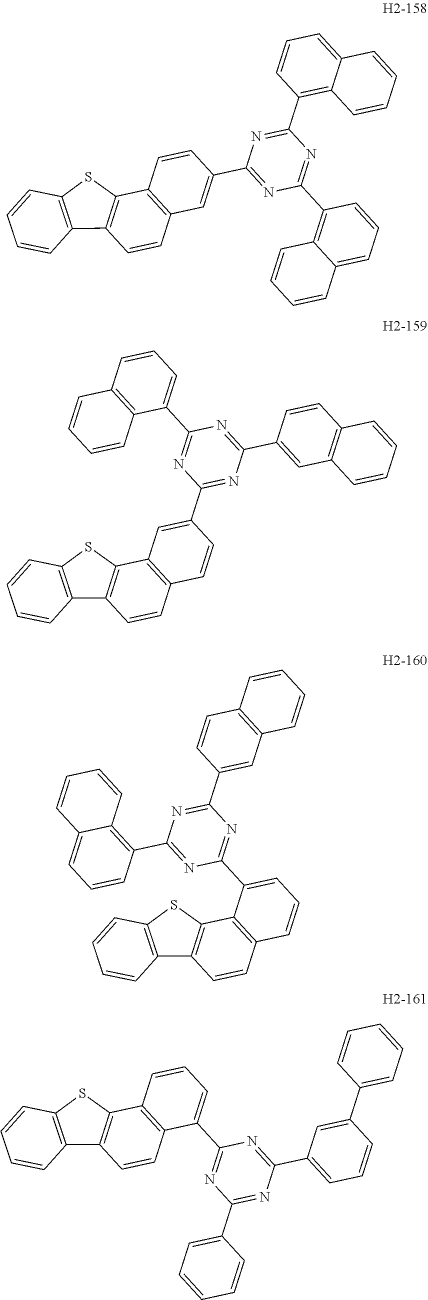 [SMILES: c1ccc2c(-c3nc(-c4ccc5c(ccc6c7ccccc7sc56)c4)nc(-c4cccc5ccccc45)n3)cccc2c1 ; c1ccc2cc(-c3nc(-c4ccc5ccc6c7ccccc7sc6c5c4)nc(-c4cccc5ccccc45)n3)ccc2c1 ; c1ccc2cc(-c3nc(-c4cccc5ccccc45)nc(-c4cccc5ccc6c7ccccc7sc6c45)n3)ccc2c1 ; c1ccc(-c2cccc(-c3nc(-c4ccccc4)nc(-c4cccc5c4ccc4c6ccccc6sc54)n3)c2)cc1]

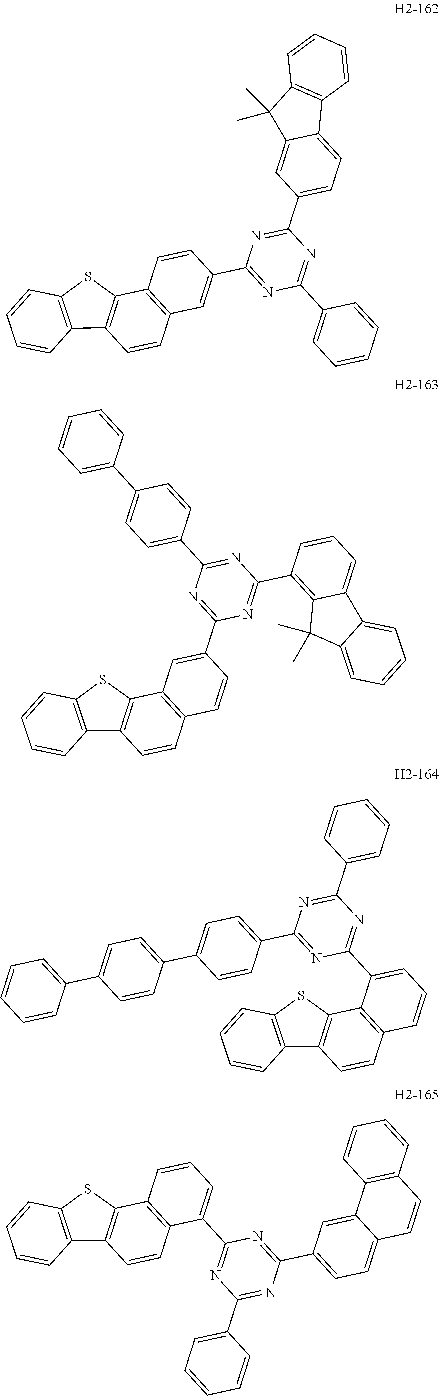 [SMILES: CC1(C)c2ccccc2-c2ccc(-c3nc(-c4ccccc4)nc(-c4ccc5c(ccc6c7ccccc7sc56)c4)n3)cc21 ; CC1(C)c2ccccc2-c2cccc(-c3nc(-c4ccc(-c5ccccc5)cc4)nc(-c4ccc5ccc6c7ccccc7sc6c5c4)n3)c21 ; c1ccc(-c2ccc(-c3ccc(-c4nc(-c5ccccc5)nc(-c5cccc6ccc7c8ccccc8sc7c56)n4)cc3)cc2)cc1 ; c1ccc(-c2nc(-c3ccc4ccc5ccccc5c4c3)nc(-c3cccc4c3ccc3c5ccccc5sc43)n2)cc1]

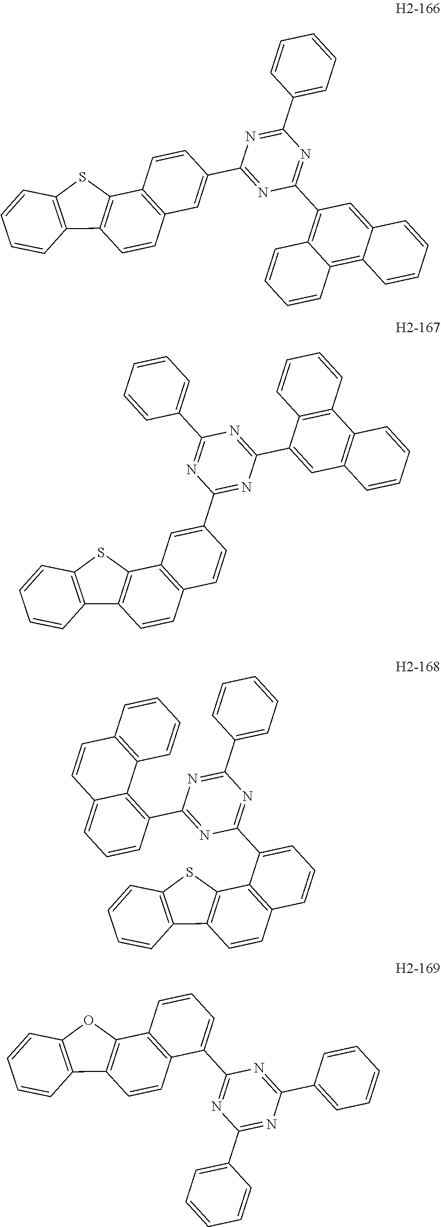 [SMILES: c1ccc(-c2nc(-c3ccc4c(ccc5c6ccccc6sc45)c3)nc(-c3cc4ccccc4c4ccccc34)n2)cc1 ; c1ccc(-c2nc(-c3ccc4ccc5c6ccccc6sc5c4c3)nc(-c3cc4ccccc4c4ccccc34)n2)cc1 ; c1ccc(-c2nc(-c3cccc4ccc5ccccc5c34)nc(-c3cccc4ccc5c6ccccc6sc5c34)n2)cc1 ; c1ccc(-c2nc(-c3ccccc3)nc(-c3cccc4c3ccc3c5ccccc5oc43)n2)cc1]

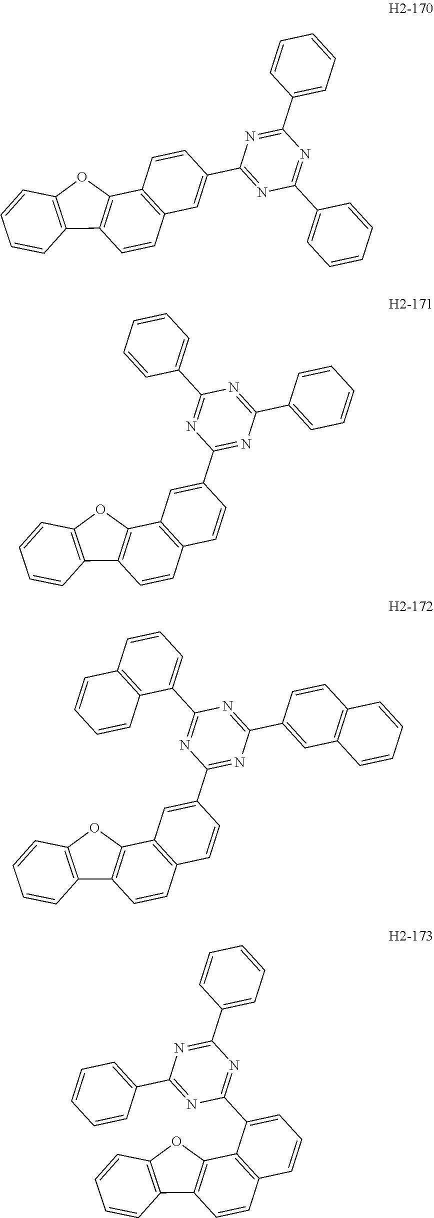 [SMILES: c1ccc(-c2nc(-c3ccccc3)nc(-c3ccc4c(ccc5c6ccccc6oc45)c3)n2)cc1 ; c1ccc(-c2nc(-c3ccccc3)nc(-c3ccc4ccc5c6ccccc6oc5c4c3)n2)cc1 ; c1ccc2cc(-c3nc(-c4ccc5ccc6c7ccccc7oc6c5c4)nc(-c4cccc5ccccc45)n3)ccc2c1 ; c1ccc(-c2nc(-c3ccccc3)nc(-c3cccc4ccc5c6ccccc6oc5c34)n2)cc1]

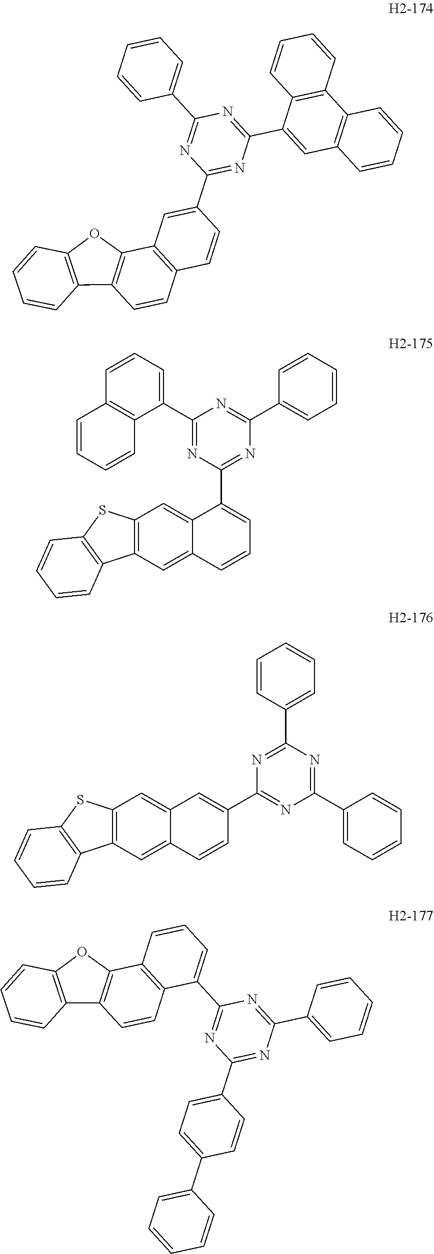

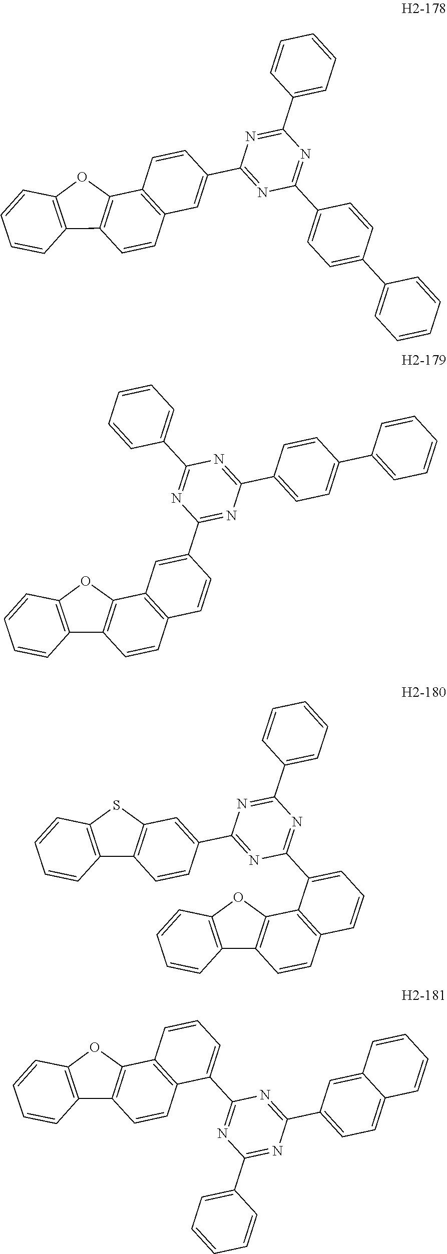 [SMILES: c1ccc(-c2ccc(-c3nc(-c4ccccc4)nc(-c4ccc5c(ccc6c7ccccc7oc56)c4)n3)cc2)cc1 ; c1ccc(-c2ccc(-c3nc(-c4ccccc4)nc(-c4ccc5ccc6c7ccccc7oc6c5c4)n3)cc2)cc1 ; c1ccc(-c2nc(-c3ccc4c(c3)sc3ccccc34)nc(-c3cccc4ccc5c6ccccc6oc5c34)n2)cc1 ; c1ccc(-c2nc(-c3ccc4ccccc4c3)nc(-c3cccc4c3ccc3c5ccccc5oc43)n2)cc1]

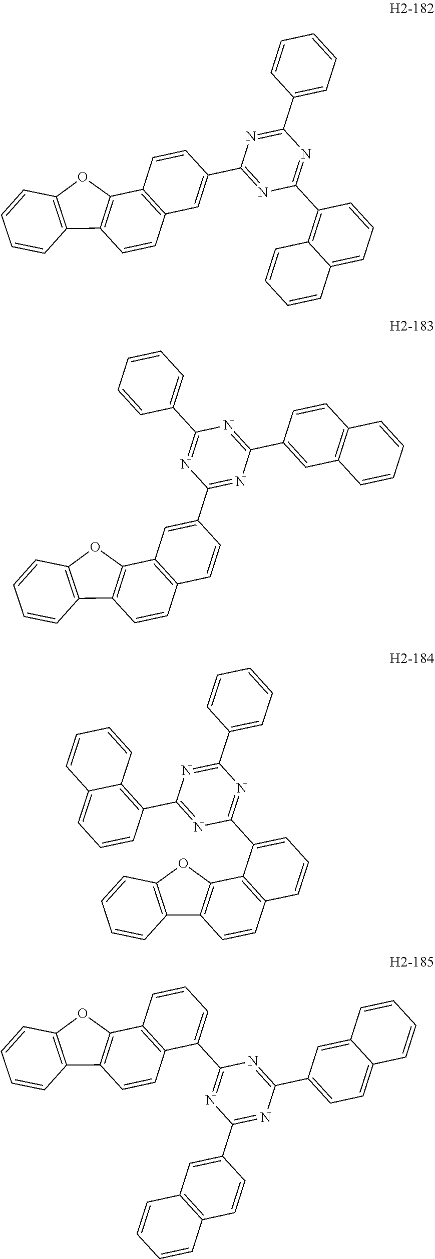 [SMILES: c1ccc(-c2nc(-c3ccc4c(ccc5c6ccccc6oc45)c3)nc(-c3cccc4ccccc34)n2)cc1 ; c1ccc(-c2nc(-c3ccc4ccccc4c3)nc(-c3ccc4ccc5c6ccccc6oc5c4c3)n2)cc1 ; c1ccc(-c2nc(-c3cccc4ccccc34)nc(-c3cccc4ccc5c6ccccc6oc5c34)n2)cc1 ; c1ccc2cc(-c3nc(-c4ccc5ccccc5c4)nc(-c4cccc5c4ccc4c6ccccc6oc54)n3)ccc2c1]

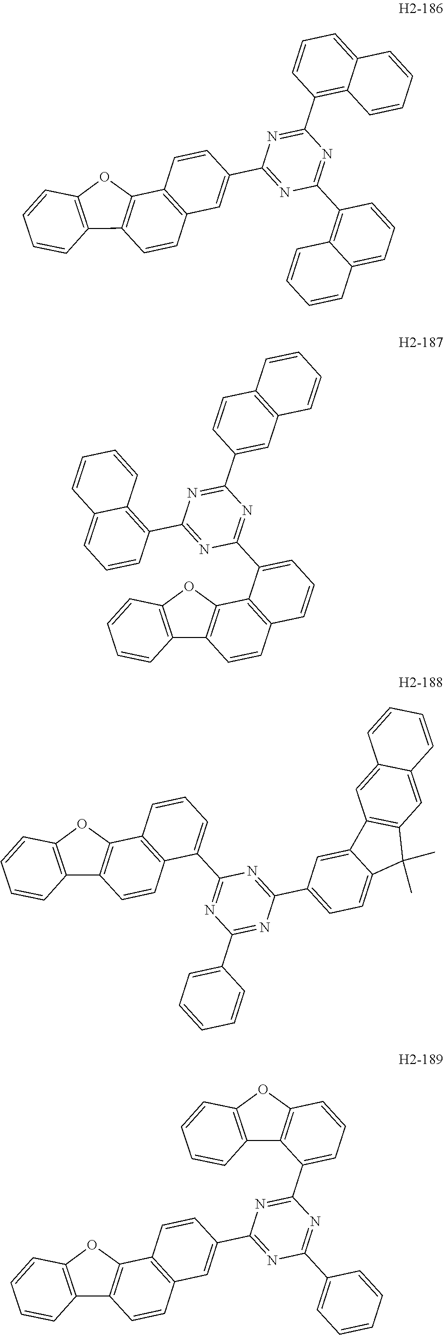 [SMILES: c1ccc2c(-c3nc(-c4ccc5c(ccc6c7ccccc7oc56)c4)nc(-c4cccc5ccccc45)n3)cccc2c1 ; c1ccc2cc(-c3nc(-c4cccc5ccccc45)nc(-c4cccc5ccc6c7ccccc7oc6c45)n3)ccc2c1 ; CC1(C)c2ccc(-c3nc(-c4ccccc4)nc(-c4cccc5c4ccc4c6ccccc6oc54)n3)cc2-c2cc3ccccc3cc21 ; c1ccc(-c2nc(-c3ccc4c(ccc5c6ccccc6oc45)c3)nc(-c3cccc4oc5ccccc5c34)n2)cc1]

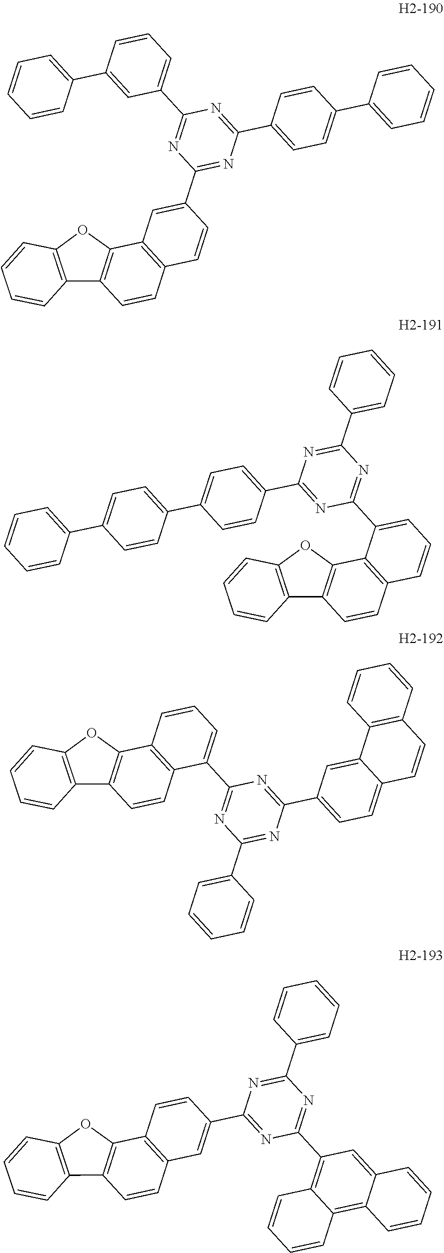 [SMILES: c1ccc(-c2ccc(-c3nc(-c4cccc(-c5ccccc5)c4)nc(-c4ccc5ccc6c7ccccc7oc6c5c4)n3)cc2)cc1 ; c1ccc(-c2ccc(-c3ccc(-c4nc(-c5ccccc5)nc(-c5cccc6ccc7c8ccccc8oc7c56)n4)cc3)cc2)cc1 ; c1ccc(-c2nc(-c3ccc4ccc5ccccc5c4c3)nc(-c3cccc4c3ccc3c5ccccc5oc43)n2)cc1 ; c1ccc(-c2nc(-c3ccc4c(ccc5c6ccccc6oc45)c3)nc(-c3cc4ccccc4c4ccccc34)n2)cc1]

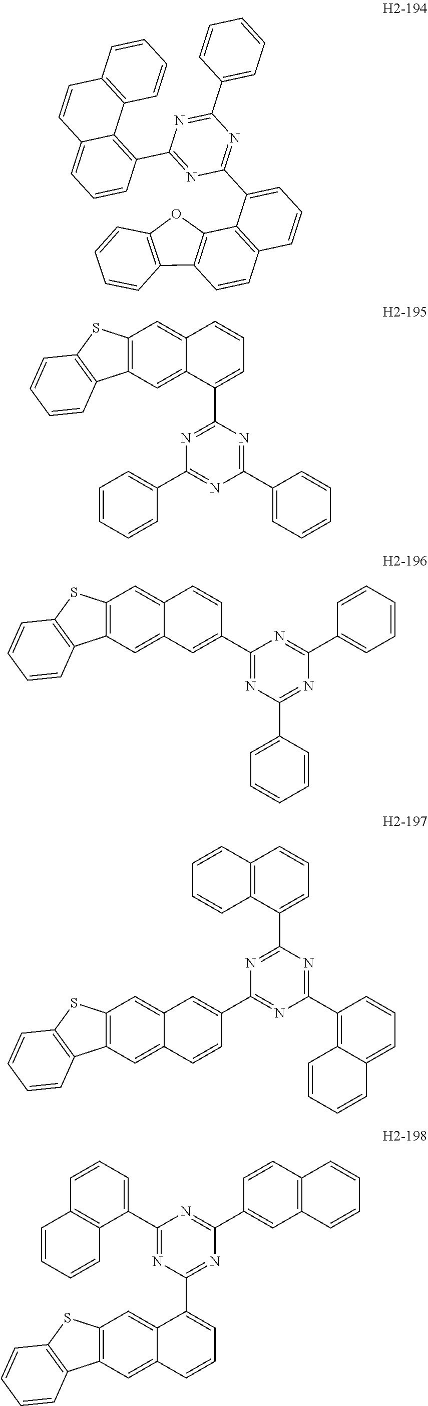

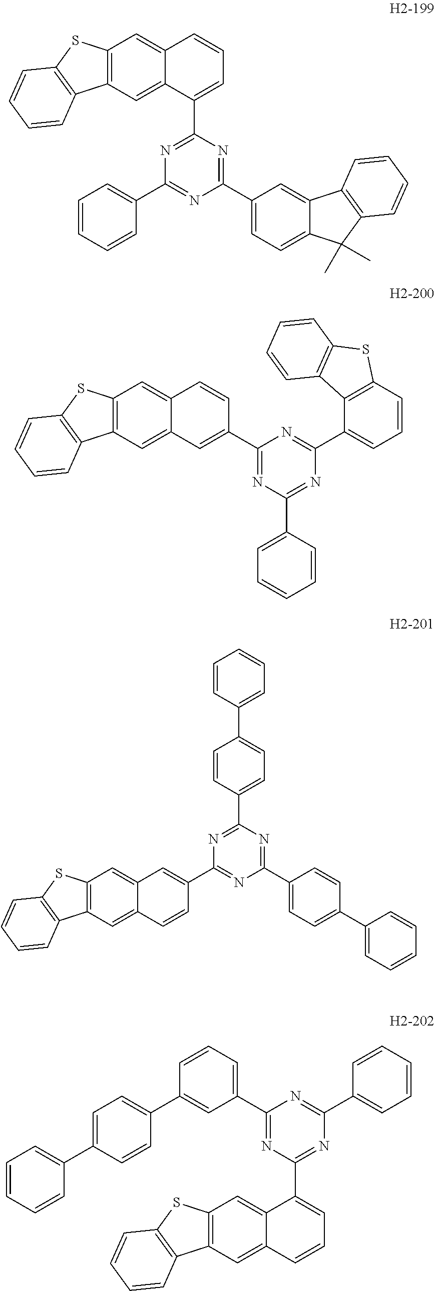 [SMILES: CC1(C)c2ccccc2-c2cc(-c3nc(-c4ccccc4)nc(-c4cccc5cc6sc7ccccc7c6cc45)n3)ccc21 ; c1ccc(-c2nc(-c3ccc4cc5sc6ccccc6c5cc4c3)nc(-c3cccc4sc5ccccc5c34)n2)cc1 ; c1ccc(-c2ccc(-c3nc(-c4ccc(-c5ccccc5)cc4)nc(-c4ccc5cc6c(cc5c4)sc4ccccc46)n3)cc2)cc1 ; c1ccc(-c2ccc(-c3cccc(-c4nc(-c5ccccc5)nc(-c5cccc6cc7c(cc56)sc5ccccc57)n4)c3)cc2)cc1]

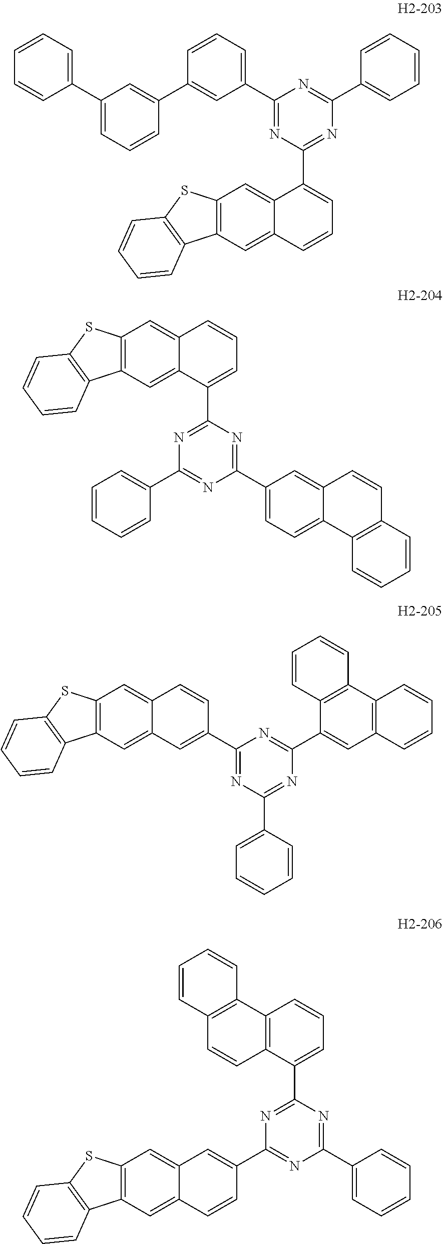

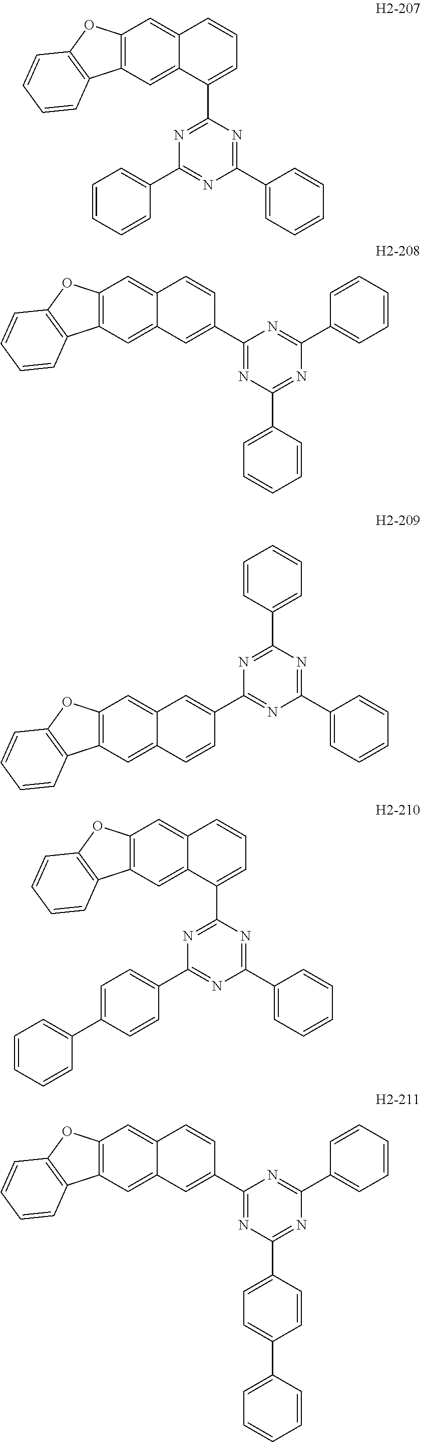

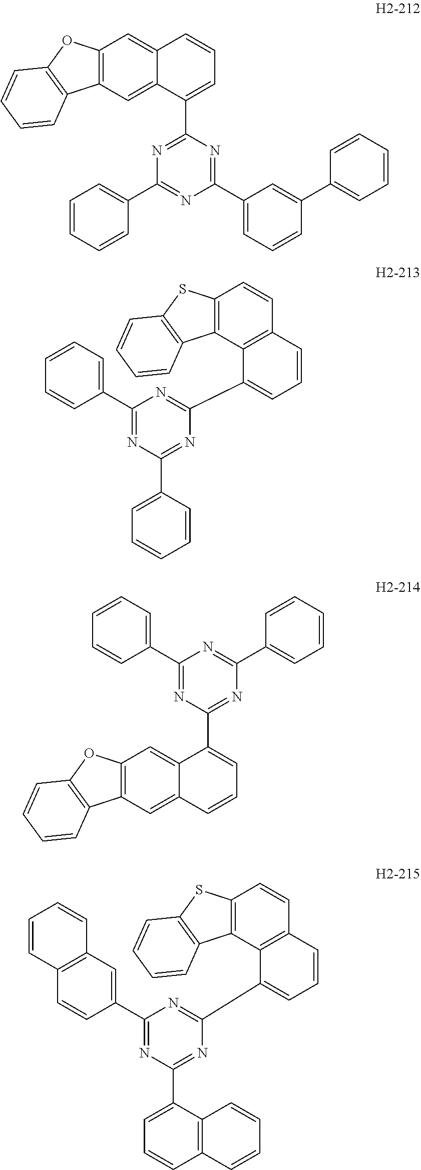

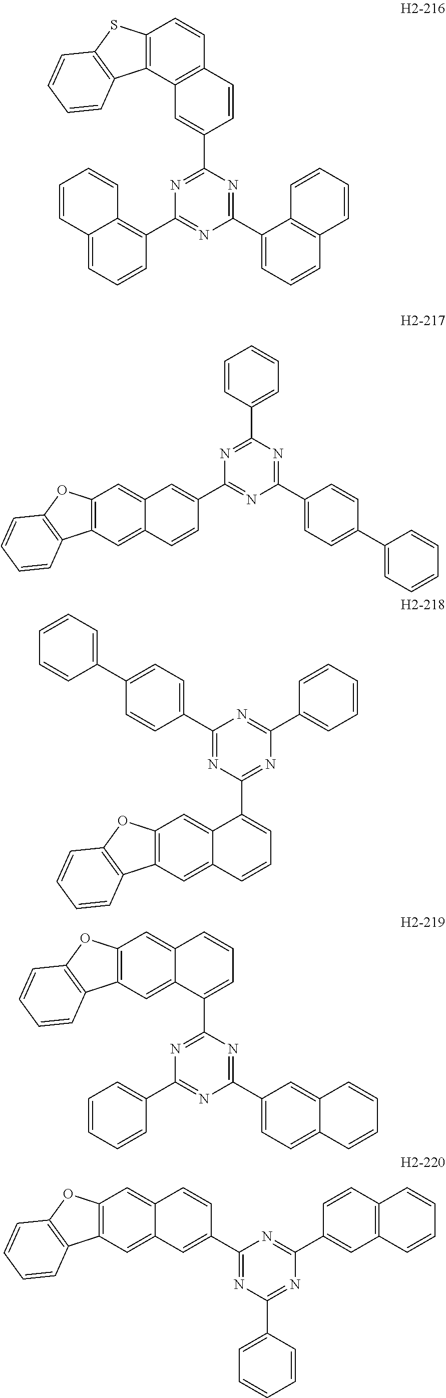

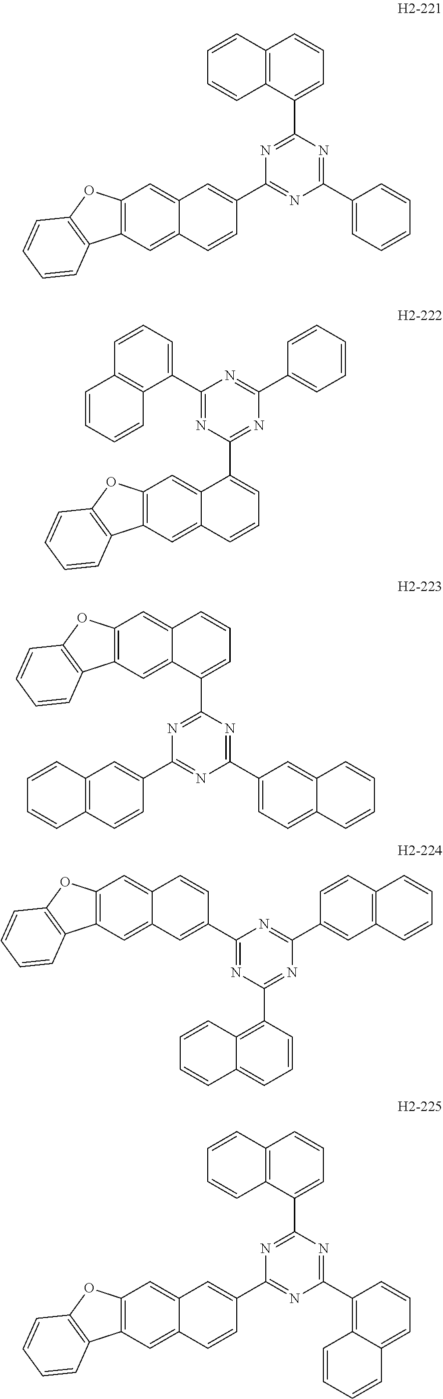 [SMILES: c1ccc(-c2nc(-c3ccc4cc5c(cc4c3)oc3ccccc35)nc(-c3cccc4ccccc34)n2)cc1 ; c1ccc(-c2nc(-c3cccc4ccccc34)nc(-c3cccc4cc5c(cc34)oc3ccccc35)n2)cc1 ; c1ccc2cc(-c3nc(-c4ccc5ccccc5c4)nc(-c4cccc5cc6oc7ccccc7c6cc45)n3)ccc2c1 ; c1ccc2cc(-c3nc(-c4ccc5cc6oc7ccccc7c6cc5c4)nc(-c4cccc5ccccc45)n3)ccc2c1 ; c1ccc2c(-c3nc(-c4ccc5cc6c(cc5c4)oc4ccccc46)nc(-c4cccc5ccccc45)n3)cccc2c1]

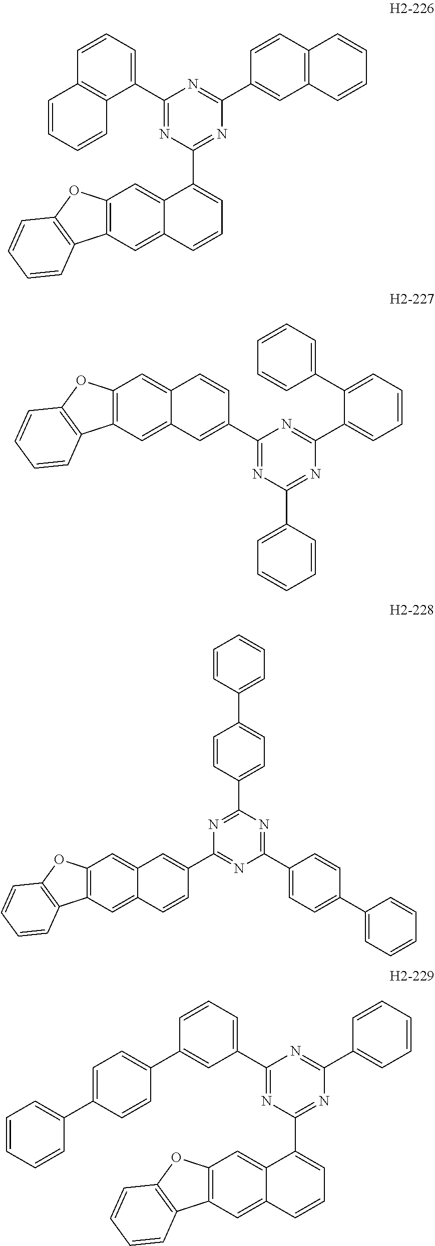

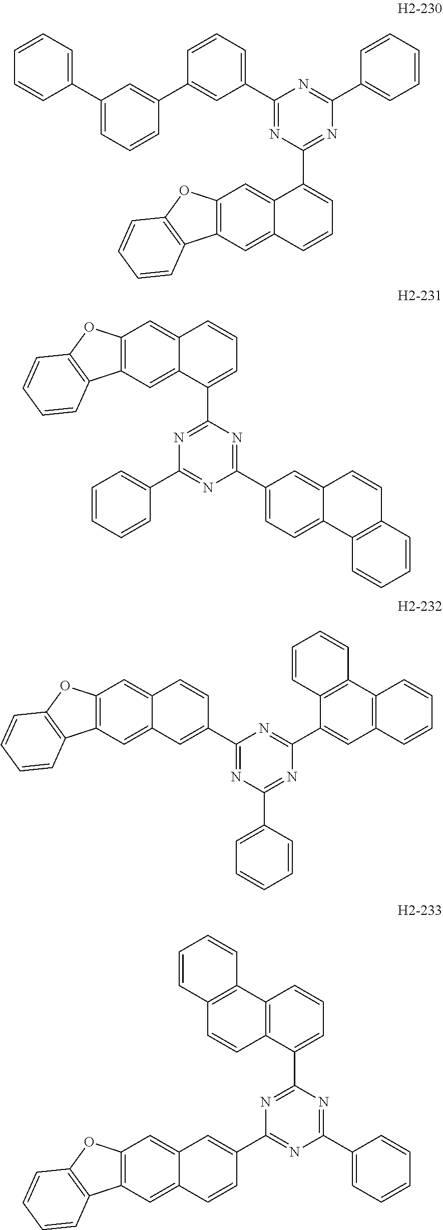

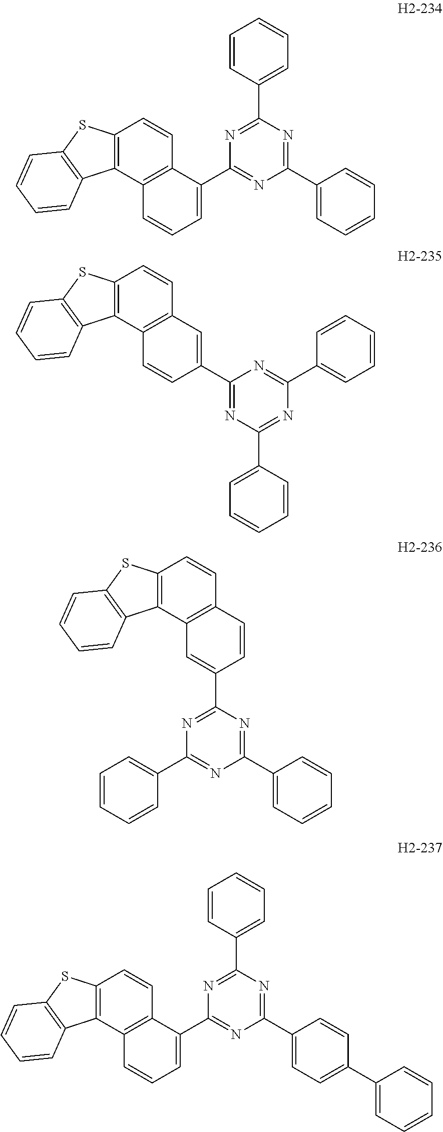

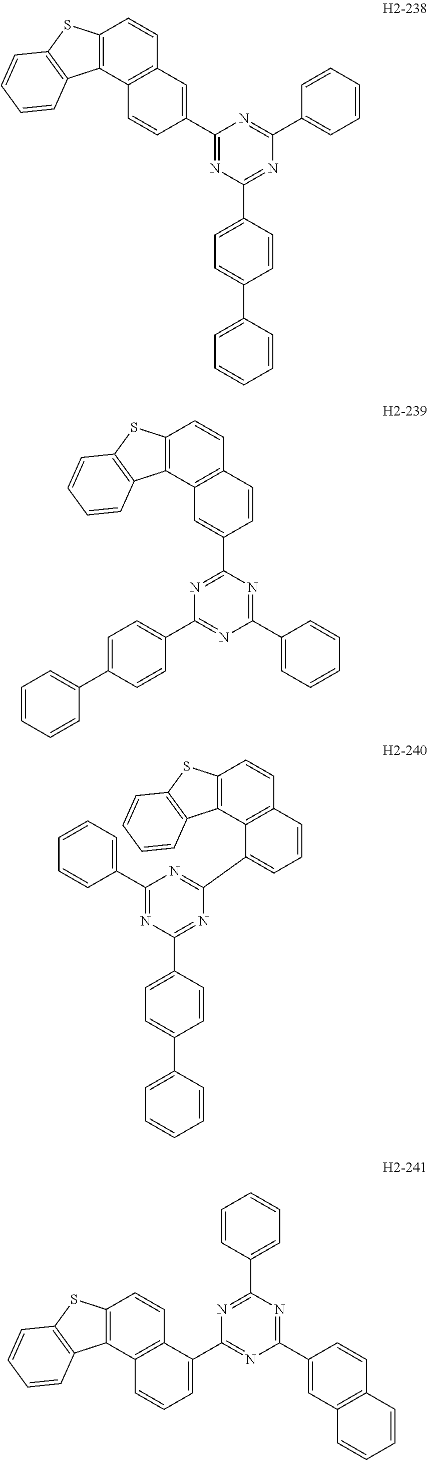 [SMILES: c1ccc(-c2ccc(-c3nc(-c4ccccc4)nc(-c4ccc5c(ccc6sc7ccccc7c65)c4)n3)cc2)cc1 ; c1ccc(-c2ccc(-c3nc(-c4ccccc4)nc(-c4ccc5ccc6sc7ccccc7c6c5c4)n3)cc2)cc1 ; c1ccc(-c2ccc(-c3nc(-c4ccccc4)nc(-c4cccc5ccc6sc7ccccc7c6c45)n3)cc2)cc1 ; c1ccc(-c2nc(-c3ccc4ccccc4c3)nc(-c3cccc4c3ccc3sc5ccccc5c34)n2)cc1]

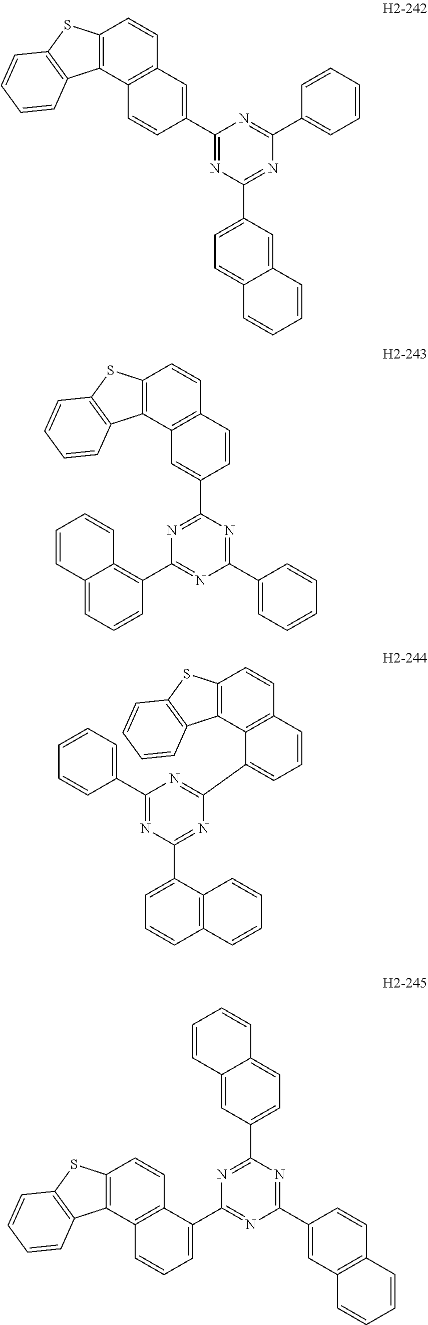 [SMILES: c1ccc(-c2nc(-c3ccc4ccccc4c3)nc(-c3ccc4c(ccc5sc6ccccc6c54)c3)n2)cc1 ; c1ccc(-c2nc(-c3ccc4ccc5sc6ccccc6c5c4c3)nc(-c3cccc4ccccc34)n2)cc1 ; c1ccc(-c2nc(-c3cccc4ccccc34)nc(-c3cccc4ccc5sc6ccccc6c5c34)n2)cc1 ; c1ccc2cc(-c3nc(-c4ccc5ccccc5c4)nc(-c4cccc5c4ccc4sc6ccccc6c45)n3)ccc2c1]

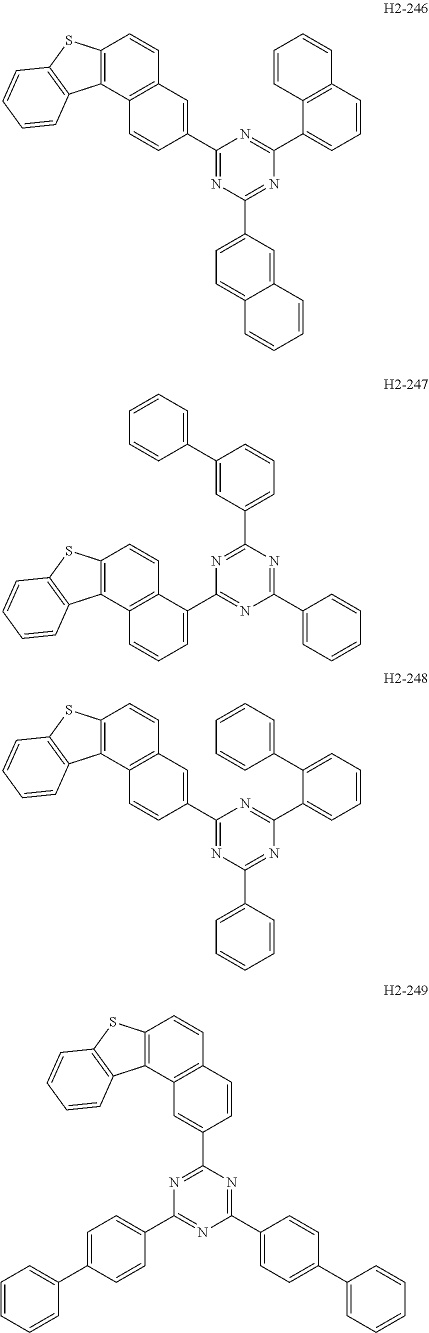 [SMILES: c1ccc2cc(-c3nc(-c4ccc5c(ccc6sc7ccccc7c65)c4)nc(-c4cccc5ccccc45)n3)ccc2c1 ; c1ccc(-c2cccc(-c3nc(-c4ccccc4)nc(-c4cccc5c4ccc4sc6ccccc6c45)n3)c2)cc1 ; c1ccc(-c2nc(-c3ccc4c(ccc5sc6ccccc6c54)c3)nc(-c3ccccc3-c3ccccc3)n2)cc1 ; c1ccc(-c2ccc(-c3nc(-c4ccc(-c5ccccc5)cc4)nc(-c4ccc5ccc6sc7ccccc7c6c5c4)n3)cc2)cc1]

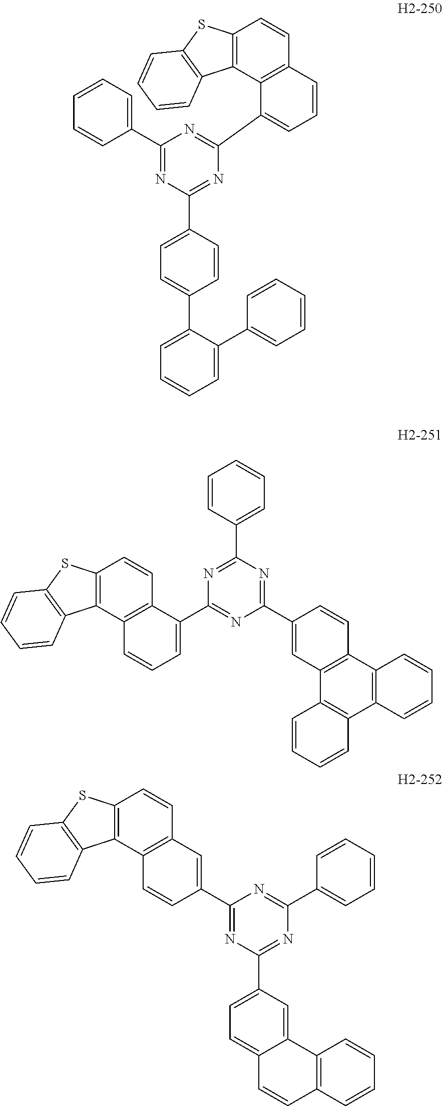 [SMILES: c1ccc(-c2nc(-c3ccc(-c4ccccc4-c4ccccc4)cc3)nc(-c3cccc4ccc5sc6ccccc6c5c34)n2)cc1 ; c1ccc(-c2nc(-c3ccc4c5ccccc5c5ccccc5c4c3)nc(-c3cccc4c3ccc3sc5ccccc5c34)n2)cc1 ; c1ccc(-c2nc(-c3ccc4c(ccc5sc6ccccc6c54)c3)nc(-c3ccc4ccc5ccccc5c4c3)n2)cc1]

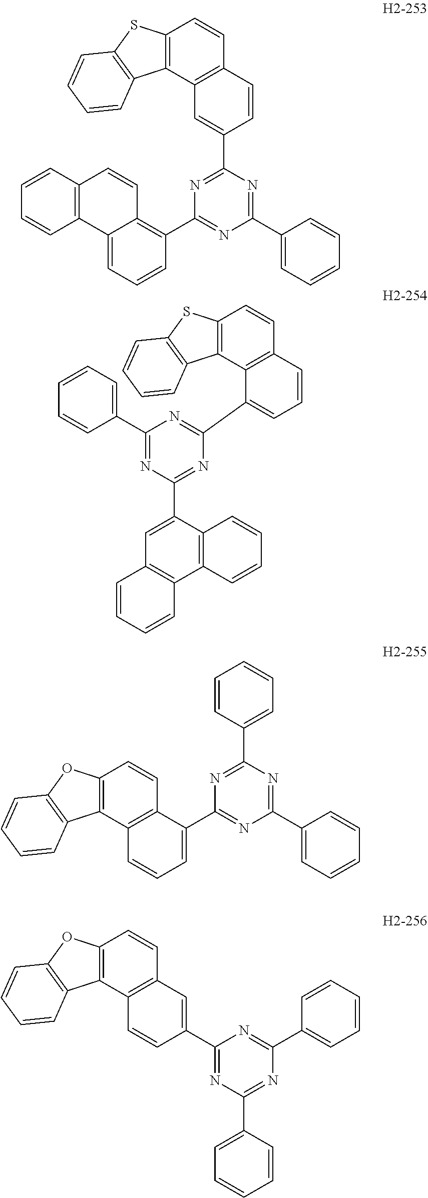 [SMILES: c1ccc(-c2nc(-c3ccc4ccc5sc6ccccc6c5c4c3)nc(-c3cccc4c3ccc3ccccc34)n2)cc1 ; c1ccc(-c2nc(-c3cc4ccccc4c4ccccc34)nc(-c3cccc4ccc5sc6ccccc6c5c34)n2)cc1 ; c1ccc(-c2nc(-c3ccccc3)nc(-c3cccc4c3ccc3oc5ccccc5c34)n2)cc1 ; c1ccc(-c2nc(-c3ccccc3)nc(-c3ccc4c(ccc5oc6ccccc6c54)c3)n2)cc1]

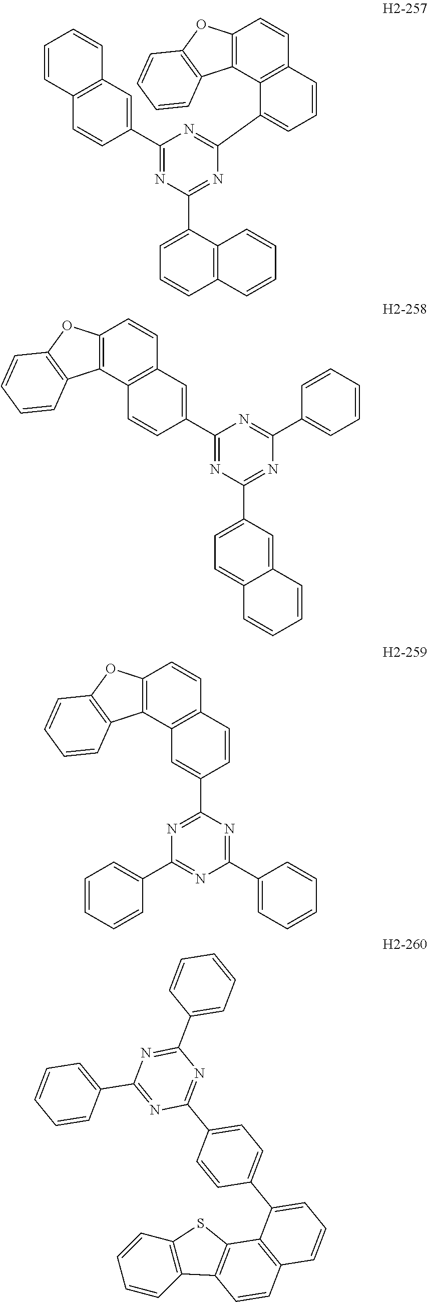 [SMILES: c1ccc2cc(-c3nc(-c4cccc5ccccc45)nc(-c4cccc5ccc6oc7ccccc7c6c45)n3)ccc2c1 ; c1ccc(-c2nc(-c3ccc4ccccc4c3)nc(-c3ccc4c(ccc5oc6ccccc6c54)c3)n2)cc1 ; c1ccc(-c2nc(-c3ccccc3)nc(-c3ccc4ccc5oc6ccccc6c5c4c3)n2)cc1 ; c1ccc(-c2nc(-c3ccccc3)nc(-c3ccc(-c4cccc5ccc6c7ccccc7sc6c45)cc3)n2)cc1]

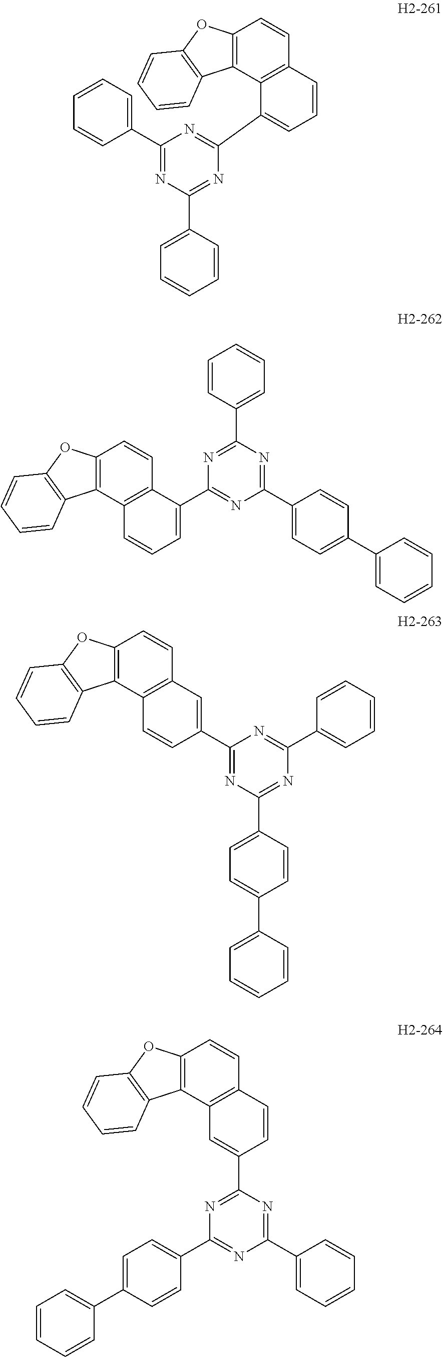 [SMILES: c1ccc(-c2nc(-c3ccccc3)nc(-c3cccc4ccc5oc6ccccc6c5c34)n2)cc1 ; c1ccc(-c2ccc(-c3nc(-c4ccccc4)nc(-c4cccc5c4ccc4oc6ccccc6c45)n3)cc2)cc1 ; c1ccc(-c2ccc(-c3nc(-c4ccccc4)nc(-c4ccc5c(ccc6oc7ccccc7c65)c4)n3)cc2)cc1 ; c1ccc(-c2ccc(-c3nc(-c4ccccc4)nc(-c4ccc5ccc6oc7ccccc7c6c5c4)n3)cc2)cc1]

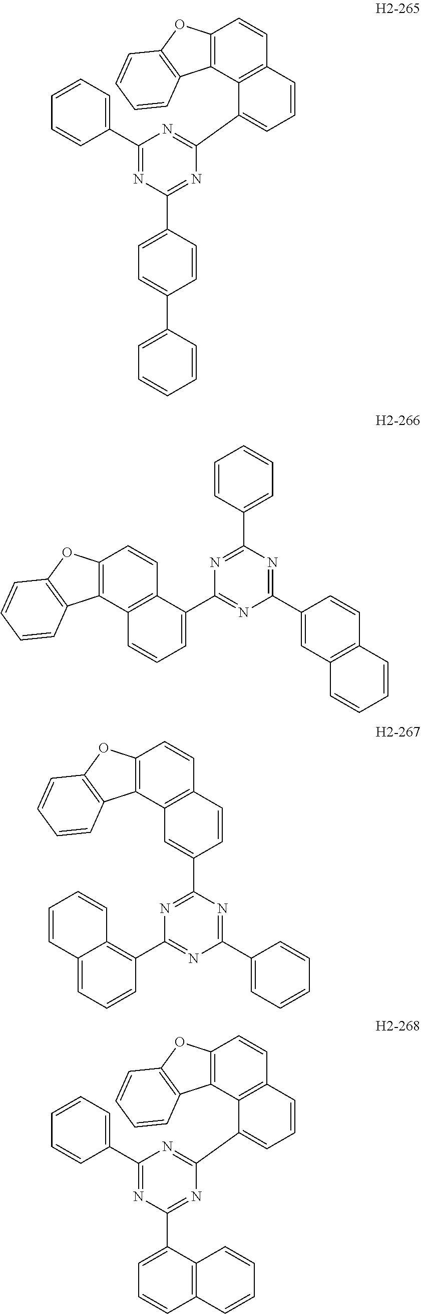

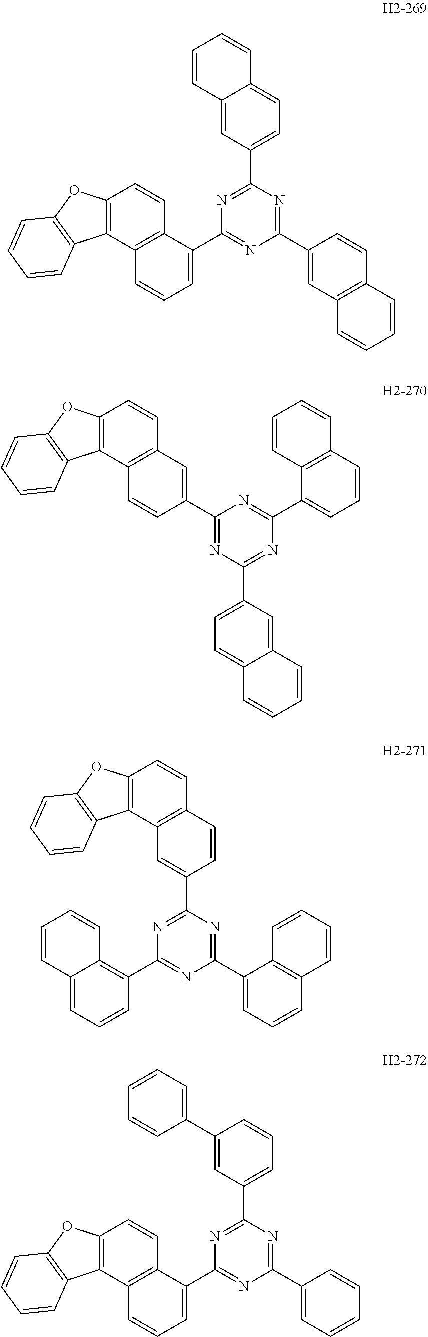 [SMILES: c1ccc2cc(-c3nc(-c4ccc5ccccc5c4)nc(-c4cccc5c4ccc4oc6ccccc6c45)n3)ccc2c1 ; c1ccc2cc(-c3nc(-c4ccc5c(ccc6oc7ccccc7c65)c4)nc(-c4cccc5ccccc45)n3)ccc2c1 ; c1ccc2c(-c3nc(-c4ccc5ccc6oc7ccccc7c6c5c4)nc(-c4cccc5ccccc45)n3)cccc2c1 ; c1ccc(-c2cccc(-c3nc(-c4ccccc4)nc(-c4cccc5c4ccc4oc6ccccc6c45)n3)c2)cc1]

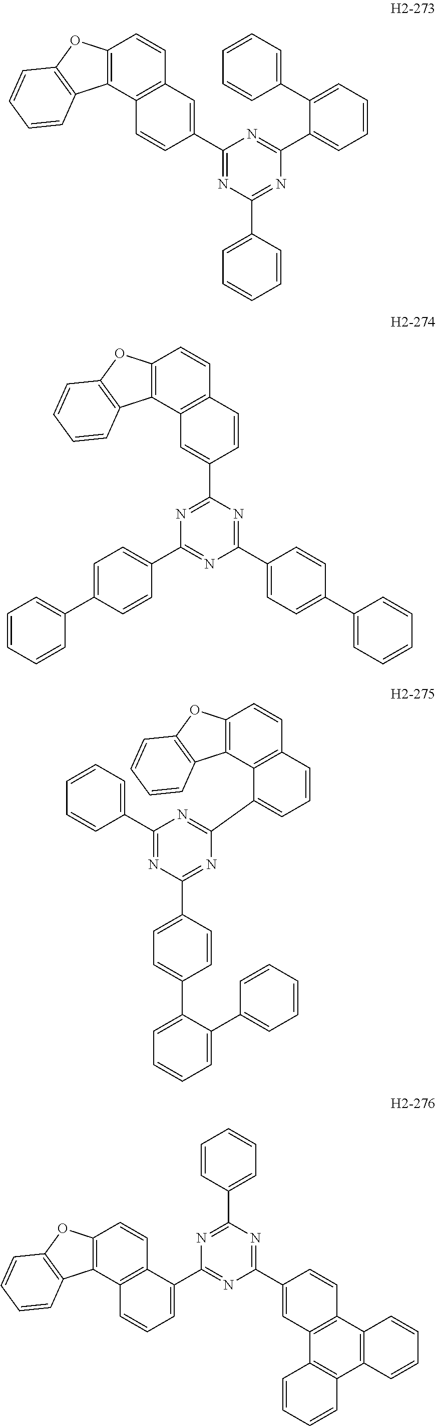 [SMILES: c1ccc(-c2nc(-c3ccc4c(ccc5oc6ccccc6c54)c3)nc(-c3ccccc3-c3ccccc3)n2)cc1 ; c1ccc(-c2ccc(-c3nc(-c4ccc(-c5ccccc5)cc4)nc(-c4ccc5ccc6oc7ccccc7c6c5c4)n3)cc2)cc1 ; c1ccc(-c2nc(-c3ccc(-c4ccccc4-c4ccccc4)cc3)nc(-c3cccc4ccc5oc6ccccc6c5c34)n2)cc1 ; c1ccc(-c2nc(-c3ccc4c5ccccc5c5ccccc5c4c3)nc(-c3cccc4c3ccc3oc5ccccc5c34)n2)cc1]

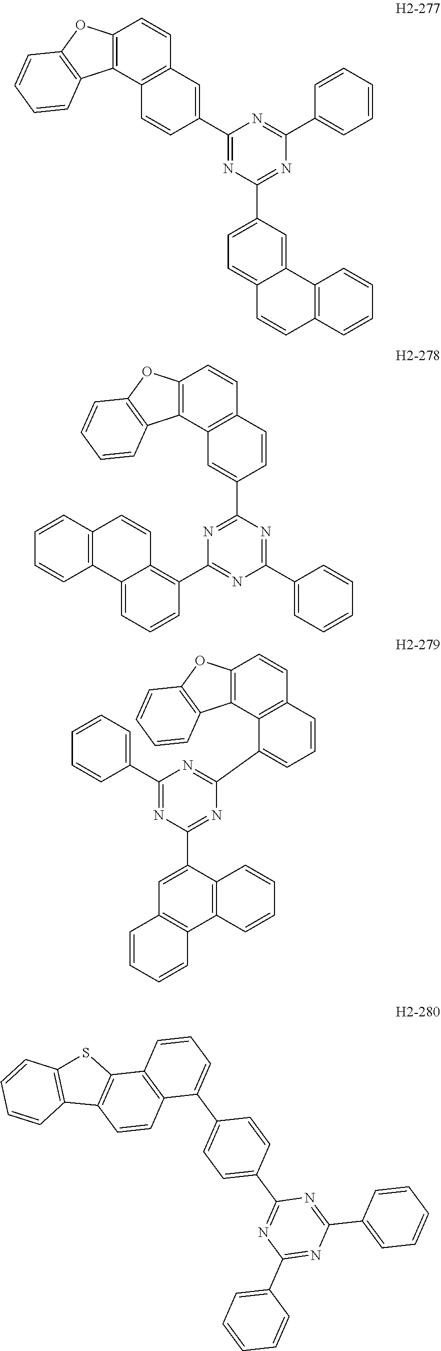 [SMILES: c1ccc(-c2nc(-c3ccc4c(ccc5oc6ccccc6c54)c3)nc(-c3ccc4ccc5ccccc5c4c3)n2)cc1 ; c1ccc(-c2nc(-c3ccc4ccc5oc6ccccc6c5c4c3)nc(-c3cccc4c3ccc3ccccc34)n2)cc1 ; c1ccc(-c2nc(-c3cc4ccccc4c4ccccc34)nc(-c3cccc4ccc5oc6ccccc6c5c34)n2)cc1 ; c1ccc(-c2nc(-c3ccccc3)nc(-c3ccc(-c4cccc5c4ccc4c6ccccc6sc54)cc3)n2)cc1]

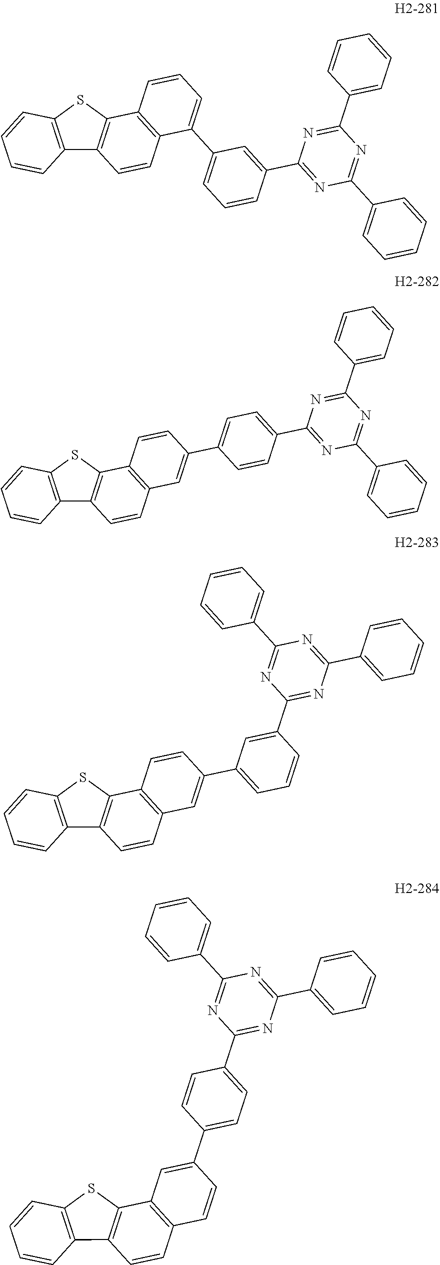 [SMILES: c1ccc(-c2nc(-c3ccccc3)nc(-c3cccc(-c4cccc5c4ccc4c6ccccc6sc54)c3)n2)cc1 ; c1ccc(-c2nc(-c3ccccc3)nc(-c3ccc(-c4ccc5c(ccc6c7ccccc7sc56)c4)cc3)n2)cc1 ; c1ccc(-c2nc(-c3ccccc3)nc(-c3cccc(-c4ccc5c(ccc6c7ccccc7sc56)c4)c3)n2)cc1 ; c1ccc(-c2nc(-c3ccccc3)nc(-c3ccc(-c4ccc5ccc6c7ccccc7sc6c5c4)cc3)n2)cc1]

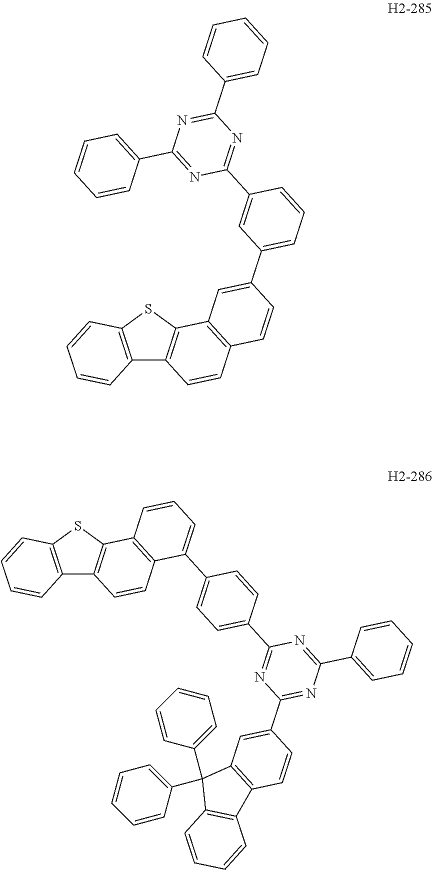 [SMILES: c1ccc(-c2nc(-c3ccccc3)nc(-c3cccc(-c4ccc5ccc6c7ccccc7sc6c5c4)c3)n2)cc1 ; c1ccc(-c2nc(-c3ccc(-c4cccc5c4ccc4c6ccccc6sc54)cc3)nc(-c3ccc4c(c3)C(c3ccccc3)(c3ccccc3)c3ccccc3-4)n2)cc1]

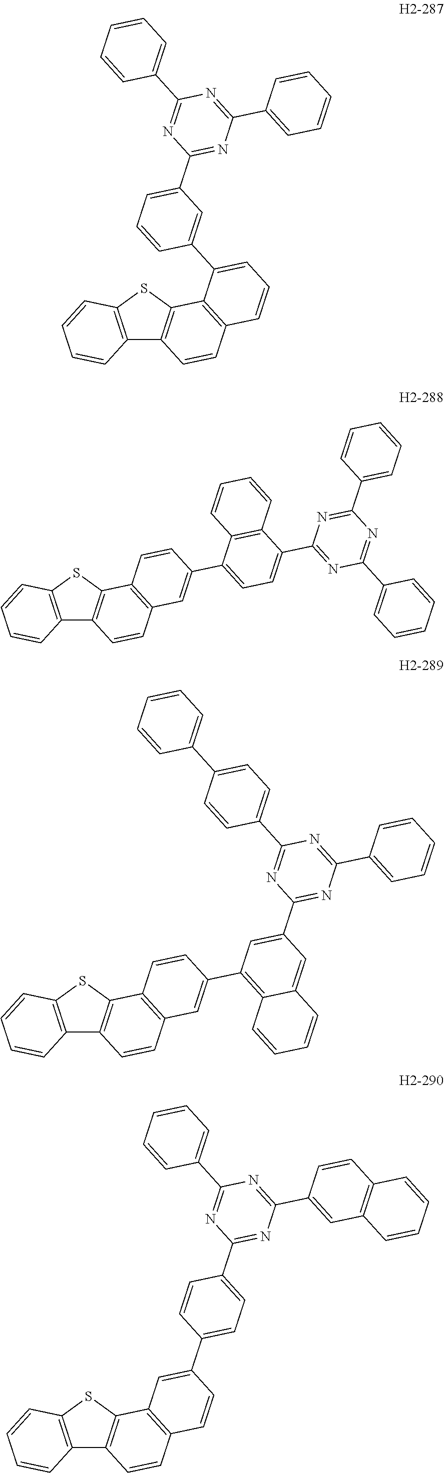 [SMILES: c1ccc(-c2nc(-c3ccccc3)nc(-c3cccc(-c4cccc5ccc6c7ccccc7sc6c45)c3)n2)cc1 ; c1ccc(-c2nc(-c3ccccc3)nc(-c3ccc(-c4ccc5c(ccc6c7ccccc7sc56)c4)c4ccccc34)n2)cc1 ; c1ccc(-c2ccc(-c3nc(-c4ccccc4)nc(-c4cc(-c5ccc6c(ccc7c8ccccc8sc67)c5)c5ccccc5c4)n3)cc2)cc1 ; c1ccc(-c2nc(-c3ccc(-c4ccc5ccc6c7ccccc7sc6c5c4)cc3)nc(-c3ccc4ccccc4c3)n2)cc1]

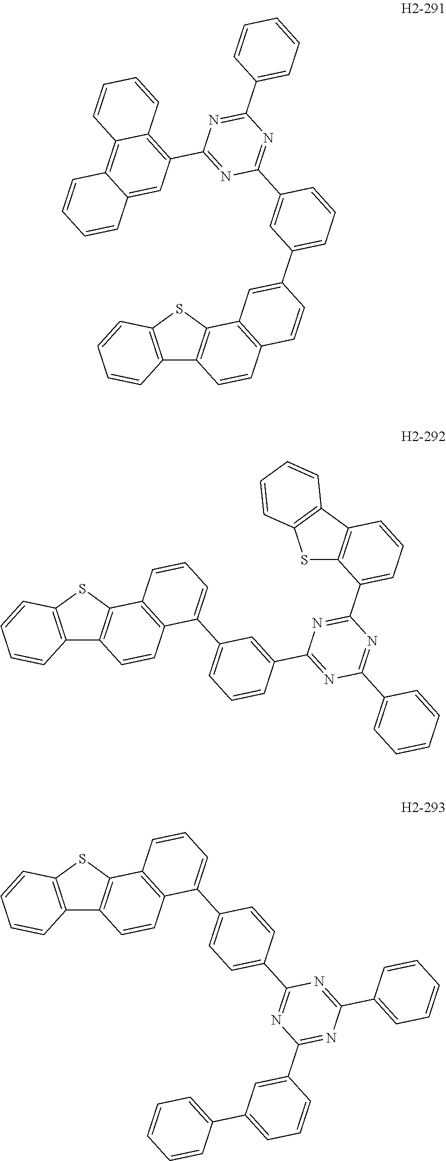 [SMILES: c1ccc(-c2nc(-c3cccc(-c4ccc5ccc6c7ccccc7sc6c5c4)c3)nc(-c3cc4ccccc4c4ccccc34)n2)cc1 ; c1ccc(-c2nc(-c3cccc(-c4cccc5c4ccc4c6ccccc6sc54)c3)nc(-c3cccc4c3sc3ccccc34)n2)cc1 ; c1ccc(-c2cccc(-c3nc(-c4ccccc4)nc(-c4ccc(-c5cccc6c5ccc5c7ccccc7sc65)cc4)n3)c2)cc1]

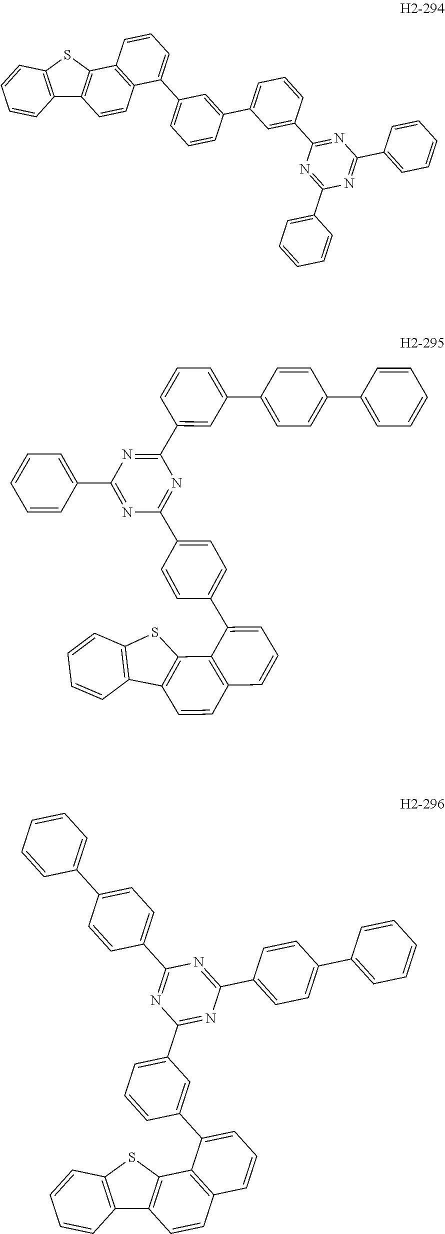 [SMILES: c1ccc(-c2nc(-c3ccccc3)nc(-c3cccc(-c4cccc(-c5cccc6c5ccc5c7ccccc7sc65)c4)c3)n2)cc1 ; c1ccc(-c2ccc(-c3cccc(-c4nc(-c5ccccc5)nc(-c5ccc(-c6cccc7ccc8c9ccccc9sc8c67)cc5)n4)c3)cc2)cc1 ; c1ccc(-c2ccc(-c3nc(-c4ccc(-c5ccccc5)cc4)nc(-c4cccc(-c5cccc6ccc7c8ccccc8sc7c56)c4)n3)cc2)cc1]

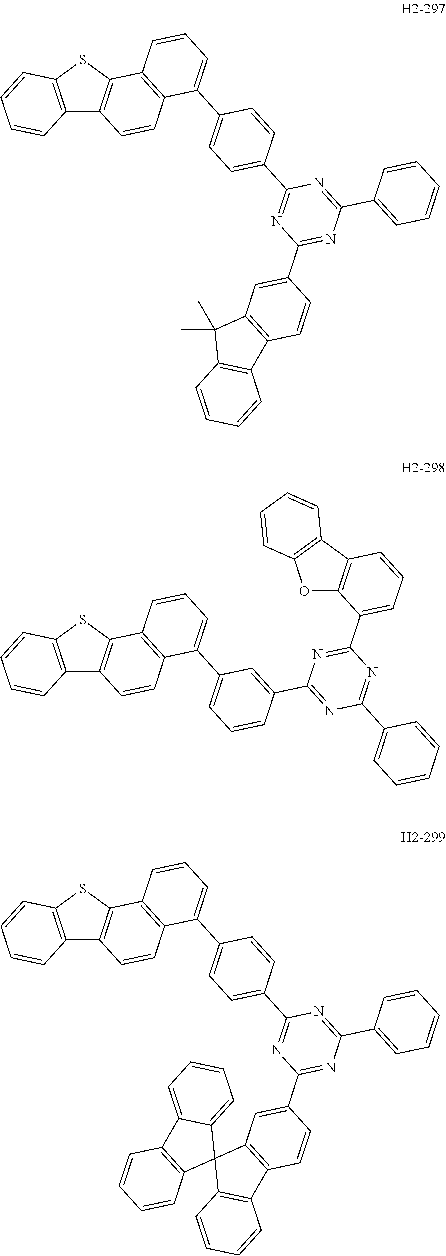 [SMILES: CC1(C)c2ccccc2-c2ccc(-c3nc(-c4ccccc4)nc(-c4ccc(-c5cccc6c5ccc5c7ccccc7sc65)cc4)n3)cc21 ; c1ccc(-c2nc(-c3cccc(-c4cccc5c4ccc4c6ccccc6sc54)c3)nc(-c3cccc4c3oc3ccccc34)n2)cc1 ; c1ccc(-c2nc(-c3ccc(-c4cccc5c4ccc4c6ccccc6sc54)cc3)nc(-c3ccc4c(c3)C3(c5ccccc5-c5ccccc53)c3ccccc3-4)n2)cc1]

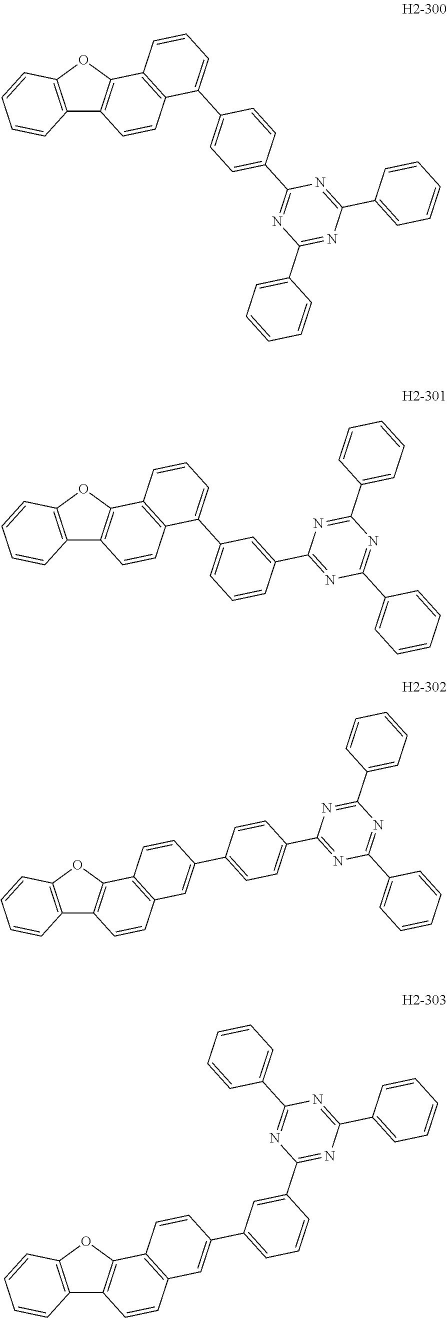 [SMILES: c1ccc(-c2nc(-c3ccccc3)nc(-c3ccc(-c4cccc5c4ccc4c6ccccc6oc54)cc3)n2)cc1 ; c1ccc(-c2nc(-c3ccccc3)nc(-c3cccc(-c4cccc5c4ccc4c6ccccc6oc54)c3)n2)cc1 ; c1ccc(-c2nc(-c3ccccc3)nc(-c3ccc(-c4ccc5c(ccc6c7ccccc7oc56)c4)cc3)n2)cc1 ; c1ccc(-c2nc(-c3ccccc3)nc(-c3cccc(-c4ccc5c(ccc6c7ccccc7oc56)c4)c3)n2)cc1]

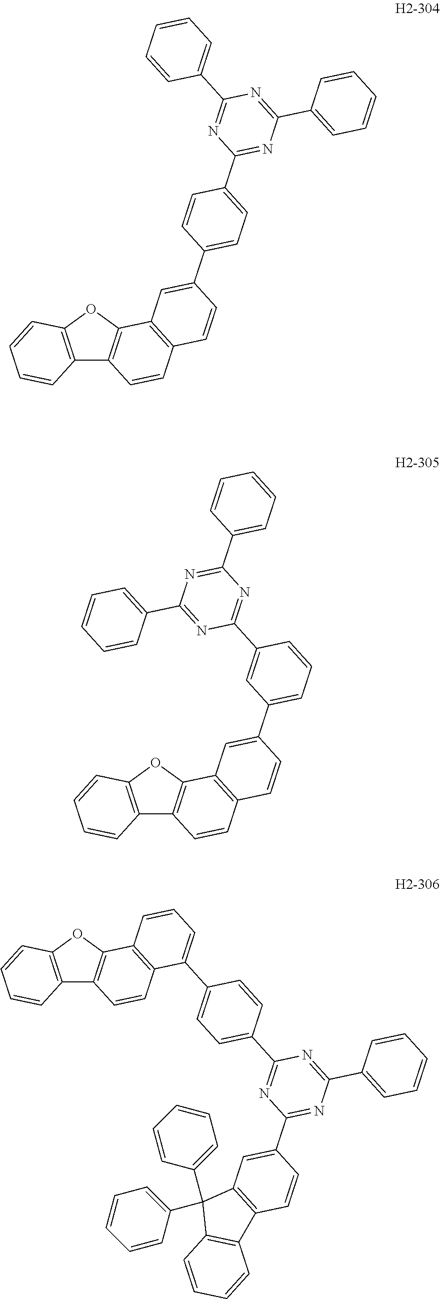 [SMILES: c1ccc(-c2nc(-c3ccccc3)nc(-c3ccc(-c4ccc5ccc6c7ccccc7oc6c5c4)cc3)n2)cc1 ; c1ccc(-c2nc(-c3ccccc3)nc(-c3cccc(-c4ccc5ccc6c7ccccc7oc6c5c4)c3)n2)cc1 ; c1ccc(-c2nc(-c3ccc(-c4cccc5c4ccc4c6ccccc6oc54)cc3)nc(-c3ccc4c(c3)C(c3ccccc3)(c3ccccc3)c3ccccc3-4)n2)cc1]

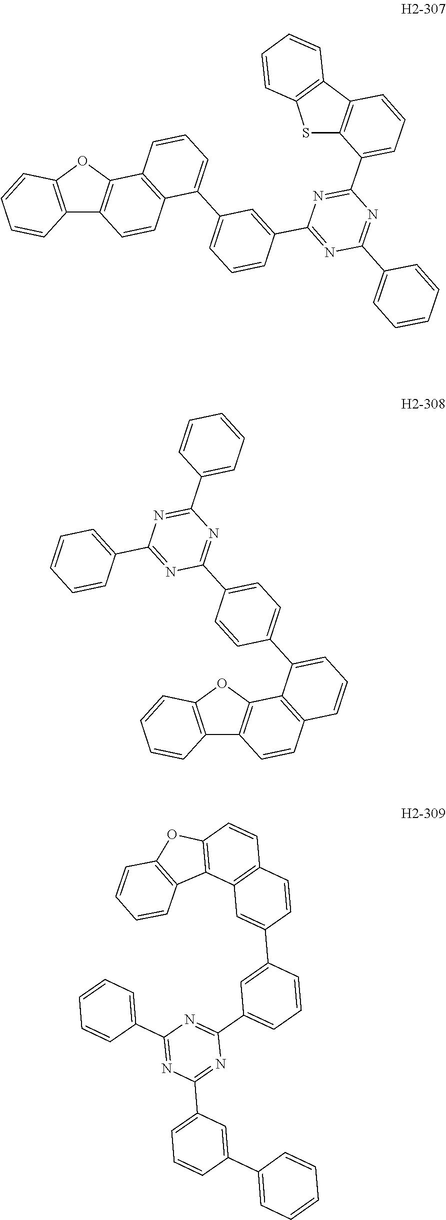 [SMILES: c1ccc(-c2nc(-c3cccc(-c4cccc5c4ccc4c6ccccc6oc54)c3)nc(-c3cccc4c3sc3ccccc34)n2)cc1 ; c1ccc(-c2nc(-c3ccccc3)nc(-c3ccc(-c4cccc5ccc6c7ccccc7oc6c45)cc3)n2)cc1 ; c1ccc(-c2cccc(-c3nc(-c4ccccc4)nc(-c4cccc(-c5ccc6ccc7oc8ccccc8c7c6c5)c4)n3)c2)cc1]

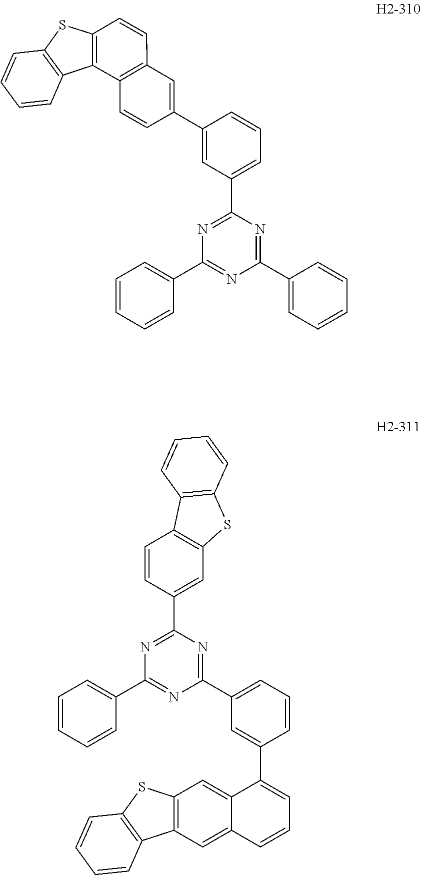 [SMILES: c1ccc(-c2nc(-c3ccccc3)nc(-c3cccc(-c4ccc5c(ccc6sc7ccccc7c65)c4)c3)n2)cc1 ; c1ccc(-c2nc(-c3cccc(-c4cccc5cc6c(cc45)sc4ccccc46)c3)nc(-c3ccc4c(c3)sc3ccccc34)n2)cc1]

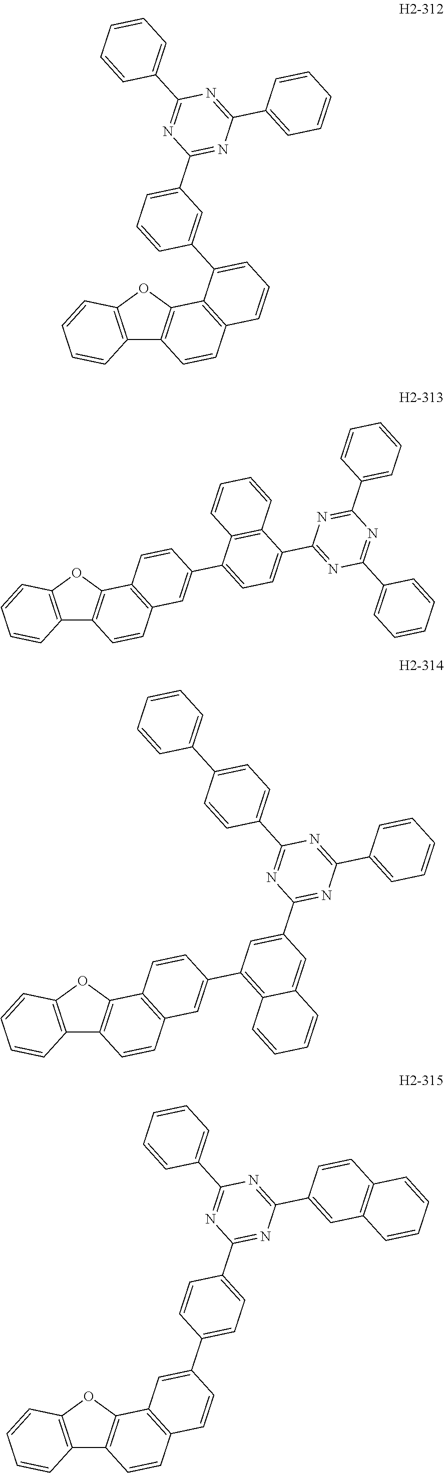 [SMILES: c1ccc(-c2nc(-c3ccccc3)nc(-c3cccc(-c4cccc5ccc6c7ccccc7oc6c45)c3)n2)cc1 ; c1ccc(-c2nc(-c3ccccc3)nc(-c3ccc(-c4ccc5c(ccc6c7ccccc7oc56)c4)c4ccccc34)n2)cc1 ; c1ccc(-c2ccc(-c3nc(-c4ccccc4)nc(-c4cc(-c5ccc6c(ccc7c8ccccc8oc67)c5)c5ccccc5c4)n3)cc2)cc1 ; c1ccc(-c2nc(-c3ccc(-c4ccc5ccc6c7ccccc7oc6c5c4)cc3)nc(-c3ccc4ccccc4c3)n2)cc1]

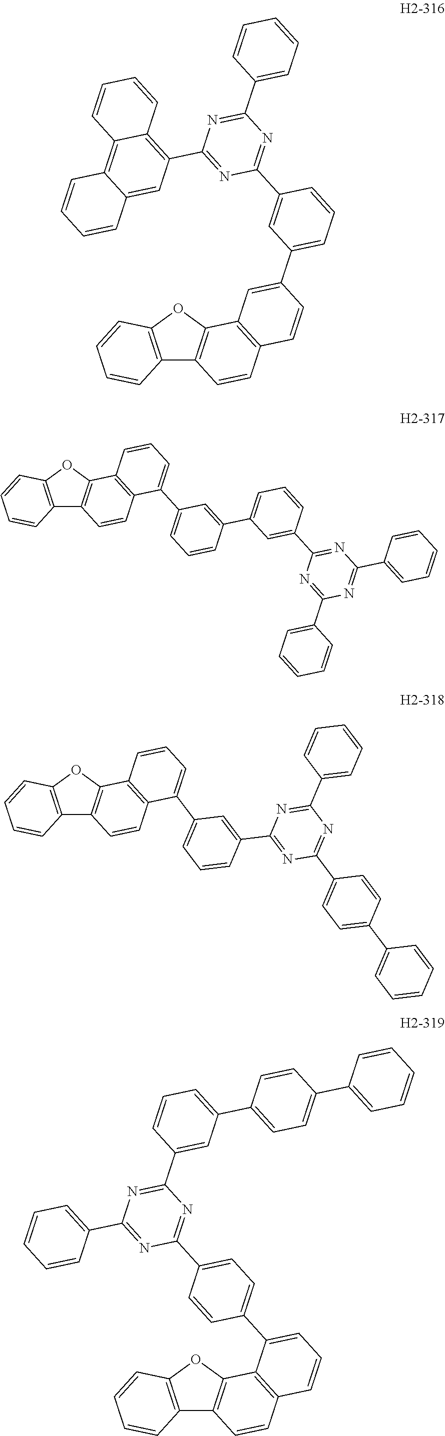 [SMILES: c1ccc(-c2nc(-c3cccc(-c4ccc5ccc6c7ccccc7oc6c5c4)c3)nc(-c3cc4ccccc4c4ccccc34)n2)cc1 ; c1ccc(-c2nc(-c3ccccc3)nc(-c3cccc(-c4cccc(-c5cccc6c5ccc5c7ccccc7oc65)c4)c3)n2)cc1 ; c1ccc(-c2ccc(-c3nc(-c4ccccc4)nc(-c4cccc(-c5cccc6c5ccc5c7ccccc7oc65)c4)n3)cc2)cc1 ; c1ccc(-c2ccc(-c3cccc(-c4nc(-c5ccccc5)nc(-c5ccc(-c6cccc7ccc8c9ccccc9oc8c67)cc5)n4)c3)cc2)cc1]

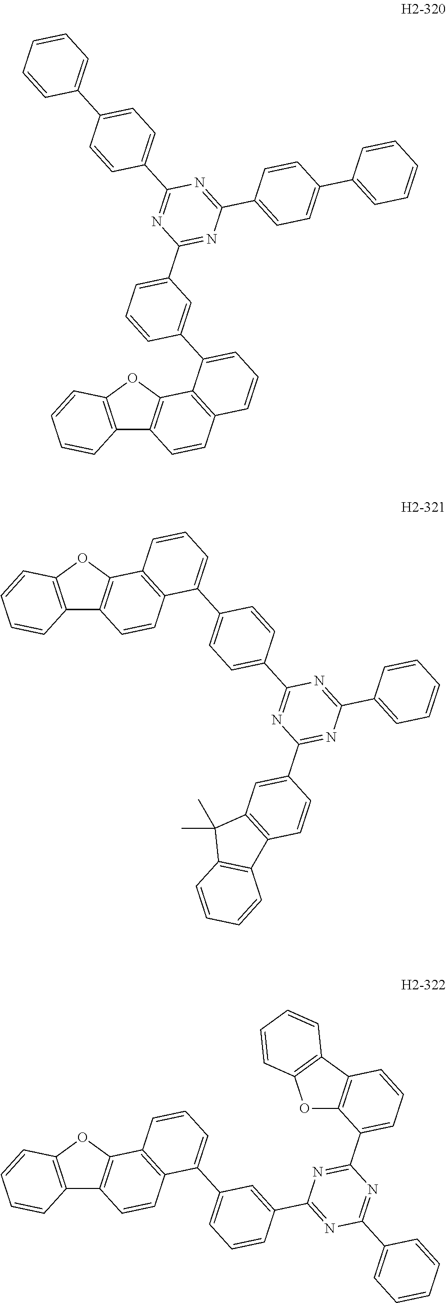 [SMILES: c1ccc(-c2ccc(-c3nc(-c4ccc(-c5ccccc5)cc4)nc(-c4cccc(-c5cccc6ccc7c8ccccc8oc7c56)c4)n3)cc2)cc1 ; CC1(C)c2ccccc2-c2ccc(-c3nc(-c4ccccc4)nc(-c4ccc(-c5cccc6c5ccc5c7ccccc7oc65)cc4)n3)cc21 ; c1ccc(-c2nc(-c3cccc(-c4cccc5c4ccc4c6ccccc6oc54)c3)nc(-c3cccc4c3oc3ccccc34)n2)cc1]

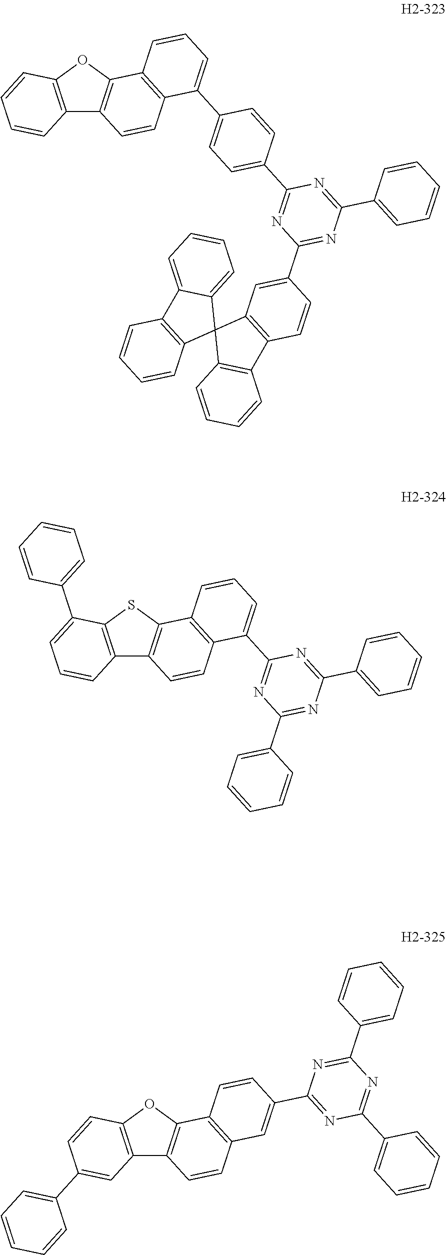 [SMILES: c1ccc(-c2nc(-c3ccc(-c4cccc5c4ccc4c6ccccc6oc54)cc3)nc(-c3ccc4c(c3)C3(c5ccccc5-c5ccccc53)c3ccccc3-4)n2)cc1 ; c1ccc(-c2nc(-c3ccccc3)nc(-c3cccc4c3ccc3c5cccc(-c6ccccc6)c5sc43)n2)cc1 ; c1ccc(-c2ccc3oc4c5ccc(-c6nc(-c7ccccc7)nc(-c7ccccc7)n6)cc5ccc4c3c2)cc1]

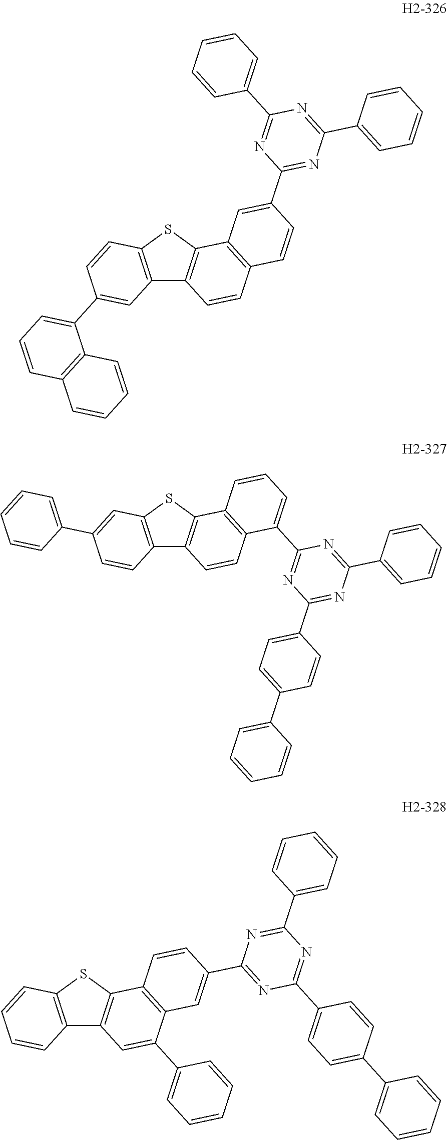 [SMILES: c1ccc(-c2nc(-c3ccccc3)nc(-c3ccc4ccc5c6cc(-c7cccc8ccccc78)ccc6sc5c4c3)n2)cc1 ; c1ccc(-c2ccc(-c3nc(-c4ccccc4)nc(-c4cccc5c4ccc4c6ccc(-c7ccccc7)cc6sc54)n3)cc2)cc1 ; c1ccc(-c2ccc(-c3nc(-c4ccccc4)nc(-c4ccc5c(c4)c(-c4ccccc4)cc4c6ccccc6sc54)n3)cc2)cc1]

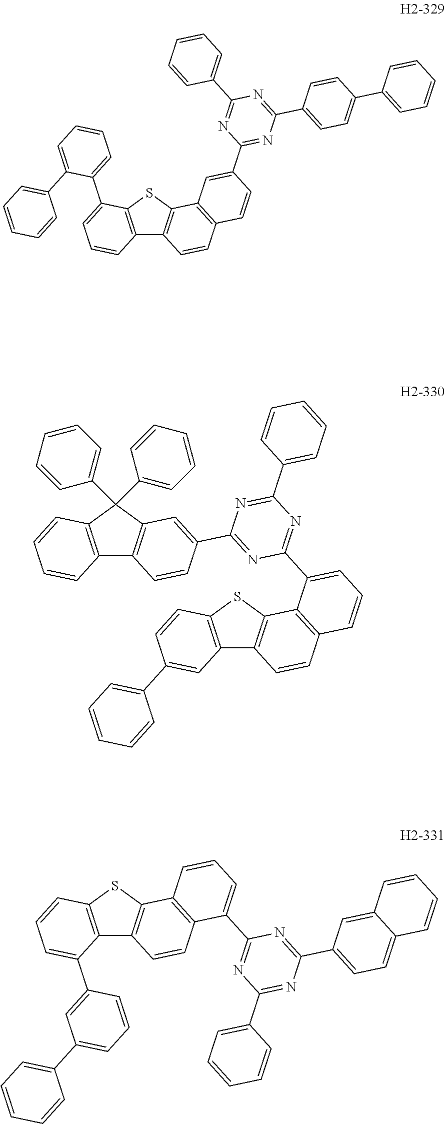 [SMILES: c1ccc(-c2ccc(-c3nc(-c4ccccc4)nc(-c4ccc5ccc6c7cccc(-c8ccccc8-c8ccccc8)c7sc6c5c4)n3)cc2)cc1 ; c1ccc(-c2ccc3sc4c(ccc5cccc(-c6nc(-c7ccccc7)nc(-c7ccc8c(c7)C(c7ccccc7)(c7ccccc7)c7ccccc7-8)n6)c54)c3c2)cc1 ; c1ccc(-c2cccc(-c3cccc4sc5c6cccc(-c7nc(-c8ccccc8)nc(-c8ccc9ccccc9c8)n7)c6ccc5c34)c2)cc1]

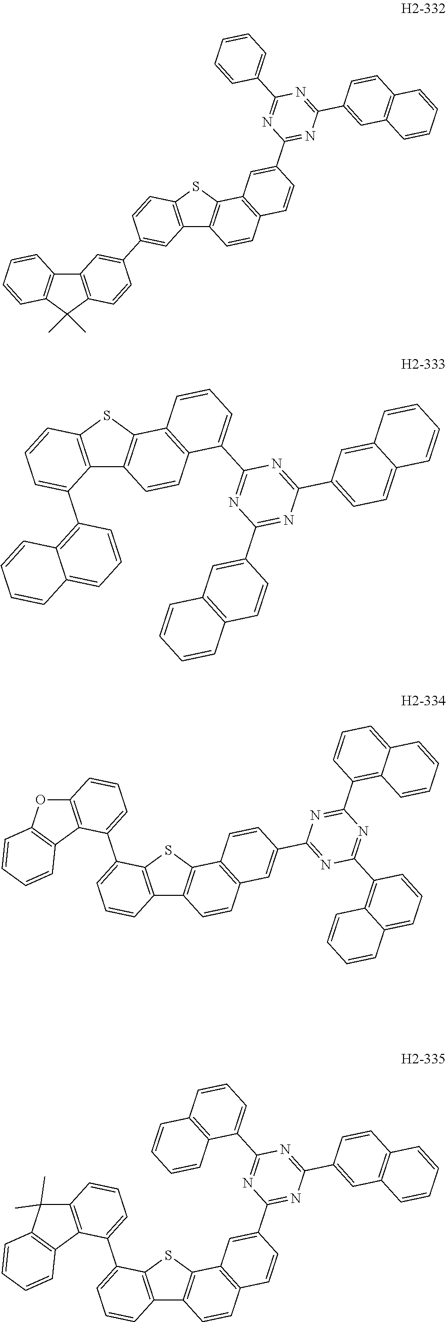 [SMILES: CC1(C)c2ccccc2-c2cc(-c3ccc4sc5c6cc(-c7nc(-c8ccccc8)nc(-c8ccc9ccccc9c8)n7)ccc6ccc5c4c3)ccc21 ; c1ccc2cc(-c3nc(-c4ccc5ccccc5c4)nc(-c4cccc5c4ccc4c5sc5cccc(-c6cccc7ccccc67)c54)n3)ccc2c1 ; c1ccc2c(-c3nc(-c4ccc5c(ccc6c7cccc(-c8cccc9oc%10ccccc%10c89)c7sc56)c4)nc(-c4cccc5ccccc45)n3)cccc2c1 ; CC1(C)c2ccccc2-c2c(-c3cccc4c3sc3c5cc(-c6nc(-c7ccc8ccccc8c7)nc(-c7cccc8ccccc78)n6)ccc5ccc43)cccc21]

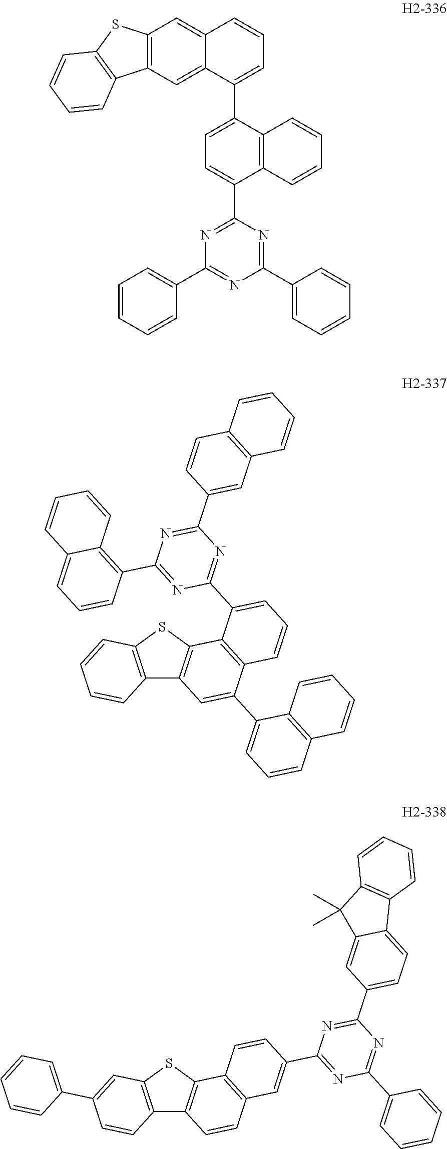 [SMILES: c1ccc(-c2nc(-c3ccccc3)nc(-c3ccc(-c4cccc5cc6sc7ccccc7c6cc45)c4ccccc34)n2)cc1 ; c1ccc2cc(-c3nc(-c4cccc5ccccc45)nc(-c4cccc5c(-c6cccc7ccccc67)cc6c7ccccc7sc6c45)n3)ccc2c1 ; CC1(C)c2ccccc2-c2ccc(-c3nc(-c4ccccc4)nc(-c4ccc5c(ccc6c7ccc(-c8ccccc8)cc7sc56)c4)n3)cc21]

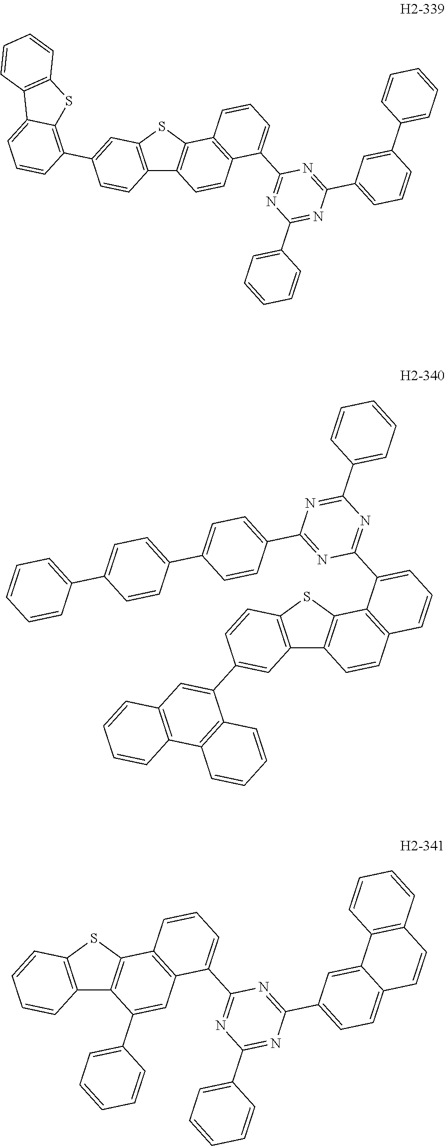 [SMILES: c1ccc(-c2cccc(-c3nc(-c4ccccc4)nc(-c4cccc5c4ccc4c6ccc(-c7cccc8c7sc7ccccc78)cc6sc54)n3)c2)cc1 ; c1ccc(-c2ccc(-c3ccc(-c4nc(-c5ccccc5)nc(-c5cccc6ccc7c8cc(-c9cc%10ccccc%10c%10ccccc9%10)ccc8sc7c56)n4)cc3)cc2)cc1 ; c1ccc(-c2nc(-c3ccc4ccc5ccccc5c4c3)nc(-c3cccc4c3cc(-c3ccccc3)c3c5ccccc5sc43)n2)cc1]

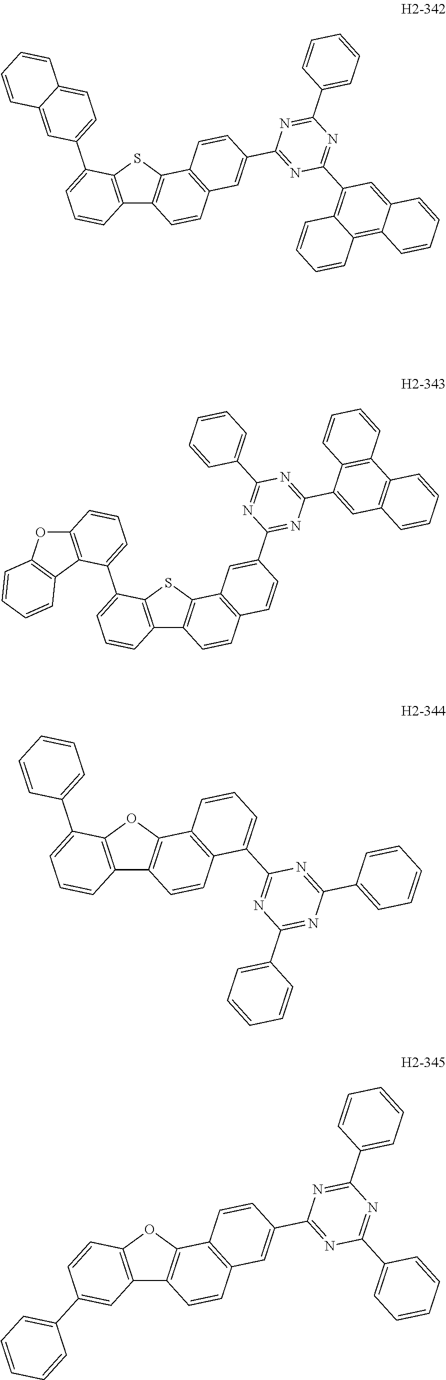 [SMILES: c1ccc(-c2nc(-c3ccc4c(ccc5c6cccc(-c7ccc8ccccc8c7)c6sc45)c3)nc(-c3cc4ccccc4c4ccccc34)n2)cc1 ; c1ccc(-c2nc(-c3ccc4ccc5c6cccc(-c7cccc8oc9ccccc9c78)c6sc5c4c3)nc(-c3cc4ccccc4c4ccccc34)n2)cc1 ; c1ccc(-c2nc(-c3ccccc3)nc(-c3cccc4c3ccc3c5cccc(-c6ccccc6)c5oc43)n2)cc1 ; c1ccc(-c2ccc3oc4c5ccc(-c6nc(-c7ccccc7)nc(-c7ccccc7)n6)cc5ccc4c3c2)cc1]

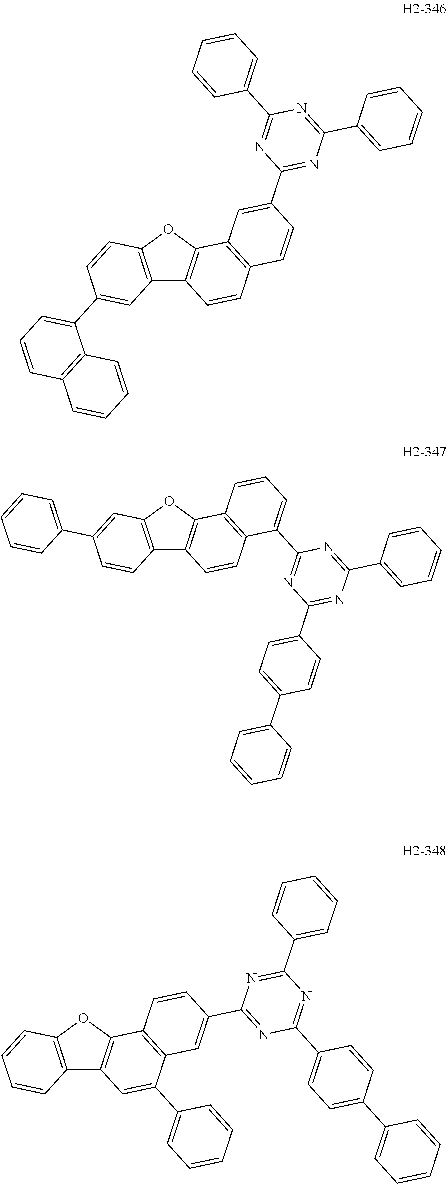 [SMILES: c1ccc(-c2nc(-c3ccccc3)nc(-c3ccc4ccc5c6cc(-c7cccc8ccccc78)ccc6oc5c4c3)n2)cc1 ; c1ccc(-c2ccc(-c3nc(-c4ccccc4)nc(-c4cccc5c4ccc4c6ccc(-c7ccccc7)cc6oc54)n3)cc2)cc1 ; c1ccc(-c2ccc(-c3nc(-c4ccccc4)nc(-c4ccc5c(c4)c(-c4ccccc4)cc4c6ccccc6oc54)n3)cc2)cc1]

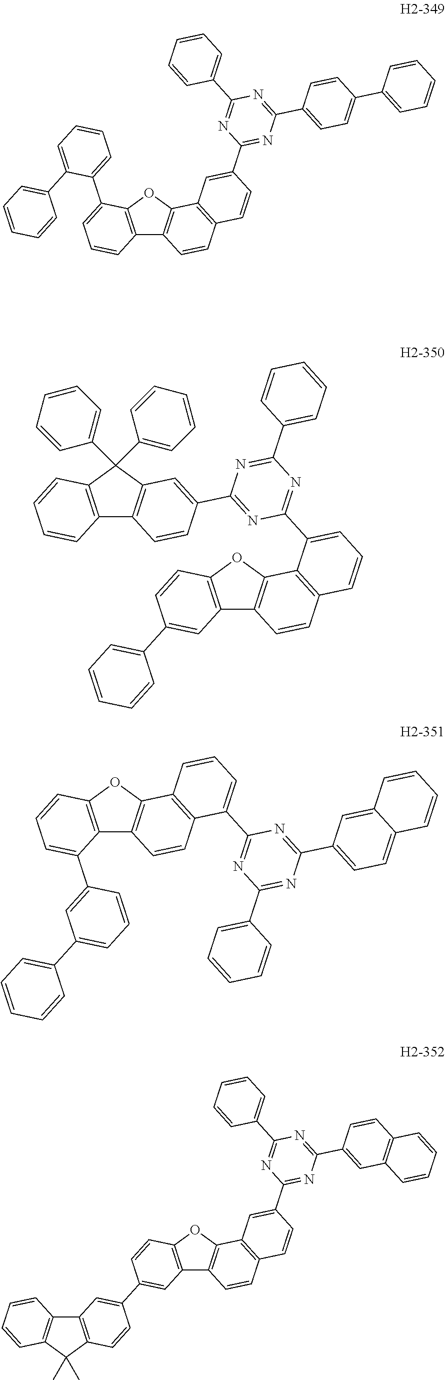 [SMILES: c1ccc(-c2ccc(-c3nc(-c4ccccc4)nc(-c4ccc5ccc6c7cccc(-c8ccccc8-c8ccccc8)c7oc6c5c4)n3)cc2)cc1 ; c1ccc(-c2ccc3oc4c(ccc5cccc(-c6nc(-c7ccccc7)nc(-c7ccc8c(c7)C(c7ccccc7)(c7ccccc7)c7ccccc7-8)n6)c54)c3c2)cc1 ; c1ccc(-c2cccc(-c3cccc4oc5c6cccc(-c7nc(-c8ccccc8)nc(-c8ccc9ccccc9c8)n7)c6ccc5c34)c2)cc1 ; CC1(C)c2ccccc2-c2cc(-c3ccc4oc5c6cc(-c7nc(-c8ccccc8)nc(-c8ccc9ccccc9c8)n7)ccc6ccc5c4c3)ccc21]

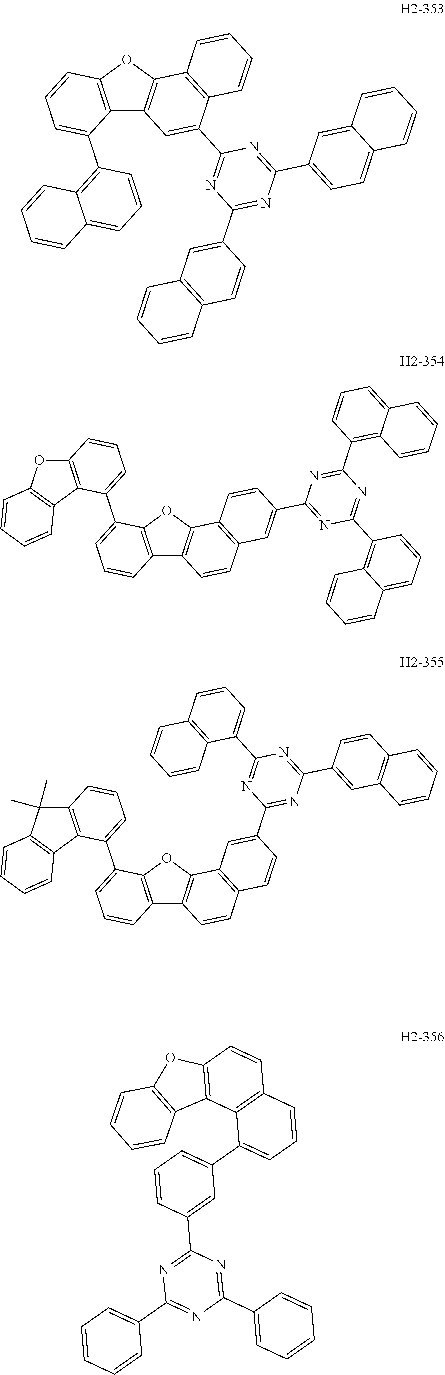 [SMILES: c1ccc2cc(-c3nc(-c4ccc5ccccc5c4)nc(-c4cc5c(oc6cccc(-c7cccc8ccccc78)c65)c5ccccc45)n3)ccc2c1 ; c1ccc2c(-c3nc(-c4ccc5c(ccc6c7cccc(-c8cccc9oc%10ccccc%10c89)c7oc56)c4)nc(-c4cccc5ccccc45)n3)cccc2c1 ; CC1(C)c2ccccc2-c2c(-c3cccc4c3oc3c5cc(-c6nc(-c7ccc8ccccc8c7)nc(-c7cccc8ccccc78)n6)ccc5ccc43)cccc21 ; c1ccc(-c2nc(-c3ccccc3)nc(-c3cccc(-c4cccc5ccc6oc7ccccc7c6c45)c3)n2)cc1]

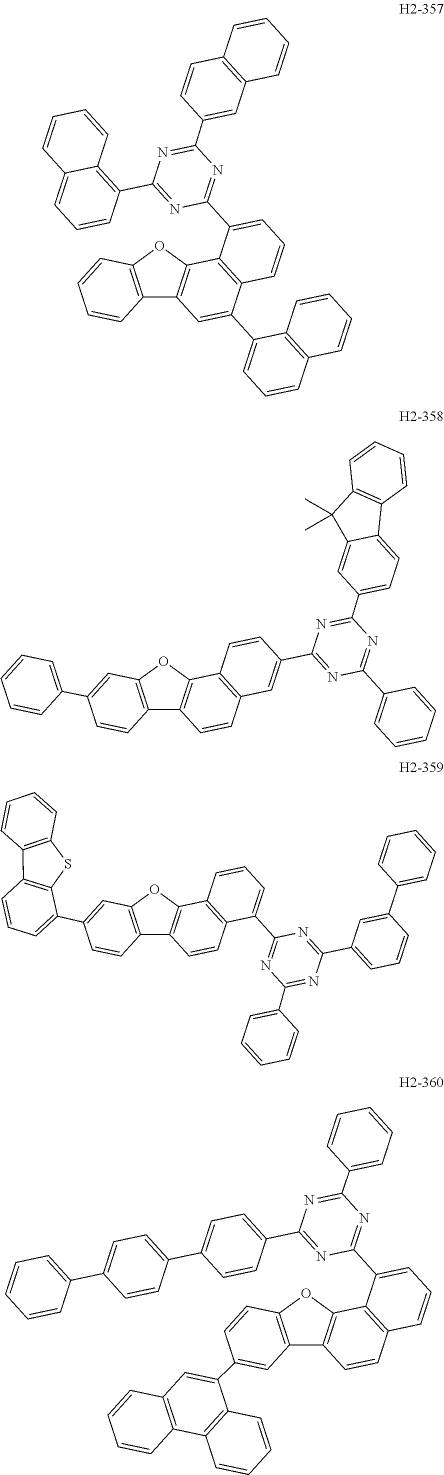 [SMILES: c1ccc2cc(-c3nc(-c4cccc5ccccc45)nc(-c4cccc5c(-c6cccc7ccccc67)cc6c7ccccc7oc6c45)n3)ccc2c1 ; CC1(C)c2ccccc2-c2ccc(-c3nc(-c4ccccc4)nc(-c4ccc5c(ccc6c7ccc(-c8ccccc8)cc7oc56)c4)n3)cc21 ; c1ccc(-c2cccc(-c3nc(-c4ccccc4)nc(-c4cccc5c4ccc4c6ccc(-c7cccc8c7sc7ccccc78)cc6oc54)n3)c2)cc1 ; c1ccc(-c2ccc(-c3ccc(-c4nc(-c5ccccc5)nc(-c5cccc6ccc7c8cc(-c9cc%10ccccc%10c%10ccccc9%10)ccc8oc7c56)n4)cc3)cc2)cc1]

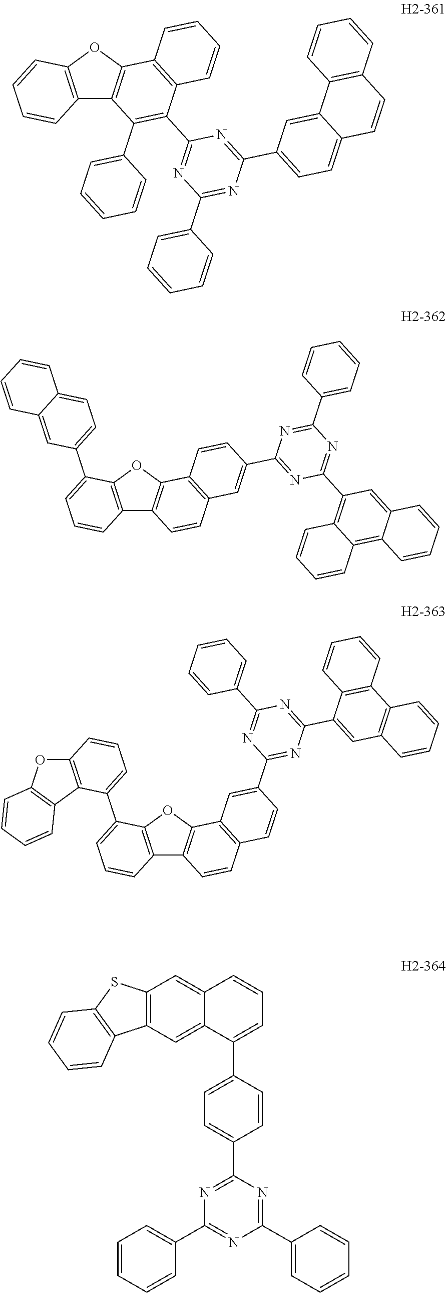 [SMILES: c1ccc(-c2nc(-c3ccc4ccc5ccccc5c4c3)nc(-c3c(-c4ccccc4)c4c5ccccc5oc4c4ccccc34)n2)cc1 ; c1ccc(-c2nc(-c3ccc4c(ccc5c6cccc(-c7ccc8ccccc8c7)c6oc45)c3)nc(-c3cc4ccccc4c4ccccc34)n2)cc1 ; c1ccc(-c2nc(-c3ccc4ccc5c6cccc(-c7cccc8oc9ccccc9c78)c6oc5c4c3)nc(-c3cc4ccccc4c4ccccc34)n2)cc1 ; c1ccc(-c2nc(-c3ccccc3)nc(-c3ccc(-c4cccc5cc6sc7ccccc7c6cc45)cc3)n2)cc1]

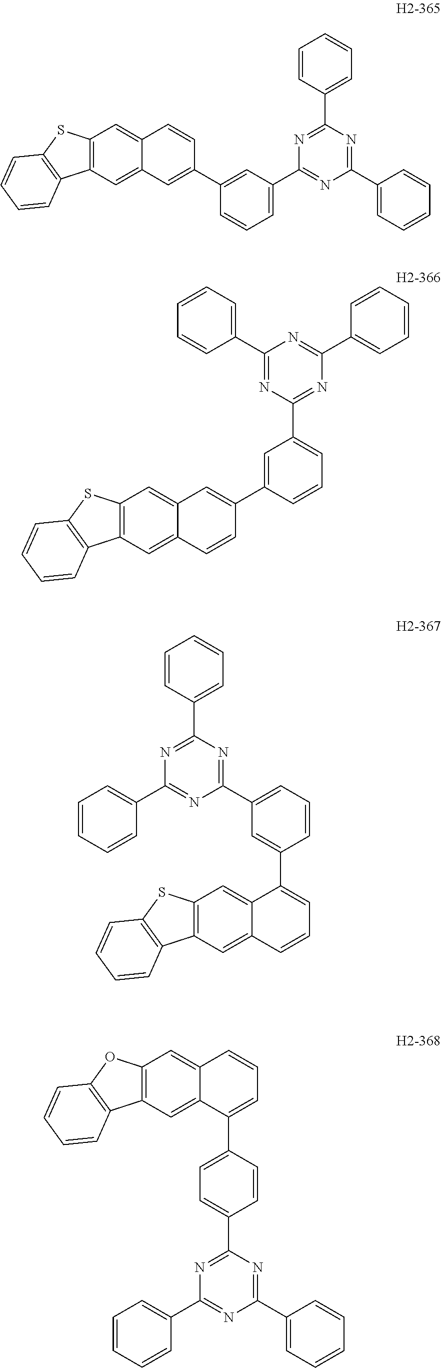 [SMILES: c1ccc(-c2nc(-c3ccccc3)nc(-c3cccc(-c4ccc5cc6sc7ccccc7c6cc5c4)c3)n2)cc1 ; c1ccc(-c2nc(-c3ccccc3)nc(-c3cccc(-c4ccc5cc6c(cc5c4)sc4ccccc46)c3)n2)cc1 ; c1ccc(-c2nc(-c3ccccc3)nc(-c3cccc(-c4cccc5cc6c(cc45)sc4ccccc46)c3)n2)cc1 ; c1ccc(-c2nc(-c3ccccc3)nc(-c3ccc(-c4cccc5cc6oc7ccccc7c6cc45)cc3)n2)cc1]

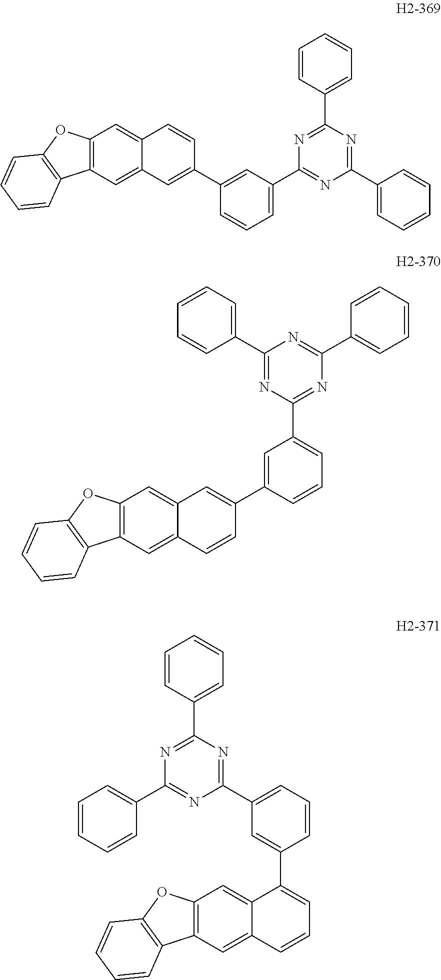 [SMILES: c1ccc(-c2nc(-c3ccccc3)nc(-c3cccc(-c4ccc5cc6oc7ccccc7c6cc5c4)c3)n2)cc1 ; c1ccc(-c2nc(-c3ccccc3)nc(-c3cccc(-c4ccc5cc6c(cc5c4)oc4ccccc46)c3)n2)cc1 ; c1ccc(-c2nc(-c3ccccc3)nc(-c3cccc(-c4cccc5cc6c(cc45)oc4ccccc46)c3)n2)cc1]

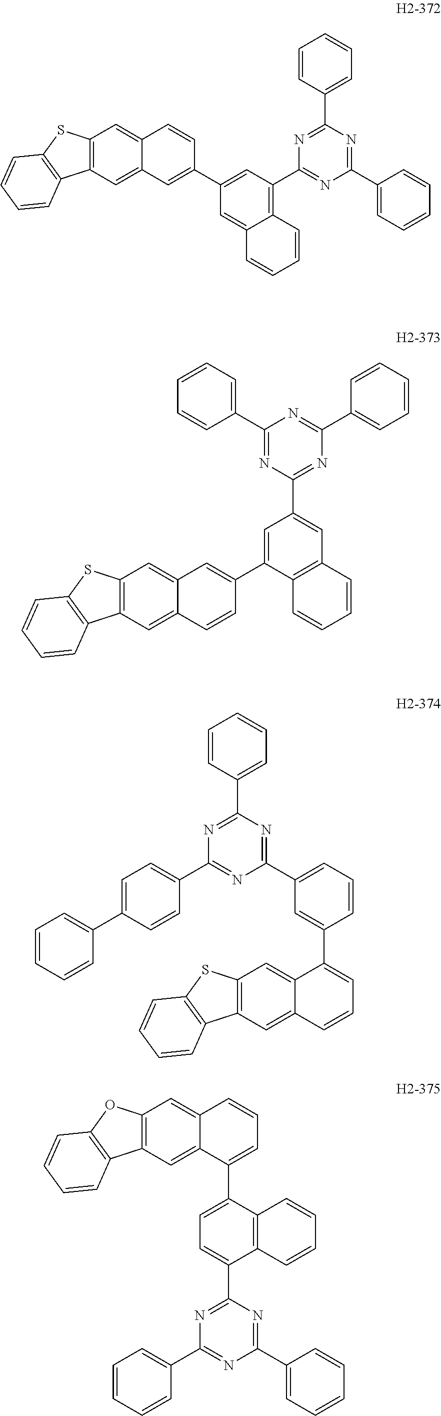

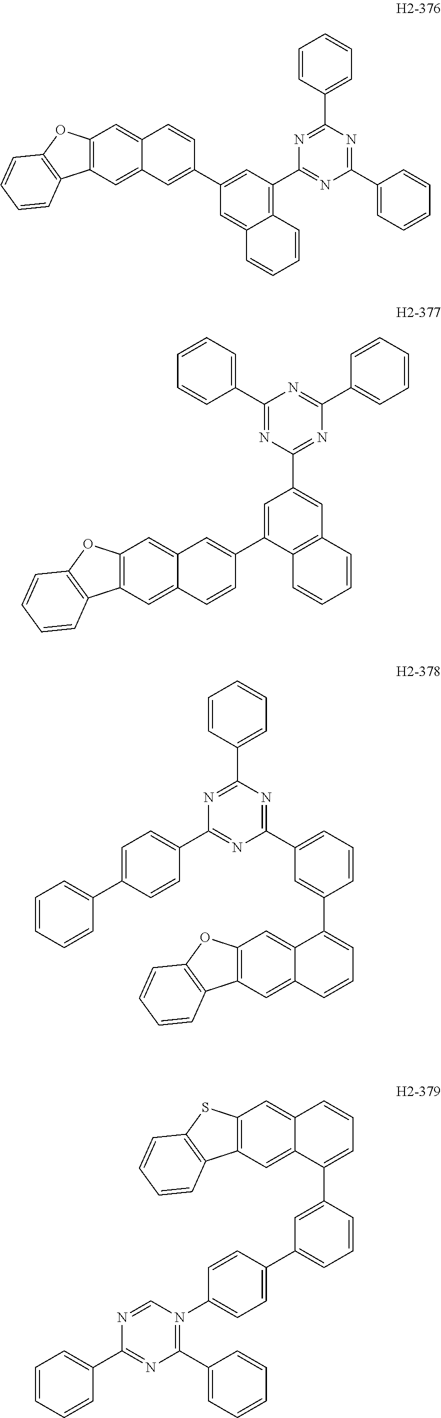

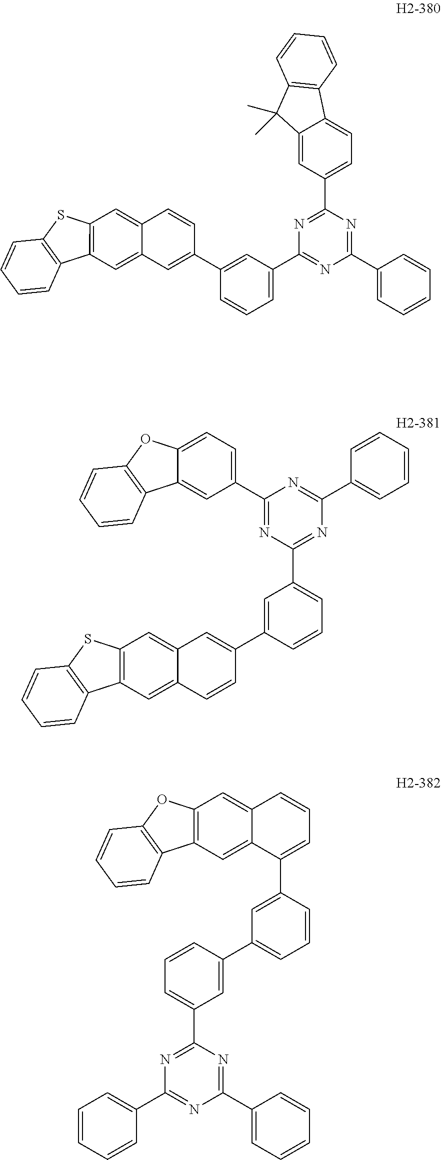 [SMILES: CC1(C)c2ccccc2-c2ccc(-c3nc(-c4ccccc4)nc(-c4cccc(-c5ccc6cc7sc8ccccc8c7cc6c5)c4)n3)cc21 ; c1ccc(-c2nc(-c3cccc(-c4ccc5cc6c(cc5c4)sc4ccccc46)c3)nc(-c3ccc4oc5ccccc5c4c3)n2)cc1 ; c1ccc(-c2nc(-c3ccccc3)nc(-c3cccc(-c4cccc(-c5cccc6cc7oc8ccccc8c7cc56)c4)c3)n2)cc1]

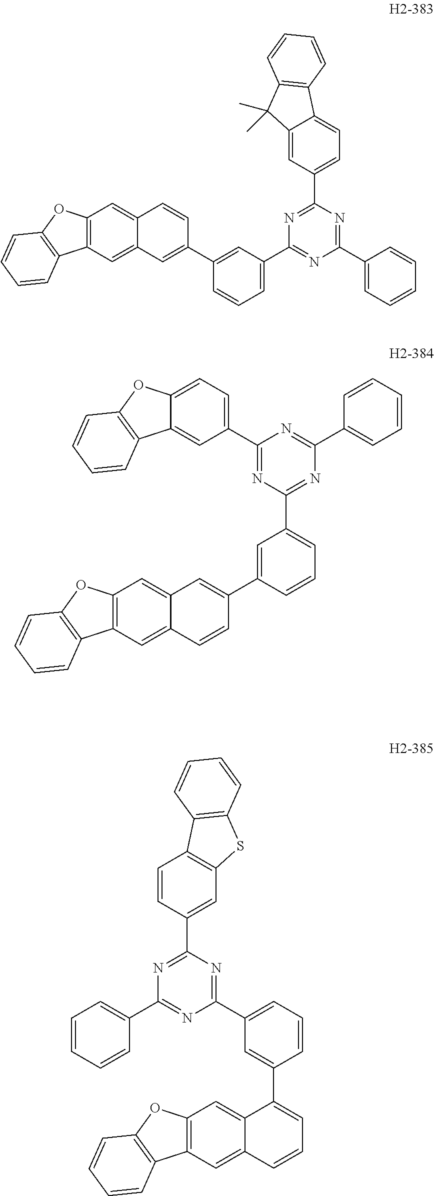 [SMILES: CC1(C)c2ccccc2-c2ccc(-c3nc(-c4ccccc4)nc(-c4cccc(-c5ccc6cc7oc8ccccc8c7cc6c5)c4)n3)cc21 ; c1ccc(-c2nc(-c3cccc(-c4ccc5cc6c(cc5c4)oc4ccccc46)c3)nc(-c3ccc4oc5ccccc5c4c3)n2)cc1 ; c1ccc(-c2nc(-c3cccc(-c4cccc5cc6c(cc45)oc4ccccc46)c3)nc(-c3ccc4c(c3)sc3ccccc34)n2)cc1]

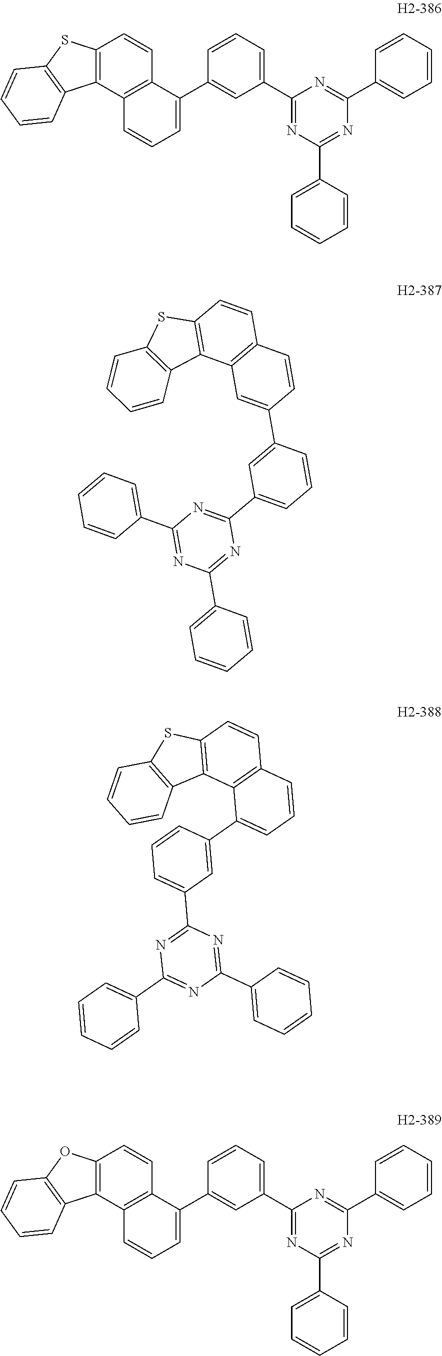 [SMILES: c1ccc(-c2nc(-c3ccccc3)nc(-c3cccc(-c4cccc5c4ccc4sc6ccccc6c45)c3)n2)cc1 ; c1ccc(-c2nc(-c3ccccc3)nc(-c3cccc(-c4ccc5ccc6sc7ccccc7c6c5c4)c3)n2)cc1 ; c1ccc(-c2nc(-c3ccccc3)nc(-c3cccc(-c4cccc5ccc6sc7ccccc7c6c45)c3)n2)cc1 ; c1ccc(-c2nc(-c3ccccc3)nc(-c3cccc(-c4cccc5c4ccc4oc6ccccc6c45)c3)n2)cc1]

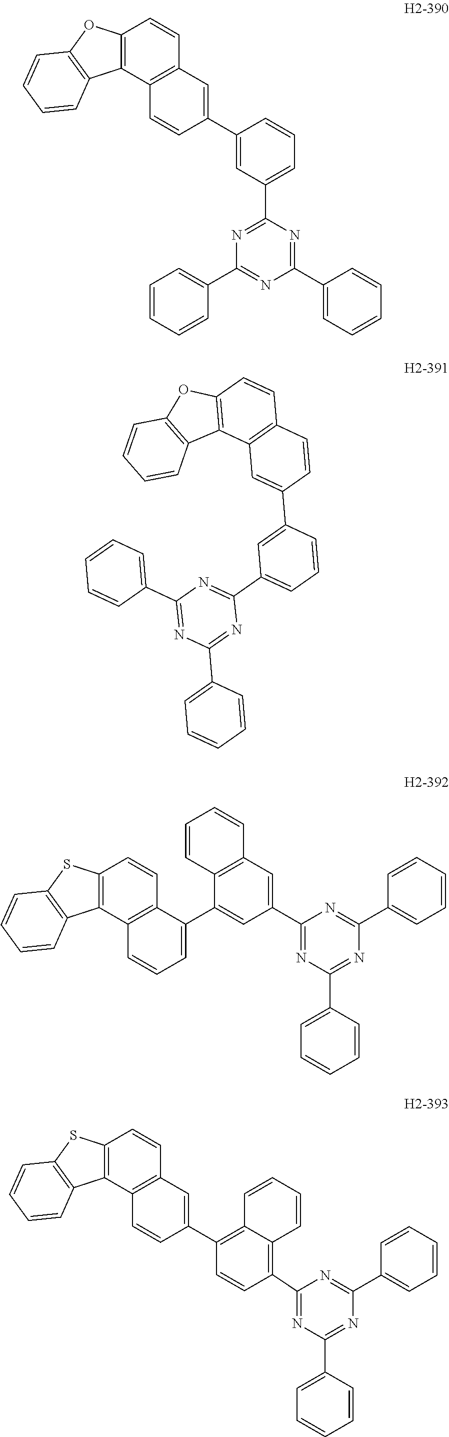 [SMILES: c1ccc(-c2nc(-c3ccccc3)nc(-c3cccc(-c4ccc5c(ccc6oc7ccccc7c65)c4)c3)n2)cc1 ; c1ccc(-c2nc(-c3ccccc3)nc(-c3cccc(-c4ccc5ccc6oc7ccccc7c6c5c4)c3)n2)cc1 ; c1ccc(-c2nc(-c3ccccc3)nc(-c3cc(-c4cccc5c4ccc4sc6ccccc6c45)c4ccccc4c3)n2)cc1 ; c1ccc(-c2nc(-c3ccccc3)nc(-c3ccc(-c4ccc5c(ccc6sc7ccccc7c65)c4)c4ccccc34)n2)cc1]

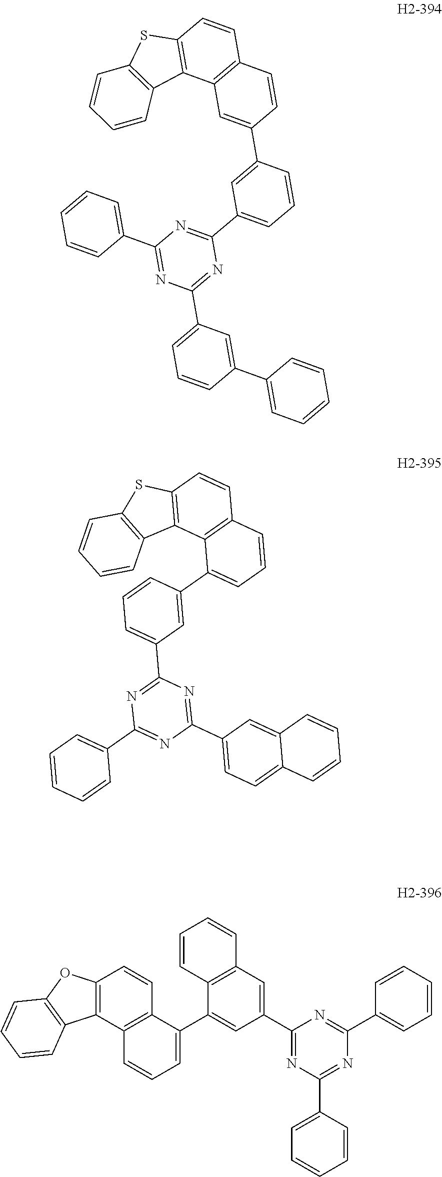 [SMILES: c1ccc(-c2cccc(-c3nc(-c4ccccc4)nc(-c4cccc(-c5ccc6ccc7sc8ccccc8c7c6c5)c4)n3)c2)cc1 ; c1ccc(-c2nc(-c3cccc(-c4cccc5ccc6sc7ccccc7c6c45)c3)nc(-c3ccc4ccccc4c3)n2)cc1 ; c1ccc(-c2nc(-c3ccccc3)nc(-c3cc(-c4cccc5c4ccc4oc6ccccc6c45)c4ccccc4c3)n2)cc1]

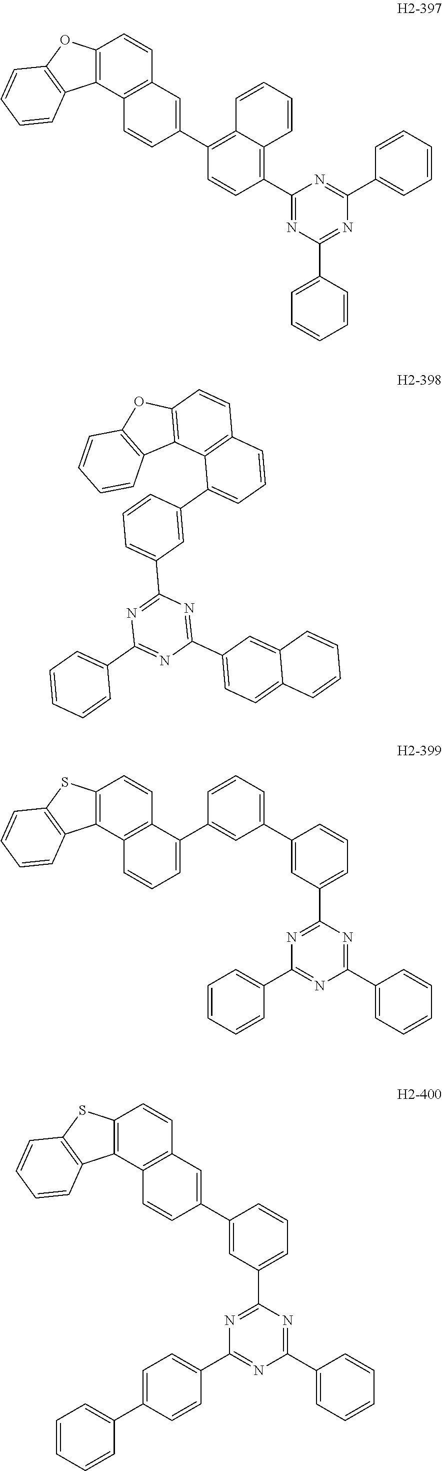 [SMILES: c1ccc(-c2nc(-c3ccccc3)nc(-c3ccc(-c4ccc5c(ccc6oc7ccccc7c65)c4)c4ccccc34)n2)cc1 ; c1ccc(-c2nc(-c3cccc(-c4cccc5ccc6oc7ccccc7c6c45)c3)nc(-c3ccc4ccccc4c3)n2)cc1 ; c1ccc(-c2nc(-c3ccccc3)nc(-c3cccc(-c4cccc(-c5cccc6c5ccc5sc7ccccc7c56)c4)c3)n2)cc1 ; c1ccc(-c2ccc(-c3nc(-c4ccccc4)nc(-c4cccc(-c5ccc6c(ccc7sc8ccccc8c76)c5)c4)n3)cc2)cc1]

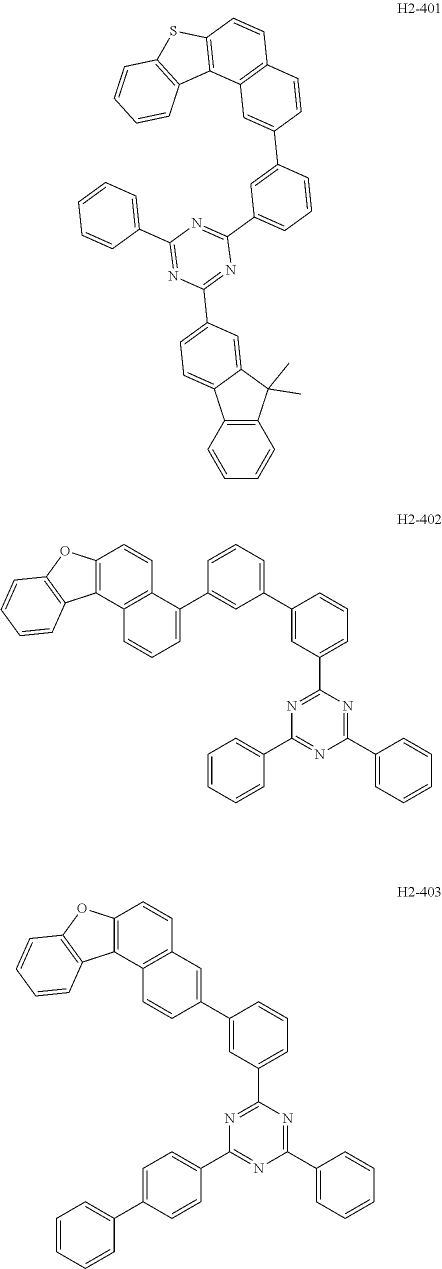 [SMILES: CC1(C)c2ccccc2-c2ccc(-c3nc(-c4ccccc4)nc(-c4cccc(-c5ccc6ccc7sc8ccccc8c7c6c5)c4)n3)cc21 ; c1ccc(-c2nc(-c3ccccc3)nc(-c3cccc(-c4cccc(-c5cccc6c5ccc5oc7ccccc7c56)c4)c3)n2)cc1 ; c1ccc(-c2ccc(-c3nc(-c4ccccc4)nc(-c4cccc(-c5ccc6c(ccc7oc8ccccc8c76)c5)c4)n3)cc2)cc1]

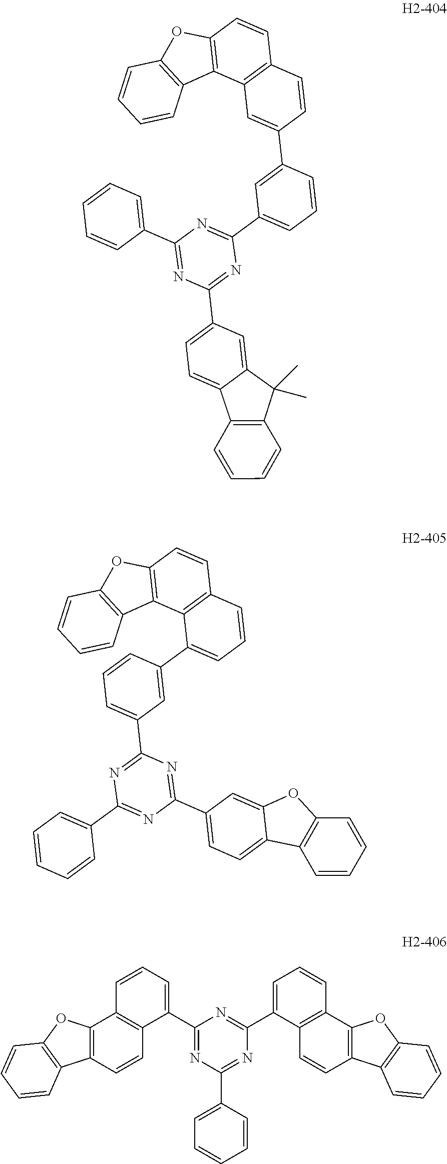 [SMILES: CC1(C)c2ccccc2-c2ccc(-c3nc(-c4ccccc4)nc(-c4cccc(-c5ccc6ccc7oc8ccccc8c7c6c5)c4)n3)cc21 ; c1ccc(-c2nc(-c3cccc(-c4cccc5ccc6oc7ccccc7c6c45)c3)nc(-c3ccc4c(c3)oc3ccccc34)n2)cc1 ; c1ccc(-c2nc(-c3cccc4c3ccc3c5ccccc5oc43)nc(-c3cccc4c3ccc3c5ccccc5oc43)n2)cc1]

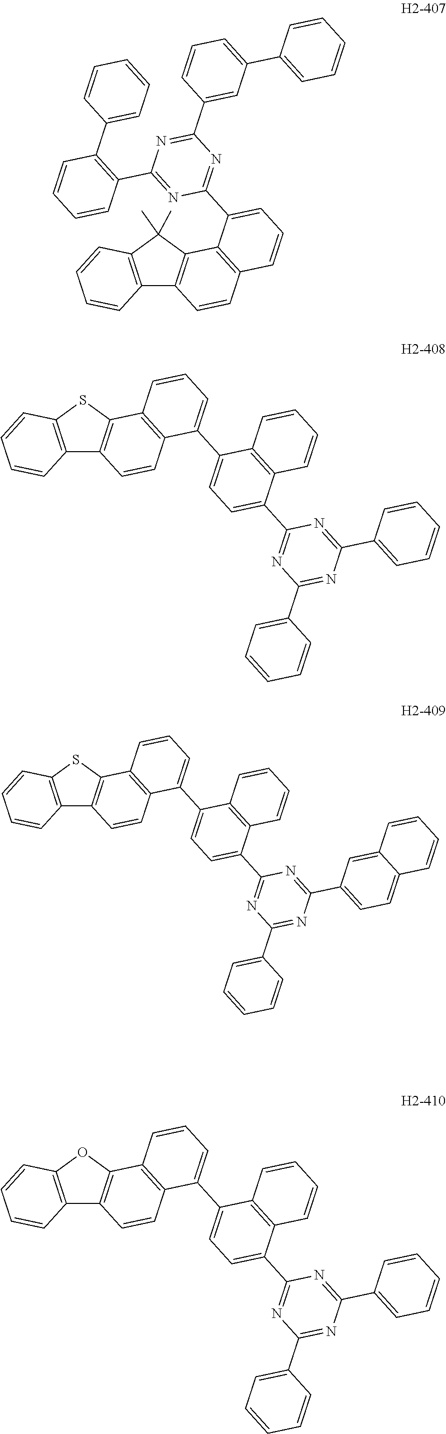 [SMILES: CC1(C)c2ccccc2-c2ccc3cccc(-c4nc(-c5cccc(-c6ccccc6)c5)nc(-c5ccccc5-c5ccccc5)n4)c3c21 ; c1ccc(-c2nc(-c3ccccc3)nc(-c3ccc(-c4cccc5c4ccc4c6ccccc6sc54)c4ccccc34)n2)cc1 ; c1ccc(-c2nc(-c3ccc4ccccc4c3)nc(-c3ccc(-c4cccc5c4ccc4c6ccccc6sc54)c4ccccc34)n2)cc1 ; c1ccc(-c2nc(-c3ccccc3)nc(-c3ccc(-c4cccc5c4ccc4c6ccccc6oc54)c4ccccc34)n2)cc1]

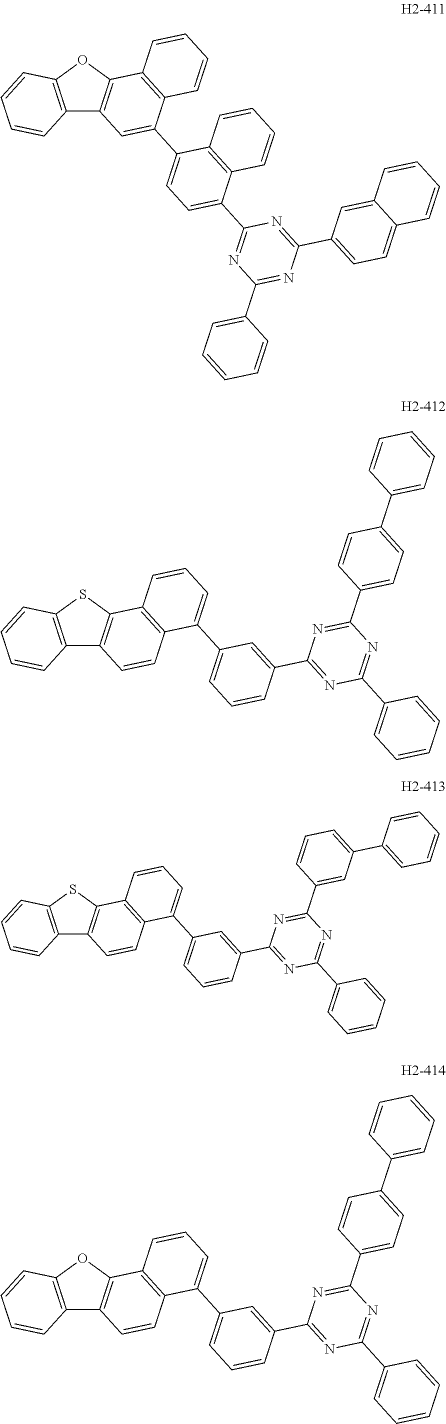 [SMILES: c1ccc(-c2nc(-c3ccc4ccccc4c3)nc(-c3ccc(-c4cc5c6ccccc6oc5c5ccccc45)c4ccccc34)n2)cc1 ; c1ccc(-c2ccc(-c3nc(-c4ccccc4)nc(-c4cccc(-c5cccc6c5ccc5c7ccccc7sc65)c4)n3)cc2)cc1 ; c1ccc(-c2cccc(-c3nc(-c4ccccc4)nc(-c4cccc(-c5cccc6c5ccc5c7ccccc7sc65)c4)n3)c2)cc1 ; c1ccc(-c2ccc(-c3nc(-c4ccccc4)nc(-c4cccc(-c5cccc6c5ccc5c7ccccc7oc65)c4)n3)cc2)cc1]

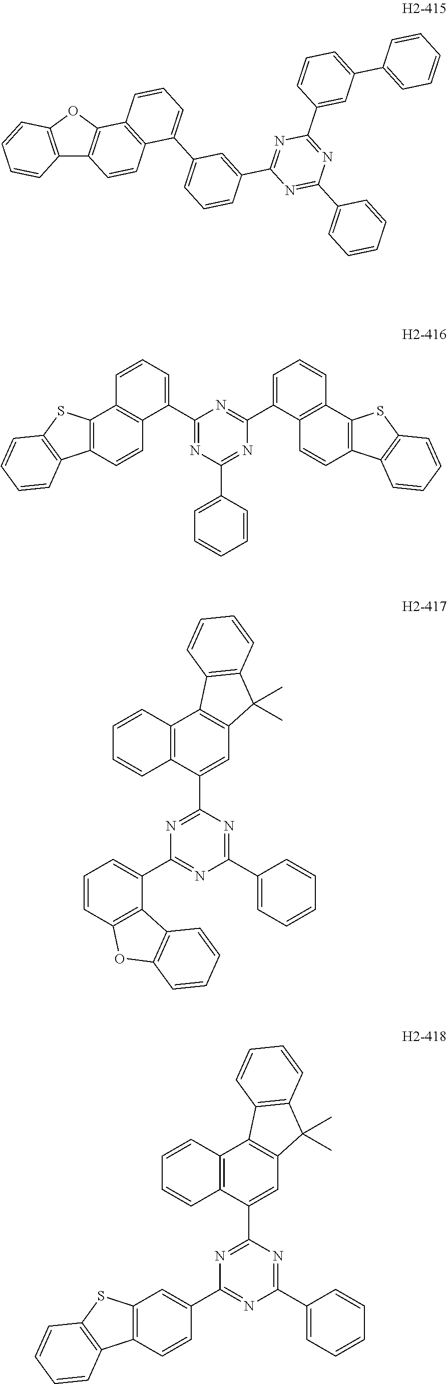 [SMILES: c1ccc(-c2cccc(-c3nc(-c4ccccc4)nc(-c4cccc(-c5cccc6c5ccc5c7ccccc7oc65)c4)n3)c2)cc1 ; c1ccc(-c2nc(-c3cccc4c3ccc3c5ccccc5sc43)nc(-c3cccc4c3ccc3c5ccccc5sc43)n2)cc1 ; CC1(C)c2ccccc2-c2c1cc(-c1nc(-c3ccccc3)nc(-c3cccc4oc5ccccc5c34)n1)c1ccccc21 ; CC1(C)c2ccccc2-c2c1cc(-c1nc(-c3ccccc3)nc(-c3ccc4c(c3)sc3ccccc34)n1)c1ccccc21]

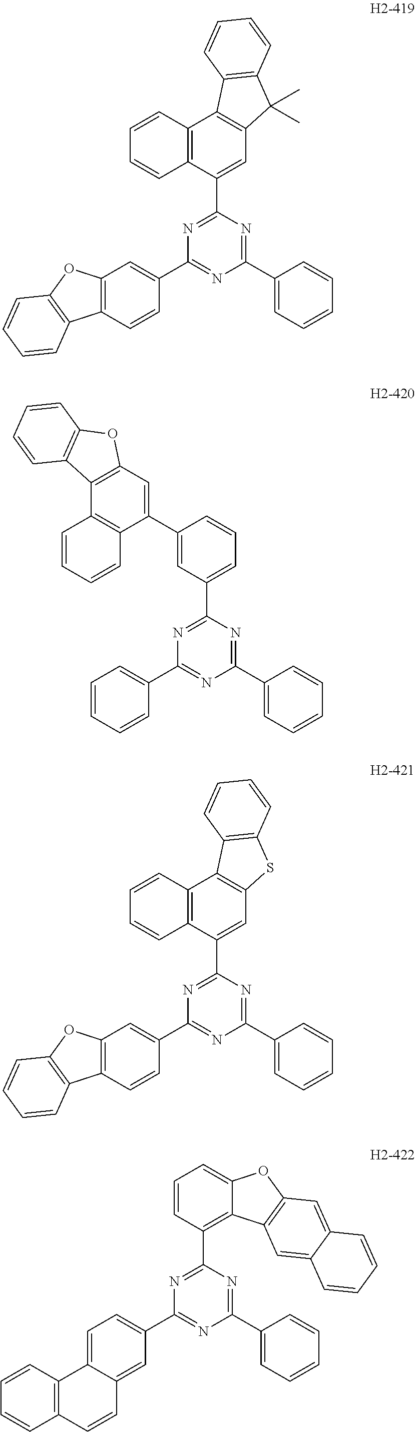 [SMILES: CC1(C)c2ccccc2-c2c1cc(-c1nc(-c3ccccc3)nc(-c3ccc4c(c3)oc3ccccc34)n1)c1ccccc21 ; c1ccc(-c2nc(-c3ccccc3)nc(-c3cccc(-c4cc5oc6ccccc6c5c5ccccc45)c3)n2)cc1 ; c1ccc(-c2nc(-c3ccc4c(c3)oc3ccccc34)nc(-c3cc4sc5ccccc5c4c4ccccc34)n2)cc1 ; c1ccc(-c2nc(-c3ccc4c(ccc5ccccc54)c3)nc(-c3cccc4oc5cc6ccccc6cc5c34)n2)cc1]

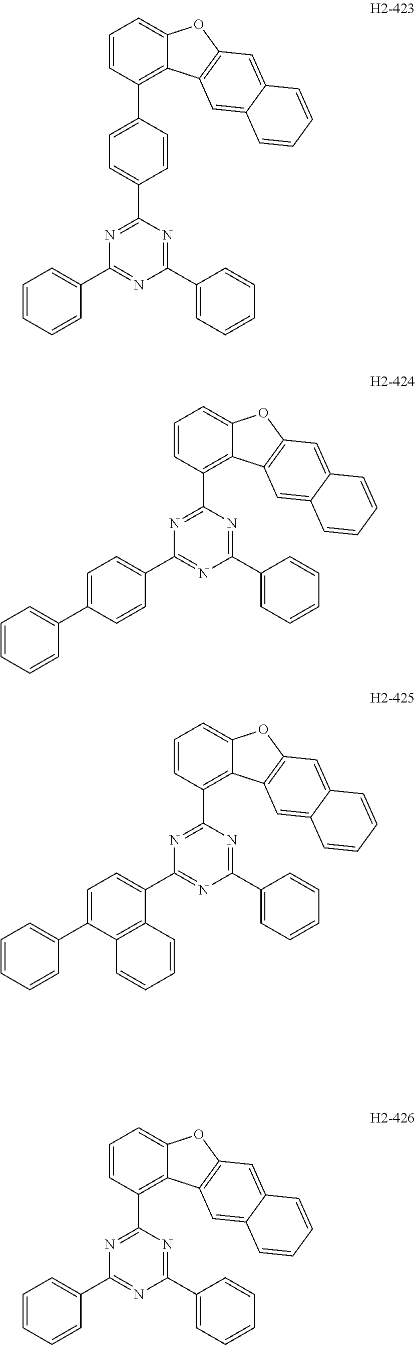 [SMILES: c1ccc(-c2nc(-c3ccccc3)nc(-c3ccc(-c4cccc5oc6cc7ccccc7cc6c45)cc3)n2)cc1 ; c1ccc(-c2ccc(-c3nc(-c4ccccc4)nc(-c4cccc5oc6cc7ccccc7cc6c45)n3)cc2)cc1 ; c1ccc(-c2nc(-c3ccc(-c4ccccc4)c4ccccc34)nc(-c3cccc4oc5cc6ccccc6cc5c34)n2)cc1 ; c1ccc(-c2nc(-c3ccccc3)nc(-c3cccc4oc5cc6ccccc6cc5c34)n2)cc1]

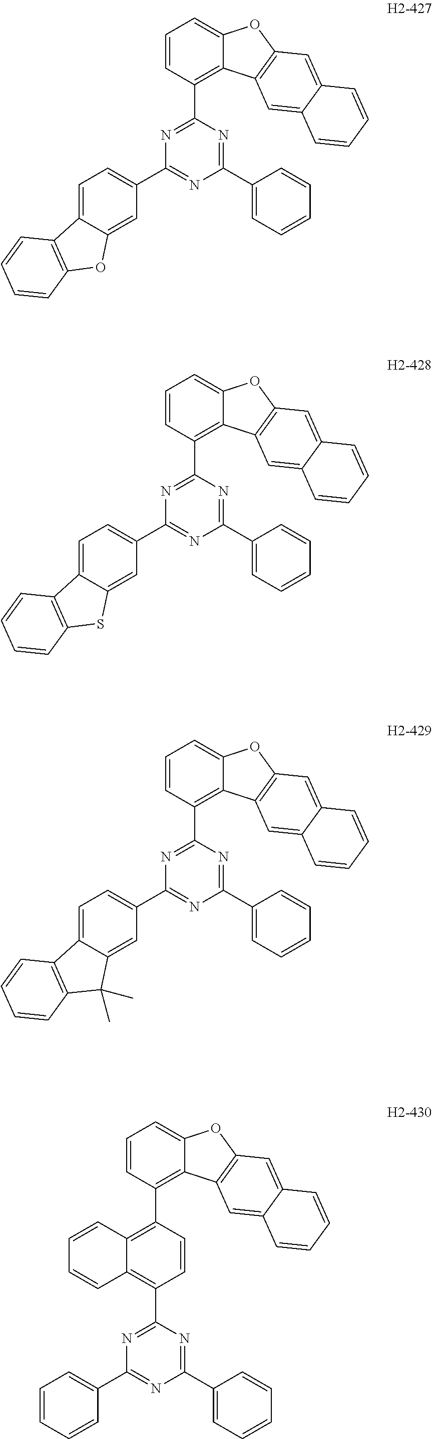 [SMILES: c1ccc(-c2nc(-c3ccc4c(c3)oc3ccccc34)nc(-c3cccc4oc5cc6ccccc6cc5c34)n2)cc1 ; c1ccc(-c2nc(-c3ccc4c(c3)sc3ccccc34)nc(-c3cccc4oc5cc6ccccc6cc5c34)n2)cc1 ; CC1(C)c2ccccc2-c2ccc(-c3nc(-c4ccccc4)nc(-c4cccc5oc6cc7ccccc7cc6c45)n3)cc21 ; c1ccc(-c2nc(-c3ccccc3)nc(-c3ccc(-c4cccc5oc6cc7ccccc7cc6c45)c4ccccc34)n2)cc1]

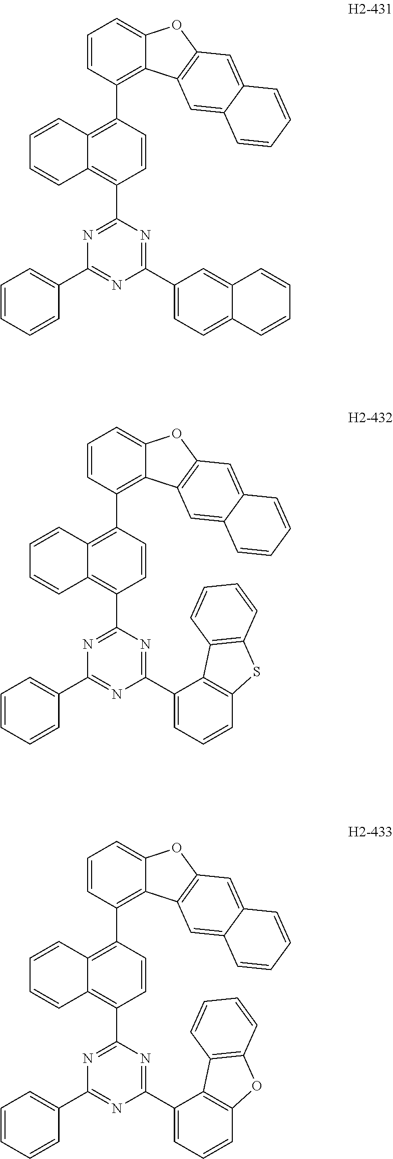 [SMILES: c1ccc(-c2nc(-c3ccc4ccccc4c3)nc(-c3ccc(-c4cccc5oc6cc7ccccc7cc6c45)c4ccccc34)n2)cc1 ; c1ccc(-c2nc(-c3ccc(-c4cccc5oc6cc7ccccc7cc6c45)c4ccccc34)nc(-c3cccc4sc5ccccc5c34)n2)cc1 ; c1ccc(-c2nc(-c3ccc(-c4cccc5oc6cc7ccccc7cc6c45)c4ccccc34)nc(-c3cccc4oc5ccccc5c34)n2)cc1]

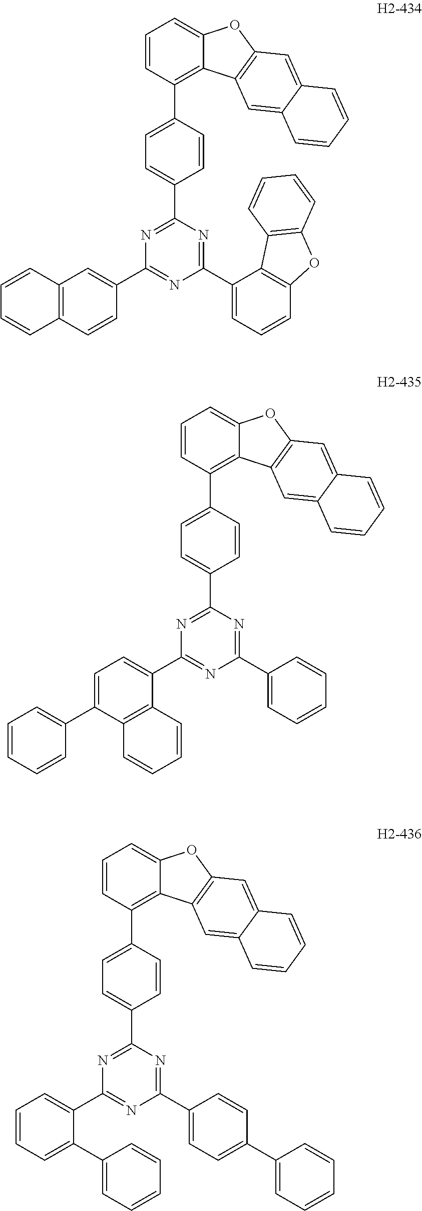 [SMILES: c1ccc2cc(-c3nc(-c4ccc(-c5cccc6oc7cc8ccccc8cc7c56)cc4)nc(-c4cccc5oc6ccccc6c45)n3)ccc2c1 ; c1ccc(-c2nc(-c3ccc(-c4cccc5oc6cc7ccccc7cc6c45)cc3)nc(-c3ccc(-c4ccccc4)c4ccccc34)n2)cc1 ; c1ccc(-c2ccc(-c3nc(-c4ccc(-c5cccc6oc7cc8ccccc8cc7c56)cc4)nc(-c4ccccc4-c4ccccc4)n3)cc2)cc1]

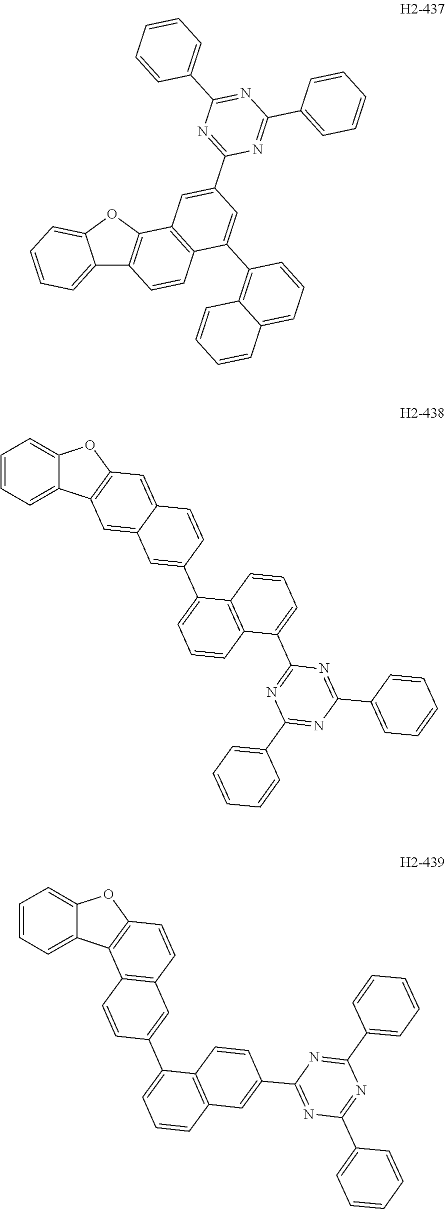 [SMILES: c1ccc(-c2nc(-c3ccccc3)nc(-c3cc(-c4cccc5ccccc45)c4ccc5c6ccccc6oc5c4c3)n2)cc1 ; c1ccc(-c2nc(-c3ccccc3)nc(-c3cccc4c(-c5ccc6cc7oc8ccccc8c7cc6c5)cccc34)n2)cc1 ; c1ccc(-c2nc(-c3ccccc3)nc(-c3ccc4c(-c5ccc6c(ccc7oc8ccccc8c76)c5)cccc4c3)n2)cc1]

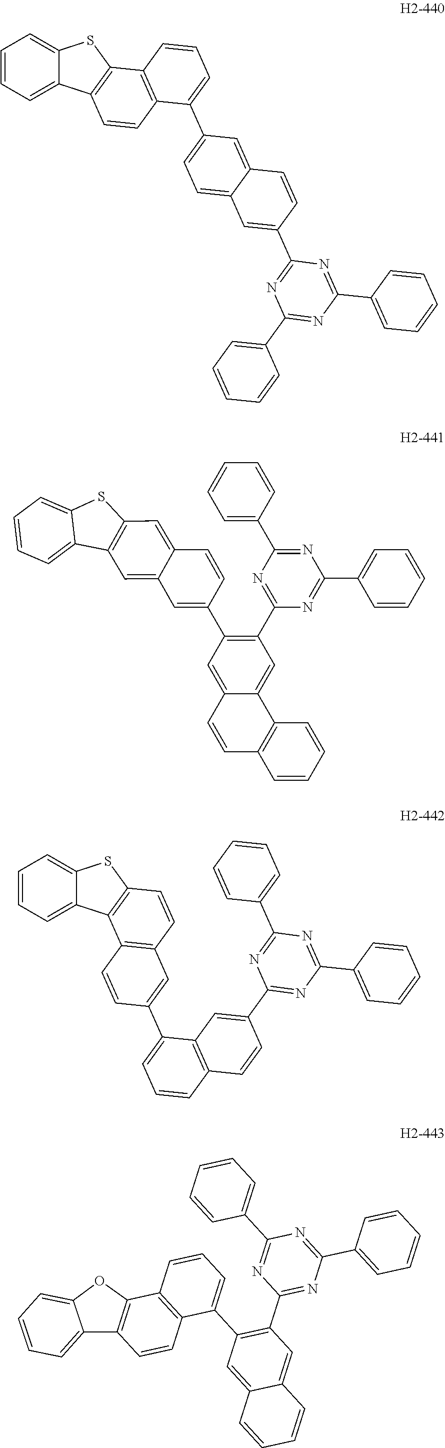 [SMILES: c1ccc(-c2nc(-c3ccccc3)nc(-c3ccc4cc(-c5cccc6c5ccc5c7ccccc7sc65)ccc4c3)n2)cc1 ; c1ccc(-c2nc(-c3ccccc3)nc(-c3cc4c(ccc5ccccc54)cc3-c3ccc4cc5sc6ccccc6c5cc4c3)n2)cc1 ; c1ccc(-c2nc(-c3ccccc3)nc(-c3ccc4cccc(-c5ccc6c(ccc7sc8ccccc8c76)c5)c4c3)n2)cc1 ; c1ccc(-c2nc(-c3ccccc3)nc(-c3cc4ccccc4cc3-c3cccc4c3ccc3c5ccccc5oc43)n2)cc1]

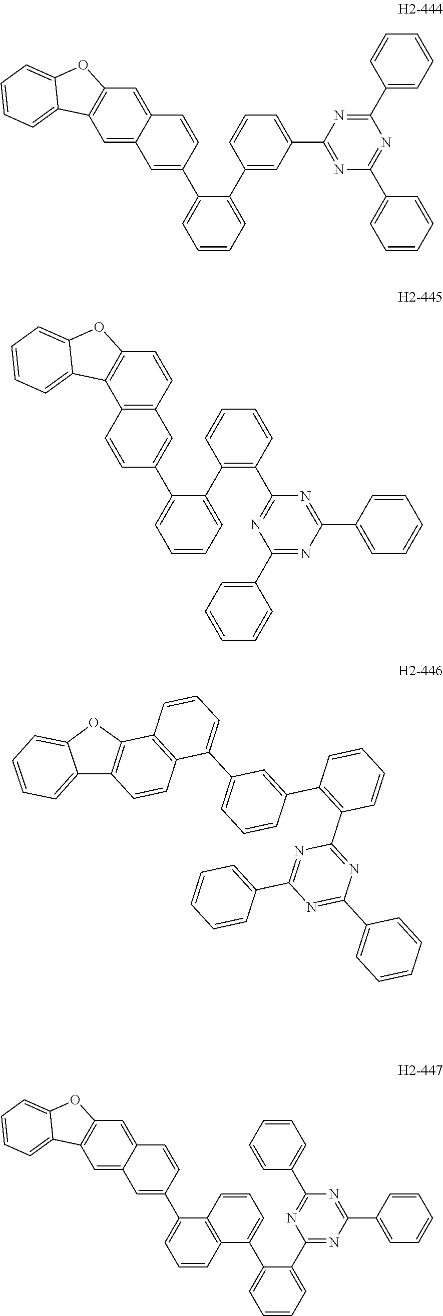 [SMILES: c1ccc(-c2nc(-c3ccccc3)nc(-c3cccc(-c4ccccc4-c4ccc5cc6oc7ccccc7c6cc5c4)c3)n2)cc1 ; c1ccc(-c2nc(-c3ccccc3)nc(-c3ccccc3-c3ccccc3-c3ccc4c(ccc5oc6ccccc6c54)c3)n2)cc1 ; c1ccc(-c2nc(-c3ccccc3)nc(-c3ccccc3-c3cccc(-c4cccc5c4ccc4c6ccccc6oc54)c3)n2)cc1 ; c1ccc(-c2nc(-c3ccccc3)nc(-c3ccccc3-c3cccc4c(-c5ccc6cc7oc8ccccc8c7cc6c5)cccc34)n2)cc1]

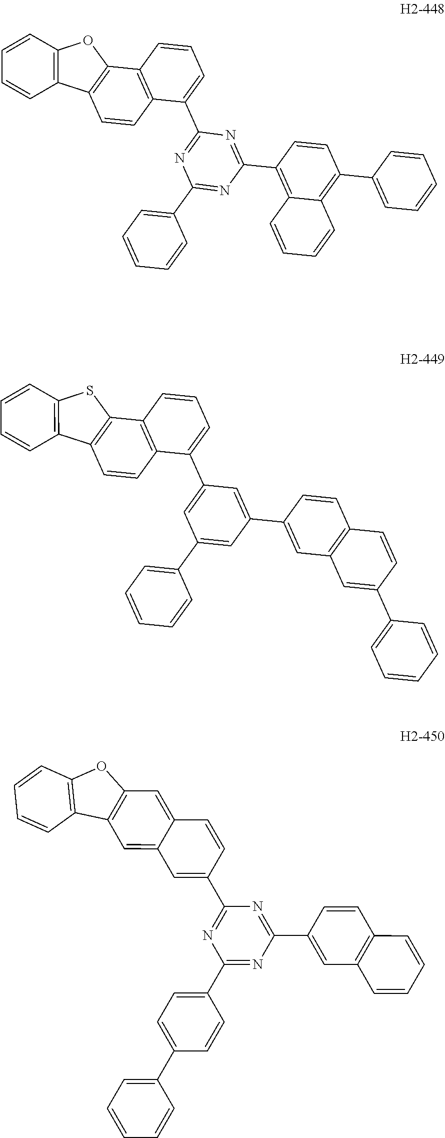 [SMILES: c1ccc(-c2nc(-c3ccc(-c4ccccc4)c4ccccc34)nc(-c3cccc4c3ccc3c5ccccc5oc43)n2)cc1 ; c1ccc(-c2cc(-c3ccc4ccc(-c5ccccc5)cc4c3)cc(-c3cccc4c3ccc3c5ccccc5sc43)c2)cc1 ; c1ccc(-c2ccc(-c3nc(-c4ccc5ccccc5c4)nc(-c4ccc5cc6oc7ccccc7c6cc5c4)n3)cc2)cc1]

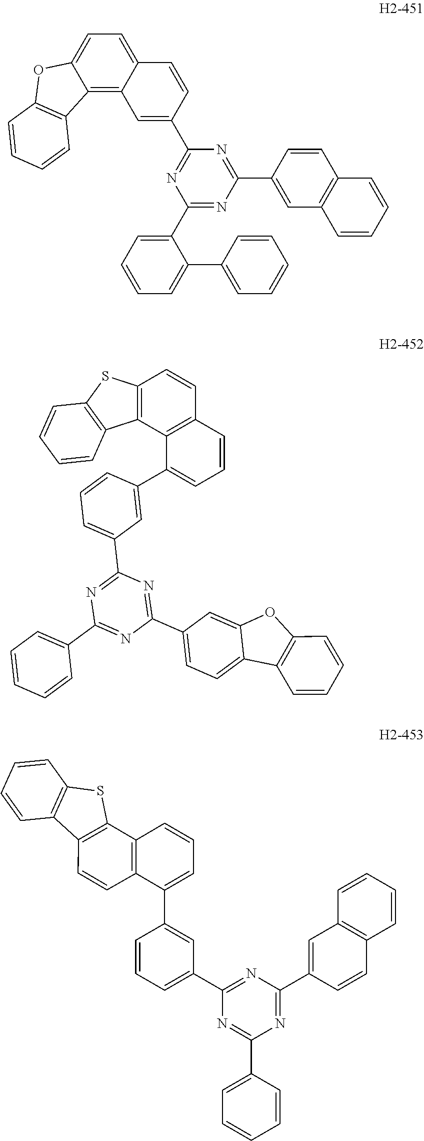 [SMILES: c1ccc(-c2ccccc2-c2nc(-c3ccc4ccccc4c3)nc(-c3ccc4ccc5oc6ccccc6c5c4c3)n2)cc1 ; c1ccc(-c2nc(-c3cccc(-c4cccc5ccc6sc7ccccc7c6c45)c3)nc(-c3ccc4c(c3)oc3ccccc34)n2)cc1 ; c1ccc(-c2nc(-c3cccc(-c4cccc5c4ccc4c6ccccc6sc54)c3)nc(-c3ccc4ccccc4c3)n2)cc1]

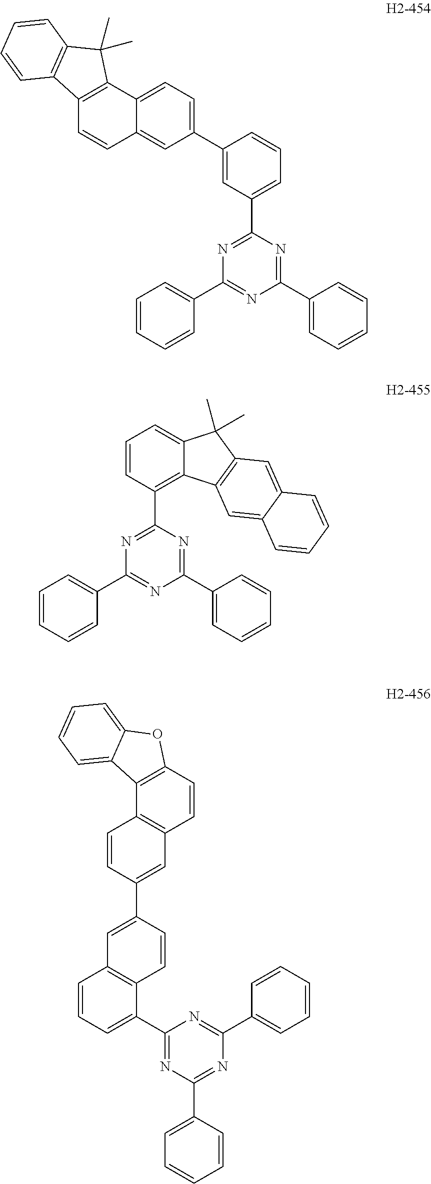 [SMILES: CC1(C)c2ccccc2-c2ccc3cc(-c4cccc(-c5nc(-c6ccccc6)nc(-c6ccccc6)n5)c4)ccc3c21 ; CC1(C)c2cc3ccccc3cc2-c2c(-c3nc(-c4ccccc4)nc(-c4ccccc4)n3)cccc21 ; c1ccc(-c2nc(-c3ccccc3)nc(-c3cccc4cc(-c5ccc6c(ccc7oc8ccccc8c76)c5)ccc34)n2)cc1]

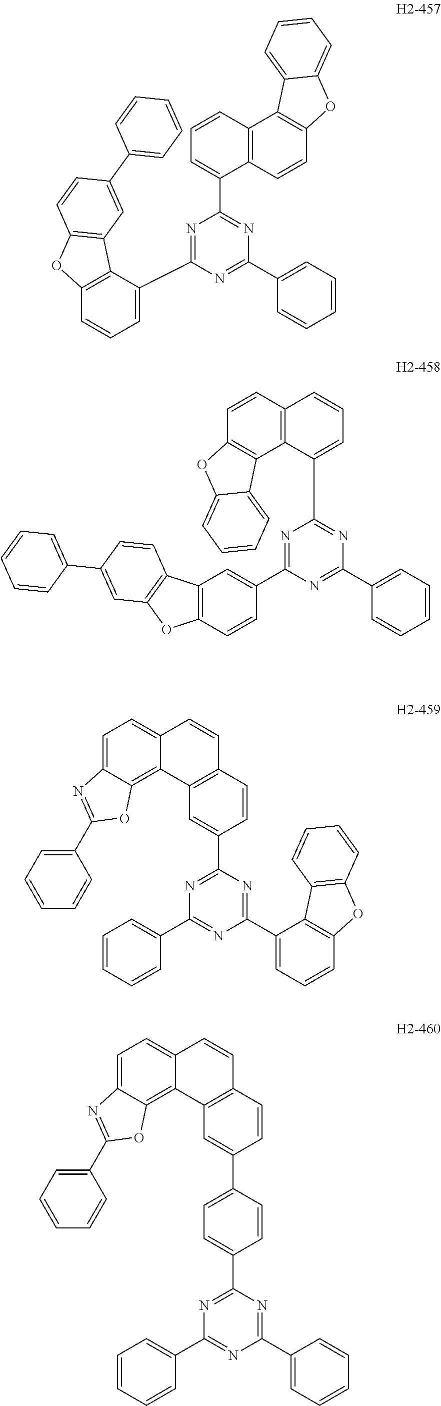 [SMILES: c1ccc(-c2ccc3oc4cccc(-c5nc(-c6ccccc6)nc(-c6cccc7c6ccc6oc8ccccc8c67)n5)c4c3c2)cc1 ; c1ccc(-c2ccc3c(c2)oc2ccc(-c4nc(-c5ccccc5)nc(-c5cccc6ccc7oc8ccccc8c7c56)n4)cc23)cc1 ; c1ccc(-c2nc(-c3ccc4ccc5ccc6nc(-c7ccccc7)oc6c5c4c3)nc(-c3cccc4oc5ccccc5c34)n2)cc1 ; c1ccc(-c2nc(-c3ccccc3)nc(-c3ccc(-c4ccc5ccc6ccc7nc(-c8ccccc8)oc7c6c5c4)cc3)n2)cc1]

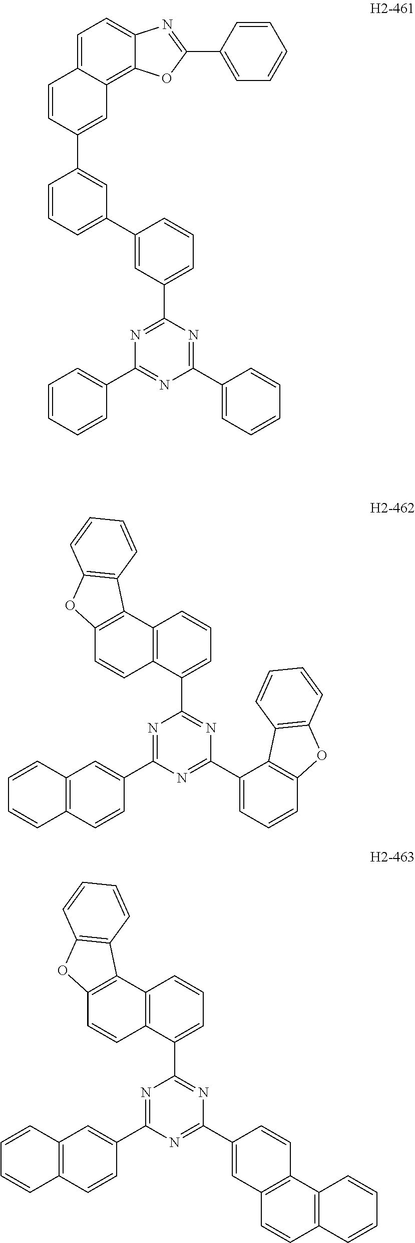 [SMILES: c1ccc(-c2nc(-c3ccccc3)nc(-c3cccc(-c4cccc(-c5ccc6ccc7nc(-c8ccccc8)oc7c6c5)c4)c3)n2)cc1 ; c1ccc2cc(-c3nc(-c4cccc5c4ccc4oc6ccccc6c45)nc(-c4cccc5oc6ccccc6c45)n3)ccc2c1 ; c1ccc2cc(-c3nc(-c4ccc5c(ccc6ccccc65)c4)nc(-c4cccc5c4ccc4oc6ccccc6c45)n3)ccc2c1]

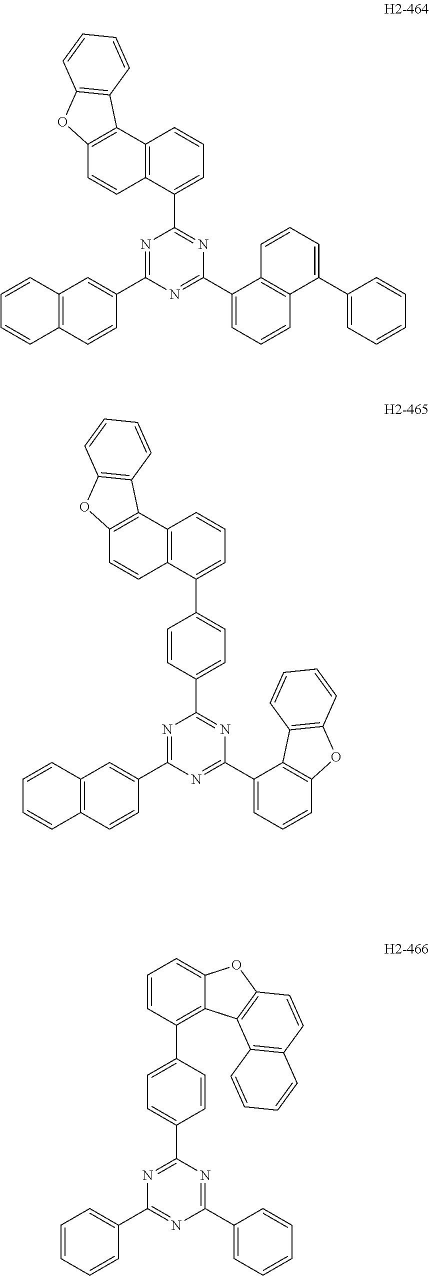 [SMILES: c1ccc(-c2cccc3c(-c4nc(-c5ccc6ccccc6c5)nc(-c5cccc6c5ccc5oc7ccccc7c56)n4)cccc23)cc1 ; c1ccc2cc(-c3nc(-c4ccc(-c5cccc6c5ccc5oc7ccccc7c56)cc4)nc(-c4cccc5oc6ccccc6c45)n3)ccc2c1 ; c1ccc(-c2nc(-c3ccccc3)nc(-c3ccc(-c4cccc5oc6ccc7ccccc7c6c45)cc3)n2)cc1]

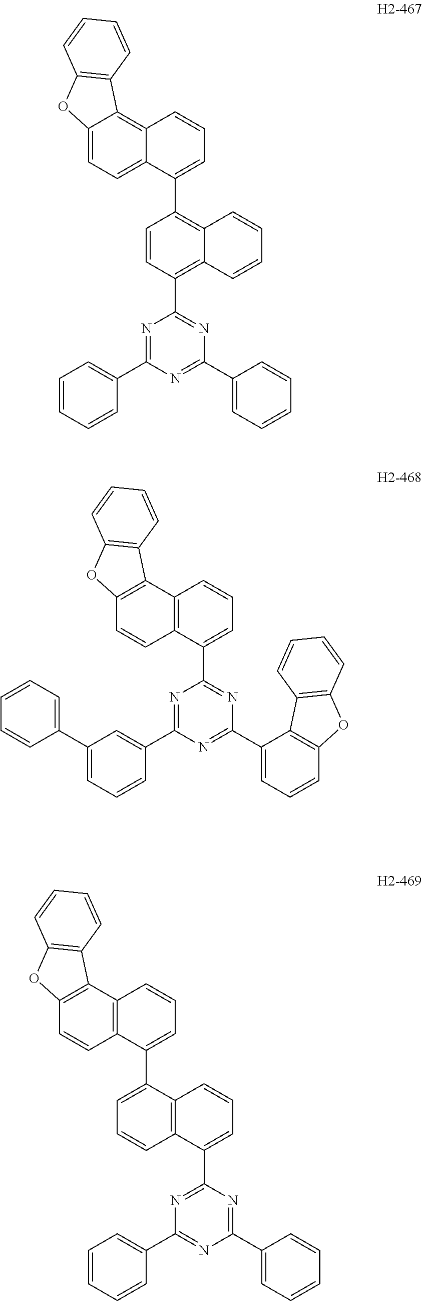 [SMILES: c1ccc(-c2nc(-c3ccccc3)nc(-c3ccc(-c4cccc5c4ccc4oc6ccccc6c45)c4ccccc34)n2)cc1 ; c1ccc(-c2cccc(-c3nc(-c4cccc5c4ccc4oc6ccccc6c45)nc(-c4cccc5oc6ccccc6c45)n3)c2)cc1 ; c1ccc(-c2nc(-c3ccccc3)nc(-c3cccc4c(-c5cccc6c5ccc5oc7ccccc7c56)cccc34)n2)cc1]

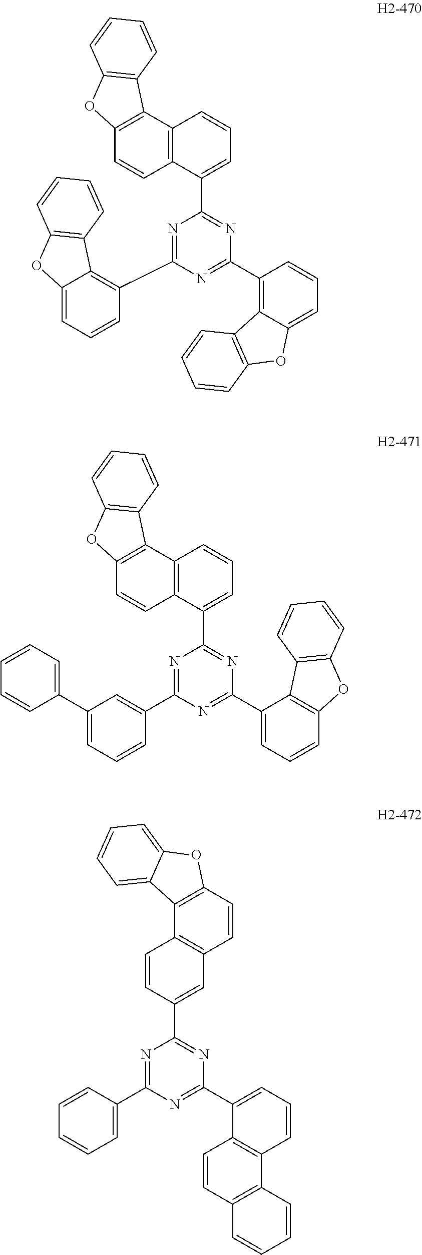 [SMILES: c1ccc2c(c1)oc1cccc(-c3nc(-c4cccc5c4ccc4oc6ccccc6c45)nc(-c4cccc5oc6ccccc6c45)n3)c12 ; c1ccc(-c2cccc(-c3nc(-c4cccc5c4ccc4oc6ccccc6c45)nc(-c4cccc5oc6ccccc6c45)n3)c2)cc1 ; c1ccc(-c2nc(-c3ccc4c(ccc5oc6ccccc6c54)c3)nc(-c3cccc4c3ccc3ccccc34)n2)cc1]

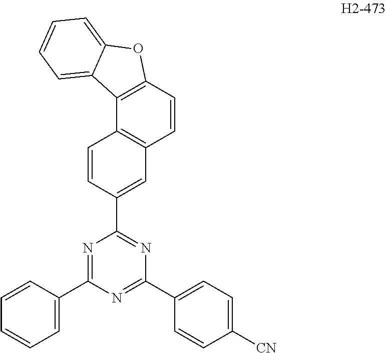 [SMILES: N#Cc1ccc(-c2nc(-c3ccccc3)nc(-c3ccc4c(ccc5oc6ccccc6c54)c3)n2)cc1]

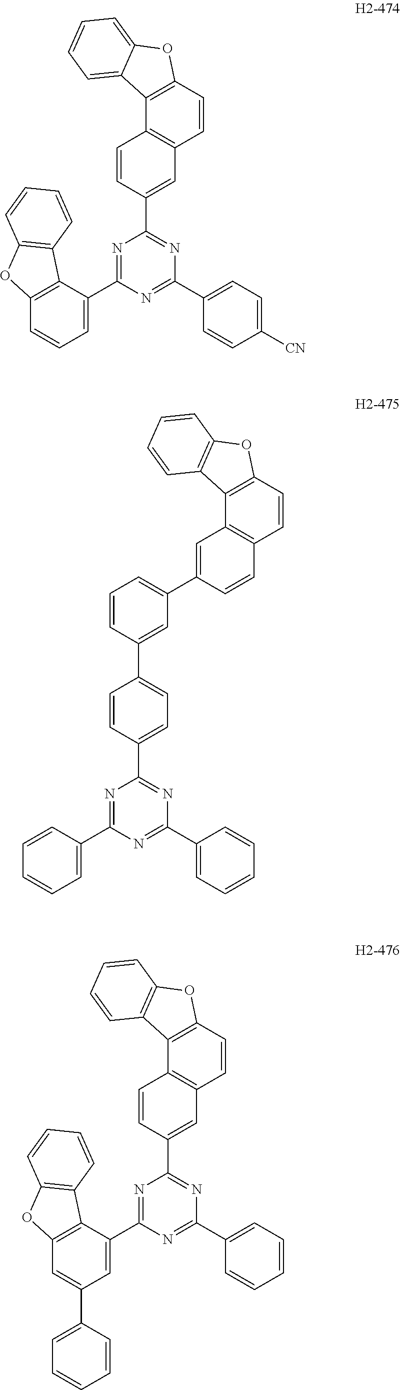 [SMILES: N#Cc1ccc(-c2nc(-c3ccc4c(ccc5oc6ccccc6c54)c3)nc(-c3cccc4oc5ccccc5c34)n2)cc1 ; c1ccc(-c2nc(-c3ccccc3)nc(-c3ccc(-c4cccc(-c5ccc6ccc7oc8ccccc8c7c6c5)c4)cc3)n2)cc1 ; c1ccc(-c2cc(-c3nc(-c4ccccc4)nc(-c4ccc5c(ccc6oc7ccccc7c65)c4)n3)c3c(c2)oc2ccccc23)cc1]

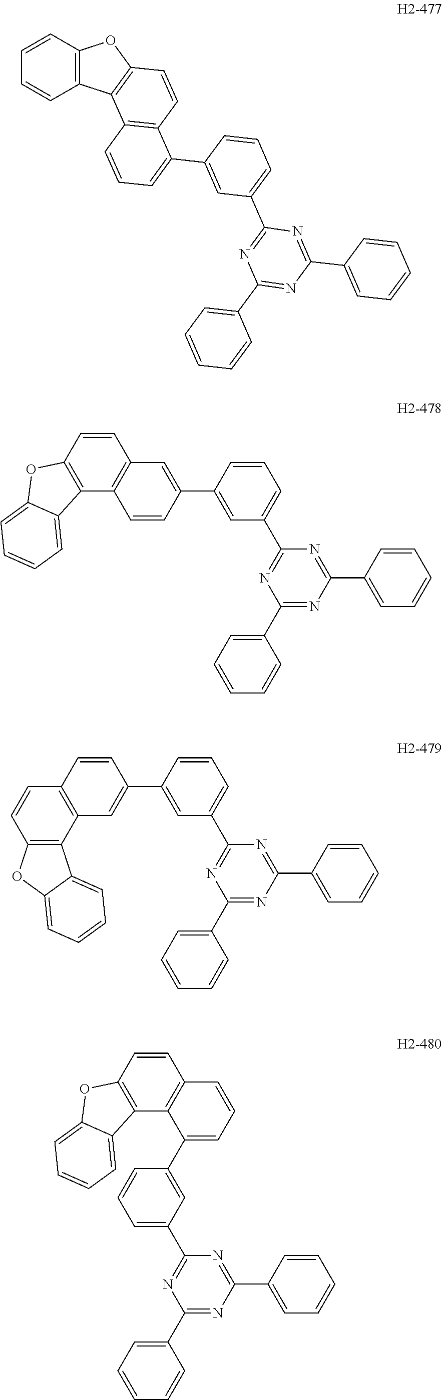 [SMILES: c1ccc(-c2nc(-c3ccccc3)nc(-c3cccc(-c4cccc5c4ccc4oc6ccccc6c45)c3)n2)cc1 ; c1ccc(-c2nc(-c3ccccc3)nc(-c3cccc(-c4ccc5c(ccc6oc7ccccc7c65)c4)c3)n2)cc1 ; c1ccc(-c2nc(-c3ccccc3)nc(-c3cccc(-c4ccc5ccc6oc7ccccc7c6c5c4)c3)n2)cc1 ; c1ccc(-c2nc(-c3ccccc3)nc(-c3cccc(-c4cccc5ccc6oc7ccccc7c6c45)c3)n2)cc1]

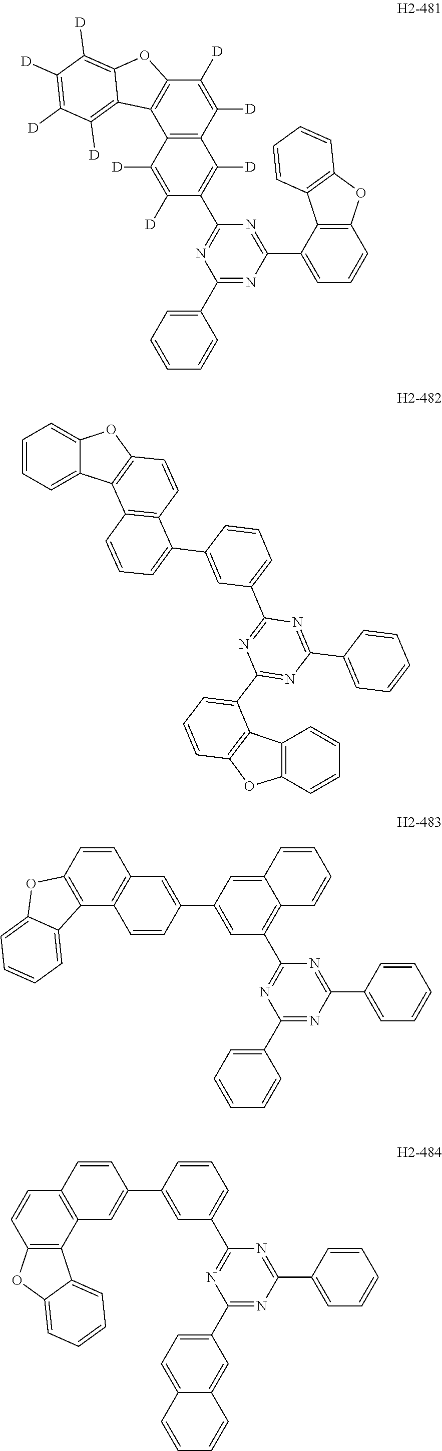 [SMILES: [2H]c1c([2H])c([2H])c2c(oc3c([2H])c([2H])c4c([2H])c(-c5nc(-c6ccccc6)nc(-c6cccc7oc8ccccc8c67)n5)c([2H])c([2H])c4c32)c1[2H] ; c1ccc(-c2nc(-c3cccc(-c4cccc5c4ccc4oc6ccccc6c45)c3)nc(-c3cccc4oc5ccccc5c34)n2)cc1 ; c1ccc(-c2nc(-c3ccccc3)nc(-c3cc(-c4ccc5c(ccc6oc7ccccc7c65)c4)cc4ccccc34)n2)cc1 ; c1ccc(-c2nc(-c3cccc(-c4ccc5ccc6oc7ccccc7c6c5c4)c3)nc(-c3ccc4ccccc4c3)n2)cc1]

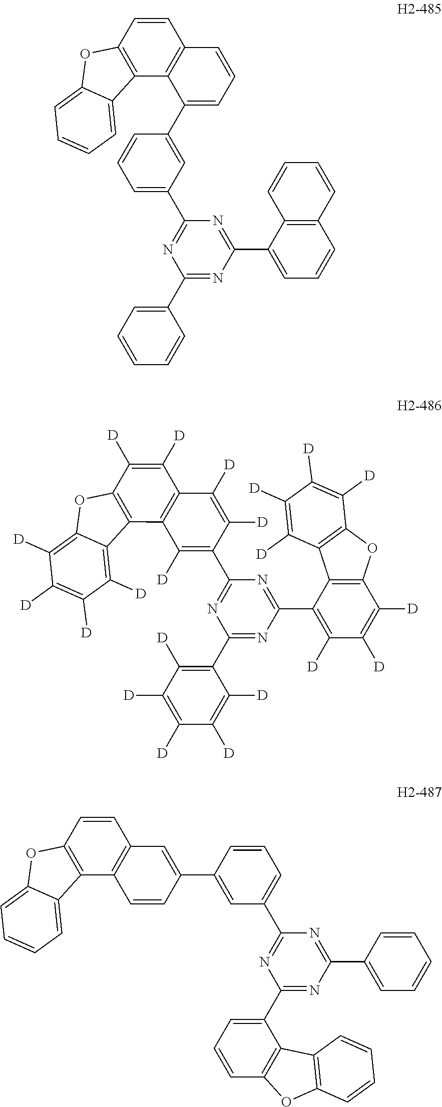 [SMILES: c1ccc(-c2nc(-c3cccc(-c4cccc5ccc6oc7ccccc7c6c45)c3)nc(-c3cccc4ccccc34)n2)cc1 ; [2H]c1c([2H])c([2H])c(-c2nc(-c3c([2H])c([2H])c4c([2H])c([2H])c5oc6c([2H])c([2H])c([2H])c([2H])c6c5c4c3[2H])nc(-c3c([2H])c([2H])c([2H])c4oc5c([2H])c([2H])c([2H])c([2H])c5c34)n2)c([2H])c1[2H] ; c1ccc(-c2nc(-c3cccc(-c4ccc5c(ccc6oc7ccccc7c65)c4)c3)nc(-c3cccc4oc5ccccc5c34)n2)cc1]

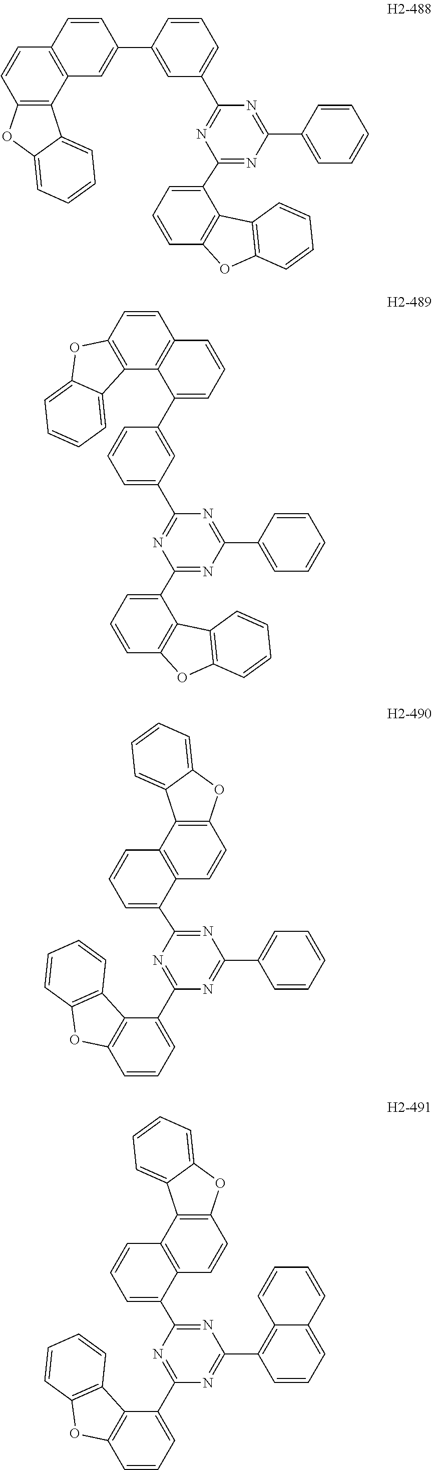

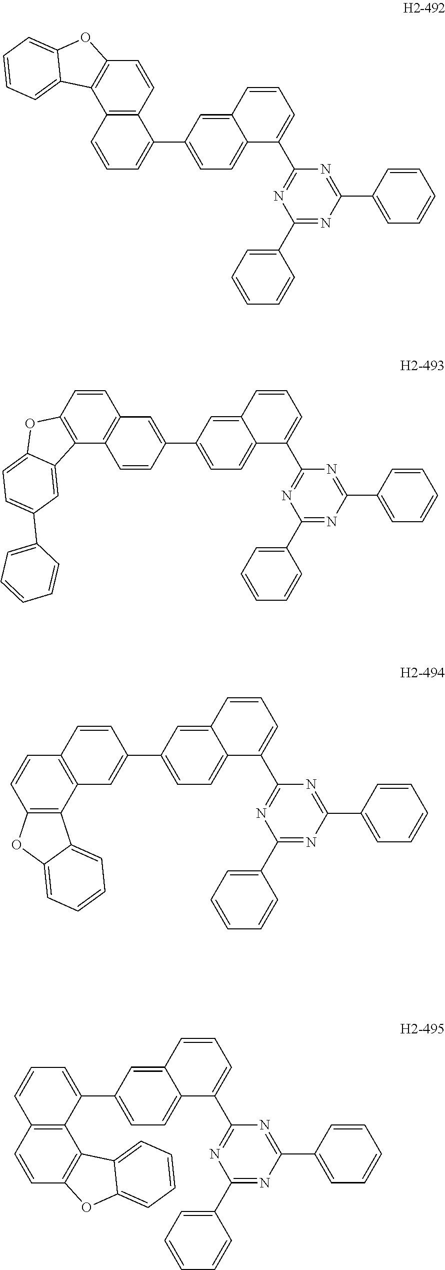 [SMILES: c1ccc(-c2nc(-c3ccccc3)nc(-c3cccc4cc(-c5cccc6c5ccc5oc7ccccc7c56)ccc34)n2)cc1 ; c1ccc(-c2ccc3oc4ccc5cc(-c6ccc7c(-c8nc(-c9ccccc9)nc(-c9ccccc9)n8)cccc7c6)ccc5c4c3c2)cc1 ; c1ccc(-c2nc(-c3ccccc3)nc(-c3cccc4cc(-c5ccc6ccc7oc8ccccc8c7c6c5)ccc34)n2)cc1 ; c1ccc(-c2nc(-c3ccccc3)nc(-c3cccc4cc(-c5cccc6ccc7oc8ccccc8c7c56)ccc34)n2)cc1]

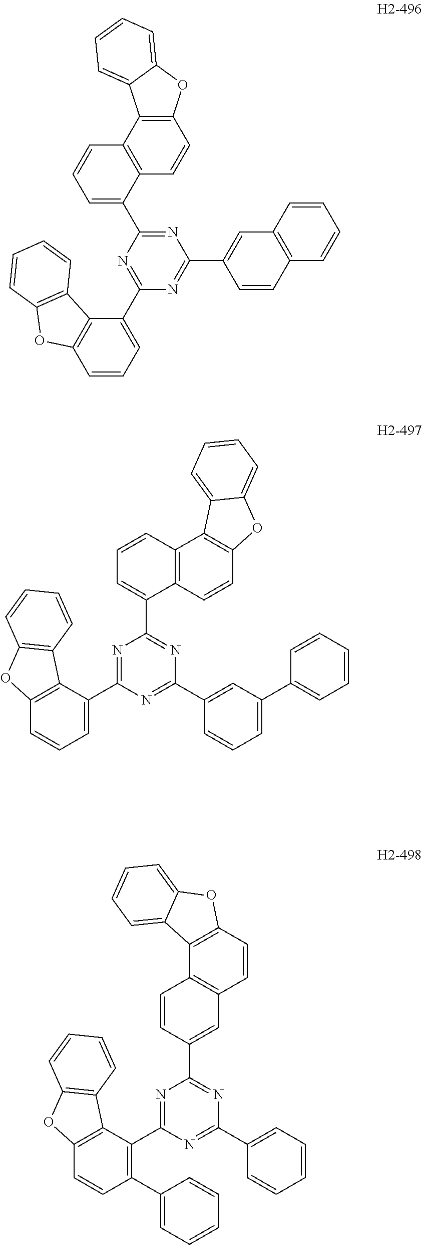 [SMILES: c1ccc2cc(-c3nc(-c4cccc5c4ccc4oc6ccccc6c45)nc(-c4cccc5oc6ccccc6c45)n3)ccc2c1 ; c1ccc(-c2cccc(-c3nc(-c4cccc5c4ccc4oc6ccccc6c45)nc(-c4cccc5oc6ccccc6c45)n3)c2)cc1 ; c1ccc(-c2nc(-c3ccc4c(ccc5oc6ccccc6c54)c3)nc(-c3c(-c4ccccc4)ccc4oc5ccccc5c34)n2)cc1]

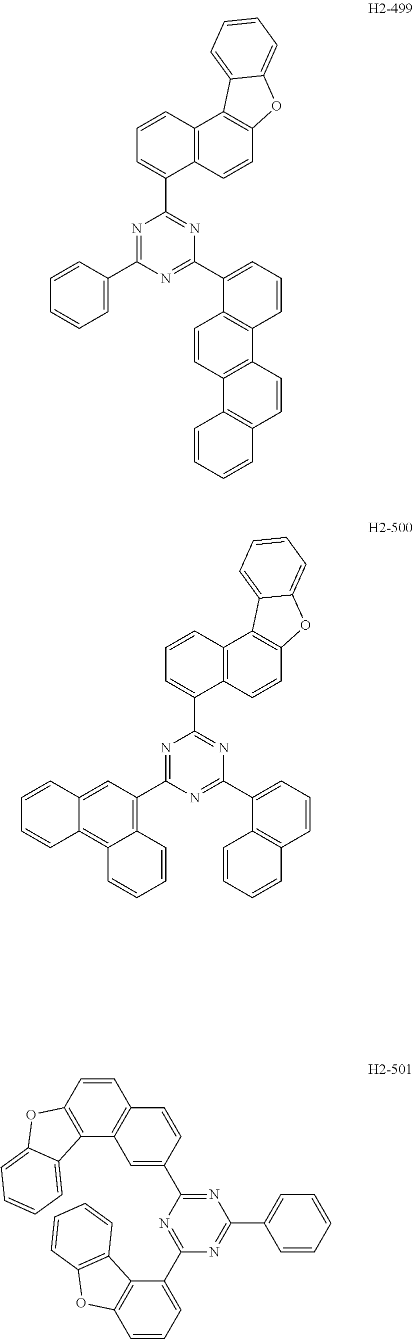 [SMILES: c1ccc(-c2nc(-c3cccc4c3ccc3c5ccccc5ccc43)nc(-c3cccc4c3ccc3oc5ccccc5c34)n2)cc1 ; c1ccc2c(-c3nc(-c4cc5ccccc5c5ccccc45)nc(-c4cccc5c4ccc4oc6ccccc6c45)n3)cccc2c1 ; c1ccc(-c2nc(-c3ccc4ccc5oc6ccccc6c5c4c3)nc(-c3cccc4oc5ccccc5c34)n2)cc1]

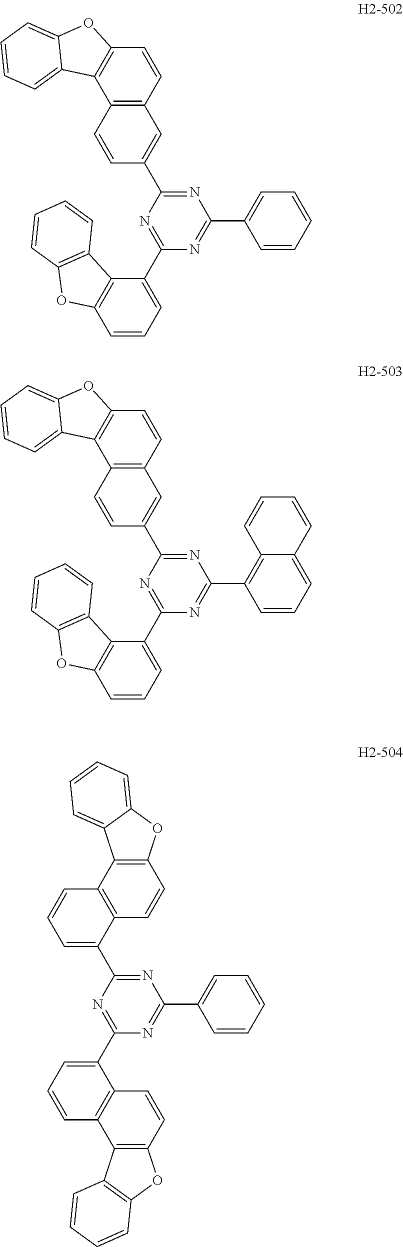 [SMILES: c1ccc(-c2nc(-c3ccc4c(ccc5oc6ccccc6c54)c3)nc(-c3cccc4oc5ccccc5c34)n2)cc1 ; c1ccc2c(-c3nc(-c4ccc5c(ccc6oc7ccccc7c65)c4)nc(-c4cccc5oc6ccccc6c45)n3)cccc2c1 ; c1ccc(-c2nc(-c3cccc4c3ccc3oc5ccccc5c34)nc(-c3cccc4c3ccc3oc5ccccc5c34)n2)cc1]

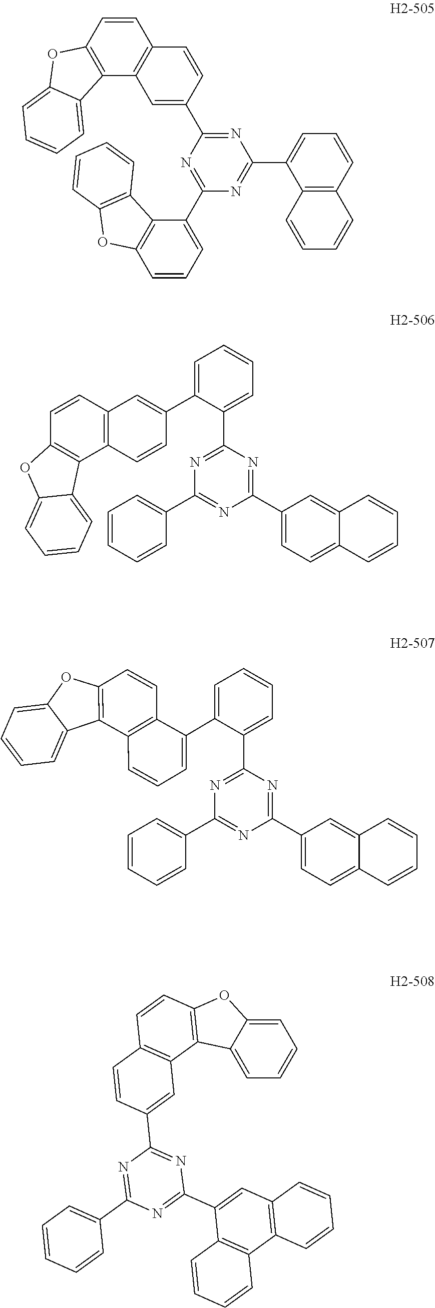 [SMILES: c1ccc2c(-c3nc(-c4ccc5ccc6oc7ccccc7c6c5c4)nc(-c4cccc5oc6ccccc6c45)n3)cccc2c1 ; c1ccc(-c2nc(-c3ccc4ccccc4c3)nc(-c3ccccc3-c3ccc4c(ccc5oc6ccccc6c54)c3)n2)cc1 ; c1ccc(-c2nc(-c3ccc4ccccc4c3)nc(-c3ccccc3-c3cccc4c3ccc3oc5ccccc5c34)n2)cc1 ; c1ccc(-c2nc(-c3ccc4ccc5oc6ccccc6c5c4c3)nc(-c3cc4ccccc4c4ccccc34)n2)cc1]

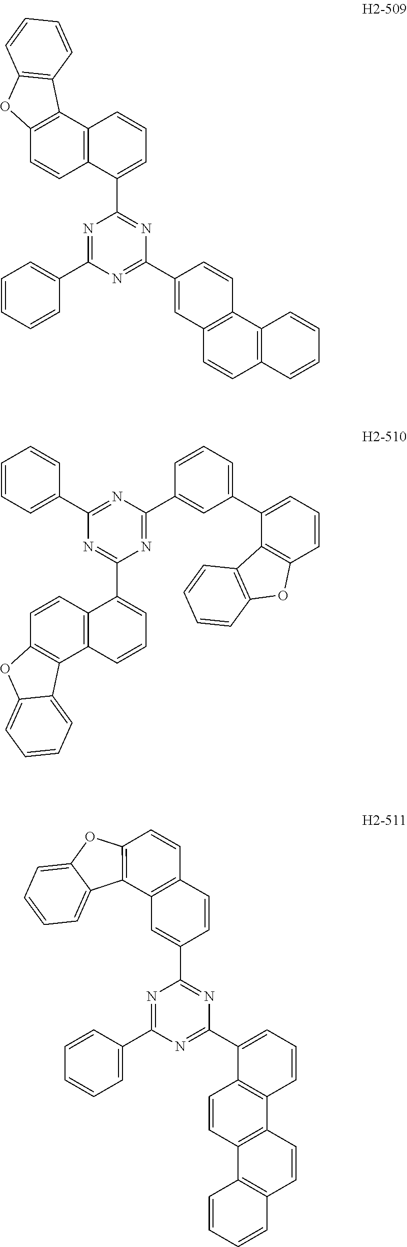 [SMILES: c1ccc(-c2nc(-c3ccc4c(ccc5ccccc54)c3)nc(-c3cccc4c3ccc3oc5ccccc5c34)n2)cc1 ; c1ccc(-c2nc(-c3cccc(-c4cccc5oc6ccccc6c45)c3)nc(-c3cccc4c3ccc3oc5ccccc5c34)n2)cc1 ; c1ccc(-c2nc(-c3ccc4ccc5oc6ccccc6c5c4c3)nc(-c3cccc4c3ccc3c5ccccc5ccc43)n2)cc1]

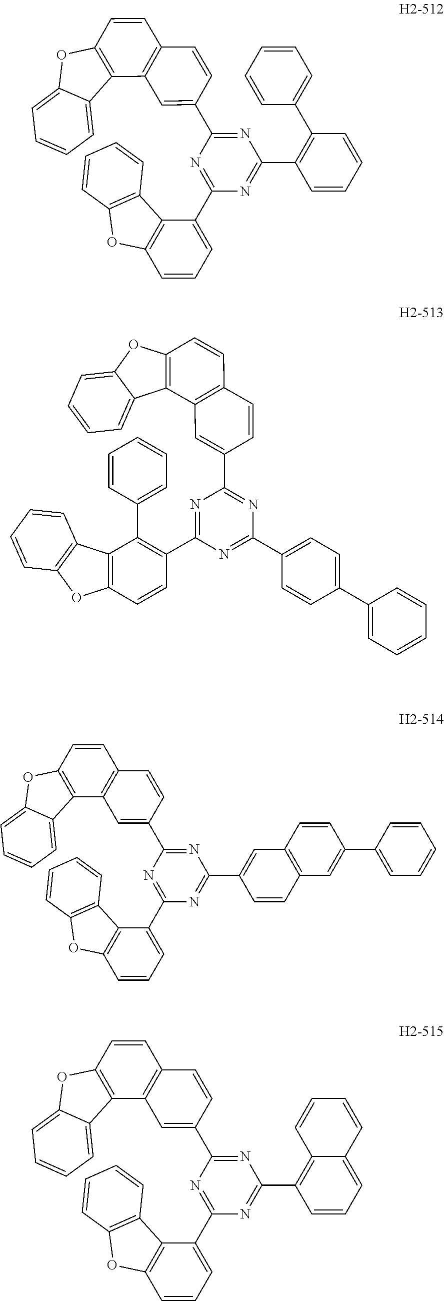 [SMILES: c1ccc(-c2ccccc2-c2nc(-c3ccc4ccc5oc6ccccc6c5c4c3)nc(-c3cccc4oc5ccccc5c34)n2)cc1 ; c1ccc(-c2ccc(-c3nc(-c4ccc5ccc6oc7ccccc7c6c5c4)nc(-c4ccc5oc6ccccc6c5c4-c4ccccc4)n3)cc2)cc1 ; c1ccc(-c2ccc3cc(-c4nc(-c5ccc6ccc7oc8ccccc8c7c6c5)nc(-c5cccc6oc7ccccc7c56)n4)ccc3c2)cc1 ; c1ccc2c(-c3nc(-c4ccc5ccc6oc7ccccc7c6c5c4)nc(-c4cccc5oc6ccccc6c45)n3)cccc2c1]

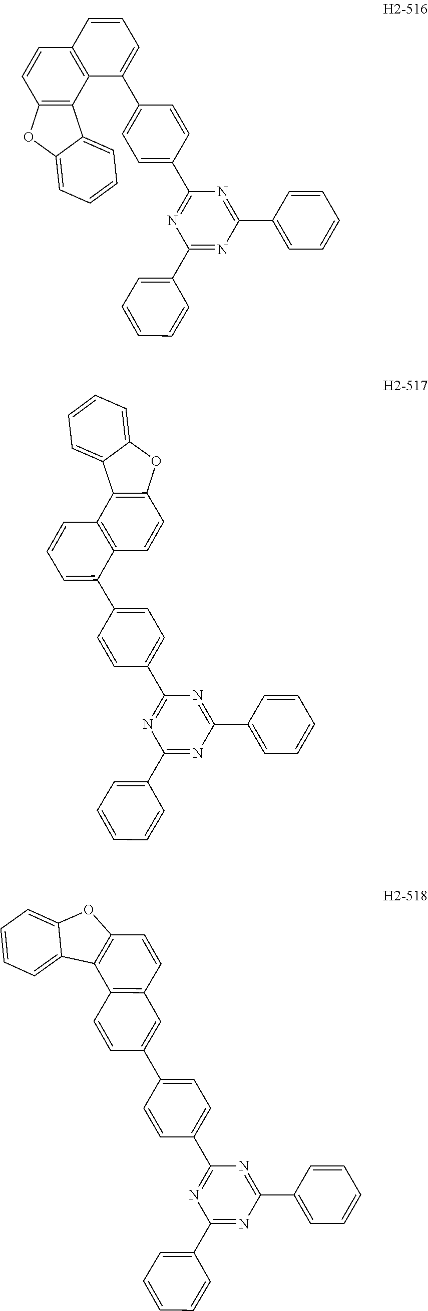 [SMILES: c1ccc(-c2nc(-c3ccccc3)nc(-c3ccc(-c4cccc5ccc6oc7ccccc7c6c45)cc3)n2)cc1 ; c1ccc(-c2nc(-c3ccccc3)nc(-c3ccc(-c4cccc5c4ccc4oc6ccccc6c45)cc3)n2)cc1 ; c1ccc(-c2nc(-c3ccccc3)nc(-c3ccc(-c4ccc5c(ccc6oc7ccccc7c65)c4)cc3)n2)cc1]

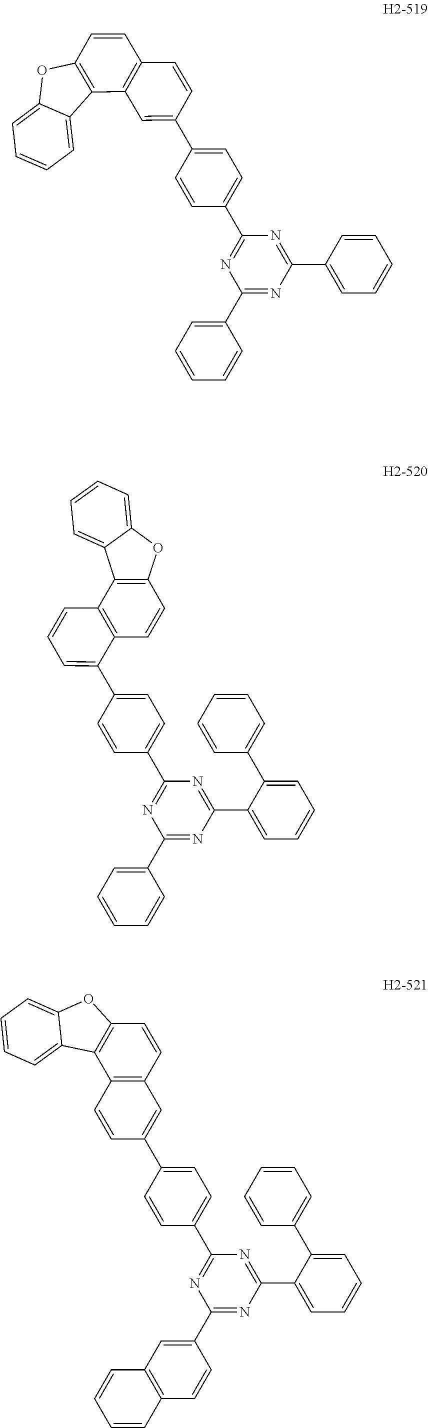 [SMILES: c1ccc(-c2nc(-c3ccccc3)nc(-c3ccc(-c4ccc5ccc6oc7ccccc7c6c5c4)cc3)n2)cc1 ; c1ccc(-c2nc(-c3ccc(-c4cccc5c4ccc4oc6ccccc6c45)cc3)nc(-c3ccccc3-c3ccccc3)n2)cc1 ; c1ccc(-c2ccccc2-c2nc(-c3ccc(-c4ccc5c(ccc6oc7ccccc7c65)c4)cc3)nc(-c3ccc4ccccc4c3)n2)cc1]

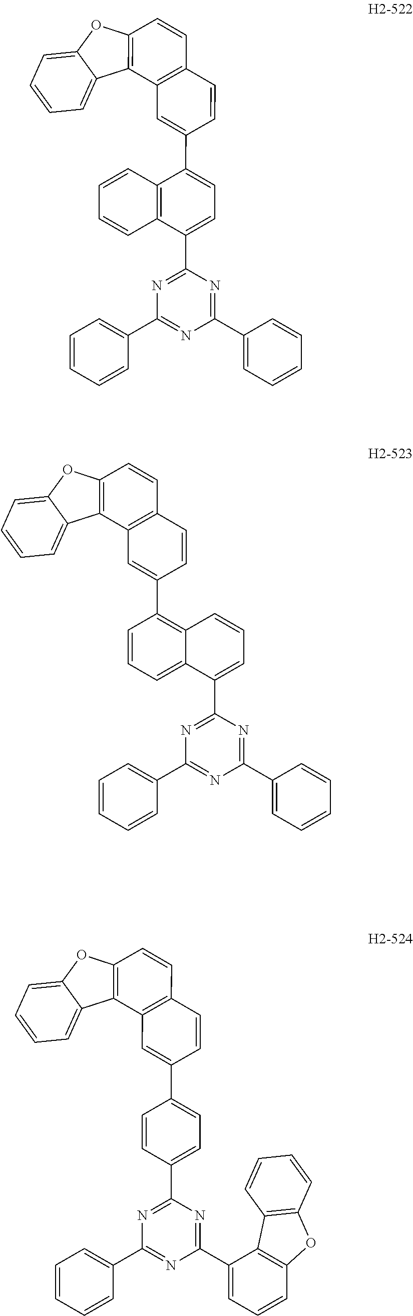 [SMILES: c1ccc(-c2nc(-c3ccccc3)nc(-c3ccc(-c4ccc5ccc6oc7ccccc7c6c5c4)c4ccccc34)n2)cc1 ; c1ccc(-c2nc(-c3ccccc3)nc(-c3cccc4c(-c5ccc6ccc7oc8ccccc8c7c6c5)cccc34)n2)cc1 ; c1ccc(-c2nc(-c3ccc(-c4ccc5ccc6oc7ccccc7c6c5c4)cc3)nc(-c3cccc4oc5ccccc5c34)n2)cc1]

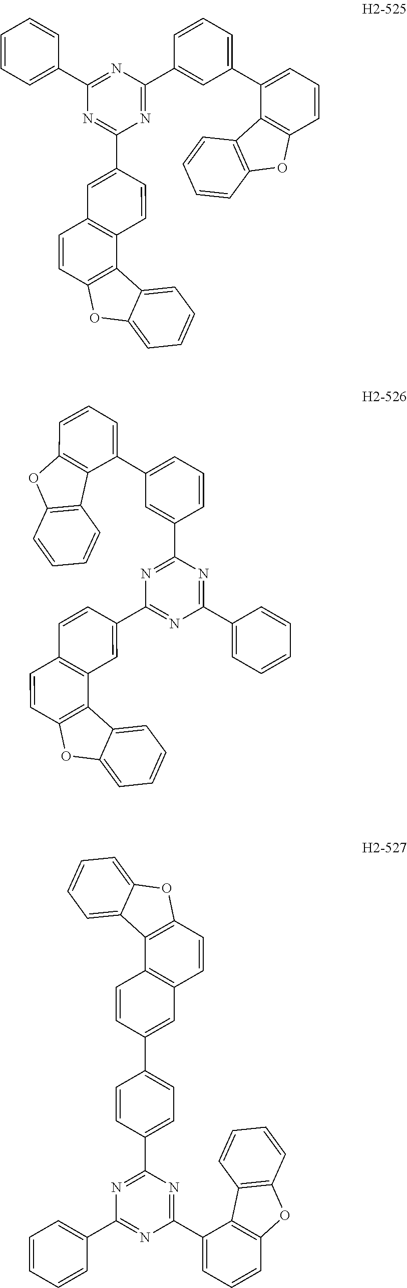 [SMILES: c1ccc(-c2nc(-c3cccc(-c4cccc5oc6ccccc6c45)c3)nc(-c3ccc4c(ccc5oc6ccccc6c54)c3)n2)cc1 ; c1ccc(-c2nc(-c3cccc(-c4cccc5oc6ccccc6c45)c3)nc(-c3ccc4ccc5oc6ccccc6c5c4c3)n2)cc1 ; c1ccc(-c2nc(-c3ccc(-c4ccc5c(ccc6oc7ccccc7c65)c4)cc3)nc(-c3cccc4oc5ccccc5c34)n2)cc1]

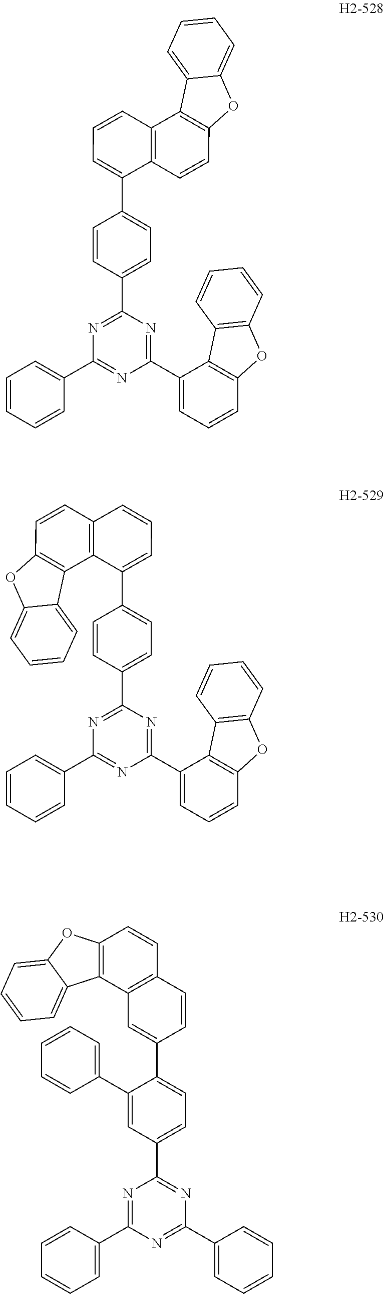 [SMILES: c1ccc(-c2nc(-c3ccc(-c4cccc5c4ccc4oc6ccccc6c45)cc3)nc(-c3cccc4oc5ccccc5c34)n2)cc1 ; c1ccc(-c2nc(-c3ccc(-c4cccc5ccc6oc7ccccc7c6c45)cc3)nc(-c3cccc4oc5ccccc5c34)n2)cc1 ; c1ccc(-c2nc(-c3ccccc3)nc(-c3ccc(-c4ccc5ccc6oc7ccccc7c6c5c4)c(-c4ccccc4)c3)n2)cc1]

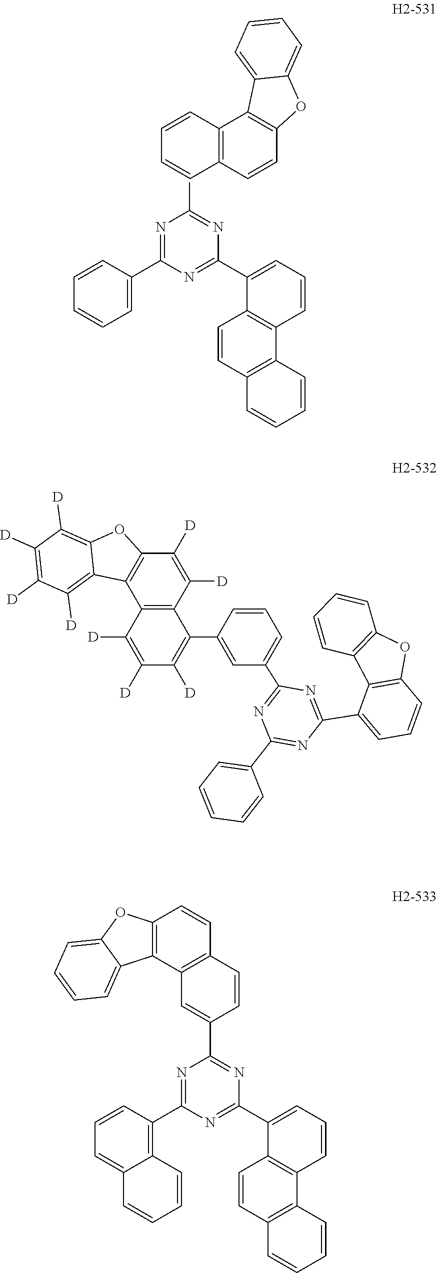

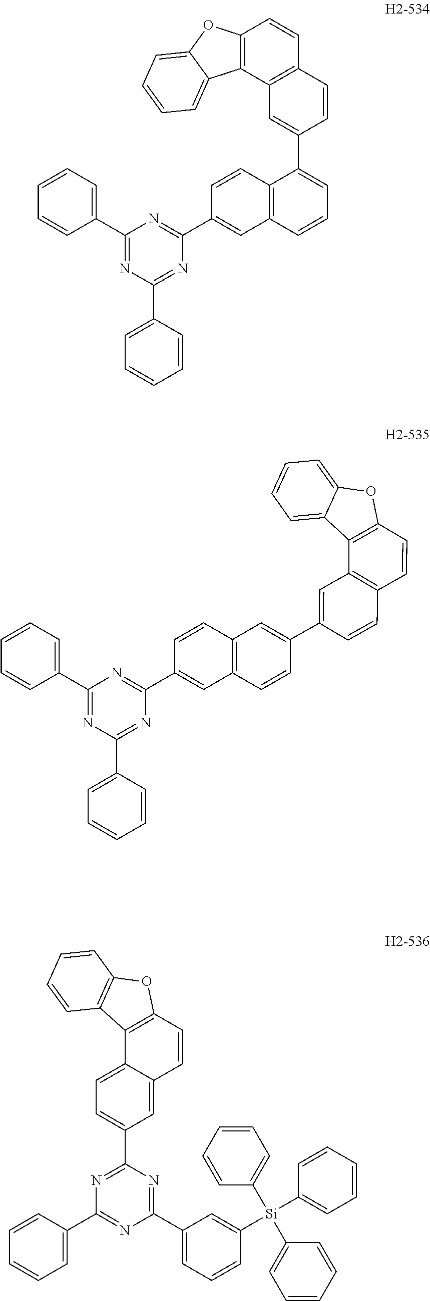 [SMILES: c1ccc(-c2nc(-c3ccccc3)nc(-c3ccc4c(-c5ccc6ccc7oc8ccccc8c7c6c5)cccc4c3)n2)cc1 ; c1ccc(-c2nc(-c3ccccc3)nc(-c3ccc4cc(-c5ccc6ccc7oc8ccccc8c7c6c5)ccc4c3)n2)cc1 ; c1ccc(-c2nc(-c3cccc([Si](c4ccccc4)(c4ccccc4)c4ccccc4)c3)nc(-c3ccc4c(ccc5oc6ccccc6c54)c3)n2)cc1]

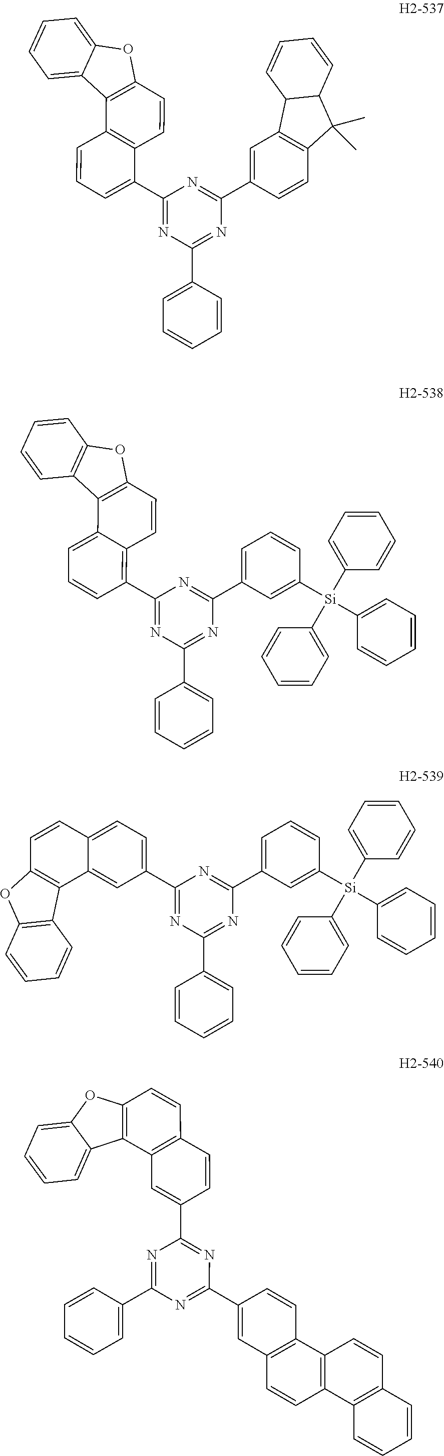 [SMILES: CC1(C)c2ccc(-c3nc(-c4ccccc4)nc(-c4cccc5c4ccc4oc6ccccc6c45)n3)cc2C2C=CC=CC21 ; c1ccc(-c2nc(-c3cccc([Si](c4ccccc4)(c4ccccc4)c4ccccc4)c3)nc(-c3cccc4c3ccc3oc5ccccc5c34)n2)cc1 ; c1ccc(-c2nc(-c3cccc([Si](c4ccccc4)(c4ccccc4)c4ccccc4)c3)nc(-c3ccc4ccc5oc6ccccc6c5c4c3)n2)cc1 ; c1ccc(-c2nc(-c3ccc4c(ccc5c6ccccc6ccc45)c3)nc(-c3ccc4ccc5oc6ccccc6c5c4c3)n2)cc1]

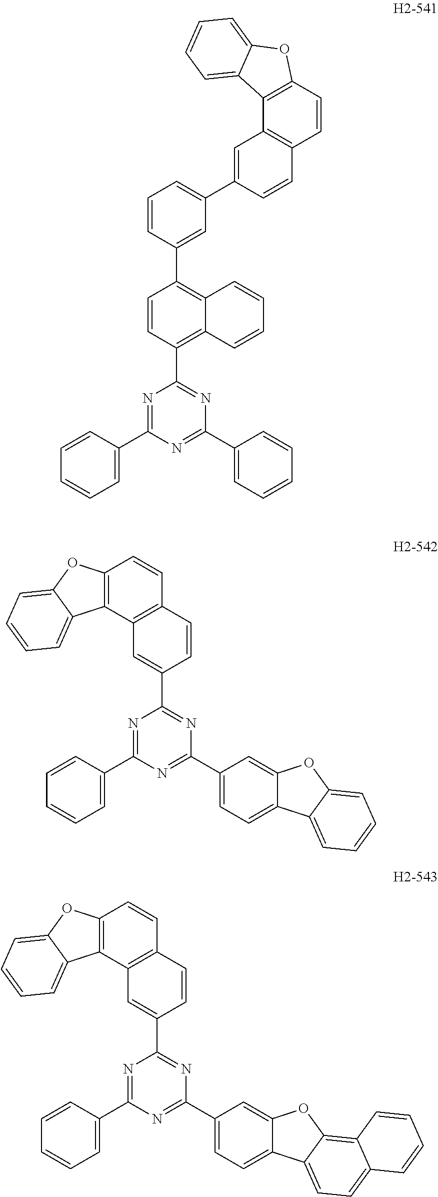 [SMILES: c1ccc(-c2nc(-c3ccccc3)nc(-c3ccc(-c4cccc(-c5ccc6ccc7oc8ccccc8c7c6c5)c4)c4ccccc34)n2)cc1 ; c1ccc(-c2nc(-c3ccc4c(c3)oc3ccccc34)nc(-c3ccc4ccc5oc6ccccc6c5c4c3)n2)cc1 ; c1ccc(-c2nc(-c3ccc4c(c3)oc3c5ccccc5ccc43)nc(-c3ccc4ccc5oc6ccccc6c5c4c3)n2)cc1]

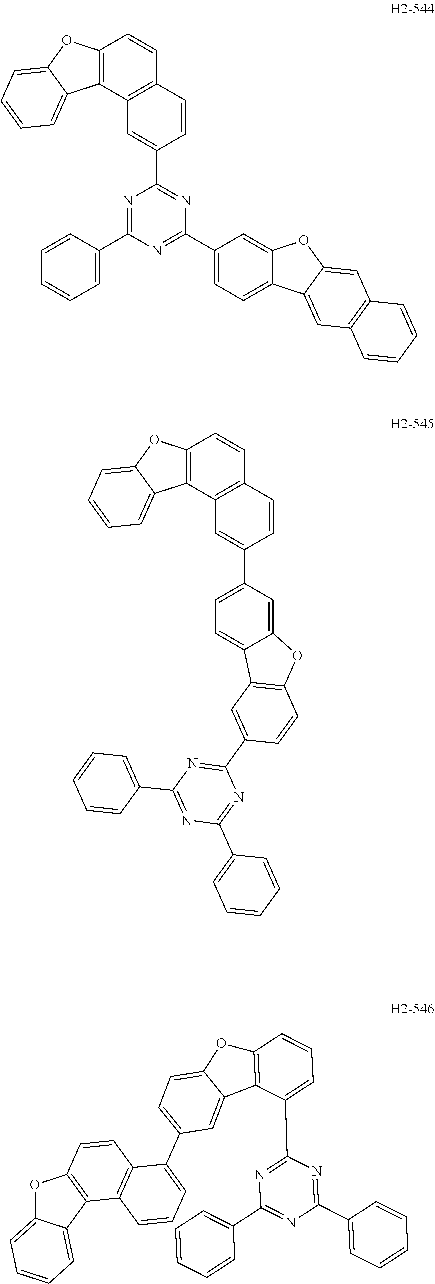 [SMILES: c1ccc(-c2nc(-c3ccc4c(c3)oc3cc5ccccc5cc34)nc(-c3ccc4ccc5oc6ccccc6c5c4c3)n2)cc1 ; c1ccc(-c2nc(-c3ccccc3)nc(-c3ccc4oc5cc(-c6ccc7ccc8oc9ccccc9c8c7c6)ccc5c4c3)n2)cc1 ; c1ccc(-c2nc(-c3ccccc3)nc(-c3cccc4oc5ccc(-c6cccc7c6ccc6oc8ccccc8c67)cc5c34)n2)cc1]

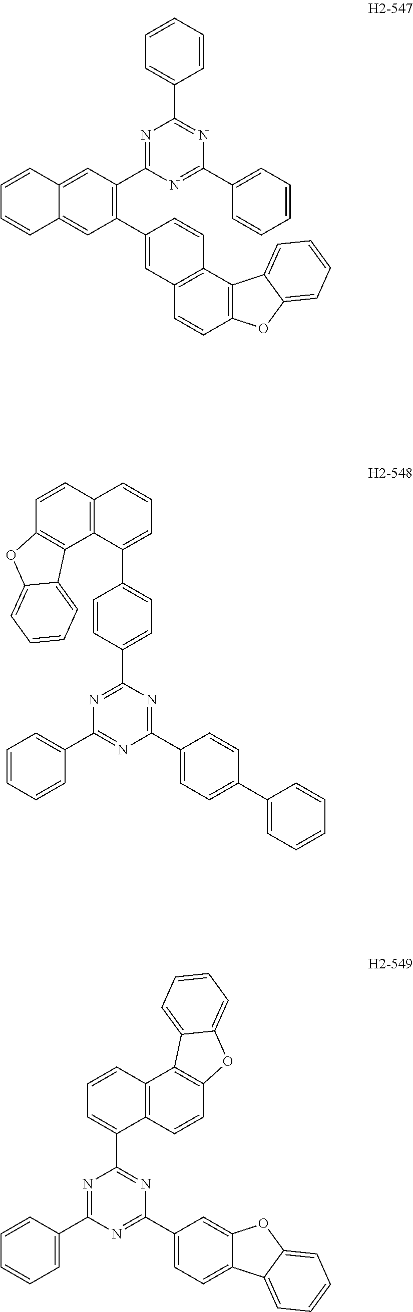 [SMILES: c1ccc(-c2nc(-c3ccccc3)nc(-c3cc4ccccc4cc3-c3ccc4c(ccc5oc6ccccc6c54)c3)n2)cc1 ; c1ccc(-c2ccc(-c3nc(-c4ccccc4)nc(-c4ccc(-c5cccc6ccc7oc8ccccc8c7c56)cc4)n3)cc2)cc1 ; c1ccc(-c2nc(-c3ccc4c(c3)oc3ccccc34)nc(-c3cccc4c3ccc3oc5ccccc5c34)n2)cc1]

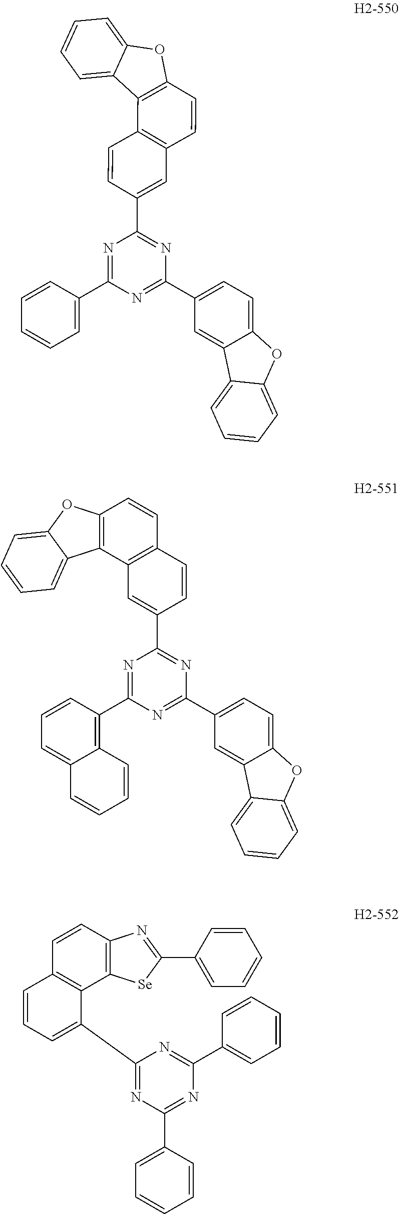 [SMILES: c1ccc(-c2nc(-c3ccc4c(ccc5oc6ccccc6c54)c3)nc(-c3ccc4oc5ccccc5c4c3)n2)cc1 ; c1ccc2c(-c3nc(-c4ccc5oc6ccccc6c5c4)nc(-c4ccc5ccc6oc7ccccc7c6c5c4)n3)cccc2c1 ; c1ccc(-c2nc(-c3ccccc3)nc(-c3cccc4ccc5nc(-c6ccccc6)[se]c5c34)n2)cc1]

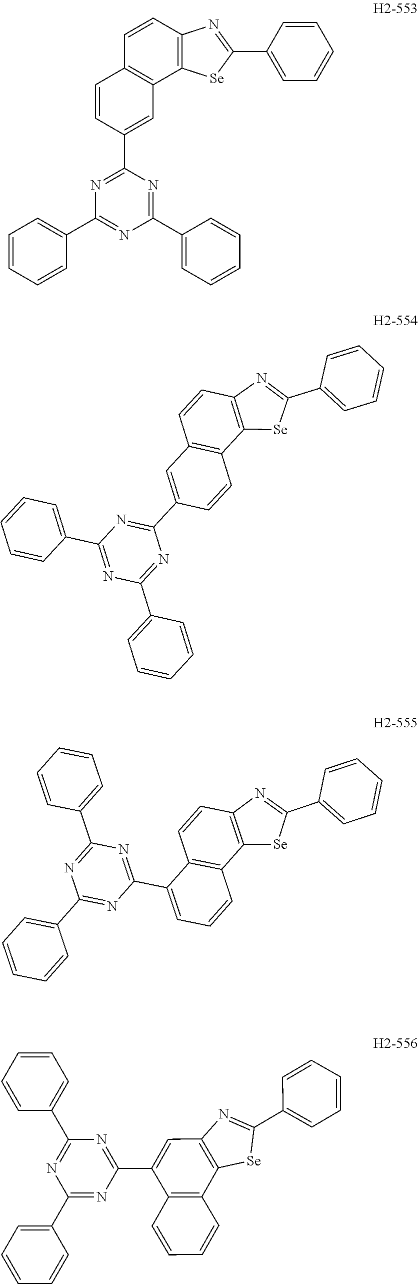 [SMILES: c1ccc(-c2nc(-c3ccccc3)nc(-c3ccc4ccc5nc(-c6ccccc6)[se]c5c4c3)n2)cc1 ; c1ccc(-c2nc(-c3ccccc3)nc(-c3ccc4c(ccc5nc(-c6ccccc6)[se]c54)c3)n2)cc1 ; c1ccc(-c2nc(-c3ccccc3)nc(-c3cccc4c3ccc3nc(-c5ccccc5)[se]c34)n2)cc1 ; c1ccc(-c2nc(-c3ccccc3)nc(-c3cc4nc(-c5ccccc5)[se]c4c4ccccc34)n2)cc1]

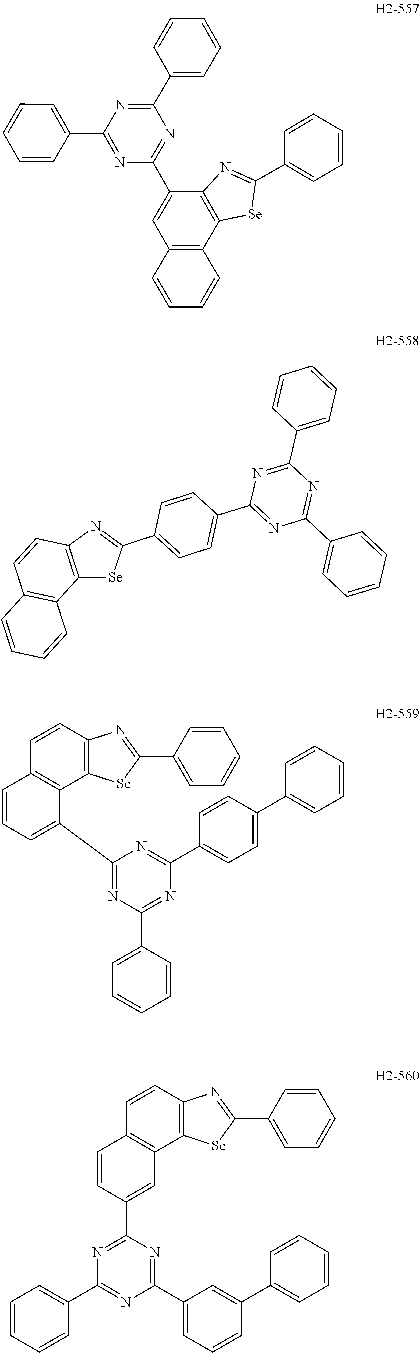 [SMILES: c1ccc(-c2nc(-c3ccccc3)nc(-c3cc4ccccc4c4[se]c(-c5ccccc5)nc34)n2)cc1 ; c1ccc(-c2nc(-c3ccccc3)nc(-c3ccc(-c4nc5ccc6ccccc6c5[se]4)cc3)n2)cc1 ; c1ccc(-c2ccc(-c3nc(-c4ccccc4)nc(-c4cccc5ccc6nc(-c7ccccc7)[se]c6c45)n3)cc2)cc1 ; c1ccc(-c2cccc(-c3nc(-c4ccccc4)nc(-c4ccc5ccc6nc(-c7ccccc7)[se]c6c5c4)n3)c2)cc1]

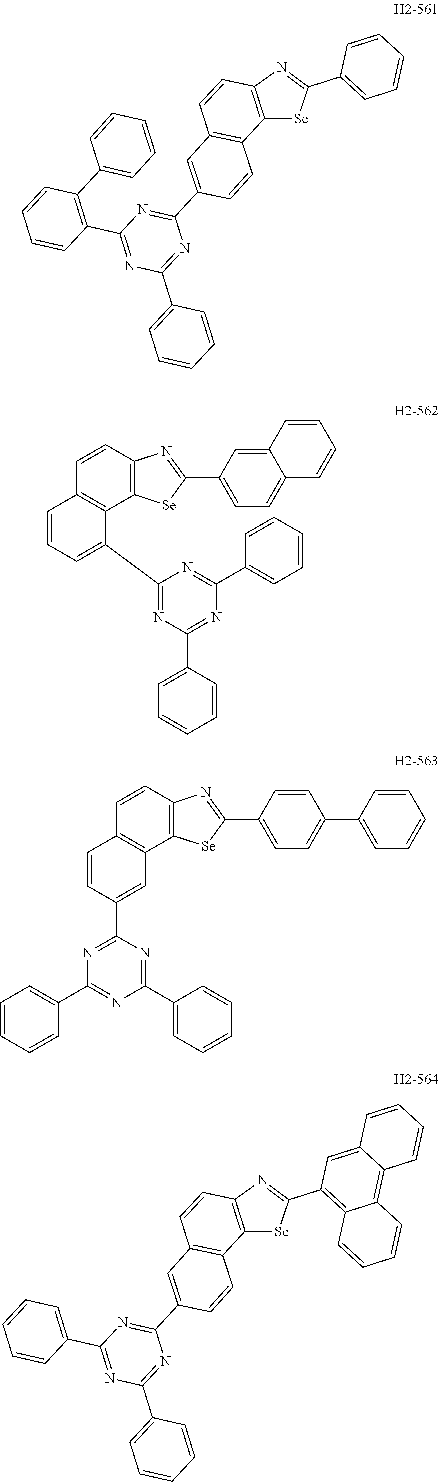 [SMILES: c1ccc(-c2nc(-c3ccc4c(ccc5nc(-c6ccccc6)[se]c54)c3)nc(-c3ccccc3-c3ccccc3)n2)cc1 ; c1ccc(-c2nc(-c3ccccc3)nc(-c3cccc4ccc5nc(-c6ccc7ccccc7c6)[se]c5c34)n2)cc1 ; c1ccc(-c2ccc(-c3nc4ccc5ccc(-c6nc(-c7ccccc7)nc(-c7ccccc7)n6)cc5c4[se]3)cc2)cc1 ; c1ccc(-c2nc(-c3ccccc3)nc(-c3ccc4c(ccc5nc(-c6cc7ccccc7c7ccccc67)[se]c54)c3)n2)cc1]

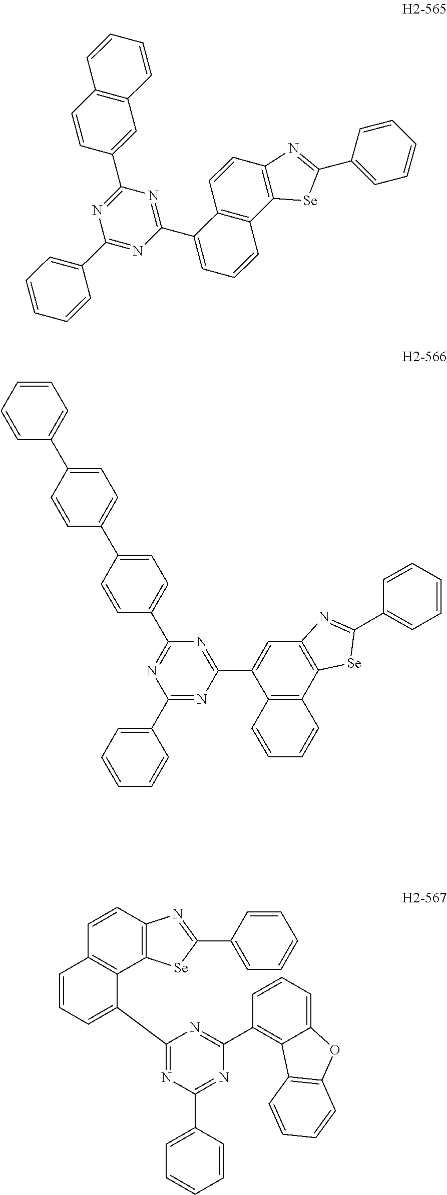 [SMILES: c1ccc(-c2nc(-c3ccc4ccccc4c3)nc(-c3cccc4c3ccc3nc(-c5ccccc5)[se]c34)n2)cc1 ; c1ccc(-c2ccc(-c3ccc(-c4nc(-c5ccccc5)nc(-c5cc6nc(-c7ccccc7)[se]c6c6ccccc56)n4)cc3)cc2)cc1 ; c1ccc(-c2nc(-c3cccc4oc5ccccc5c34)nc(-c3cccc4ccc5nc(-c6ccccc6)[se]c5c34)n2)cc1]

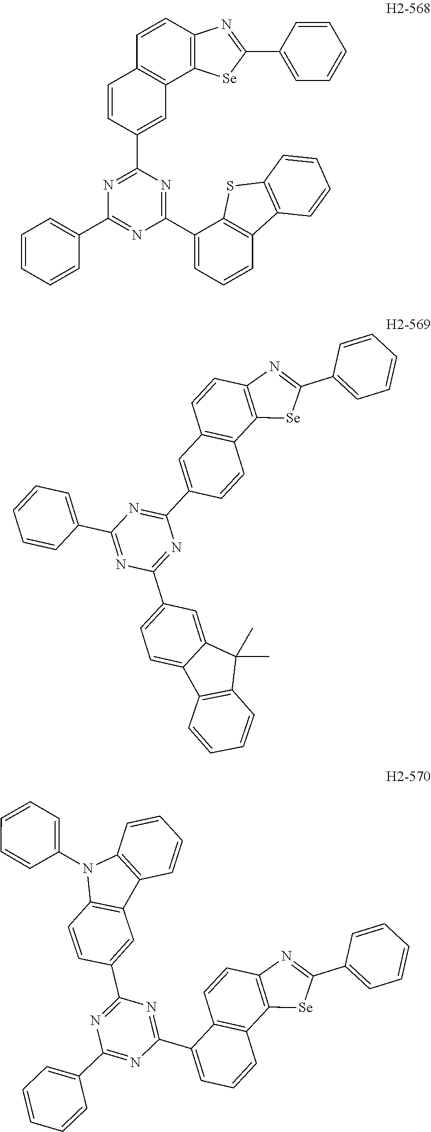 [SMILES: c1ccc(-c2nc(-c3ccc4ccc5nc(-c6ccccc6)[se]c5c4c3)nc(-c3cccc4c3sc3ccccc34)n2)cc1 ; CC1(C)c2ccccc2-c2ccc(-c3nc(-c4ccccc4)nc(-c4ccc5c(ccc6nc(-c7ccccc7)[se]c65)c4)n3)cc21 ; c1ccc(-c2nc(-c3ccc4c(c3)c3ccccc3n4-c3ccccc3)nc(-c3cccc4c3ccc3nc(-c5ccccc5)[se]c34)n2)cc1]

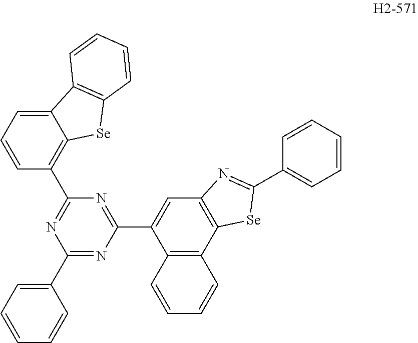 [SMILES: c1ccc(-c2nc(-c3cc4nc(-c5ccccc5)[se]c4c4ccccc34)nc(-c3cccc4c3[se]c3ccccc34)n2)cc1]

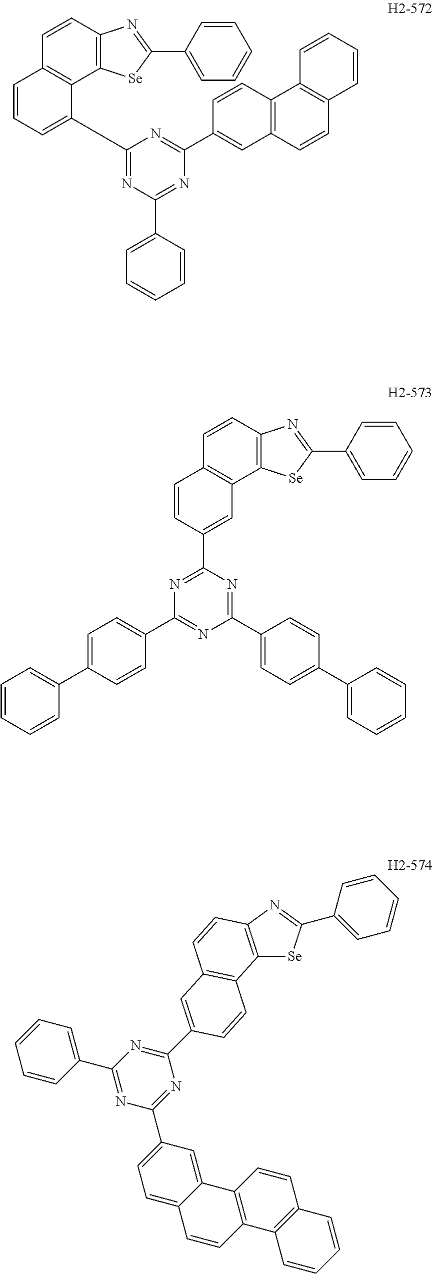 [SMILES: c1ccc(-c2nc(-c3ccc4c(ccc5ccccc54)c3)nc(-c3cccc4ccc5nc(-c6ccccc6)[se]c5c34)n2)cc1 ; c1ccc(-c2ccc(-c3nc(-c4ccc(-c5ccccc5)cc4)nc(-c4ccc5ccc6nc(-c7ccccc7)[se]c6c5c4)n3)cc2)cc1 ; c1ccc(-c2nc(-c3ccc4c(ccc5nc(-c6ccccc6)[se]c54)c3)nc(-c3ccc4ccc5c6ccccc6ccc5c4c3)n2)cc1]

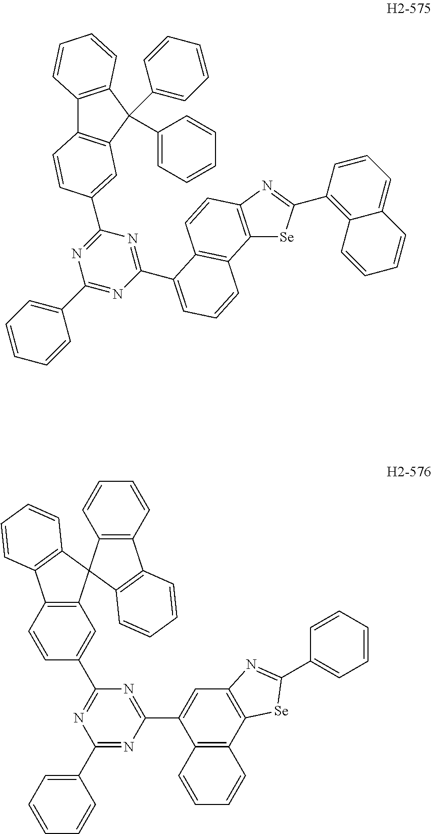 [SMILES: c1ccc(-c2nc(-c3ccc4c(c3)C(c3ccccc3)(c3ccccc3)c3ccccc3-4)nc(-c3cccc4c3ccc3nc(-c5cccc6ccccc56)[se]c34)n2)cc1 ; c1ccc(-c2nc(-c3ccc4c(c3)C3(c5ccccc5-c5ccccc53)c3ccccc3-4)nc(-c3cc4nc(-c5ccccc5)[se]c4c4ccccc34)n2)cc1]

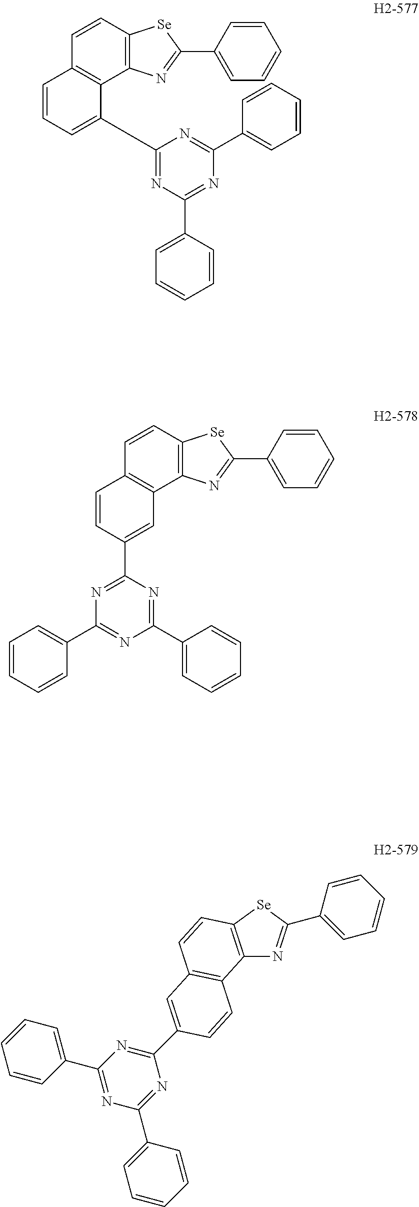 [SMILES: c1ccc(-c2nc(-c3ccccc3)nc(-c3cccc4ccc5[se]c(-c6ccccc6)nc5c34)n2)cc1 ; c1ccc(-c2nc(-c3ccccc3)nc(-c3ccc4ccc5[se]c(-c6ccccc6)nc5c4c3)n2)cc1 ; c1ccc(-c2nc(-c3ccccc3)nc(-c3ccc4c(ccc5[se]c(-c6ccccc6)nc54)c3)n2)cc1]

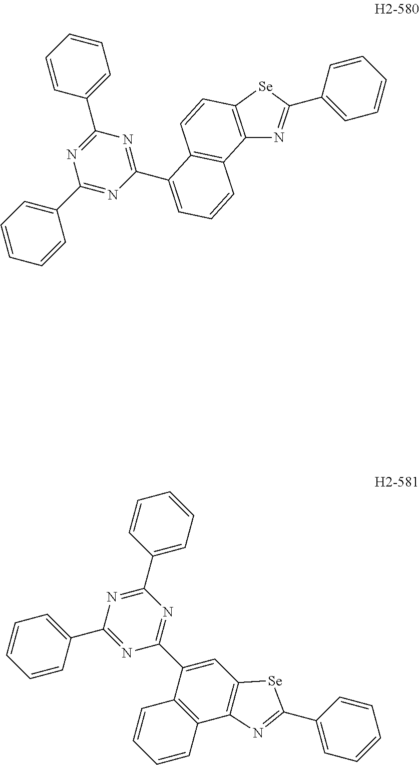 [SMILES: c1ccc(-c2nc(-c3ccccc3)nc(-c3cccc4c3ccc3[se]c(-c5ccccc5)nc34)n2)cc1 ; c1ccc(-c2nc(-c3ccccc3)nc(-c3cc4[se]c(-c5ccccc5)nc4c4ccccc34)n2)cc1]

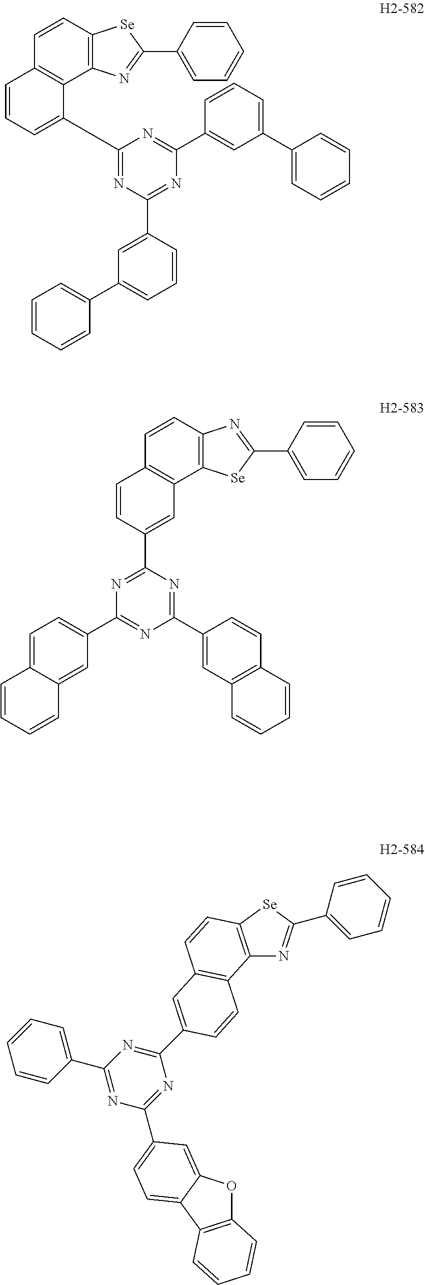 [SMILES: c1ccc(-c2cccc(-c3nc(-c4cccc(-c5ccccc5)c4)nc(-c4cccc5ccc6[se]c(-c7ccccc7)nc6c45)n3)c2)cc1 ; c1ccc(-c2nc3ccc4ccc(-c5nc(-c6ccc7ccccc7c6)nc(-c6ccc7ccccc7c6)n5)cc4c3[se]2)cc1 ; c1ccc(-c2nc(-c3ccc4c(ccc5[se]c(-c6ccccc6)nc54)c3)nc(-c3ccc4c(c3)oc3ccccc34)n2)cc1]

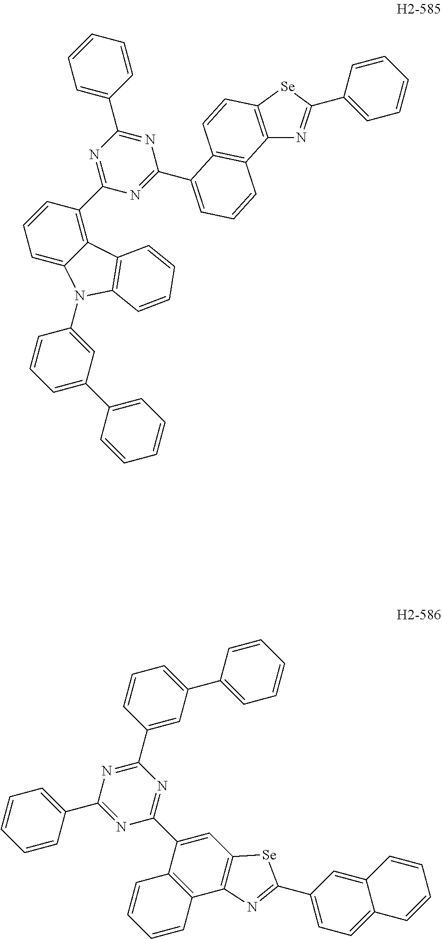 [SMILES: c1ccc(-c2cccc(-n3c4ccccc4c4c(-c5nc(-c6ccccc6)nc(-c6cccc7c6ccc6[se]c(-c8ccccc8)nc67)n5)cccc43)c2)cc1 ; c1ccc(-c2cccc(-c3nc(-c4ccccc4)nc(-c4cc5[se]c(-c6ccc7ccccc7c6)nc5c5ccccc45)n3)c2)cc1]

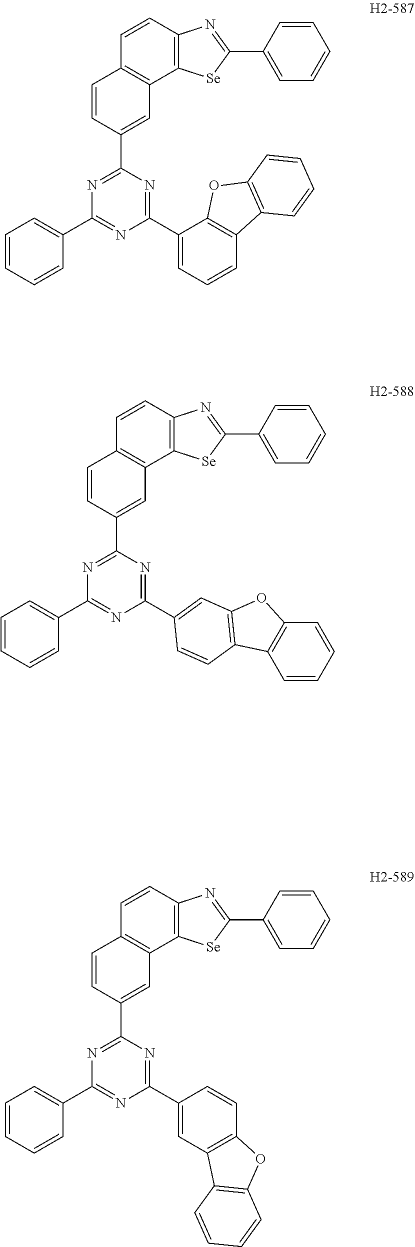 [SMILES: c1ccc(-c2nc(-c3ccc4ccc5nc(-c6ccccc6)[se]c5c4c3)nc(-c3cccc4c3oc3ccccc34)n2)cc1 ; c1ccc(-c2nc(-c3ccc4c(c3)oc3ccccc34)nc(-c3ccc4ccc5nc(-c6ccccc6)[se]c5c4c3)n2)cc1 ; c1ccc(-c2nc(-c3ccc4oc5ccccc5c4c3)nc(-c3ccc4ccc5nc(-c6ccccc6)[se]c5c4c3)n2)cc1]

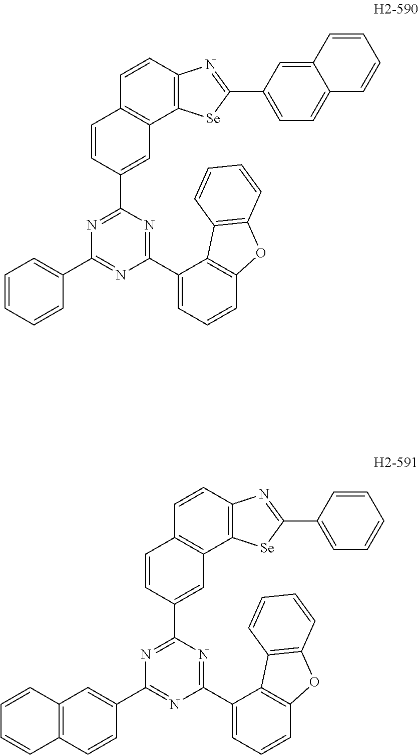 [SMILES: c1ccc(-c2nc(-c3ccc4ccc5nc(-c6ccc7ccccc7c6)[se]c5c4c3)nc(-c3cccc4oc5ccccc5c34)n2)cc1 ; c1ccc(-c2nc3ccc4ccc(-c5nc(-c6ccc7ccccc7c6)nc(-c6cccc7oc8ccccc8c67)n5)cc4c3[se]2)cc1]

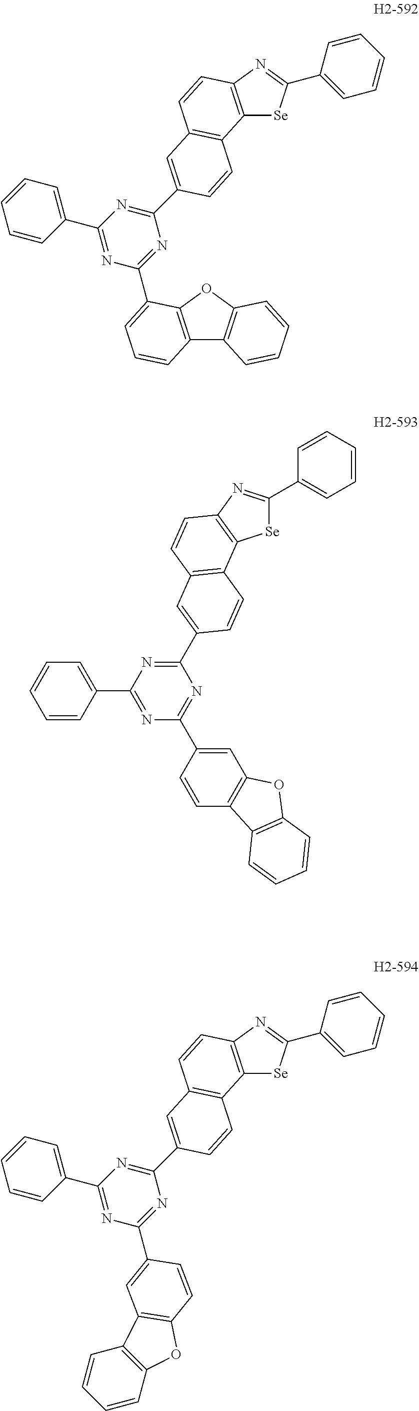 [SMILES: c1ccc(-c2nc(-c3ccc4c(ccc5nc(-c6ccccc6)[se]c54)c3)nc(-c3cccc4c3oc3ccccc34)n2)cc1 ; c1ccc(-c2nc(-c3ccc4c(ccc5nc(-c6ccccc6)[se]c54)c3)nc(-c3ccc4c(c3)oc3ccccc34)n2)cc1 ; c1ccc(-c2nc(-c3ccc4c(ccc5nc(-c6ccccc6)[se]c54)c3)nc(-c3ccc4oc5ccccc5c4c3)n2)cc1]

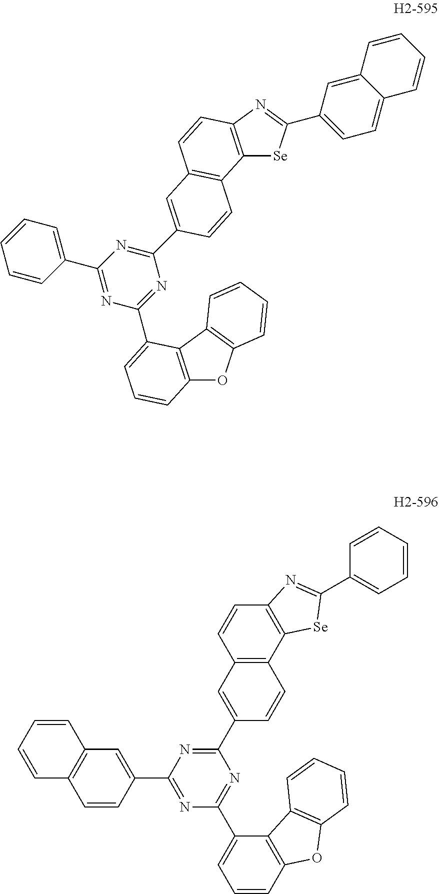 [SMILES: c1ccc(-c2nc(-c3ccc4c(ccc5nc(-c6ccc7ccccc7c6)[se]c54)c3)nc(-c3cccc4oc5ccccc5c34)n2)cc1 ; c1ccc(-c2nc3ccc4cc(-c5nc(-c6ccc7ccccc7c6)nc(-c6cccc7oc8ccccc8c67)n5)ccc4c3[se]2)cc1]

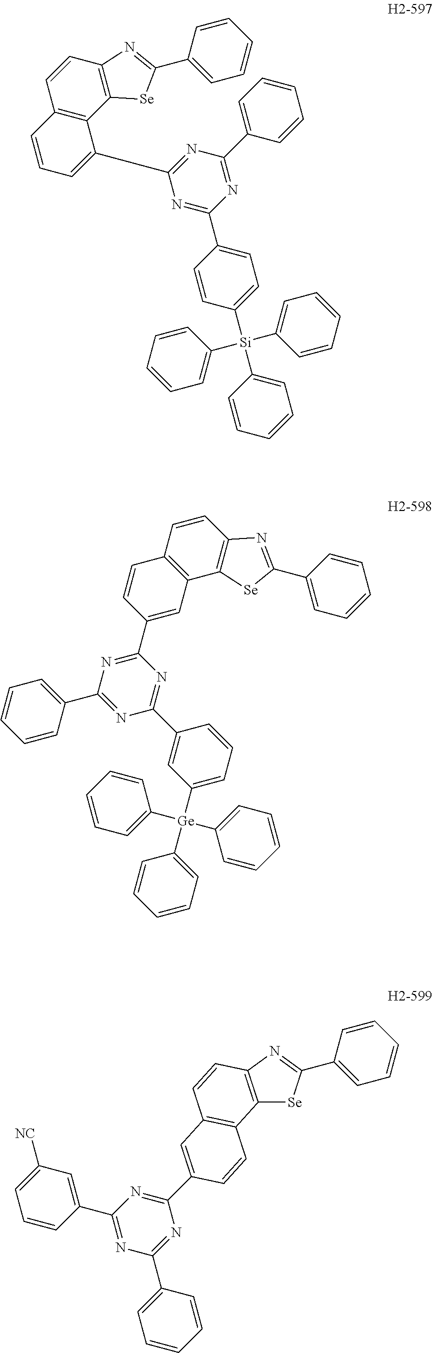

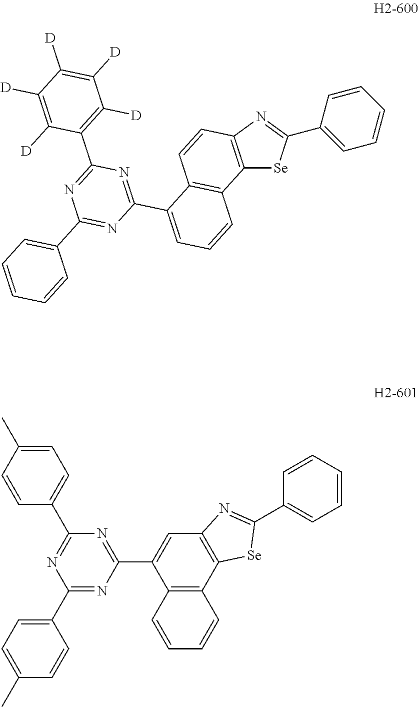 [SMILES: [2H]c1c([2H])c([2H])c(-c2nc(-c3ccccc3)nc(-c3cccc4c3ccc3nc(-c5ccccc5)[se]c34)n2)c([2H])c1[2H] ; Cc1ccc(-c2nc(-c3ccc(C)cc3)nc(-c3cc4nc(-c5ccccc5)[se]c4c4ccccc34)n2)cc1]

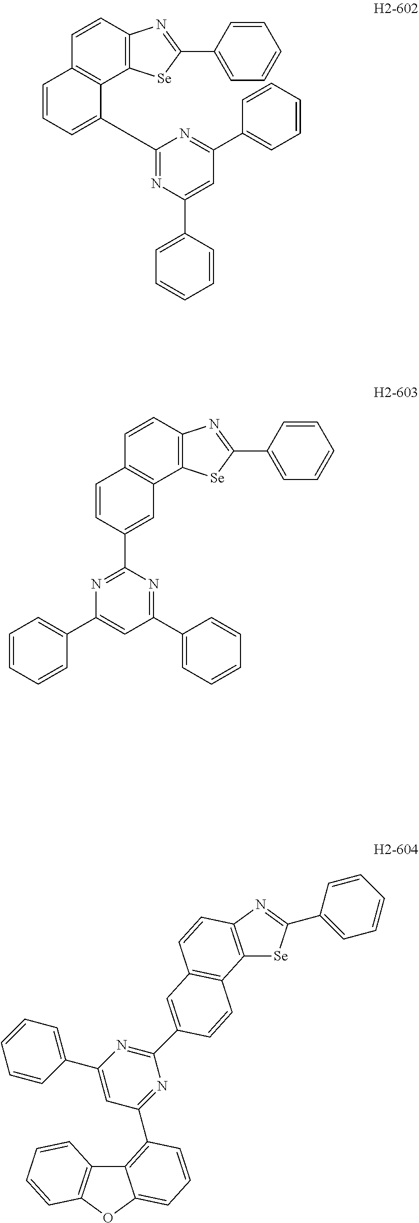 [SMILES: c1ccc(-c2cc(-c3ccccc3)nc(-c3cccc4ccc5nc(-c6ccccc6)[se]c5c34)n2)cc1 ; c1ccc(-c2cc(-c3ccccc3)nc(-c3ccc4ccc5nc(-c6ccccc6)[se]c5c4c3)n2)cc1 ; c1ccc(-c2cc(-c3cccc4oc5ccccc5c34)nc(-c3ccc4c(ccc5nc(-c6ccccc6)[se]c54)c3)n2)cc1]

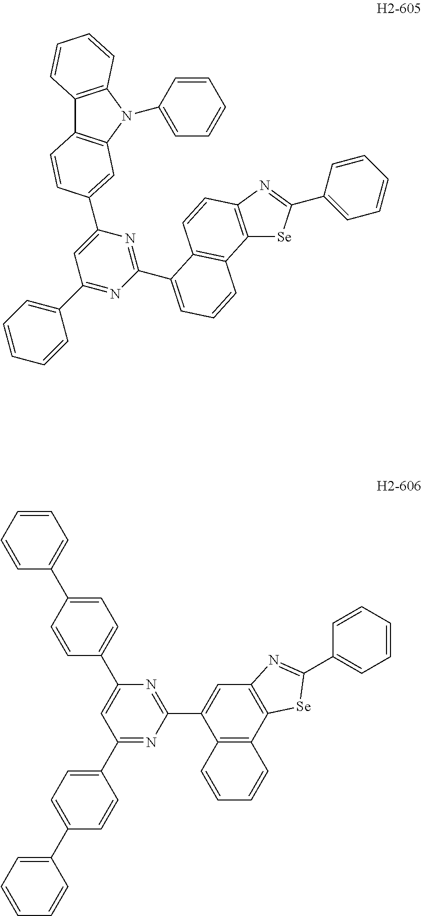 [SMILES: c1ccc(-c2cc(-c3ccc4c5ccccc5n(-c5ccccc5)c4c3)nc(-c3cccc4c3ccc3nc(-c5ccccc5)[se]c34)n2)cc1 ; c1ccc(-c2ccc(-c3cc(-c4ccc(-c5ccccc5)cc4)nc(-c4cc5nc(-c6ccccc6)[se]c5c5ccccc45)n3)cc2)cc1]

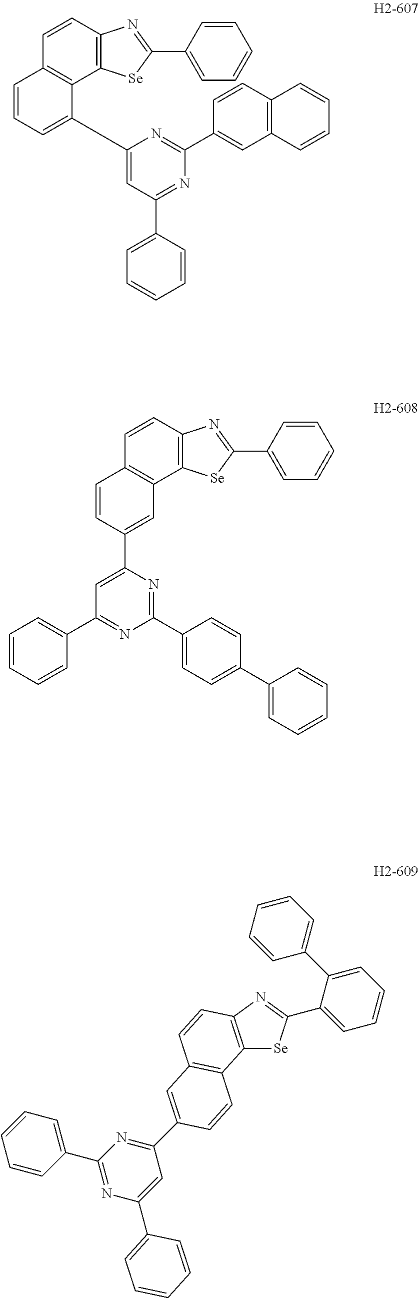 [SMILES: c1ccc(-c2cc(-c3cccc4ccc5nc(-c6ccccc6)[se]c5c34)nc(-c3ccc4ccccc4c3)n2)cc1 ; c1ccc(-c2ccc(-c3nc(-c4ccccc4)cc(-c4ccc5ccc6nc(-c7ccccc7)[se]c6c5c4)n3)cc2)cc1 ; c1ccc(-c2cc(-c3ccc4c(ccc5nc(-c6ccccc6-c6ccccc6)[se]c54)c3)nc(-c3ccccc3)n2)cc1]

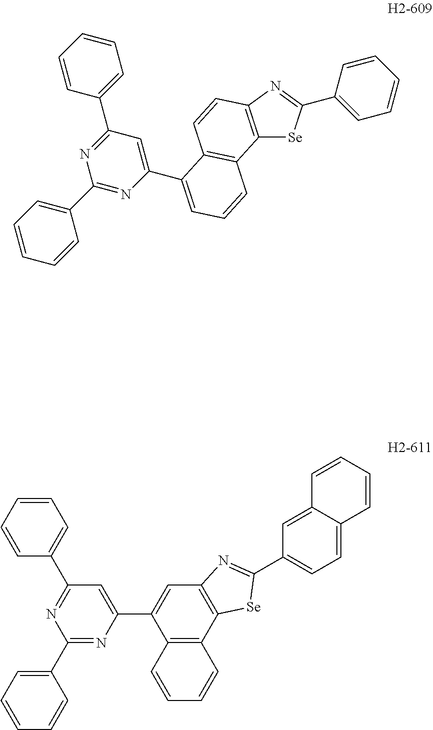 [SMILES: c1ccc(-c2cc(-c3cccc4c3ccc3nc(-c5ccccc5)[se]c34)nc(-c3ccccc3)n2)cc1 ; c1ccc(-c2cc(-c3cc4nc(-c5ccc6ccccc6c5)[se]c4c4ccccc34)nc(-c3ccccc3)n2)cc1]

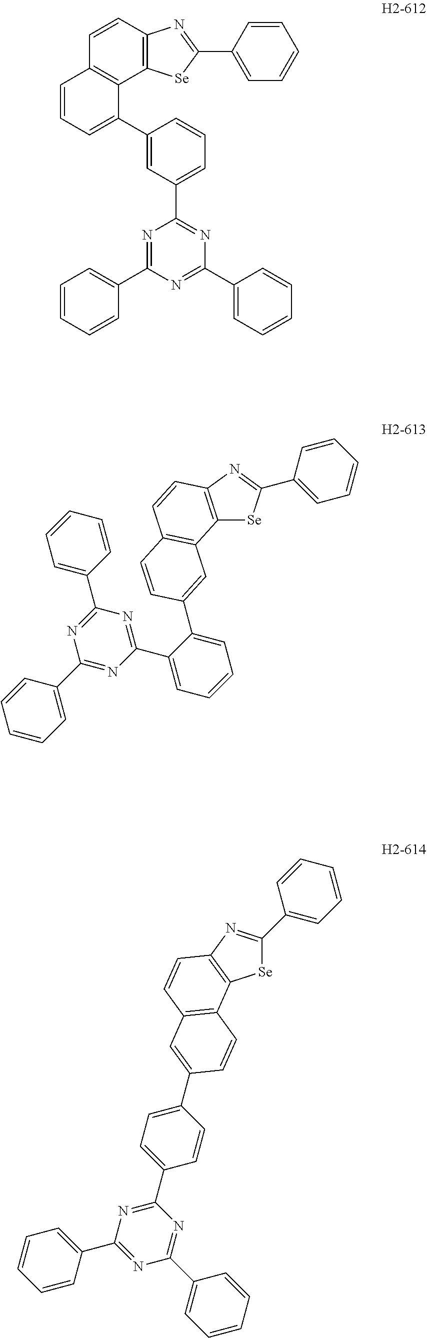 [SMILES: c1ccc(-c2nc(-c3ccccc3)nc(-c3cccc(-c4cccc5ccc6nc(-c7ccccc7)[se]c6c45)c3)n2)cc1 ; c1ccc(-c2nc(-c3ccccc3)nc(-c3ccccc3-c3ccc4ccc5nc(-c6ccccc6)[se]c5c4c3)n2)cc1 ; c1ccc(-c2nc(-c3ccccc3)nc(-c3ccc(-c4ccc5c(ccc6nc(-c7ccccc7)[se]c65)c4)cc3)n2)cc1]

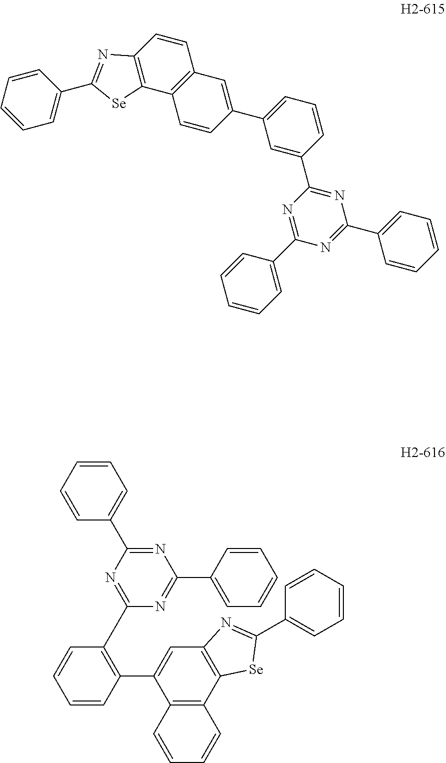 [SMILES: c1ccc(-c2nc(-c3ccccc3)nc(-c3cccc(-c4ccc5c(ccc6nc(-c7ccccc7)[se]c65)c4)c3)n2)cc1 ; c1ccc(-c2nc(-c3ccccc3)nc(-c3ccccc3-c3cc4nc(-c5ccccc5)[se]c4c4ccccc34)n2)cc1]

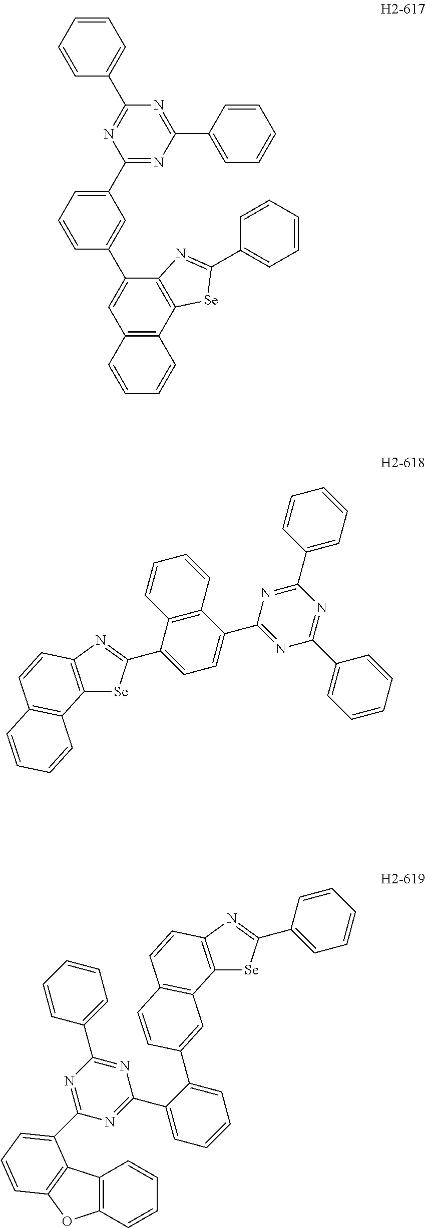 [SMILES: c1ccc(-c2nc(-c3ccccc3)nc(-c3cccc(-c4cc5ccccc5c5[se]c(-c6ccccc6)nc45)c3)n2)cc1 ; c1ccc(-c2nc(-c3ccccc3)nc(-c3ccc(-c4nc5ccc6ccccc6c5[se]4)c4ccccc34)n2)cc1 ; c1ccc(-c2nc(-c3ccccc3-c3ccc4ccc5nc(-c6ccccc6)[se]c5c4c3)nc(-c3cccc4oc5ccccc5c34)n2)cc1]

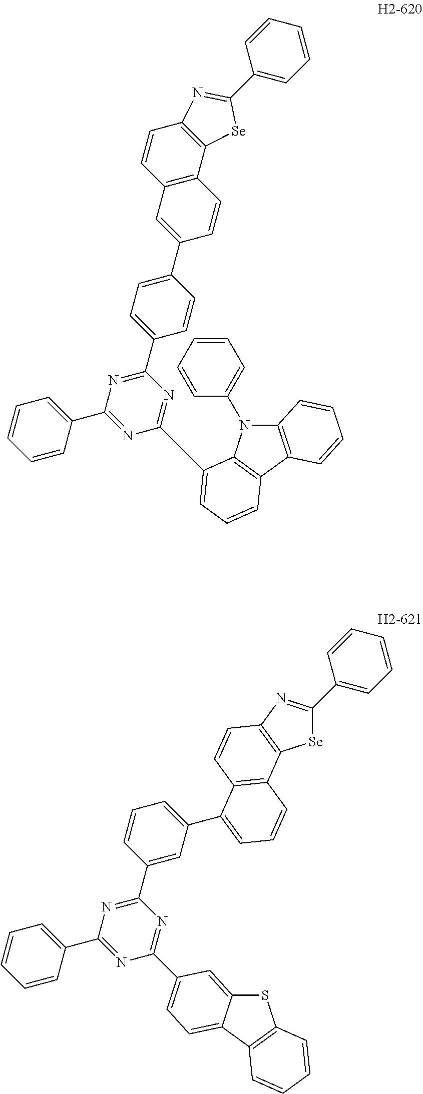 [SMILES: c1ccc(-c2nc(-c3ccc(-c4ccc5c(ccc6nc(-c7ccccc7)[se]c65)c4)cc3)nc(-c3cccc4c5ccccc5n(-c5ccccc5)c34)n2)cc1 ; c1ccc(-c2nc(-c3cccc(-c4cccc5c4ccc4nc(-c6ccccc6)[se]c45)c3)nc(-c3ccc4c(c3)sc3ccccc34)n2)cc1]

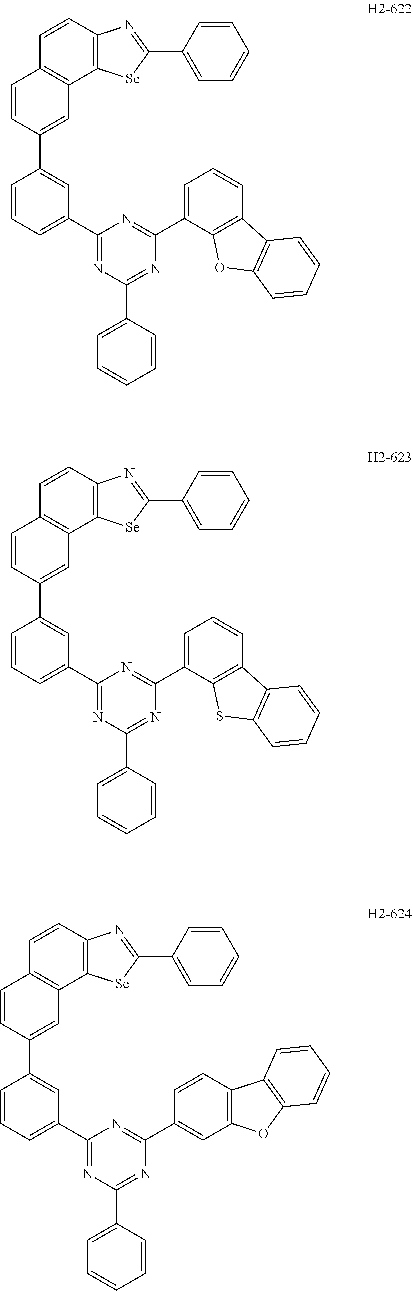 [SMILES: c1ccc(-c2nc(-c3cccc(-c4ccc5ccc6nc(-c7ccccc7)[se]c6c5c4)c3)nc(-c3cccc4c3oc3ccccc34)n2)cc1 ; c1ccc(-c2nc(-c3cccc(-c4ccc5ccc6nc(-c7ccccc7)[se]c6c5c4)c3)nc(-c3cccc4c3sc3ccccc34)n2)cc1 ; c1ccc(-c2nc(-c3cccc(-c4ccc5ccc6nc(-c7ccccc7)[se]c6c5c4)c3)nc(-c3ccc4c(c3)oc3ccccc34)n2)cc1]

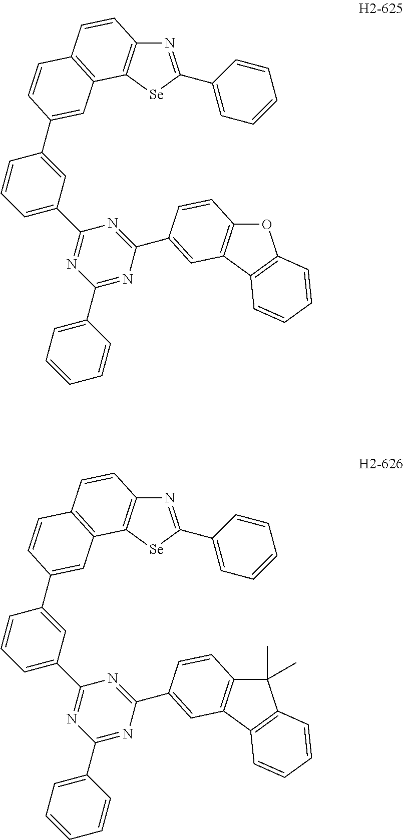 [SMILES: c1ccc(-c2nc(-c3cccc(-c4ccc5ccc6nc(-c7ccccc7)[se]c6c5c4)c3)nc(-c3ccc4oc5ccccc5c4c3)n2)cc1 ; CC1(C)c2ccccc2-c2cc(-c3nc(-c4ccccc4)nc(-c4cccc(-c5ccc6ccc7nc(-c8ccccc8)[se]c7c6c5)c4)n3)ccc21]

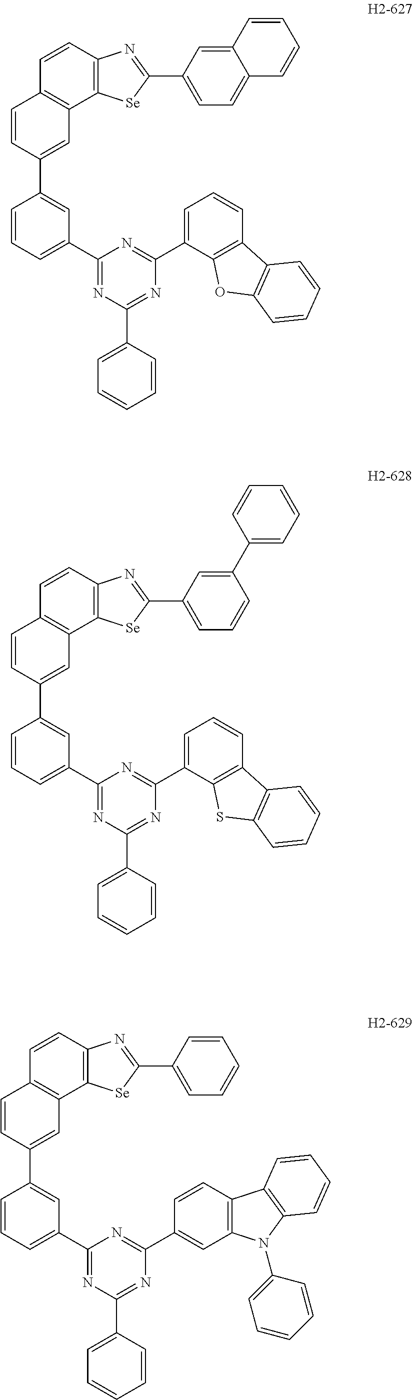 [SMILES: c1ccc(-c2nc(-c3cccc(-c4ccc5ccc6nc(-c7ccc8ccccc8c7)[se]c6c5c4)c3)nc(-c3cccc4c3oc3ccccc34)n2)cc1 ; c1ccc(-c2cccc(-c3nc4ccc5ccc(-c6cccc(-c7nc(-c8ccccc8)nc(-c8cccc9c8sc8ccccc89)n7)c6)cc5c4[se]3)c2)cc1 ; c1ccc(-c2nc(-c3cccc(-c4ccc5ccc6nc(-c7ccccc7)[se]c6c5c4)c3)nc(-c3ccc4c5ccccc5n(-c5ccccc5)c4c3)n2)cc1]

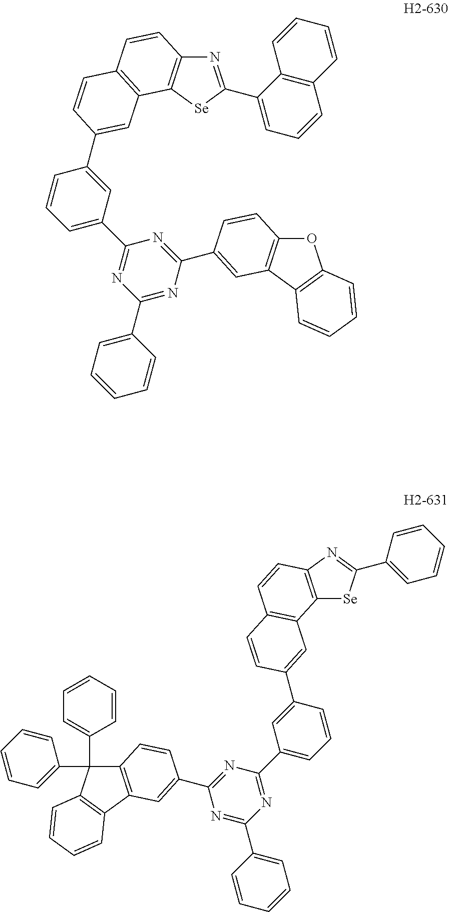 [SMILES: c1ccc(-c2nc(-c3cccc(-c4ccc5ccc6nc(-c7cccc8ccccc78)[se]c6c5c4)c3)nc(-c3ccc4oc5ccccc5c4c3)n2)cc1 ; c1ccc(-c2nc(-c3cccc(-c4ccc5ccc6nc(-c7ccccc7)[se]c6c5c4)c3)nc(-c3ccc4c(c3)-c3ccccc3C4(c3ccccc3)c3ccccc3)n2)cc1]

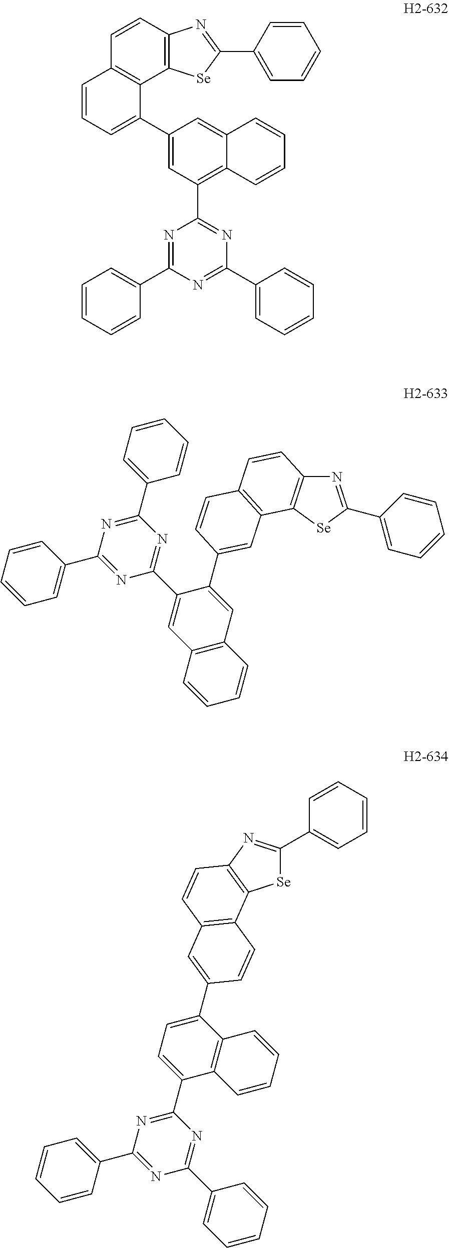 [SMILES: c1ccc(-c2nc(-c3ccccc3)nc(-c3cc(-c4cccc5ccc6nc(-c7ccccc7)[se]c6c45)cc4ccccc34)n2)cc1 ; c1ccc(-c2nc(-c3ccccc3)nc(-c3cc4ccccc4cc3-c3ccc4ccc5nc(-c6ccccc6)[se]c5c4c3)n2)cc1 ; c1ccc(-c2nc(-c3ccccc3)nc(-c3ccc(-c4ccc5c(ccc6nc(-c7ccccc7)[se]c65)c4)c4ccccc34)n2)cc1]

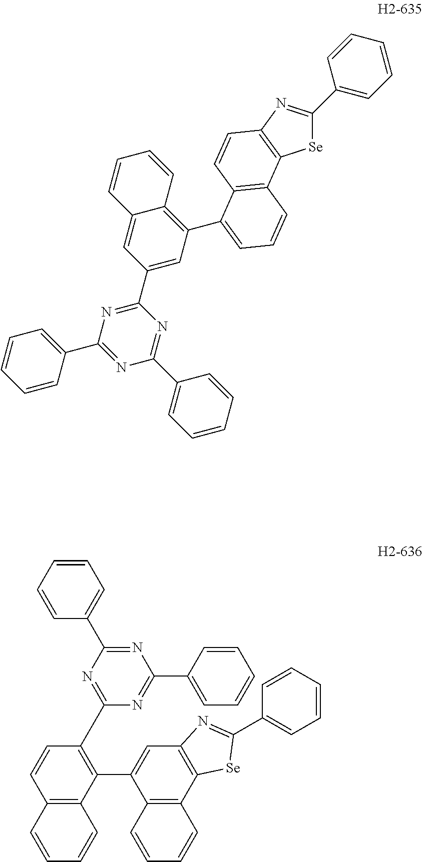 [SMILES: c1ccc(-c2nc(-c3ccccc3)nc(-c3cc(-c4cccc5c4ccc4nc(-c6ccccc6)[se]c45)c4ccccc4c3)n2)cc1 ; c1ccc(-c2nc(-c3ccccc3)nc(-c3ccc4ccccc4c3-c3cc4nc(-c5ccccc5)[se]c4c4ccccc34)n2)cc1]

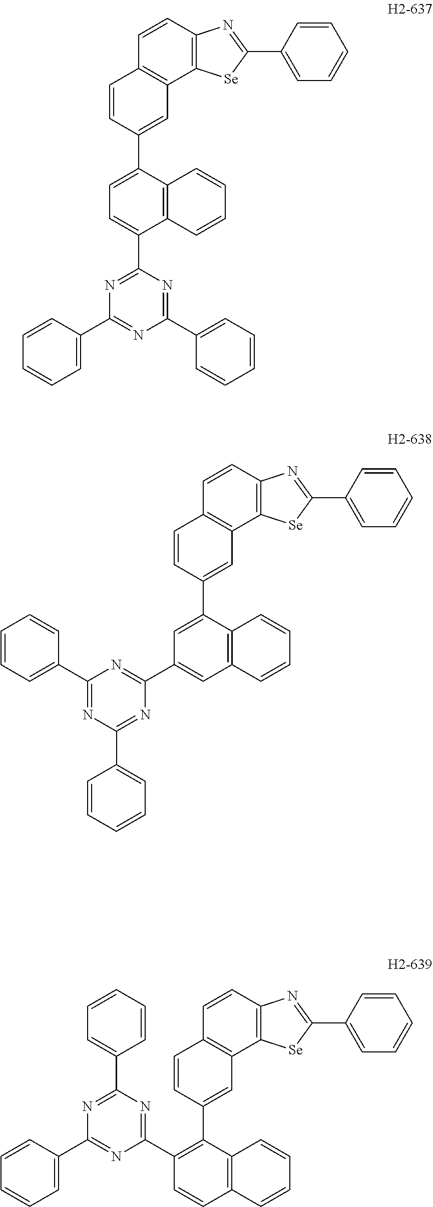 [SMILES: c1ccc(-c2nc(-c3ccccc3)nc(-c3ccc(-c4ccc5ccc6nc(-c7ccccc7)[se]c6c5c4)c4ccccc34)n2)cc1 ; c1ccc(-c2nc(-c3ccccc3)nc(-c3cc(-c4ccc5ccc6nc(-c7ccccc7)[se]c6c5c4)c4ccccc4c3)n2)cc1 ; c1ccc(-c2nc(-c3ccccc3)nc(-c3ccc4ccccc4c3-c3ccc4ccc5nc(-c6ccccc6)[se]c5c4c3)n2)cc1]

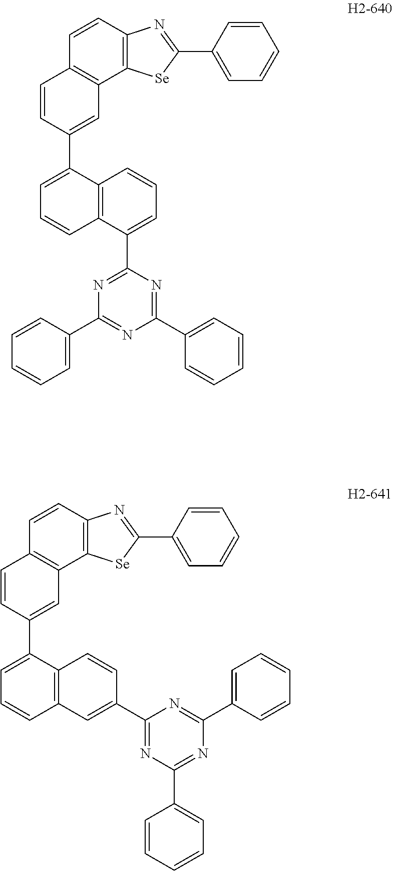 [SMILES: c1ccc(-c2nc(-c3ccccc3)nc(-c3cccc4c(-c5ccc6ccc7nc(-c8ccccc8)[se]c7c6c5)cccc34)n2)cc1 ; c1ccc(-c2nc(-c3ccccc3)nc(-c3ccc4c(-c5ccc6ccc7nc(-c8ccccc8)[se]c7c6c5)cccc4c3)n2)cc1]

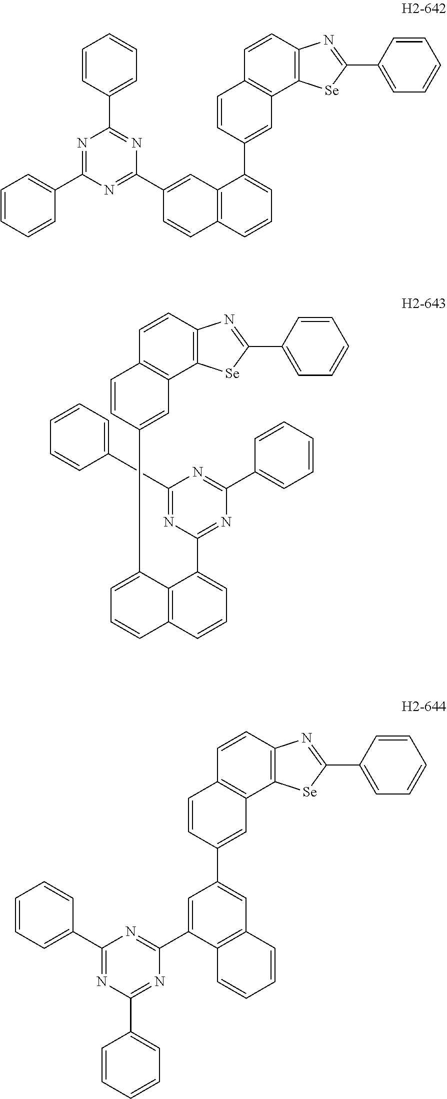 [SMILES: c1ccc(-c2nc(-c3ccccc3)nc(-c3ccc4cccc(-c5ccc6ccc7nc(-c8ccccc8)[se]c7c6c5)c4c3)n2)cc1 ; c1ccc(-c2nc(-c3ccccc3)nc(-c3cccc4cccc(-c5ccc6ccc7nc(-c8ccccc8)[se]c7c6c5)c34)n2)cc1 ; c1ccc(-c2nc(-c3ccccc3)nc(-c3cc(-c4ccc5ccc6nc(-c7ccccc7)[se]c6c5c4)cc4ccccc34)n2)cc1]

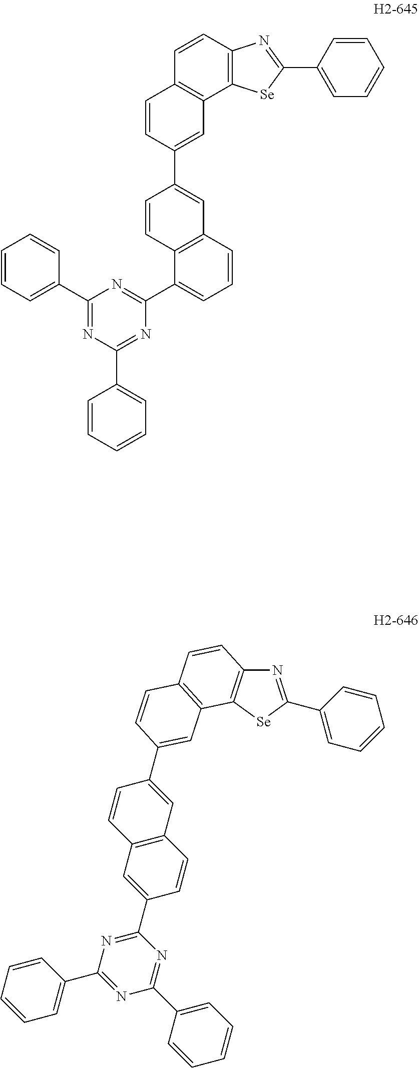 [SMILES: c1ccc(-c2nc(-c3ccccc3)nc(-c3cccc4cc(-c5ccc6ccc7nc(-c8ccccc8)[se]c7c6c5)ccc34)n2)cc1 ; c1ccc(-c2nc(-c3ccccc3)nc(-c3ccc4cc(-c5ccc6ccc7nc(-c8ccccc8)[se]c7c6c5)ccc4c3)n2)cc1]

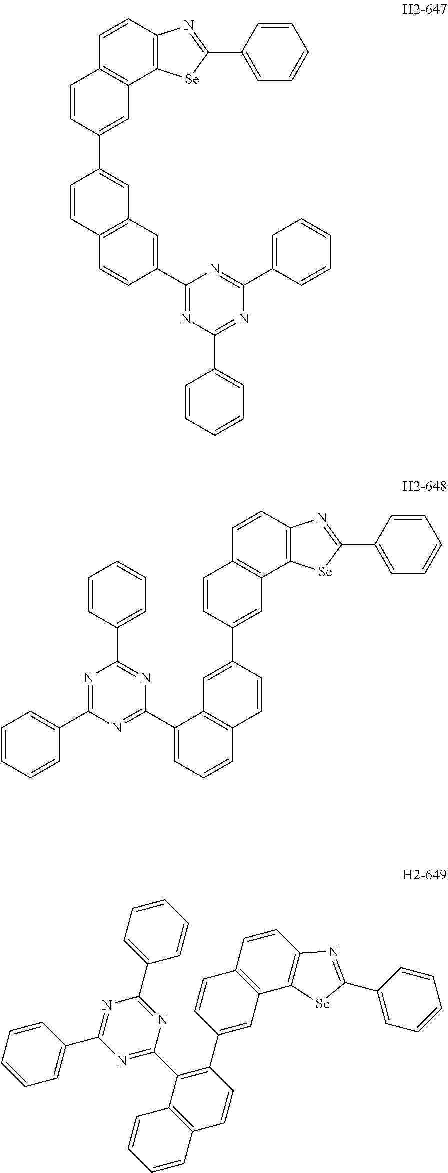

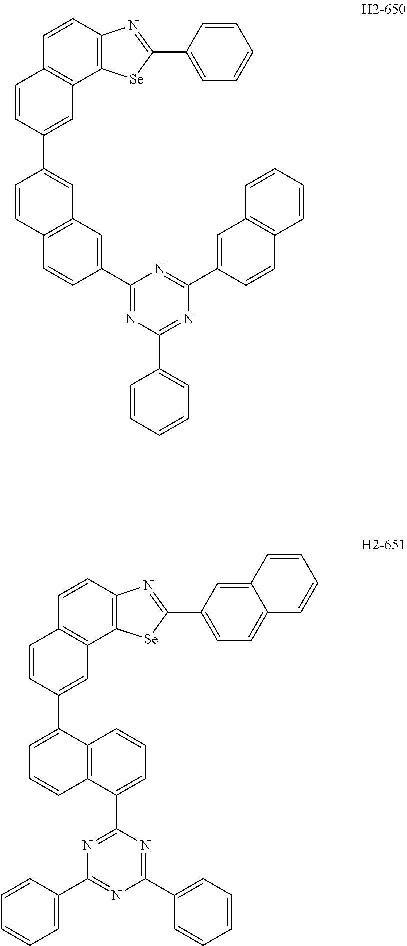 [SMILES: c1ccc(-c2nc(-c3ccc4ccccc4c3)nc(-c3ccc4ccc(-c5ccc6ccc7nc(-c8ccccc8)[se]c7c6c5)cc4c3)n2)cc1 ; c1ccc(-c2nc(-c3ccccc3)nc(-c3cccc4c(-c5ccc6ccc7nc(-c8ccc9ccccc9c8)[se]c7c6c5)cccc34)n2)cc1]

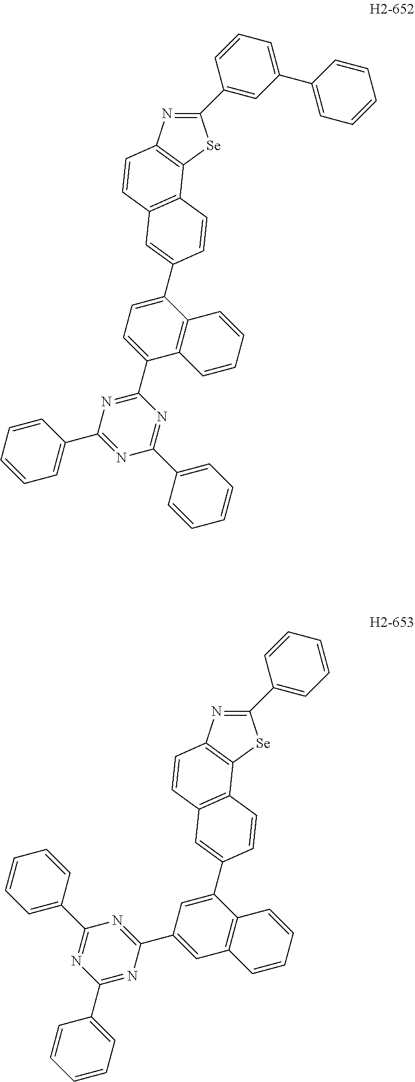 [SMILES: c1ccc(-c2cccc(-c3nc4ccc5cc(-c6ccc(-c7nc(-c8ccccc8)nc(-c8ccccc8)n7)c7ccccc67)ccc5c4[se]3)c2)cc1 ; c1ccc(-c2nc(-c3ccccc3)nc(-c3cc(-c4ccc5c(ccc6nc(-c7ccccc7)[se]c65)c4)c4ccccc4c3)n2)cc1]

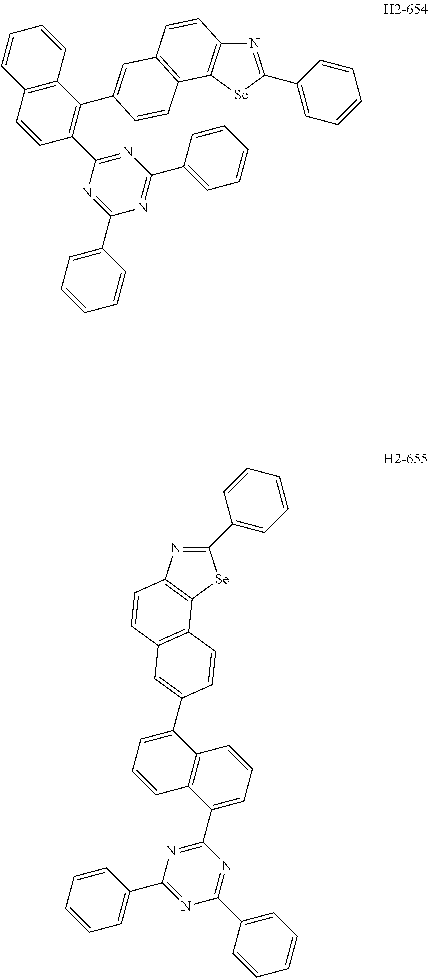 [SMILES: c1ccc(-c2nc(-c3ccccc3)nc(-c3ccc4ccccc4c3-c3ccc4c(ccc5nc(-c6ccccc6)[se]c54)c3)n2)cc1 ; c1ccc(-c2nc(-c3ccccc3)nc(-c3cccc4c(-c5ccc6c(ccc7nc(-c8ccccc8)[se]c76)c5)cccc34)n2)cc1]

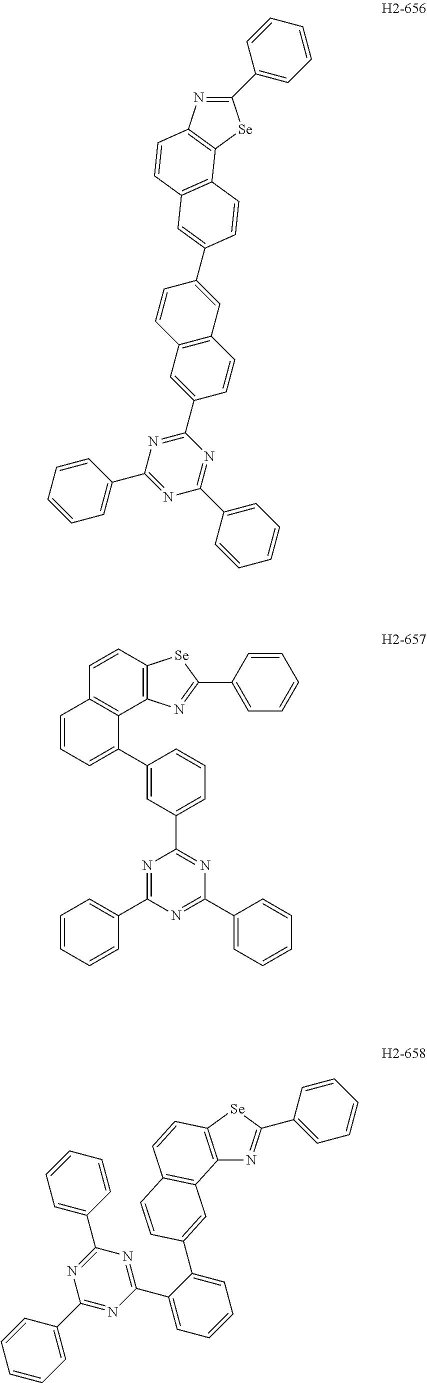 [SMILES: c1ccc(-c2nc(-c3ccccc3)nc(-c3ccc4cc(-c5ccc6c(ccc7nc(-c8ccccc8)[se]c76)c5)ccc4c3)n2)cc1 ; c1ccc(-c2nc(-c3ccccc3)nc(-c3cccc(-c4cccc5ccc6[se]c(-c7ccccc7)nc6c45)c3)n2)cc1 ; c1ccc(-c2nc(-c3ccccc3)nc(-c3ccccc3-c3ccc4ccc5[se]c(-c6ccccc6)nc5c4c3)n2)cc1]

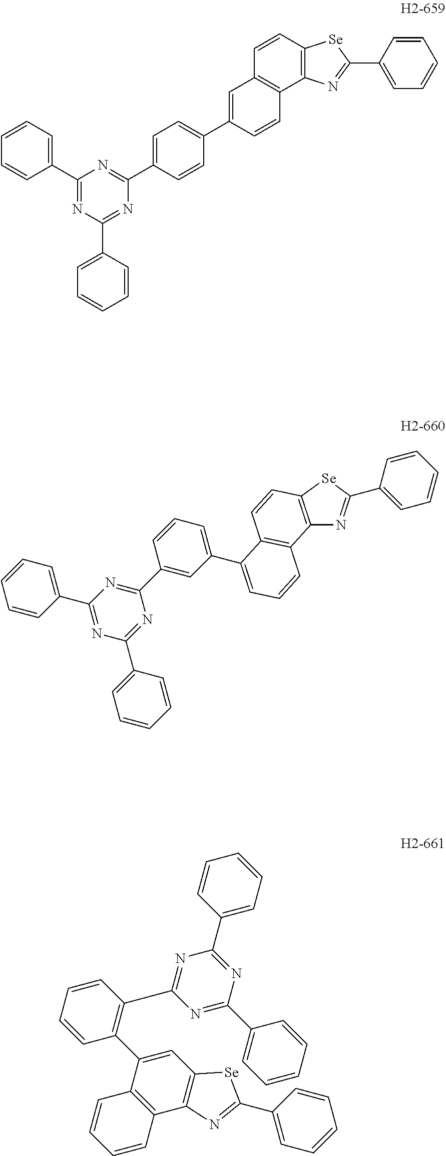 [SMILES: c1ccc(-c2nc(-c3ccccc3)nc(-c3ccc(-c4ccc5c(ccc6[se]c(-c7ccccc7)nc65)c4)cc3)n2)cc1 ; c1ccc(-c2nc(-c3ccccc3)nc(-c3cccc(-c4cccc5c4ccc4[se]c(-c6ccccc6)nc45)c3)n2)cc1 ; c1ccc(-c2nc(-c3ccccc3)nc(-c3ccccc3-c3cc4[se]c(-c5ccccc5)nc4c4ccccc34)n2)cc1]

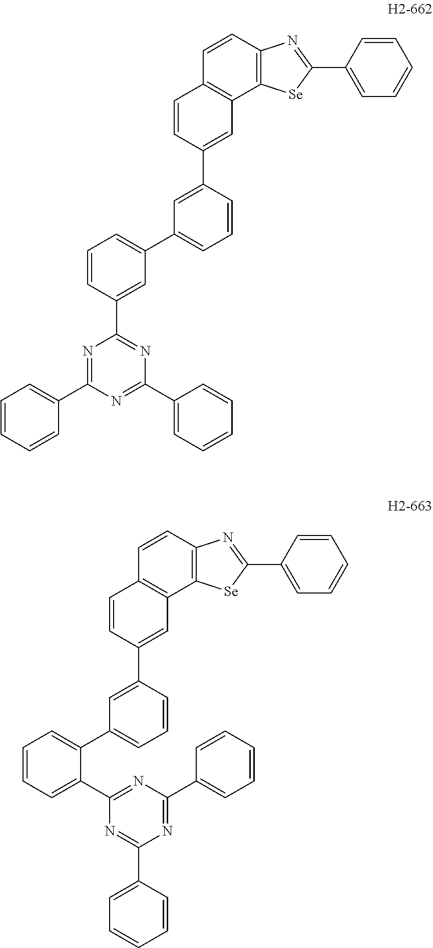 [SMILES: c1ccc(-c2nc(-c3ccccc3)nc(-c3cccc(-c4cccc(-c5ccc6ccc7nc(-c8ccccc8)[se]c7c6c5)c4)c3)n2)cc1 ; c1ccc(-c2nc(-c3ccccc3)nc(-c3ccccc3-c3cccc(-c4ccc5ccc6nc(-c7ccccc7)[se]c6c5c4)c3)n2)cc1]

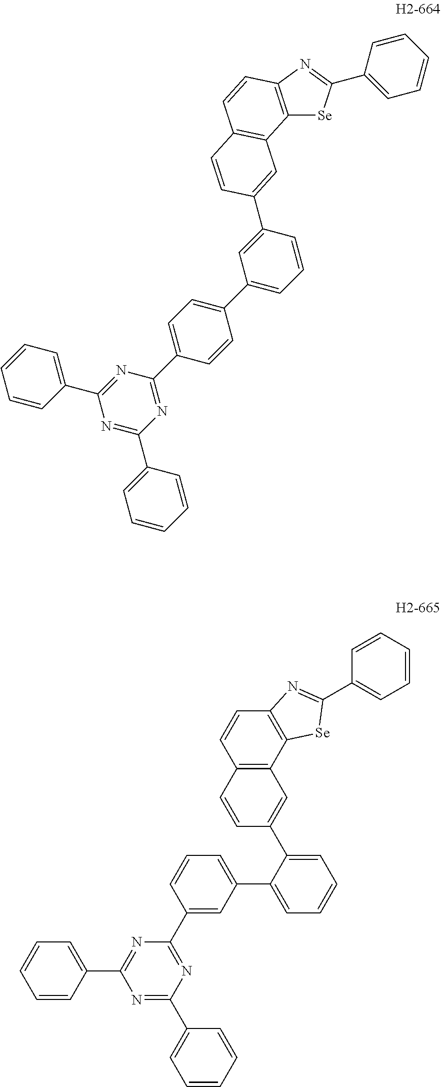 [SMILES: c1ccc(-c2nc(-c3ccccc3)nc(-c3ccc(-c4cccc(-c5ccc6ccc7nc(-c8ccccc8)[se]c7c6c5)c4)cc3)n2)cc1 ; c1ccc(-c2nc(-c3ccccc3)nc(-c3cccc(-c4ccccc4-c4ccc5ccc6nc(-c7ccccc7)[se]c6c5c4)c3)n2)cc1]

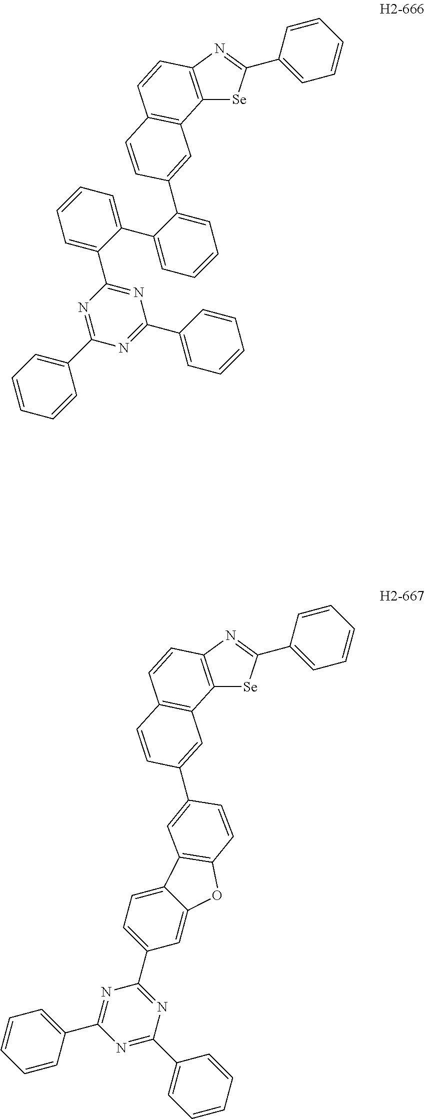 [SMILES: c1ccc(-c2nc(-c3ccccc3)nc(-c3ccccc3-c3ccccc3-c3ccc4ccc5nc(-c6ccccc6)[se]c5c4c3)n2)cc1 ; c1ccc(-c2nc(-c3ccccc3)nc(-c3ccc4c(c3)oc3ccc(-c5ccc6ccc7nc(-c8ccccc8)[se]c7c6c5)cc34)n2)cc1]

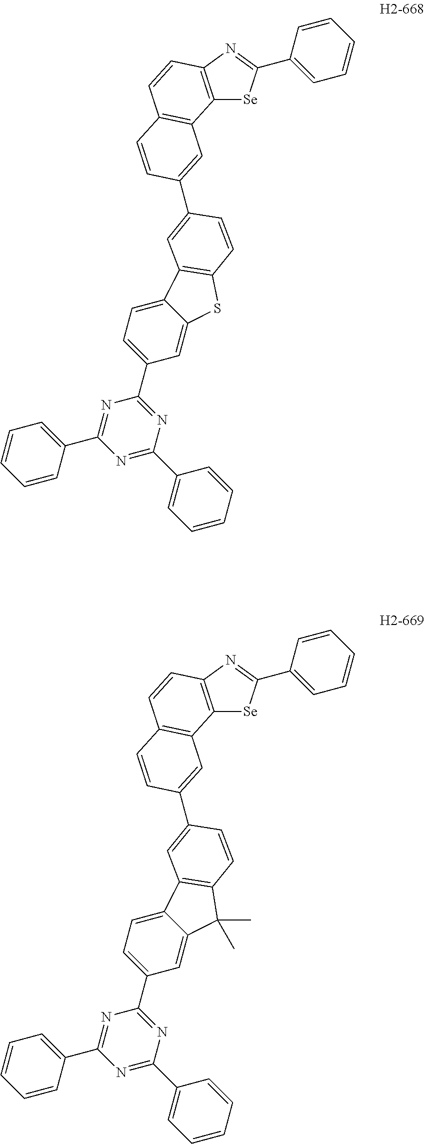 [SMILES: c1ccc(-c2nc(-c3ccccc3)nc(-c3ccc4c(c3)sc3ccc(-c5ccc6ccc7nc(-c8ccccc8)[se]c7c6c5)cc34)n2)cc1 ; CC1(C)c2ccc(-c3ccc4ccc5nc(-c6ccccc6)[se]c5c4c3)cc2-c2ccc(-c3nc(-c4ccccc4)nc(-c4ccccc4)n3)cc21]

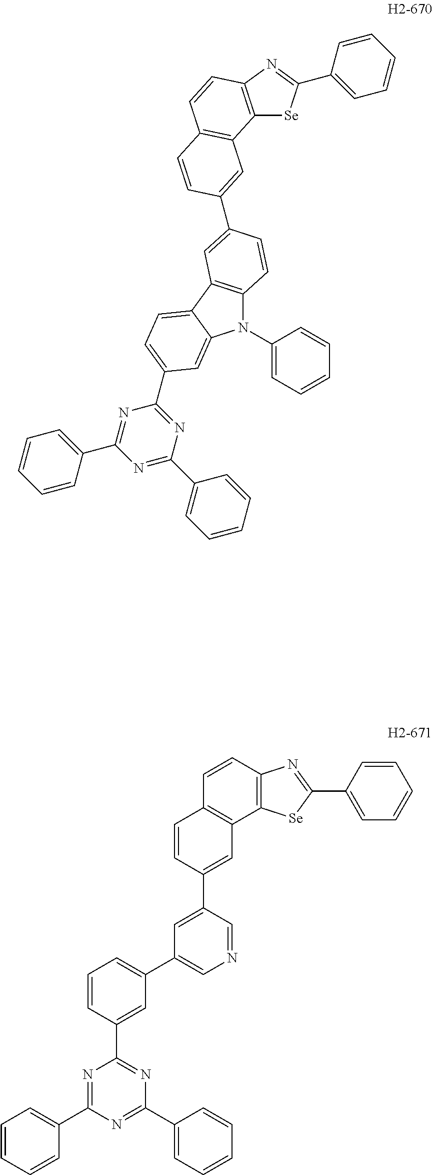 [SMILES: c1ccc(-c2nc(-c3ccccc3)nc(-c3ccc4c5cc(-c6ccc7ccc8nc(-c9ccccc9)[se]c8c7c6)ccc5n(-c5ccccc5)c4c3)n2)cc1 ; c1ccc(-c2nc(-c3ccccc3)nc(-c3cccc(-c4cncc(-c5ccc6ccc7nc(-c8ccccc8)[se]c7c6c5)c4)c3)n2)cc1]

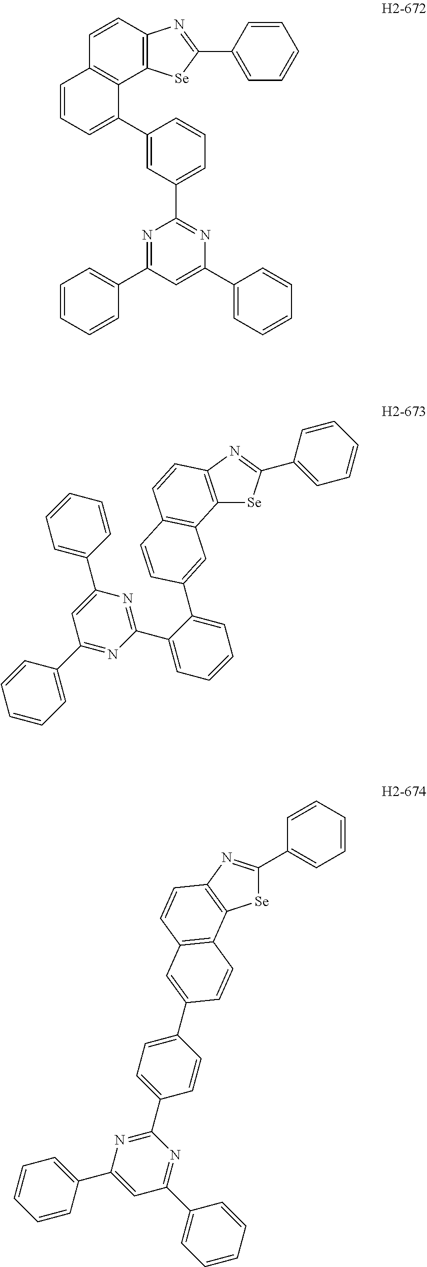 [SMILES: c1ccc(-c2cc(-c3ccccc3)nc(-c3cccc(-c4cccc5ccc6nc(-c7ccccc7)[se]c6c45)c3)n2)cc1 ; c1ccc(-c2cc(-c3ccccc3)nc(-c3ccccc3-c3ccc4ccc5nc(-c6ccccc6)[se]c5c4c3)n2)cc1 ; c1ccc(-c2cc(-c3ccccc3)nc(-c3ccc(-c4ccc5c(ccc6nc(-c7ccccc7)[se]c65)c4)cc3)n2)cc1]

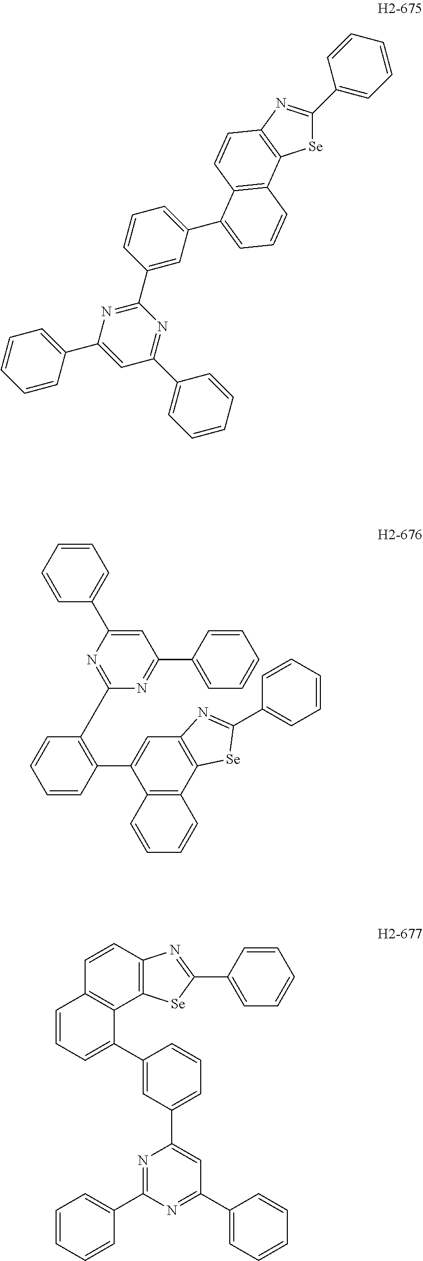 [SMILES: c1ccc(-c2cc(-c3ccccc3)nc(-c3cccc(-c4cccc5c4ccc4nc(-c6ccccc6)[se]c45)c3)n2)cc1 ; c1ccc(-c2cc(-c3ccccc3)nc(-c3ccccc3-c3cc4nc(-c5ccccc5)[se]c4c4ccccc34)n2)cc1 ; c1ccc(-c2cc(-c3cccc(-c4cccc5ccc6nc(-c7ccccc7)[se]c6c45)c3)nc(-c3ccccc3)n2)cc1]

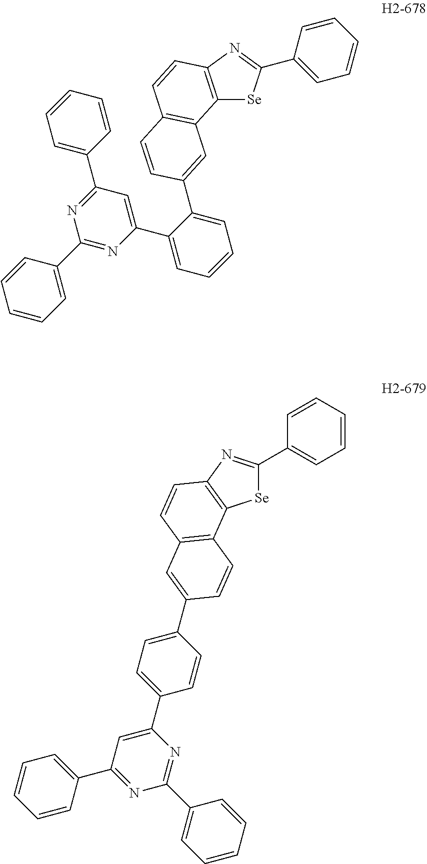 [SMILES: c1ccc(-c2cc(-c3ccccc3-c3ccc4ccc5nc(-c6ccccc6)[se]c5c4c3)nc(-c3ccccc3)n2)cc1 ; c1ccc(-c2cc(-c3ccc(-c4ccc5c(ccc6nc(-c7ccccc7)[se]c65)c4)cc3)nc(-c3ccccc3)n2)cc1]

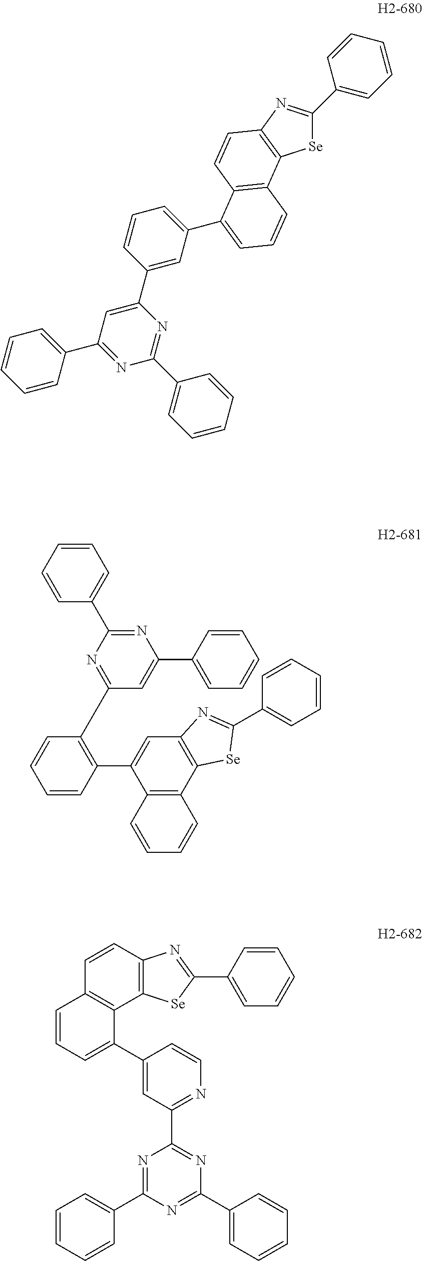 [SMILES: c1ccc(-c2cc(-c3cccc(-c4cccc5c4ccc4nc(-c6ccccc6)[se]c45)c3)nc(-c3ccccc3)n2)cc1 ; c1ccc(-c2cc(-c3ccccc3-c3cc4nc(-c5ccccc5)[se]c4c4ccccc34)nc(-c3ccccc3)n2)cc1 ; c1ccc(-c2nc(-c3ccccc3)nc(-c3cc(-c4cccc5ccc6nc(-c7ccccc7)[se]c6c45)ccn3)n2)cc1]

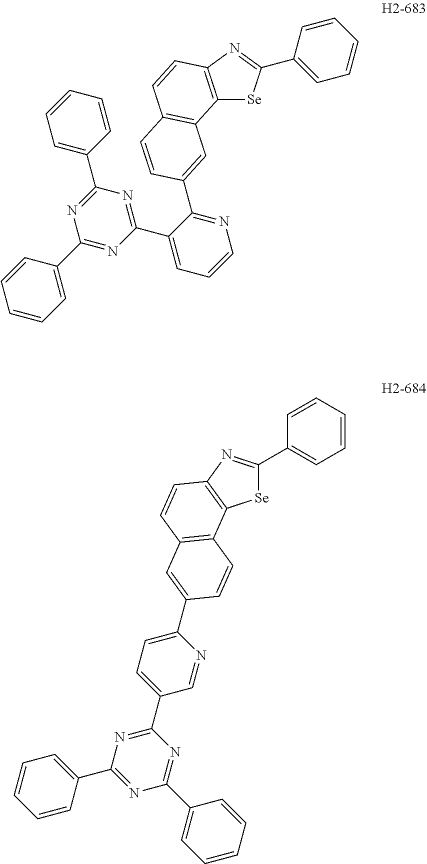 [SMILES: c1ccc(-c2nc(-c3ccccc3)nc(-c3cccnc3-c3ccc4ccc5nc(-c6ccccc6)[se]c5c4c3)n2)cc1 ; c1ccc(-c2nc(-c3ccccc3)nc(-c3ccc(-c4ccc5c(ccc6nc(-c7ccccc7)[se]c65)c4)nc3)n2)cc1]

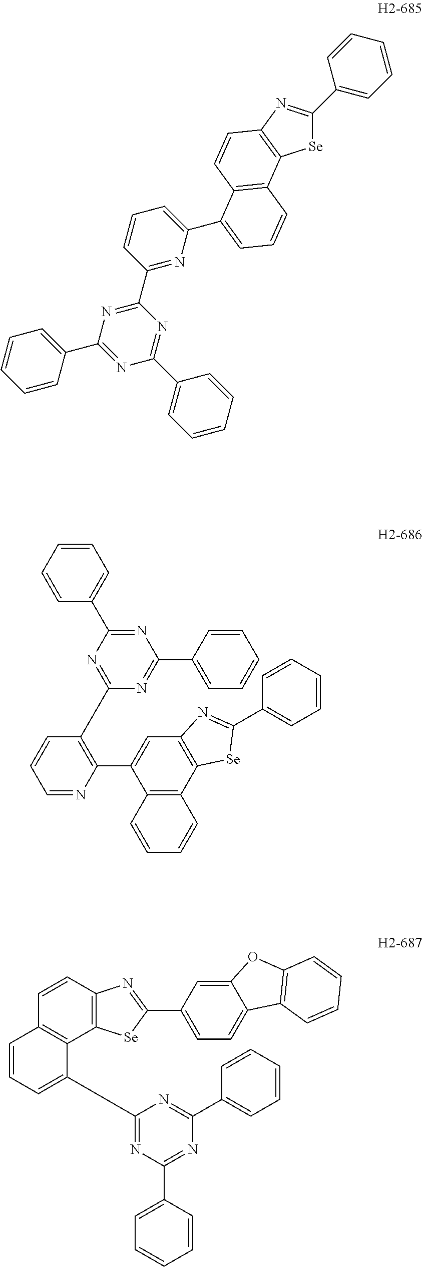 [SMILES: c1ccc(-c2nc(-c3ccccc3)nc(-c3cccc(-c4cccc5c4ccc4nc(-c6ccccc6)[se]c45)n3)n2)cc1 ; c1ccc(-c2nc(-c3ccccc3)nc(-c3cccnc3-c3cc4nc(-c5ccccc5)[se]c4c4ccccc34)n2)cc1 ; c1ccc(-c2nc(-c3ccccc3)nc(-c3cccc4ccc5nc(-c6ccc7c(c6)oc6ccccc67)[se]c5c34)n2)cc1]

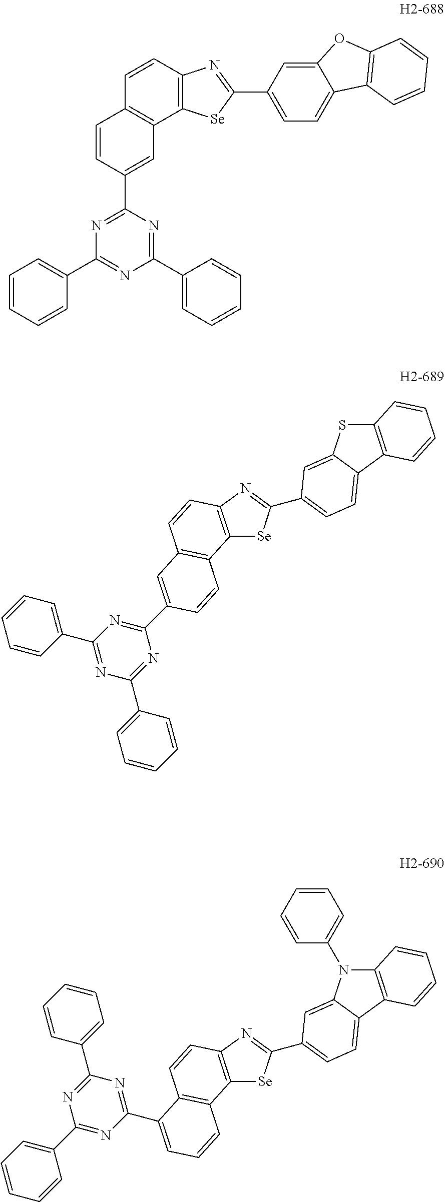 [SMILES: c1ccc(-c2nc(-c3ccccc3)nc(-c3ccc4ccc5nc(-c6ccc7c(c6)oc6ccccc67)[se]c5c4c3)n2)cc1 ; c1ccc(-c2nc(-c3ccccc3)nc(-c3ccc4c(ccc5nc(-c6ccc7c(c6)sc6ccccc67)[se]c54)c3)n2)cc1 ; c1ccc(-c2nc(-c3ccccc3)nc(-c3cccc4c3ccc3nc(-c5ccc6c7ccccc7n(-c7ccccc7)c6c5)[se]c34)n2)cc1]

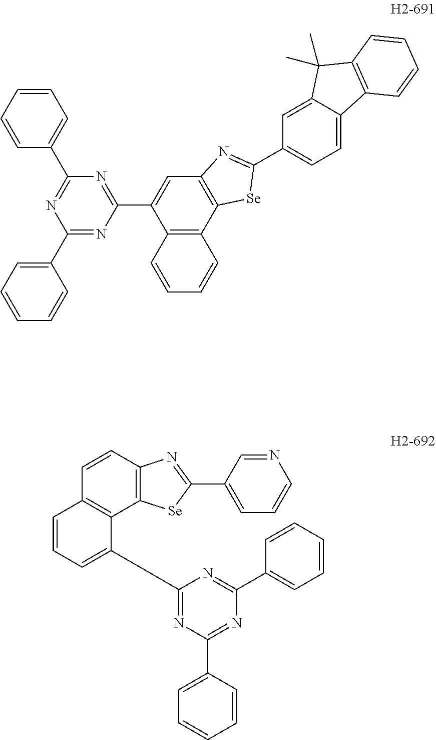 [SMILES: CC1(C)c2ccccc2-c2ccc(-c3nc4cc(-c5nc(-c6ccccc6)nc(-c6ccccc6)n5)c5ccccc5c4[se]3)cc21 ; c1ccc(-c2nc(-c3ccccc3)nc(-c3cccc4ccc5nc(-c6cccnc6)[se]c5c34)n2)cc1]

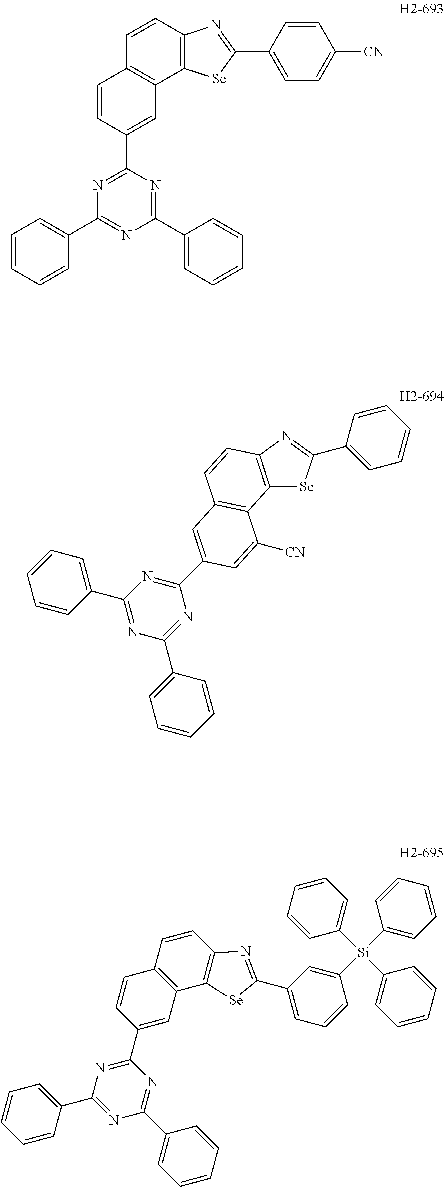 [SMILES: N#Cc1ccc(-c2nc3ccc4ccc(-c5nc(-c6ccccc6)nc(-c6ccccc6)n5)cc4c3[se]2)cc1 ; N#Cc1cc(-c2nc(-c3ccccc3)nc(-c3ccccc3)n2)cc2ccc3nc(-c4ccccc4)[se]c3c12 ; c1ccc(-c2nc(-c3ccccc3)nc(-c3ccc4ccc5nc(-c6cccc([Si](c7ccccc7)(c7ccccc7)c7ccccc7)c6)[se]c5c4c3)n2)cc1]

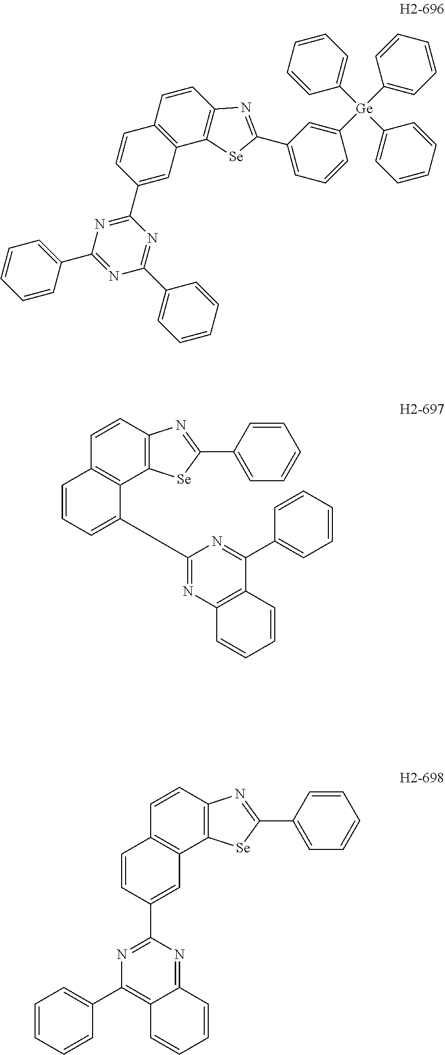

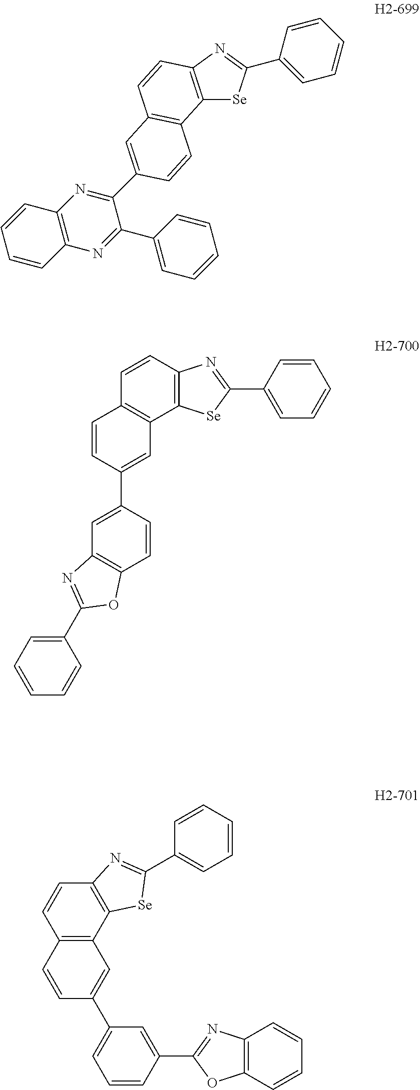 [SMILES: c1ccc(-c2nc3ccc4cc(-c5nc6ccccc6nc5-c5ccccc5)ccc4c3[se]2)cc1 ; c1ccc(-c2nc3cc(-c4ccc5ccc6nc(-c7ccccc7)[se]c6c5c4)ccc3o2)cc1 ; c1ccc(-c2nc3ccc4ccc(-c5cccc(-c6nc7ccccc7o6)c5)cc4c3[se]2)cc1]

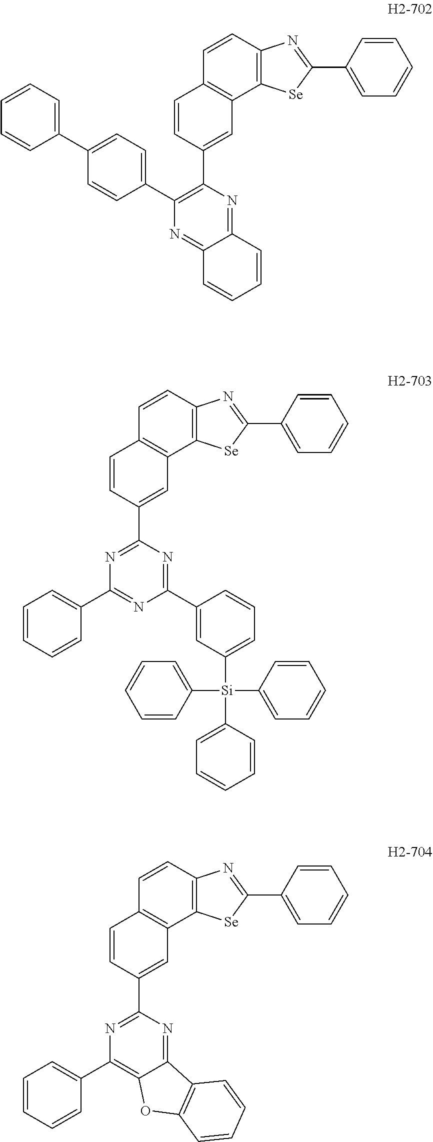 [SMILES: c1ccc(-c2ccc(-c3nc4ccccc4nc3-c3ccc4ccc5nc(-c6ccccc6)[se]c5c4c3)cc2)cc1 ; c1ccc(-c2nc(-c3cccc([Si](c4ccccc4)(c4ccccc4)c4ccccc4)c3)nc(-c3ccc4ccc5nc(-c6ccccc6)[se]c5c4c3)n2)cc1 ; c1ccc(-c2nc3ccc4ccc(-c5nc(-c6ccccc6)c6oc7ccccc7c6n5)cc4c3[se]2)cc1]

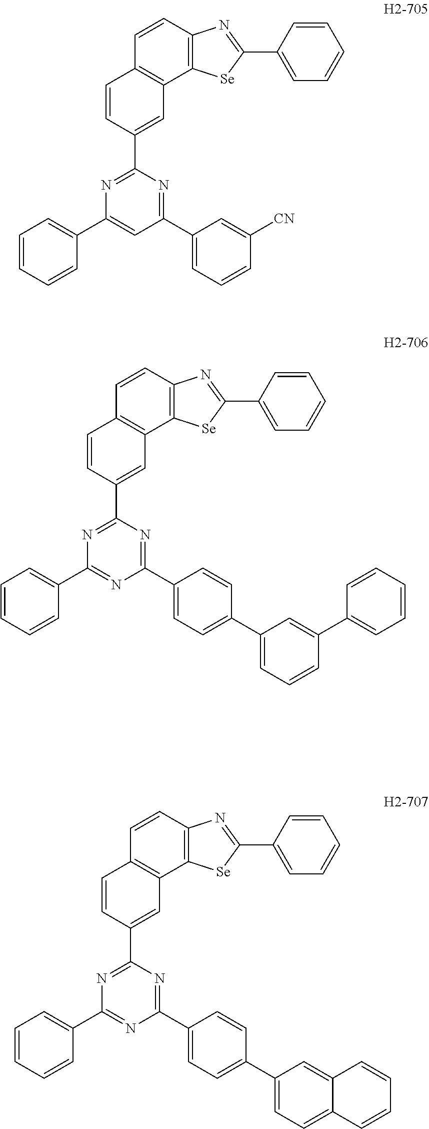 [SMILES: N#Cc1cccc(-c2cc(-c3ccccc3)nc(-c3ccc4ccc5nc(-c6ccccc6)[se]c5c4c3)n2)c1 ; c1ccc(-c2cccc(-c3ccc(-c4nc(-c5ccccc5)nc(-c5ccc6ccc7nc(-c8ccccc8)[se]c7c6c5)n4)cc3)c2)cc1 ; c1ccc(-c2nc(-c3ccc(-c4ccc5ccccc5c4)cc3)nc(-c3ccc4ccc5nc(-c6ccccc6)[se]c5c4c3)n2)cc1]

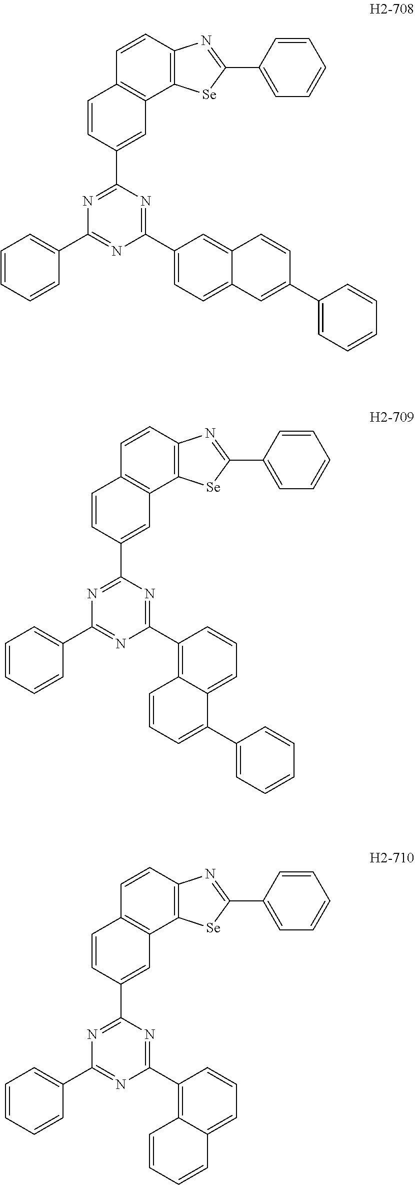 [SMILES: c1ccc(-c2ccc3cc(-c4nc(-c5ccccc5)nc(-c5ccc6ccc7nc(-c8ccccc8)[se]c7c6c5)n4)ccc3c2)cc1 ; c1ccc(-c2nc(-c3ccc4ccc5nc(-c6ccccc6)[se]c5c4c3)nc(-c3cccc4c(-c5ccccc5)cccc34)n2)cc1 ; c1ccc(-c2nc(-c3ccc4ccc5nc(-c6ccccc6)[se]c5c4c3)nc(-c3cccc4ccccc34)n2)cc1]

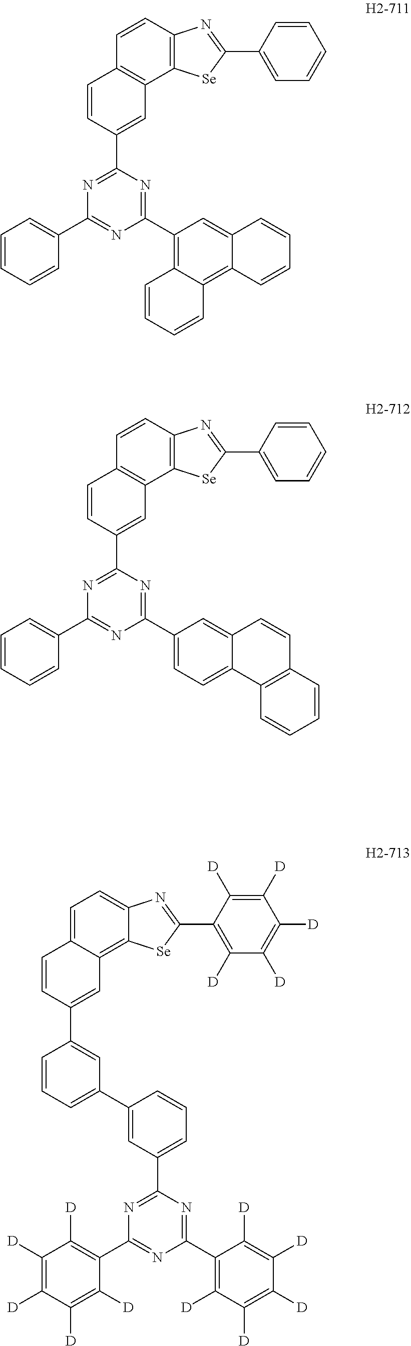 [SMILES: c1ccc(-c2nc(-c3ccc4ccc5nc(-c6ccccc6)[se]c5c4c3)nc(-c3cc4ccccc4c4ccccc34)n2)cc1 ; c1ccc(-c2nc(-c3ccc4c(ccc5ccccc54)c3)nc(-c3ccc4ccc5nc(-c6ccccc6)[se]c5c4c3)n2)cc1 ; [2H]c1c([2H])c([2H])c(-c2nc(-c3cccc(-c4cccc(-c5ccc6ccc7nc(-c8c([2H])c([2H])c([2H])c([2H])c8[2H])[se]c7c6c5)c4)c3)nc(-c3c([2H])c([2H])c([2H])c([2H])c3[2H])n2)c([2H])c1[2H]]

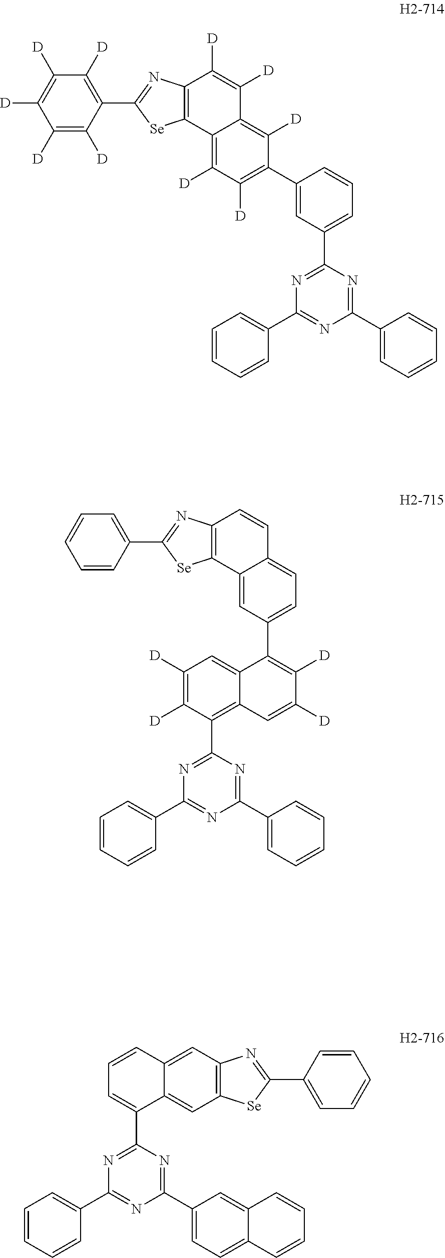 [SMILES: [2H]c1c([2H])c([2H])c(-c2nc3c([2H])c([2H])c4c([2H])c(-c5cccc(-c6nc(-c7ccccc7)nc(-c7ccccc7)n6)c5)c([2H])c([2H])c4c3[se]2)c([2H])c1[2H] ; [2H]c1cc2c(-c3nc(-c4ccccc4)nc(-c4ccccc4)n3)c([2H])c([2H])cc2c(-c2ccc3ccc4nc(-c5ccccc5)[se]c4c3c2)c1[2H] ; c1ccc(-c2nc(-c3ccc4ccccc4c3)nc(-c3cccc4cc5nc(-c6ccccc6)[se]c5cc34)n2)cc1]

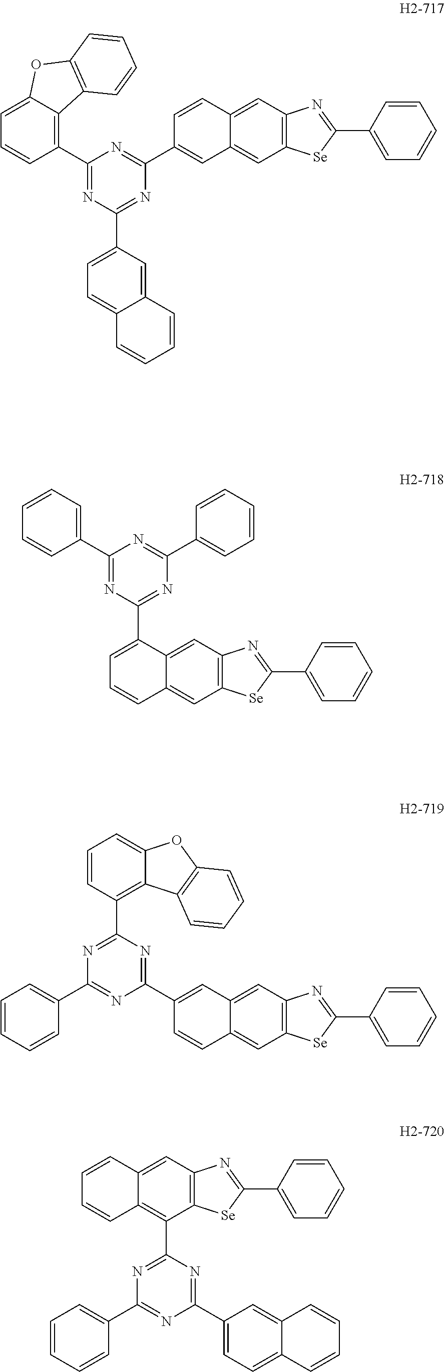 [SMILES: c1ccc(-c2nc3cc4ccc(-c5nc(-c6ccc7ccccc7c6)nc(-c6cccc7oc8ccccc8c67)n5)cc4cc3[se]2)cc1 ; c1ccc(-c2nc(-c3ccccc3)nc(-c3cccc4cc5[se]c(-c6ccccc6)nc5cc34)n2)cc1 ; c1ccc(-c2nc(-c3ccc4cc5[se]c(-c6ccccc6)nc5cc4c3)nc(-c3cccc4oc5ccccc5c34)n2)cc1 ; c1ccc(-c2nc(-c3ccc4ccccc4c3)nc(-c3c4ccccc4cc4nc(-c5ccccc5)[se]c34)n2)cc1]

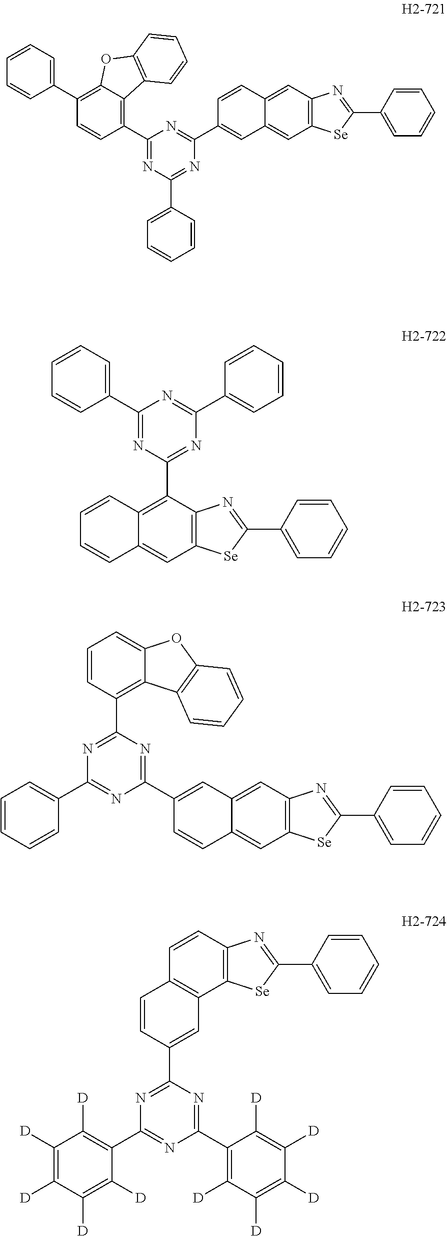 [SMILES: c1ccc(-c2nc(-c3ccc4cc5nc(-c6ccccc6)[se]c5cc4c3)nc(-c3ccc(-c4ccccc4)c4oc5ccccc5c34)n2)cc1 ; c1ccc(-c2nc(-c3ccccc3)nc(-c3c4ccccc4cc4[se]c(-c5ccccc5)nc34)n2)cc1 ; c1ccc(-c2nc(-c3ccc4cc5[se]c(-c6ccccc6)nc5cc4c3)nc(-c3cccc4oc5ccccc5c34)n2)cc1 ; [2H]c1c([2H])c([2H])c(-c2nc(-c3ccc4ccc5nc(-c6ccccc6)[se]c5c4c3)nc(-c3c([2H])c([2H])c([2H])c([2H])c3[2H])n2)c([2H])c1[2H]]

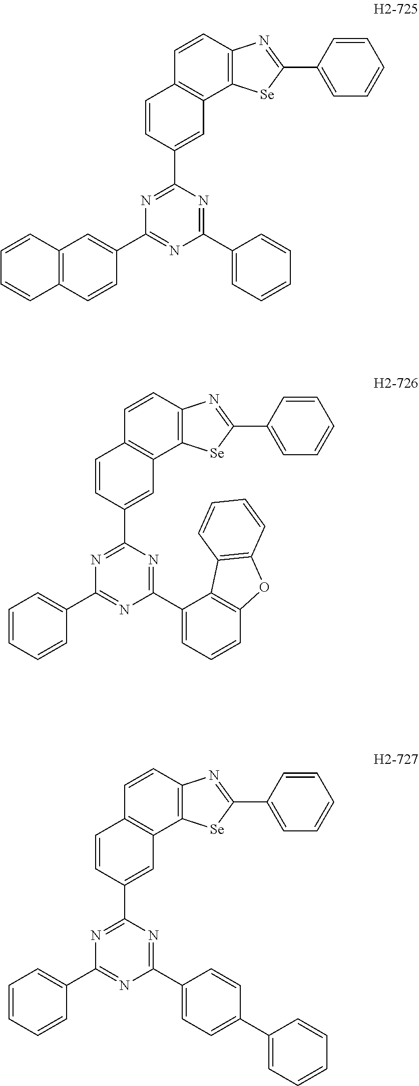 [SMILES: c1ccc(-c2nc(-c3ccc4ccccc4c3)nc(-c3ccc4ccc5nc(-c6ccccc6)[se]c5c4c3)n2)cc1 ; c1ccc(-c2nc(-c3ccc4ccc5nc(-c6ccccc6)[se]c5c4c3)nc(-c3cccc4oc5ccccc5c34)n2)cc1 ; c1ccc(-c2ccc(-c3nc(-c4ccccc4)nc(-c4ccc5ccc6nc(-c7ccccc7)[se]c6c5c4)n3)cc2)cc1]

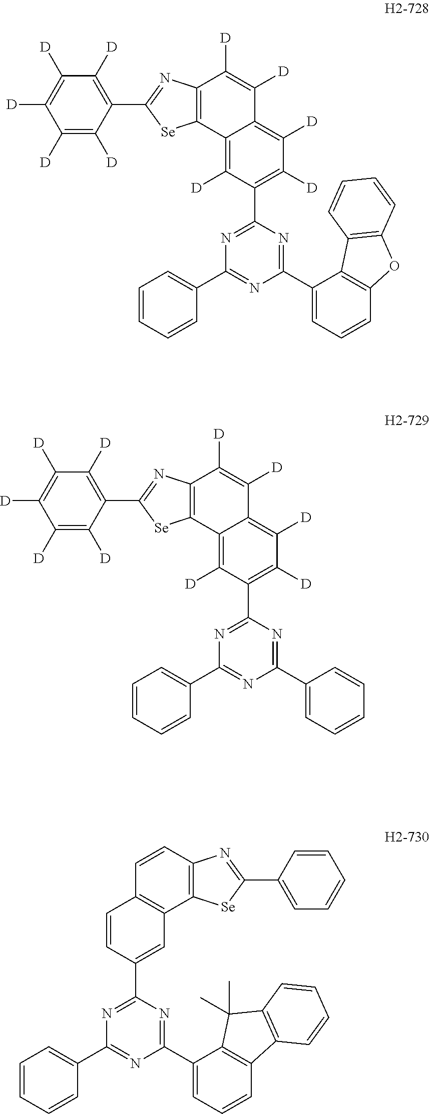 [SMILES: [2H]c1c([2H])c([2H])c(-c2nc3c([2H])c([2H])c4c([2H])c([2H])c(-c5nc(-c6ccccc6)nc(-c6cccc7oc8ccccc8c67)n5)c([2H])c4c3[se]2)c([2H])c1[2H] ; [2H]c1c([2H])c([2H])c(-c2nc3c([2H])c([2H])c4c([2H])c([2H])c(-c5nc(-c6ccccc6)nc(-c6ccccc6)n5)c([2H])c4c3[se]2)c([2H])c1[2H] ; CC1(C)c2ccccc2-c2cccc(-c3nc(-c4ccccc4)nc(-c4ccc5ccc6nc(-c7ccccc7)[se]c6c5c4)n3)c21]

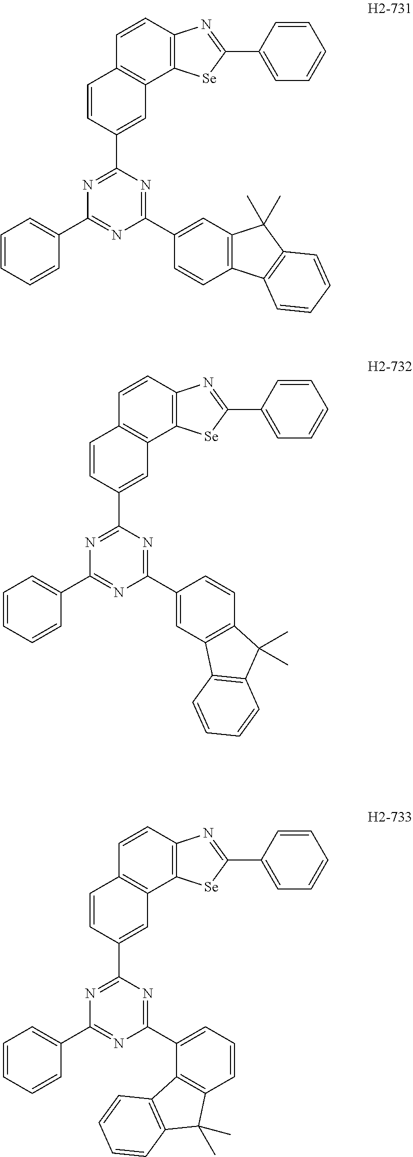 [SMILES: CC1(C)c2ccccc2-c2ccc(-c3nc(-c4ccccc4)nc(-c4ccc5ccc6nc(-c7ccccc7)[se]c6c5c4)n3)cc21 ; CC1(C)c2ccccc2-c2cc(-c3nc(-c4ccccc4)nc(-c4ccc5ccc6nc(-c7ccccc7)[se]c6c5c4)n3)ccc21 ; CC1(C)c2ccccc2-c2c(-c3nc(-c4ccccc4)nc(-c4ccc5ccc6nc(-c7ccccc7)[se]c6c5c4)n3)cccc21]

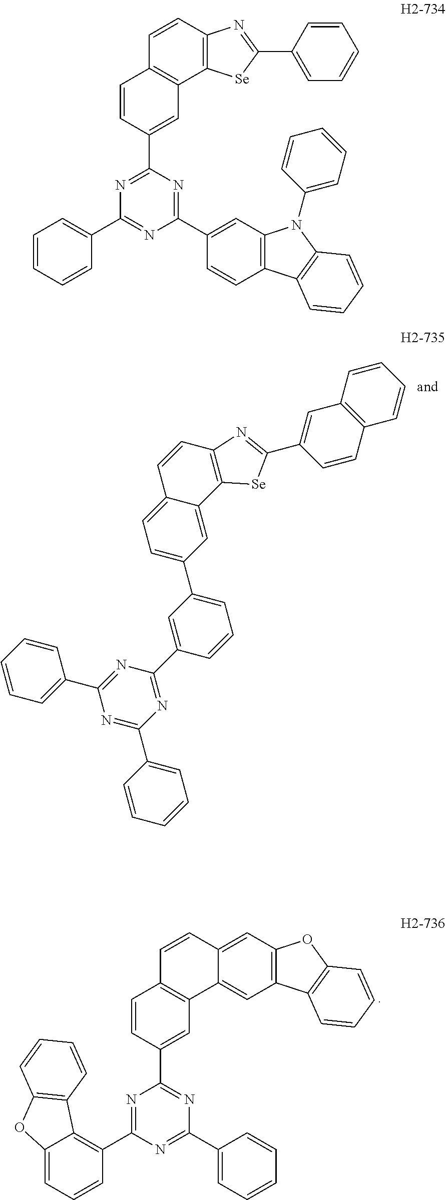 [SMILES: c1ccc(-c2nc(-c3ccc4ccc5nc(-c6ccccc6)[se]c5c4c3)nc(-c3ccc4c5ccccc5n(-c5ccccc5)c4c3)n2)cc1 ; c1ccc(-c2nc(-c3ccccc3)nc(-c3cccc(-c4ccc5ccc6nc(-c7ccc8ccccc8c7)[se]c6c5c4)c3)n2)cc1 ; c1ccc(-c2nc(-c3ccc4ccc5cc6oc7ccccc7c6cc5c4c3)nc(-c3cccc4oc5ccccc5c34)n2)cc1]

8. The plurality of host materials according to claim 1, wherein the plurality of host materials further comprises at least one third host compound which is represented by the formula 1 or 2, but is different from the first host compound or the second host compound.

9. An organic electroluminescent device comprising a first electrode; a second electrode; and at least one light-emitting layer between the first electrode and the second electrode, wherein the at least one light-emitting layer comprise a plurality of host materials according to claim 1.

10. An organic electroluminescent device comprising a first electrode; a second electrode; and at least one light-emitting layer between the first electrode and the second electrode, wherein the at least one light-emitting layer comprise a plurality of host materials according to claim 8.

11. An organic electroluminescent compound represented by the following formula 1′: 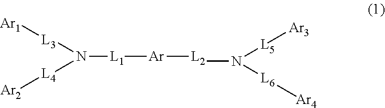
wherein
Ar represents a substituted or unsubstituted (C6-C30)arylene, a substituted or unsubstituted (3- to 30-membered)heteroarylene, or a substituent represented by any one of the following formulas 1-1-1 to 1-1-21; 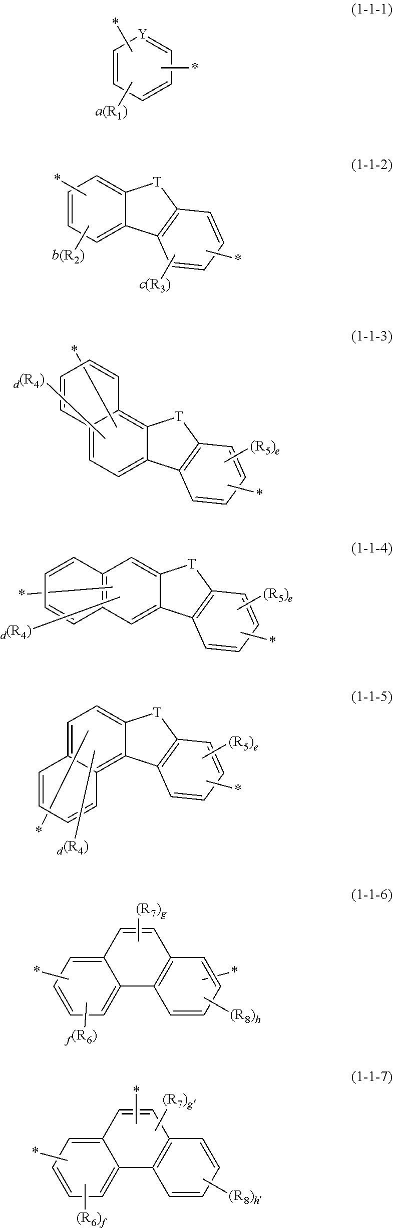 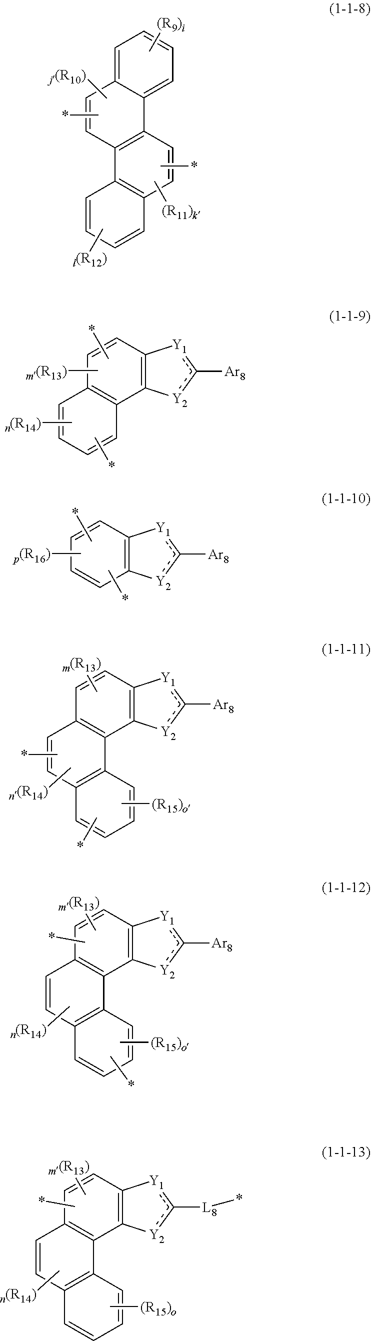 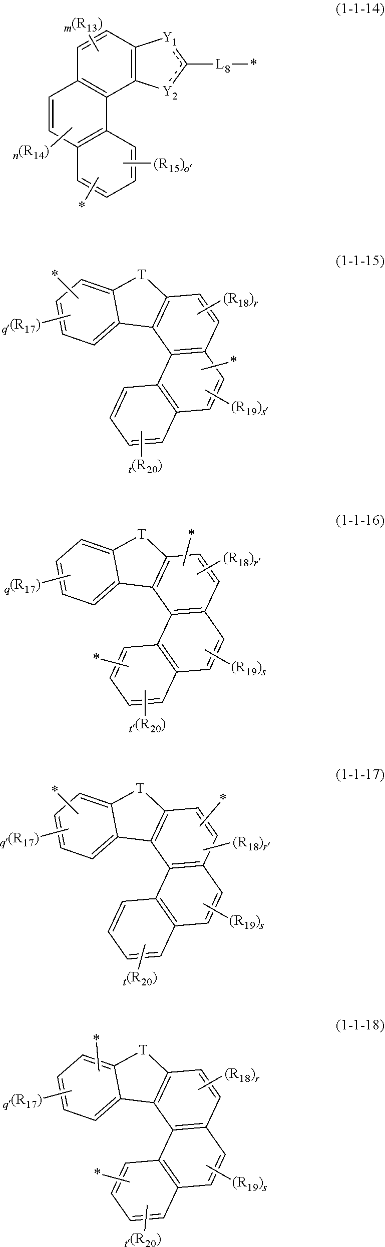 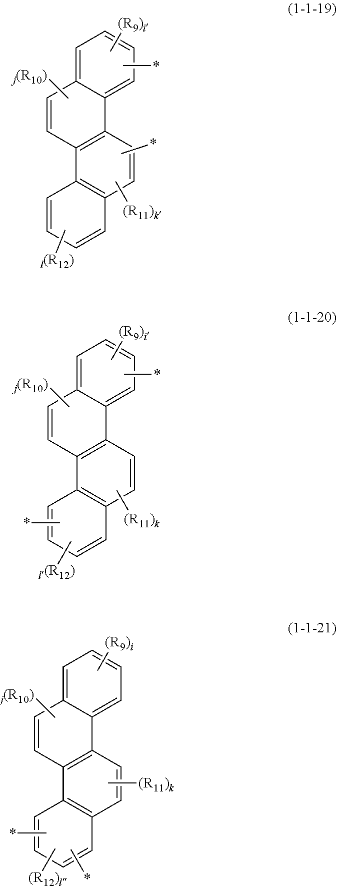
wherein
T represents —O—, —S—, —CR₂₁R₂₂—, or —NR₂₃—;
Y represents CH or N;
Y₁ and Y₂ each independently represent, —N═, —NR₂₄—, —O—, —S—, or —Se—; provided that any one of Y₁ and Y₂ is —N═, and the other of Y₁ and Y₂ is —NR₂₄—, —O—, —S—, or —Se—;
R₁ to R₂₀ each independently represent, hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or —N—(R′)(R″); or may be linked to the adjacent substituents to form a ring(s);
R′ and R″ each independently represent, a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl;
R₂₁ to R₂₄ each independently represent, a substituted or unsubstituted (C1-C30)alkyl, a substituted or unsubstituted (C6-C30)aryl, or a substituted or unsubstituted (3- to 30-membered)heteroaryl; or may be linked to the adjacent substituents to form a ring(s);
Ar₈ represents a substituted or unsubstituted (C6-C30)aryl or a substituted or unsubstituted (3- to 30-membered)heteroaryl;
L₈ represents a single bond, a substituted or unsubstituted (C6-C30)arylene, or a substituted or unsubstituted (3- to 30-membered)heteroarylene;
h′, i, l, o, q, and t are an integer of 1 to 4; a, b, c, e, f, h, i′, l′, o′, q′, and t′ are an integer of 1 to 3; d is an integer of 1 to 5; g, j, k, l″, m, n, p, r, and s are an integer of 1 or 2; g′, j′, k′, m′, n′, r′ and s′ are 1;
when a to t, h′, i′, l′, l″, o′, q′, and t′ are an integer of 2 or more, each of R₁ to R₂₀ may be the same or different;
* represents a linking site with L₁ and L₂ in formula 1′;
L₁ to L₆ each independently represent, a single bond, a substituted or unsubstituted (C6-C30)arylene, a substituted or unsubstituted (C3-C30)cycloalkylene, or a substituted or unsubstituted (3- to 30-membered)heteroarylene;
Ar₁ to Ar₄ each independently represent, deuterium, a substituted or unsubstituted (C1-C30)alkyl, a substituted or unsubstituted (C6-C30)aryl, a substituted or unsubstituted fused ring of (C3-C30) aliphatic ring and (C6-C30) aromatic ring, or a substituted or unsubstituted (3- to 30-membered)heteroaryl; or may be linked to the adjacent substituents to form a ring(s); provided that at least one of Ar₁ to Ar₄ is a substituent selected from the following formulas 1-1, 1-8 to 1-15, 1-17 to 1-21, and 1-27; 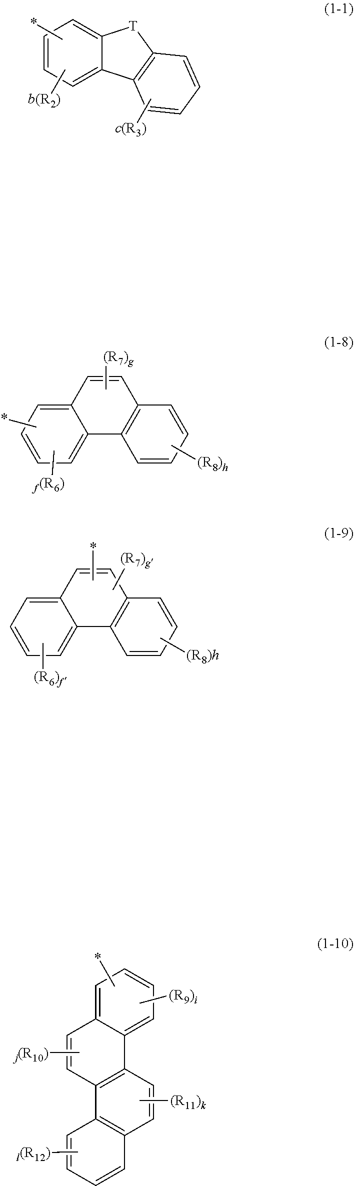 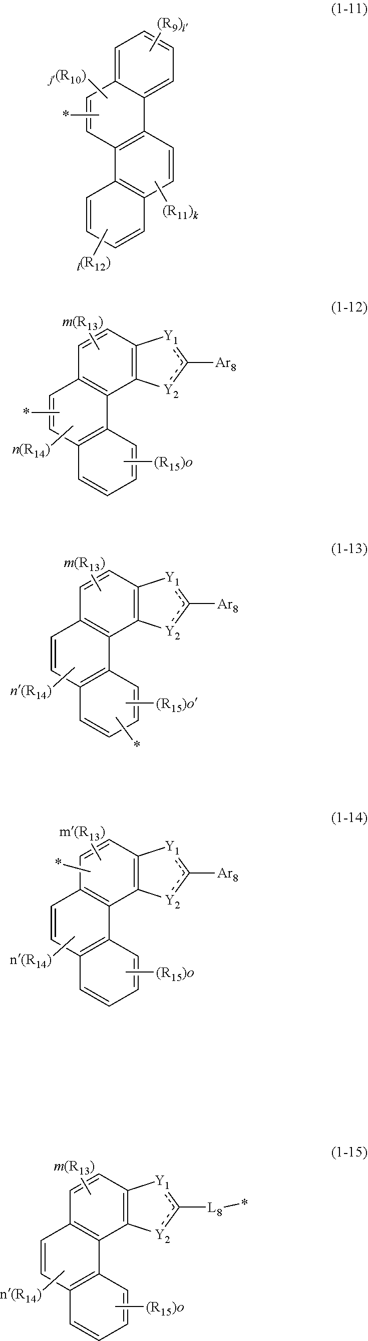 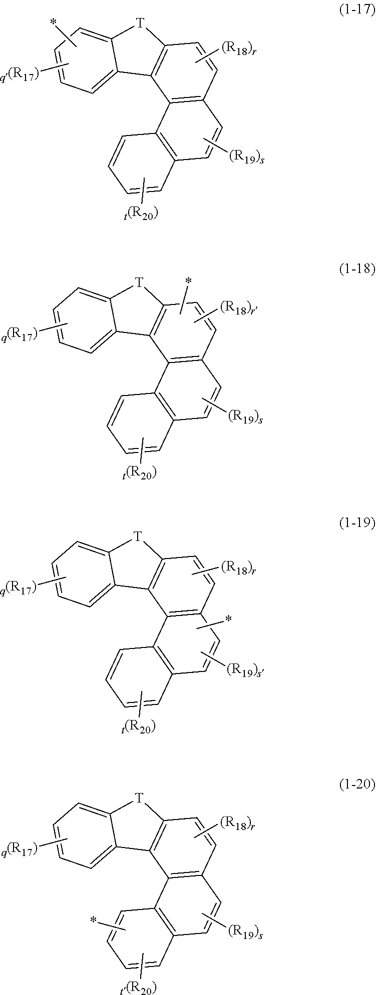 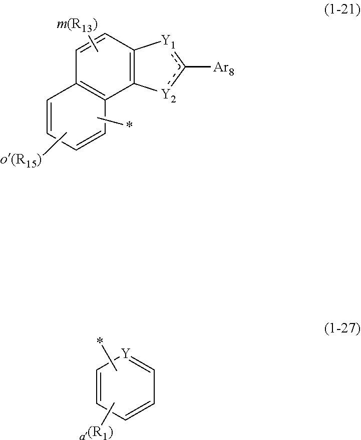
wherein
T represents —O—, —S—, —Se—, —CR₂₁R₂₂—, or —NR₂₃—;
Y represents CH or N;
Y₁ and Y₂ each independently represent, —N═, —NR₂₄—, —O—, —S—, or —Se; provided that any one of Y₁ and Y₂ is —N═, and the other of Y₁ and Y₂ is —NR₂₄—, —O—, —S—, or —Se—;
R₁ to R₃, R₆ to R₁₅, and R₁₇ to R₂₀ each independently represent, hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or —N—(R′)(R″); or may be linked to the adjacent substituents to form a ring(s);
R′ and R″ each independently represent, a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl;
R₂₁ to R₂₄ each independently represent, a substituted or unsubstituted (C1-C30)alkyl, a substituted or unsubstituted (C6-C30)aryl, or a substituted or unsubstituted (3- to 30-membered)heteroaryl; or may be linked to the adjacent substituents to form a ring(s);
Ar₈ represents a substituted or unsubstituted (C6-C30)aryl or a substituted or unsubstituted (3- to 30-membered)heteroaryl;
L₈ represents a single bond, a substituted or unsubstituted (C6-C30)arylene, or a substituted or unsubstituted (3- to 30-membered)heteroarylene;
b, f, i, o′, q′, and t′ are an integer of 1 to 3; a′, c, h, f′, l, i′, o, q, and t are an integer of 1 to 4; g, j, k, m, n′, r and s are an integer of 1 or 2; g′, j′, m′, n, r′, and s′ are 1;
when a′, b, c, f to m, o, q to t, f′ i′, n′, o′, q′, and t′ are an integer of 2 or more, each of R₁ to R₃, R₆ to R₁₅, and R₁₇ to R₂₀ may be the same or different; and
* represents a linking site with L₃ to L₆ in formula 1′.

12. The organic electroluminescent compound according to claim 11, wherein the compound represented by formula 1′ is selected from the following compounds:

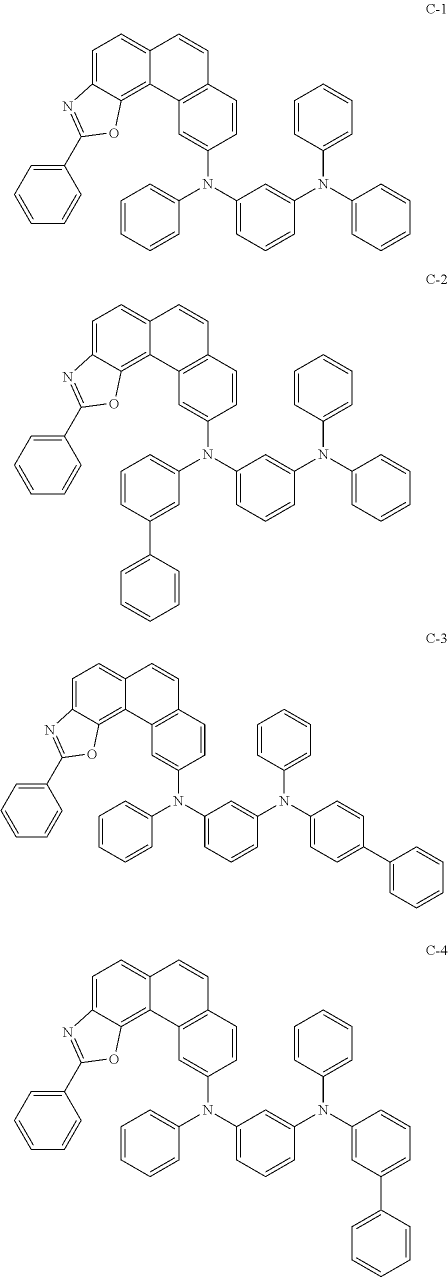

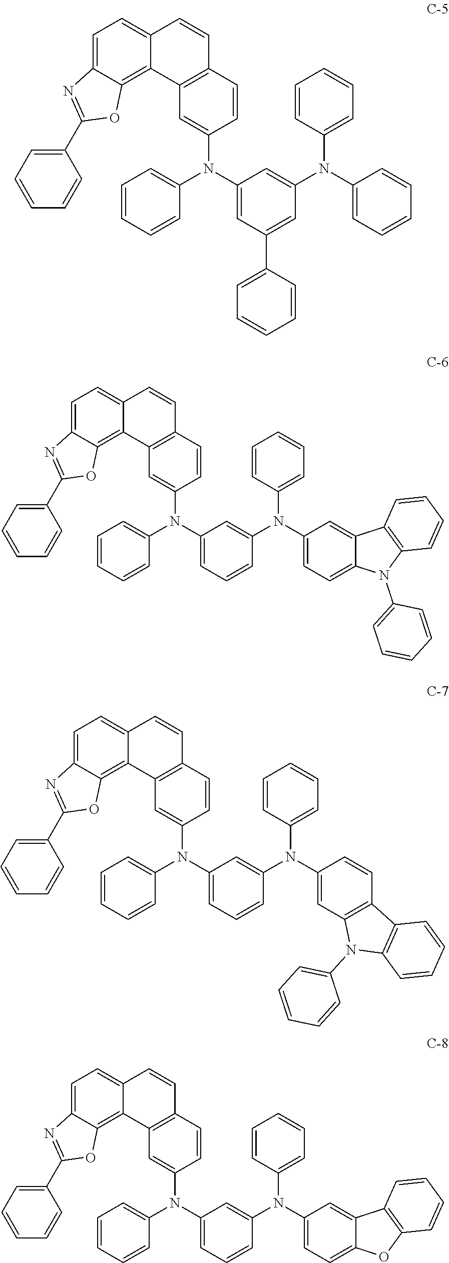 [SMILES: c1ccc(-c2cc(N(c3ccccc3)c3ccccc3)cc(N(c3ccccc3)c3ccc4ccc5ccc6nc(-c7ccccc7)oc6c5c4c3)c2)cc1 ; c1ccc(-c2nc3ccc4ccc5ccc(N(c6ccccc6)c6cccc(N(c7ccccc7)c7ccc8c(c7)c7ccccc7n8-c7ccccc7)c6)cc5c4c3o2)cc1 ; c1ccc(-c2nc3ccc4ccc5ccc(N(c6ccccc6)c6cccc(N(c7ccccc7)c7ccc8c9ccccc9n(-c9ccccc9)c8c7)c6)cc5c4c3o2)cc1 ; c1ccc(-c2nc3ccc4ccc5ccc(N(c6ccccc6)c6cccc(N(c7ccccc7)c7ccc8oc9ccccc9c8c7)c6)cc5c4c3o2)cc1]

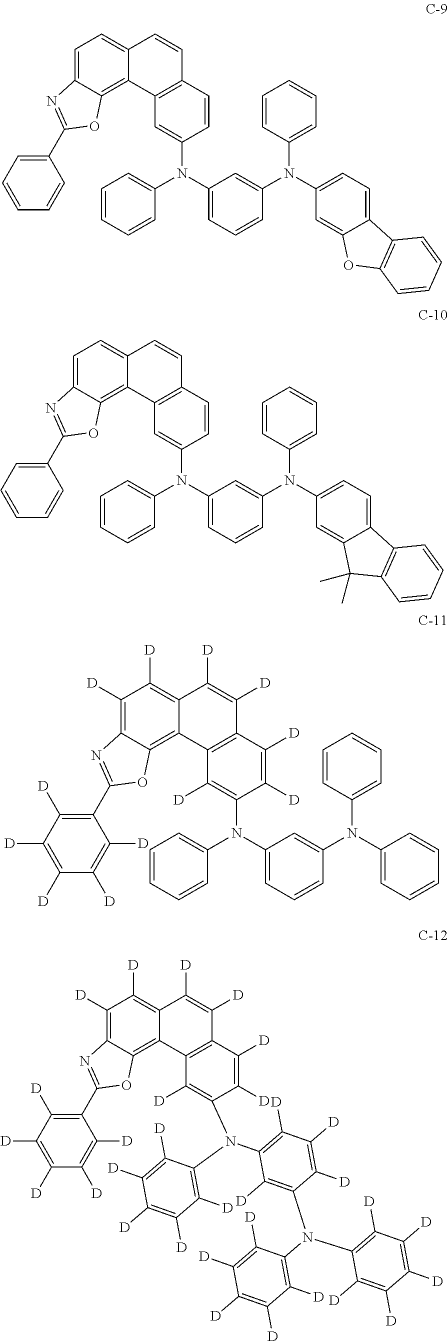

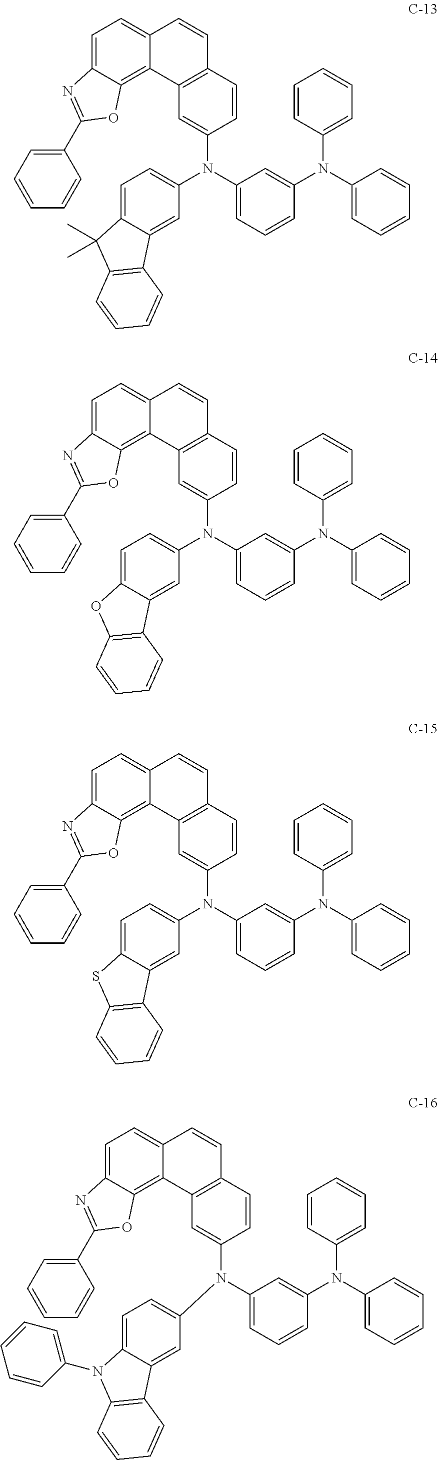 [SMILES: CC1(C)c2ccccc2-c2cc(N(c3cccc(N(c4ccccc4)c4ccccc4)c3)c3ccc4ccc5ccc6nc(-c7ccccc7)oc6c5c4c3)ccc21 ; c1ccc(-c2nc3ccc4ccc5ccc(N(c6cccc(N(c7ccccc7)c7ccccc7)c6)c6ccc7oc8ccccc8c7c6)cc5c4c3o2)cc1 ; c1ccc(-c2nc3ccc4ccc5ccc(N(c6cccc(N(c7ccccc7)c7ccccc7)c6)c6ccc7sc8ccccc8c7c6)cc5c4c3o2)cc1 ; c1ccc(-c2nc3ccc4ccc5ccc(N(c6cccc(N(c7ccccc7)c7ccccc7)c6)c6ccc7c(c6)c6ccccc6n7-c6ccccc6)cc5c4c3o2)cc1]

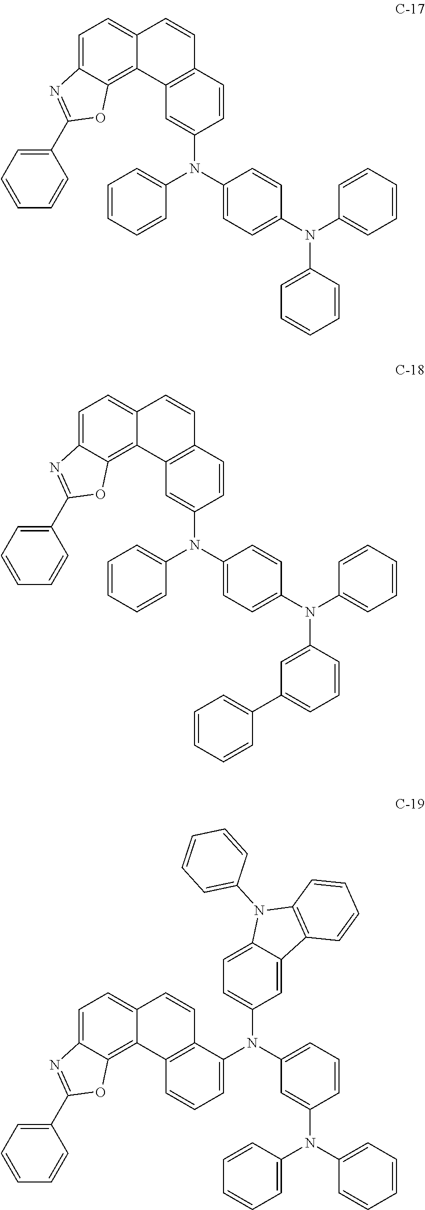 [SMILES: c1ccc(-c2nc3ccc4ccc5ccc(N(c6ccccc6)c6ccc(N(c7ccccc7)c7ccccc7)cc6)cc5c4c3o2)cc1 ; c1ccc(-c2cccc(N(c3ccccc3)c3ccc(N(c4ccccc4)c4ccc5ccc6ccc7nc(-c8ccccc8)oc7c6c5c4)cc3)c2)cc1 ; c1ccc(-c2nc3ccc4ccc5c(N(c6cccc(N(c7ccccc7)c7ccccc7)c6)c6ccc7c(c6)c6ccccc6n7-c6ccccc6)cccc5c4c3o2)cc1]

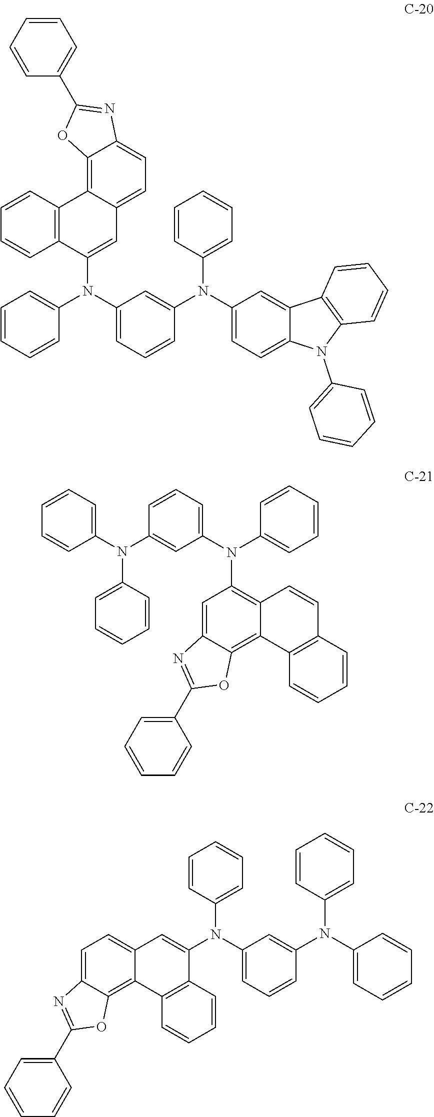 [SMILES: c1ccc(-c2nc3ccc4cc(N(c5ccccc5)c5cccc(N(c6ccccc6)c6ccc7c(c6)c6ccccc6n7-c6ccccc6)c5)c5ccccc5c4c3o2)cc1 ; c1ccc(-c2nc3cc(N(c4ccccc4)c4cccc(N(c5ccccc5)c5ccccc5)c4)c4ccc5ccccc5c4c3o2)cc1 ; c1ccc(-c2nc3ccc4cc(N(c5ccccc5)c5cccc(N(c6ccccc6)c6ccccc6)c5)c5ccccc5c4c3o2)cc1]

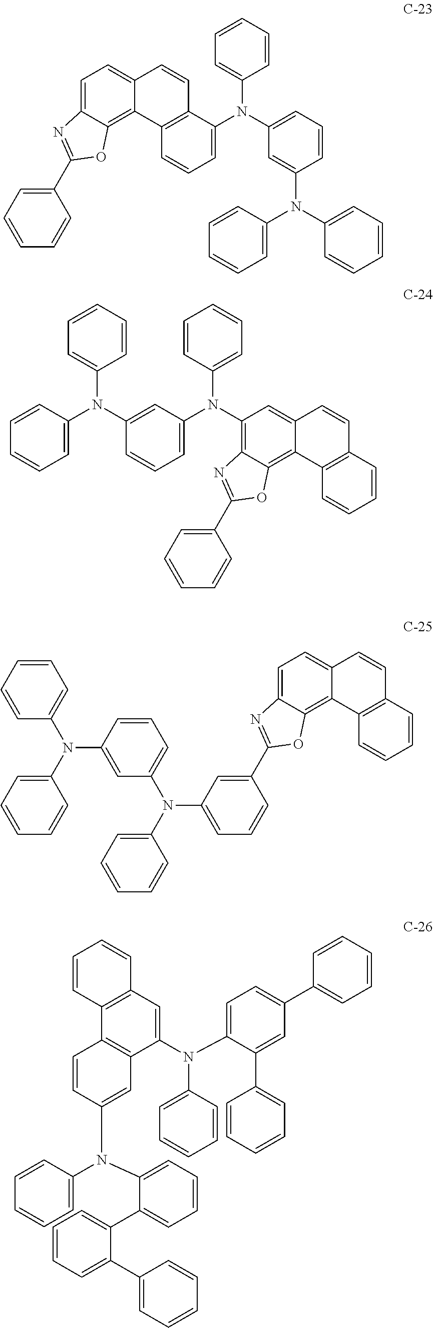

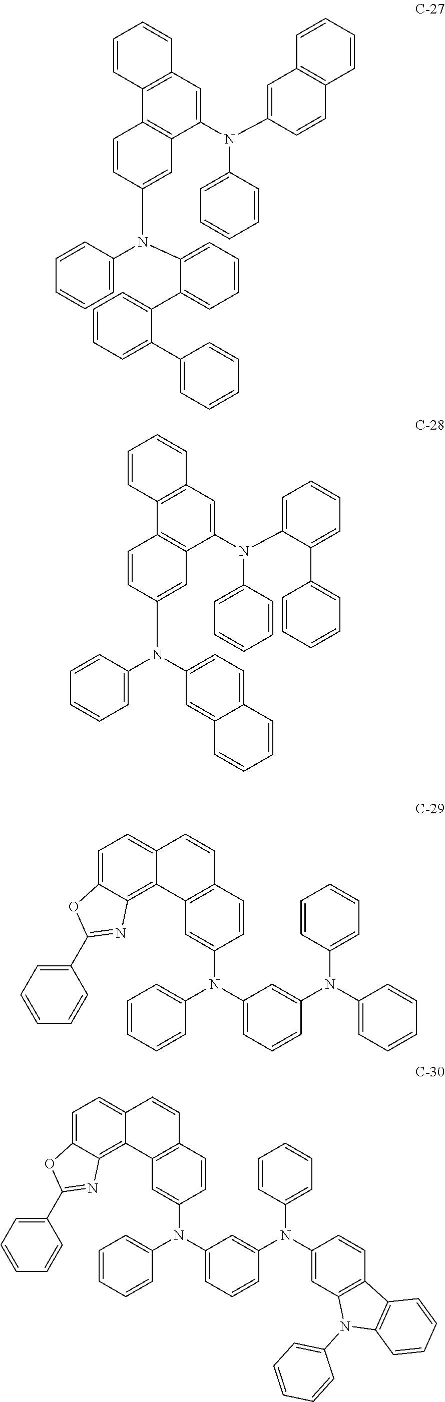

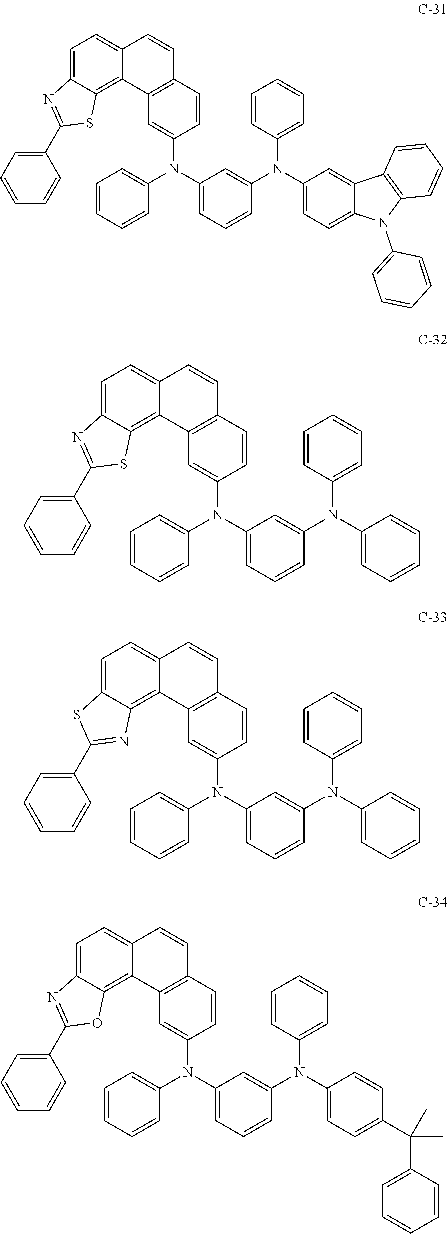 [SMILES: c1ccc(-c2nc3ccc4ccc5ccc(N(c6ccccc6)c6cccc(N(c7ccccc7)c7ccc8c(c7)c7ccccc7n8-c7ccccc7)c6)cc5c4c3s2)cc1 ; c1ccc(-c2nc3ccc4ccc5ccc(N(c6ccccc6)c6cccc(N(c7ccccc7)c7ccccc7)c6)cc5c4c3s2)cc1 ; c1ccc(-c2nc3c(ccc4ccc5ccc(N(c6ccccc6)c6cccc(N(c7ccccc7)c7ccccc7)c6)cc5c43)s2)cc1 ; CC(C)(c1ccccc1)c1ccc(N(c2ccccc2)c2cccc(N(c3ccccc3)c3ccc4ccc5ccc6nc(-c7ccccc7)oc6c5c4c3)c2)cc1]

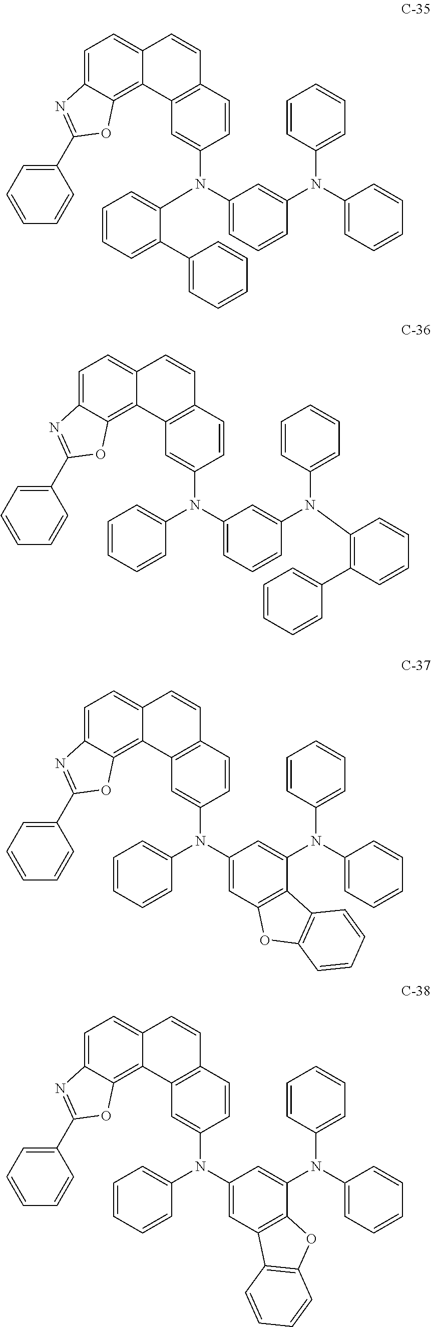 [SMILES: c1ccc(-c2nc3ccc4ccc5ccc(N(c6cccc(N(c7ccccc7)c7ccccc7)c6)c6ccccc6-c6ccccc6)cc5c4c3o2)cc1 ; c1ccc(-c2nc3ccc4ccc5ccc(N(c6ccccc6)c6cccc(N(c7ccccc7)c7ccccc7-c7ccccc7)c6)cc5c4c3o2)cc1 ; c1ccc(-c2nc3ccc4ccc5ccc(N(c6ccccc6)c6cc(N(c7ccccc7)c7ccccc7)c7c(c6)oc6ccccc67)cc5c4c3o2)cc1 ; c1ccc(-c2nc3ccc4ccc5ccc(N(c6ccccc6)c6cc(N(c7ccccc7)c7ccccc7)c7oc8ccccc8c7c6)cc5c4c3o2)cc1]

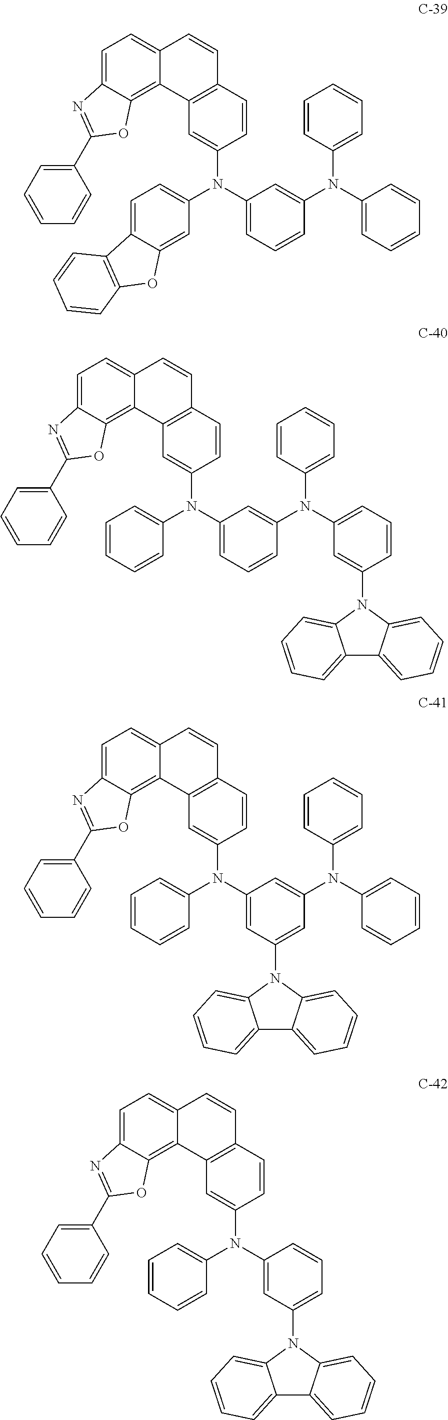

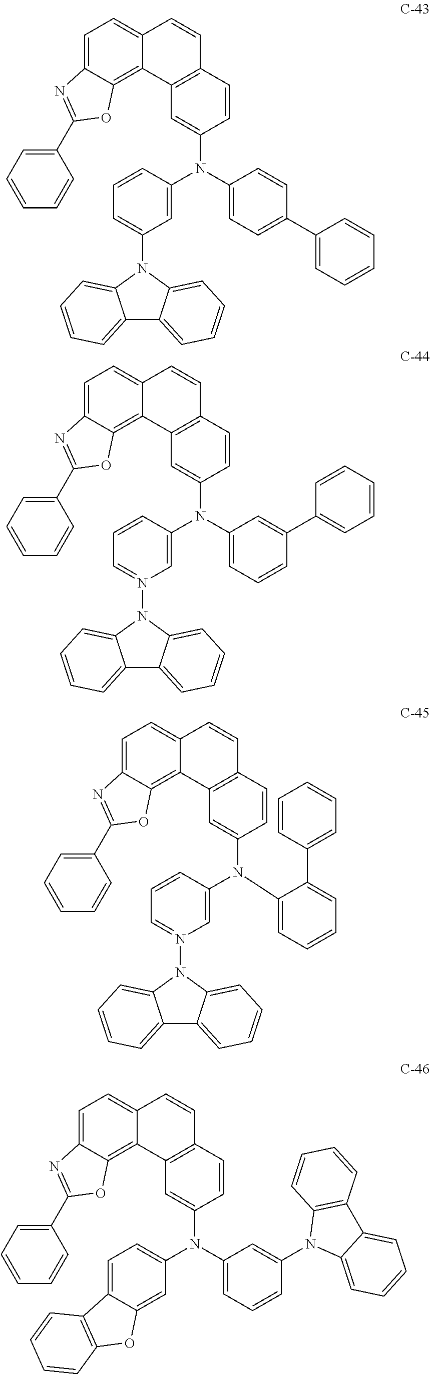

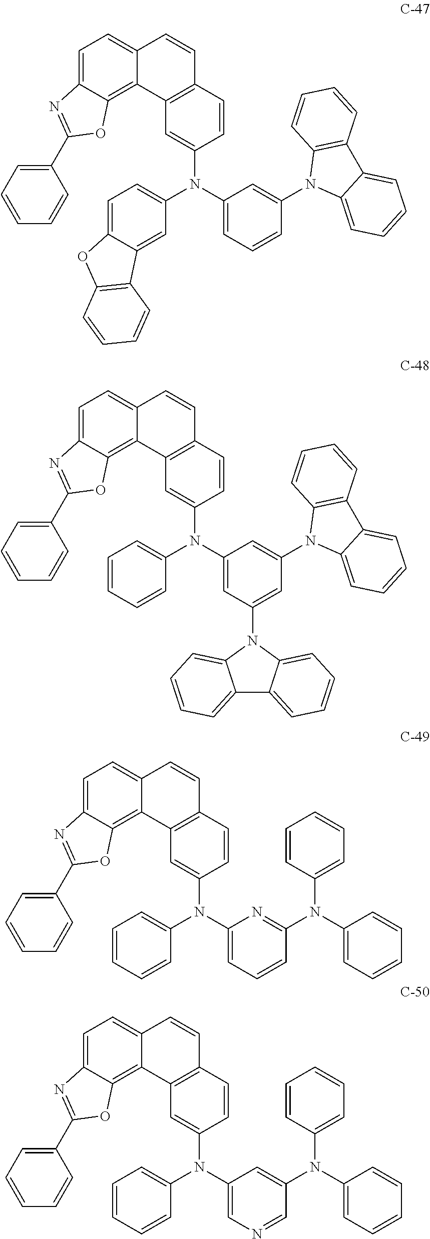

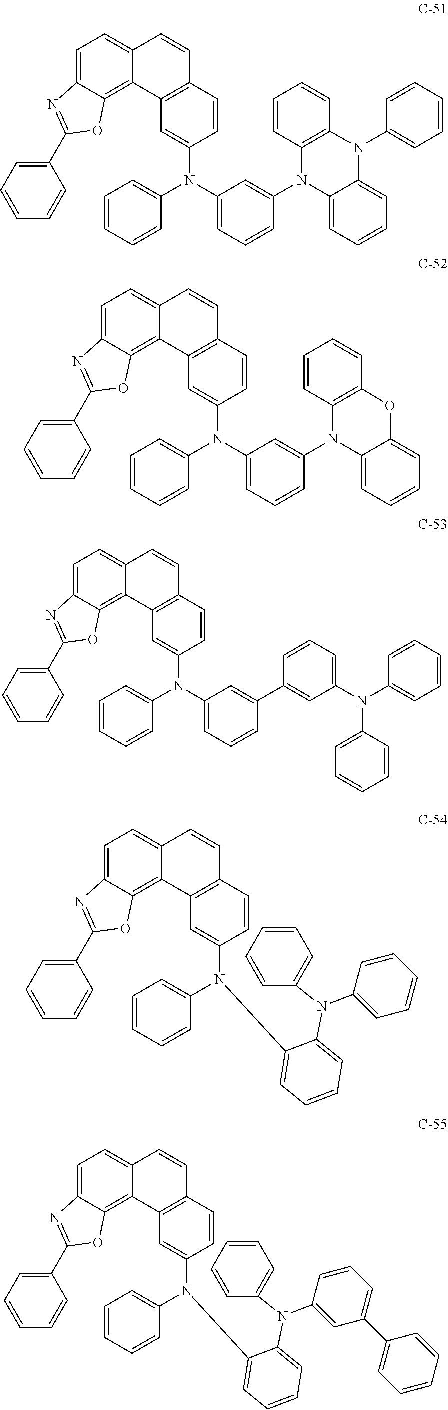

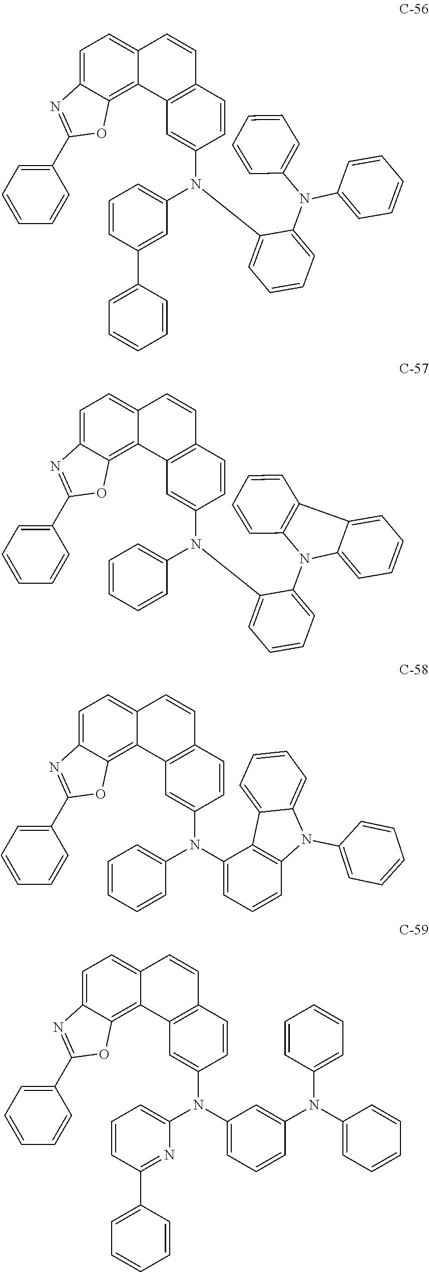 [SMILES: c1ccc(-c2cccc(N(c3ccc4ccc5ccc6nc(-c7ccccc7)oc6c5c4c3)c3ccccc3N(c3ccccc3)c3ccccc3)c2)cc1 ; c1ccc(-c2nc3ccc4ccc5ccc(N(c6ccccc6)c6ccccc6-n6c7ccccc7c7ccccc76)cc5c4c3o2)cc1 ; c1ccc(-c2nc3ccc4ccc5ccc(N(c6ccccc6)c6cccc7c6c6ccccc6n7-c6ccccc6)cc5c4c3o2)cc1 ; c1ccc(-c2cccc(N(c3cccc(N(c4ccccc4)c4ccccc4)c3)c3ccc4ccc5ccc6nc(-c7ccccc7)oc6c5c4c3)n2)cc1]

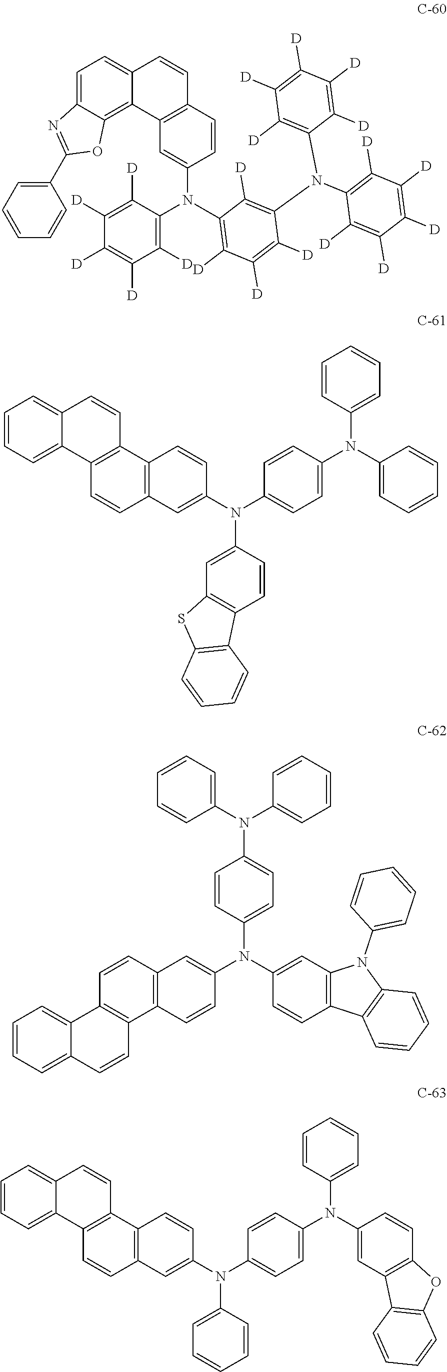 [SMILES: [2H]c1c([2H])c([2H])c(N(c2ccc3ccc4ccc5nc(-c6ccccc6)oc5c4c3c2)c2c([2H])c([2H])c([2H])c(N(c3c([2H])c([2H])c([2H])c([2H])c3[2H])c3c([2H])c([2H])c([2H])c([2H])c3[2H])c2[2H])c([2H])c1[2H] ; c1ccc(N(c2ccccc2)c2ccc(N(c3ccc4c(ccc5c6ccccc6ccc45)c3)c3ccc4c(c3)sc3ccccc34)cc2)cc1 ; c1ccc(N(c2ccccc2)c2ccc(N(c3ccc4c(ccc5c6ccccc6ccc45)c3)c3ccc4c5ccccc5n(-c5ccccc5)c4c3)cc2)cc1 ; c1ccc(N(c2ccc(N(c3ccccc3)c3ccc4oc5ccccc5c4c3)cc2)c2ccc3c(ccc4c5ccccc5ccc34)c2)cc1]

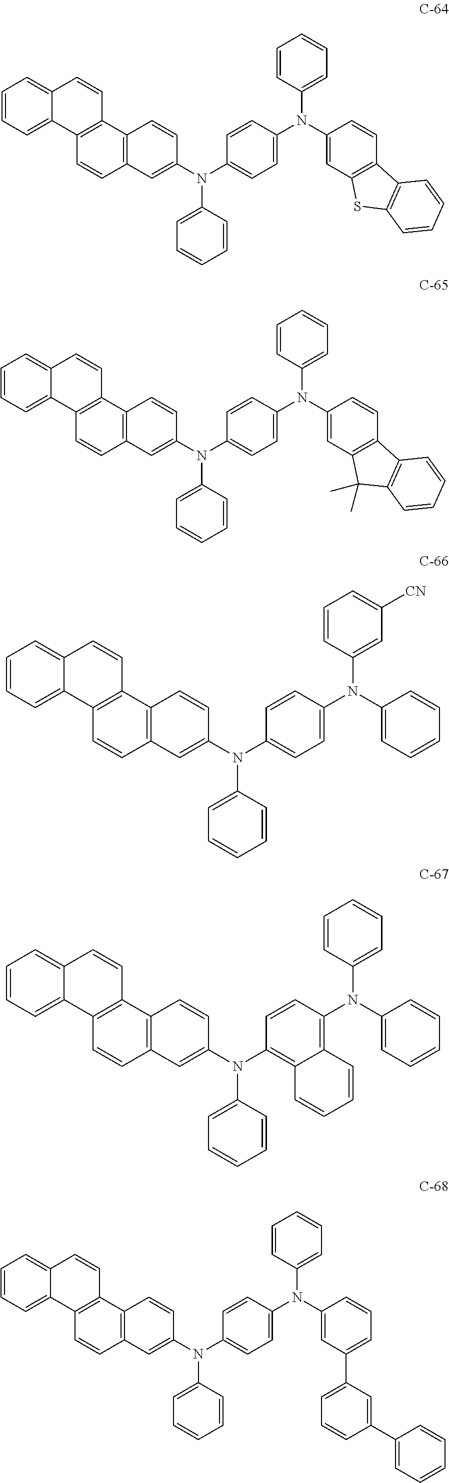 [SMILES: c1ccc(N(c2ccc(N(c3ccccc3)c3ccc4c(c3)sc3ccccc34)cc2)c2ccc3c(ccc4c5ccccc5ccc34)c2)cc1 ; CC1(C)c2ccccc2-c2ccc(N(c3ccccc3)c3ccc(N(c4ccccc4)c4ccc5c(ccc6c7ccccc7ccc56)c4)cc3)cc21 ; N#Cc1cccc(N(c2ccccc2)c2ccc(N(c3ccccc3)c3ccc4c(ccc5c6ccccc6ccc45)c3)cc2)c1 ; c1ccc(N(c2ccccc2)c2ccc(N(c3ccccc3)c3ccc4c(ccc5c6ccccc6ccc45)c3)c3ccccc23)cc1 ; c1ccc(-c2cccc(-c3cccc(N(c4ccccc4)c4ccc(N(c5ccccc5)c5ccc6c(ccc7c8ccccc8ccc67)c5)cc4)c3)c2)cc1]

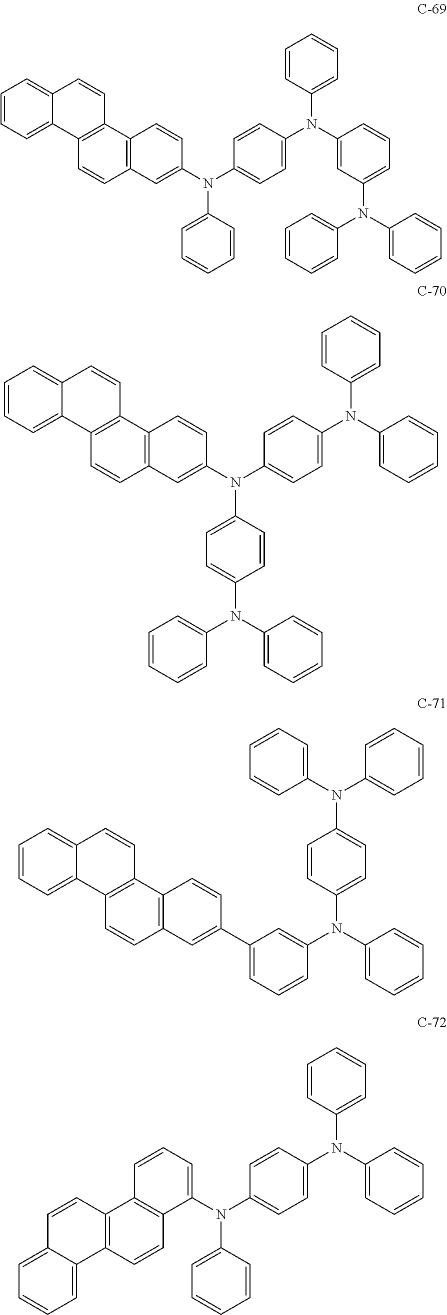 [SMILES: c1ccc(N(c2ccccc2)c2cccc(N(c3ccccc3)c3ccc(N(c4ccccc4)c4ccc5c(ccc6c7ccccc7ccc56)c4)cc3)c2)cc1 ; c1ccc(N(c2ccccc2)c2ccc(N(c3ccc(N(c4ccccc4)c4ccccc4)cc3)c3ccc4c(ccc5c6ccccc6ccc45)c3)cc2)cc1 ; c1ccc(N(c2ccccc2)c2ccc(N(c3ccccc3)c3cccc(-c4ccc5c(ccc6c7ccccc7ccc56)c4)c3)cc2)cc1 ; c1ccc(N(c2ccccc2)c2ccc(N(c3ccccc3)c3cccc4c3ccc3c5ccccc5ccc43)cc2)cc1]

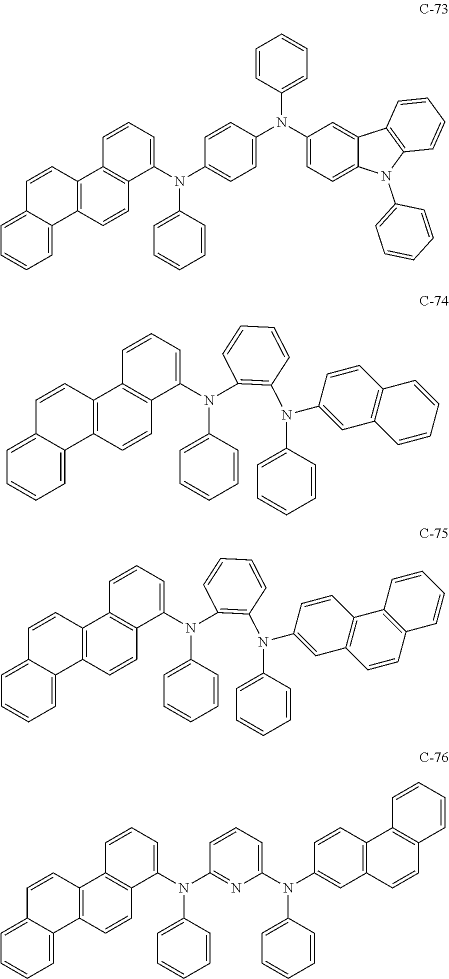 [SMILES: c1ccc(N(c2ccc(N(c3ccccc3)c3cccc4c3ccc3c5ccccc5ccc43)cc2)c2ccc3c(c2)c2ccccc2n3-c2ccccc2)cc1 ; c1ccc(N(c2ccc3ccccc3c2)c2ccccc2N(c2ccccc2)c2cccc3c2ccc2c4ccccc4ccc32)cc1 ; c1ccc(N(c2ccc3c(ccc4ccccc43)c2)c2ccccc2N(c2ccccc2)c2cccc3c2ccc2c4ccccc4ccc32)cc1 ; c1ccc(N(c2ccc3c(ccc4ccccc43)c2)c2cccc(N(c3ccccc3)c3cccc4c3ccc3c5ccccc5ccc43)n2)cc1]

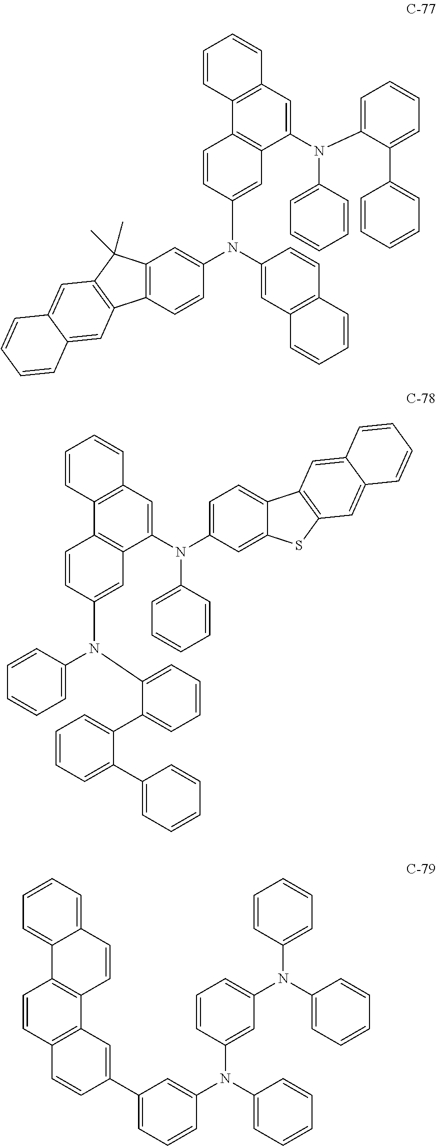 [SMILES: CC1(C)c2cc(N(c3ccc4ccccc4c3)c3ccc4c(c3)c(N(c3ccccc3)c3ccccc3-c3ccccc3)cc3ccccc34)ccc2-c2cc3ccccc3cc21 ; c1ccc(-c2ccccc2-c2ccccc2N(c2ccccc2)c2ccc3c(c2)c(N(c2ccccc2)c2ccc4c(c2)sc2cc5ccccc5cc24)cc2ccccc23)cc1 ; c1ccc(N(c2ccccc2)c2cccc(N(c3ccccc3)c3cccc(-c4ccc5ccc6c7ccccc7ccc6c5c4)c3)c2)cc1]

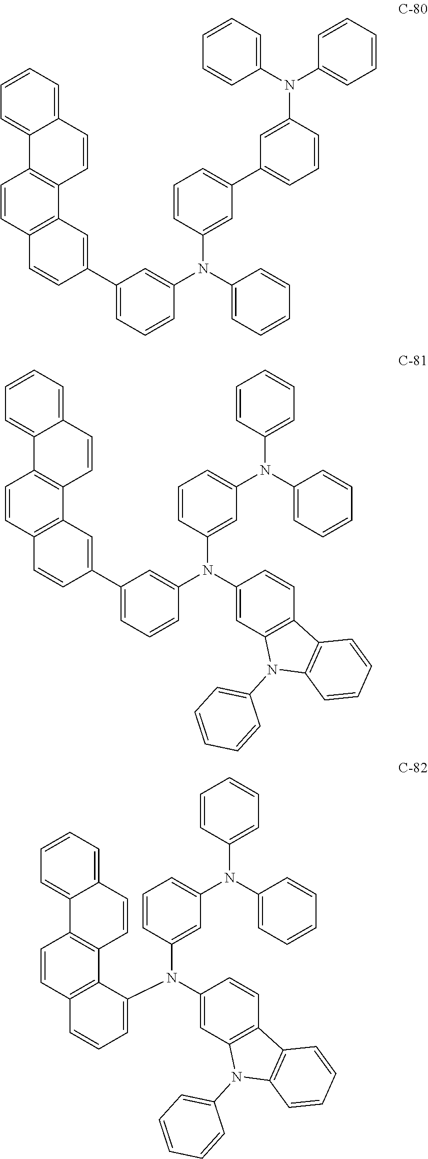

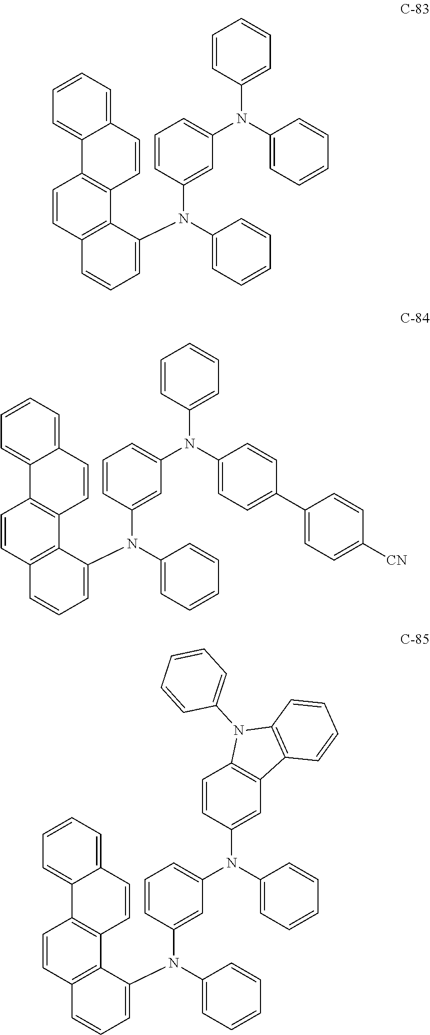

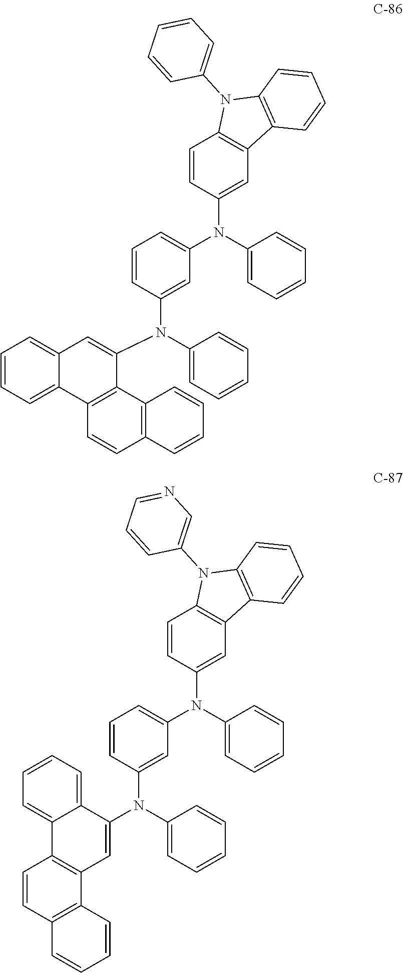

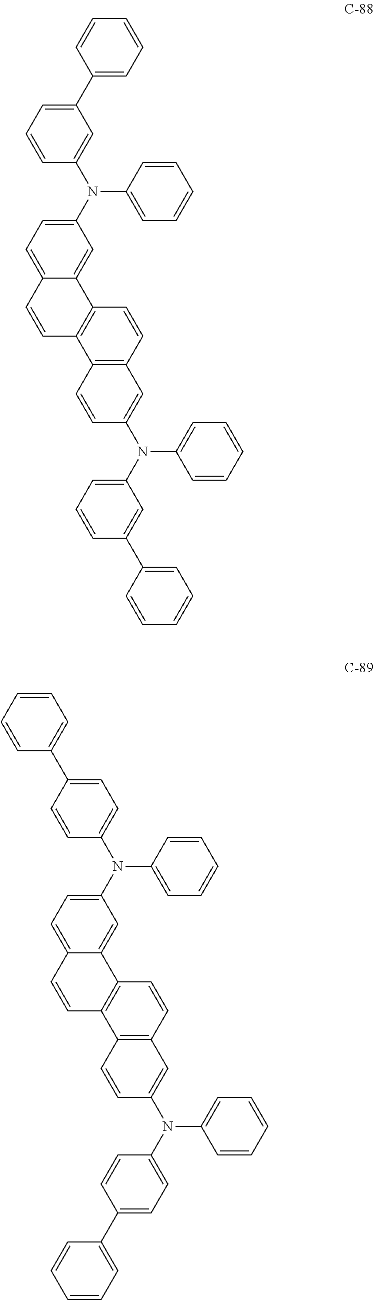 [SMILES: c1ccc(-c2cccc(N(c3ccccc3)c3ccc4c(ccc5c6cc(N(c7ccccc7)c7cccc(-c8ccccc8)c7)ccc6ccc45)c3)c2)cc1 ; c1ccc(-c2ccc(N(c3ccccc3)c3ccc4c(ccc5c6cc(N(c7ccccc7)c7ccc(-c8ccccc8)cc7)ccc6ccc45)c3)cc2)cc1]

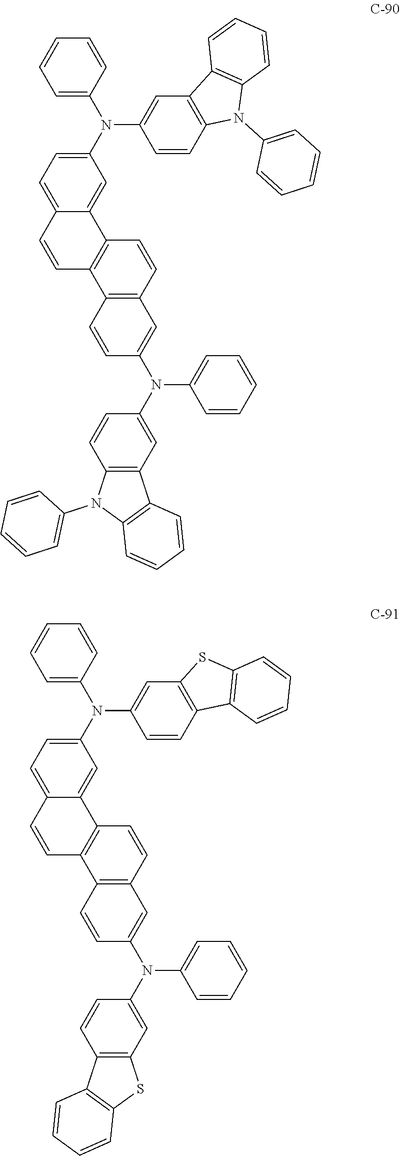 [SMILES: c1ccc(N(c2ccc3c(ccc4c5cc(N(c6ccccc6)c6ccc7c(c6)c6ccccc6n7-c6ccccc6)ccc5ccc34)c2)c2ccc3c(c2)c2ccccc2n3-c2ccccc2)cc1 ; c1ccc(N(c2ccc3c(ccc4c5cc(N(c6ccccc6)c6ccc7c(c6)sc6ccccc67)ccc5ccc34)c2)c2ccc3c(c2)sc2ccccc23)cc1]

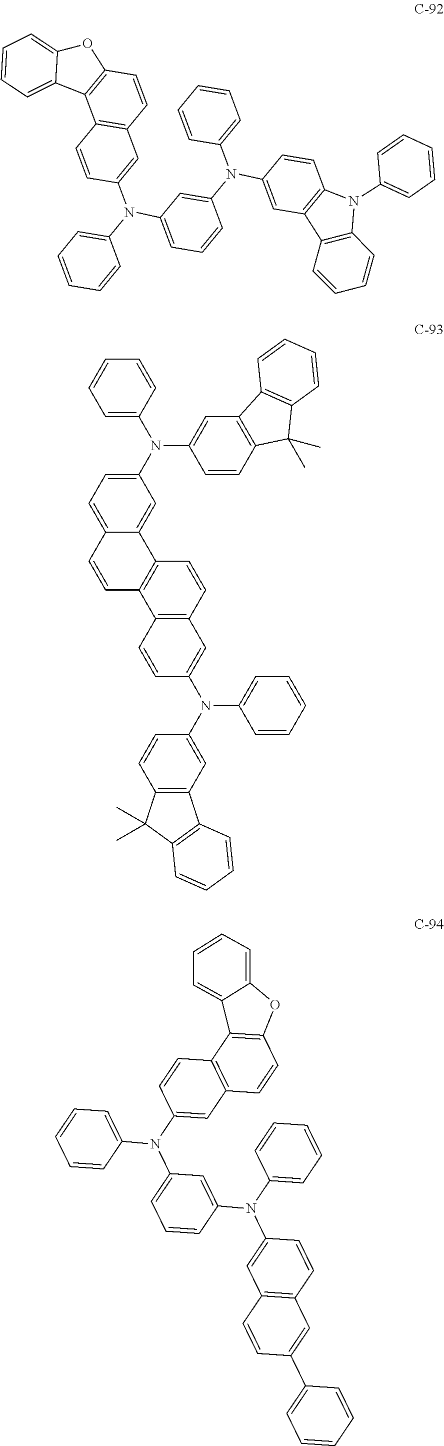

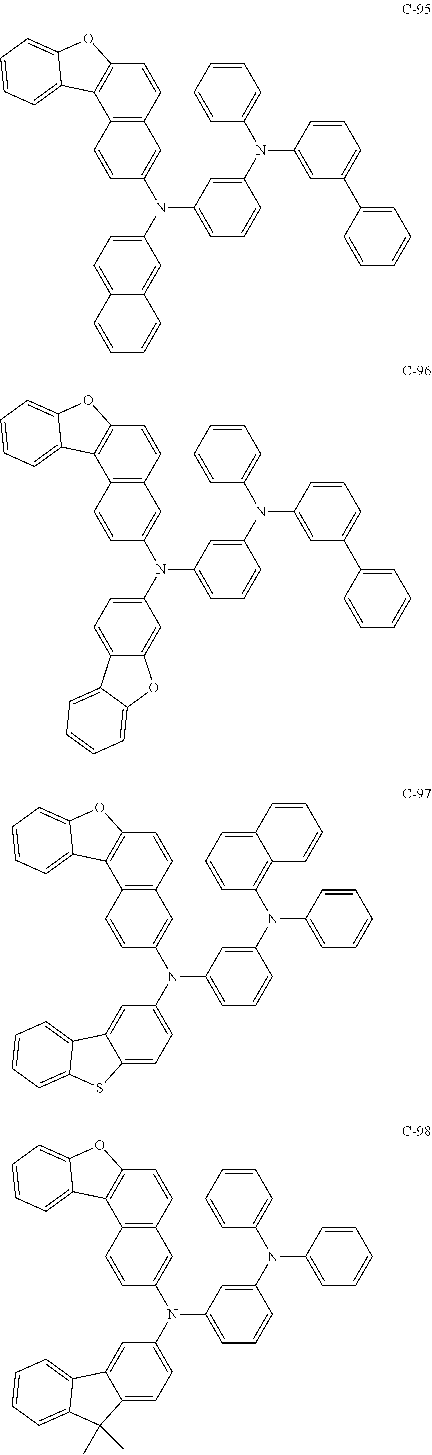 [SMILES: c1ccc(-c2cccc(N(c3ccccc3)c3cccc(N(c4ccc5ccccc5c4)c4ccc5c(ccc6oc7ccccc7c65)c4)c3)c2)cc1 ; c1ccc(-c2cccc(N(c3ccccc3)c3cccc(N(c4ccc5c(ccc6oc7ccccc7c65)c4)c4ccc5c(c4)oc4ccccc45)c3)c2)cc1 ; c1ccc(N(c2cccc(N(c3ccc4c(ccc5oc6ccccc6c54)c3)c3ccc4sc5ccccc5c4c3)c2)c2cccc3ccccc23)cc1 ; CC1(C)c2ccccc2-c2cc(N(c3cccc(N(c4ccccc4)c4ccccc4)c3)c3ccc4c(ccc5oc6ccccc6c54)c3)ccc21]

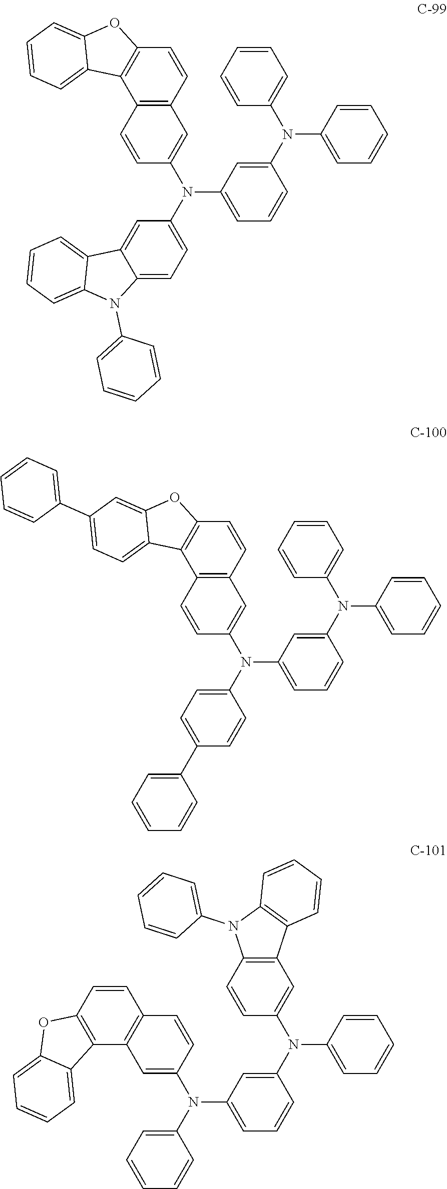

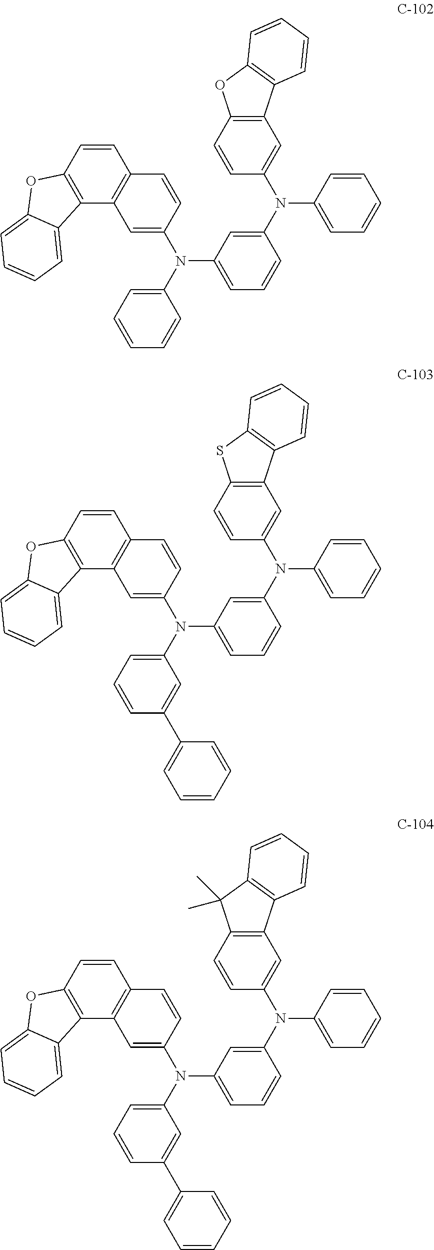 [SMILES: c1ccc(N(c2cccc(N(c3ccccc3)c3ccc4ccc5oc6ccccc6c5c4c3)c2)c2ccc3oc4ccccc4c3c2)cc1 ; c1ccc(-c2cccc(N(c3cccc(N(c4ccccc4)c4ccc5sc6ccccc6c5c4)c3)c3ccc4ccc5oc6ccccc6c5c4c3)c2)cc1 ; CC1(C)c2ccccc2-c2cc(N(c3ccccc3)c3cccc(N(c4cccc(-c5ccccc5)c4)c4ccc5ccc6oc7ccccc7c6c5c4)c3)ccc21]

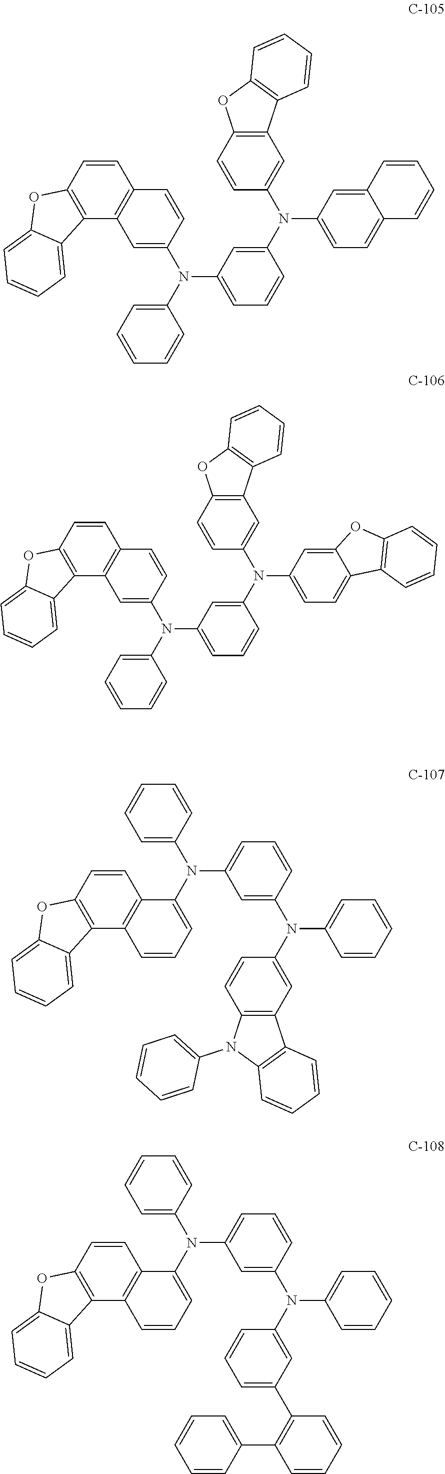 [SMILES: c1ccc(N(c2cccc(N(c3ccc4ccccc4c3)c3ccc4oc5ccccc5c4c3)c2)c2ccc3ccc4oc5ccccc5c4c3c2)cc1 ; c1ccc(N(c2cccc(N(c3ccc4c(c3)oc3ccccc34)c3ccc4oc5ccccc5c4c3)c2)c2ccc3ccc4oc5ccccc5c4c3c2)cc1 ; c1ccc(N(c2cccc(N(c3ccccc3)c3cccc4c3ccc3oc5ccccc5c34)c2)c2ccc3c(c2)c2ccccc2n3-c2ccccc2)cc1 ; c1ccc(-c2ccccc2-c2cccc(N(c3ccccc3)c3cccc(N(c4ccccc4)c4cccc5c4ccc4oc6ccccc6c45)c3)c2)cc1]

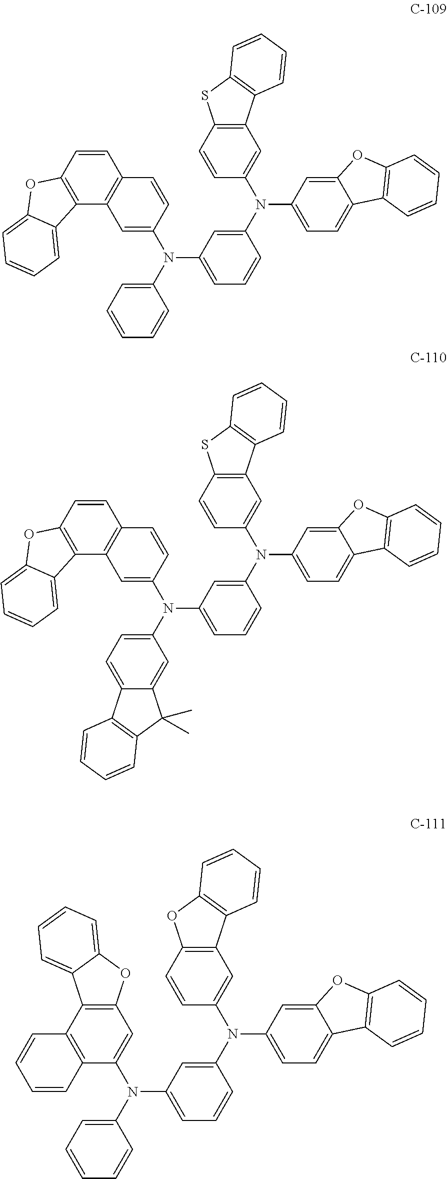 [SMILES: c1ccc(N(c2cccc(N(c3ccc4c(c3)oc3ccccc34)c3ccc4sc5ccccc5c4c3)c2)c2ccc3ccc4oc5ccccc5c4c3c2)cc1 ; CC1(C)c2ccccc2-c2ccc(N(c3cccc(N(c4ccc5c(c4)oc4ccccc45)c4ccc5sc6ccccc6c5c4)c3)c3ccc4ccc5oc6ccccc6c5c4c3)cc21 ; c1ccc(N(c2cccc(N(c3ccc4c(c3)oc3ccccc34)c3ccc4oc5ccccc5c4c3)c2)c2cc3oc4ccccc4c3c3ccccc23)cc1]

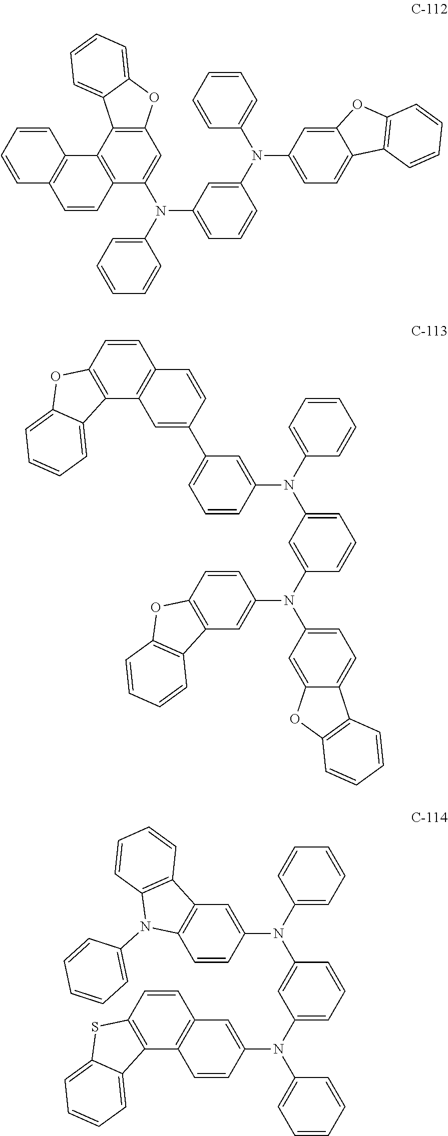 [SMILES: c1ccc(N(c2cccc(N(c3ccccc3)c3cc4oc5ccccc5c4c4c3ccc3ccccc34)c2)c2ccc3c(c2)oc2ccccc23)cc1 ; c1ccc(N(c2cccc(-c3ccc4ccc5oc6ccccc6c5c4c3)c2)c2cccc(N(c3ccc4c(c3)oc3ccccc34)c3ccc4oc5ccccc5c4c3)c2)cc1 ; c1ccc(N(c2cccc(N(c3ccccc3)c3ccc4c(c3)c3ccccc3n4-c3ccccc3)c2)c2ccc3c(ccc4sc5ccccc5c43)c2)cc1]

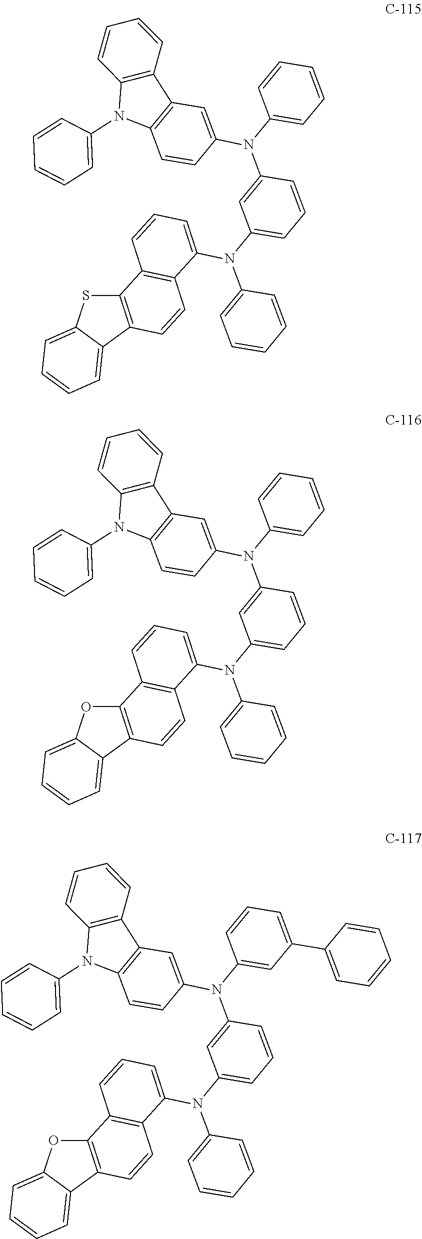 [SMILES: c1ccc(N(c2cccc(N(c3ccccc3)c3cccc4c3ccc3c5ccccc5sc43)c2)c2ccc3c(c2)c2ccccc2n3-c2ccccc2)cc1 ; c1ccc(N(c2cccc(N(c3ccccc3)c3cccc4c3ccc3c5ccccc5oc43)c2)c2ccc3c(c2)c2ccccc2n3-c2ccccc2)cc1 ; c1ccc(-c2cccc(N(c3cccc(N(c4ccccc4)c4cccc5c4ccc4c6ccccc6oc54)c3)c3ccc4c(c3)c3ccccc3n4-c3ccccc3)c2)cc1]

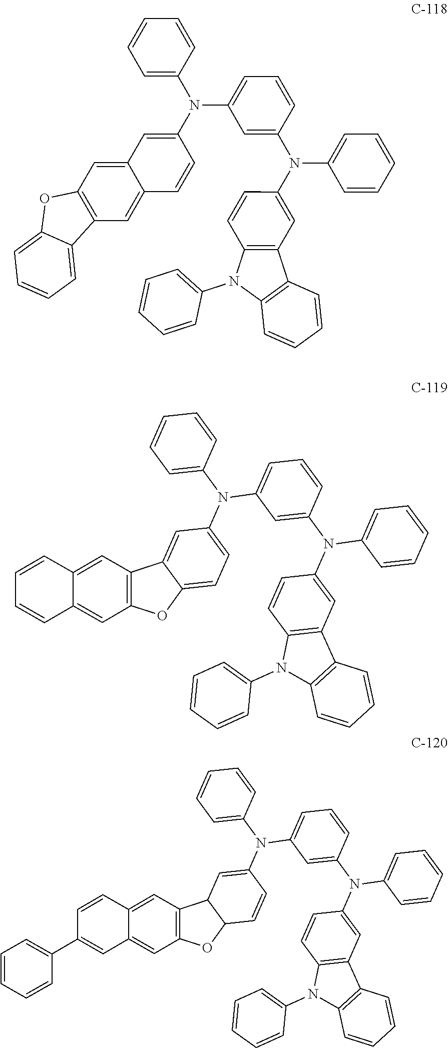

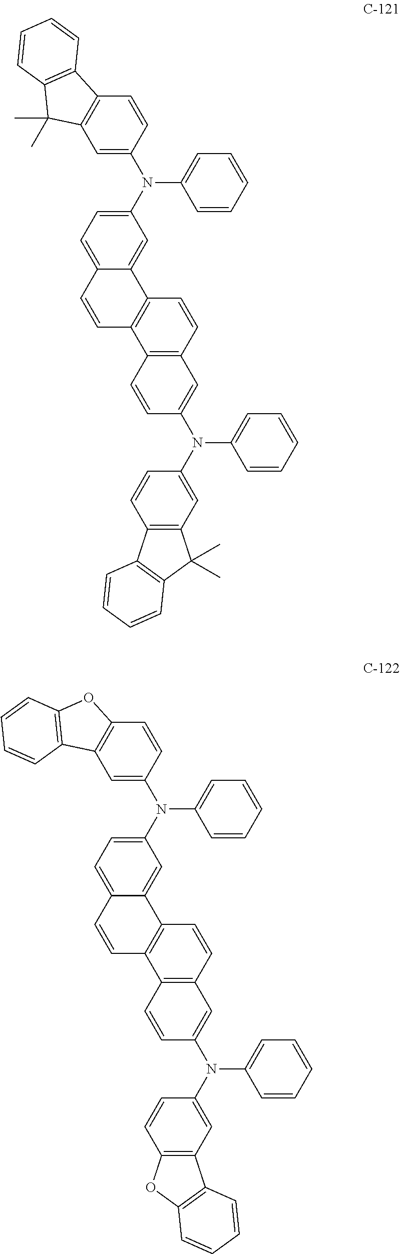 [SMILES: CC1(C)c2ccccc2-c2ccc(N(c3ccccc3)c3ccc4c(ccc5c6cc(N(c7ccccc7)c7ccc8c(c7)C(C)(C)c7ccccc7-8)ccc6ccc45)c3)cc21 ; c1ccc(N(c2ccc3c(ccc4c5cc(N(c6ccccc6)c6ccc7oc8ccccc8c7c6)ccc5ccc34)c2)c2ccc3oc4ccccc4c3c2)cc1]

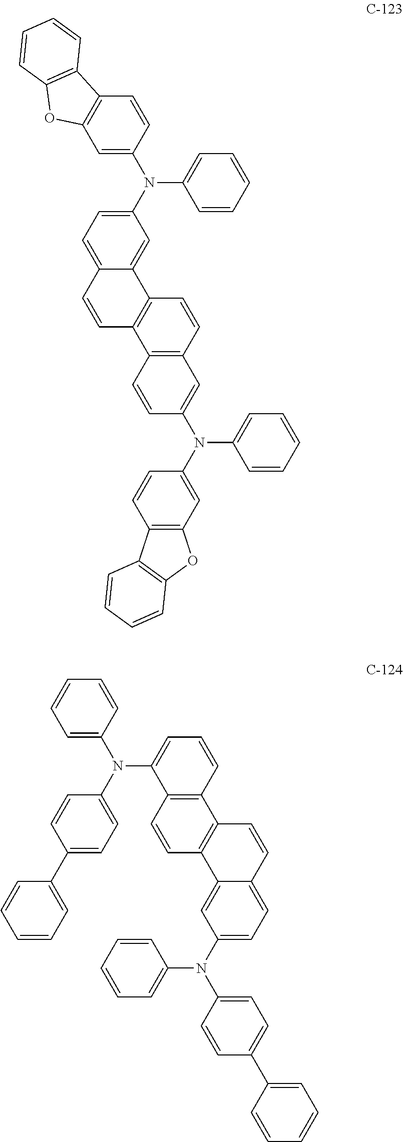 [SMILES: c1ccc(N(c2ccc3c(ccc4c5cc(N(c6ccccc6)c6ccc7c(c6)oc6ccccc67)ccc5ccc34)c2)c2ccc3c(c2)oc2ccccc23)cc1 ; c1ccc(-c2ccc(N(c3ccccc3)c3ccc4ccc5c6cccc(N(c7ccccc7)c7ccc(-c8ccccc8)cc7)c6ccc5c4c3)cc2)cc1]

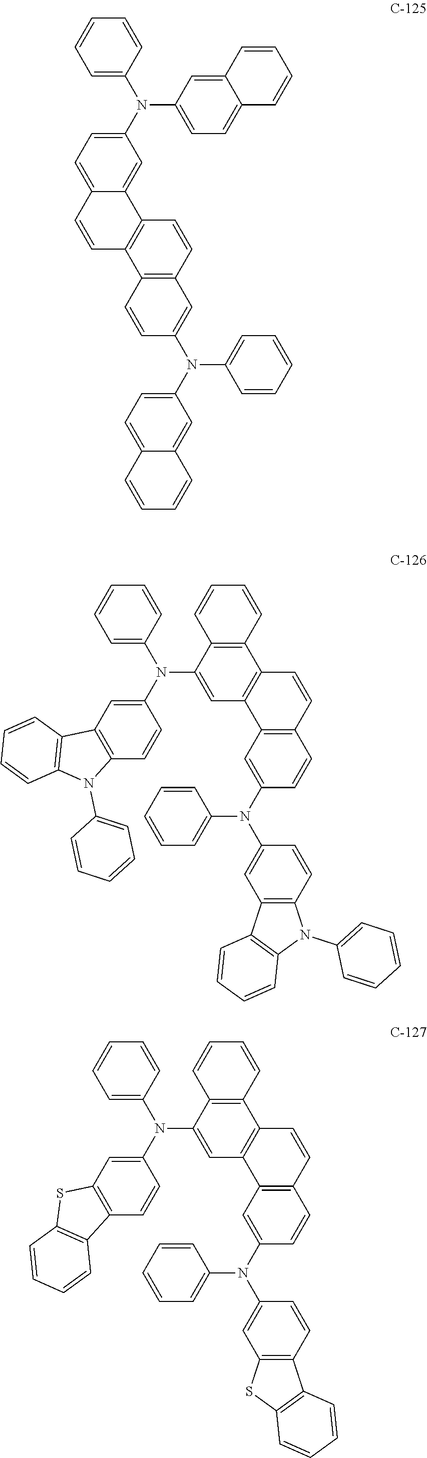

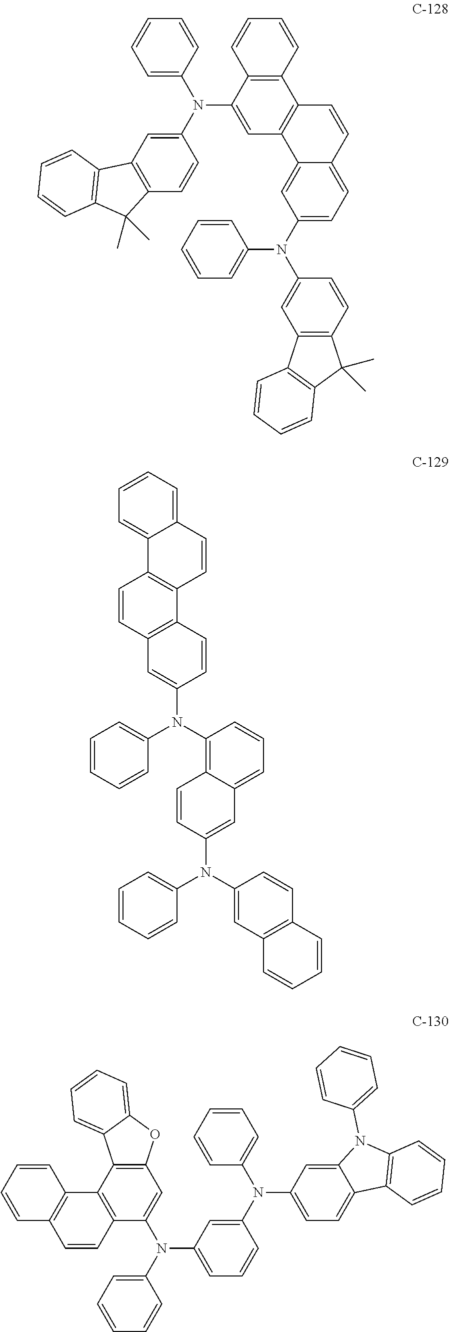 [SMILES: CC1(C)c2ccccc2-c2cc(N(c3ccccc3)c3ccc4ccc5c6ccccc6c(N(c6ccccc6)c6ccc7c(c6)-c6ccccc6C7(C)C)cc5c4c3)ccc21 ; c1ccc(N(c2ccc3ccccc3c2)c2ccc3c(N(c4ccccc4)c4ccc5c(ccc6c7ccccc7ccc56)c4)cccc3c2)cc1 ; c1ccc(N(c2cccc(N(c3ccccc3)c3cc4oc5ccccc5c4c4c3ccc3ccccc34)c2)c2ccc3c4ccccc4n(-c4ccccc4)c3c2)cc1]

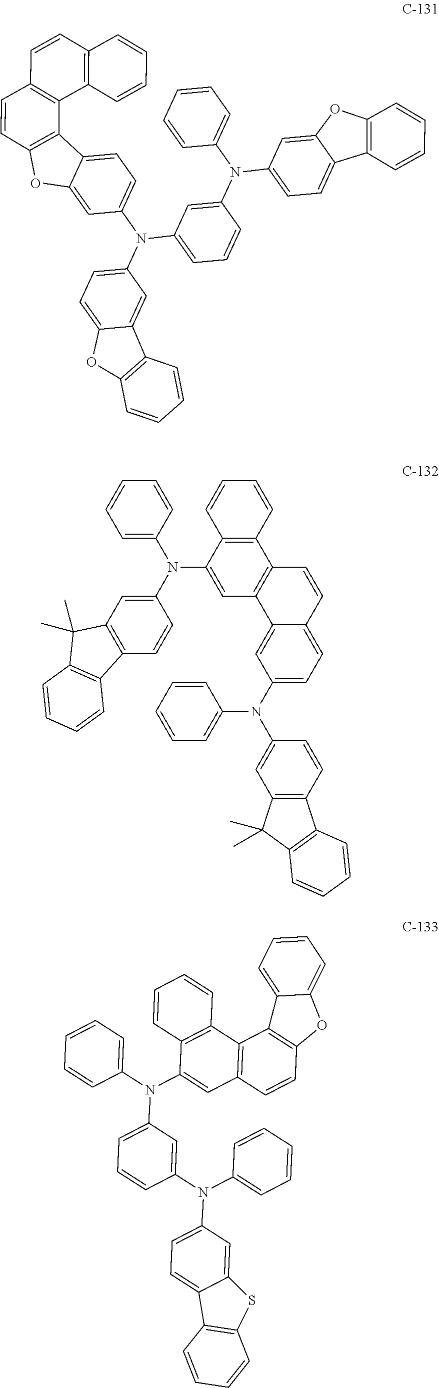

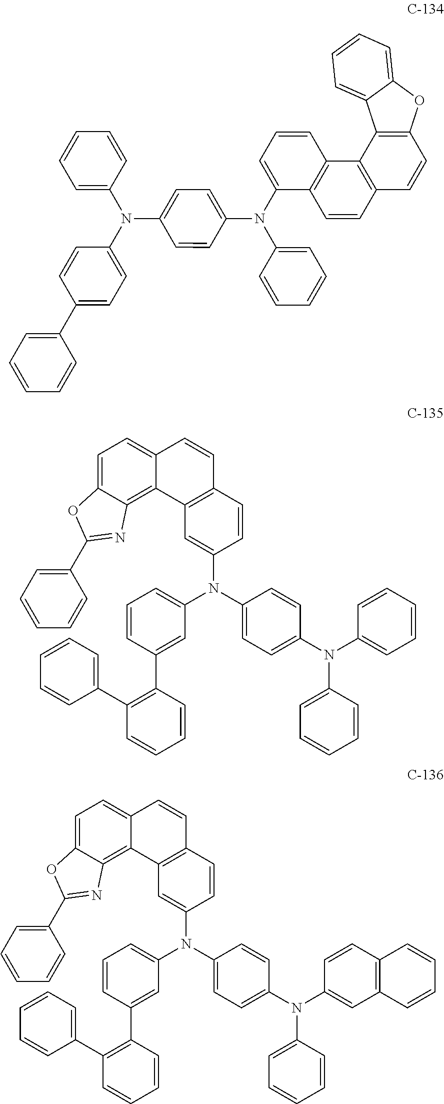

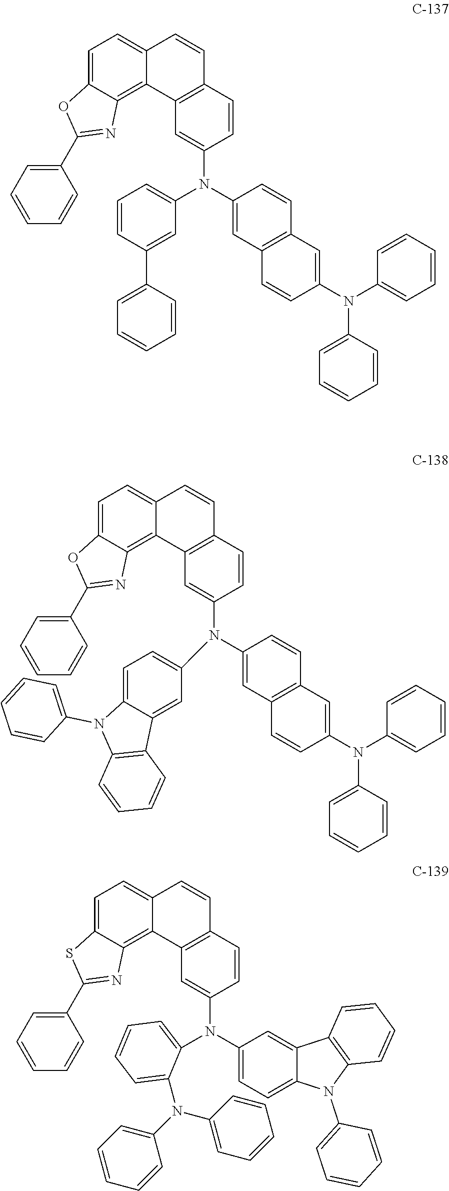 [SMILES: c1ccc(-c2cccc(N(c3ccc4cc(N(c5ccccc5)c5ccccc5)ccc4c3)c3ccc4ccc5ccc6oc(-c7ccccc7)nc6c5c4c3)c2)cc1 ; c1ccc(-c2nc3c(ccc4ccc5ccc(N(c6ccc7cc(N(c8ccccc8)c8ccccc8)ccc7c6)c6ccc7c(c6)c6ccccc6n7-c6ccccc6)cc5c43)o2)cc1 ; c1ccc(-c2nc3c(ccc4ccc5ccc(N(c6ccc7c(c6)c6ccccc6n7-c6ccccc6)c6ccccc6N(c6ccccc6)c6ccccc6)cc5c43)s2)cc1]

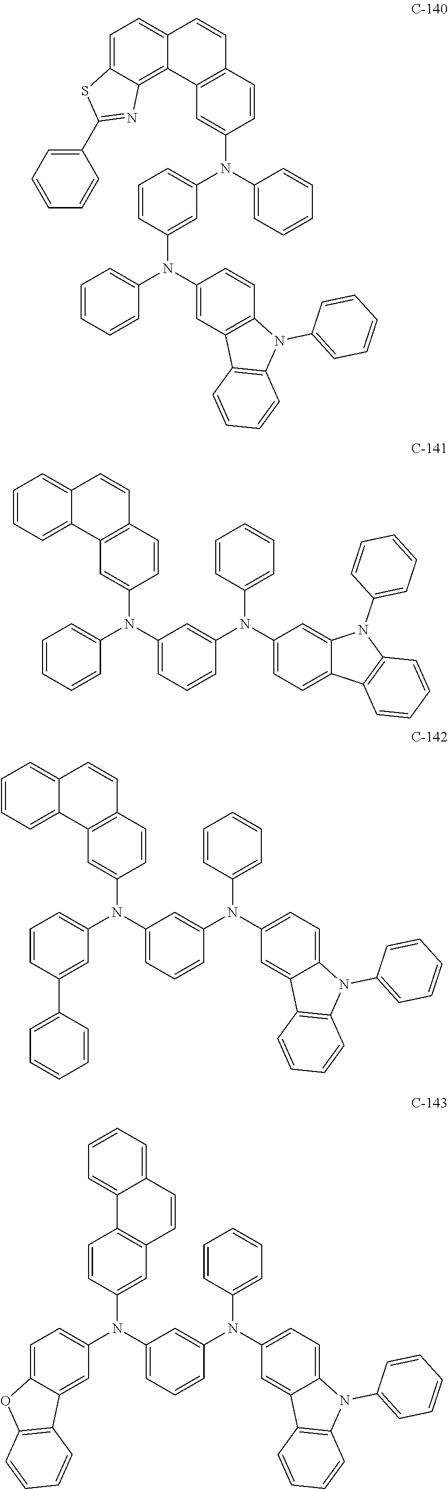 [SMILES: c1ccc(-c2nc3c(ccc4ccc5ccc(N(c6ccccc6)c6cccc(N(c7ccccc7)c7ccc8c(c7)c7ccccc7n8-c7ccccc7)c6)cc5c43)s2)cc1 ; c1ccc(N(c2cccc(N(c3ccccc3)c3ccc4c5ccccc5n(-c5ccccc5)c4c3)c2)c2ccc3ccc4ccccc4c3c2)cc1 ; c1ccc(-c2cccc(N(c3cccc(N(c4ccccc4)c4ccc5c(c4)c4ccccc4n5-c4ccccc4)c3)c3ccc4ccc5ccccc5c4c3)c2)cc1 ; c1ccc(N(c2cccc(N(c3ccc4c(ccc5ccccc54)c3)c3ccc4oc5ccccc5c4c3)c2)c2ccc3c(c2)c2ccccc2n3-c2ccccc2)cc1]

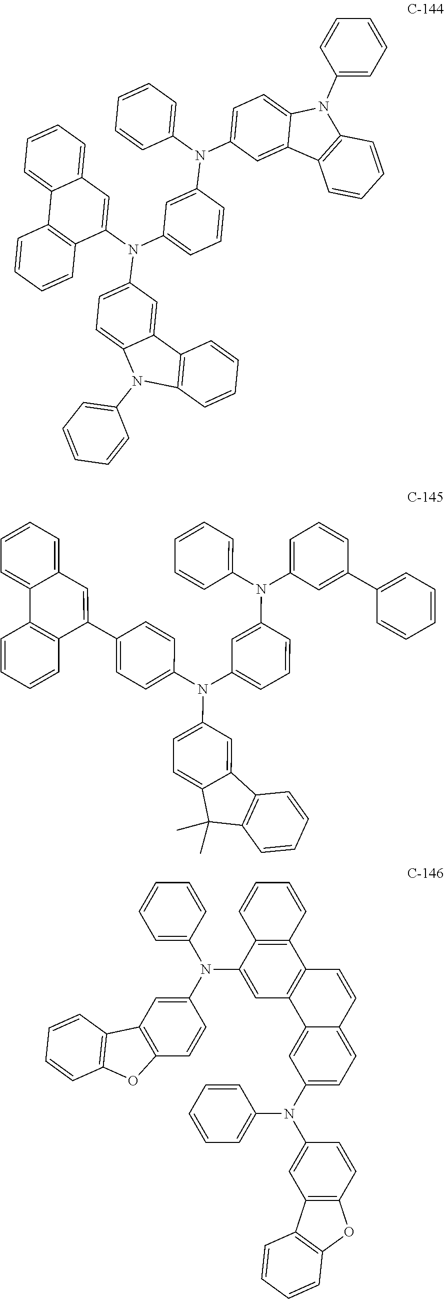

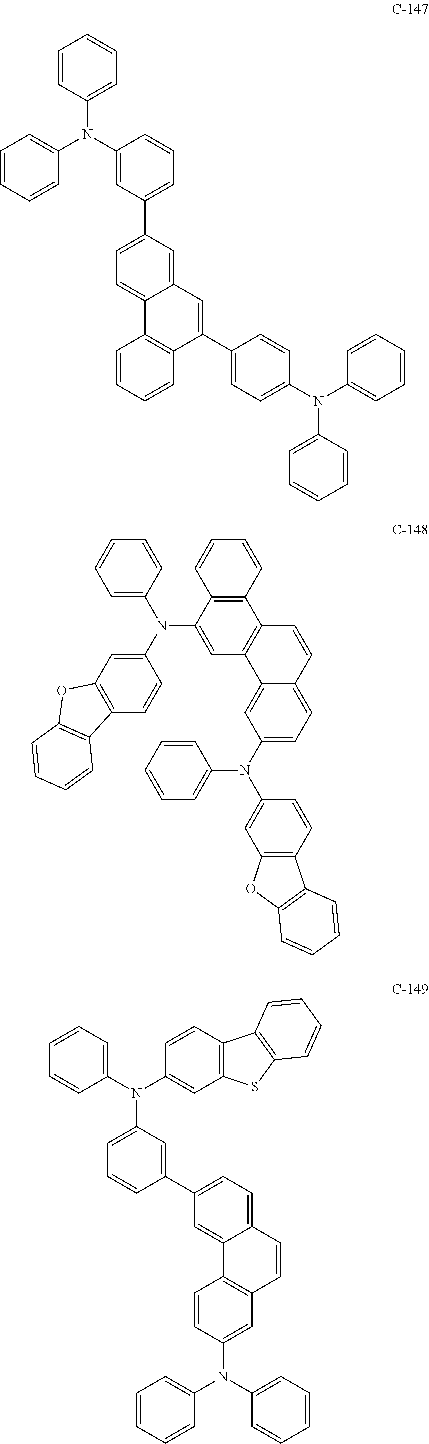

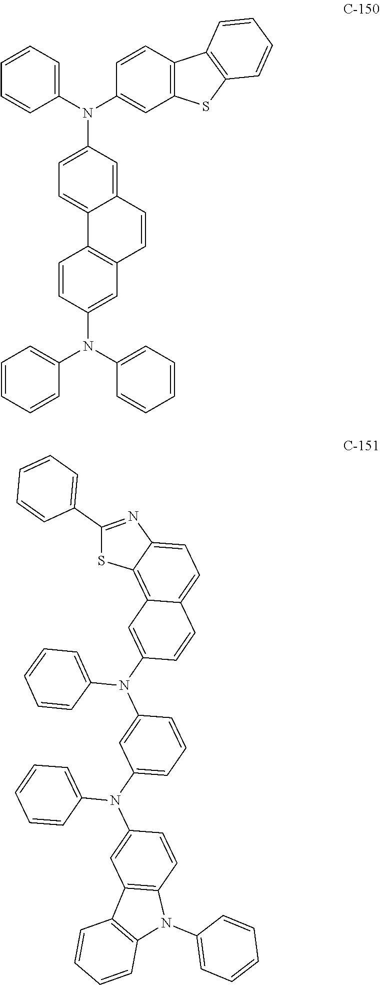 [SMILES: c1ccc(N(c2ccccc2)c2ccc3c(ccc4cc(N(c5ccccc5)c5ccc6c(c5)sc5ccccc56)ccc43)c2)cc1 ; c1ccc(-c2nc3ccc4ccc(N(c5ccccc5)c5cccc(N(c6ccccc6)c6ccc7c(c6)c6ccccc6n7-c6ccccc6)c5)cc4c3s2)cc1]

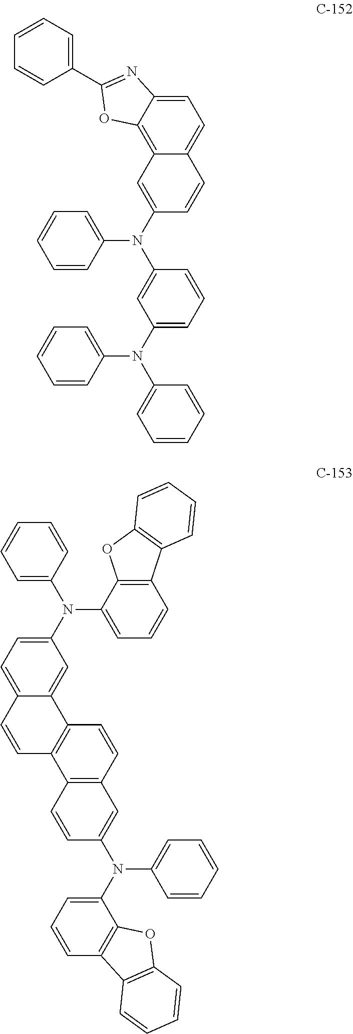

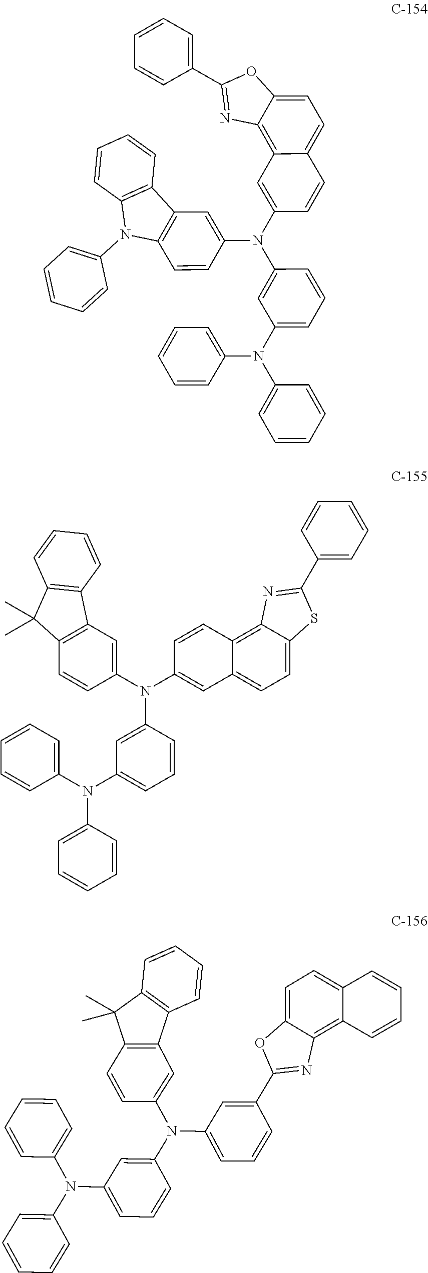 [SMILES: c1ccc(-c2nc3c(ccc4ccc(N(c5cccc(N(c6ccccc6)c6ccccc6)c5)c5ccc6c(c5)c5ccccc5n6-c5ccccc5)cc43)o2)cc1 ; CC1(C)c2ccccc2-c2cc(N(c3cccc(N(c4ccccc4)c4ccccc4)c3)c3ccc4c(ccc5sc(-c6ccccc6)nc54)c3)ccc21 ; CC1(C)c2ccccc2-c2cc(N(c3cccc(-c4nc5c(ccc6ccccc65)o4)c3)c3cccc(N(c4ccccc4)c4ccccc4)c3)ccc21]

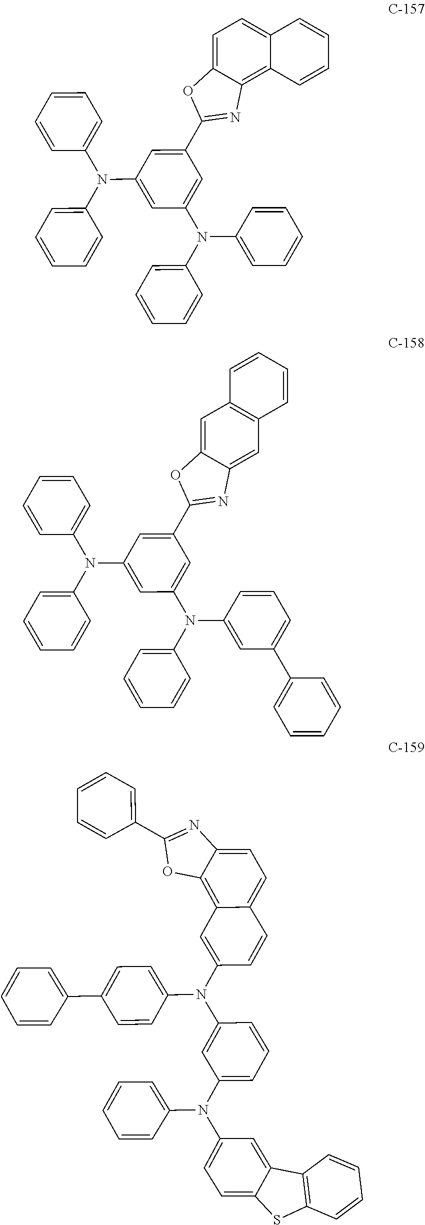 [SMILES: c1ccc(N(c2ccccc2)c2cc(-c3nc4c(ccc5ccccc54)o3)cc(N(c3ccccc3)c3ccccc3)c2)cc1 ; c1ccc(-c2cccc(N(c3ccccc3)c3cc(-c4nc5cc6ccccc6cc5o4)cc(N(c4ccccc4)c4ccccc4)c3)c2)cc1 ; c1ccc(-c2ccc(N(c3cccc(N(c4ccccc4)c4ccc5sc6ccccc6c5c4)c3)c3ccc4ccc5nc(-c6ccccc6)oc5c4c3)cc2)cc1]

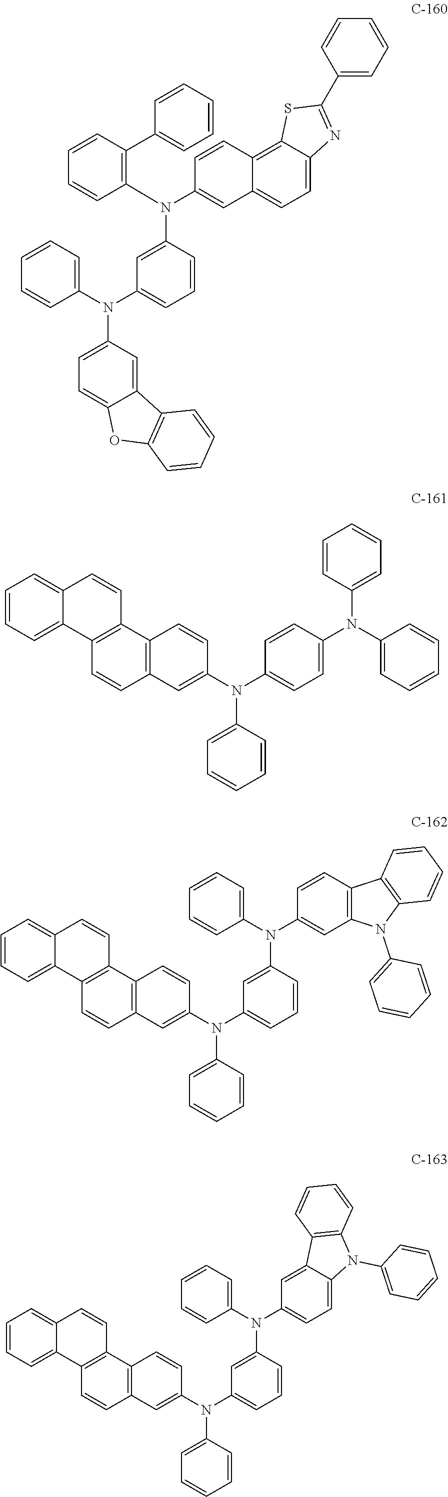 [SMILES: c1ccc(-c2nc3ccc4cc(N(c5cccc(N(c6ccccc6)c6ccc7oc8ccccc8c7c6)c5)c5ccccc5-c5ccccc5)ccc4c3s2)cc1 ; c1ccc(N(c2ccccc2)c2ccc(N(c3ccccc3)c3ccc4c(ccc5c6ccccc6ccc45)c3)cc2)cc1 ; c1ccc(N(c2cccc(N(c3ccccc3)c3ccc4c5ccccc5n(-c5ccccc5)c4c3)c2)c2ccc3c(ccc4c5ccccc5ccc34)c2)cc1 ; c1ccc(N(c2cccc(N(c3ccccc3)c3ccc4c(c3)c3ccccc3n4-c3ccccc3)c2)c2ccc3c(ccc4c5ccccc5ccc34)c2)cc1]

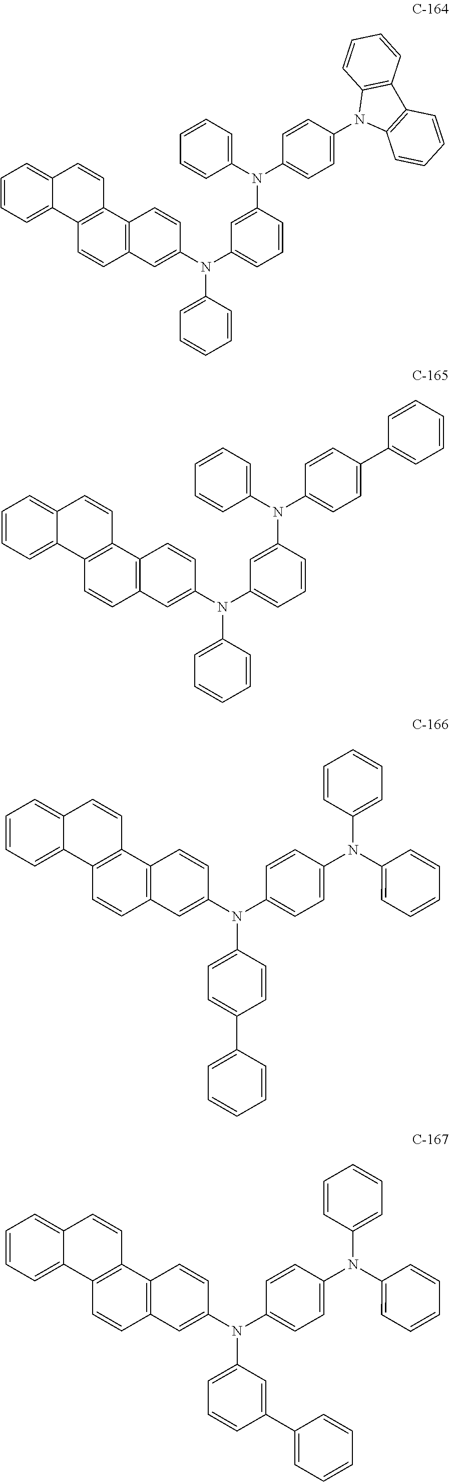 [SMILES: c1ccc(N(c2ccc(-n3c4ccccc4c4ccccc43)cc2)c2cccc(N(c3ccccc3)c3ccc4c(ccc5c6ccccc6ccc45)c3)c2)cc1 ; c1ccc(-c2ccc(N(c3ccccc3)c3cccc(N(c4ccccc4)c4ccc5c(ccc6c7ccccc7ccc56)c4)c3)cc2)cc1 ; c1ccc(-c2ccc(N(c3ccc(N(c4ccccc4)c4ccccc4)cc3)c3ccc4c(ccc5c6ccccc6ccc45)c3)cc2)cc1 ; c1ccc(-c2cccc(N(c3ccc(N(c4ccccc4)c4ccccc4)cc3)c3ccc4c(ccc5c6ccccc6ccc45)c3)c2)cc1]

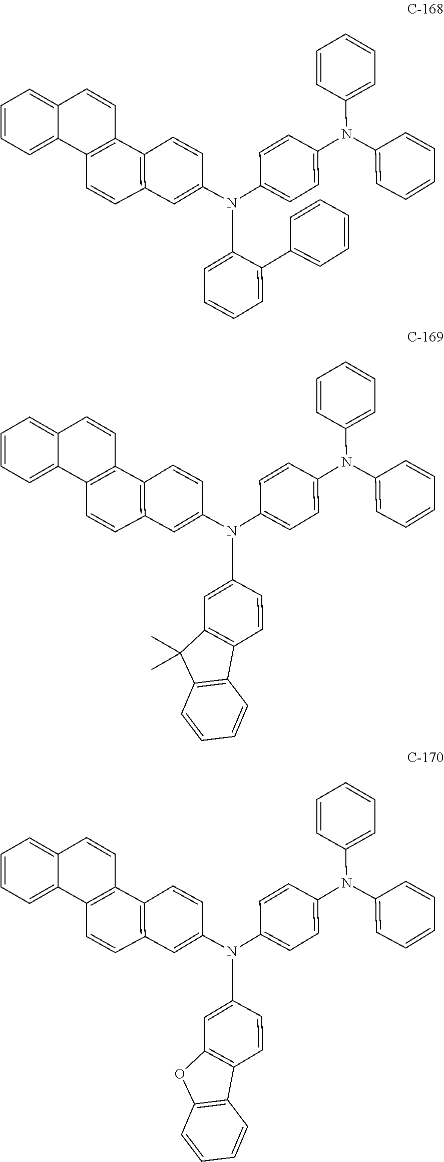 [SMILES: c1ccc(-c2ccccc2N(c2ccc(N(c3ccccc3)c3ccccc3)cc2)c2ccc3c(ccc4c5ccccc5ccc34)c2)cc1 ; CC1(C)c2ccccc2-c2ccc(N(c3ccc(N(c4ccccc4)c4ccccc4)cc3)c3ccc4c(ccc5c6ccccc6ccc45)c3)cc21 ; c1ccc(N(c2ccccc2)c2ccc(N(c3ccc4c(ccc5c6ccccc6ccc45)c3)c3ccc4c(c3)oc3ccccc34)cc2)cc1]

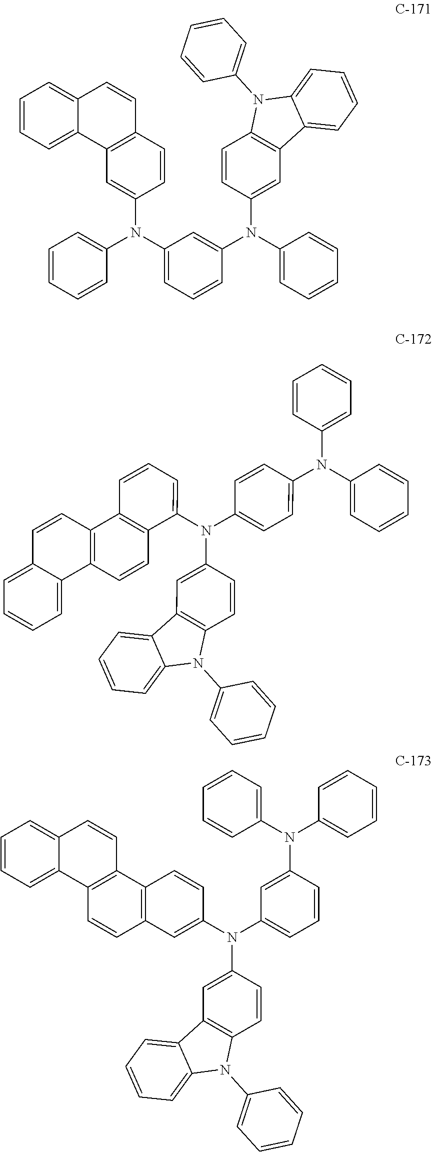

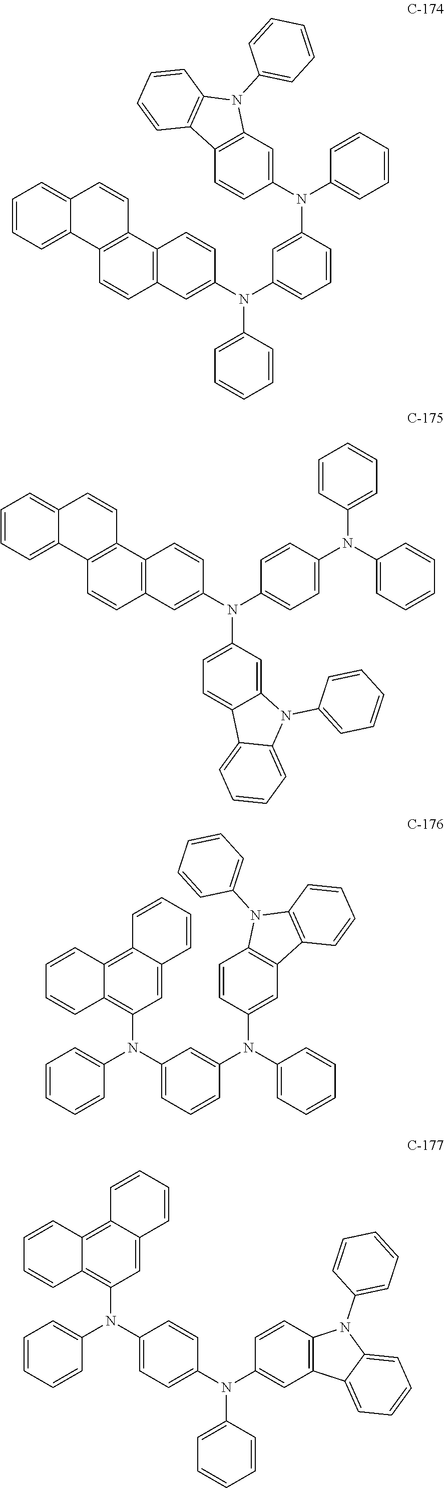

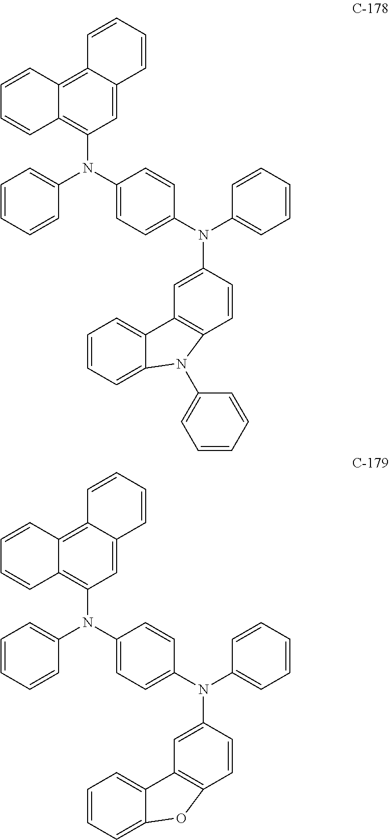 [SMILES: c1ccc(N(c2ccc(N(c3ccccc3)c3cc4ccccc4c4ccccc34)cc2)c2ccc3c(c2)c2ccccc2n3-c2ccccc2)cc1 ; c1ccc(N(c2ccc(N(c3ccccc3)c3cc4ccccc4c4ccccc34)cc2)c2ccc3oc4ccccc4c3c2)cc1]

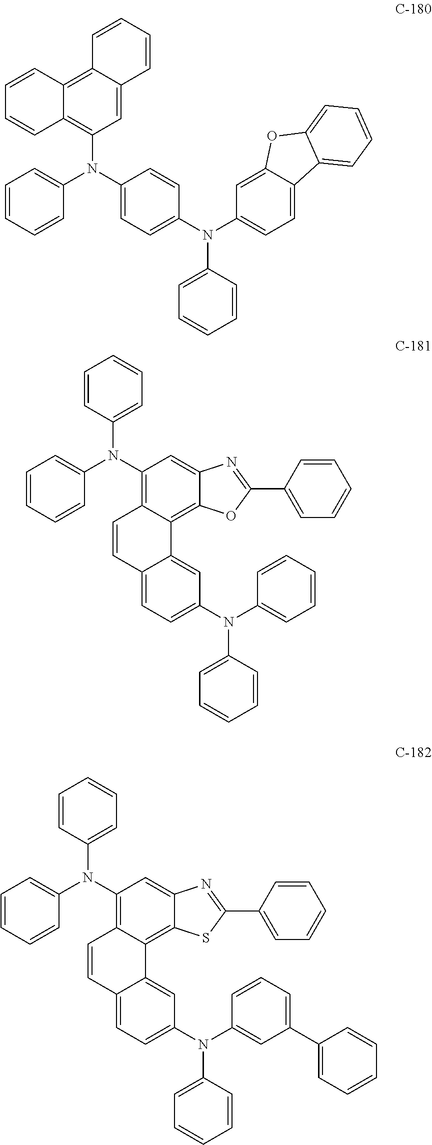 [SMILES: c1ccc(N(c2ccc(N(c3ccccc3)c3cc4ccccc4c4ccccc34)cc2)c2ccc3c(c2)oc2ccccc23)cc1 ; c1ccc(-c2nc3cc(N(c4ccccc4)c4ccccc4)c4ccc5ccc(N(c6ccccc6)c6ccccc6)cc5c4c3o2)cc1 ; c1ccc(-c2cccc(N(c3ccccc3)c3ccc4ccc5c(N(c6ccccc6)c6ccccc6)cc6nc(-c7ccccc7)sc6c5c4c3)c2)cc1]

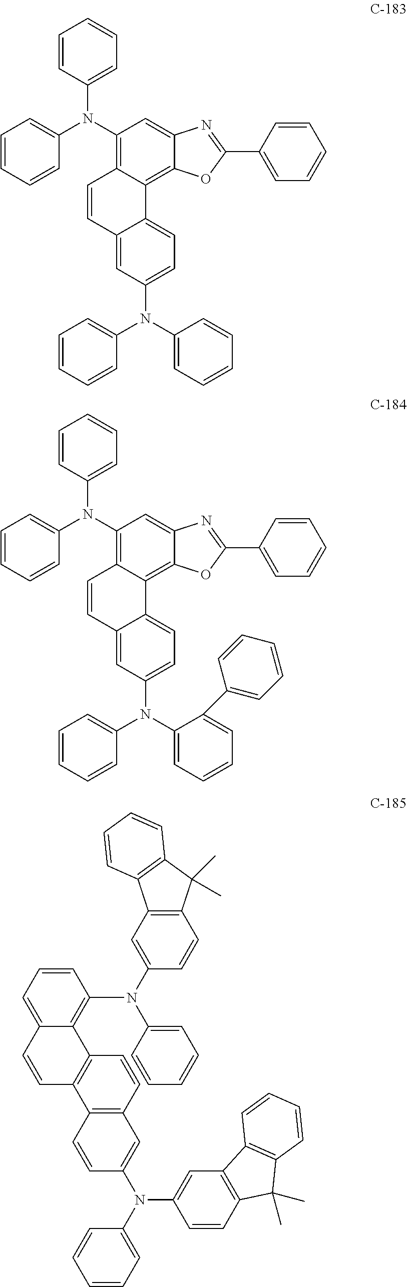

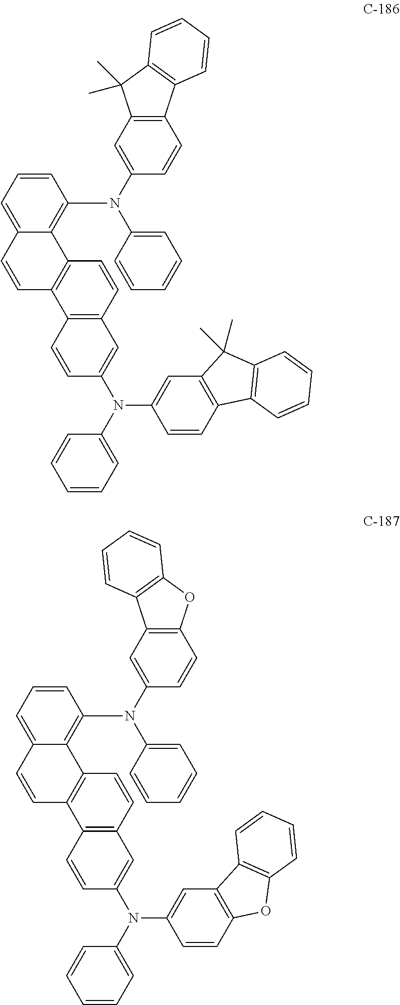 [SMILES: CC1(C)c2ccccc2-c2ccc(N(c3ccccc3)c3ccc4c(ccc5c4ccc4cccc(N(c6ccccc6)c6ccc7c(c6)C(C)(C)c6ccccc6-7)c45)c3)cc21 ; c1ccc(N(c2ccc3c(ccc4c3ccc3cccc(N(c5ccccc5)c5ccc6oc7ccccc7c6c5)c34)c2)c2ccc3oc4ccccc4c3c2)cc1]

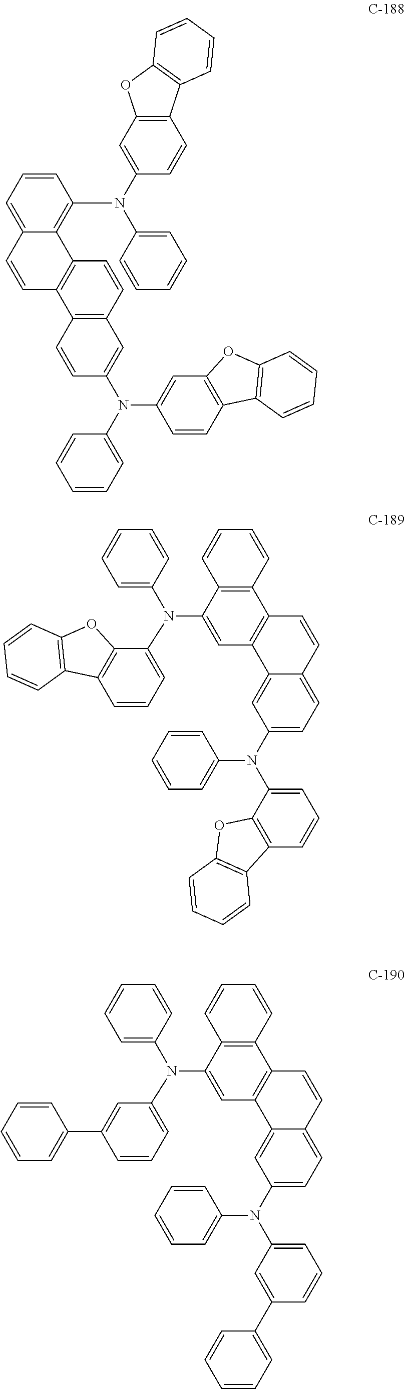

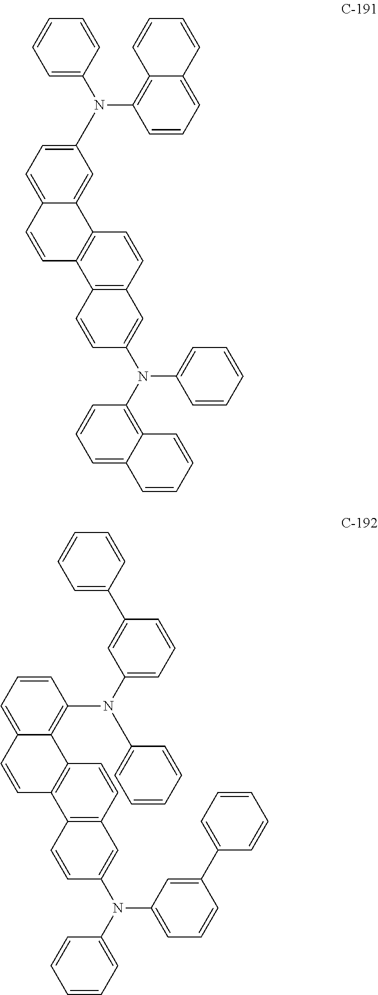 [SMILES: c1ccc(N(c2ccc3c(ccc4c5cc(N(c6ccccc6)c6cccc7ccccc67)ccc5ccc34)c2)c2cccc3ccccc23)cc1 ; c1ccc(-c2cccc(N(c3ccccc3)c3ccc4c(ccc5c4ccc4cccc(N(c6ccccc6)c6cccc(-c7ccccc7)c6)c45)c3)c2)cc1]

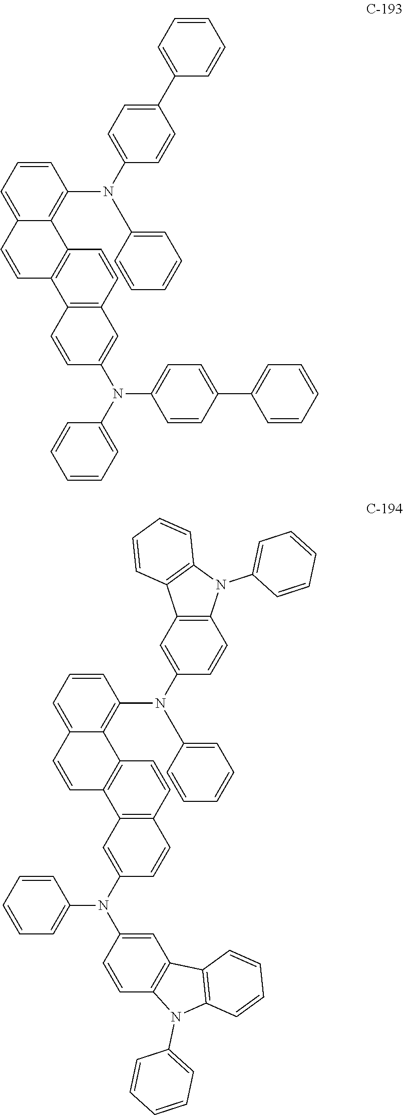 [SMILES: c1ccc(-c2ccc(N(c3ccccc3)c3ccc4c(ccc5c4ccc4cccc(N(c6ccccc6)c6ccc(-c7ccccc7)cc6)c45)c3)cc2)cc1 ; c1ccc(N(c2ccc3ccc4c(ccc5cccc(N(c6ccccc6)c6ccc7c(c6)c6ccccc6n7-c6ccccc6)c54)c3c2)c2ccc3c(c2)c2ccccc2n3-c2ccccc2)cc1]

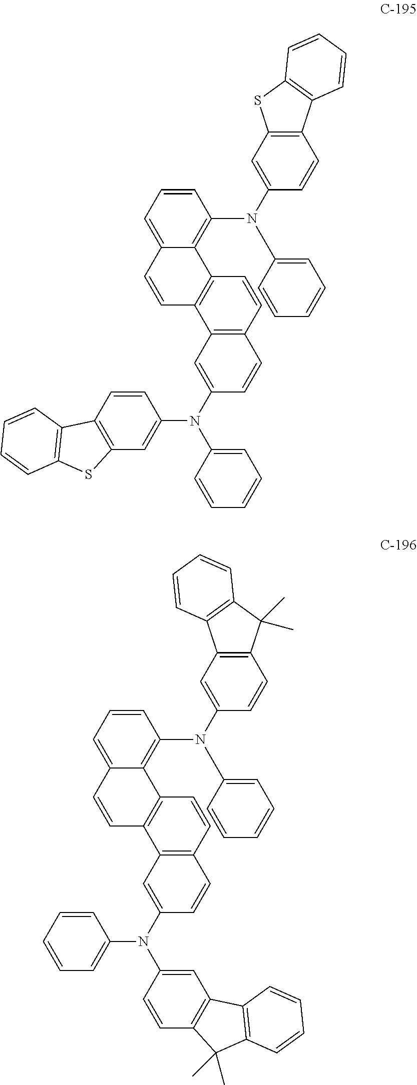 [SMILES: c1ccc(N(c2ccc3c(c2)sc2ccccc23)c2ccc3ccc4c(ccc5cccc(N(c6ccccc6)c6ccc7c(c6)sc6ccccc67)c54)c3c2)cc1 ; CC1(C)c2ccccc2-c2cc(N(c3ccccc3)c3ccc4ccc5c(ccc6cccc(N(c7ccccc7)c7ccc8c(c7)-c7ccccc7C8(C)C)c65)c4c3)ccc21]

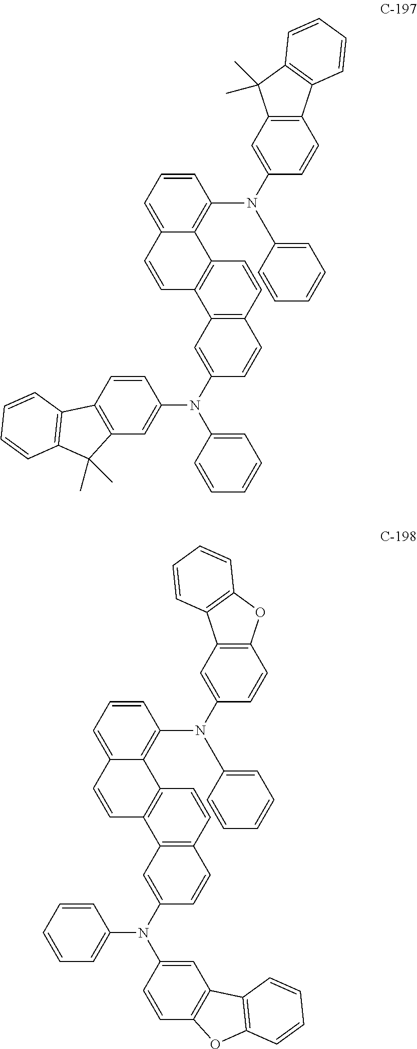 [SMILES: CC1(C)c2ccccc2-c2ccc(N(c3ccccc3)c3ccc4ccc5c(ccc6cccc(N(c7ccccc7)c7ccc8c(c7)C(C)(C)c7ccccc7-8)c65)c4c3)cc21 ; c1ccc(N(c2ccc3ccc4c(ccc5cccc(N(c6ccccc6)c6ccc7oc8ccccc8c7c6)c54)c3c2)c2ccc3oc4ccccc4c3c2)cc1]

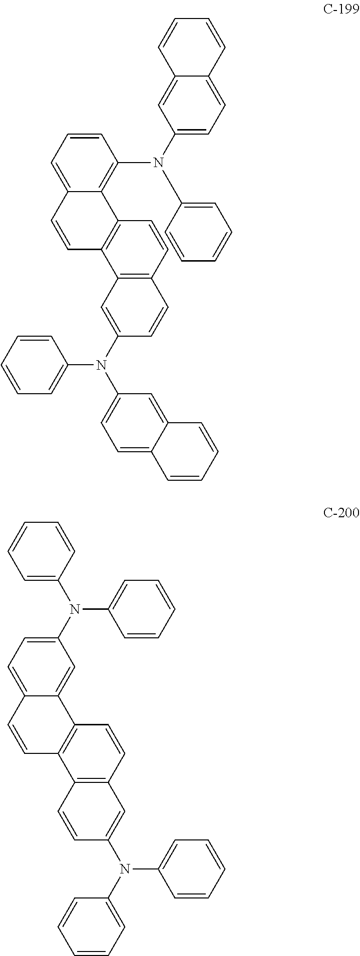 [SMILES: c1ccc(N(c2ccc3ccccc3c2)c2ccc3ccc4c(ccc5cccc(N(c6ccccc6)c6ccc7ccccc7c6)c54)c3c2)cc1 ; c1ccc(N(c2ccccc2)c2ccc3c(ccc4c5cc(N(c6ccccc6)c6ccccc6)ccc5ccc34)c2)cc1]

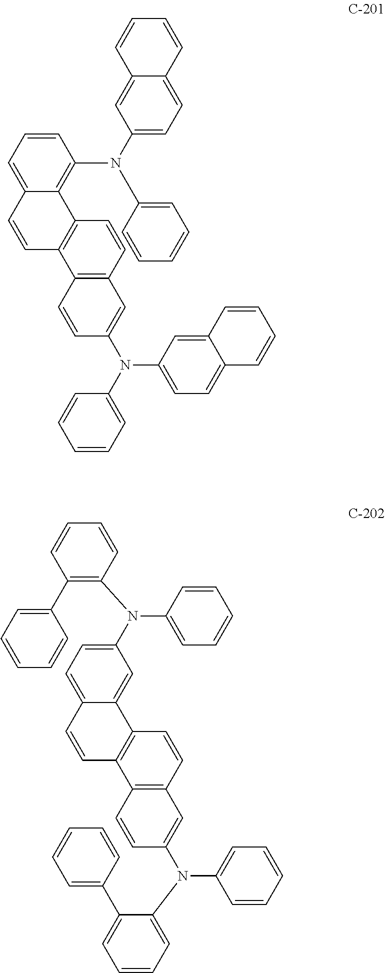 [SMILES: c1ccc(N(c2ccc3ccccc3c2)c2ccc3c(ccc4c3ccc3cccc(N(c5ccccc5)c5ccc6ccccc6c5)c34)c2)cc1 ; c1ccc(-c2ccccc2N(c2ccccc2)c2ccc3c(ccc4c5cc(N(c6ccccc6)c6ccccc6-c6ccccc6)ccc5ccc34)c2)cc1]

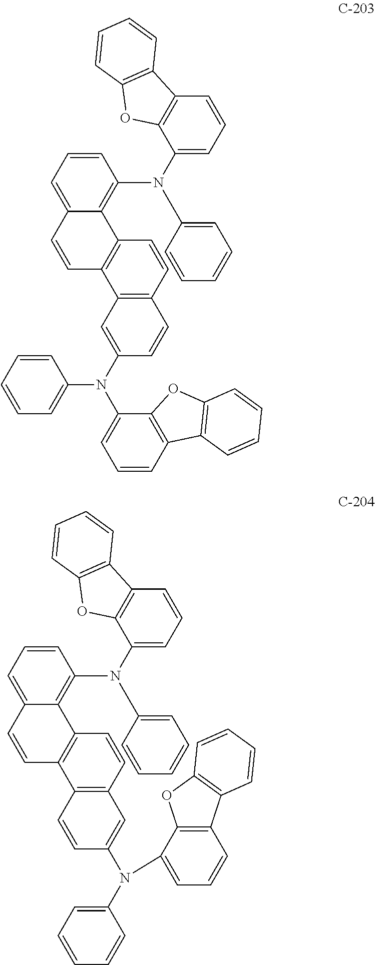 [SMILES: c1ccc(N(c2ccc3ccc4c(ccc5cccc(N(c6ccccc6)c6cccc7c6oc6ccccc67)c54)c3c2)c2cccc3c2oc2ccccc23)cc1 ; c1ccc(N(c2ccc3c(ccc4c3ccc3cccc(N(c5ccccc5)c5cccc6c5oc5ccccc56)c34)c2)c2cccc3c2oc2ccccc23)cc1]

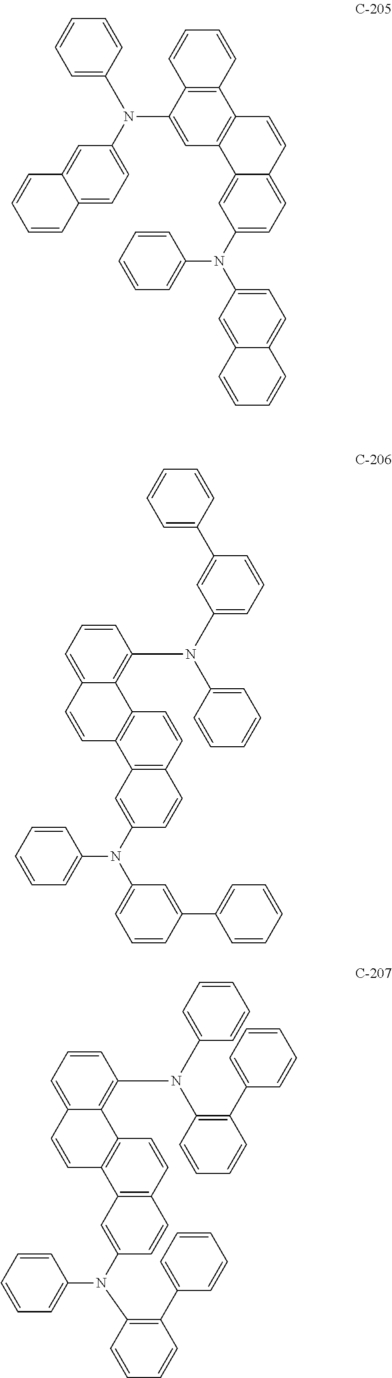

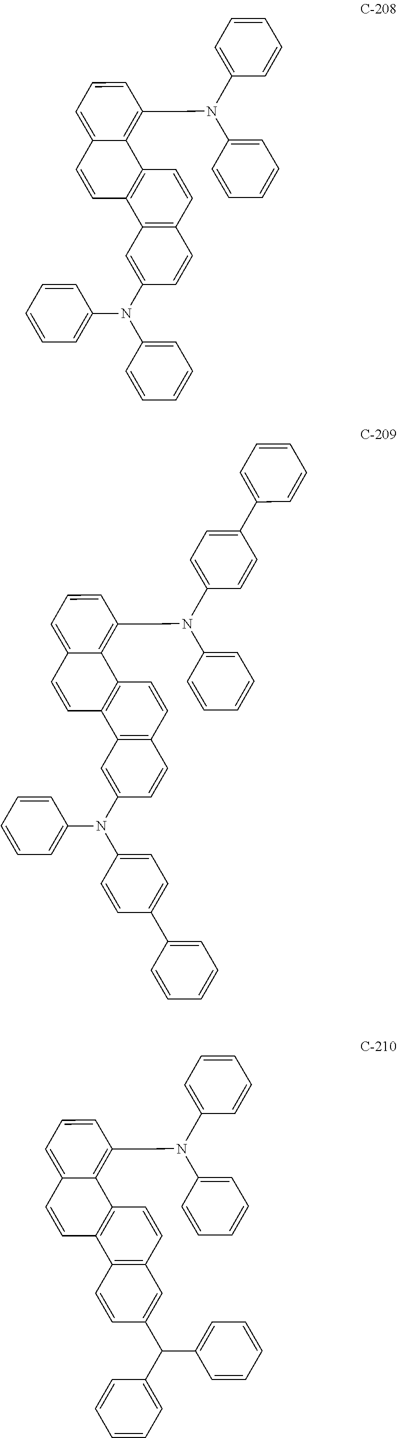 [SMILES: c1ccc(N(c2ccccc2)c2ccc3ccc4c(ccc5cccc(N(c6ccccc6)c6ccccc6)c54)c3c2)cc1 ; c1ccc(-c2ccc(N(c3ccccc3)c3ccc4ccc5c(ccc6cccc(N(c7ccccc7)c7ccc(-c8ccccc8)cc7)c65)c4c3)cc2)cc1 ; c1ccc(C(c2ccccc2)c2ccc3c(ccc4c3ccc3cccc(N(c5ccccc5)c5ccccc5)c34)c2)cc1]

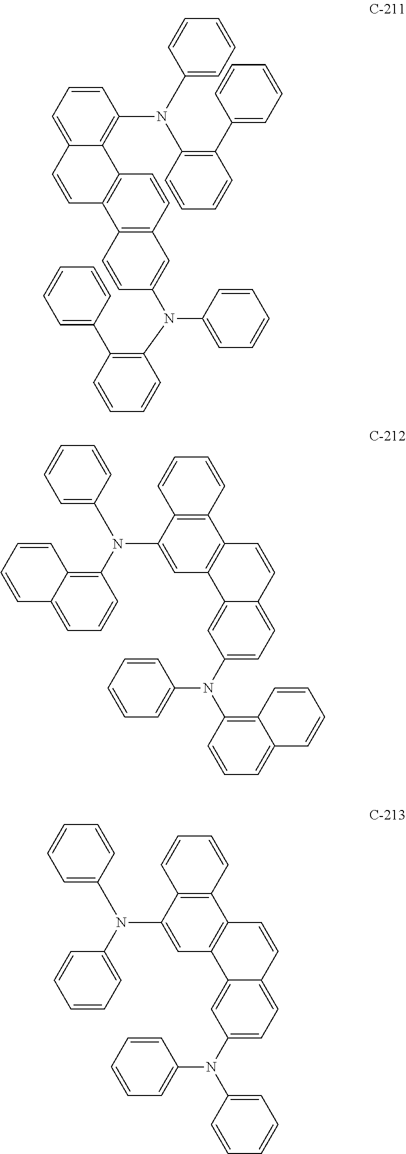

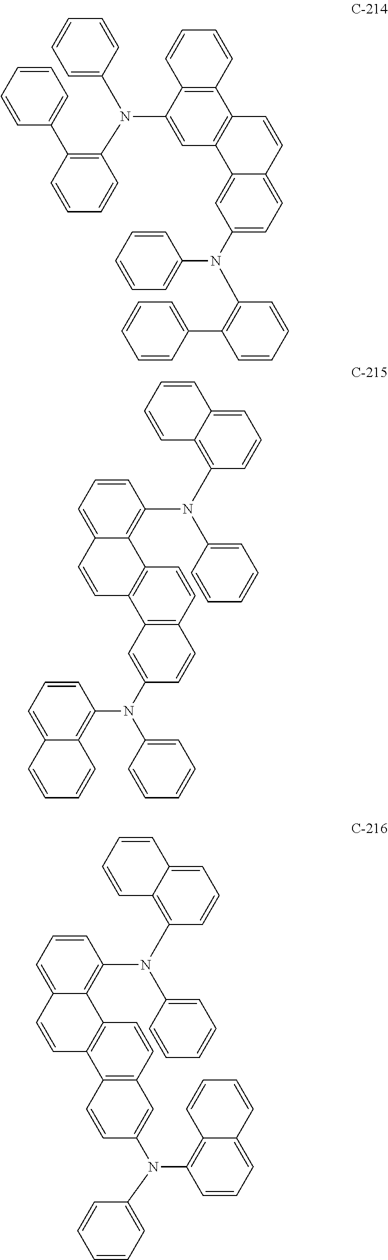

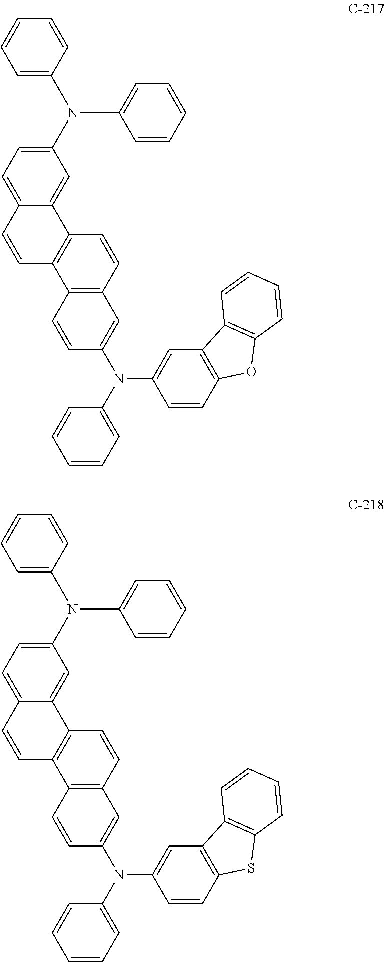 [SMILES: c1ccc(N(c2ccccc2)c2ccc3ccc4c5ccc(N(c6ccccc6)c6ccc7oc8ccccc8c7c6)cc5ccc4c3c2)cc1 ; c1ccc(N(c2ccccc2)c2ccc3ccc4c5ccc(N(c6ccccc6)c6ccc7sc8ccccc8c7c6)cc5ccc4c3c2)cc1]

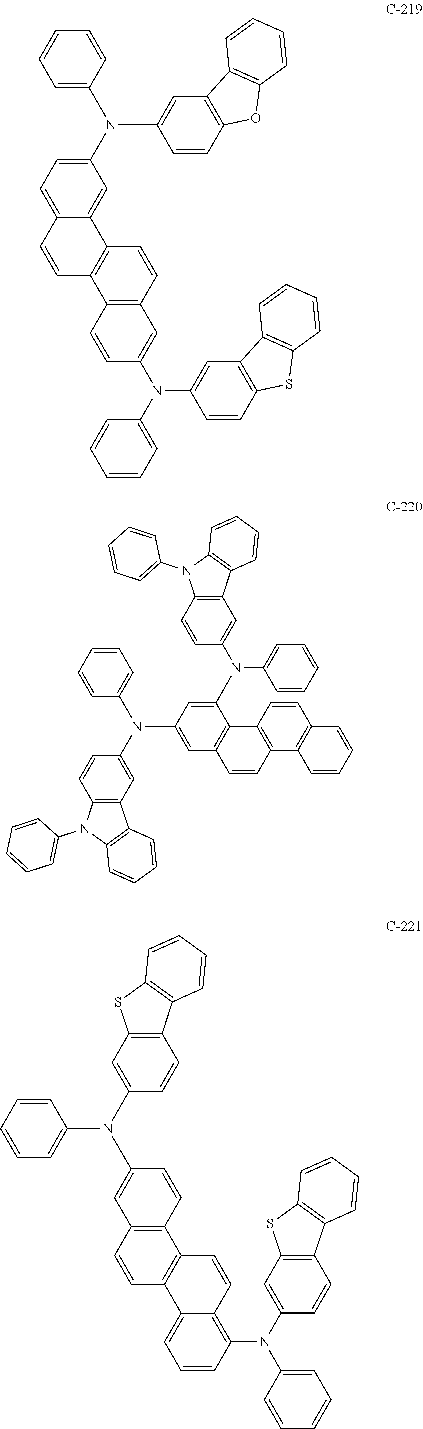 [SMILES: c1ccc(N(c2ccc3ccc4c5ccc(N(c6ccccc6)c6ccc7sc8ccccc8c7c6)cc5ccc4c3c2)c2ccc3oc4ccccc4c3c2)cc1 ; c1ccc(N(c2cc(N(c3ccccc3)c3ccc4c(c3)c3ccccc3n4-c3ccccc3)c3c(ccc4c5ccccc5ccc43)c2)c2ccc3c(c2)c2ccccc2n3-c2ccccc2)cc1 ; c1ccc(N(c2ccc3c(ccc4c5cccc(N(c6ccccc6)c6ccc7c(c6)sc6ccccc67)c5ccc34)c2)c2ccc3c(c2)sc2ccccc23)cc1]

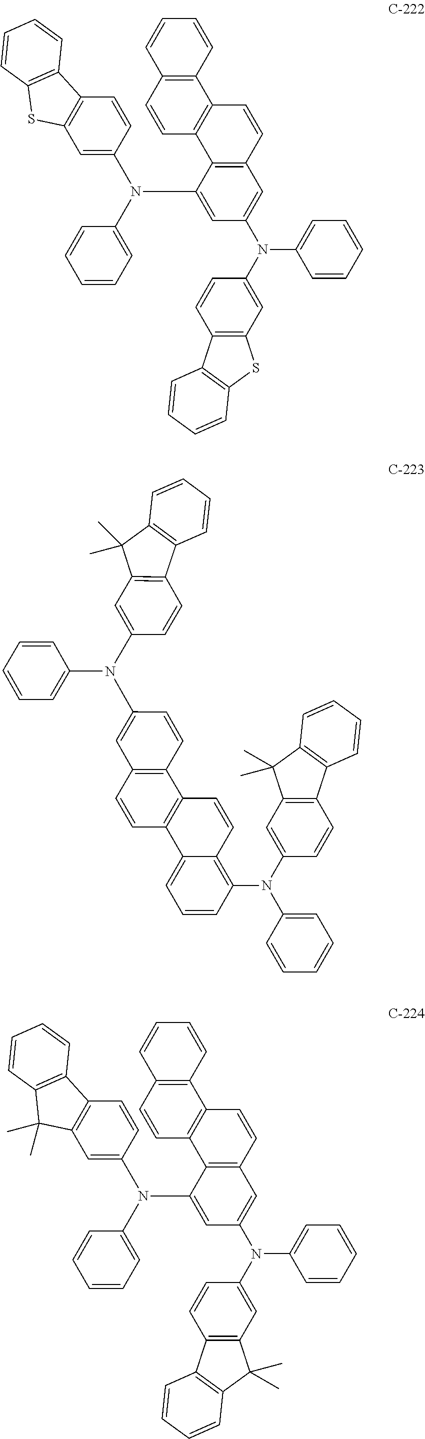

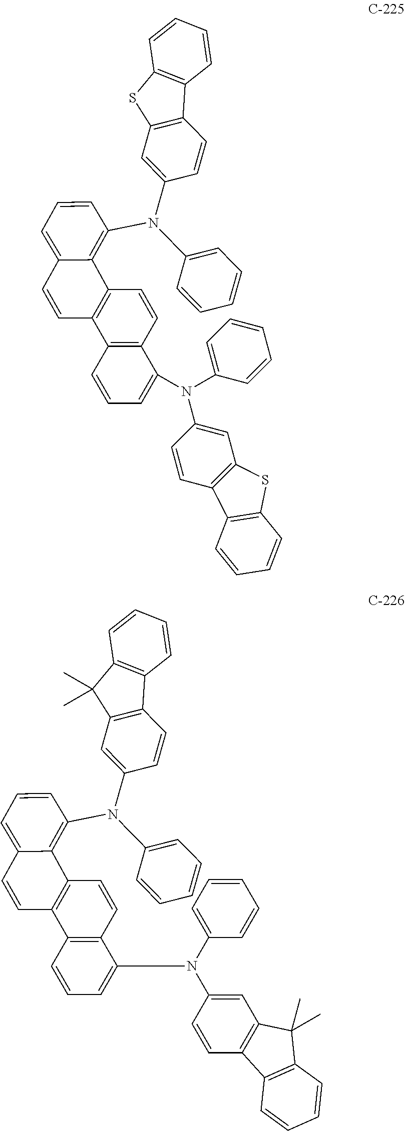 [SMILES: c1ccc(N(c2ccc3c(c2)sc2ccccc23)c2cccc3c2ccc2c3ccc3cccc(N(c4ccccc4)c4ccc5c(c4)sc4ccccc45)c32)cc1 ; CC1(C)c2ccccc2-c2ccc(N(c3ccccc3)c3cccc4c3ccc3c4ccc4cccc(N(c5ccccc5)c5ccc6c(c5)C(C)(C)c5ccccc5-6)c43)cc21]

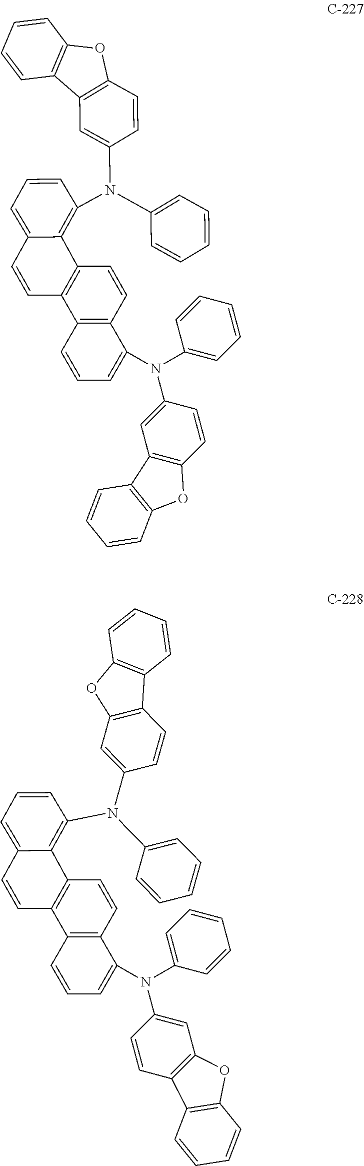 [SMILES: c1ccc(N(c2ccc3oc4ccccc4c3c2)c2cccc3c2ccc2c3ccc3cccc(N(c4ccccc4)c4ccc5oc6ccccc6c5c4)c32)cc1 ; c1ccc(N(c2ccc3c(c2)oc2ccccc23)c2cccc3c2ccc2c3ccc3cccc(N(c4ccccc4)c4ccc5c(c4)oc4ccccc45)c32)cc1]

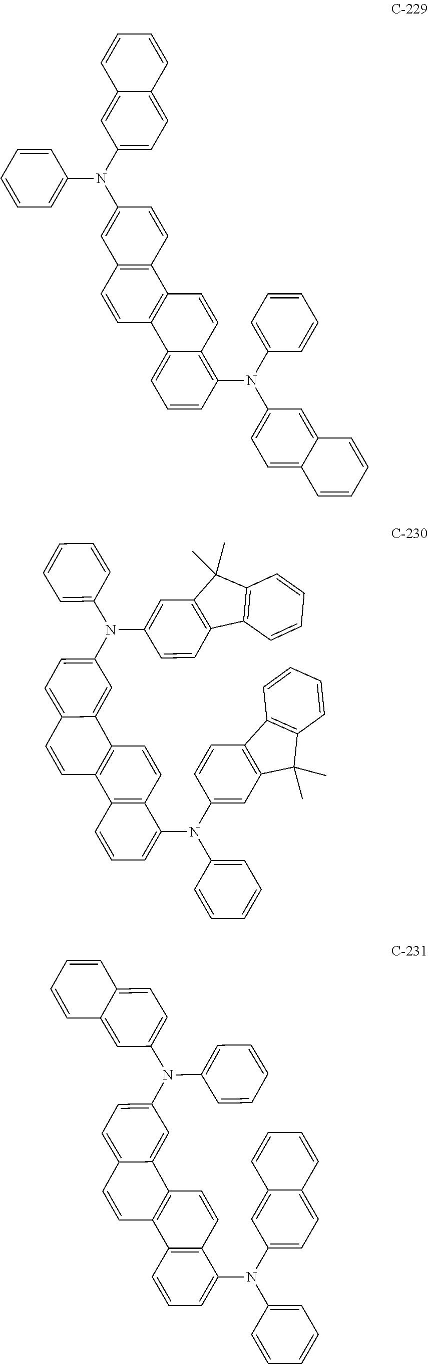 [SMILES: c1ccc(N(c2ccc3ccccc3c2)c2ccc3c(ccc4c5cccc(N(c6ccccc6)c6ccc7ccccc7c6)c5ccc34)c2)cc1 ; CC1(C)c2ccccc2-c2ccc(N(c3ccccc3)c3ccc4ccc5c6cccc(N(c7ccccc7)c7ccc8c(c7)C(C)(C)c7ccccc7-8)c6ccc5c4c3)cc21 ; c1ccc(N(c2ccc3ccccc3c2)c2ccc3ccc4c5cccc(N(c6ccccc6)c6ccc7ccccc7c6)c5ccc4c3c2)cc1]

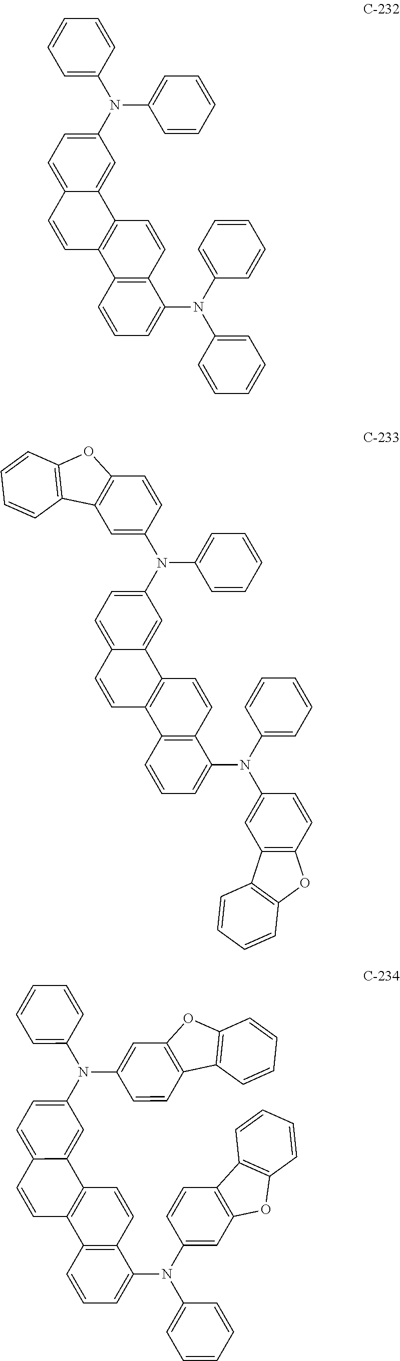 [SMILES: c1ccc(N(c2ccccc2)c2ccc3ccc4c5cccc(N(c6ccccc6)c6ccccc6)c5ccc4c3c2)cc1 ; c1ccc(N(c2ccc3ccc4c5cccc(N(c6ccccc6)c6ccc7oc8ccccc8c7c6)c5ccc4c3c2)c2ccc3oc4ccccc4c3c2)cc1 ; c1ccc(N(c2ccc3c(c2)oc2ccccc23)c2ccc3ccc4c5cccc(N(c6ccccc6)c6ccc7c(c6)oc6ccccc67)c5ccc4c3c2)cc1]

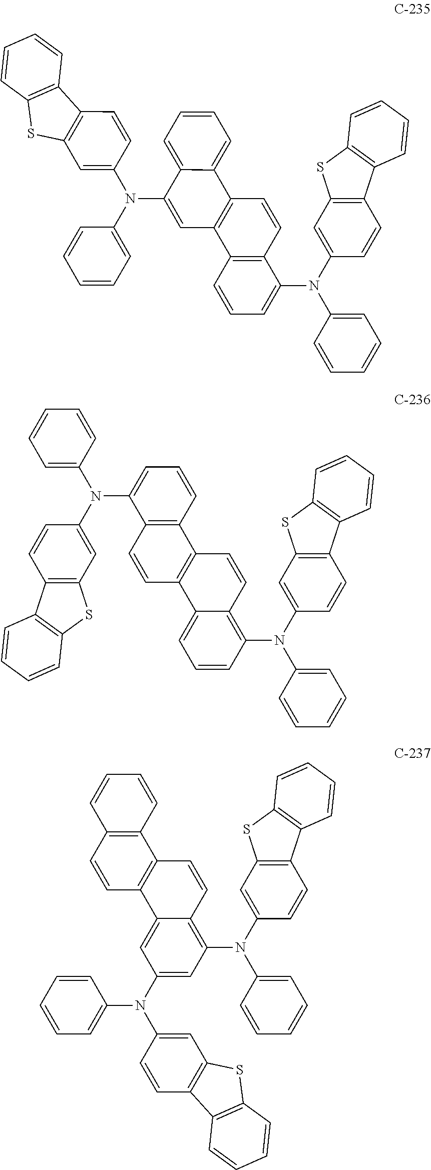

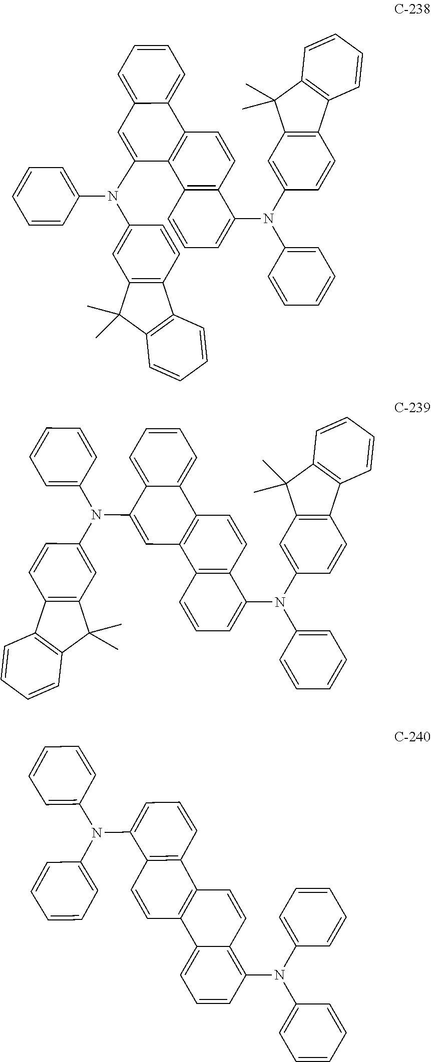 [SMILES: CC1(C)c2ccccc2-c2ccc(N(c3ccccc3)c3cccc4c3ccc3c5ccccc5cc(N(c5ccccc5)c5ccc6c(c5)C(C)(C)c5ccccc5-6)c43)cc21 ; CC1(C)c2ccccc2-c2ccc(N(c3ccccc3)c3cc4c5cccc(N(c6ccccc6)c6ccc7c(c6)C(C)(C)c6ccccc6-7)c5ccc4c4ccccc34)cc21 ; c1ccc(N(c2ccccc2)c2cccc3c2ccc2c4cccc(N(c5ccccc5)c5ccccc5)c4ccc32)cc1]

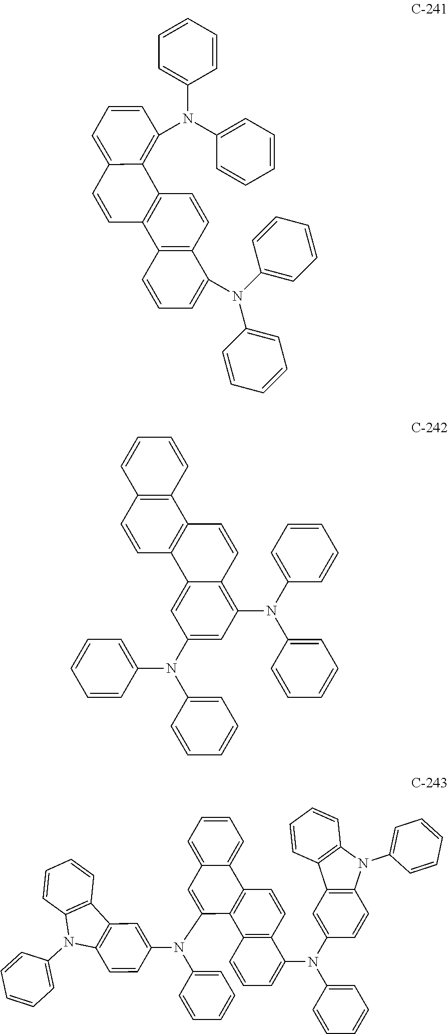 [SMILES: c1ccc(N(c2ccccc2)c2cccc3c2ccc2c3ccc3cccc(N(c4ccccc4)c4ccccc4)c32)cc1 ; c1ccc(N(c2ccccc2)c2cc(N(c3ccccc3)c3ccccc3)c3ccc4c5ccccc5ccc4c3c2)cc1 ; c1ccc(N(c2ccc3c(c2)c2ccccc2n3-c2ccccc2)c2cccc3c2ccc2c4ccccc4cc(N(c4ccccc4)c4ccc5c(c4)c4ccccc4n5-c4ccccc4)c32)cc1]

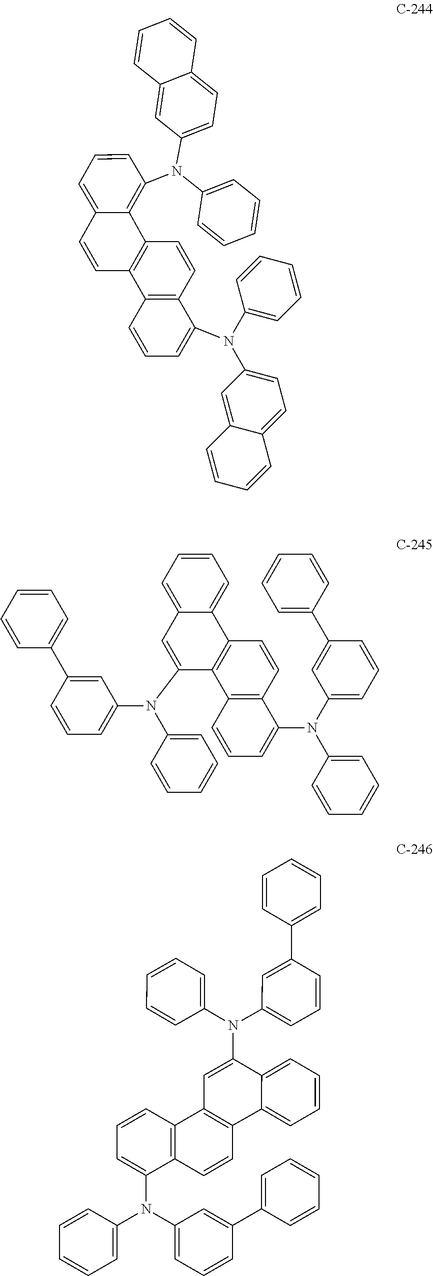 [SMILES: c1ccc(N(c2ccc3ccccc3c2)c2cccc3c2ccc2c3ccc3cccc(N(c4ccccc4)c4ccc5ccccc5c4)c32)cc1 ; c1ccc(-c2cccc(N(c3ccccc3)c3cccc4c3ccc3c5ccccc5cc(N(c5ccccc5)c5cccc(-c6ccccc6)c5)c43)c2)cc1 ; c1ccc(-c2cccc(N(c3ccccc3)c3cc4c5cccc(N(c6ccccc6)c6cccc(-c7ccccc7)c6)c5ccc4c4ccccc34)c2)cc1]

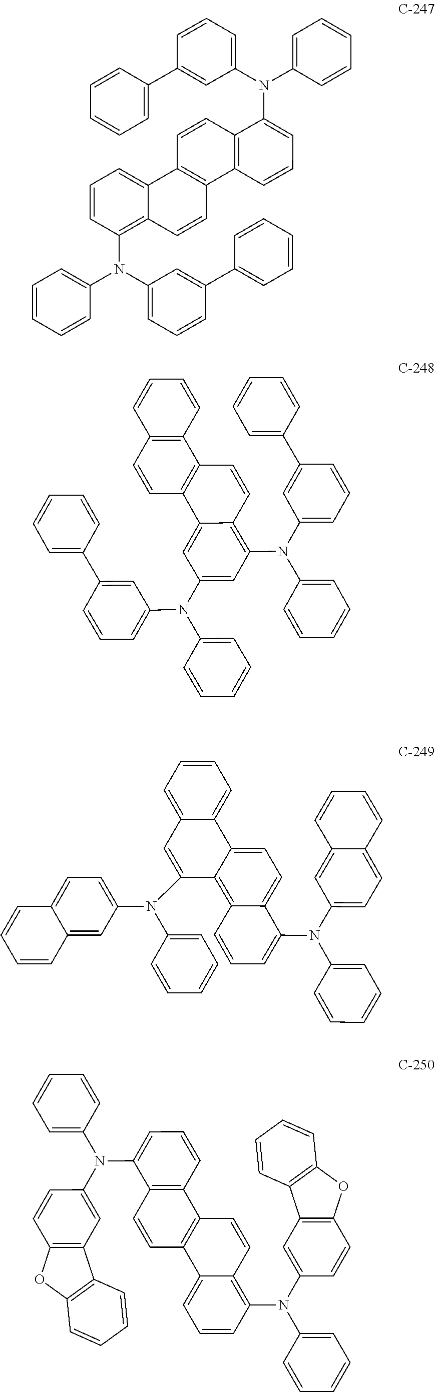

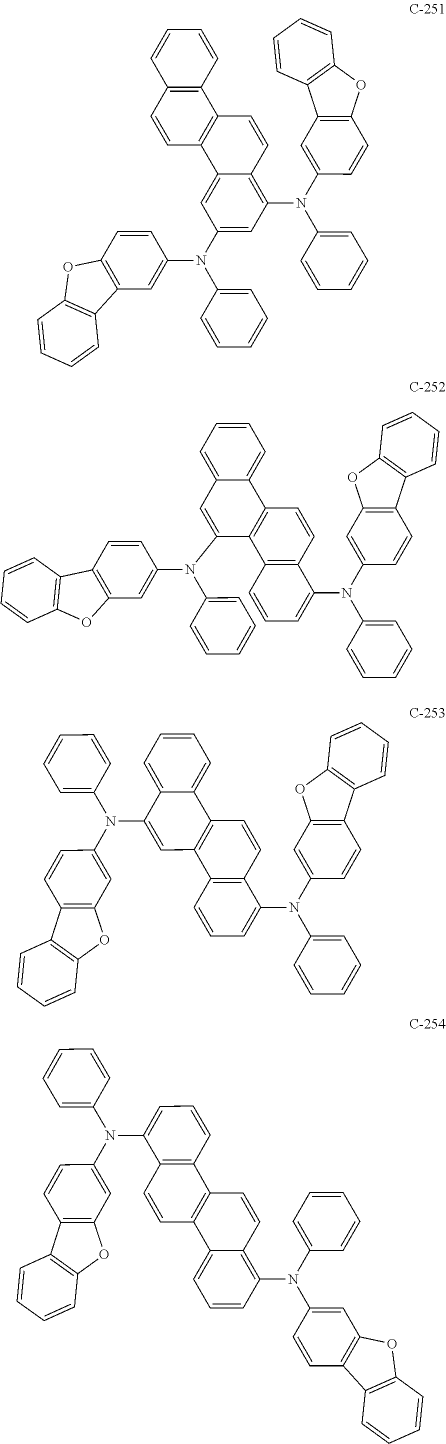

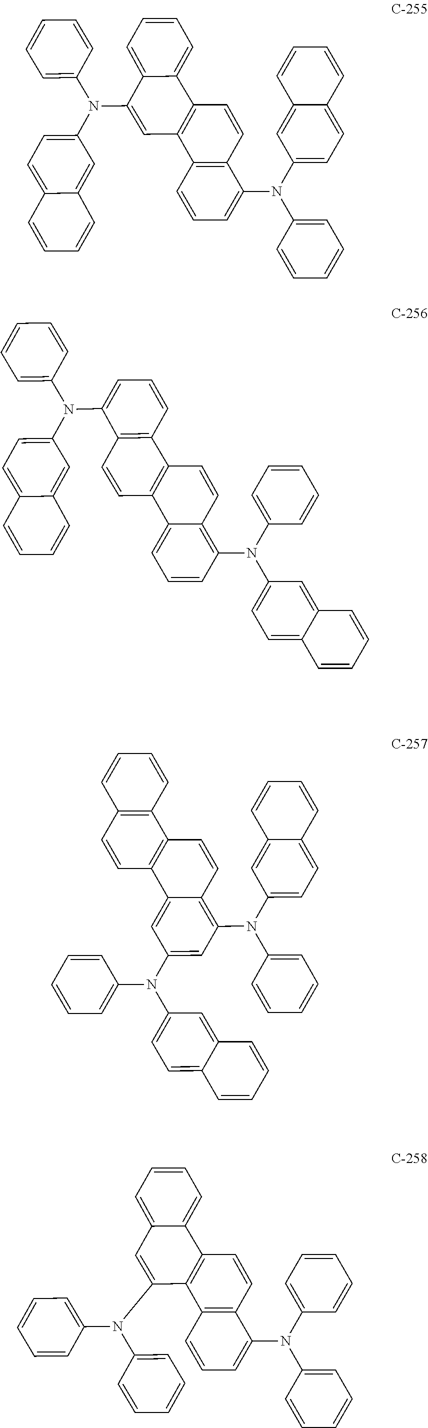 [SMILES: c1ccc(N(c2ccc3ccccc3c2)c2cc3c4cccc(N(c5ccccc5)c5ccc6ccccc6c5)c4ccc3c3ccccc23)cc1 ; c1ccc(N(c2ccc3ccccc3c2)c2cccc3c2ccc2c4cccc(N(c5ccccc5)c5ccc6ccccc6c5)c4ccc32)cc1 ; c1ccc(N(c2ccc3ccccc3c2)c2cc(N(c3ccccc3)c3ccc4ccccc4c3)c3ccc4c5ccccc5ccc4c3c2)cc1 ; c1ccc(N(c2ccccc2)c2cccc3c2ccc2c4ccccc4cc(N(c4ccccc4)c4ccccc4)c32)cc1]

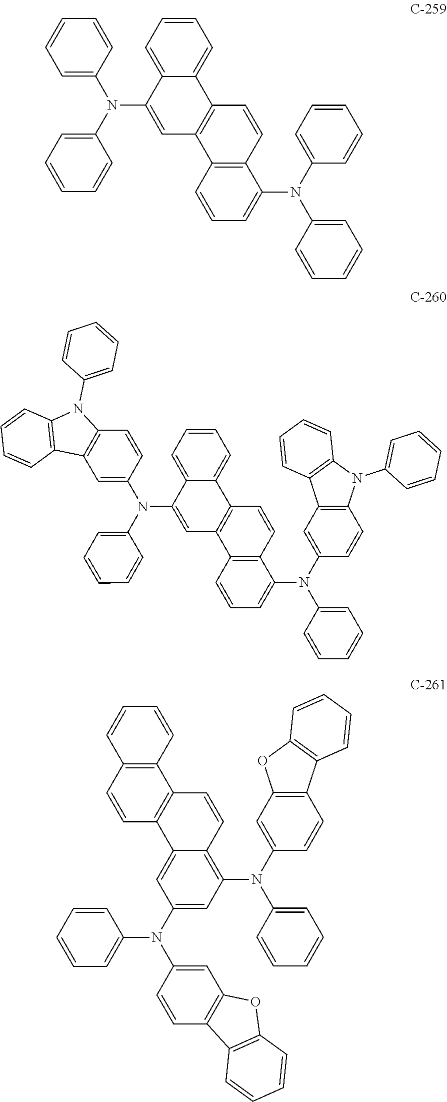

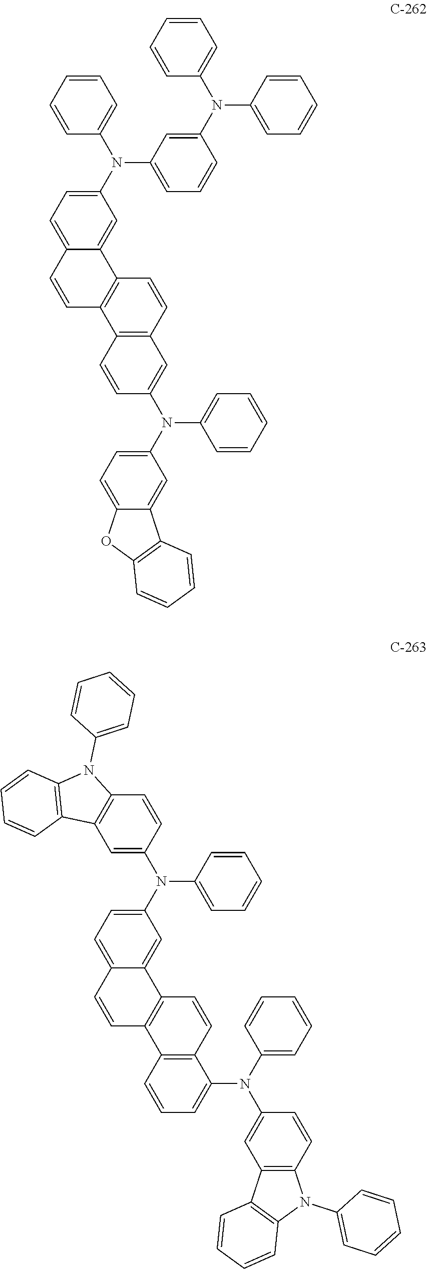 [SMILES: c1ccc(N(c2ccccc2)c2cccc(N(c3ccccc3)c3ccc4ccc5c6ccc(N(c7ccccc7)c7ccc8oc9ccccc9c8c7)cc6ccc5c4c3)c2)cc1 ; c1ccc(N(c2ccc3ccc4c5cccc(N(c6ccccc6)c6ccc7c(c6)c6ccccc6n7-c6ccccc6)c5ccc4c3c2)c2ccc3c(c2)c2ccccc2n3-c2ccccc2)cc1]

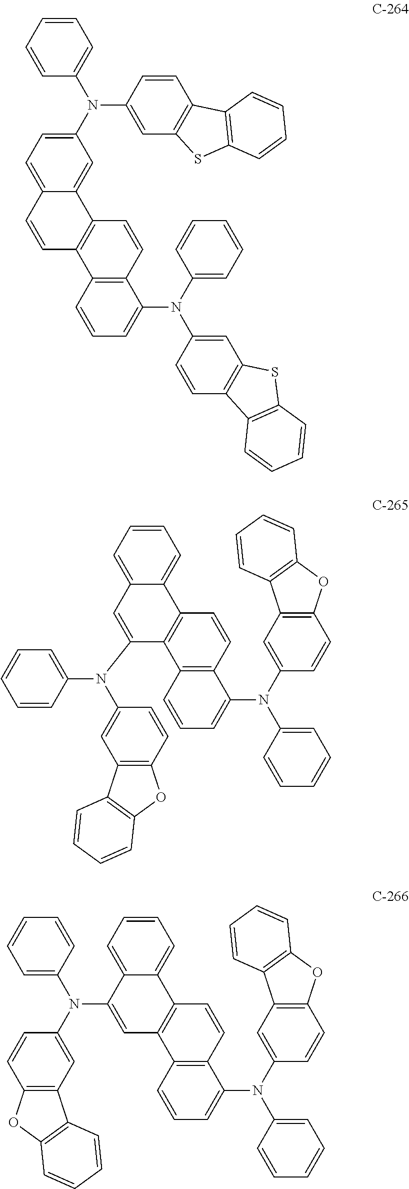

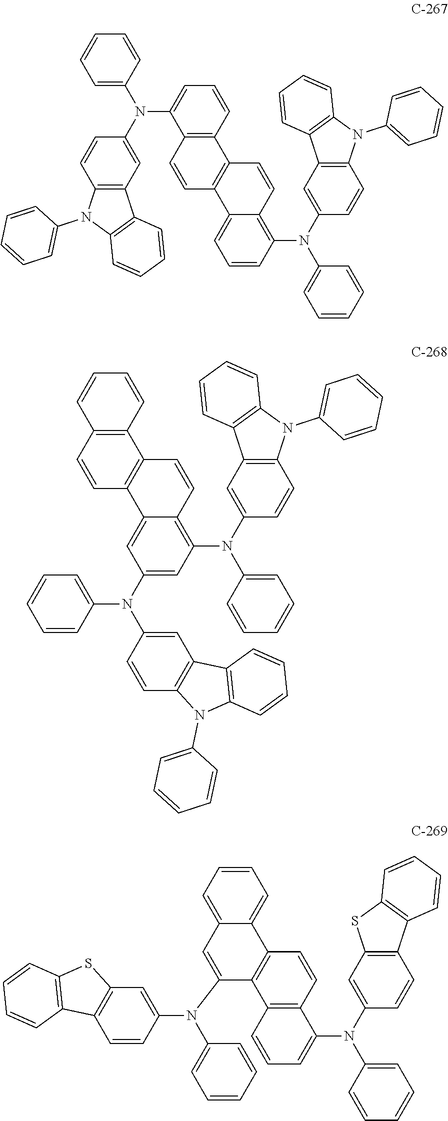 [SMILES: c1ccc(N(c2ccc3c(c2)c2ccccc2n3-c2ccccc2)c2cccc3c2ccc2c4cccc(N(c5ccccc5)c5ccc6c(c5)c5ccccc5n6-c5ccccc5)c4ccc32)cc1 ; c1ccc(N(c2cc(N(c3ccccc3)c3ccc4c(c3)c3ccccc3n4-c3ccccc3)c3ccc4c5ccccc5ccc4c3c2)c2ccc3c(c2)c2ccccc2n3-c2ccccc2)cc1 ; c1ccc(N(c2ccc3c(c2)sc2ccccc23)c2cccc3c2ccc2c4ccccc4cc(N(c4ccccc4)c4ccc5c(c4)sc4ccccc45)c32)cc1]

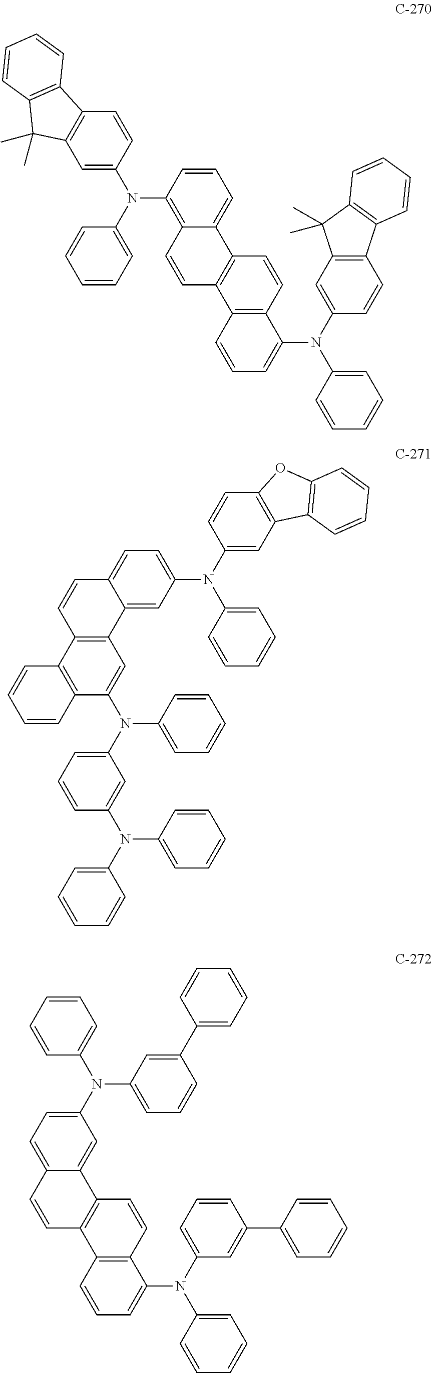

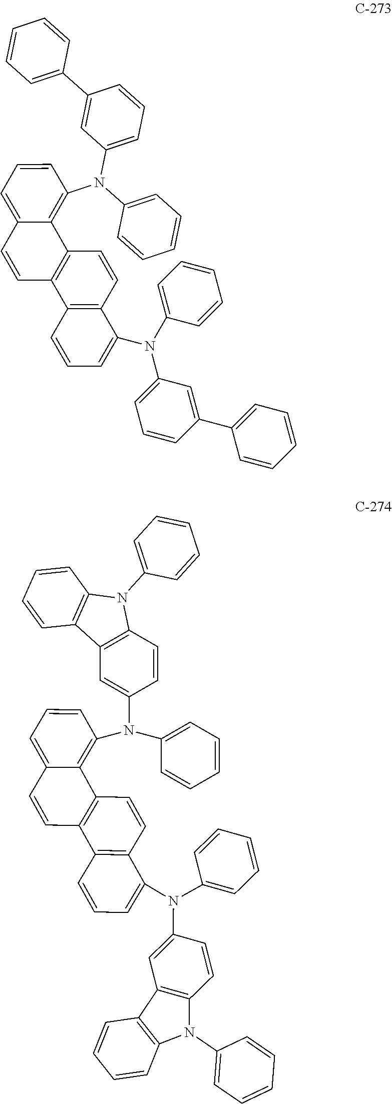 [SMILES: c1ccc(-c2cccc(N(c3ccccc3)c3cccc4c3ccc3c4ccc4cccc(N(c5ccccc5)c5cccc(-c6ccccc6)c5)c43)c2)cc1 ; c1ccc(N(c2ccc3c(c2)c2ccccc2n3-c2ccccc2)c2cccc3c2ccc2c3ccc3cccc(N(c4ccccc4)c4ccc5c(c4)c4ccccc4n5-c4ccccc4)c32)cc1]

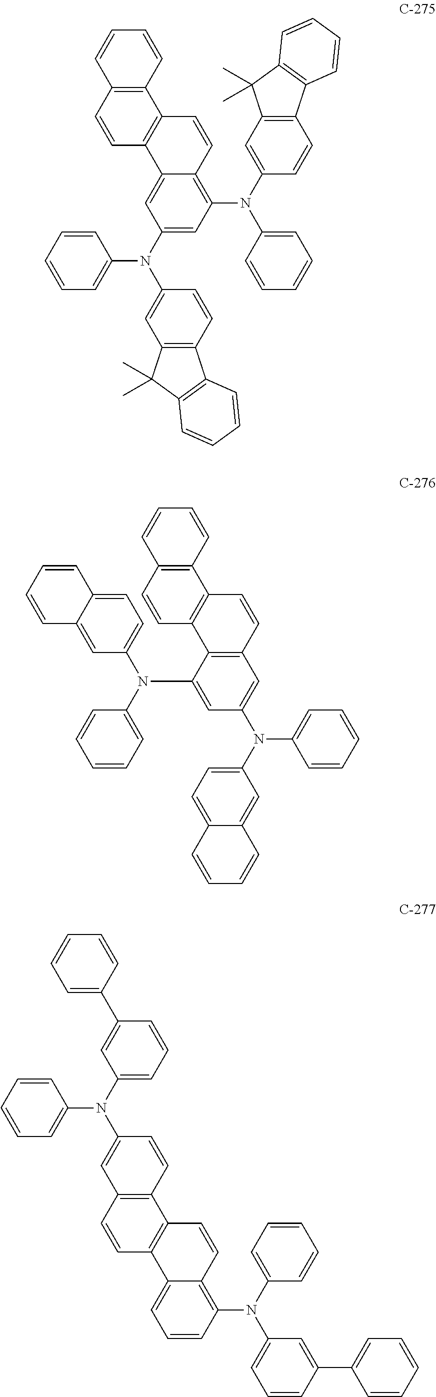 [SMILES: CC1(C)c2ccccc2-c2ccc(N(c3ccccc3)c3cc(N(c4ccccc4)c4ccc5c(c4)C(C)(C)c4ccccc4-5)c4ccc5c6ccccc6ccc5c4c3)cc21 ; c1ccc(N(c2ccc3ccccc3c2)c2cc(N(c3ccccc3)c3ccc4ccccc4c3)c3c(ccc4c5ccccc5ccc43)c2)cc1 ; c1ccc(-c2cccc(N(c3ccccc3)c3ccc4c(ccc5c6cccc(N(c7ccccc7)c7cccc(-c8ccccc8)c7)c6ccc45)c3)c2)cc1]

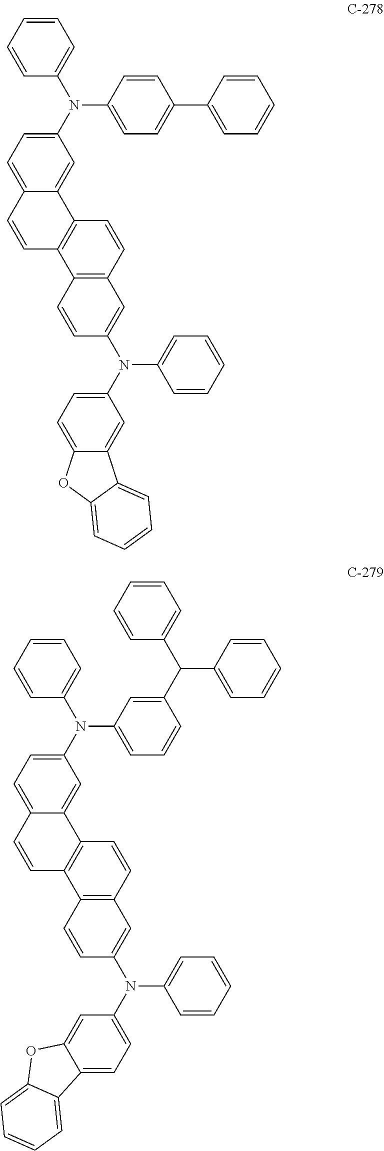

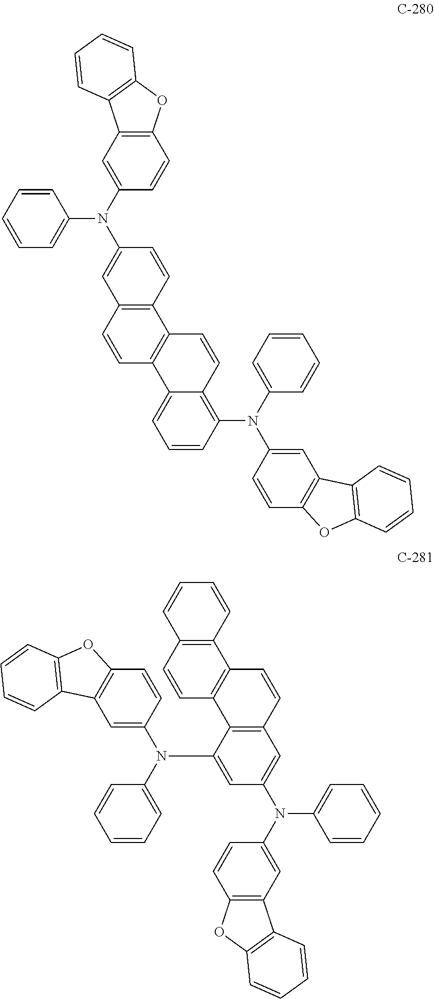 [SMILES: c1ccc(N(c2ccc3c(ccc4c5cccc(N(c6ccccc6)c6ccc7oc8ccccc8c7c6)c5ccc34)c2)c2ccc3oc4ccccc4c3c2)cc1 ; c1ccc(N(c2cc(N(c3ccccc3)c3ccc4oc5ccccc5c4c3)c3c(ccc4c5ccccc5ccc43)c2)c2ccc3oc4ccccc4c3c2)cc1]

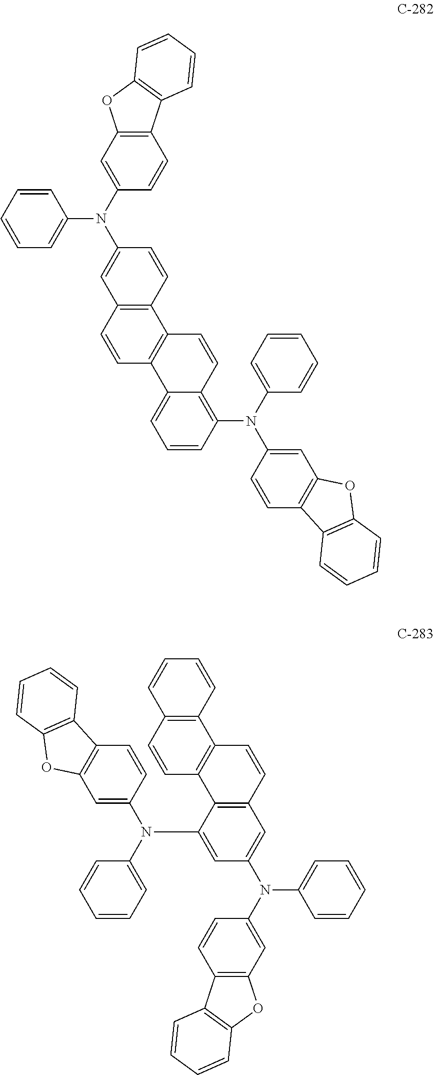 [SMILES: c1ccc(N(c2ccc3c(ccc4c5cccc(N(c6ccccc6)c6ccc7c(c6)oc6ccccc67)c5ccc34)c2)c2ccc3c(c2)oc2ccccc23)cc1 ; c1ccc(N(c2cc(N(c3ccccc3)c3ccc4c(c3)oc3ccccc34)c3c(ccc4c5ccccc5ccc43)c2)c2ccc3c(c2)oc2ccccc23)cc1]

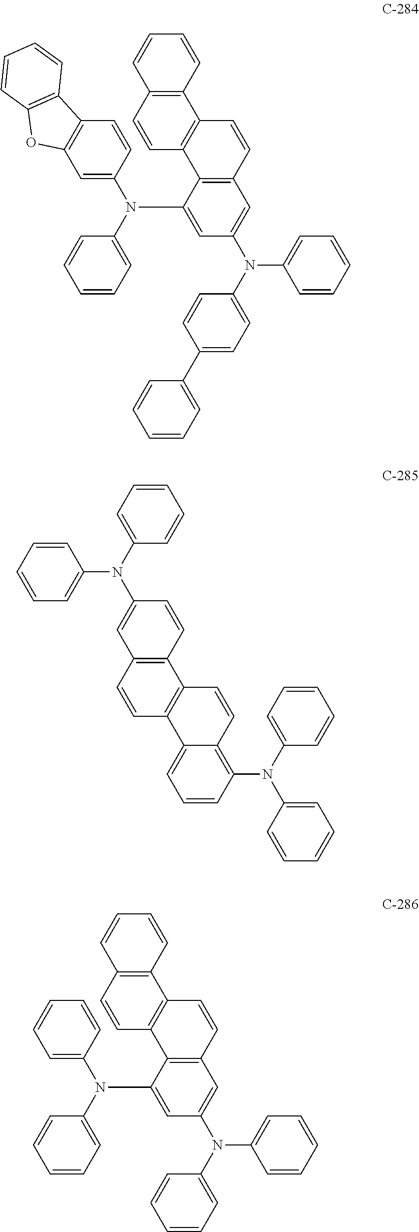 [SMILES: c1ccc(-c2ccc(N(c3ccccc3)c3cc(N(c4ccccc4)c4ccc5c(c4)oc4ccccc45)c4c(ccc5c6ccccc6ccc54)c3)cc2)cc1 ; c1ccc(N(c2ccccc2)c2ccc3c(ccc4c5cccc(N(c6ccccc6)c6ccccc6)c5ccc34)c2)cc1 ; c1ccc(N(c2ccccc2)c2cc(N(c3ccccc3)c3ccccc3)c3c(ccc4c5ccccc5ccc43)c2)cc1]

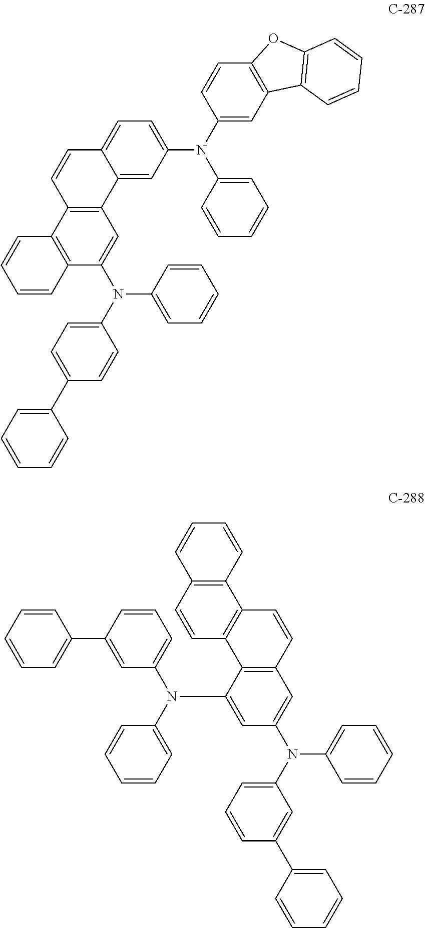 [SMILES: c1ccc(-c2ccc(N(c3ccccc3)c3cc4c5cc(N(c6ccccc6)c6ccc7oc8ccccc8c7c6)ccc5ccc4c4ccccc34)cc2)cc1 ; c1ccc(-c2cccc(N(c3ccccc3)c3cc(N(c4ccccc4)c4cccc(-c5ccccc5)c4)c4c(ccc5c6ccccc6ccc54)c3)c2)cc1]

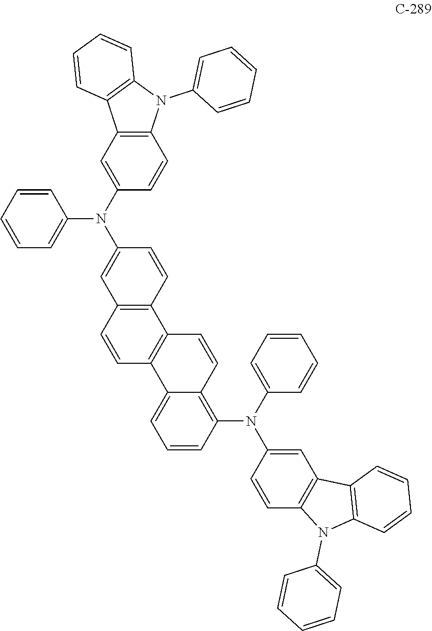 [SMILES: c1ccc(N(c2ccc3c(ccc4c5cccc(N(c6ccccc6)c6ccc7c(c6)c6ccccc6n7-c6ccccc6)c5ccc34)c2)c2ccc3c(c2)c2ccccc2n3-c2ccccc2)cc1]

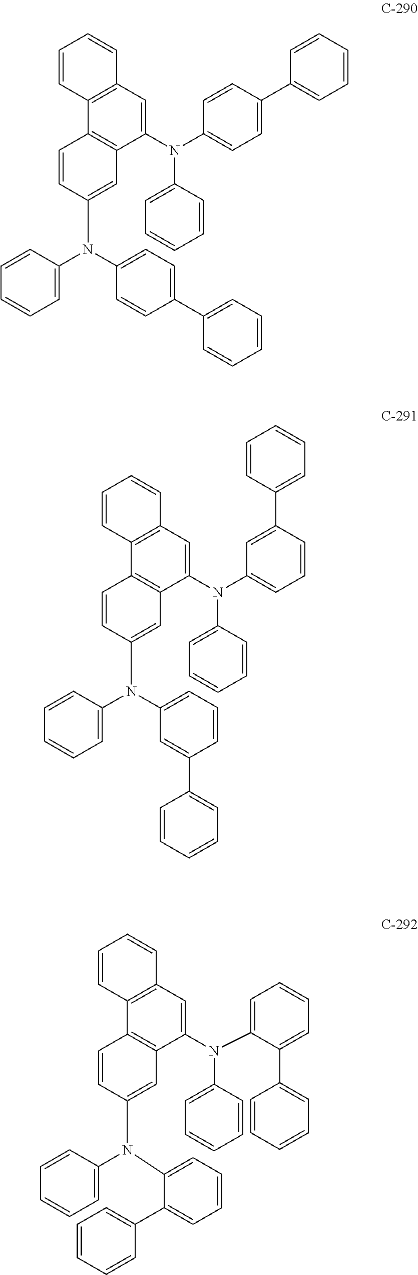 [SMILES: c1ccc(-c2ccc(N(c3ccccc3)c3ccc4c(c3)c(N(c3ccccc3)c3ccc(-c5ccccc5)cc3)cc3ccccc34)cc2)cc1 ; c1ccc(-c2cccc(N(c3ccccc3)c3ccc4c(c3)c(N(c3ccccc3)c3cccc(-c5ccccc5)c3)cc3ccccc34)c2)cc1 ; c1ccc(-c2ccccc2N(c2ccccc2)c2ccc3c(c2)c(N(c2ccccc2)c2ccccc2-c2ccccc2)cc2ccccc23)cc1]

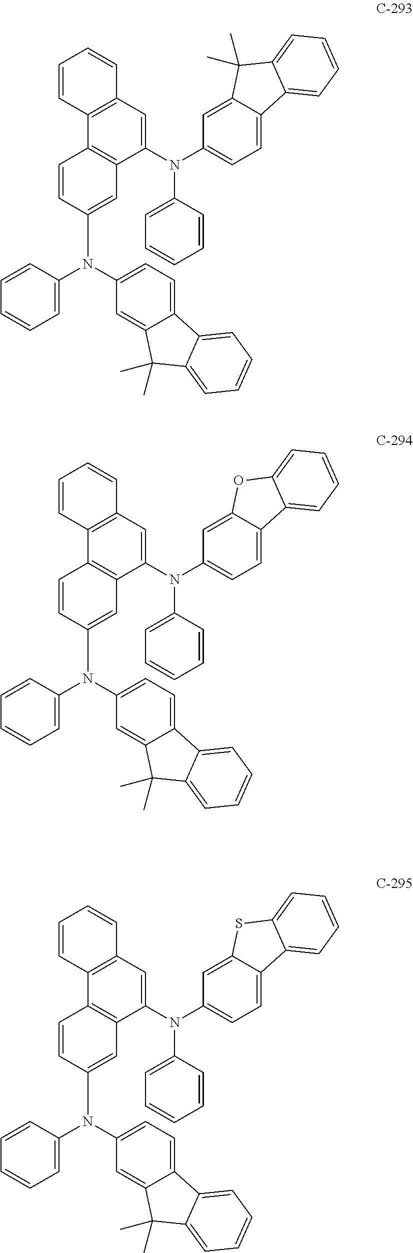 [SMILES: CC1(C)c2ccccc2-c2ccc(N(c3ccccc3)c3ccc4c(c3)c(N(c3ccccc3)c3ccc5c(c3)C(C)(C)c3ccccc3-5)cc3ccccc34)cc21 ; CC1(C)c2ccccc2-c2ccc(N(c3ccccc3)c3ccc4c(c3)c(N(c3ccccc3)c3ccc5c(c3)oc3ccccc35)cc3ccccc34)cc21 ; CC1(C)c2ccccc2-c2ccc(N(c3ccccc3)c3ccc4c(c3)c(N(c3ccccc3)c3ccc5c(c3)sc3ccccc35)cc3ccccc34)cc21]

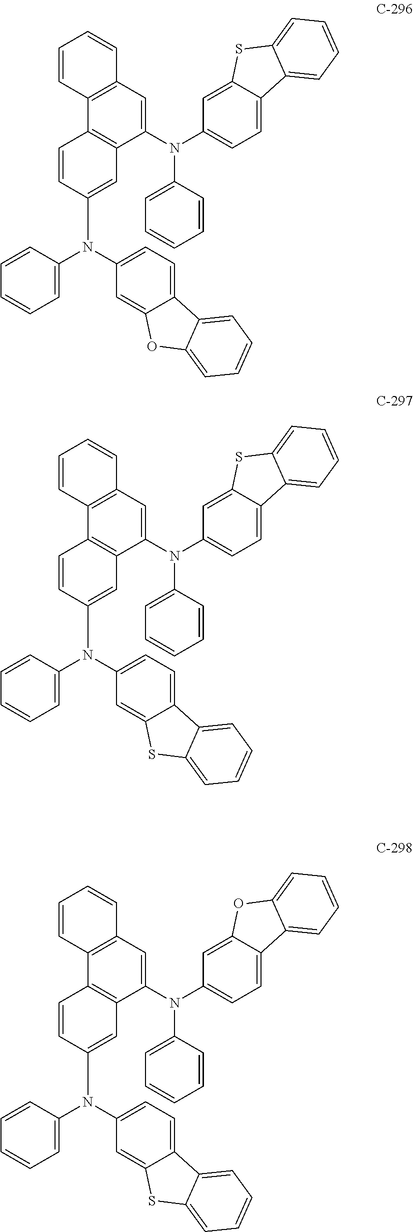 [SMILES: c1ccc(N(c2ccc3c(c2)oc2ccccc23)c2ccc3c(c2)c(N(c2ccccc2)c2ccc4c(c2)sc2ccccc24)cc2ccccc23)cc1 ; c1ccc(N(c2ccc3c(c2)sc2ccccc23)c2ccc3c(c2)c(N(c2ccccc2)c2ccc4c(c2)sc2ccccc24)cc2ccccc23)cc1 ; c1ccc(N(c2ccc3c(c2)sc2ccccc23)c2ccc3c(c2)c(N(c2ccccc2)c2ccc4c(c2)oc2ccccc24)cc2ccccc23)cc1]

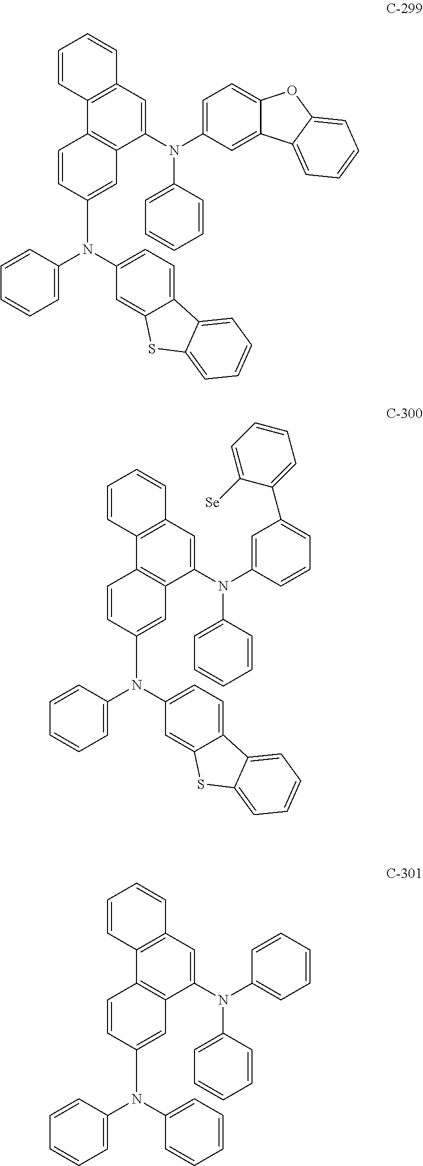

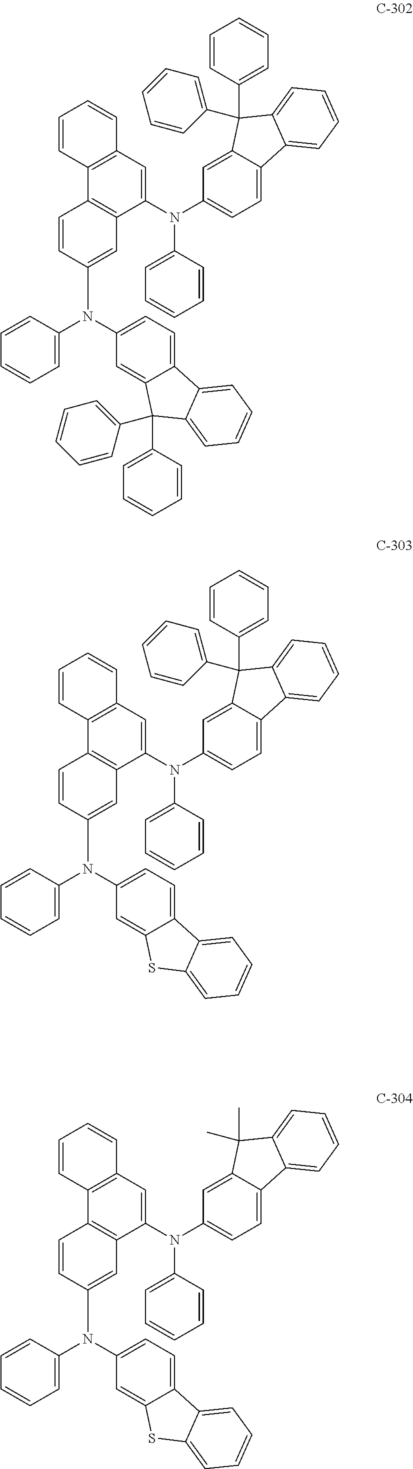 [SMILES: c1ccc(N(c2ccc3c(c2)C(c2ccccc2)(c2ccccc2)c2ccccc2-3)c2ccc3c(c2)c(N(c2ccccc2)c2ccc4c(c2)C(c2ccccc2)(c2ccccc2)c2ccccc2-4)cc2ccccc23)cc1 ; c1ccc(N(c2ccc3c(c2)sc2ccccc23)c2ccc3c(c2)c(N(c2ccccc2)c2ccc4c(c2)C(c2ccccc2)(c2ccccc2)c2ccccc2-4)cc2ccccc23)cc1 ; CC1(C)c2ccccc2-c2ccc(N(c3ccccc3)c3cc4ccccc4c4ccc(N(c5ccccc5)c5ccc6c(c5)sc5ccccc56)cc34)cc21]

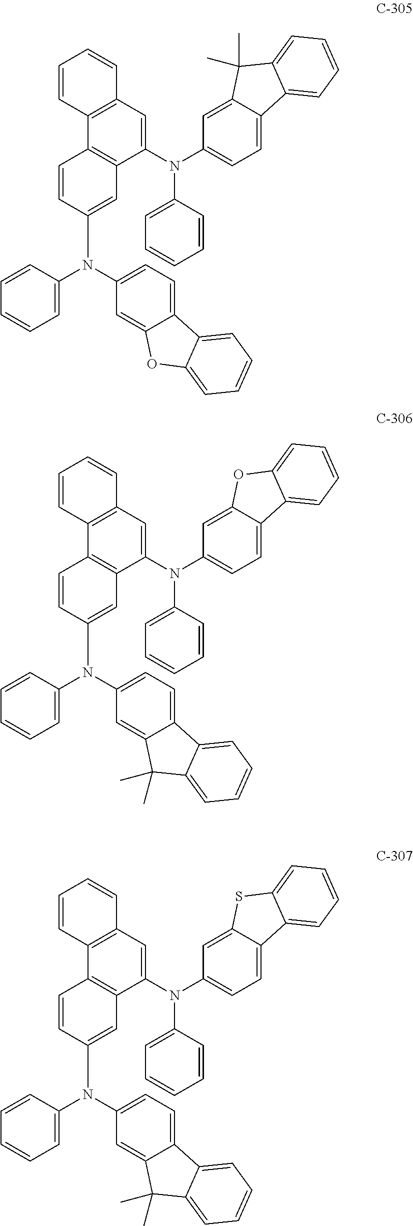 [SMILES: CC1(C)c2ccccc2-c2ccc(N(c3ccccc3)c3cc4ccccc4c4ccc(N(c5ccccc5)c5ccc6c(c5)oc5ccccc56)cc34)cc21 ; CC1(C)c2ccccc2-c2ccc(N(c3ccccc3)c3ccc4c(c3)c(N(c3ccccc3)c3ccc5c(c3)oc3ccccc35)cc3ccccc34)cc21 ; CC1(C)c2ccccc2-c2ccc(N(c3ccccc3)c3ccc4c(c3)c(N(c3ccccc3)c3ccc5c(c3)sc3ccccc35)cc3ccccc34)cc21]

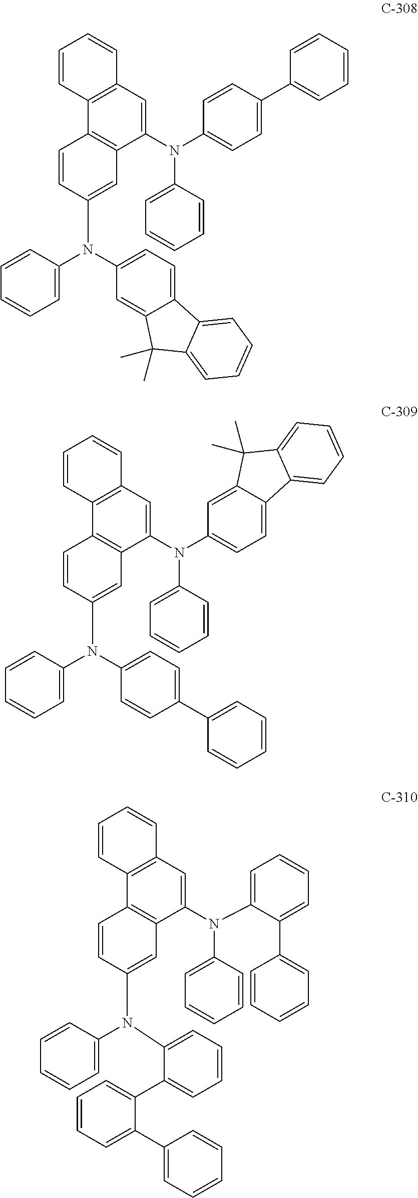

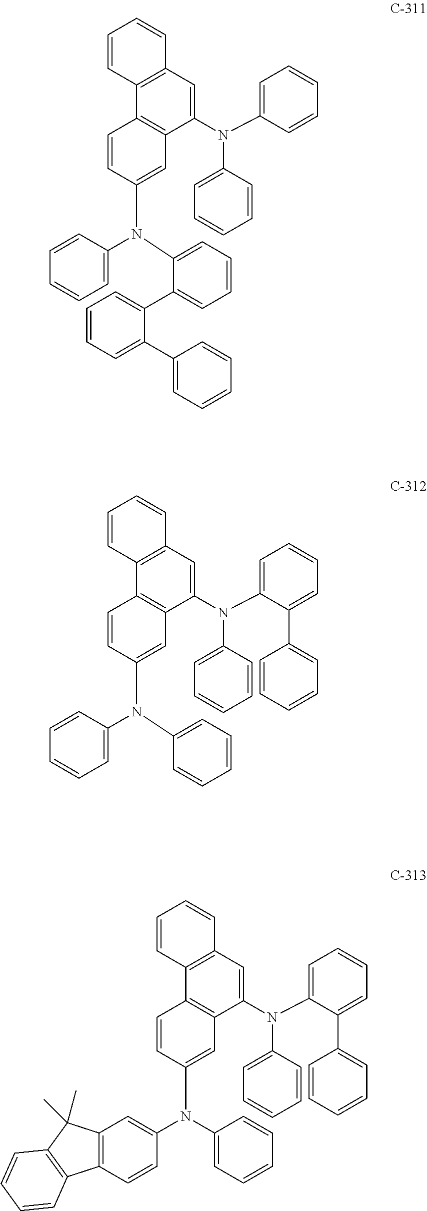 [SMILES: c1ccc(-c2ccccc2-c2ccccc2N(c2ccccc2)c2ccc3c(c2)c(N(c2ccccc2)c2ccccc2)cc2ccccc23)cc1 ; c1ccc(-c2ccccc2N(c2ccccc2)c2cc3ccccc3c3ccc(N(c4ccccc4)c4ccccc4)cc23)cc1 ; CC1(C)c2ccccc2-c2ccc(N(c3ccccc3)c3ccc4c(c3)c(N(c3ccccc3)c3ccccc3-c3ccccc3)cc3ccccc34)cc21]

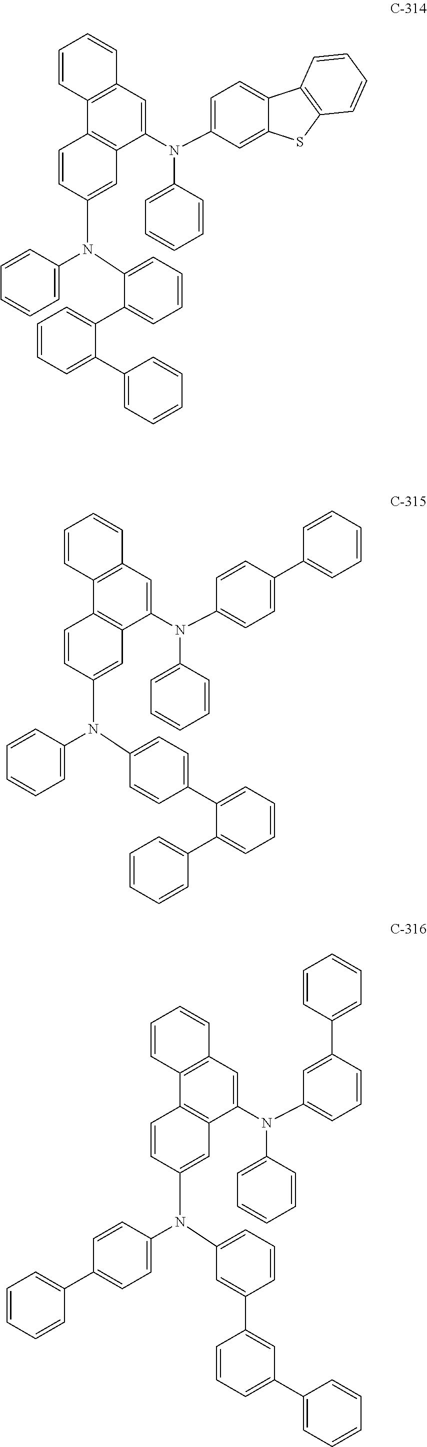 [SMILES: c1ccc(-c2ccccc2-c2ccccc2N(c2ccccc2)c2ccc3c(c2)c(N(c2ccccc2)c2ccc4c(c2)sc2ccccc24)cc2ccccc23)cc1 ; c1ccc(-c2ccc(N(c3ccccc3)c3cc4ccccc4c4ccc(N(c5ccccc5)c5ccc(-c6ccccc6-c6ccccc6)cc5)cc34)cc2)cc1 ; c1ccc(-c2ccc(N(c3cccc(-c4cccc(-c5ccccc5)c4)c3)c3ccc4c(c3)c(N(c3ccccc3)c3cccc(-c5ccccc5)c3)cc3ccccc34)cc2)cc1]

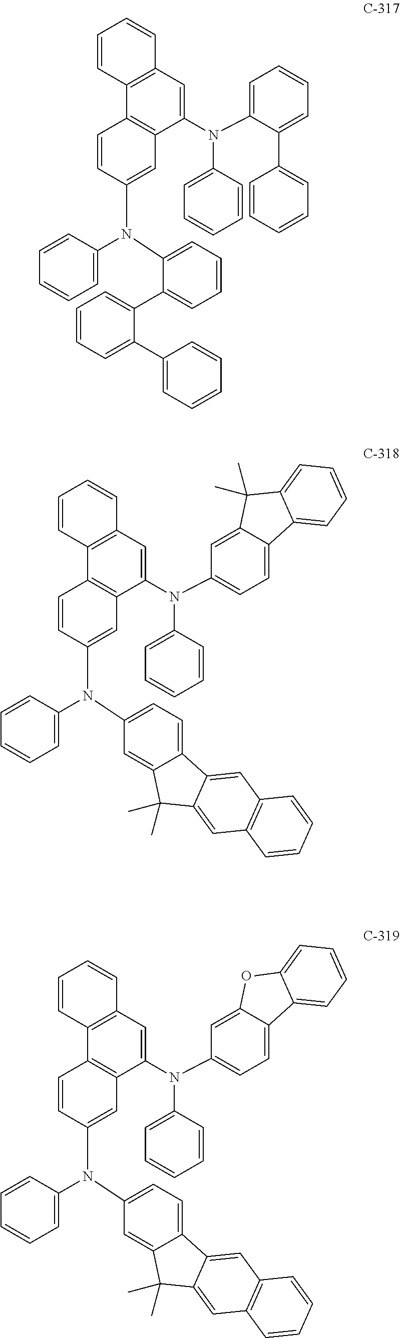 [SMILES: c1ccc(-c2ccccc2-c2ccccc2N(c2ccccc2)c2ccc3c(c2)c(N(c2ccccc2)c2ccccc2-c2ccccc2)cc2ccccc23)cc1 ; CC1(C)c2ccccc2-c2ccc(N(c3ccccc3)c3cc4ccccc4c4ccc(N(c5ccccc5)c5ccc6c(c5)C(C)(C)c5cc7ccccc7cc5-6)cc34)cc21 ; CC1(C)c2cc(N(c3ccccc3)c3ccc4c(c3)c(N(c3ccccc3)c3ccc5c(c3)oc3ccccc35)cc3ccccc34)ccc2-c2cc3ccccc3cc21]

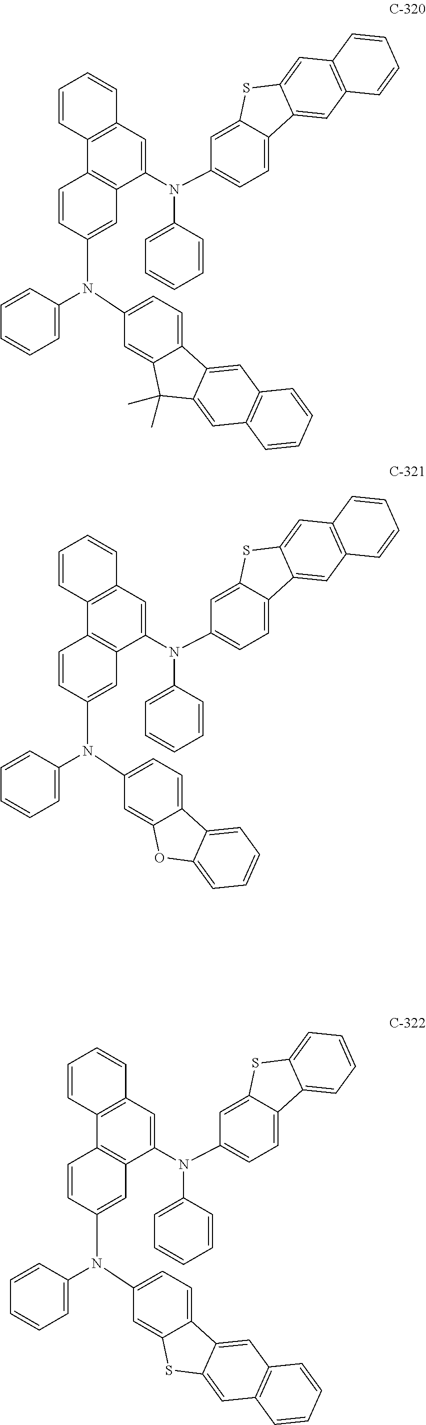 [SMILES: CC1(C)c2cc(N(c3ccccc3)c3ccc4c(c3)c(N(c3ccccc3)c3ccc5c(c3)sc3cc6ccccc6cc35)cc3ccccc34)ccc2-c2cc3ccccc3cc21 ; c1ccc(N(c2ccc3c(c2)oc2ccccc23)c2ccc3c(c2)c(N(c2ccccc2)c2ccc4c(c2)sc2cc5ccccc5cc24)cc2ccccc23)cc1 ; c1ccc(N(c2ccc3c(c2)sc2cc4ccccc4cc23)c2ccc3c(c2)c(N(c2ccccc2)c2ccc4c(c2)sc2ccccc24)cc2ccccc23)cc1]

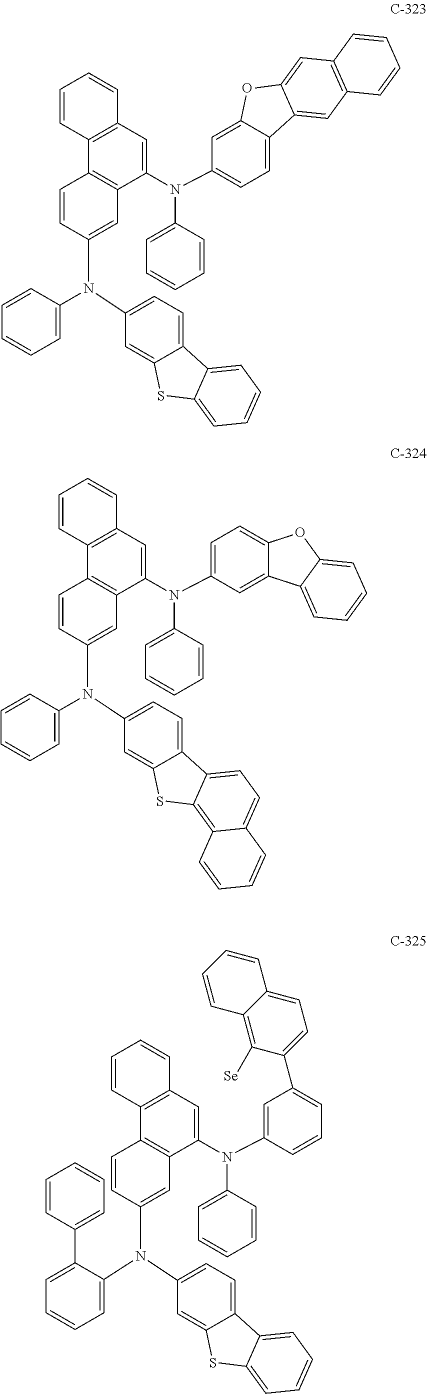

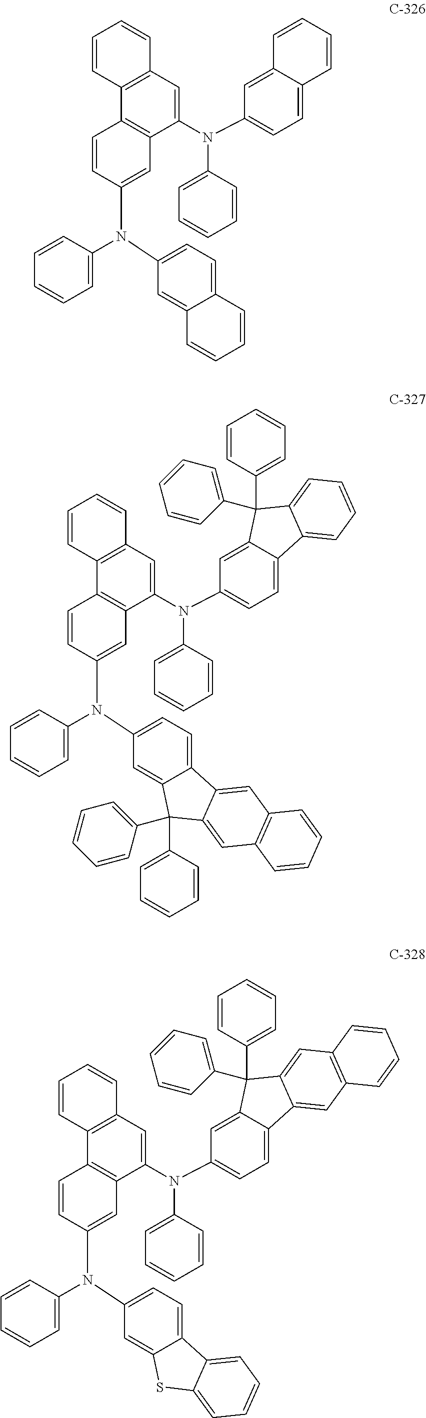 [SMILES: c1ccc(N(c2ccc3ccccc3c2)c2ccc3c(c2)c(N(c2ccccc2)c2ccc4ccccc4c2)cc2ccccc23)cc1 ; c1ccc(N(c2ccc3c(c2)C(c2ccccc2)(c2ccccc2)c2cc4ccccc4cc2-3)c2ccc3c(c2)c(N(c2ccccc2)c2ccc4c(c2)C(c2ccccc2)(c2ccccc2)c2ccccc2-4)cc2ccccc23)cc1 ; c1ccc(N(c2ccc3c(c2)sc2ccccc23)c2ccc3c(c2)c(N(c2ccccc2)c2ccc4c(c2)C(c2ccccc2)(c2ccccc2)c2cc5ccccc5cc2-4)cc2ccccc23)cc1]

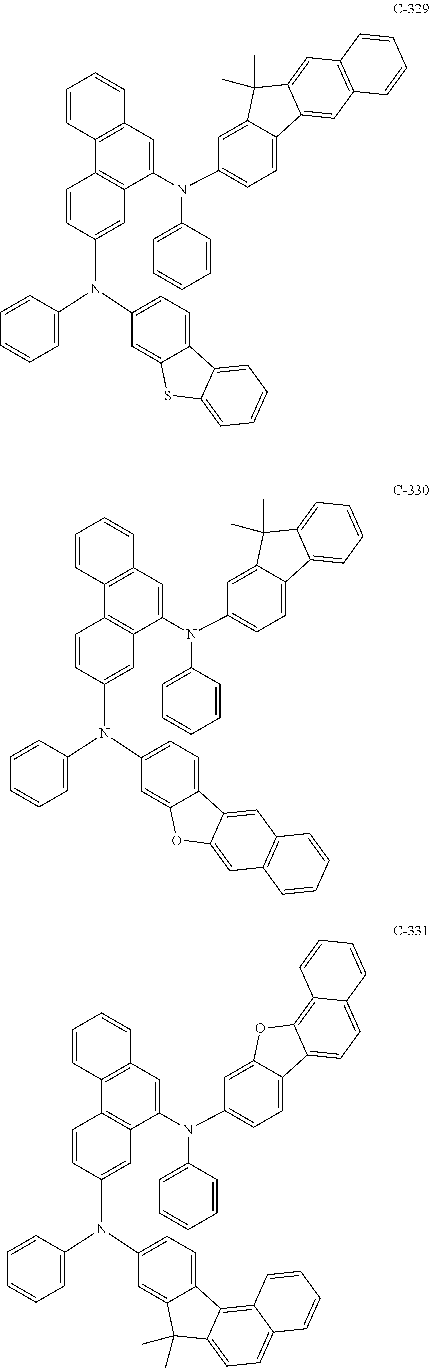 [SMILES: CC1(C)c2cc(N(c3ccccc3)c3cc4ccccc4c4ccc(N(c5ccccc5)c5ccc6c(c5)sc5ccccc56)cc34)ccc2-c2cc3ccccc3cc21 ; CC1(C)c2ccccc2-c2ccc(N(c3ccccc3)c3cc4ccccc4c4ccc(N(c5ccccc5)c5ccc6c(c5)oc5cc7ccccc7cc56)cc34)cc21 ; CC1(C)c2cc(N(c3ccccc3)c3ccc4c(c3)c(N(c3ccccc3)c3ccc5c(c3)oc3c6ccccc6ccc53)cc3ccccc34)ccc2-c2c1ccc1ccccc21]

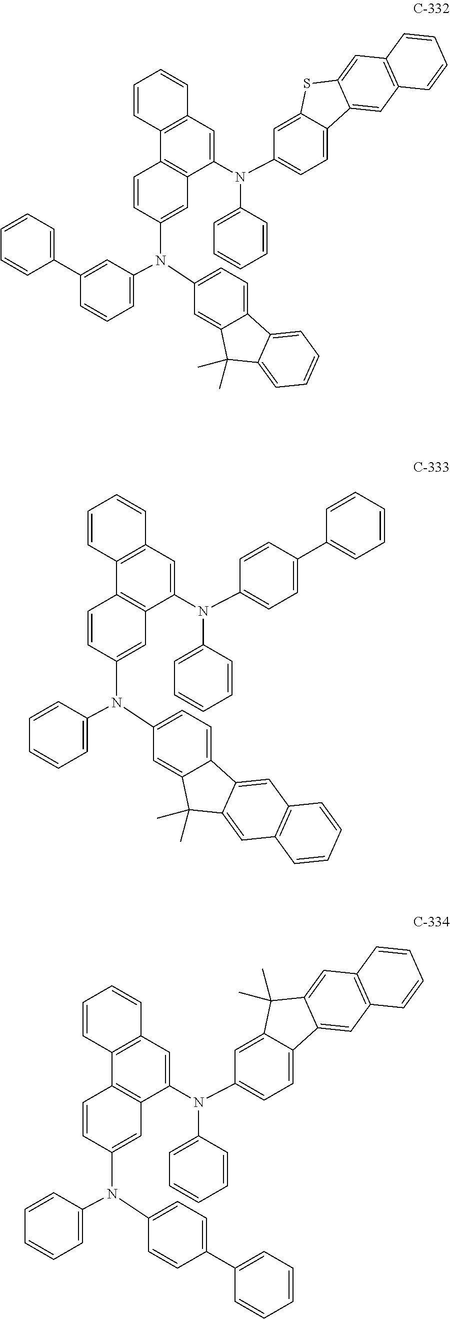 [SMILES: CC1(C)c2ccccc2-c2ccc(N(c3cccc(-c4ccccc4)c3)c3ccc4c(c3)c(N(c3ccccc3)c3ccc5c(c3)sc3cc6ccccc6cc35)cc3ccccc34)cc21 ; CC1(C)c2cc(N(c3ccccc3)c3ccc4c(c3)c(N(c3ccccc3)c3ccc(-c5ccccc5)cc3)cc3ccccc34)ccc2-c2cc3ccccc3cc21 ; CC1(C)c2cc(N(c3ccccc3)c3cc4ccccc4c4ccc(N(c5ccccc5)c5ccc(-c6ccccc6)cc5)cc34)ccc2-c2cc3ccccc3cc21]

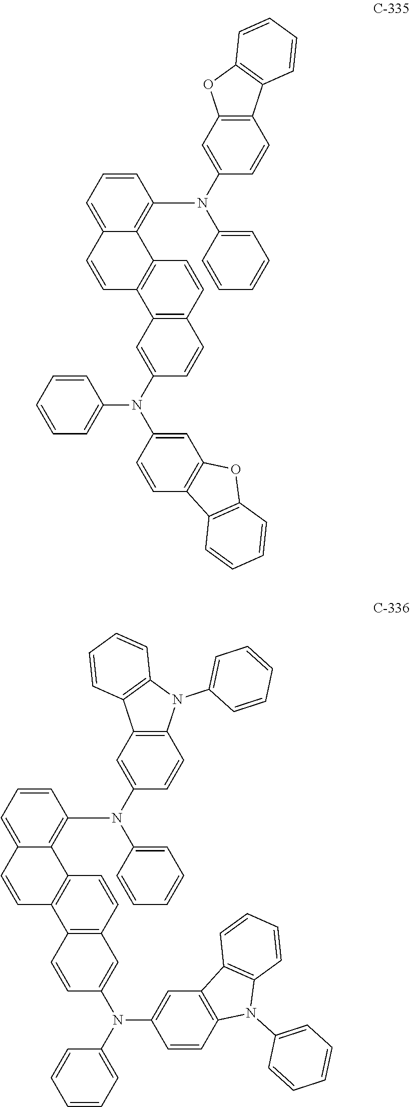 [SMILES: c1ccc(N(c2ccc3c(c2)oc2ccccc23)c2ccc3ccc4c(ccc5cccc(N(c6ccccc6)c6ccc7c(c6)oc6ccccc67)c54)c3c2)cc1 ; c1ccc(N(c2ccc3c(ccc4c3ccc3cccc(N(c5ccccc5)c5ccc6c(c5)c5ccccc5n6-c5ccccc5)c34)c2)c2ccc3c(c2)c2ccccc2n3-c2ccccc2)cc1]

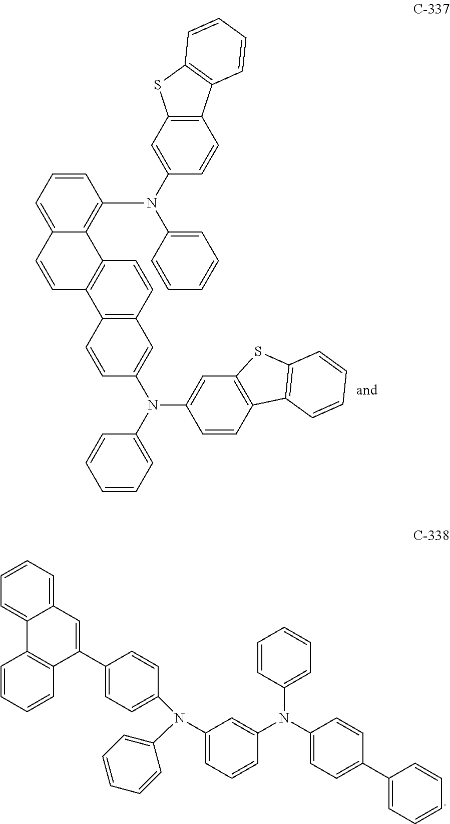 [SMILES: c1ccc(N(c2ccc3c(ccc4c3ccc3cccc(N(c5ccccc5)c5ccc6c(c5)sc5ccccc56)c34)c2)c2ccc3c(c2)sc2ccccc23)cc1 ; c1ccc(-c2ccc(N(c3ccccc3)c3cccc(N(c4ccccc4)c4ccc(-c5cc6ccccc6c6ccccc56)cc4)c3)cc2)cc1]

13. An organic electroluminescent device comprising the organic electroluminescent compound according to claim 11.
